(19) United States
(12) Patent Application Publication
(10) Pub. No.: US 2022/0052278 A1
(43) Pub. Date: Feb. 17, 2022

(54) DISPLAY APPARATUS

(71) Applicant: Samsung Electronics Co., Ltd., Suwon-si (KR)

(72) Inventors: Banglin Lee, Suwon-si (KR); Byungjoon KANG, Seoul (KR); Seungyeon Kwak, Suwon-si (KR); Kum Hee Lee, Suwon-si (KR); Sunghun Lee, Hwaseong-si (KR); Shingo ISHIHARA, Suwon-si (KR); Yong Joo Lee, Suwon-si (KR); Jeoungin Yi, Seoul (KR); Byoungki Choi, Hwaseong-si (KR); Kyuyoung Hwang, Anyang-si (KR)

(21) Appl. No.: 17/379,314

(22) Filed: Jul. 19, 2021

(30) Foreign Application Priority Data
Jul. 21, 2020 (KR) 10-2020-0090567
Jul. 15, 2021 (KR) 10-2021-0093126

(51) Int. Cl. H01L 51/00; H01L 27/32; H01L 51/50; C07F 15/00; C09K 11/06

(52) U.S. Cl. CPC H01L 51/0094; H01L 27/322; H01L 51/5268; C07F 15/0033; C09K 11/06; H01L 51/5044

(57) ABSTRACT

Provided is a display apparatus. The display apparatus may include an organic light-emitting device (OLED) substrate including a structure in which at least one blue emission unit and at least one green emission unit may be stacked and emitting mixed light of blue light and green light; and a color-controlling unit for controlling color of light generated from the OLED substrate.

### CROSS-REFERENCE TO RELATED APPLICATION

This application claims priority under 35 U.S.C. § 119 to Korean Patent Applications No. 10-2020-0090567, filed on Jul. 21, 2020, and 10-2021-0093126, filed on Jul. 16, 2021, in the Korean Intellectual Property Office, the contents of which are incorporated by reference herein in their entirety.

### BACKGROUND

### 1. Field

One or more embodiments relate to a display apparatus.

### 2. Description of Related Art

Organic light-emitting devices (OLEDs) are self-emissive devices which have wide viewing angles, high contrast ratios, short response times, and excellent driving voltage and luminance, and produce full-color images.

An OLED may include an anode, a cathode, and an emission layer (an organic matter-containing emission layer) located between the anode and the cathode. A hole transport region may be located between the anode and the emission layer, and an electron transport region may be located between the emission layer and the cathode. Holes provided from the anode may move toward the emission layer through the hole transport region, and electrons provided from the cathode may move toward the emission layer through the electron transport region. Carriers, such as holes and electrons, may recombine in the emission layer to produce excitons, and these excitons may transit from an excited state to a ground state, thus generating light.

In OLED displays including a plurality of quantum dot color-conversion elements, a blue-OLED substrate or a white-OLED substrate is mainly used as a light source.

### SUMMARY

One or more embodiments include a display apparatus having excellent performance.

One or more embodiments include a display apparatus having high luminescence efficiency and excellent color characteristics.

One or more embodiments include a display apparatus in which green light is applied to a light source organic light-emitting device (OLED).

One or more embodiments include a display apparatus in which green light and blue light is applied to a light source OLED, and a plurality of quantum dot color-conversion elements and a plurality of color filter elements may be used.

Additional aspects will be set forth in part in the description which follows and, in part, will be apparent from the description, or may be learned by practice of the presented embodiments of the disclosure.

According to an aspect of an embodiment, a display apparatus includes: an organic light-emitting device (OLED) substrate including a structure in which at least one blue emission unit and at least one green emission unit are stacked and wherein the structure emits a mixture of blue light and green light; and

a color-controlling unit on the OLED substrate for controlling color of light generated from the OLED substrate,

wherein the color-controlling unit includes a first color-controlling element including a first quantum dot for green color conversion, a second color-controlling element including a second quantum dot for red color conversion, a third color-controlling element for blue light emission, a first color filter located on the first color-controlling element, and a second color filter located on the second color-controlling element,

wherein at least one of the at least one green emission unit of the OLED substrate includes an organometallic compound represented by Formula 1:

M(L₁)ₙ₁(L₂)ₙ₂ Formula 1

wherein, in Formula 1,

M is a transition metal,

L₁ is a ligand represented by Formula 2A,

n1 is 1, 2, or 3, and when n1 is 2 or greater, at least two L₁(s) may be identical to or different from each other,

L₂ is an organic ligand,

n2 is 0, 1, or 2, and when n2 is 2, two L₂(s) may be identical to or different from each other,

the sum of n1 and n2 is 2 or 3, and

L₁ may be different from L₂,

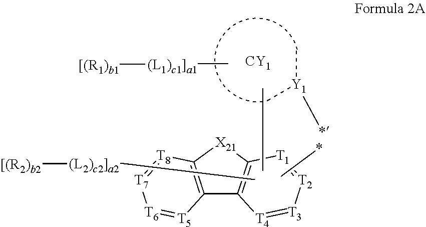

wherein, in Formula 2A,

Y₁ is C or N,

ring CY₁ is a C₅-C₃₀ carbocyclic group or a C₁-C₃₀ heterocyclic group,

X₂₁ is O, S, S(═O), Se, N(R₂₉), C(R₂₉)(R₃₀), or Si(R₂₉)(R₃₀), T₁ to T₄ are each independently a carbon atom not bound to ring CY₁, or M in Formula 1, N, a carbon atom bound to ring CY₁, or a carbon atom bound to M in Formula 1, one of T₁ to T₄ is a carbon atom bound to M in Formula 1, another one of T₁ to T₄, which is not be bound to bound to M, is a carbon atom bound to ring CY₁,

T₅ to T₈ are each independently C or N,

L₁ and L₂ are each independently a single bond, a C₅-C₃₀ carbocyclic group unsubstituted or substituted with at least one R₁₀ₐ, or a C₁-C₃₀ heterocyclic group unsubstituted or substituted with at least one R₁₀ₐ,

c1 and c2 are each independently an integer from 1 to 5,

R₁, R₂, R₂₉, and R₃₀ are each independently hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed hetero polycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉),

b1 and b2 are each independently an integer from 0 to 20,

a1 is an integer from 0 to 20, and when a1 is 2 or greater, at least two groups represented by *-[(L₁)_{c1}-(R₁)_{b1}] may be identical to or different from each other,

a2 is an integer from 0 to 6, and when a2 is 2 or greater, at least two groups represented by *-[(L₂)_{c2}-(R₂)_{b2}] may be identical to or different from each other,

at least two of a plurality of R₁(s) may optionally be bound to each other to form a C₅-C₃₀ carbocyclic group unsubstituted or substituted with at least one R₁₀ₐ or a C₁-C₃₀ heterocyclic group unsubstituted or substituted with at least one R₁₀ₐ,

at least two of a plurality of R₂(s) may optionally be bound to each other to form a C₅-C₃₀ carbocyclic group unsubstituted or substituted with at least one R₁₀ₐ or a Cr C₃₀ heterocyclic group unsubstituted or substituted with at least one R₁₀ₐ,

at least two of R₁, R₂, R₂₉, and R₃₀ may optionally be bound to form a C₅-C₃₀ carbocyclic group unsubstituted or substituted with at least one R₁₀ₐ or a C₁-C₃₀ heterocyclic group unsubstituted or substituted with at least one R₁₀ₐ, R₁₀ₐ may be understood by referring to the description of R₁ provided herein,

* and *′ in Formula 2A each indicate a binding site to M in Formula 1, and

a substituent of the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, and the substituted monovalent non-aromatic condensed heteropolycyclic group is:

deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group;

a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or any combination thereof;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a Cr C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or any combination thereof;

—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉); or

any combination thereof,

wherein Q₁ to Q₉, Q₁₁ to Q₁₉, Q₂₁ to Q₂₉ and to Q₃₉ are each independently: hydrogen; deuterium; —F; —Cl; —Br; —I; a hydroxyl group; a cyano group; a nitro group; an amino group; an amidino group; a hydrazine group; a hydrazone group; a carboxylic acid group or a salt thereof; a sulfonic acid group or a salt thereof; a phosphoric acid group or a salt thereof; a C₁-C₆₀ alkyl group unsubstituted or substituted with deuterium, a C₁-C₆₀ alkyl group, a C₆-C₆₀ aryl group, or any combination thereof; a C₂-C₆₀ alkenyl group; a C₂-C₆₀ alkynyl group; a C₁-C₆₀ alkoxy group; a C₁-C₆₀ alkylthio group; a C₃-C₁₀ cycloalkyl group; a C₁-C₁₀ heterocycloalkyl group; a C₃-C₁₀ cycloalkenyl group; a C₁-C₁₀ heterocycloalkenyl group; a C₆-C₆₀ aryl group unsubstituted or substituted with deuterium, a C₁-C₆₀ alkyl group, a C₆-C₆₀ aryl group, or any combination thereof; a C₆-C₆₀ aryloxy group; a C₆-C₆₀ arylthio group; a C₁-C₆₀ heteroaryl group; a monovalent non-aromatic condensed polycyclic group; or a monovalent non-aromatic condensed heteropolycyclic group.

The OLED substrate may have a tandem structure.

The OLED substrate may include a first blue emission unit, a green emission unit, and a second blue emission unit, which may be sequentially stacked, and the green emission unit may be located between the first and second blue emission units.

The OLED substrate may further include a first charge-generation layer located between the first blue emission unit and the green emission unit; and a second charge-generation layer located between the green emission unit and the second blue emission unit.

The first color filter may be a blue cut filter, and the second color filter may be a blue and green cut filter.

The first color filter may be an absorption-type green color filter, and the second color filter may be an absorption-type red color filter.

The third color-controlling element may include a blue color filter, and the display apparatus may further include a light-scattering element located between the blue color filter and the OLED substrate.

The third color-controlling element may include a color-conversion element including a third quantum dot for blue conversion, and the display apparatus may further include a third color filter on the third color-controlling element.

The third color filter may be a green cut filter or an absorption-type blue color filter.

The third color filter may be an absorption-type blue color filter.

A core portion of the second quantum dot may be greater in size than a core portion of the first quantum dot.

The first color-controlling element may correspond to a first sub-pixel region, the second color-controlling element may correspond to a second sub-pixel region, and the third color-controlling element may correspond to a third sub-pixel region, and the display apparatus may further include a fourth sub-pixel region, and the fourth sub-pixel region may emit a color different from colors emitted from the first to third sub-pixel regions.

The fourth sub-pixel region may be a blank region not having a color-controlling element on the OLED substrate or include a light-scattering element the OLED substrate.

A selective reflection film may be further included between the OLED substrate and the color-controlling unit.

The selective reflection film may transmit blue light and green light and reflect red light.

The display apparatus may further include a thin-film transistor (TFT) array substrate including a plurality of TFTs for driving pixel regions on the OLED substrate.

According to another aspect of an embodiment, an electronic apparatus may include the display apparatus.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of the display apparatus according to an exemplary embodiment;

FIG. 2 is a schematic cross-sectional view of the display apparatus according to another exemplary embodiment;

FIG. 3 is a schematic cross-sectional view of the display apparatus according to another exemplary embodiment;

FIG. 4 is a schematic cross-sectional view of the display apparatus according to another exemplary embodiment;

FIG. 5 is a schematic cross-sectional view of the display apparatus according to another exemplary embodiment;

FIG. 6 is a schematic cross-sectional view of the display apparatus according to another exemplary embodiment;

FIG. 7 is a schematic cross-sectional view of the display apparatus according to another exemplary embodiment;

FIG. 8 is a schematic cross-sectional view of the display apparatus according to another exemplary embodiment;

FIG. 8 is a schematic cross-sectional view of a structure of the display apparatus according to an exemplary embodiment;

FIG. 10 is a schematic cross-sectional view of a structure of an organic light-emitting device (OLED) substrate that may be applied to the display apparatus according to an exemplary embodiment; and

FIG. 11 is a schematic cross-sectional view of a structure of the display apparatus according to an exemplary embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a display apparatus according to one or more embodiments will be described in detail with reference to the accompanying drawings. The width and thickness of the layers or regions shown in the accompanying drawings may be exaggerated for clarity of the specification and convenience of description. The same reference numerals denote the same elements throughout the detailed description.

It will be understood that when an element is referred to as being “on” another element, it can be directly on the other element or intervening elements may be present therebetween In contrast, when an element is referred to as being “directly on” another element, there are no intervening elements present

It will be understood that, although the terms “first,” “second,” “third” etc. may be used herein to describe various elements, components, regions, layers and/or sections, these elements, components, regions, layers and/or sections should not be limited by these terms These terms are only used to distinguish one element, component, region, layer or section from another element, component, region, layer or section Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a,” “an,” “the,” and “at least one” do not denote a limitation of quantity, and are intended to cover both the singular and plural, unless the context clearly indicates otherwise. For example, “an element” has the same meaning as “at least one element,” unless the context clearly indicates otherwise.

“Or” means “and/or.” As used herein, the term “and/or” includes any and all combinations of one or more of the associated listed items It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures It will be understood that relative terms are intended to encompass different orientations of the device in addition to the orientation depicted in the Figures For example, if the device in one of the figures is turned over, elements described as being on the “lower” side of other elements would then be oriented on “upper” sides of the other elements The exemplary term “lower,” can therefore, encompasses both an orientation of “lower” and “upper,” depending on the particular orientation of the figure Similarly, if the device in one of the figures is turned over, elements described as “below” or “beneath” other elements would then be oriented “above” the other elements The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments As such, variations from the shapes of the illustrations as a result, for example, of manufacturing techniques and/or tolerances, are to be expected Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features Moreover, sharp angles that are illustrated may be rounded Thus, the regions illustrated in the figures are schematic in nature and their shapes are not intended to illustrate the precise shape of a region and are not intended to limit the scope of the present claims.

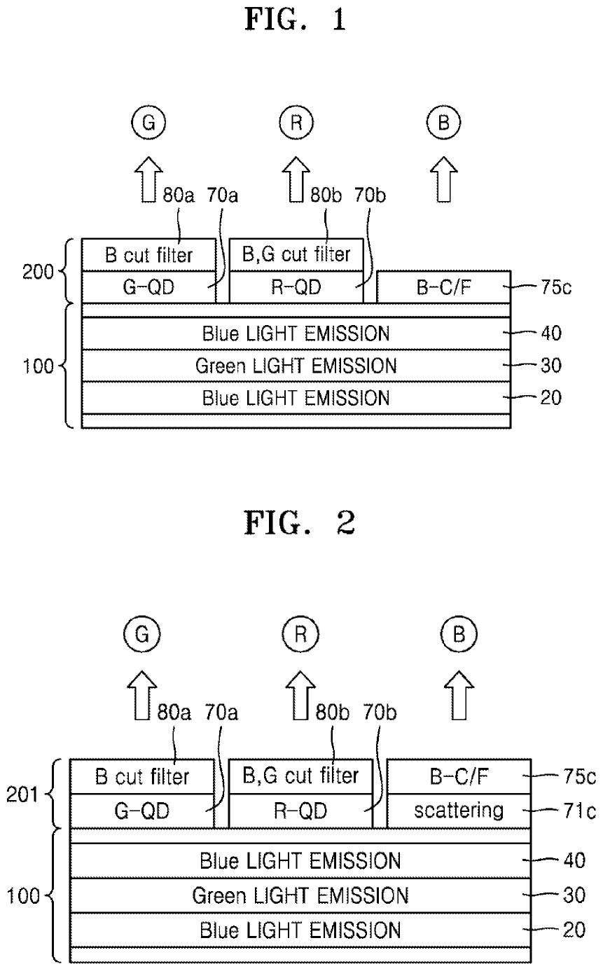

FIG. 1 is a schematic cross-sectional view of the display apparatus according to an exemplary embodiment.

As shown in FIG. 1, an organic light-emitting device (OLED) substrate 100 may be provided, and a color-controlling unit 200 may be provided for controlling color of light generated from the OLED substrate 100.

The OLED substrate 100 may be referred to as a light source OLED. The OLED substrate 100 may include a structure in which at least one blue emission unit and at least one green emission unit are sequentially stacked. The blue emission unit may emit blue light having a peak wavelength band in a range of about 440 nanometers (nm) to about 500 nm or about 450 nm to about 480 nm, and the green emission unit may emit green light having a peak wavelength range in a range of about 500 to about 550 nm or about 510 nm to about 540 nm. Accordingly, the OLED substrate 100 may emit mixed light of blue light and green light. The blue emission unit may include a blue fluorescent material and/or a blue phosphorescent material. The green emission unit may include a green phosphorescent material and/or a green fluorescent material.

For example, the OLED substrate 100 may include a first blue emission unit 20, a green emission unit 30, and a second blue emission unit 40. The green emission unit 30 may be located between the first blue emission unit 20 and the second blue emission unit 40. The green emission unit 30 and the second blue emission unit 40 may be sequentially stacked on the first blue emission unit 20. The lifespan of each of the blue emission units 20 and 40 may be shorter than the lifespan of the green emission unit 30, and thus, it may be advantageous to use at least two blue emission units 20 and 40 and green emission units 30 less than the blue emission units 20. In consideration of luminescence efficiency, lifespan, performance, and the like, one green emission unit 30 may be used between the two blue emission units 20 and 40. However, the structure of the OLED substrate 100 may vary.

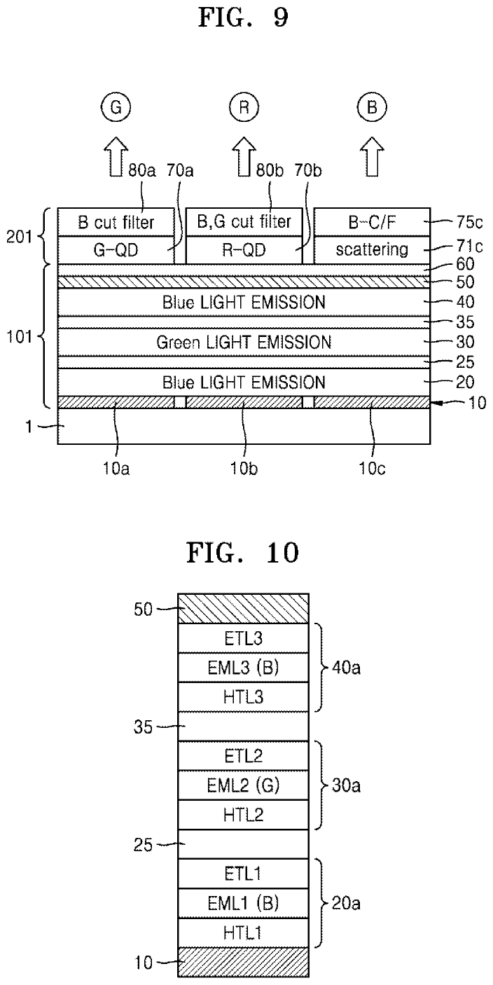

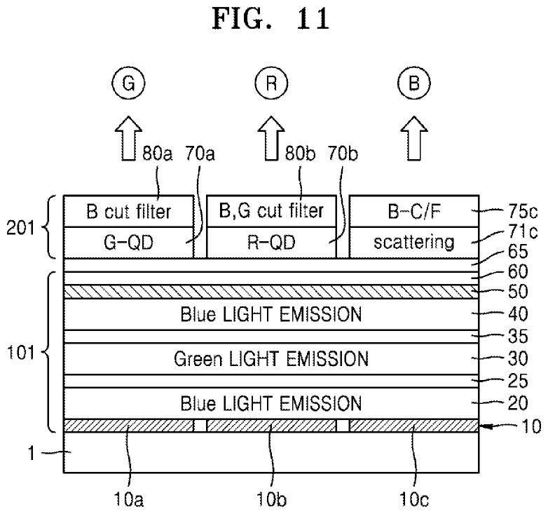

The OLED substrate 100 may have a tandem structure. In this embodiment, a first charge-generation layer (not shown) may be between the first blue emission unit 20 and the green emission unit 30. In addition, a second charge-generation layer (not shown) may be between the green emission unit 30 and the second blue emission unit 40. The tandem structure and the first and second charge-generation layers will be described in detail with reference to FIGS. 9 and 10. In addition, the OLED substrate 100 may further include a lower layer under the first blue emission unit 20 and an upper layer disposed on the second blue emission unit 40. As shown in FIG. 1, the lower layer and the upper layer are not denoted with a reference numeral, however, the lower layer and the upper layer may also be regarded as components included in the OLED substrate 100. The upper layer and the lower layer will be described in detail with reference to FIGS. 9 and 11.

A color-controlling unit 200 may be disposed on the OLED substrate 100. The color-controlling unit 200 may include a first color-controlling element 70a including a first quantum dot (QD) for green color conversion, a second color-controlling element 70b including a second QD for red color conversion, and a third color-controlling element 75c for emitting blue light. In addition, the color-controlling unit 200 may further include a first color filter 80a on the first color-controlling element 70a and a second color filter 80b on the second color-controlling element 70b.

The first color-controlling element 70a may be a green-QD containing layer and serve to convert light generated from the OLED substrate 100 to green light G. The second color-controlling element 70b may be a red-QD containing layer and serve to convert light generated from the OLED substrate 100 to red light R. Accordingly, the first color-controlling element 70a may be referred to as a first color-conversion element, and the second color-controlling element 70b may be referred to as a second color-conversion element. The color-conversion element may be prepared by mixing a resin material, specific quantum dots, and a light-scattering agent. The resin material may include, for example, a photoresist (PR) material. The third color-controlling element 75c may be a color filter that allows light generated from the OLED substrate 100 to selectively transmit a blue B wavelength region. In other words, the third color-controlling element 75c may be a blue-color filter (C/F). In this embodiment, the third color-controlling element 75c may be an absorption-type colorfilter including a specific pigment or quantum dots. The absorption-type color filter may serve to absorb light of wavelength band except light of the target wavelength band.

The first color filter 80a may cut wavelengths of a blue light region from light passed through the first color-controlling element 70a. The second colorfilter 80b may cut wavelengths of a blue and a green light region from light passed through the second color-controlling element 70b. The first color filter 80a may be referred to as a blue-cut filter, and the second color filter 80b may be referred to as a blue and green-cut filter. Accordingly, color-controlling/filtering characteristics may be improved by the first and second color filters 80a and 80b. Although it is not shown in FIG. 1, an additional separate optical film may be disposed on the third color-controlling element 75c. Full colors of RGB may be realized by using the color-controlling unit 200. Here, the arrangement order or arrangement method of the RGB subpixels is exemplary, and may be variously changed.

The first quantum dot that may be included in the first color-controlling element 70a may be a green-QD, and the second quantum dot that may be included in the second color-controlling element 70b may be a red-QD. A quantum dot refers to a semiconductor particle of a small sphere of nanometer (nm) size or a similar shape, and may have a size (diameter) of about several nm to several tens of nm. A quantum dot may have a monolithic structure or a core-shell structure, and in the case of a core-shell structure, the quantum dot may have a single shell structure or a multi-shell structure. For example, a quantum dot may include a core portion (center) including a predetermined first semiconductor and a shell portion including a second semiconductor. Here, a material for the core portion (center) may include cadmium selenide (CdSe), cadmium telluride (CdTe), or cadmium sulfide (CdS), and a material for the shell portion may include zinc sulfide (ZnS). Also, a non-cadmium-based quantum dot (QD) may be used. That is, various materials not including cadmium (Cd) may be applied to the quantum dot. However, the materials specifically presented here are exemplary, and other various materials may be applied to the quantum dot. For example, the quantum dot may include at least one of a group II-VI semiconductor, a group III-V semiconductor, a group IV-VI semiconductor, a group IV semiconductor, or a combination thereof.

Because quantum dots are very small in size, quantum dots may exhibit a quantum confinement effect. When a particle is very small, electrons in the particle form a discontinuous energy state by the outer wall of the particle. As the size of the space inside the particle is small, the energy state of the electrons is relatively high, and the energy band gap increases. This effect is called as the quantum confinement effect. According to such a quantum confinement effect, when light such as ultraviolet rays or visible rays is incident on a quantum dot, light of various wavelengths may be generated. The wavelength of light generated from a quantum dot may be determined by the size, material, or structure of the particle (quantum dot). Specifically, when light with a wavelength greater than the energy band width is incident on the quantum dot, the quantum dot may be excited by absorbing the energy of the light and may transit to a ground state while emitting light of a specific wavelength. In this case, as the size of the quantum dot (or, the core portion of the quantum dot) is smaller, light of a relatively short wavelength, for example, bluish light or greenish light may be generated, and as the size of the quantum dot (or, the core portion of the quantum dot) is larger, light of a relatively long wavelength, for example, reddish light may be generated. Therefore, light of various colors may be realized according to the size of the quantum dot (or the core portion of the quantum dot). Quantum dot particles that may emit greenish light may be referred to as green light quantum dot particles, and quantum dot particles that may emit reddish light may be referred to as red light quantum dot particles. For example, green light quantum dot particles (or the core portion thereof) may be particles having a particle width (diameter) in a range of about 2 nm to about 3 nm, and red light quantum dot particles (or the core portion thereof) may be particles having a width (diameter) of about 5 nm to about 6 nm. The emission wavelength may be controlled not only by the size (diameter) of the quantum dot but also by the material and structure.

The first color-controlling element 70a may be regarded as a kind of color filters that causes color conversion by using quantum dots. Thus, the first color-controlling element 70a may be referred to as a “first QD color filter”. Similarly, the second color-controlling element 70b may be referred to as a “second QD color filter”.

The first color filter 80a and the second color filter 80b of a cut-off filter type may be formed in, for example, a distributed Bragg reflector (DBR) structure. A DBR structure that passes or reflects only the desired wavelength band may be created by repeatedly stacking two material layers (dielectrics) having different refractive indices and adjusting the thickness and the number of layers to be stacked of the material layers. The DBR structure may be applied to the first color filter 80a and the second color filter 80b. For example, a SiO₂ layer and a TiO₂ layer may be repeatedly stacked under λ/4 condition (here, “λ” represents a wavelength of light), and the thickness and the number of layers to be stacked may be controlled to increase a reflectance and a transmittance of a desired wavelength band. As the DBR structure is well known, the detailed descriptions thereof are omitted herein. In addition, at least one of the first color filter 80a and the second color filter 80b may have a structure other than the DBR structure, for example, a high-contrast grating (HCG) structure.

According to one or more embodiments, a light-scattering element may be further provided between the third color-controlling element 75c and the OLED substrate 100 of FIG. 1. An example thereof is shown in FIG. 2.

As shown in FIG. 2, a light-scattering element 71c may be further provided between the third color-controlling element 75c and the OLED substrate 100. The third color-controlling element 75c may be a blue-color filter (C/F). The light-scattering element 71c may include a resin material and a light-scattering agent. In this embodiment, the resin material may include a photoresist (PR) material. The light-scattering agent may include, for example, titanium oxide (TiO₂) or the like, but embodiments are not limited thereto. The first and the second color-controlling elements 70a and 70b may each include a light-scattering agent, and thus, the light-scattering element 71c may be provided under the third color-controlling element 75c, thus balancing the impression of colors. In other words, change in visibility in a RGB region may be reduced. In FIG. 2, a reference numeral “201” represents a color-controlling unit.

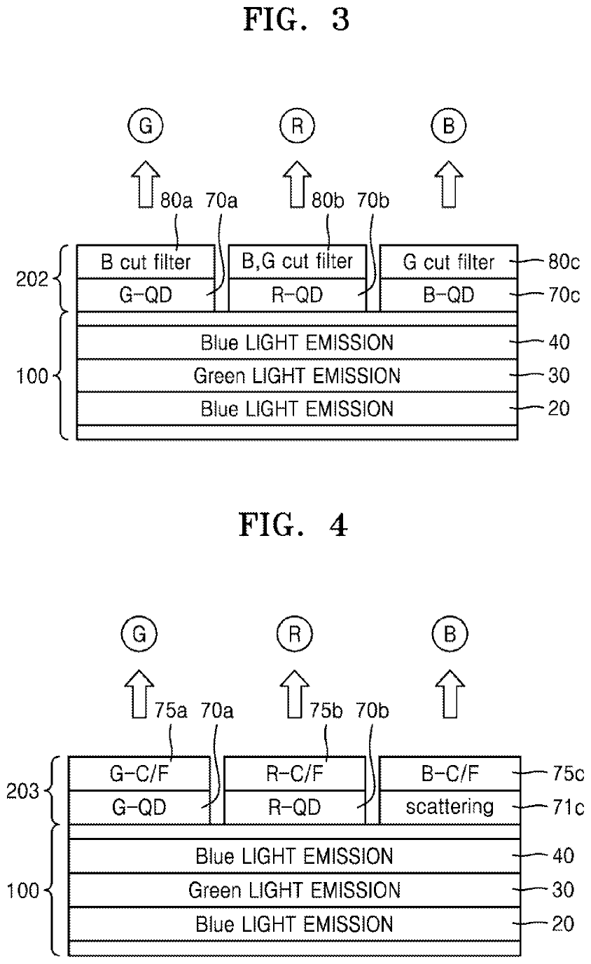

In some embodiments, as the third color-controlling element 75c in FIG. 1, a color-conversion element containing a quantum dot (blue-QD) may be used instead of the blue-color filter (C/F). An example thereof are shown in FIG. 3.

As shown in FIG. 3, although FIG. 3 is similar with FIG. 1, a layer containing blue-QD may be used instead of the blue-color filter (C/F) as the third color-controlling element 70c. The third color-controlling element 70c may serve to convert light generated from the OLED substrate 100 to blue light B. Thus, the third color-controlling element 70c may be referred to as a third color-conversion element. The third color-controlling element 70c may include a resin material, quantum dots, and a light-scattering agent. In this exemplary embodiment, a color-controlling unit 202 may further include a third color filter 80c on the third color-controlling element 70c. The third color filter 80c may cut wavelengths of a green light region from light passed through the third color-controlling element 70c. That is, the third color filter 80c may be a green-cut filter.

In some embodiments, an absorption-type color filter may be used instead of the first and second color filters 80a and 80b of the cut-off filter type in FIGS. 1 and 2. An example thereof are shown in FIG. 4. FIG. 4 is a modification of the example of FIG. 2.

As shown in FIG. 4, a green-color filter (C/F) may be used as the first color filter 75a instead of the blue-cut filter, and an absorption-type red-color filter (C/F) may be used as the second color filter 75b instead of the blue and green-cut filter. The green-color filter 75a may selectively transmit light in the green wavelength region and absorb light in the other wavelength regions. Similarly, the red-color filter 75b may selectively transmit light in the red wavelength region and absorb light in the other wavelength regions. In a color-controlling unit 203 in this embodiment, the absorption-type color filters 75a, 75b, and 75c are commonly used in a R-subpixel, a G-subpixel, and a B-subpixel region. In this embodiment, the third color-controlling element 70c containing the blue-QD in FIG. 3 may be used instead of a light-scattering element 71c.

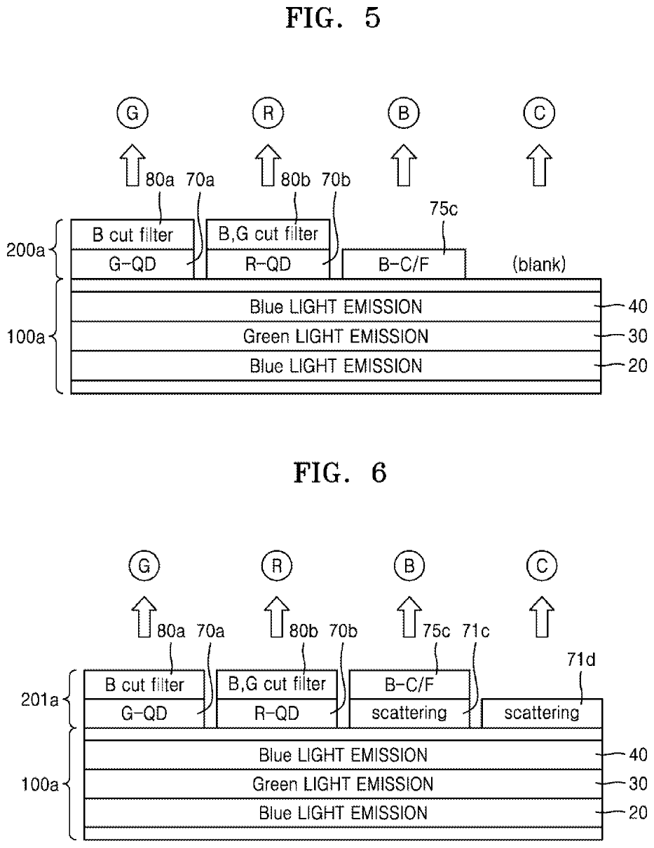

In some embodiments, a display apparatus may further include a fourth subpixel region, in addition to the R-subpixel (a first subpixel), the G-subpixel (a second subpixel), and the B-subpixel (a third subpixel). The fourth subpixel may exhibit a color (a fourth color) different from R, G, and B. The color (the fourth color) may be, for example, cyan (C), but embodiments are not limited thereto. Exemplary embodiments further including the fourth subpixel region are illustrated in FIGS. 5 to 8. In FIGS. 5 to 8, a reference numeral “100a” represents an OLED substrate, and reference numerals “200a”, “201a”, “202a”, and “203a” each represent a color-controlling unit.

As shown in FIG. 5, FIG. 5 may be similar with FIG. 1, however, a portion of an OLED substrate 100a may be a blank region. The blank region may correspond to the fourth subpixel region, and cyan (C) color may be exhibited from the blank region.

As shown in FIG. 6, FIG. 6 may be similar with FIG. 2, however, a light-scattering element 71d may be further included in the fourth subpixel region of the OLED substrate 100a. When the light-scattering element 71c under the third color-controlling element 75c is referred to as a first light-scattering element, the light-scattering element 71d provided on the fourth subpixel region may be referred to as a second light-scattering element. The first light-scattering element 71c and the second light-scattering element 71d may have the same or similar material composition.

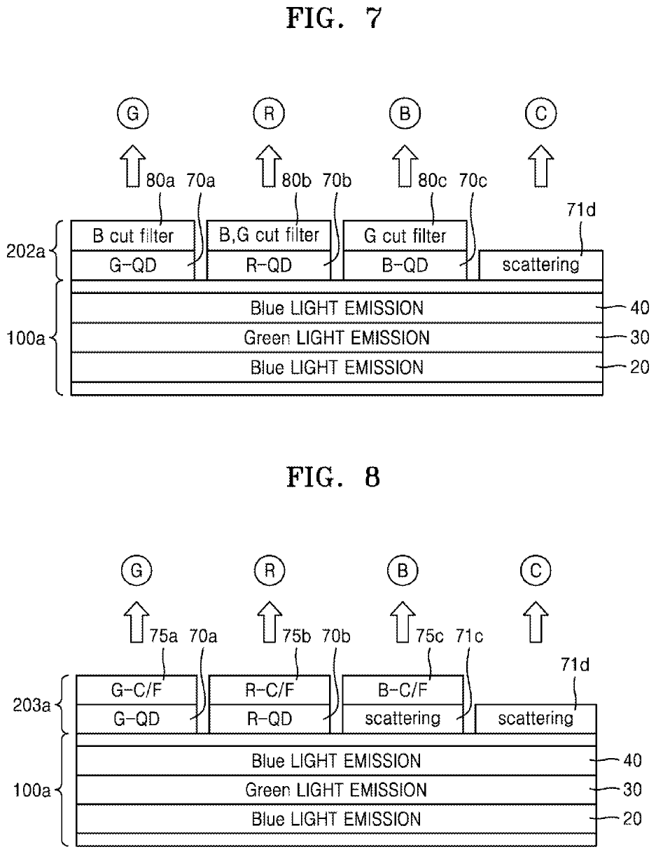

As shown in FIG. 7, FIG. 7 may be similar with FIG. 3, however, the light-scattering element 71d may be further included in the fourth subpixel region of the OLED substrate 100a.

As shown in FIG. 8, FIG. 8 may be similar with FIG. 4, however, the light-scattering element 71d may be further included in the fourth subpixel region of the OLED substrate 100a.

In the Examples shown in FIGS. 5 to 8, the arrangement of the R-subpixel (the first subpixel), the G-subpixel (the second subpixel), the B-subpixel (the third subpixel), and the C-subpixel (the fourth subpixel) with respect to the other elements are for illustrative purposes only, and various embodiments may be made. In some embodiments, the R, G, B, and C subpixel regions may be arranged such that a square shape matrix form may be formed when viewed from a top view. In addition, the color exhibited by the C-subpixel (the fourth subpixel) region may be any other color other than cyan (C).

FIG. 9 is a schematic cross-sectional view of a structure of the display apparatus according to an exemplary embodiment.

As shown in FIG. 9, a TFT array substrate 1 including a plurality of thin-film transistors (TFT, not shown) may be provided, and an OLED substrate 101 may be provided on the TFT array substrate 1. A plurality of TFTs in the TFT array substrate 1 may be devices for driving subpixel regions in the OLED substrate 101. The color-controlling unit 201 may be on the OLED substrate 101.

The OLED substrate 101 may include a first electrode 10 comprising a plurality of first electrodes 10a, 10b, and 10c. Each of the plurality of first electrodes 10a, 10b, and 10c may respectively be a patterned element corresponding to each subpixel region. The plurality of first electrodes 10a, 10b, and 10c may each be electrically connected to each TFT device of the TFT array substrate 1. The first blue emission unit 20, the green emission unit 30, and the second blue emission unit 40 may be sequentially stacked on the plurality of first electrodes 10a, 10b, and 10c. The first charge-generation layer 25 may be between the first blue emission unit 20 and the green emission unit 30. In addition, the second charge-generation layer 35 may be between the green emission unit 30 and the second blue emission unit 40. Thus, the first blue emission unit 20, the green emission unit 30, and the second blue emission unit 40 may be connected in series to each other to form a tandem structure. A second electrode 50 may be on the second blue emission unit 40. Here, the second electrode 50 is illustrated as not being patterned, however, the second electrode 50 may be patterned with a plurality of electrode elements. The first electrode 10 may be an anode, and the second electrode 50 may be a cathode, or vice versa. The first electrode 10 may not be patterned, and the second electrode 50 may be patterned, or, the first electrode 10 and the second electrode 50 may both be patterned. In addition, a plurality of the emission units 20, 30, and 40 and the charge-generation layers 25 and 35, which may be between the emission units 20, 30, and 40, between the first electrode 10 and the second electrode 50 may also be patterned according to a subpixel unit. A protection layer 60 may be further provided on the second electrode 50. The protection layer 60 may be formed of a transparent insulating material.

The color-controlling unit 201 may be on the protection layer 60. The color-controlling unit 201 is illustrated as having the same composition as the color-controlling unit 201 in FIG. 2, however, the composition thereof may vary.

FIG. 10 is a schematic cross-sectional view of a structure of an organic light-emitting device (OLED) substrate that may be applied to the display apparatus according to an exemplary embodiment. FIG. 10 shows the composition of the OLED substrate 101 shown in FIG. 9 more specifically.

As shown in FIG. 10, a first blue emission unit 20a, the first charge-generation layer 25, a green emission unit 30a, the second charge-generation layer 35, a second blue emission unit 40a, and the second electrode 50 may be sequentially stacked on the first electrode 10.

The first blue emission unit 20a may include a first blue emission layer EML1 including an organic material-based blue luminous material, a first hole transport layer HTL1, and a first electron transport layer ETL1. The first hole transport layer HTL1 may be between the first blue emission layer EML1 and the first electrode 10, and the first electron transport layer ETL1 may be between the first blue emission layer EML1 and the first charge-generation layer 25. The green emission unit 30a may include a green emission layer EML2 including an organic material-based green luminous material, a second hole transport layer HTL2, and a second electron transport layer ETL2. The second blue emission unit 40a may include a second blue emission layer EML3 including an organic material-based blue luminous material, a third hole transport layer HTL3, and a third electron transport layer ETL3. Although it is not illustrated, the first blue emission unit 20a, the green emission unit 30a, and the second blue emission unit 40a may each include at least one of a hole injection layer and an electron injection layer. The first and second charge-generation layers 25 and 35 may be formed of a metal or metallic material, and the first and second charge-generation layers 25 and 35 may serve to improve luminescence efficiency of an OLED substrate.

In some embodiments, a “selective reflection film” may be further included between the OLED substrate 101 and the color-controlling unit 201 in the structure shown in FIG. 9. An example thereof is shown in FIG. 11.

FIG. 11 may be similar to FIG. 9, however a selective reflection film 65 may be further included between the OLED substrate 101 and the color-controlling unit 201. The selective reflection film 65, for example, may transmit blue light and green light and reflect red light. The selective reflection film 65 may transmit a wavelength band in a range of about 440 nm to about 550 nm and reflect a wavelength band in a range of about 610 nm to about 760 nm. Thus, a mixed light of blue and green emitted from the OLED substrate 101 may transmit the selective reflection film 65 and be incident on the color-controlling unit 201. In addition, red light emitted from the second color-controlling element 70b downward may be reflected by the selective reflection film 65 to be emitted upward. The selective reflection film 65 may improve optical efficiency. If necessary, the selective reflection film 65 may be optionally formed under the second color-controlling element 70b.

For example, the selective reflection film 65 may be formed in a DBR structure. A DBR structure that passes or reflects only the desired wavelength band may be created by repeatedly stacking two material layers (dielectrics) having different refractive indices and adjusting the thickness and the number of layers to be stacked of the material layers. The DBR structure may be applied to the selective reflection film 65. For example, a first dielectric layer and a second dielectric layer may be repeatedly stacked, and the reflectance or transmittance of the desired wavelength band may be increased by adjusting the material, the thickness, and the number of layers to be stacked of the material layers. However, the composition of the selective reflection film 65 may not be limited to DBR and may vary. The selective reflection film 65 may have a dichroic mirror structure.

In FIGS. 9 and 11, the TFT array substrate 1 may be under the OLED substrate 101, and the color-controlling unit 201 may be on the OLED substrate 101, however, the relative location relationship may change. When the OLED substrate 101 is a bottom-emission device, not a top-emission device, the color-controlling unit 201 may be under the TFT array substrate 1. The composition of the display apparatus described in relation to FIGS. 9 and 11 may vary.

Hereinafter, a blue luminescence material and a green luminescence material that may be applied to an OLED substrate of the display apparatus.

The blue luminescence material may be any suitable luminescence material that may emit blue light. For example, the blue luminescence material may be a blue phosphorescent dopant, a blue fluorescent dopant, or any combination thereof.

In some embodiments, at least one of the green emission units 30a (e.g., the green emission layer EML2 of the green emission unit 30a) in the OLED substrate 101 may include an organometallic compound represented by Formula 1:

M(L₁)ₙ₁(L₂)ₙ₂ Formula 1

wherein, in Formula 1, M may be a transition metal.

In some embodiments, M may be a first-row transition metal, a second-row transition metal, or a third-row transition metal.

In some embodiments, M may be iridium (Ir), platinum (Pt), osmium (Os), titanium (Ti), zirconium (Zr), hafnium (Hf), europium (Eu), terbium (Tb), thulium (Tm), or rhodium (Rh).

In an embodiment, M may be Ir, Pt, Os, or Rh.

In one or more embodiments, M may be iridium (Ir).

In Formula 1, U may be a ligand represented by Formula 2A:

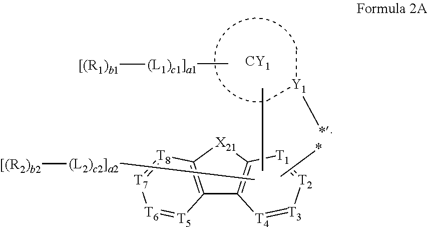

Formula 2A may be understood by referring to the descriptions herein.

n1 in Formula 1 indicates the number of U(s), and n1 may be 1, 2, or 3. When n1 is 2 or greater, at least two U(s) may be identical to or different from each other. In some embodiments, n1 may be 1 or 2.

L₂ in Formula 1 may be an organic ligand. In some embodiments, L₂ in Formula 1 may be any suitable ligand, e.g., a monodentate ligand, a bidentate ligand, a tridentate ligand, or a tetradentate ligand.

In Formula 1, n2 indicates the number of L₂(s), and n2 may be 0, 1, or 2. When n2 is 2, the two L₂(s) may be identical to or different from each other. In some embodiments, n2 may be 1 or 2.

In Formula 1, the sum of n1 and n2 may be 3.

L₁ and L₂ in Formula 1 may be different from each other.

In some embodiments, in Formula 1, 1) M may be Ir, and n1+n2=3, or M may be Pt, and n1+n2=2.

In Formula 2A, Y₁ may be C or N. In some embodiments, Y₁ may be N.

In Formula 2A, ring CY₁ may be a C₅-C₃₀ carbocyclic group or a C₁-C₃₀ heterocyclic group.

In some embodiments, ring CY₁ may be i) a first ring, ii) a second ring, iii) a condensed ring in which at least two first rings are condensed, iv) a condensed ring in which at least two second rings are condensed, or v) a condensed ring in which at least one first ring and at least one second ring are condensed,

the first ring may be a cyclopentane group, a cyclopentene group, a furan group, a thiophene group, a pyrrole group, a silole group, an oxazole group, an oxadiazole group, an oxatriazole group, a thiazole group, a thiadiazole group, a thiatriazole group, a pyrazole group, an imidazole group, a triazole group, a tetrazole group, an azasilole group, a borole group, a selenophene group, a germole group, or a phosphole group, and

the second ring may be an adamantane group, a norbornane group, a norbornene group, a cyclohexane group, a cyclohexene group, a benzene group, a pyridine group, a pyrimidine group, a pyrazine group, a pyridazine group, ora triazine group.

In some embodiments, in Formula 2, ring CY₁ may be a cyclopentene group, a cyclohexane group, a cyclohexene group, a benzene group, a naphthalene group, an anthracene group, a phenanthrene group, a triphenylene group, a pyrene group, a chrysene group, a cyclopentadiene group, a 1,2,3,4-tetrahydronaphthalene group, a thiophene group, a furan group, an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophenegroup, a dibenzofuran group, a dibenzothiophene 5-oxide group, a 9H-fluorene-9-one group, a dibenzothiophene 5,5-dioxide group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluoren-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isooxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, a 5,6,7,8-tetrahydroquinoline group, an adamantane group, a norbornane group, a norbornene group, a benzene group condensed with a cyclohexane group, or a benzene group condensed with a norbornane group.

In some embodiments,

Y₁ in Formula 2A may be N, and

ring CY₁ in Formula 2A may be:

a pyridine group, a pyrimidine group, a quinoline group, an isoquinoline group, a benzoquinoline group, a benzoisoquinoline group, an imidazole group, a benzimidazole group, a naphthoimidazole group, a pyridoimidazole group, or a pyrimidoimidazole group; or

a pyridine group, a pyrimidine group, a quinoline group, an isoquinoline group, a benzoquinoline group, a benzoisoquinoline group, an imidazole group, a benzimidazole group, a naphthoimidazole group, a pyridoimidazole group, or a pyrimidoimidazole group, each condensed with a cyclohexane group, a cyclohexene group, a norbornane group, or any combination thereof.

In Formula 2A, X₂₁ may be O, S, S(═O), Se, N(R₂₉), C(R₂₉)(R₃₀), or Si(R₂₉)(R₃₀). In some embodiments, X₂₁ in Formula 2A may be O or S.

In Formula 2A, T₁ to T₄ may each independently be a carbon atom not bound to ring CY₁ or M in Formula 1, N, a carbon atom bound to ring CY₁, or a carbon atom bound to M in Formula 1, one of T₁ to T₄ may be a carbon atom bound to M in Formula 1, another one of T₁ to T₄, which may not be bound to bound to M, may be a carbon atom bound to ring CY₁, and T₅ to T₈ may each independently be C or N.

According to an embodiment, in Formula 2A, T₁ to T₈ may not each be N.

In one or more embodiments, in Formula 2A, T₁ to T₇ may not each be N, and T₈ may be N.

In Formula 2A, L₁ and L₂ may each independently be a single bond, a C₅-C₃₀ carbocyclic group unsubstituted or substituted with at least one R₁₀ₐ, or a C₁-C₃₀ heterocyclic group unsubstituted or substituted with at least one R₁₀ₐ.

In some embodiments, U and L₂ in Formula 1 may each independently be:

a single bond; or

a benzene group, a naphthalene group, an anthracene group, a phenanthrene group, a triphenylene group, a pyrene group, a chrysene group, a cyclopentadiene group, a 1,2,3,4-tetrahydronaphthalene group, a thiophene group, a furan group, an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluorene-9-one group, a dibenzothiophene 5,5-dioxide group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluoren-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isooxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, or a 5,6,7,8-tetrahydroquinoline group, each unsubstituted or substituted with at least one R₁₀ₐ.

In Formula 2A, c1 and c2 may respectively indicate the number of U(s) and L₂(s), and c1 and c2 may each independently be an integer from 1 to 5. When c1 is 2 or greater, at least two U(s) may be identical to or different from each other. When c2 is 2 or greater, at least two L₂(s) may be identical to or different from each other. In some embodiments, c1 and c2 may each independently be 1 or 2.

In Formula 2A, R₁, R₂, R₂₉, and R₃₀ may each independently be hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉). Q₁ to Q₉ may respectively be understood by referring to the descriptions of Q₁ to Q₉ provided herein.

In some embodiments, in Formula 2A, R₂, R₂₉, and R₃₀ may each independently be:

hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, —SF₅, a C₁-C₂₀ alkyl group, a C₂-C₂₀ alkenyl group, a C₁-C₂₀ alkoxy group, or a C₁-C₂₀ alkylthio group; a C₁-C₂₀ alkyl group, a C₂-C₂₀ alkenyl group, a C₁-C₂₀ alkoxy group, or a C₁, C₂₀ alkylthio group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.2]octyl group, a phenyl group, a (C₁-C₂₀ alkyl)phenyl group, a biphenyl group, a terphenyl group, a naphthyl group, a pyridinyl group, a pyrimidinyl group, or any combination thereof;

a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.2]hexyl group, a bicyclo[2.2.2]octyl group, a phenyl group, a (C₁-C₂₀ alkyl)phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, or an azadibenzothiophenyl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a (deuterated)C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.2]octyl group, a phenyl group, a (C₁-C₂₀ alkyl)phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, or any combination thereof; or

—N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉),

wherein Q₁ to Q₉ may each independently be:

deuterium, —F, —CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, —CD₂CDH₂, —CF₃, —CF₂H, —CFH₂, —CH₂CF₃, —CH₂CF₂H, —CH₂CFH₂, —CHFCH₃, —CHFCF₂H, —CHFCFH₂, —CHFCF₃, —CF₂CF₃, —CF₂CF₂H, or —CF₂CFH₂; or

an n-propyl group, an iso-propyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, a phenyl group, a biphenyl group, or a naphthyl group, each unsubstituted or substituted with deuterium, —F, a C₁-C₁₀ alkyl group, a phenyl group, or any combination thereof.

In some embodiments, in Formula 2A, R₁, R₂, R₂₉, and R₃₀ may each independently be:

hydrogen, deuterium, —F, or a cyano group;

a C₁-C₂₀ alkyl group unsubstituted or substituted with deuterium, —F, a cyano group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a C₁-C₁₀ heterocycloalkyl group, a deuterated C₁-C₁₀ heterocycloalkyl group, a fluorinated Cr C₁₀ heterocycloalkyl group, a (C₁-C₂₀ alkyl)C₁-C₁₀ heterocycloalkyl group, a phenyl group, a deuterated phenyl group, a fluorinated a phenyl group, a (C₁-C₂₀ alkyl)phenyl group, a biphenyl group, a deuterated biphenyl group, a fluorinated biphenyl group, a (C₁-C₂₀ alkyl)biphenyl group, or any combination thereof;

a C₃-C₁₀ cycloalkyl group, a C₁-C₁₀ heterocycloalkyl group, a phenyl group, or a biphenyl group, each unsubstituted or substituted with deuterium, —F, a cyano group, a C₁-C₂₀ alkyl group, a deuterated C₁-C₂₀ alkyl group, a fluorinated C₁-C₂₀ alkyl group, a C₁-C₂₀ alkoxy group, a deuterated C₁-C₂₀ alkoxy group, a fluorinated C₁-C₂₀ alkoxy group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a C₁-C₁₀ heterocycloalkyl group, a deuterated C₁-C₁₀ heterocycloalkyl group, a fluorinated C₁, C₁₀ heterocycloalkyl group, a (C₁-C₂₀ alkyl)C₁-C₁₀ heterocycloalkyl group, a phenyl group, a deuterated phenyl group, a fluorinated a phenyl group, a (C₁-C₂₀ alkyl)phenyl group, a biphenyl group, a deuterated biphenyl group, a fluorinated a biphenyl group, a (C₁-C₂₀ alkyl)biphenyl group, or any combination thereof; or

—Si(Q₃)(Q₄)(Q₅) or —Ge(Q₃)(Q₄)(Q₅).

In Formula 2A, b1 and b2 may respectively indicate the number of R₁(s) and R₂(S), and b1 and b2 may each independently be an integer from 0 to 20. When b1 is 2 or greater, at least two R₁(s) may be identical to or different from each other. When b2 is 2 or greater, at least two R₂(s) may be identical to or different from each other. In some embodiments, b1 and b2 may each independently be an integer from 0 to 6.

In Formula 2A, a1 may indicate the number of *-[(L₁)_{c1}-(R₁)_{b1}](s), and a1 may be an integer from 0 to 20. When a1 is 2 or greater, at least two *-[(L₁)_{c1}-(R₁)_{b1}](s) may be identical to or different from each other. In some embodiments, a1 may be 0, 1, 2, 3, or 4.

In Formula 2A, a2 may indicate the number of *-[(L₂)_{c2}-(R₂)_{b2}](s), and a2 may be an integer from 0 to 6. When a2 is 2 or greater, at least two *-[(L₂)_{c2}-(R₂)_{b2}](s) may be identical to or different from each other. In some embodiments, a2 may be 0, 1, 2, 3, or 4.

In some embodiments, in Formula 2A, ring CY₁ may be represented by one of Formulae CY1-1 to CY1-44:

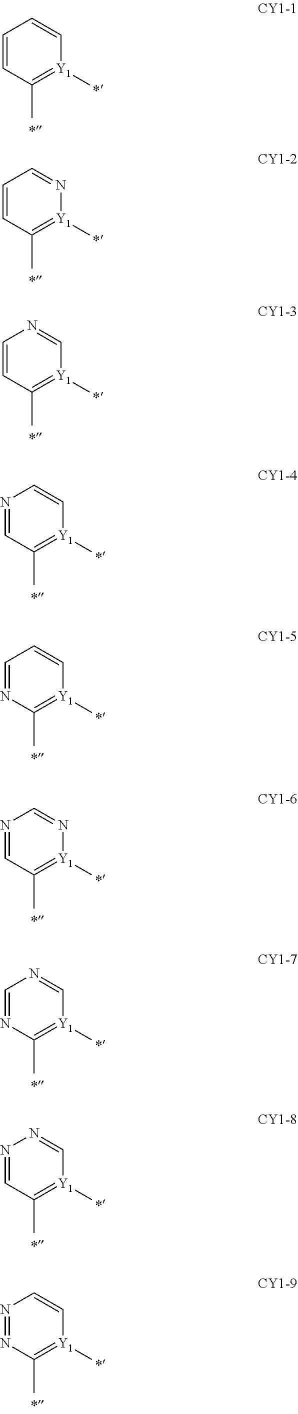

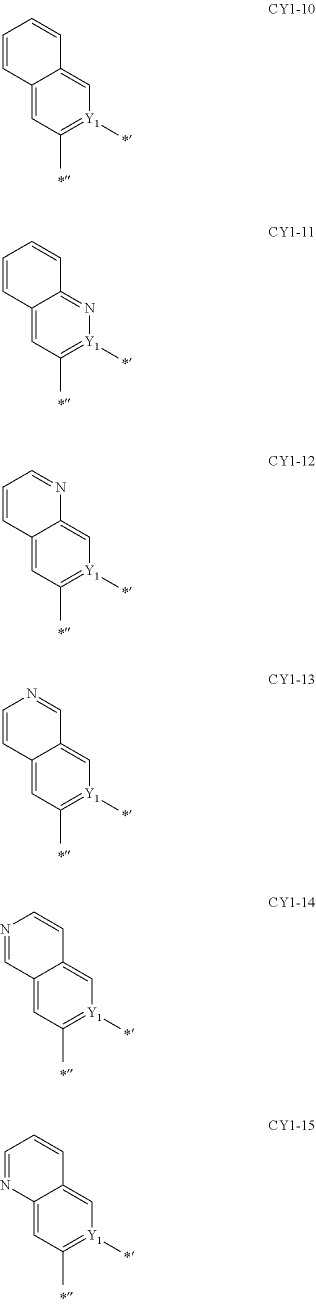

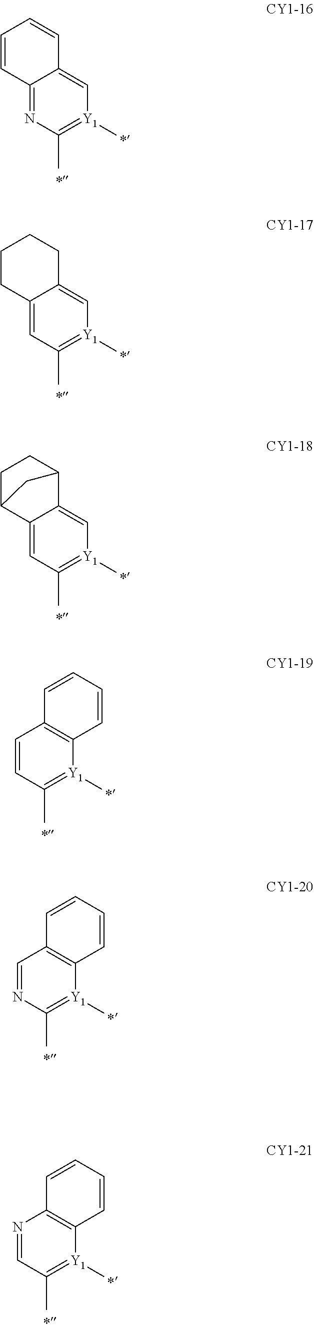

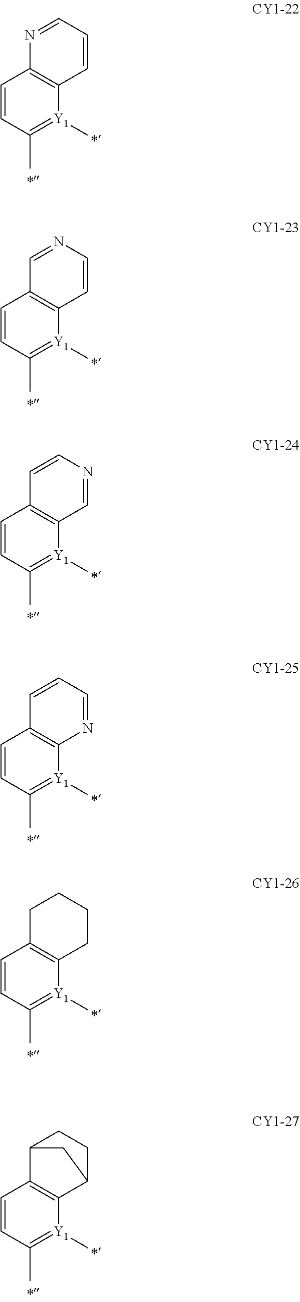

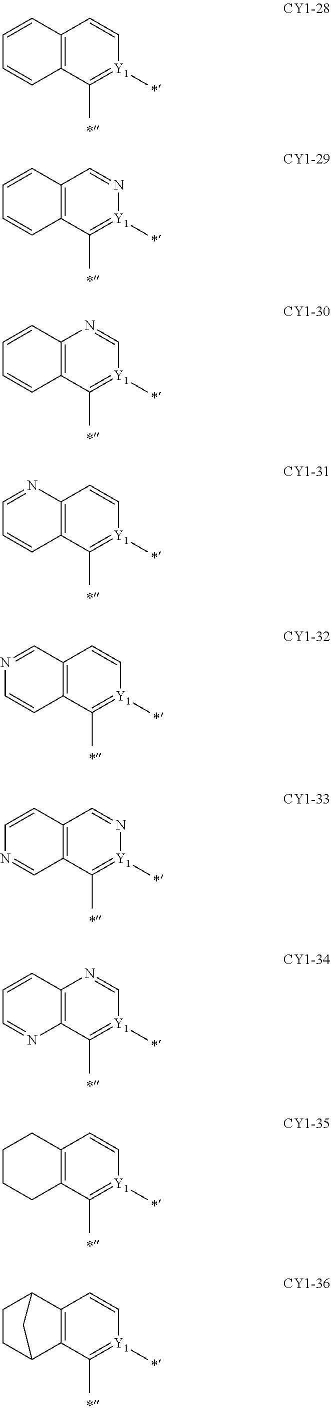

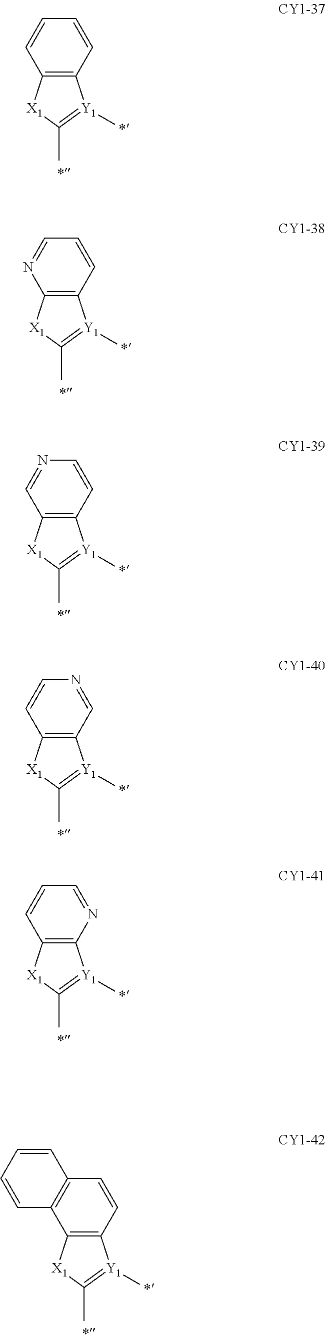

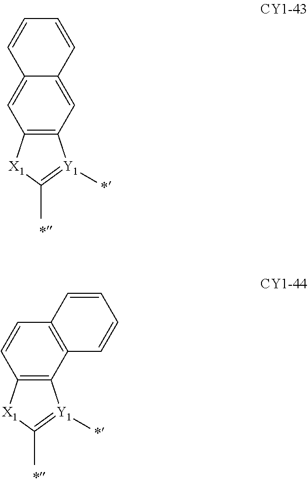

wherein, in Formulae CY1-1 to CY1-44,

Y₁ may be understood by referring to the description of Y₁ provided herein,

X₁ may be O, S, S(═O), N-[(L₁)_{c1}-(R₁)_{b1}], C(R₁ₐ)(R_{1b}), or C(R₁ₐ)(R_{1b}),

L₁, c1, R₁, and b1 may respectively be understood by referring to the descriptions of L₁, c1, R₁, and b1 provided herein,

R₁ₐ and R_{1b} may each be understood by referring to the description of R₁ provided herein,

*′ indicates a binding site to M in Formula 1, and

*″ indicates a binding site to one of T₁ to T₄ in Formula 2A.

In one or more embodiments, in Formula 2A, a group represented by

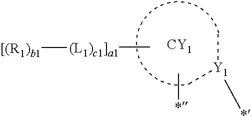

may be represented by one of Formulae CY1(1) to CY1(28):

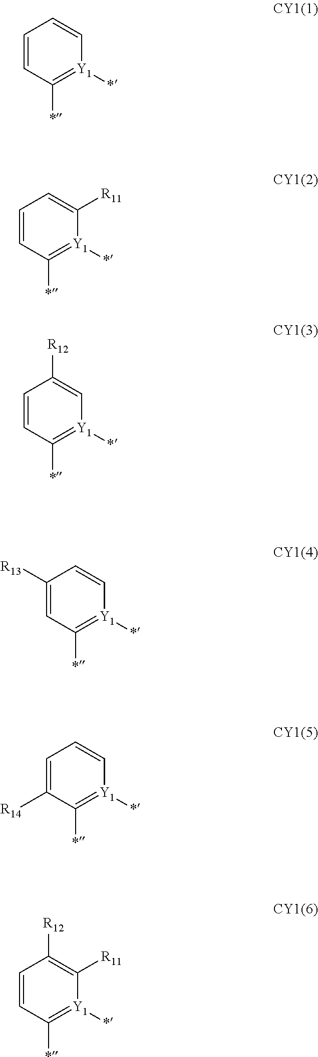

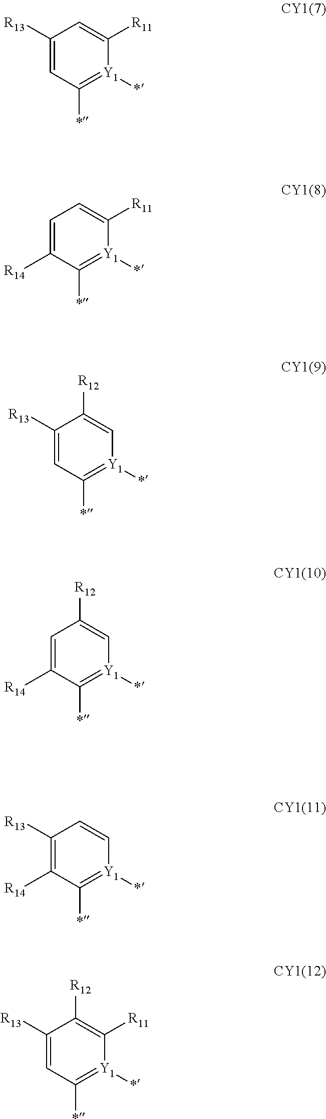

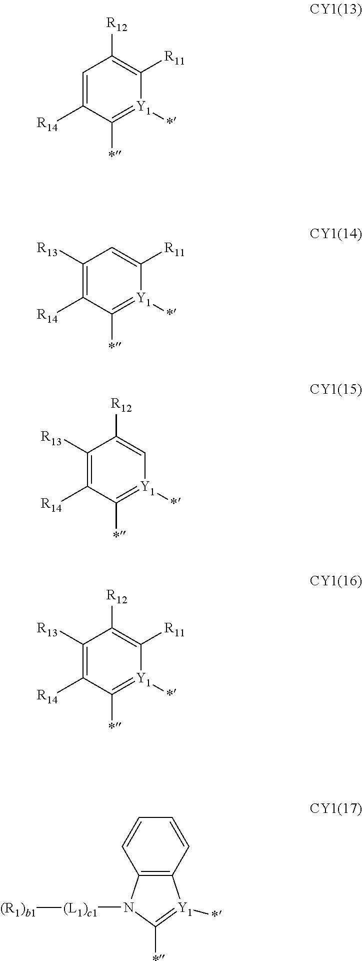

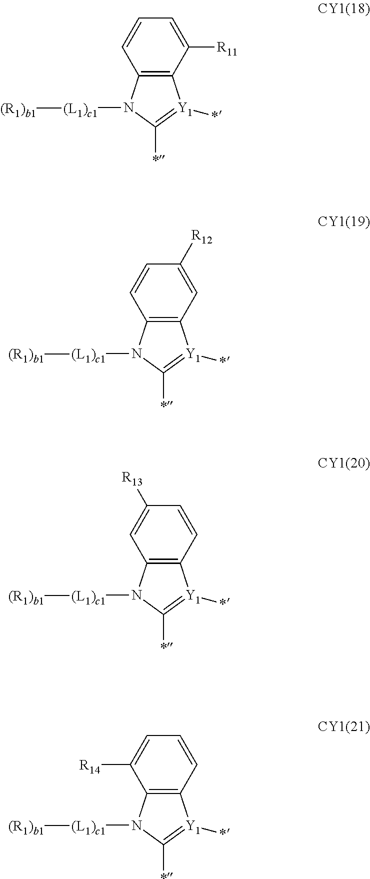

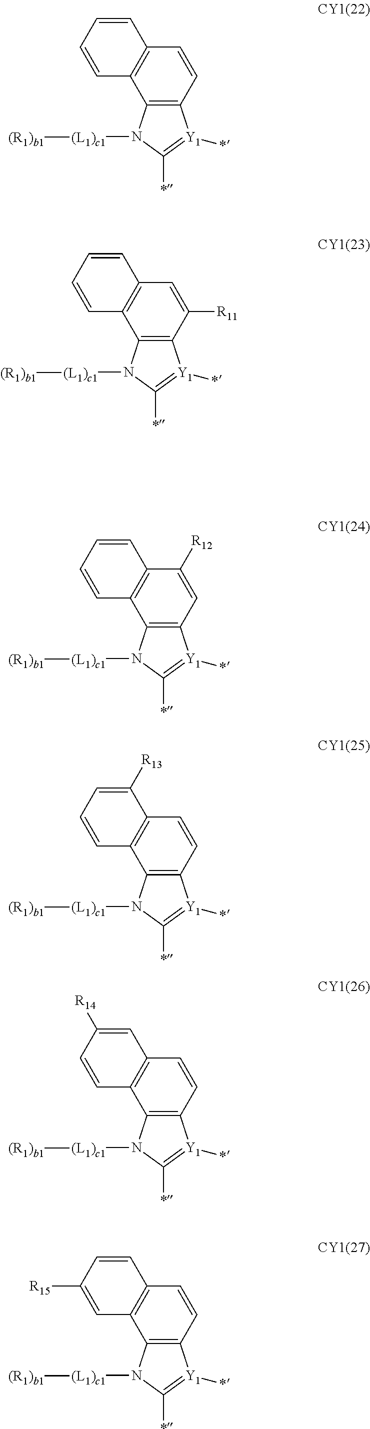

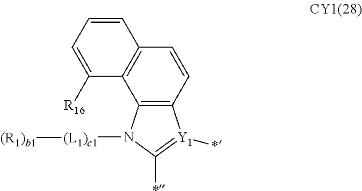

wherein, in Formulae CY1(1) to CY1(28),

Y₁ may be understood by referring to the description of Y₁ provided herein,

L₁, c1, R₁, and b1 may respectively be understood by referring to the descriptions of L₁, c1, R₁, and b1 provided herein,

R₁₁ to R₁₄ may each be understood by referring to the description of R₁ provided herein, wherein R₁₁ to R₁₄ may not each be hydrogen,

*′ indicates a binding site to M in Formula 1, and

*″ indicates a binding site to one of T₁ to T₄ in Formula 2A.

In one or more embodiments, in Formula 2A, a group represented by

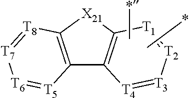

may be represented by one of Formulae CY2-1 to CY2-6:

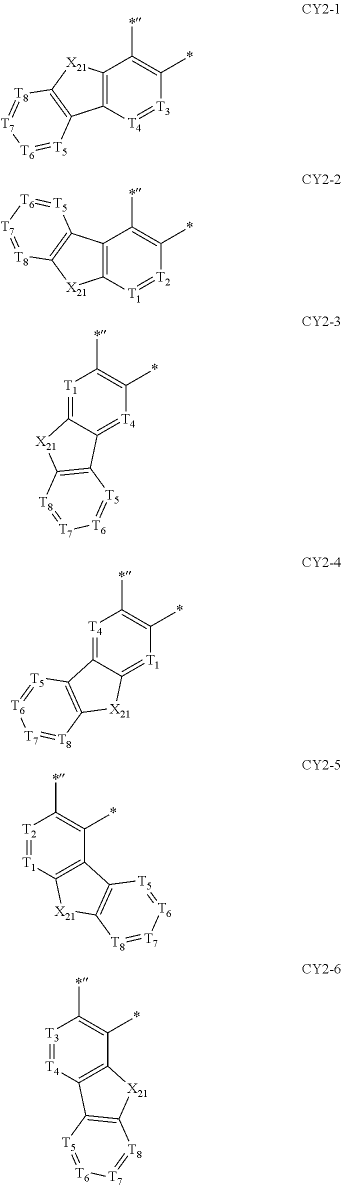

wherein, in Formulae CY2-1 to CY2-6,

T₁ to T₄ may each independently be C or N,

X₂₁ and T₅ to T₈ may respectively be understood by referring to the descriptions of X₂₁ and T₅ to T₈ provided herein,

* indicates a binding site to M in Formula 1, and

*″ indicates a binding site to ring CY₁ in Formula 2A.

In some embodiments, in Formulae CY2-1 to CY2-6, T₁ to T₈ may each be C.

In some embodiments, in Formulae CY2-1 to CY2-6, T₁ to T₇ may each be C, and T₈ may be N.

In one or more embodiments, in Formula 1, L₁ may include deuterium, a fluoro group (—F), a deuterated C₁-C₂₀ alkyl group, a fluorinated C₁-C₂₀ alkyl group, a cyano group, a group represented by —Si(Qs)(Q₄)(Q₅), a group represented by —Ge(Q₃)(Q₄)(Q₅), or any combination thereof.

In Formula 1, L₂ may be represented by one of Formulae 3A to 3F:

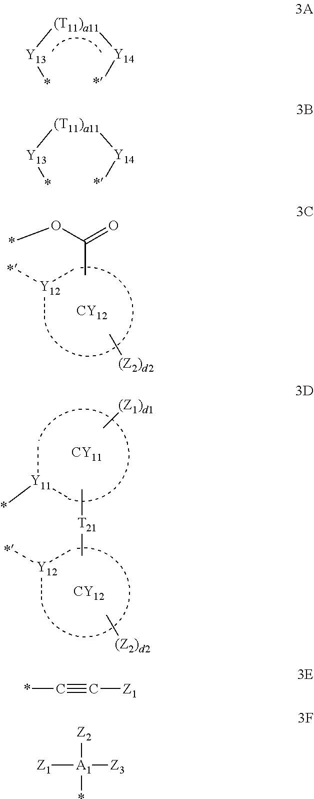

wherein in Formulae 3A to 3F,

Y₁₃ may be O, N, N(Z₁), P(Z₁)(Z₂), or As(Z₁)(Z₂),

Y₁₄ may be O, N, N(Z₃), P(Z₃)(Z₄), or As(Z₃)(Z₄),

Tn may be a single bond, a double bond, *—C(Z₁₁)(Z₁₂)—*′, *—C(Z₁₁)═C(Z₁₂)—*′, *═C(Z₁₁)—*′, *—C(Z₁₁)=*′, *═C(Z₁₁)—C(Z₁₂)═C(Z₁₃)—*′, *—C(Z₁₁)═C(Z₁₂)—C(Z₁₃)=*′, *—N(Z₁₁)—*′, or a C₅-C₃₀ carbocyclic group unsubstituted or substituted with at least one Z₁₁,

a11 may be an integer from 1 to 10, and when a11 is 2 or greater, at least two T₁₁ (s) may be identical to or different from each other,

Y₁₁ and Y₁₂ may each independently be C or N,

T₂₁ may be a single bond, a double bond, O, S, C(Z₁₁)(Z₁₂), Si(Z₁₁)(Z₁₂), or N(Z-n),

ring CY₁₁ and ring CY₁₂ may each independently be a C₅-C₃₀ carbocyclic group or a C₁-C₃₀ heterocyclic group,

A₁ may be P or As,

Z₁ to Z₄ and Z₁₁ to Z₁₃ may each be understood by referring to the descriptions of R₁ provided herein,

d1 and d2 may each independently be an integer from 0 to 20, and

* and *′ each indicate a binding site to M in Formula 1.

In some embodiments, in Formula 1, L₂ may be a group represented by Formula 3D.

In some embodiments, in Formula 3D, ring CY₁₁ may be represented by one of Formulae CY11-1 to CY11-36:

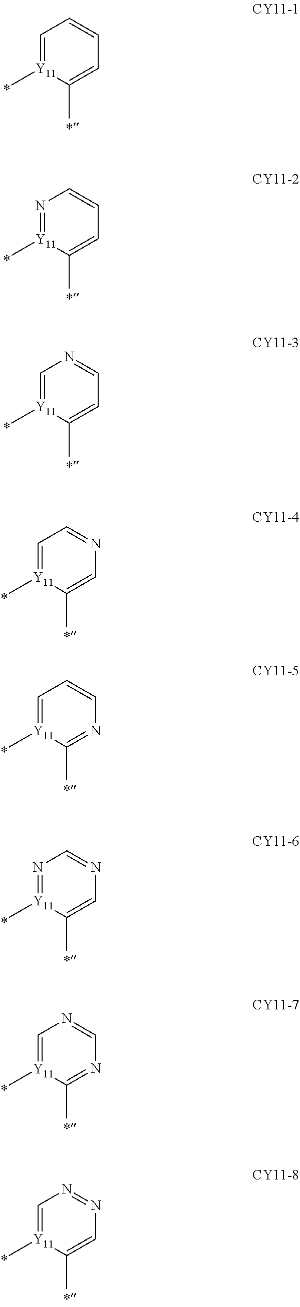

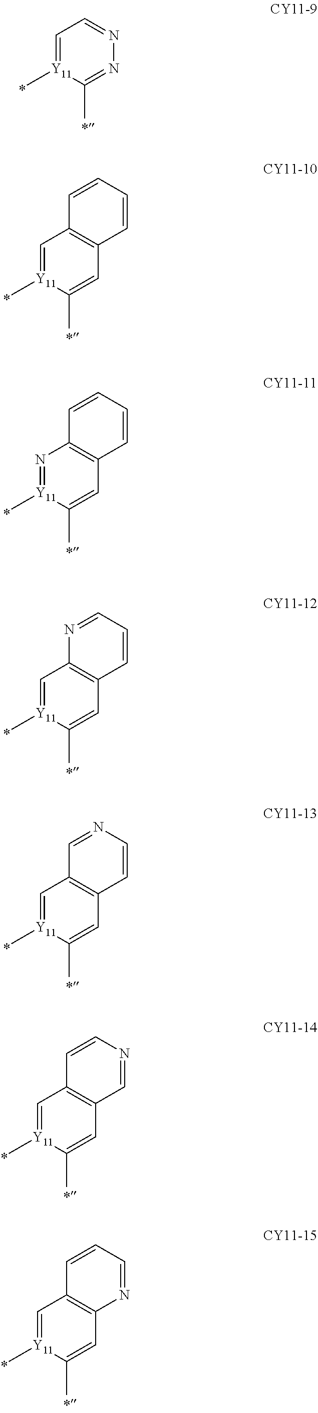

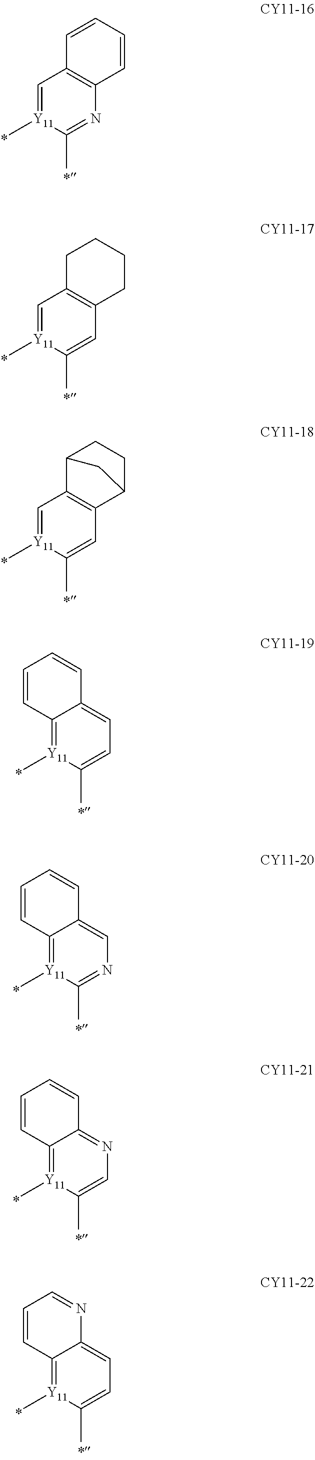

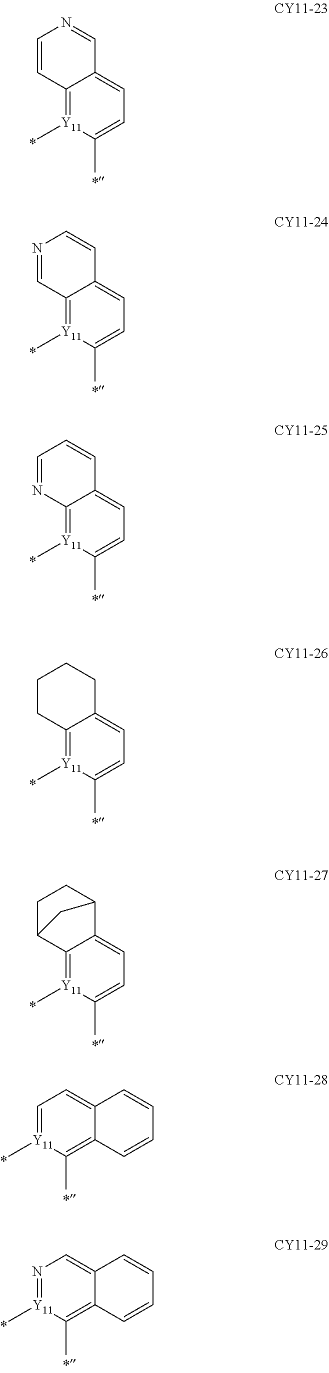

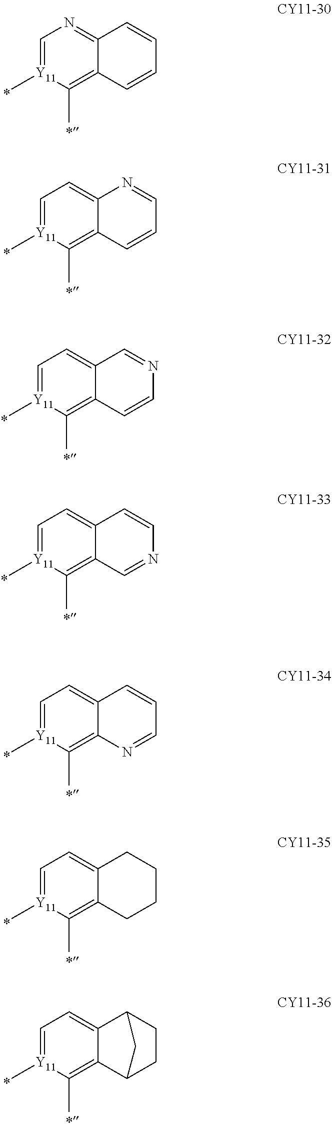

wherein, in Formulae CY11-1 to CY11-36,

Y₁₁ may be understood by referring to the description of Y₁ provided herein,

* indicates a binding site to M in Formula 1, and

*″ indicates a binding site to T₂₁ in Formula 3D.

In Formula 3D, at least one hydrogen in Formulae CY11-1 to CY11-36 may optionally be substituted with Z₁ in Formula 3D.

In one or more embodiments, in Formula 3D, a group represented by

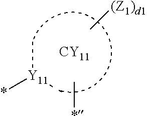

may be represented by one of Formulae CY11(1) to CY11(25):

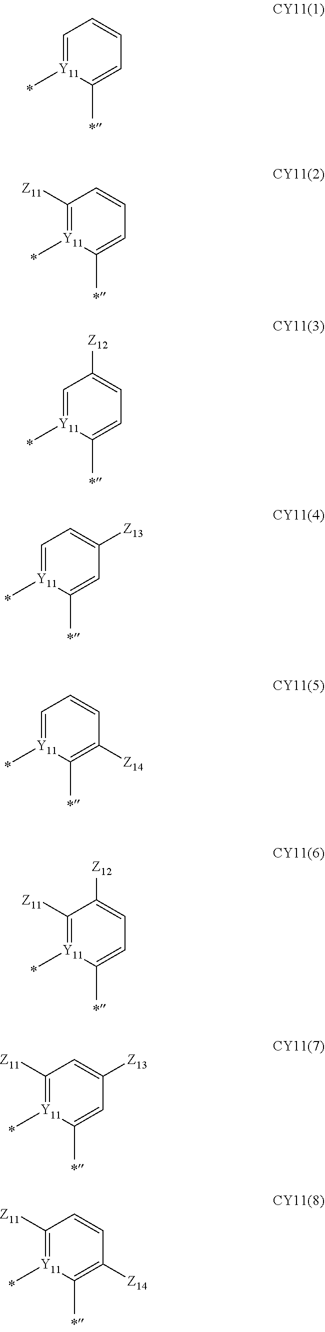

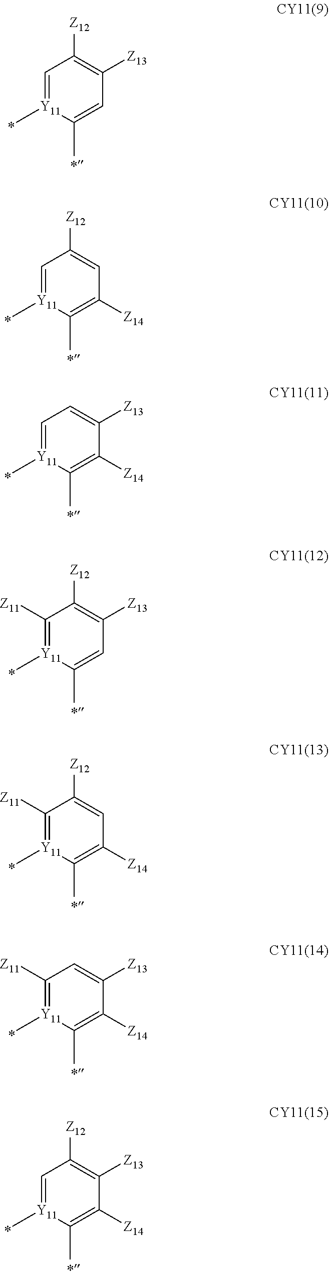

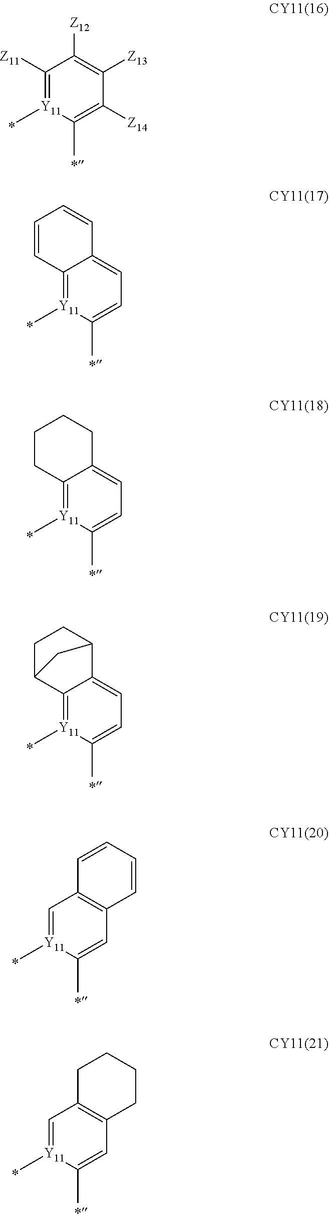

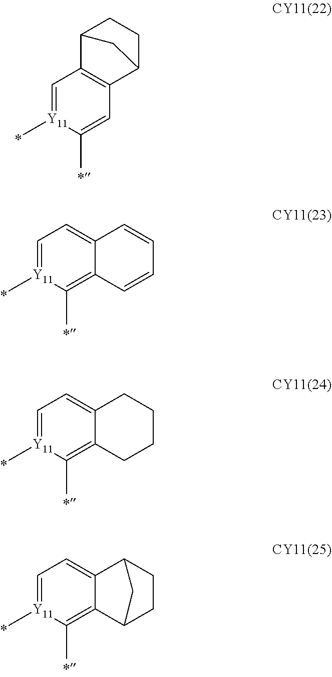

wherein, in Formulae CY11(1) to CY11(25),

Y₁₁ may be understood by referring to the description of Yu provided herein,

Z₁₁ to Z₁₄ may each be understood by referring to the description of Z₁ provided herein, wherein Z₁₁ to Z₁₄ may not each be hydrogen,

* indicates a binding site to M in Formula 1, and

*″ indicates a binding site to T₂₁ in Formula 3D.

In some embodiments, Z₁₂ in Formulae CY11(3), CY11(6), CY11(9), CY11(10), CY11(12), CY11(13), CY11(15), and CY11(16) may be a group represented by —Si(Q₃)(Q₄)(Q₅) or —Ge(Q₃)(Q₄)(Q₅).

In some embodiments, the number of carbon atoms included in Z₁₃ in Formulae CY11(4), CY11(7), CY11(9), CY11(11), CY11(12), CY11(14), and CY11(15) may be 2 or greater.

In one or more embodiments, in Formulae 3C and 3D, ring CY₁₂ may be represented by one of Formulae CY12-1 to CY12-56:

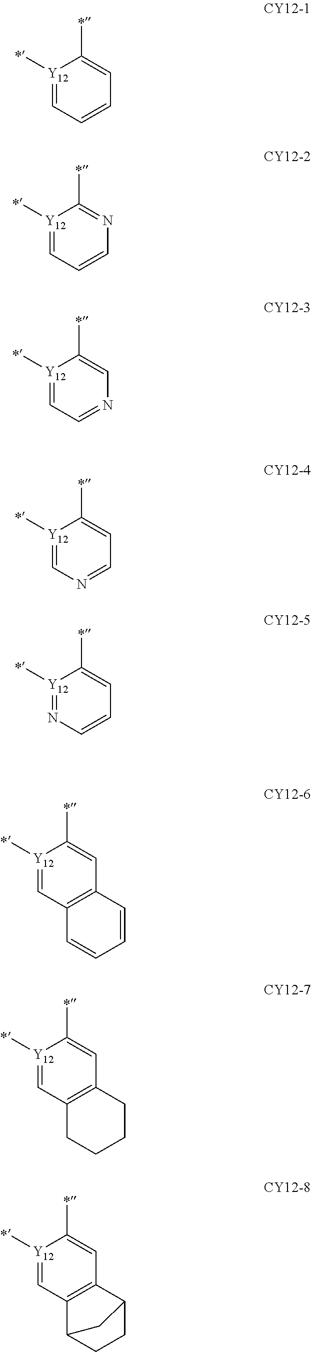

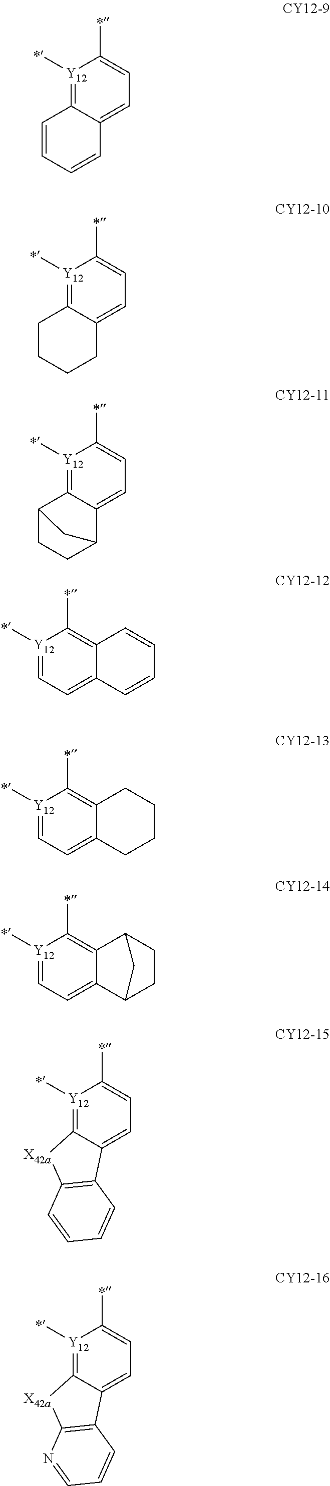

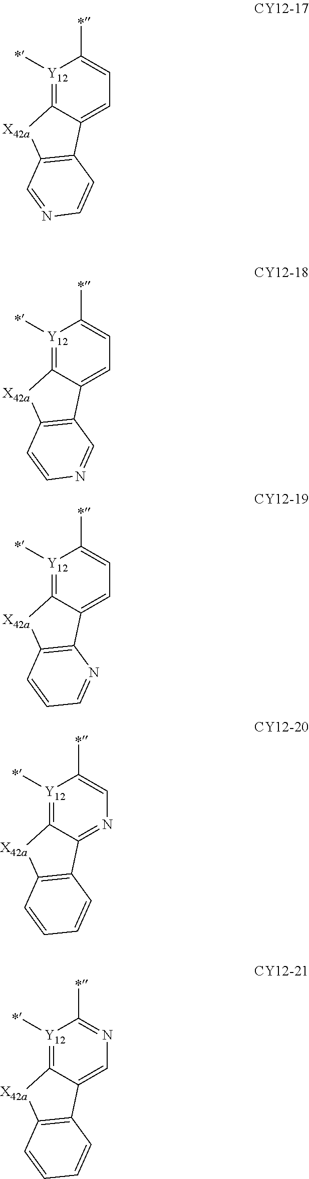

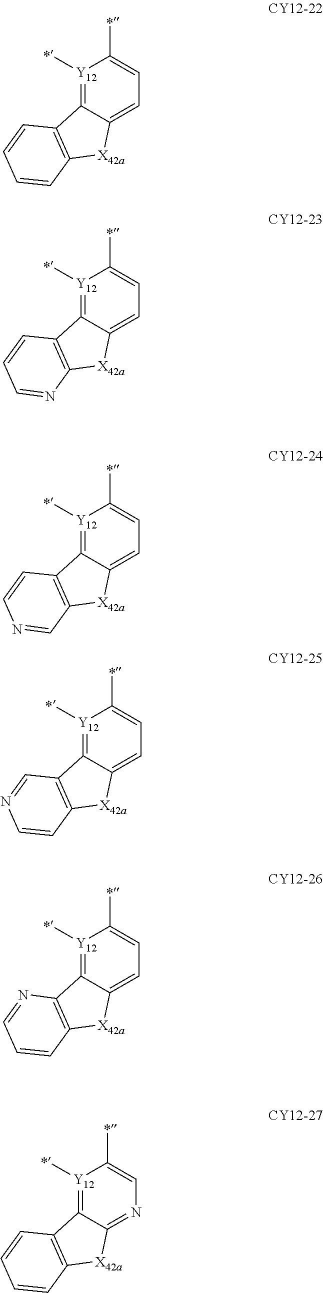

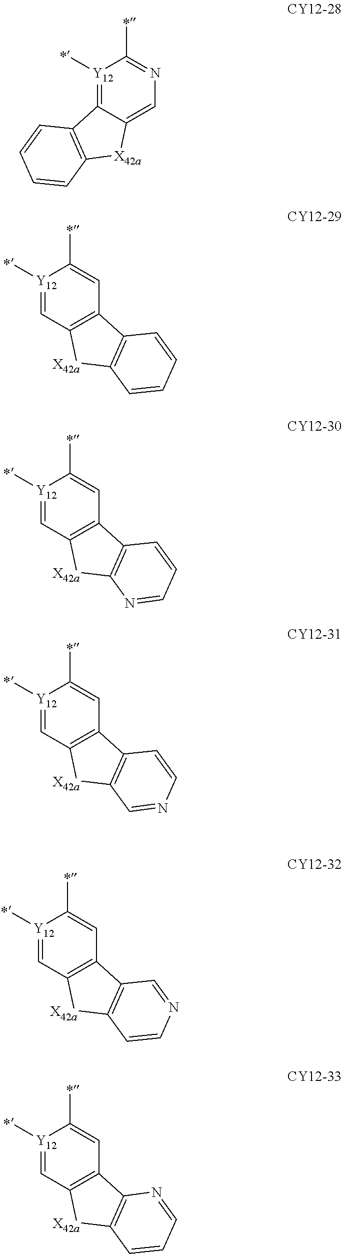

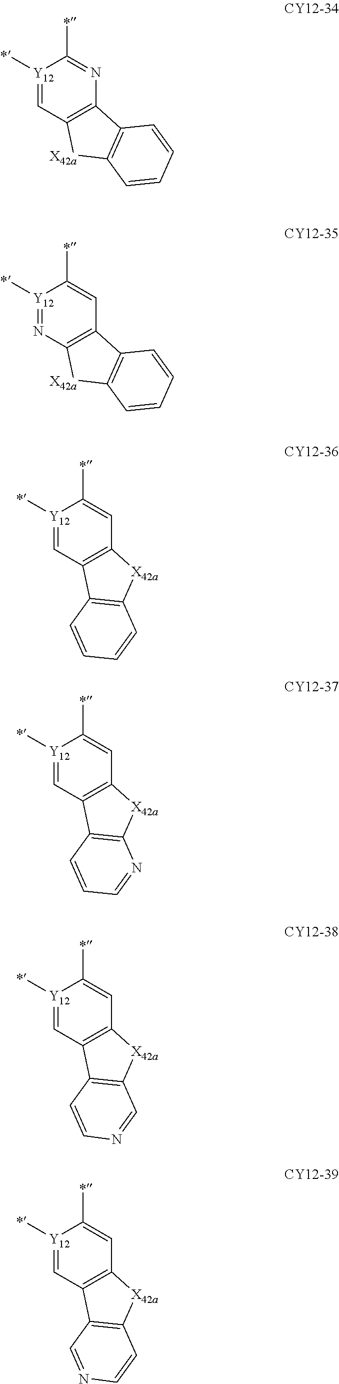

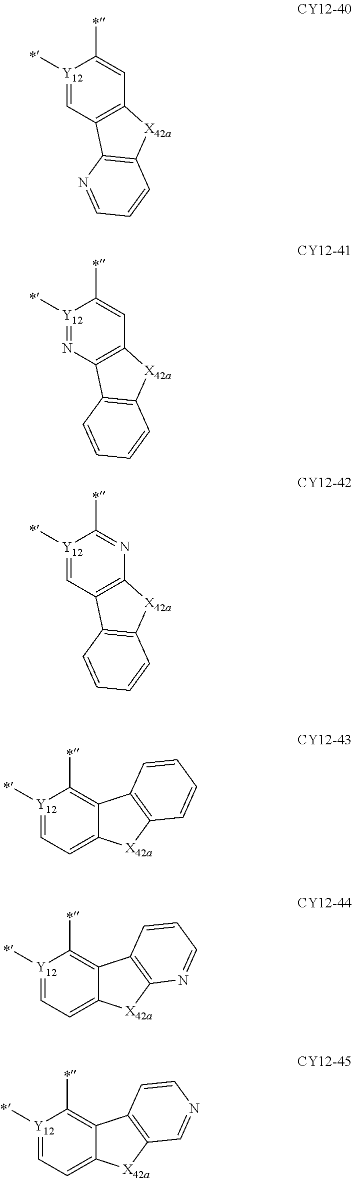

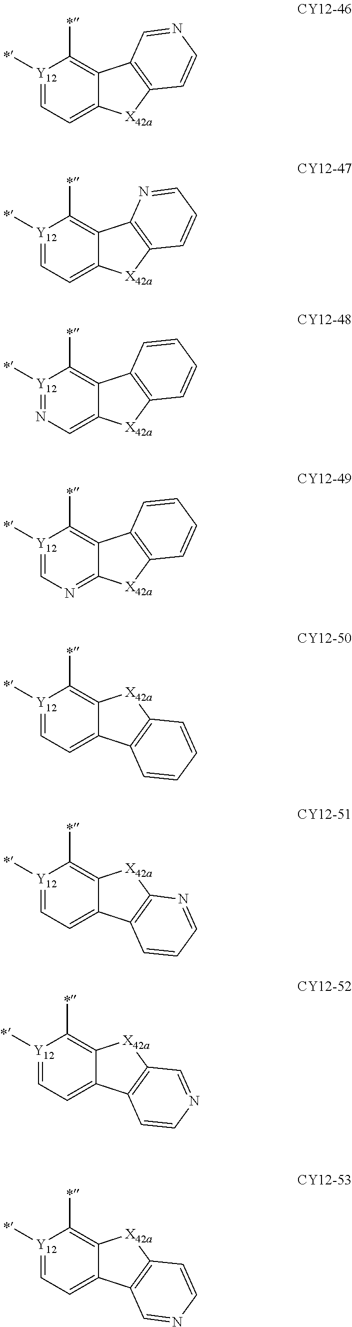

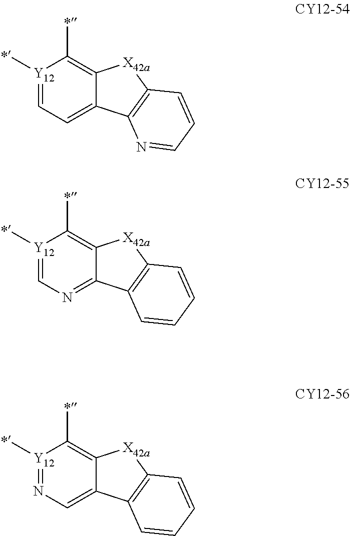

wherein, in Formulae CY12-1 to CY12-56,

Y₁₂ may be understood by referring to the description of Y₁₂ provided herein,

X₄₂ₐ may be O, S, N, C, or Si,

*′ indicates a binding site to M in Formula 1, and

* indicates a binding site to an adjacent atom.

In Formulae 3C and 3D, at least one hydrogen of Formulae CY12-1 to CY12-56 may optionally be substituted with Z₂ in Formulae 3C and 3D.

In one or more embodiments, in Formulae 3C and 3D, a group represented by

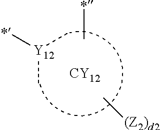

may be represented by Formulae CY12(1) to CY12(63):

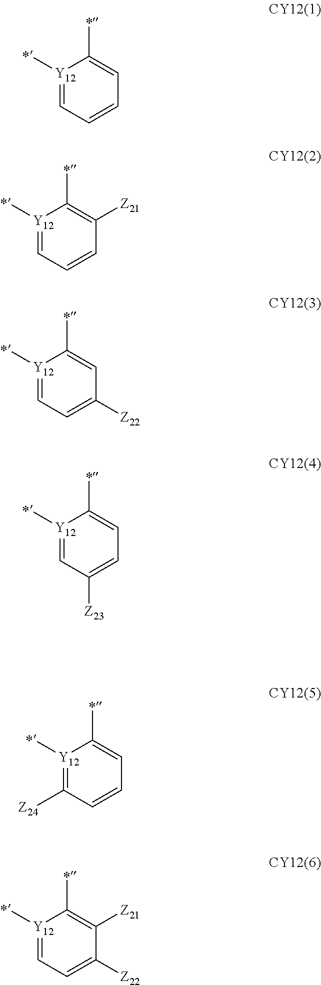

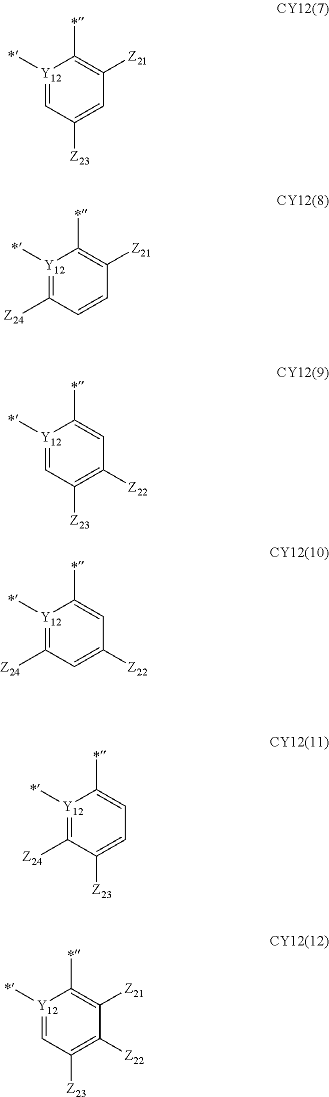

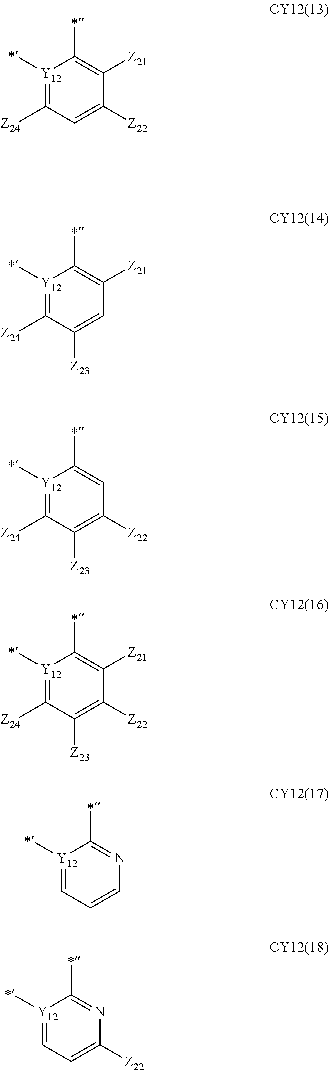

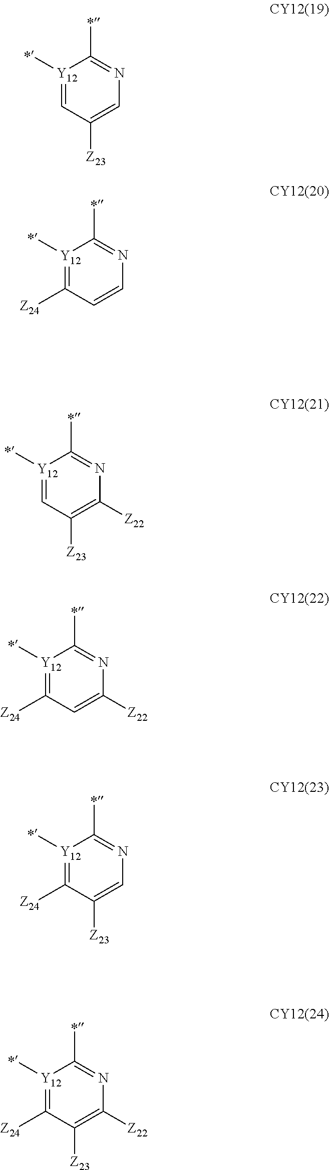

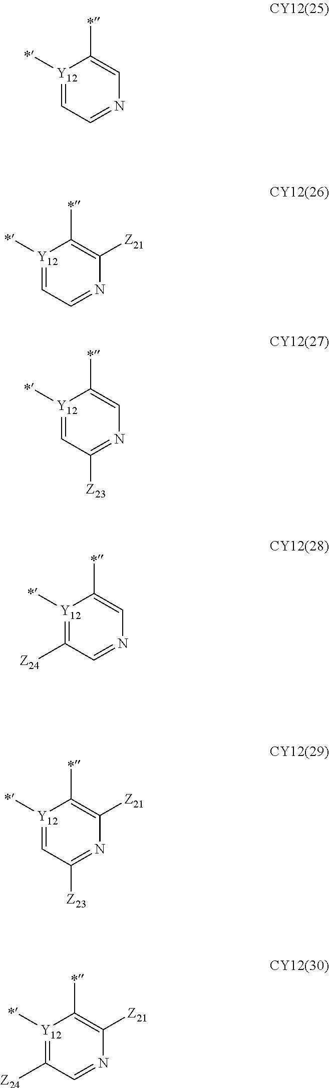

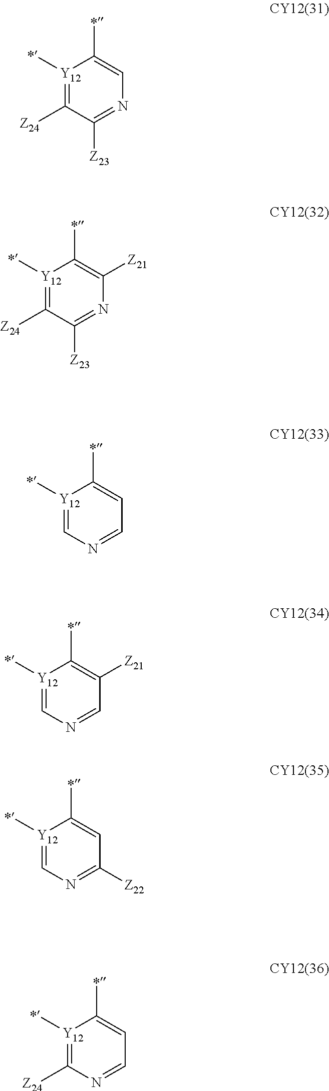

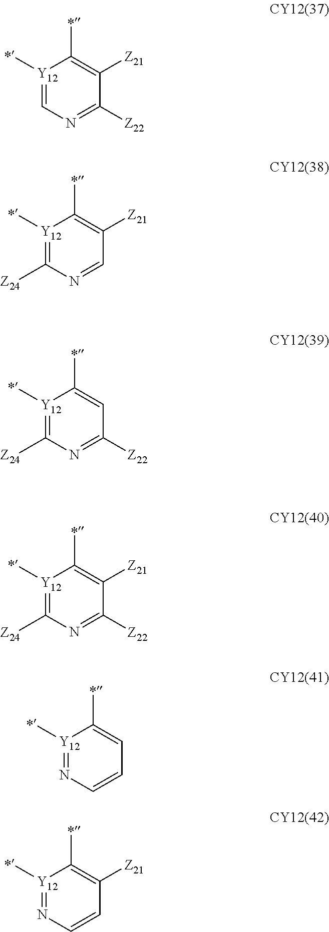

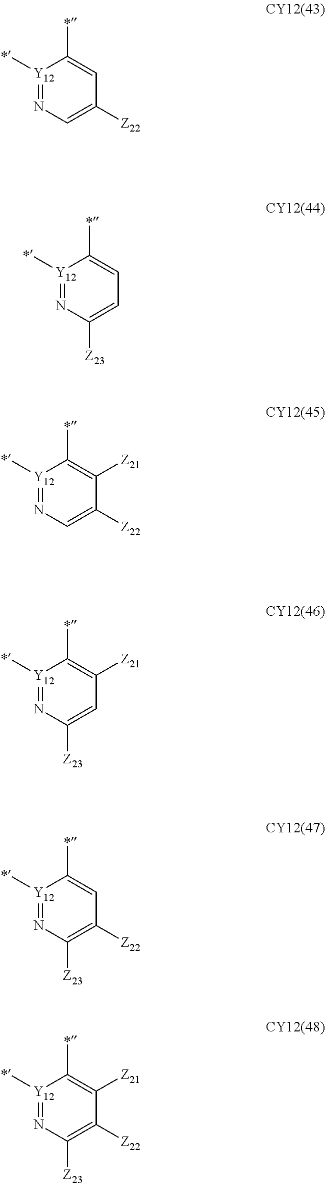

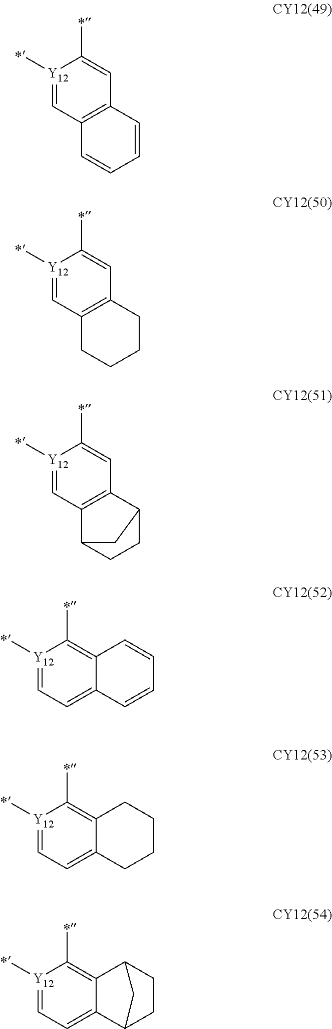

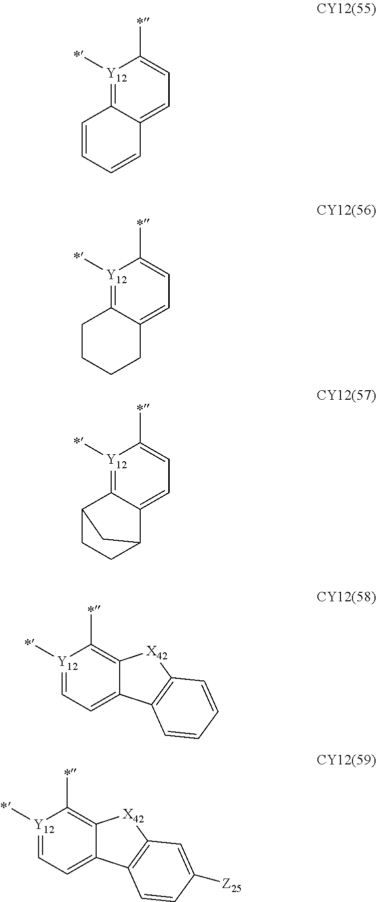

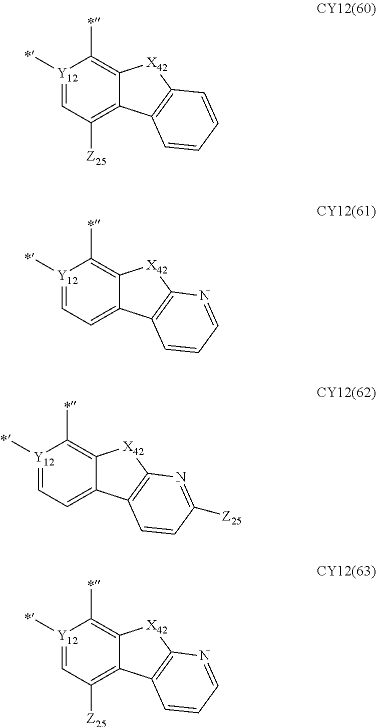

wherein, in Formulae CY12(1) to CY12(63),

Y₁₂ may be understood by referring to the description of Y₁₂ provided herein,

X₄₂ may be C(Z₂₈)(Z₂₉), N(Z₂₈), O, S, or Si(Z₂₈)(Z₂₉),

Z₂₁ to Z₂₅, Z₂₈, and Z₂₉ may each be understood by referring to the description of Z₂ provided herein, wherein Z₂₁ to Z₂₄ may not each be hydrogen,

*′ indicates a binding site to ring M in Formula 1, and

* indicates a binding site to an adjacent atom.

In one or more embodiments, in Formula 1, L₂ may include deuterium, a fluoro group (—F), a deuterated C₁-C₂₀ alkyl group, a fluorinated C₁-C₂₀ alkyl group, a cyano group, a group represented by —Si(Q₃)(Q₄)(Q₅), a group represented by —Ge(Q₃)(Q₄)(Q₅), or any combination thereof.

In one or more embodiments, R₂, R₂₉, and R₃₀ in Formula 2A and Z₁ to Z₄ and Z₁₁ to Z₁₃ in Formulae 3A to 3F may each independently be hydrogen, deuterium, —F, a cyano group, a nitro group, —SF₅, —CH₃, —CD₃, —CD₂H, —CDH₂, —CF₃, —CF₂H, —CFH₂, —OCH₃,-OCDH₂,-OCD₂H, -OCD₃, —SCH₃,-SCDH₂, -SCD₂H, -SCD₃, a group represented by one of Formulae 9-1 to 9-39, a group represented by one of Formulae 9-1 to 9-39 in which at least one hydrogen is substituted with deuterium, a group represented by one of Formulae 9-1 to 9-39 in which at least one hydrogen is substituted with —F, a group represented by one of Formulae 9-201 to 9-233, a group represented by one of Formulae 9-201 to 9-233 in which at least one hydrogen is substituted with deuterium, a group represented by one of Formulae 9-201 to 9-233 in which at least one hydrogen is substituted with —F, a group represented by one of Formulae 10-1 to 10-132, a group represented by one of Formulae 10-1 to 10-132 in which at least one hydrogen is substituted with deuterium, a group represented by one of Formulae 10-1 to 10-132 in which at least one hydrogen is substituted with —F, a group represented by one of Formulae 10-201 to 10-353, a group represented by one of Formulae 10-201 to 10-353 in which at least one hydrogen is substituted with deuterium, a group represented by one of Formulae 10-201 to 10-353 in which at least one hydrogen is substituted with —F, —Si(Q₃)(Q₄)(Q₅), or —Ge(Q₃)(Q₄)(Q₅), wherein to Q₅ may respectively be understood by referring to the descriptions of Q₁ to Q₅ provided herein:

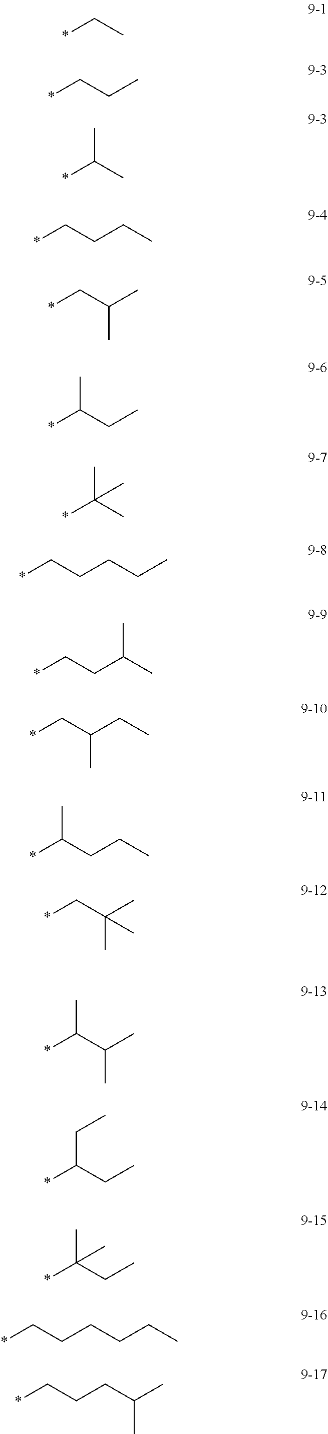

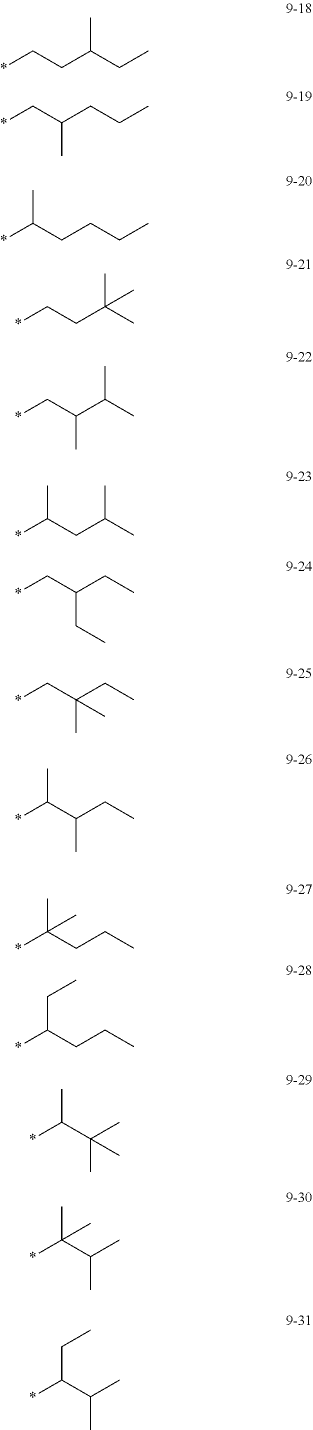

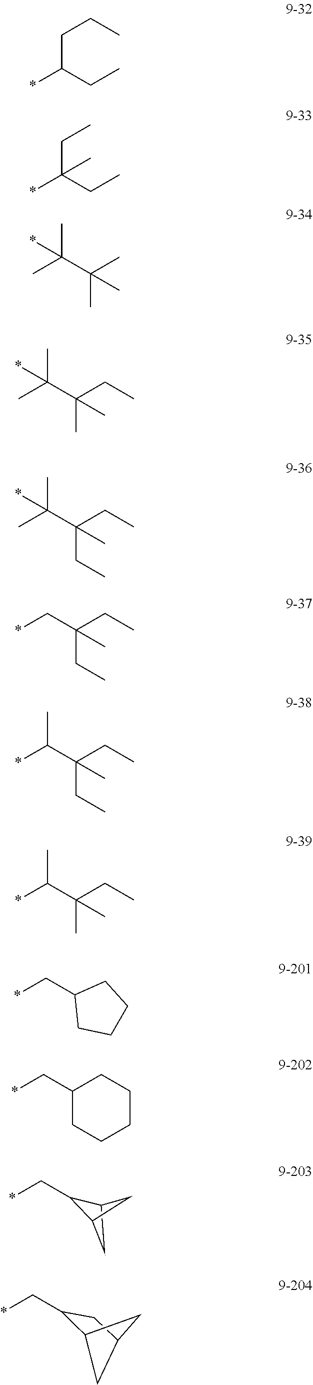

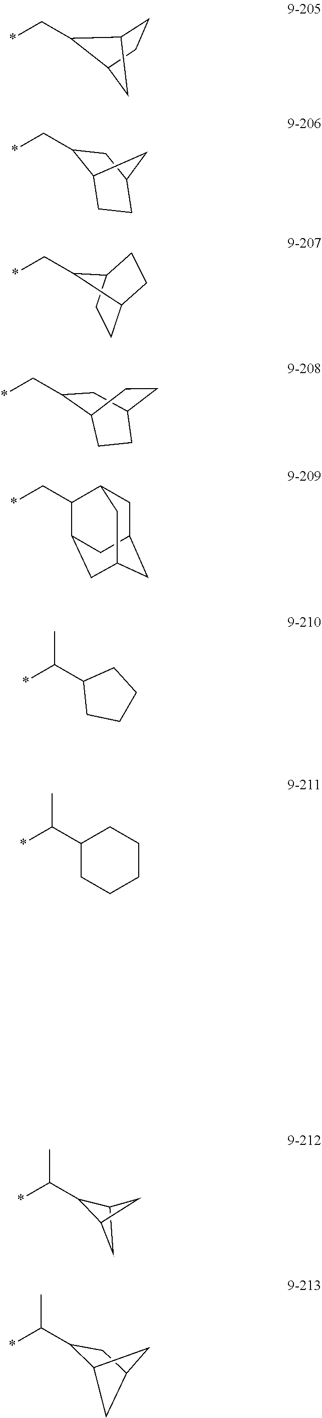

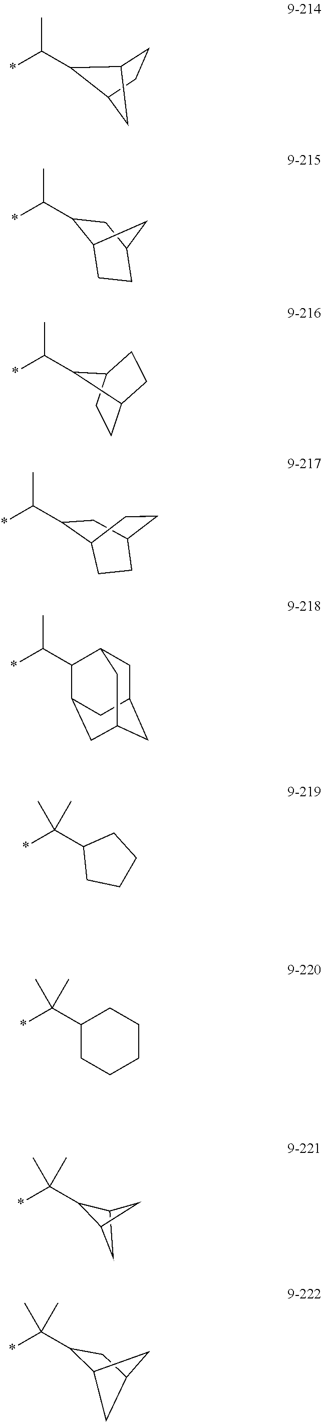

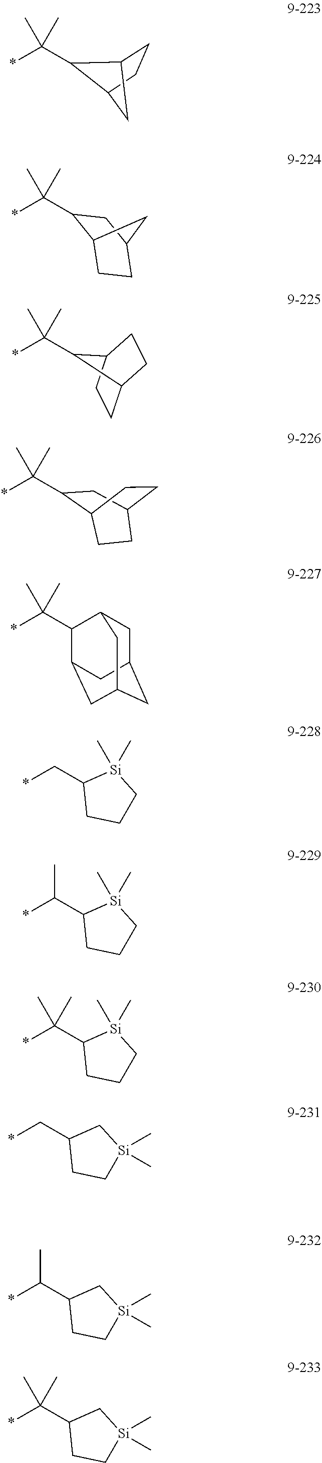

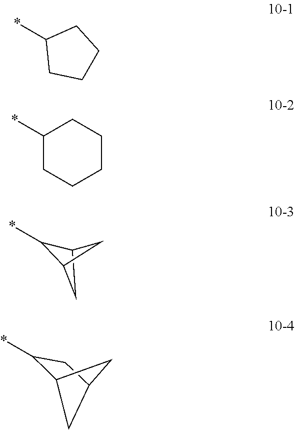

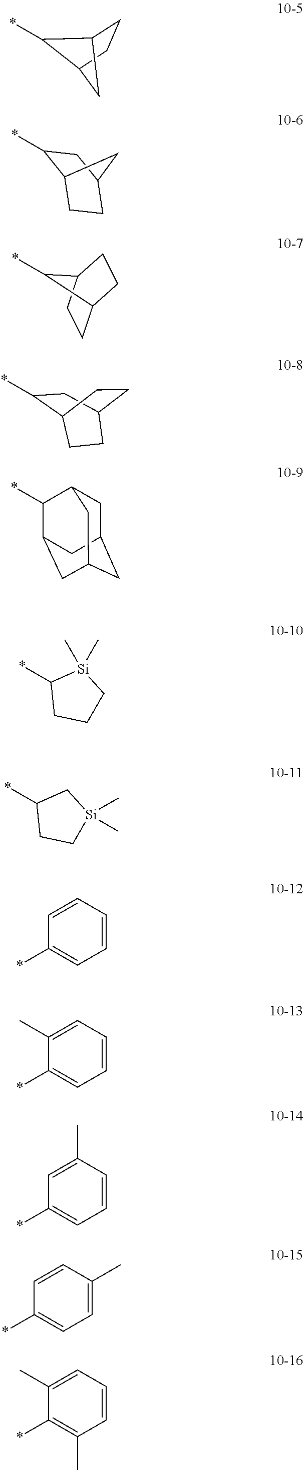

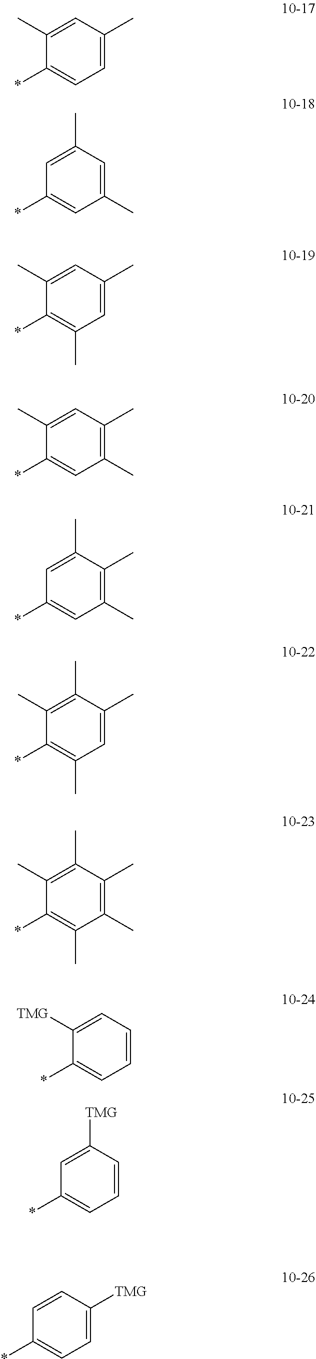

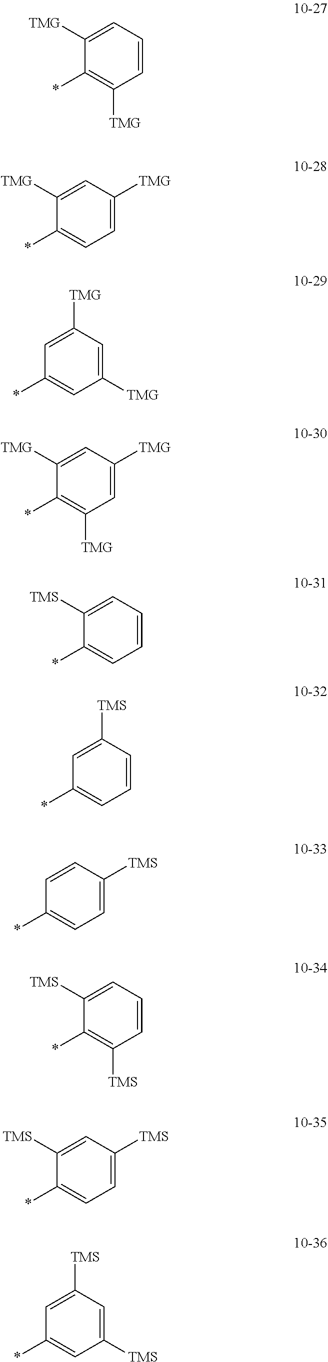

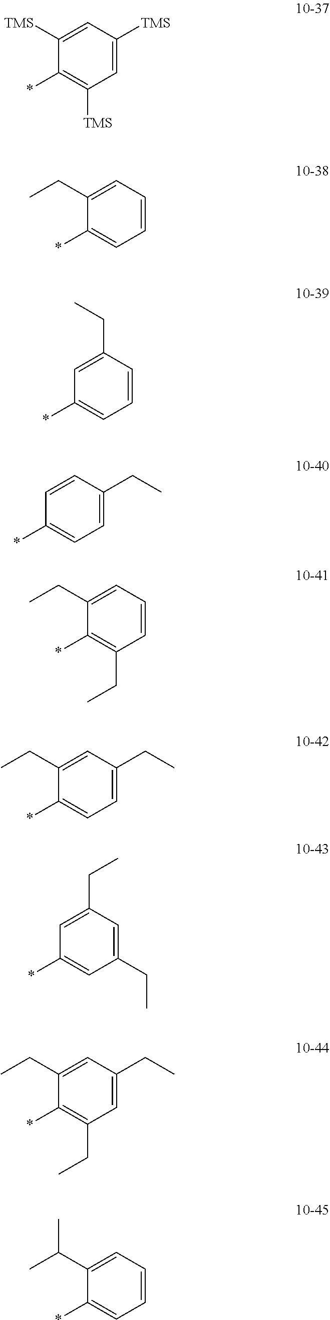

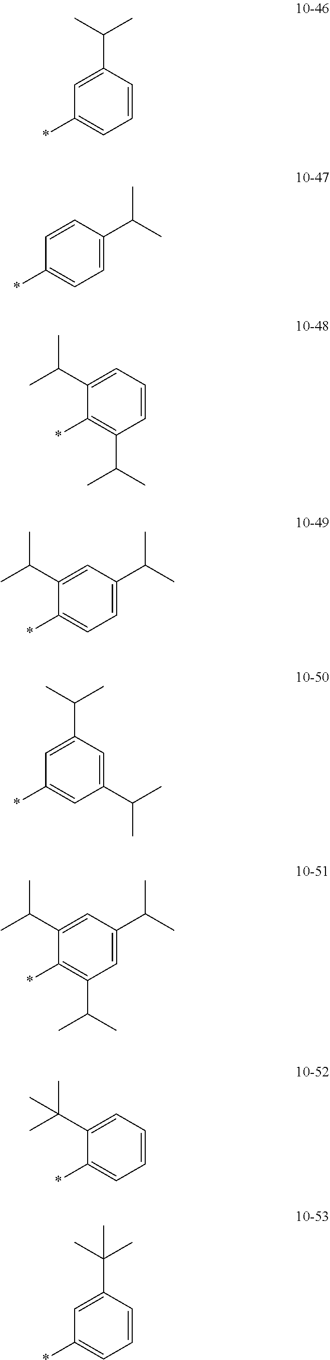

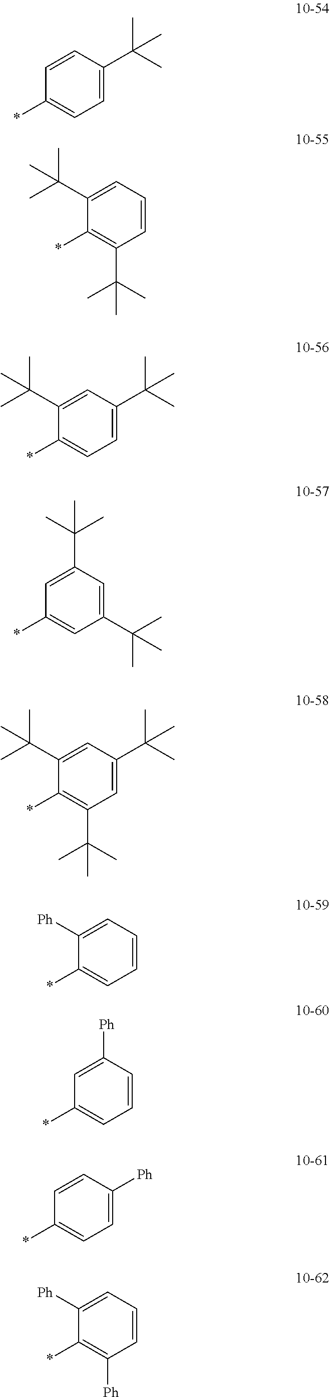

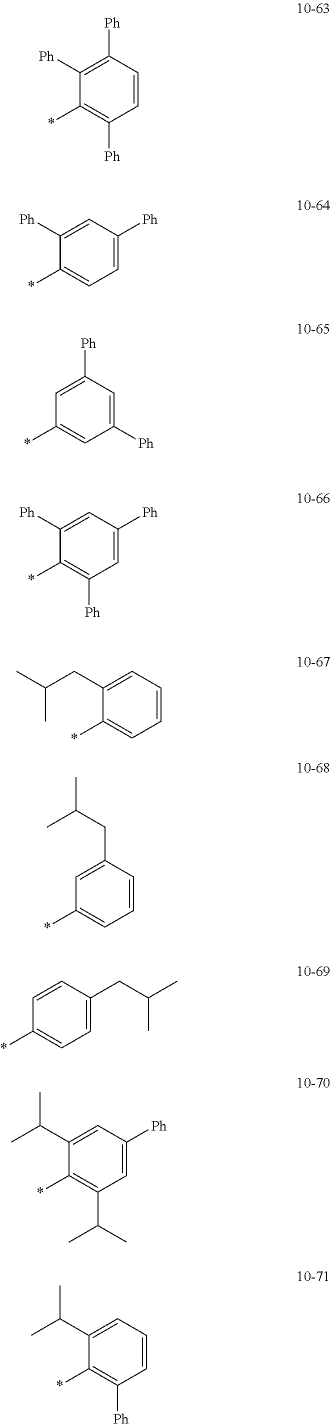

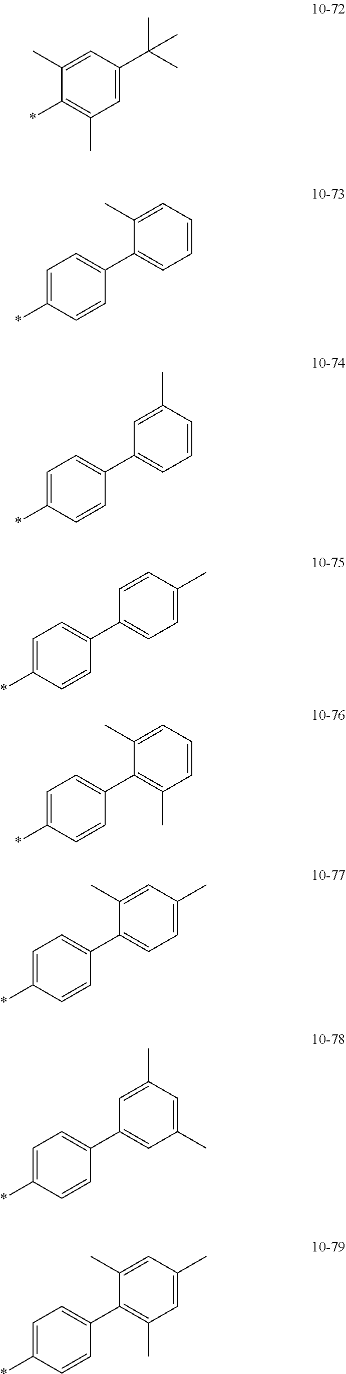

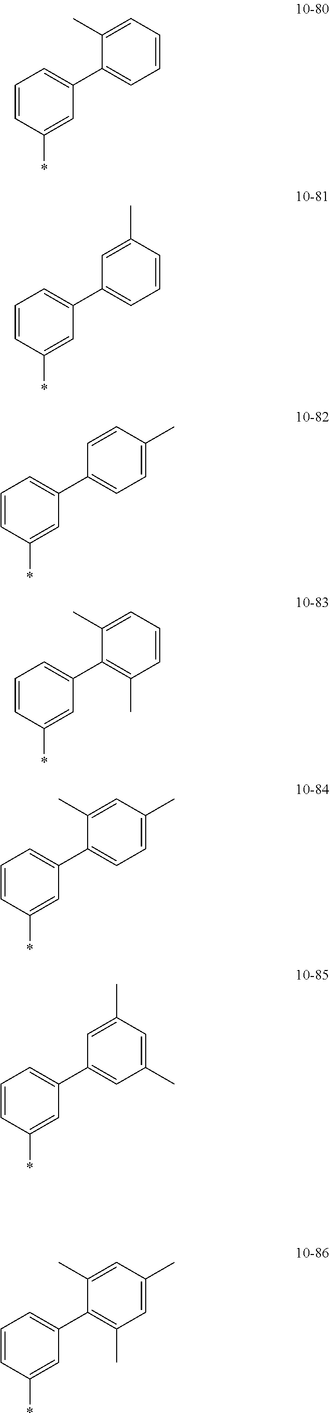

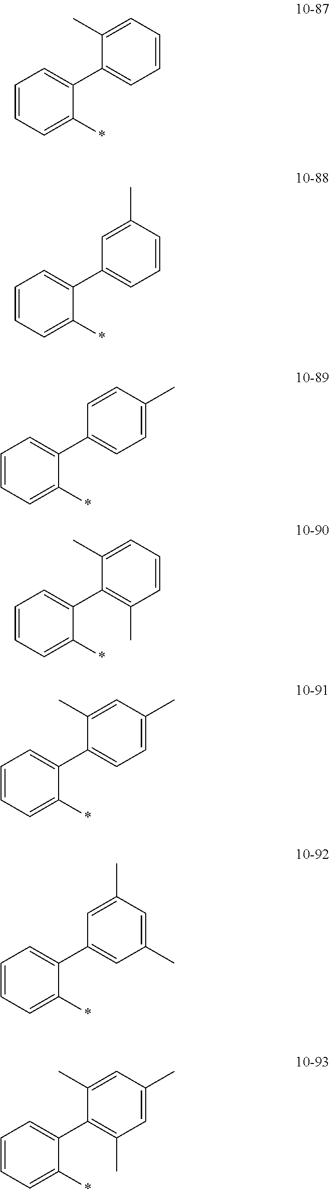

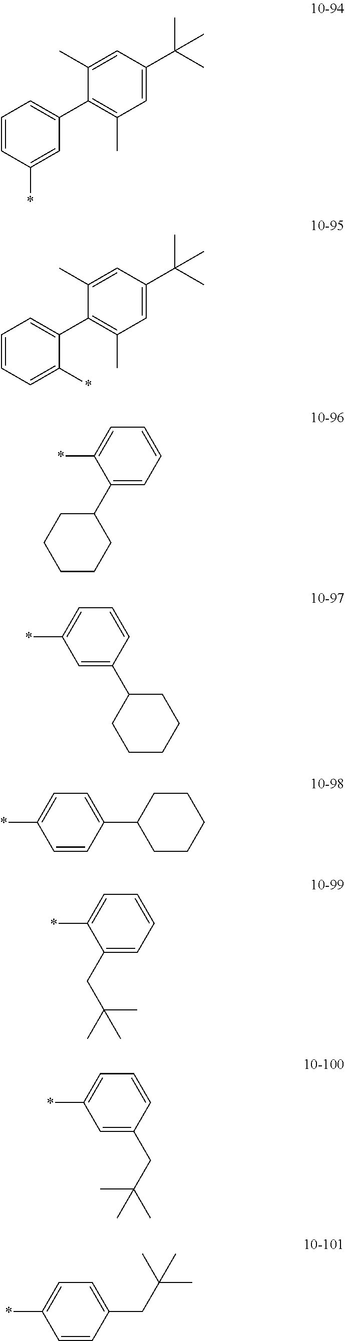

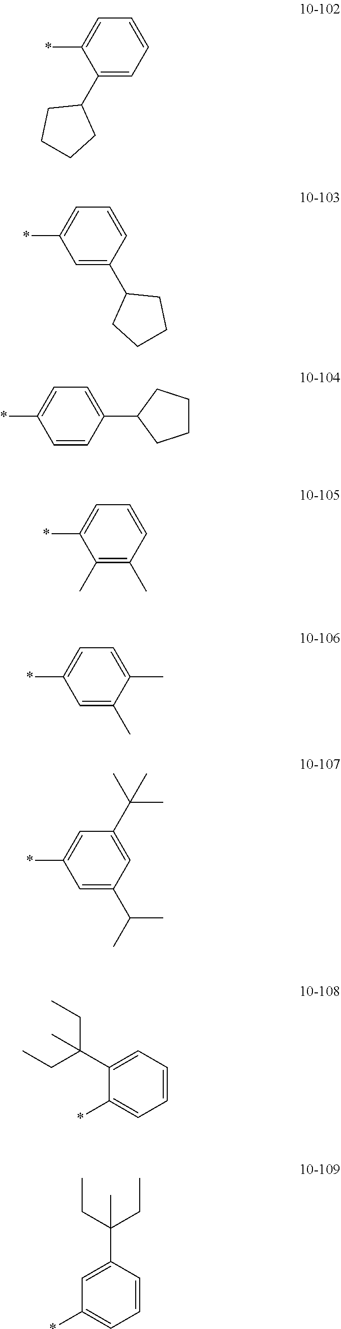

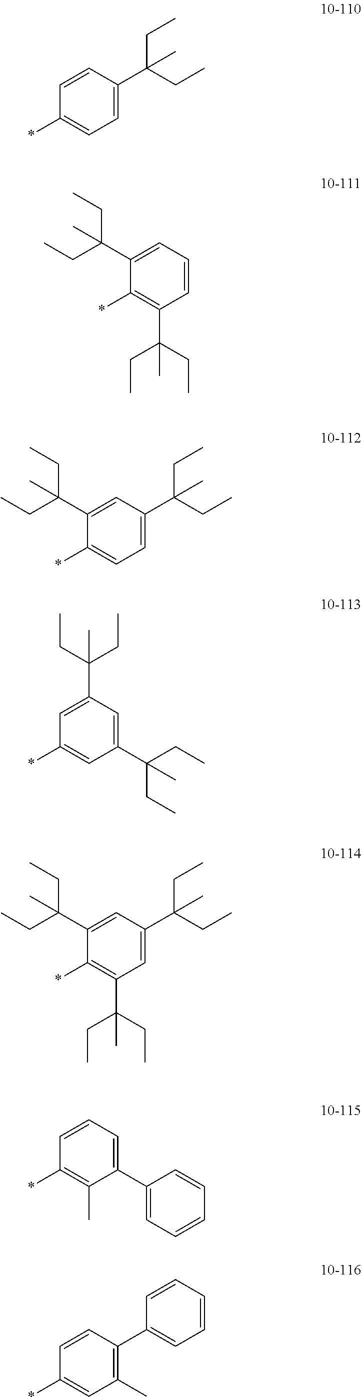

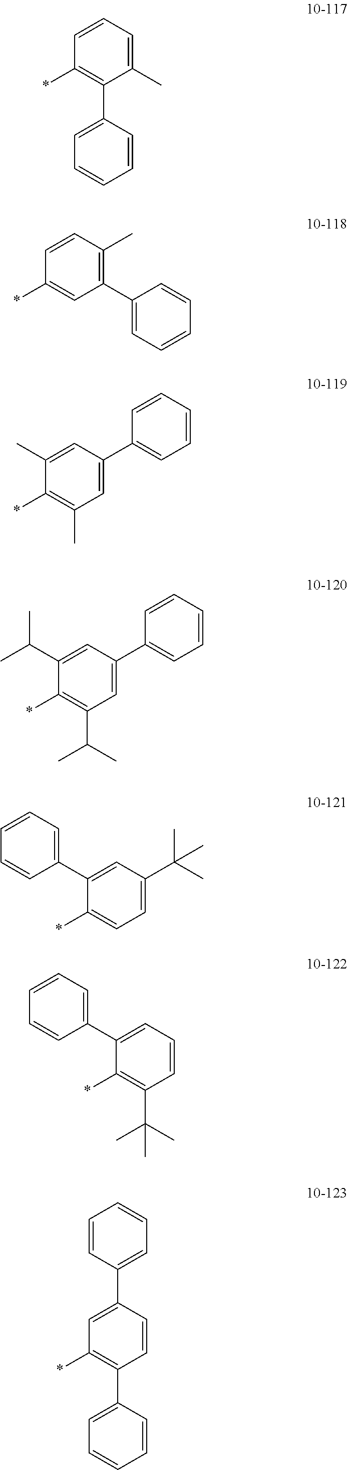

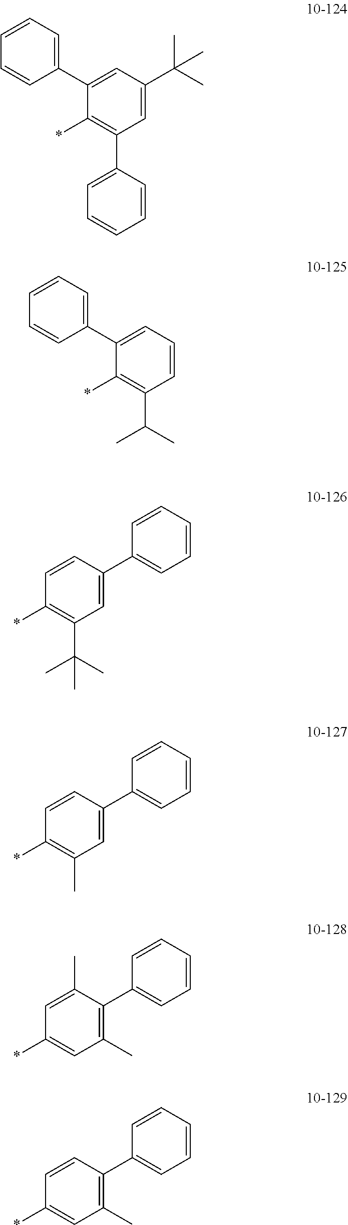 [SMILES: *c1c(-c2ccccc2)cc(C(C)(C)C)cc1-c1ccccc1 ; *c1c(-c2ccccc2)cccc1C(C)C ; *c1ccc(-c2ccccc2)cc1C(C)(C)C ; *c1ccc(-c2ccccc2)cc1C ; *c1cc(C)c(-c2ccccc2)c(C)c1 ; *c1ccc(-c2ccccc2)c(C)c1]

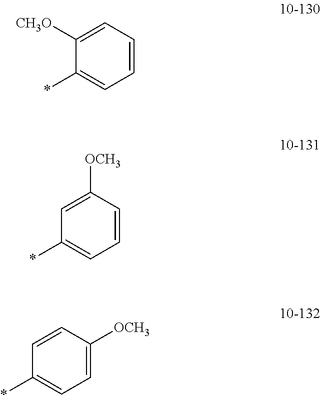

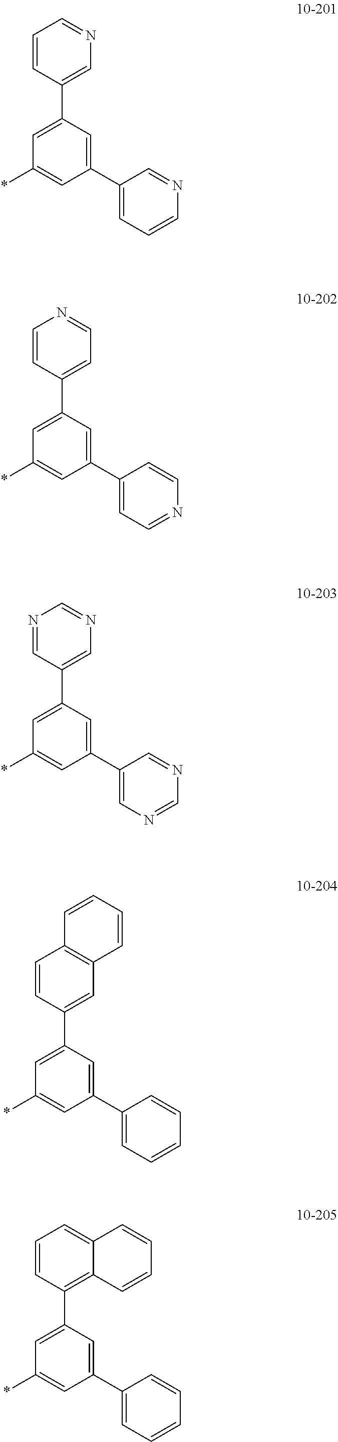 [SMILES: *c1cc(-c2cccnc2)cc(-c2cccnc2)c1 ; *c1cc(-c2ccncc2)cc(-c2ccncc2)c1 ; *c1cc(-c2cncnc2)cc(-c2cncnc2)c1 ; *c1cc(-c2ccccc2)cc(-c2ccc3ccccc3c2)c1 ; *c1cc(-c2ccccc2)cc(-c2cccc3ccccc23)c1]

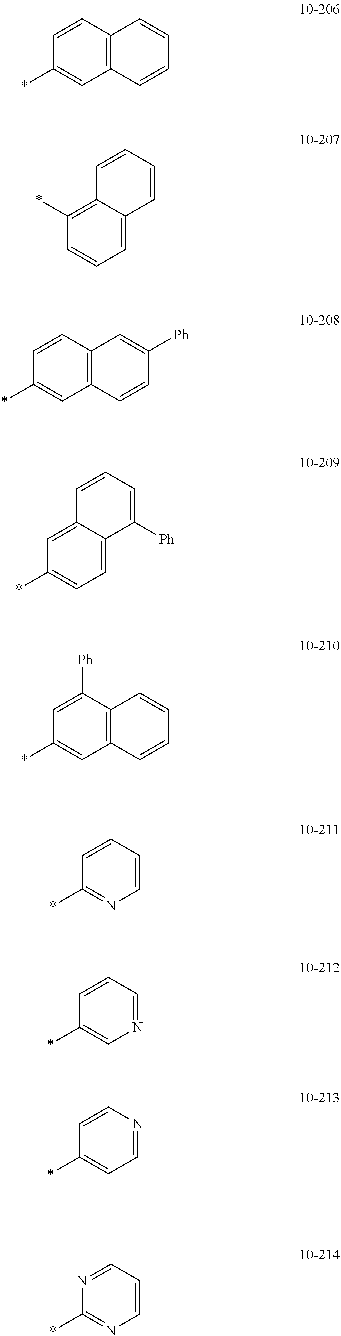

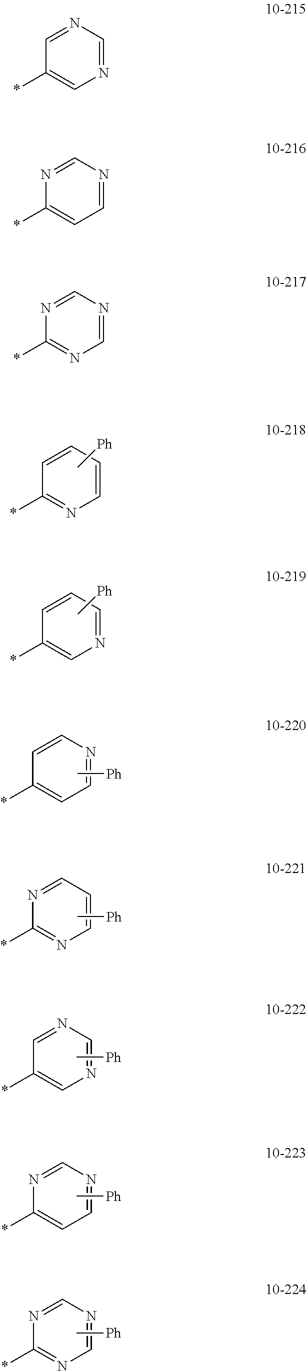

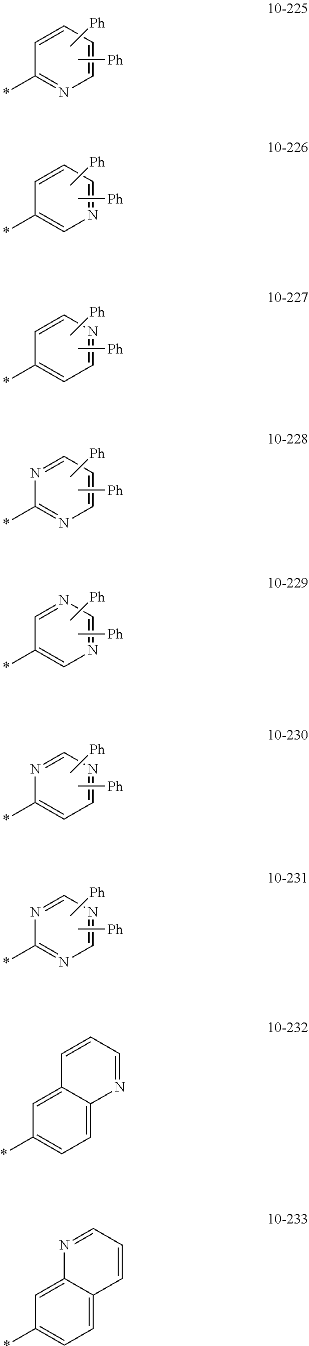

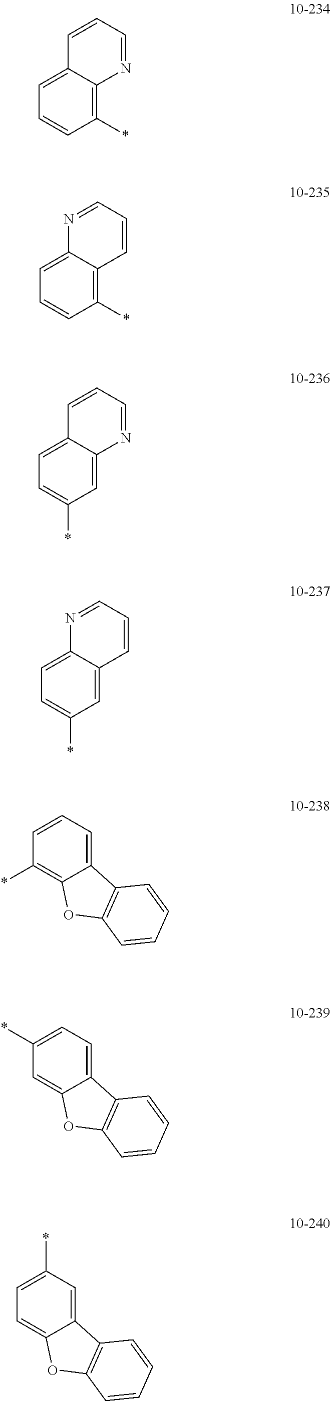

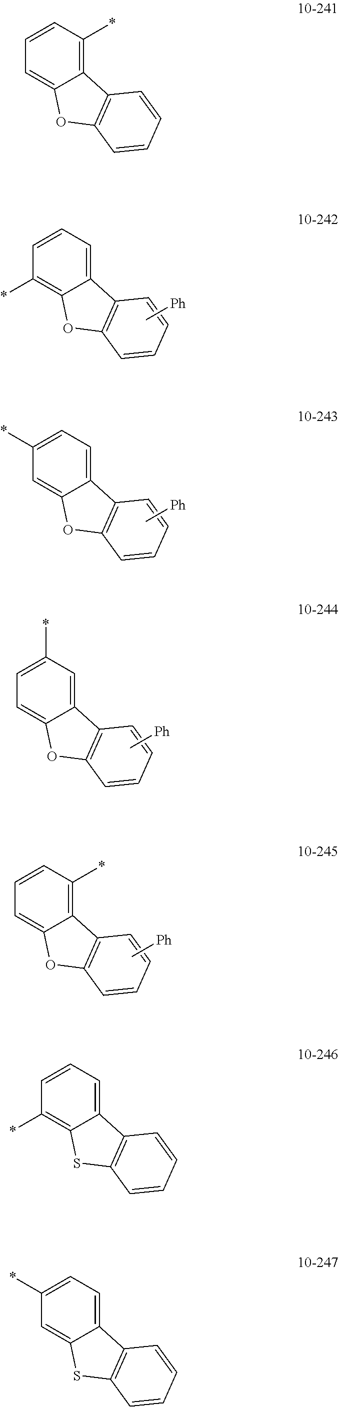

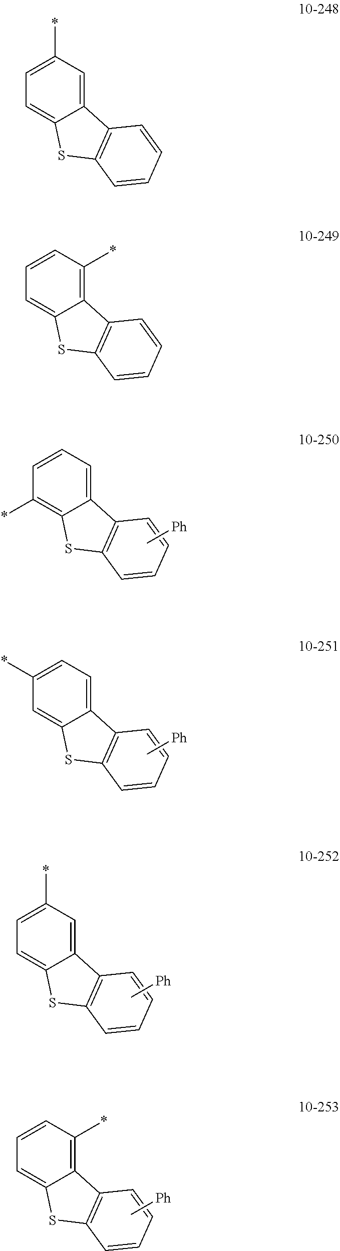

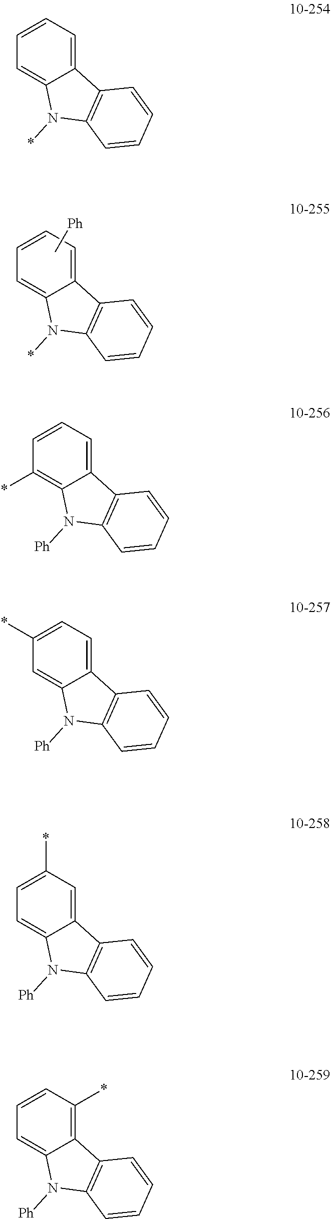

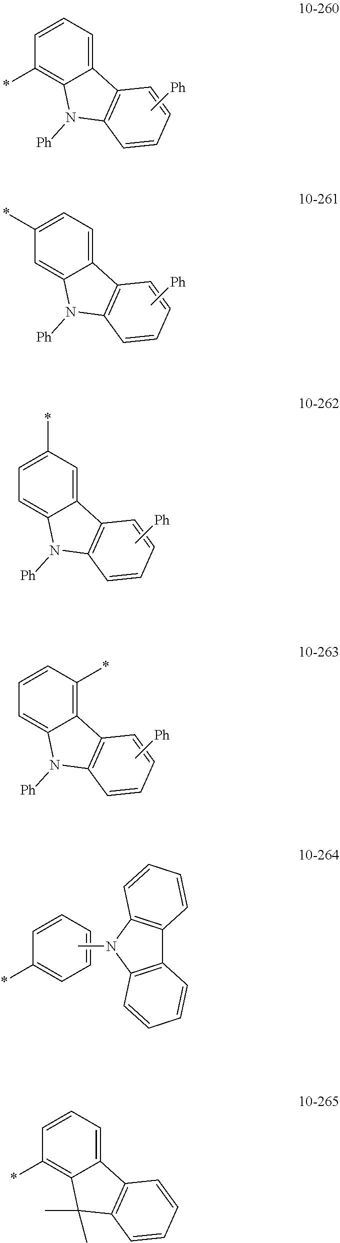

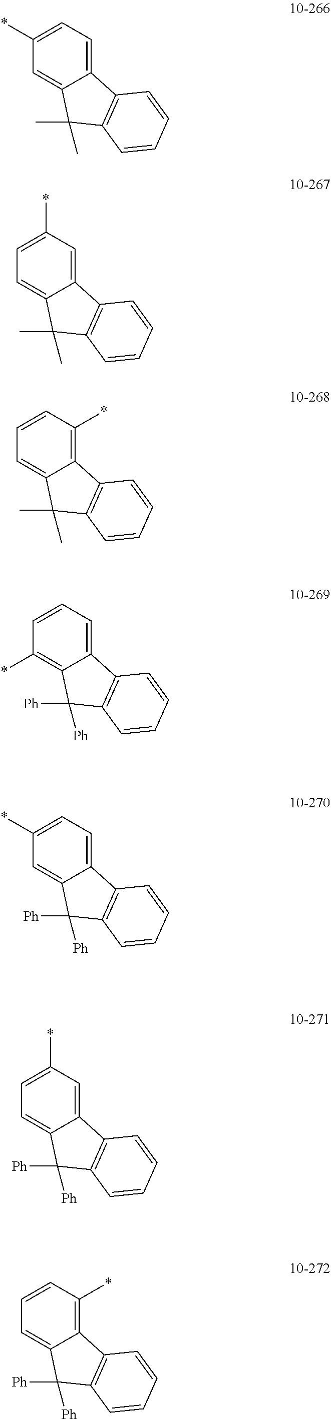

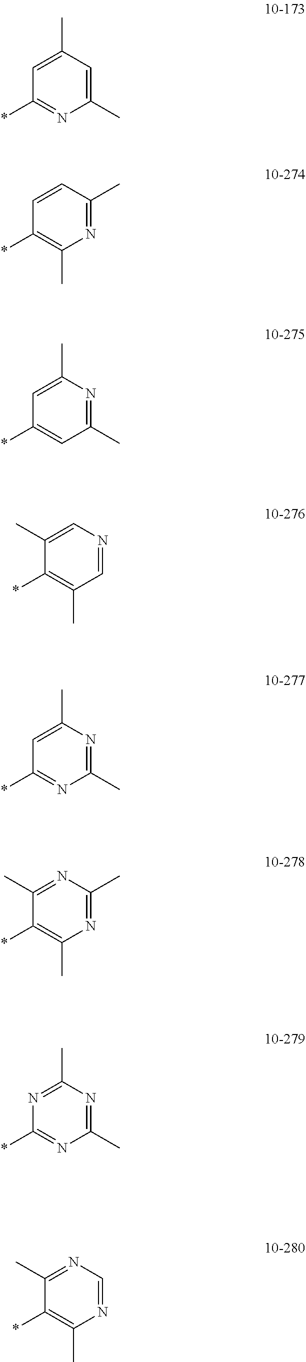

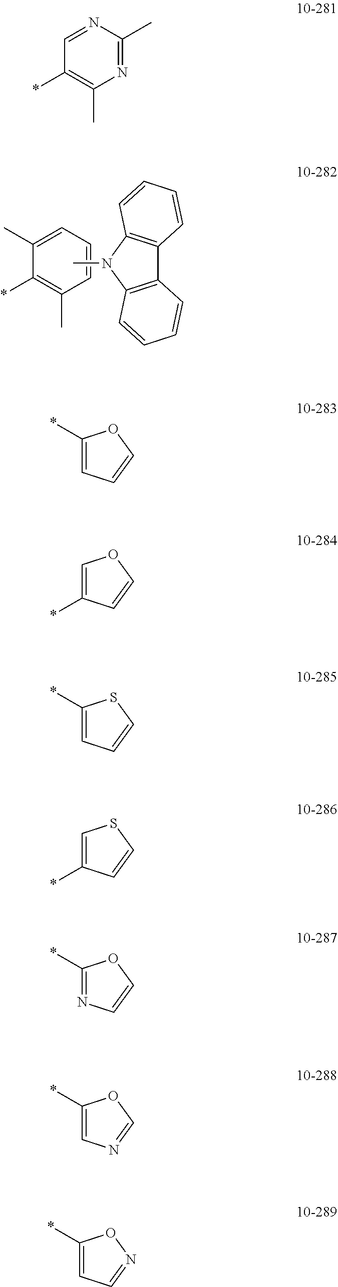

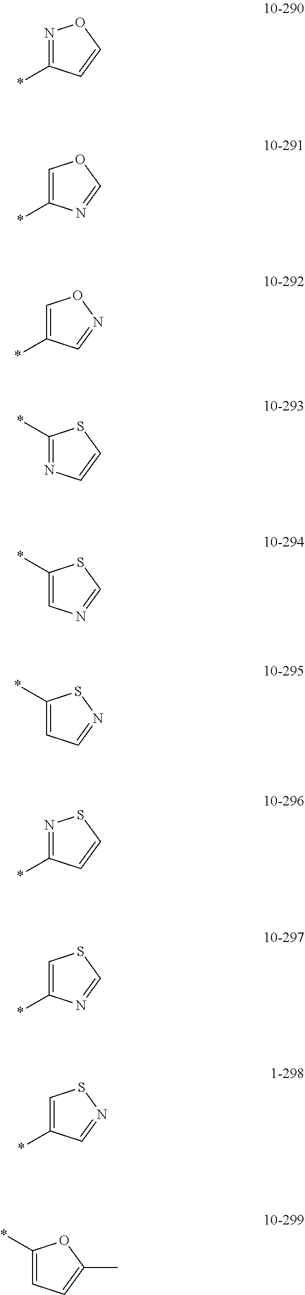

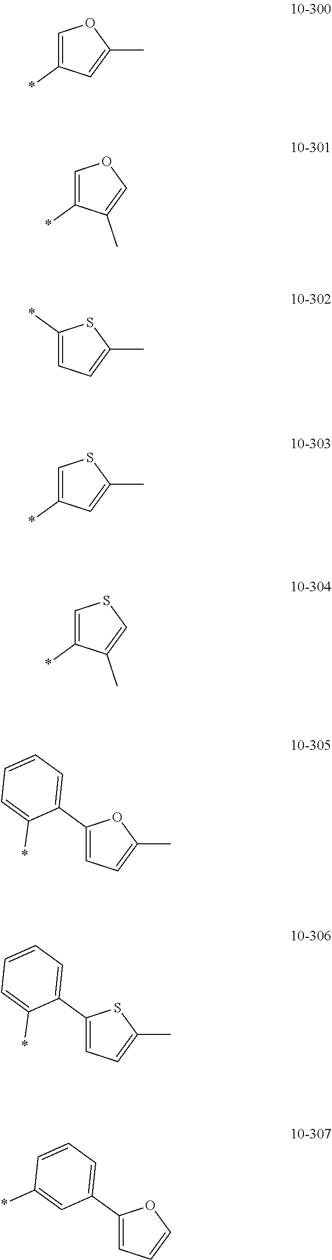

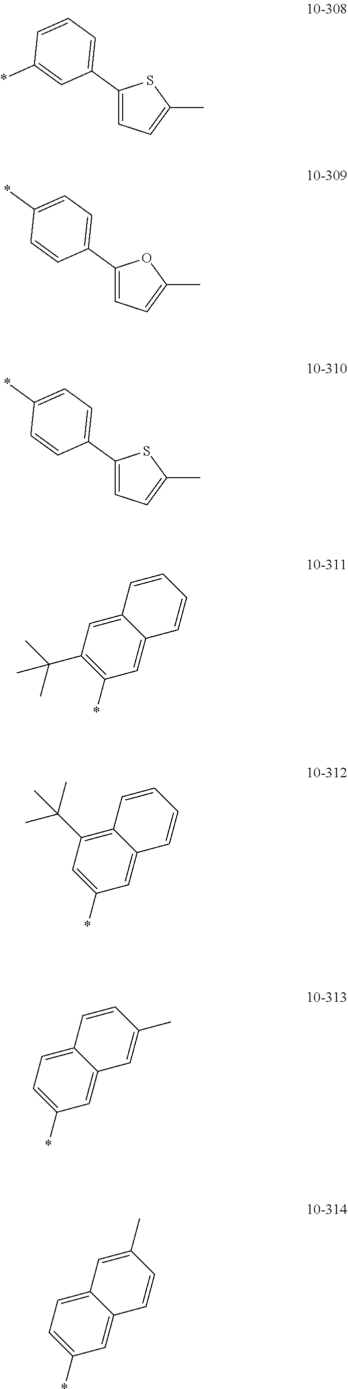

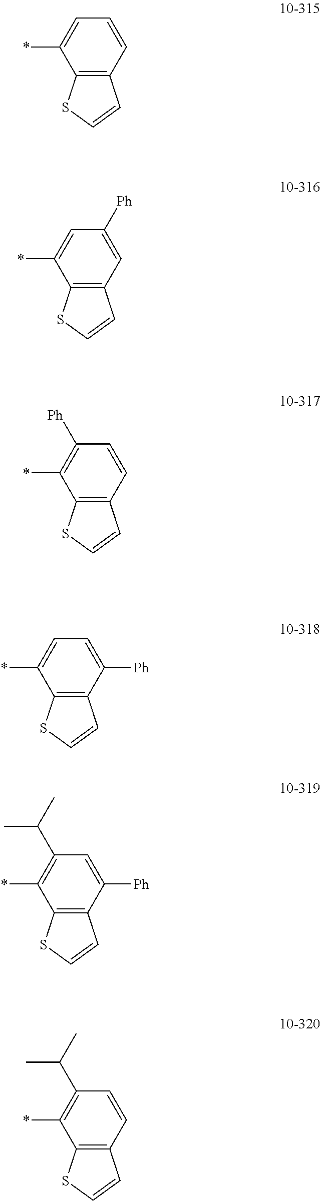 [SMILES: *c1cccc2ccsc12 ; *c1cc(-c2ccccc2)cc2ccsc12 ; *c1c(-c2ccccc2)ccc2ccsc12 ; *c1ccc(-c2ccccc2)c2ccsc12 ; *c1c(C(C)C)cc(-c2ccccc2)c2ccsc12 ; *c1c(C(C)C)ccc2ccsc12]

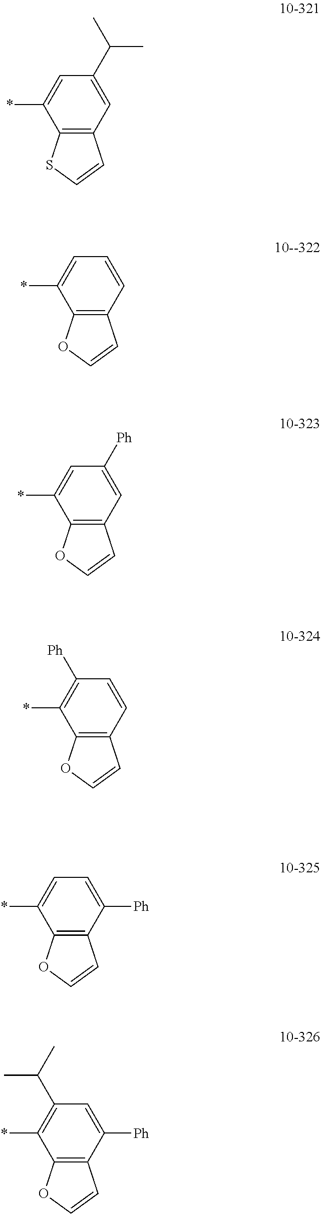 [SMILES: *c1cc(C(C)C)cc2ccsc12 ; *c1cccc2ccoc12 ; *c1cc(-c2ccccc2)cc2ccoc12 ; *c1c(-c2ccccc2)ccc2ccoc12 ; *c1ccc(-c2ccccc2)c2ccoc12 ; *c1c(C(C)C)cc(-c2ccccc2)c2ccoc12]

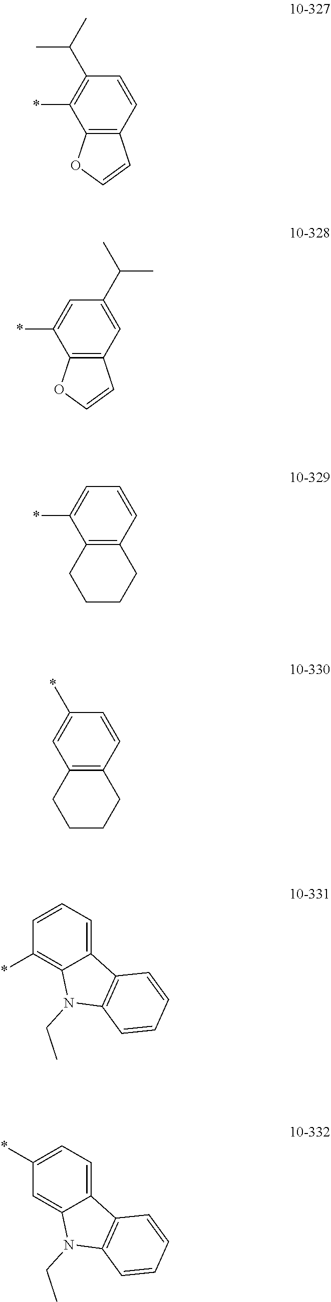 [SMILES: *c1c(C(C)C)ccc2ccoc12 ; *c1cc(C(C)C)cc2ccoc12 ; *c1cccc2c1CCCC2 ; *c1ccc2c(c1)CCCC2 ; *c1cccc2c3ccccc3n(CC)c12 ; *c1ccc2c3ccccc3n(CC)c2c1]

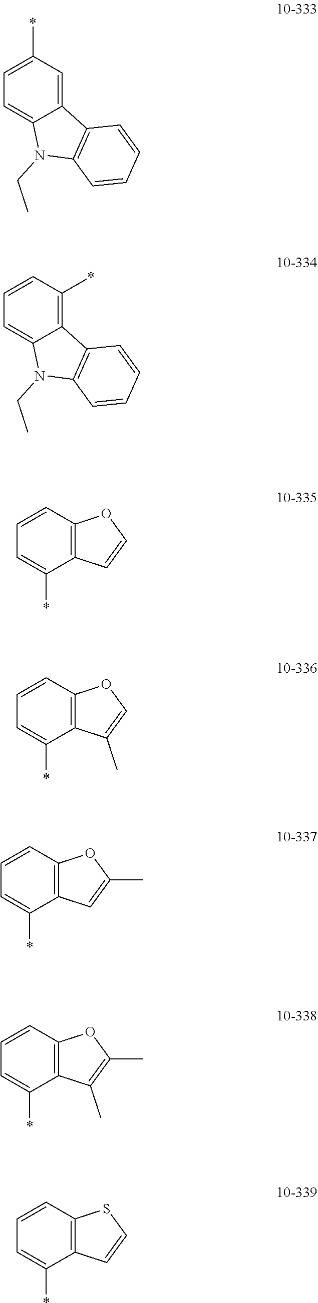

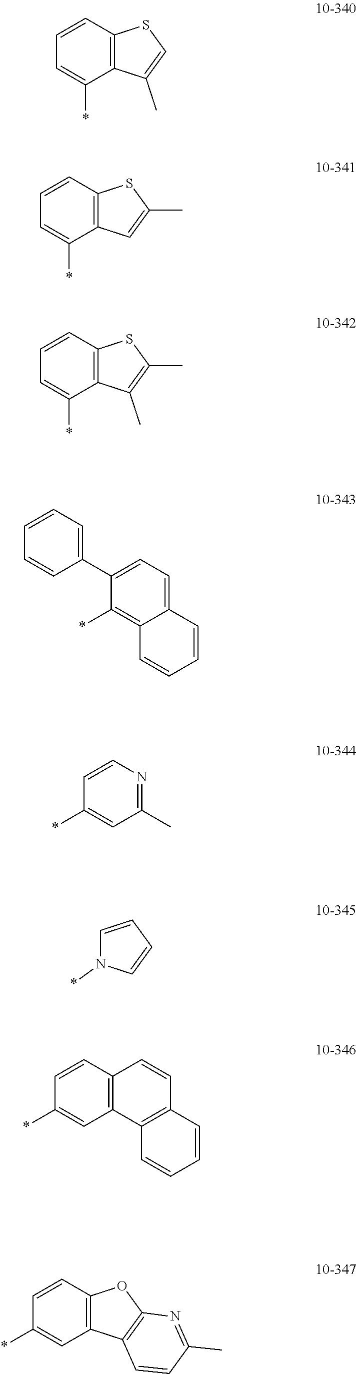

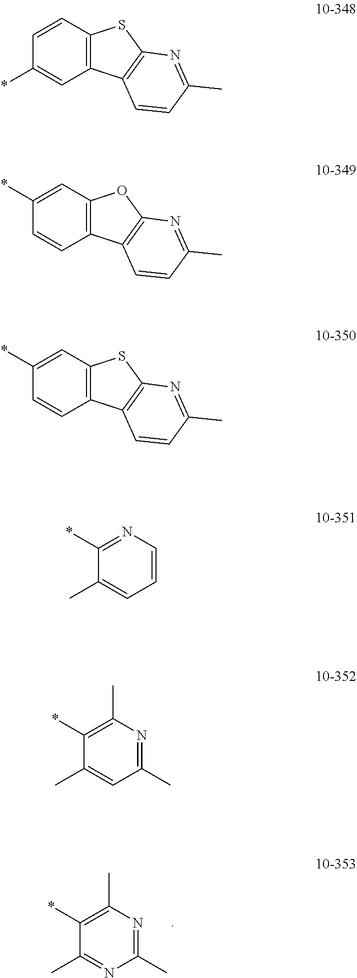

In Formulae 9-1 to 9-39, 9-201 to 9-233, 10-1 to 10-132, and 10-201 to 10-353, * indicates a binding site to an adjacent atom, “Ph” represents a phenyl group, “TMS” represents a trimethylsilyl group, “TMG” represents a trimethylgermyl group, and “OMe” represents a methoxy group.

The “group represented by one of Formulae 9-1 to 9-39 in which at least one hydrogen is substituted with deuterium” and the “group represented by one of Formulae 9-201 to 9-233 in which at least one hydrogen is substituted with deuterium” may each be, for example, a group represented by one of Formulae 9-501 to 9-514 and 9-601 to 9-635:

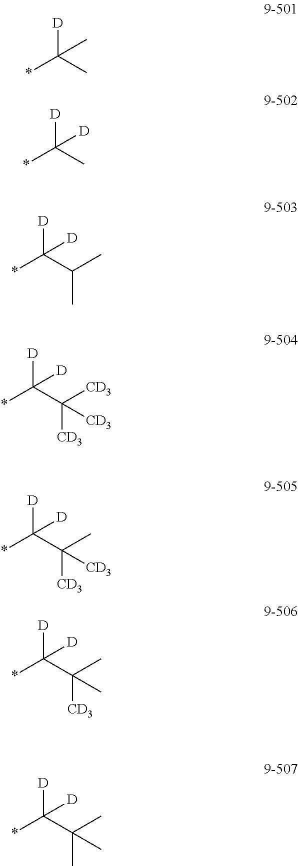

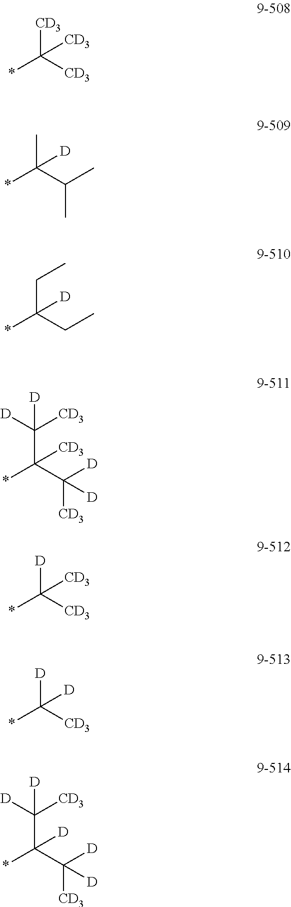

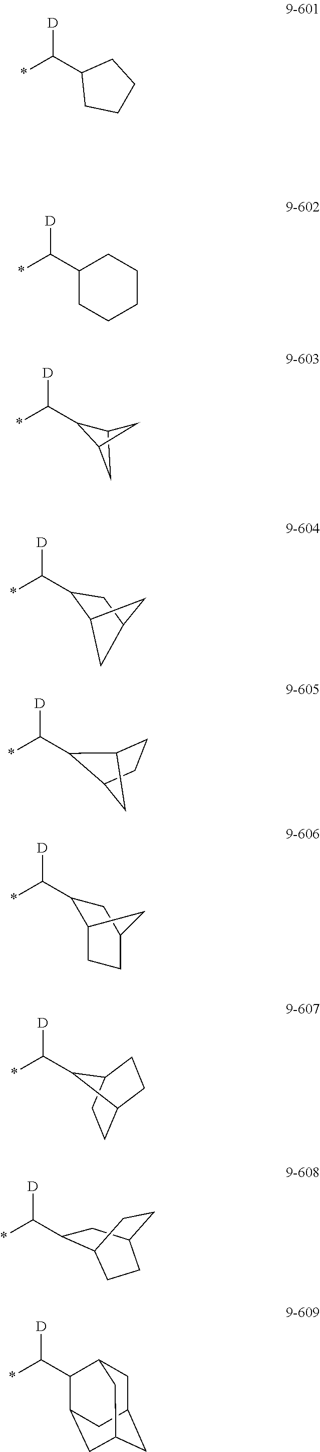

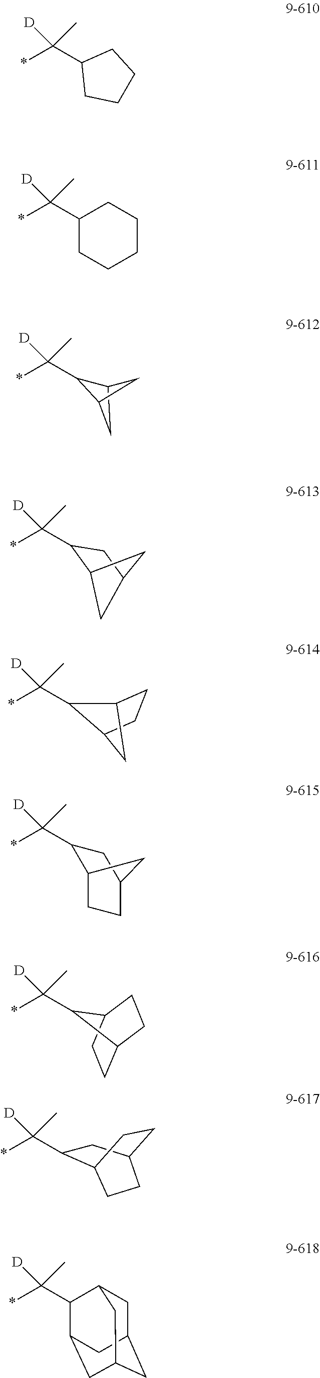

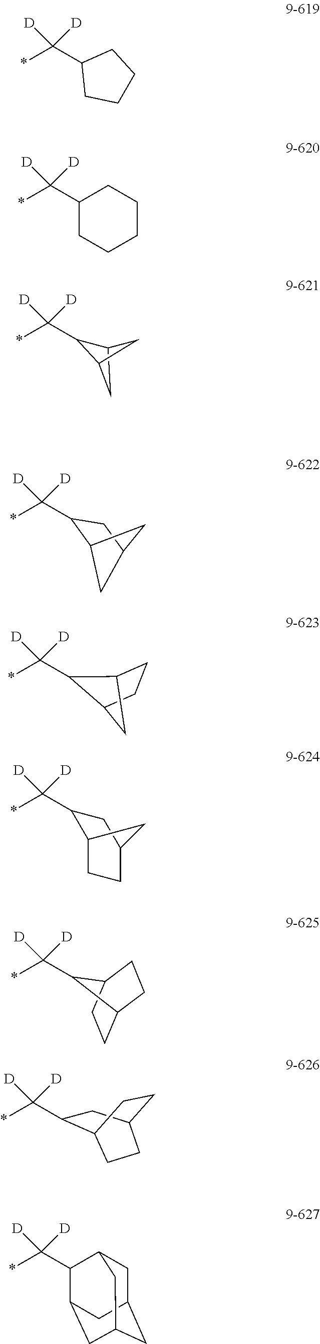

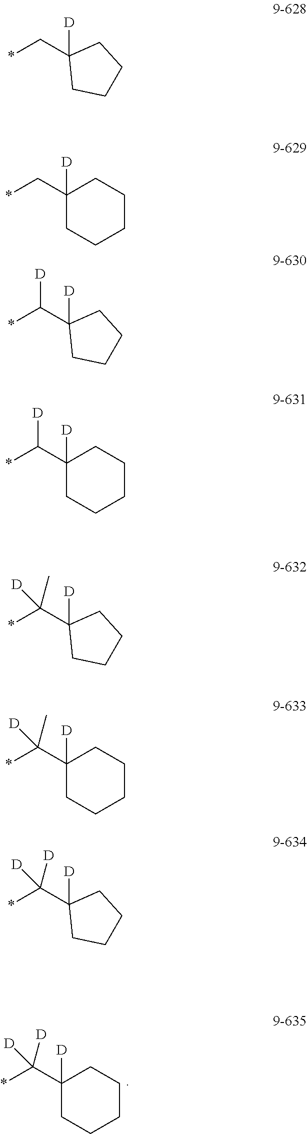

The “group represented by one of Formulae 9-1 to 9-39 in which at least one hydrogen is substituted with —F” and the “group represented by one of Formulae 9-201 to 9-233 in which at least one hydrogen is substituted with —F” may each be, for example, a group represented by one of Formulae 9-701 to 9-710:

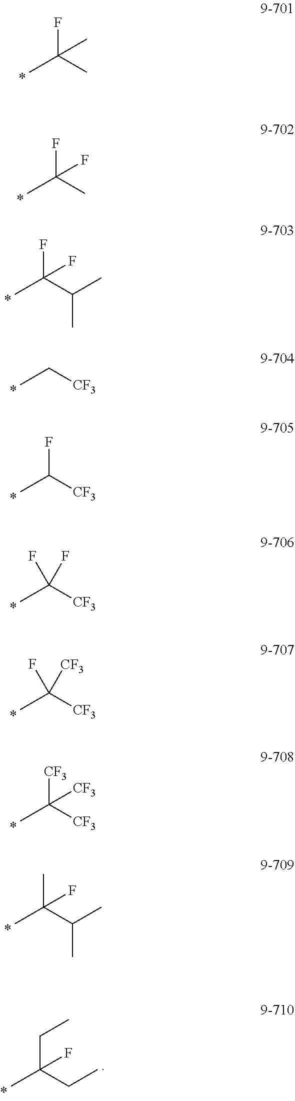

The “group represented by one of Formulae 10-1 to 10-132 in which at least one hydrogen is substituted with a deuterium” and the “group represented by one of Formulae 10-201 to 10-353 in which at least one hydrogen is substituted with deuterium” may each be, for example, a group represented by one of Formulae 10-501 to 10-553:

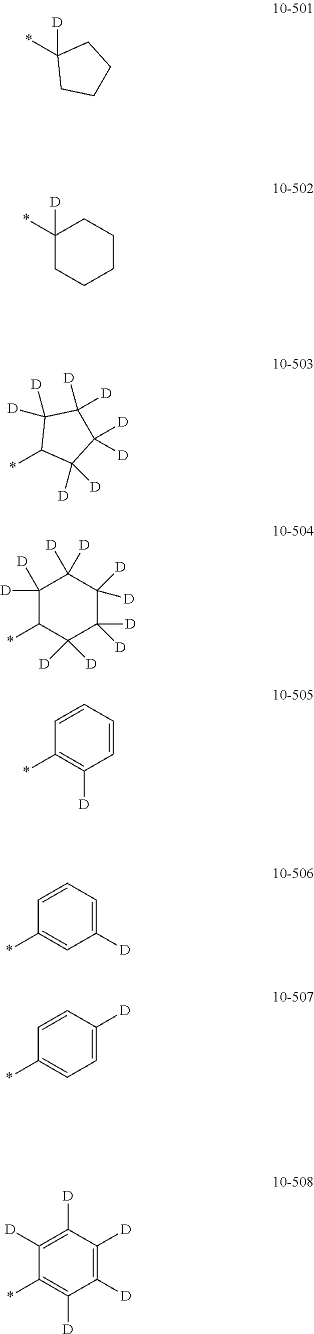

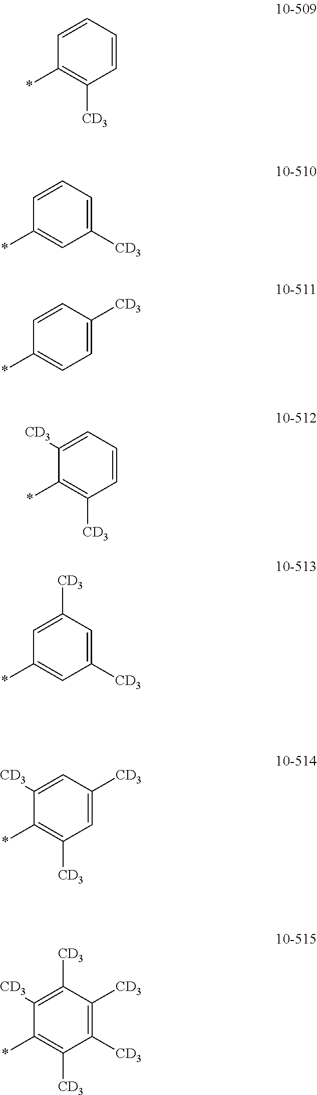

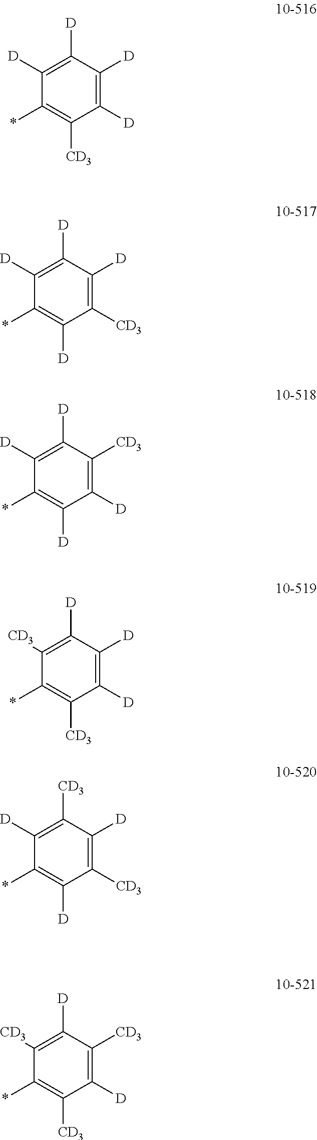 [SMILES: *c1c([2H])c([2H])c([2H])c([2H])c1C([2H])([2H])[2H] ; *c1c([2H])c([2H])c([2H])c(C([2H])([2H])[2H])c1[2H] ; *c1c([2H])c([2H])c(C([2H])([2H])[2H])c([2H])c1[2H] ; *c1c(C([2H])([2H])[2H])c([2H])c([2H])c([2H])c1C([2H])([2H])[2H] ; *c1c([2H])c(C([2H])([2H])[2H])c([2H])c(C([2H])([2H])[2H])c1[2H] ; *c1c(C([2H])([2H])[2H])c([2H])c(C([2H])([2H])[2H])c([2H])c1C([2H])([2H])[2H]]

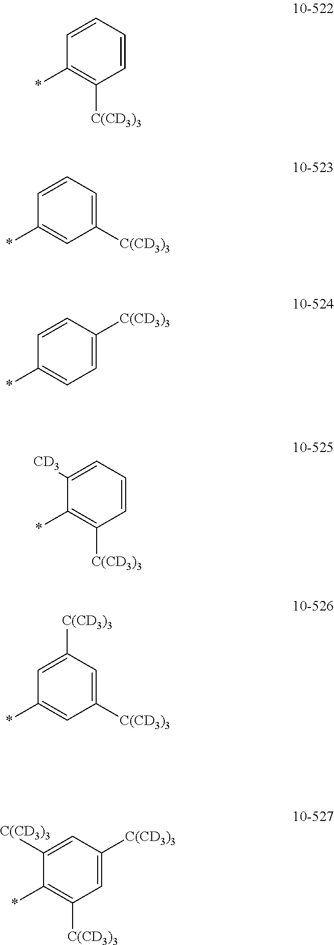

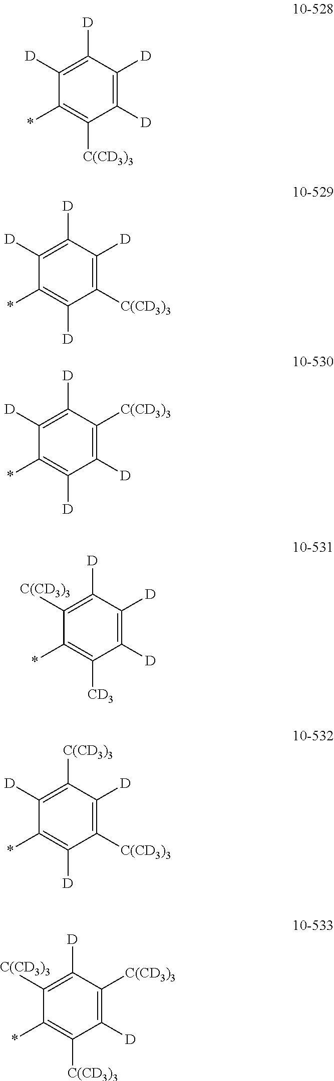

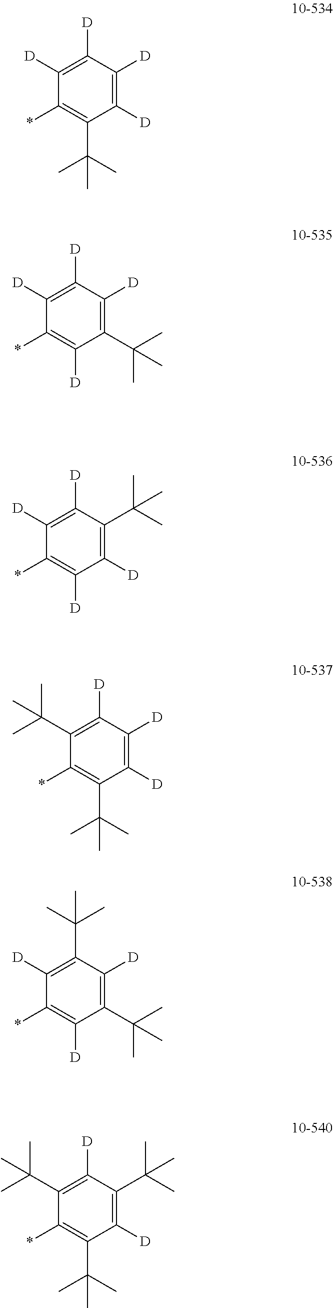

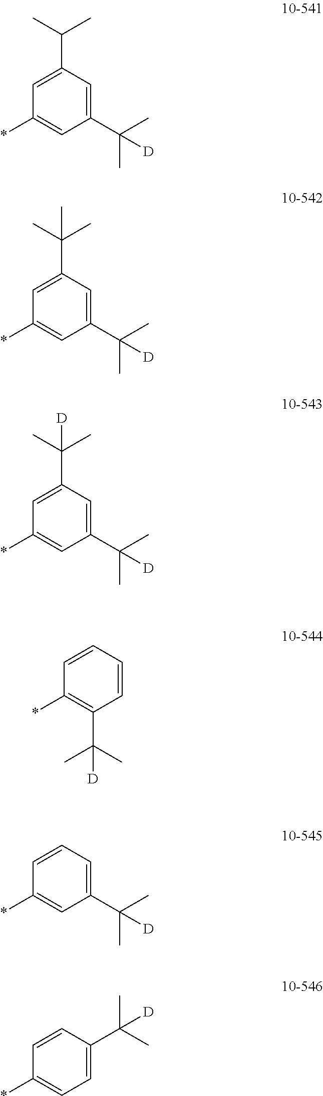 [SMILES: *c1cc(C(C)C)cc(C([2H])(C)C)c1 ; *c1cc(C([2H])(C)C)cc(C(C)(C)C)c1 ; *c1cc(C([2H])(C)C)cc(C([2H])(C)C)c1 ; *c1ccccc1C([2H])(C)C ; *c1cccc(C([2H])(C)C)c1 ; *c1ccc(C([2H])(C)C)cc1]

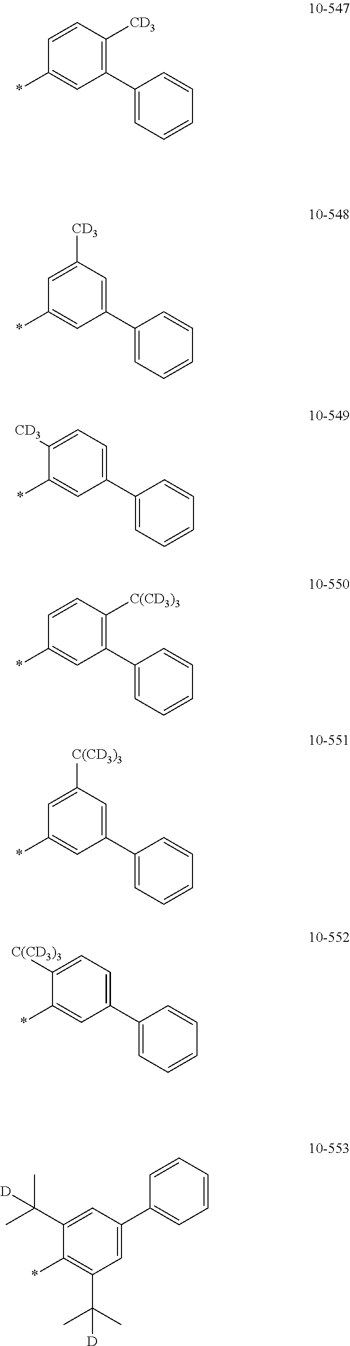

The “group represented by one of Formulae 10-1 to 10-132 in which at least one hydrogen is substituted with —F” and the “group represented by one of Formulae 10-201 to 10-353 in which at least one hydrogen is substituted with —F” may each be, for example, a group represented by one of Formulae 10-601 to 10-620:

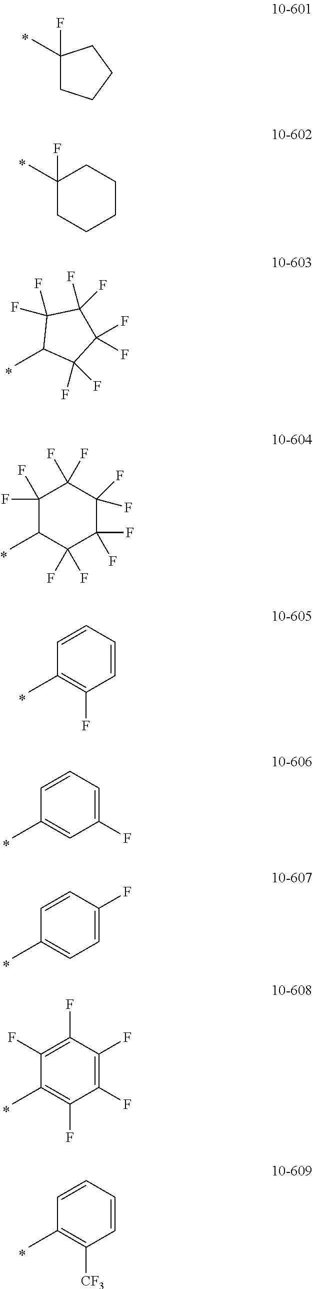

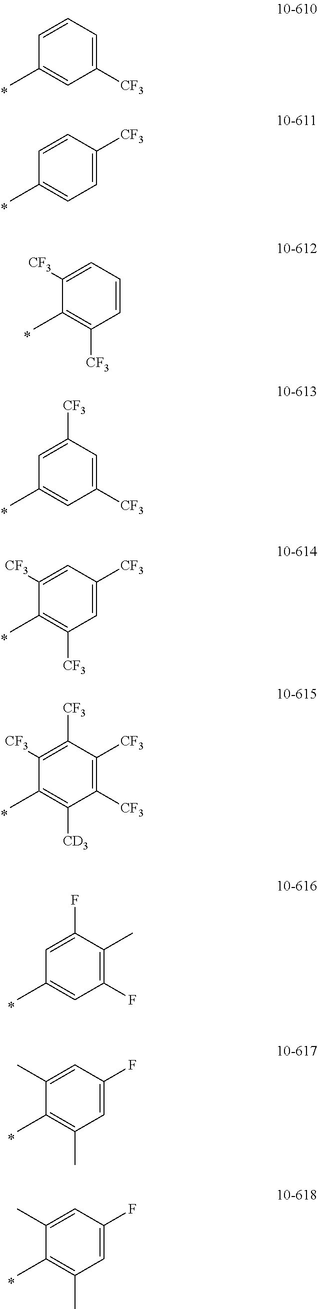

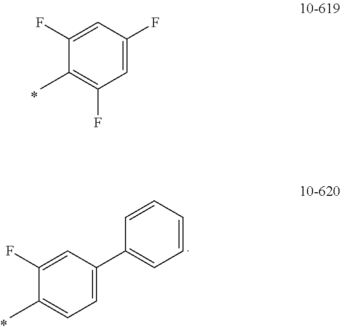

In Formula 2A, i) at least two of a plurality of R₁(s) may optionally be bound to form a C₅-C₃₀ carbocyclic group unsubstituted or substituted with at least one R₁₀ₐ or a C₁-C₃₀ heterocyclic group unsubstituted or substituted with at least one R₁₀ₐ, ii) at least two of a plurality of R₂(s) may optionally be bound to from a C₅-C₃₀ carbocyclic group unsubstituted or substituted with at least one R₁₀ₐ or a C₁-C₃₀ heterocyclic group unsubstituted or substituted with at least one R₁₀ₐ, and iii) at least two of R₁, R₂, R₂₉, and R₃₀ may optionally be bound to form a C₅-C₃₀ carbocyclic group unsubstituted or substituted with at least one R₁₀ₐ or a C₁-C₃₀ heterocyclic group unsubstituted or substituted with at least one R₁₀ₐ.

In the present specification, R₁₀ₐ may be understood by referring to the description of R₁ provided herein.

* and *′ in Formula 2A each indicate a binding site to M in Formula 1.

At least one of the green emission units 30a in the OLED substrate 101 may include, in addition to the organometallic compound represented by Formula 1, a hole transporting compound, an electron transporting compound, or any combination thereof.

In some embodiments, at least one of the green emission layer EML2 in the green emission unit 30a in the OLED substrate 101 may include a dopant and a host, the dopant may include the organometallic compound represented by Formula 1, and the host may include a hole transporting Compound, an electron transporting compound, or any combination thereof.

The hole transporting compound may include at least one π electron-rich C₃-C₆₀ cyclic group and not include an electron transporting moiety,

the electron transporting compound may include at least one π electron-rich C₃-C₆₀ cyclic group and at least one electron transporting moiety, and

the electron transporting moiety may include a cyano group, a π electron-deficient nitrogen-containing C₁-C₆₀ cyclic group, a group represented by one of the following Formulae, or any combination thereof:

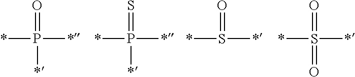

wherein, in the Formulae above, *, and *″ may each indicate a binding site to an adjacent atom.

The term “π electron-deficient nitrogen-containing C₁-C₆₀ cyclic group” as used herein refers to a group including a cyclic group having 1 to 60 carbon atoms and at least one *—N=*′ moiety, for example, an imidazole group, a pyrazole group, a thiazole group, an isothiazole group, an oxazole group, an isoxazole group, a pyridine group, a pyrazine group, a pyridazine group, a pyrimidine group, an indazole group, a purine group, a quinoline group, an isoquinoline group, a benzoquinoline group, a benzoisoquinolic group, a phthalazine group, a naphthyridine group, a quinoxaline group, a benzoquinoxaline group, a quinazoline group, a cinnoline group, a phenanthridine group, a phenanthroline group, a phenazine group, a benzimidazole group, an isobenzothiazole group, a benzoxazole group, an isobenzoxazole group, a triazole group, a tetrazole group, an oxadiazole group, a triazine group, a thiadiazole group, an imidazopyridine group, an imidazopyrimidine group, an azaindene group, an azaindole group, an azabenzofuran group, an azabenzothiophene group, an azabenzosilole group, an azafluorene group, an azacarbazole group, an azadibenzofuran group, an azadibenzothiophene group, or an azadibenzosilole group.

The term “π electron-rich C₃-C₆₀ cyclic group” as used herein refers to a cyclic group including 3 to 60 carbon atoms and not including a *—N=*′ moiety, for example, a benzene group, a heptalene group, an indene group, a naphthalene group, an azulene group, a heptalene group, an indacene group, acenaphthylene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentacene group, a hexacene group, a pentaphene group, a rubicene group, a coronene group, an ovalene group, a pyrrole group, an isoindole group, an indole group, a furan group, a thiophene group, a benzofuran group, a benzothiophene group, a benzosilole group, a benzocarbazole group, a dibenzocarbazole group, a dibenzofuran group, a dibenzothiophene group, a dibenzothiophene sulfone group, a carbazole group, a dibenzosilole group, an indenocarbazole group, an indolocarbazole group, a benzofurocarbazole group, a benzothienocarbazole group, a benzosilolocarbazole group, a triindolobenzene group, an acridine group, ora dihydroacridine group.

The hole transporting compound may be different from the electron transporting compound.

In an embodiment, the hole transporting compound may include at least one carbazole group.

In one or more embodiments, the electron transporting compound may include at least one π electron-deficient nitrogen-containing C₁-C₆₀ cyclic group (e.g., a triazine group).

In some embodiments, the organometallic compound represented by Formula 1 may be one of Group 1 to Group 5:

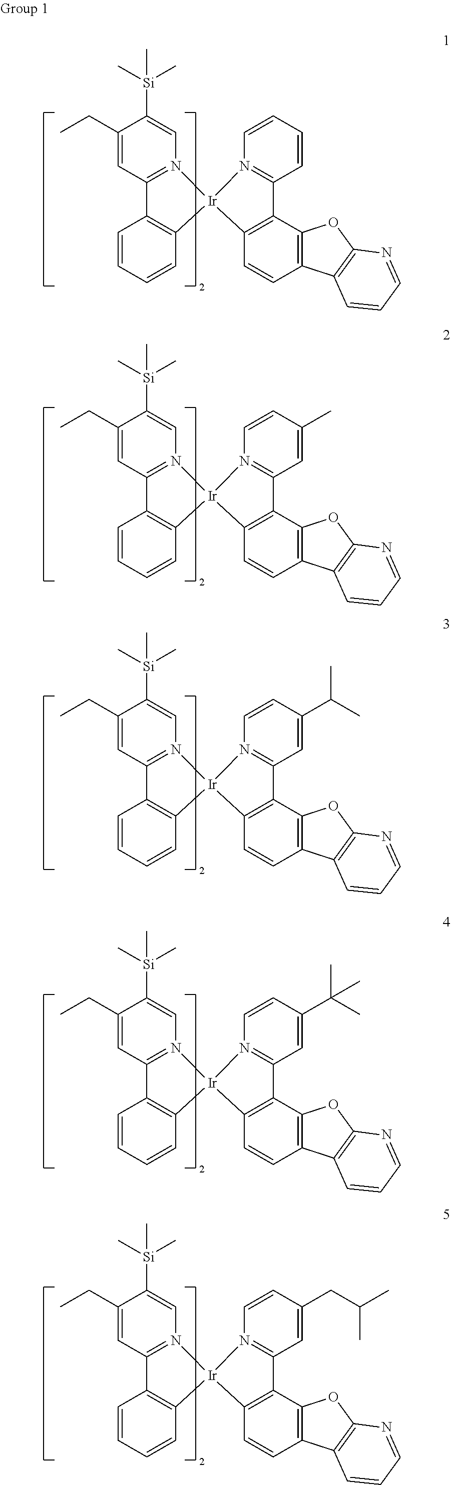

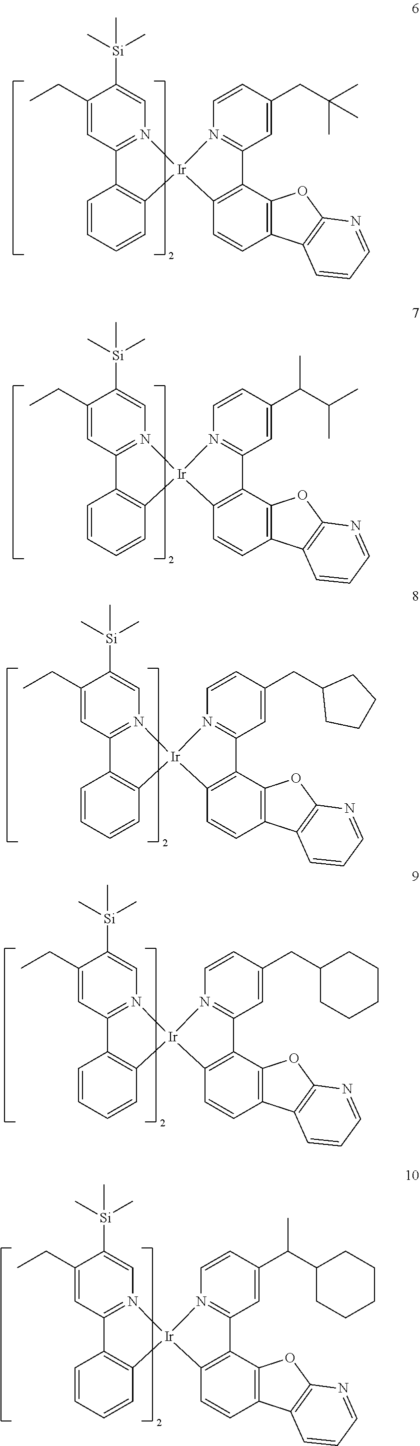

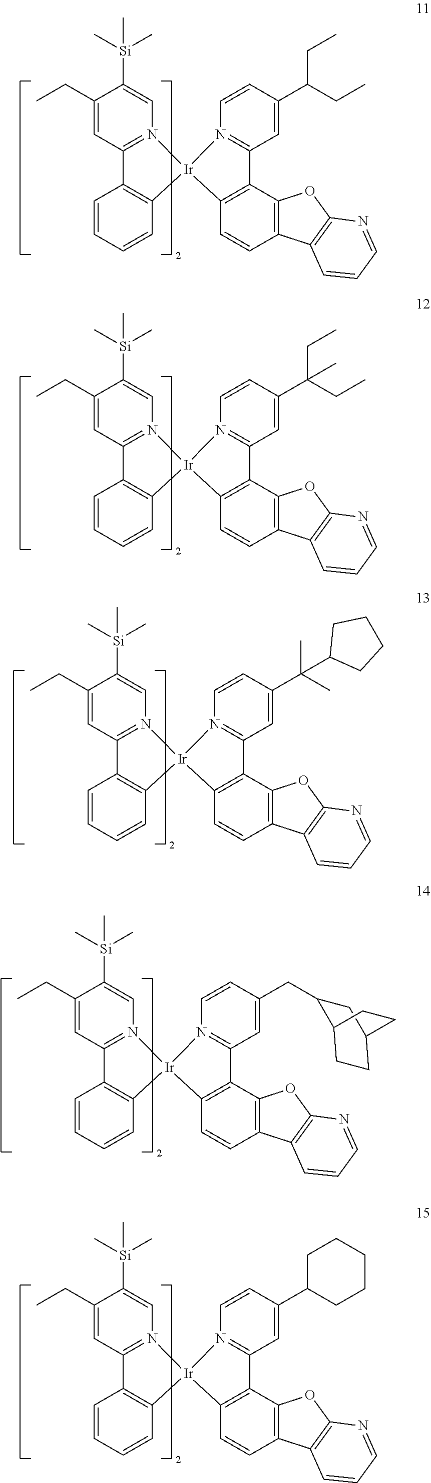

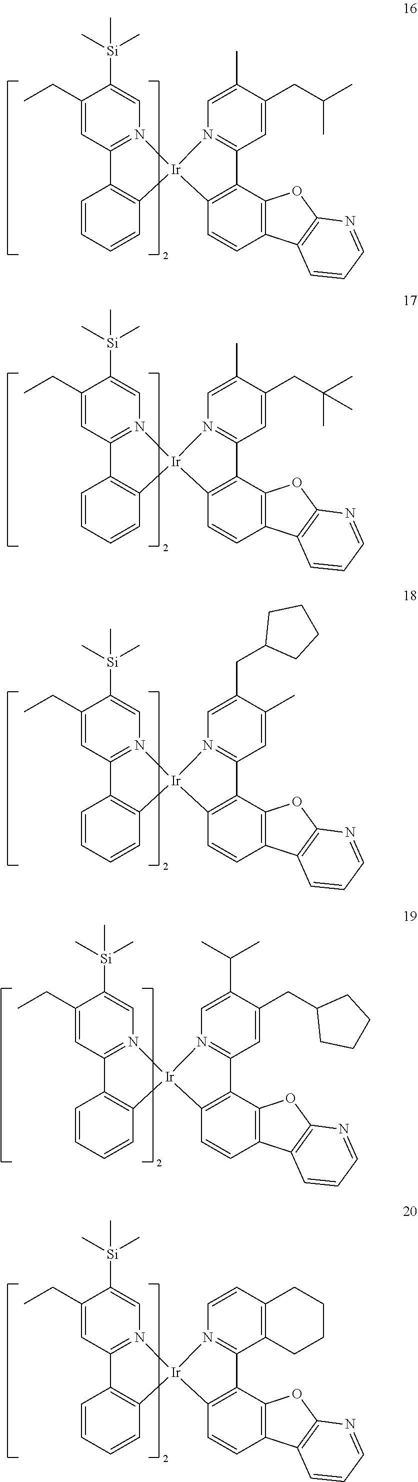

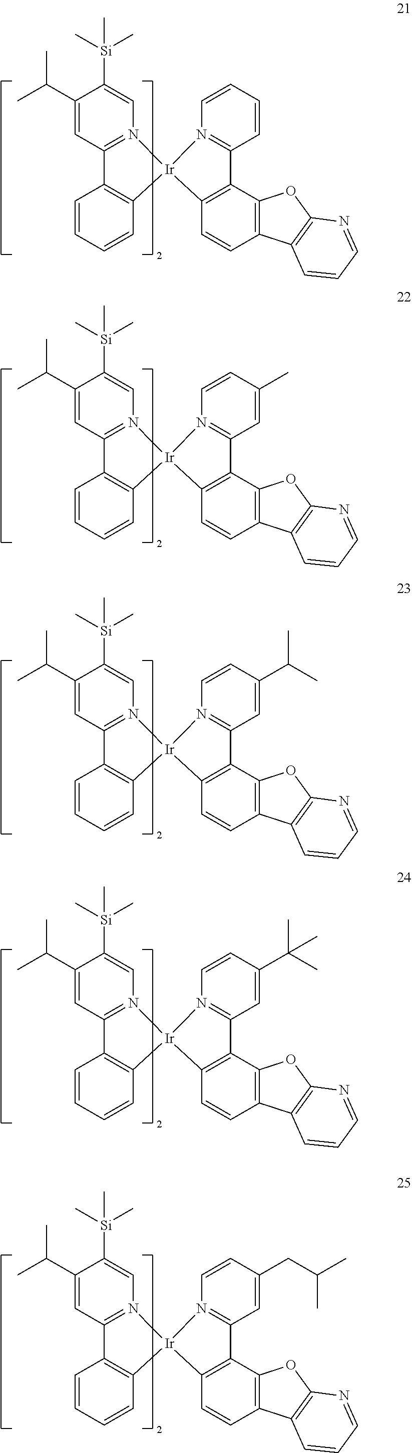

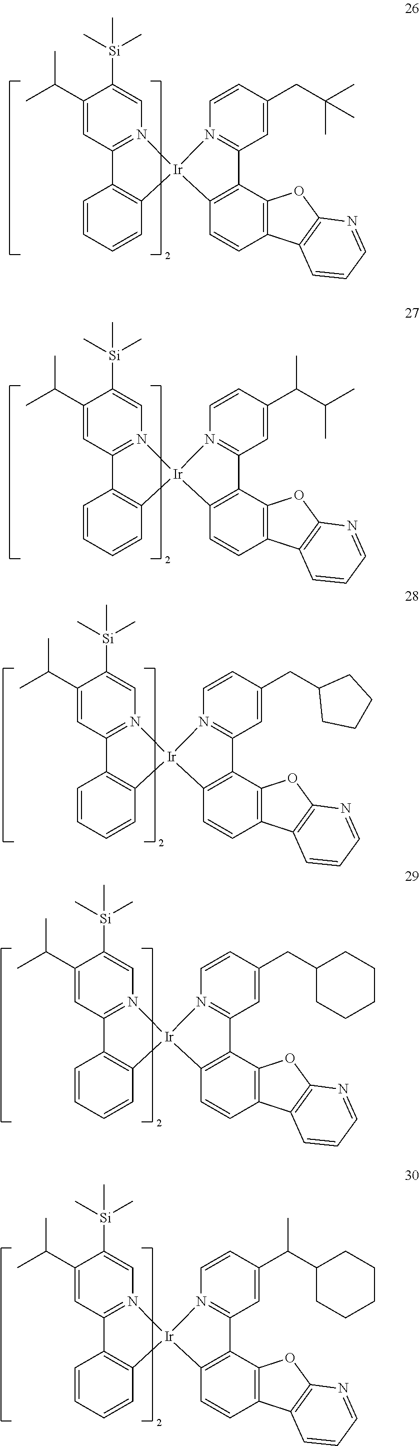

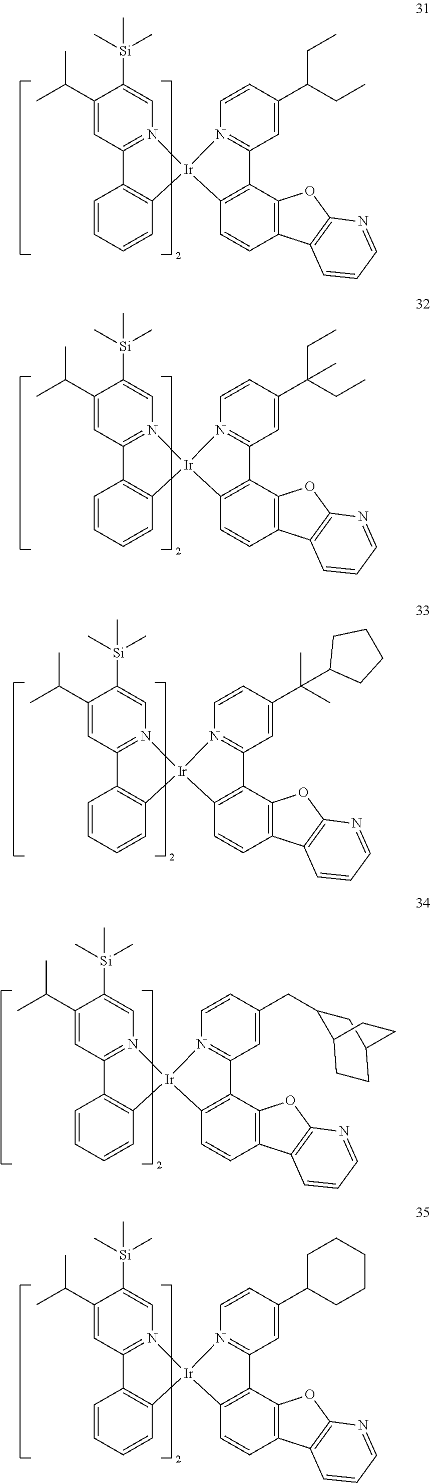

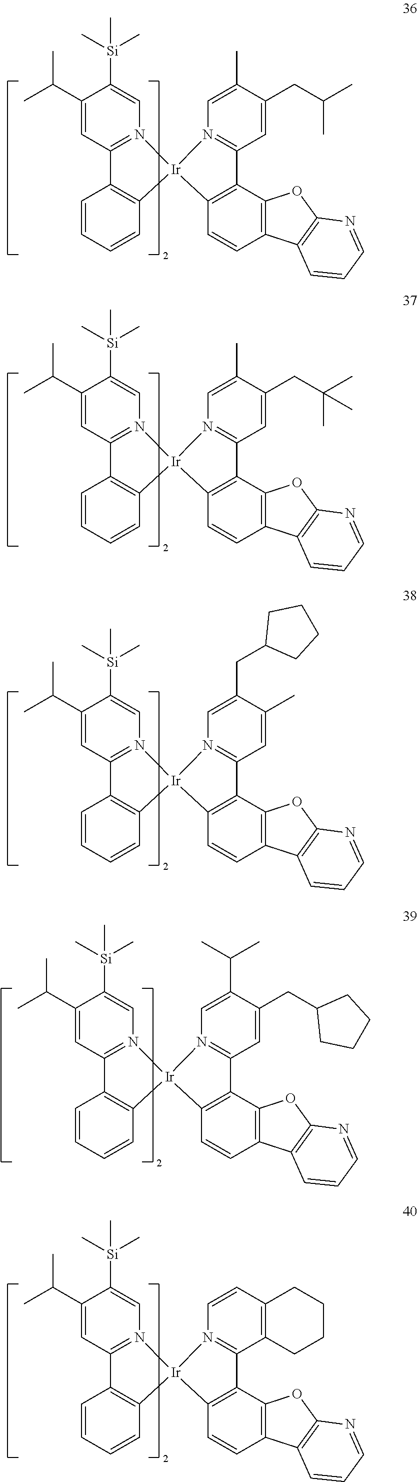

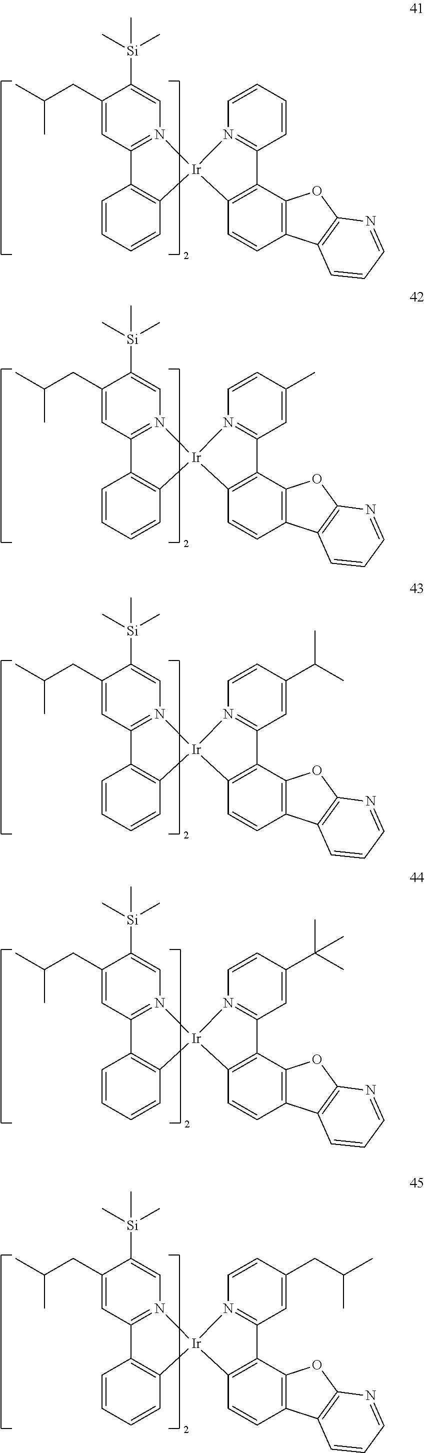

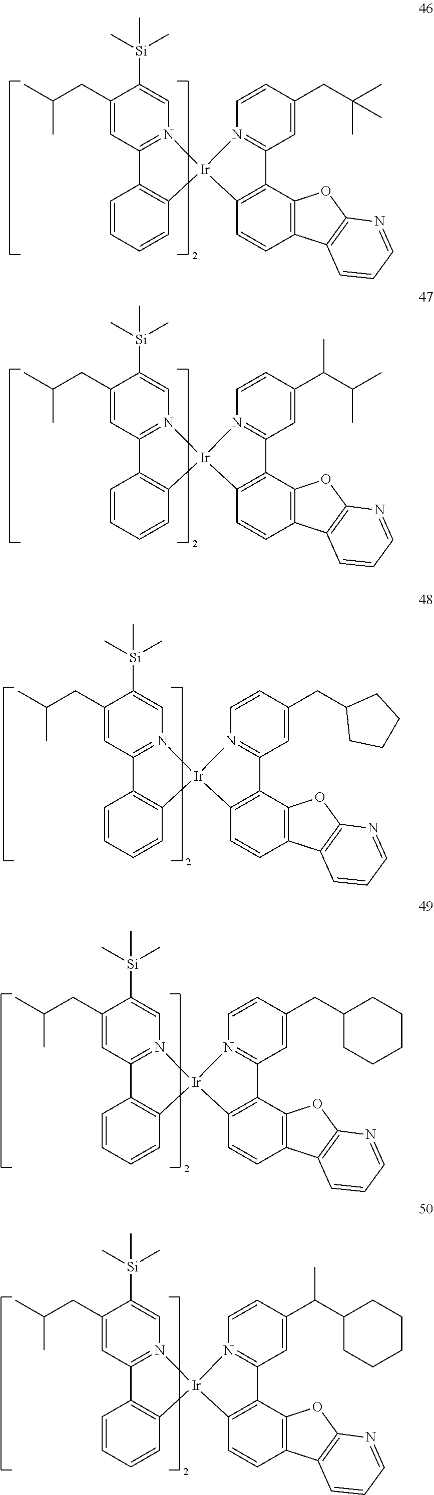

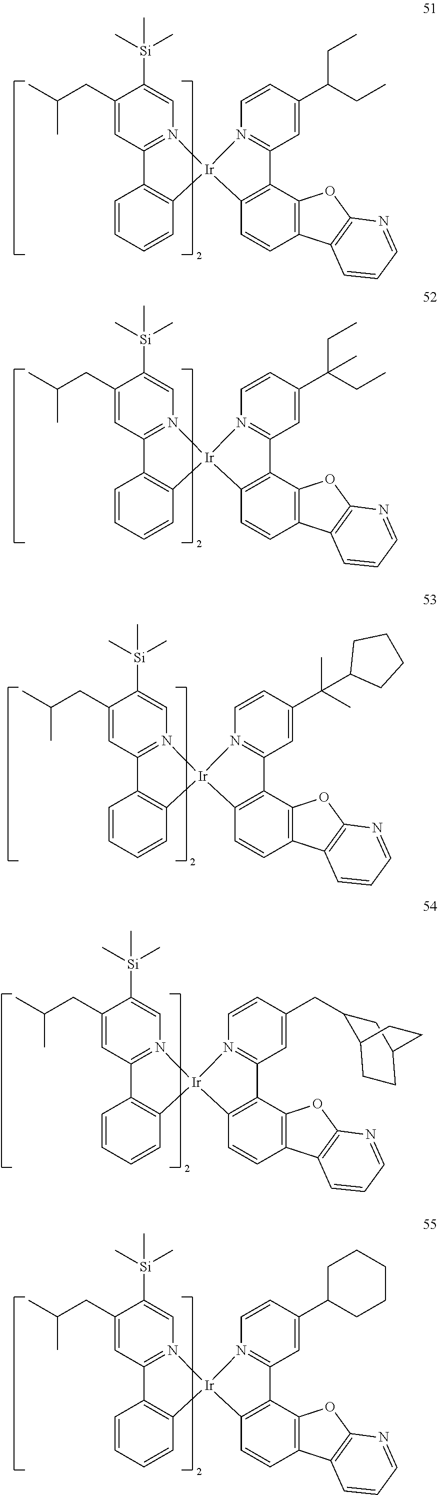

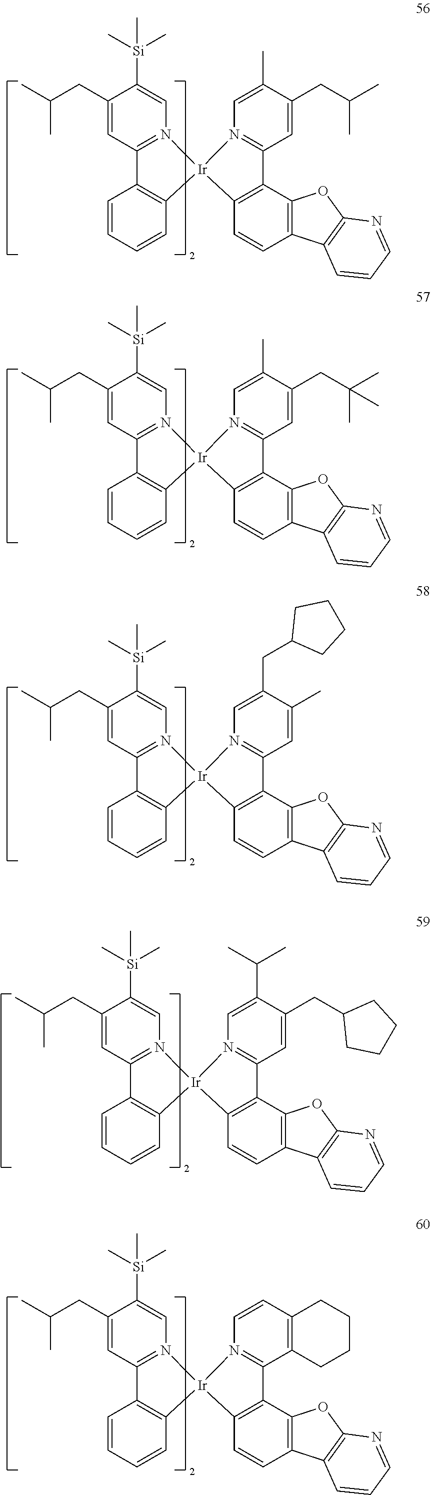

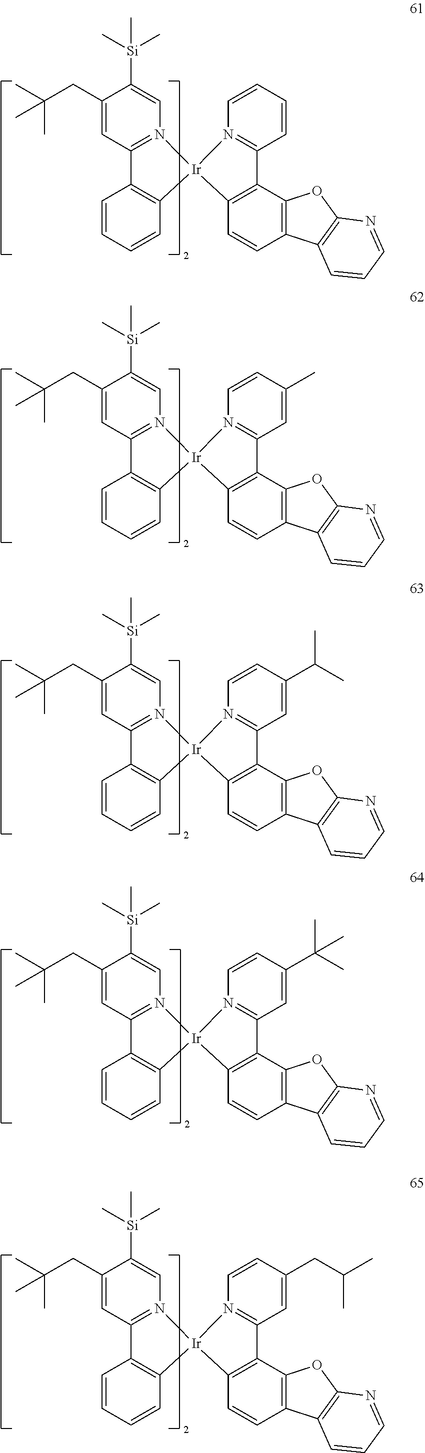

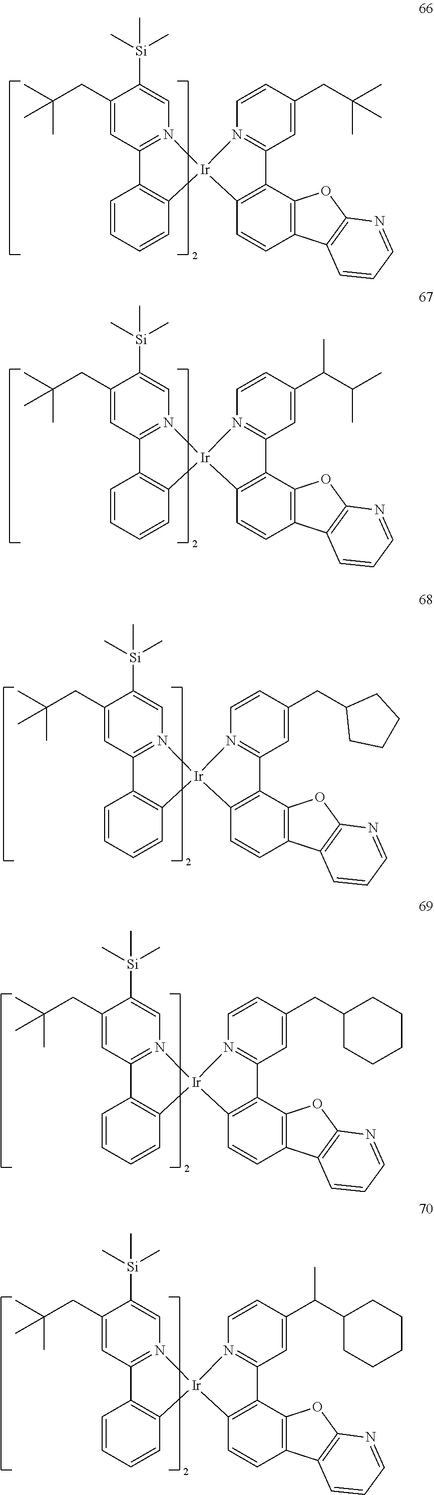

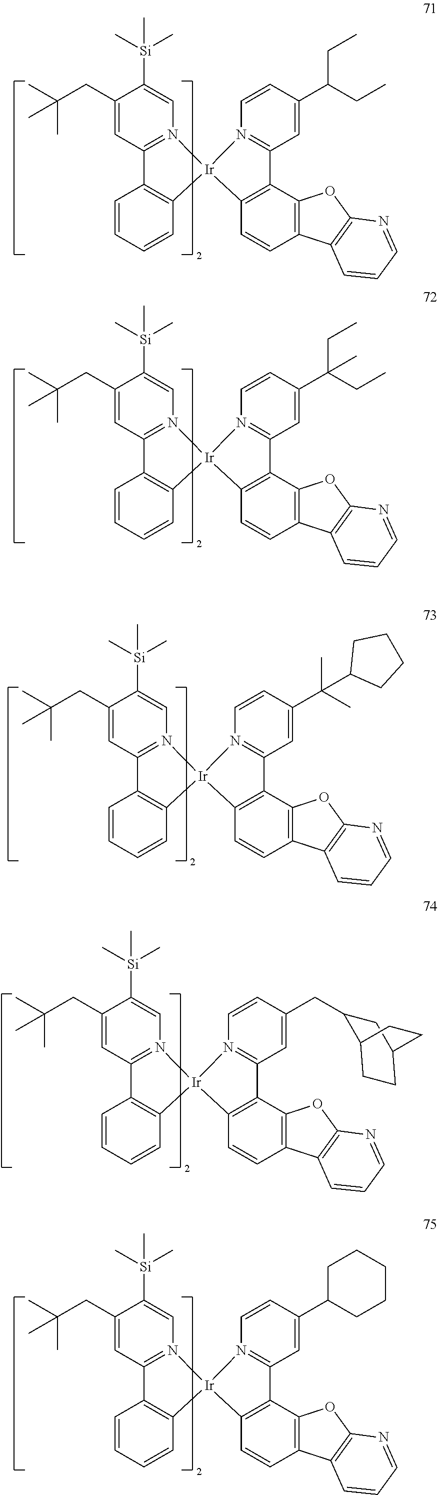

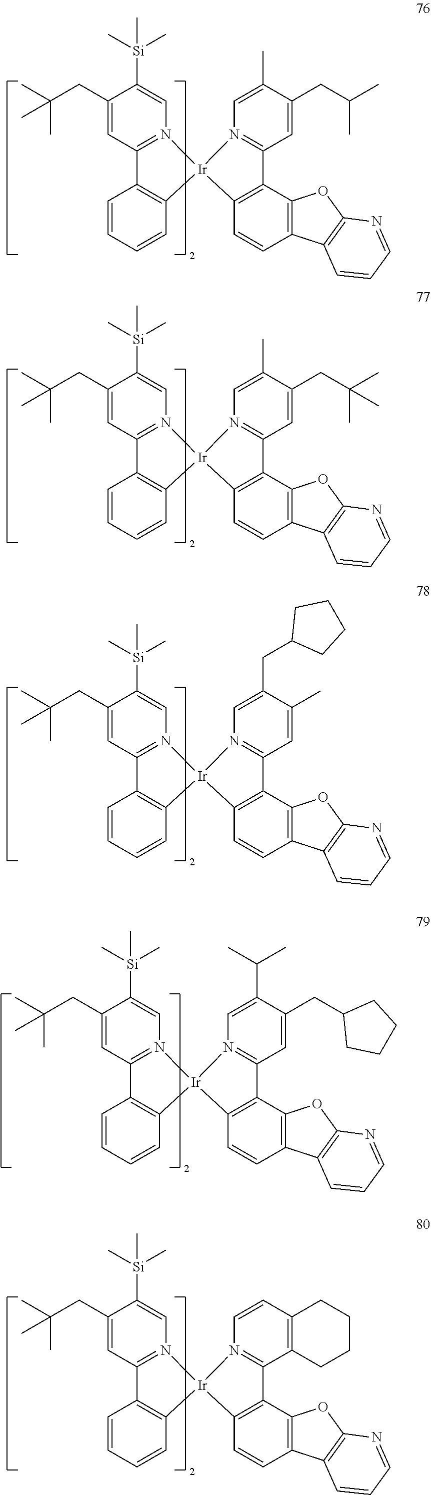

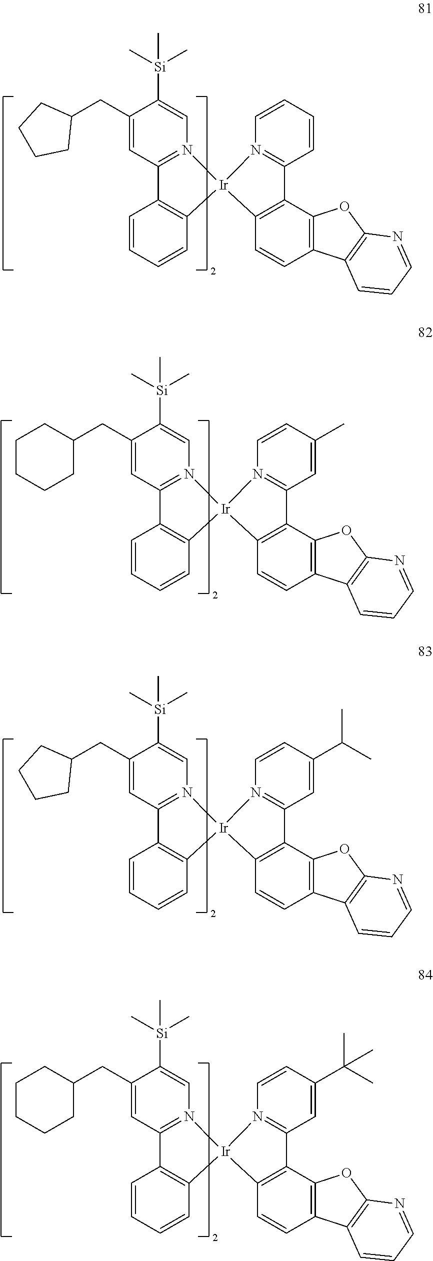

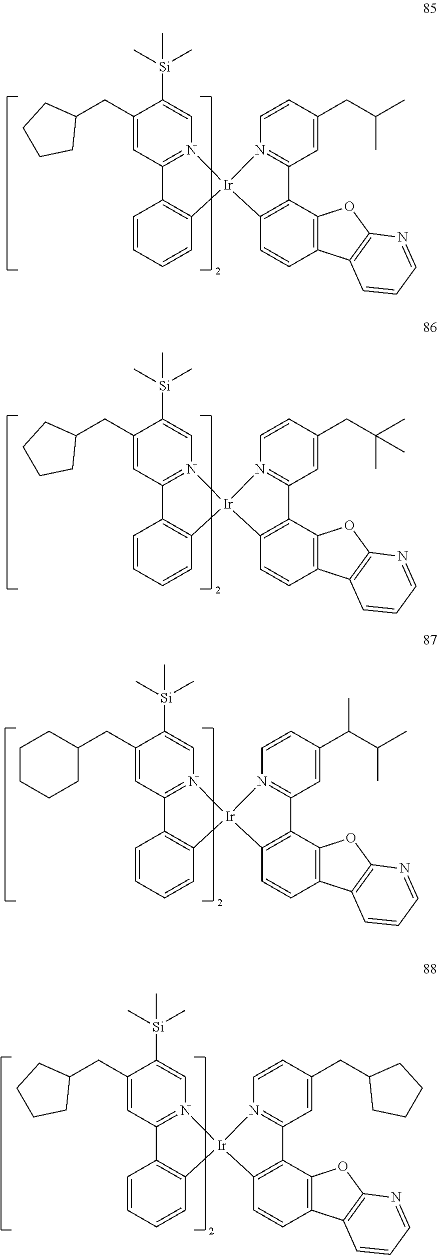

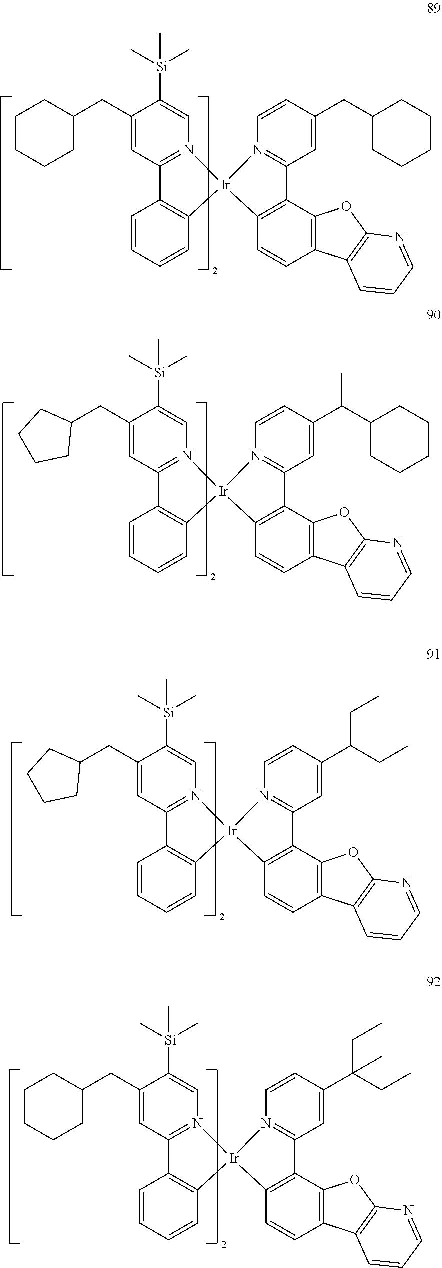

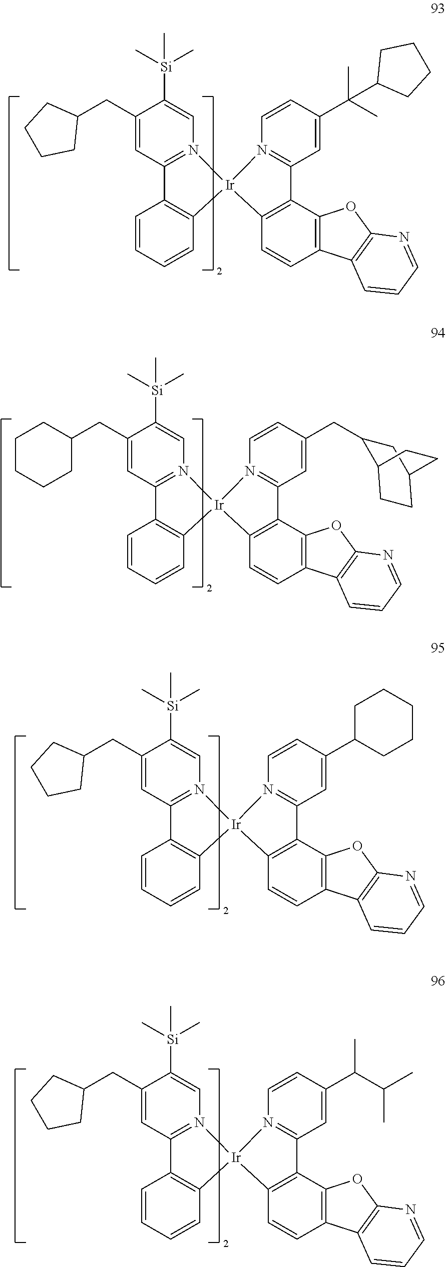

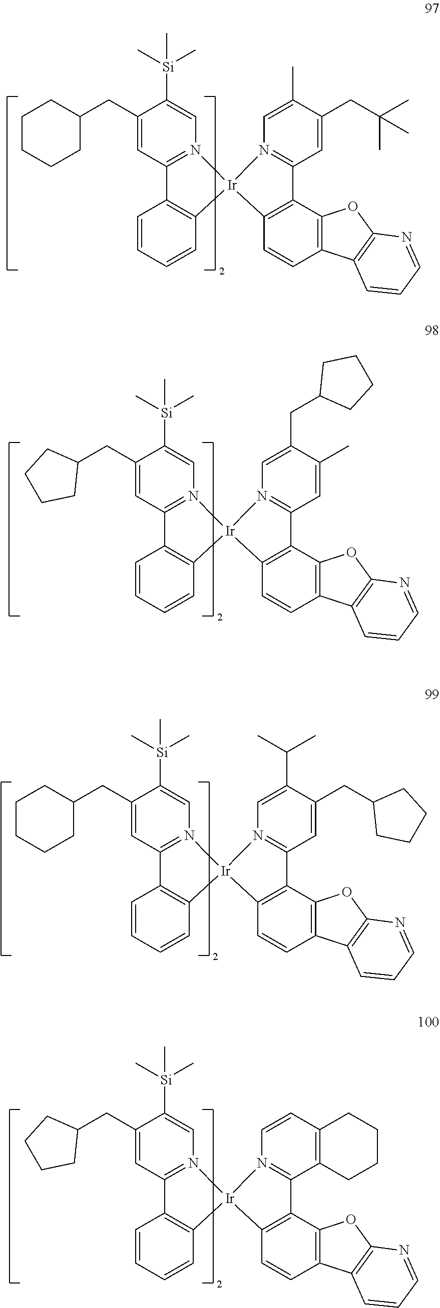

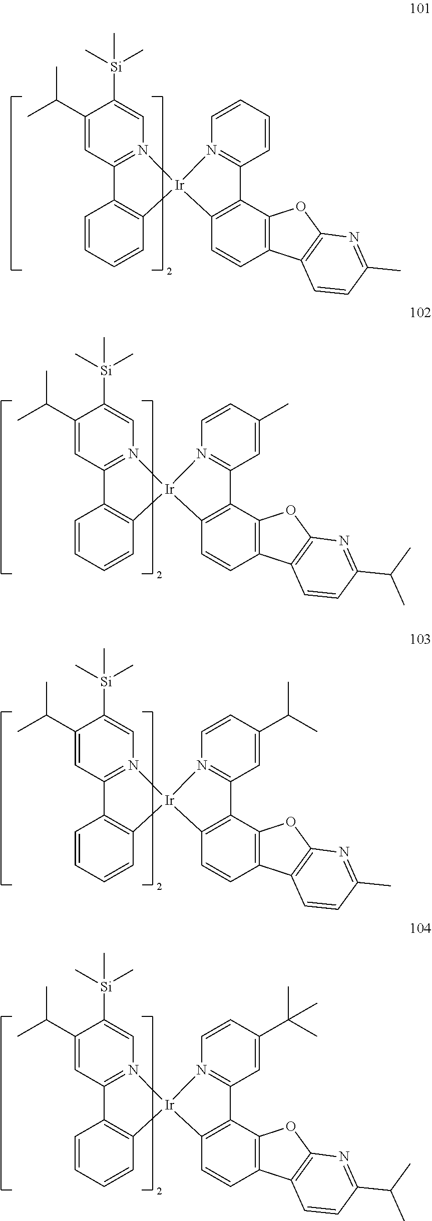

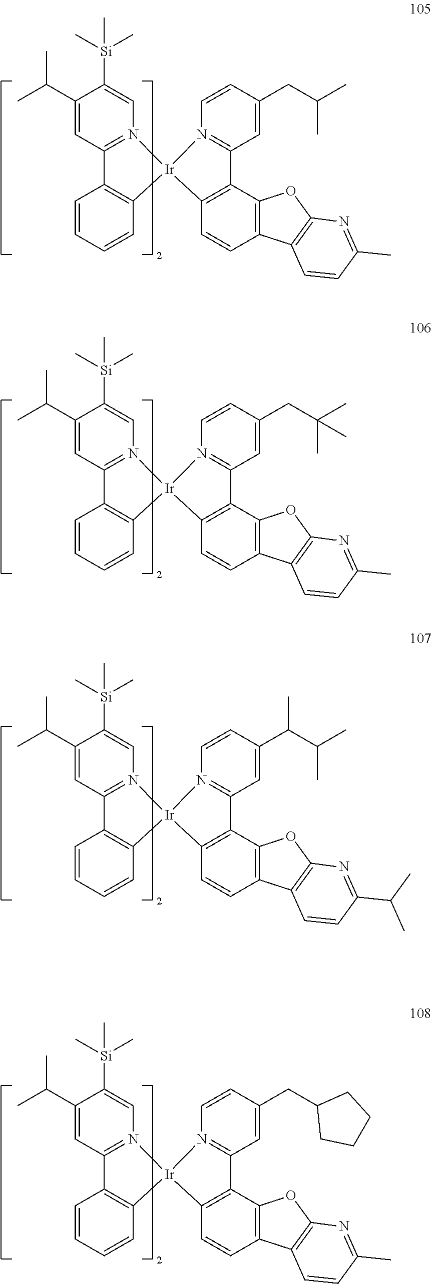

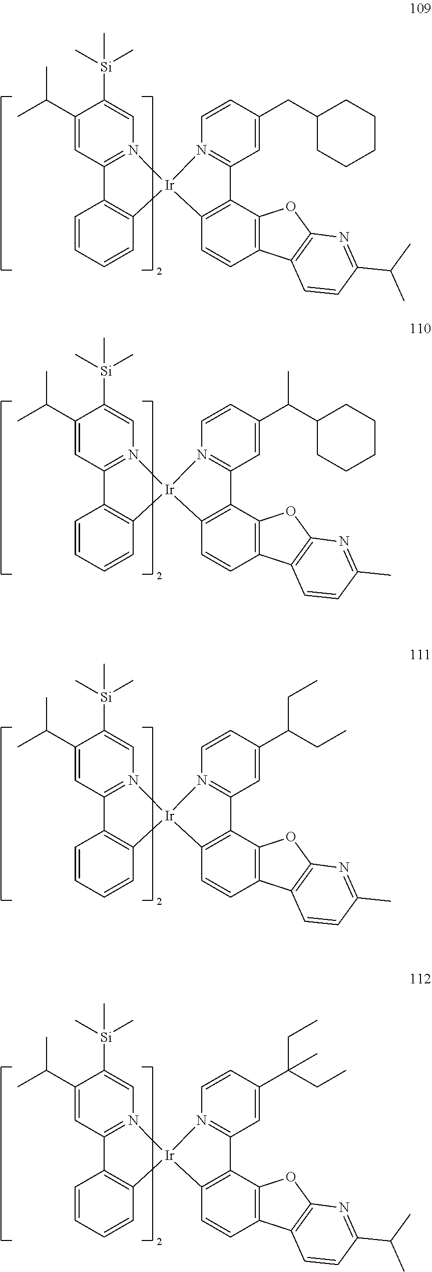

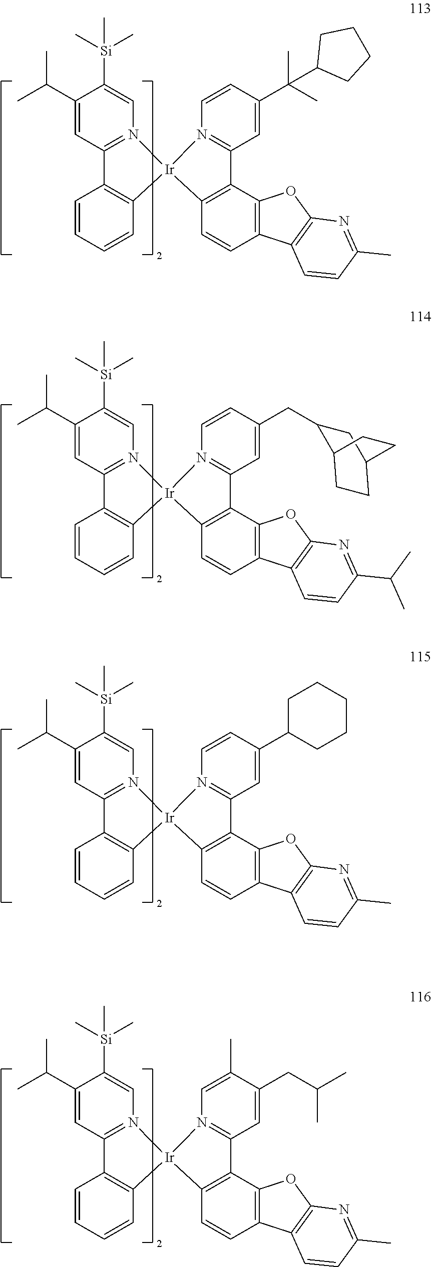

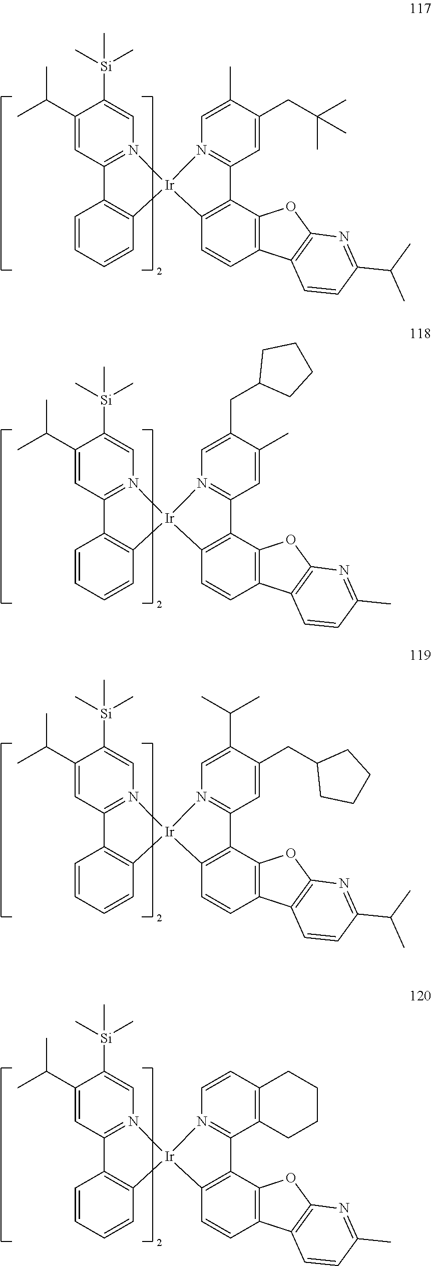

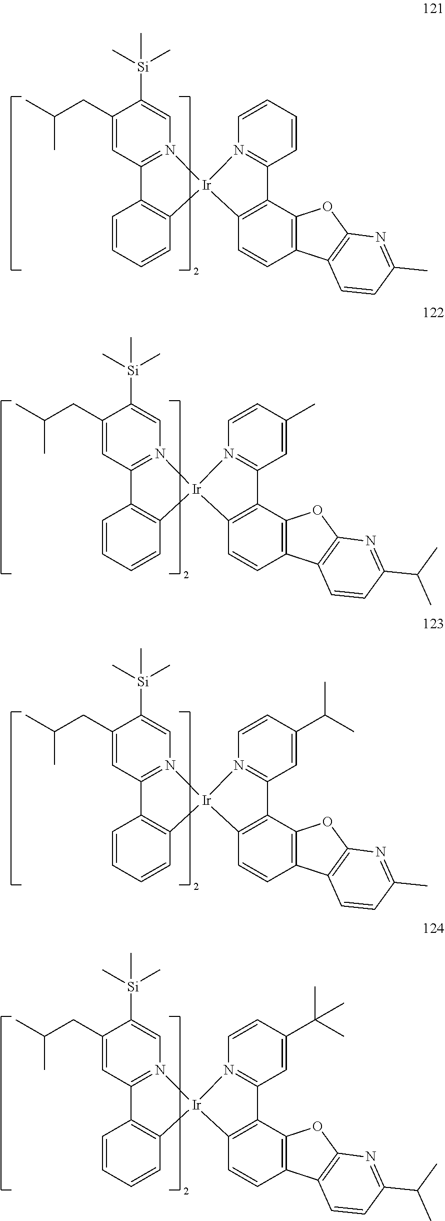

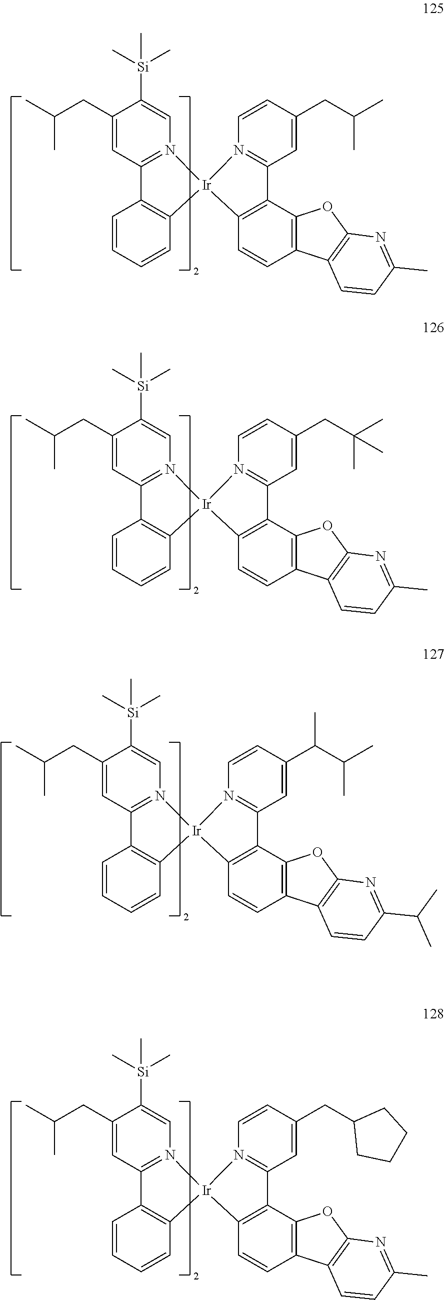

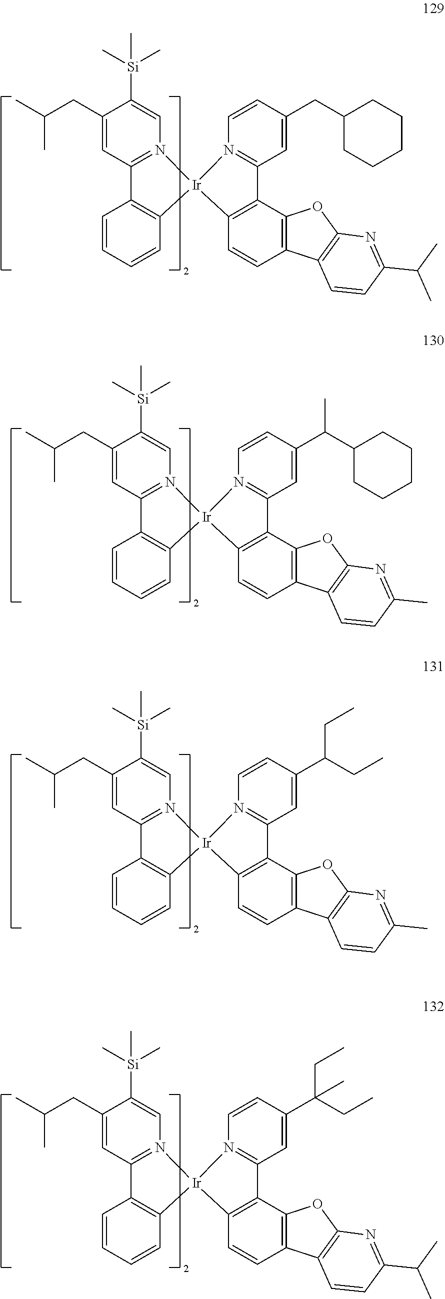

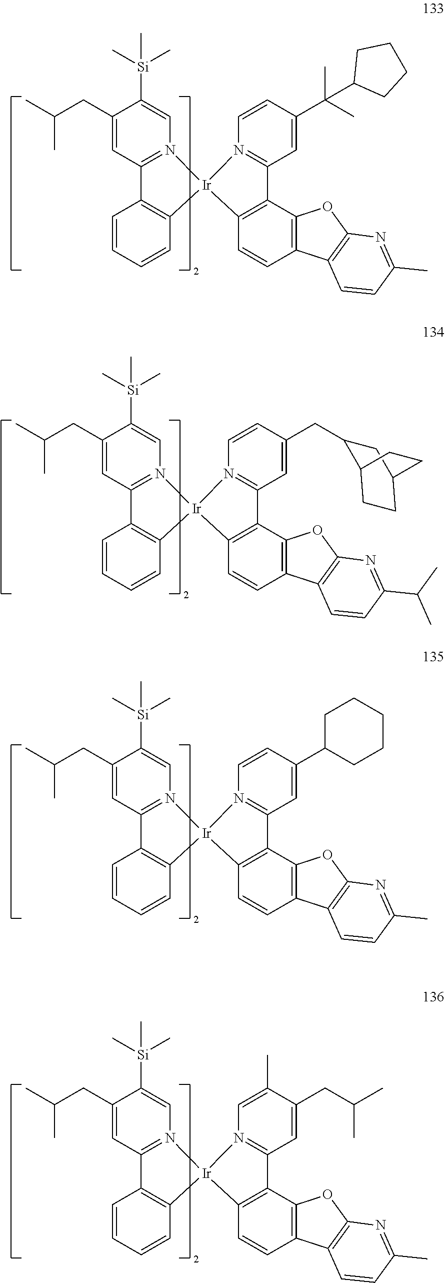

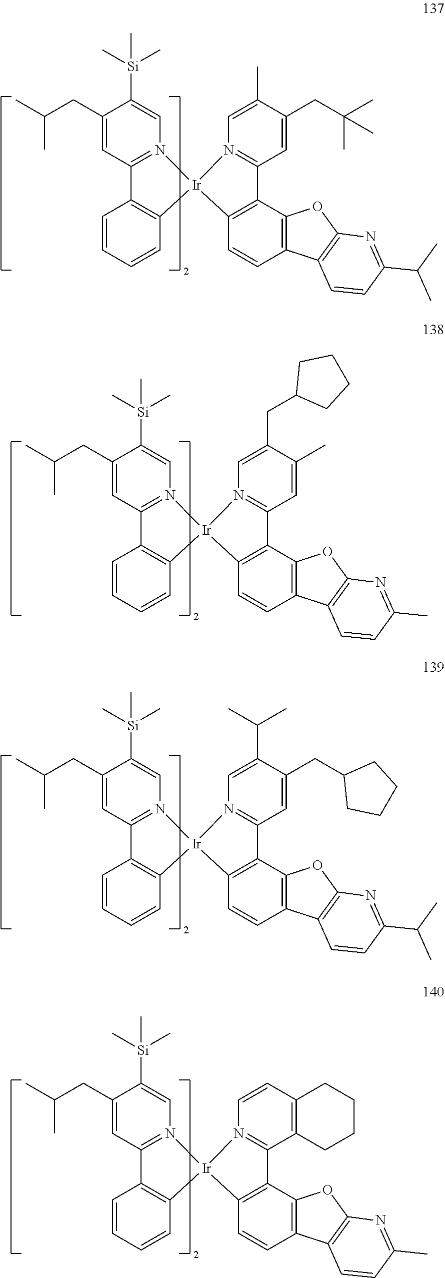

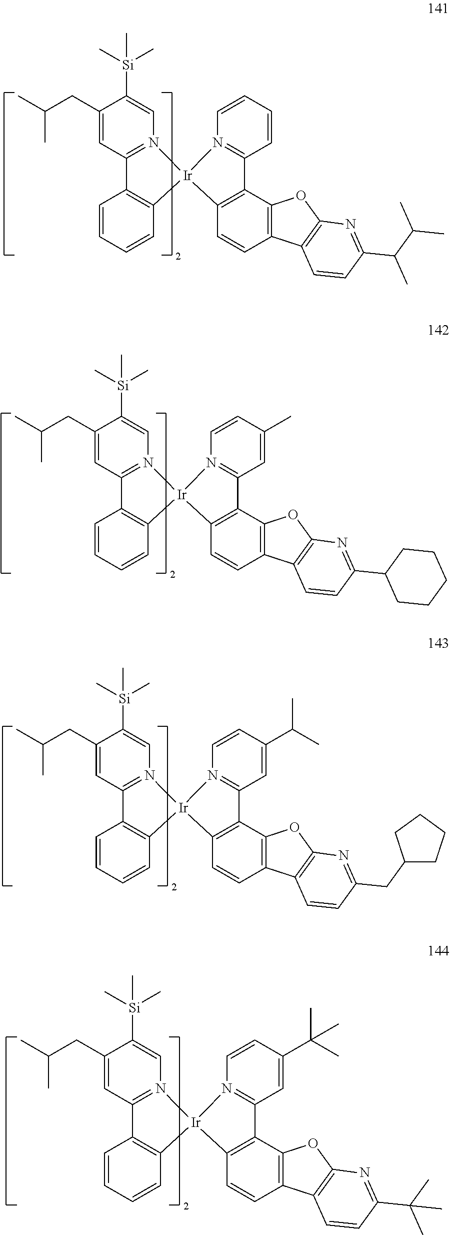

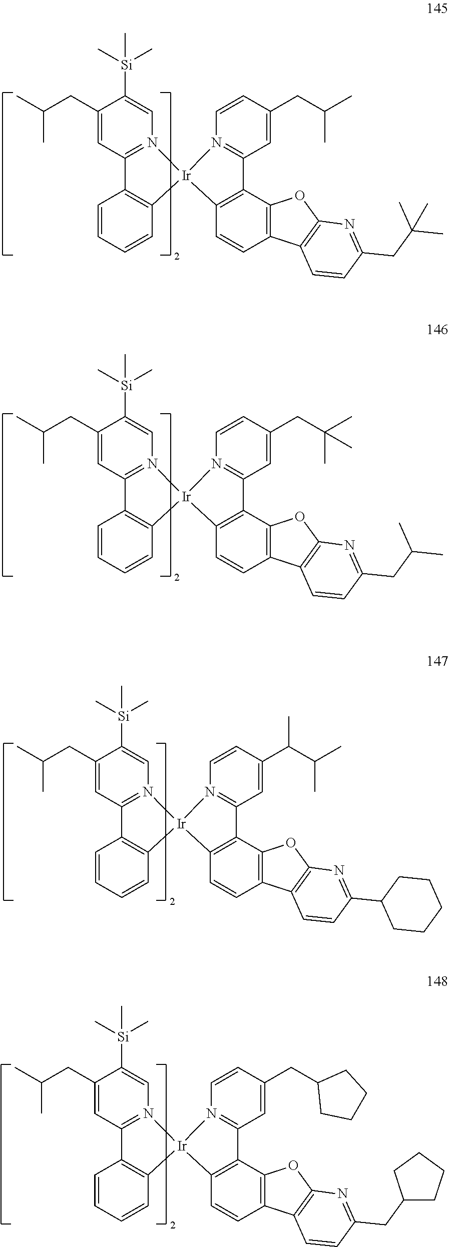

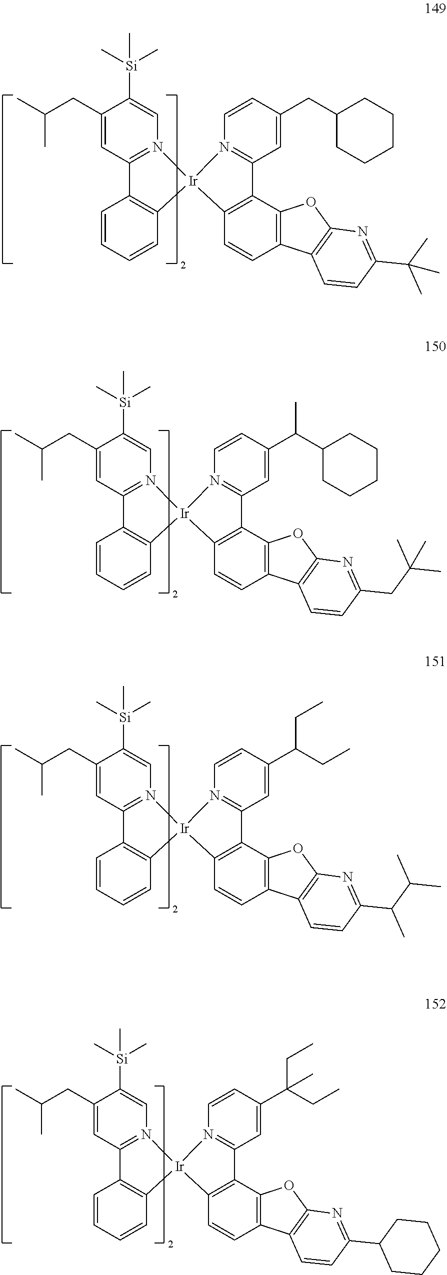

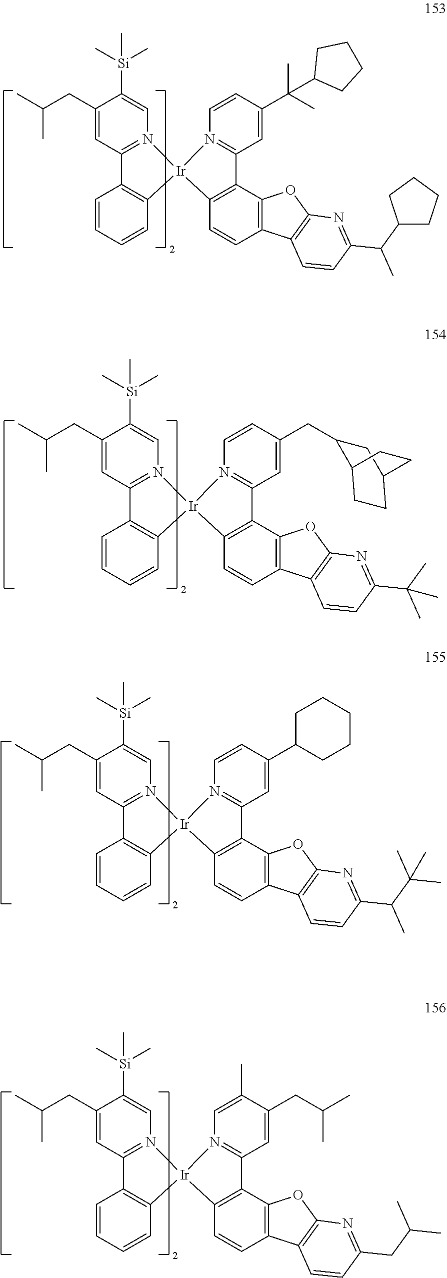

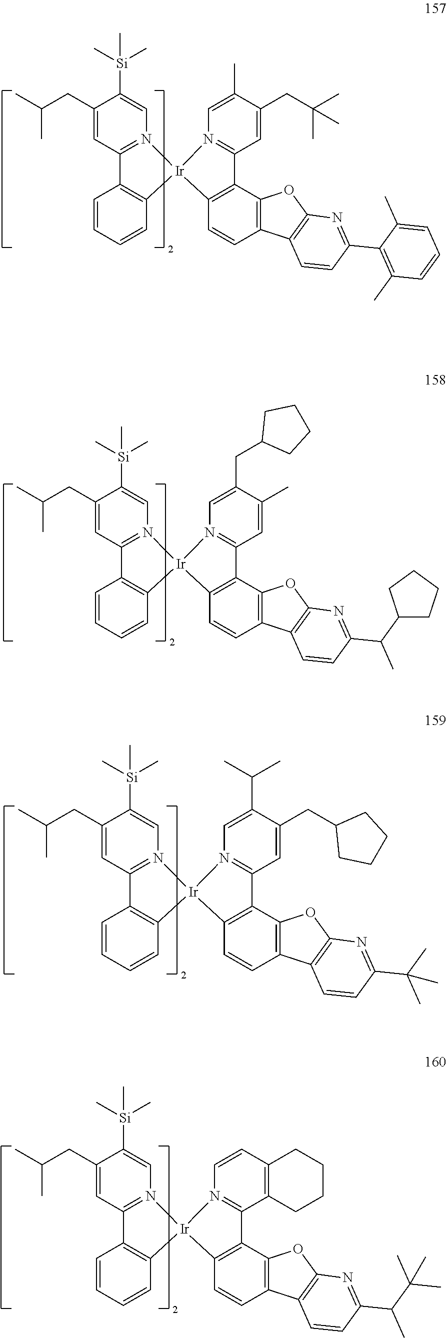

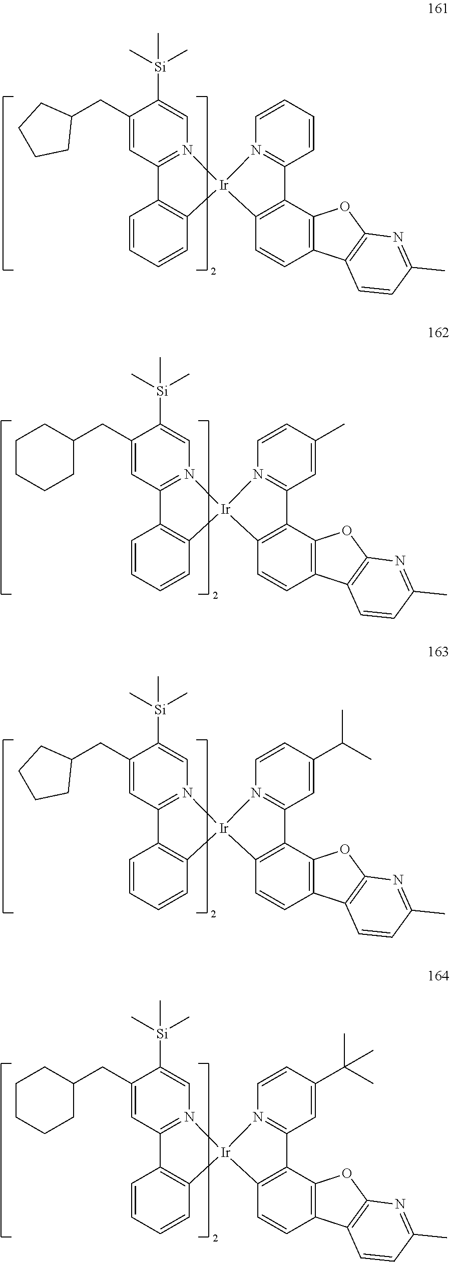

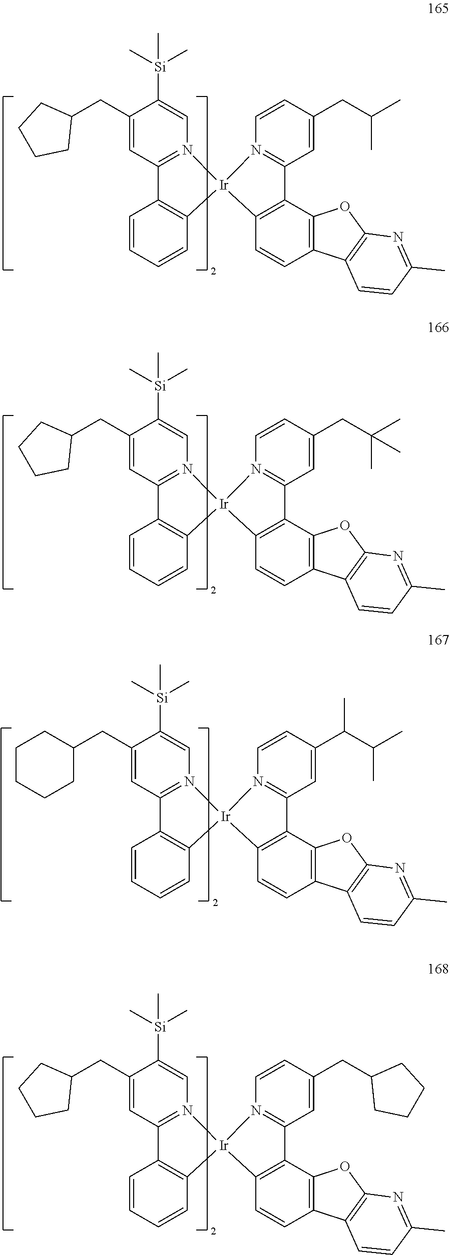

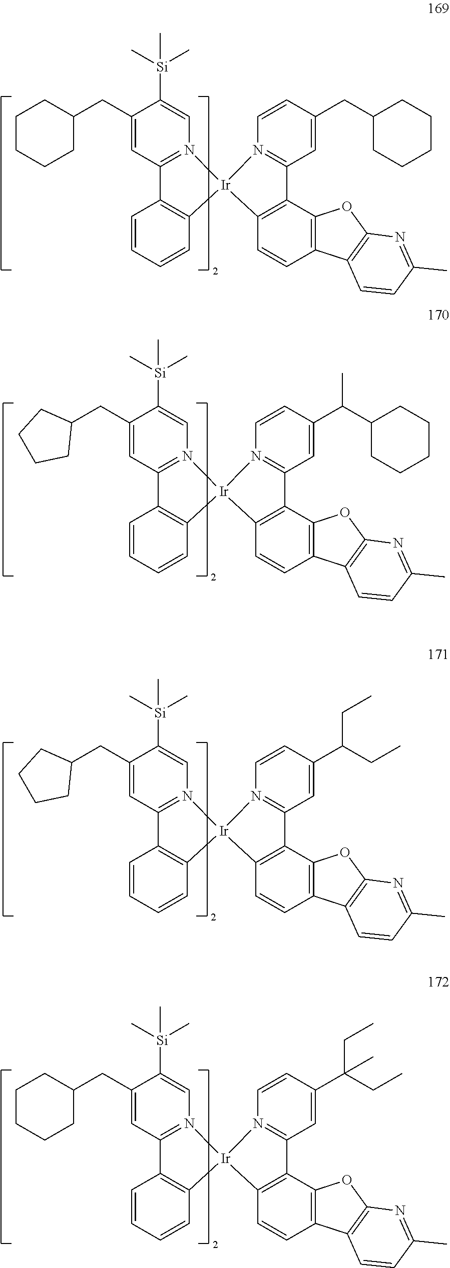

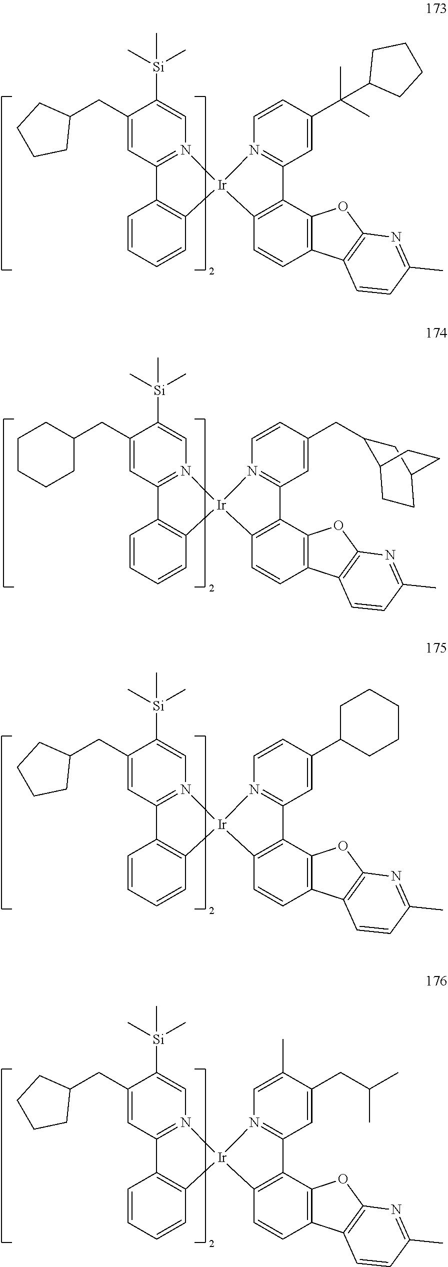

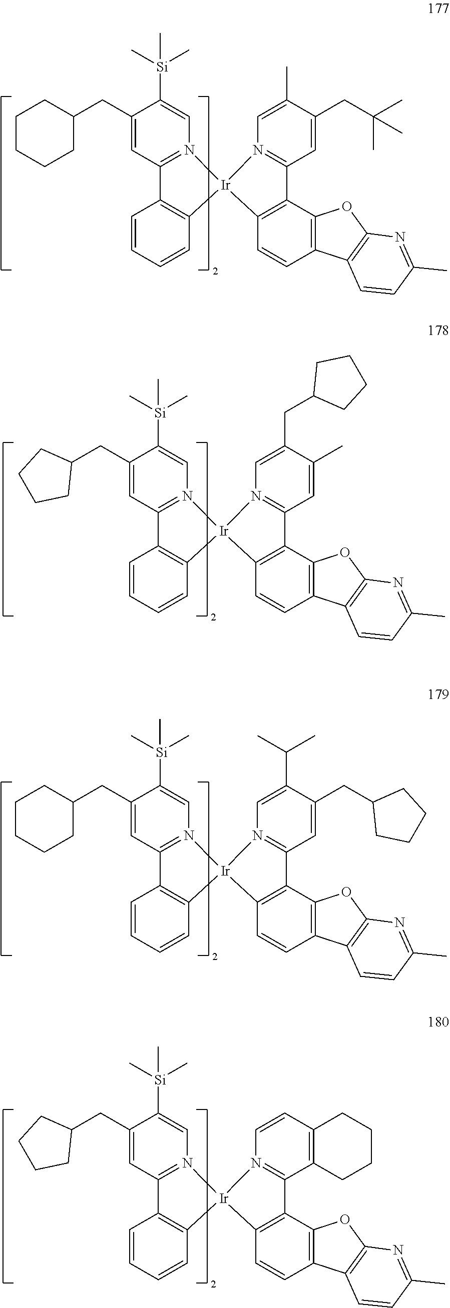

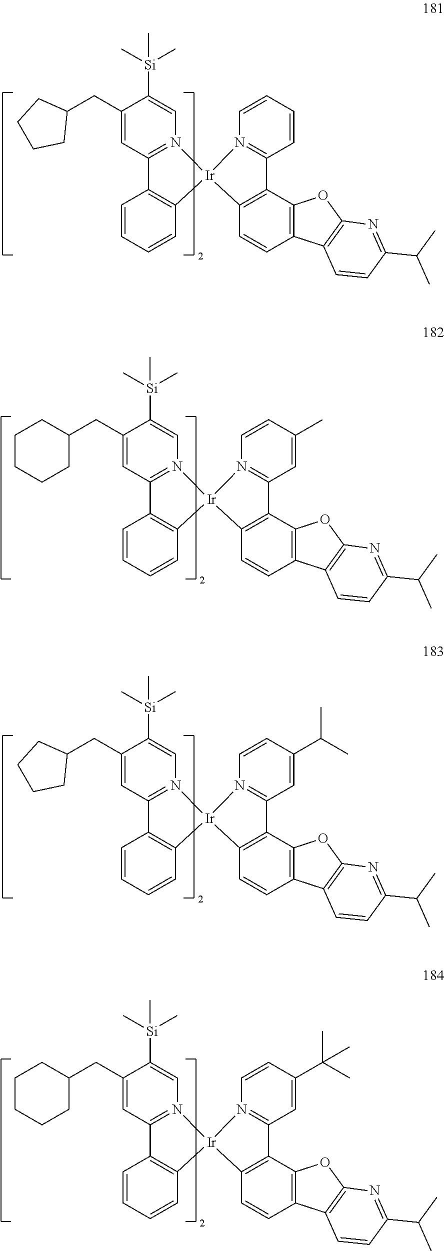

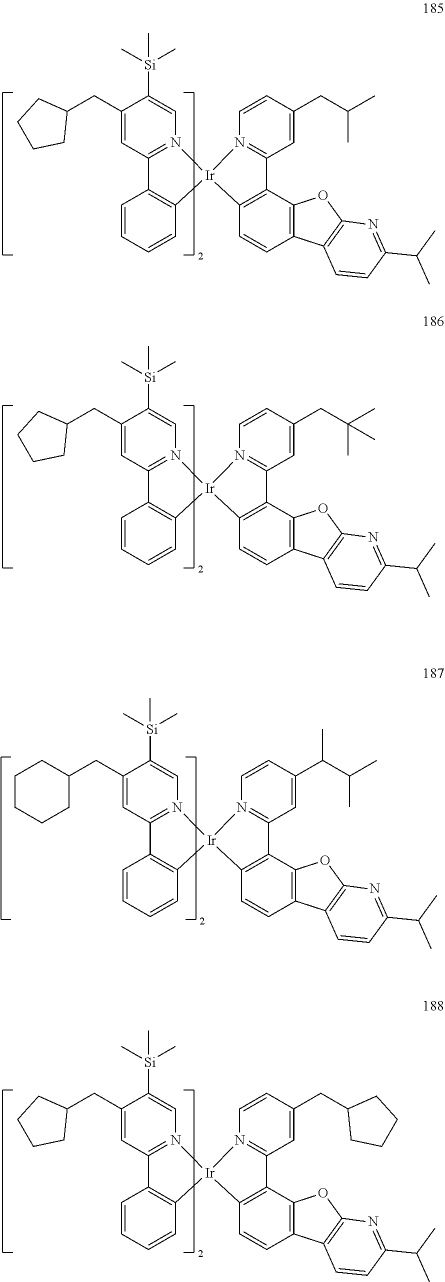

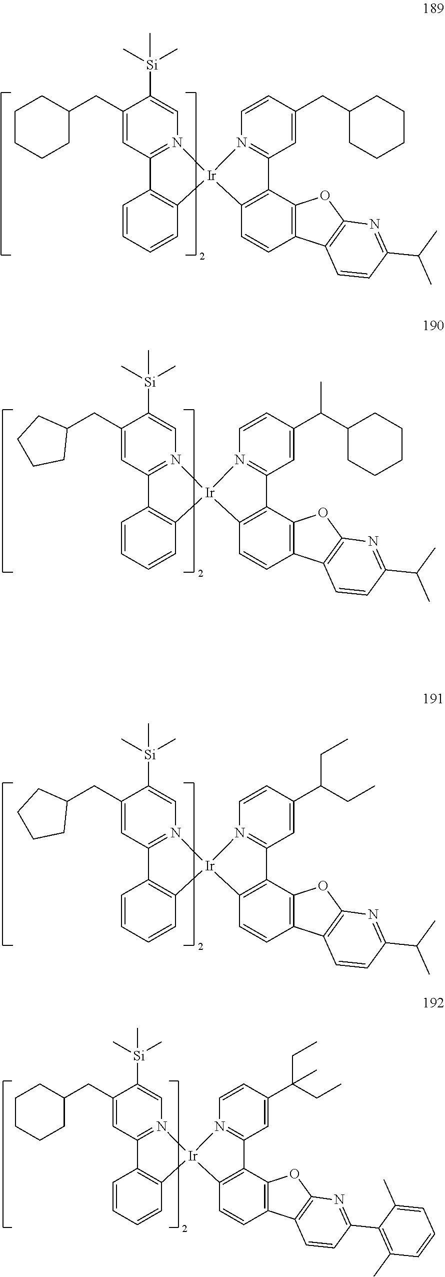

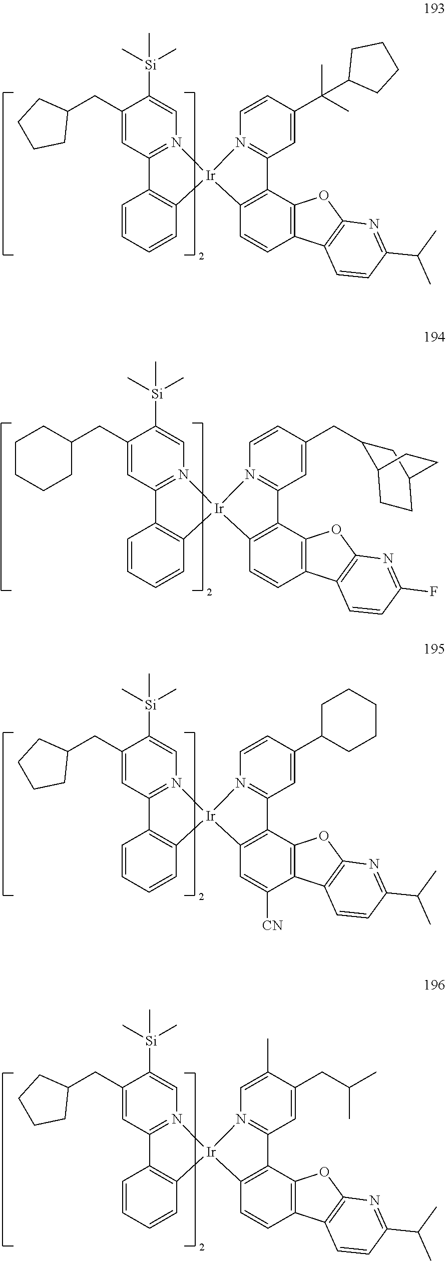

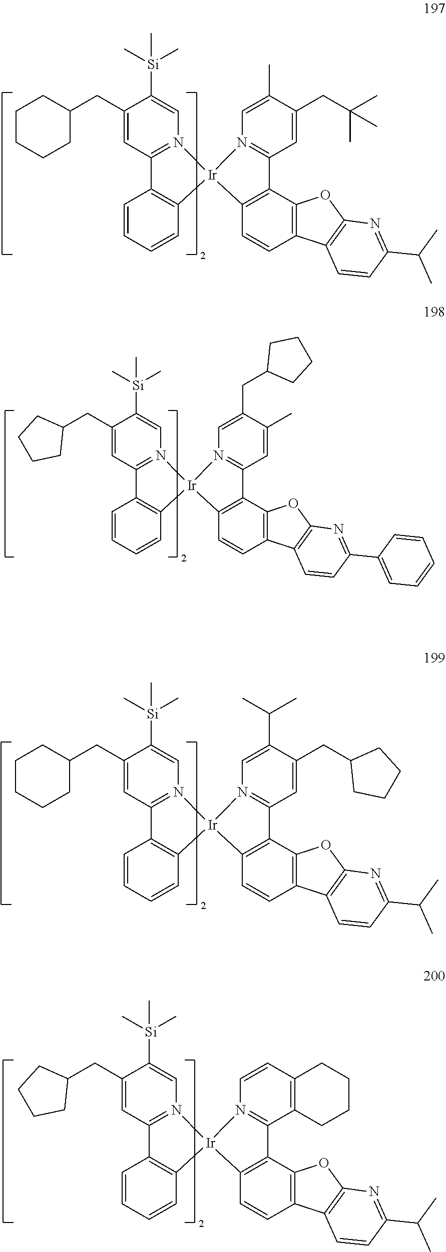

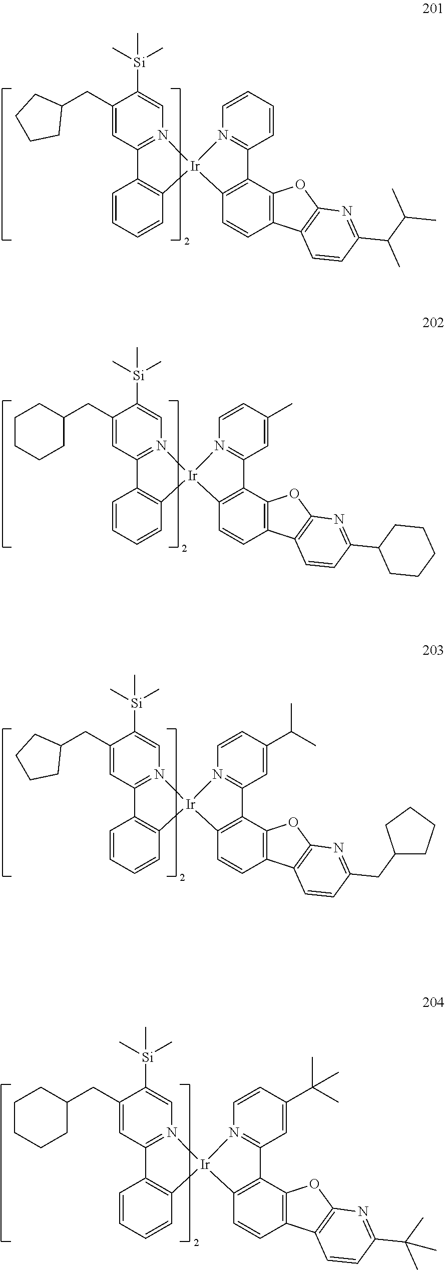

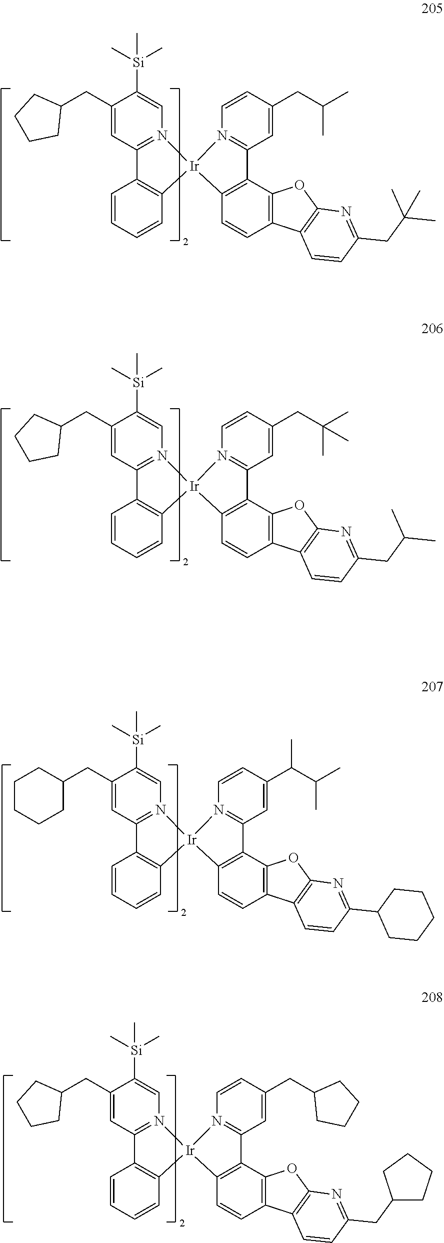

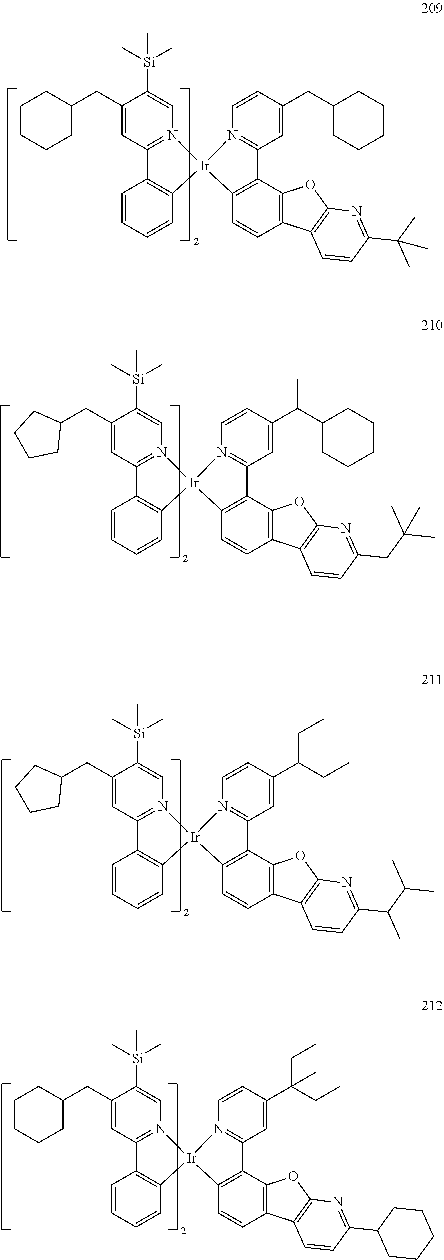

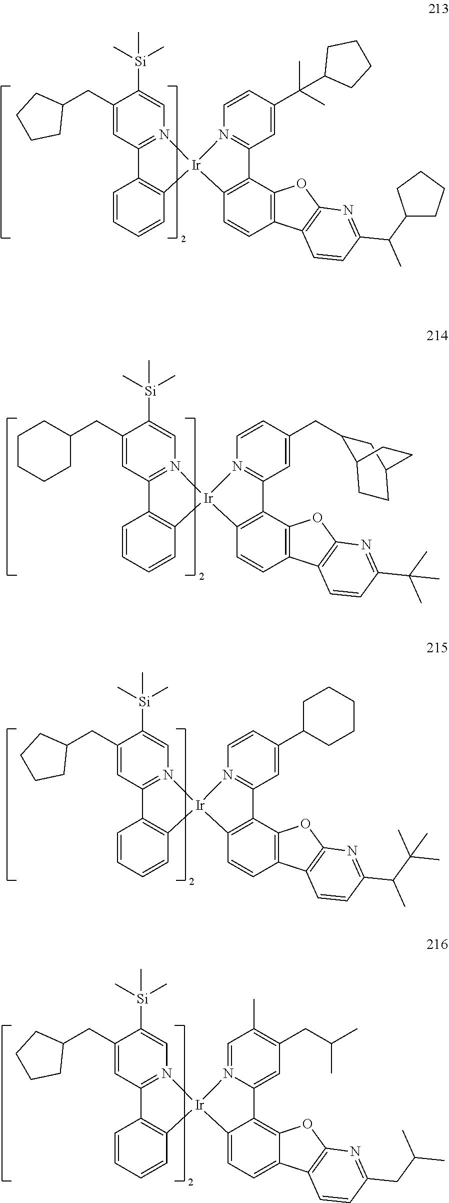

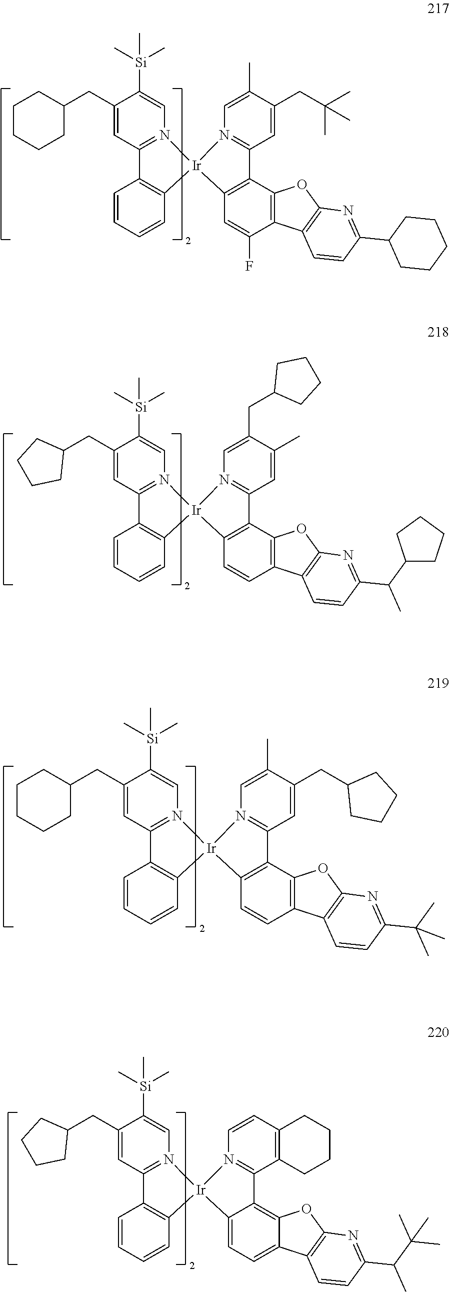

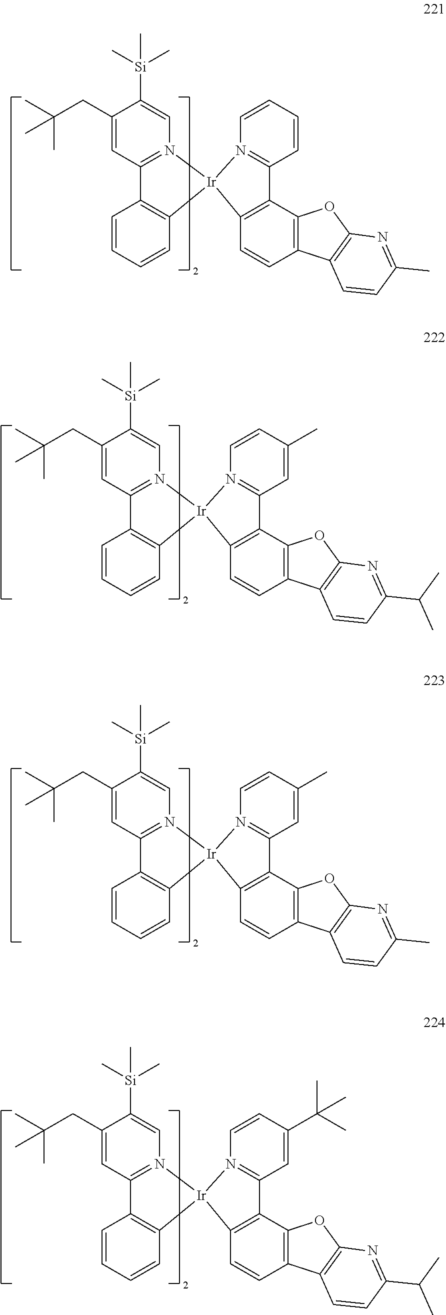

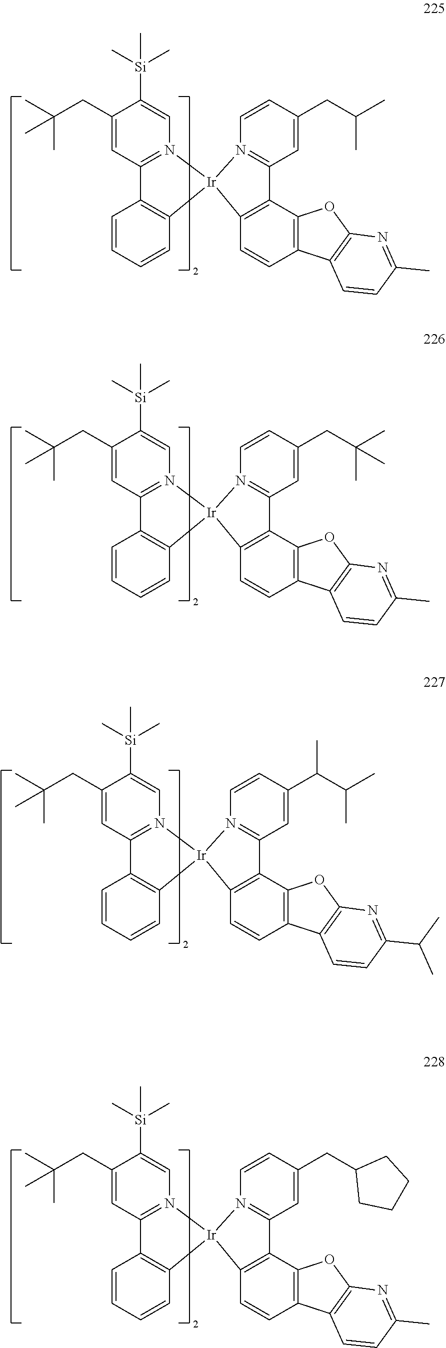

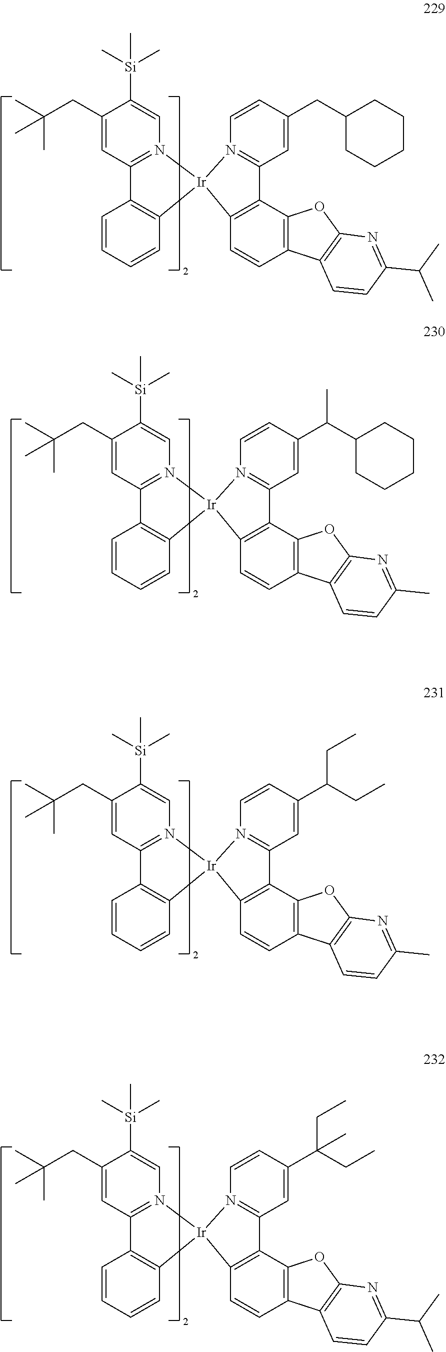

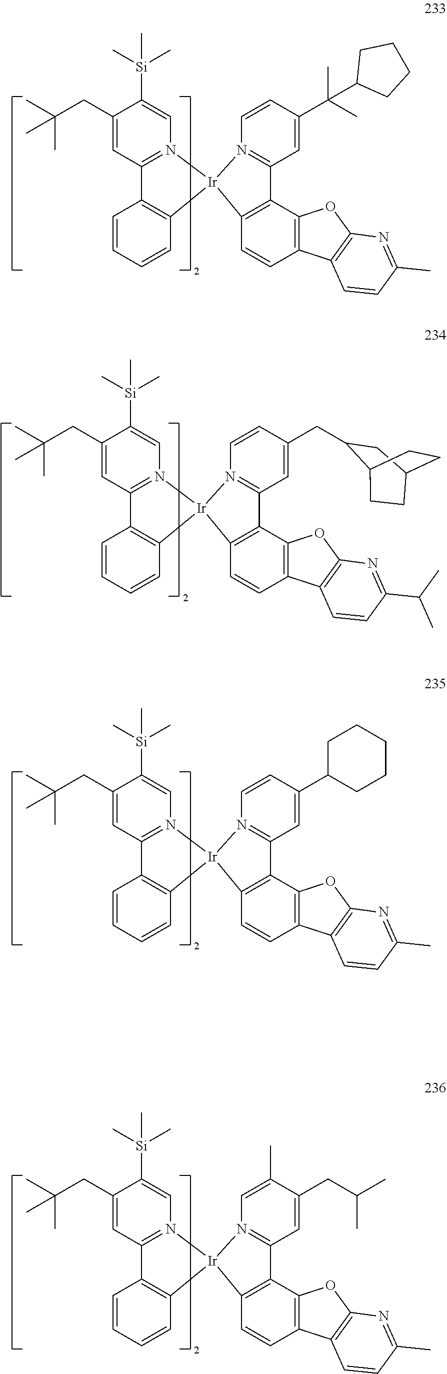

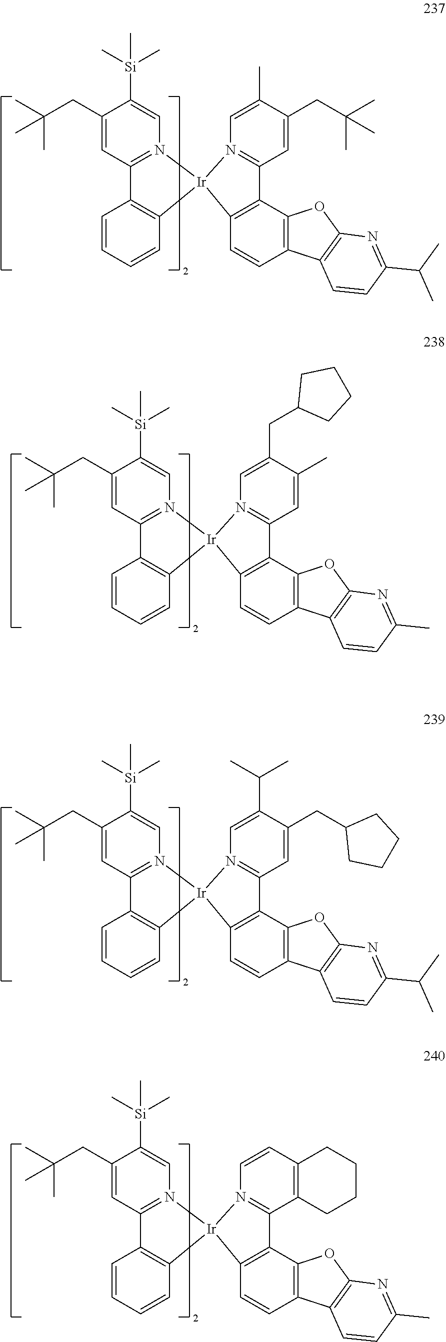

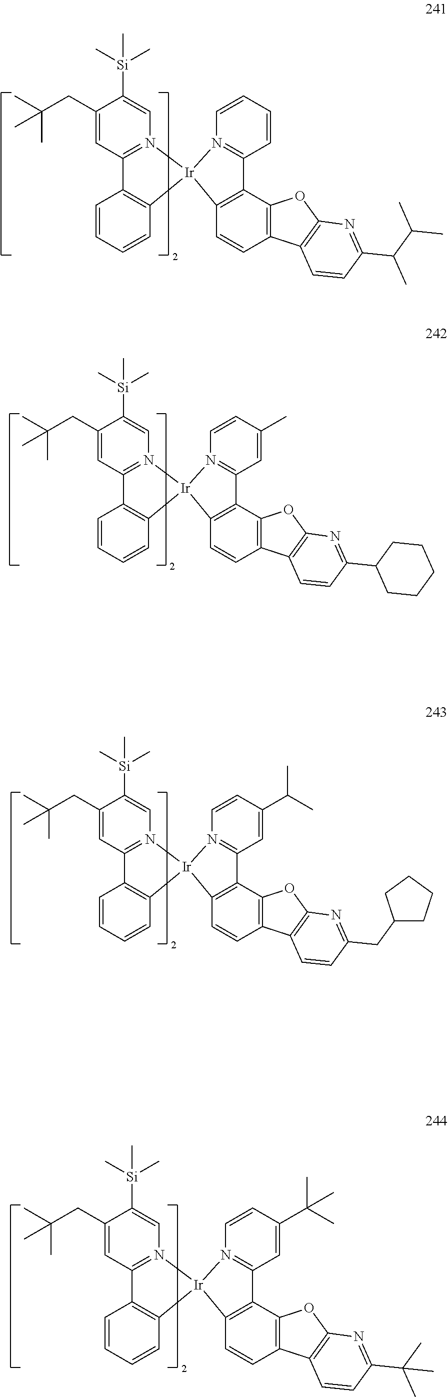

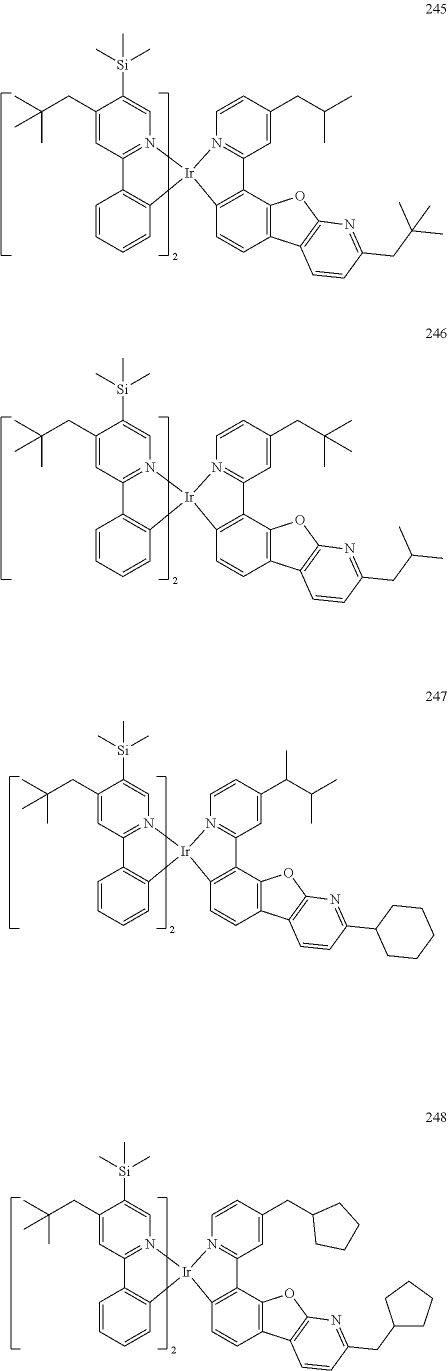

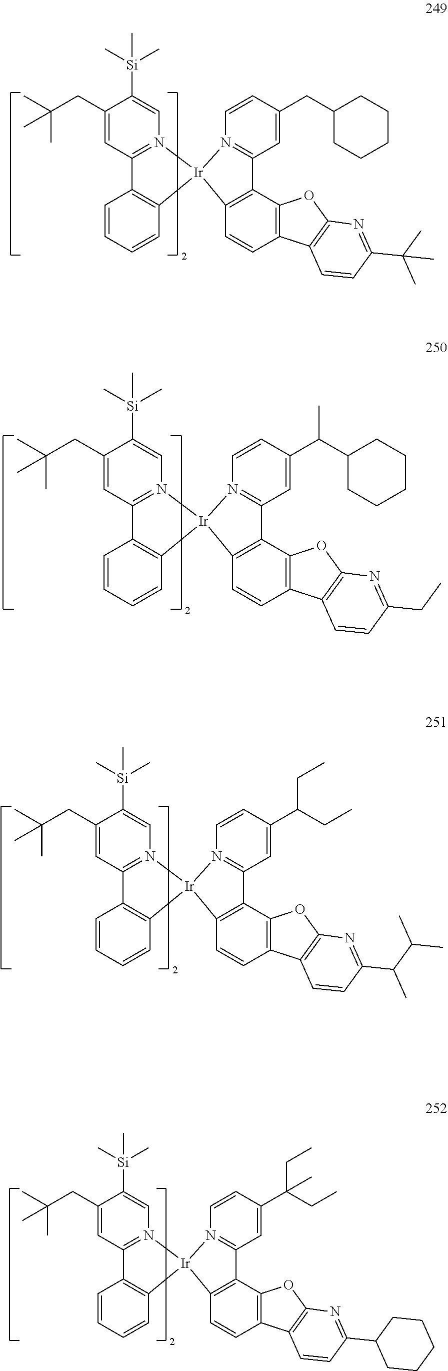

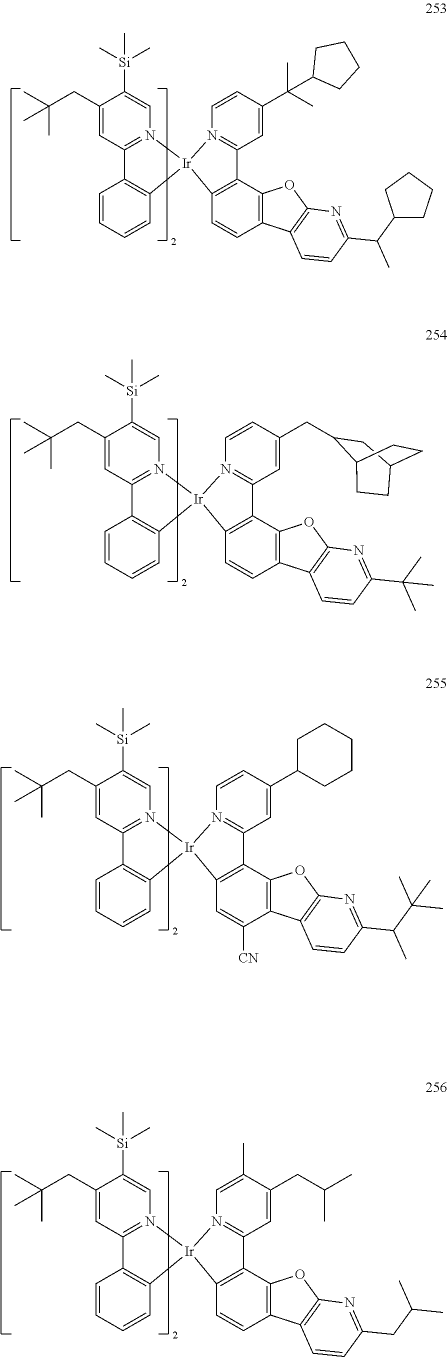

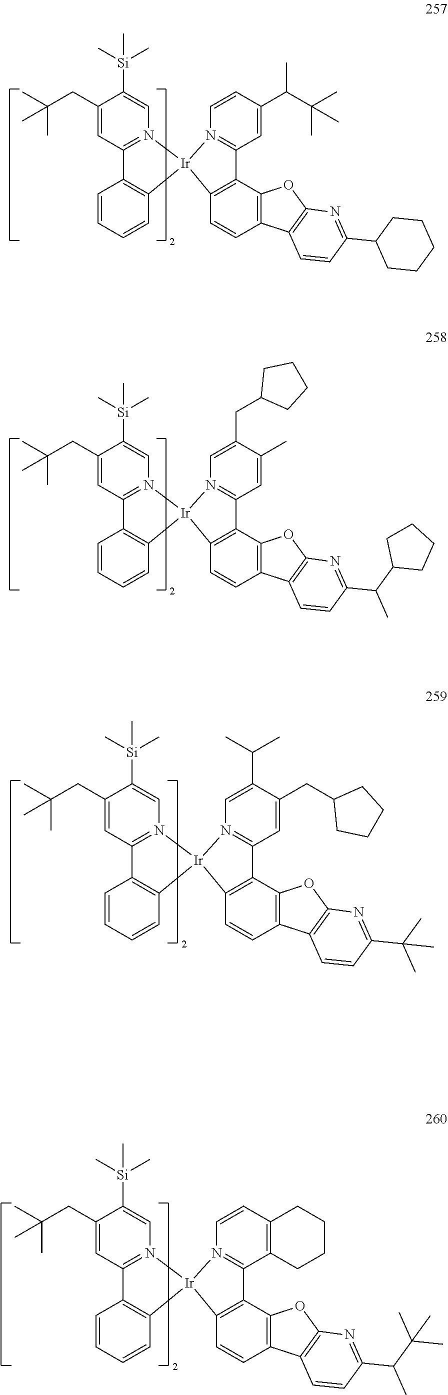

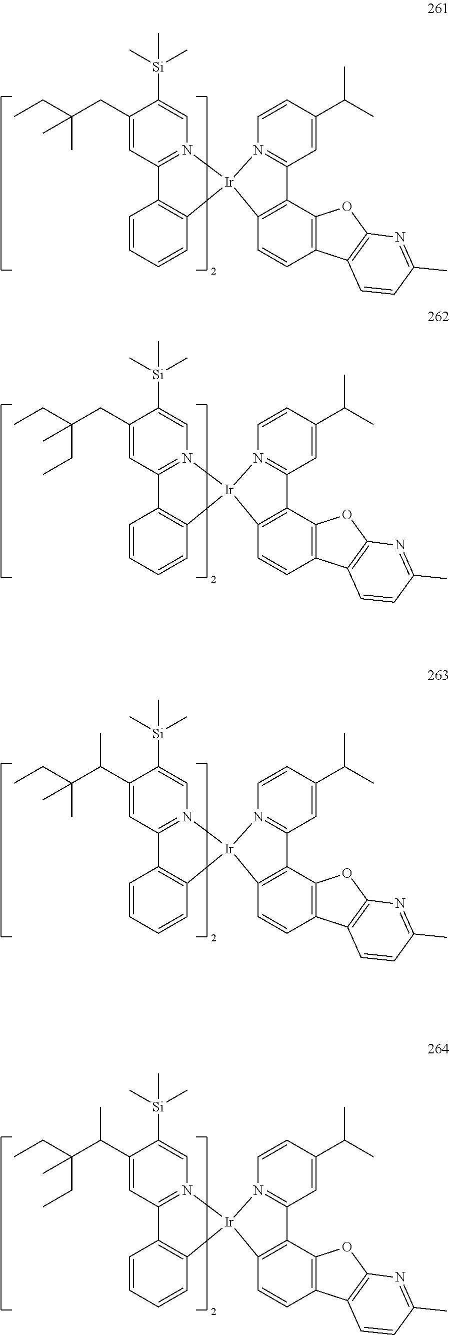

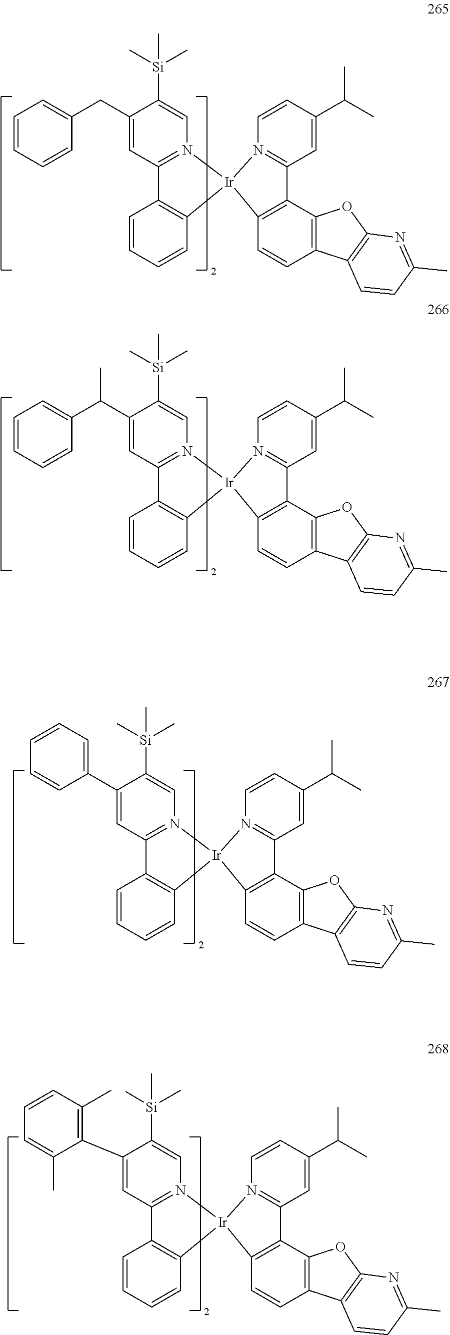

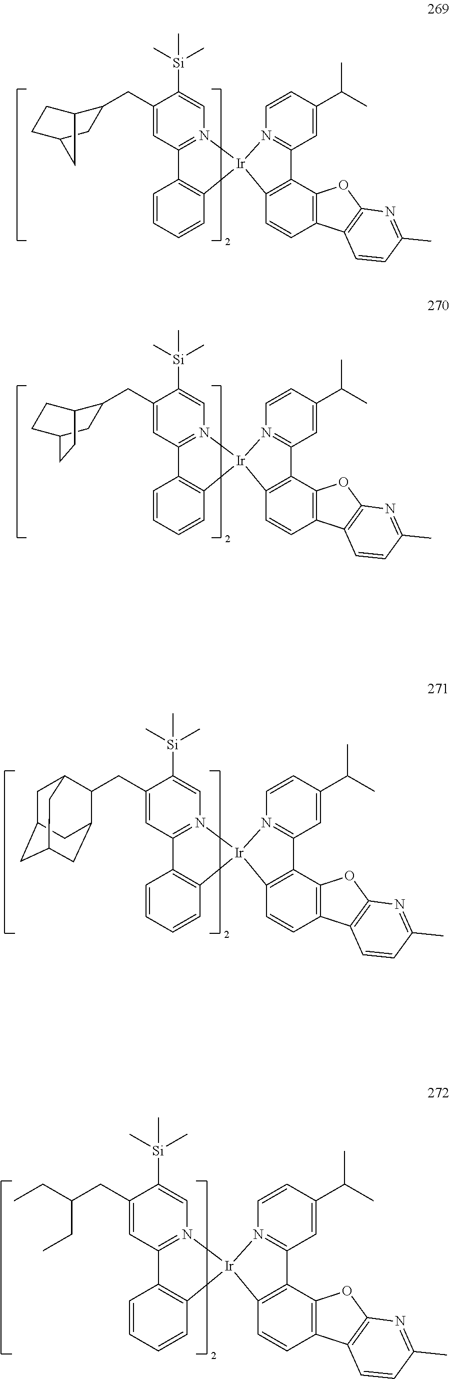

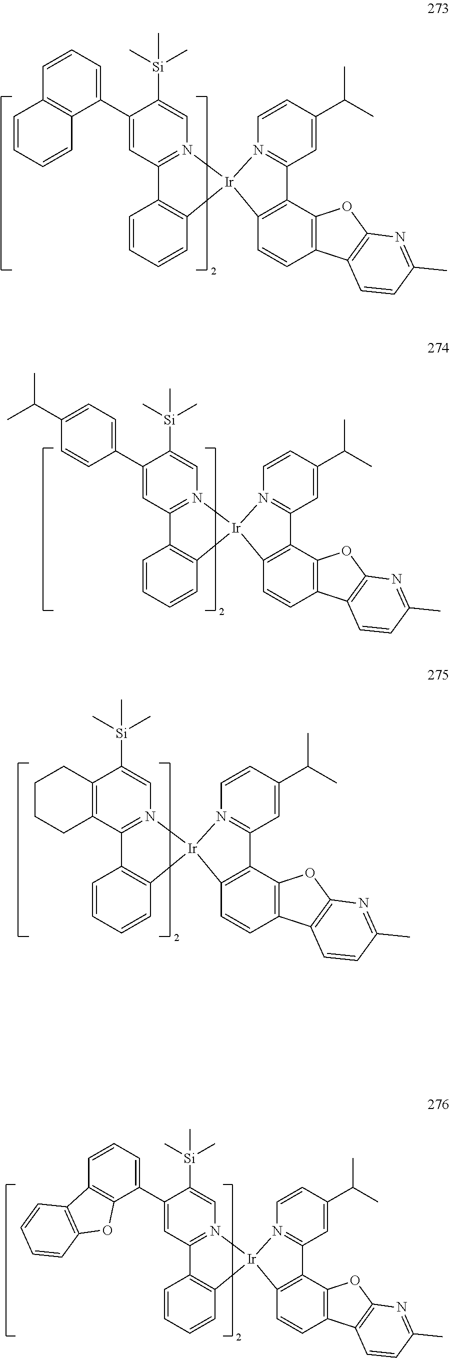

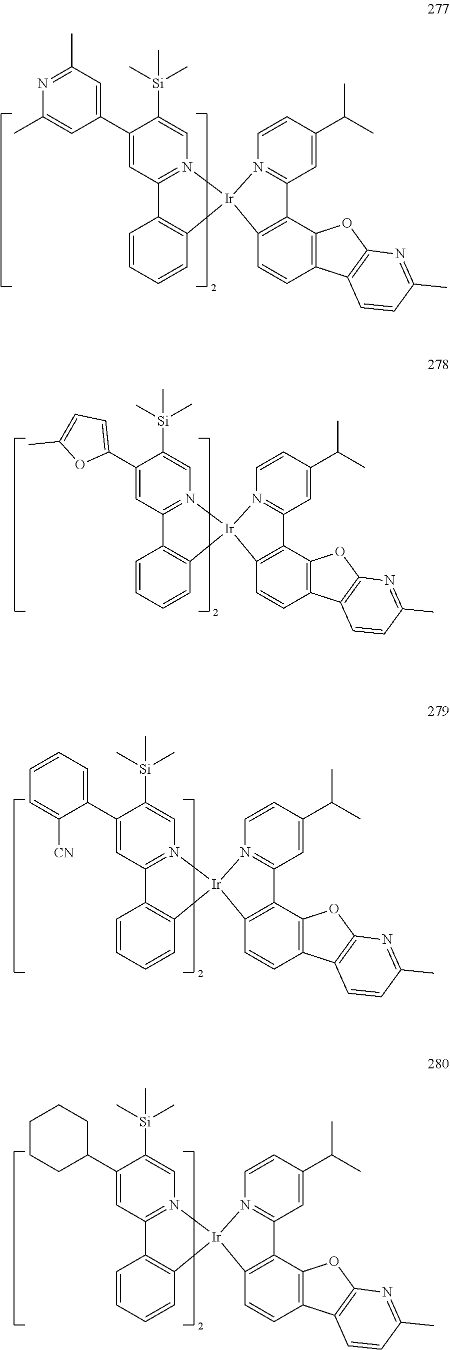

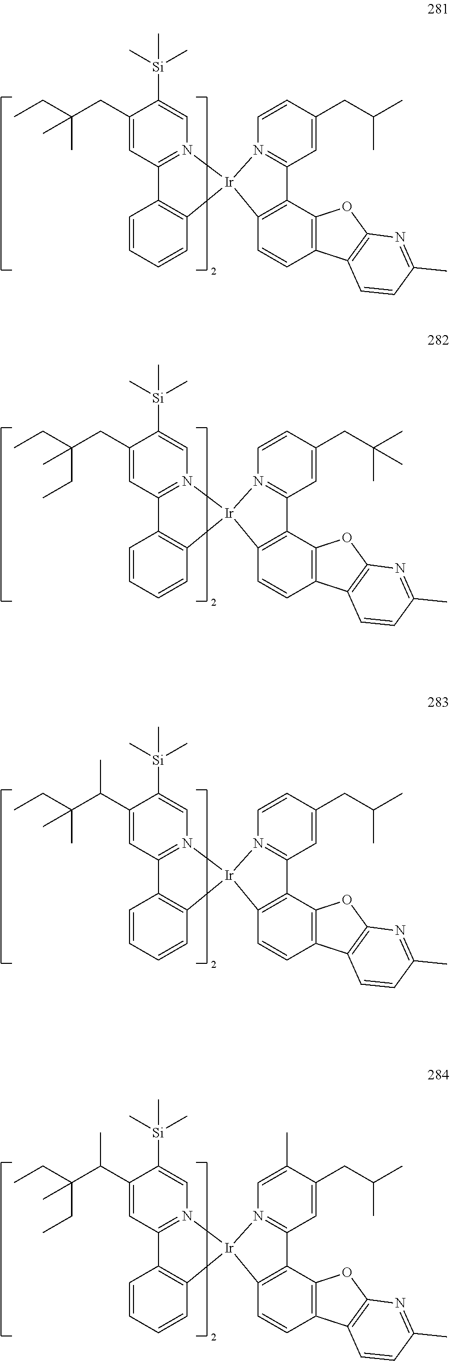

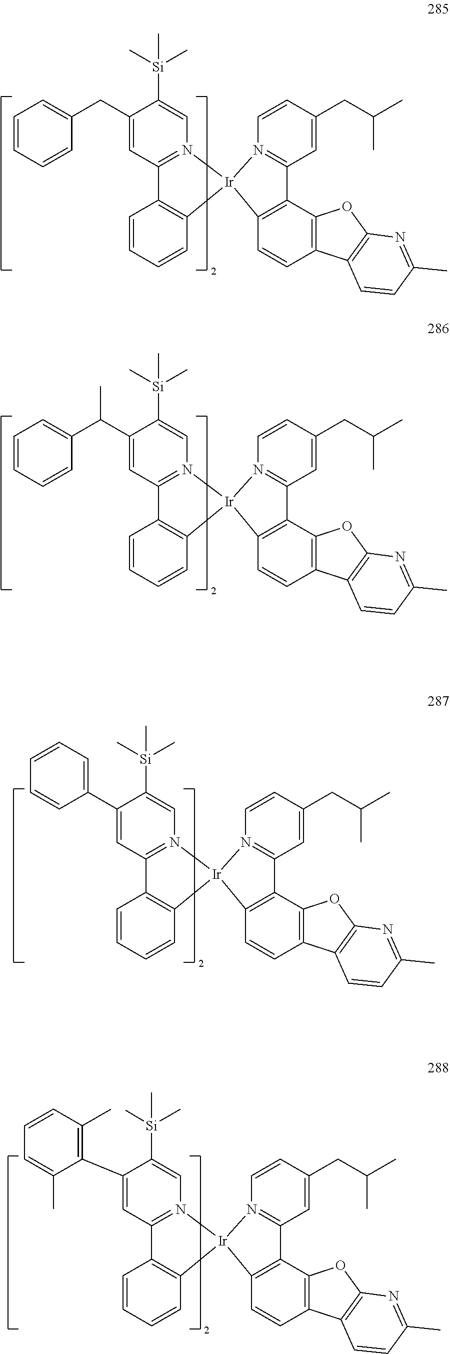

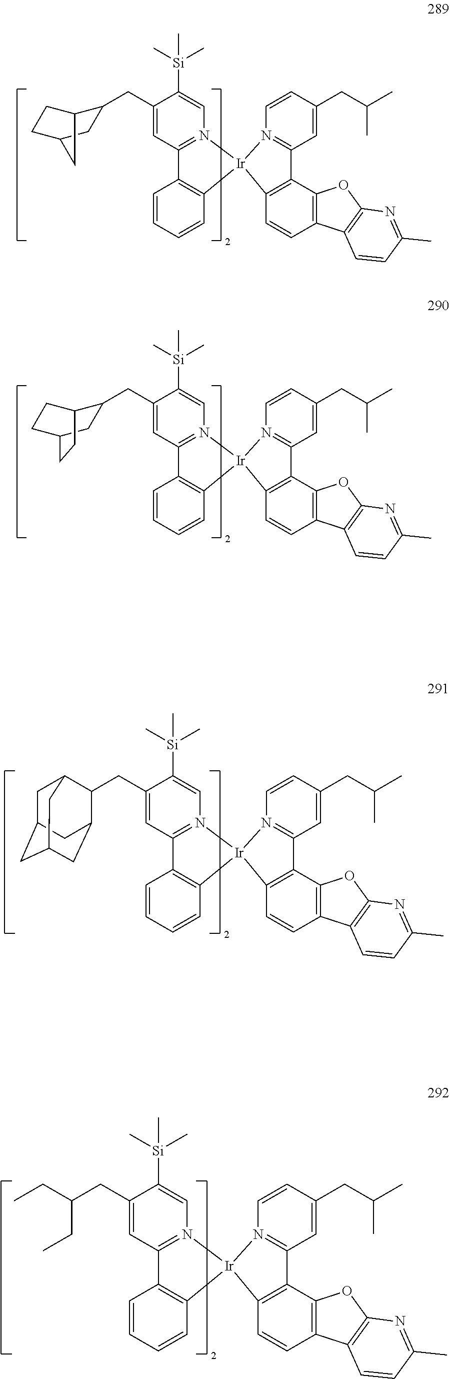

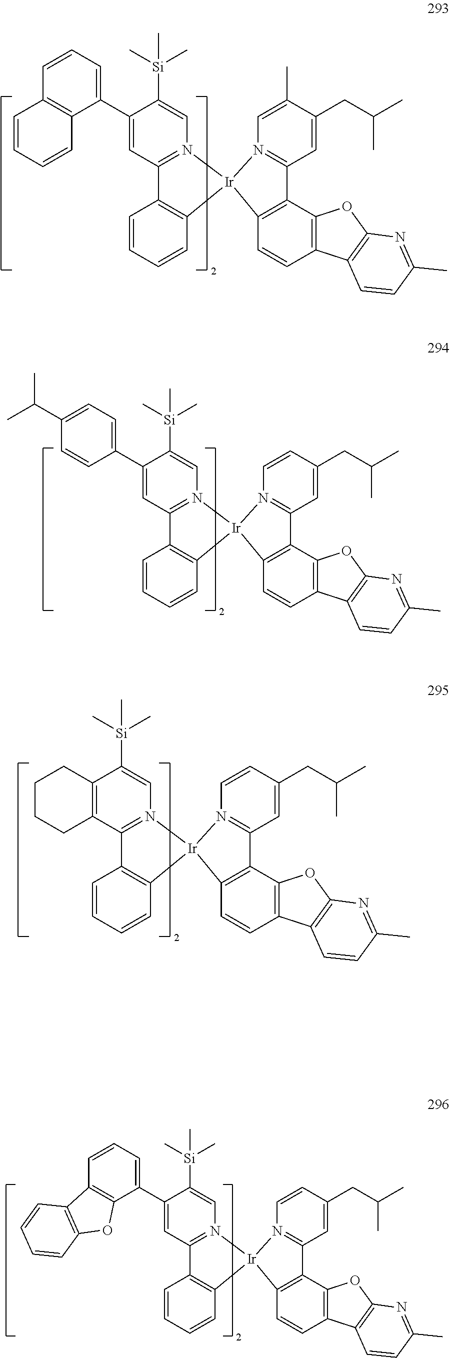

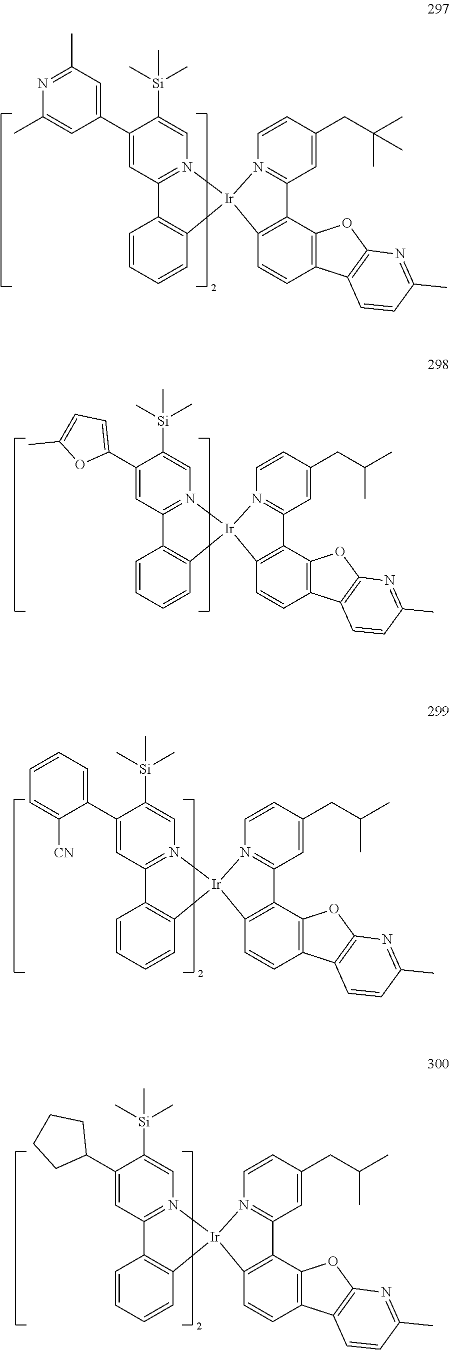

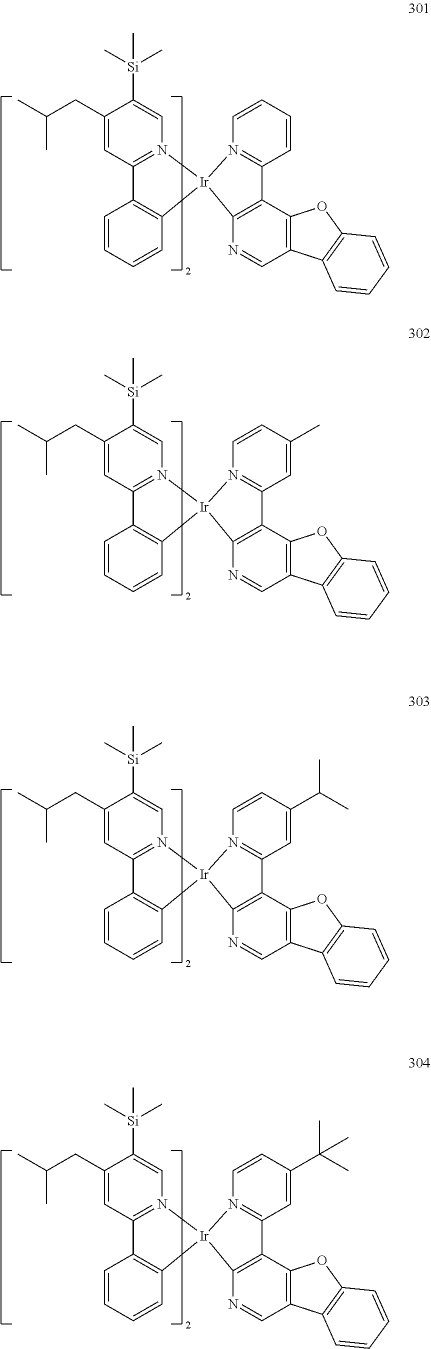

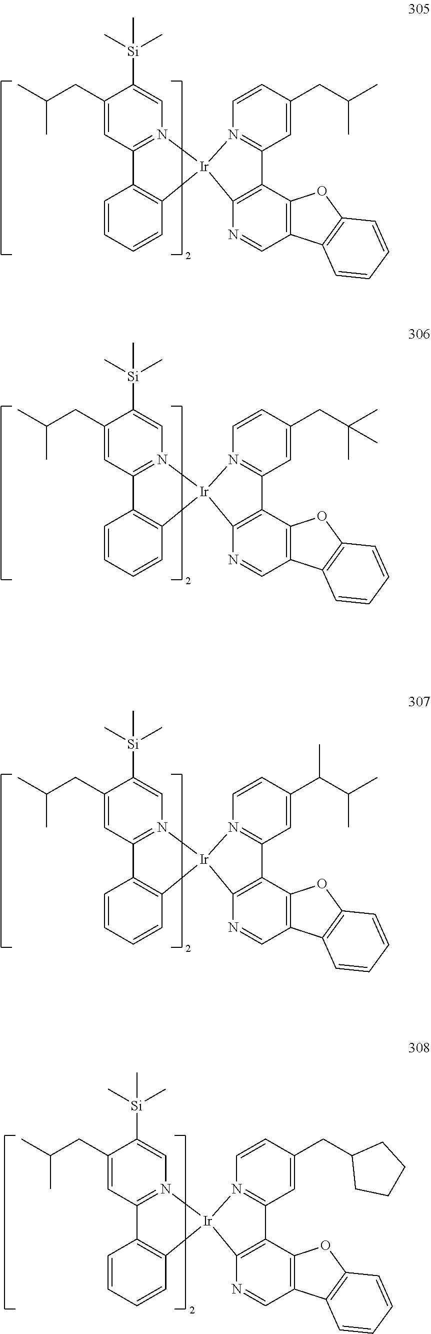

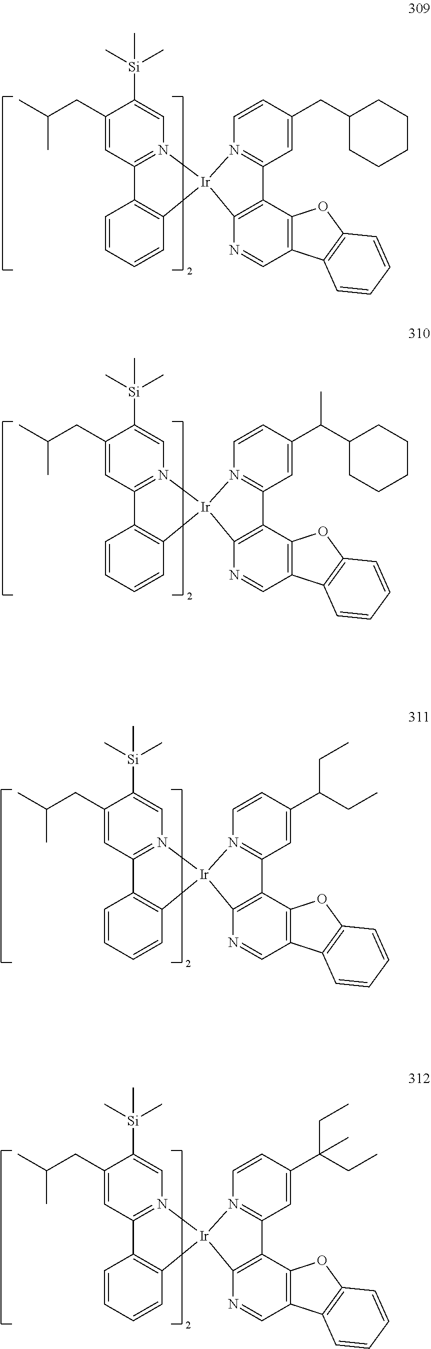

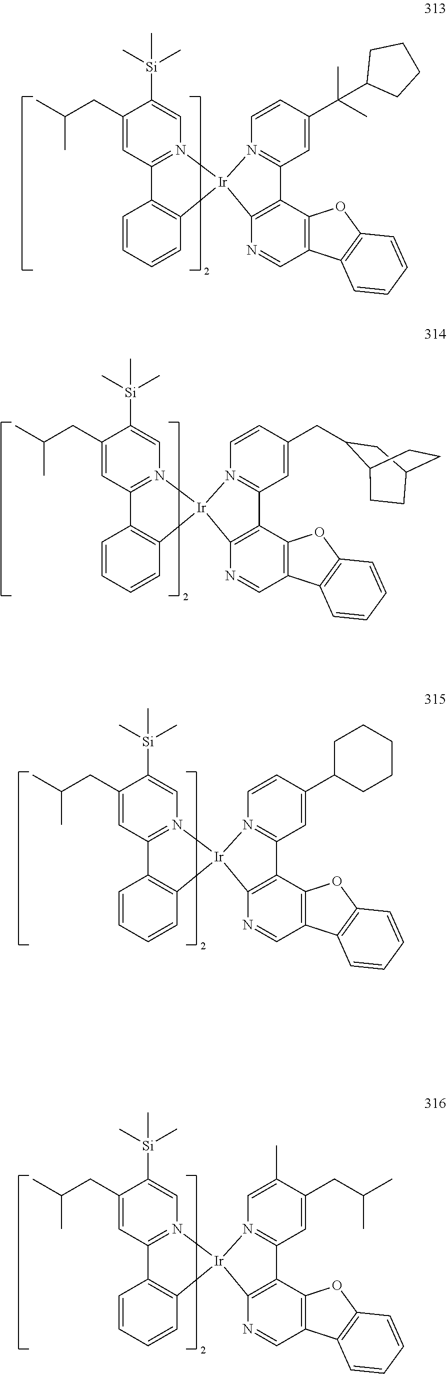

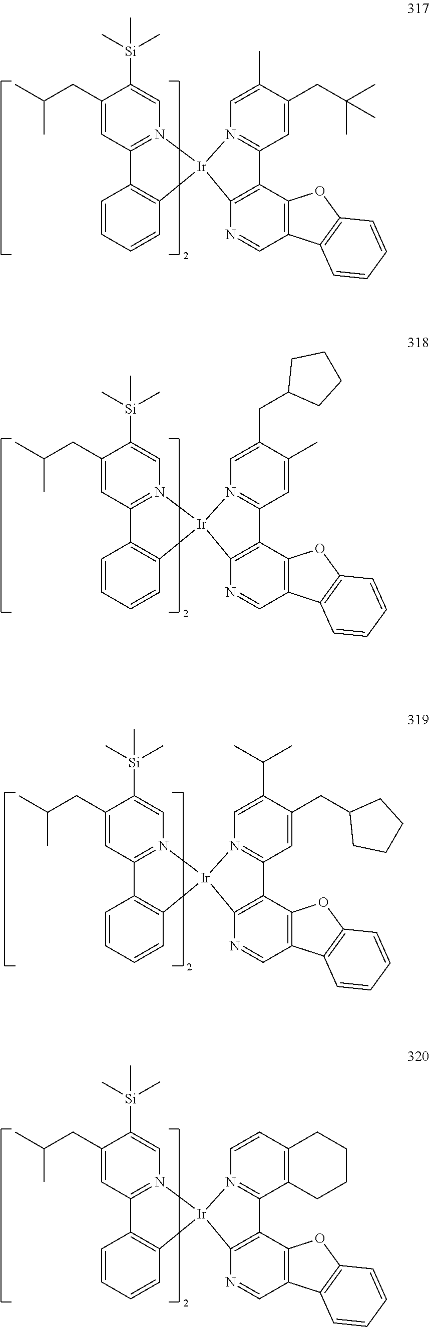

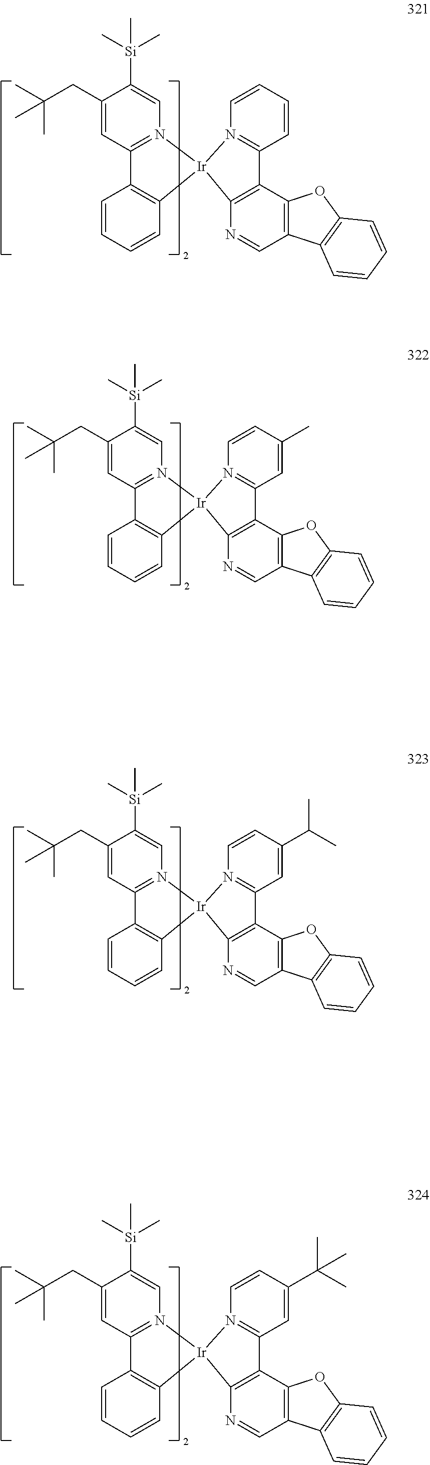

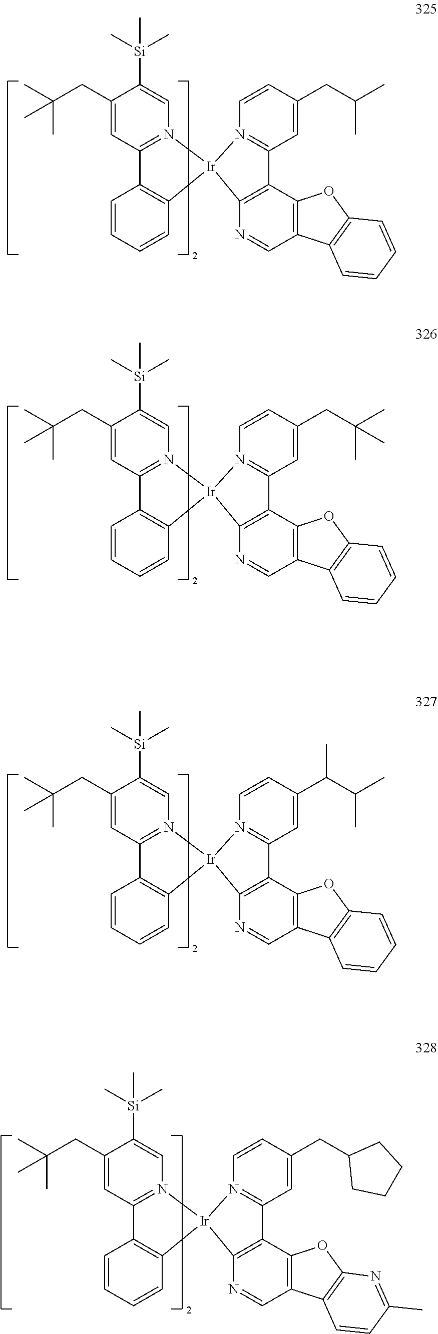

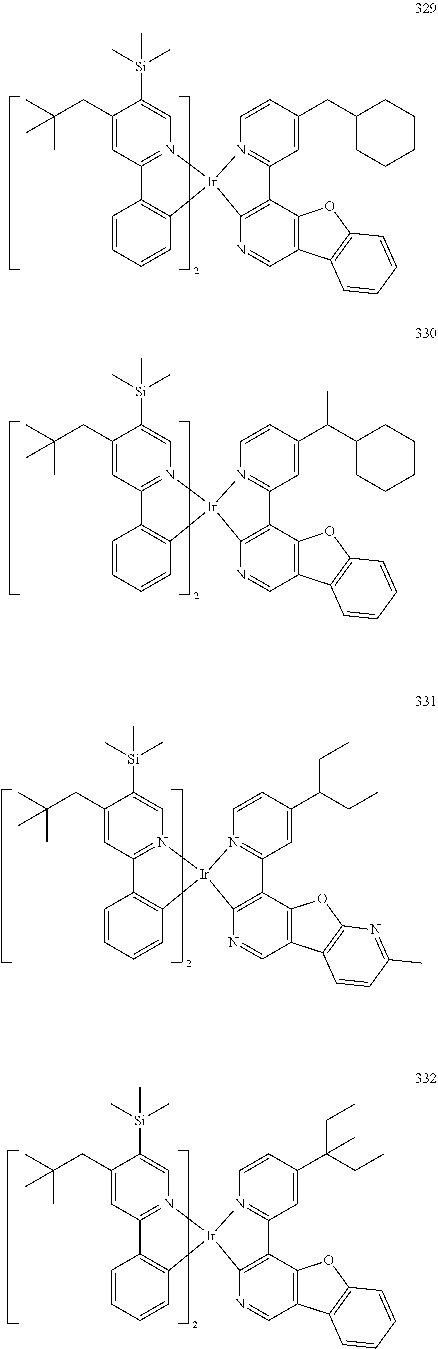

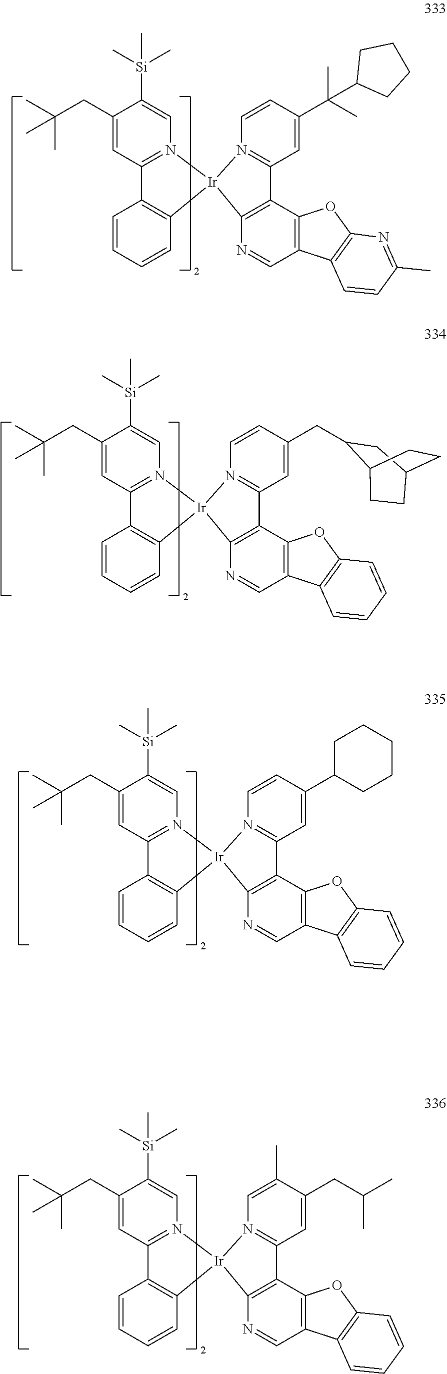

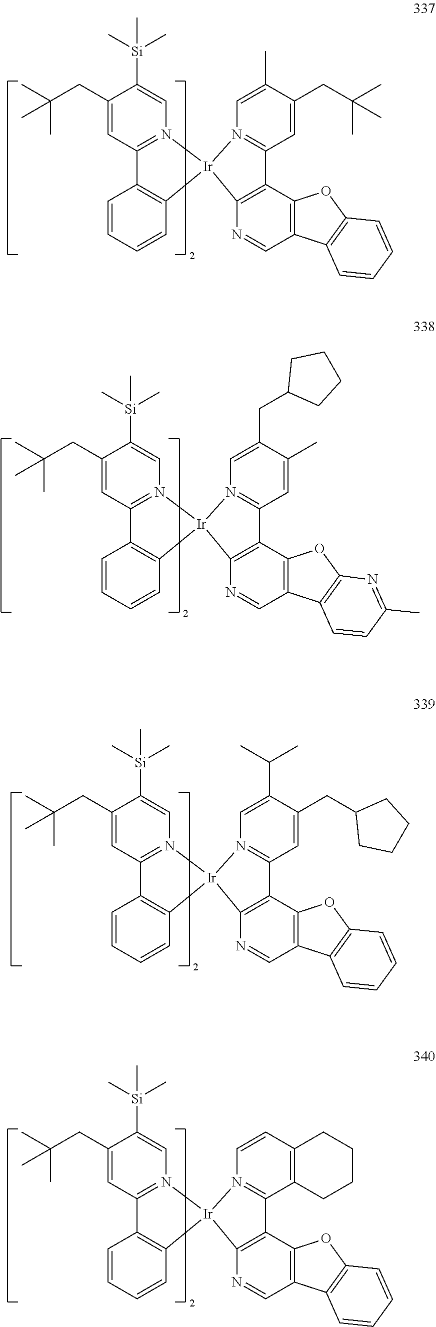

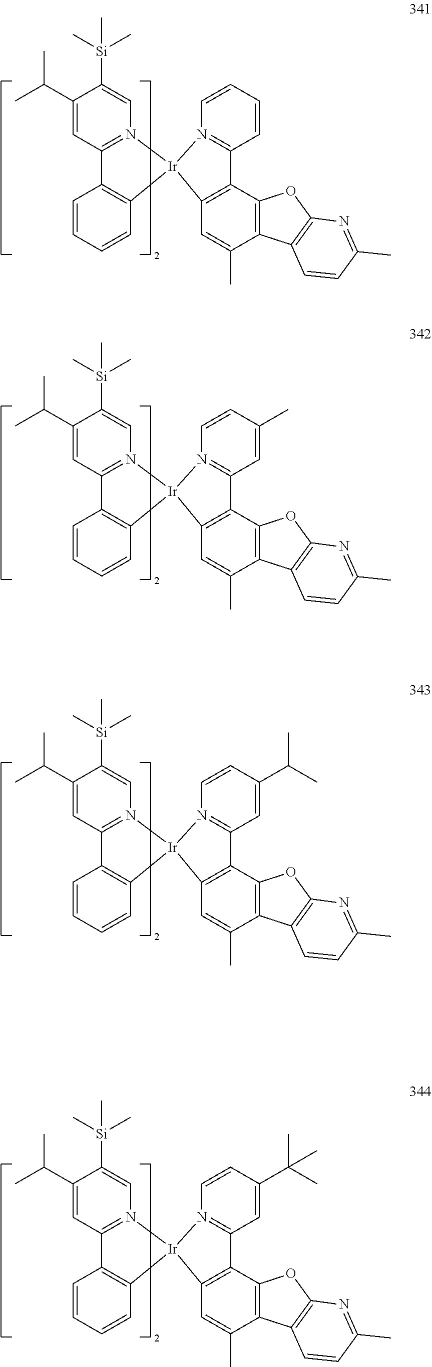

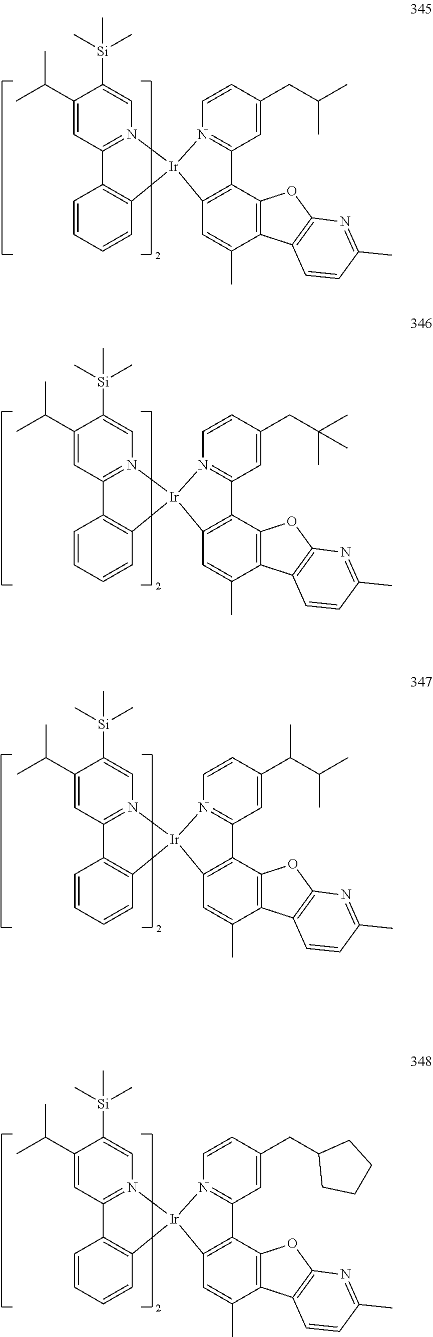

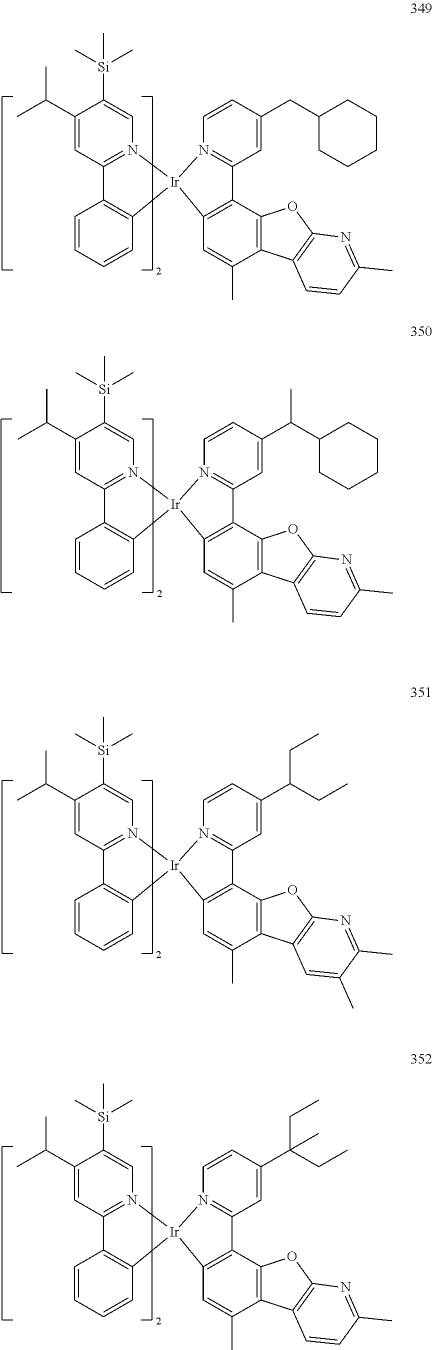

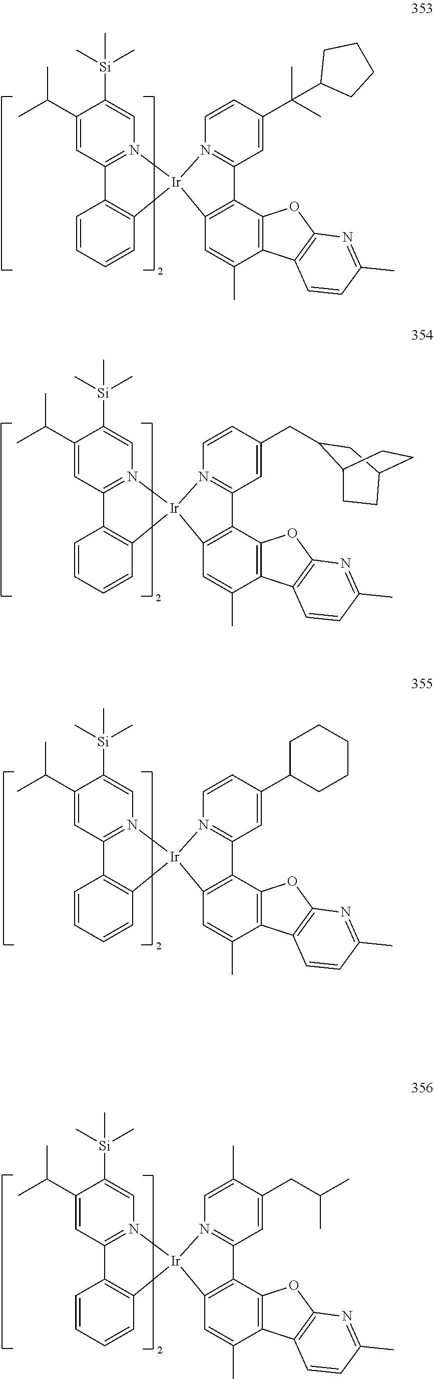

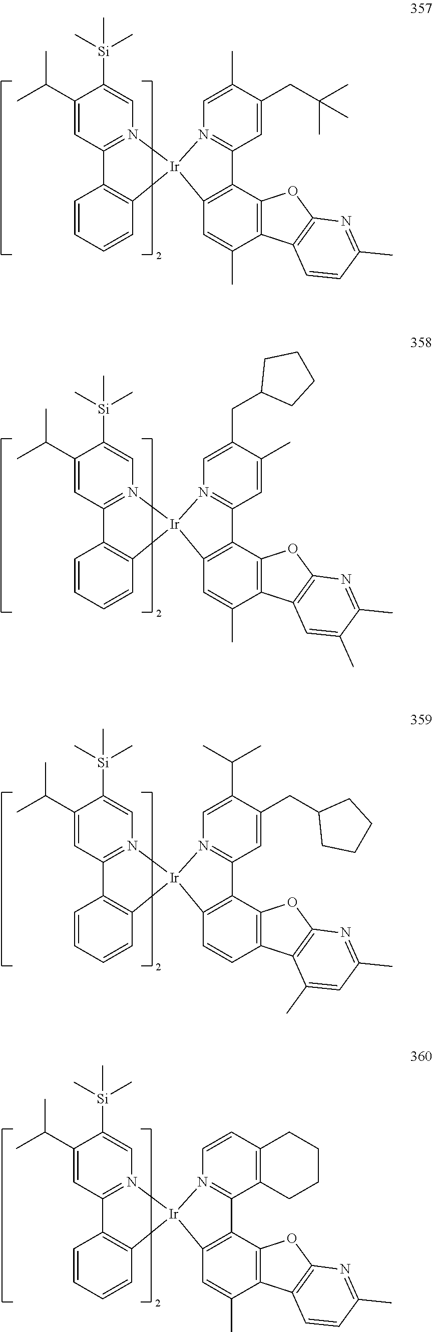

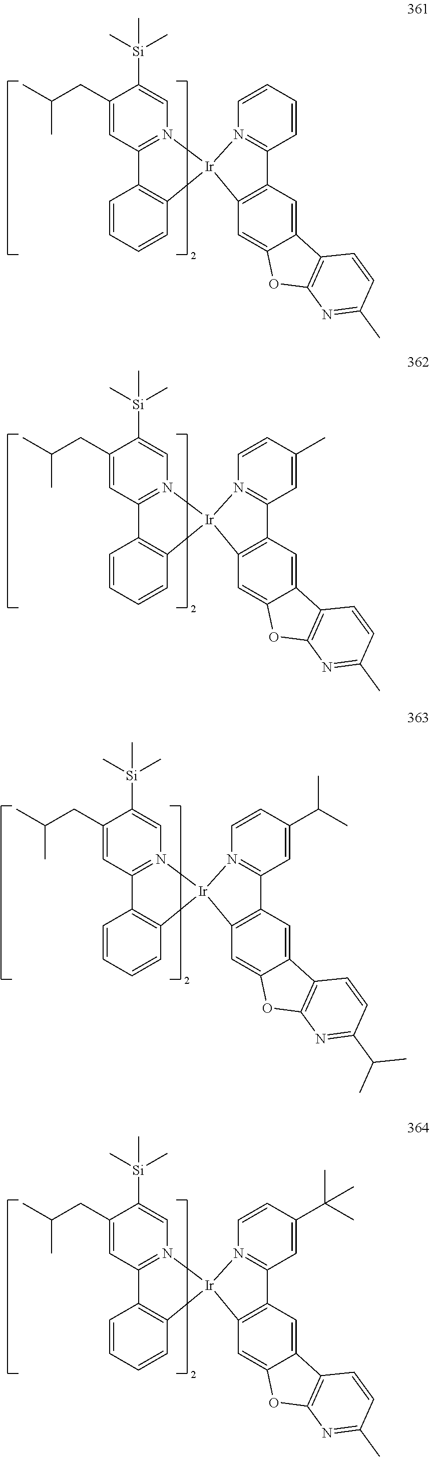

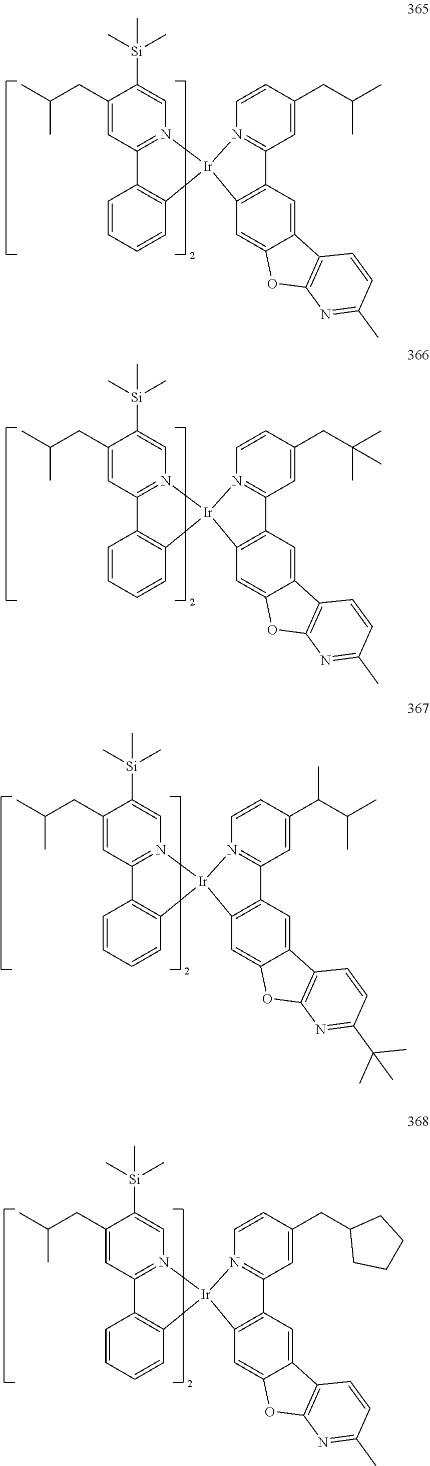

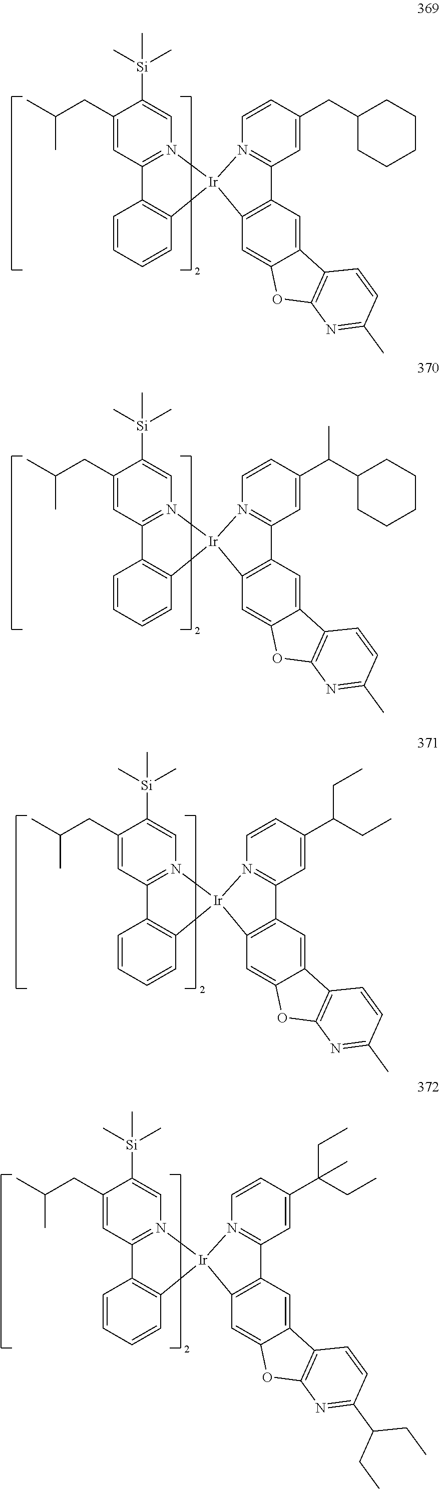

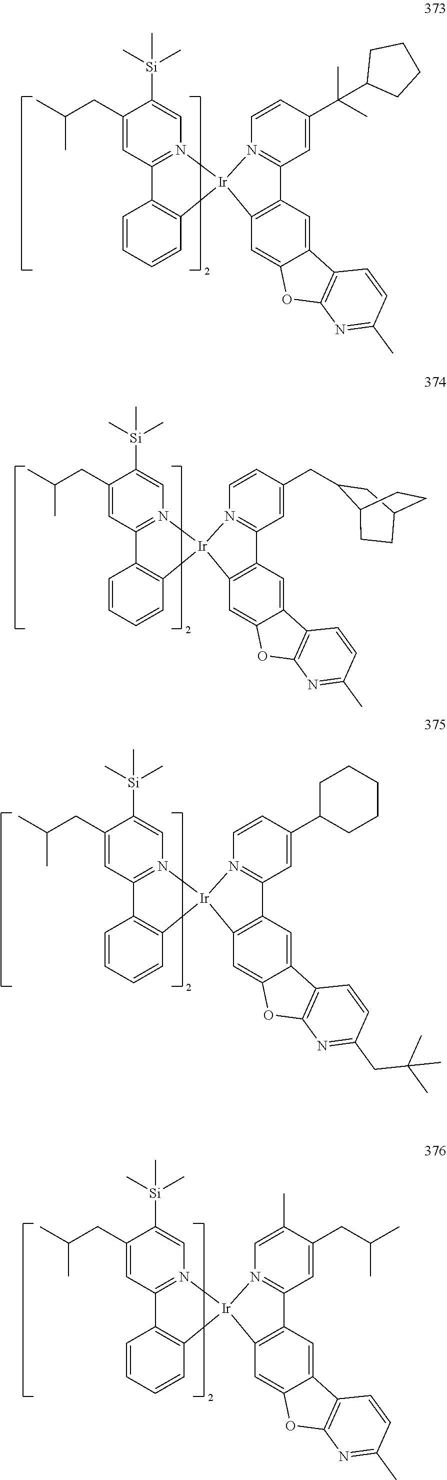

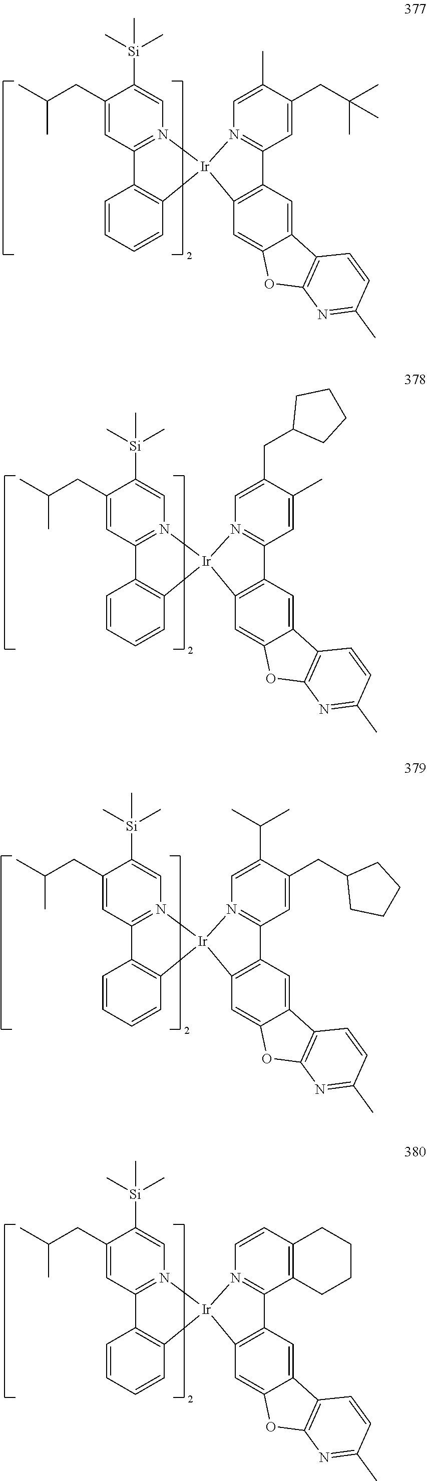

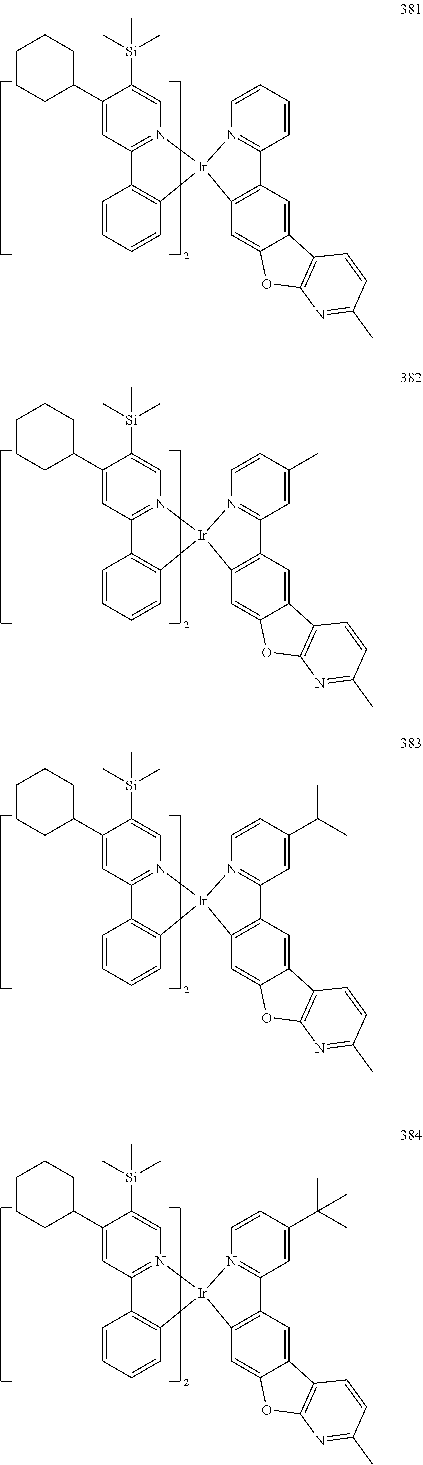

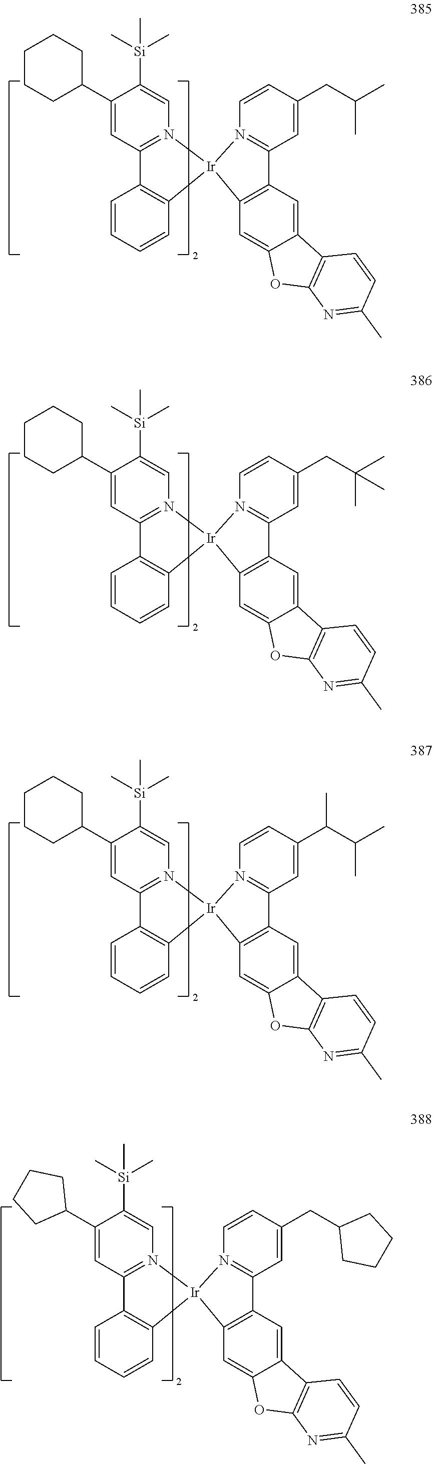

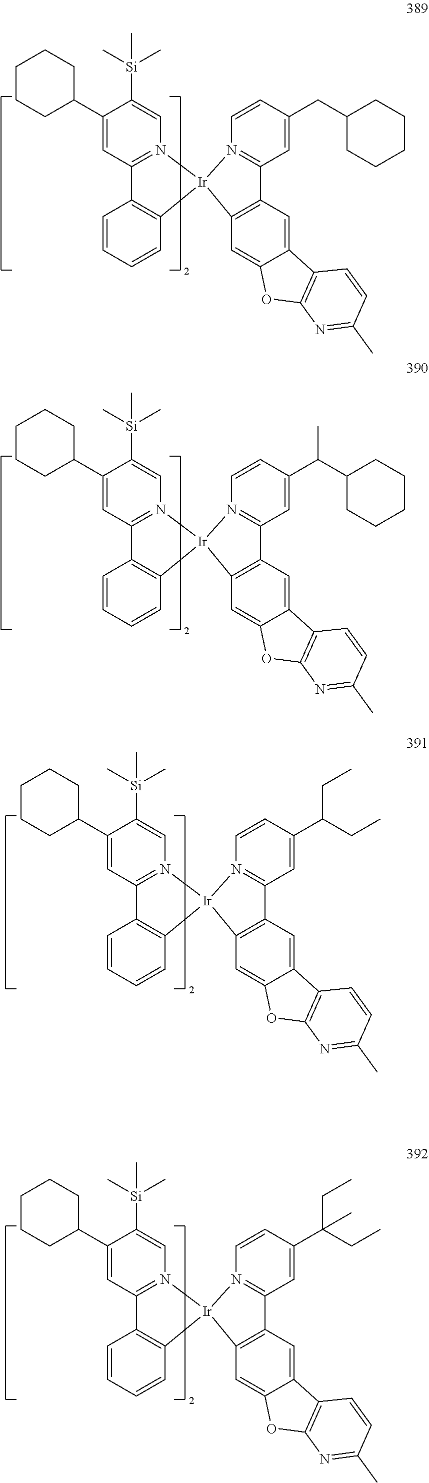

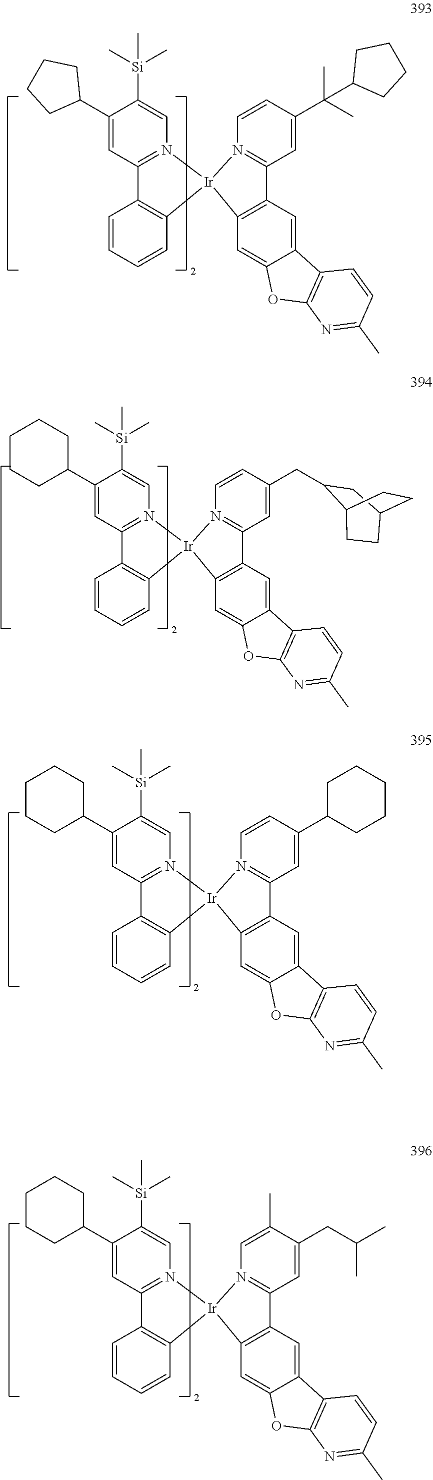

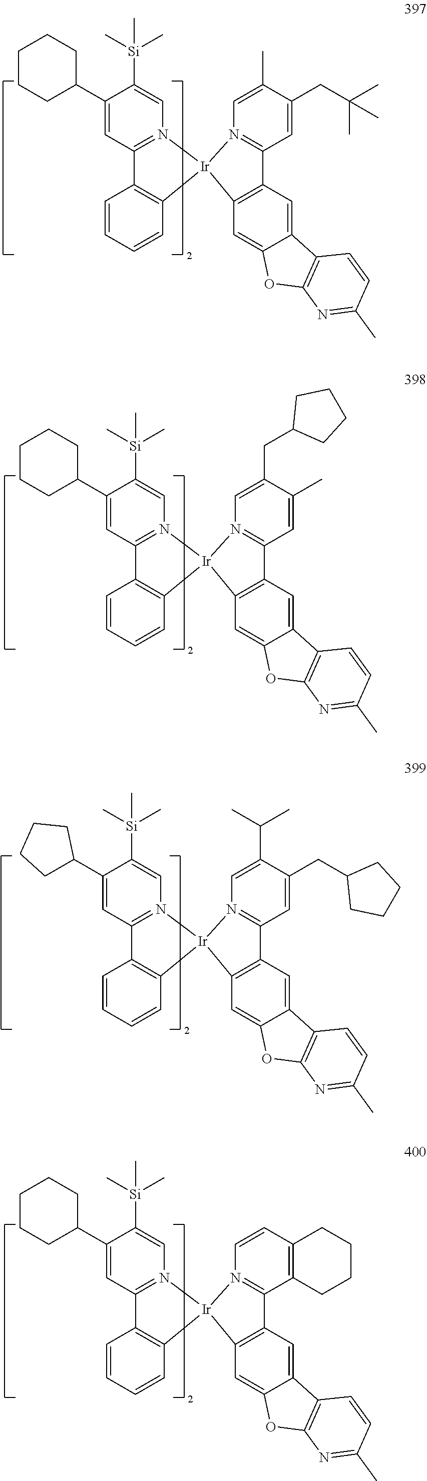

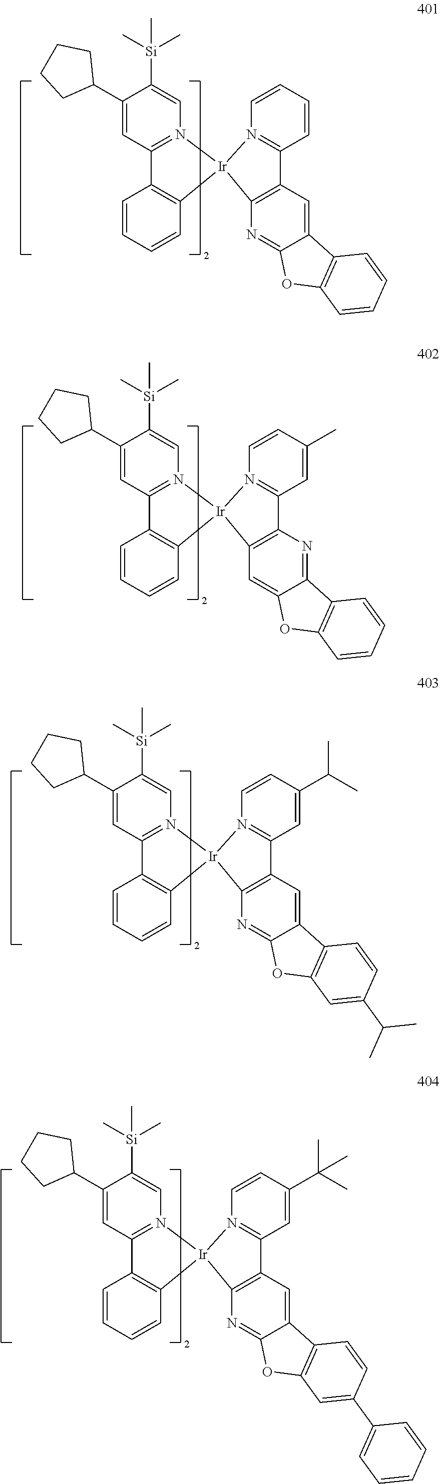

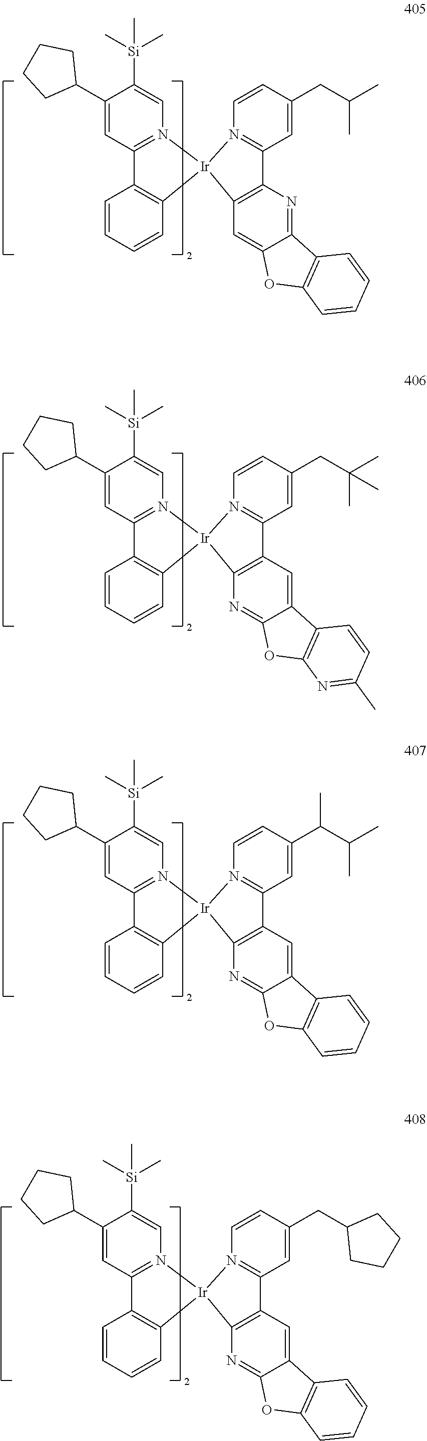

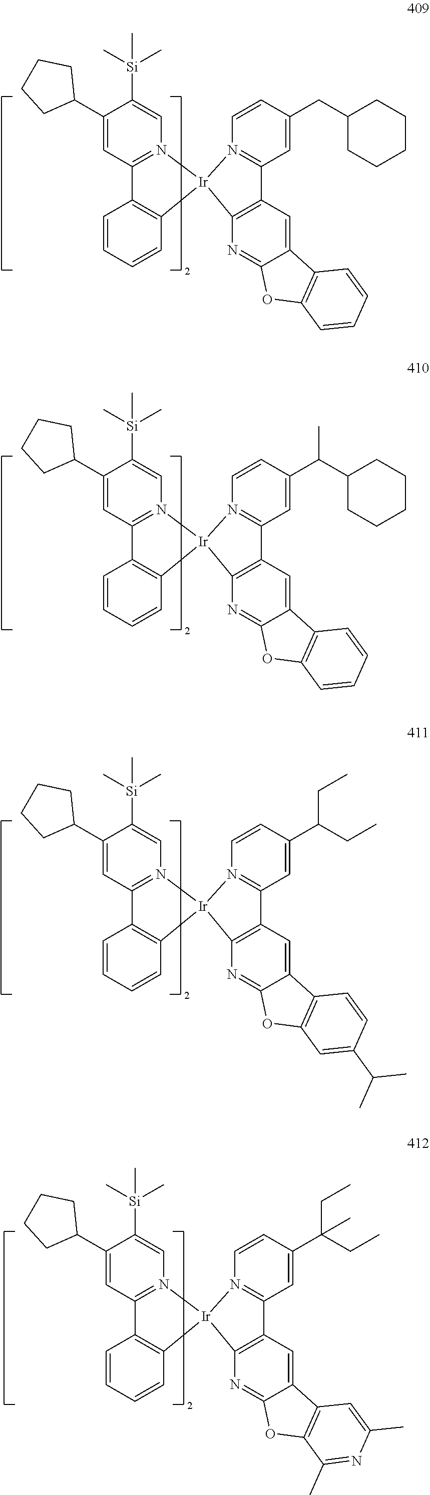

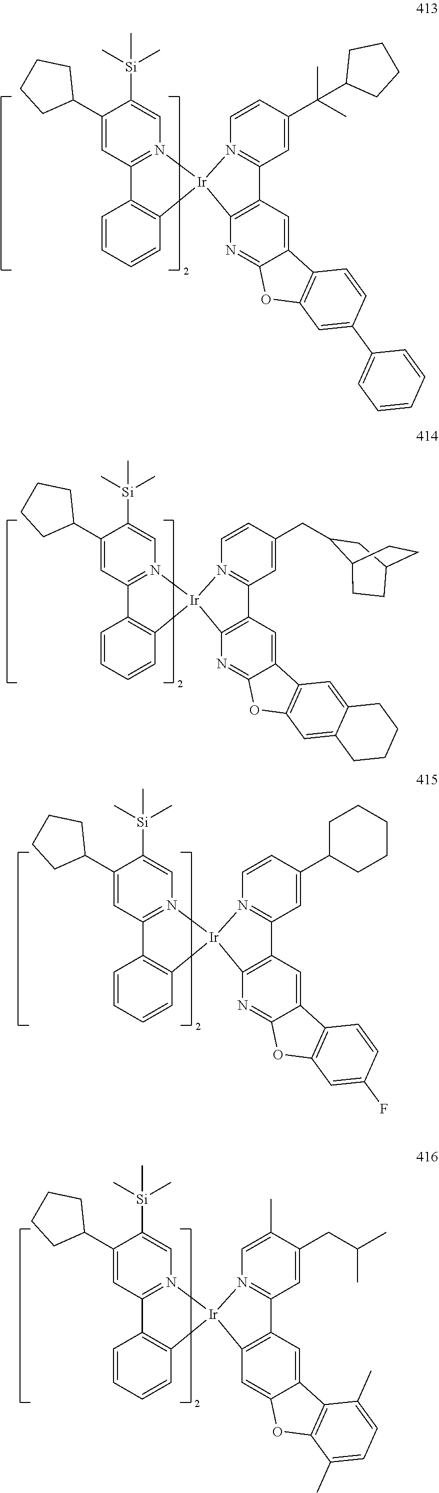

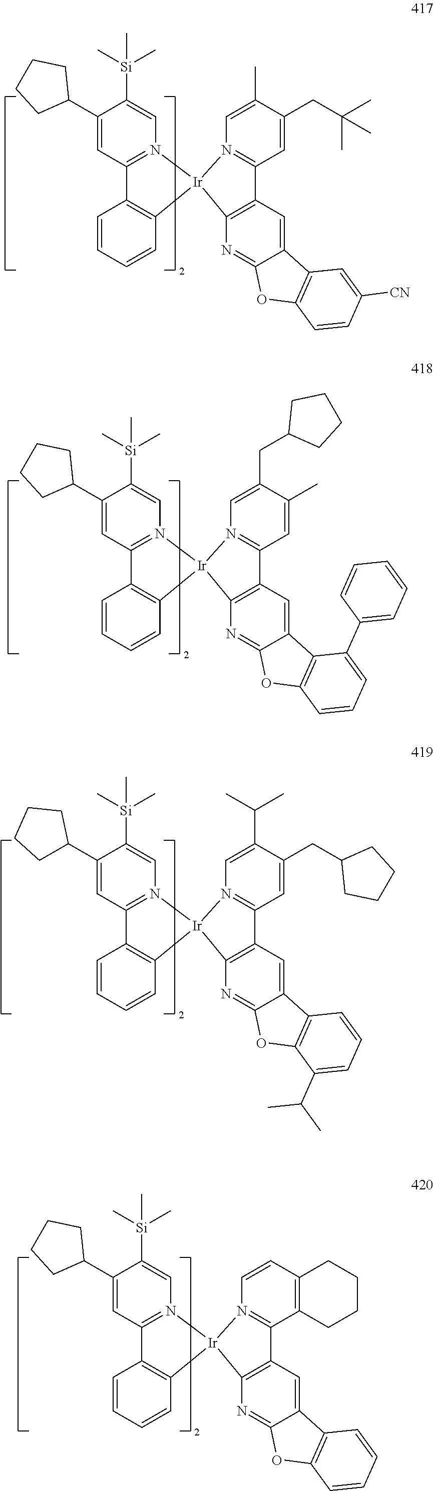

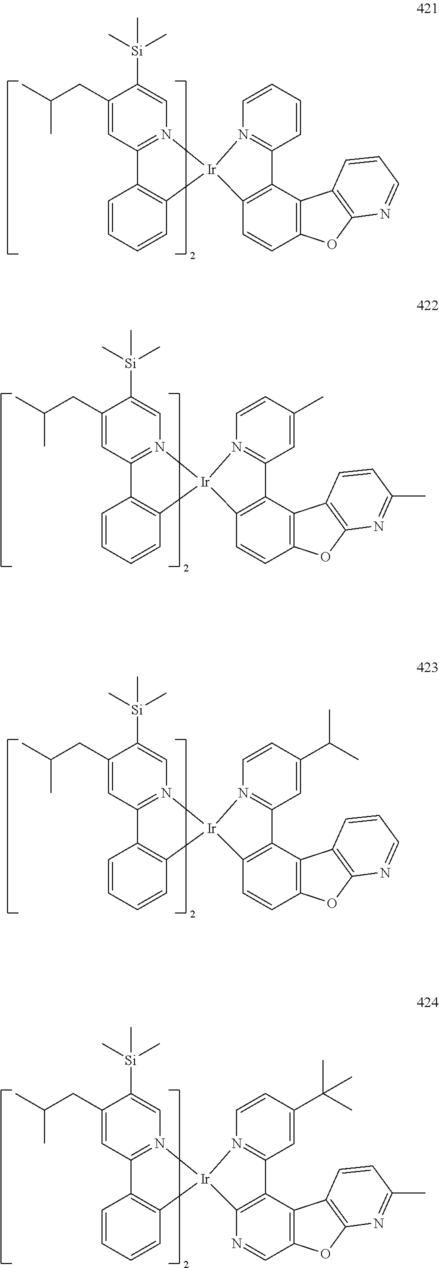

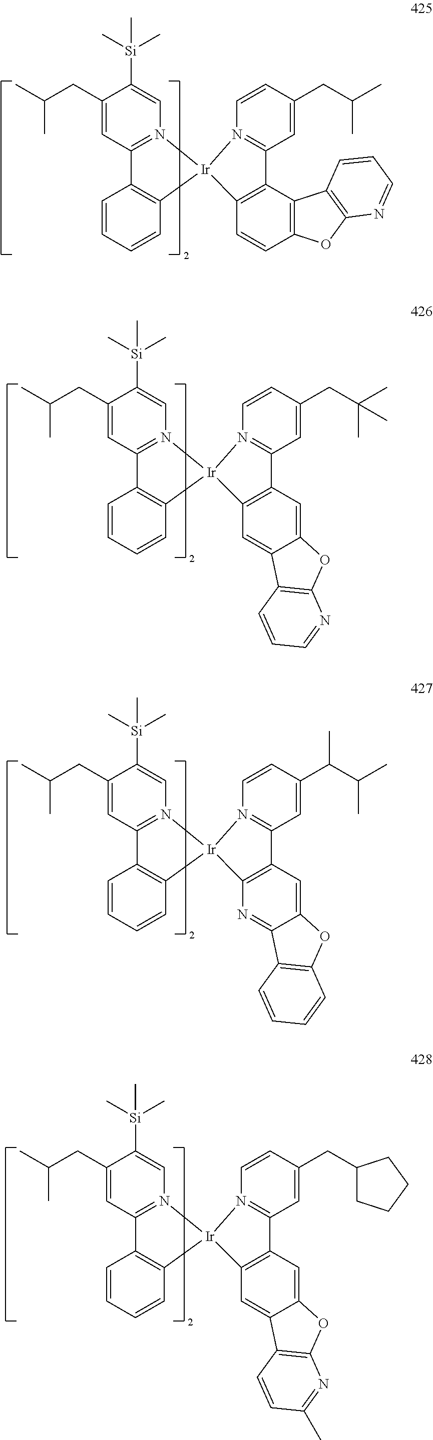

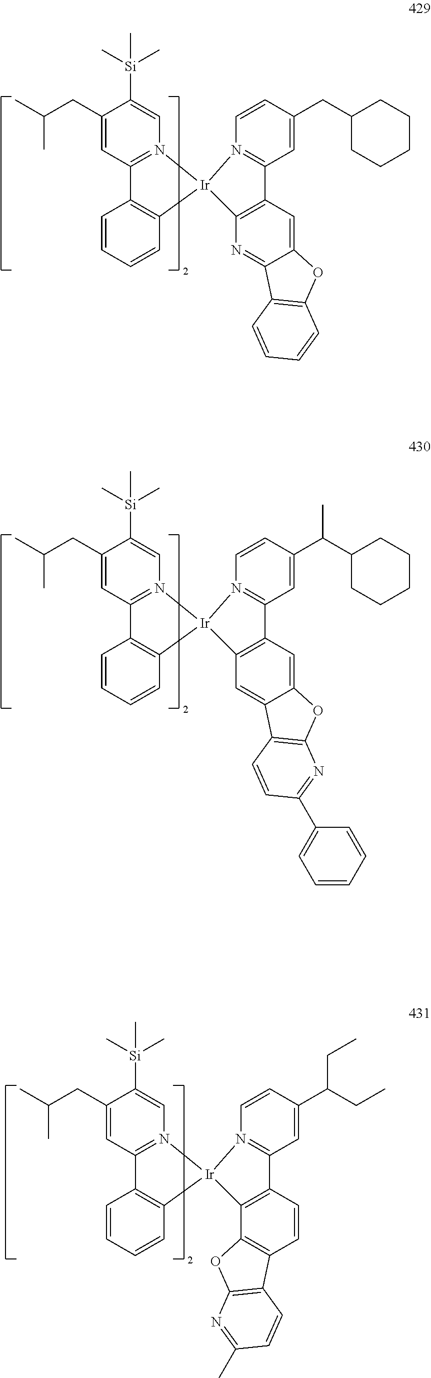

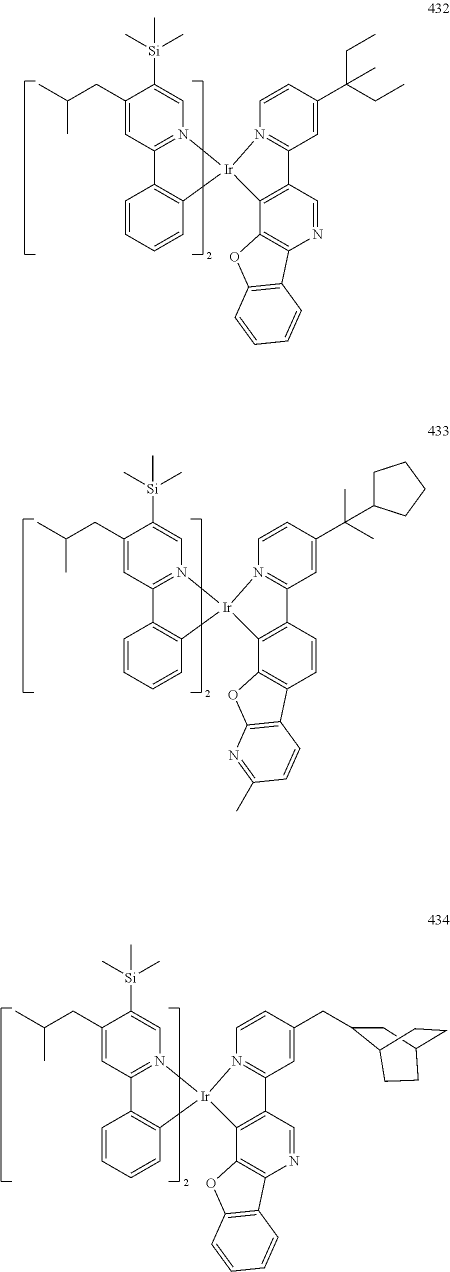

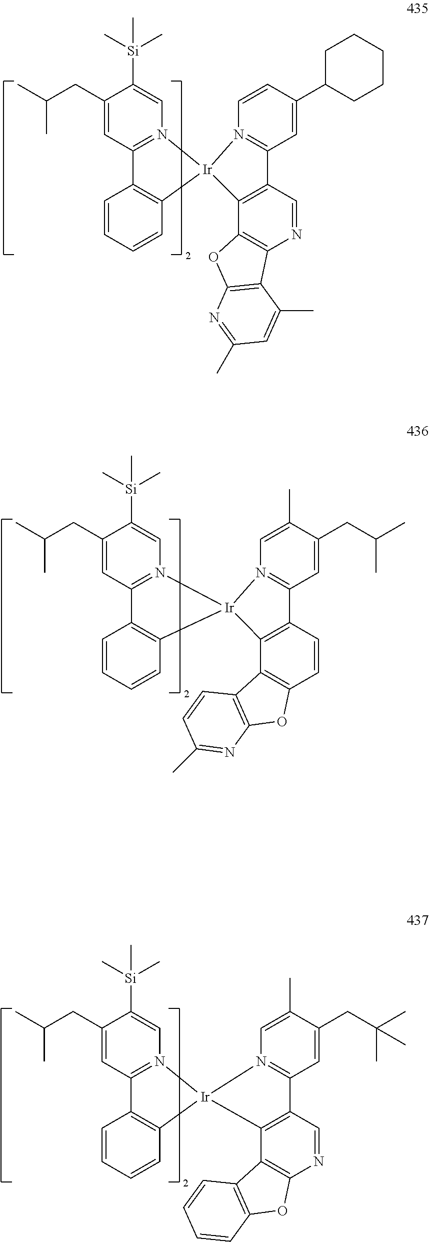

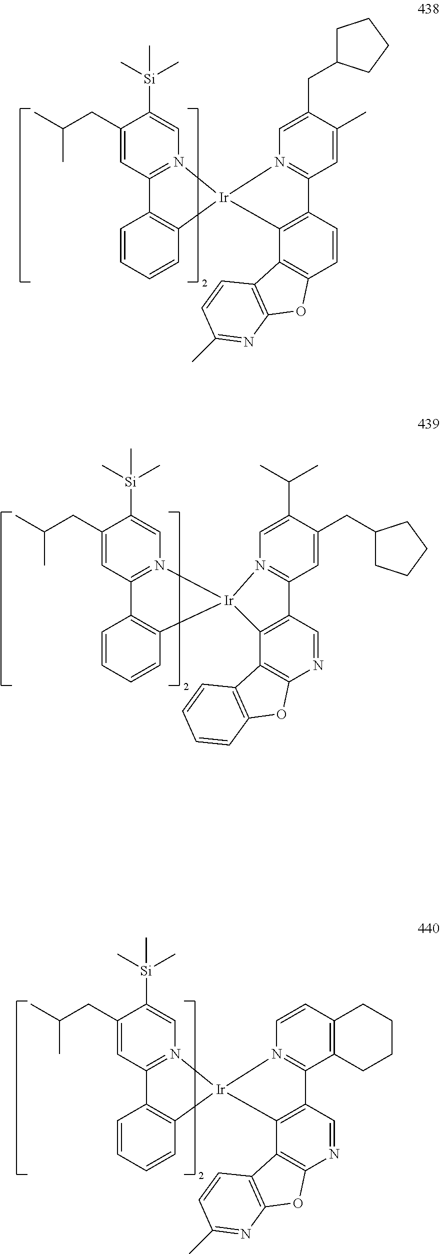

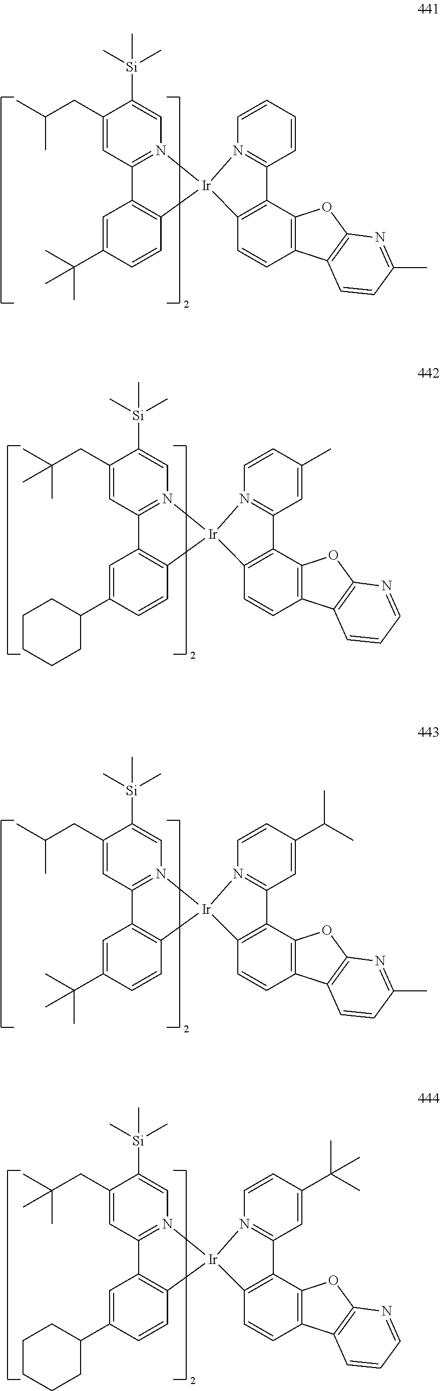

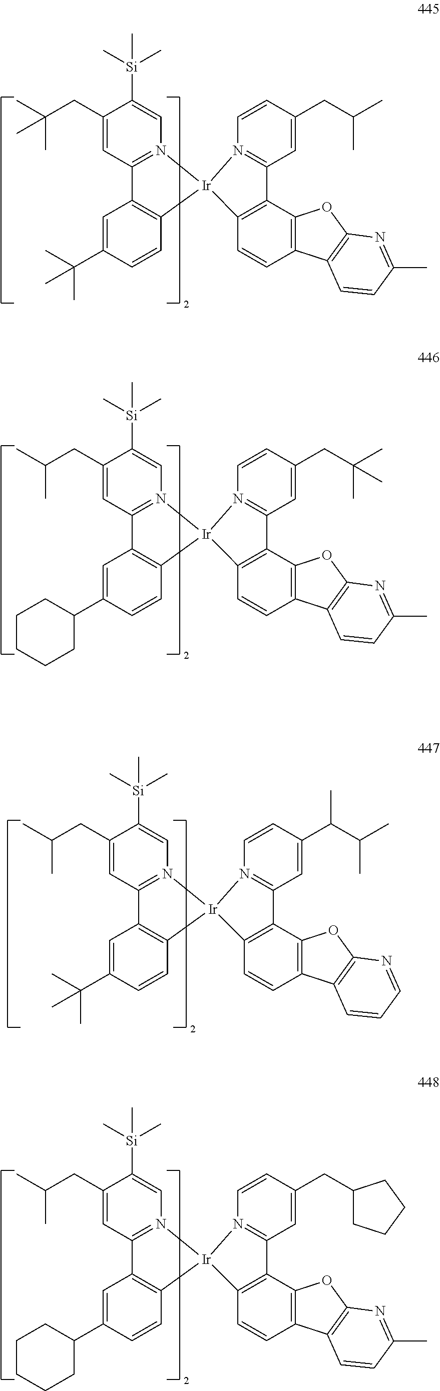

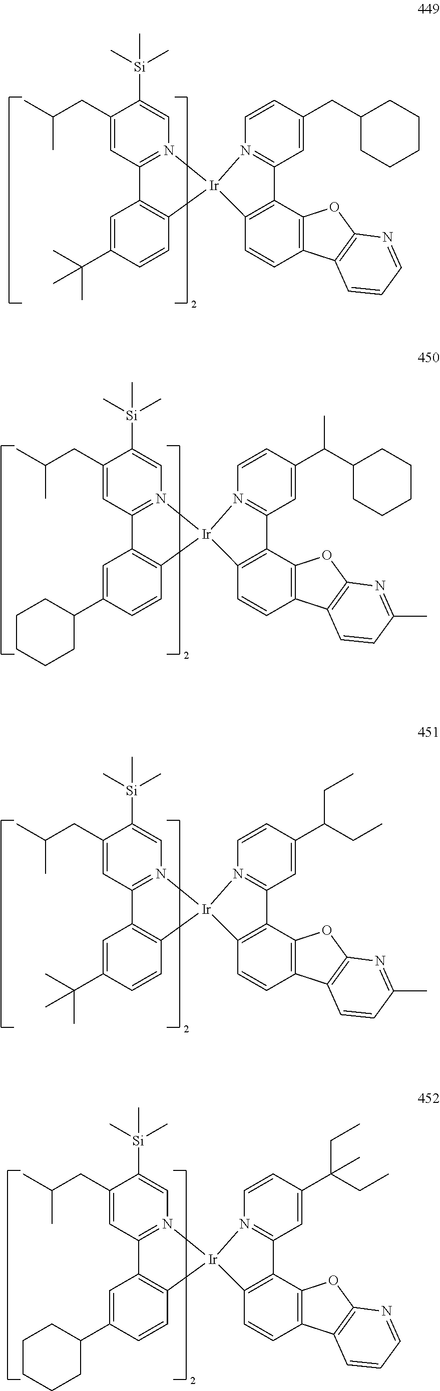

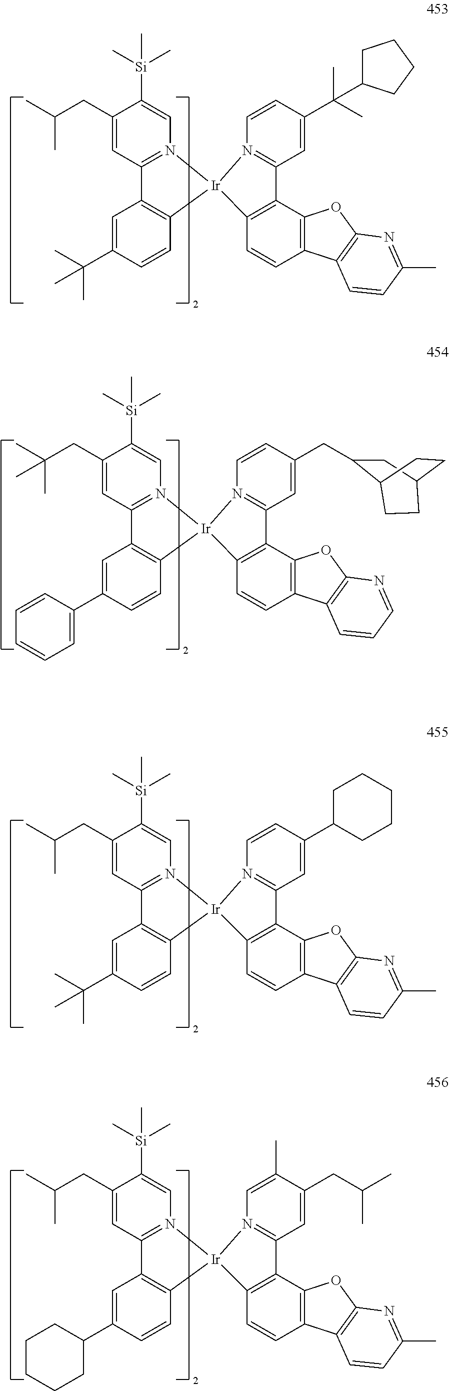

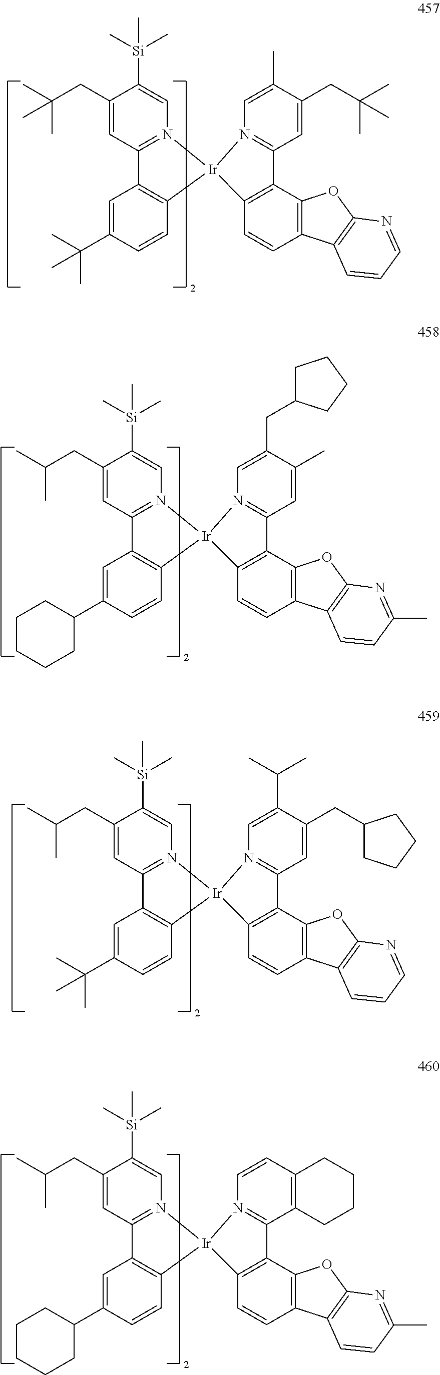

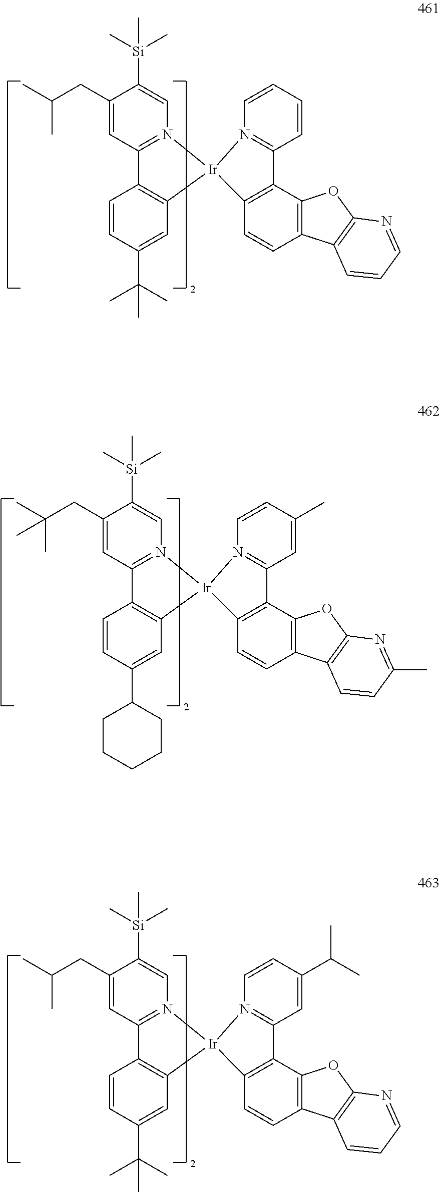

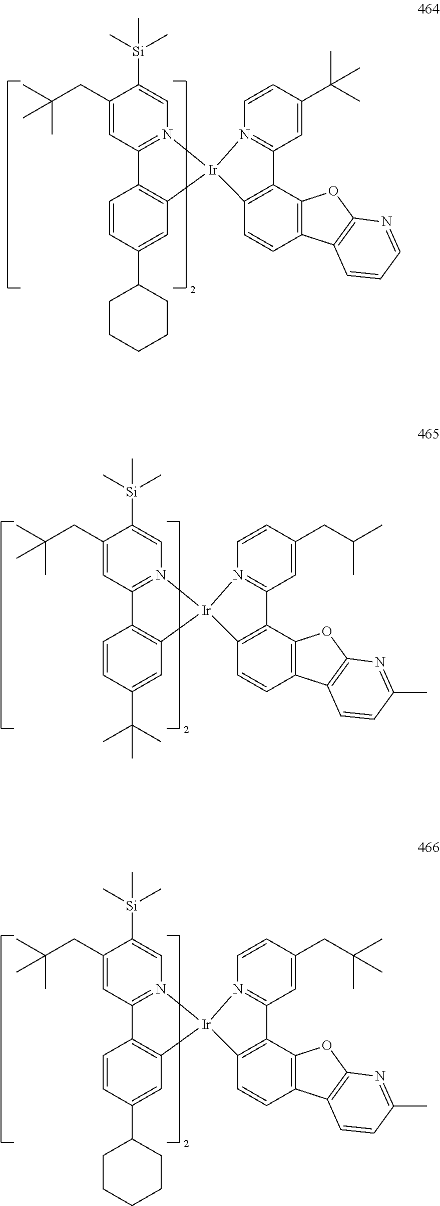

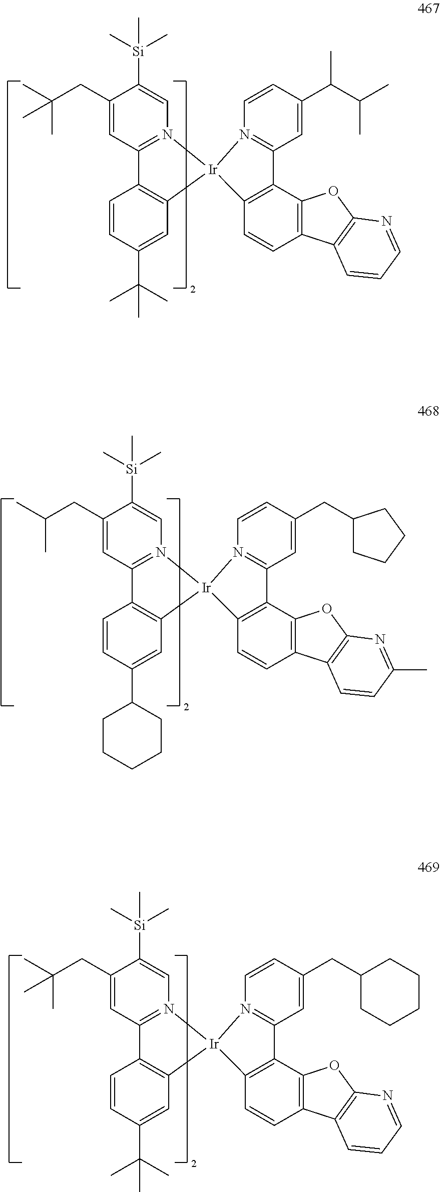

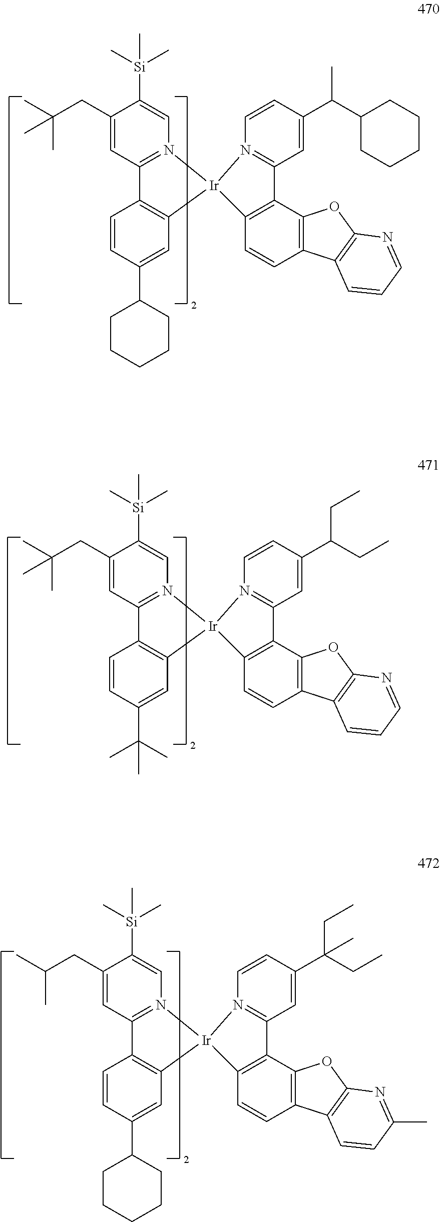

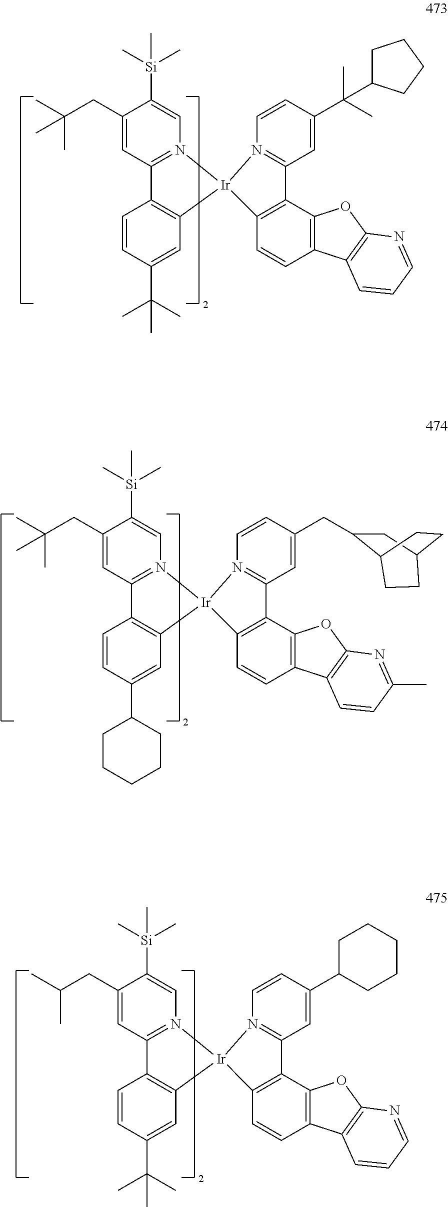

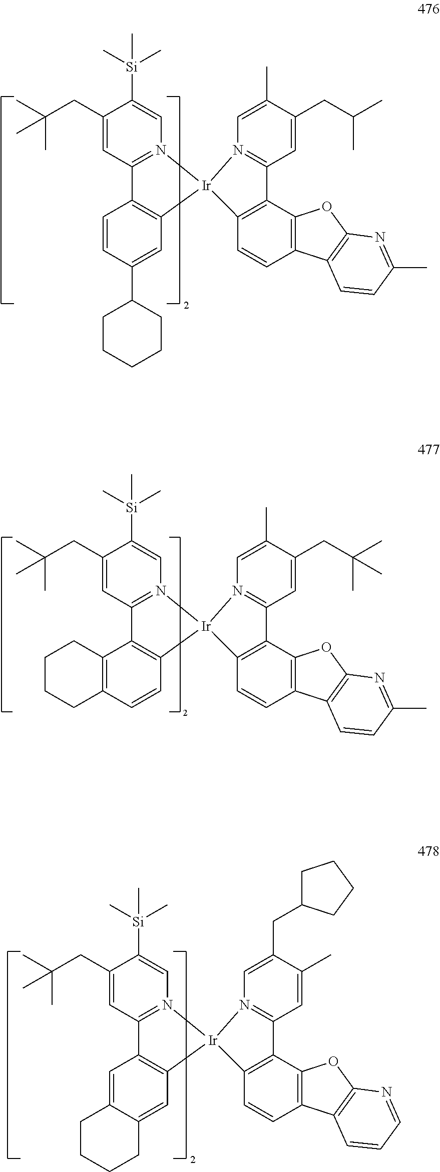

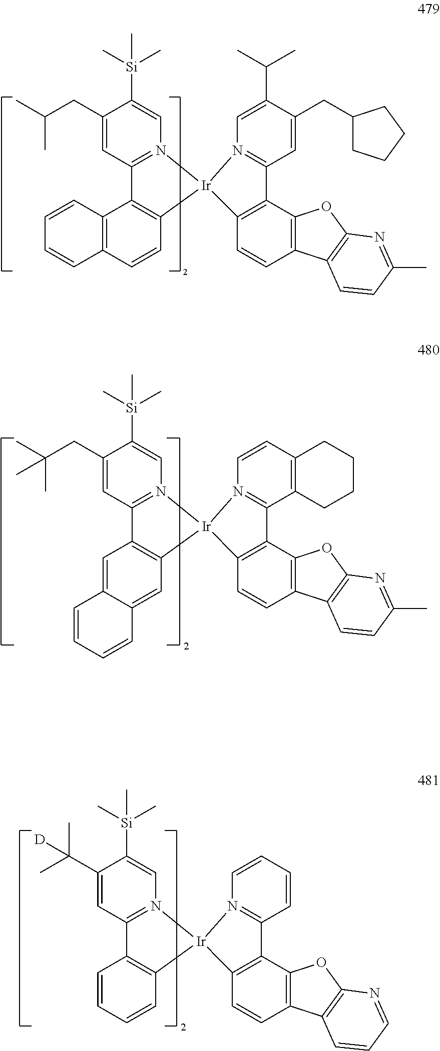

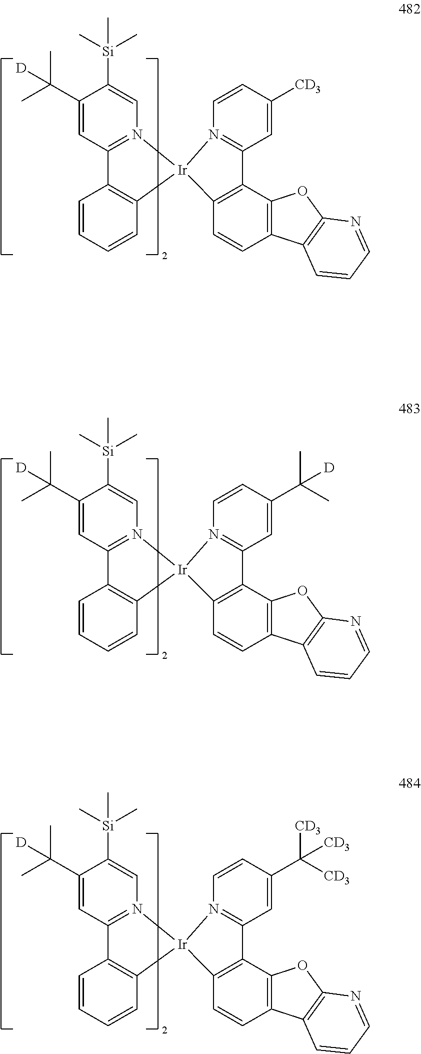

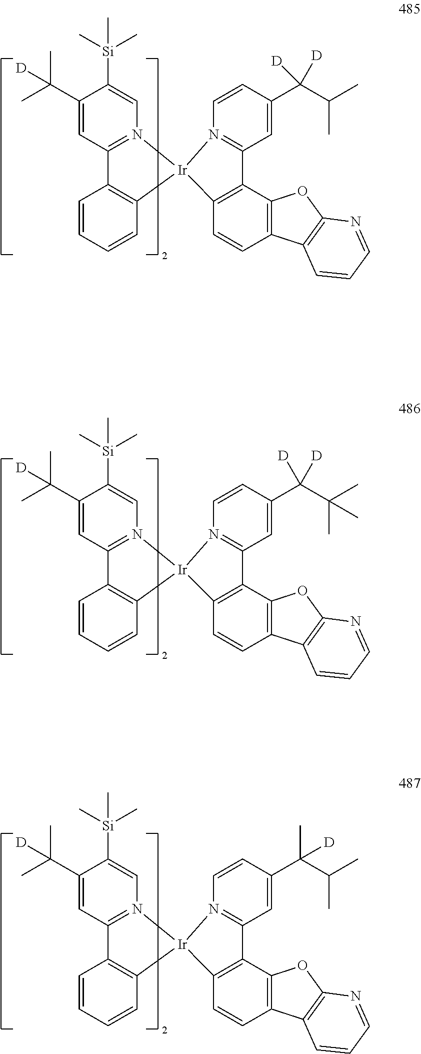

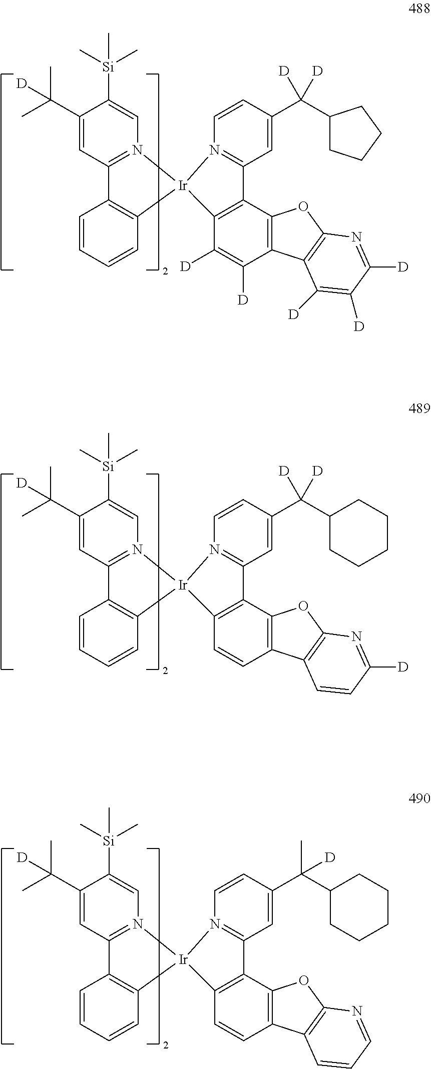

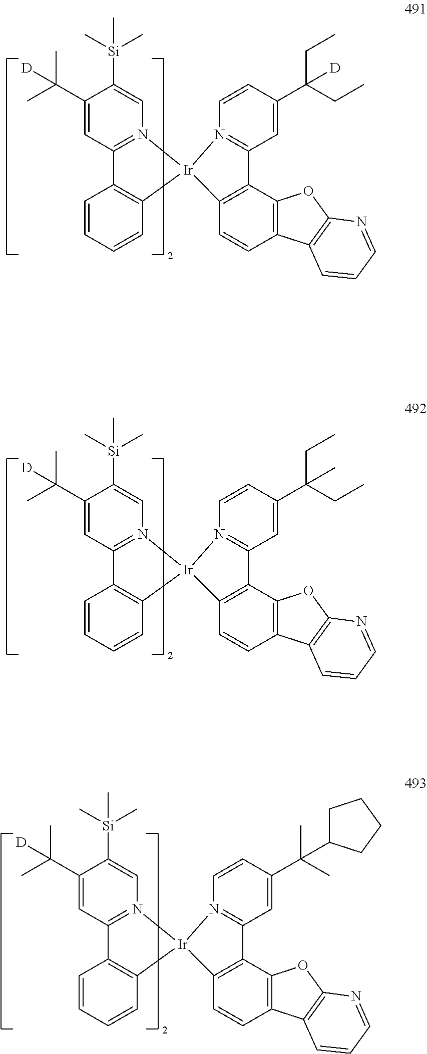

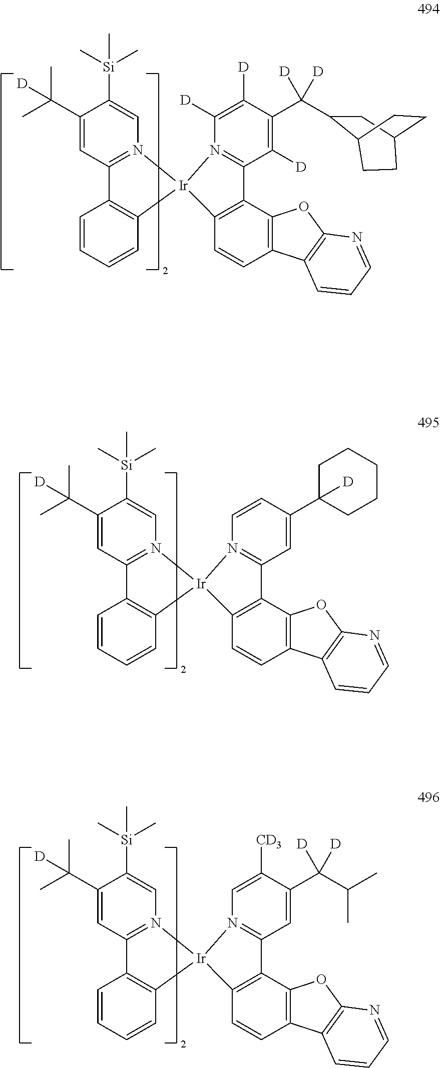

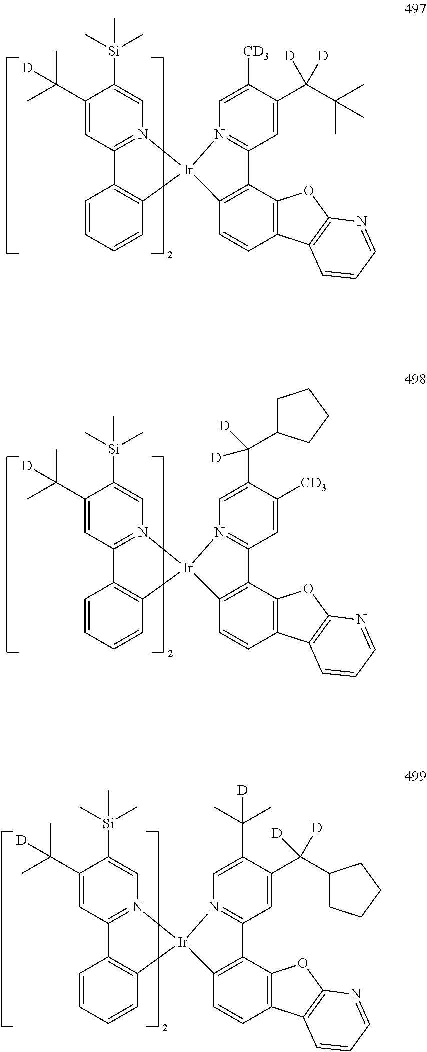

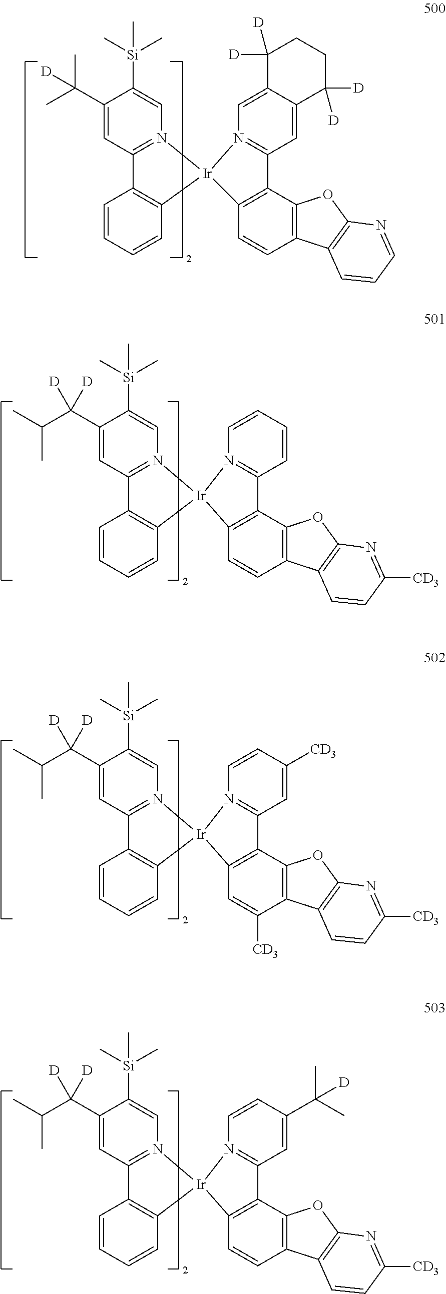

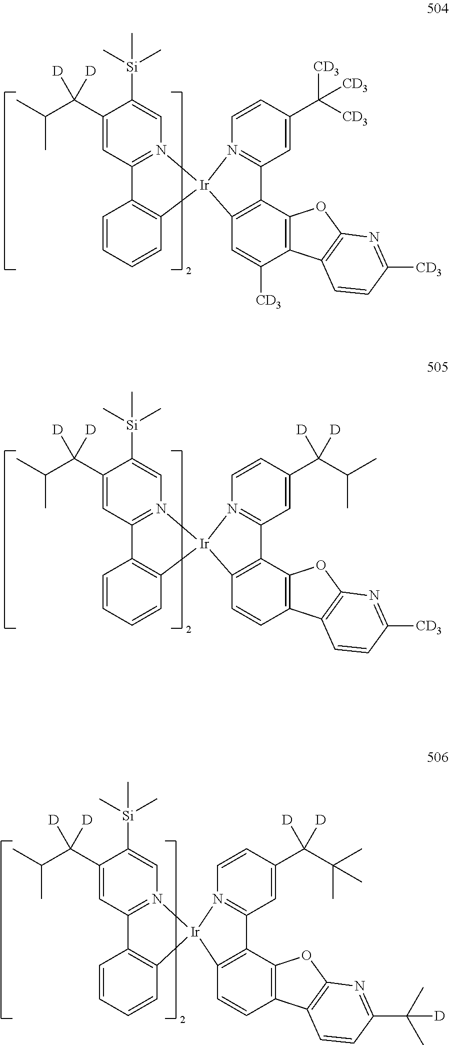

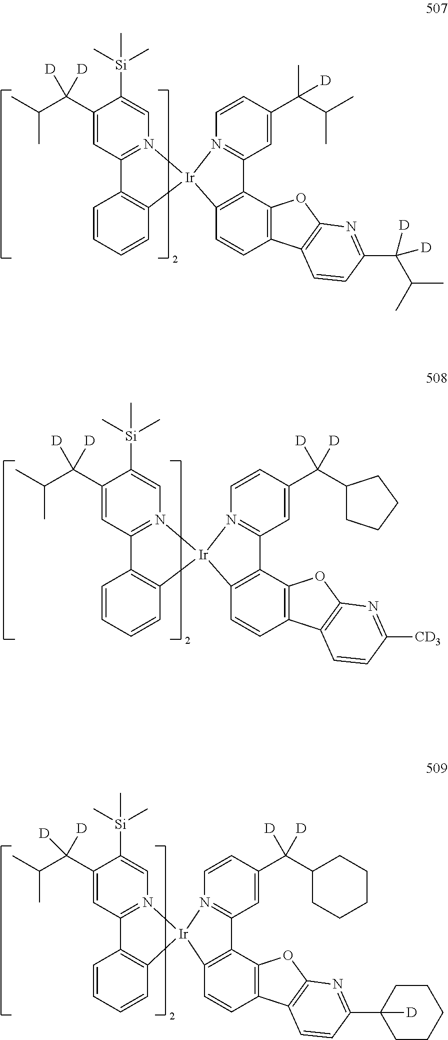

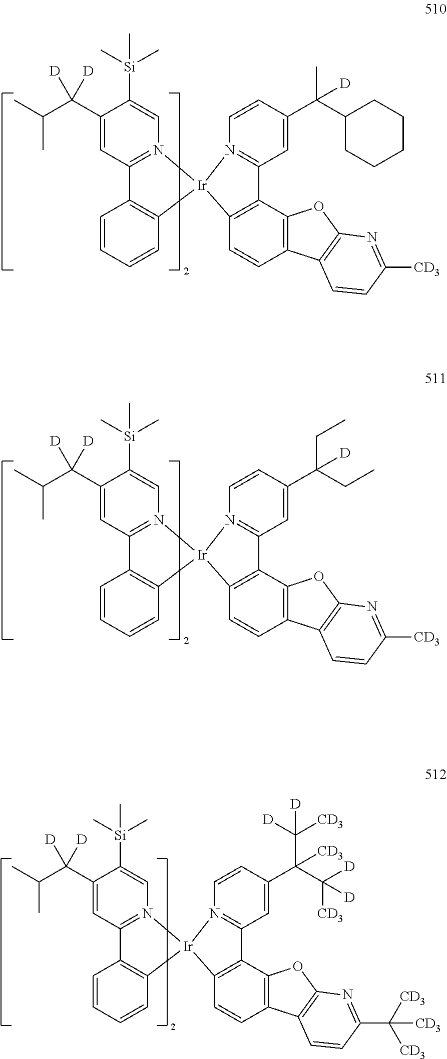

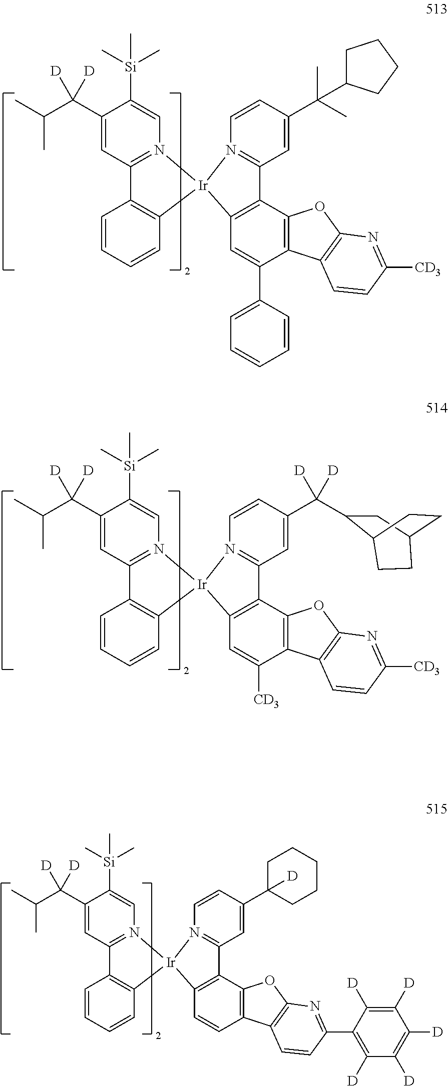

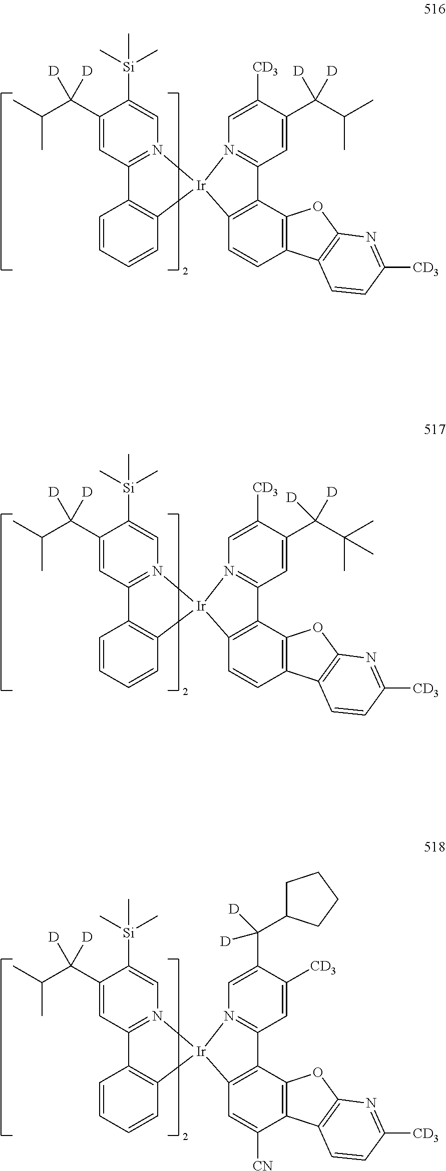

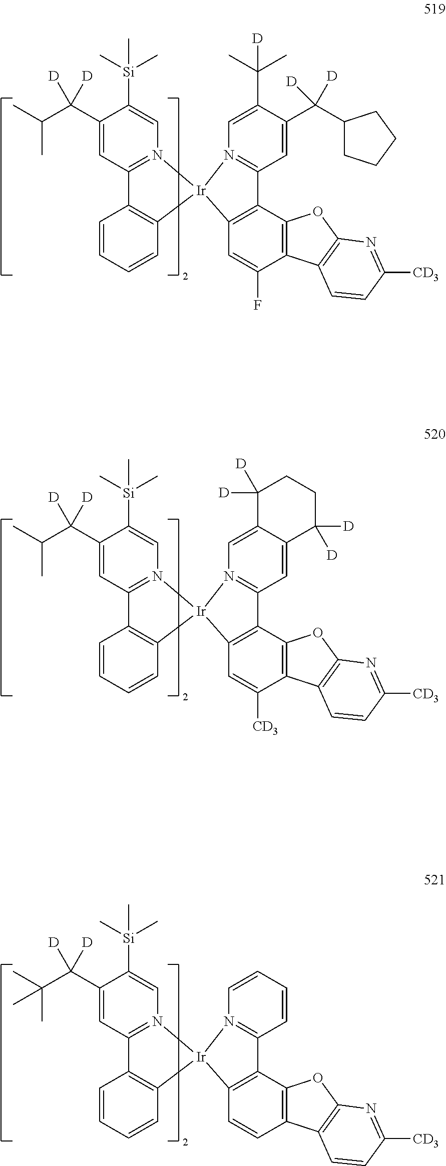

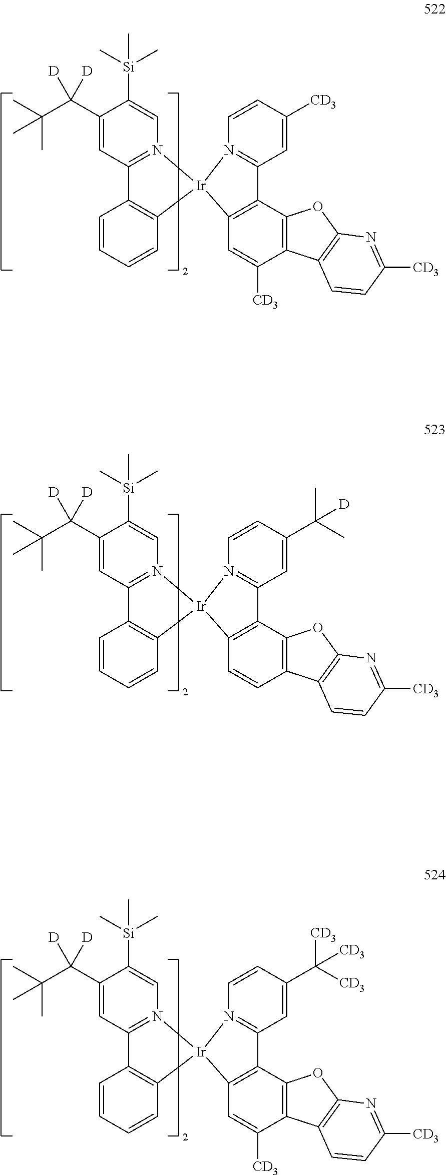

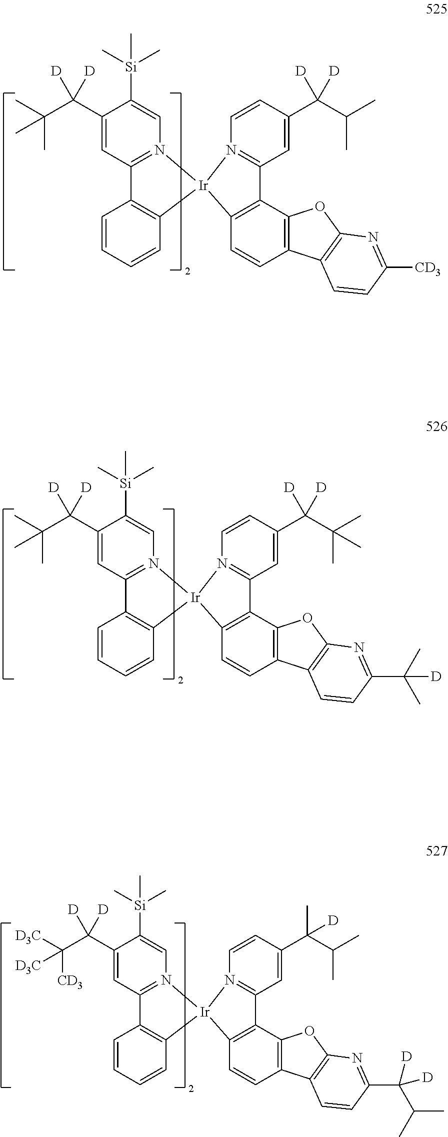

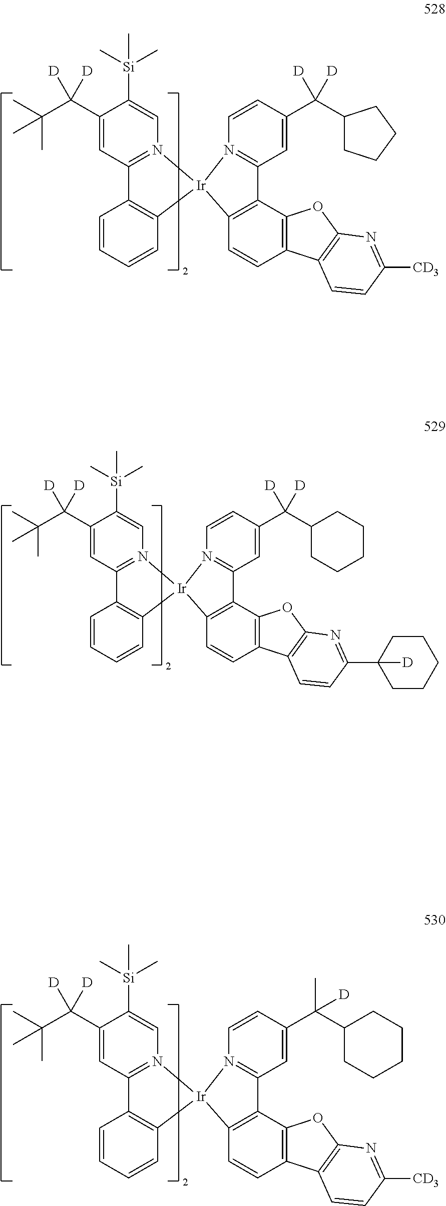

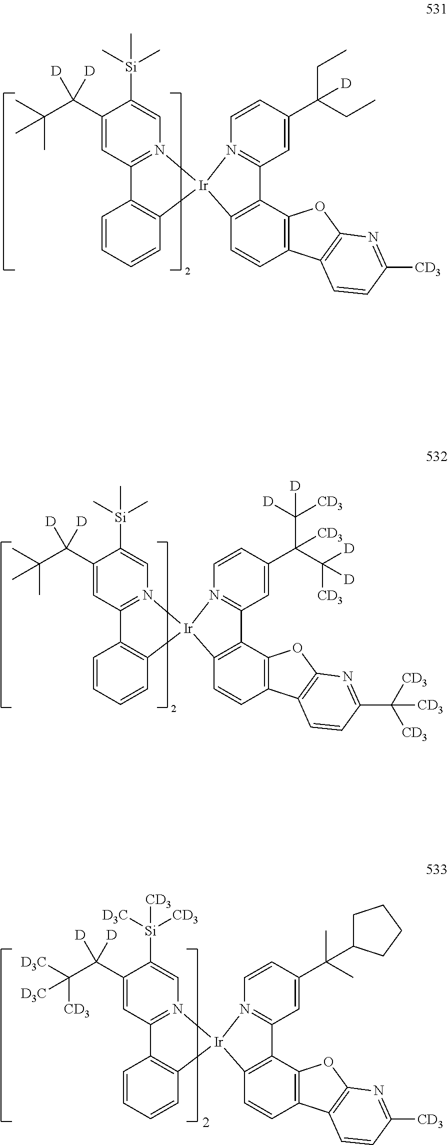

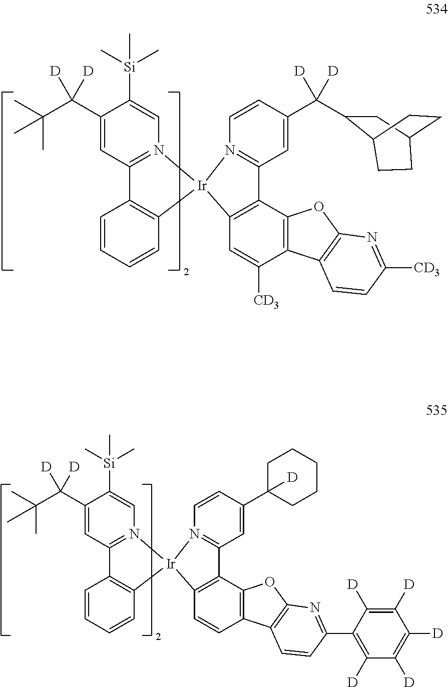

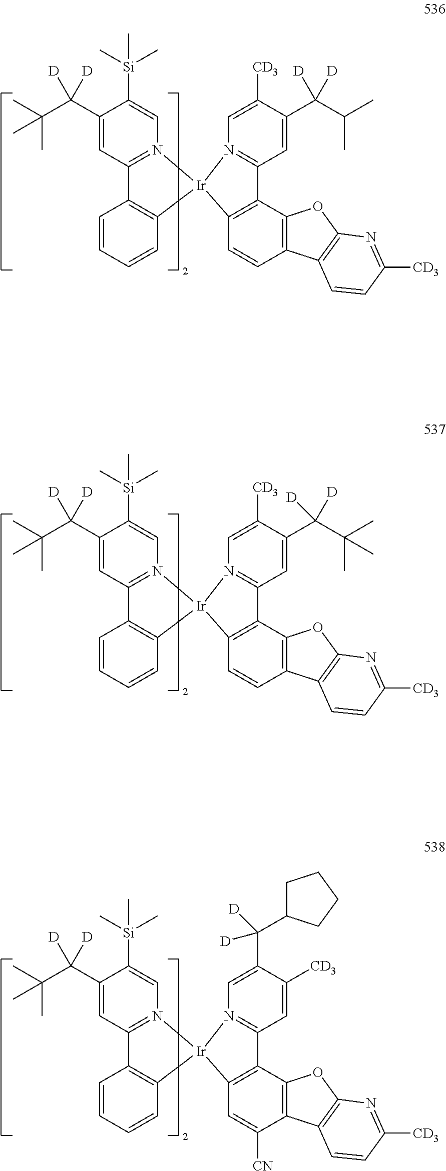

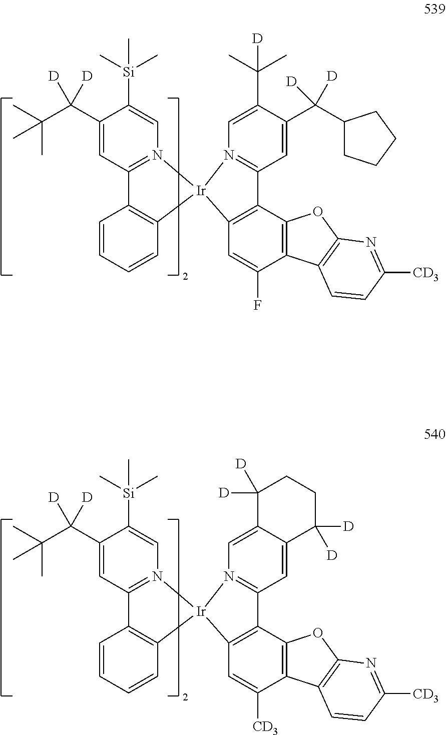

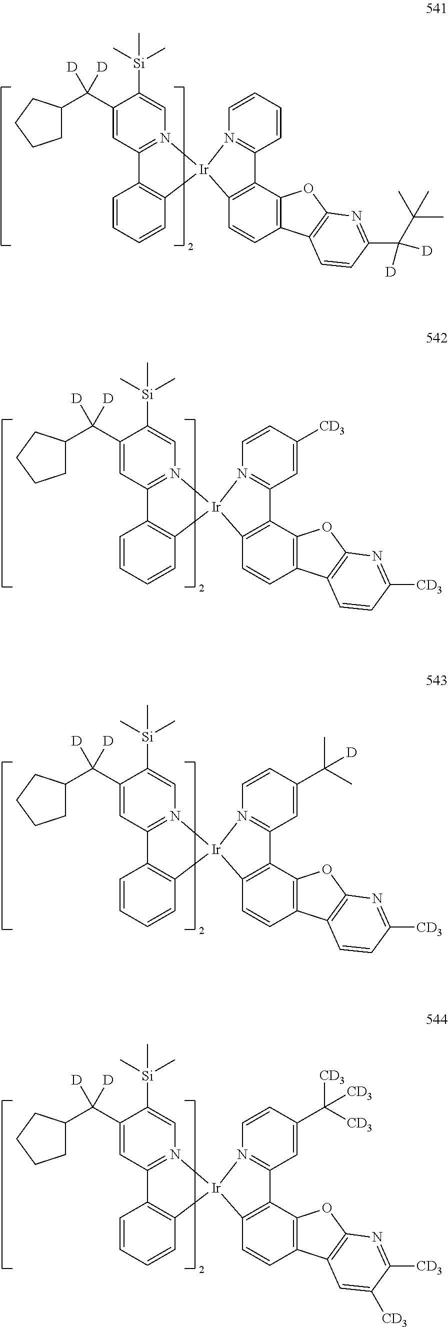

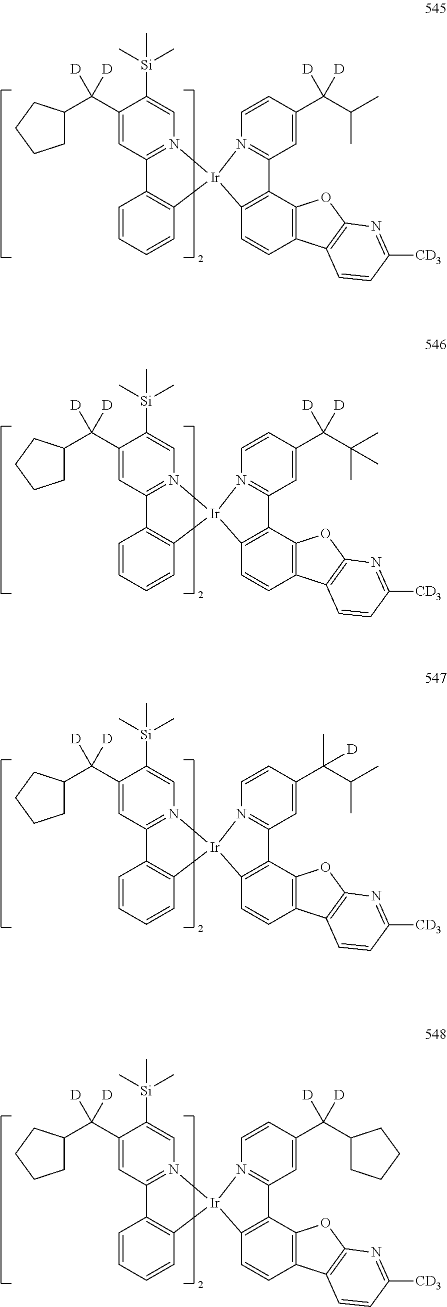

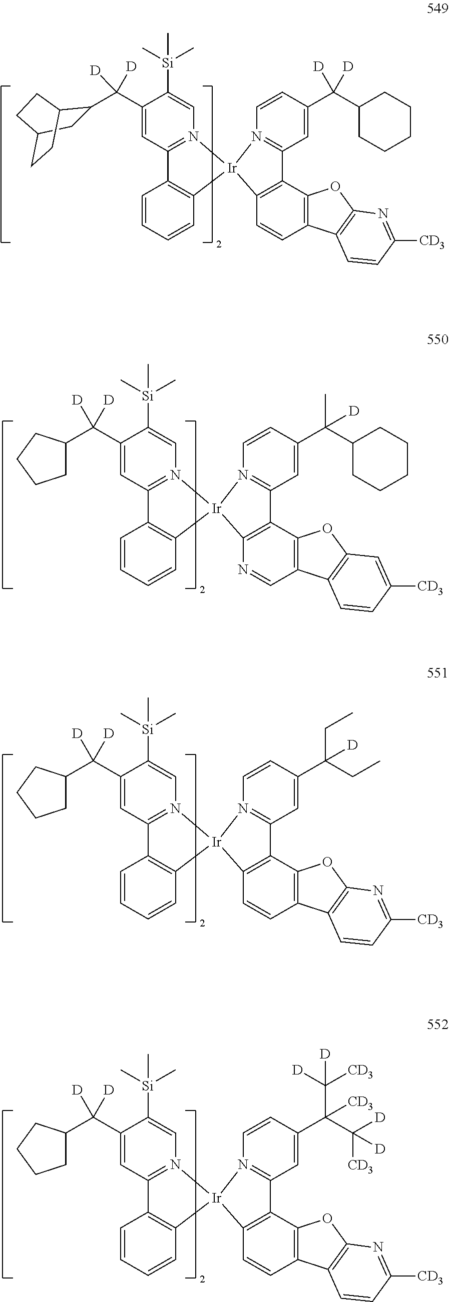

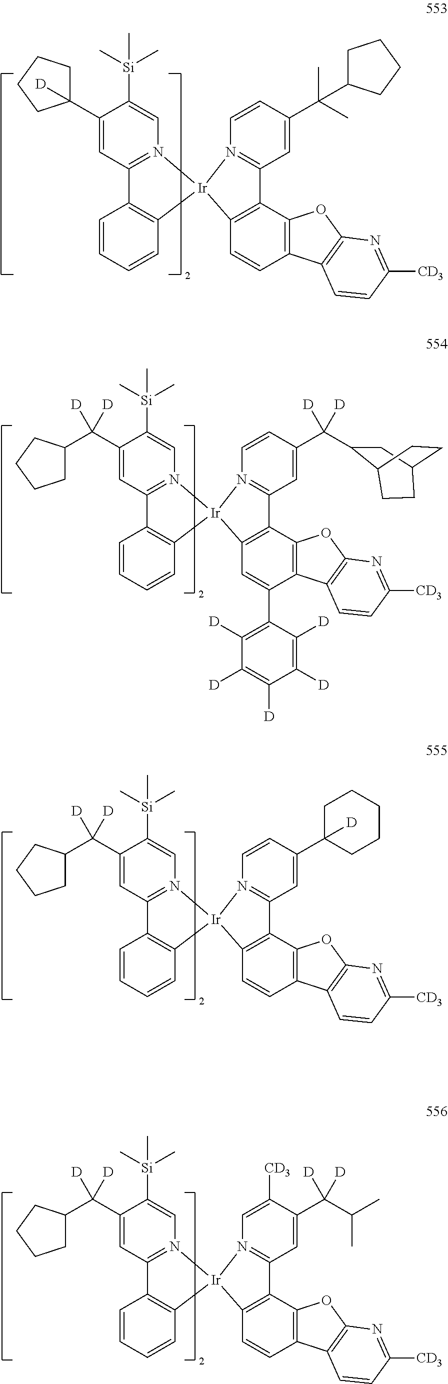

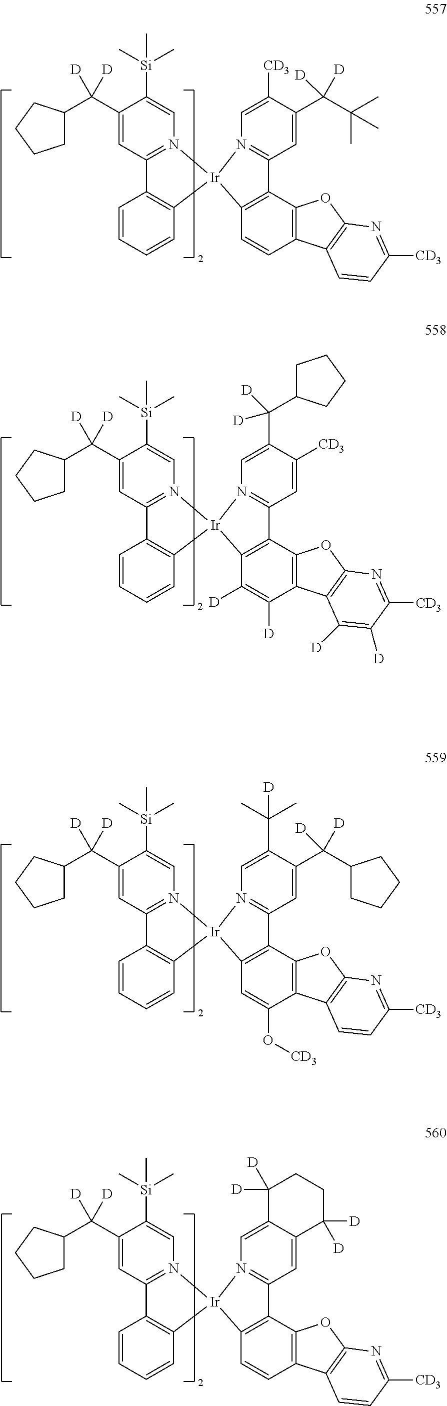

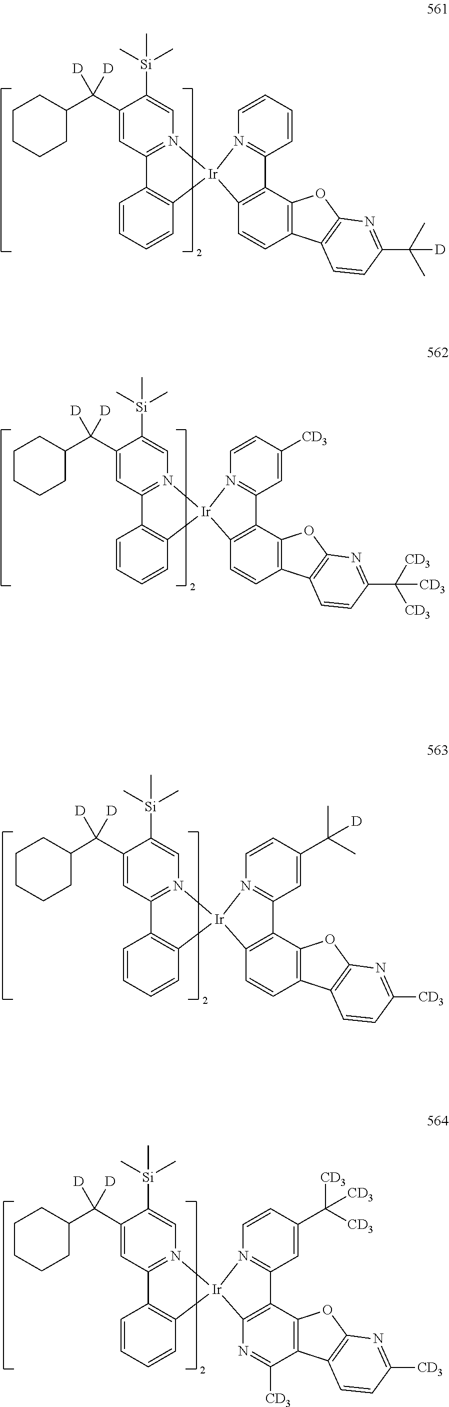

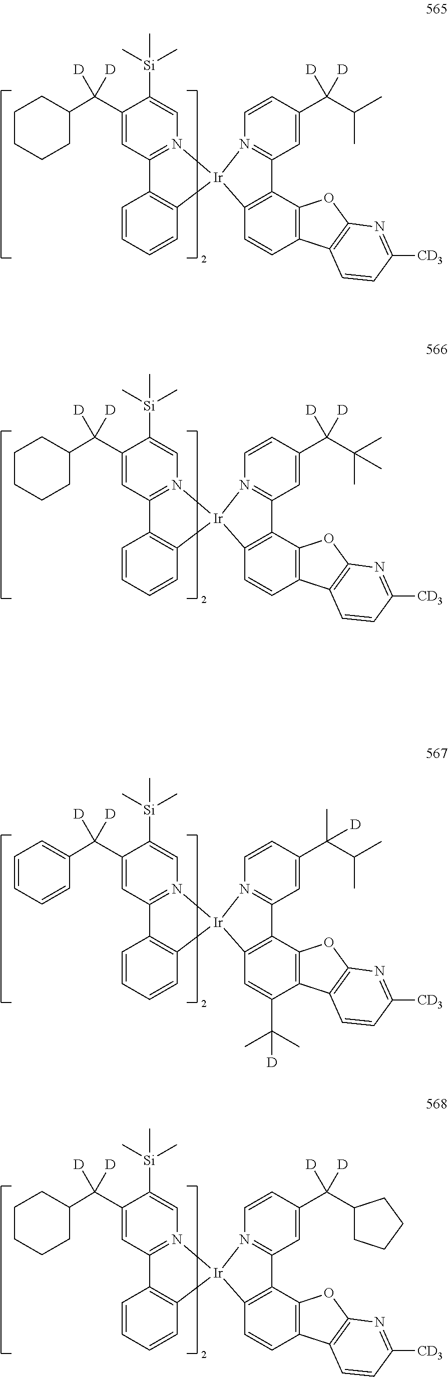

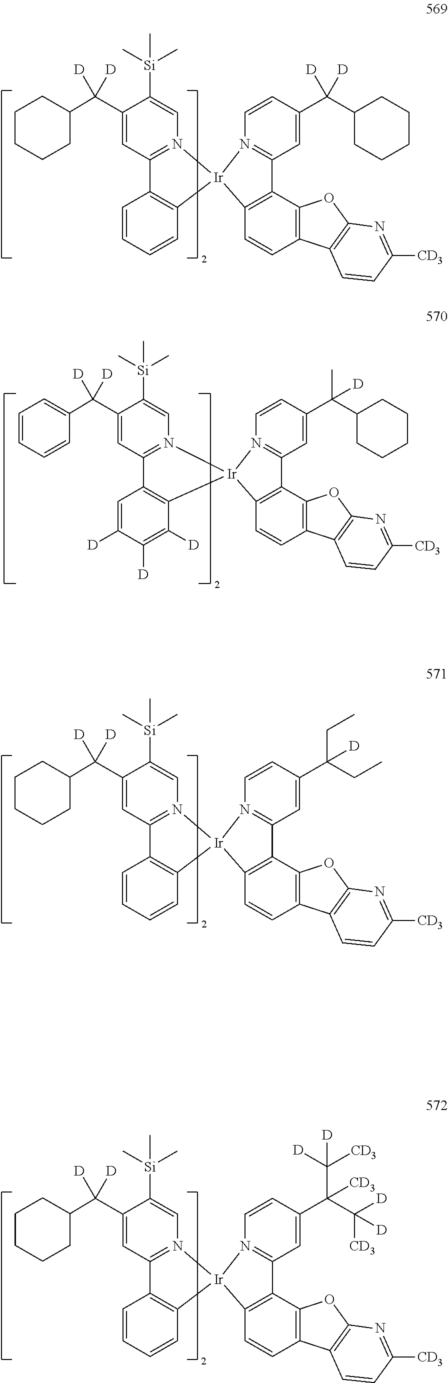

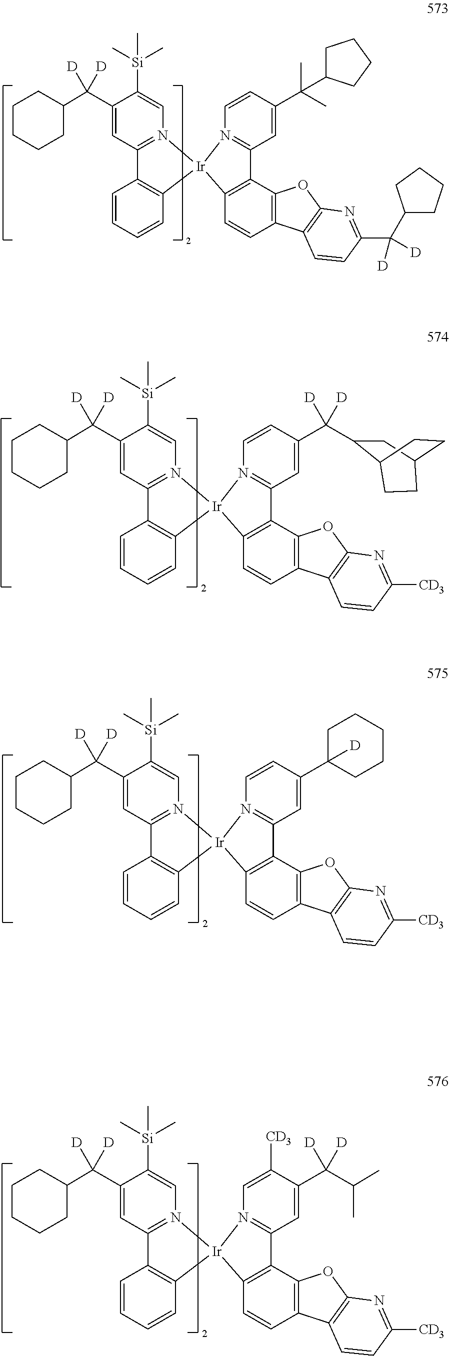

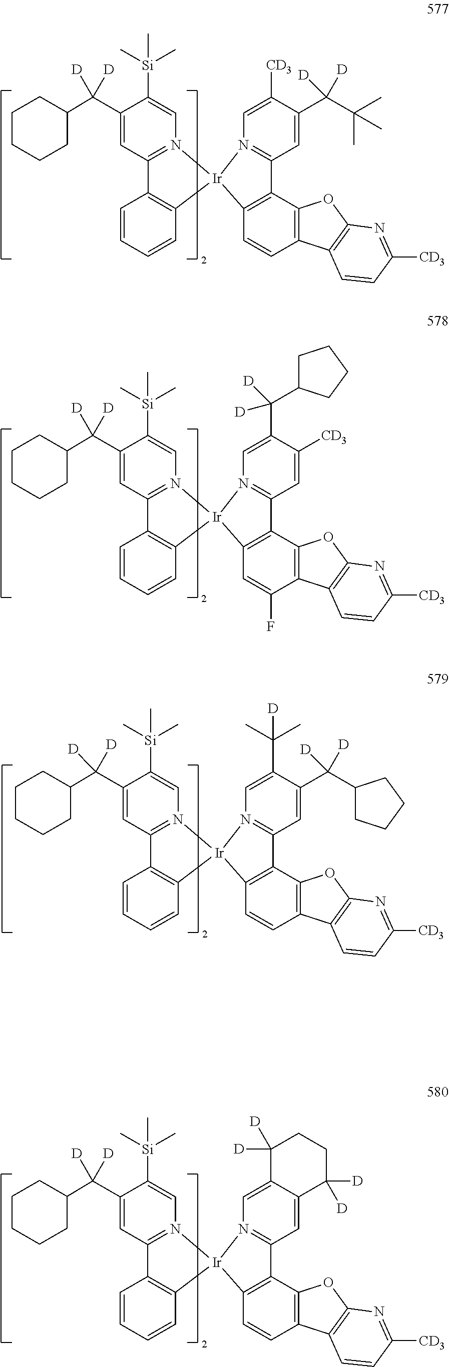

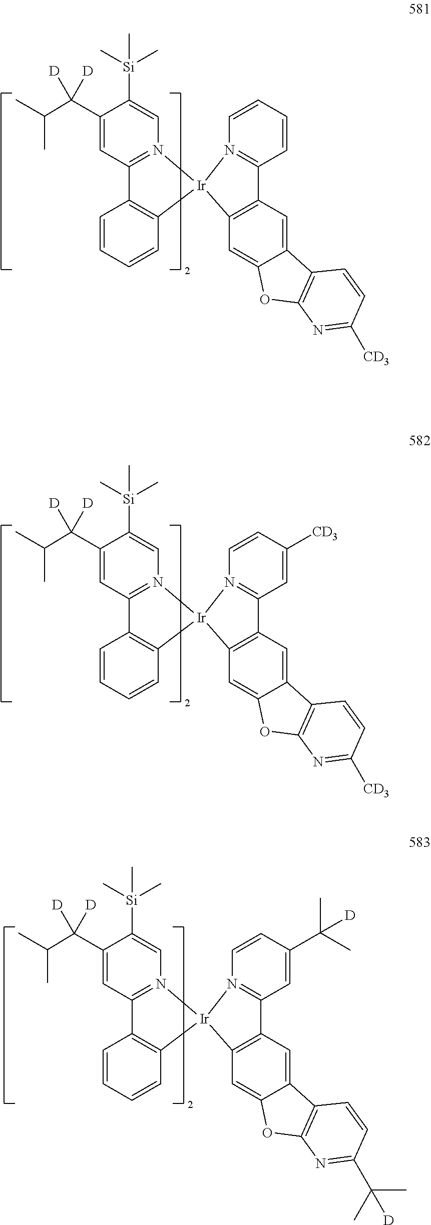

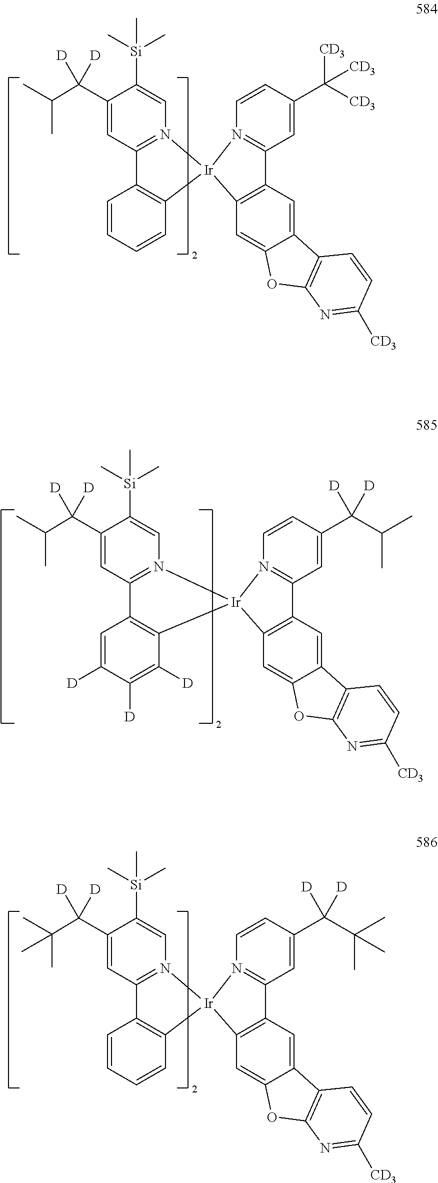

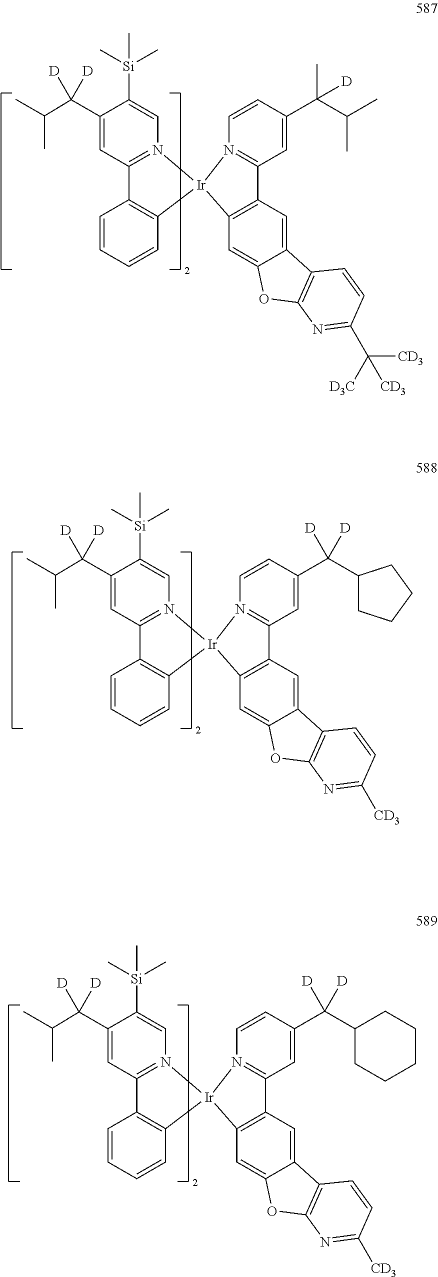

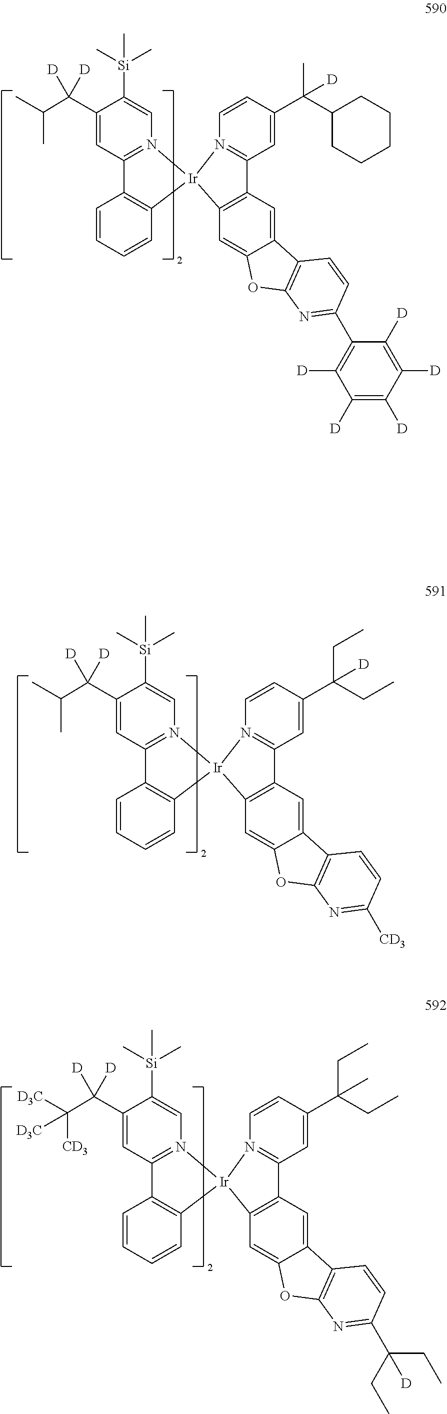

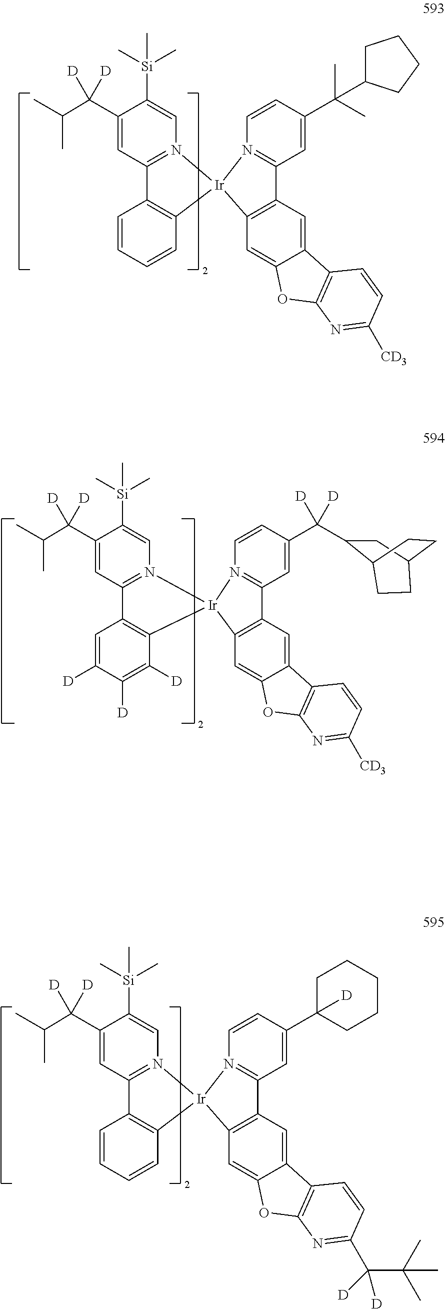

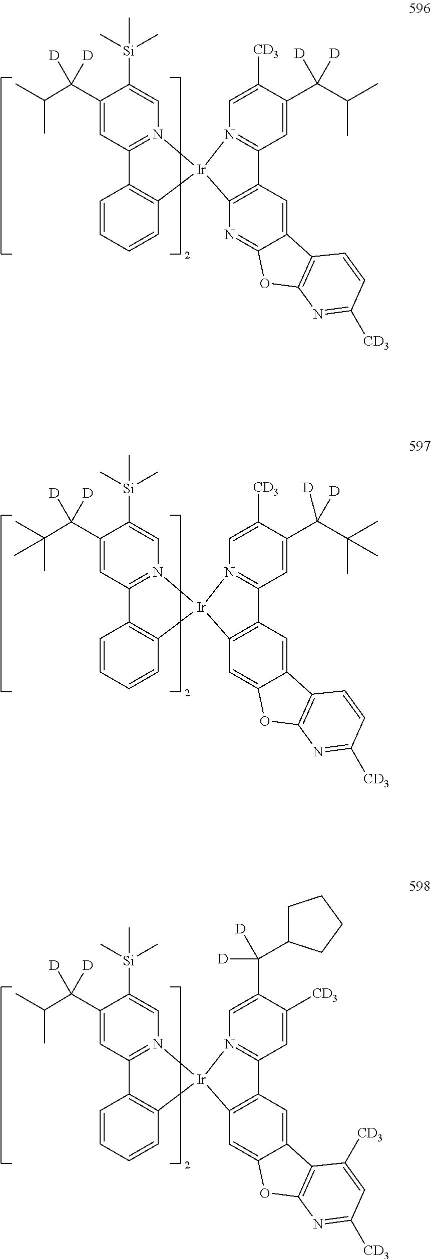

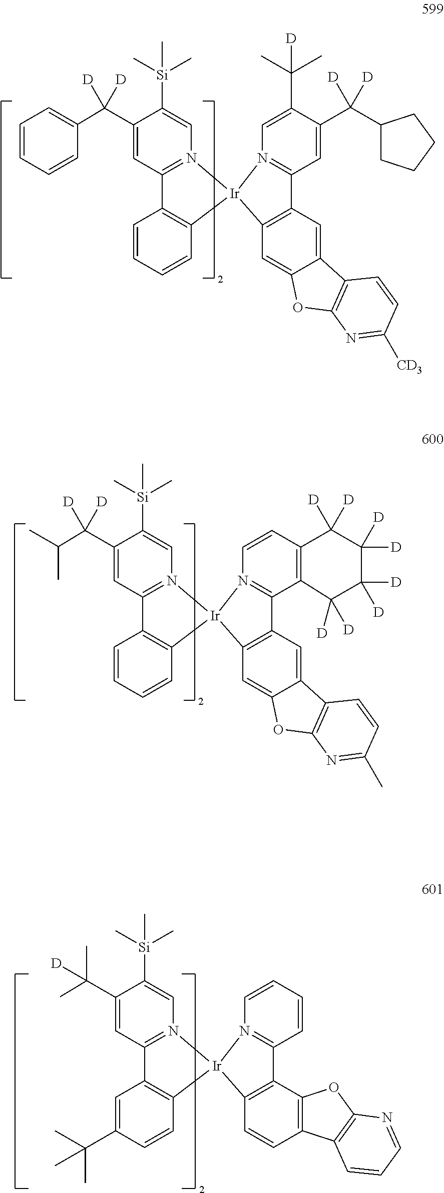

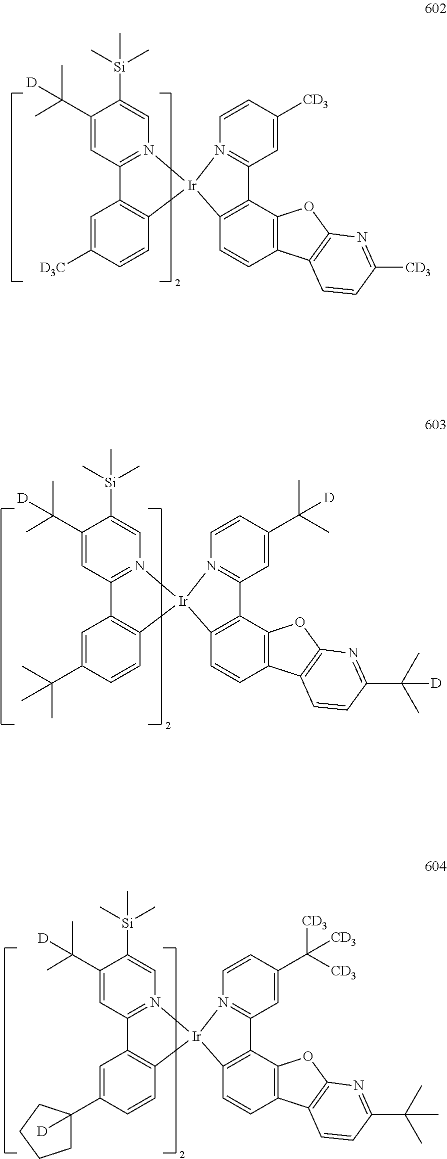

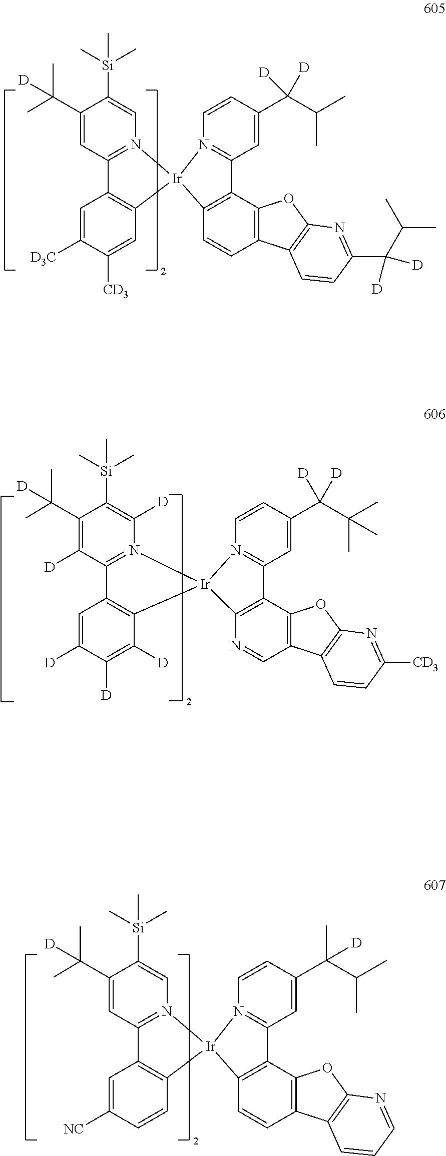

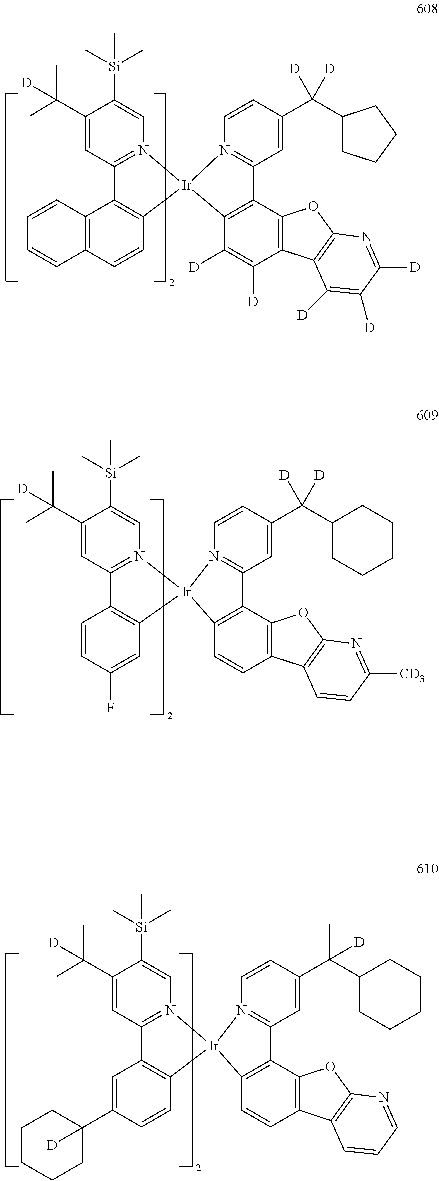

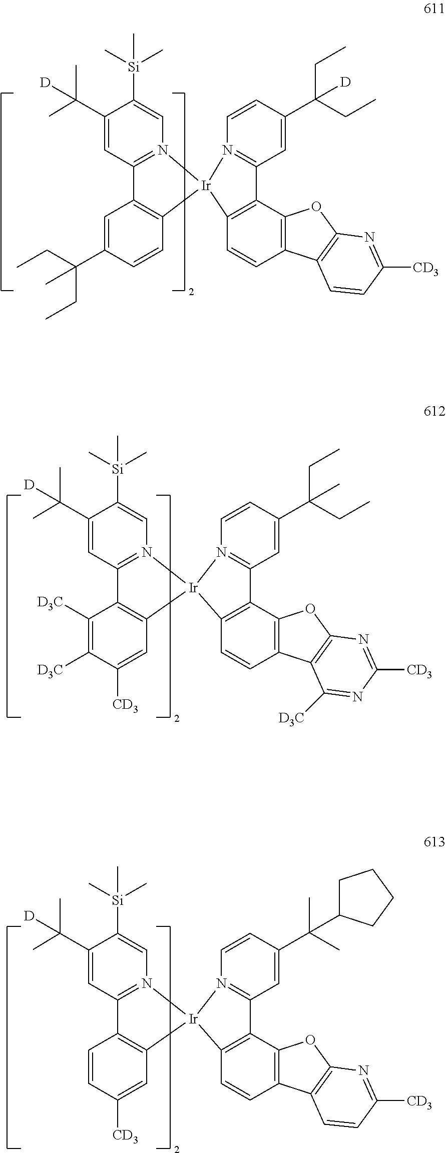

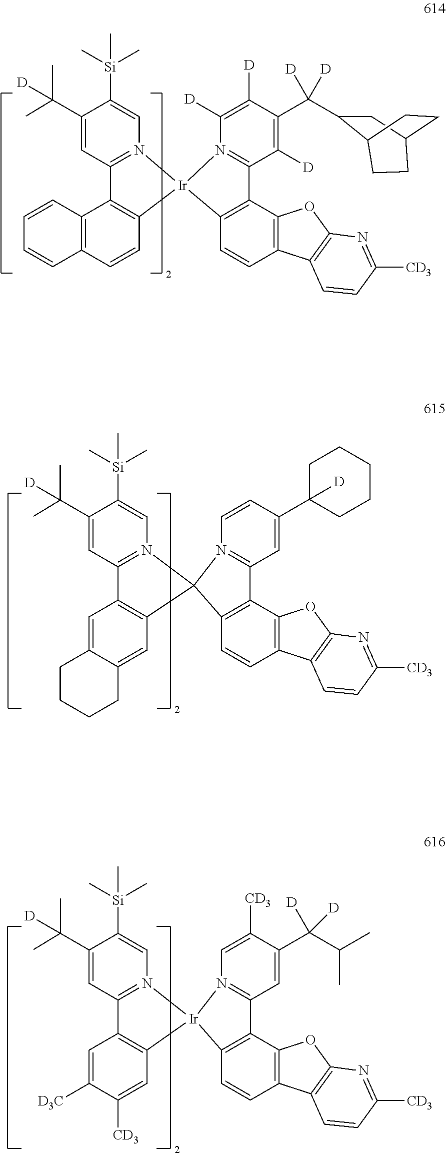

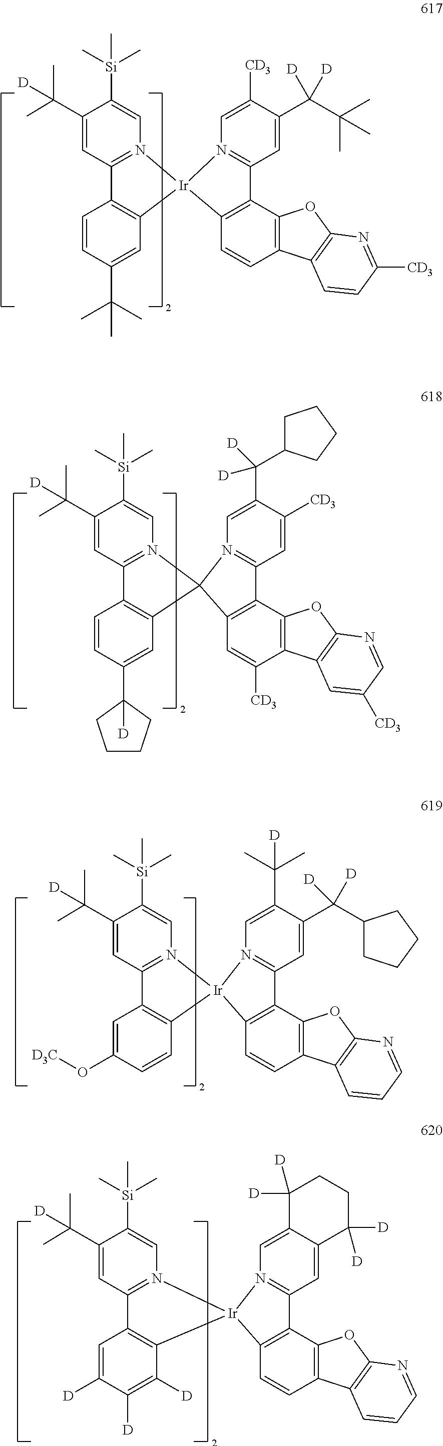

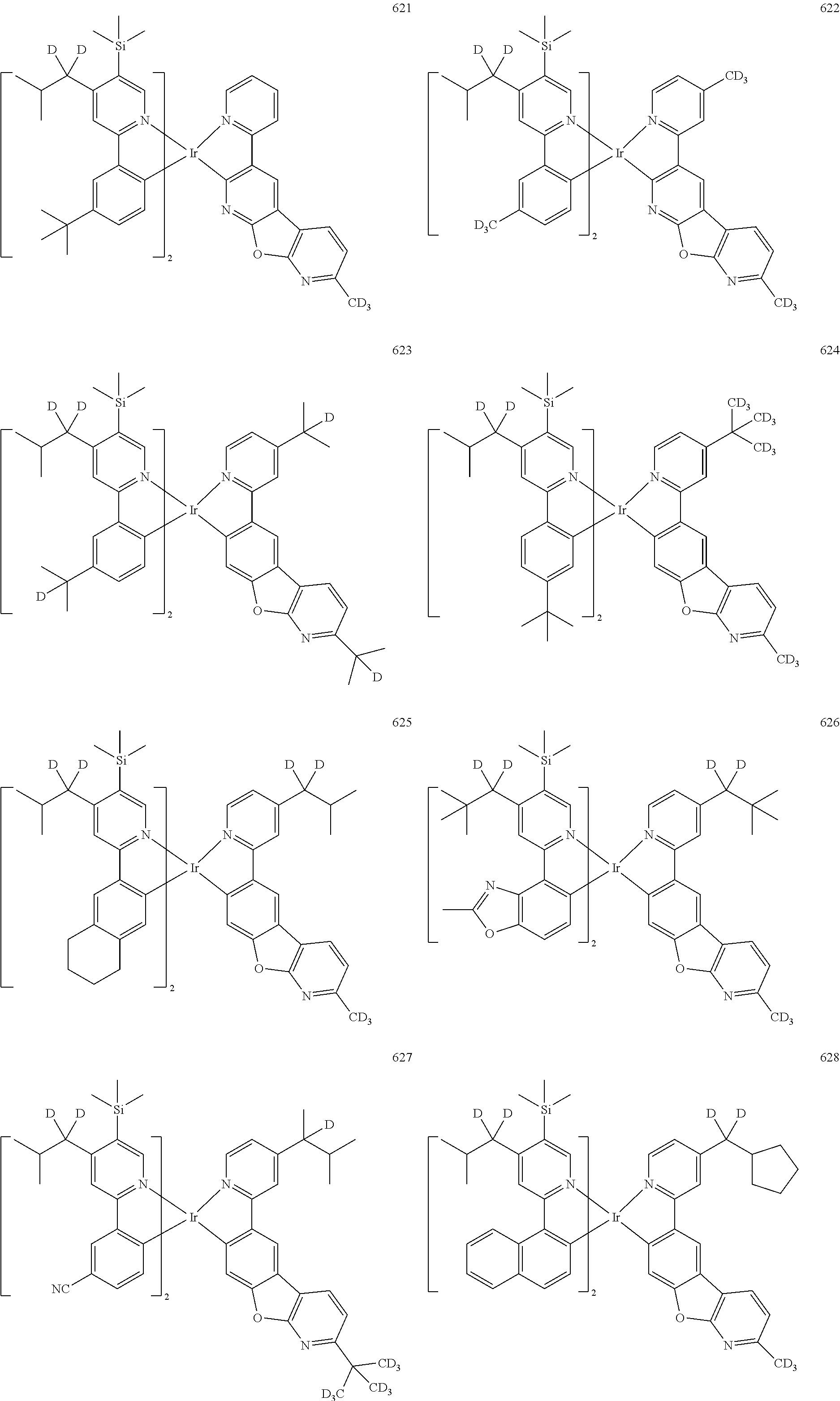

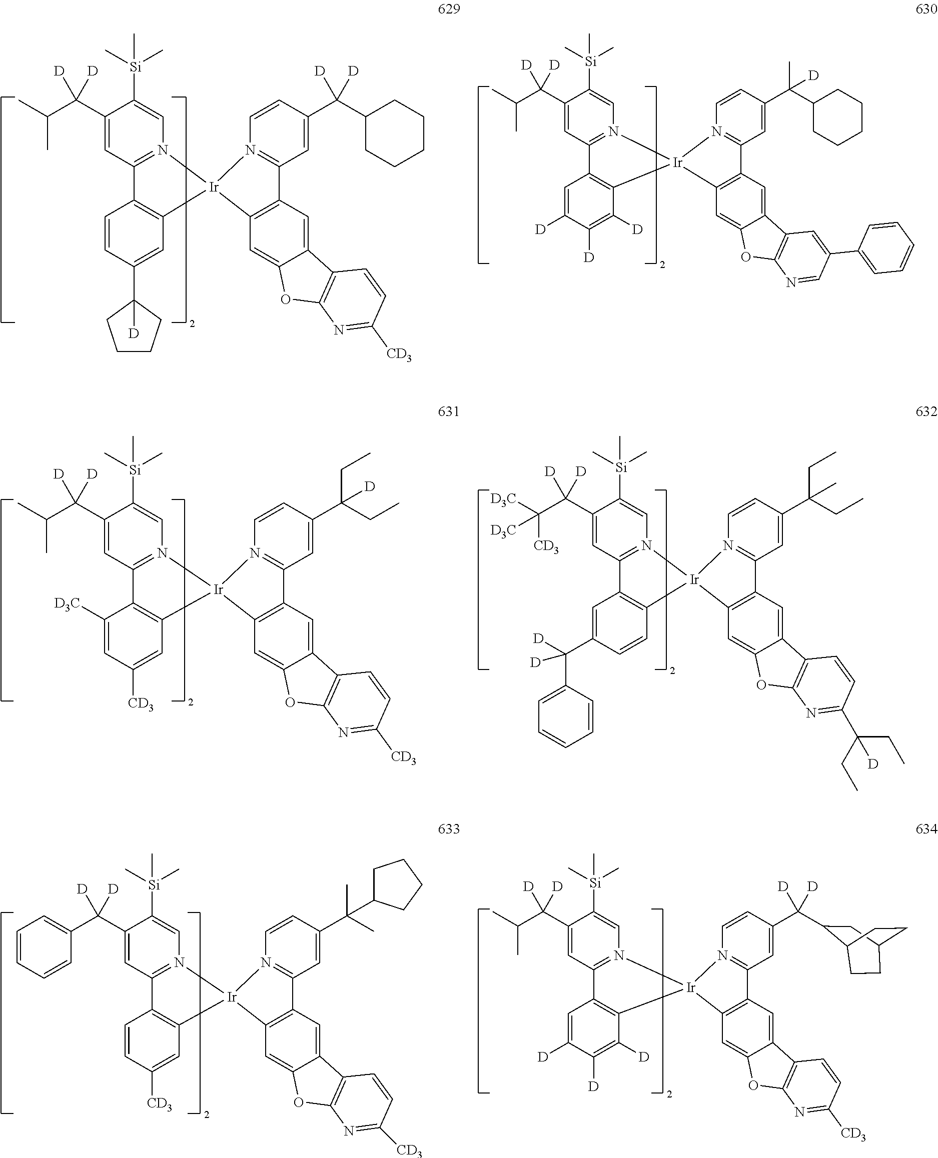

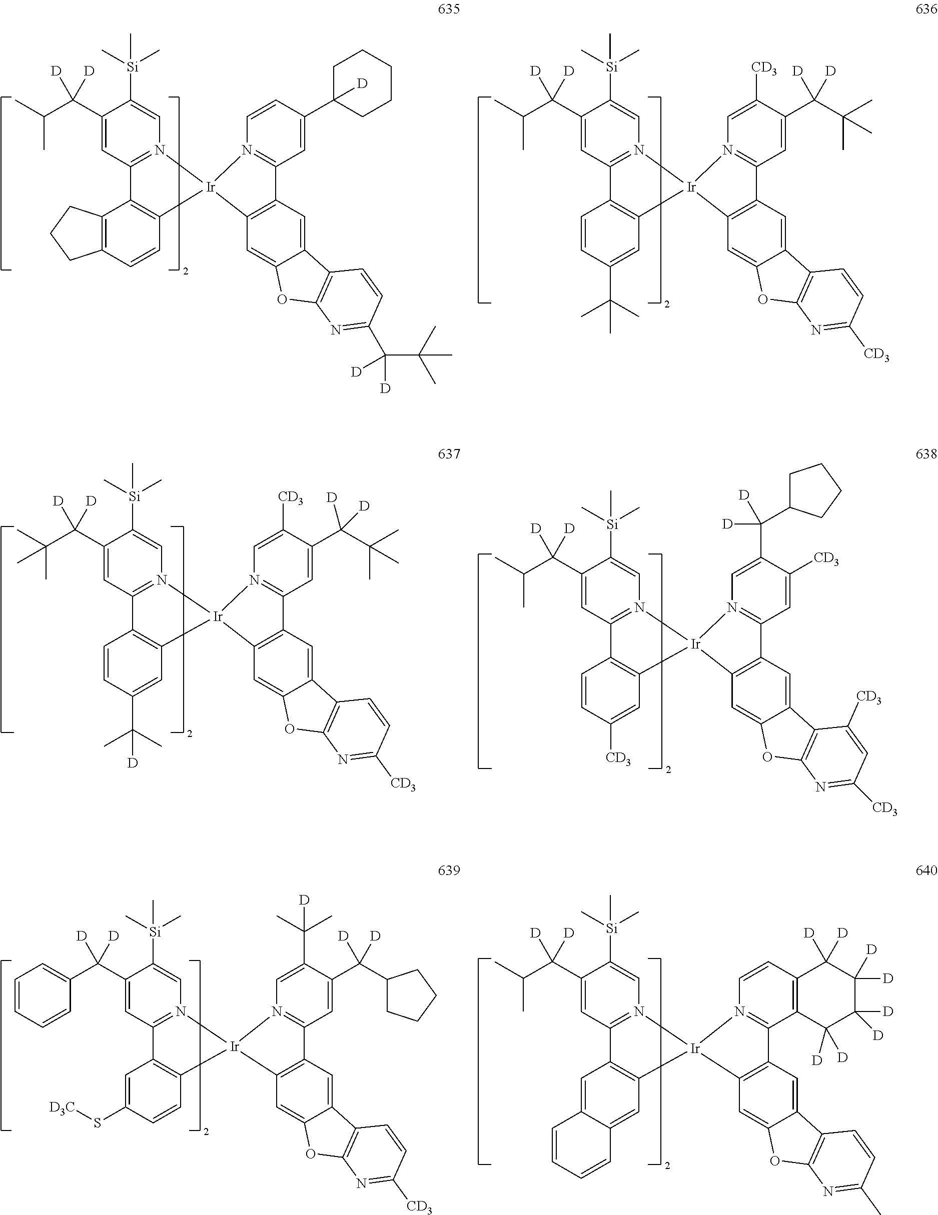

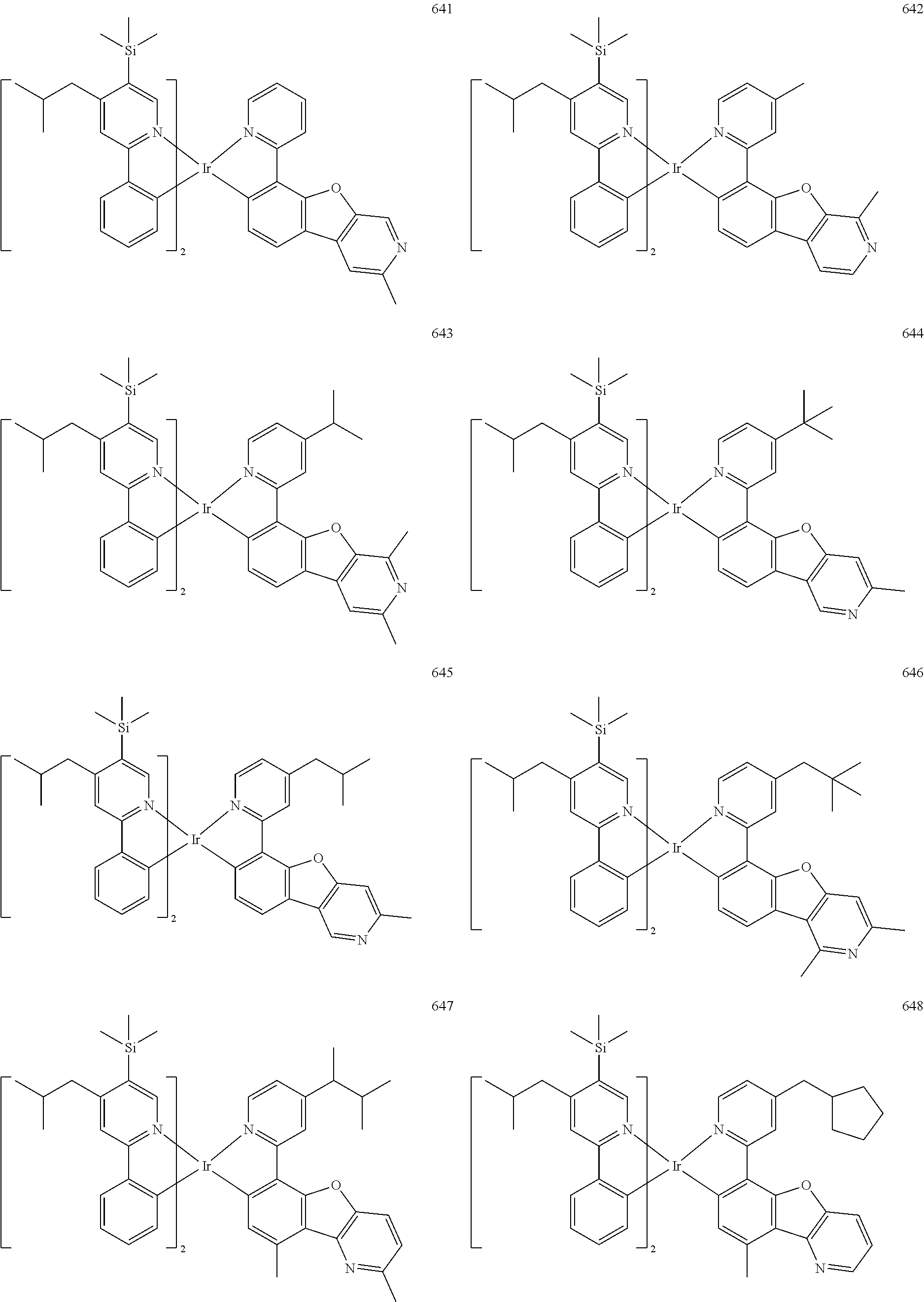

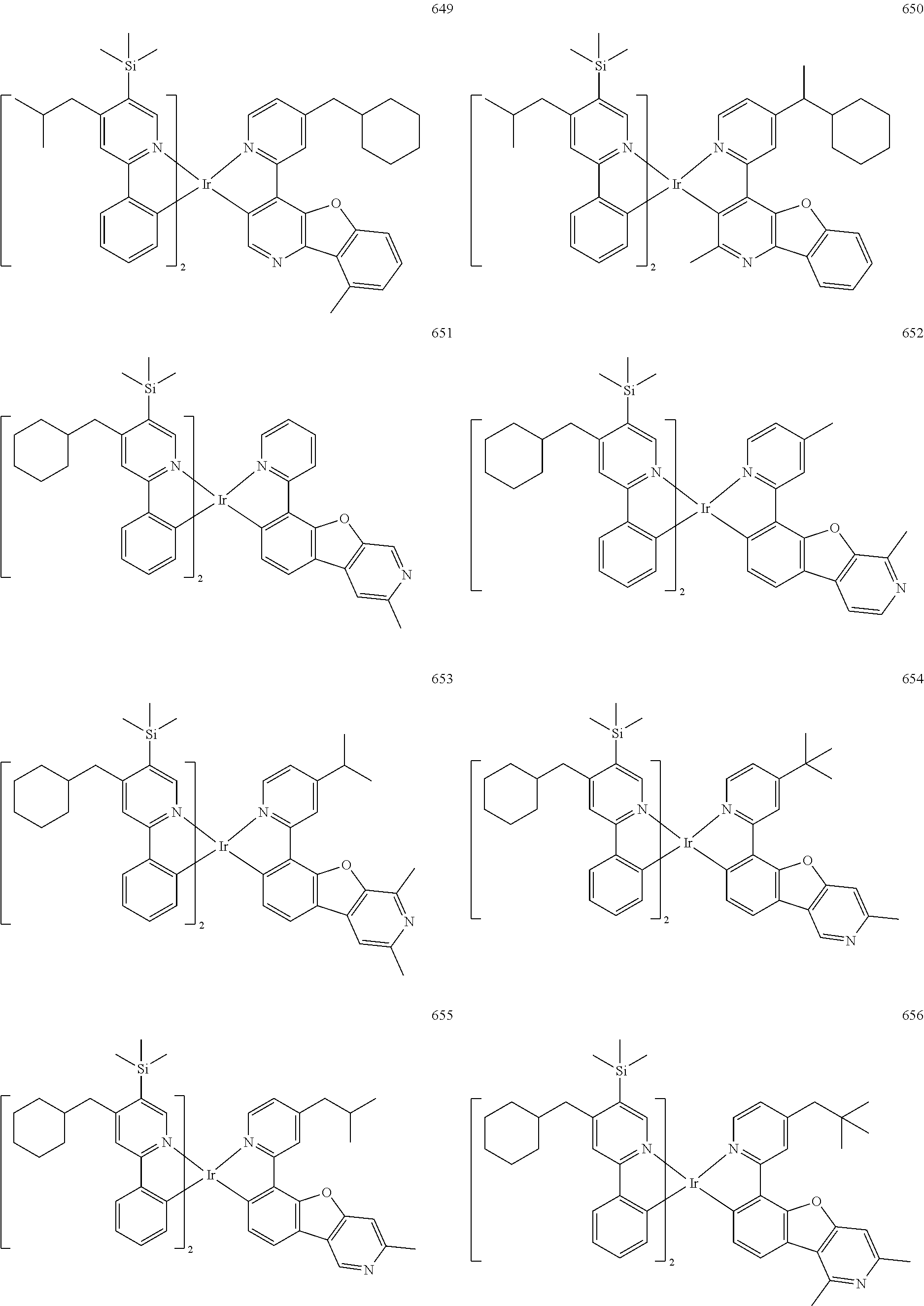

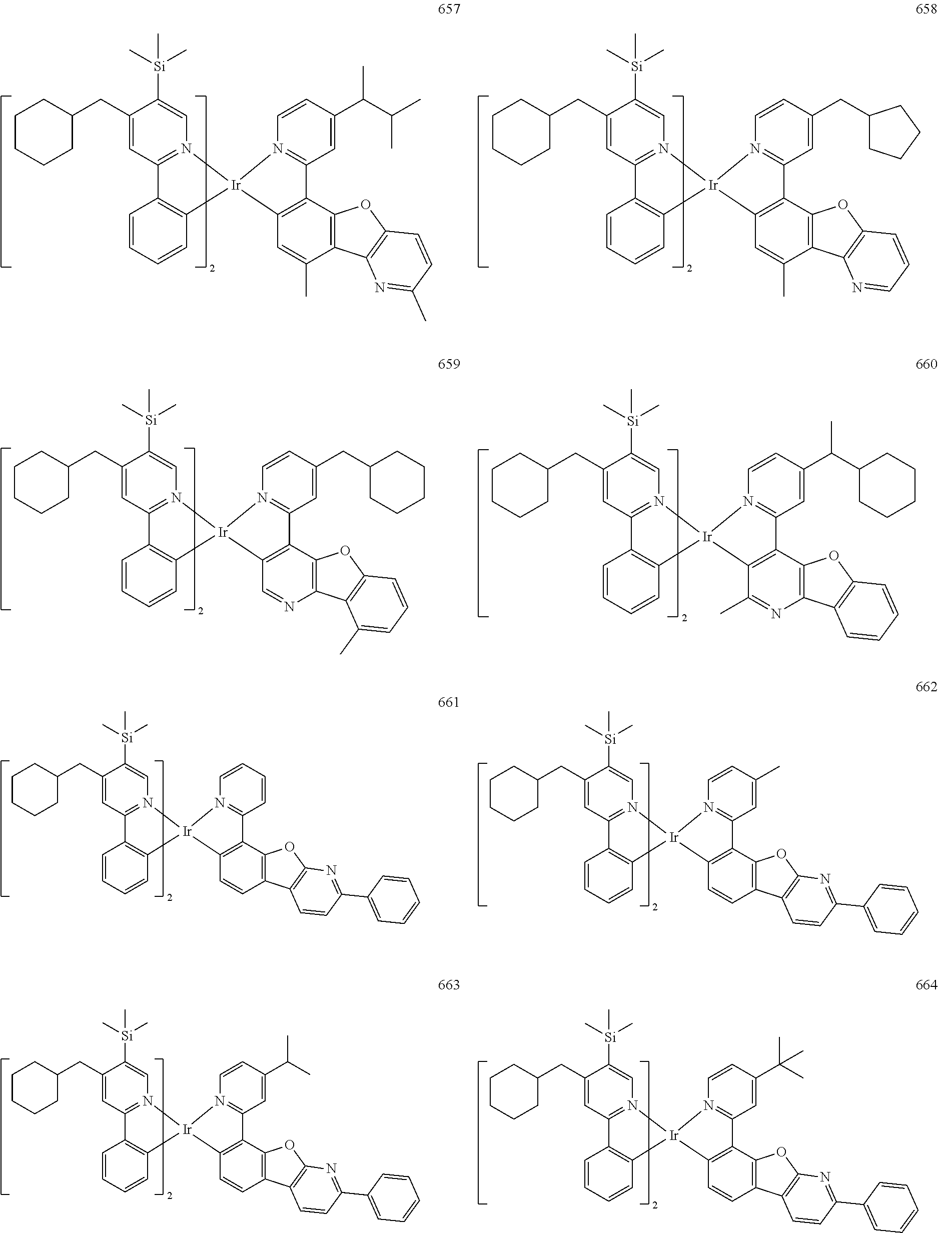

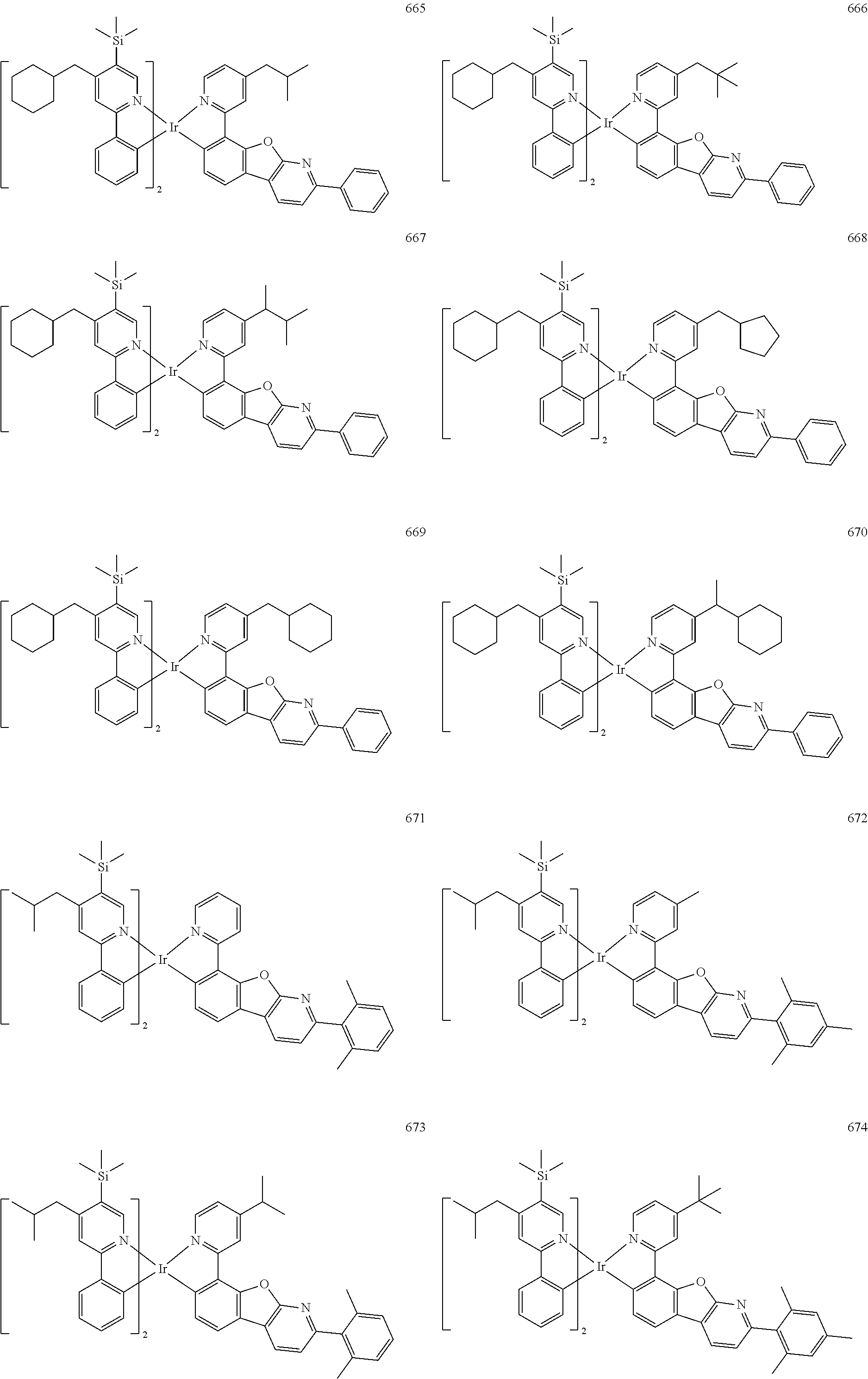

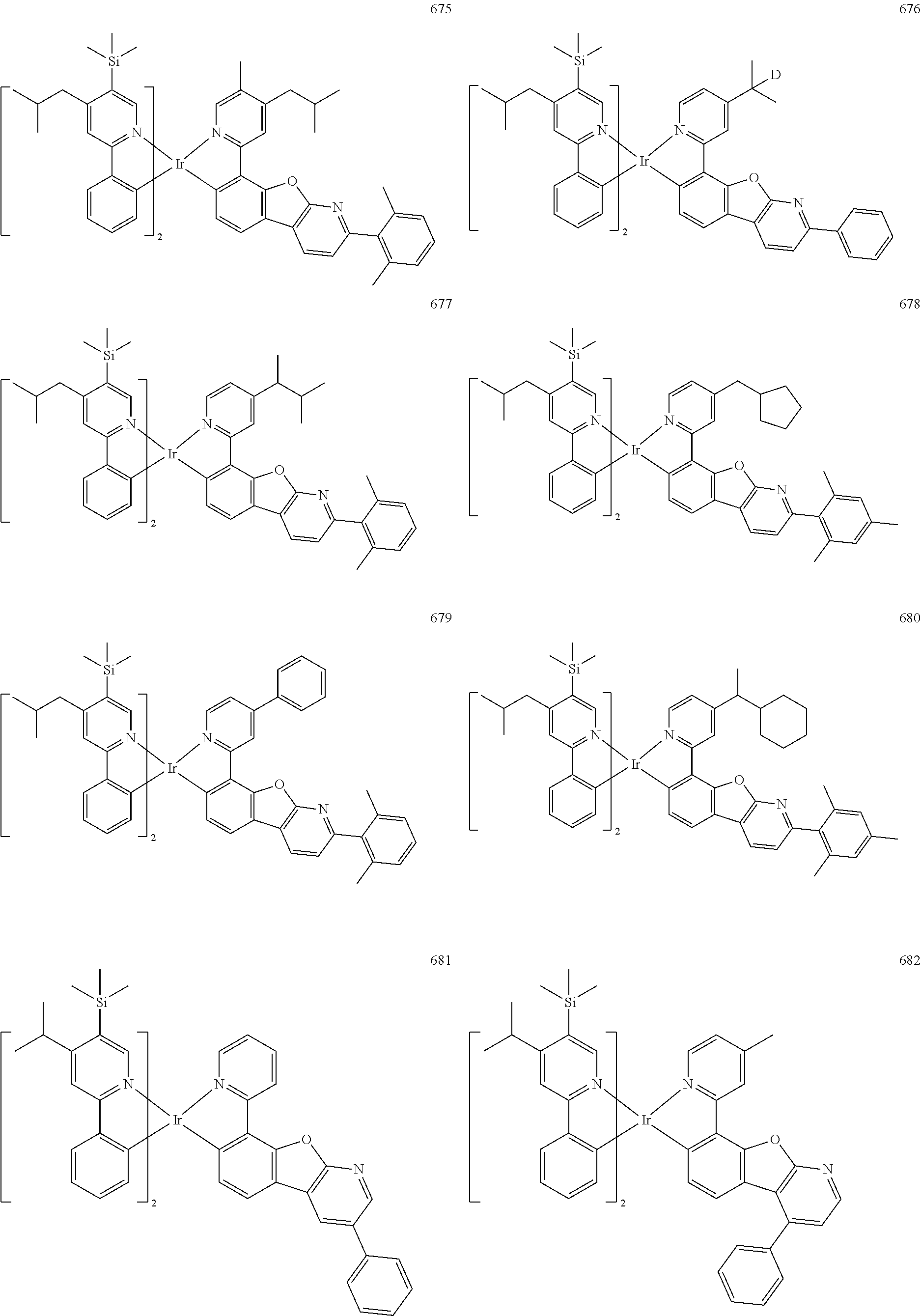

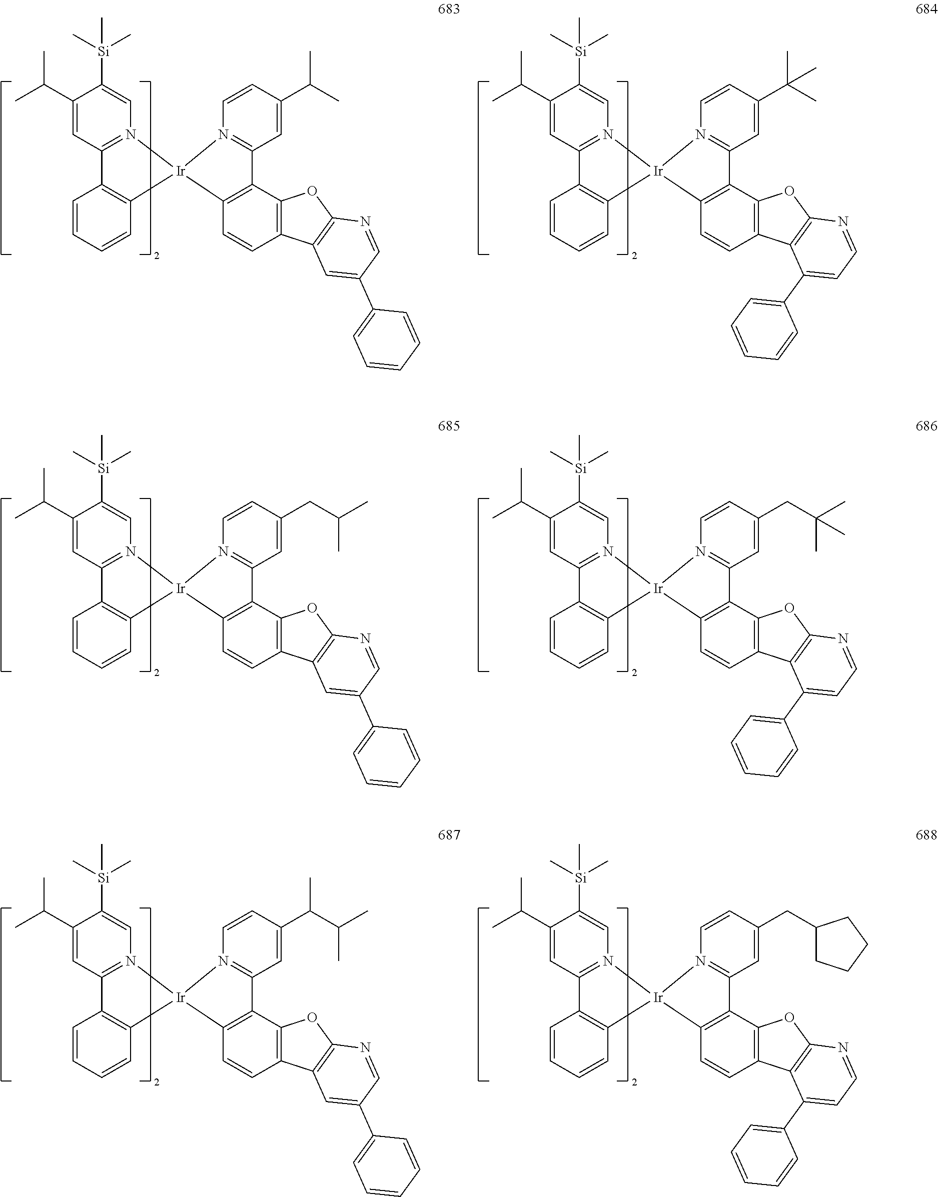

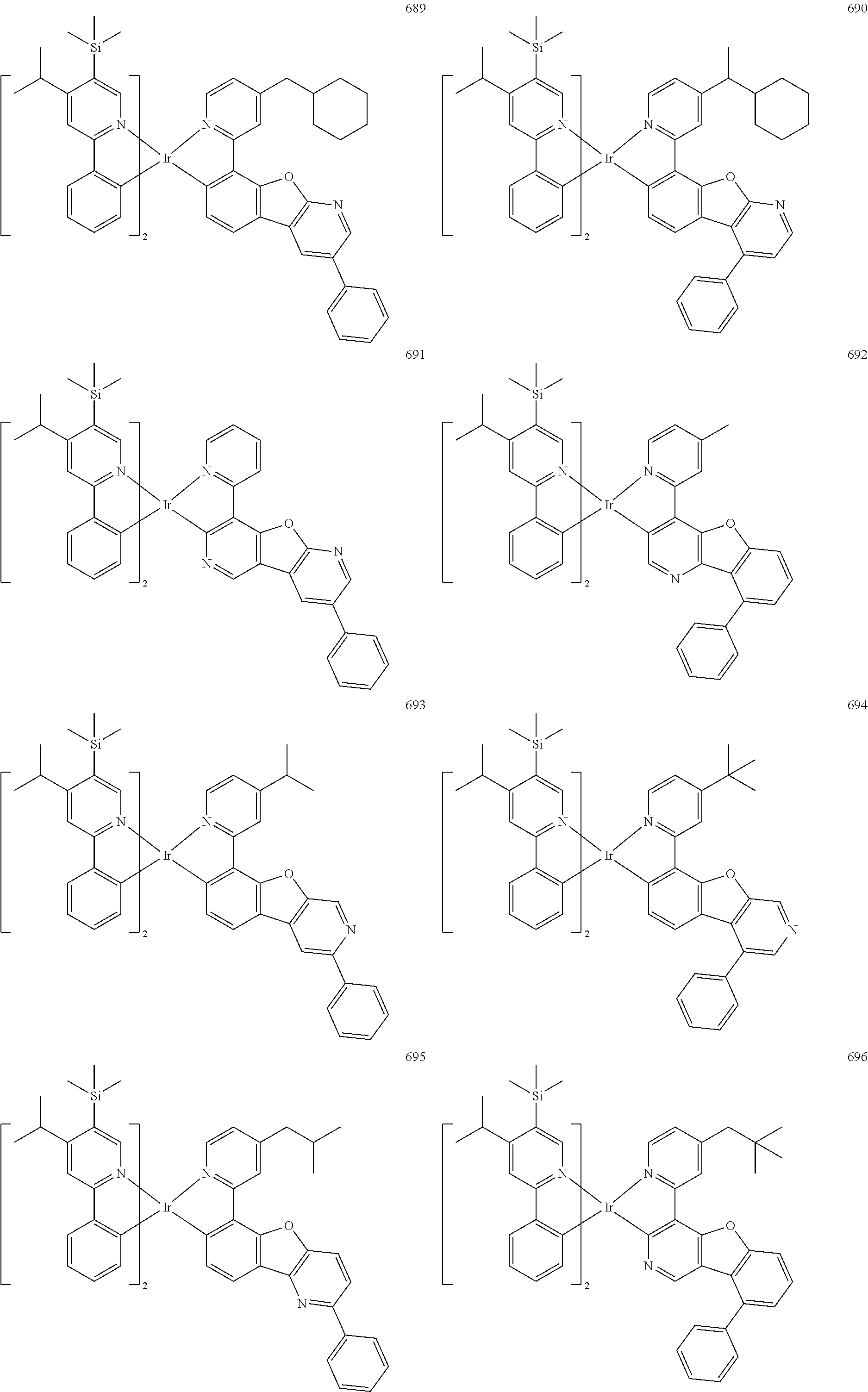

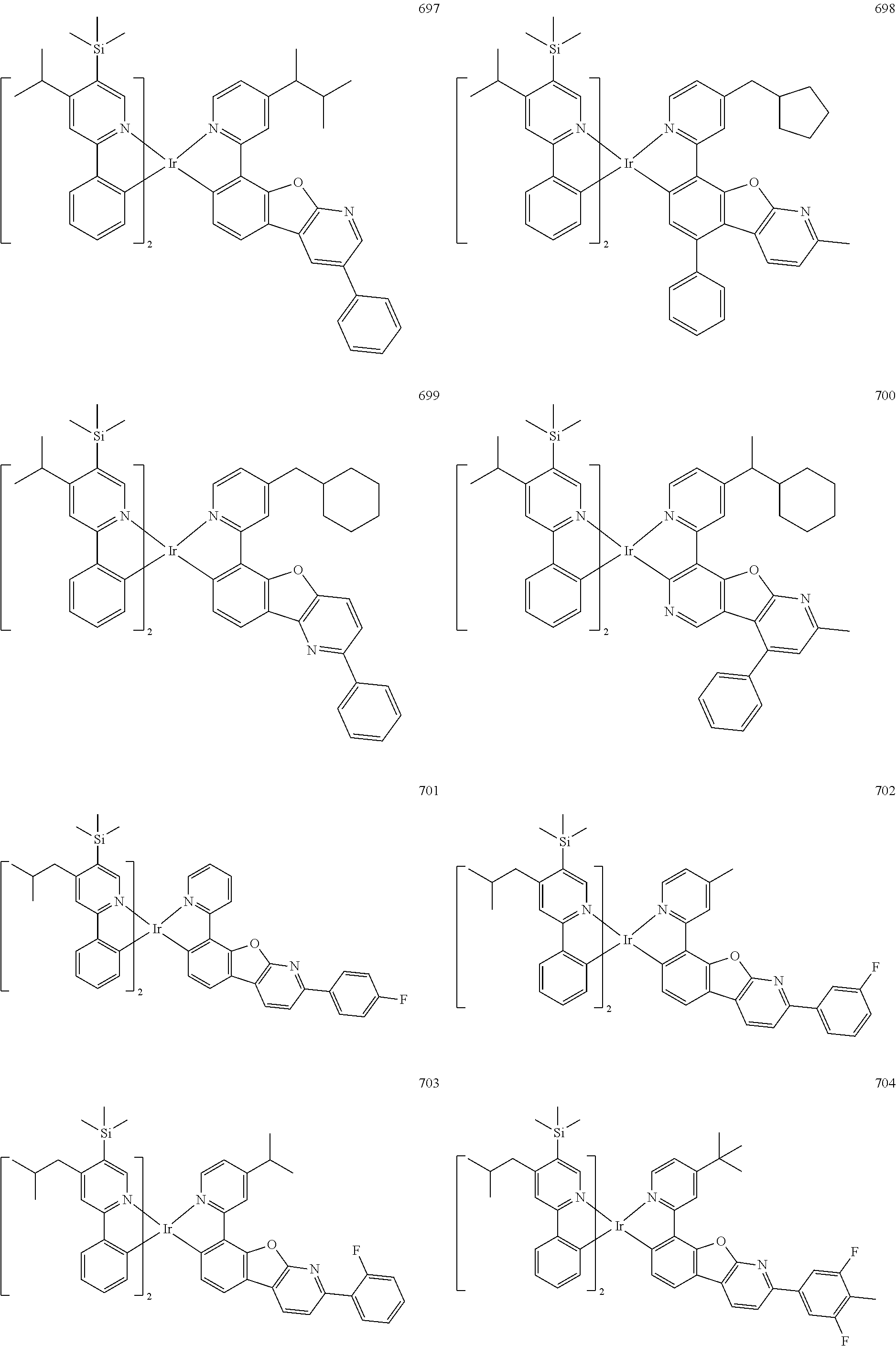

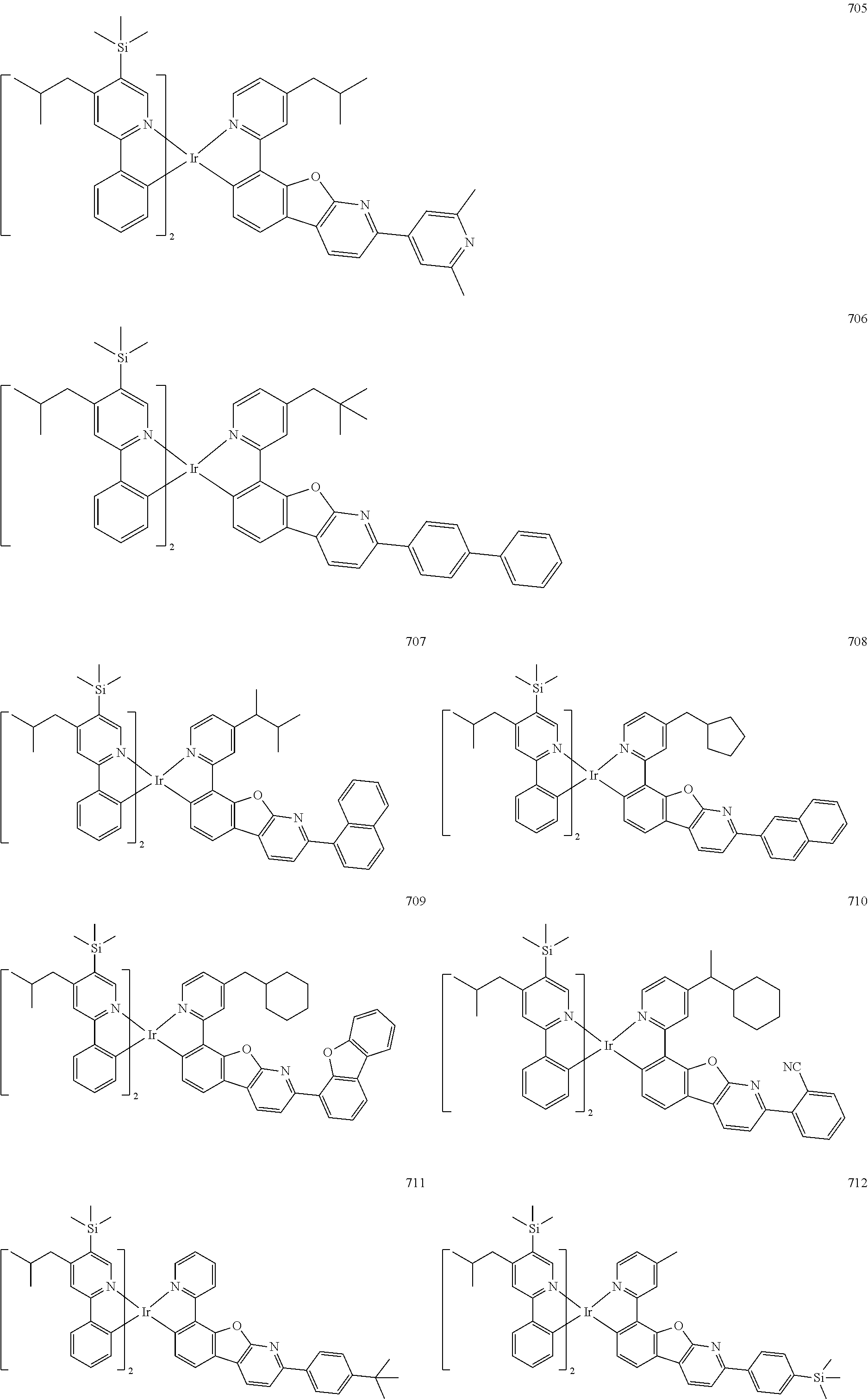

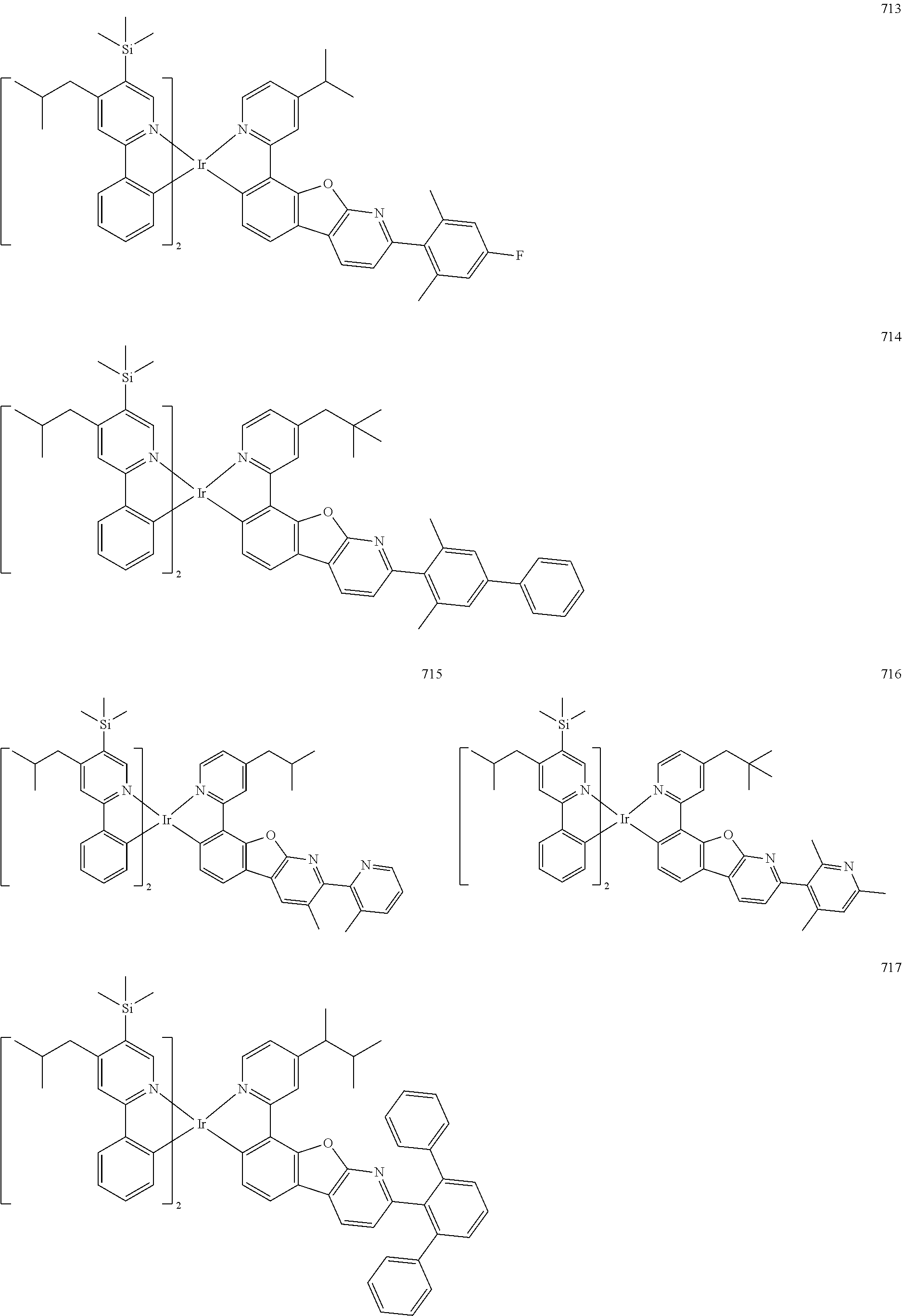

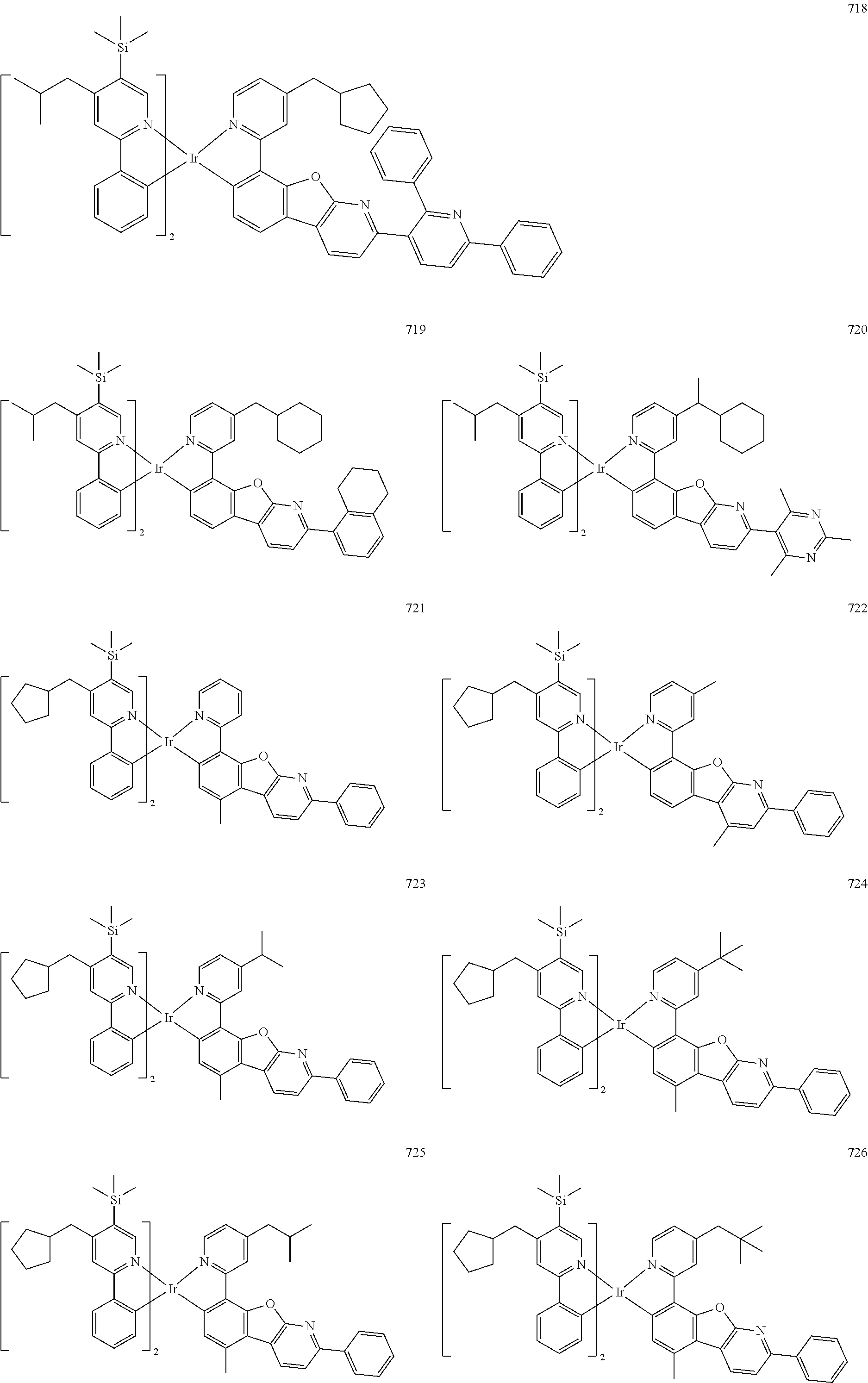

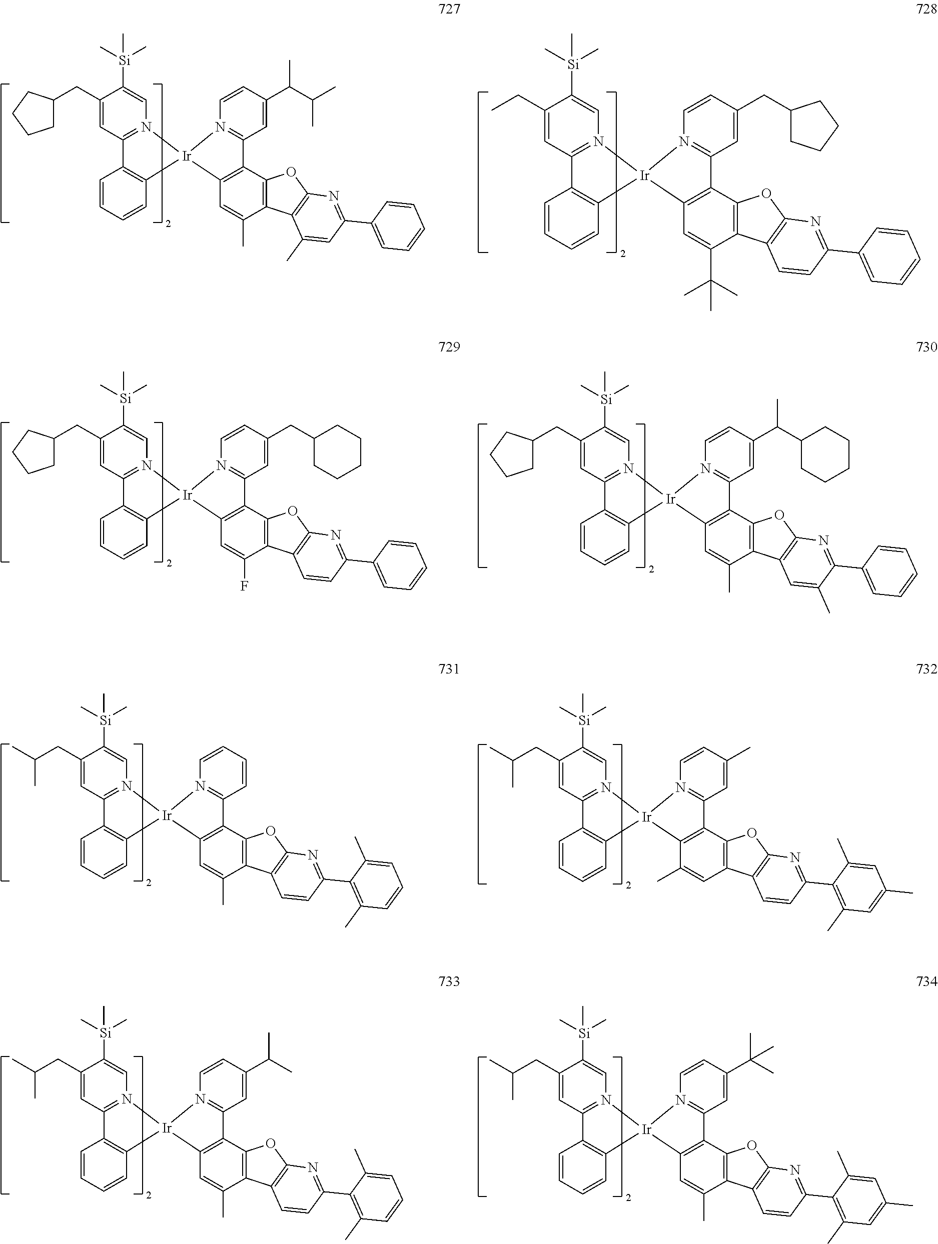

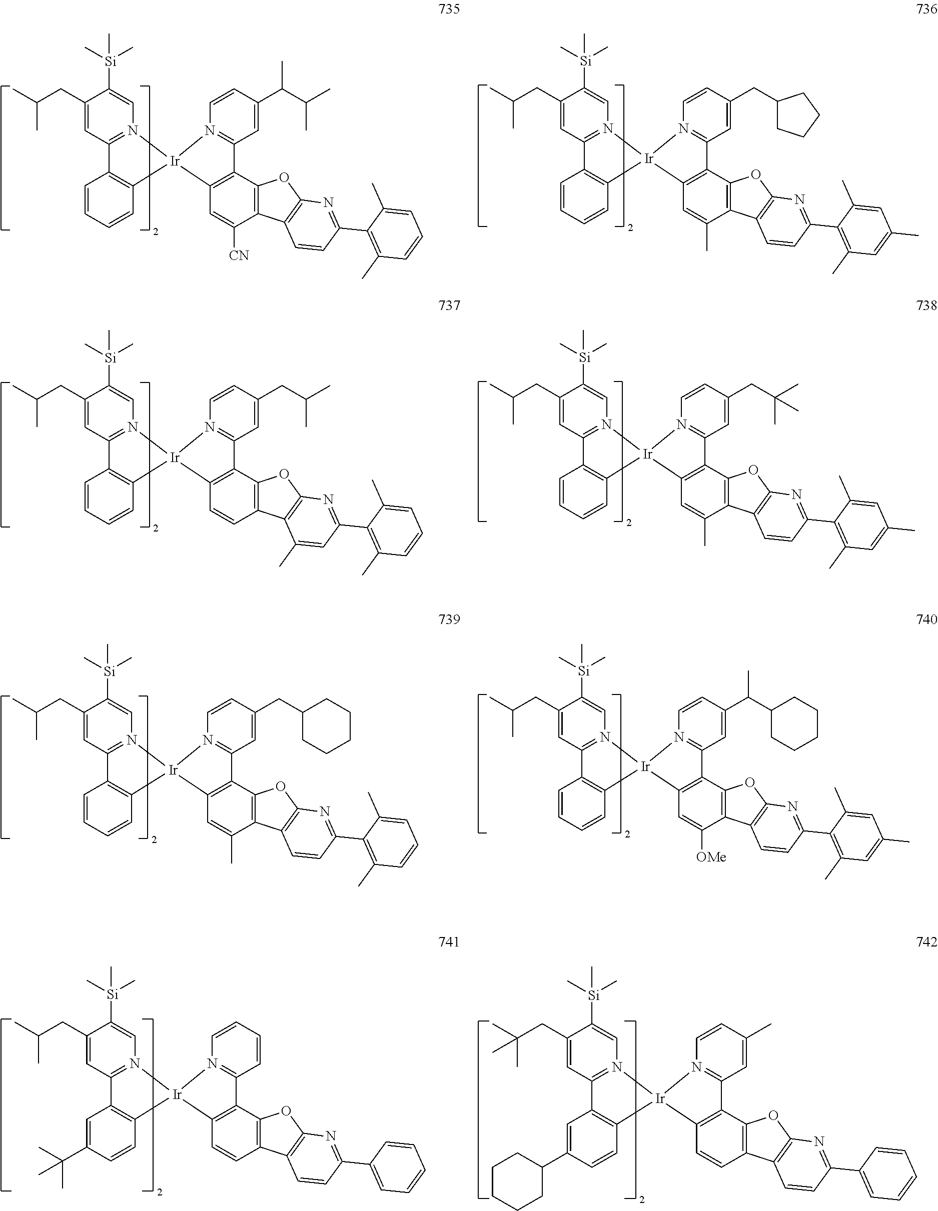

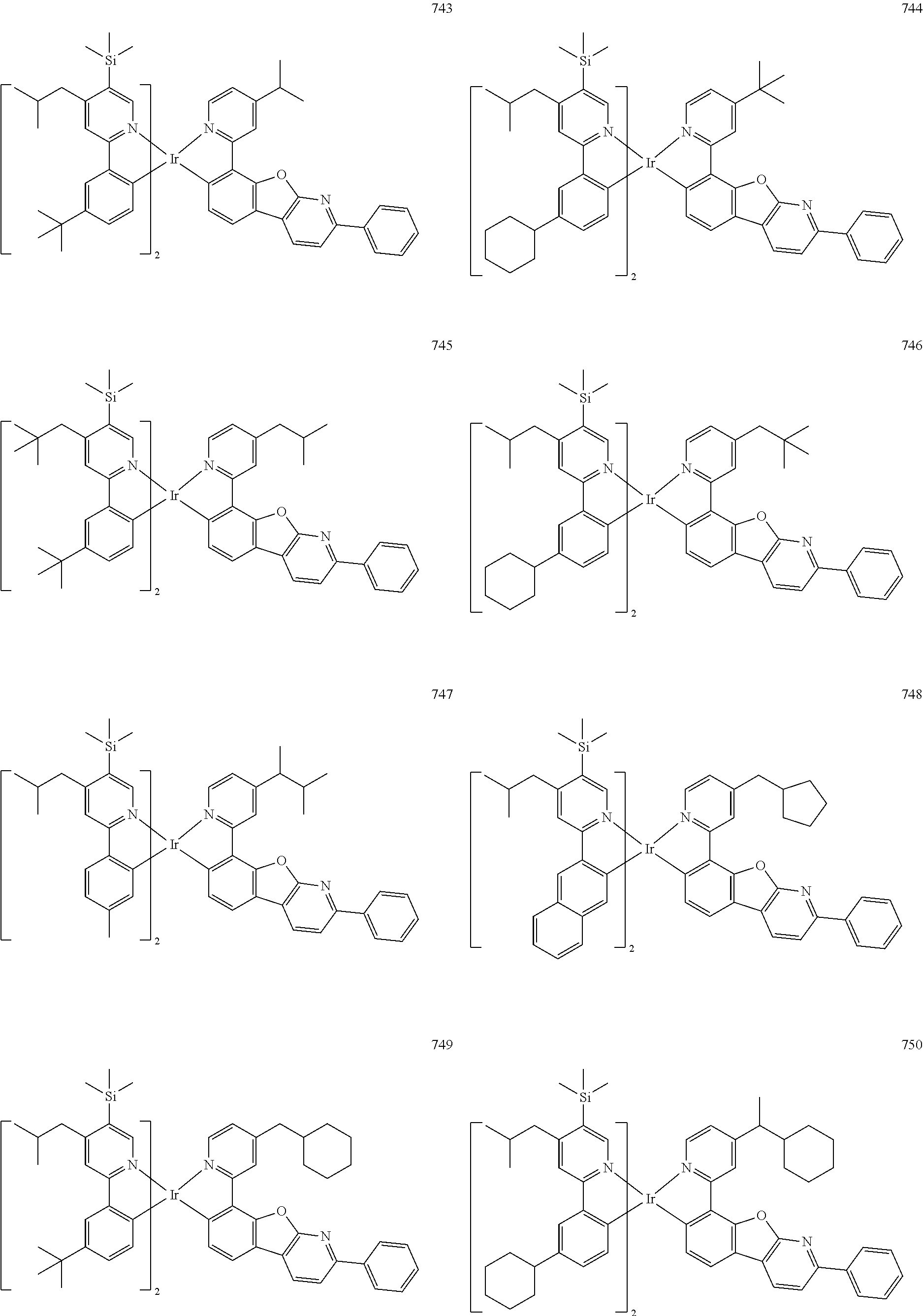

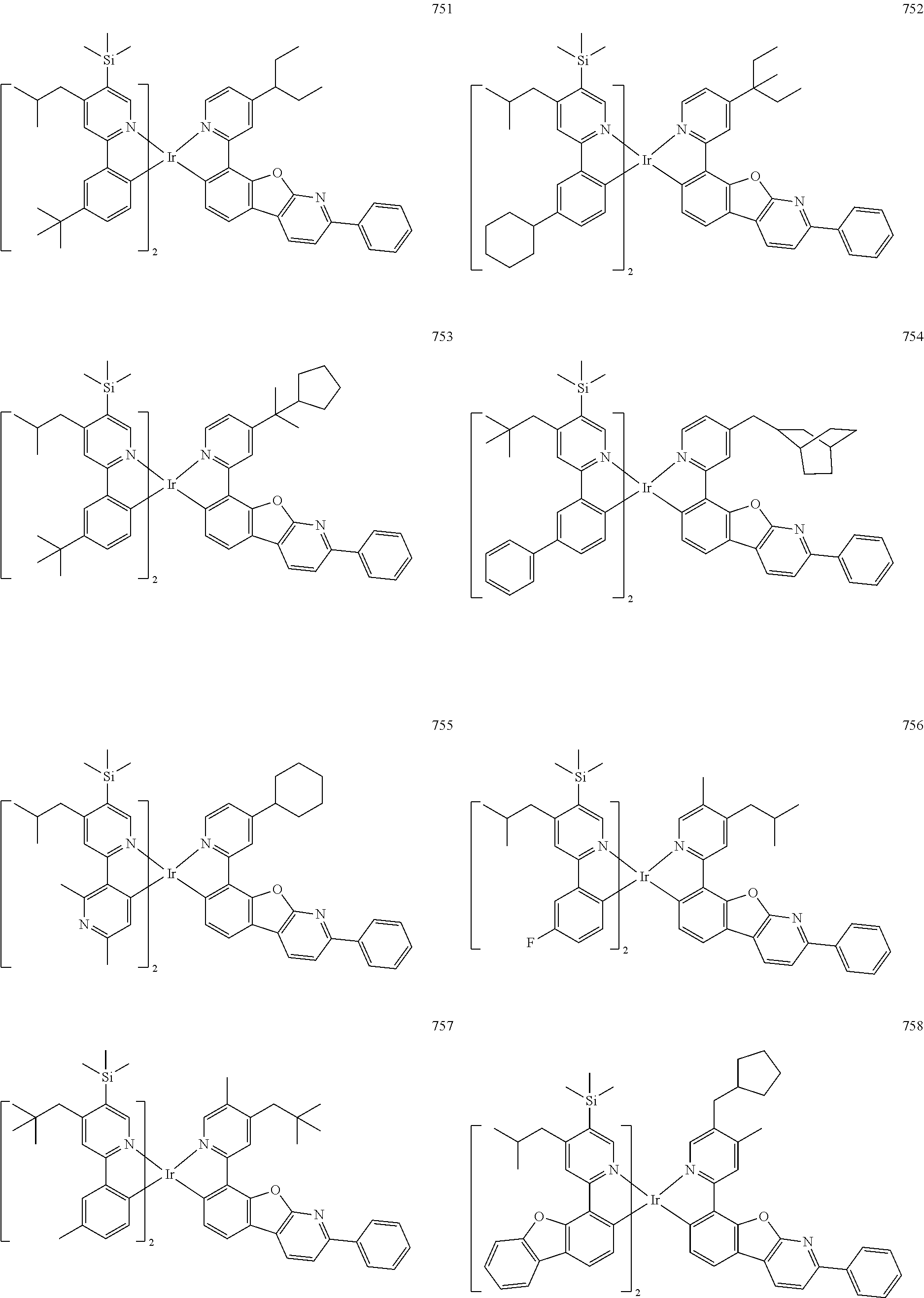

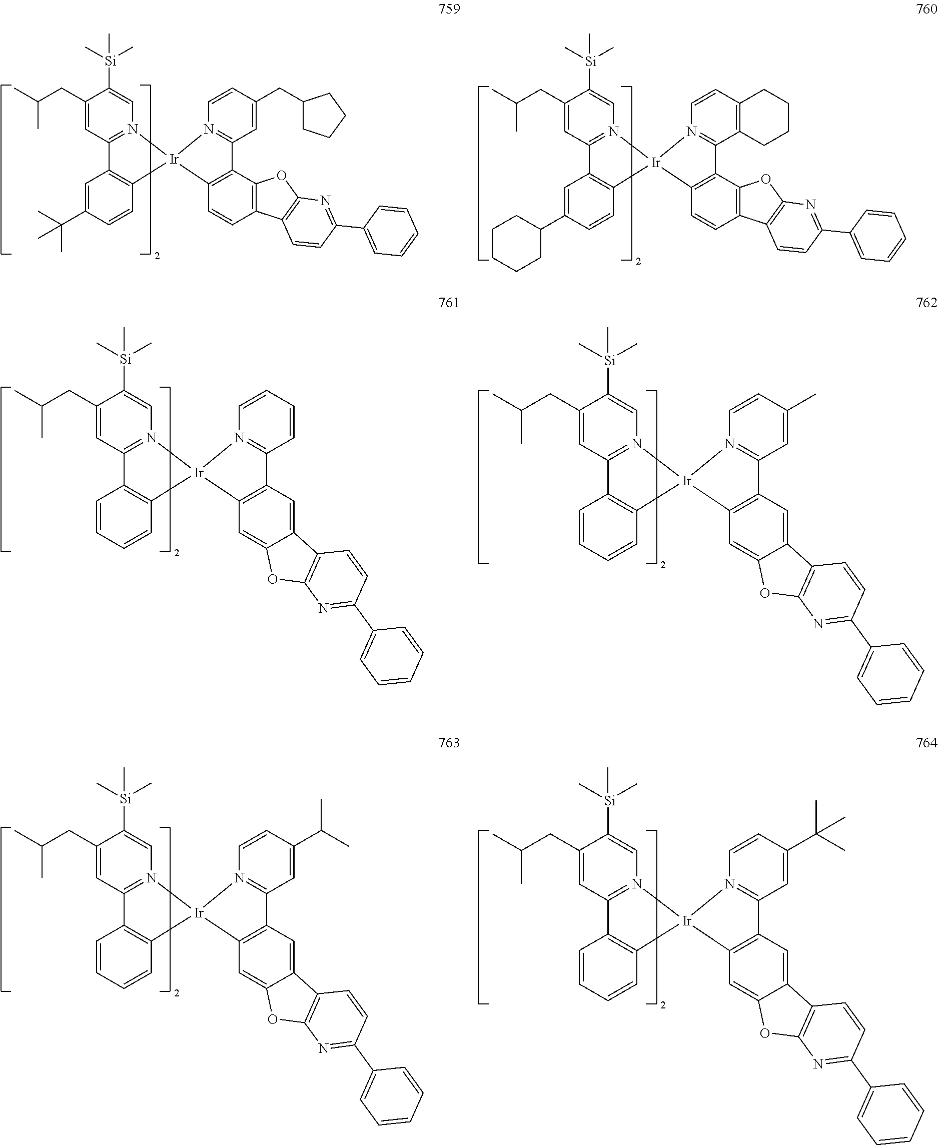

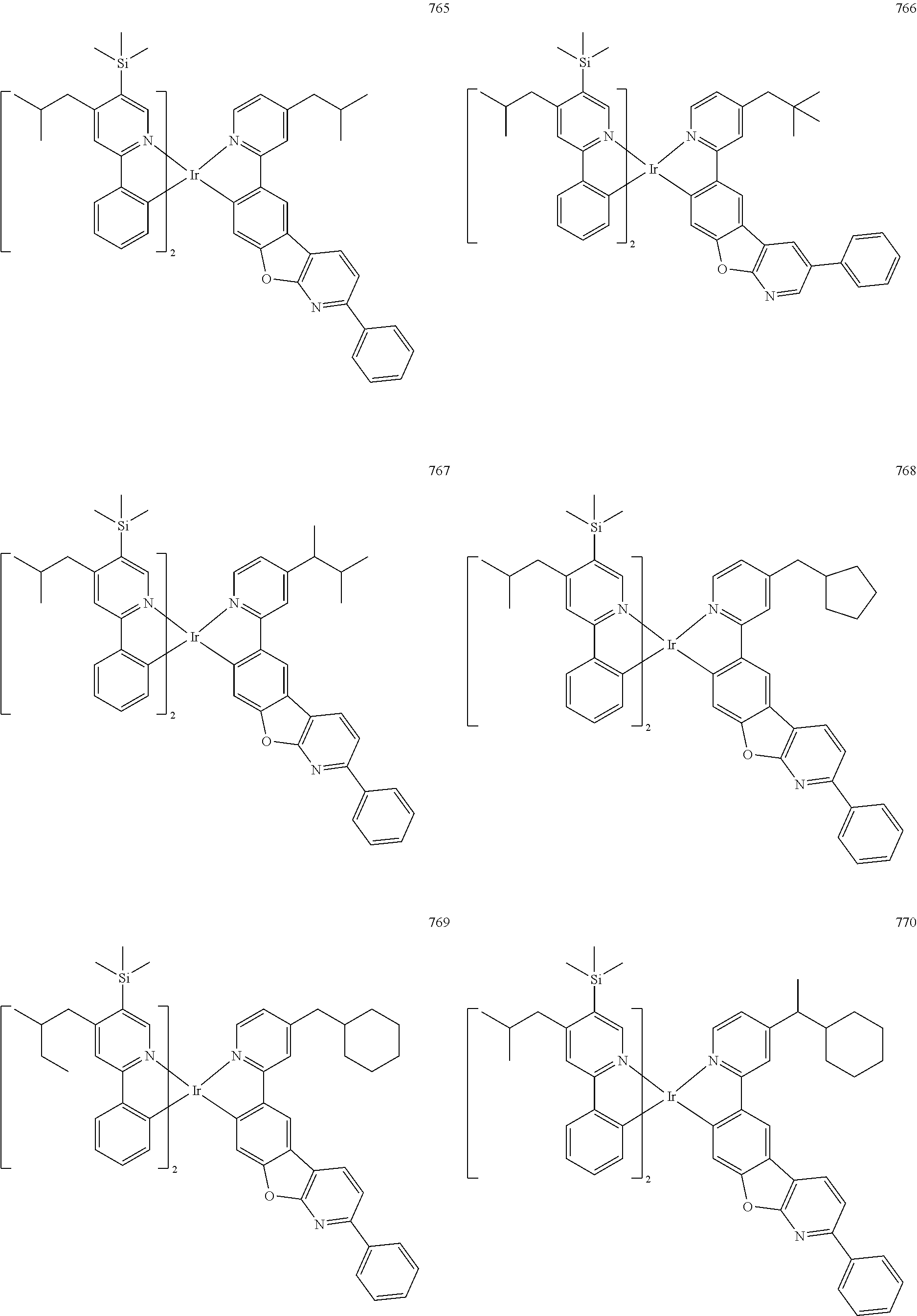

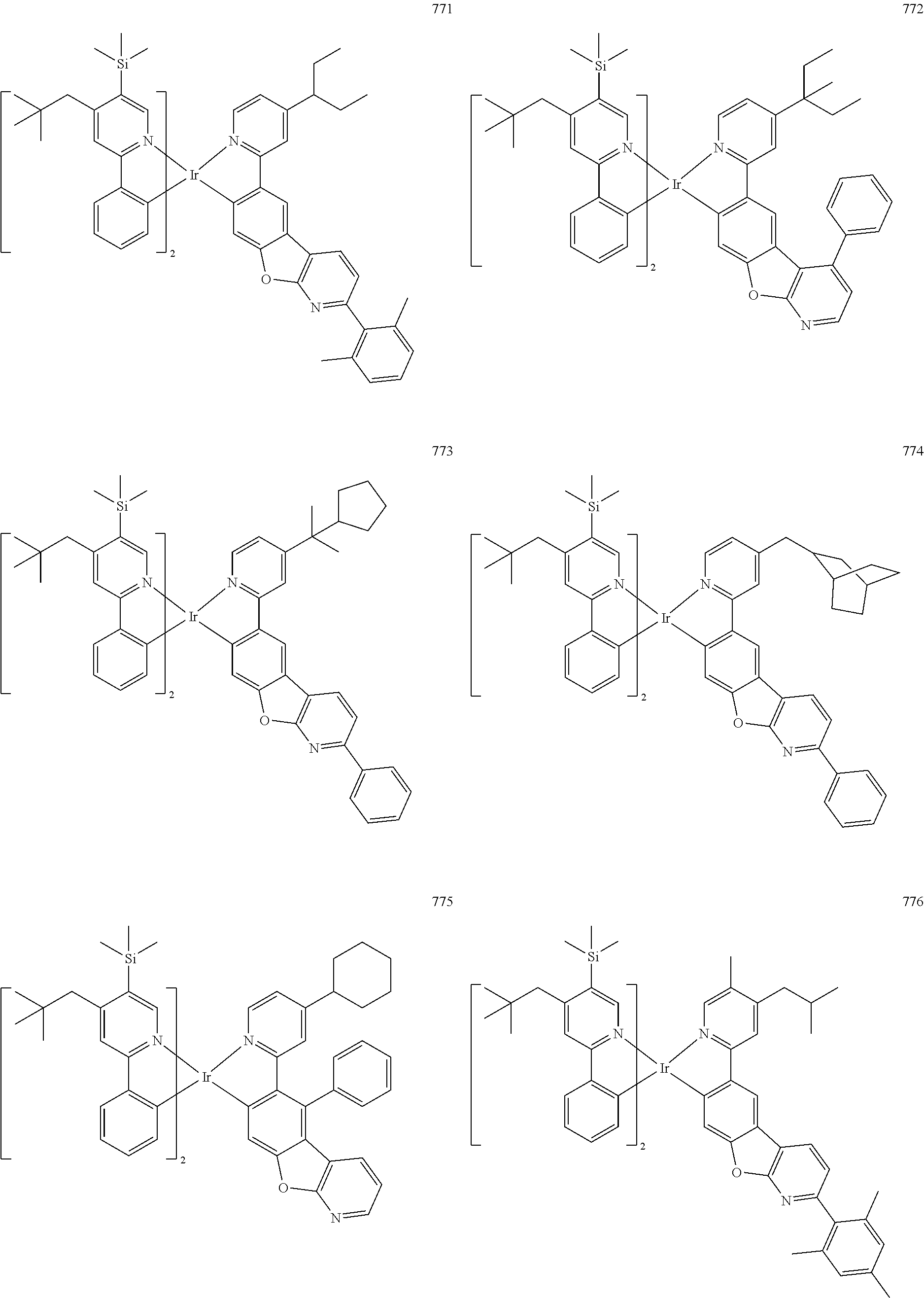

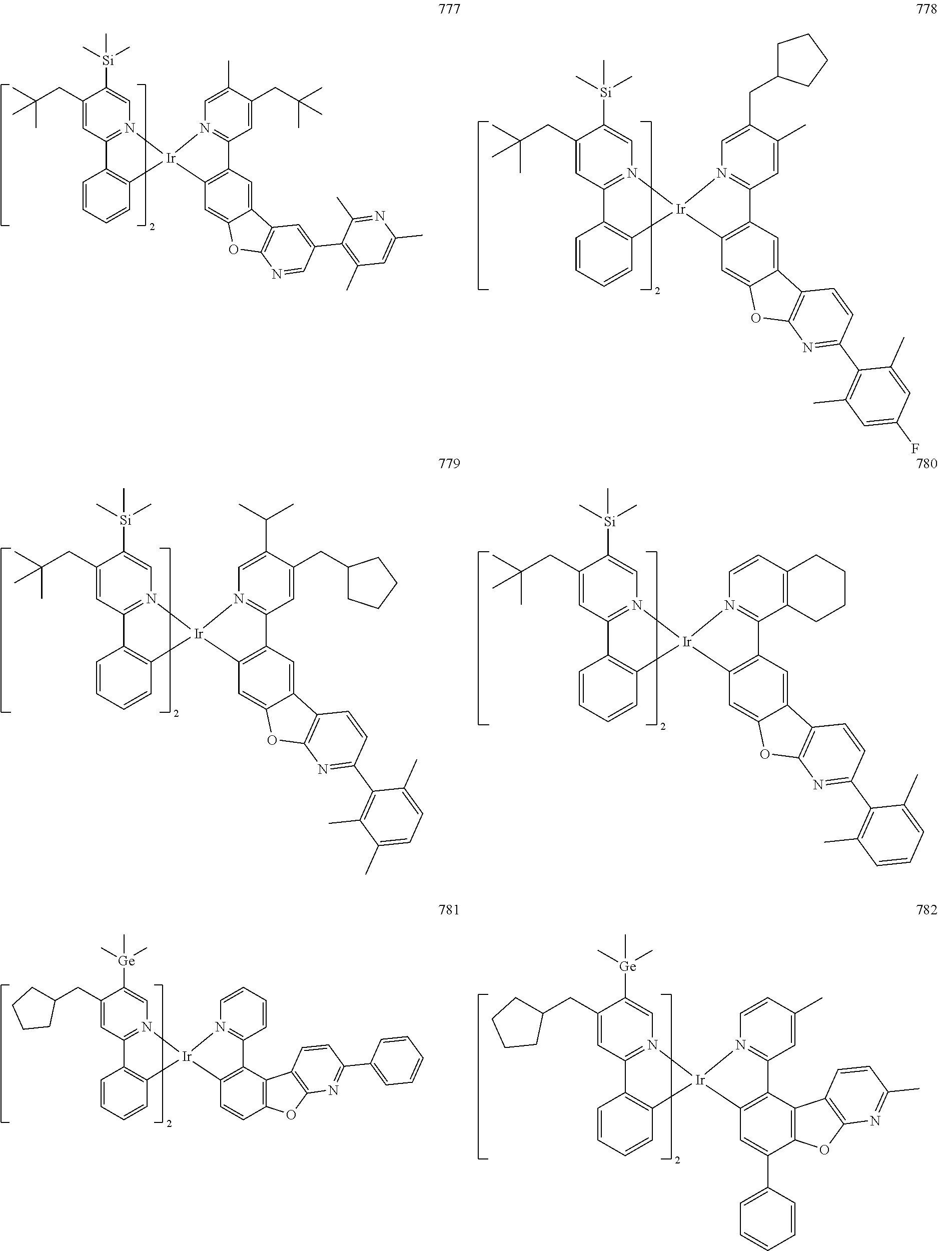

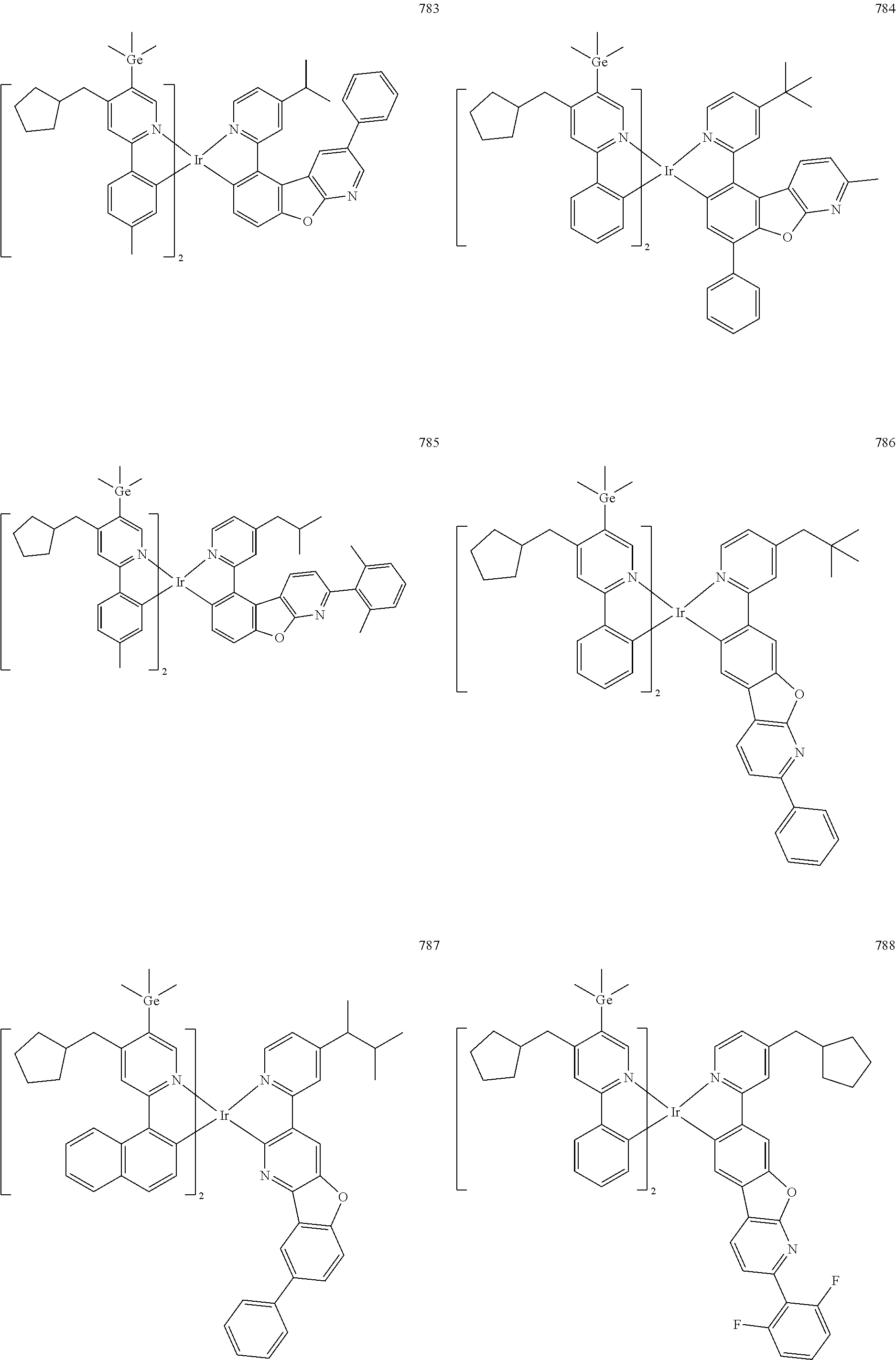

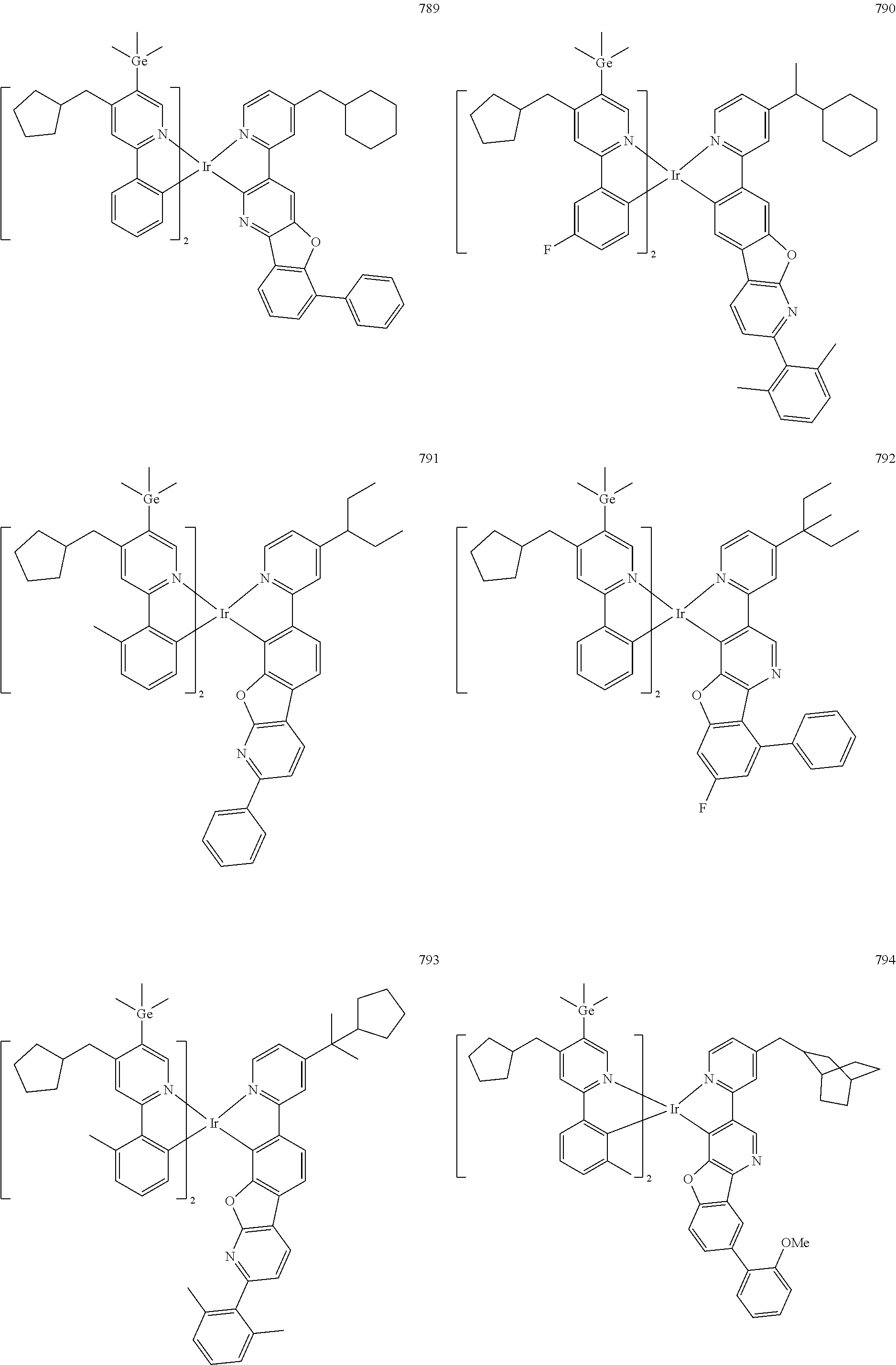

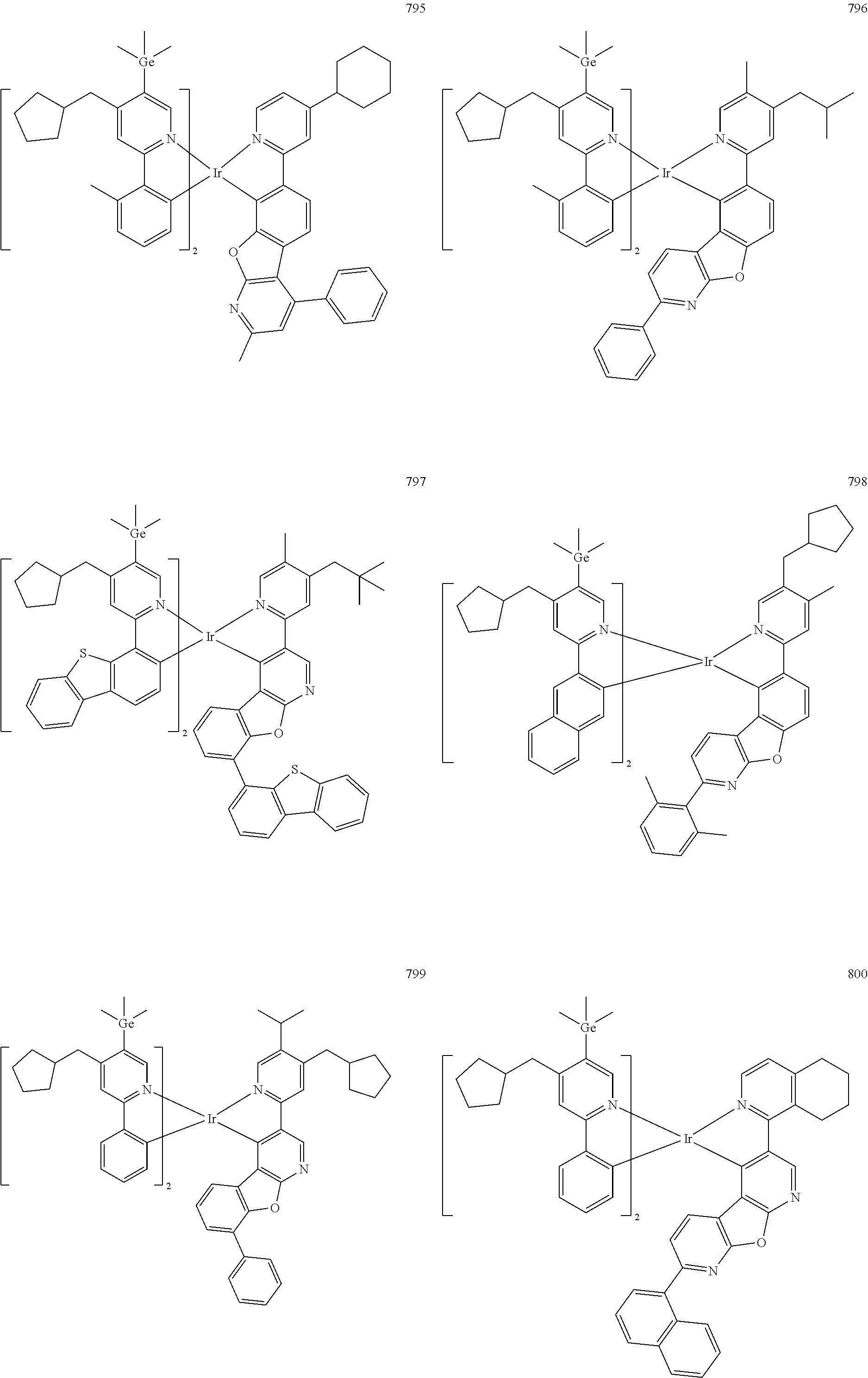

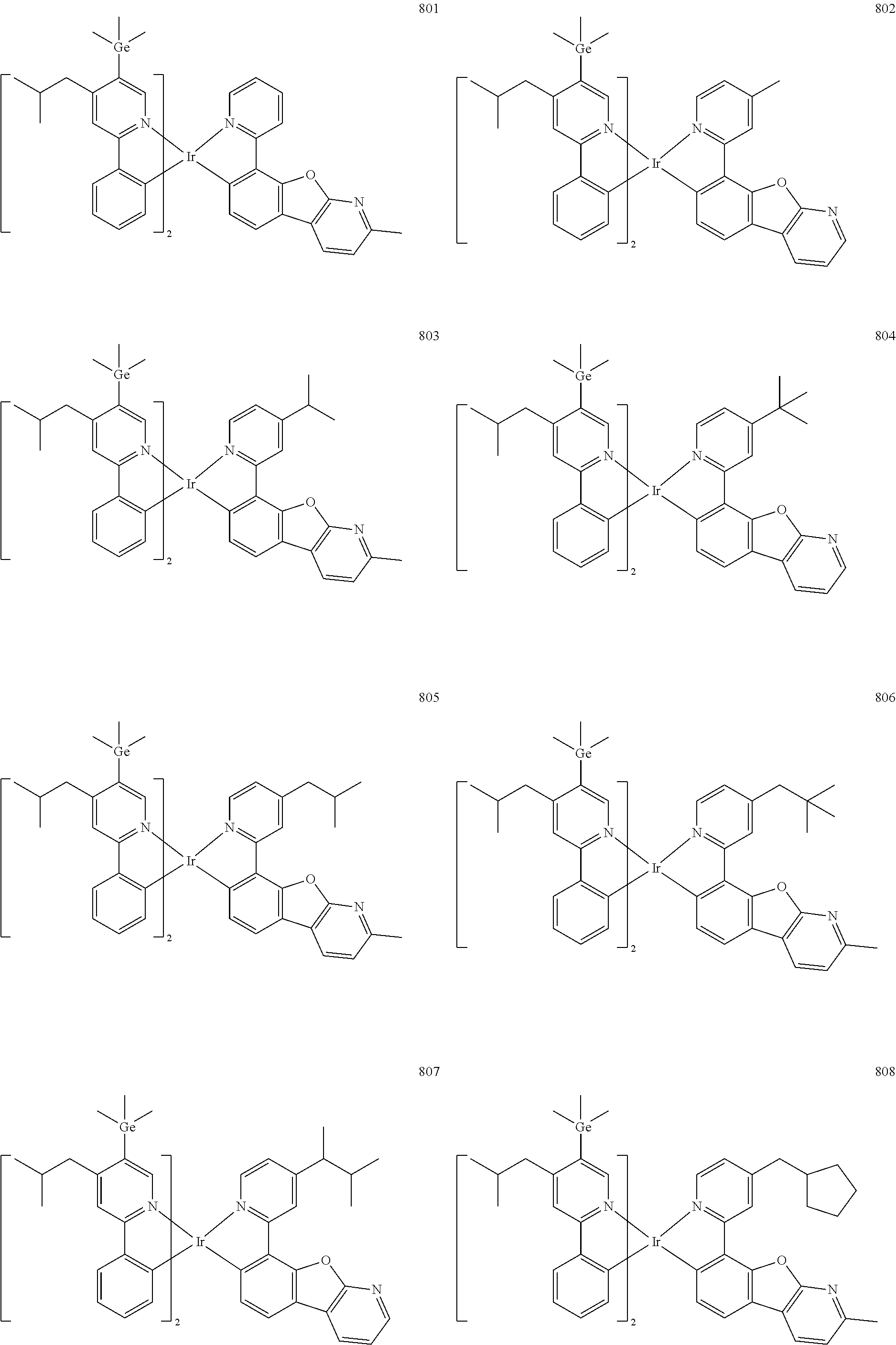

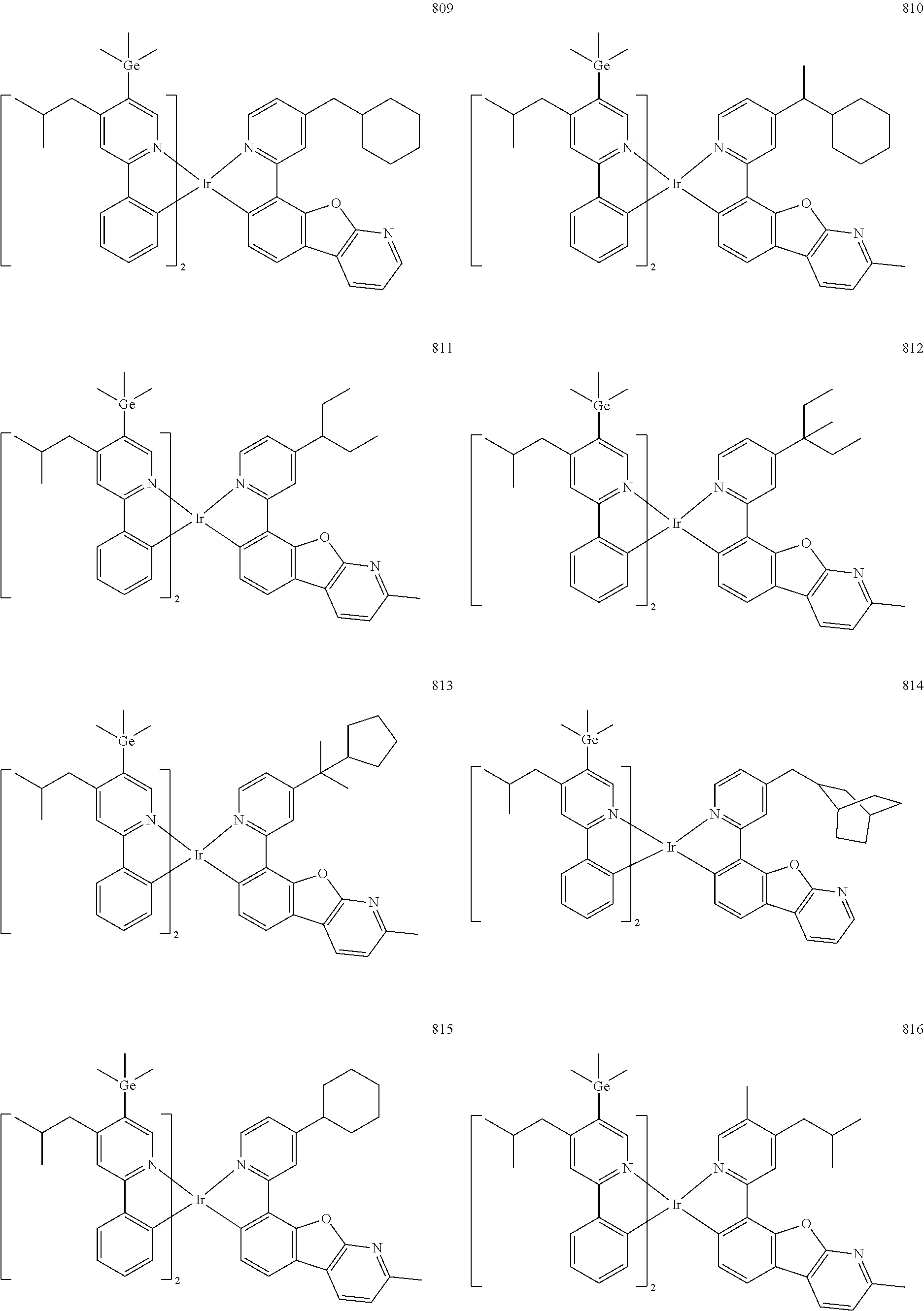

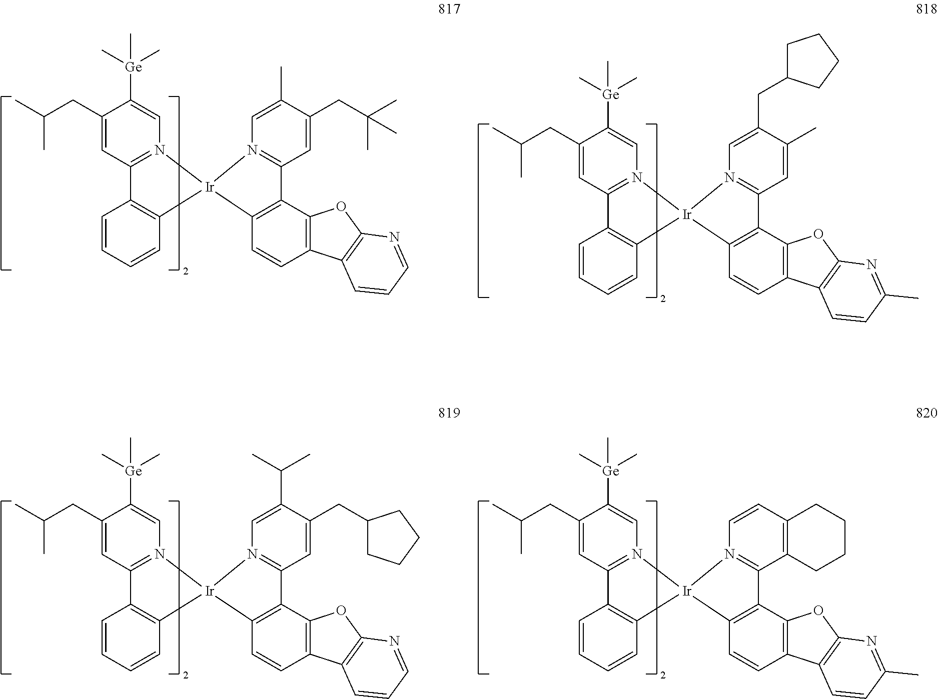

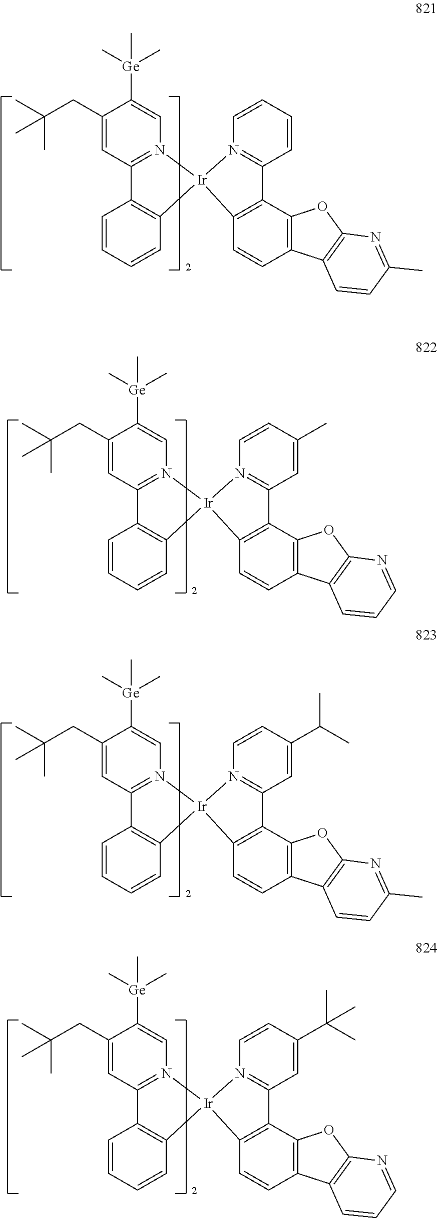

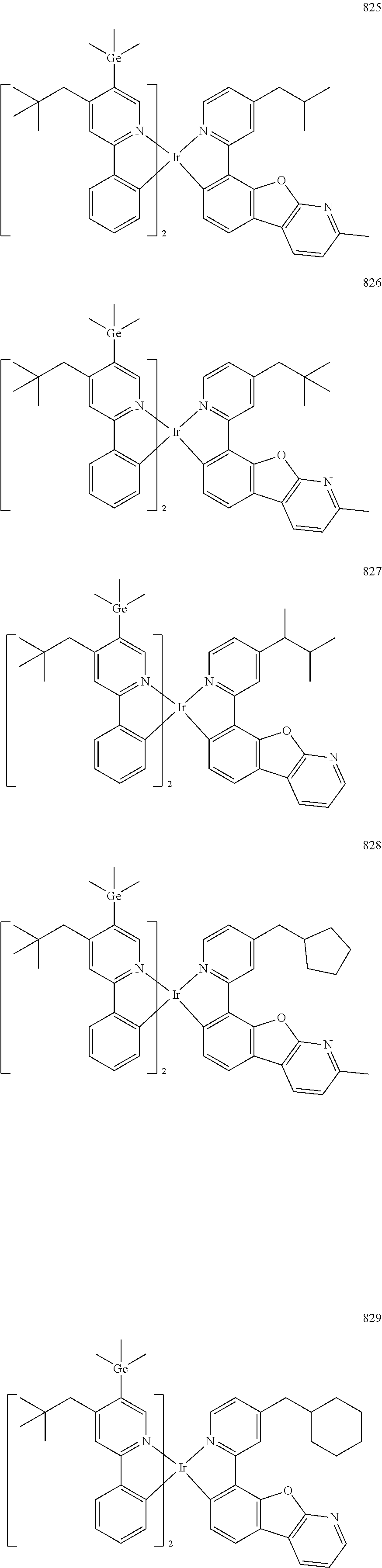

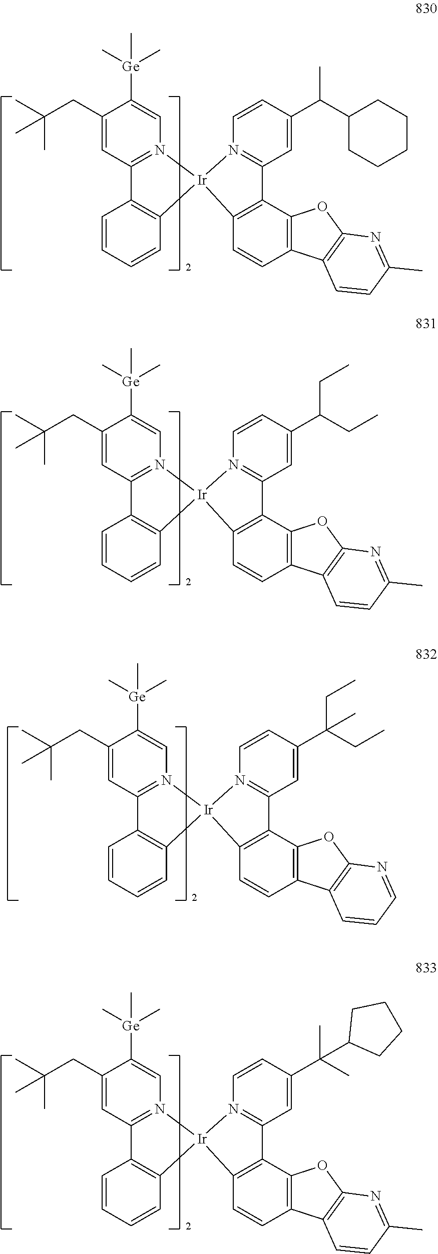

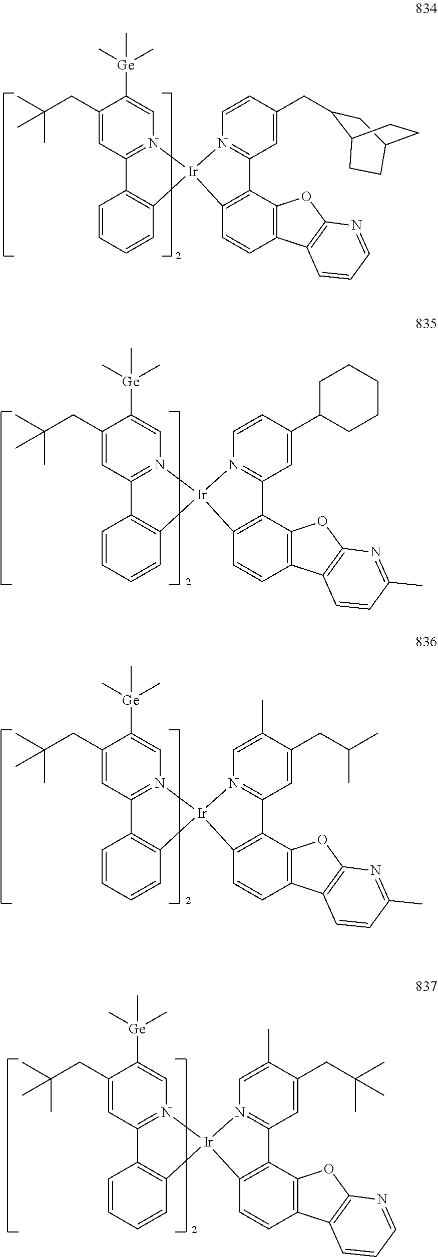

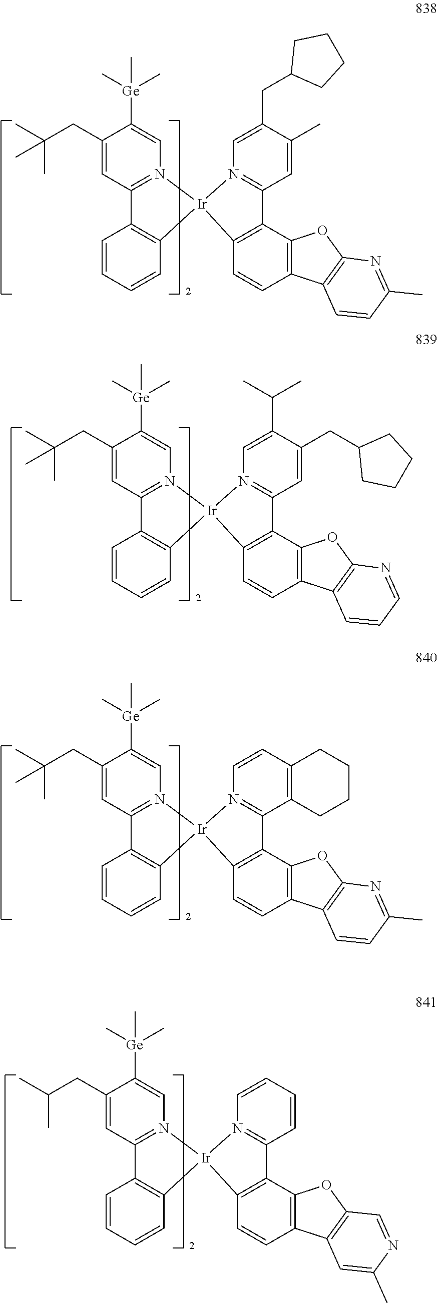

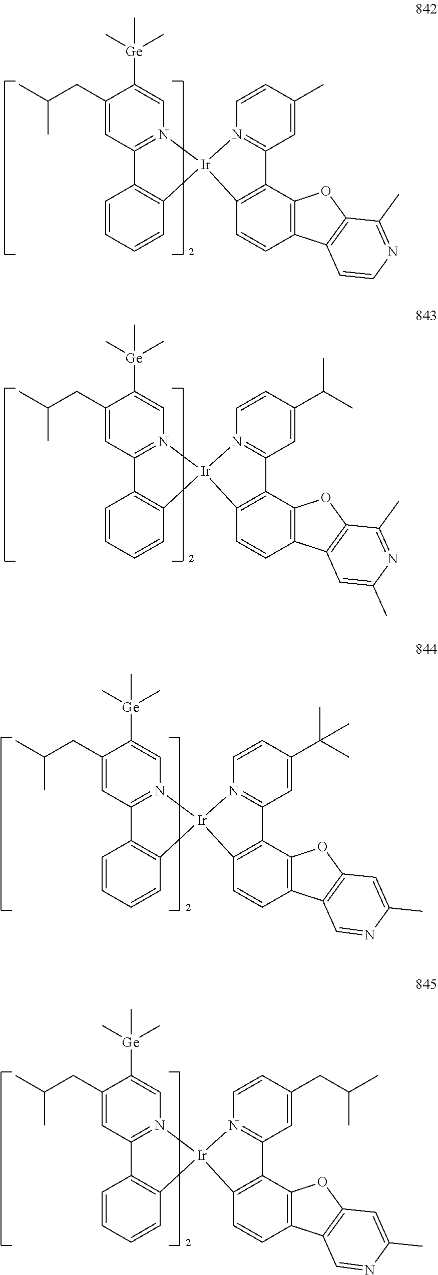

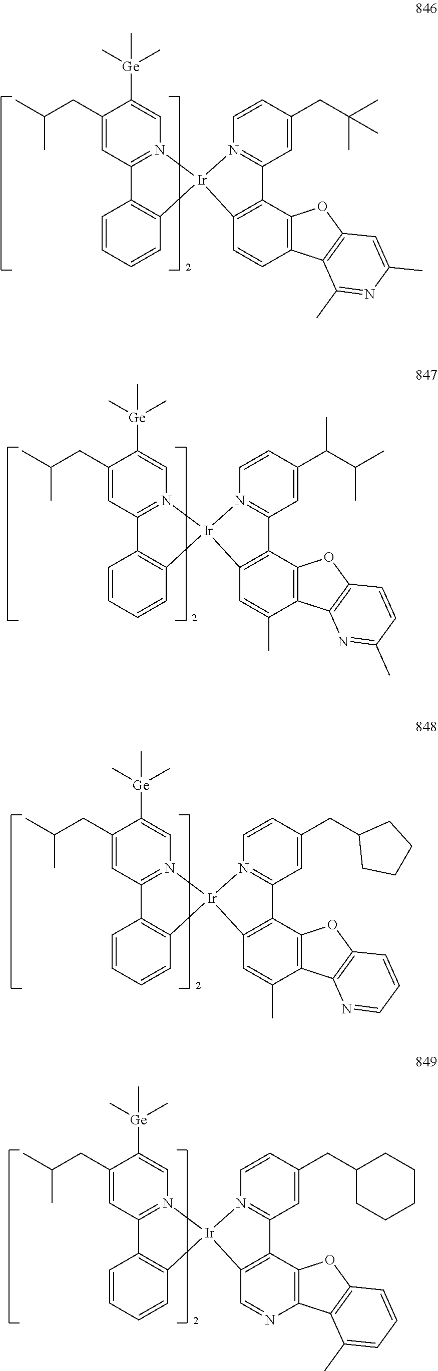

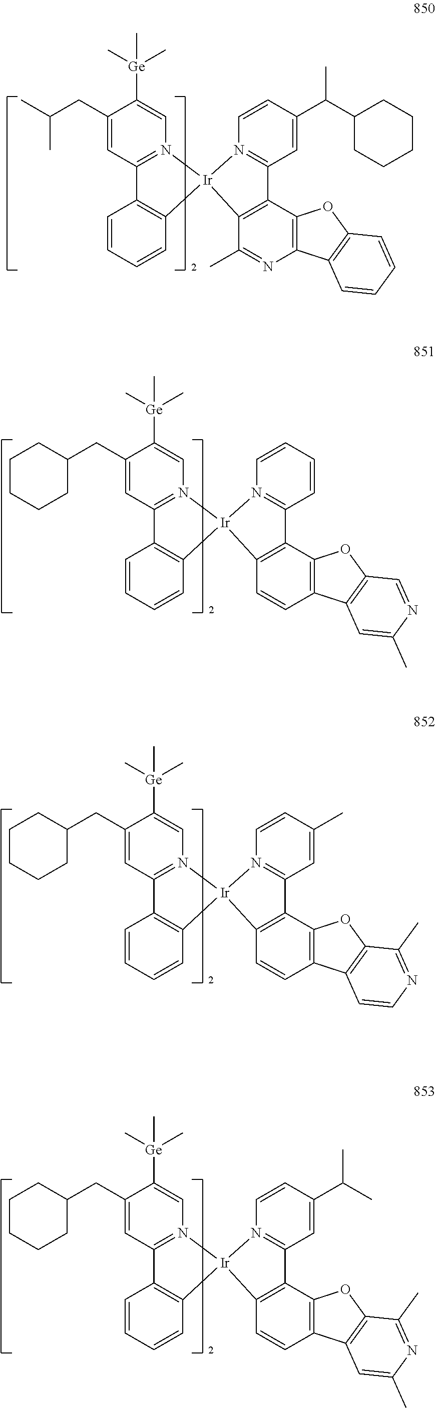

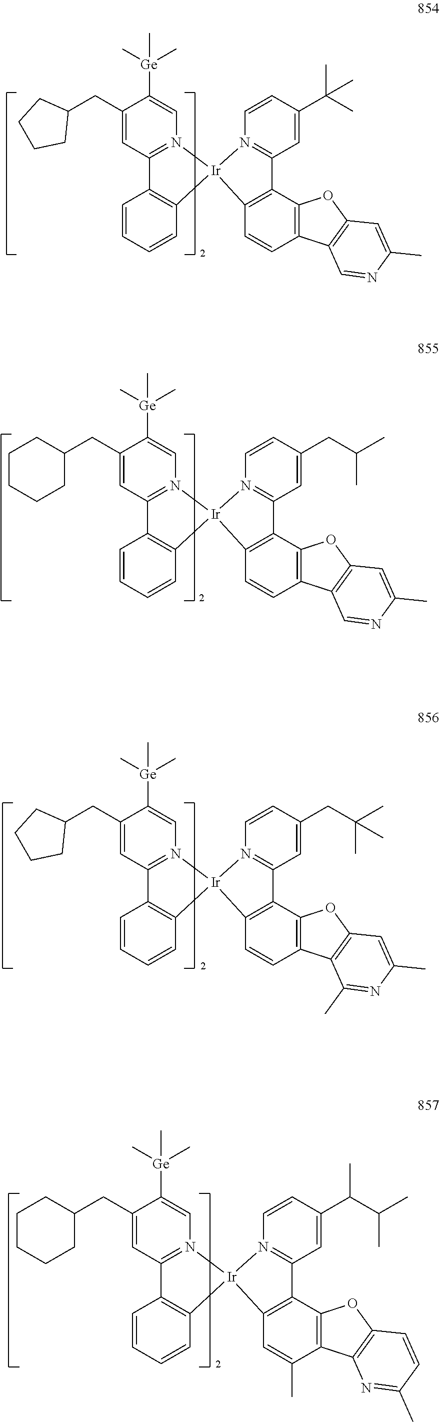

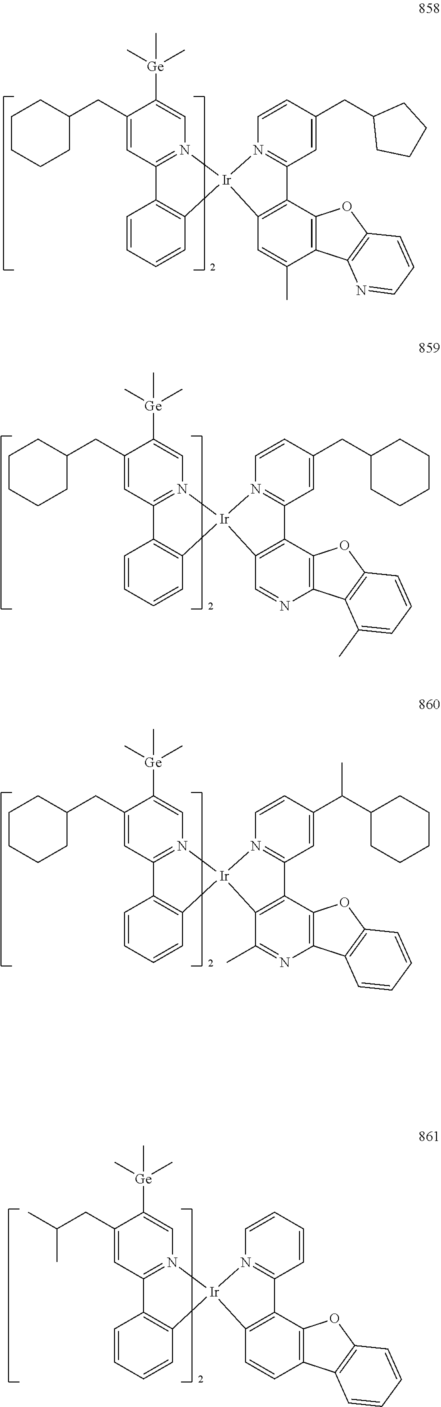

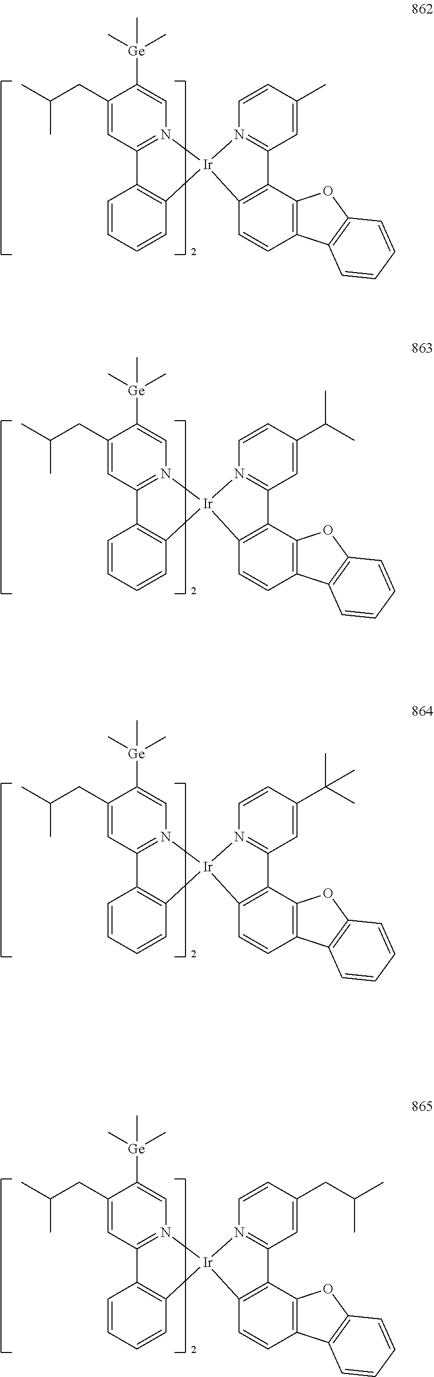

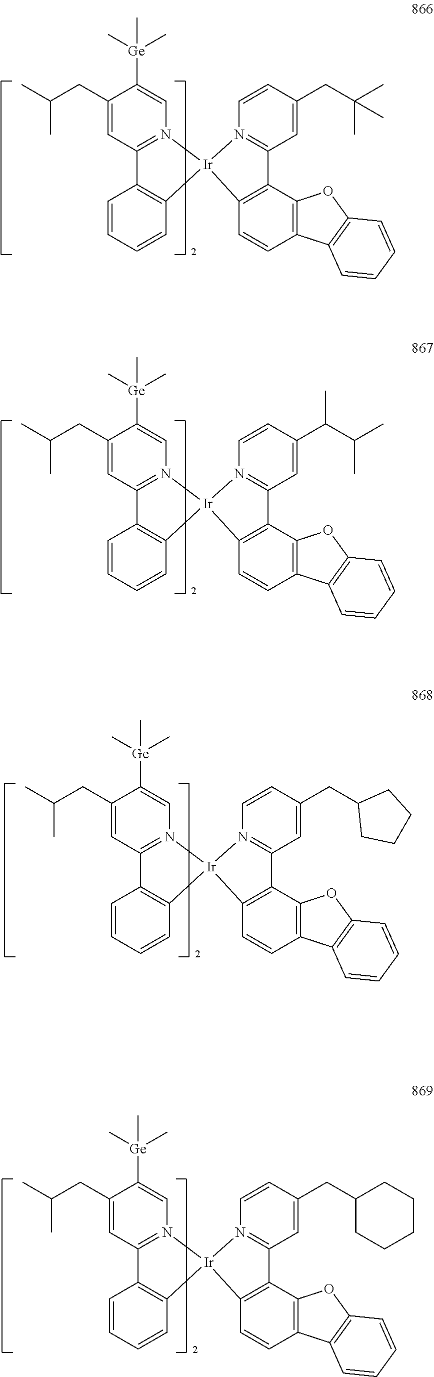

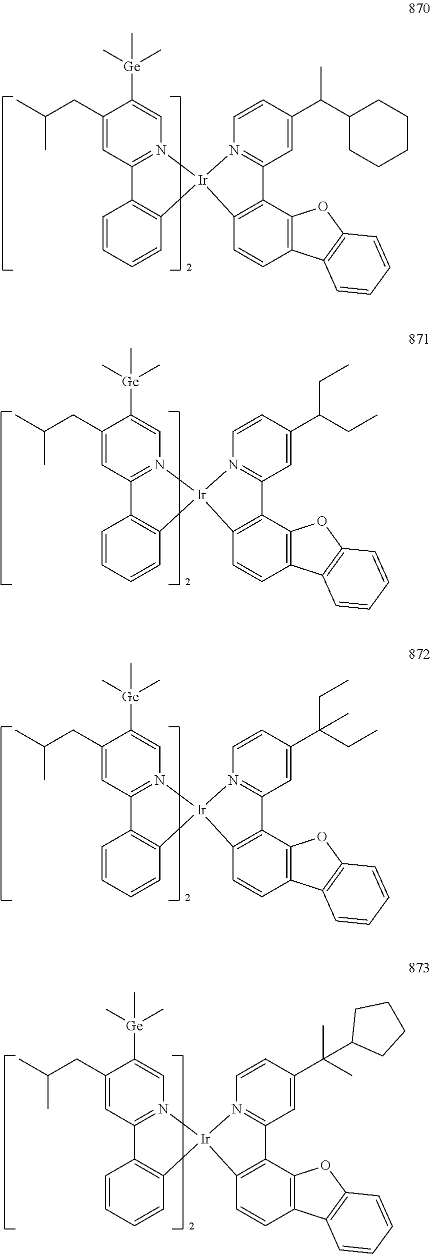

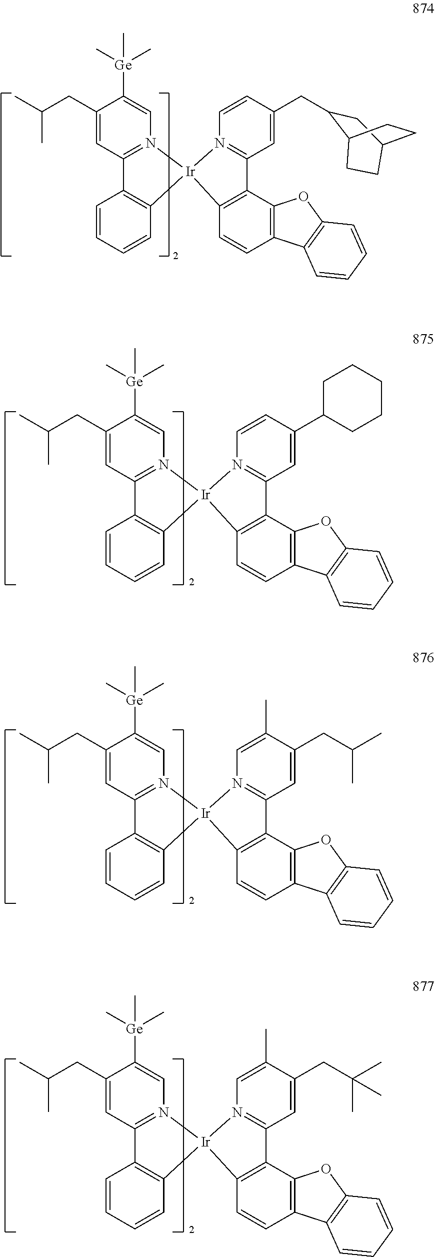

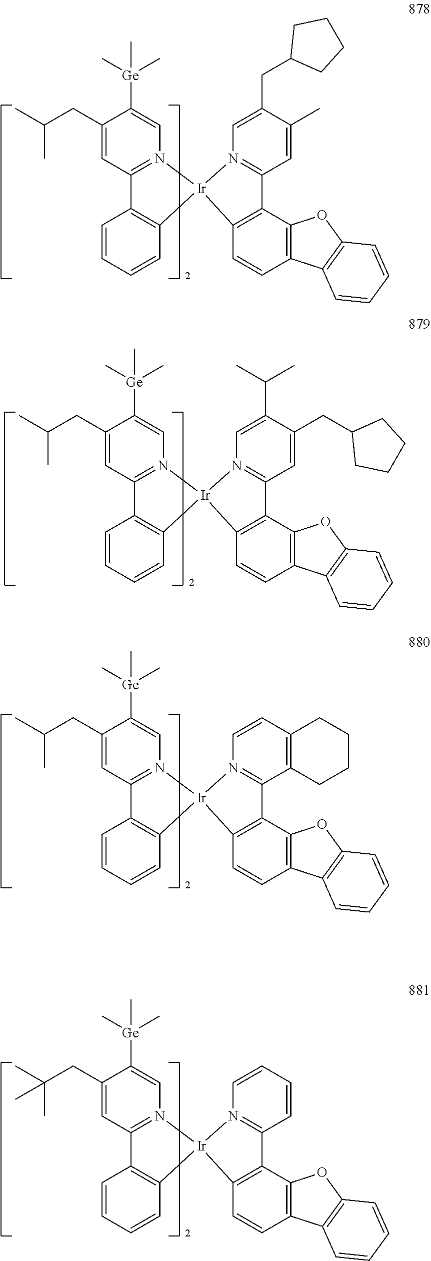

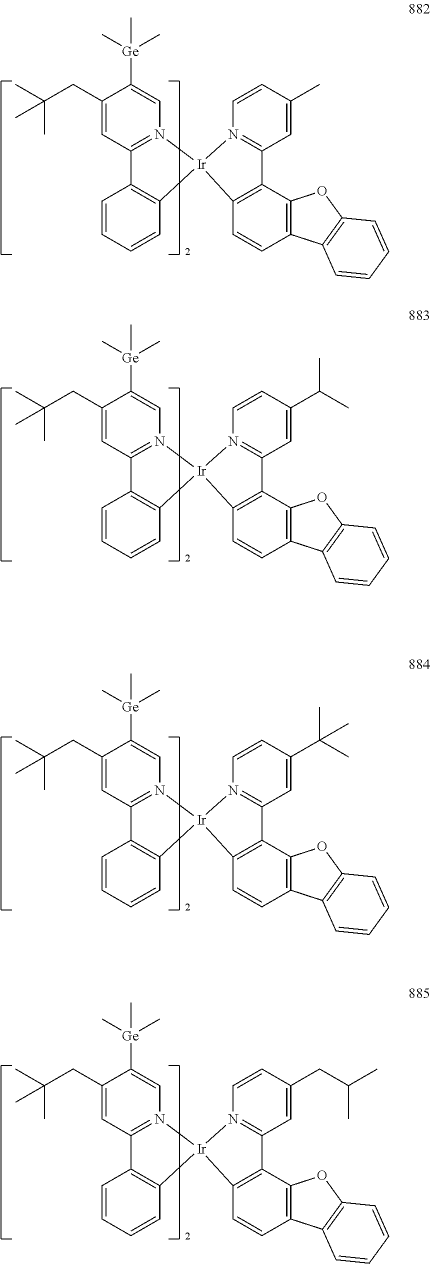

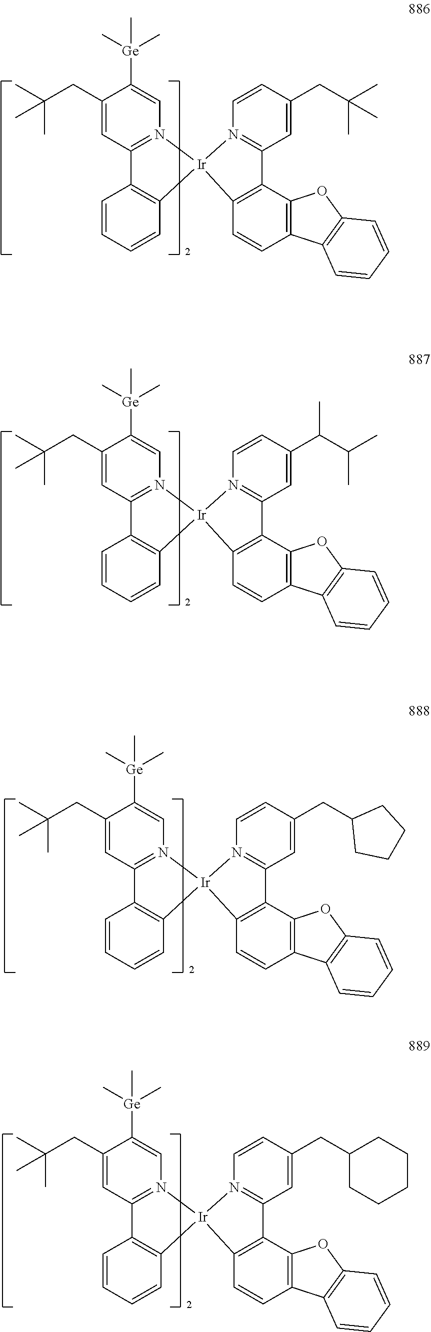

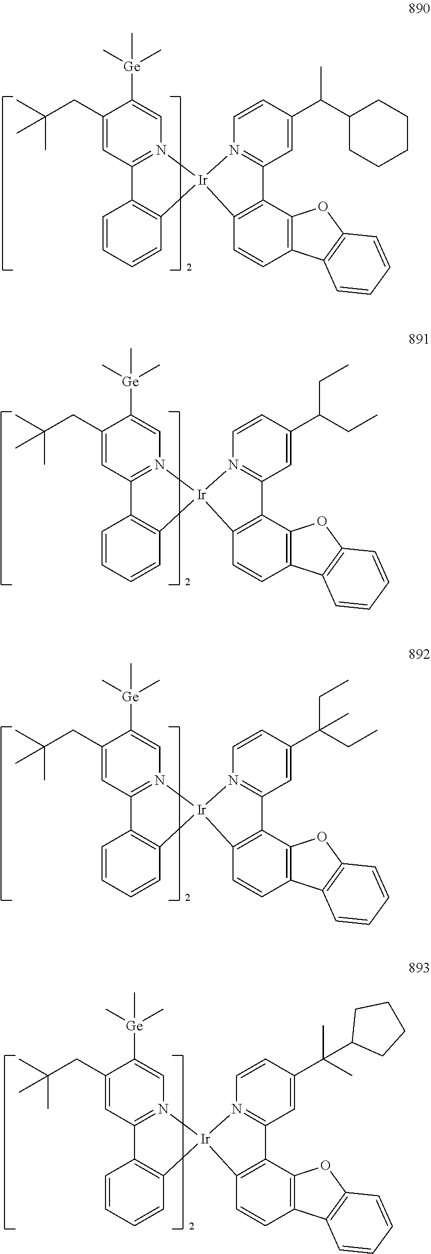

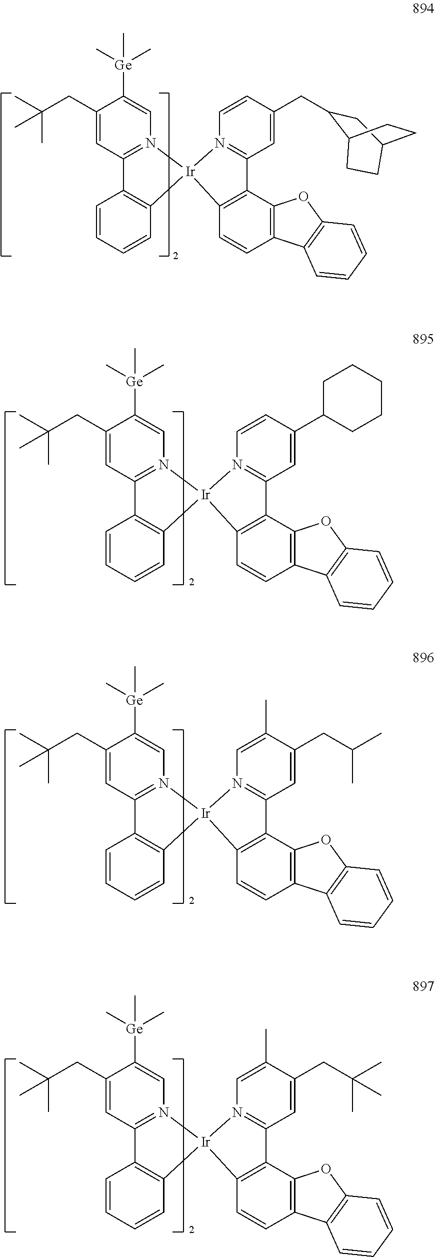

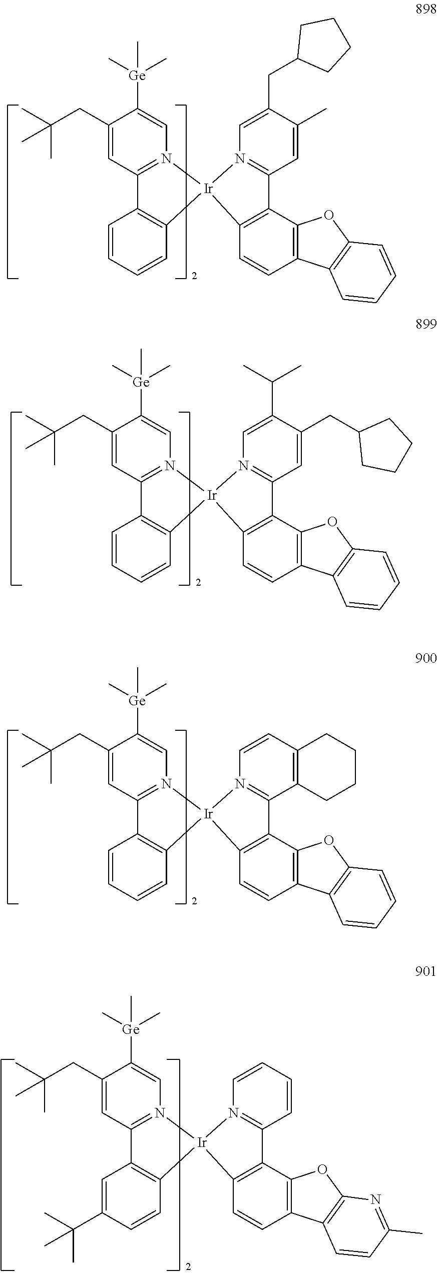

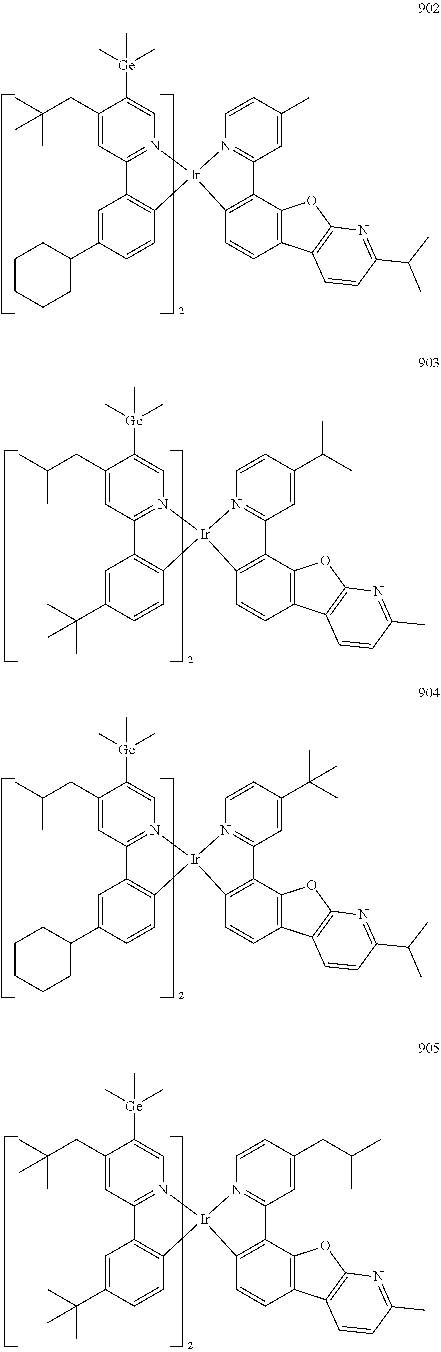

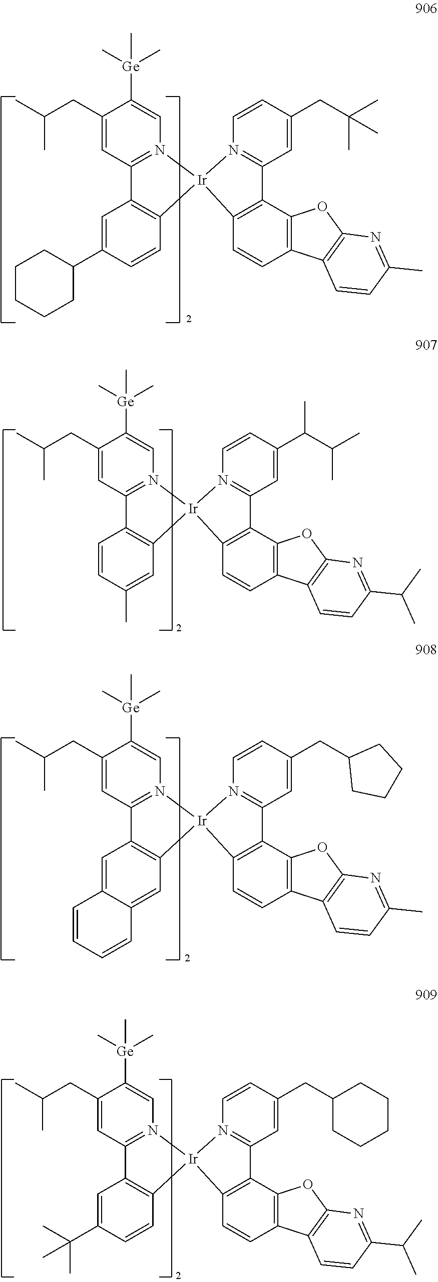

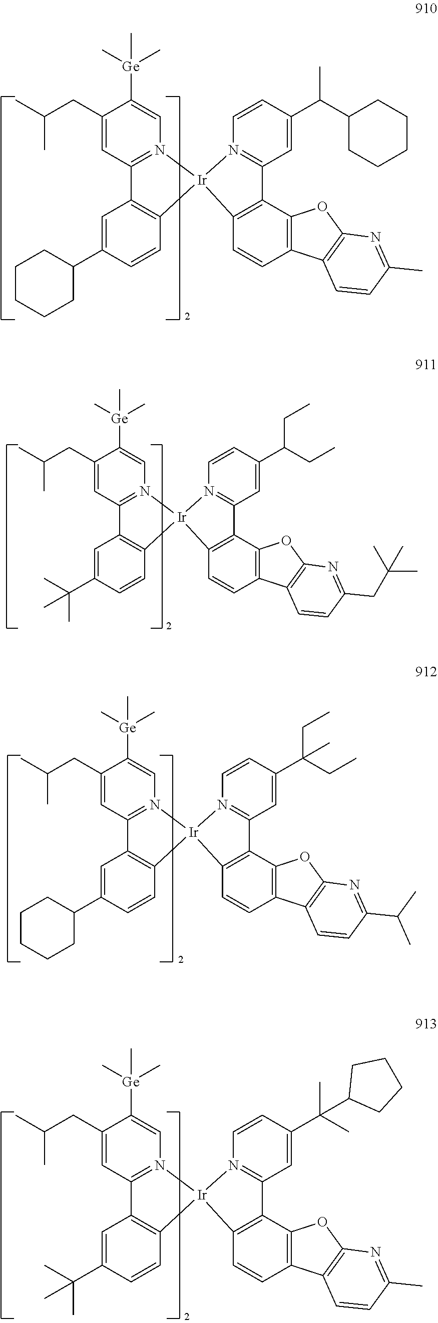

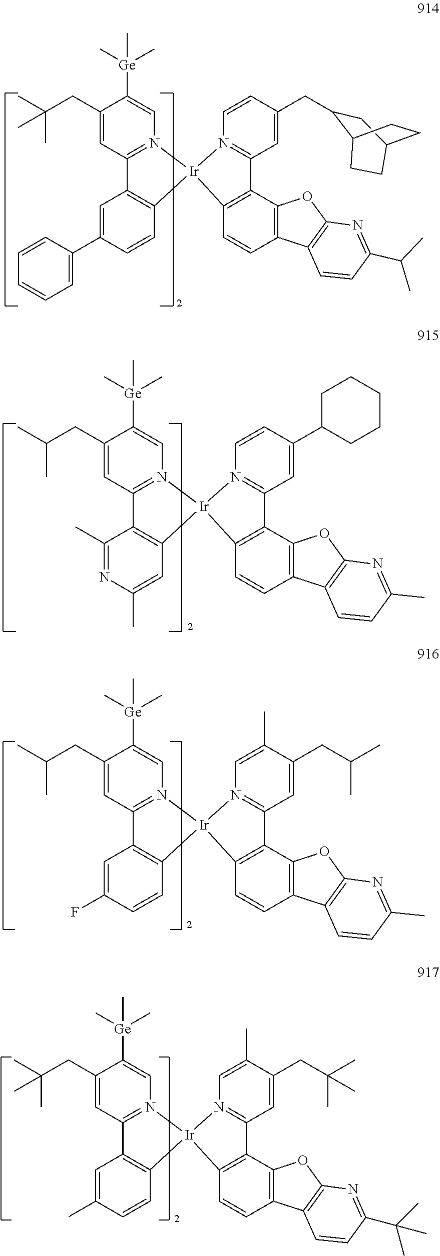

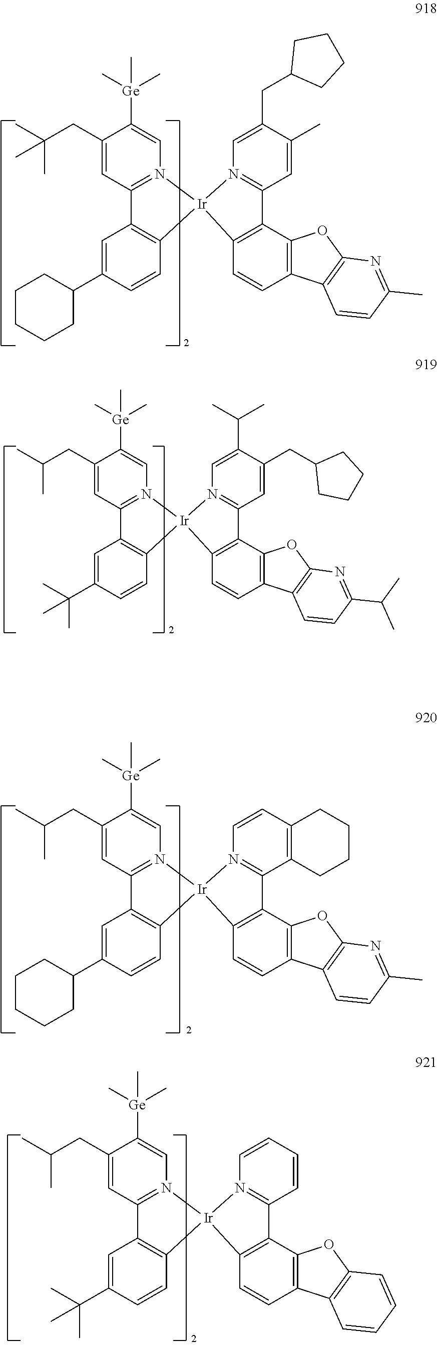

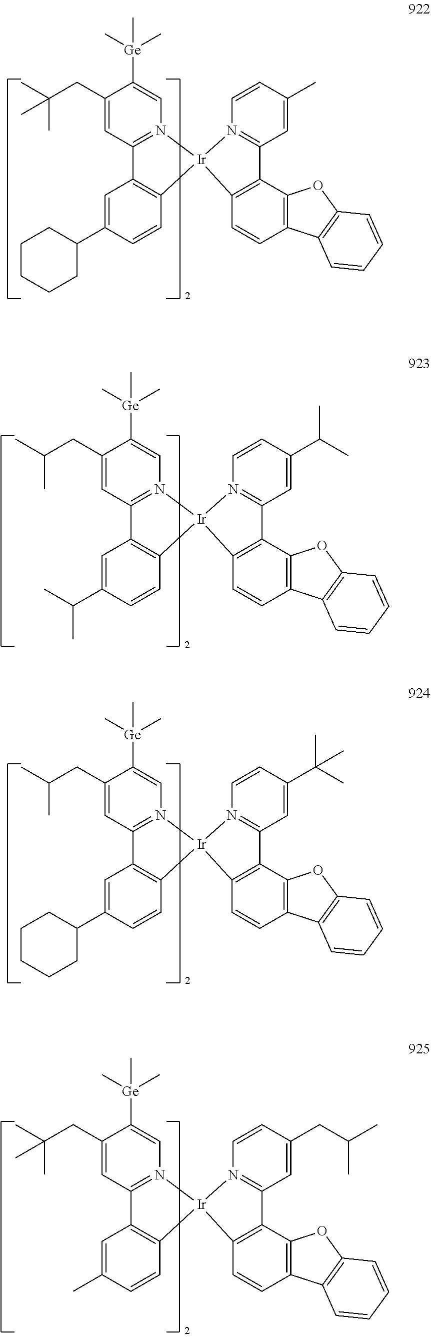

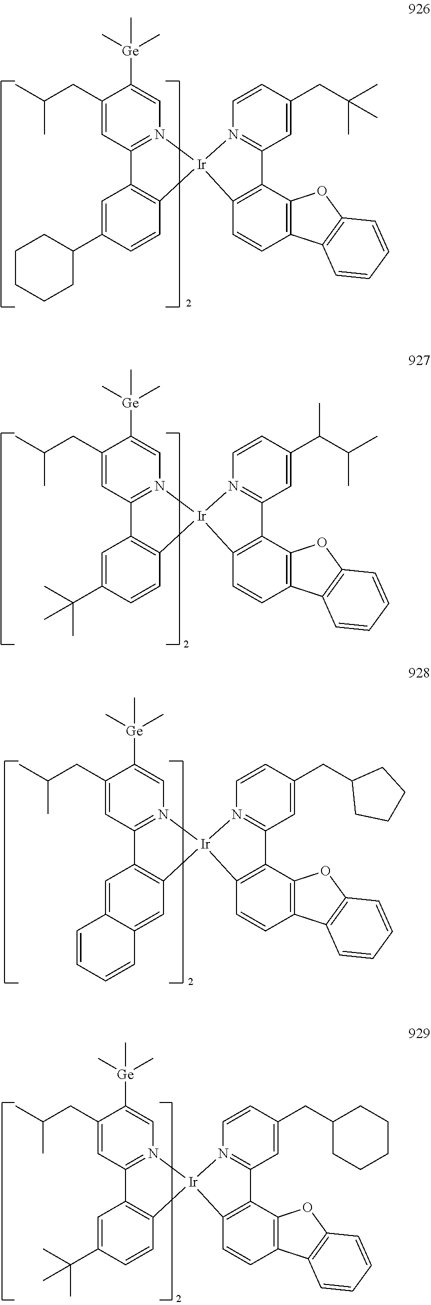

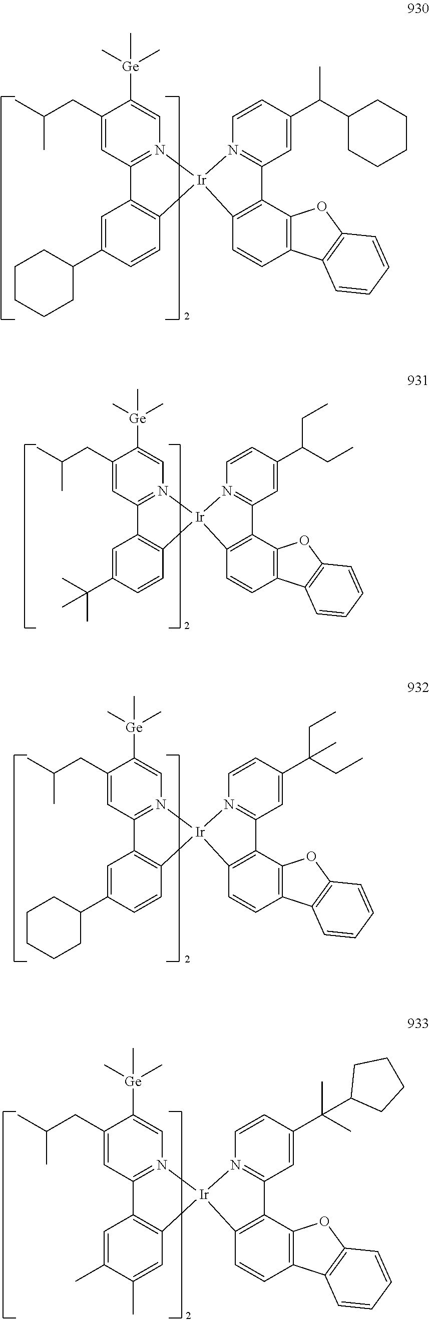

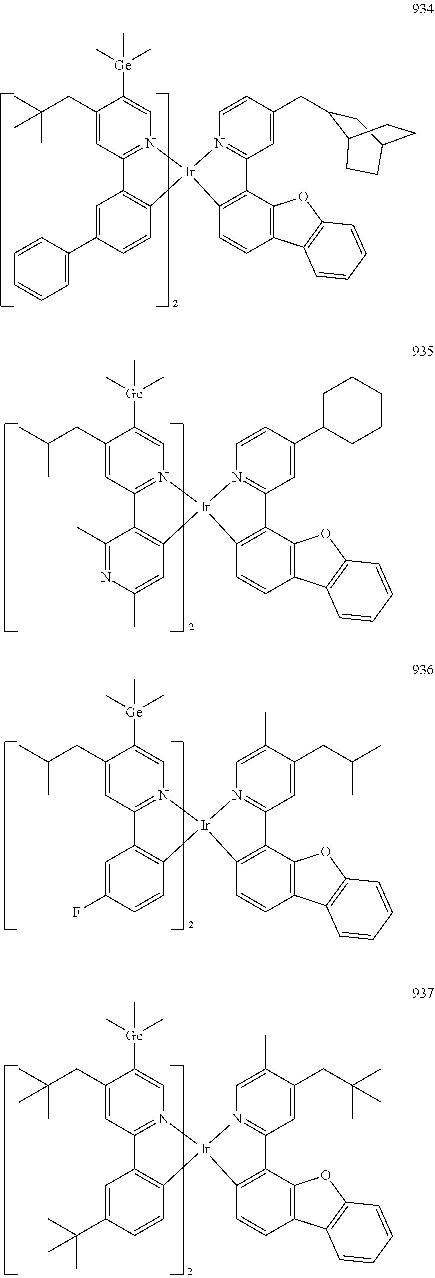

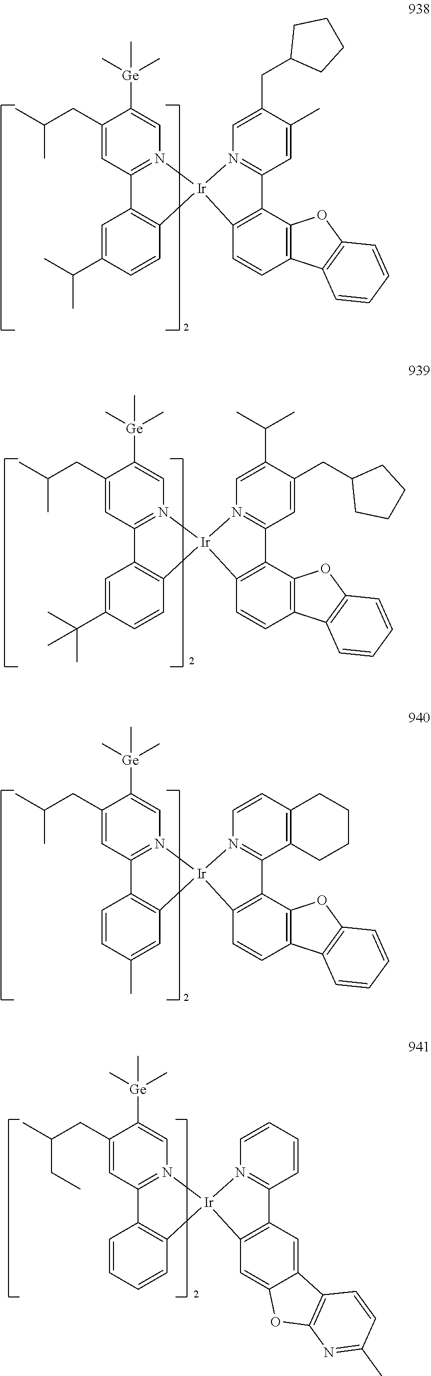

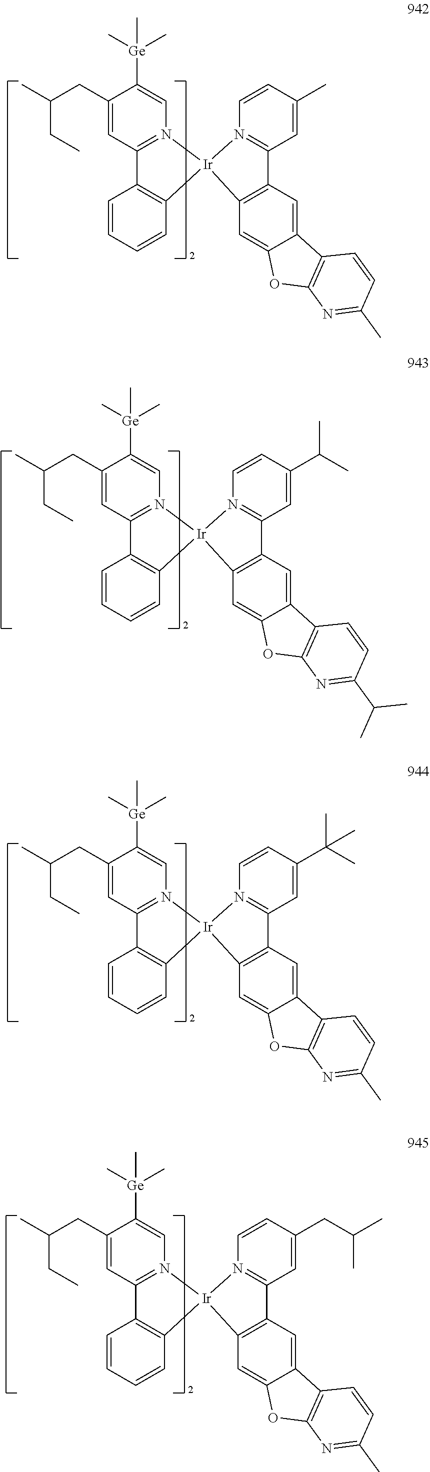

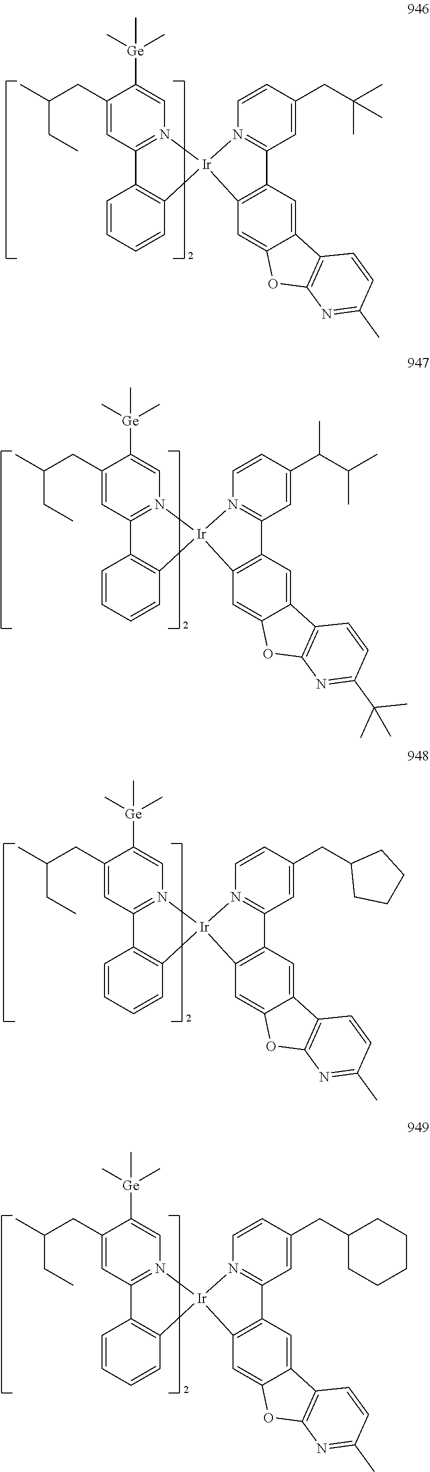

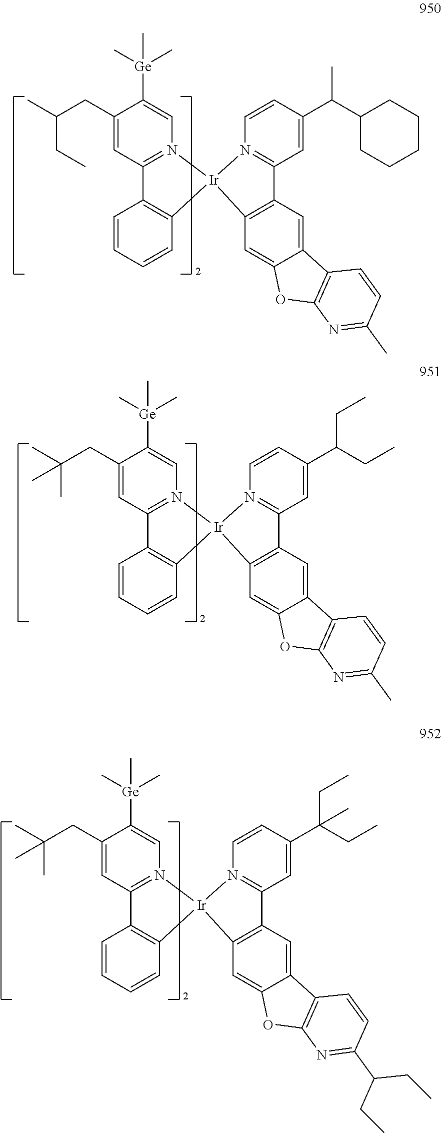

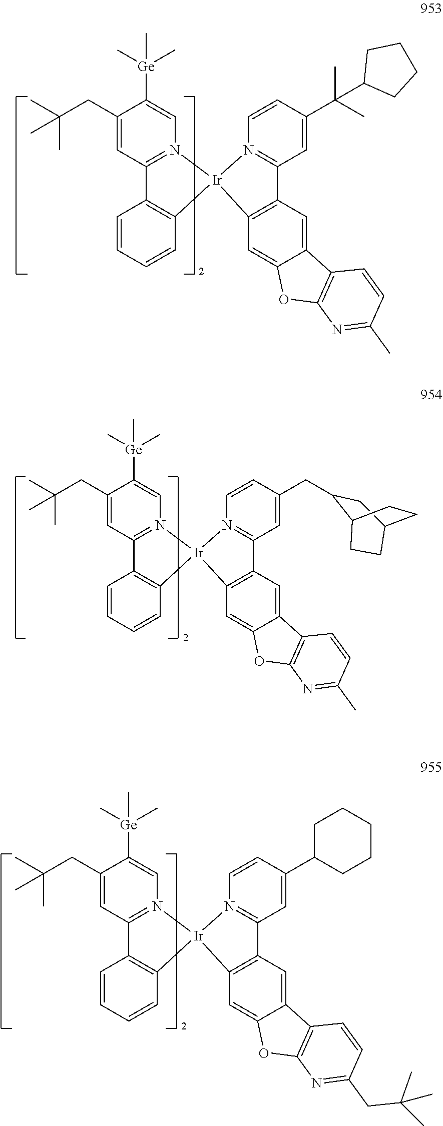

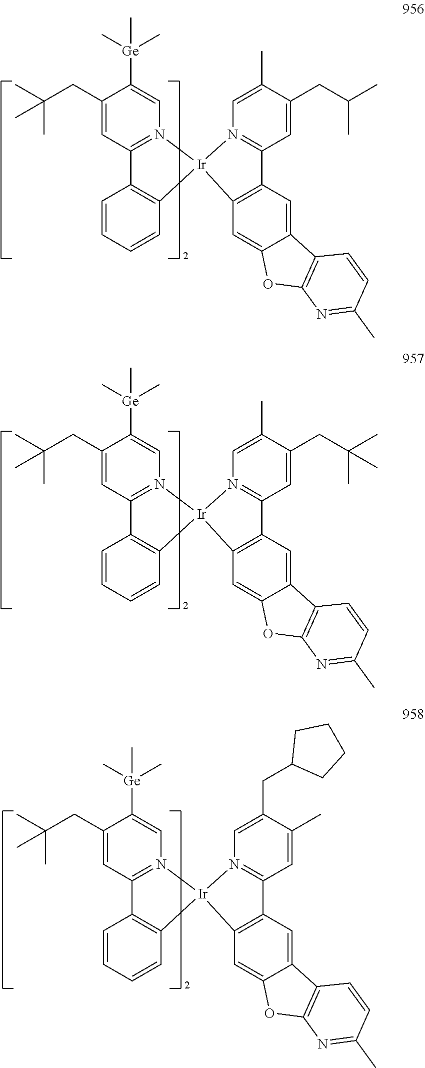

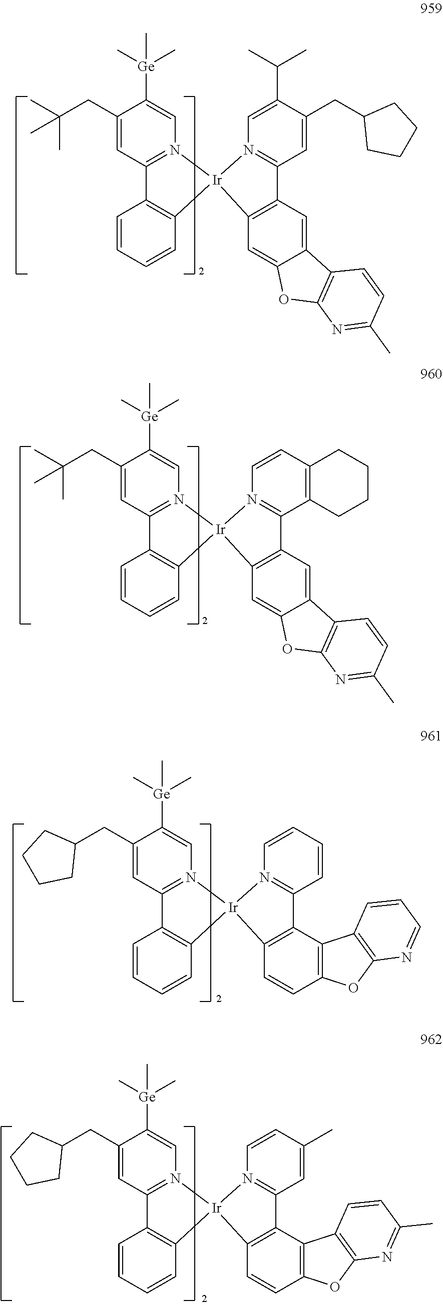

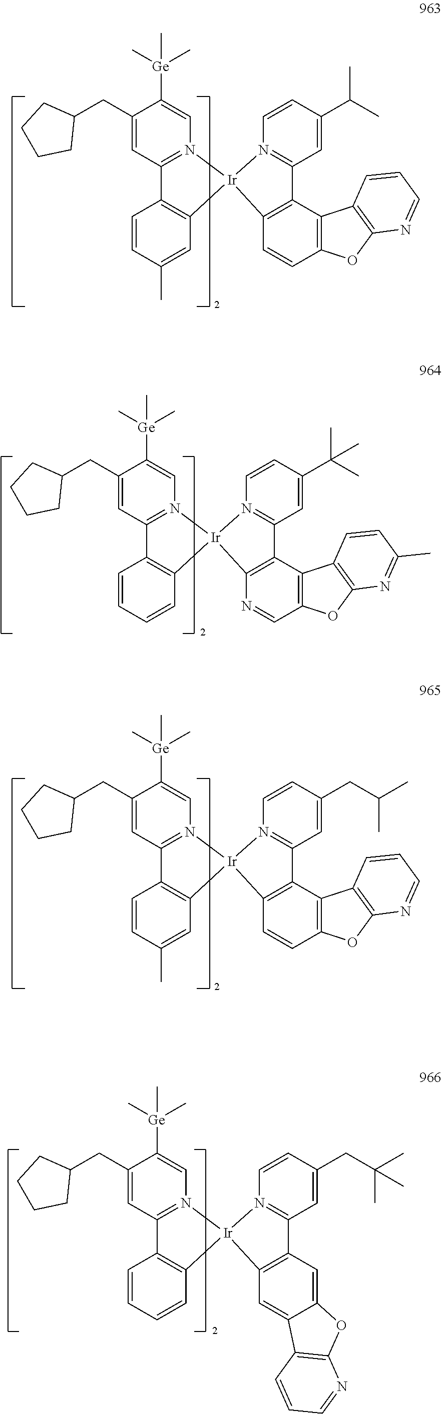

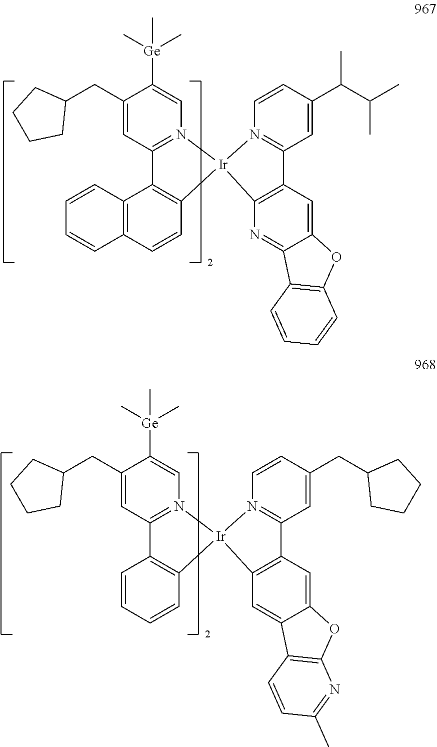

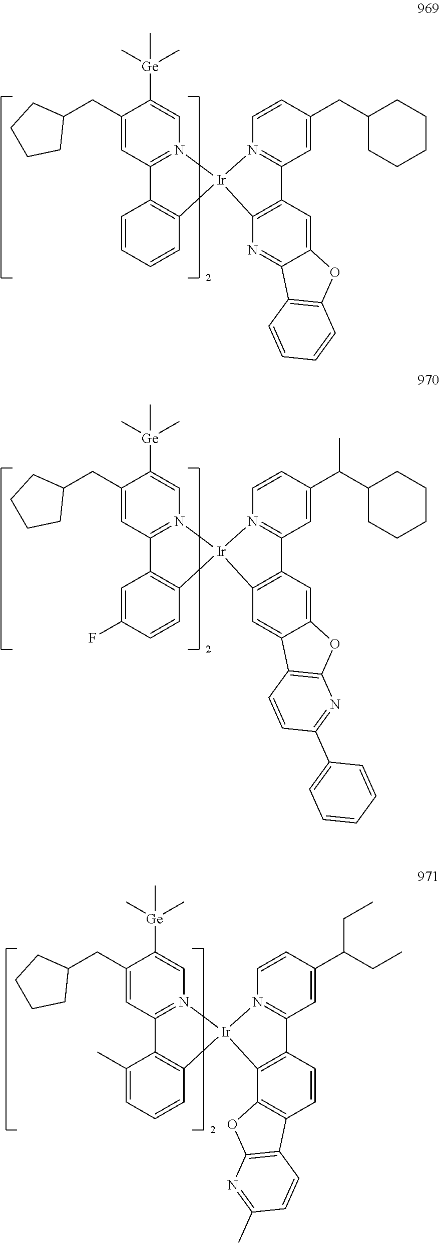

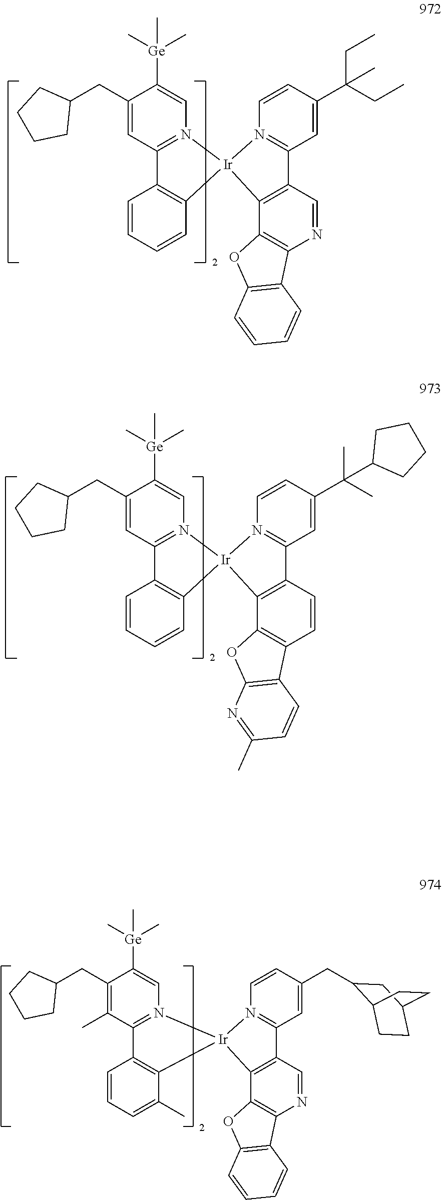

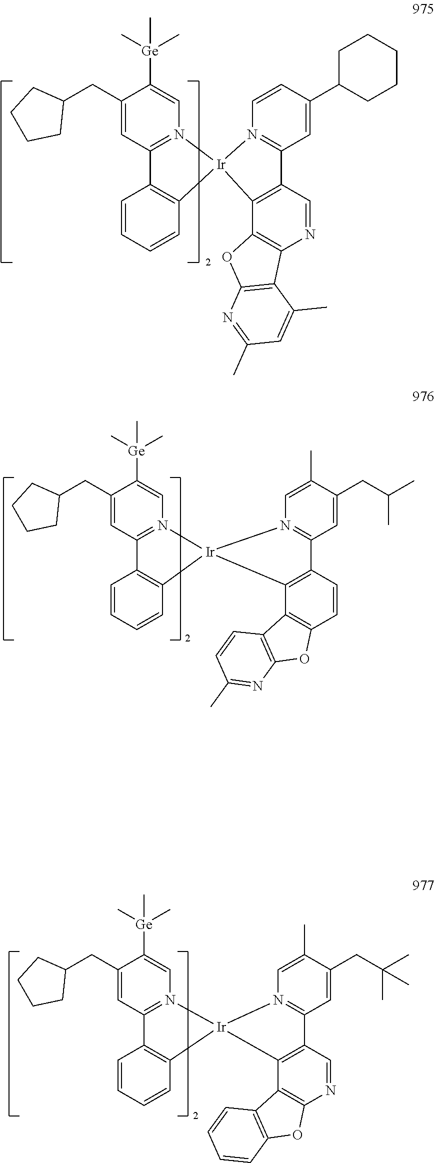

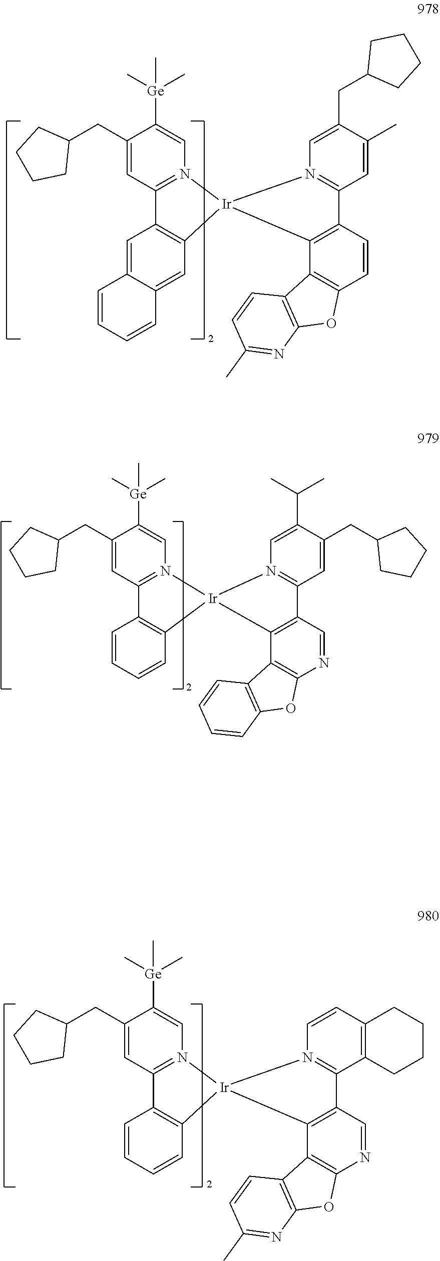

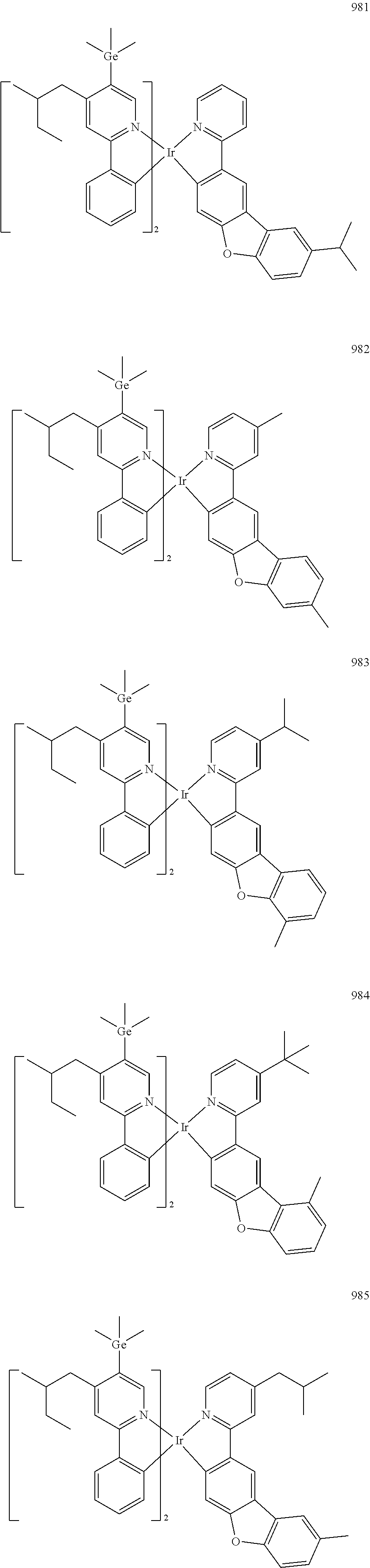

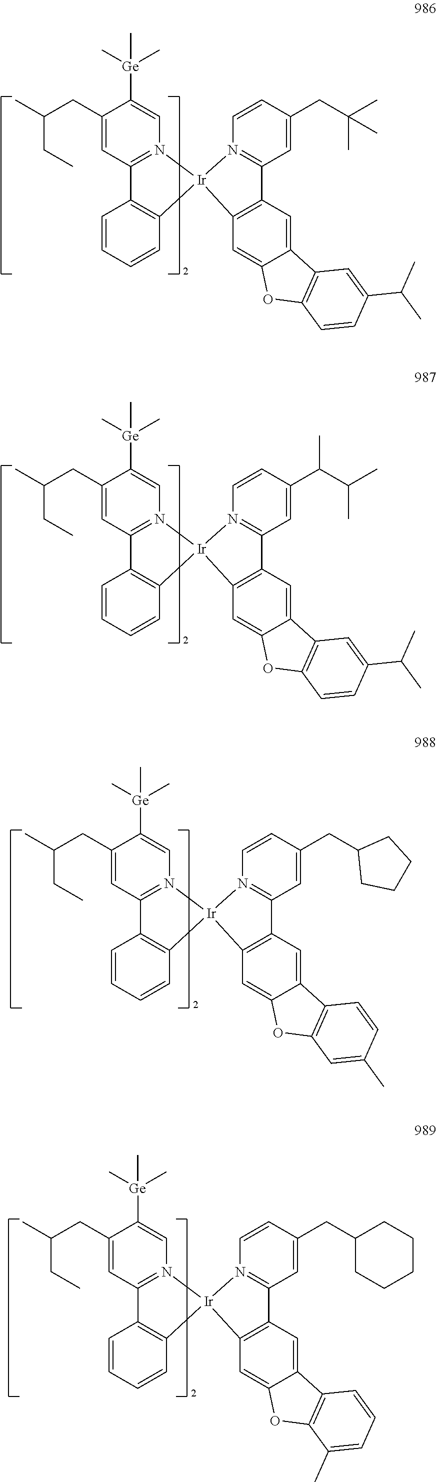

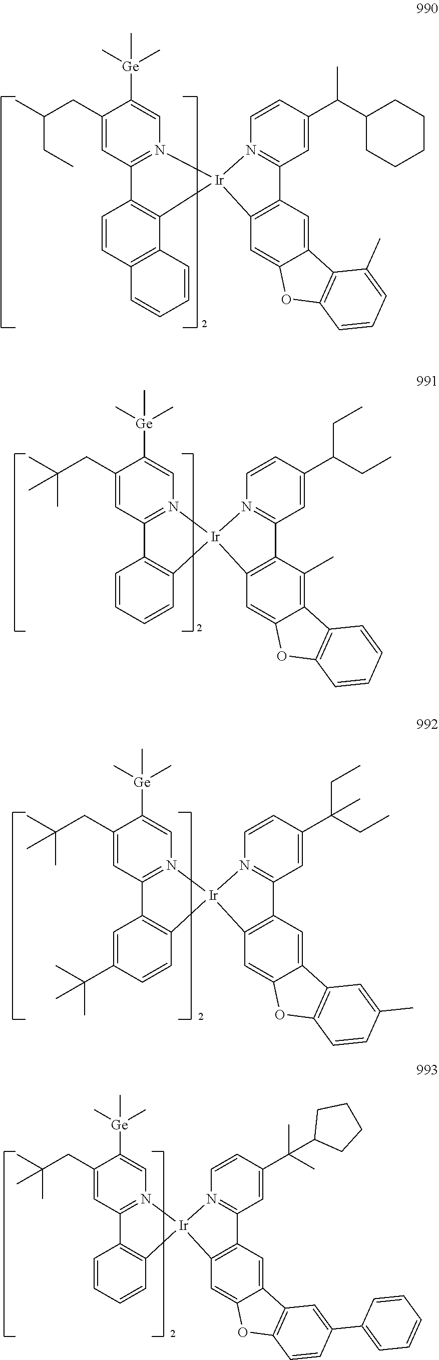

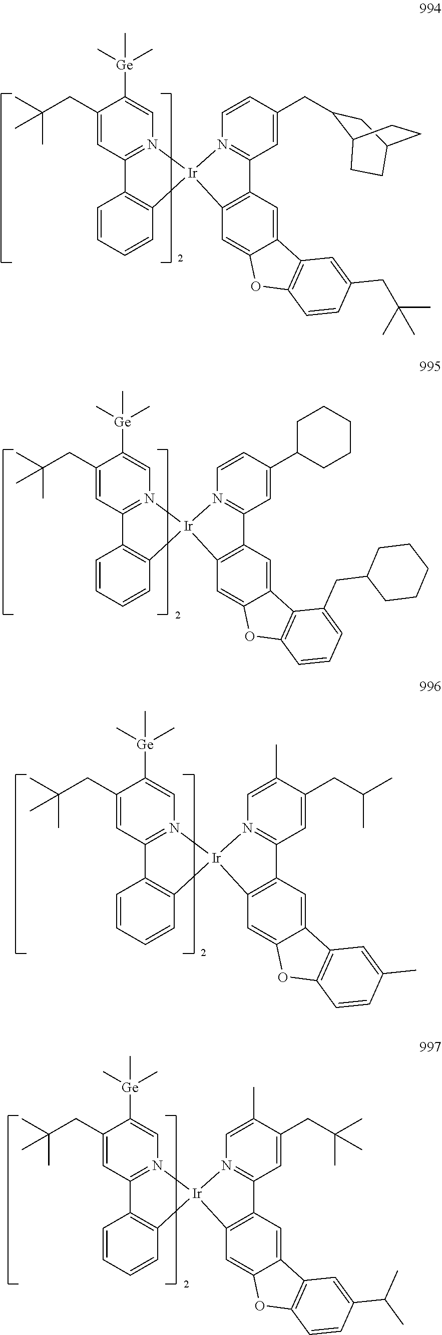

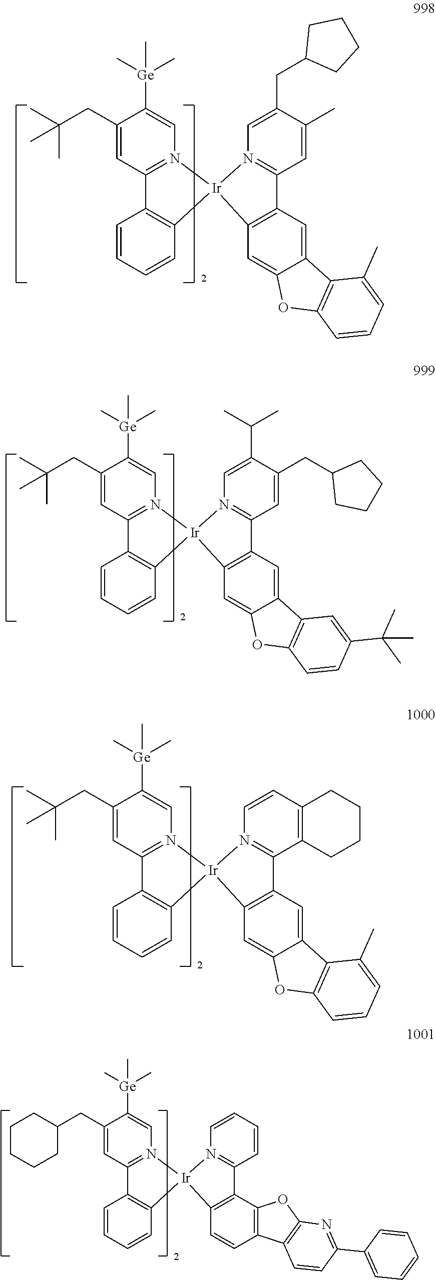

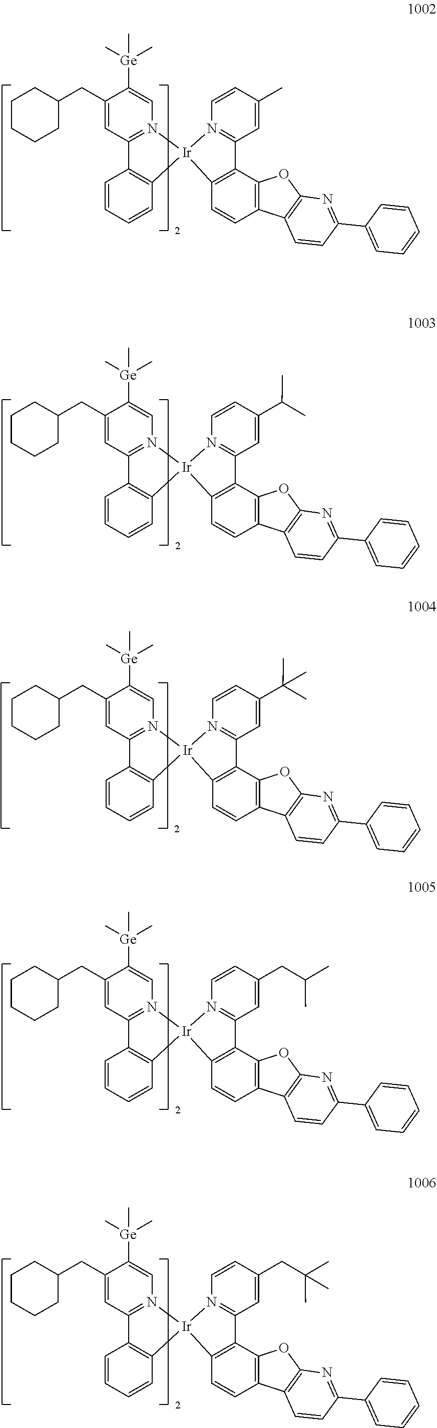

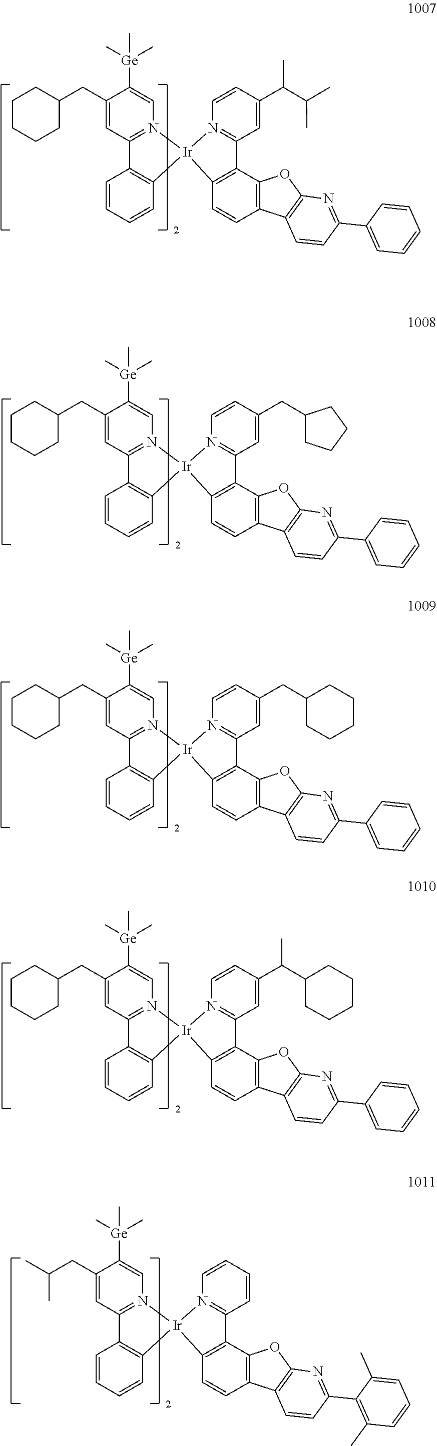

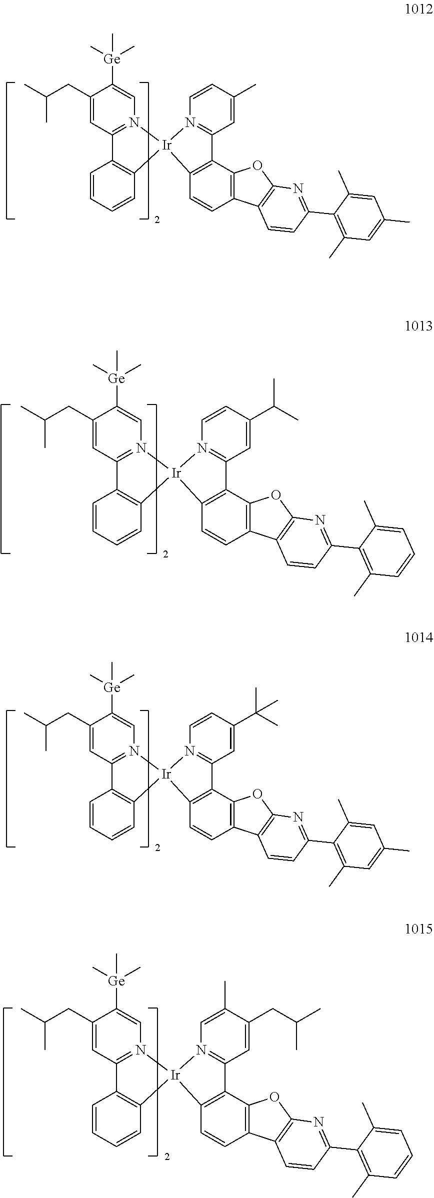

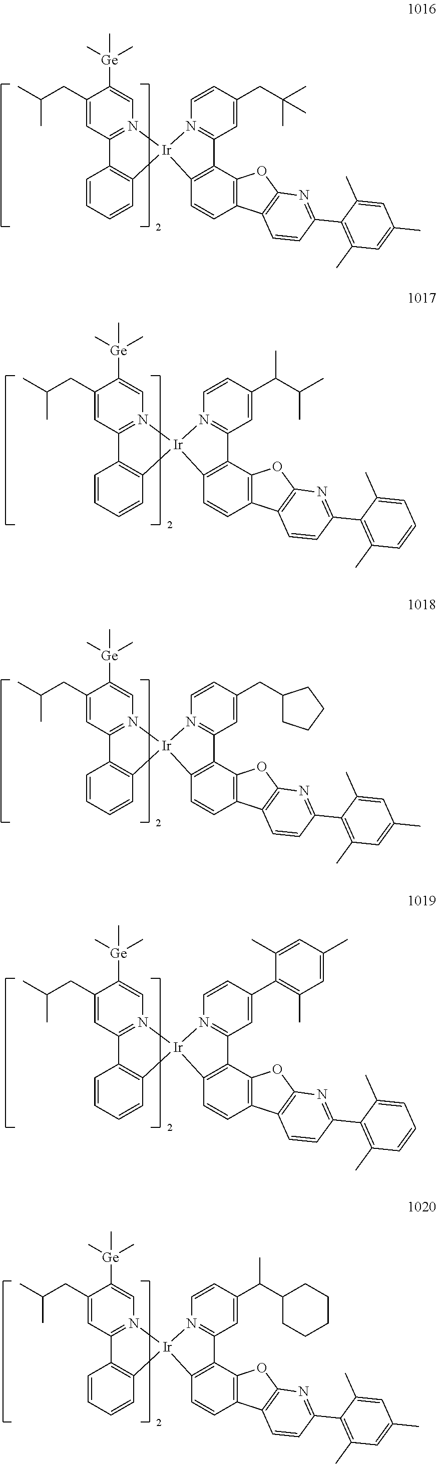

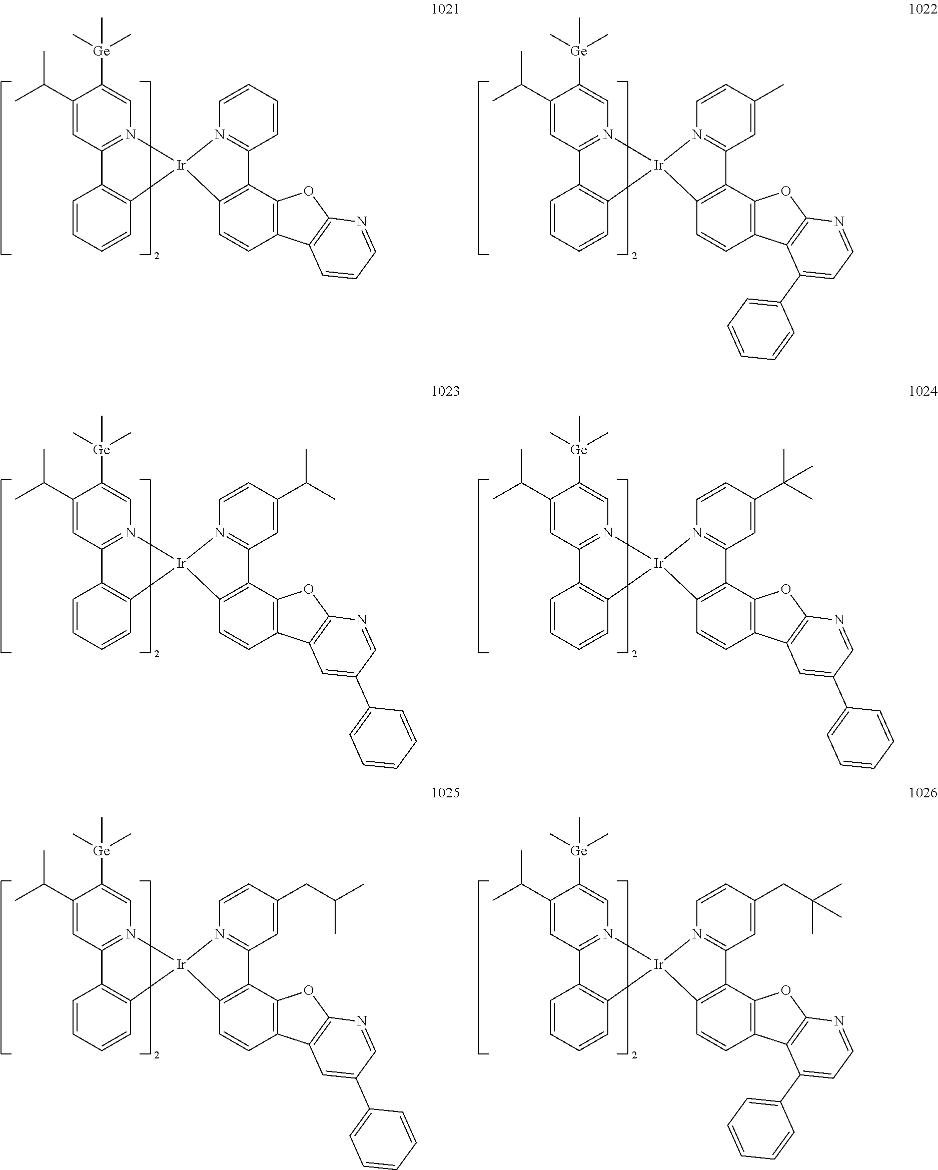

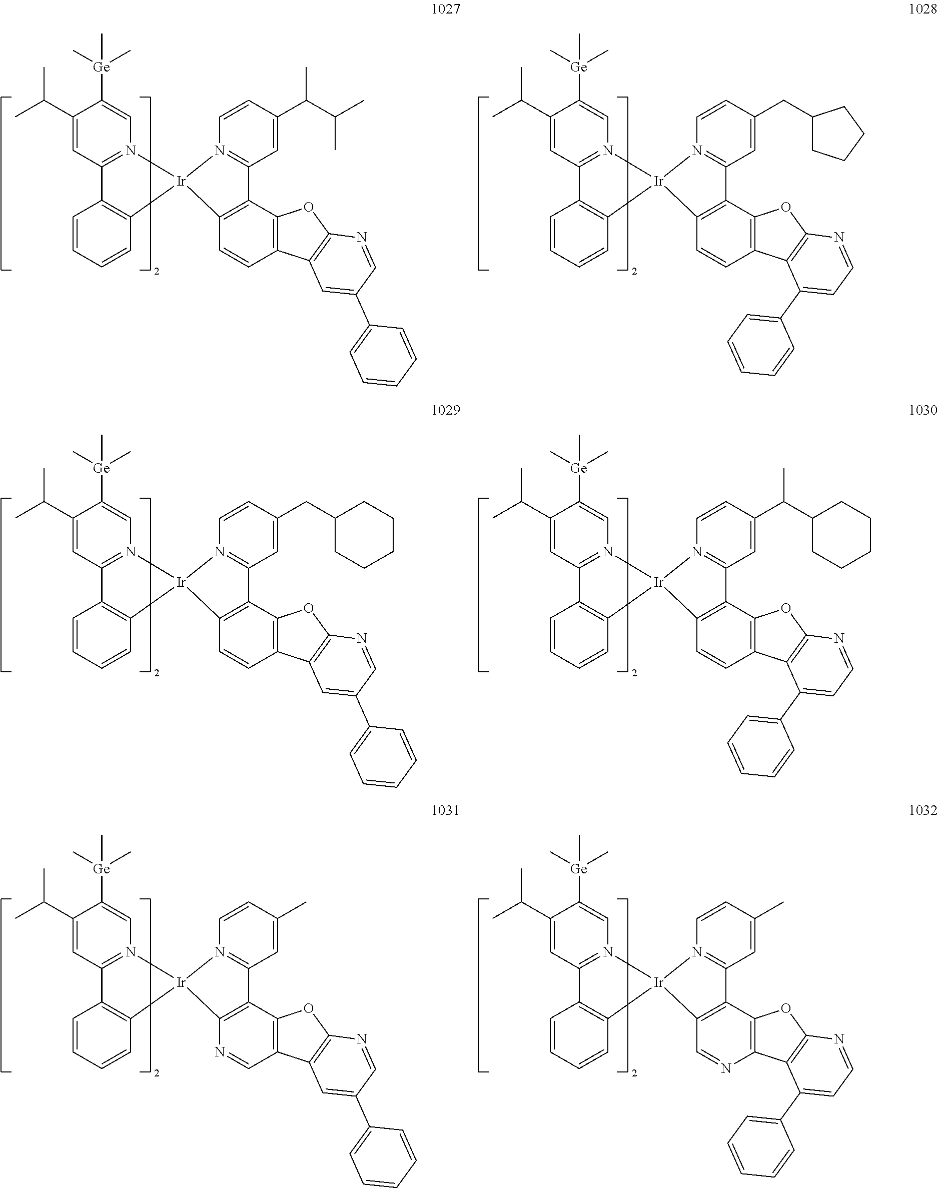

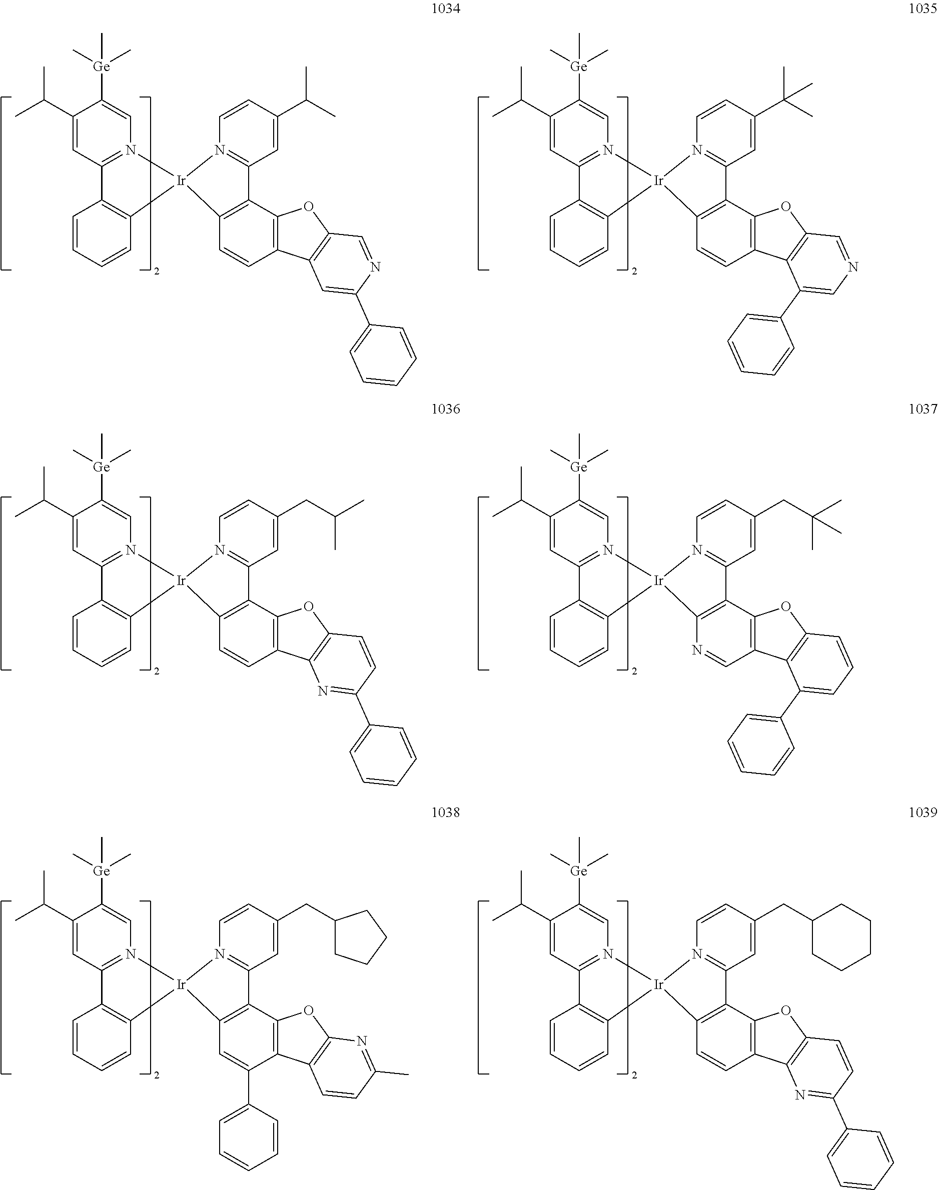

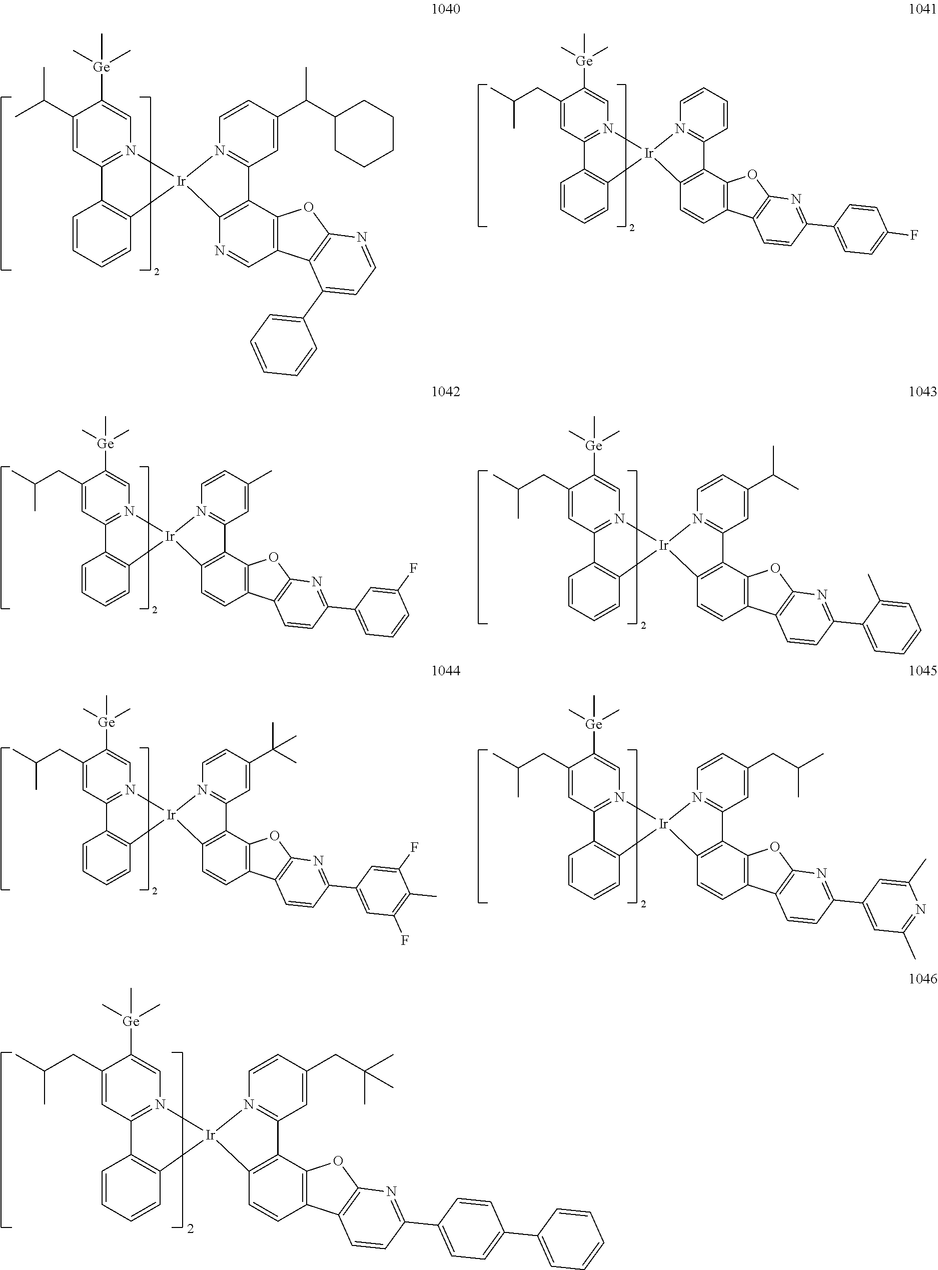

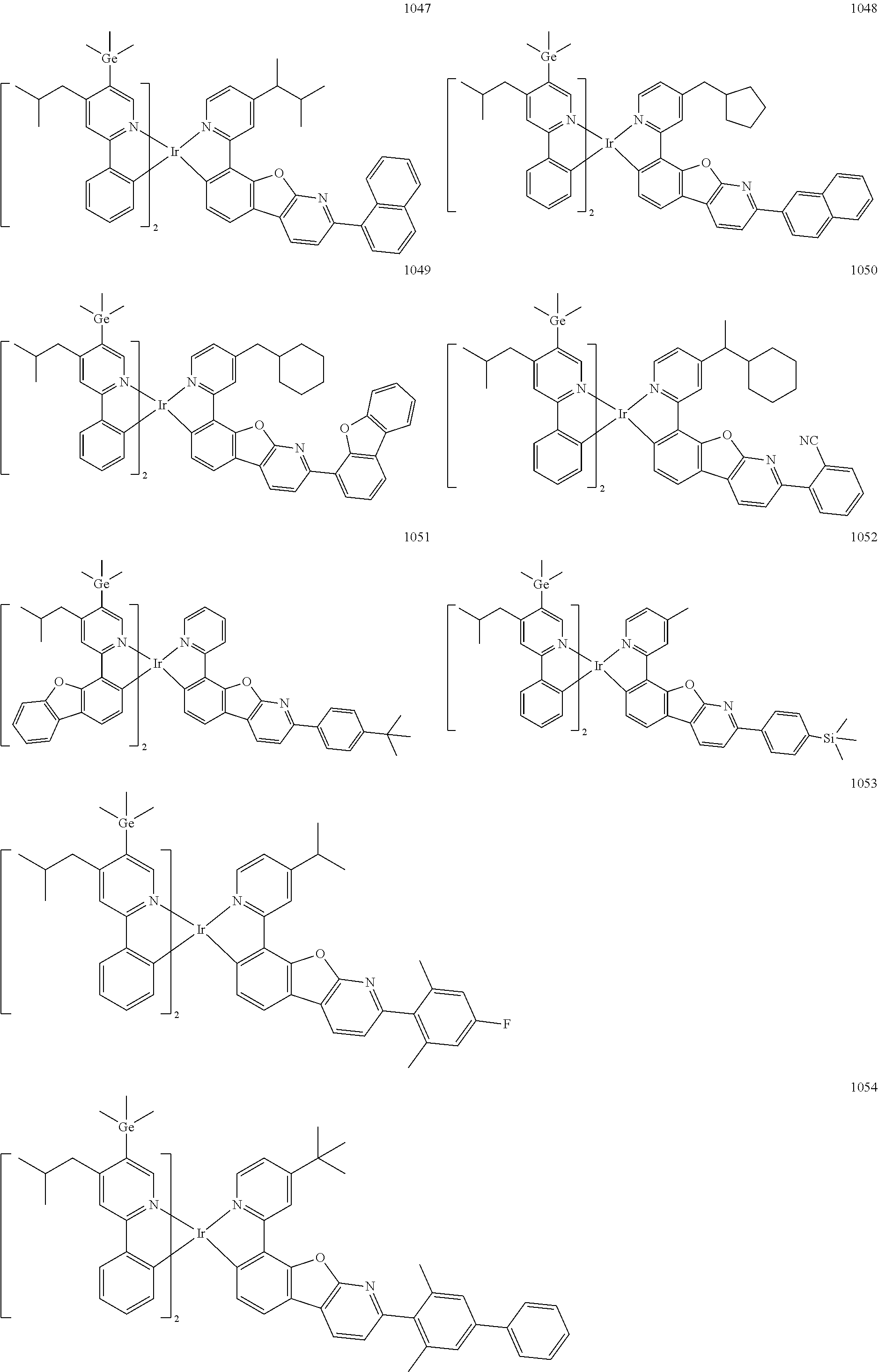

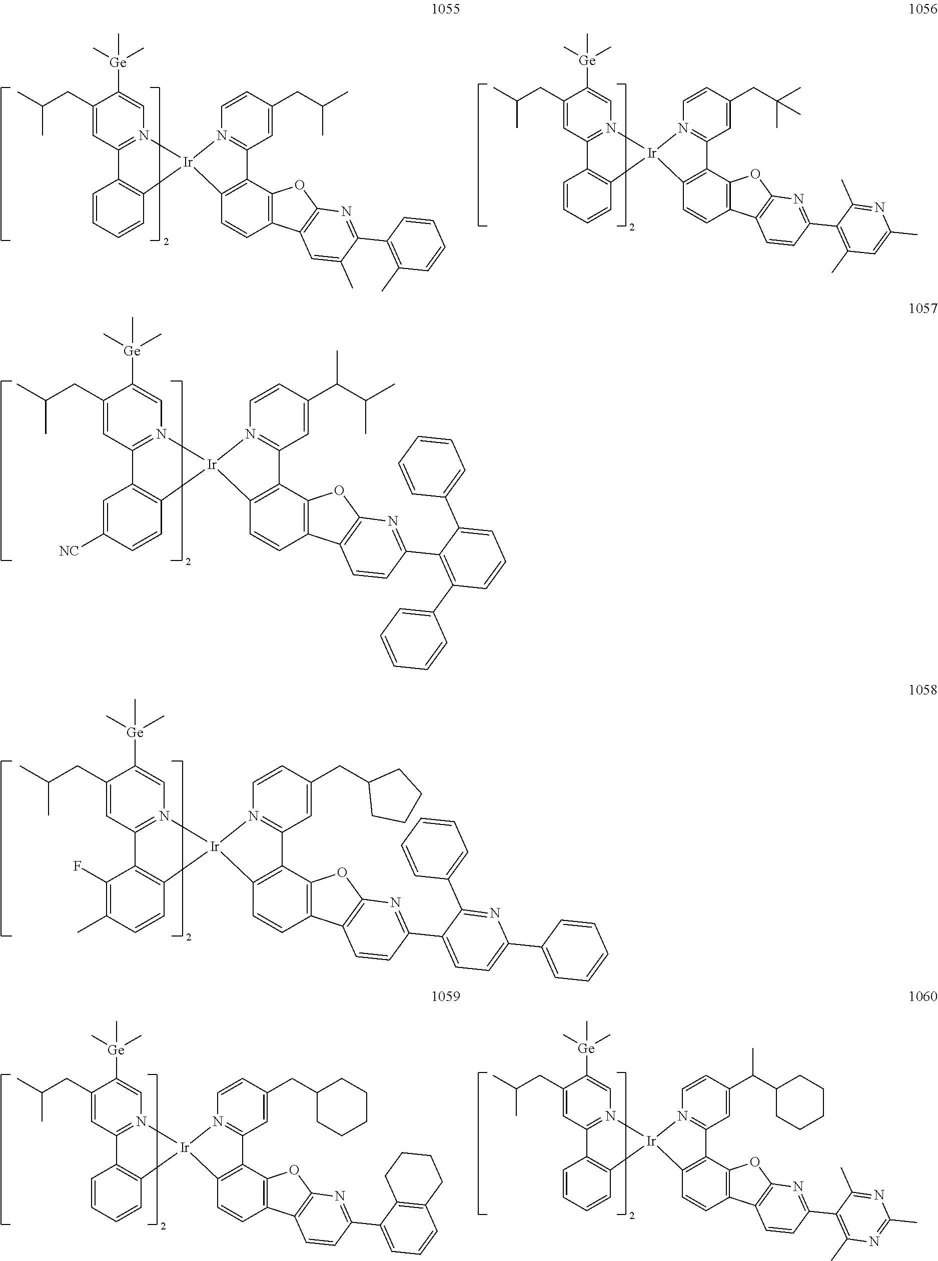

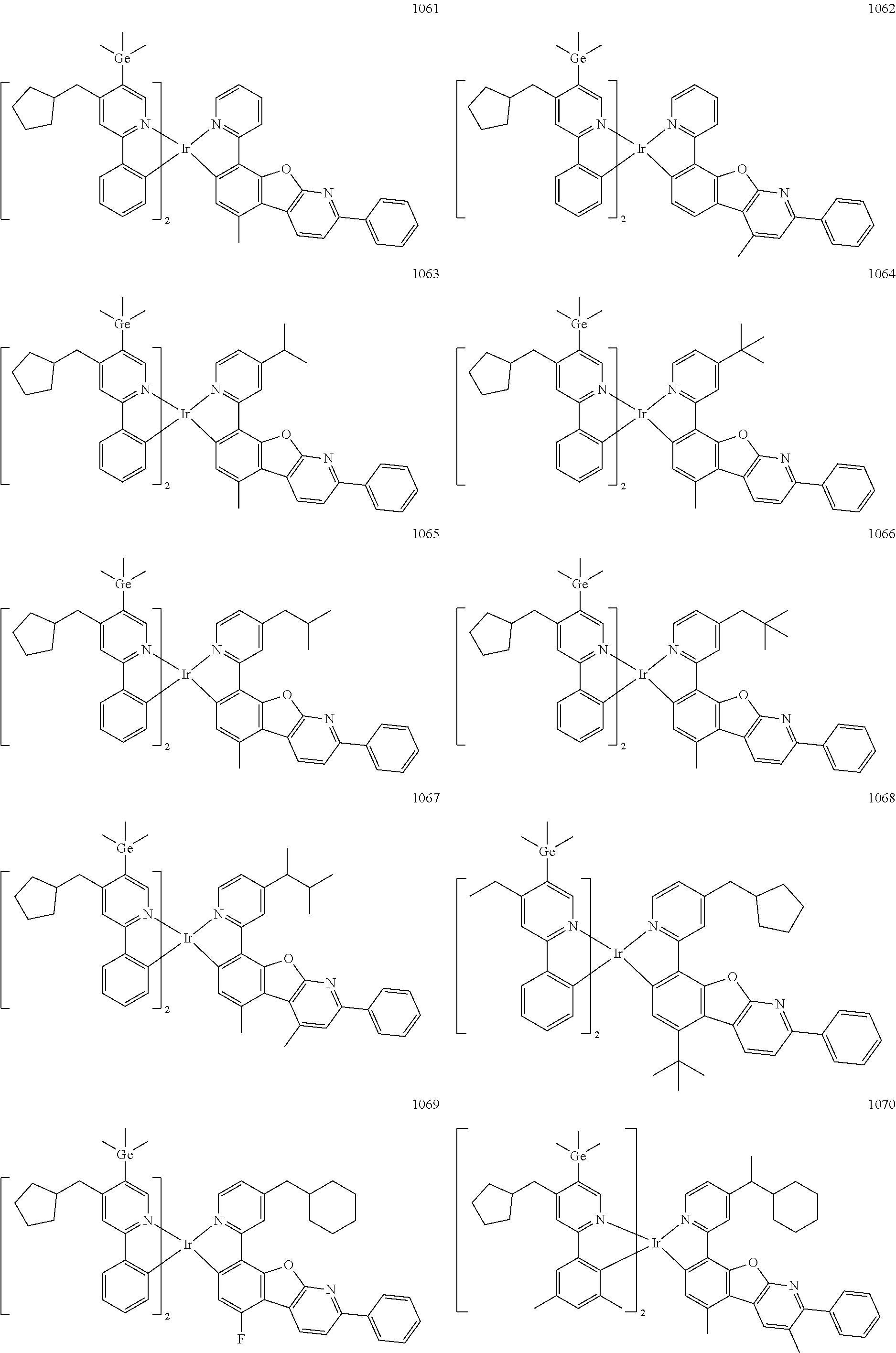

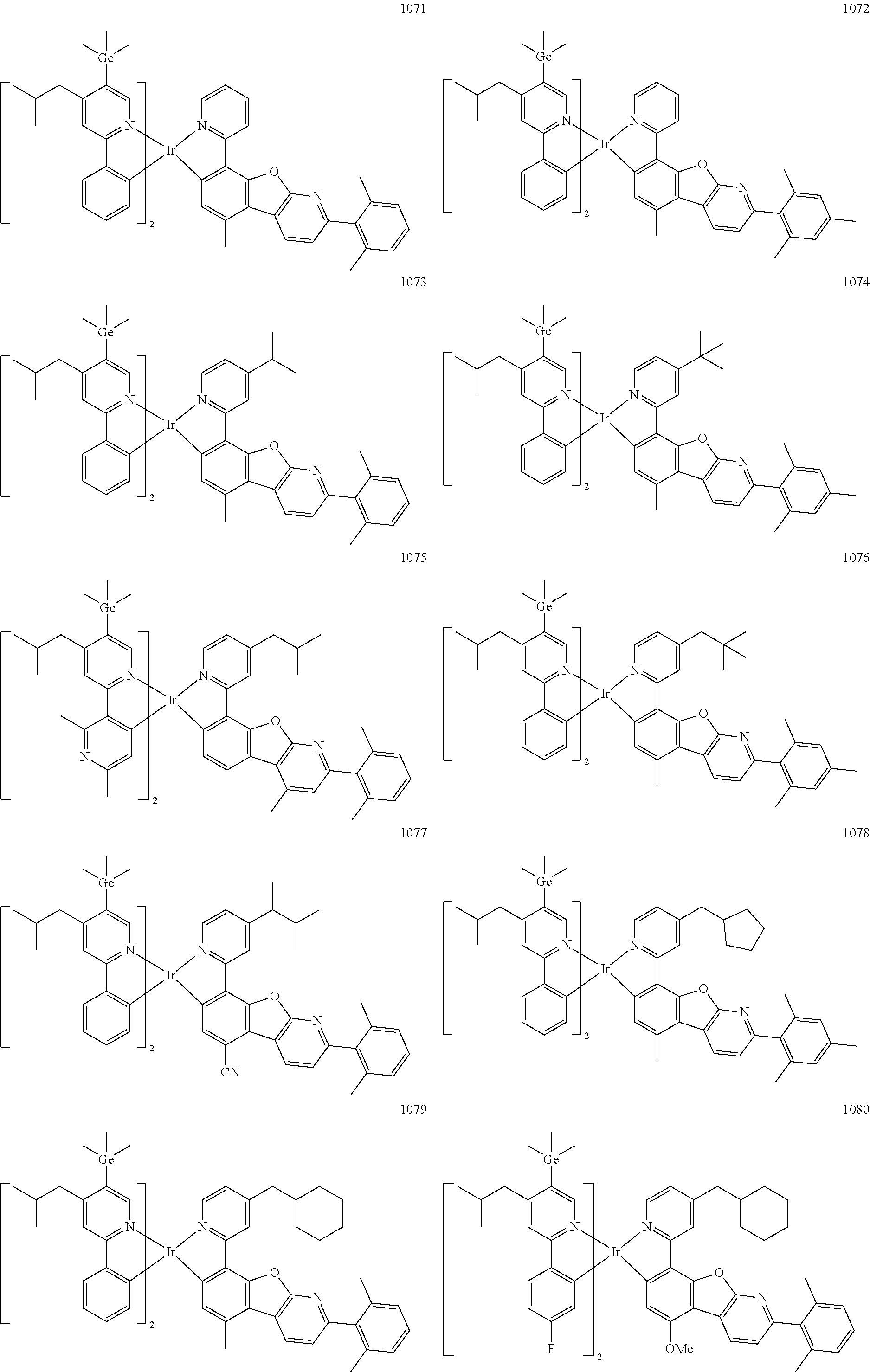

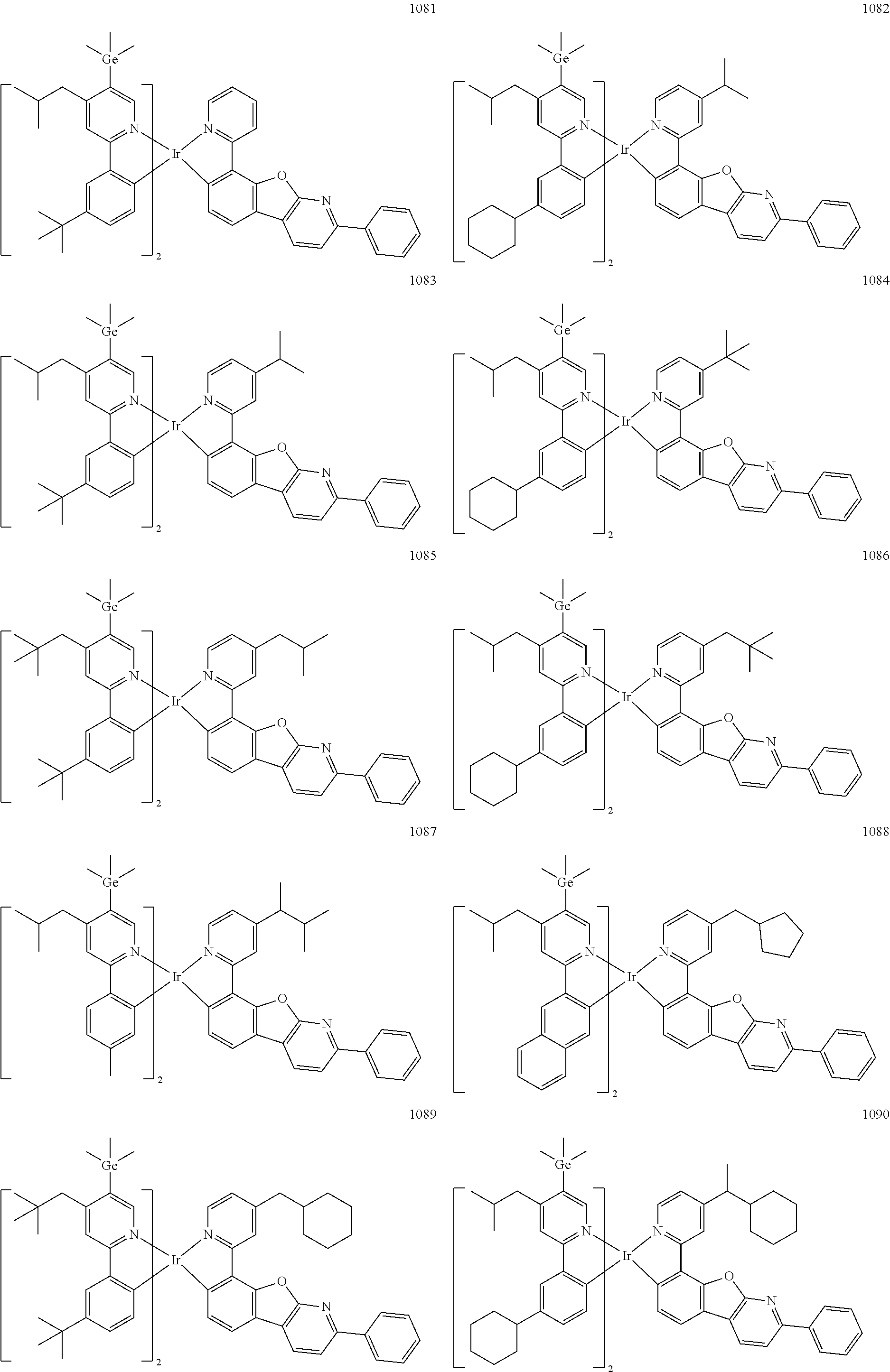

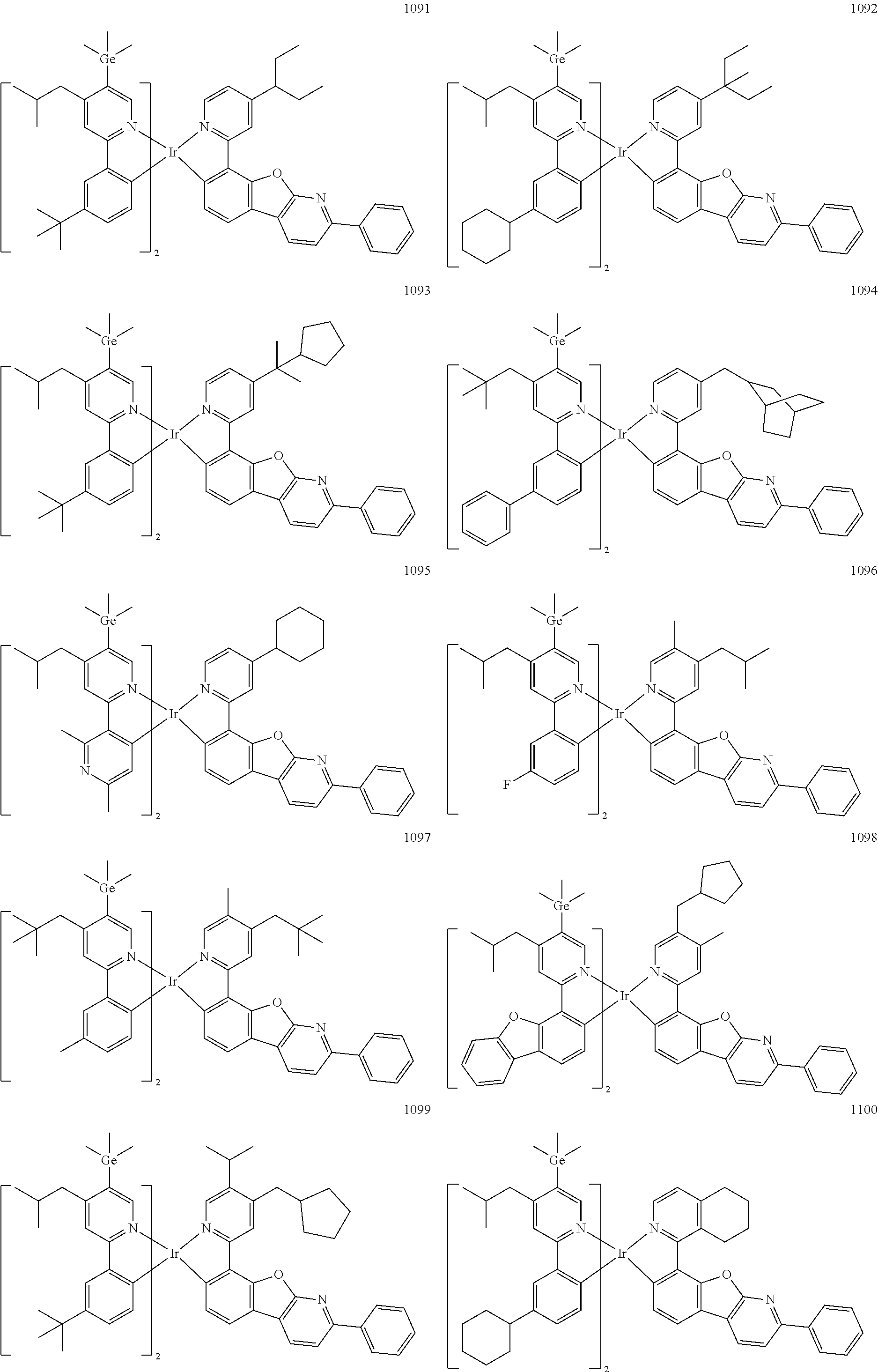

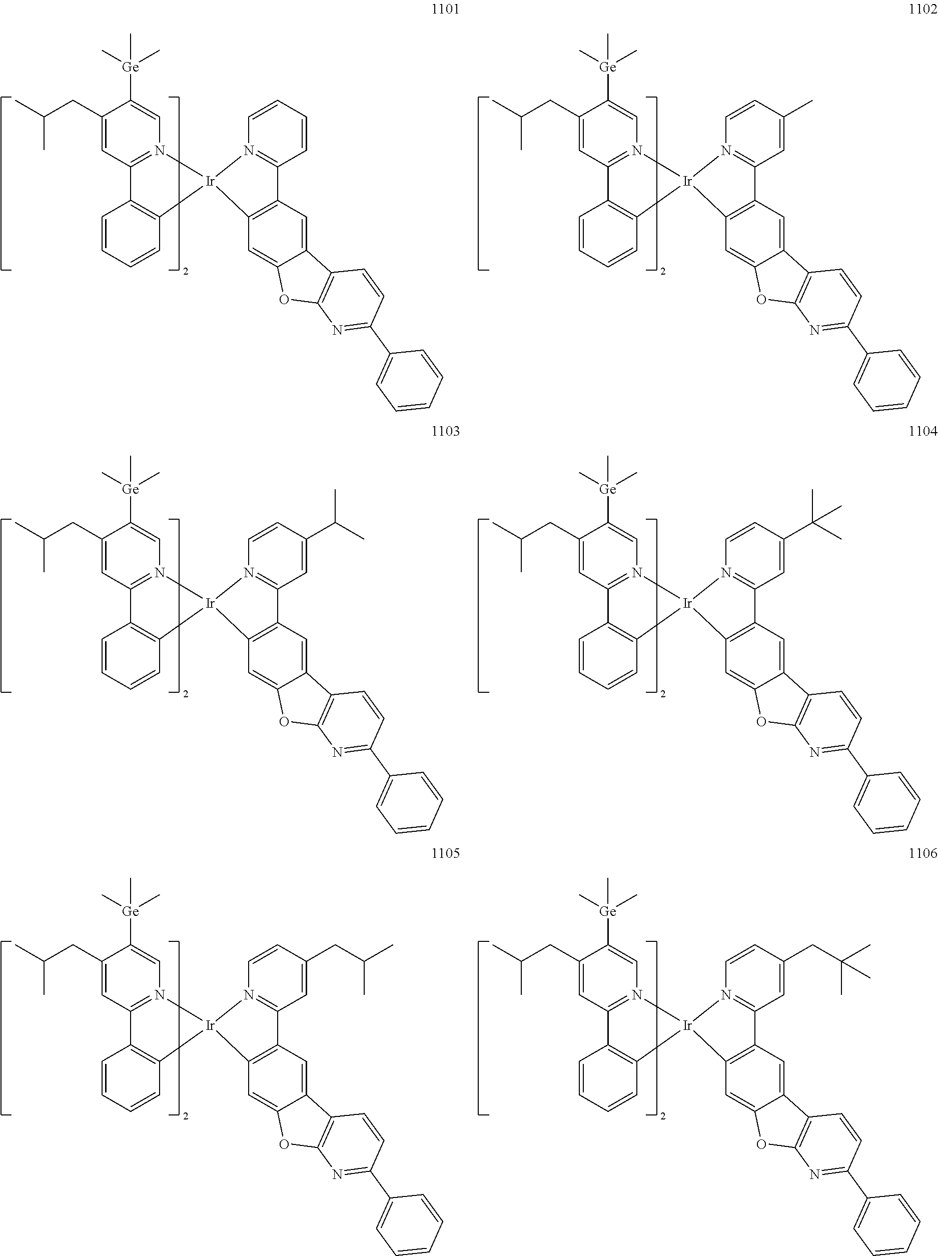

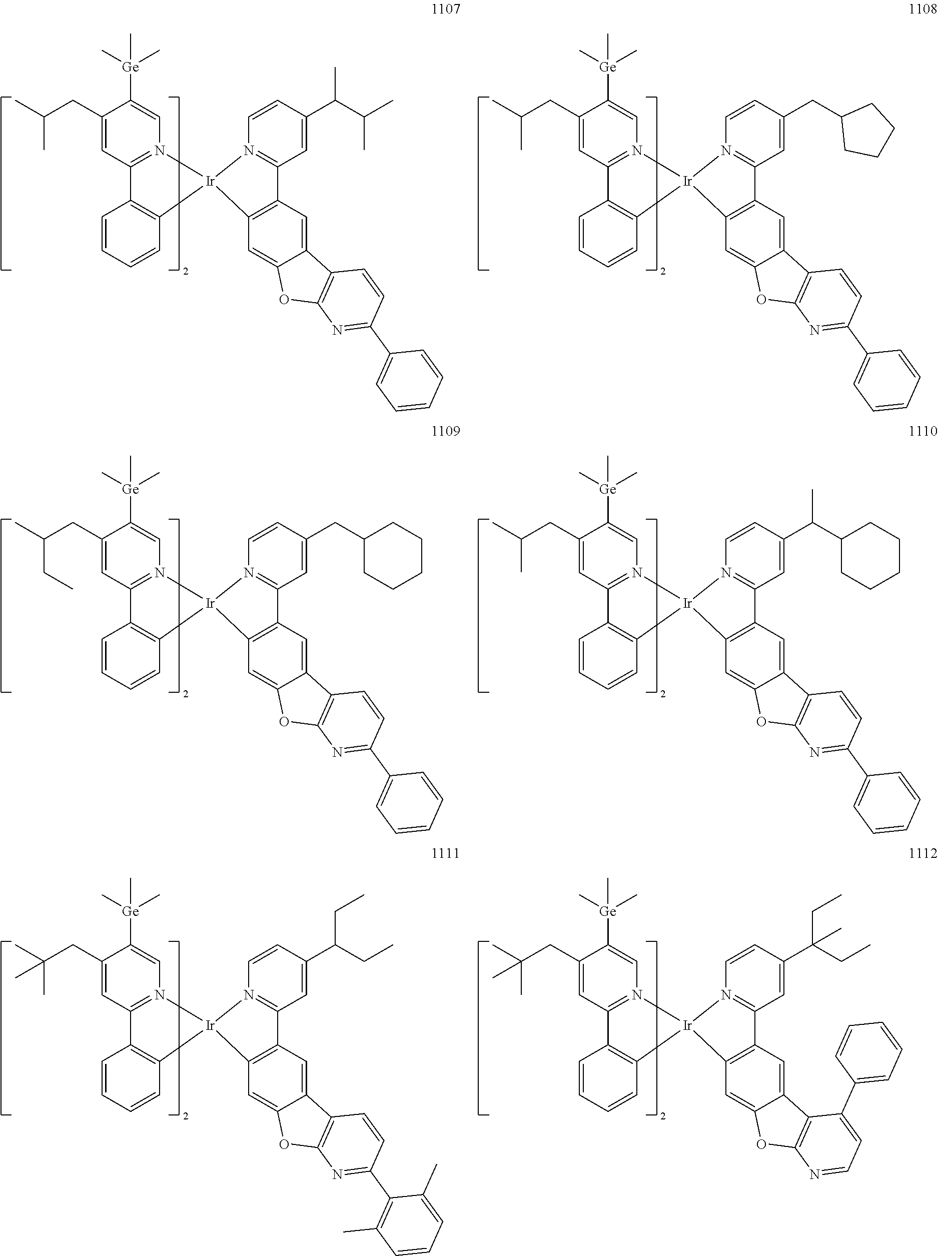

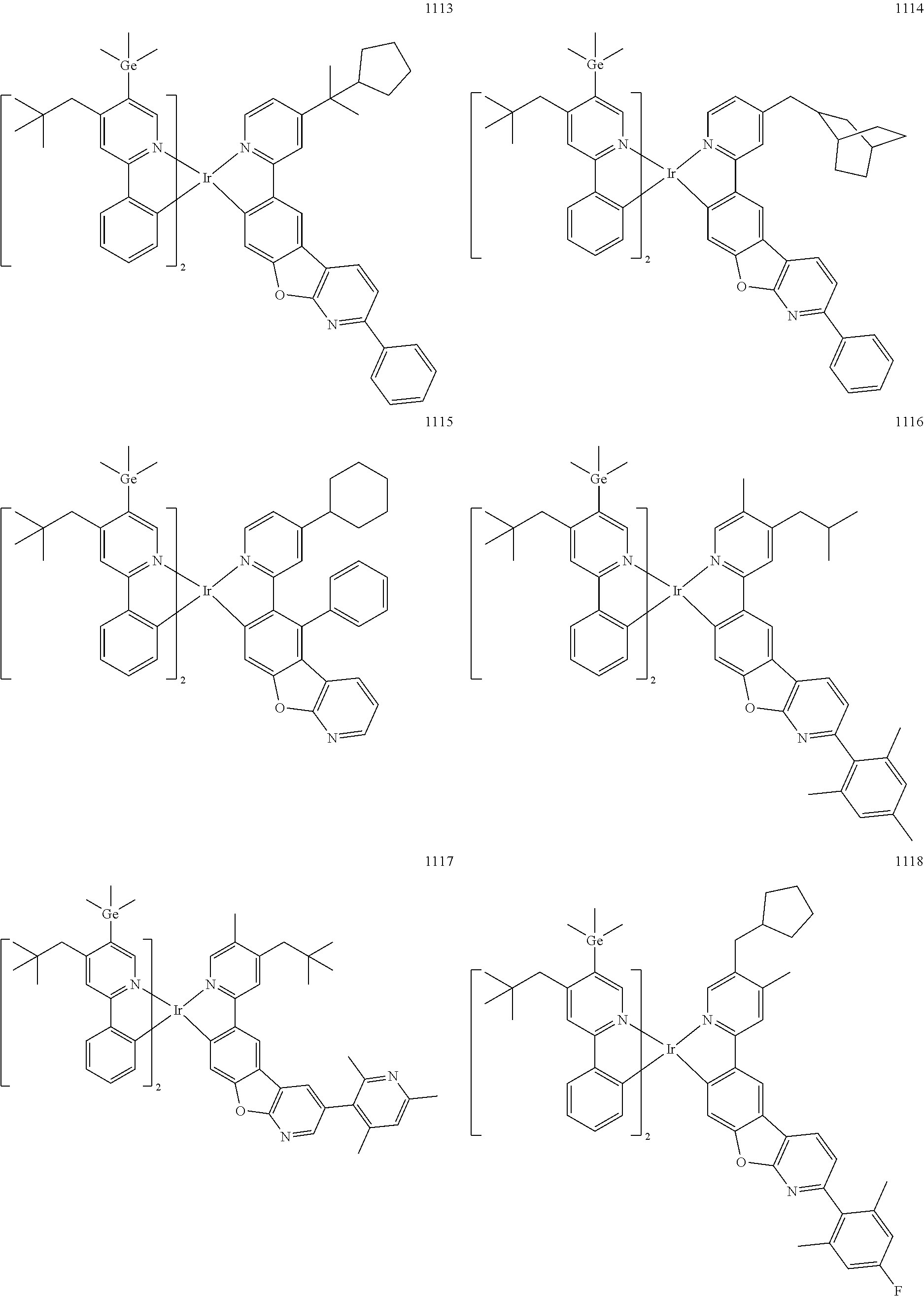

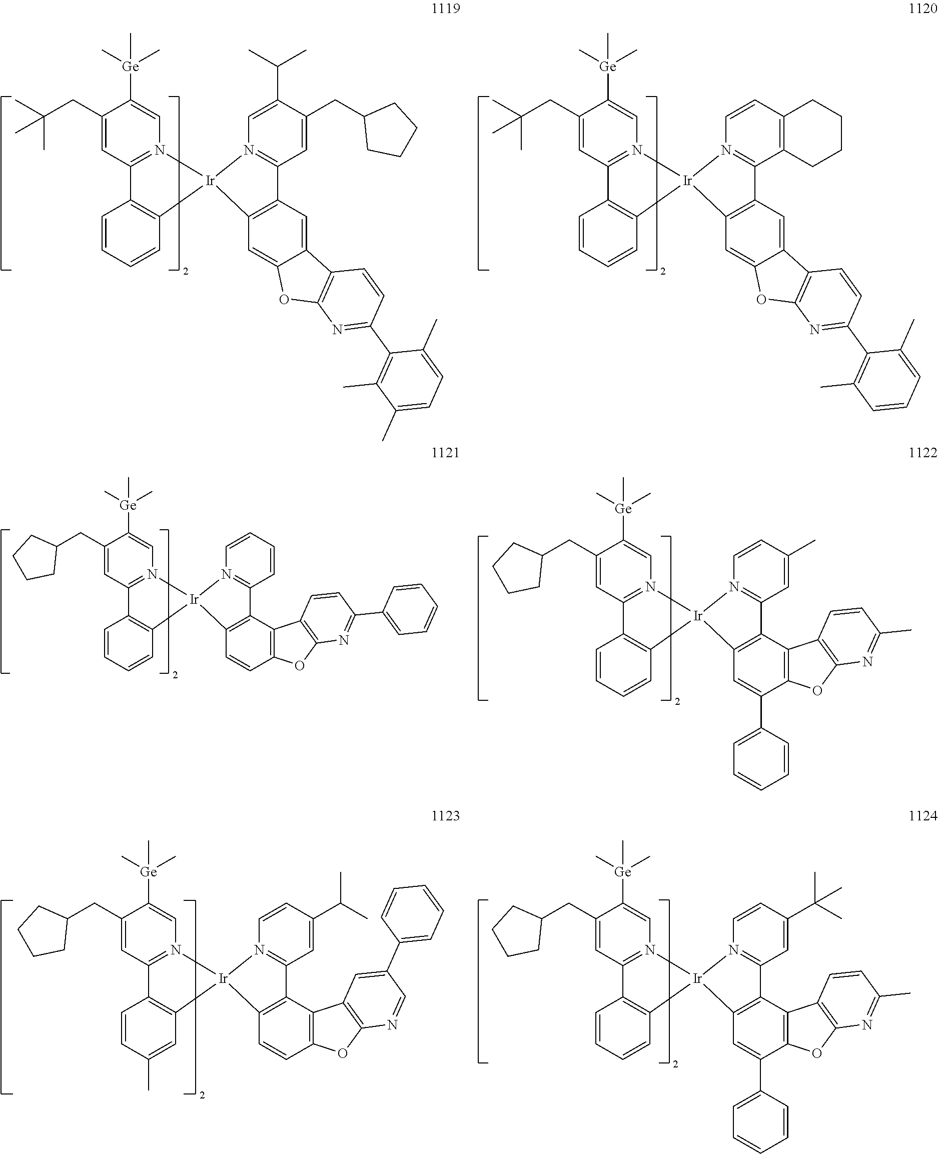

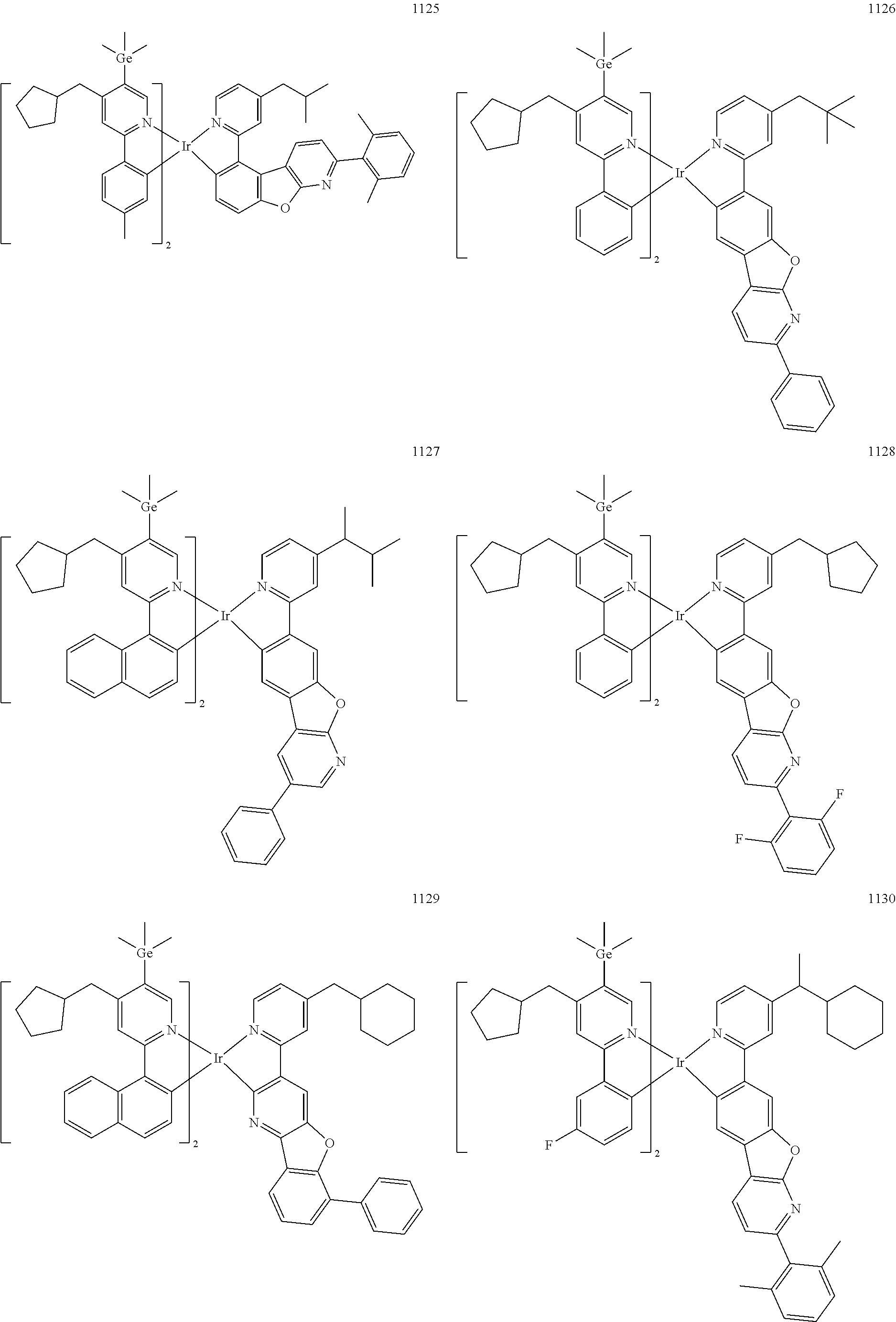

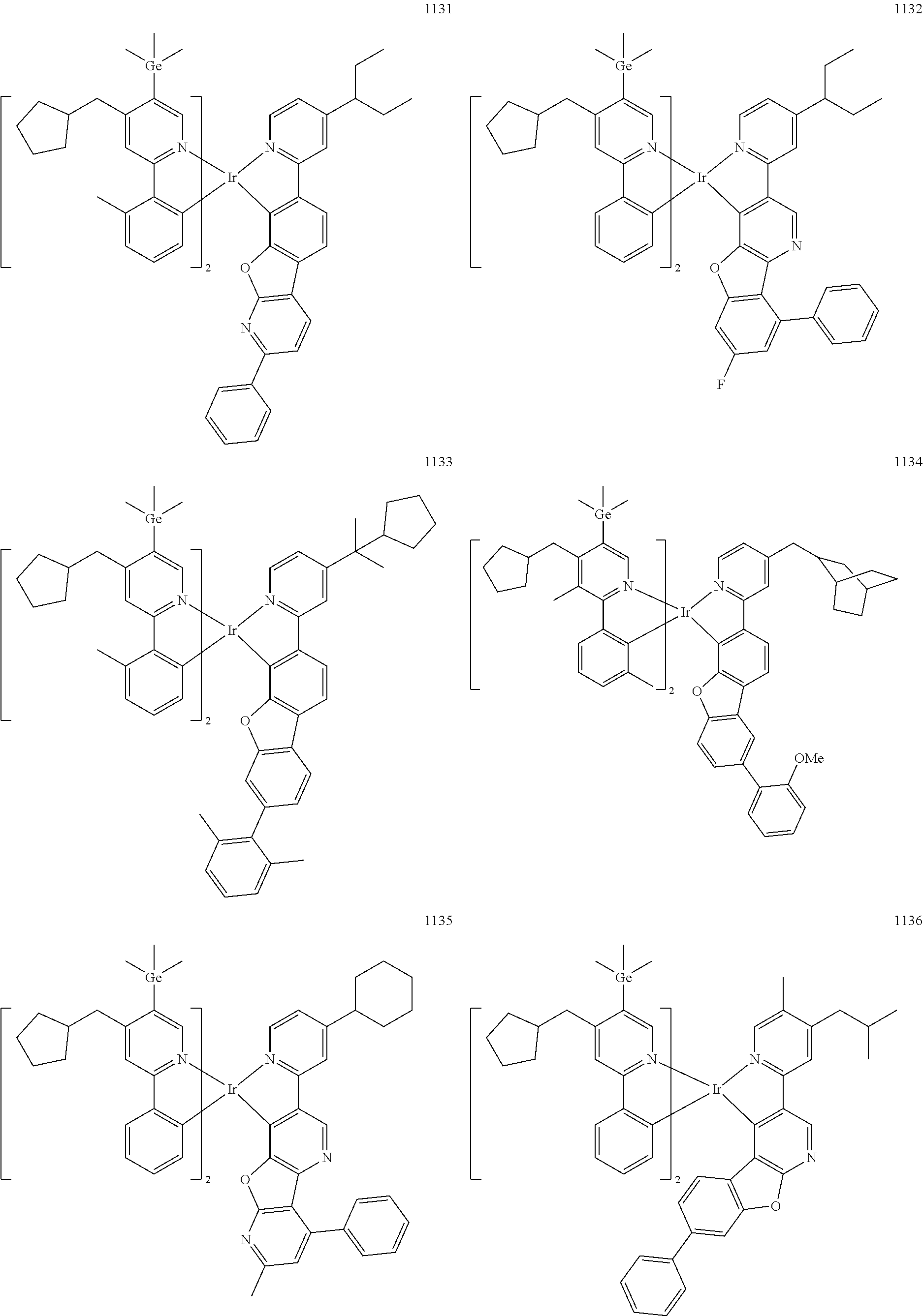

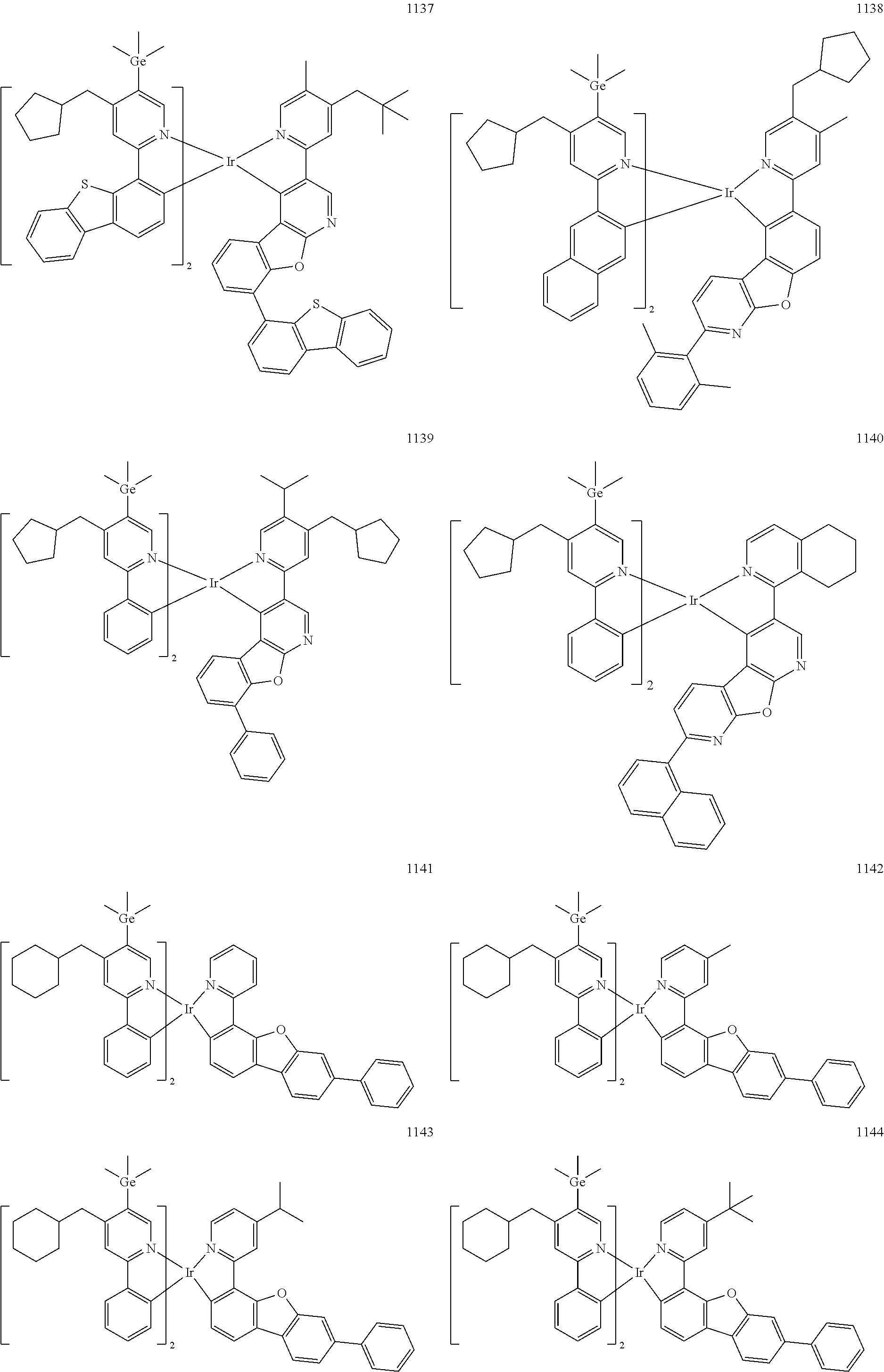

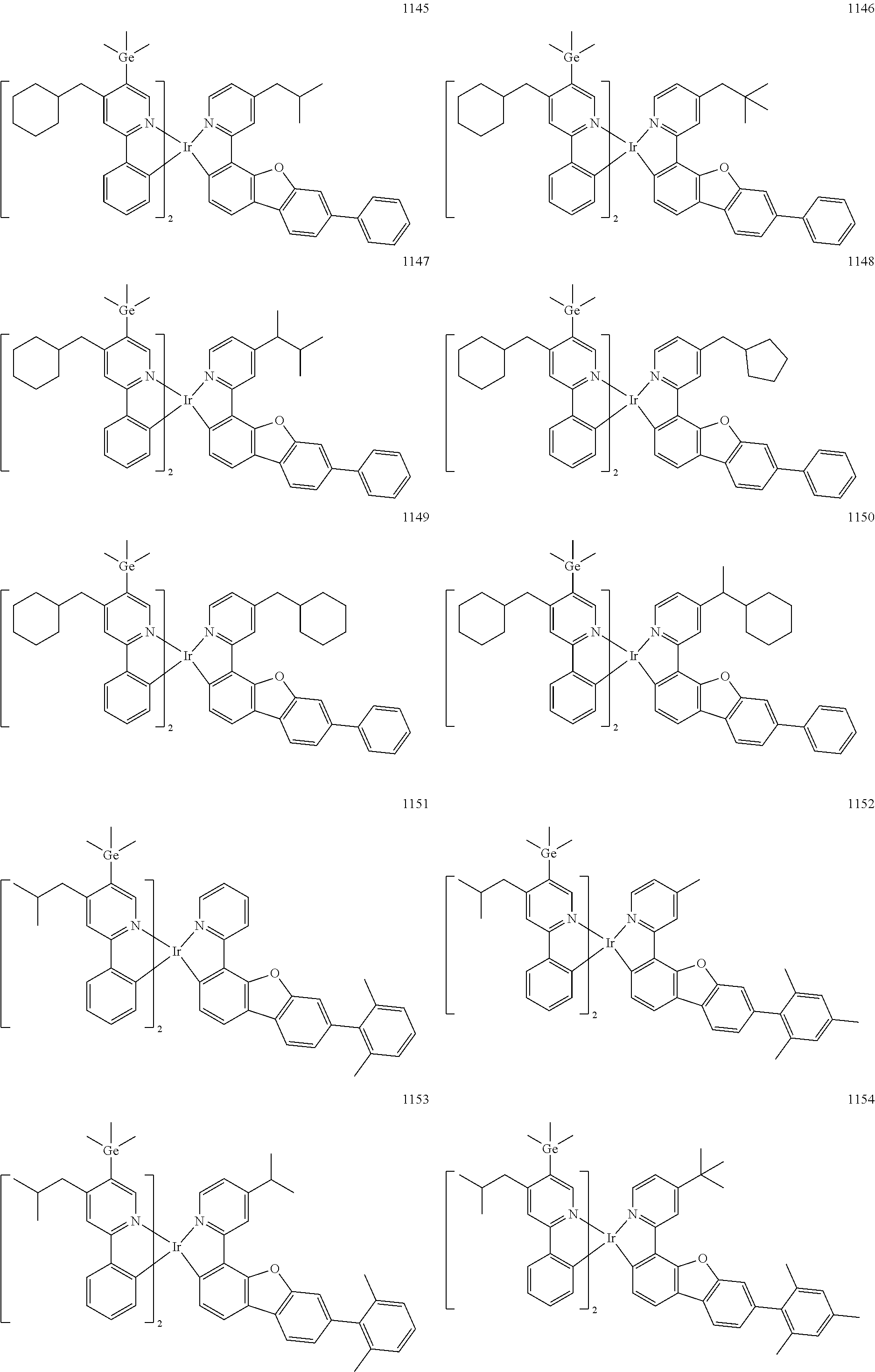

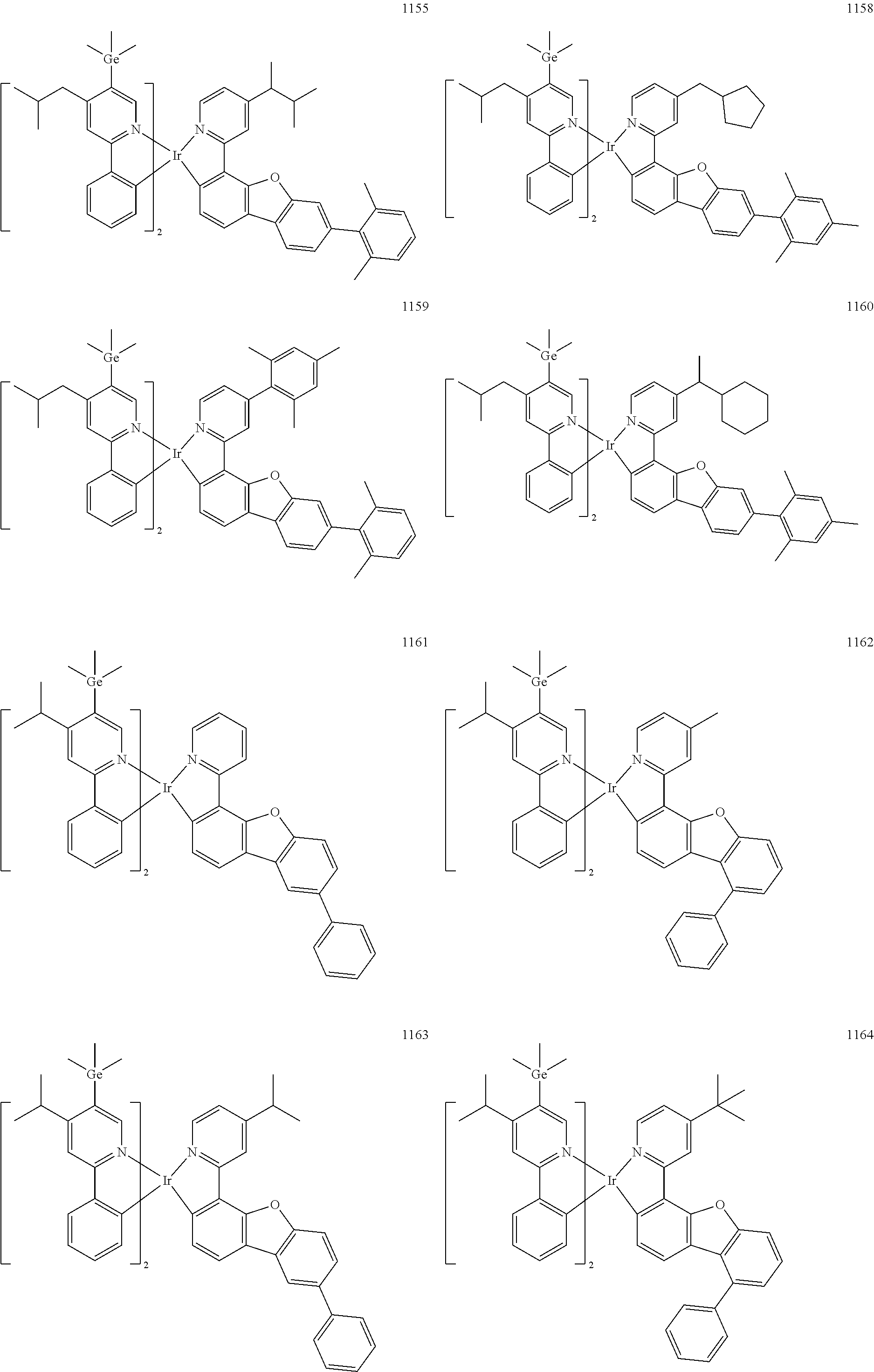

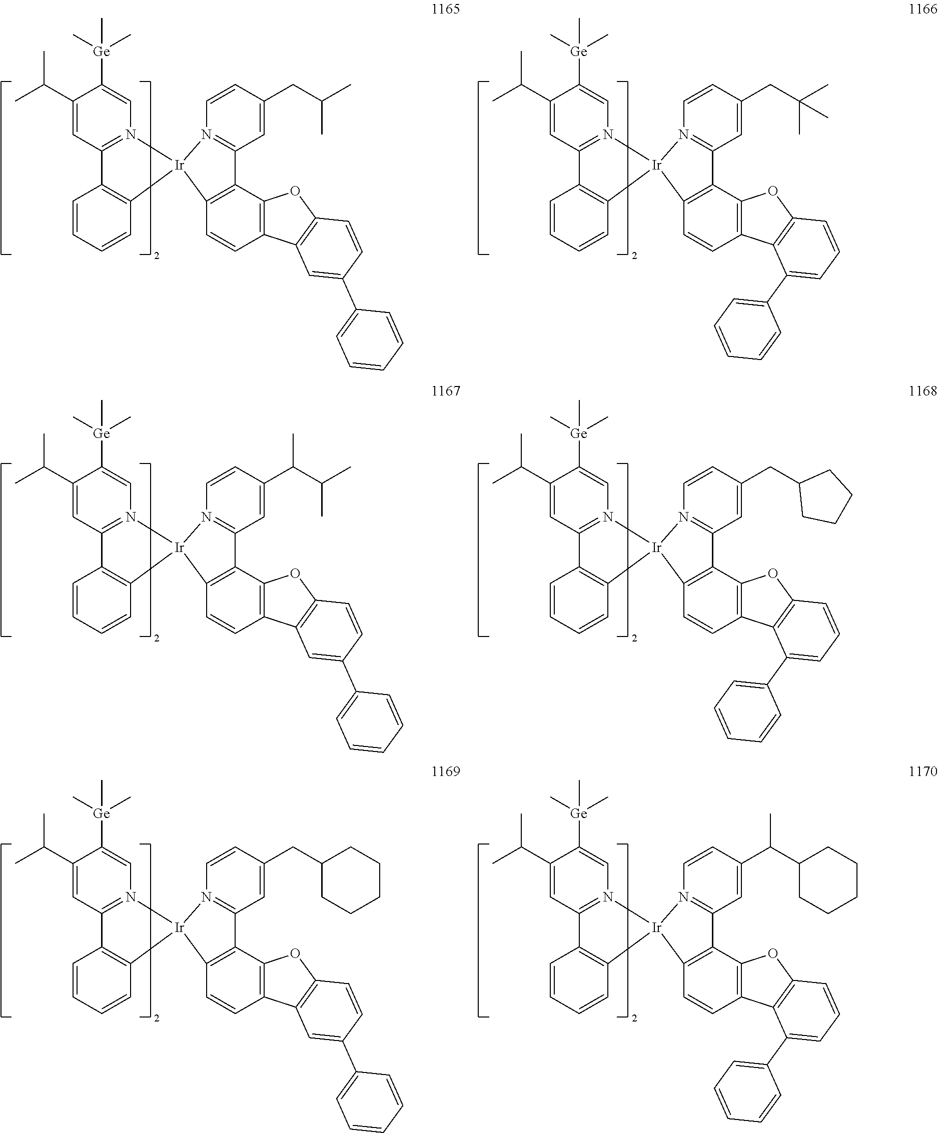

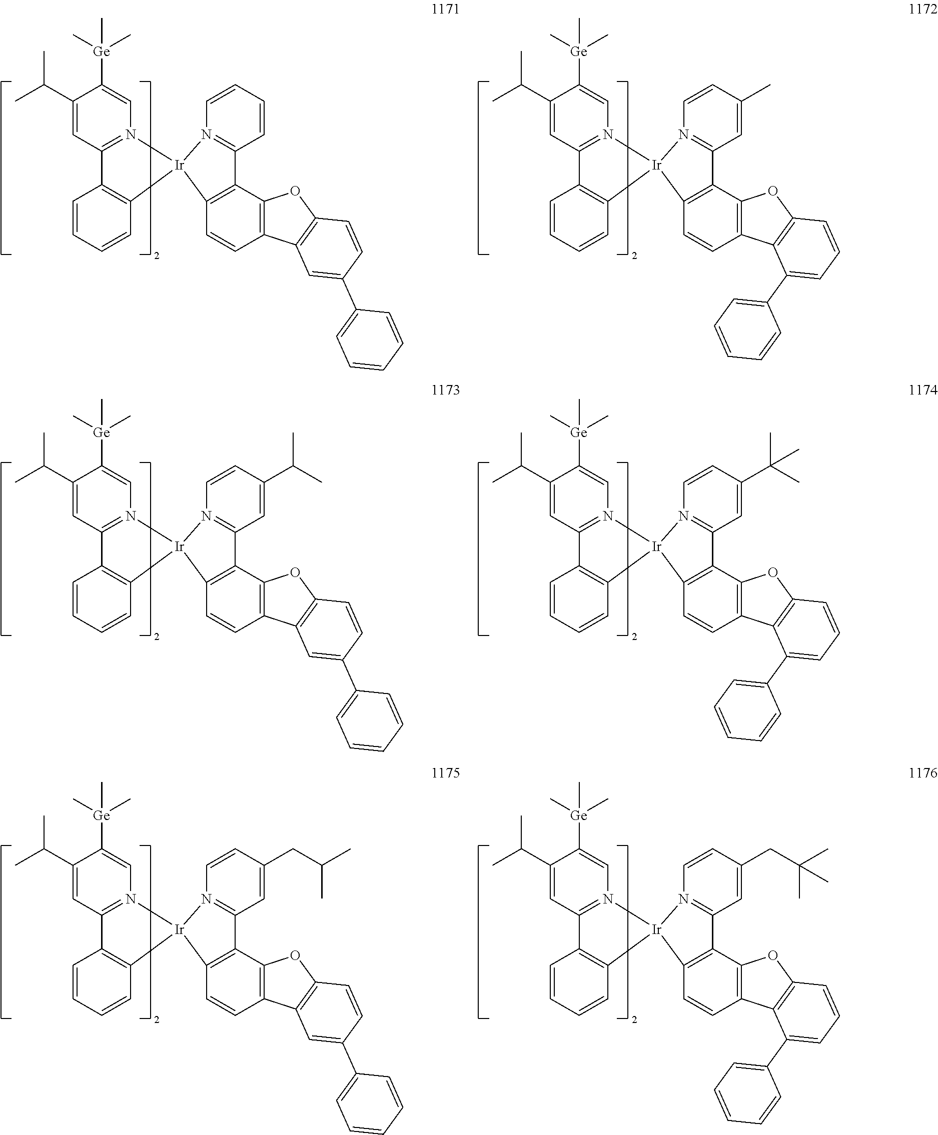

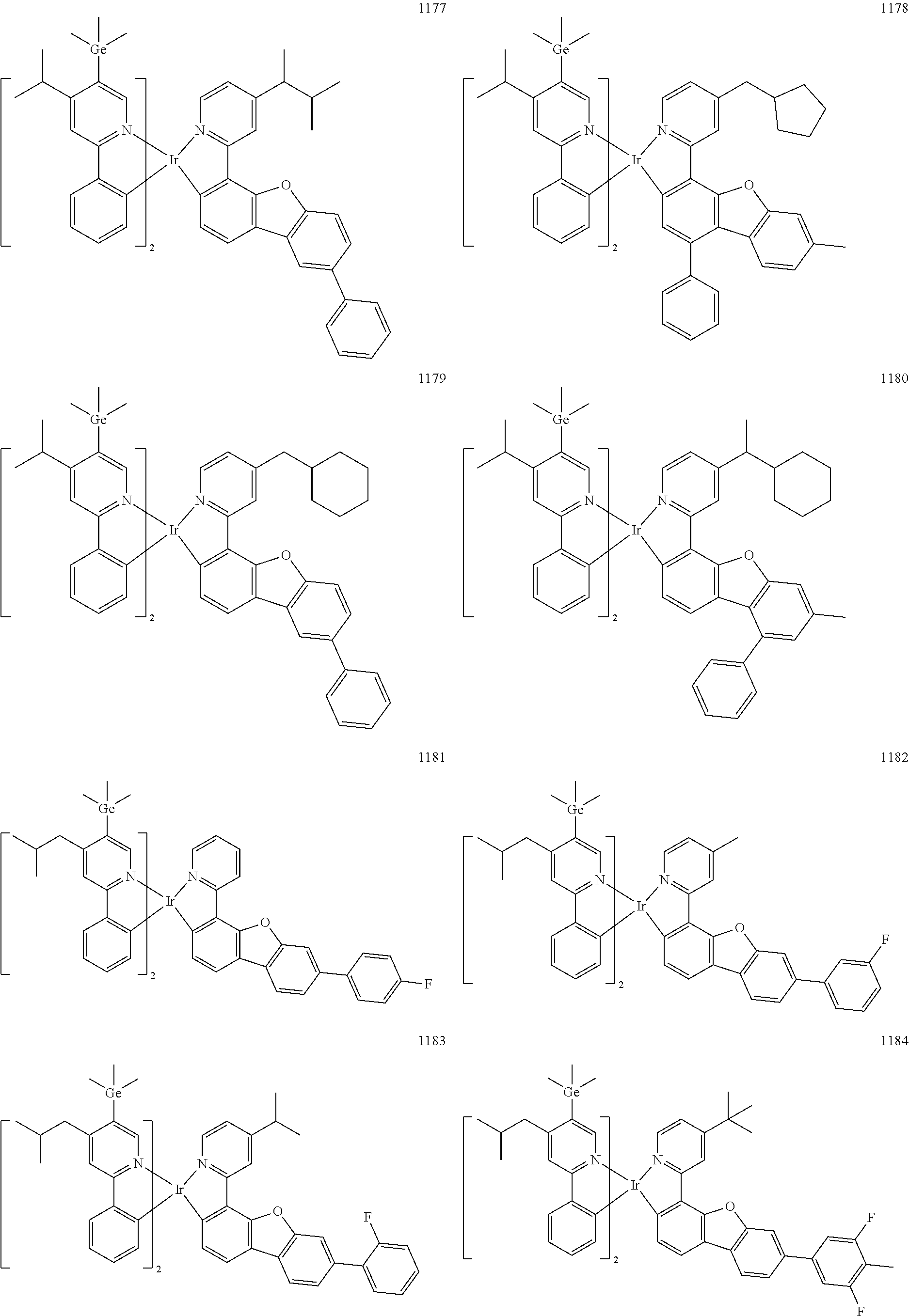

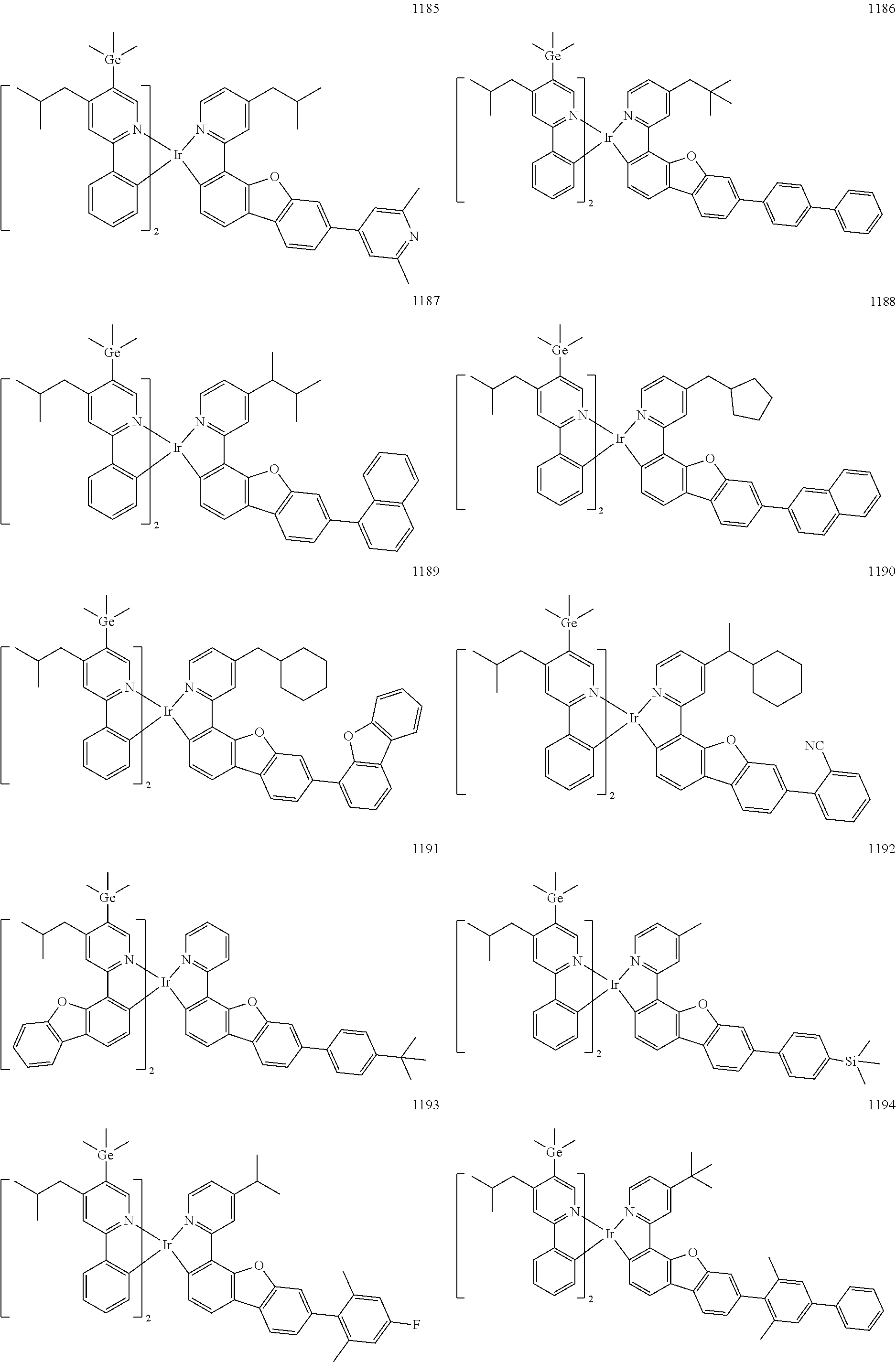

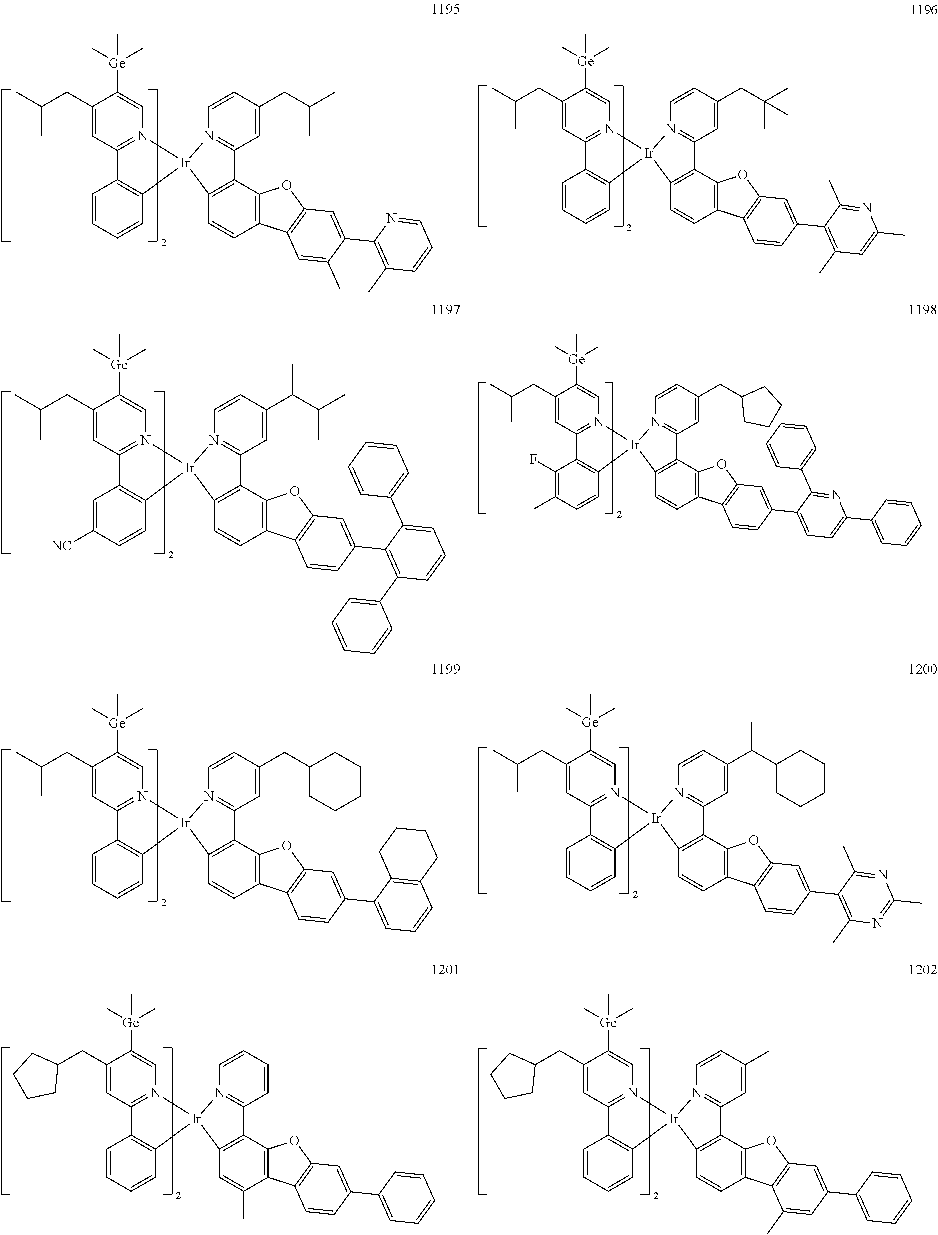

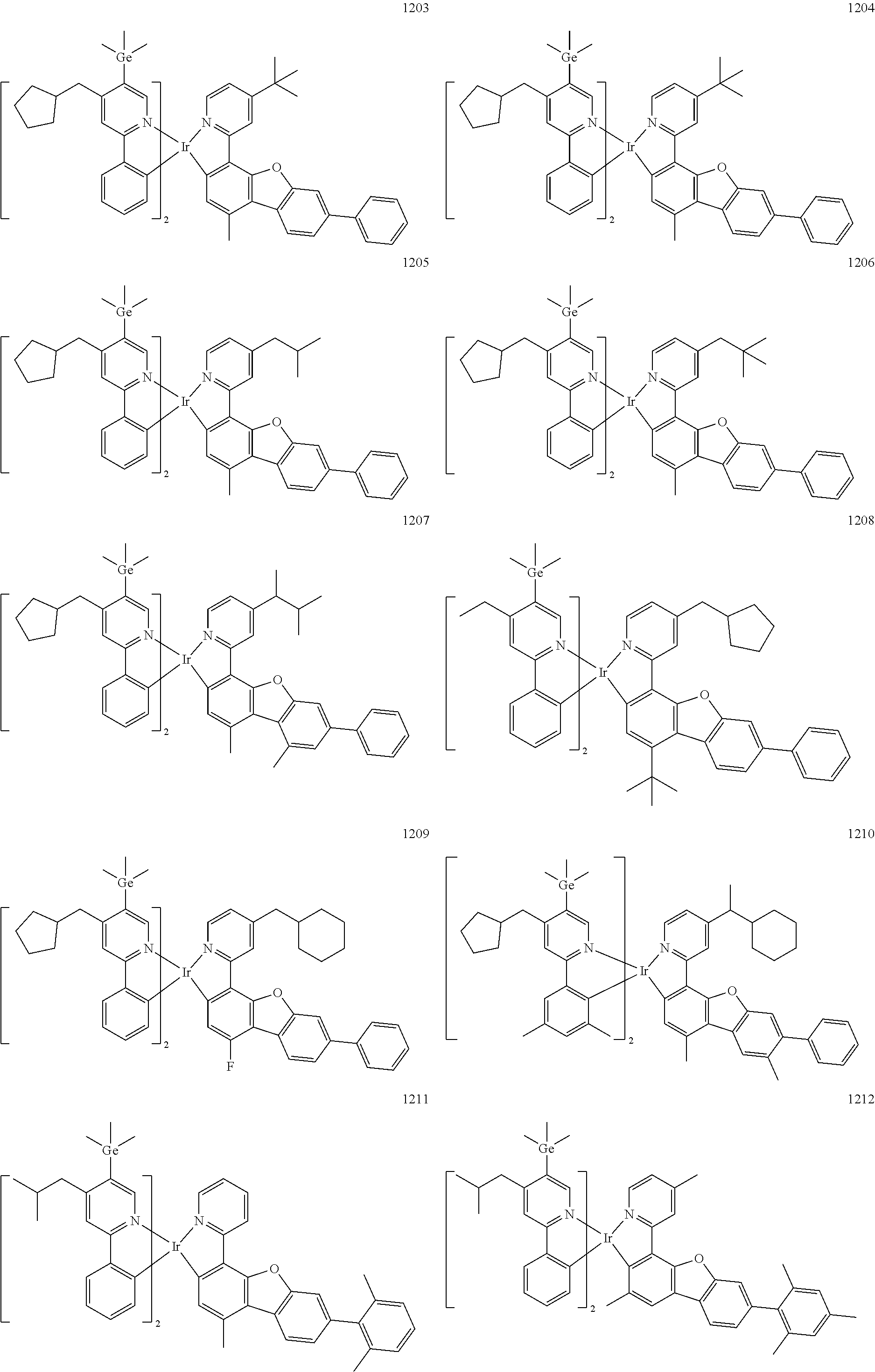

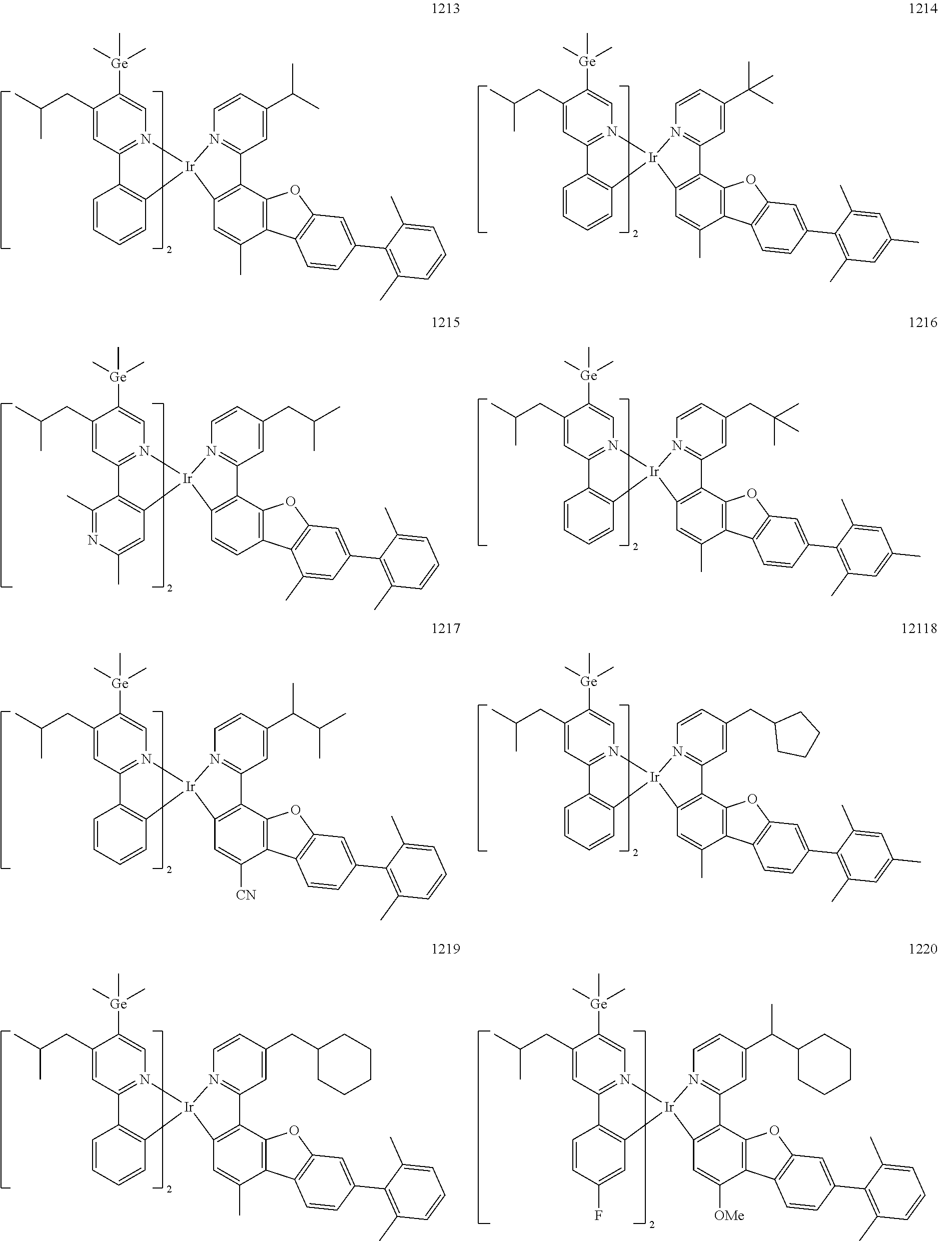

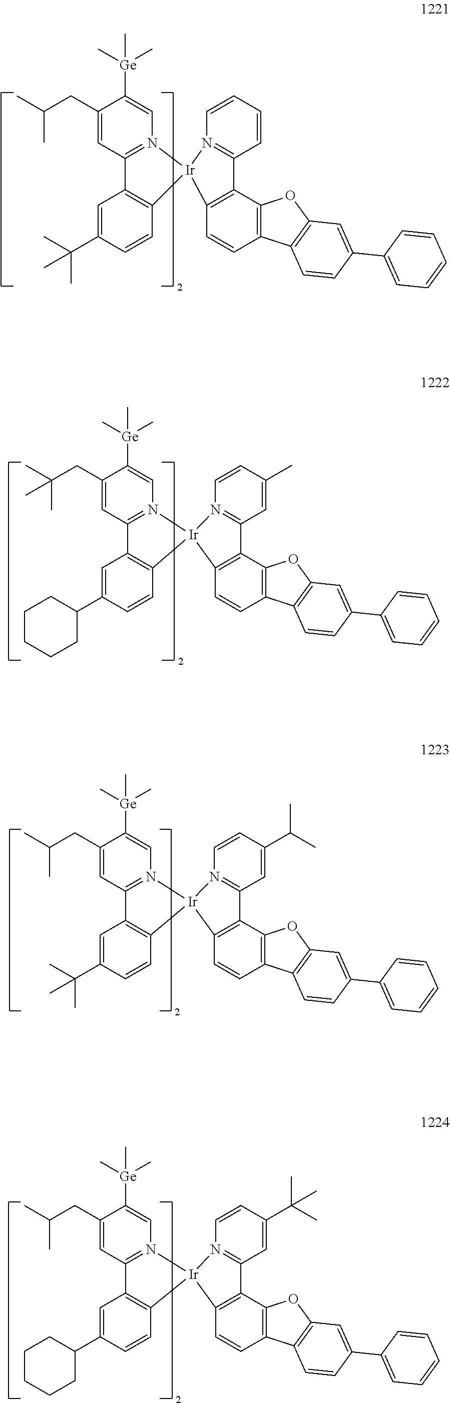

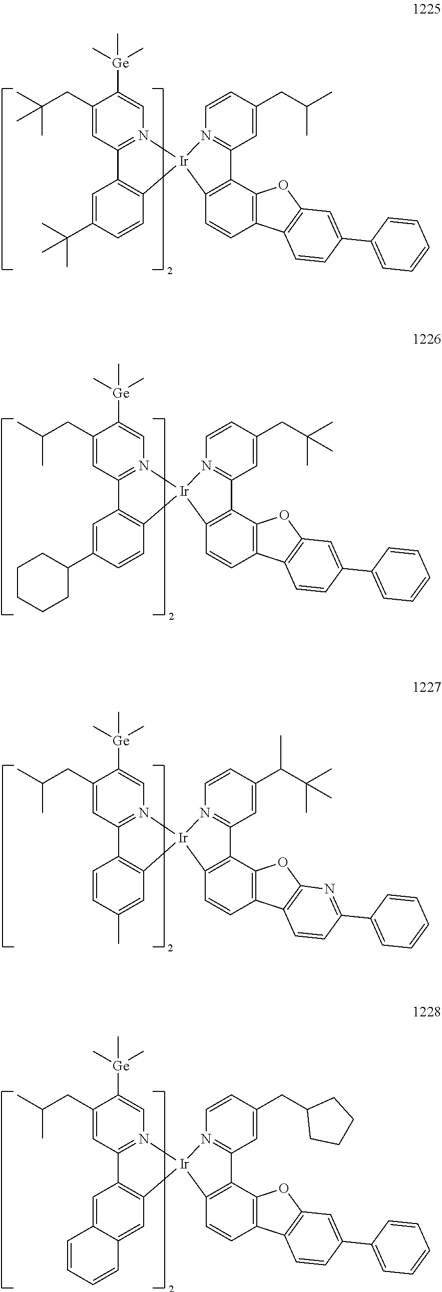

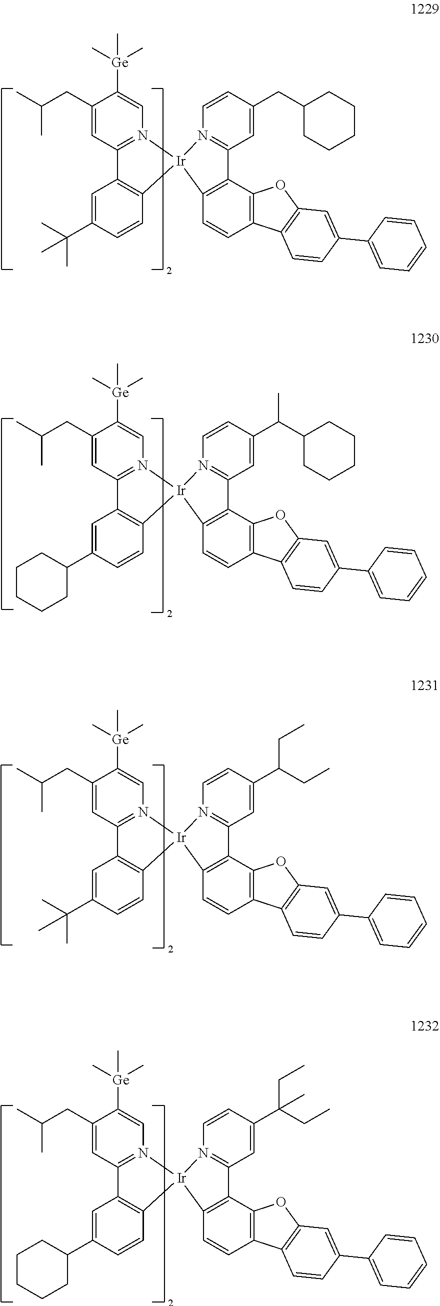

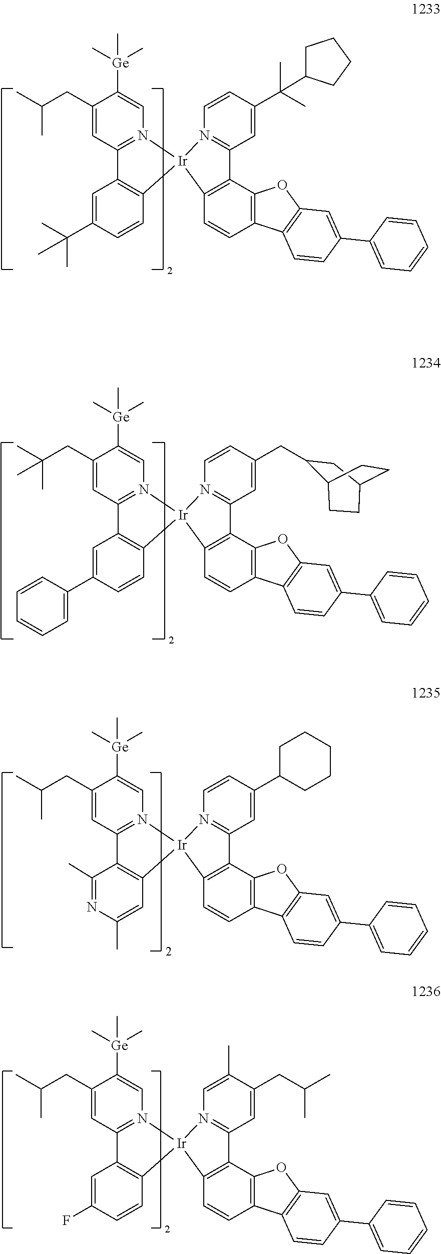

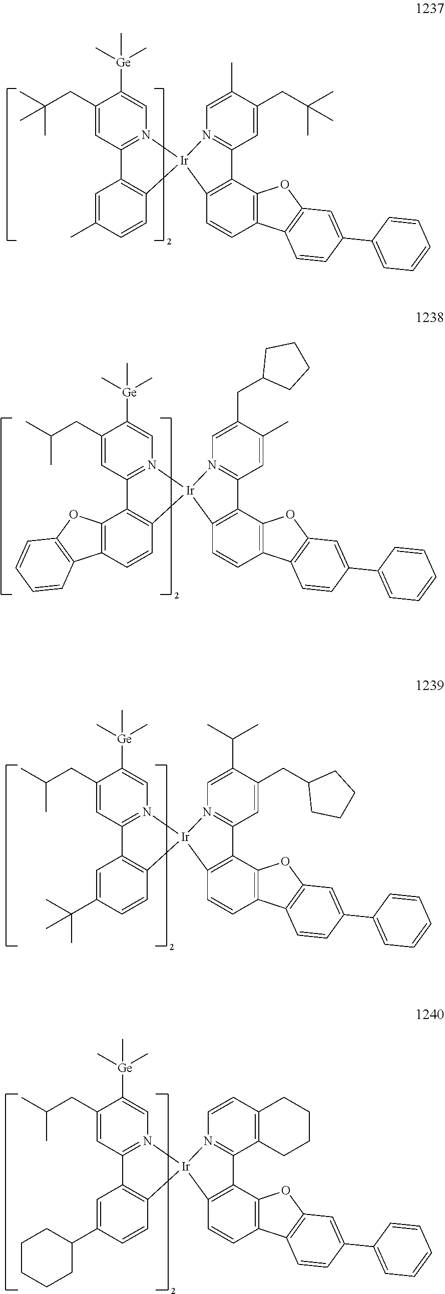

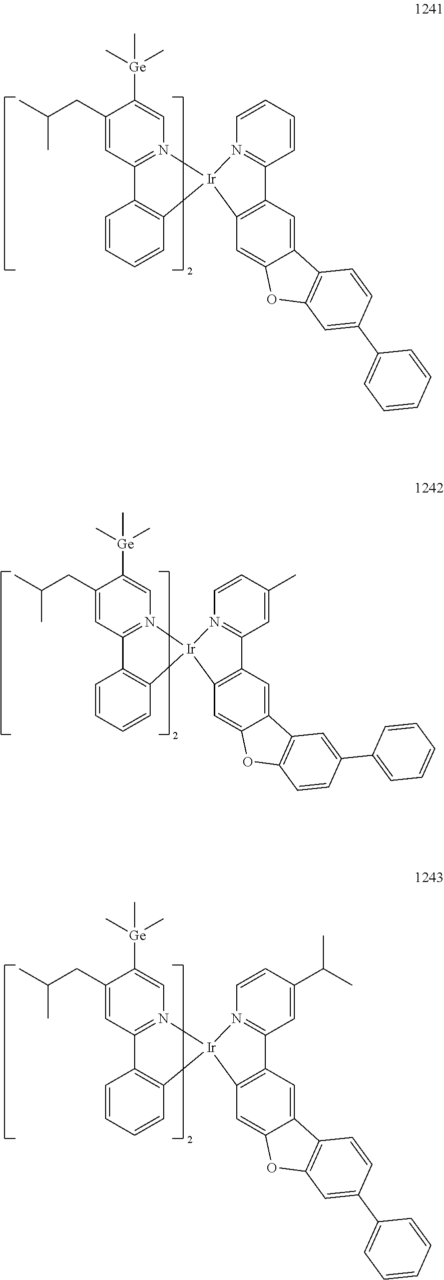

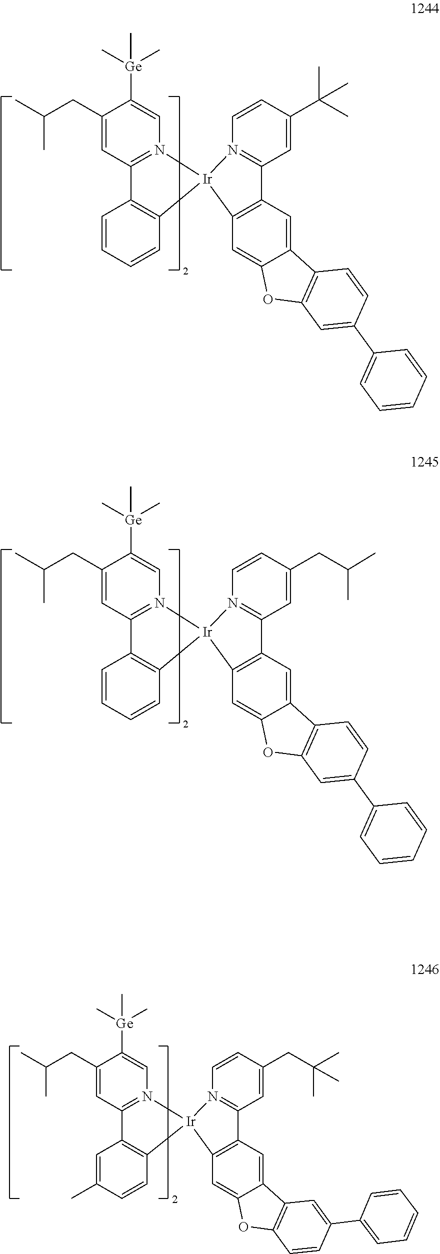

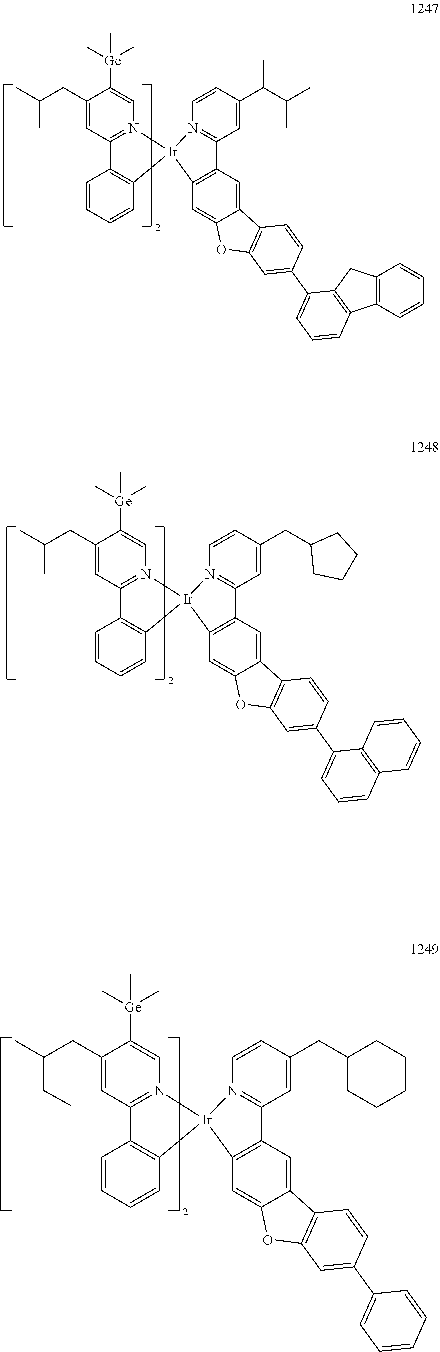

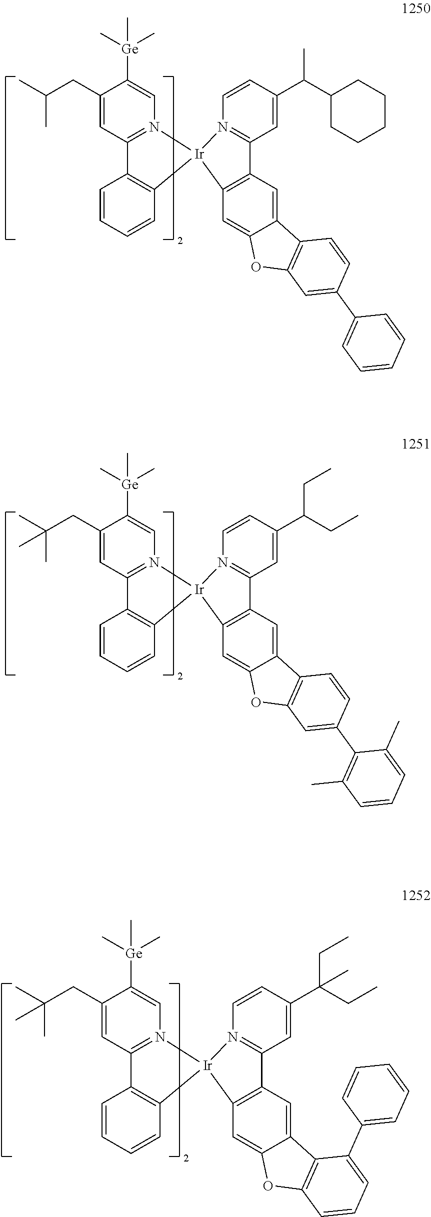

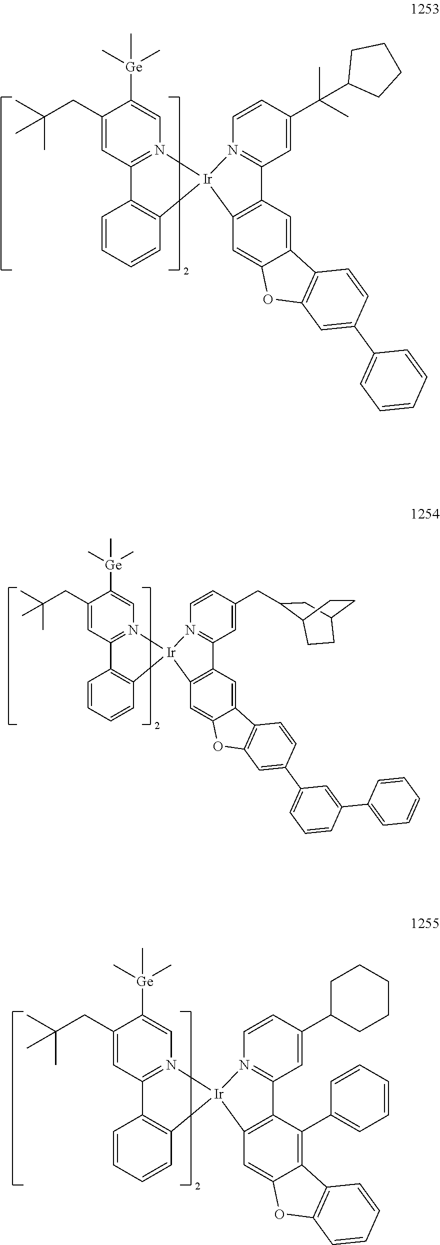

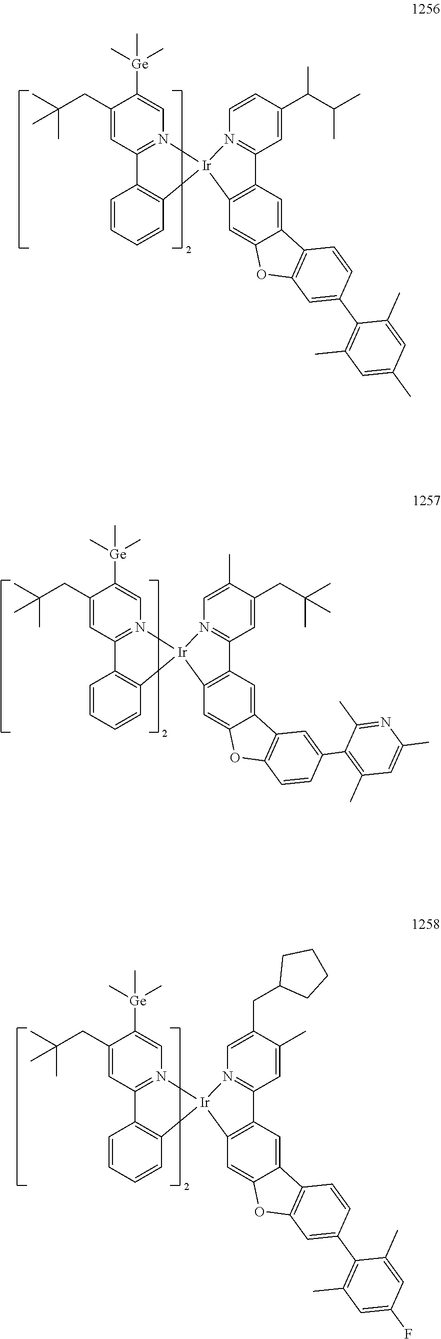

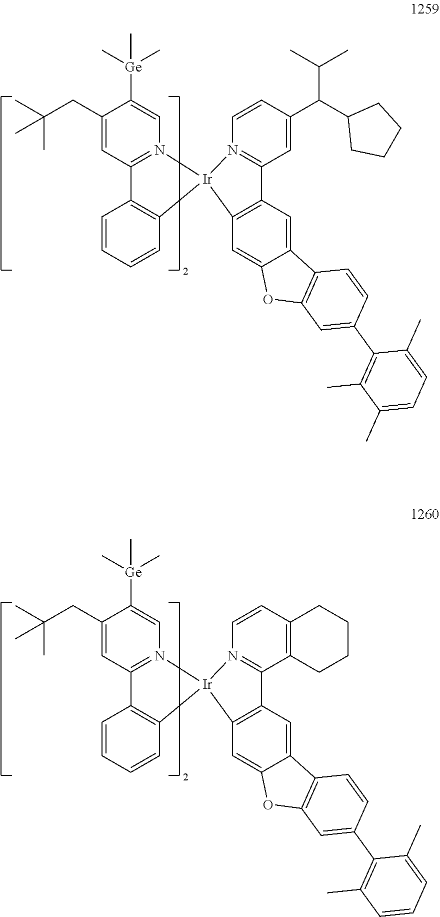

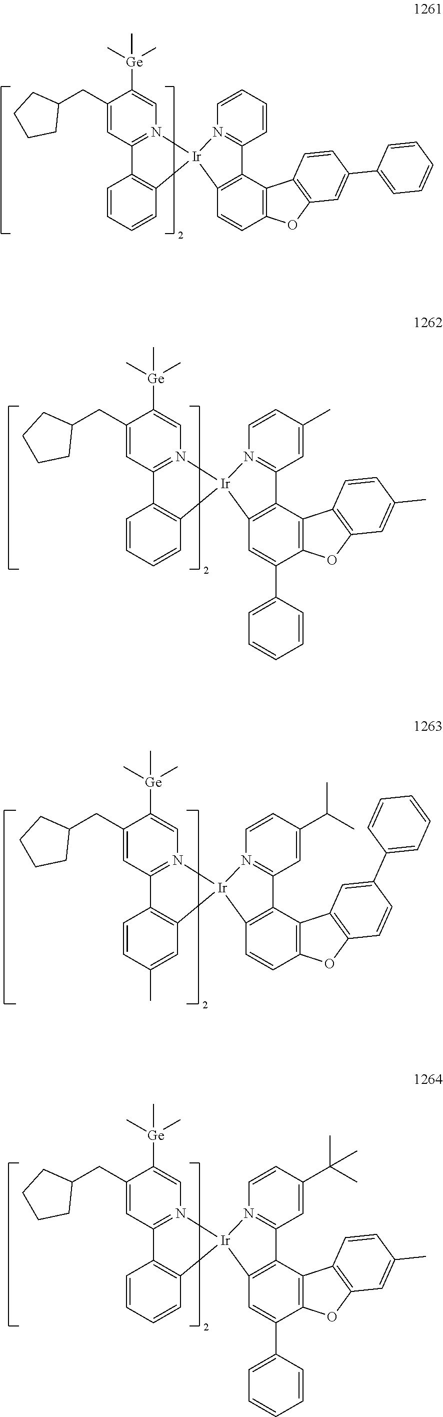

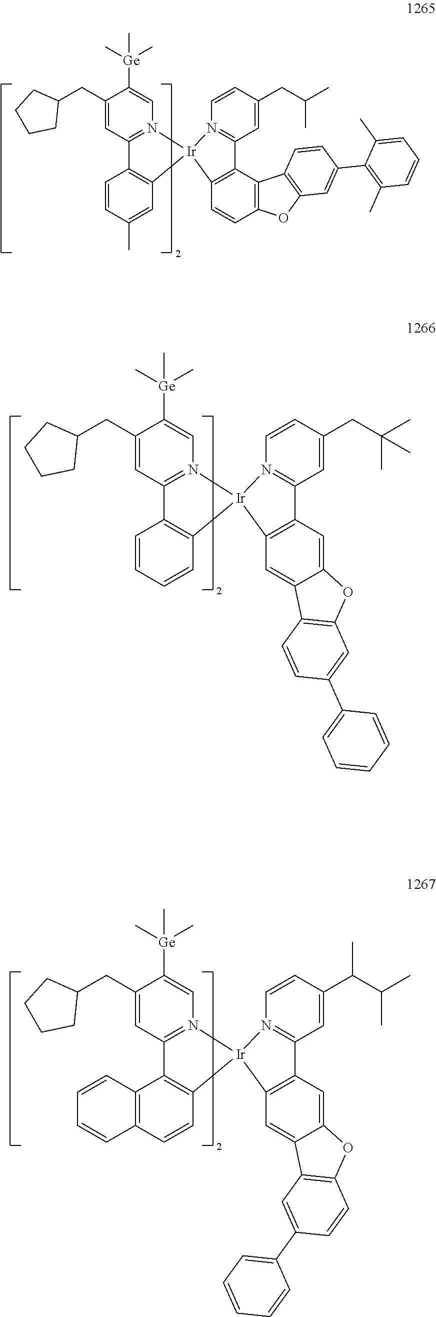

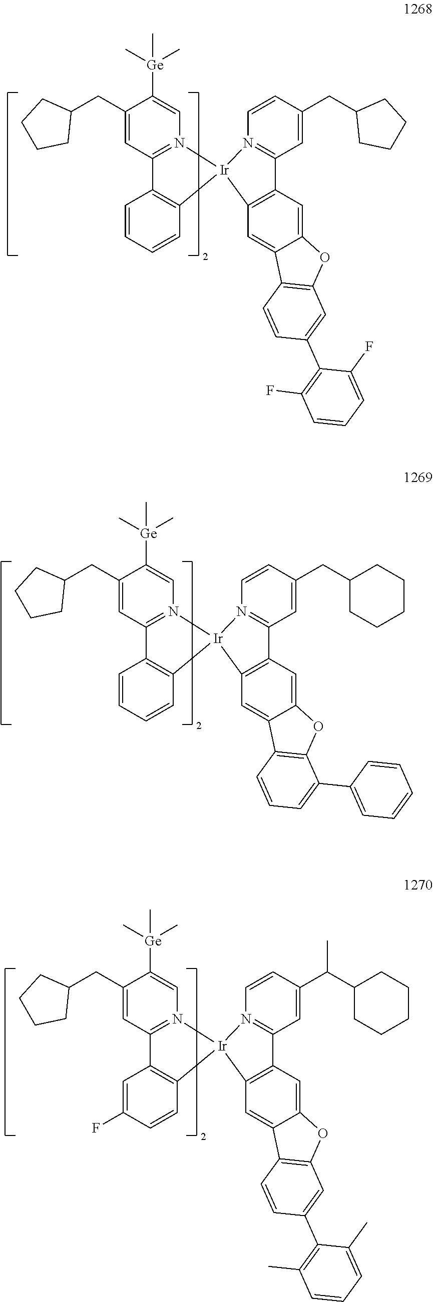

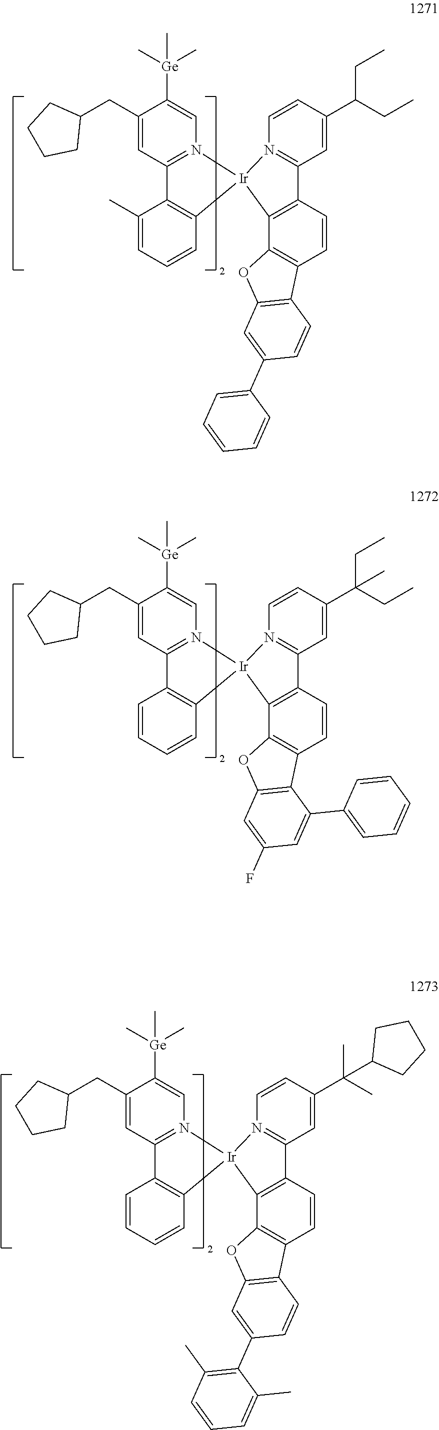

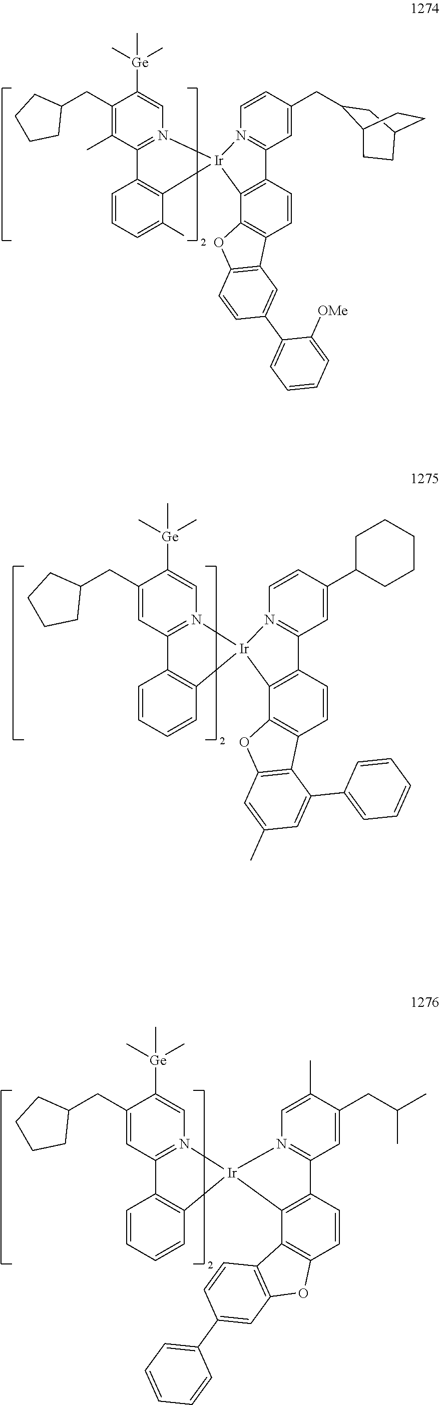

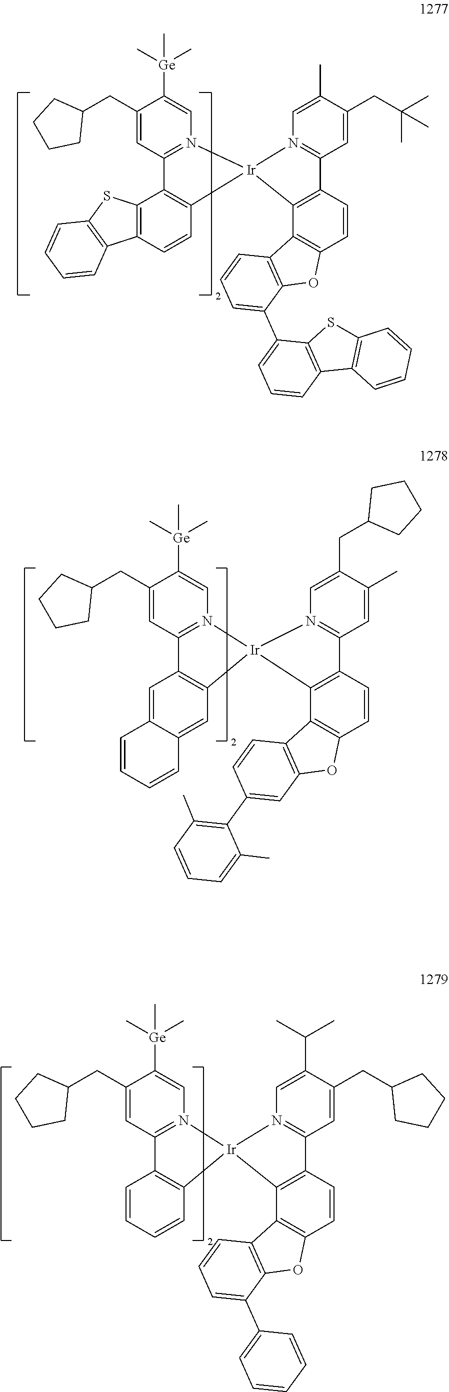

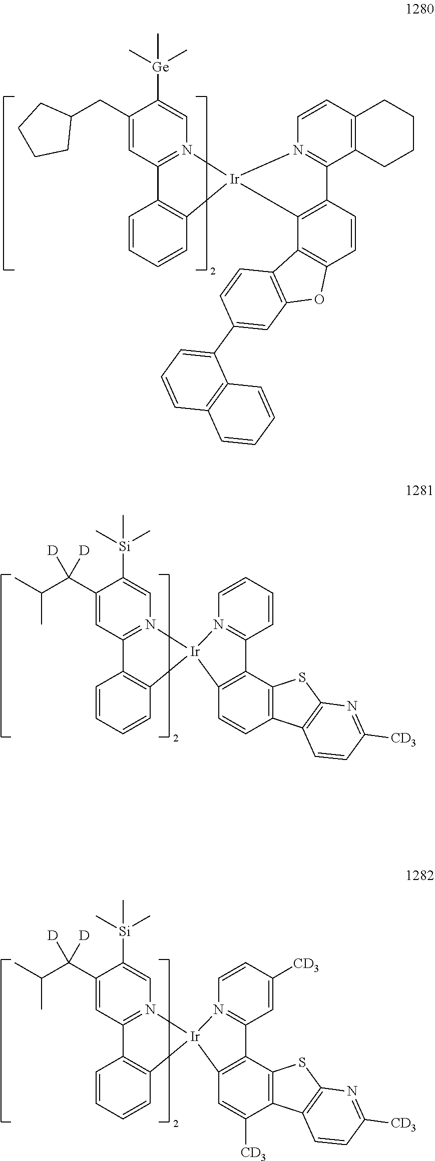

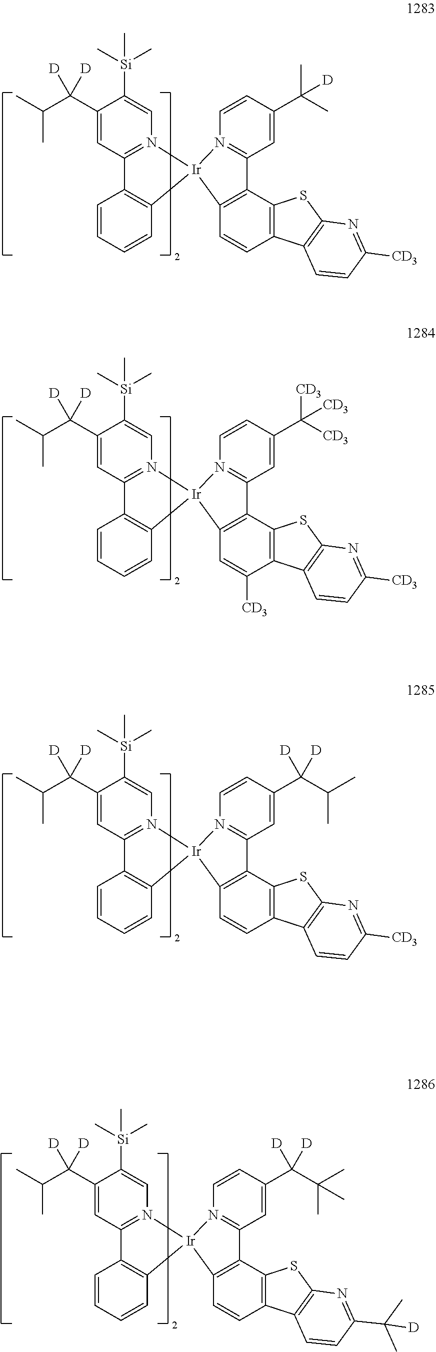

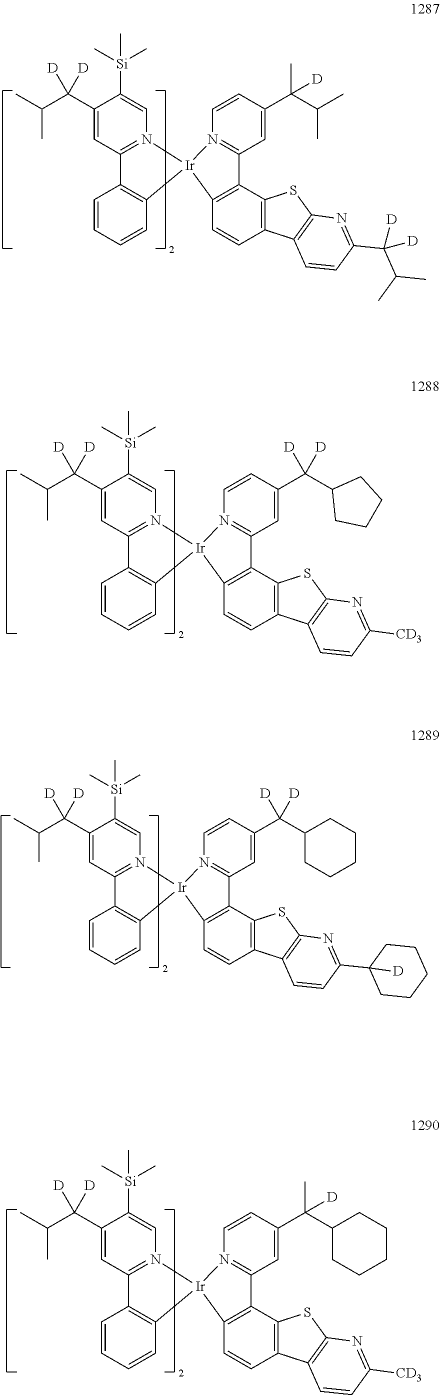

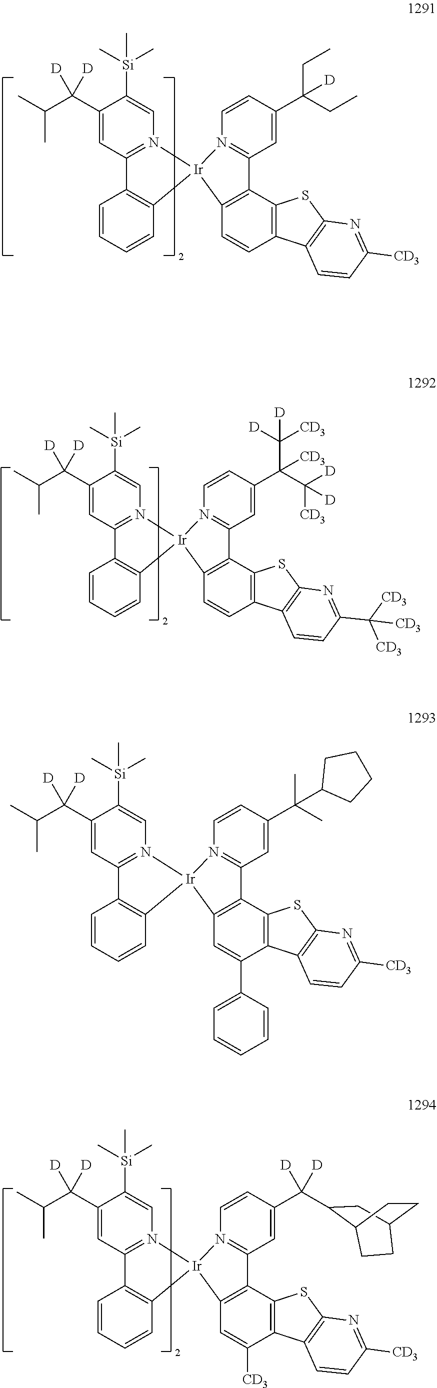

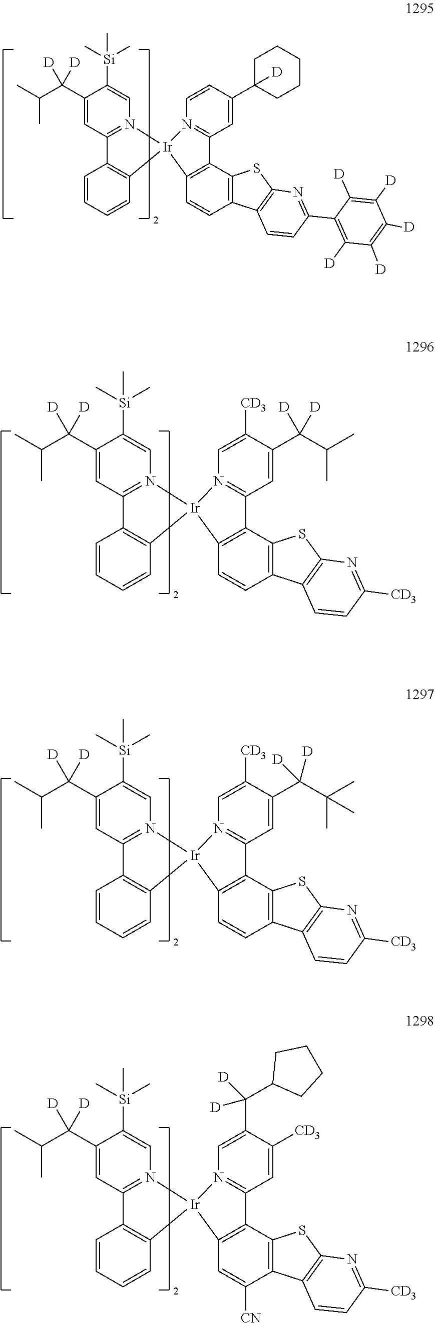

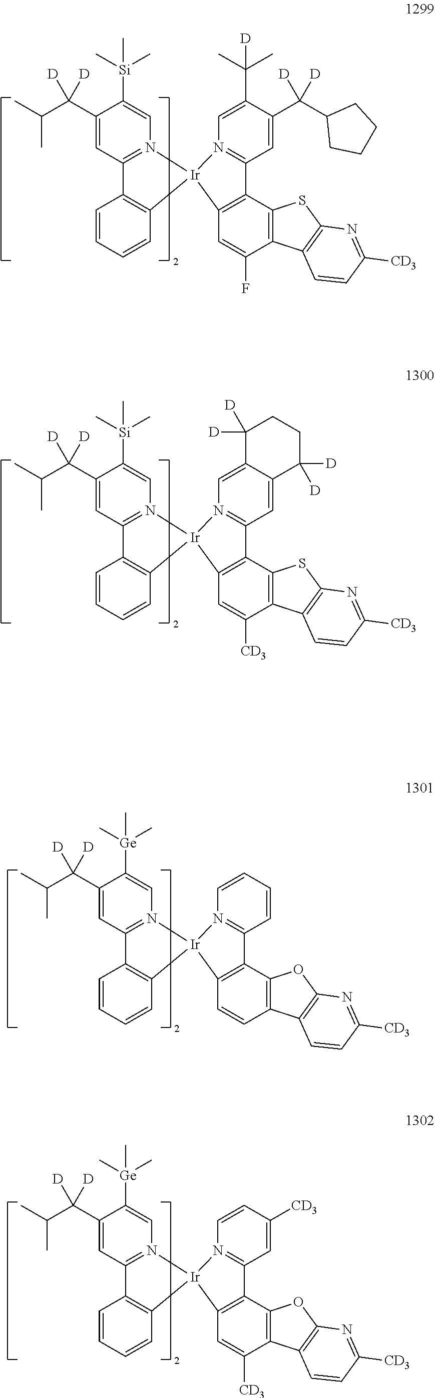

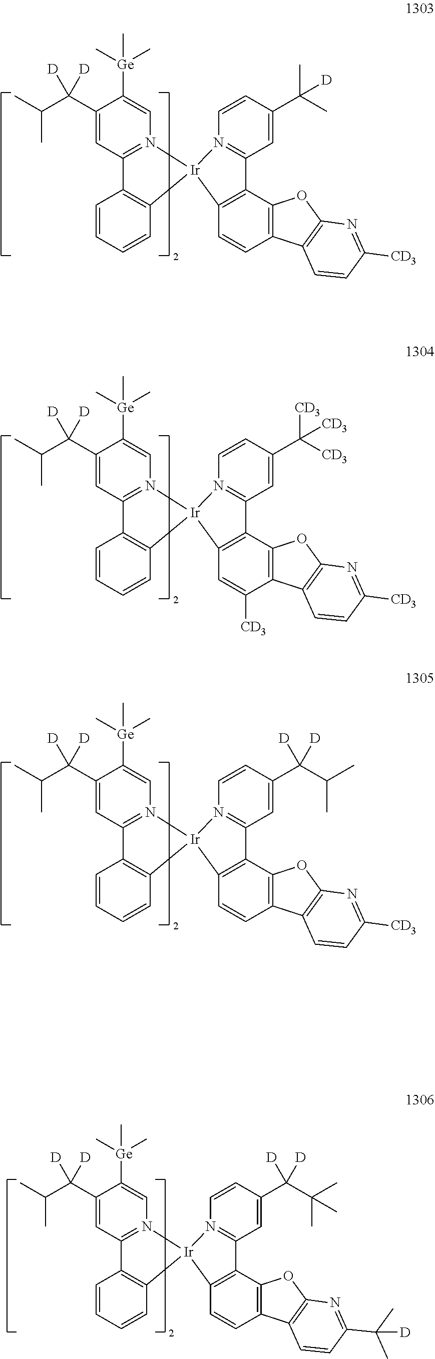

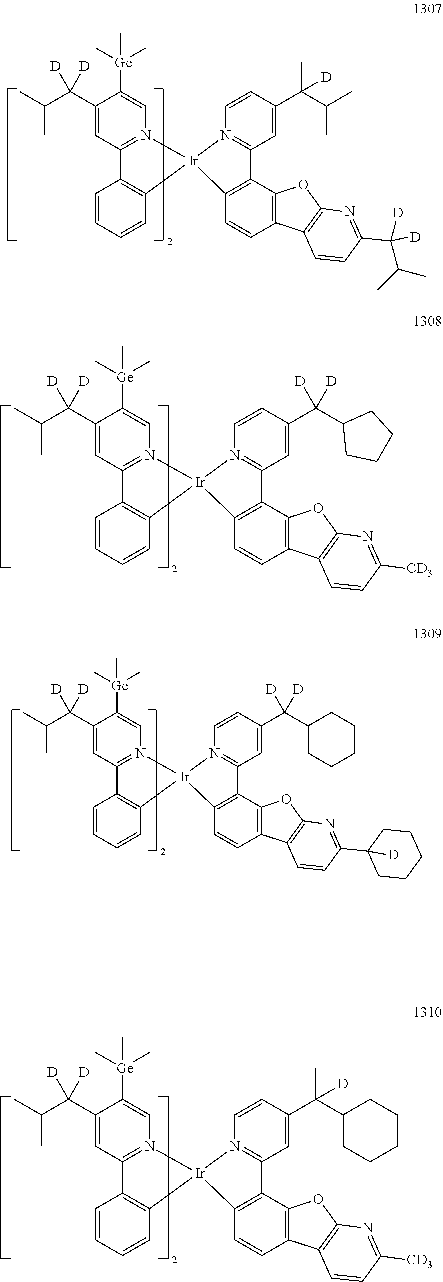

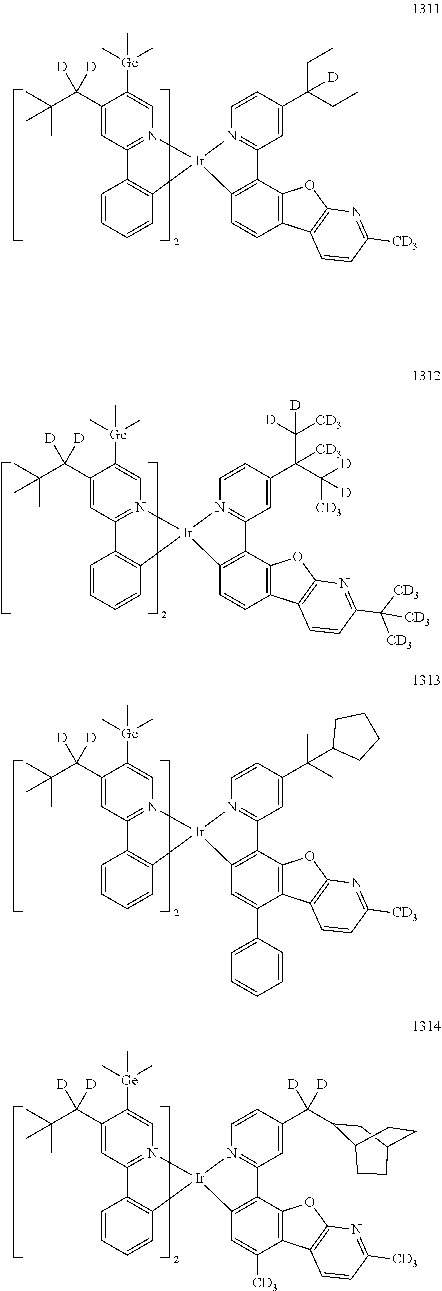

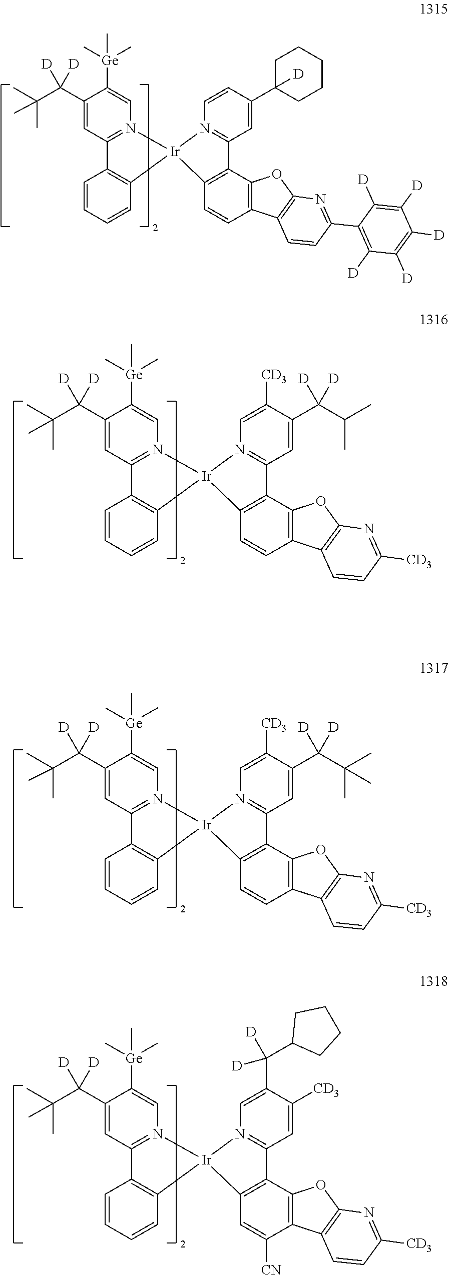

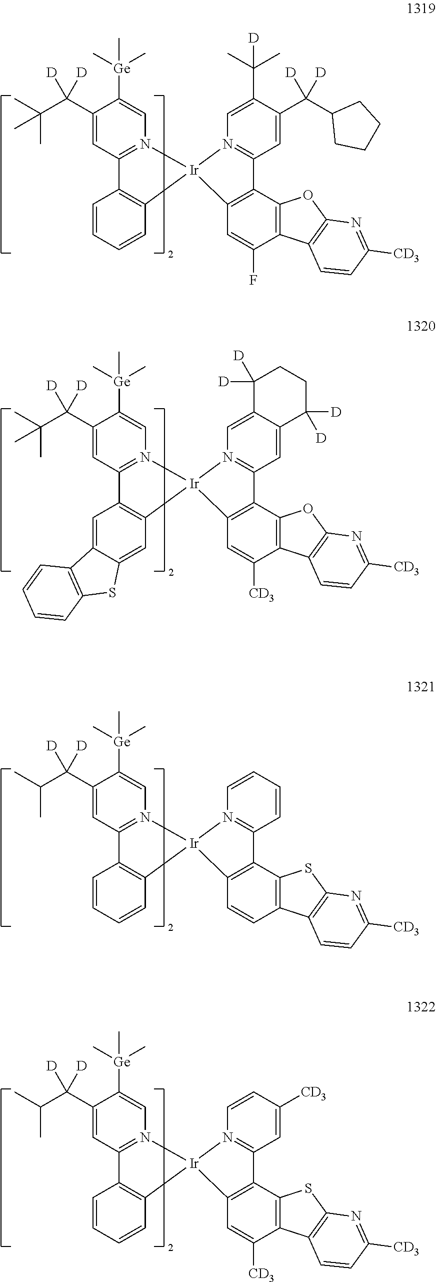

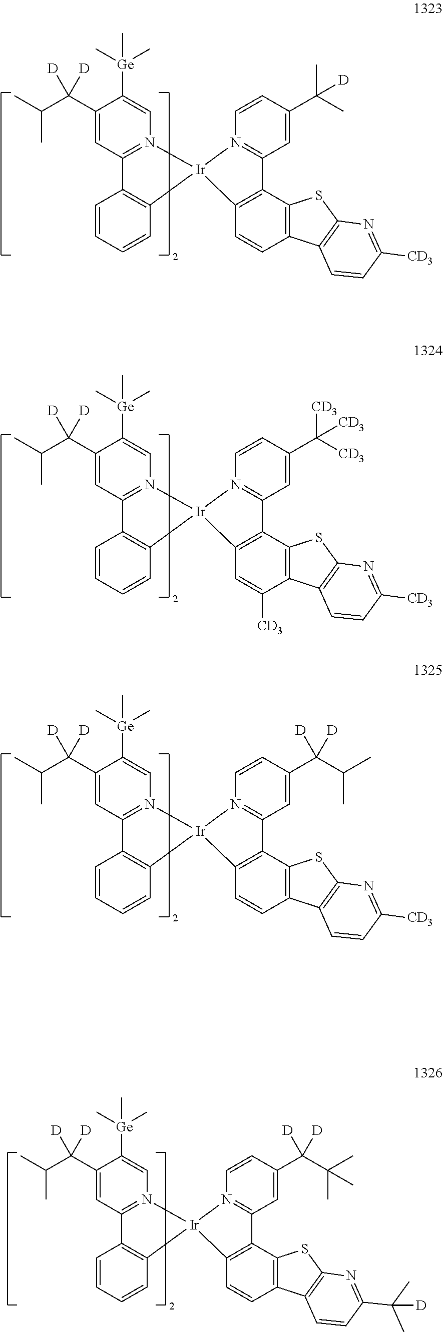

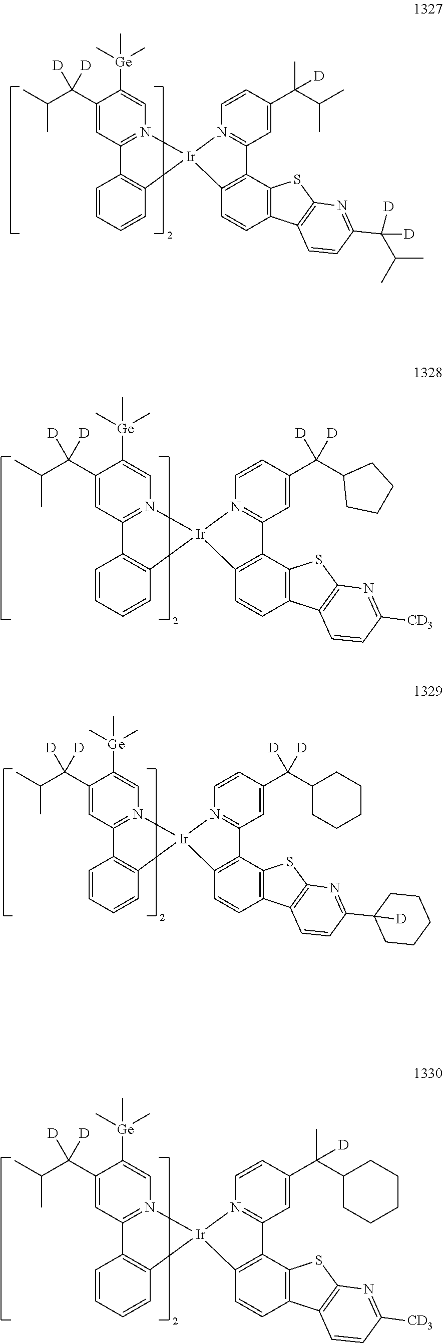

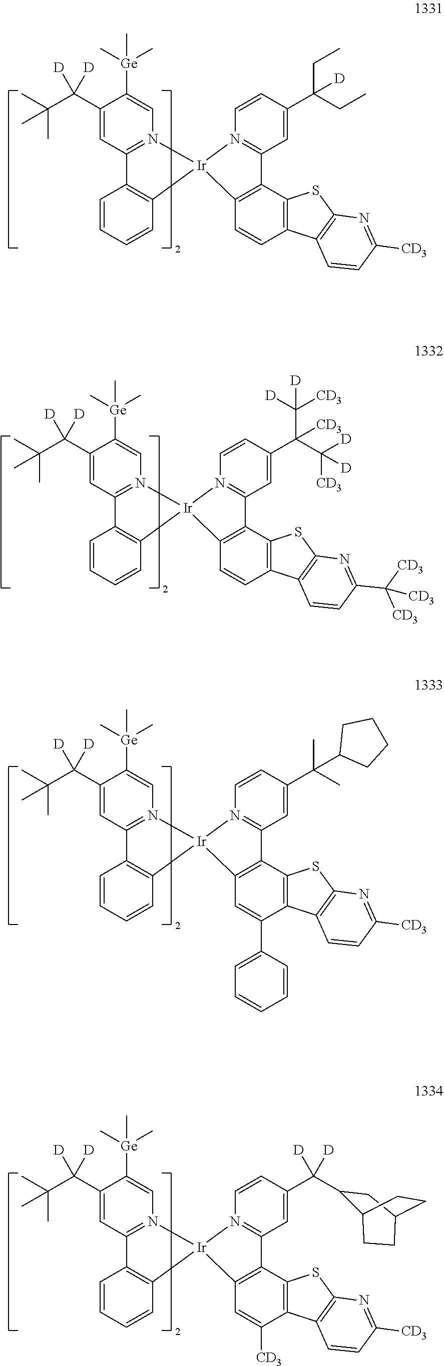

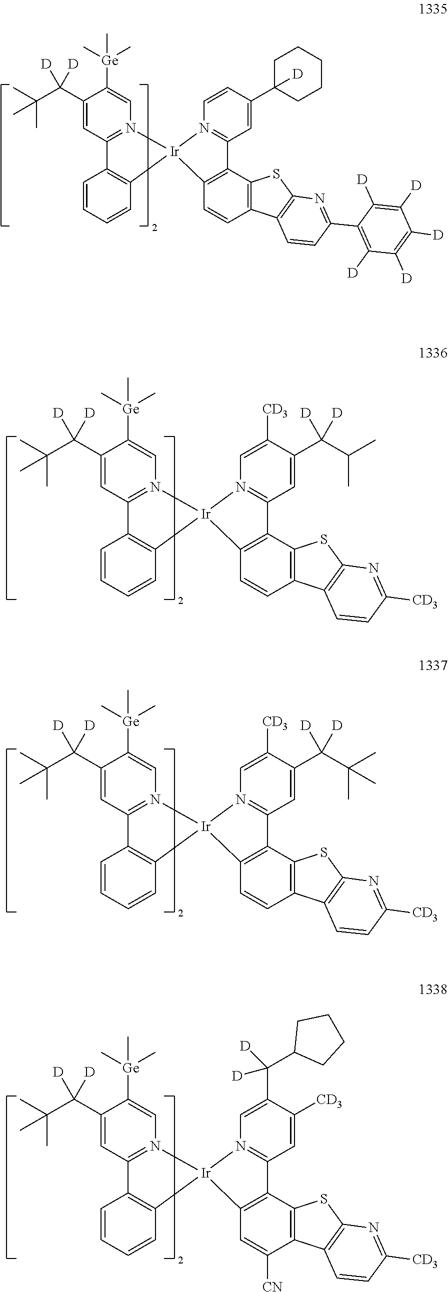

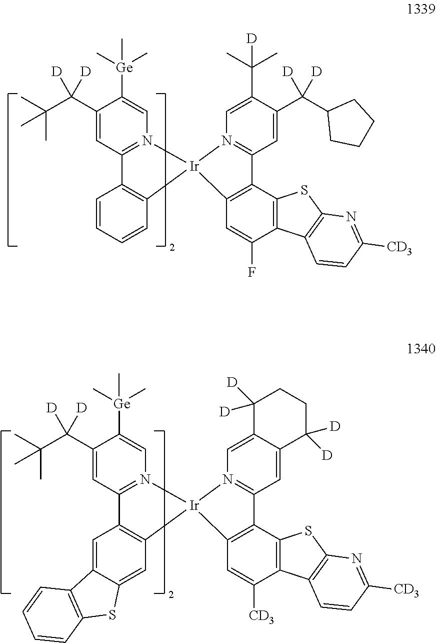

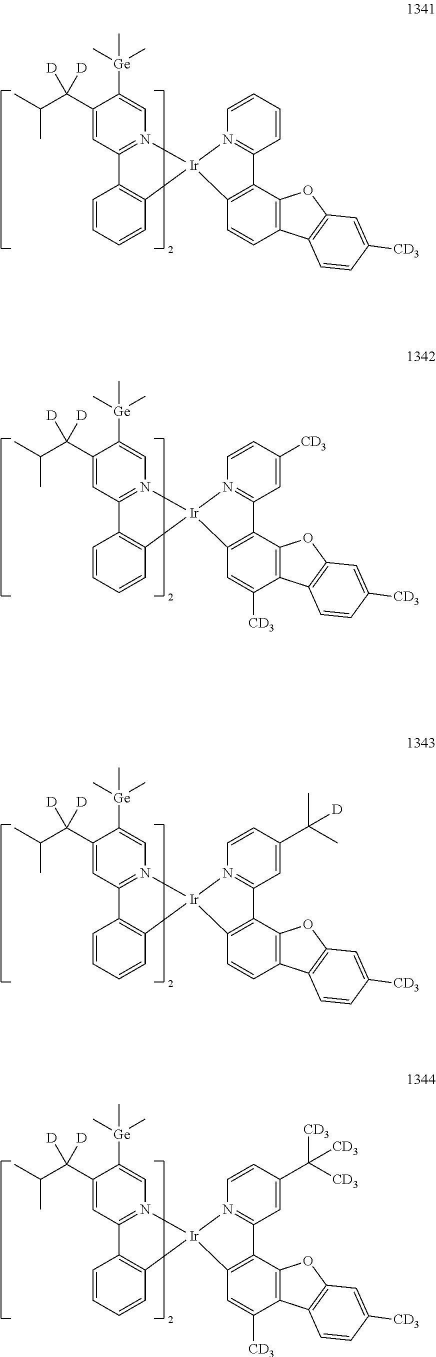

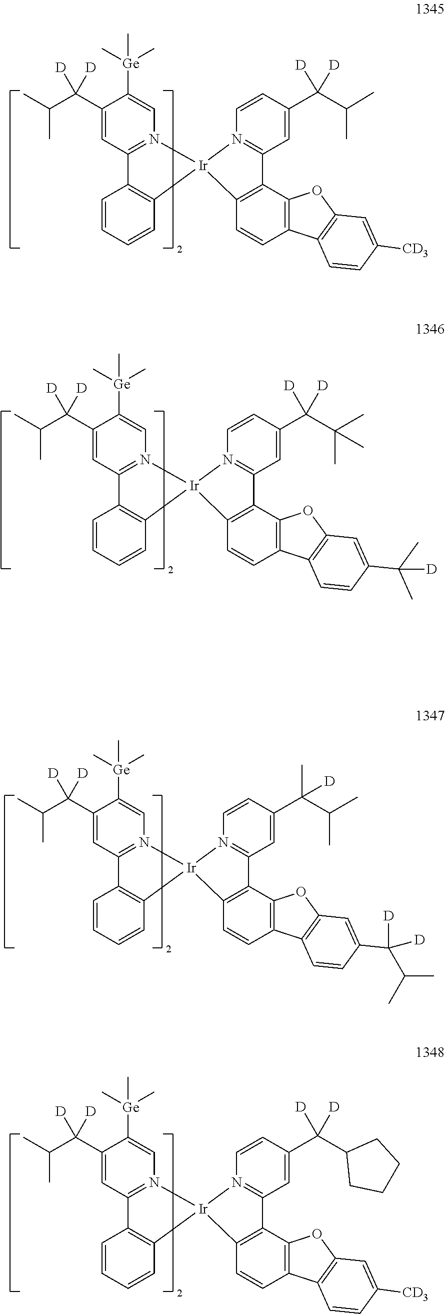

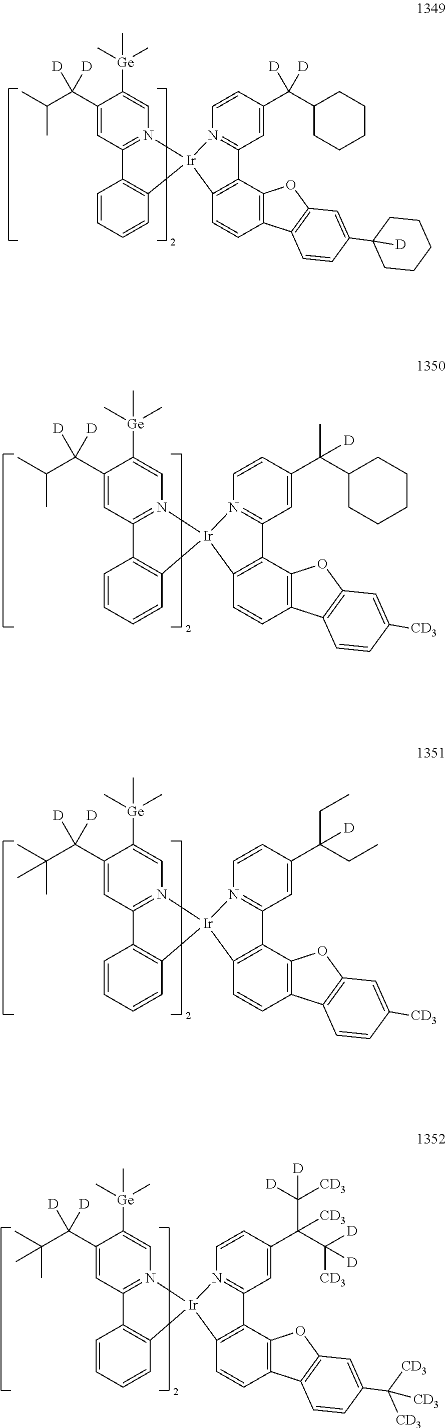

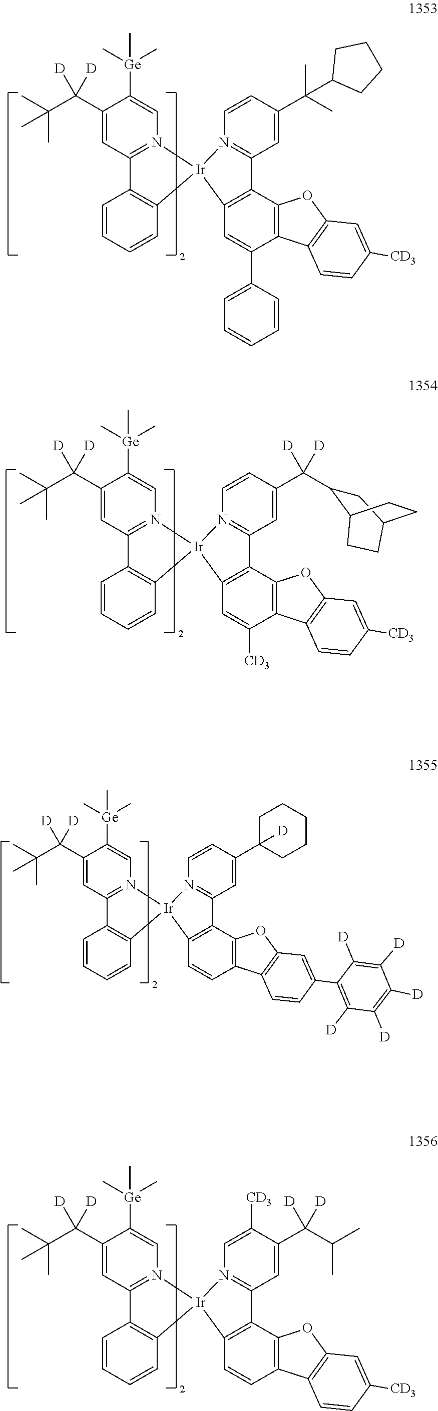

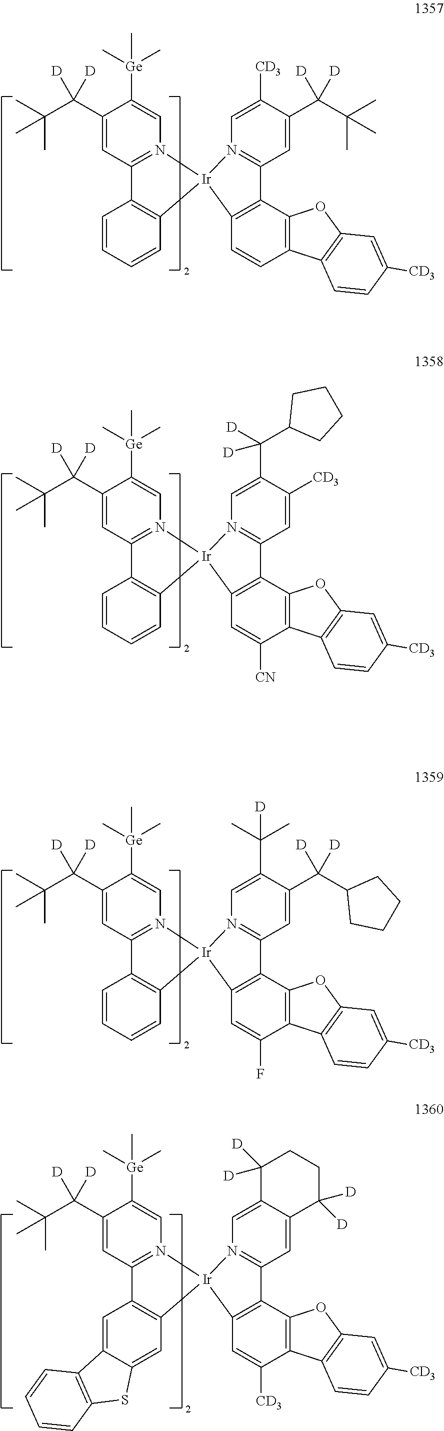

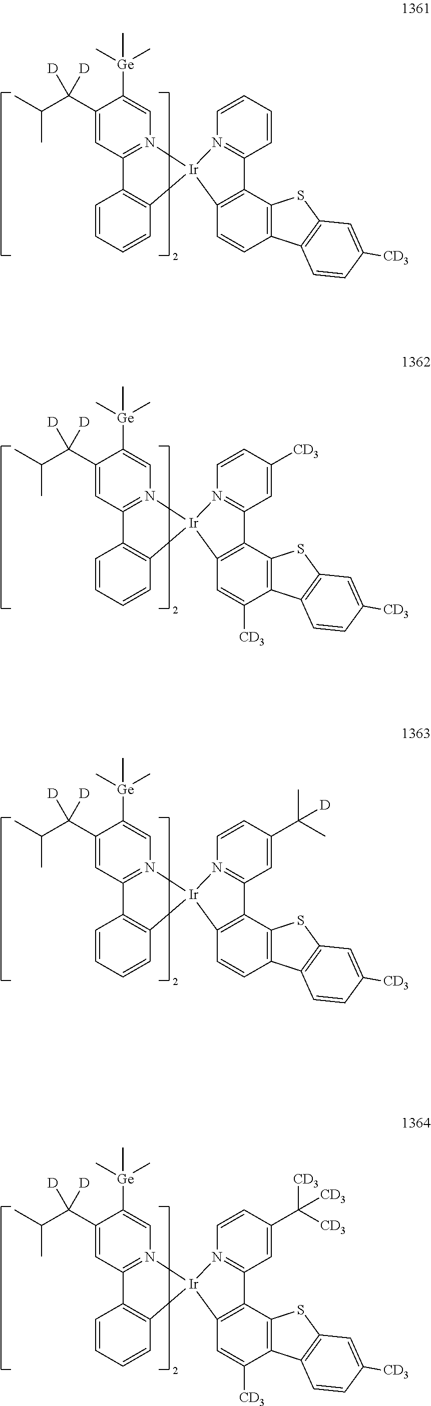

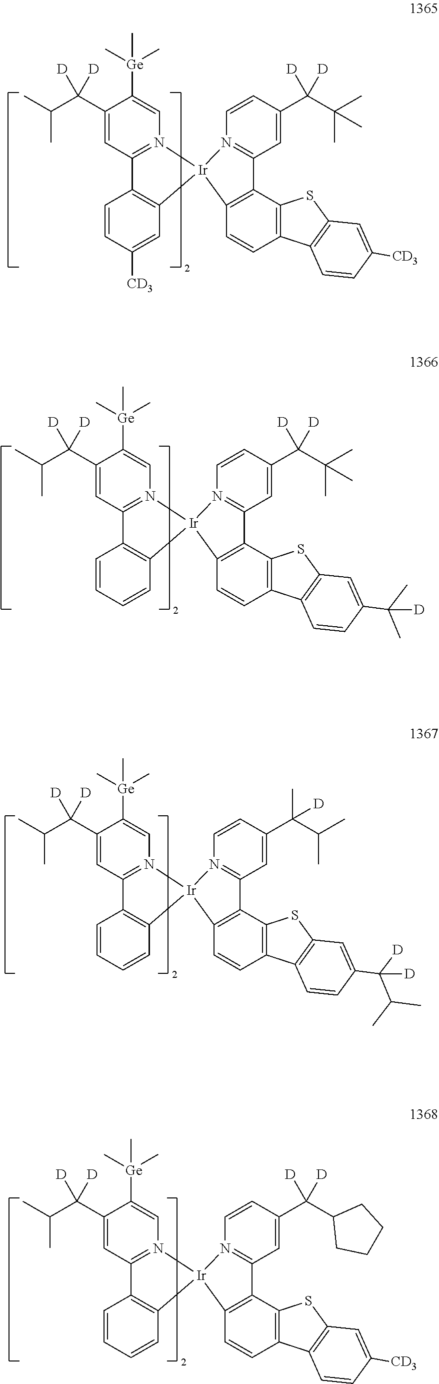

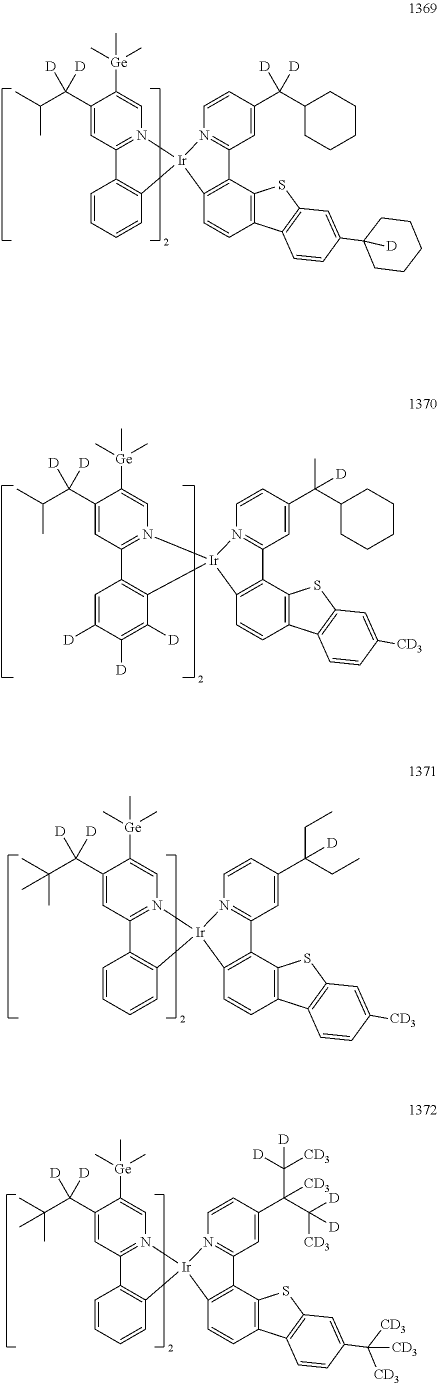

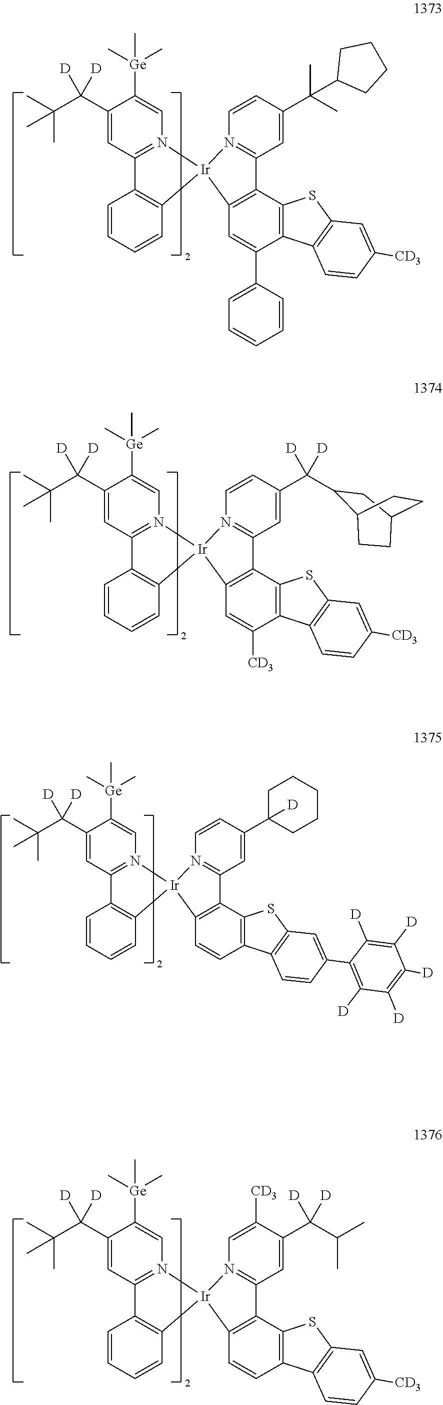

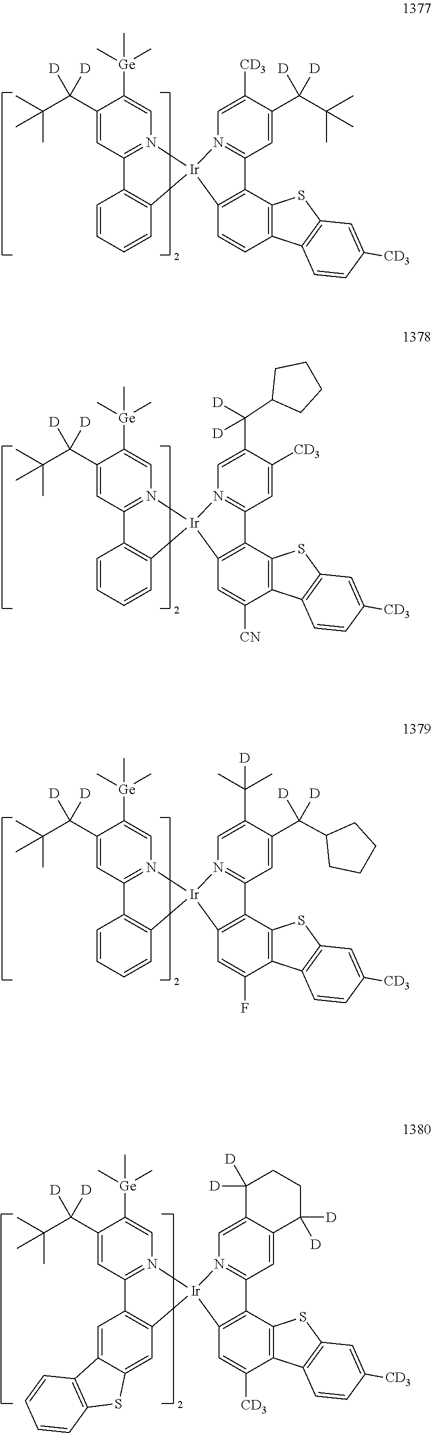

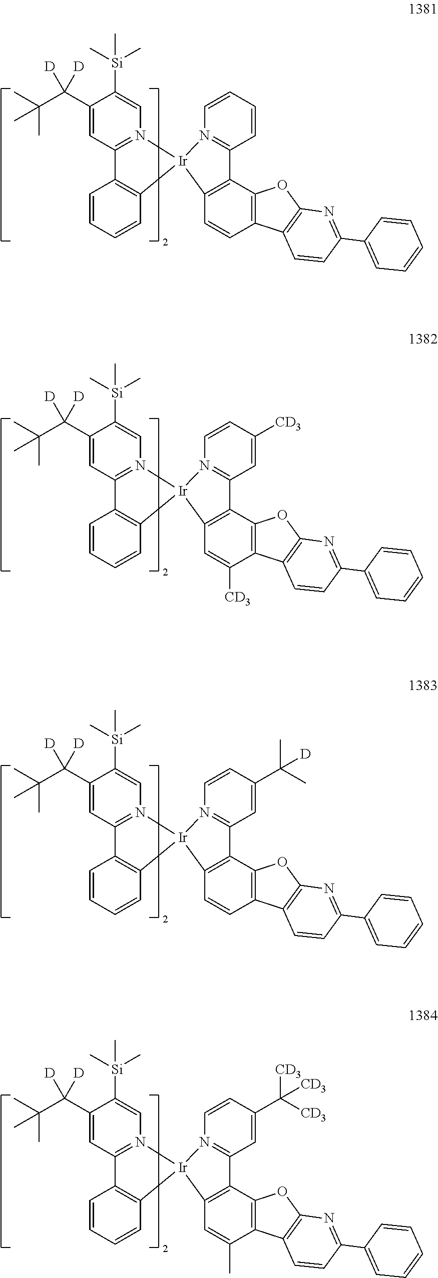

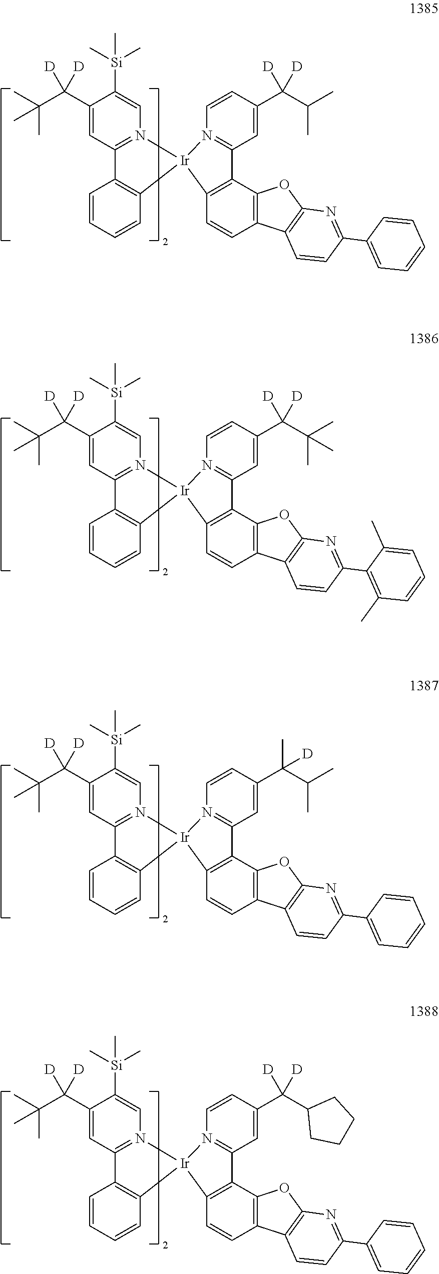

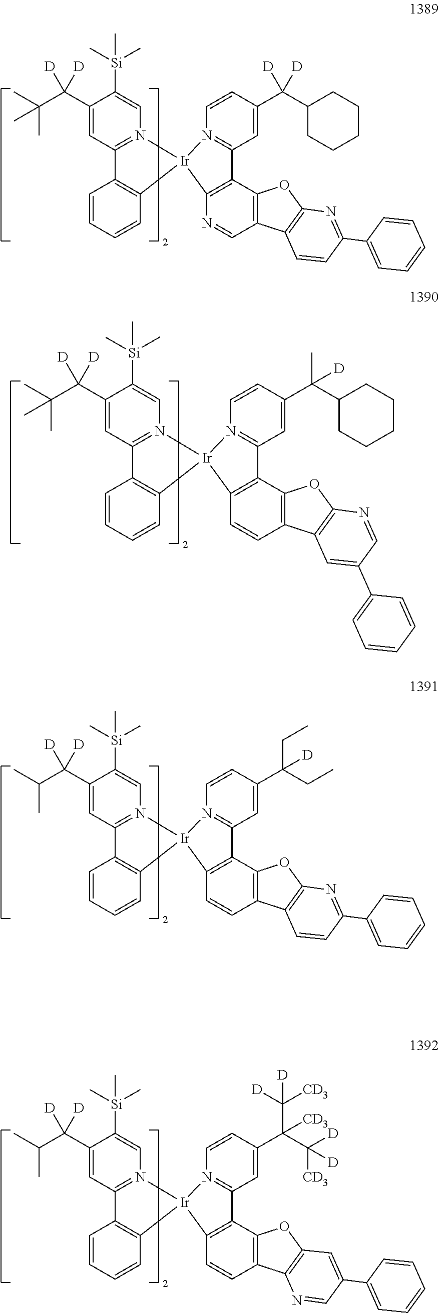

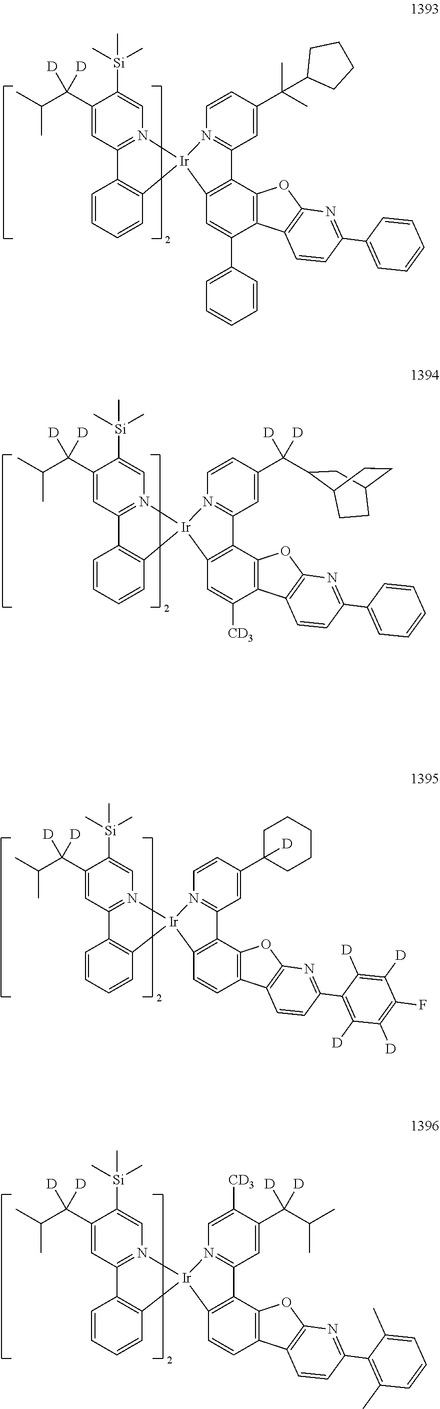

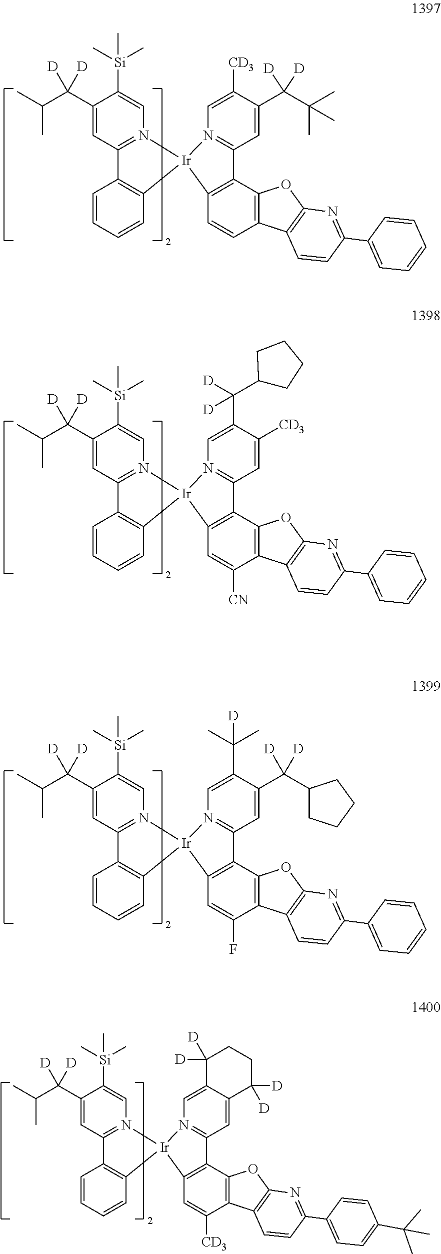

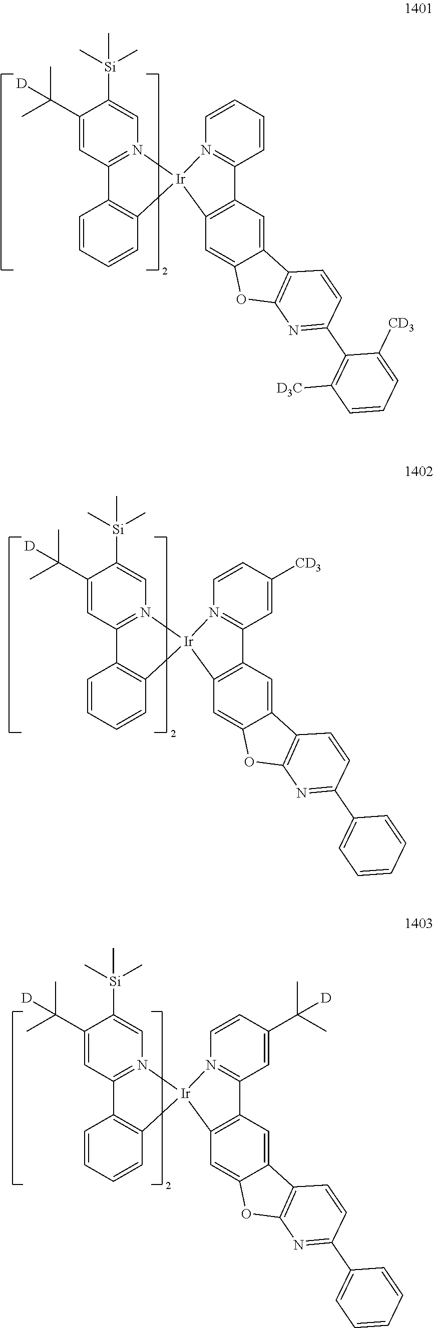

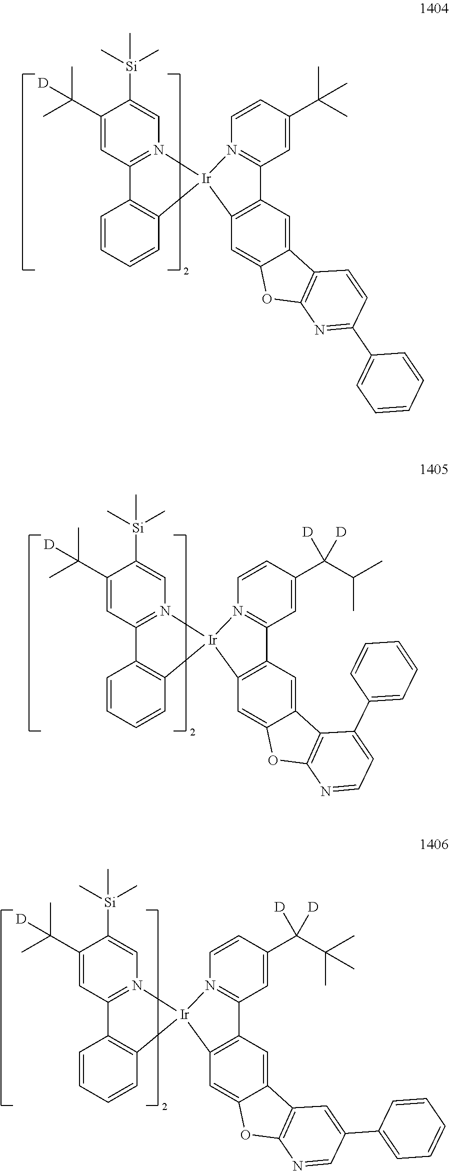

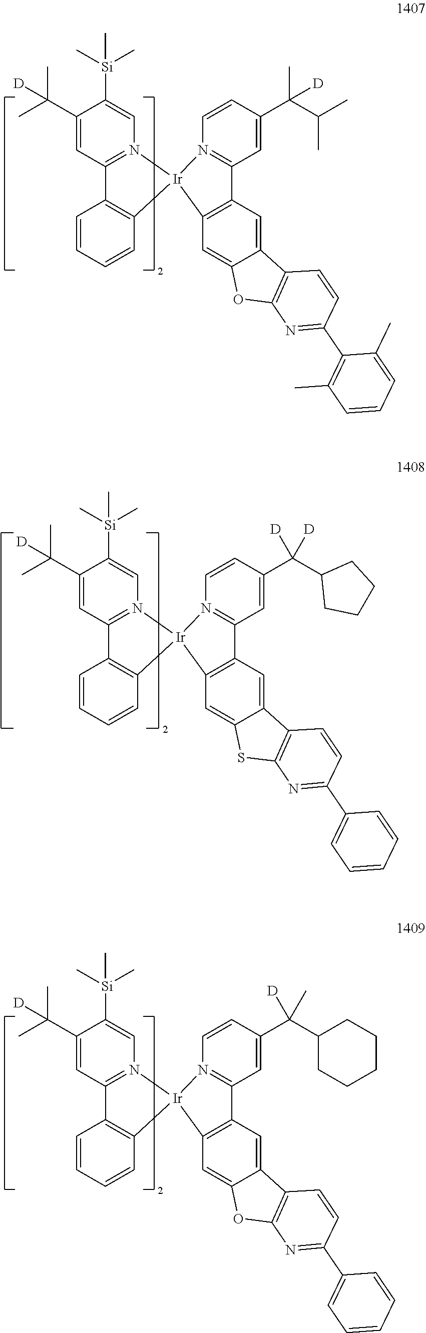

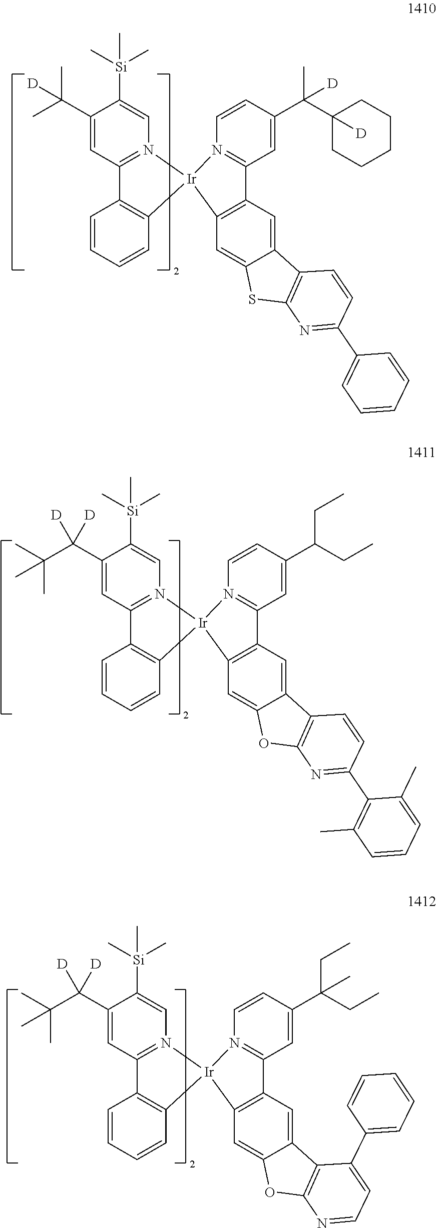

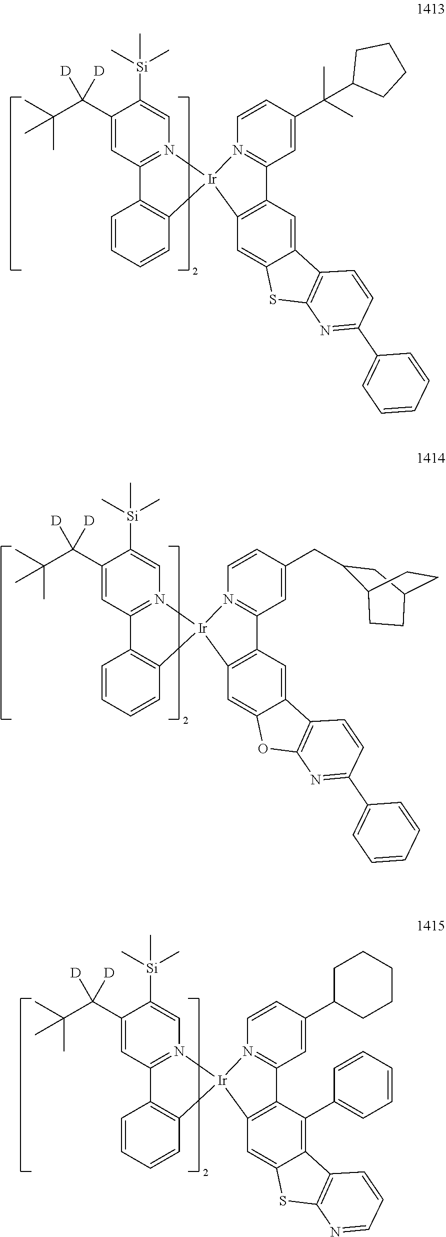

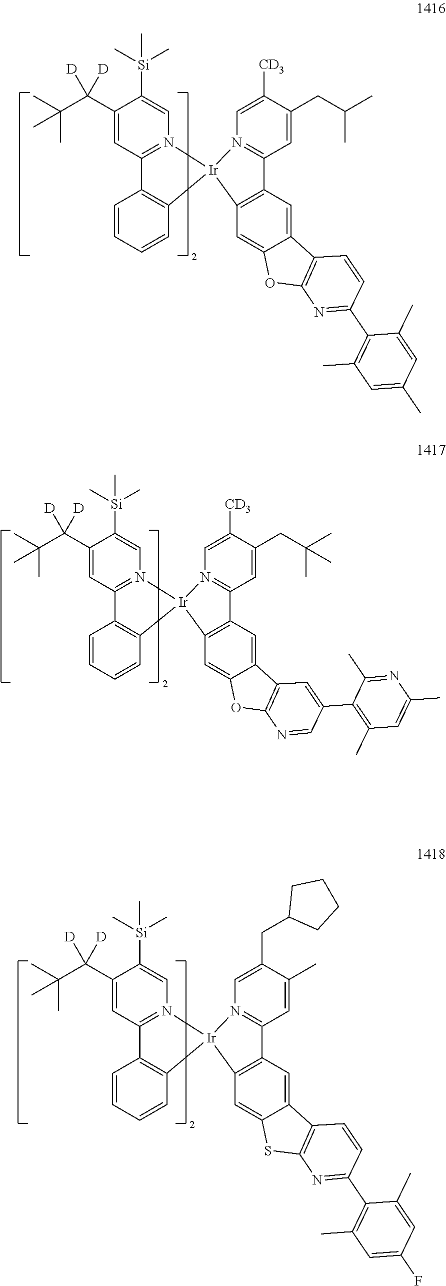

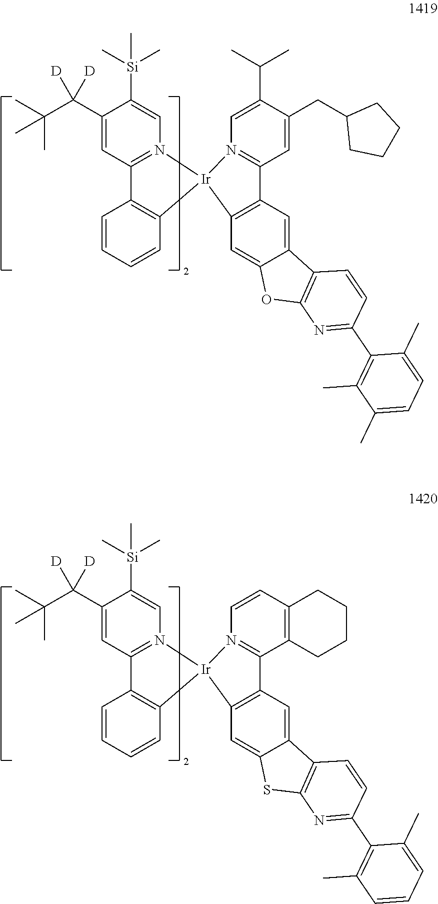

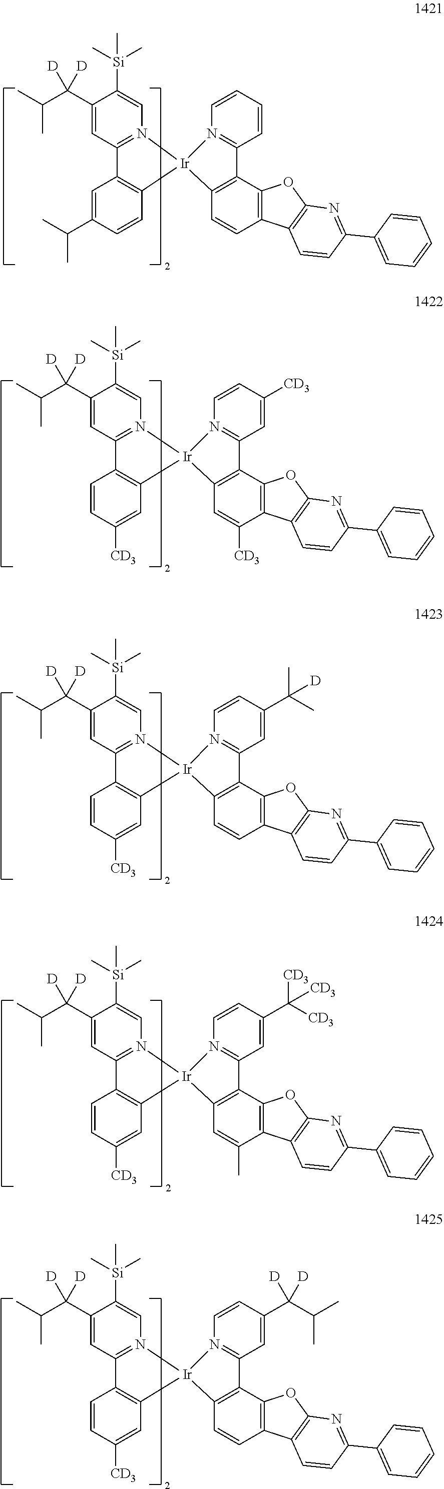

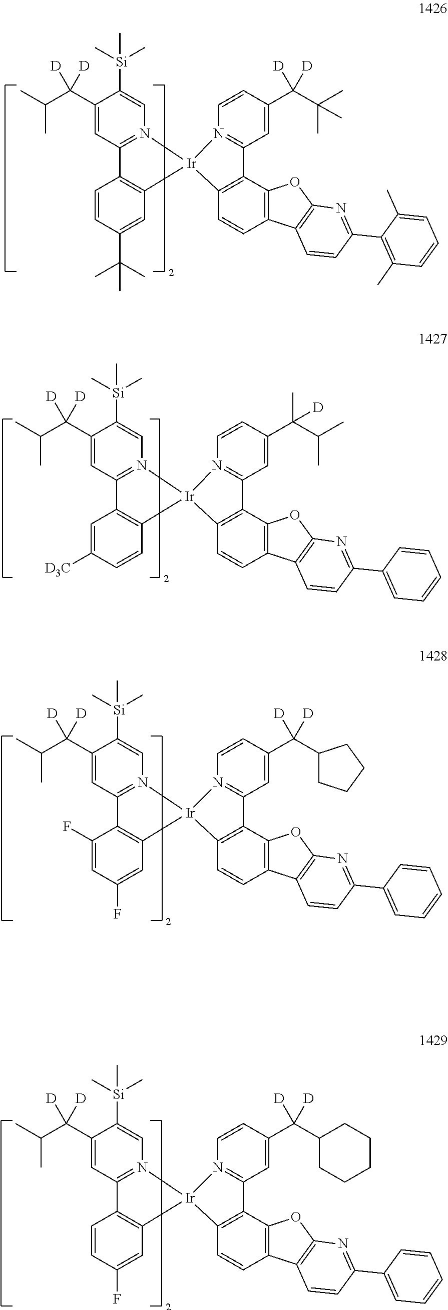

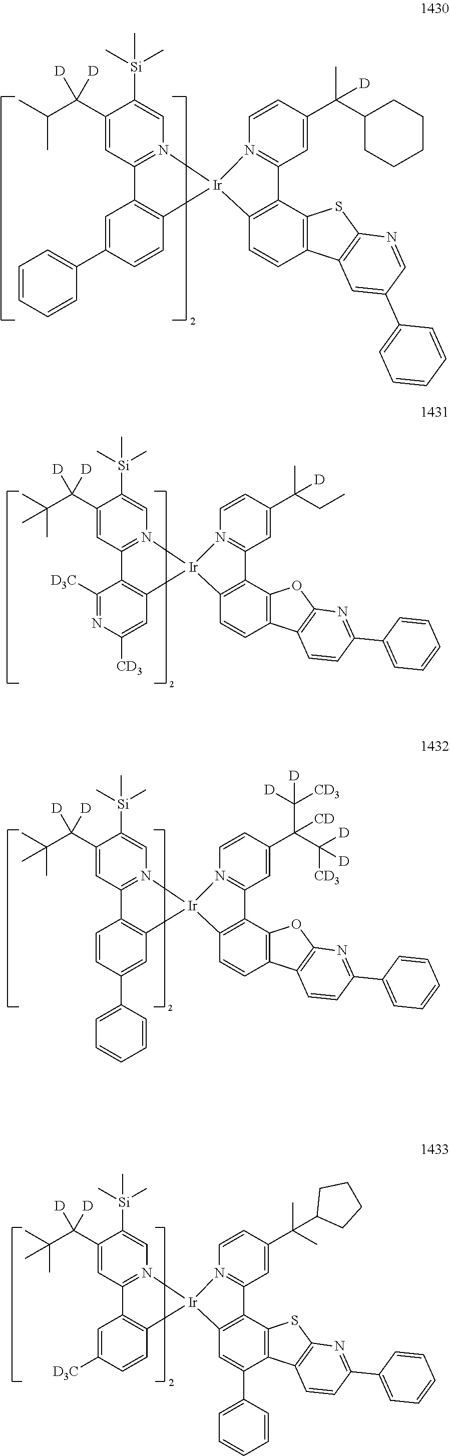

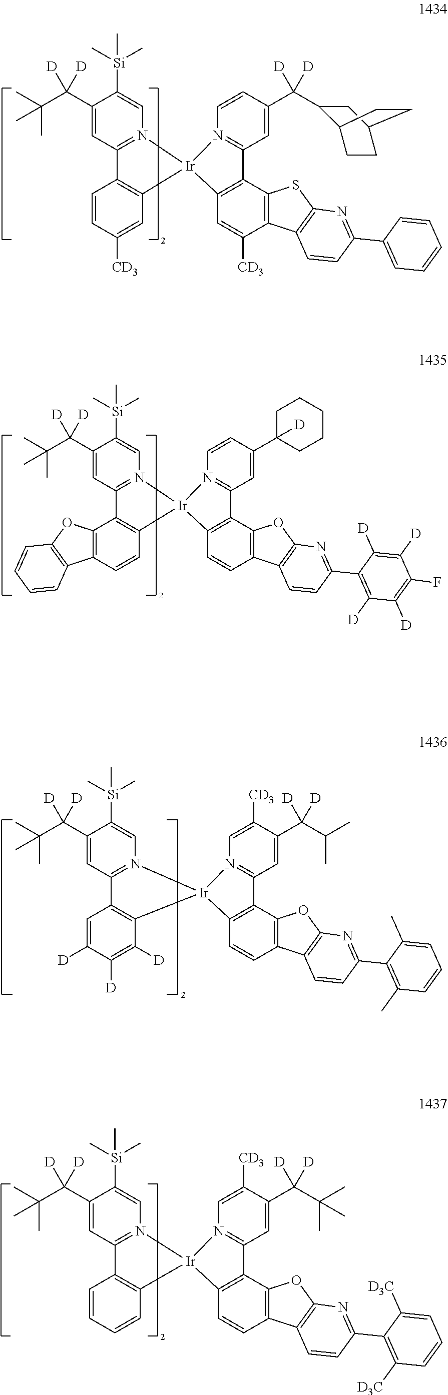

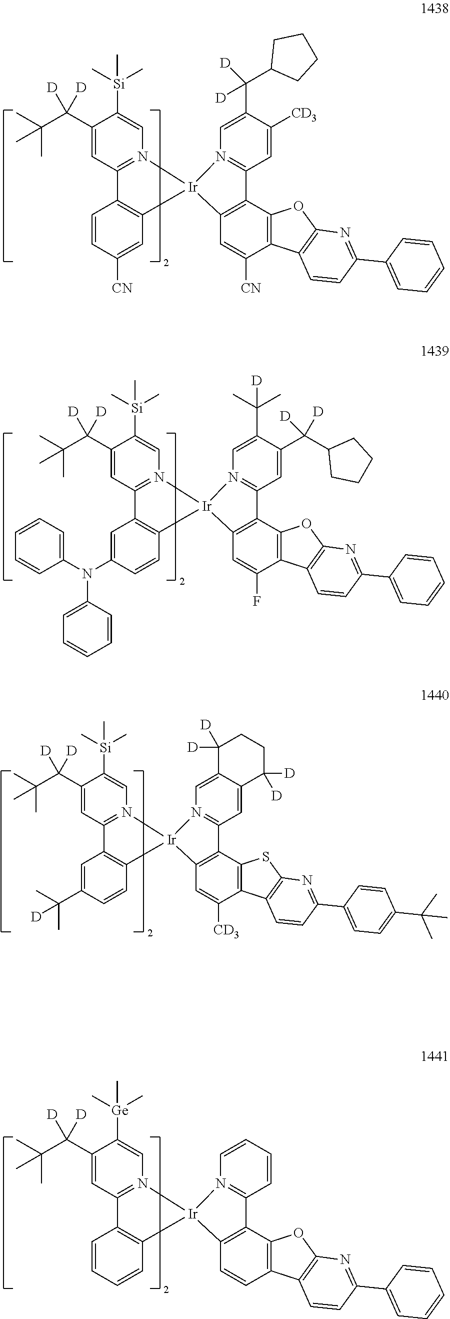

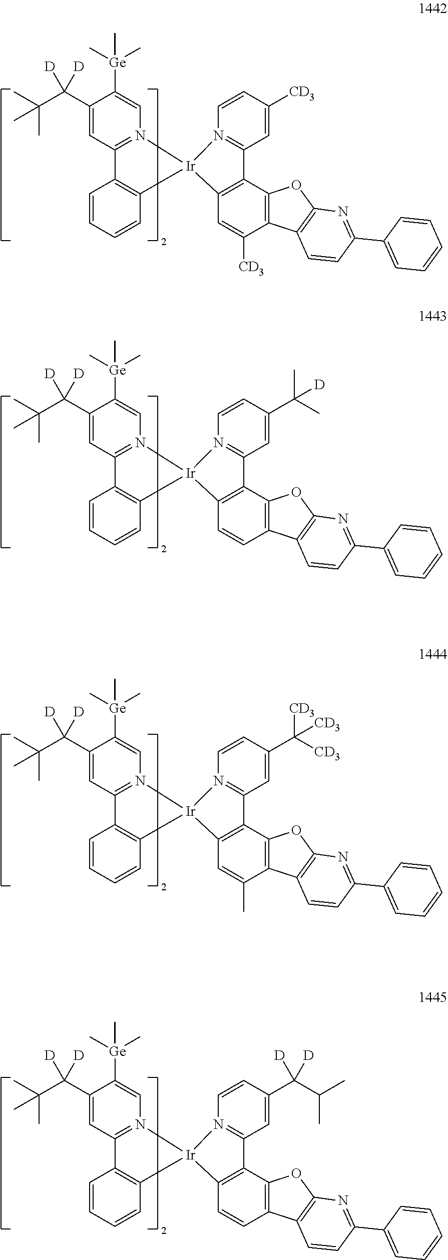

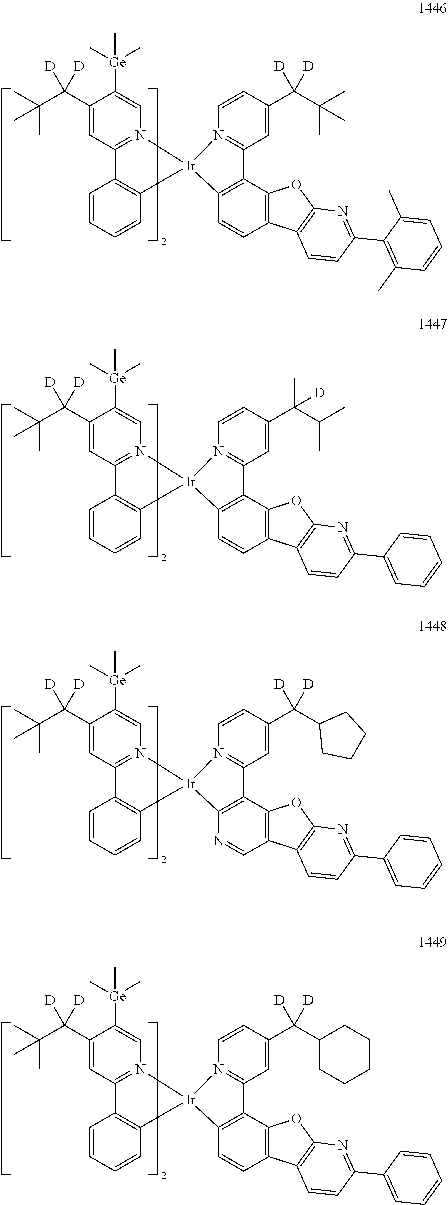

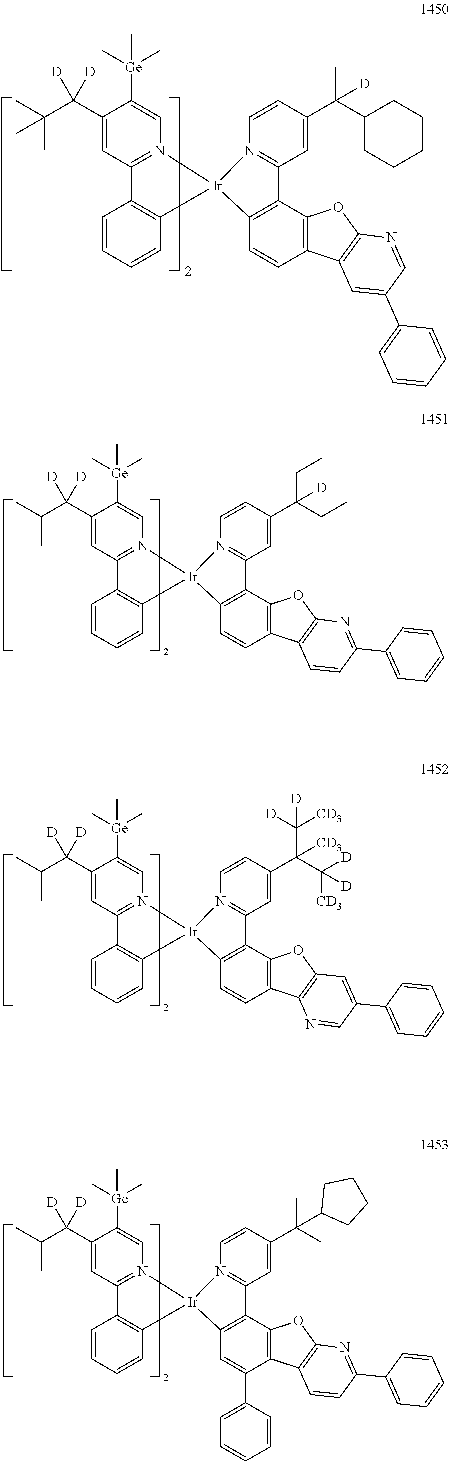

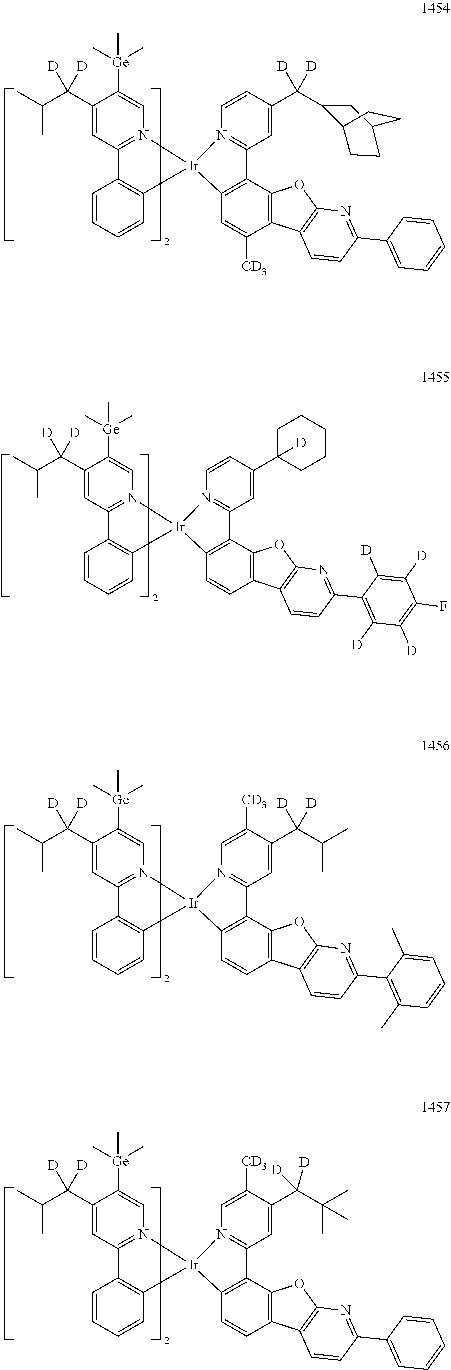

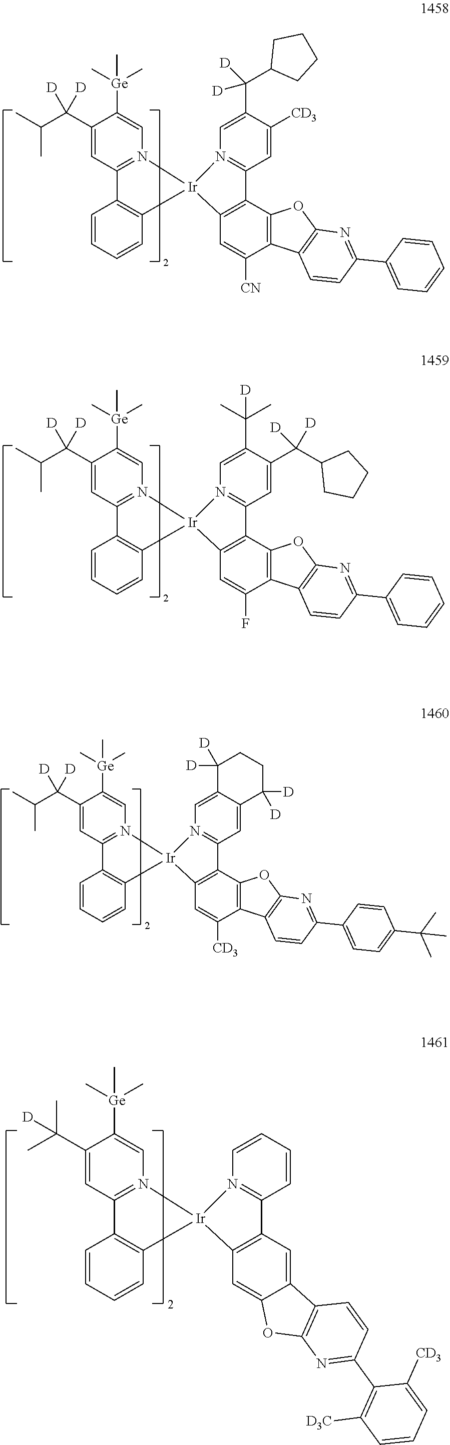

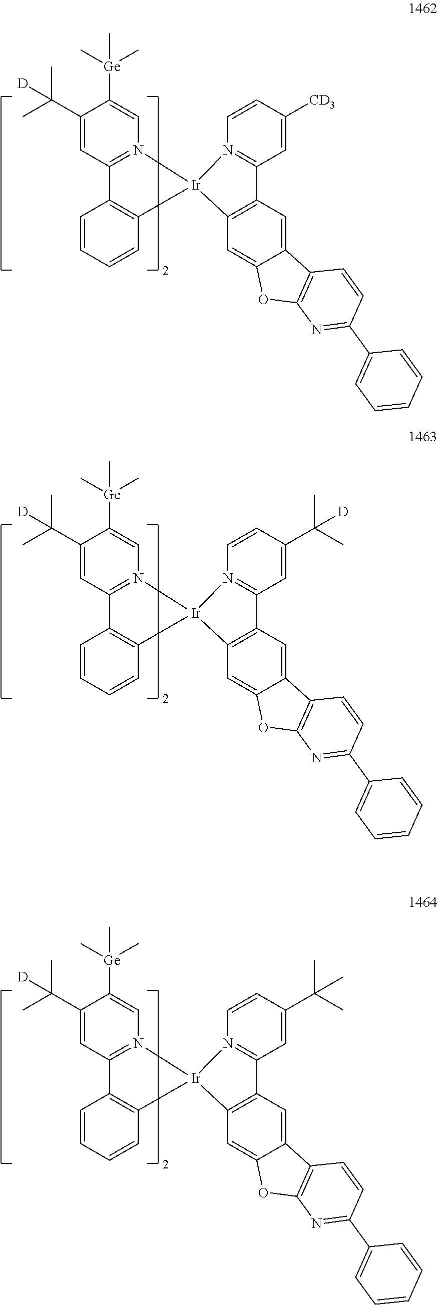

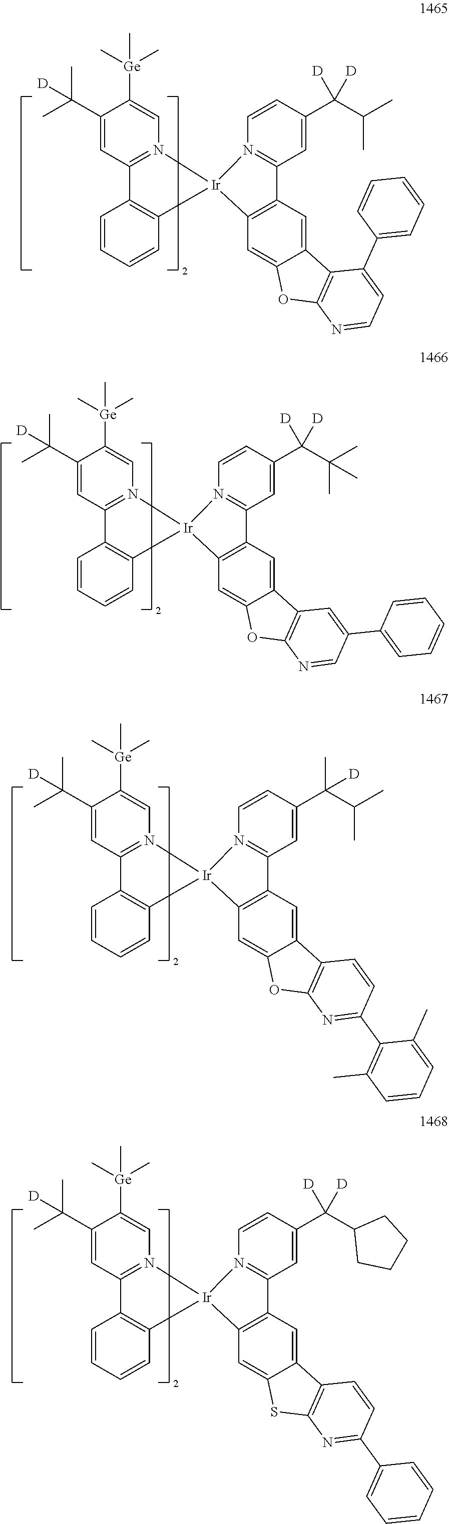

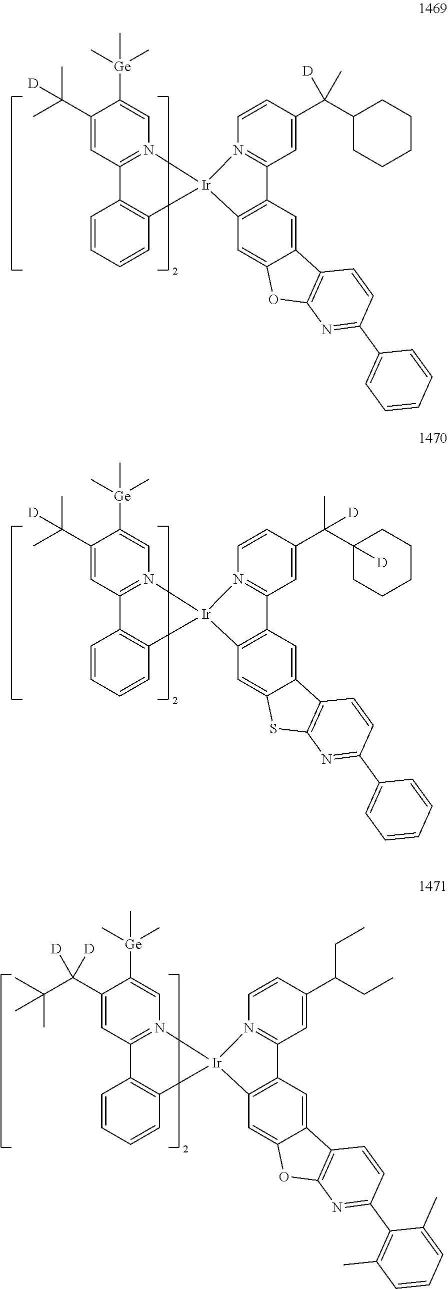

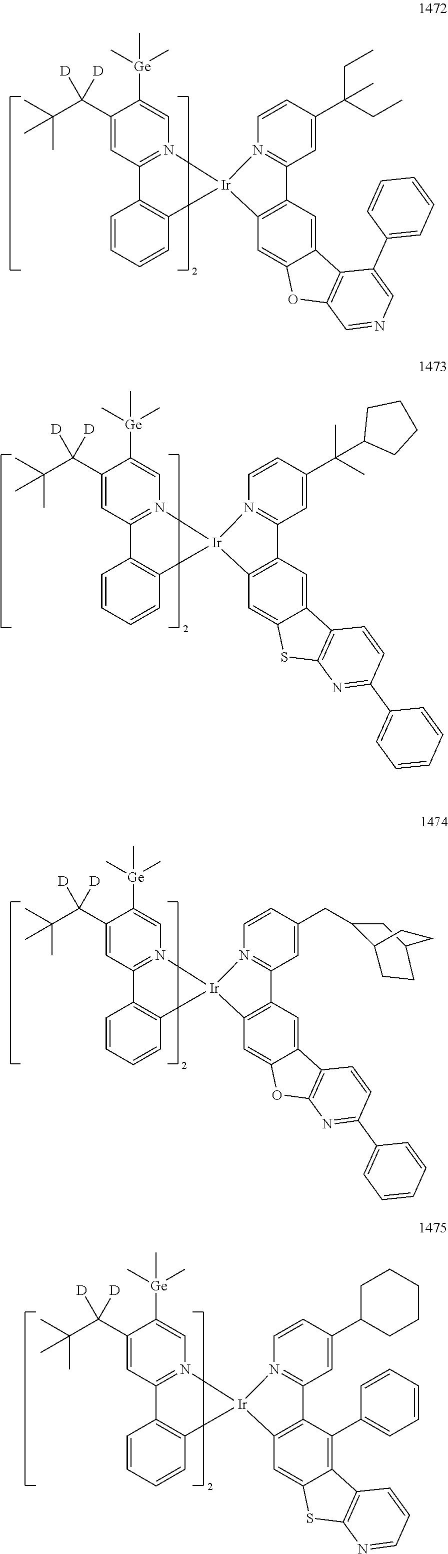

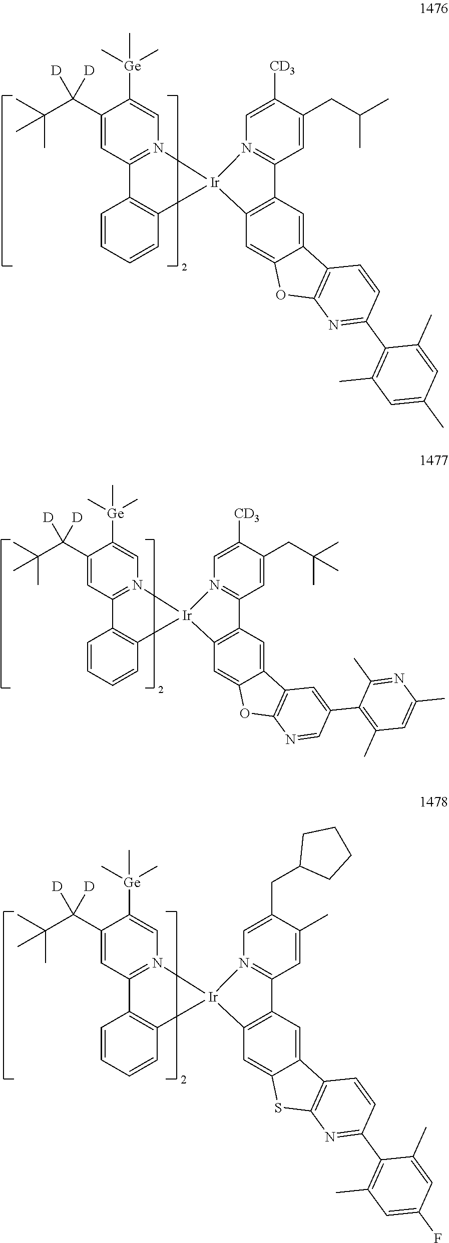

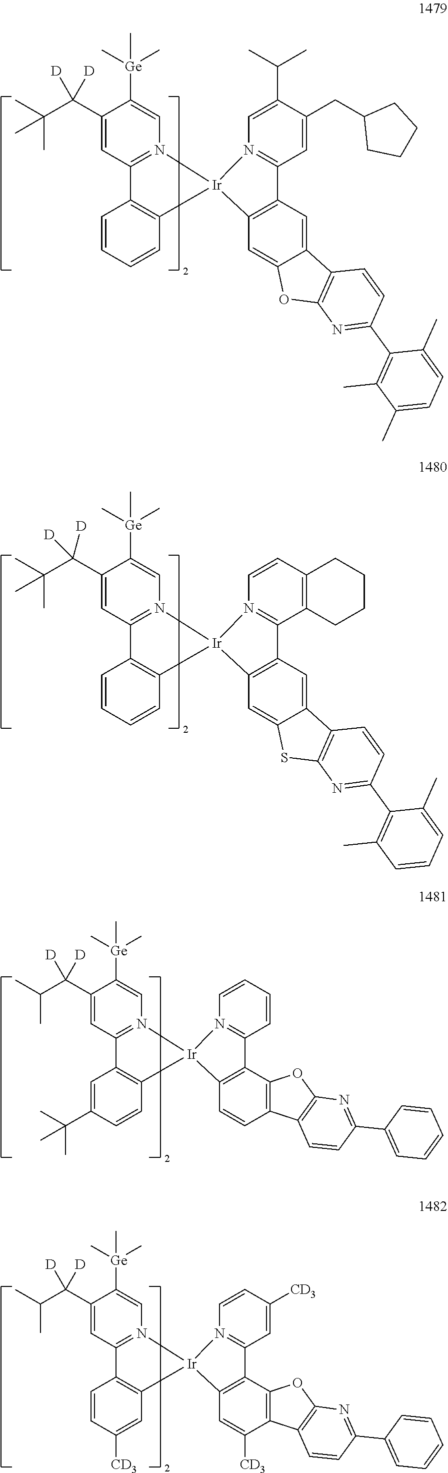

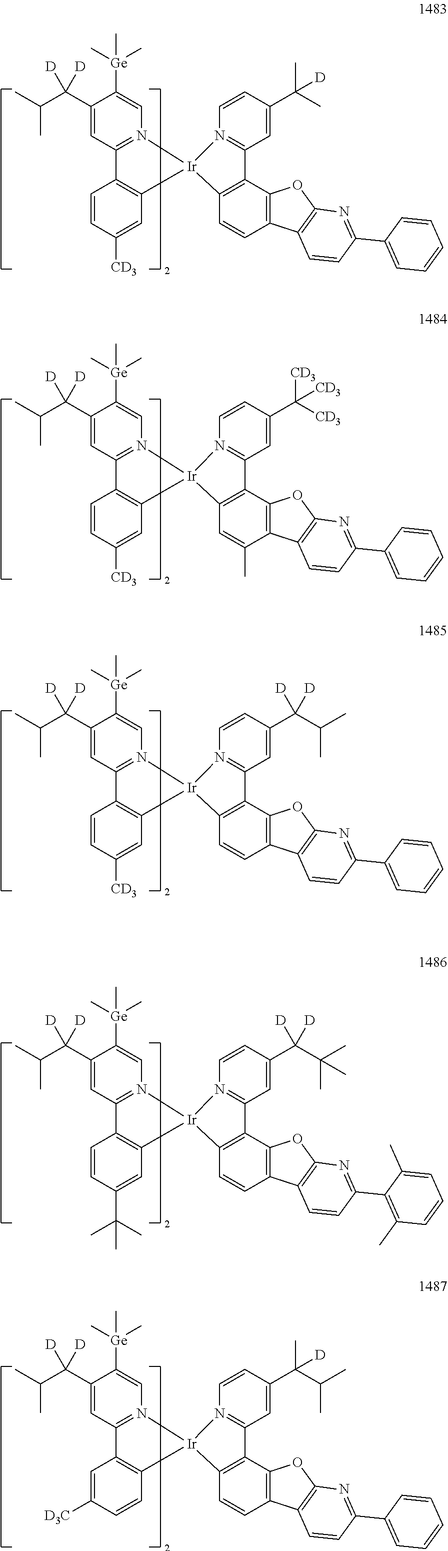

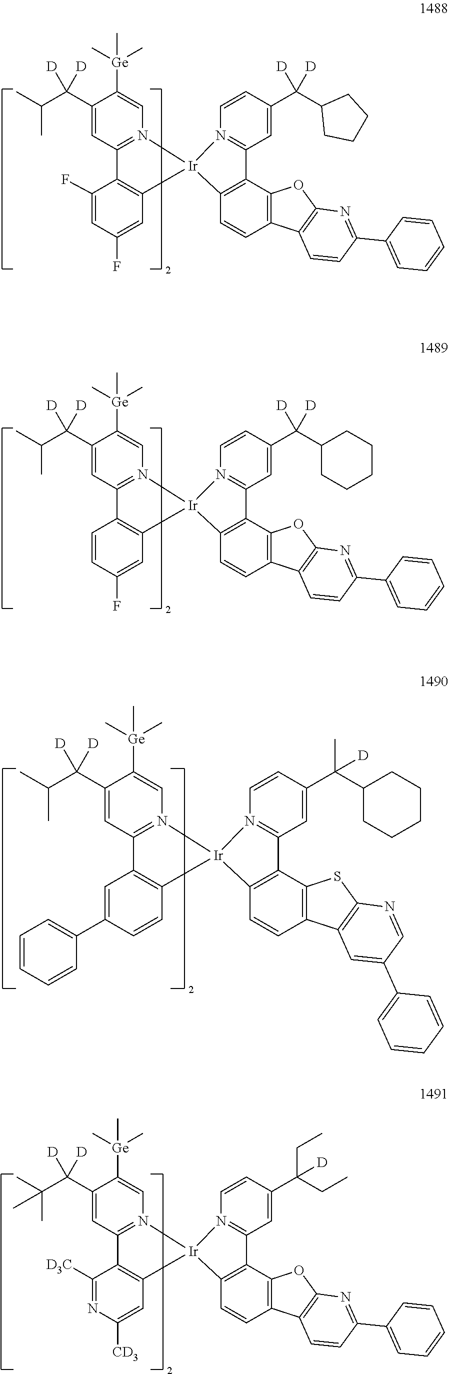

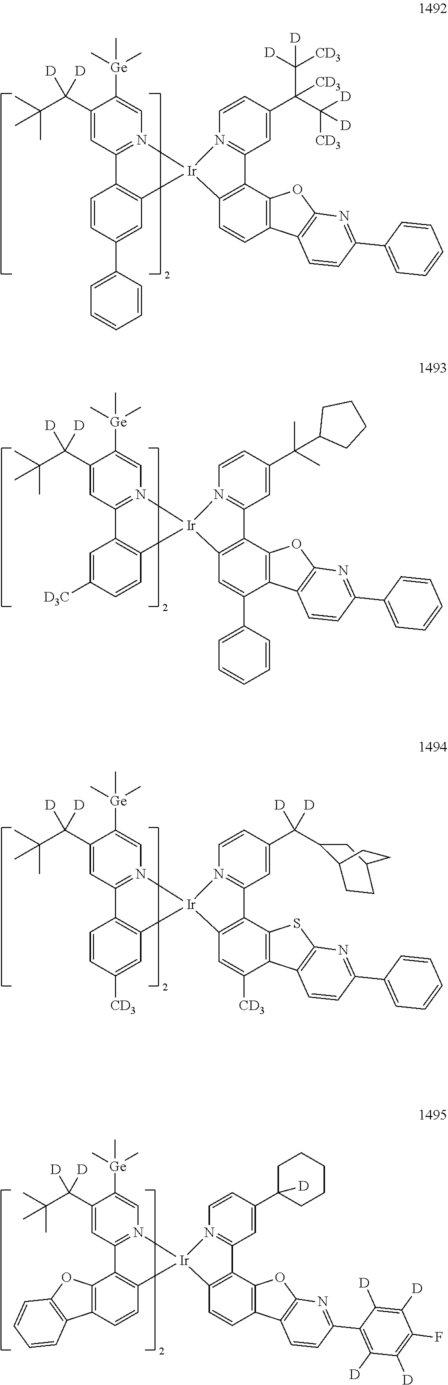

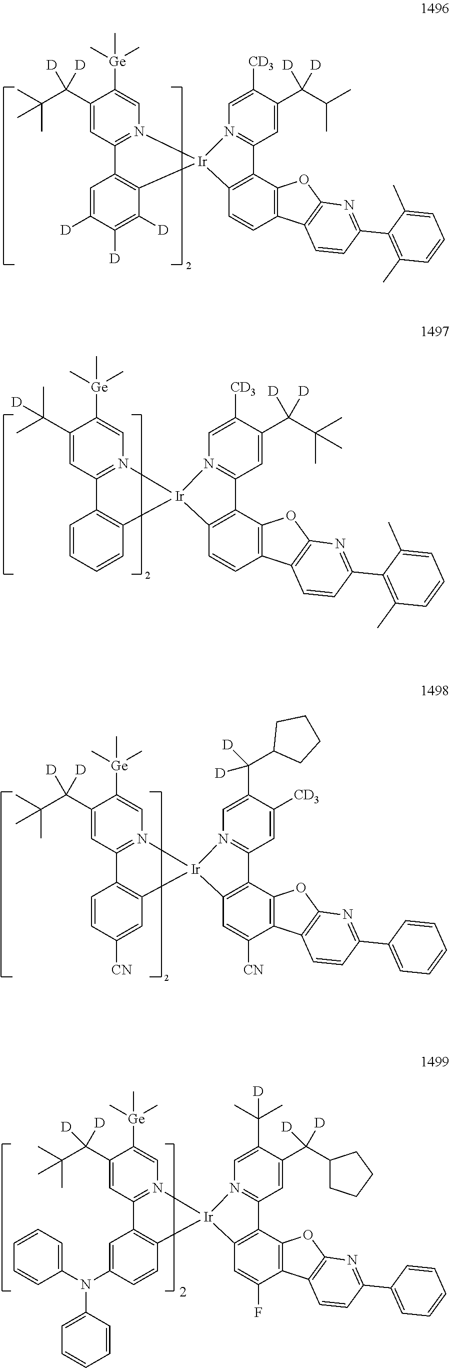

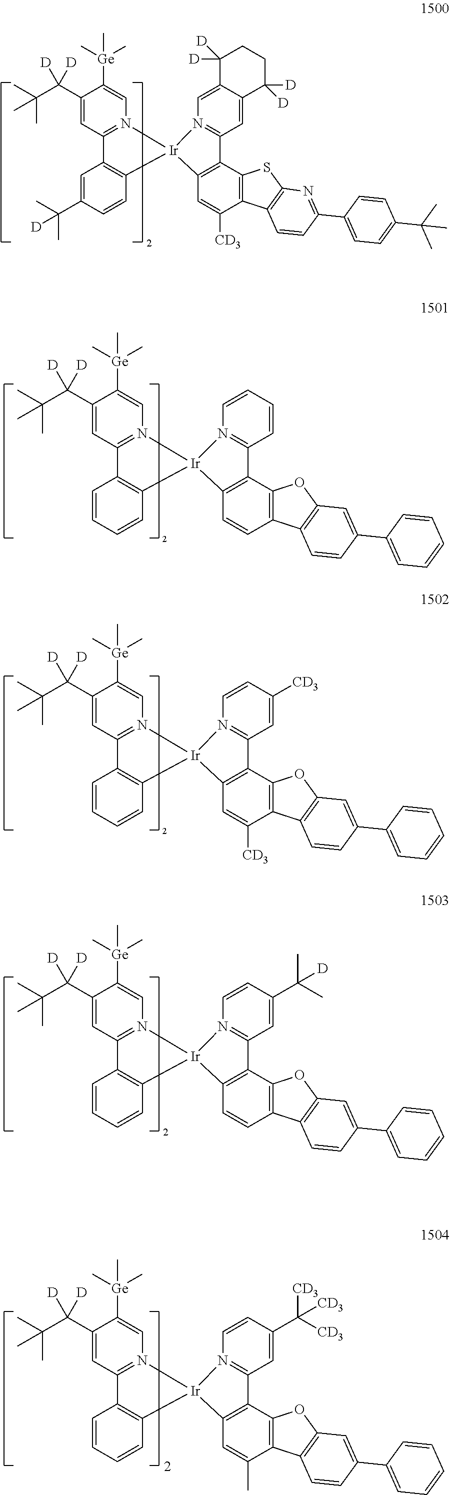

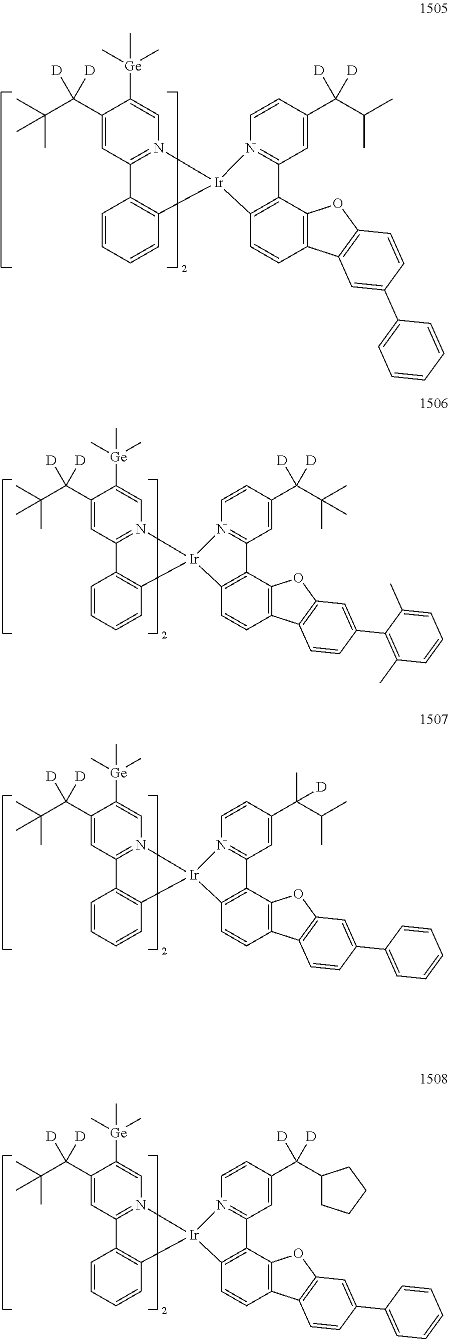

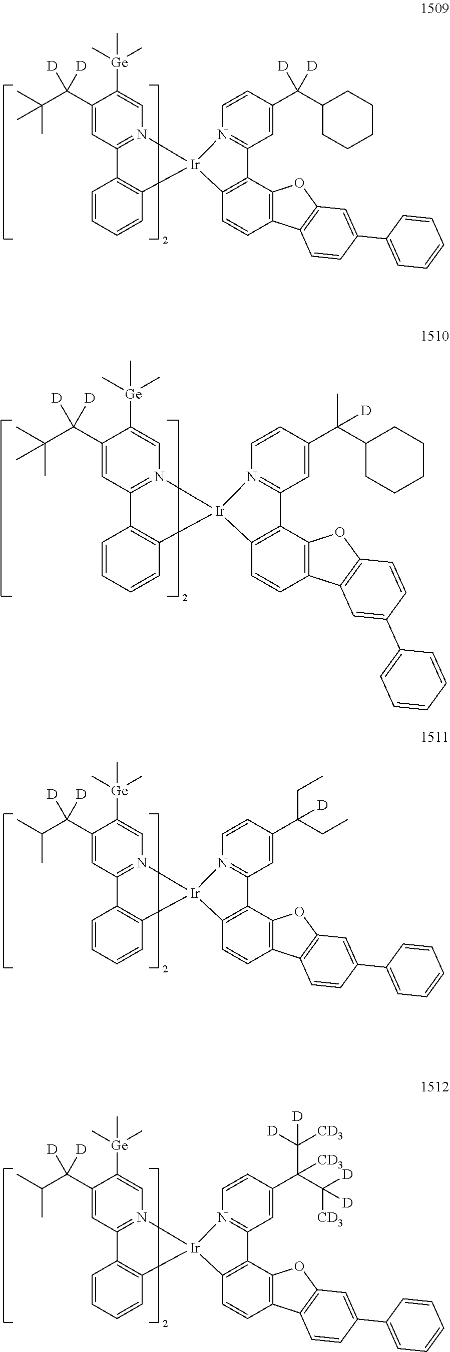

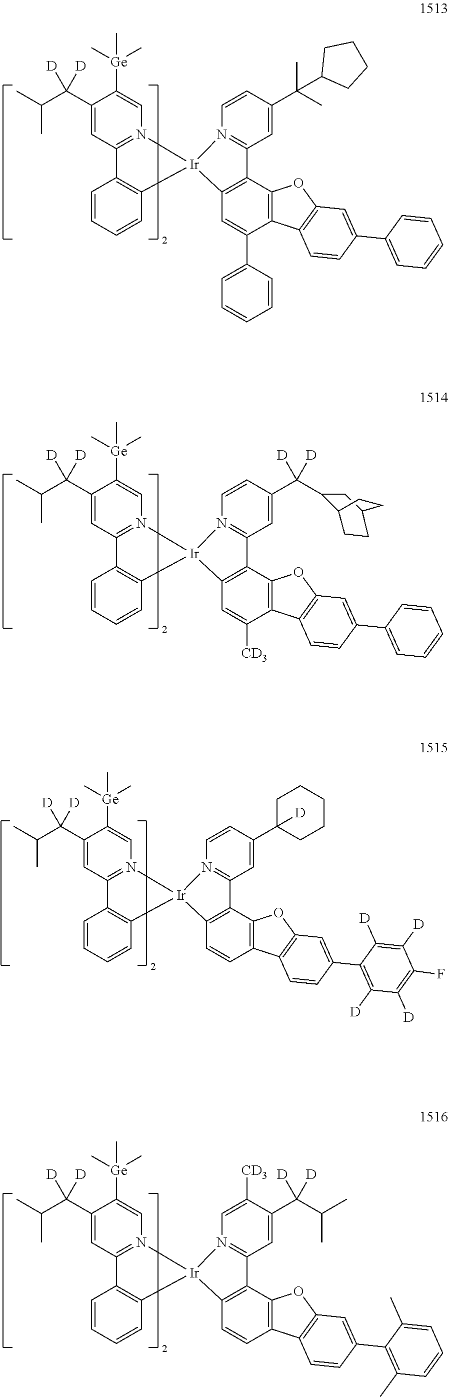

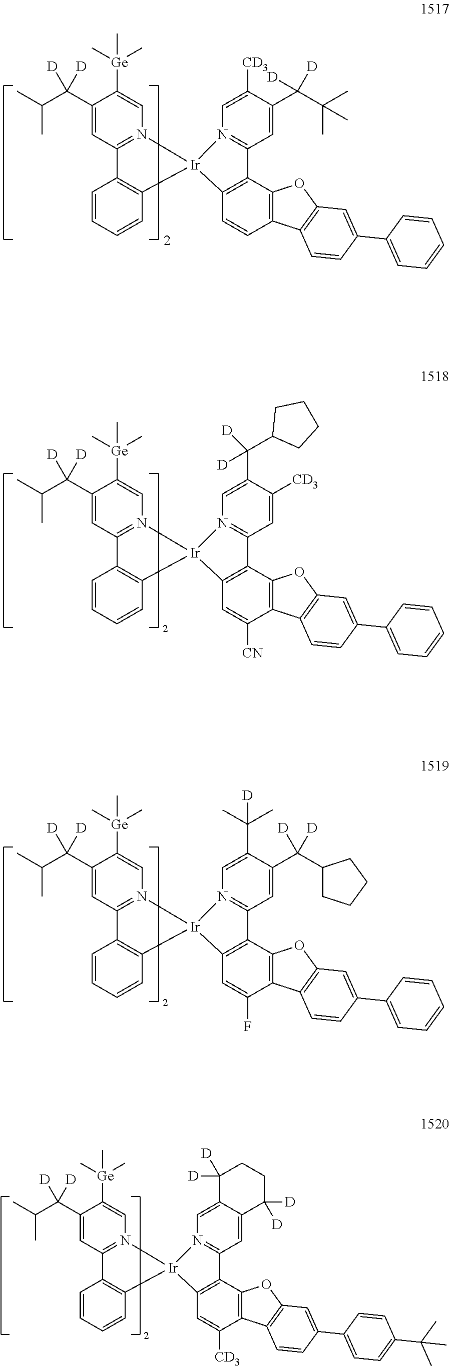

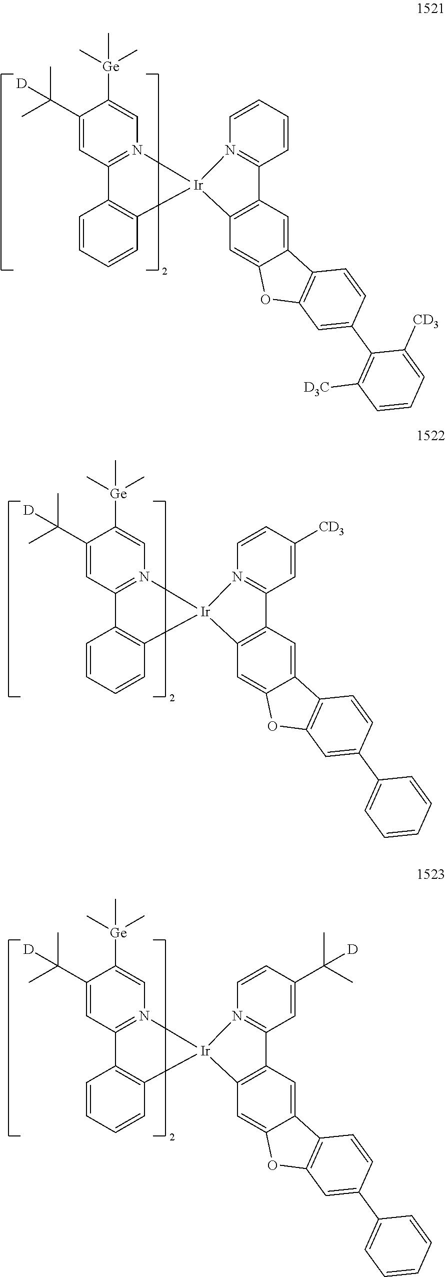

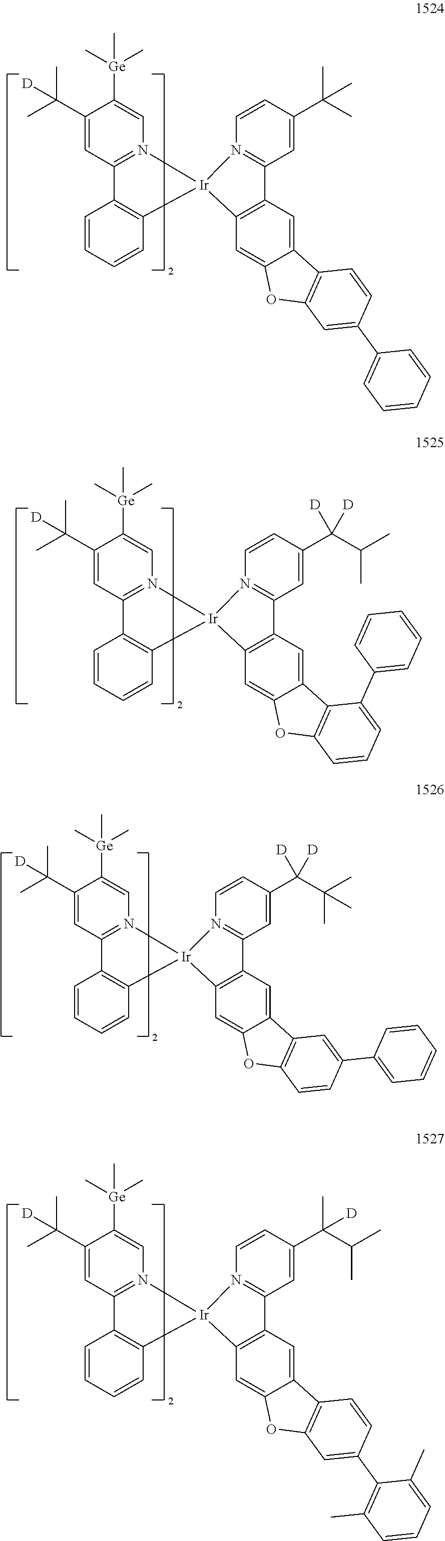

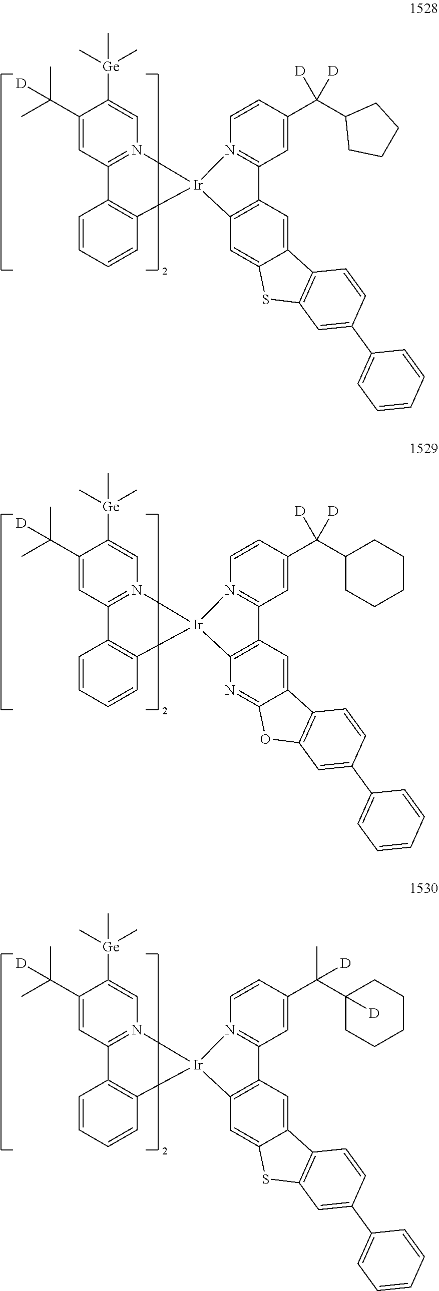

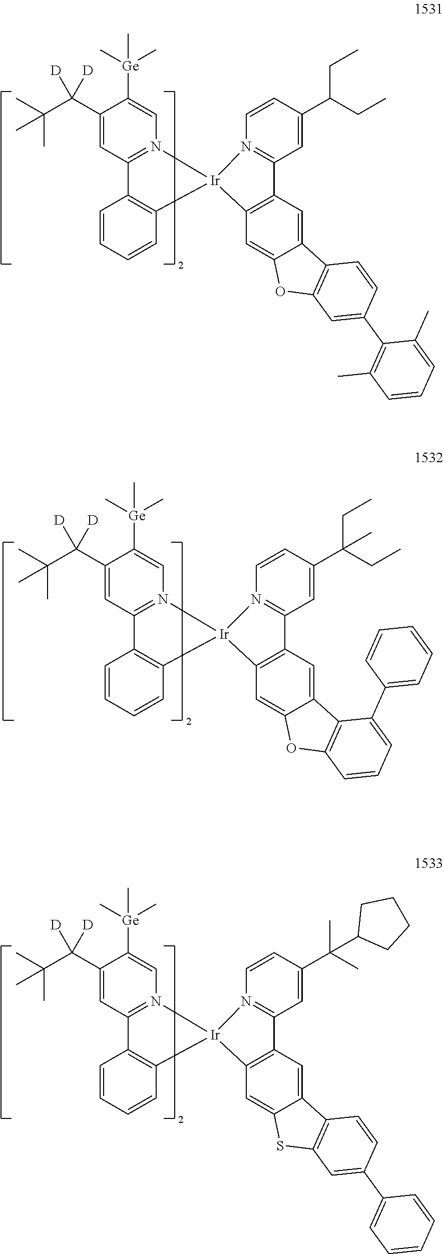

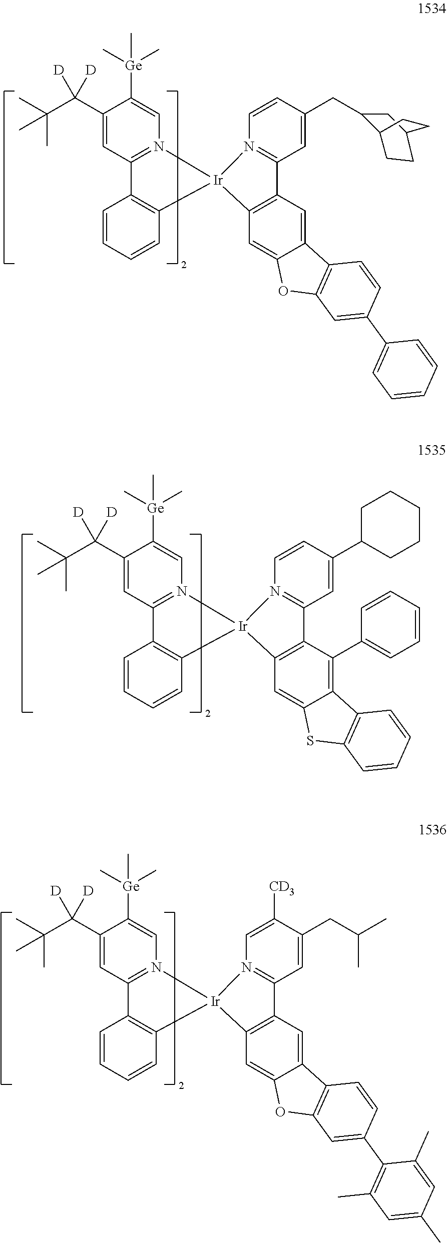

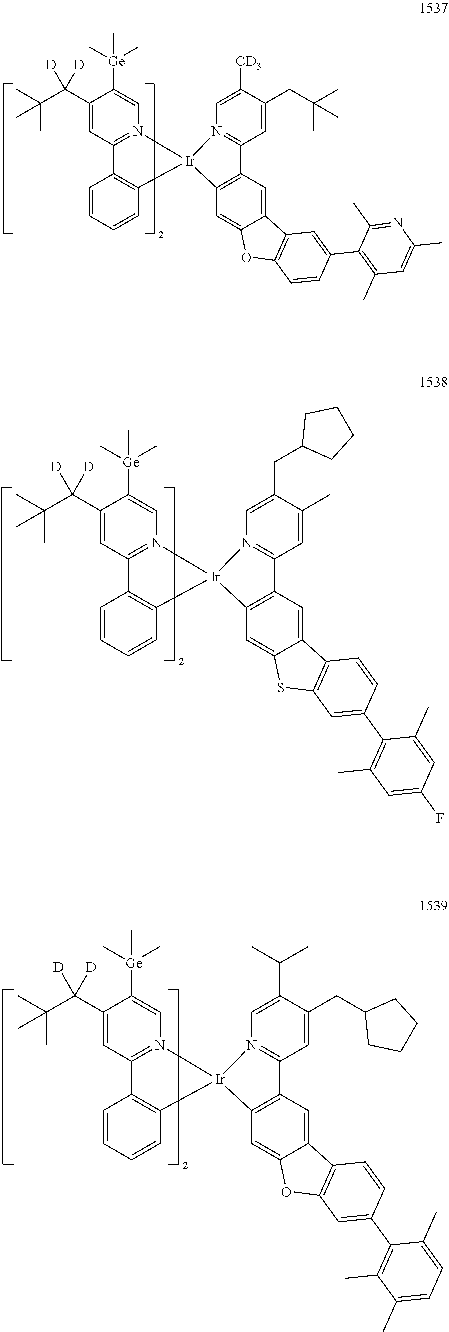

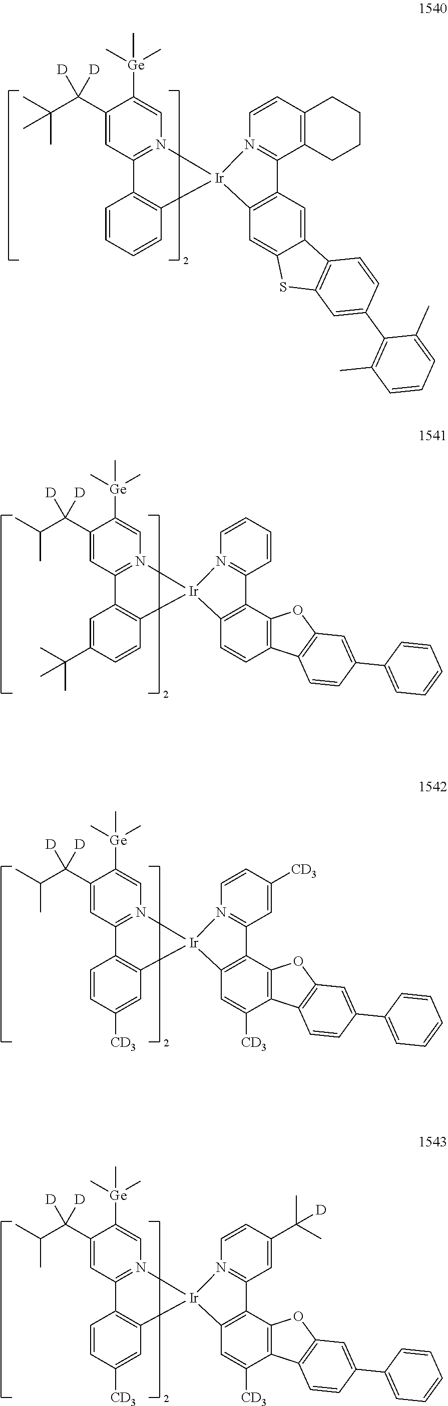

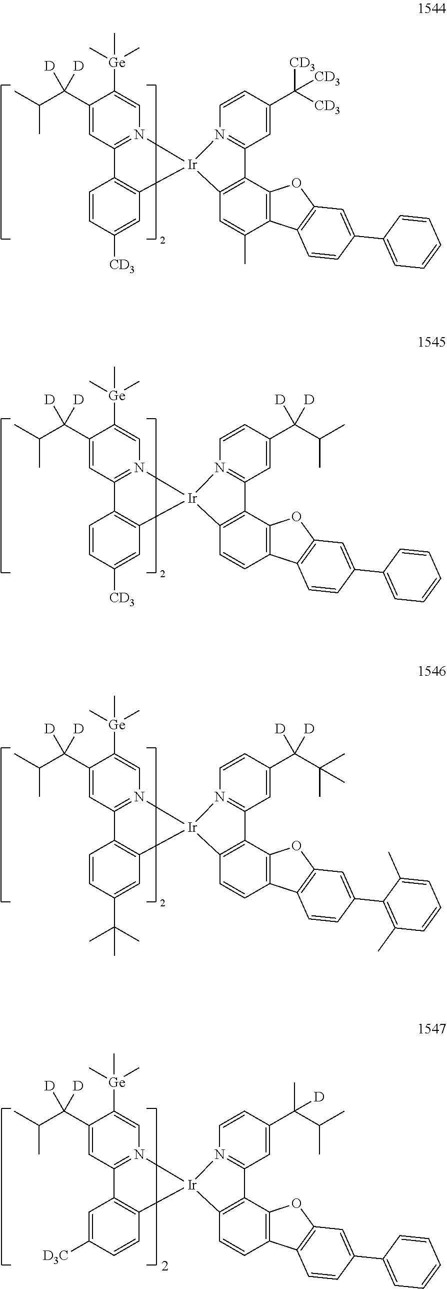

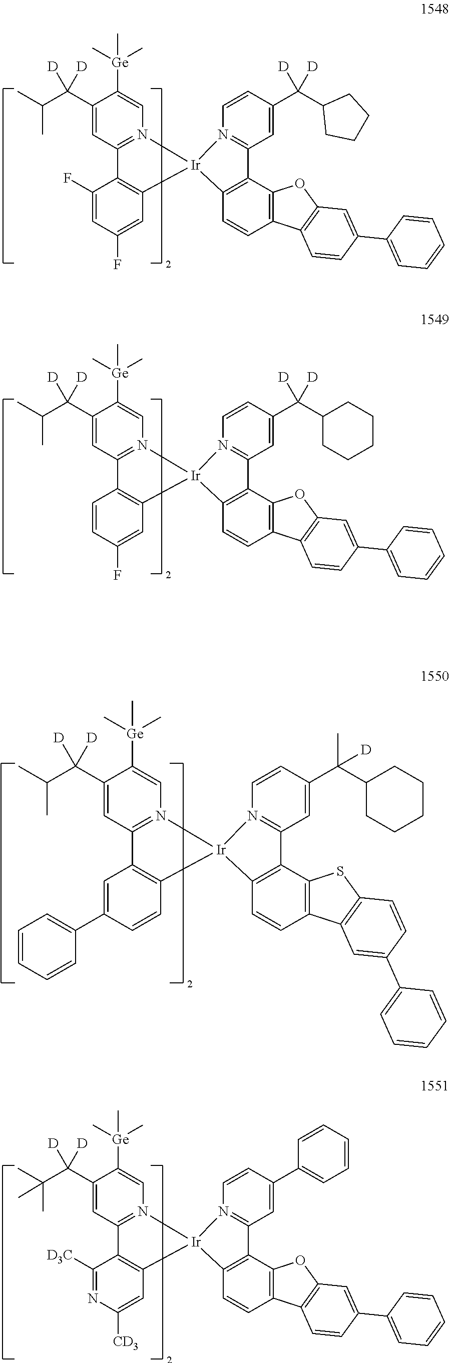

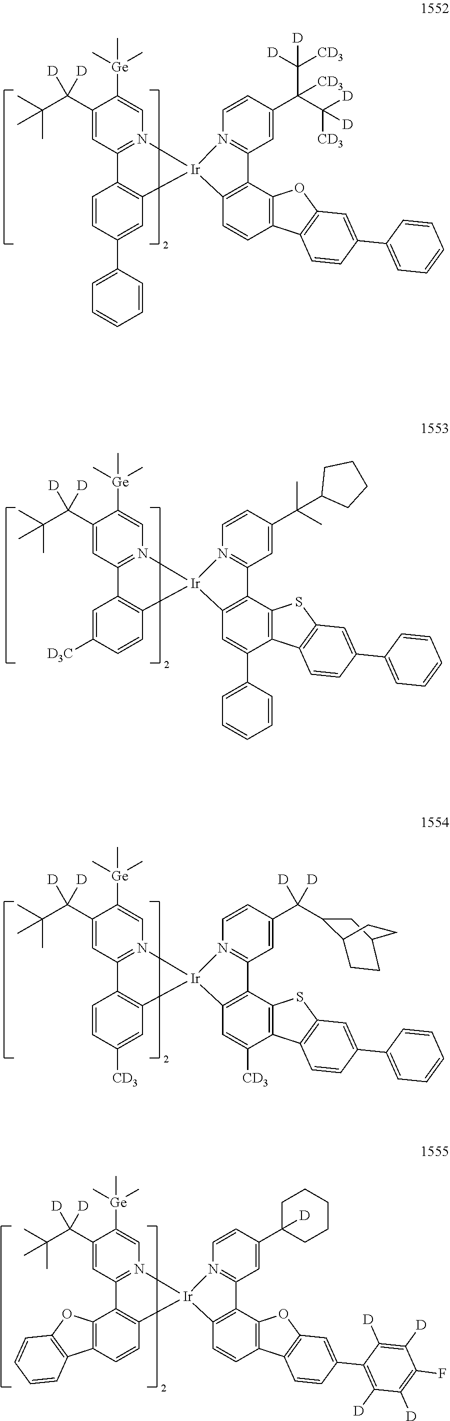

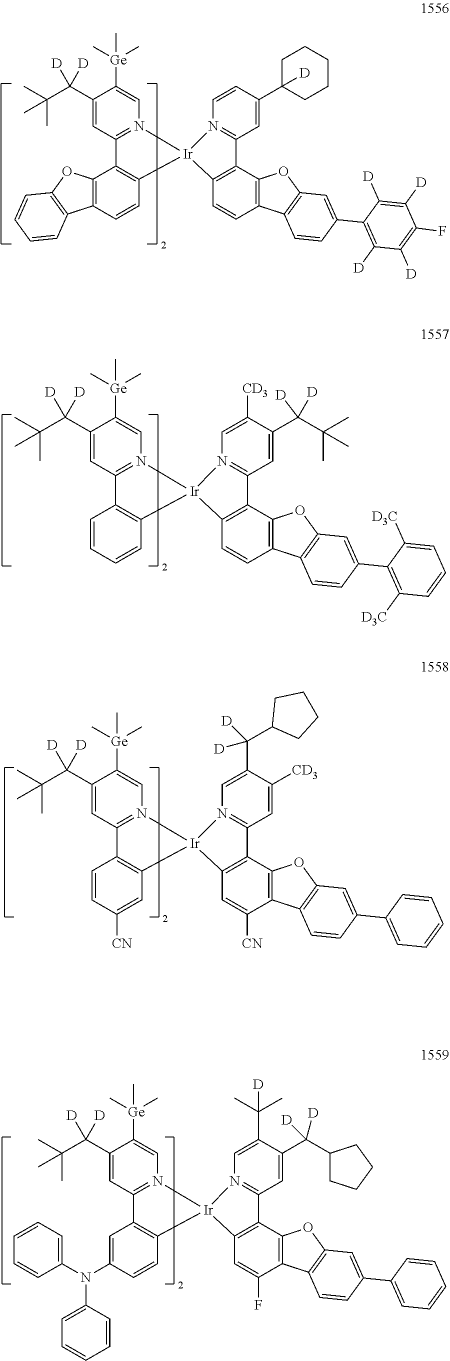

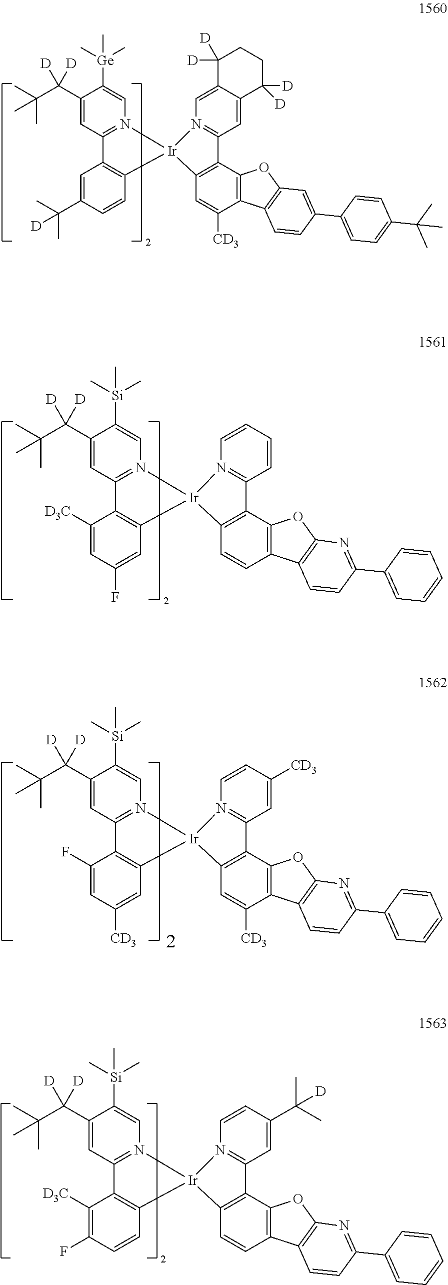

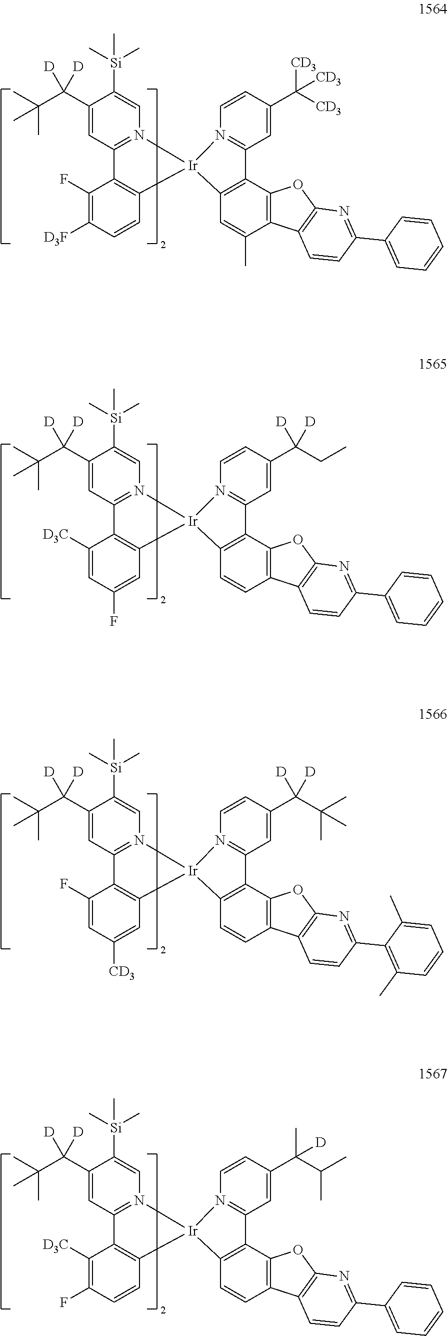

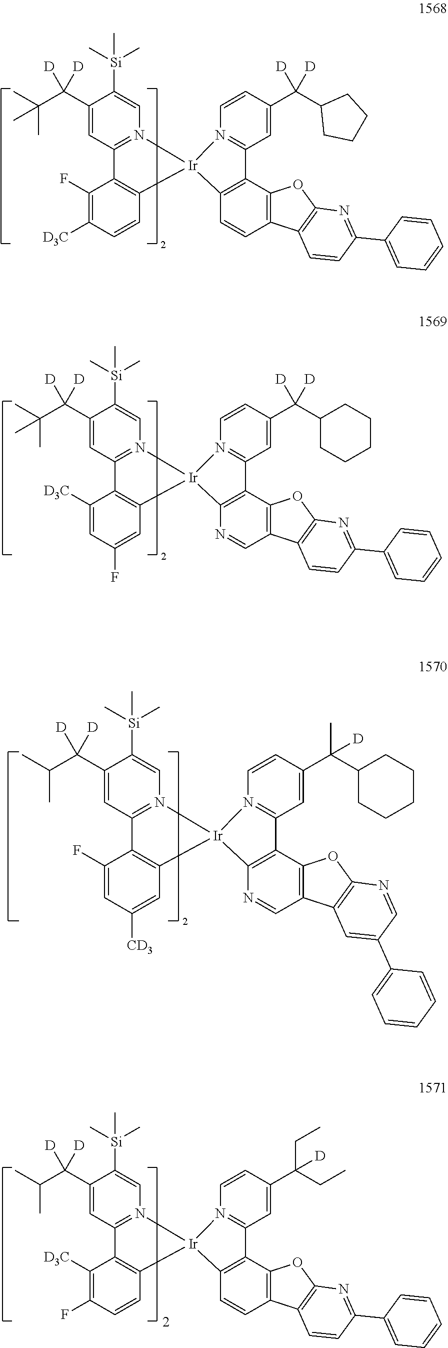

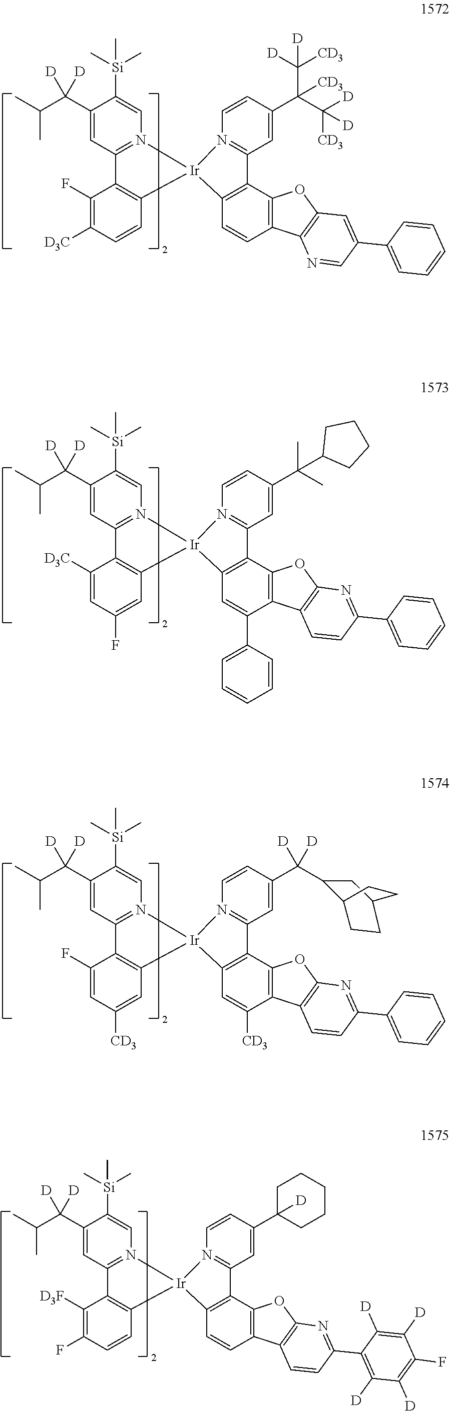

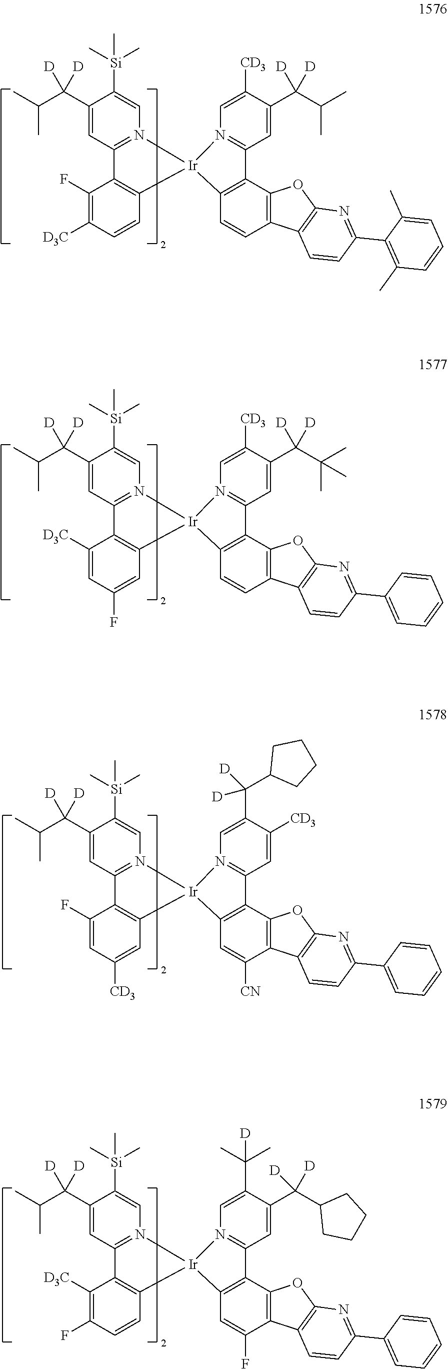

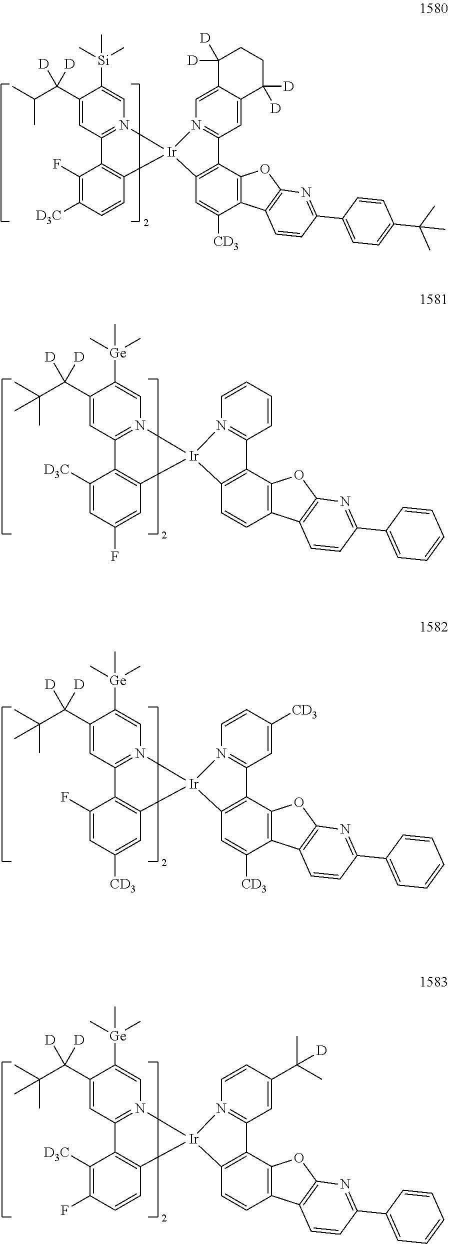

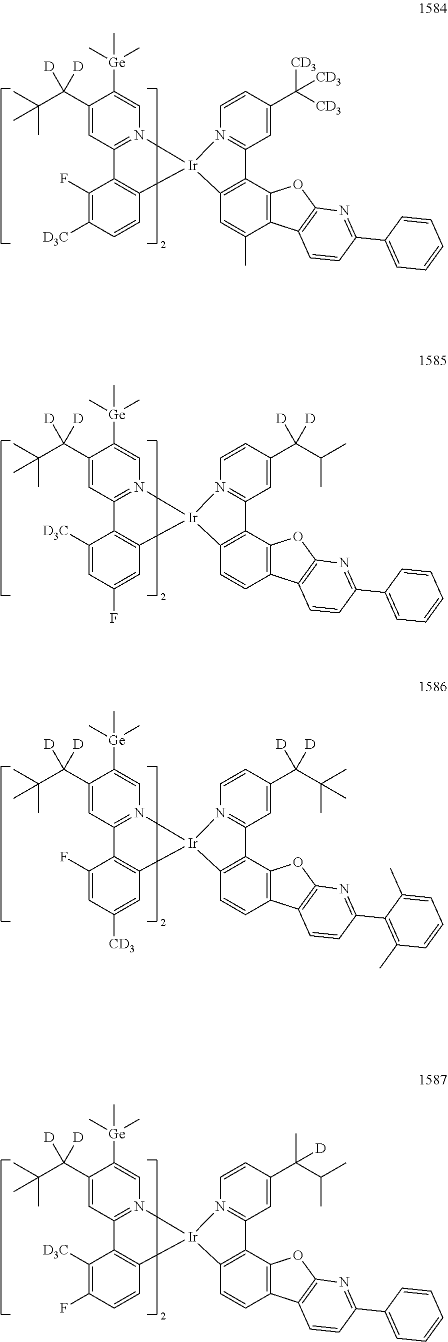

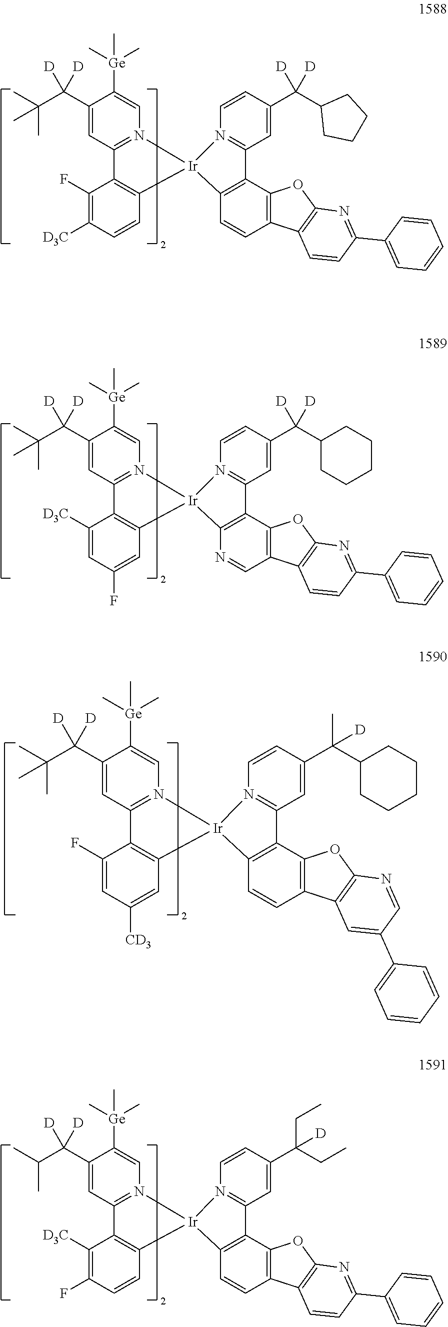

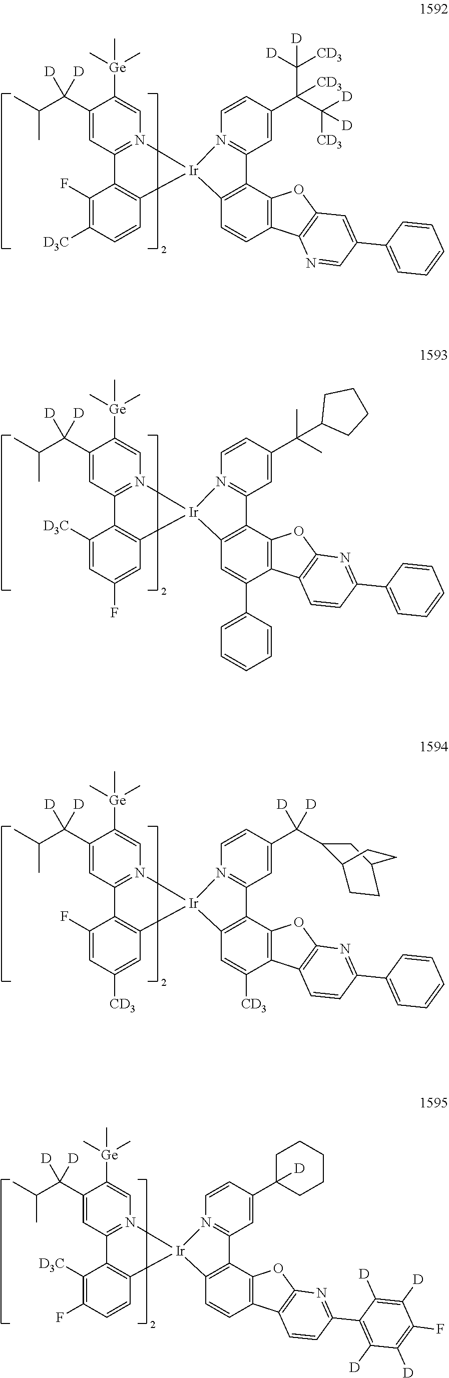

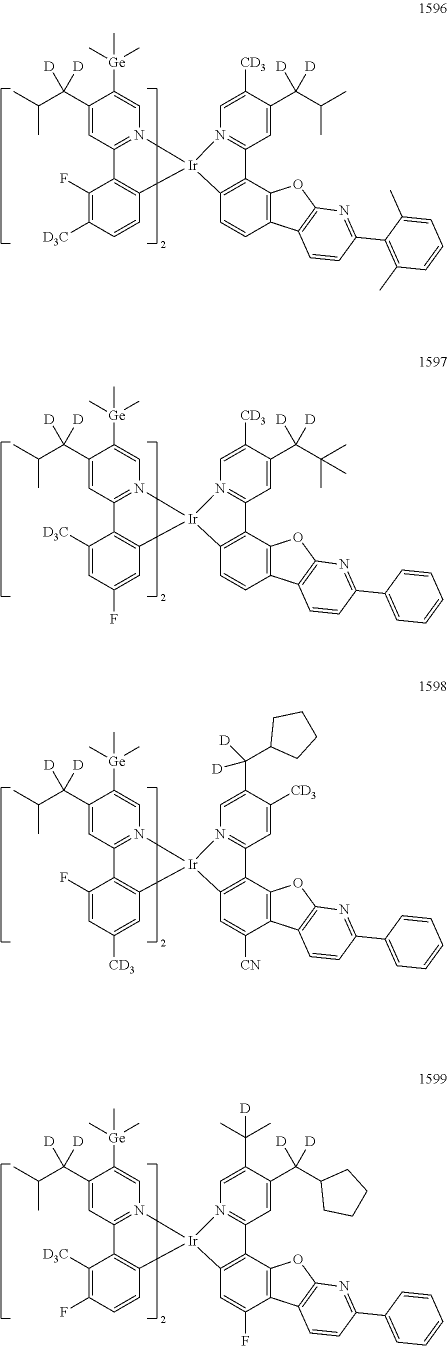

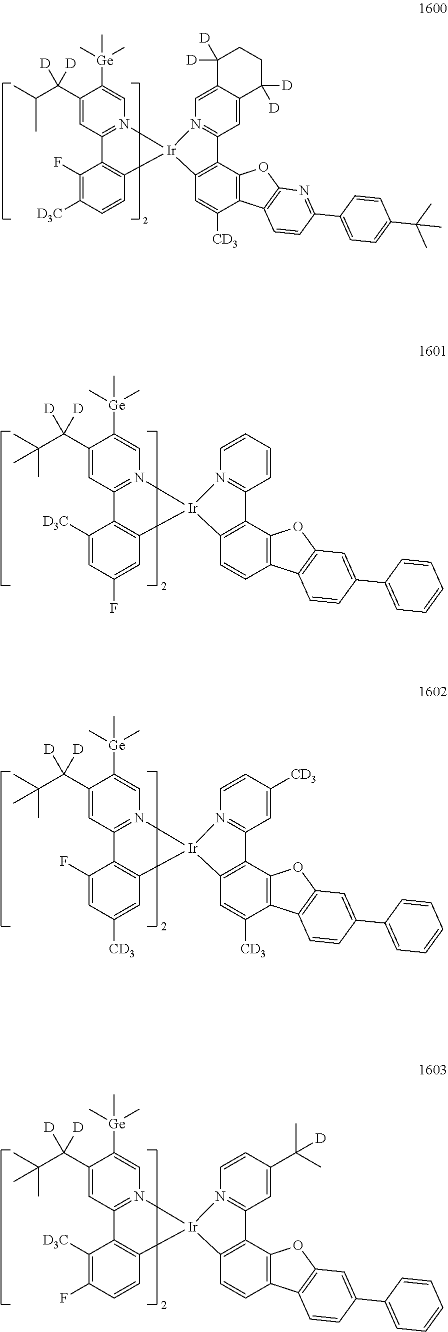

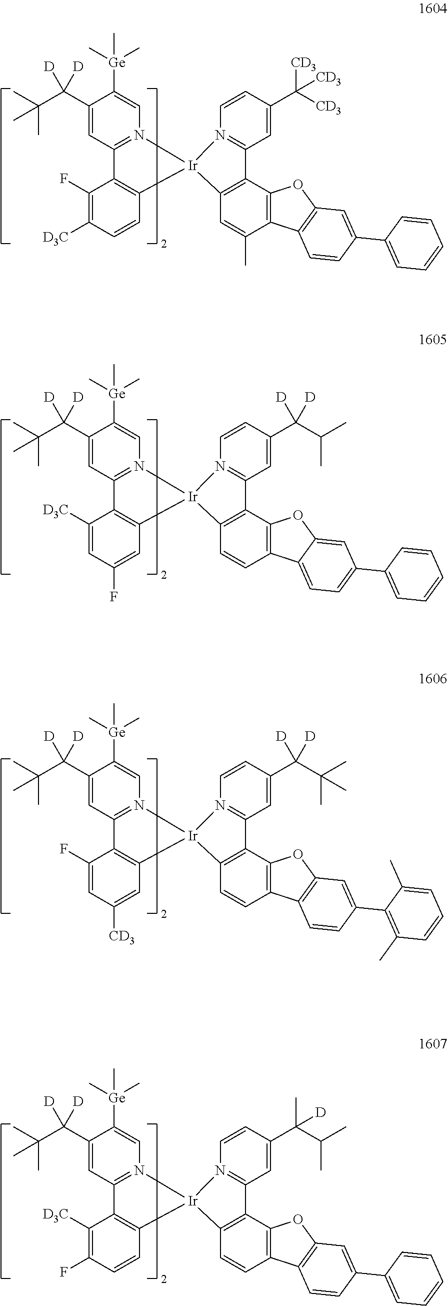

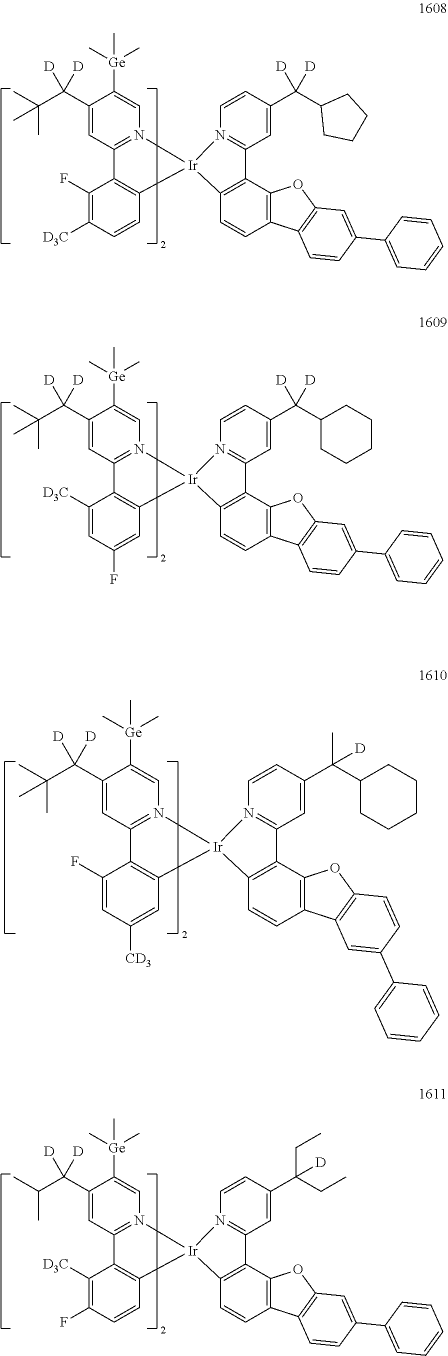

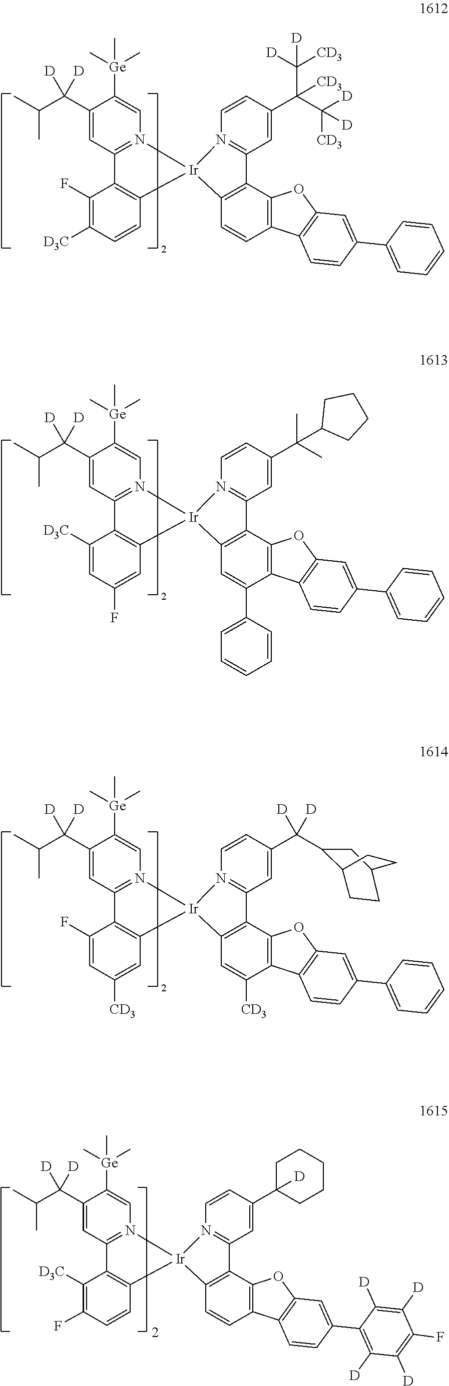

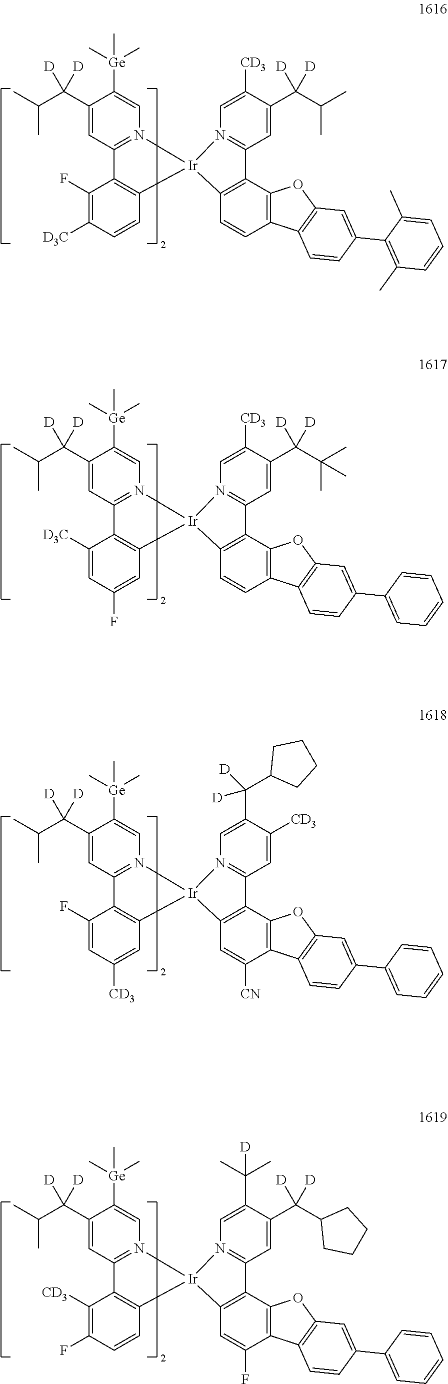

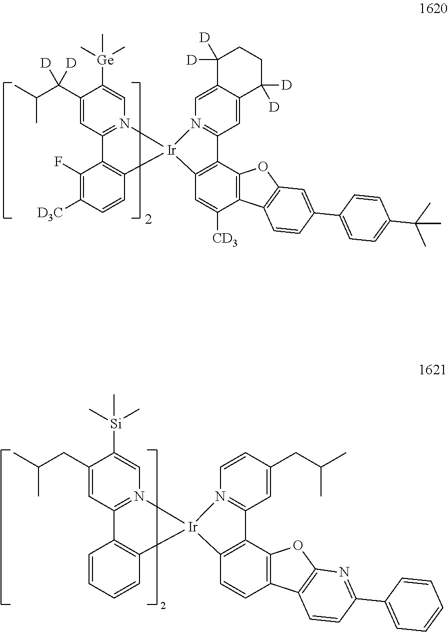

wherein “OMe” in Compounds 1 to 1621 in Group 1 represents a methoxy group.

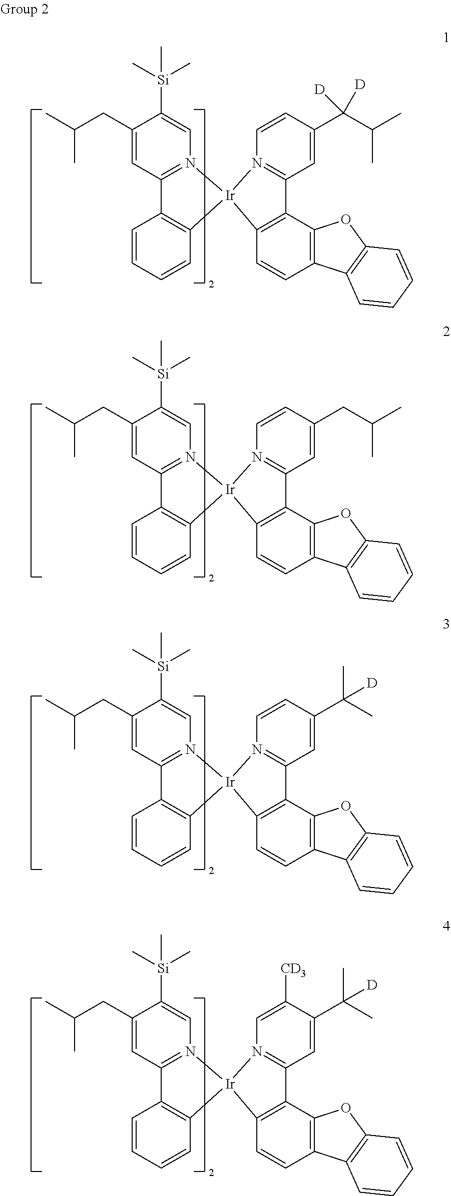

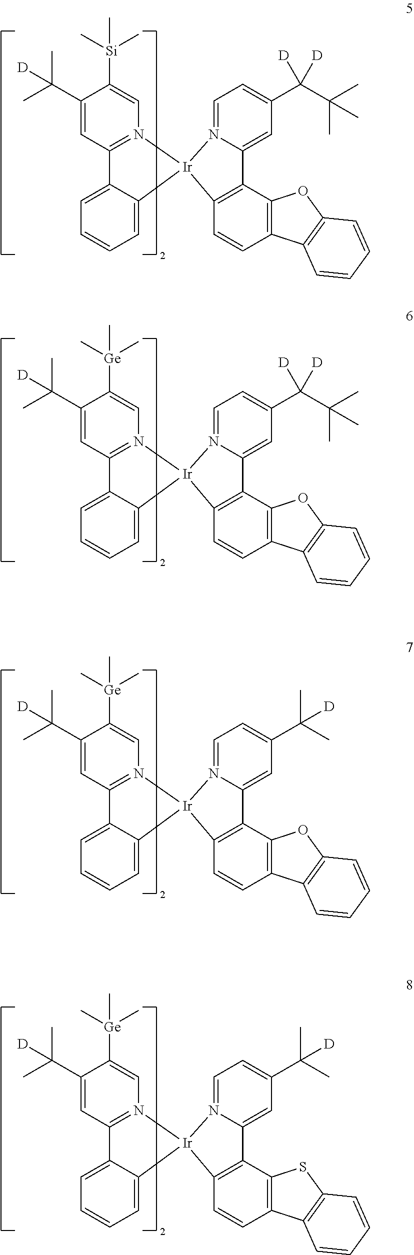

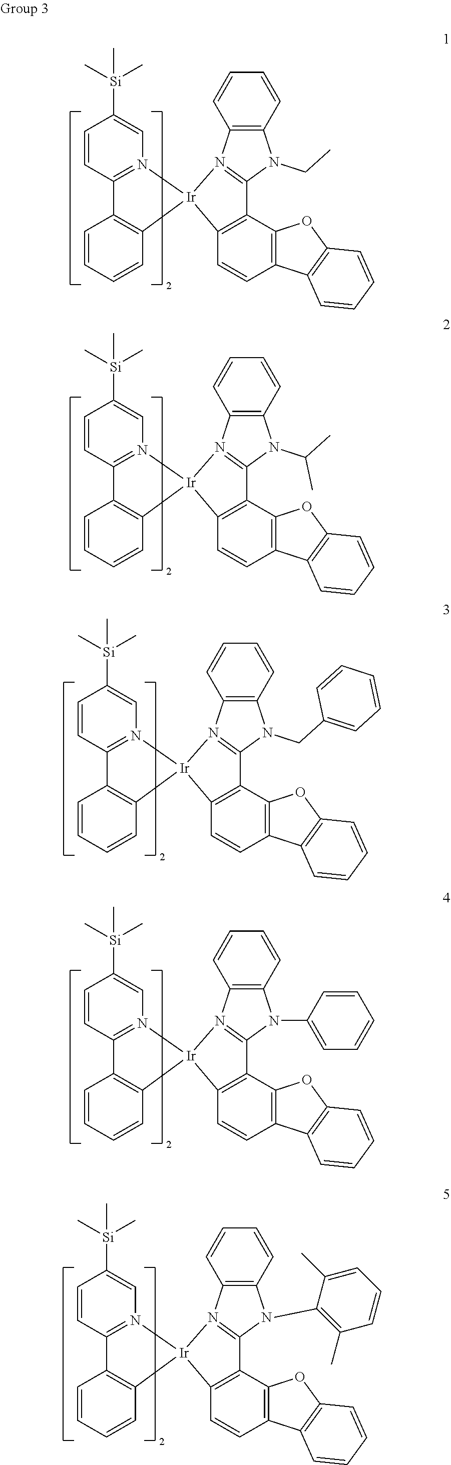

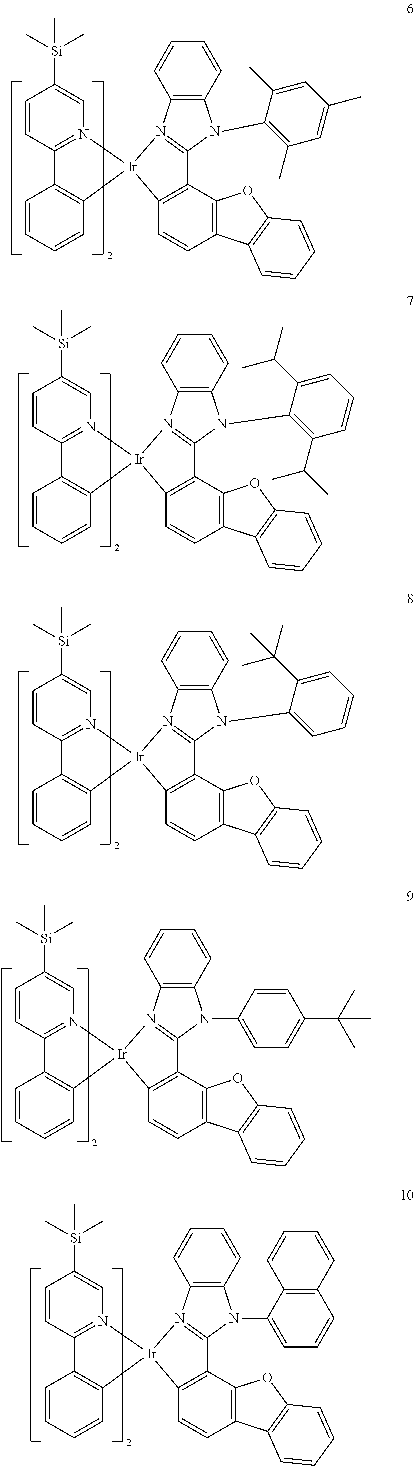

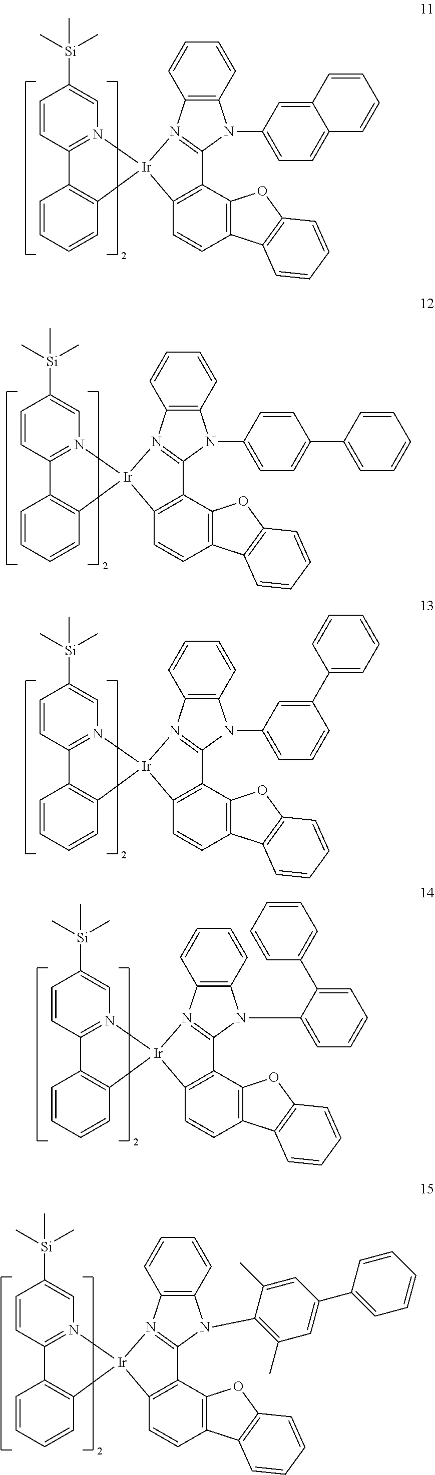

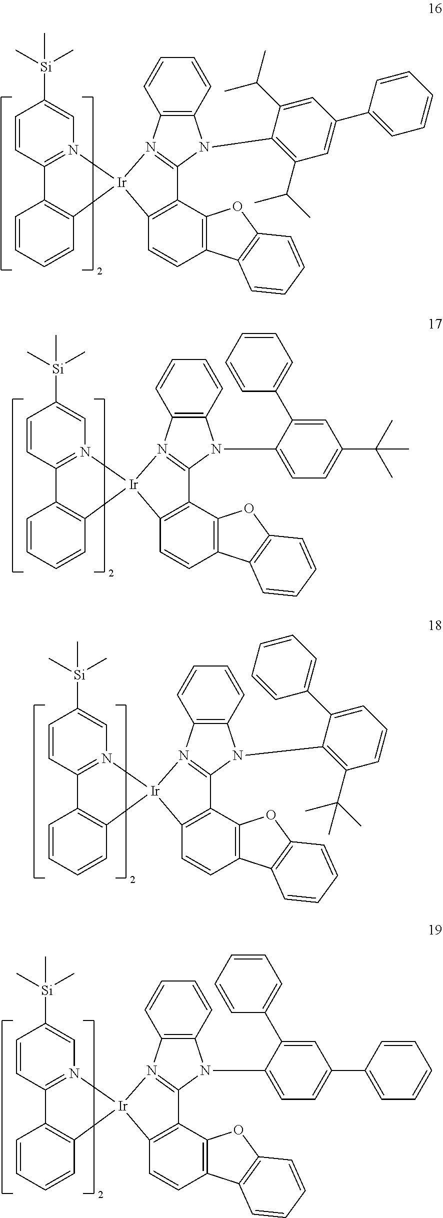

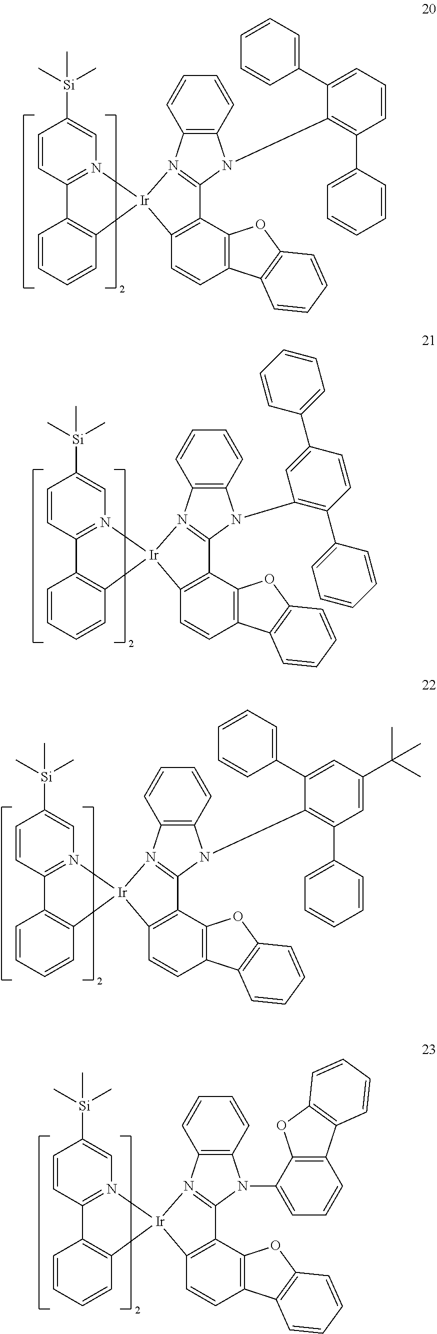

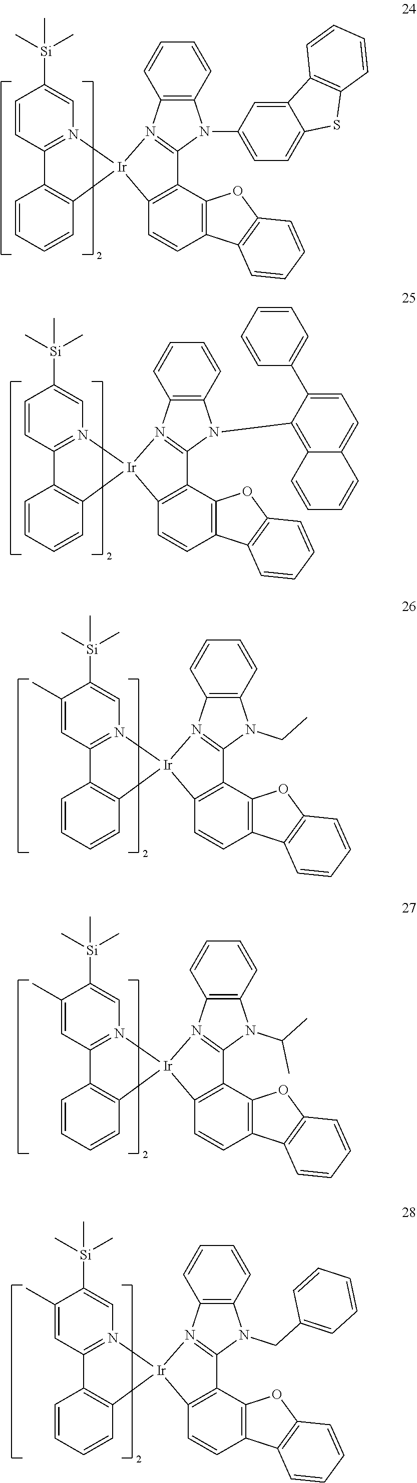

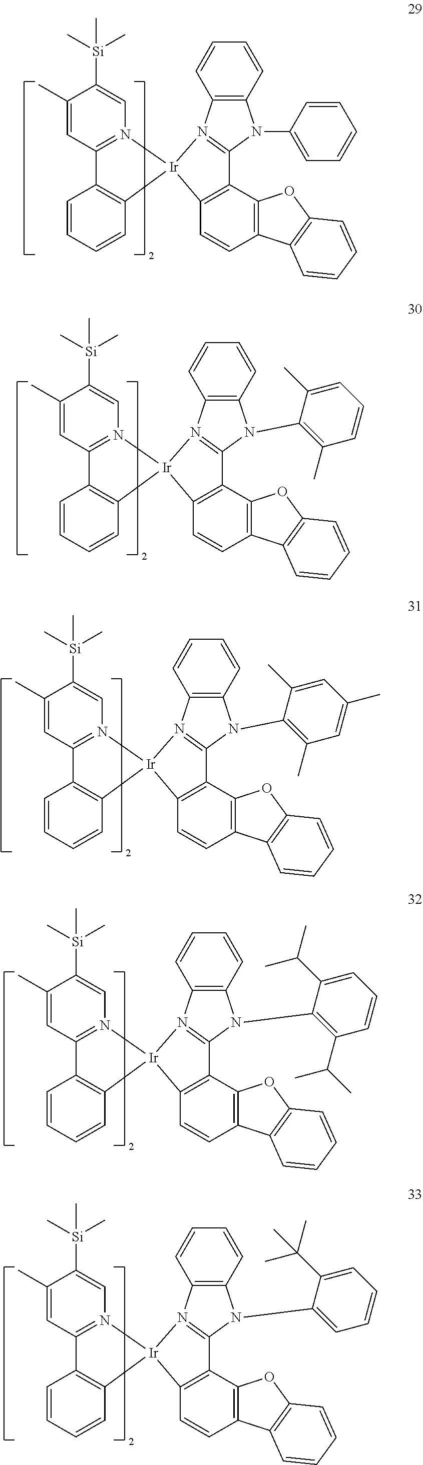

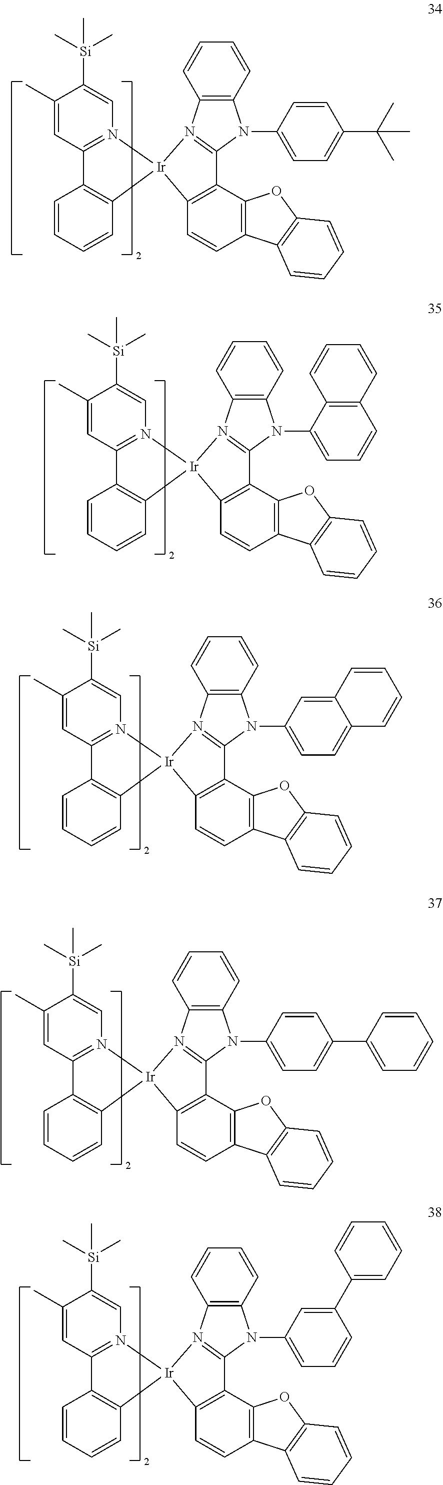

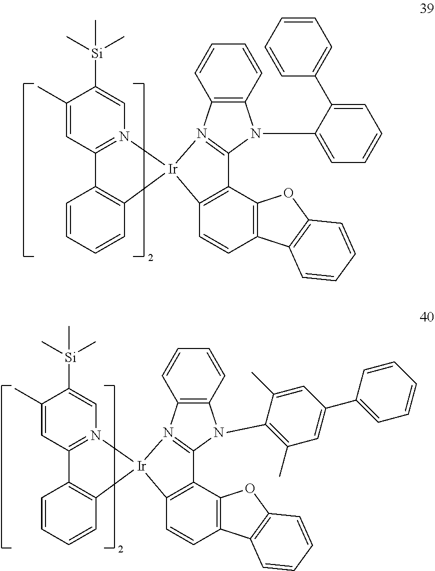

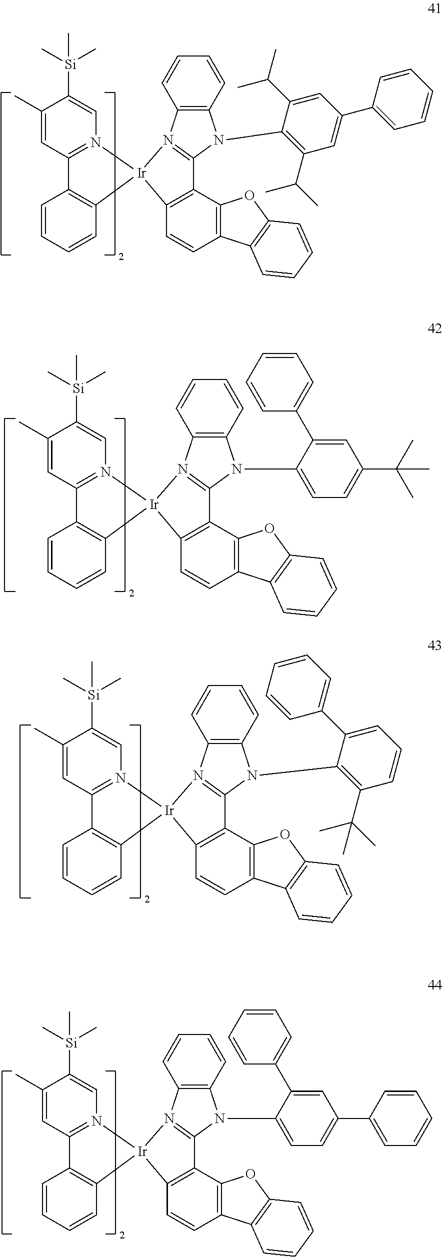

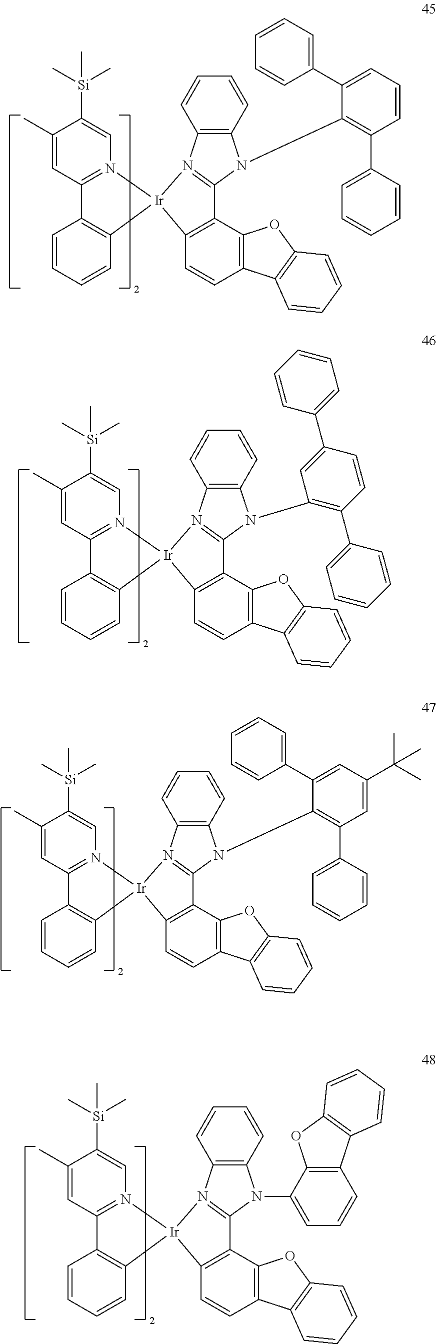

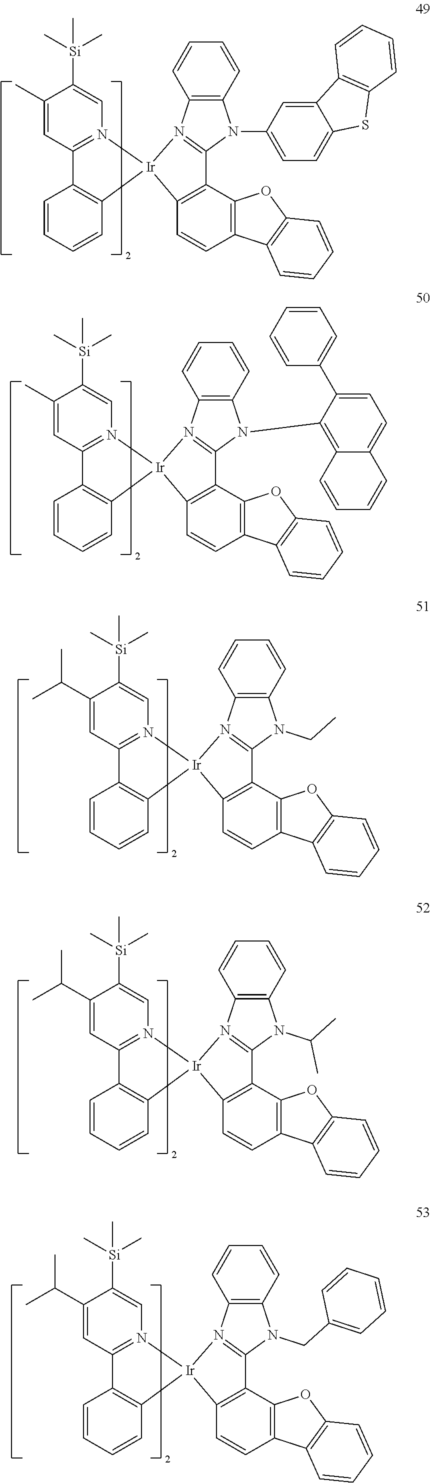

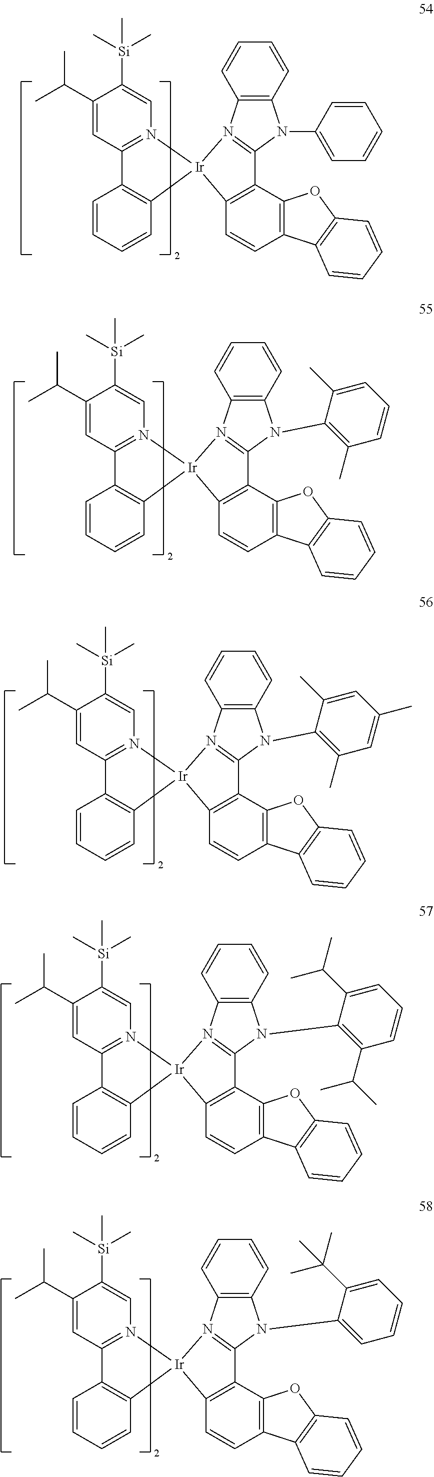

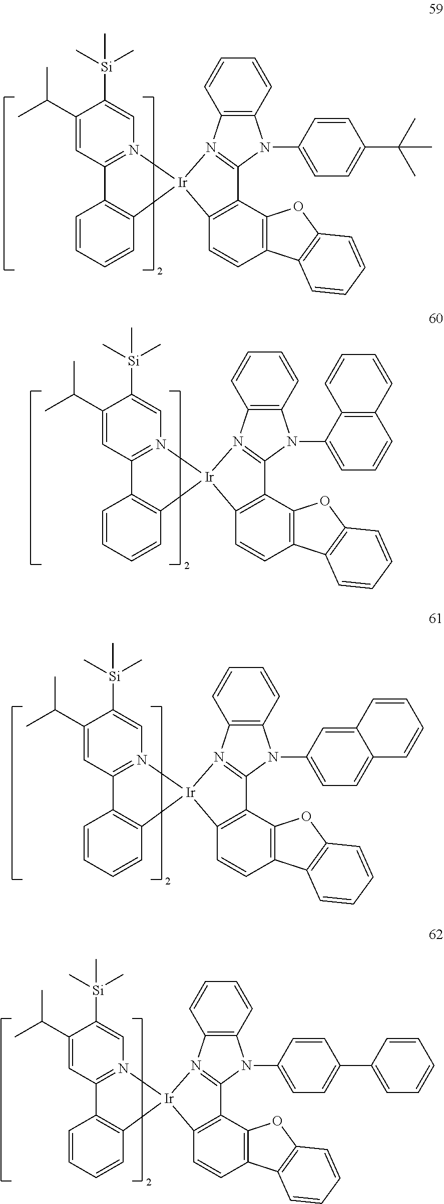

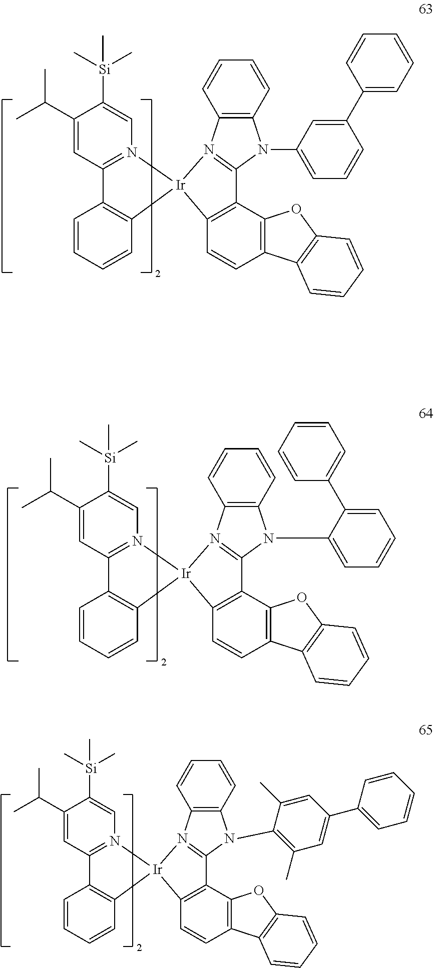

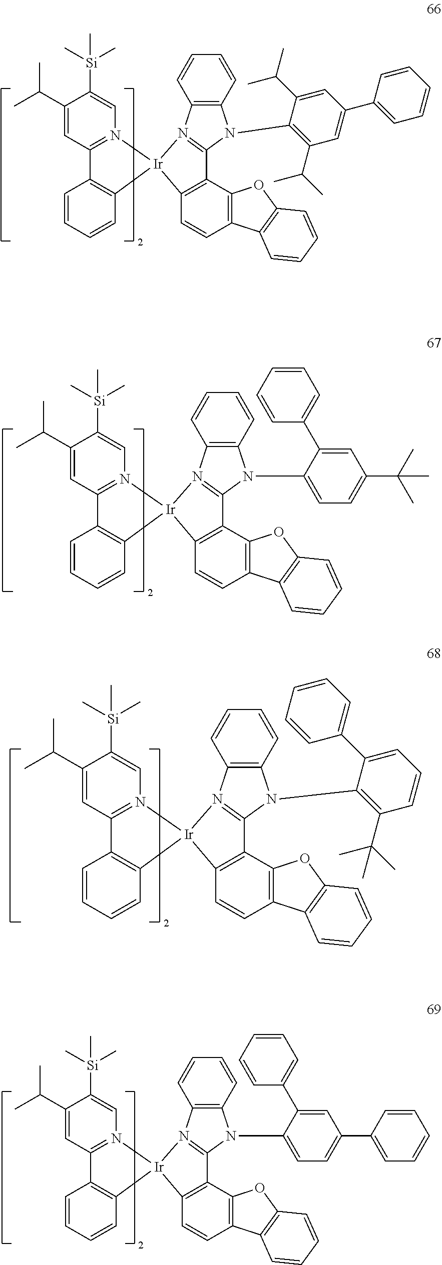

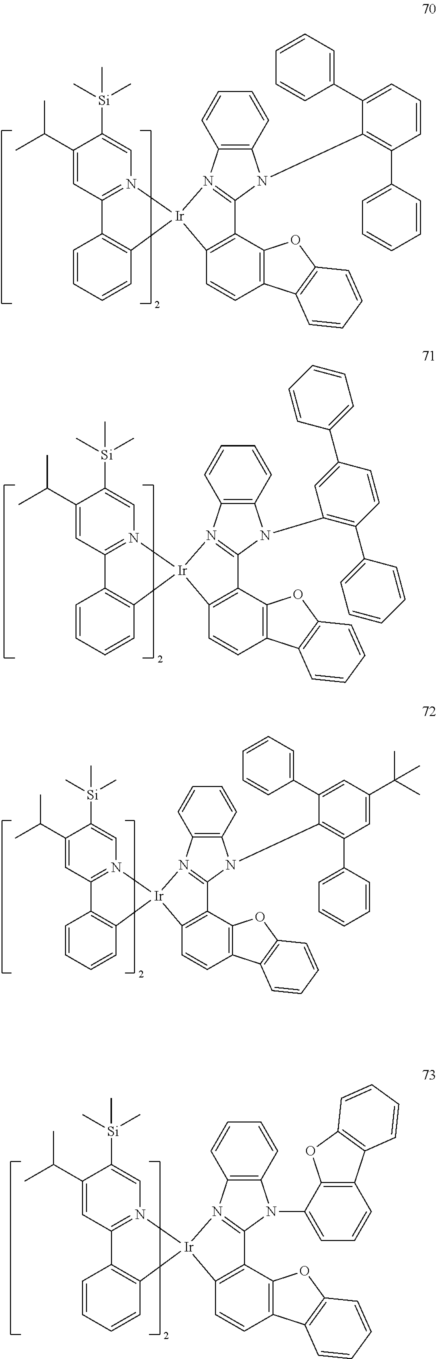

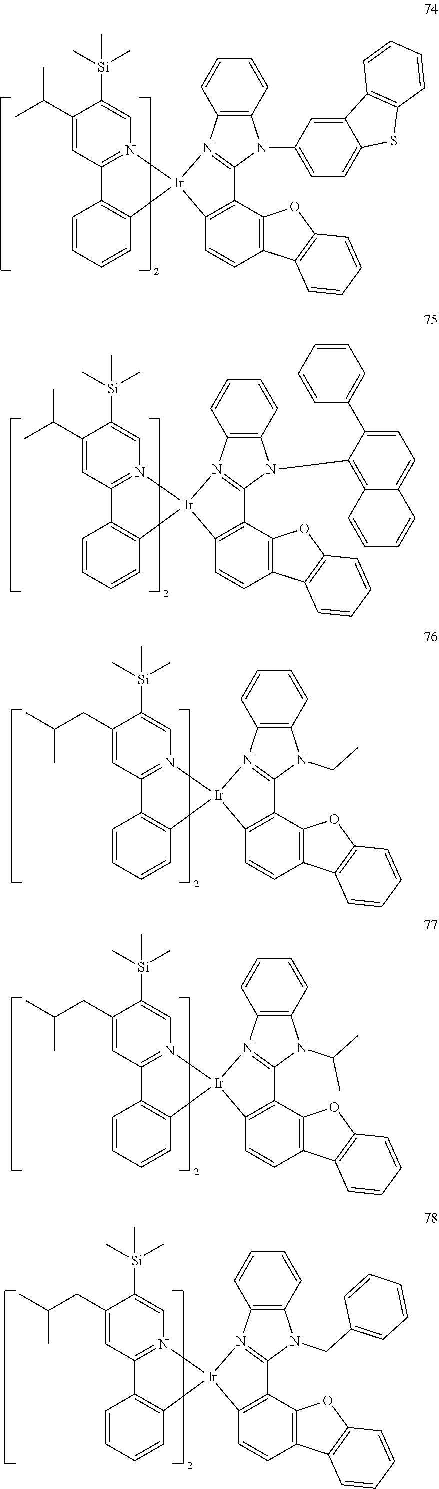

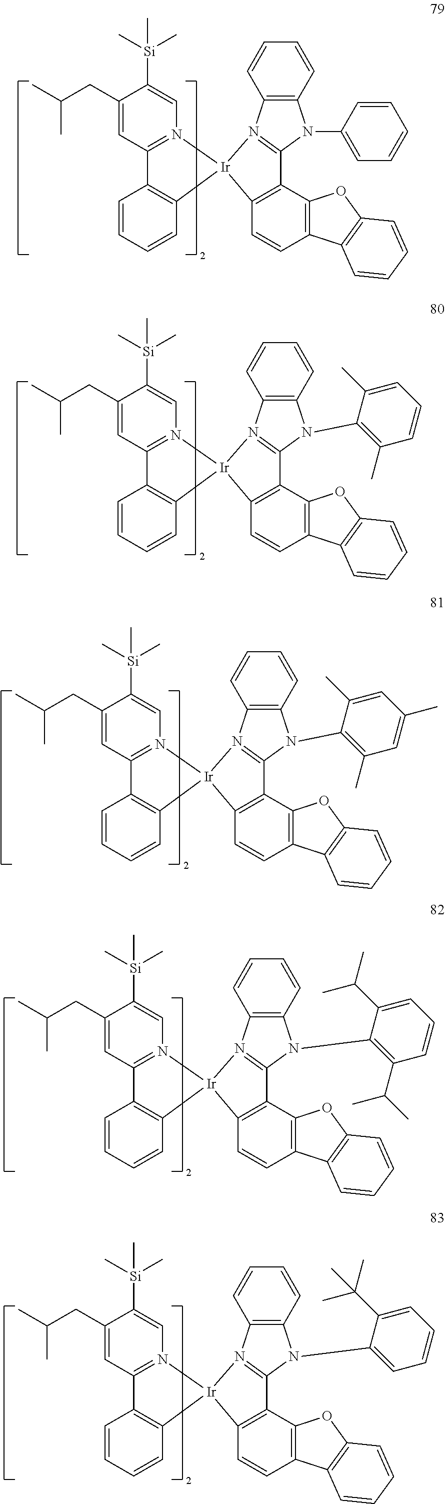

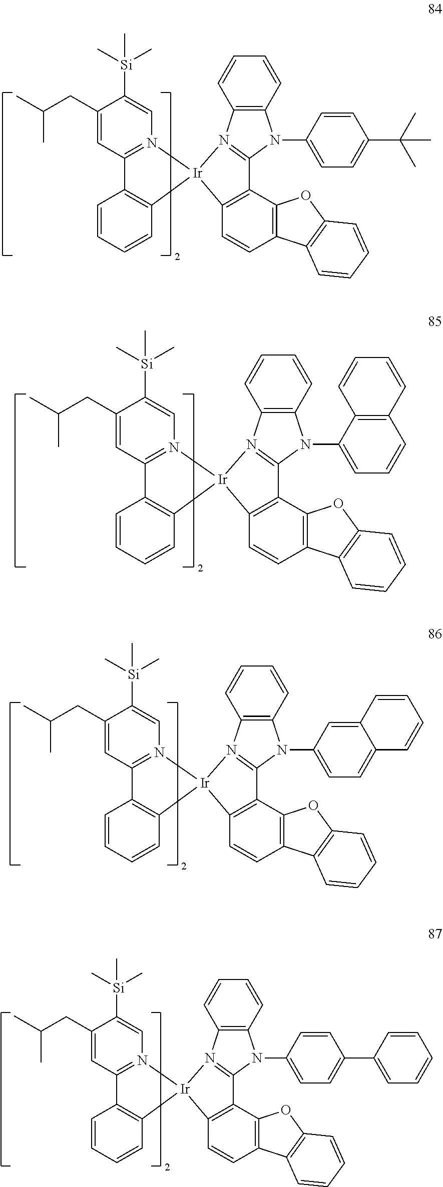

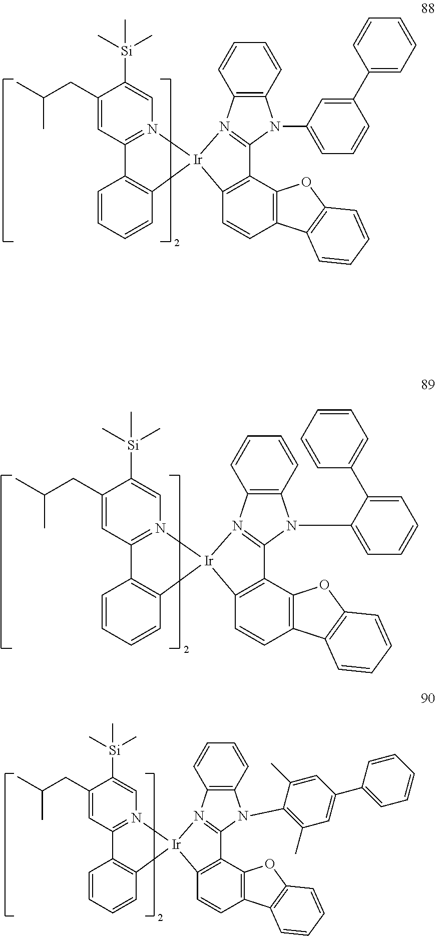

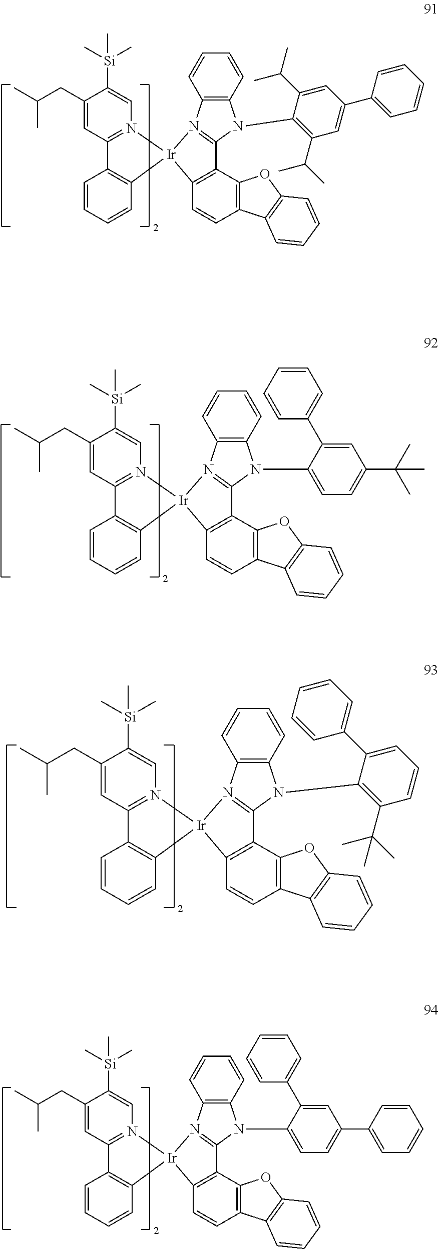

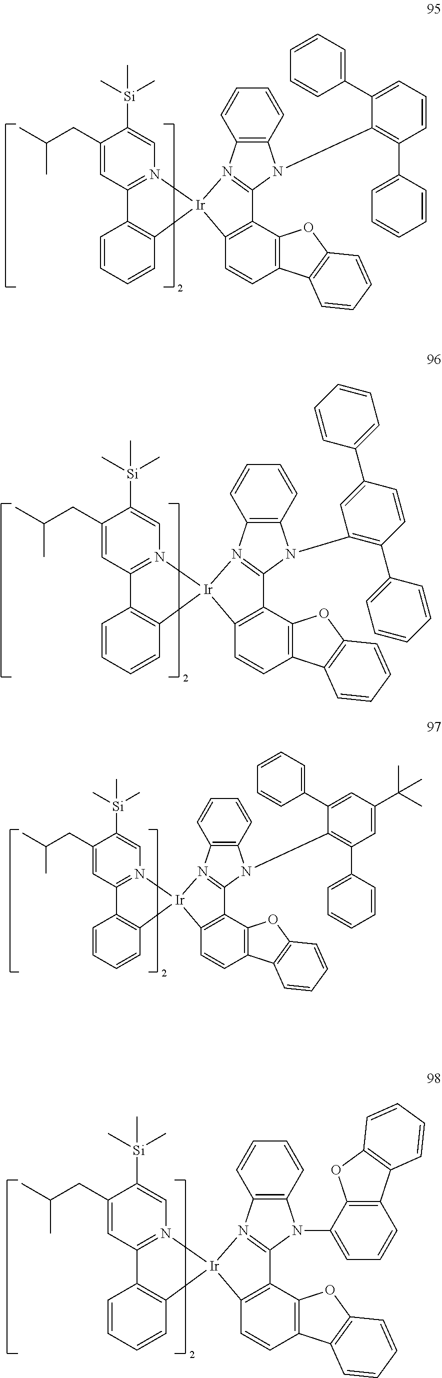

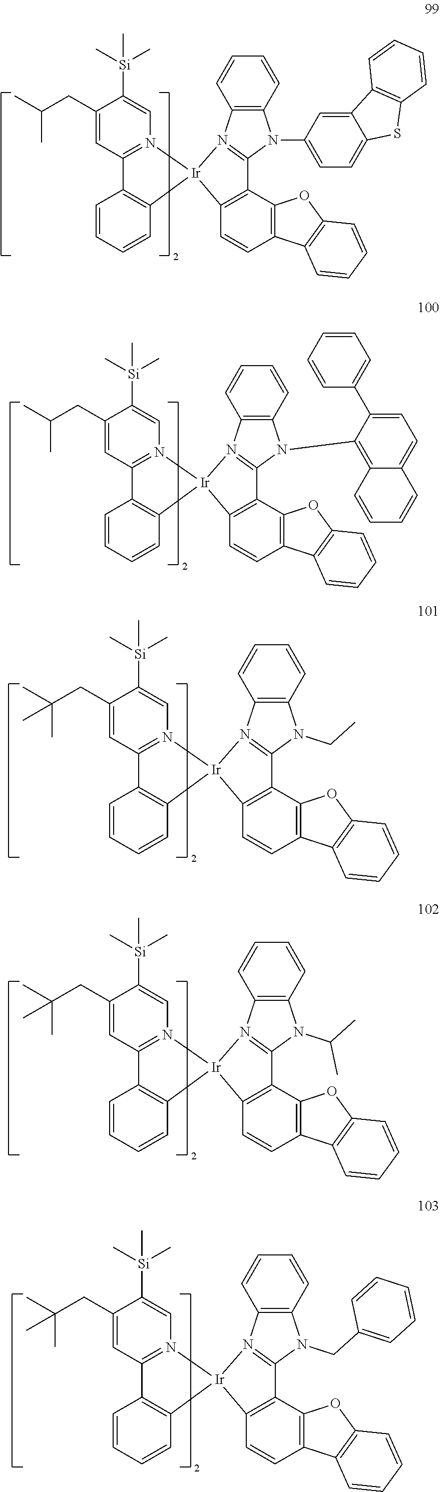

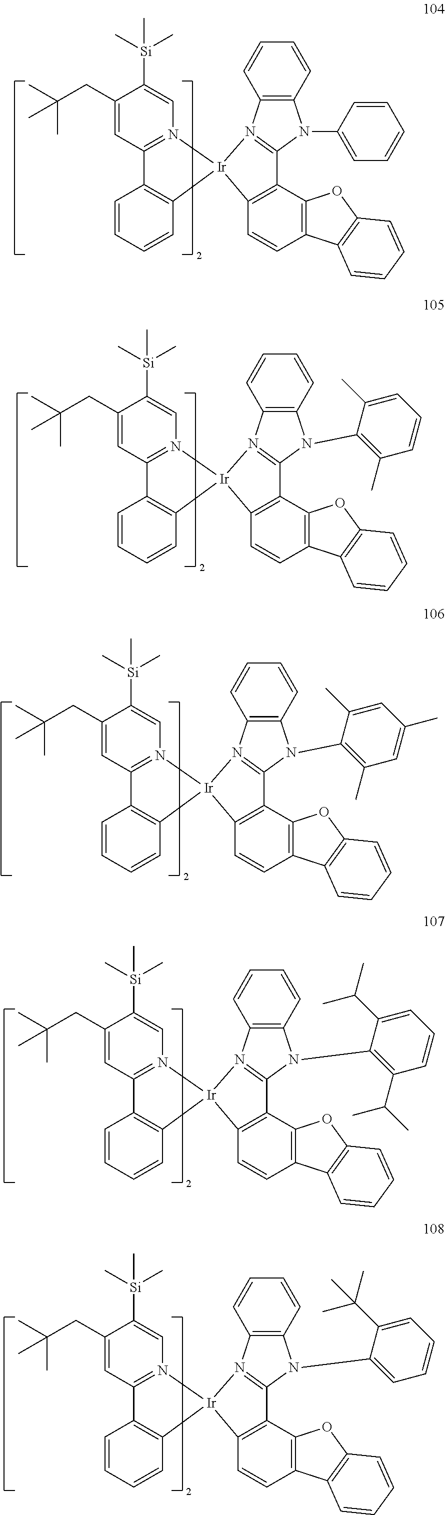

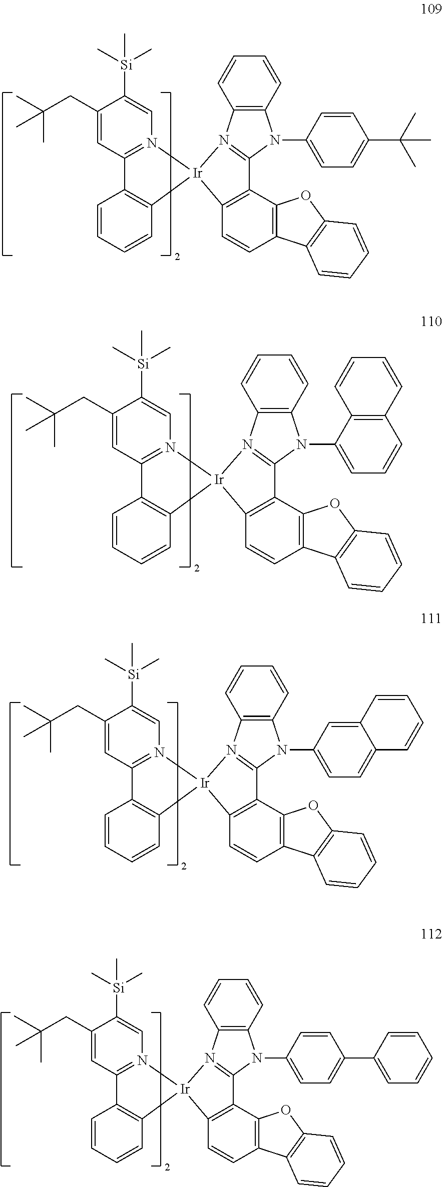

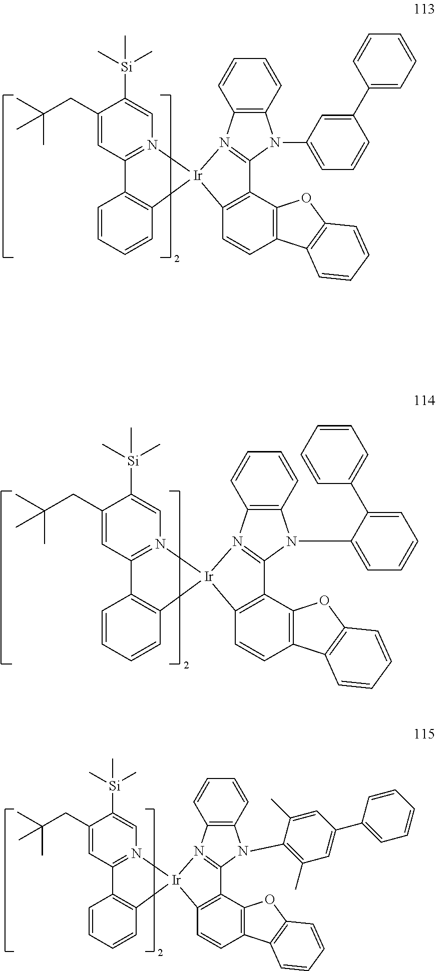

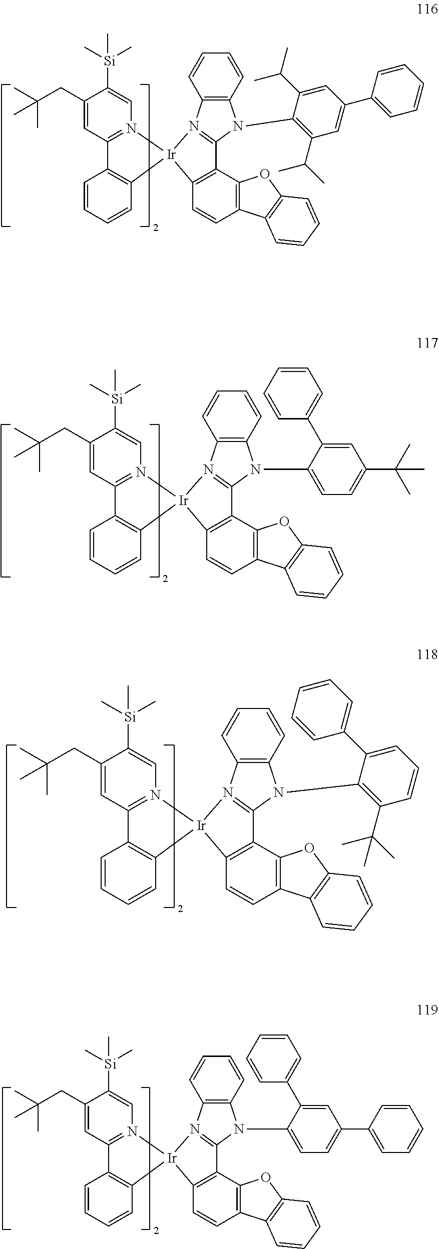

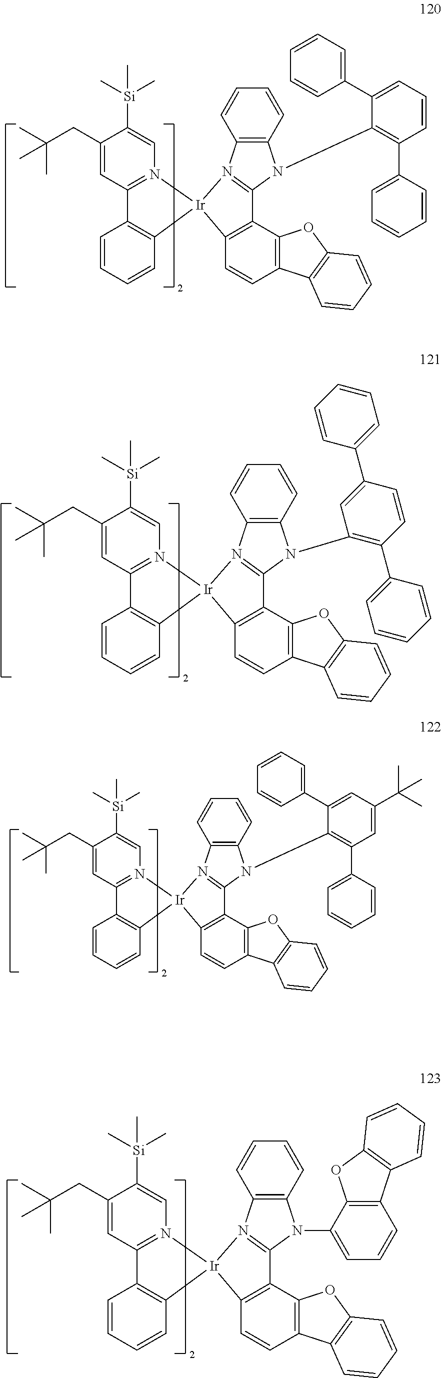

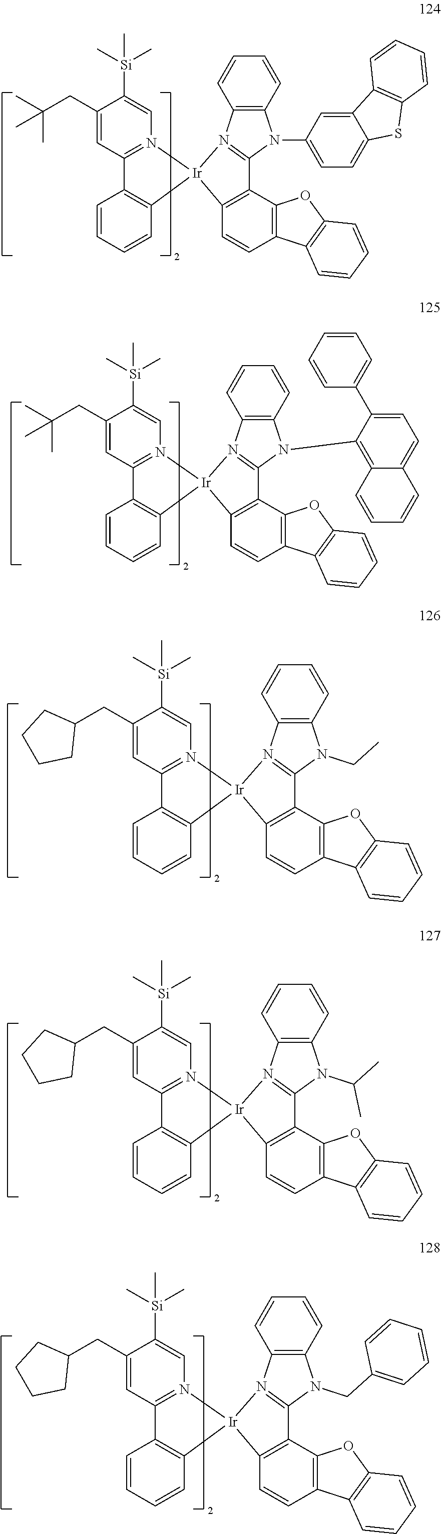

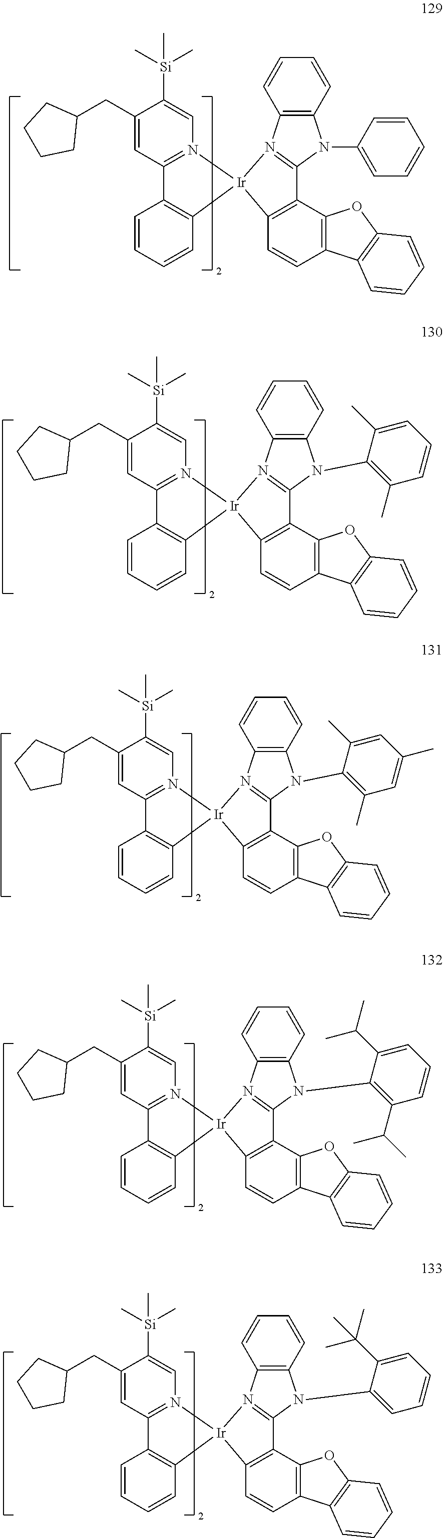

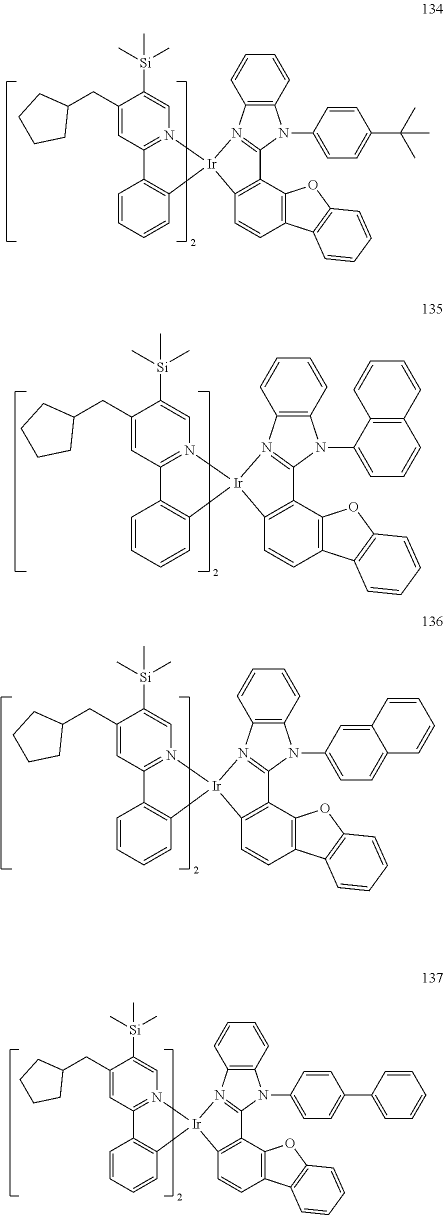

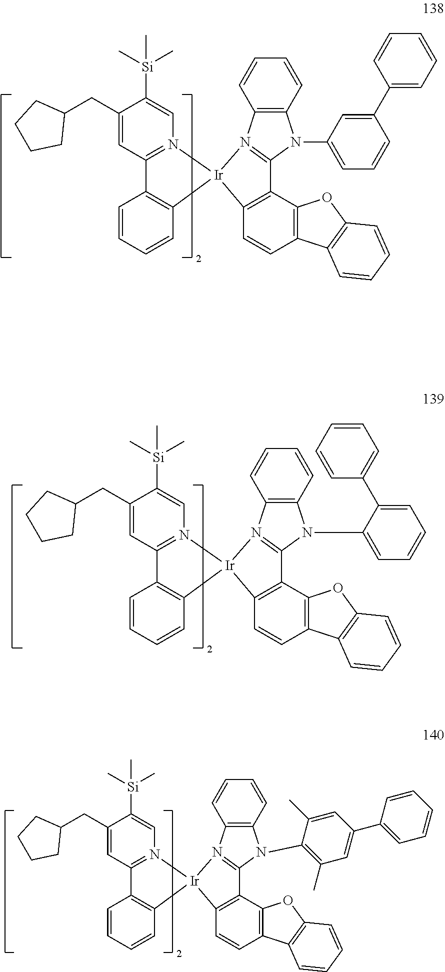

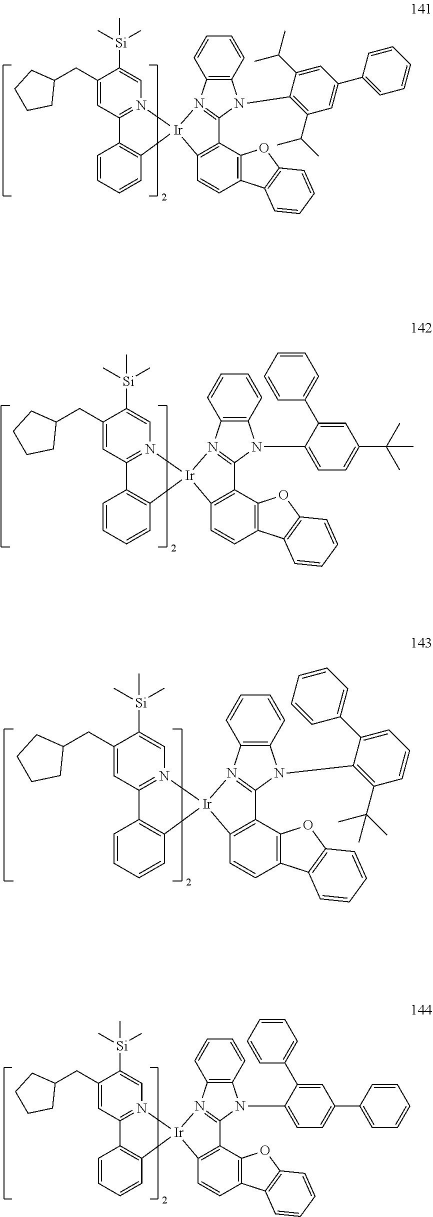

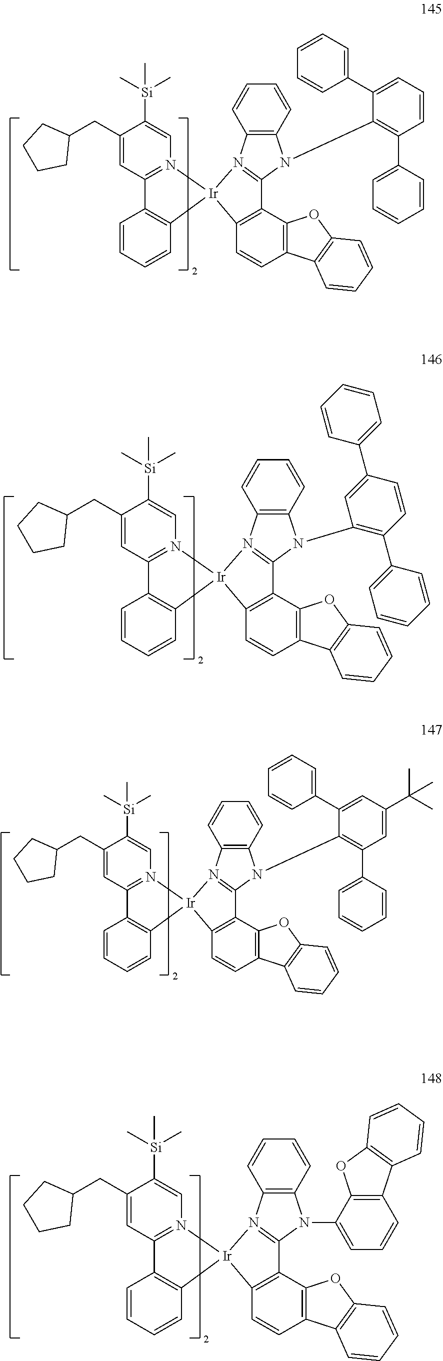

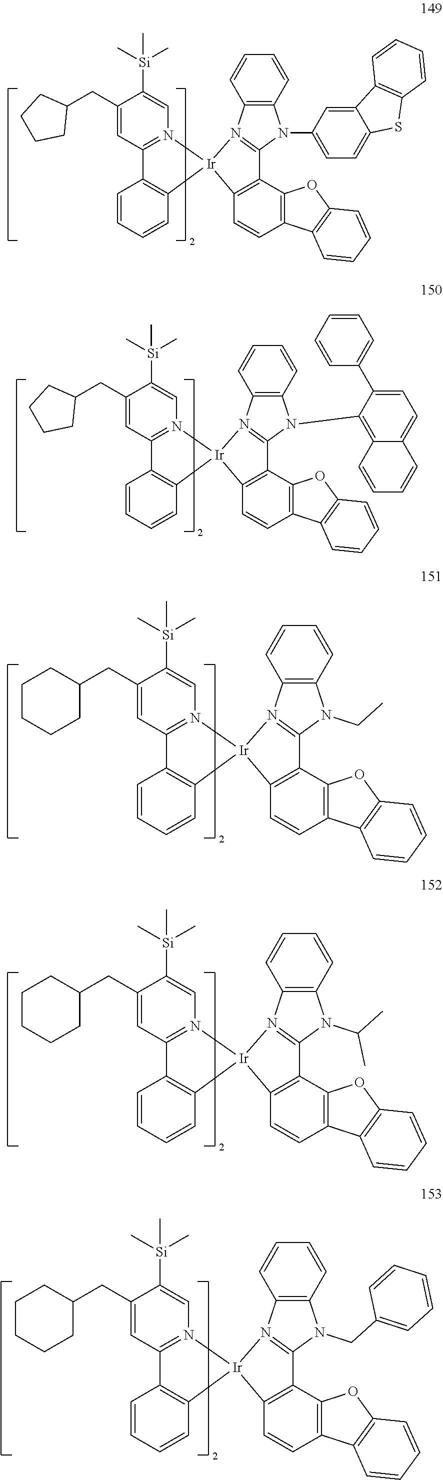

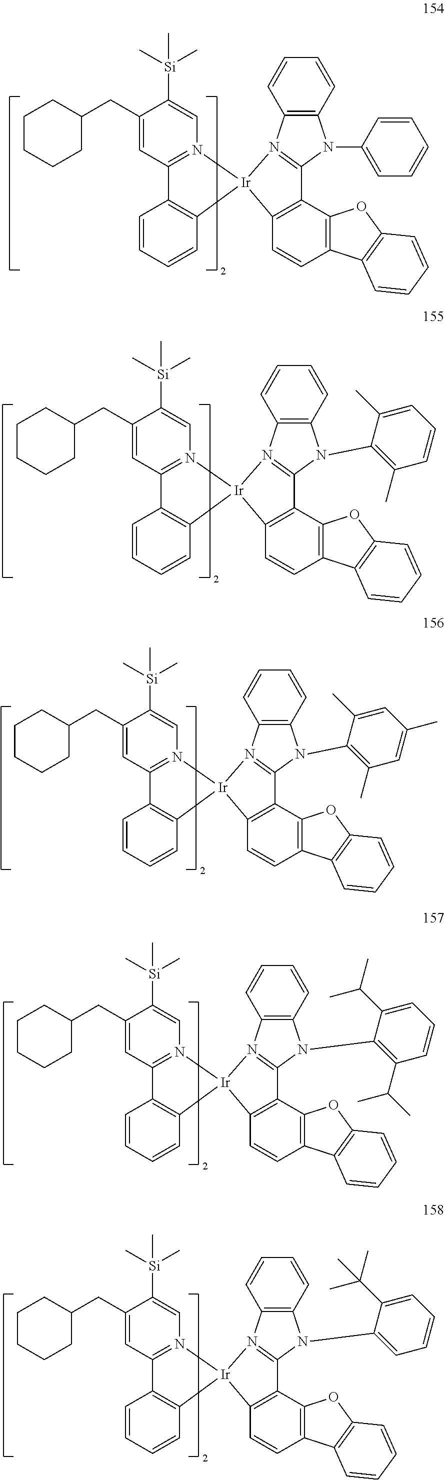

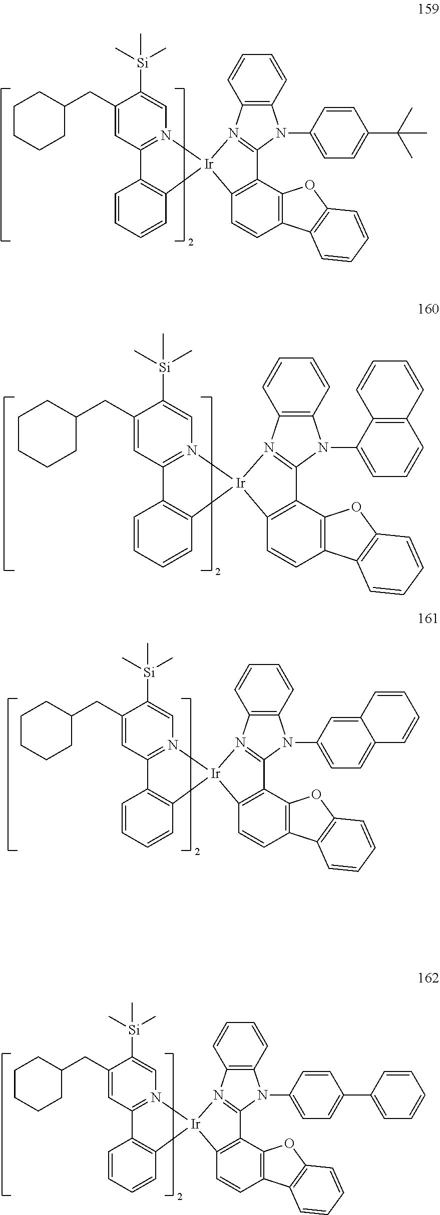

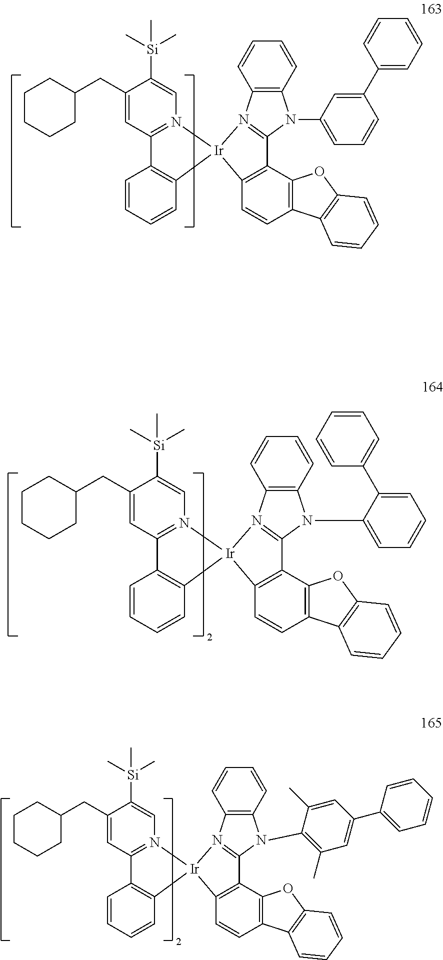

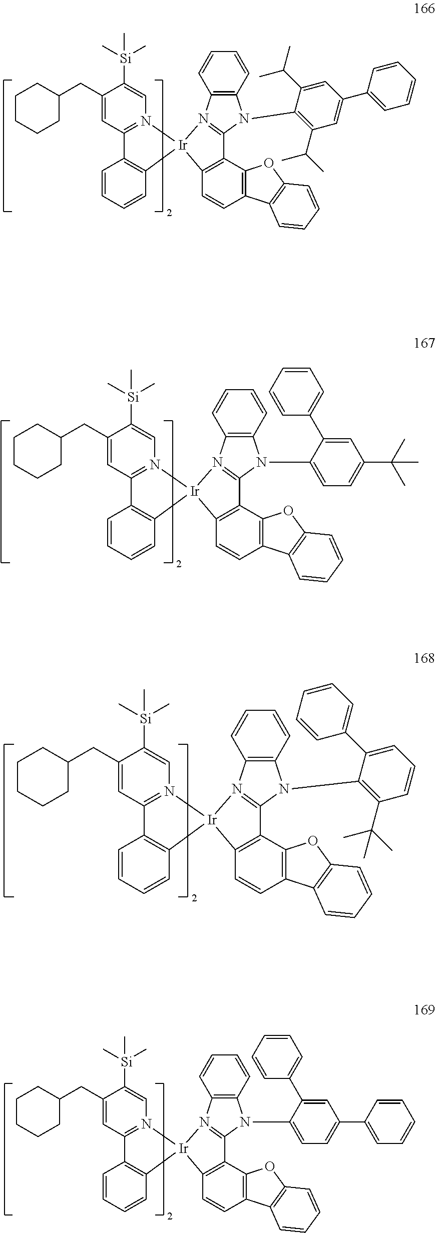

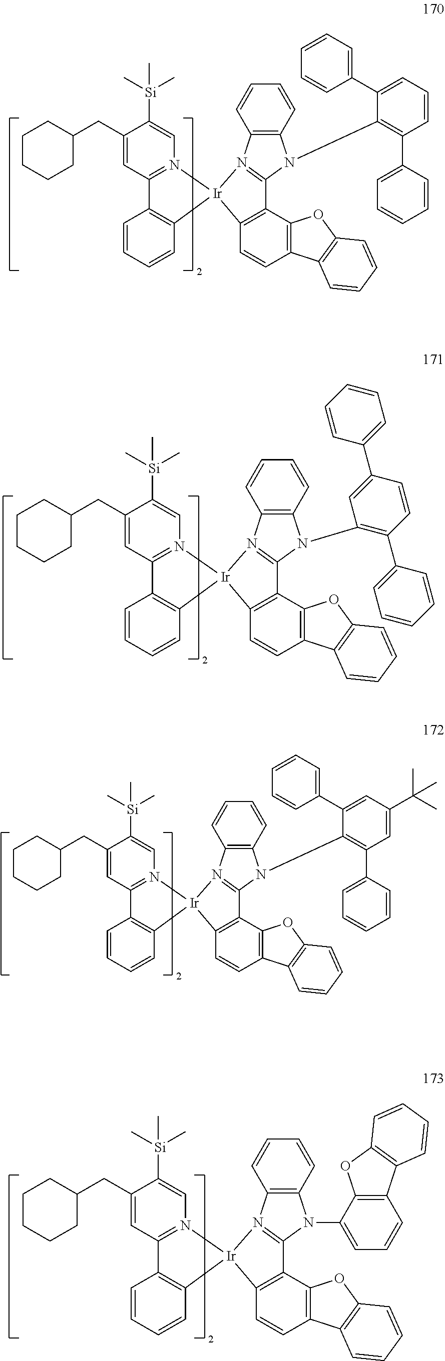

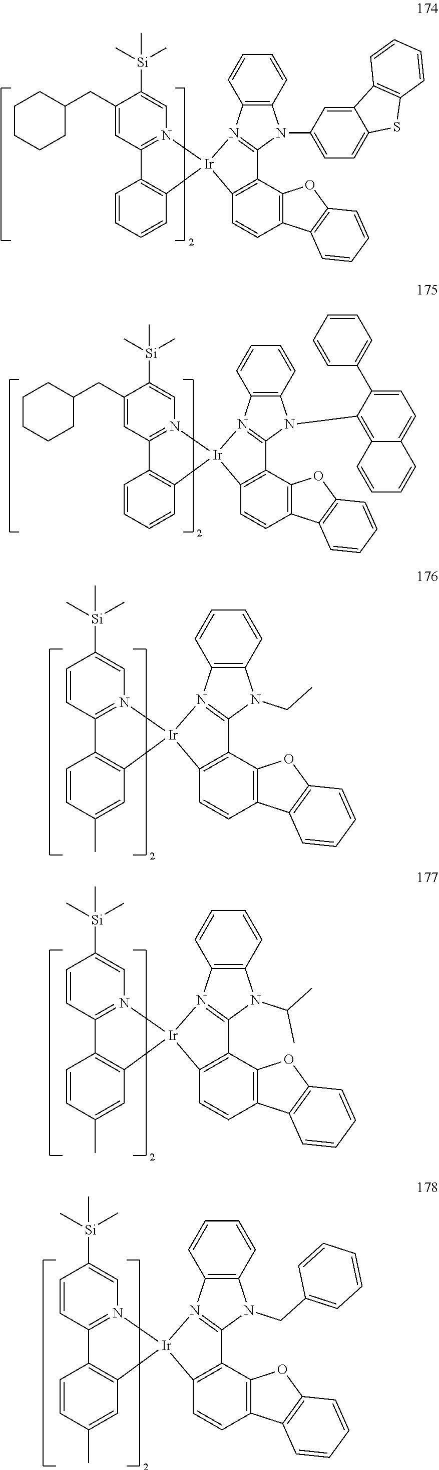

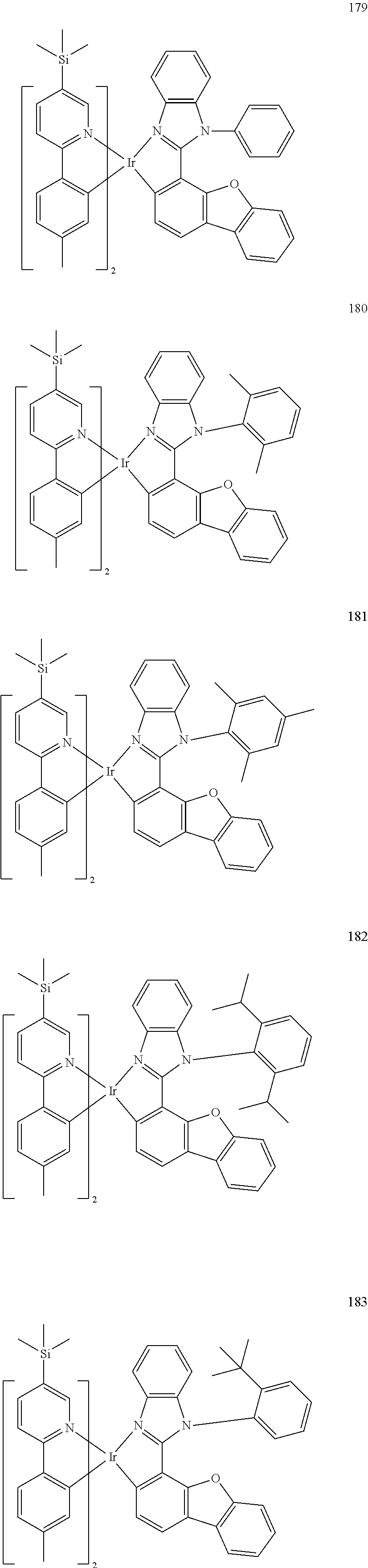

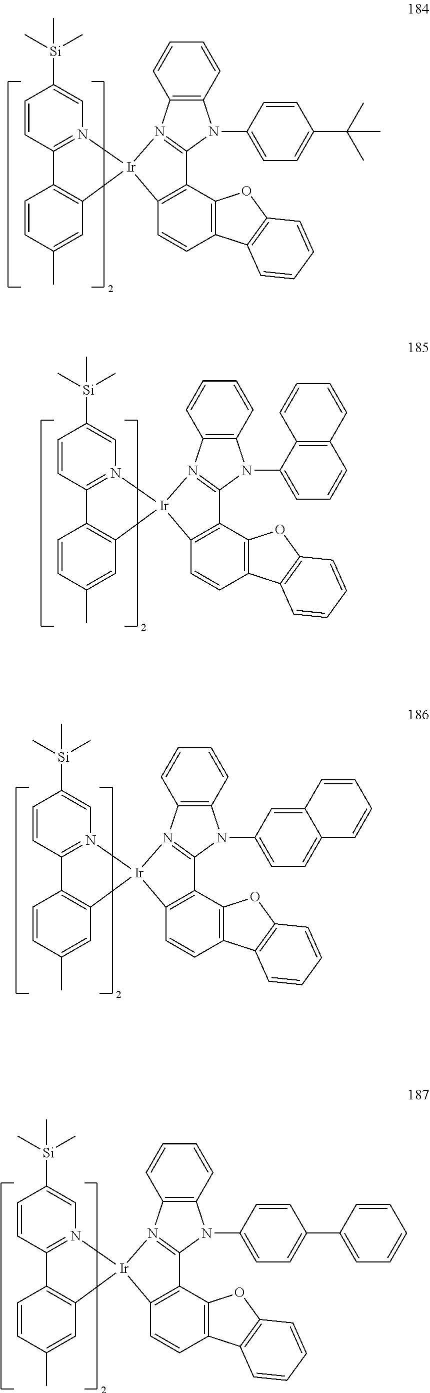

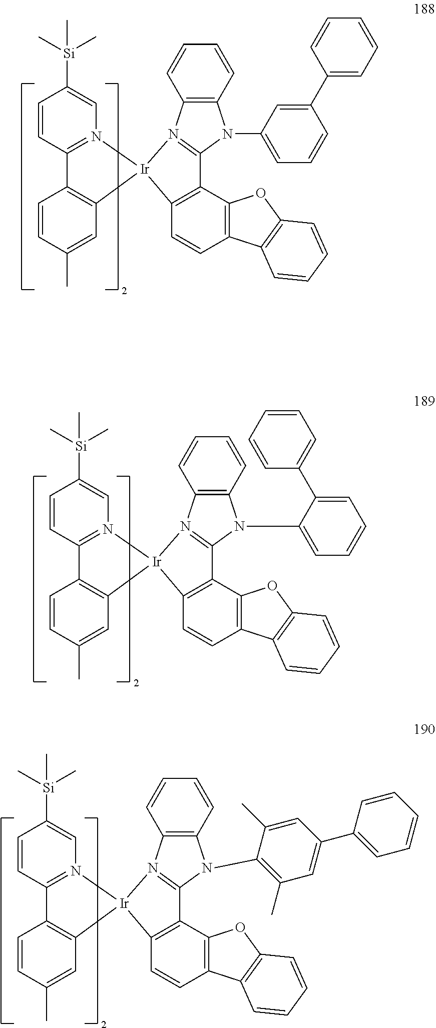

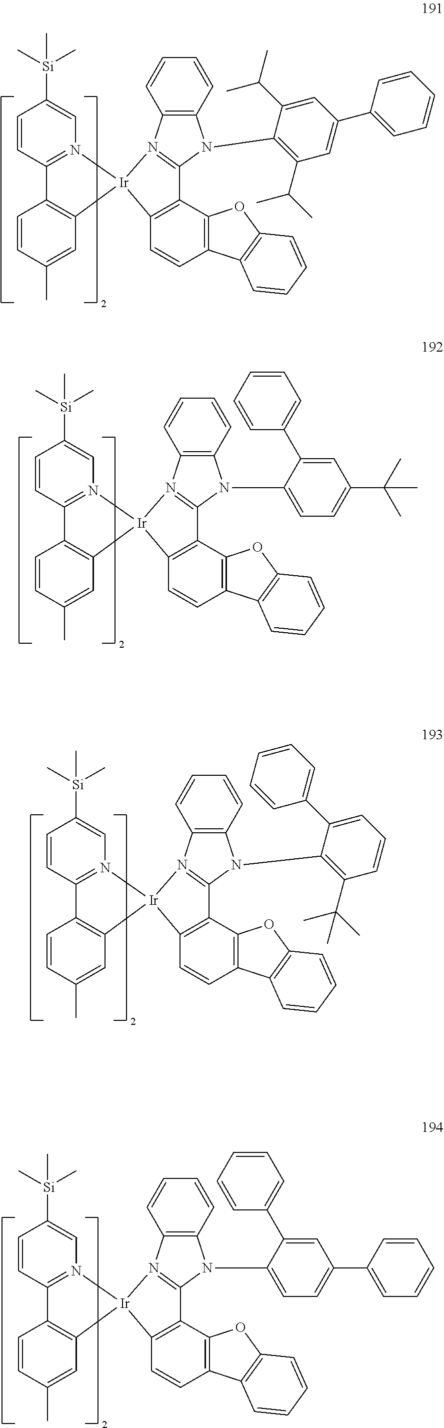

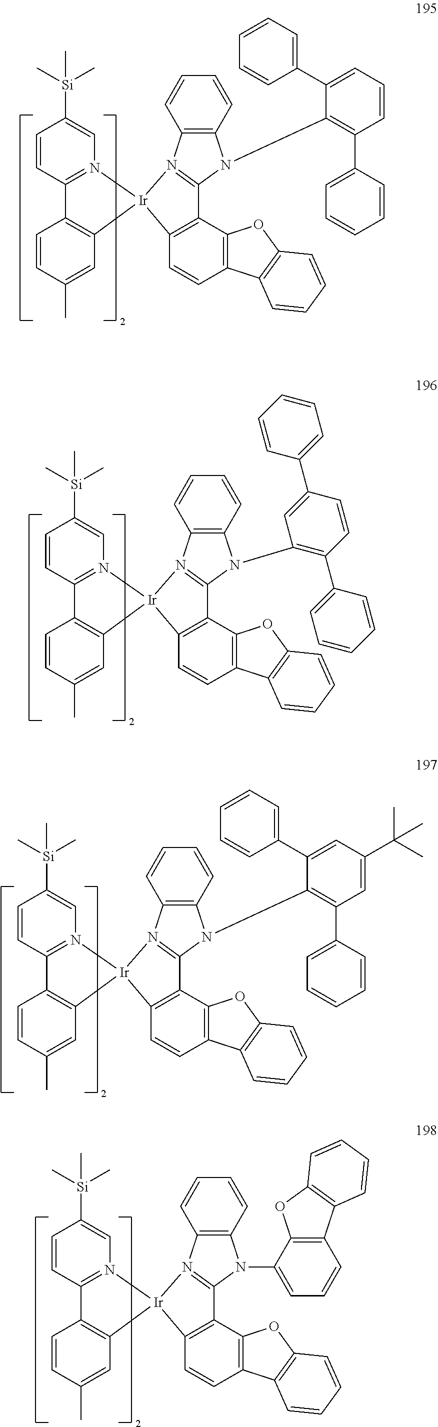

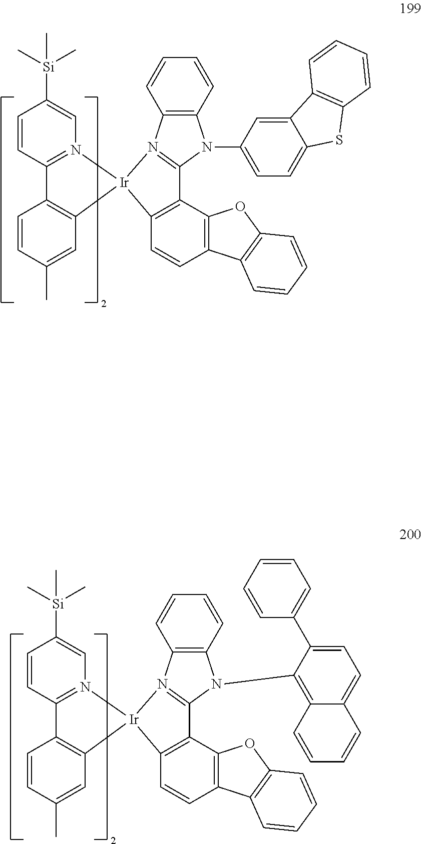

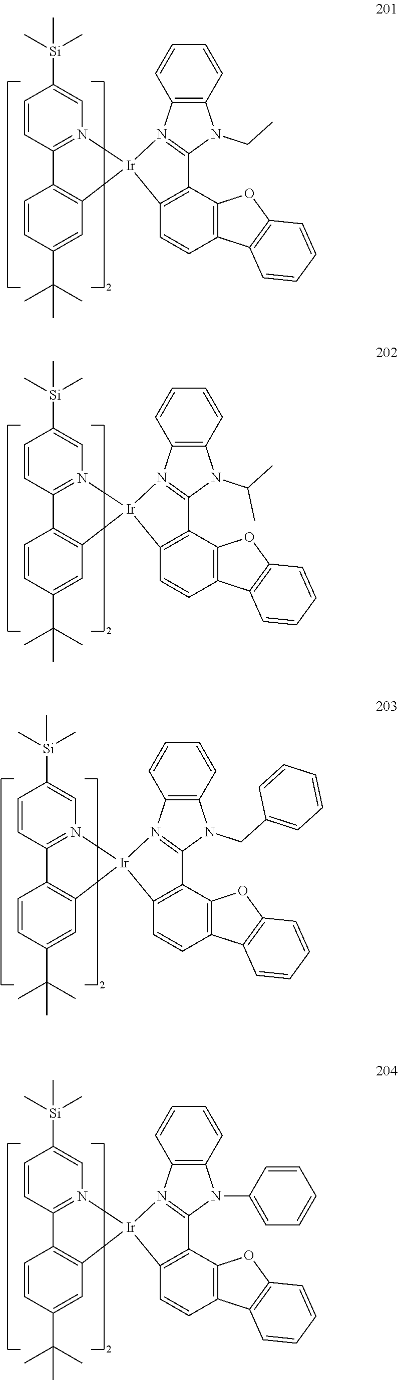

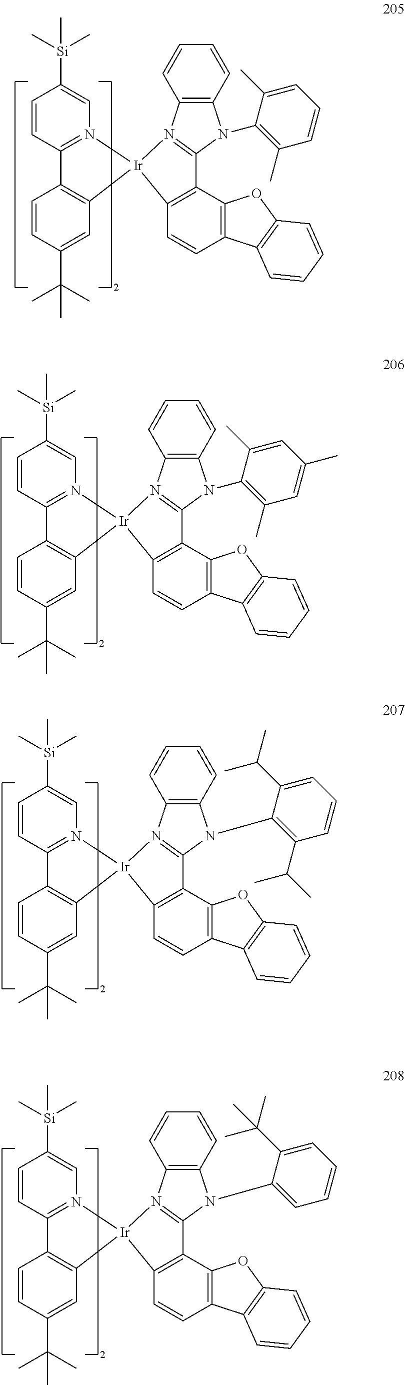

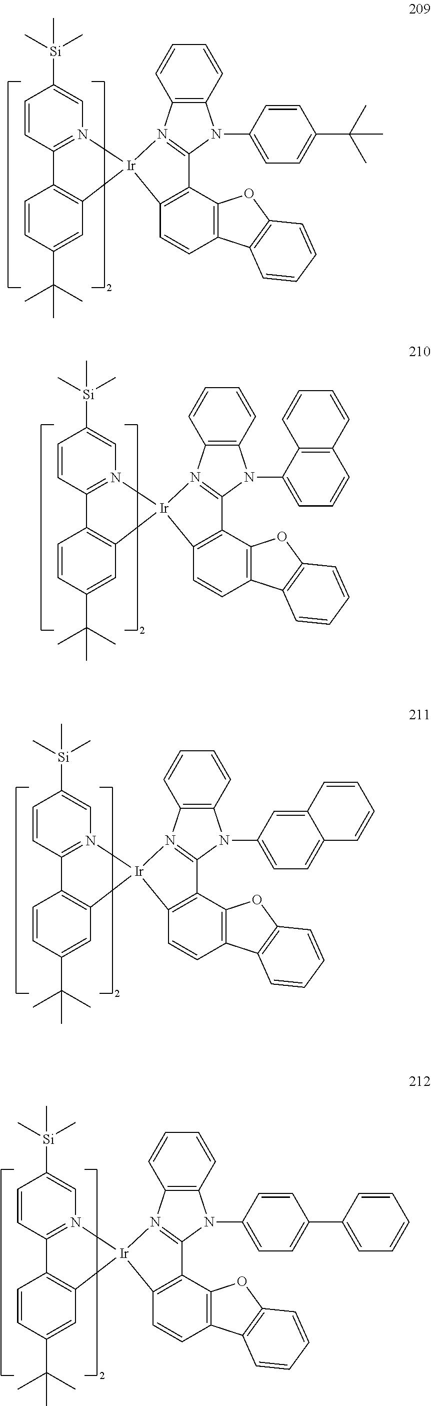

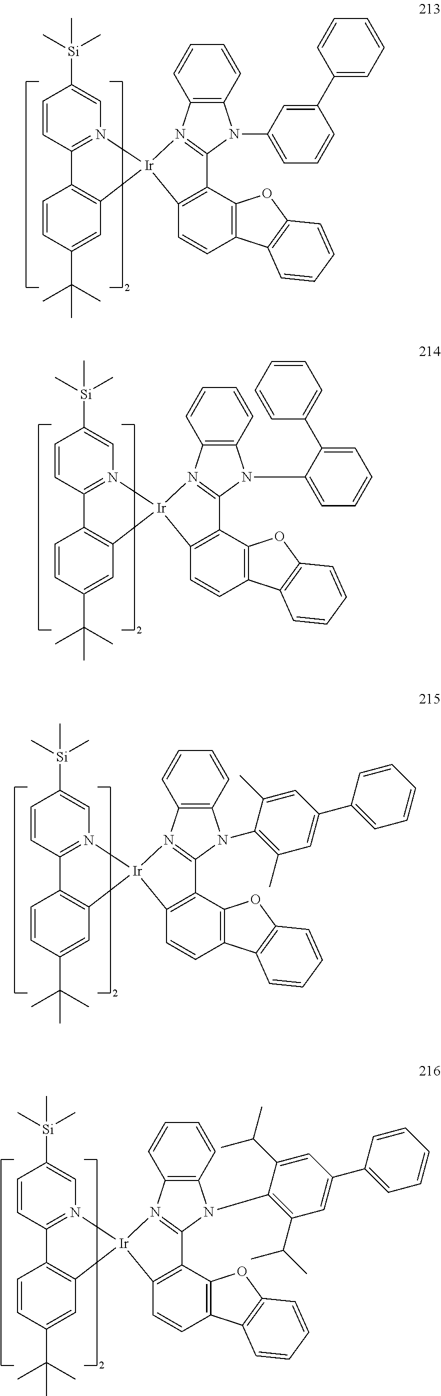

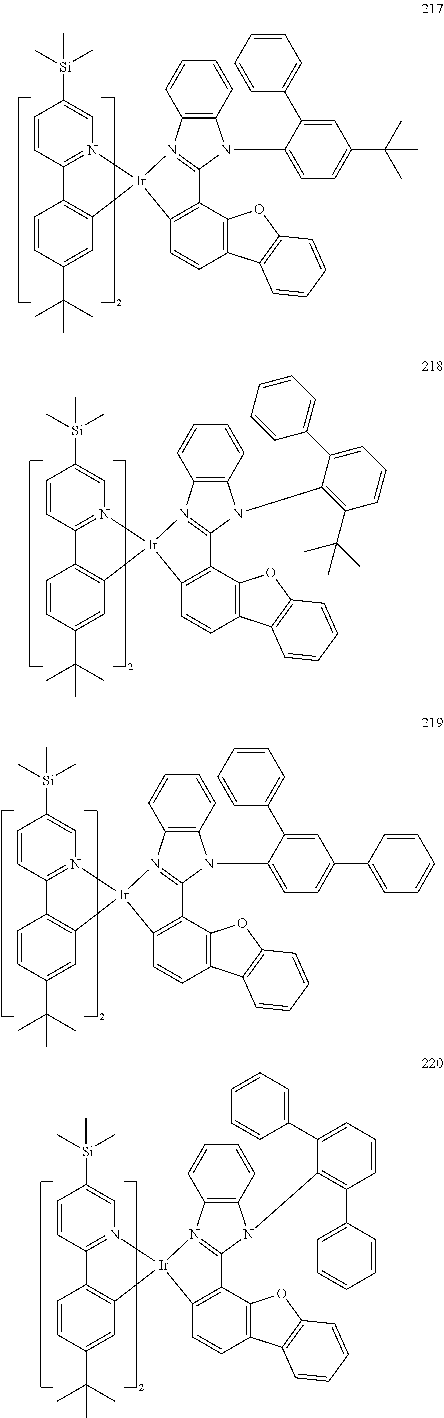

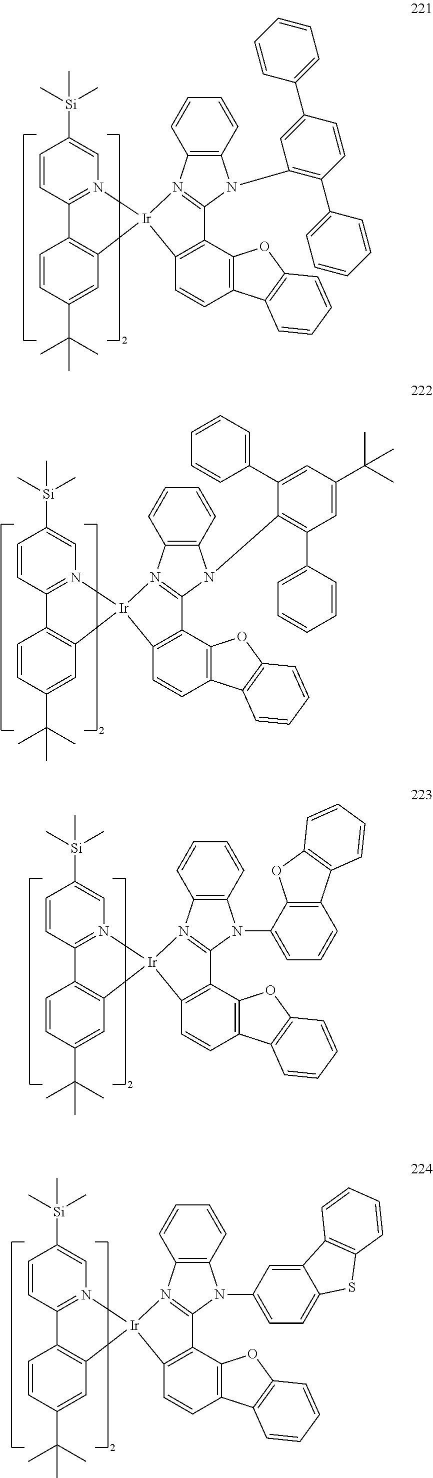

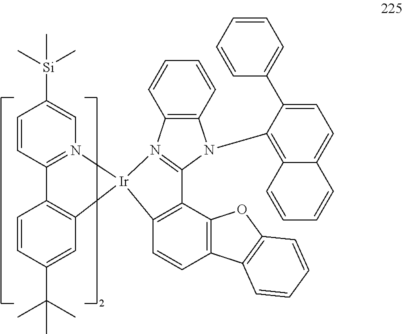

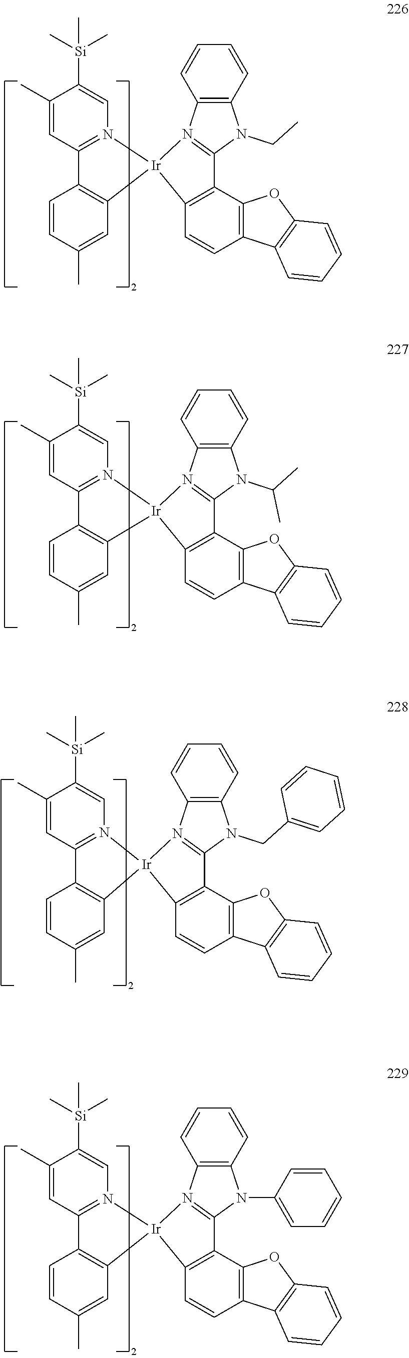

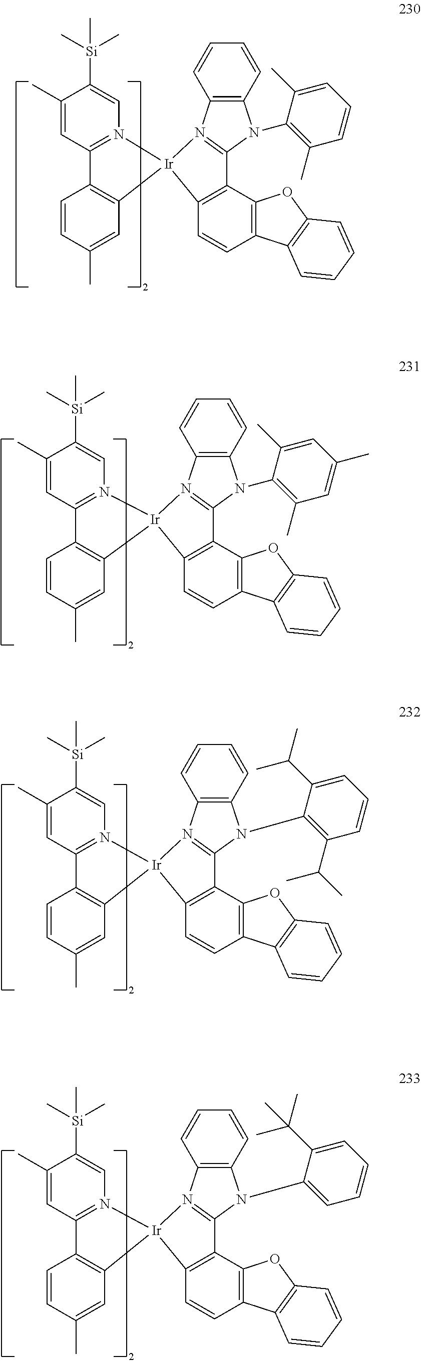

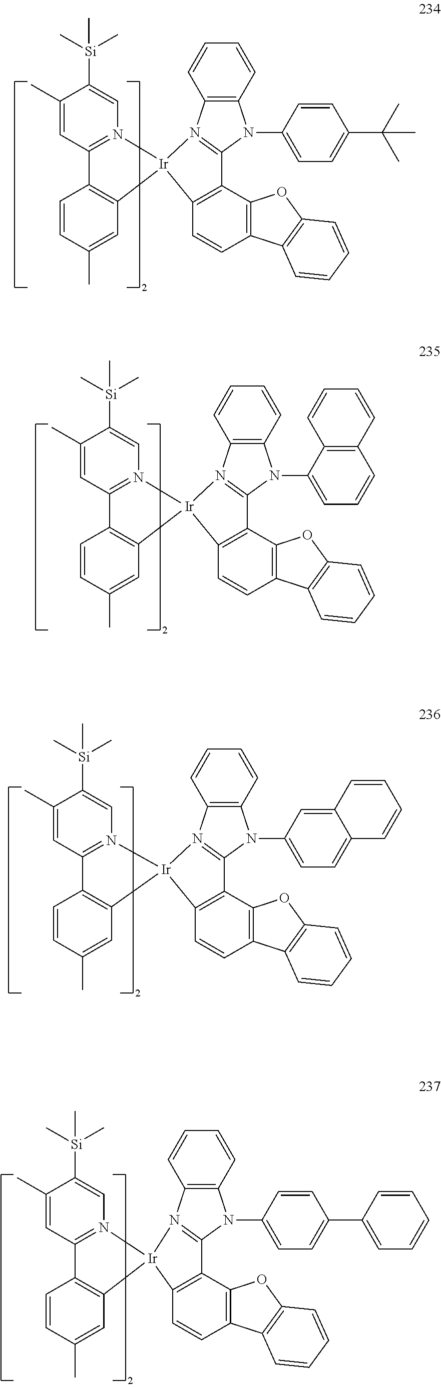

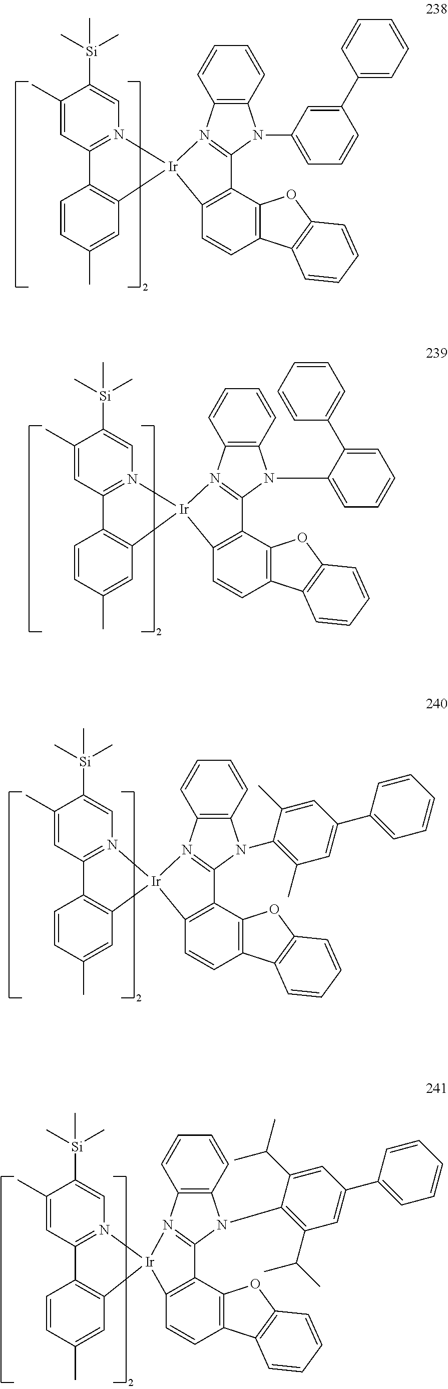

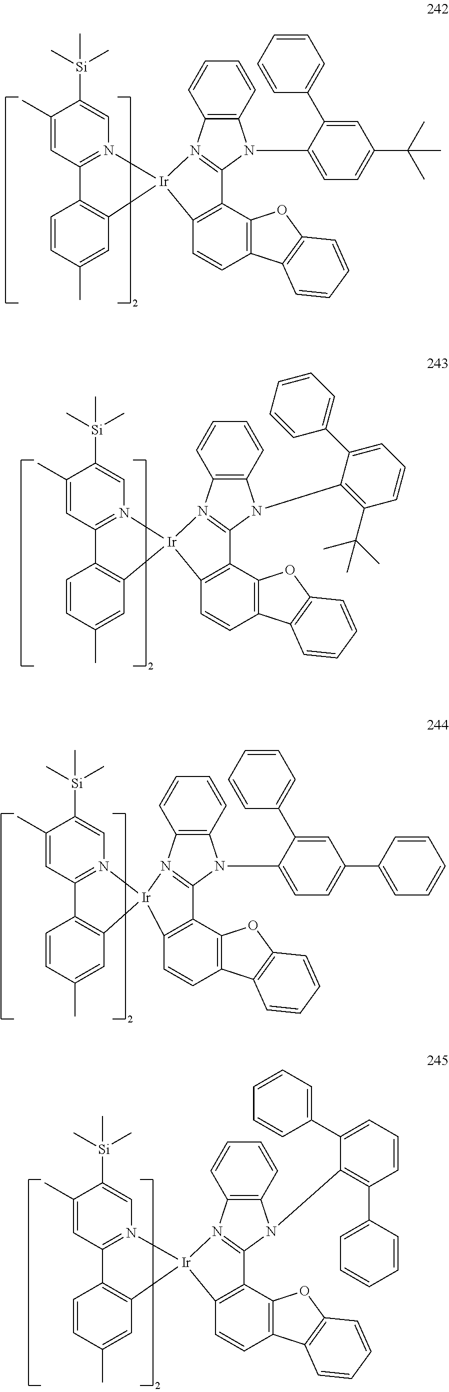

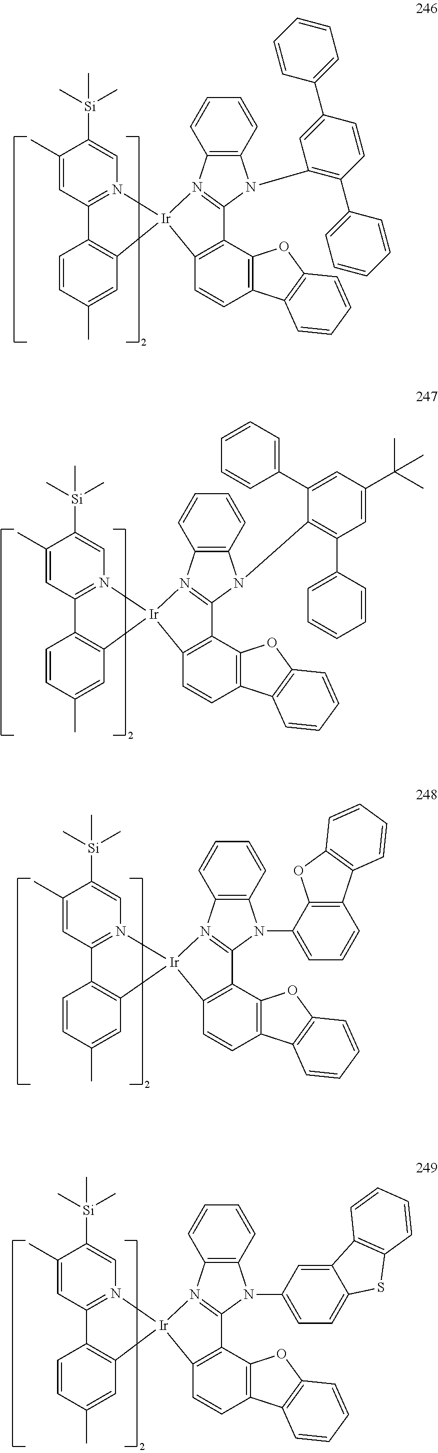

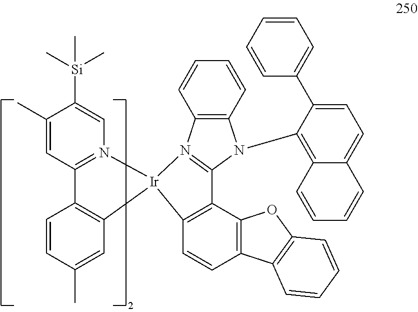

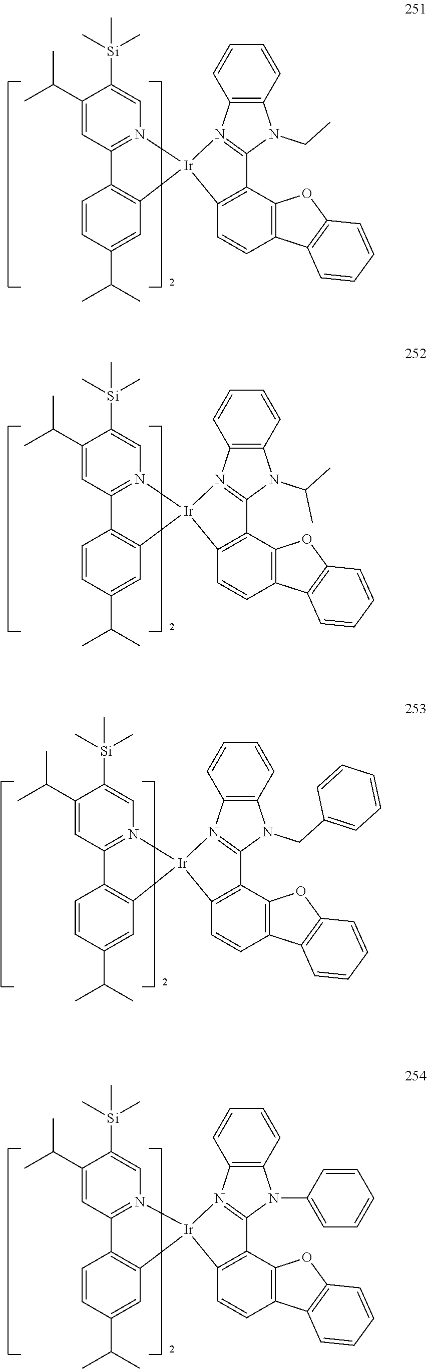

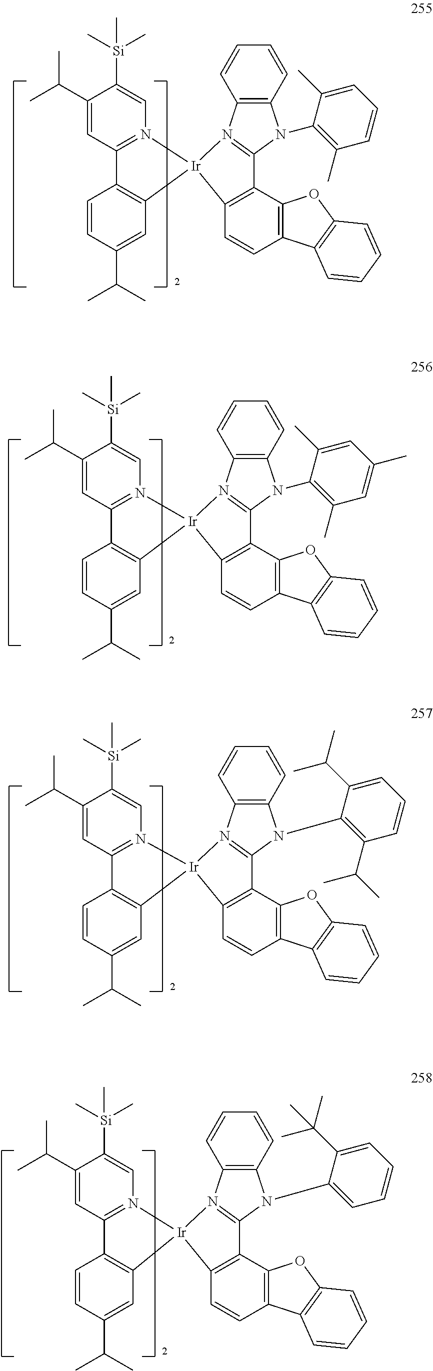

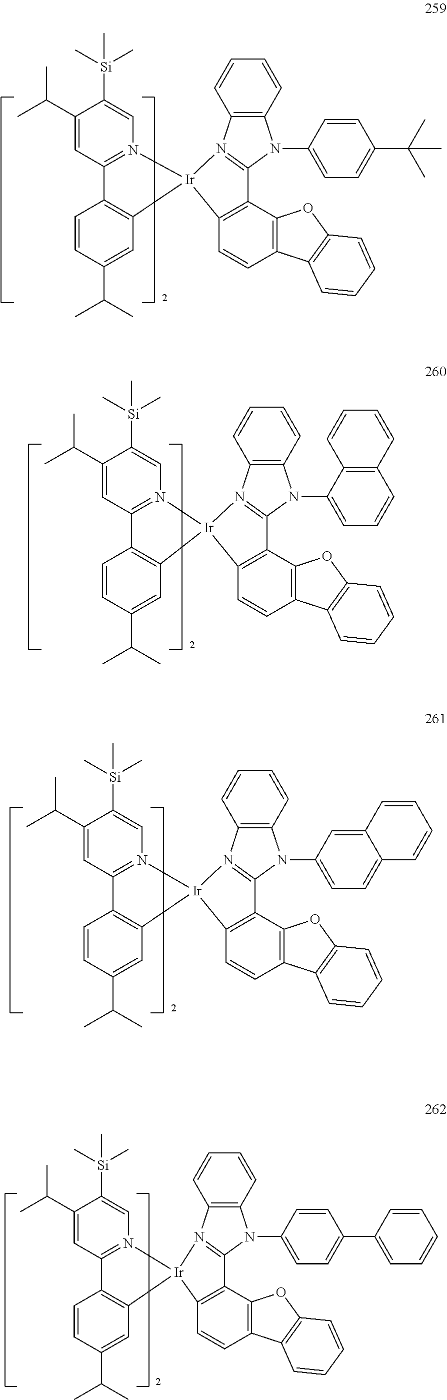

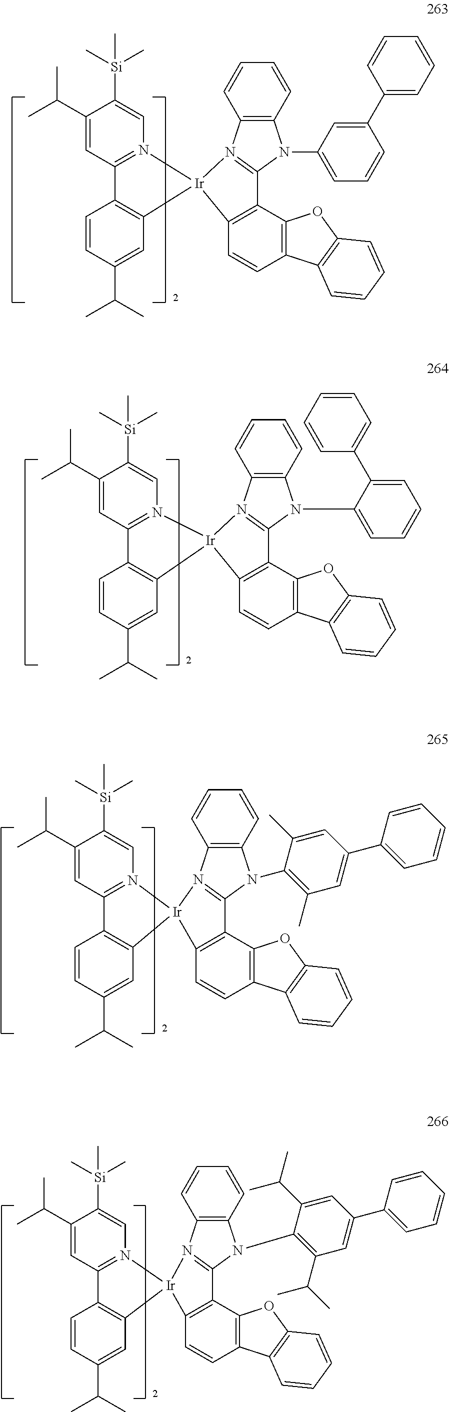

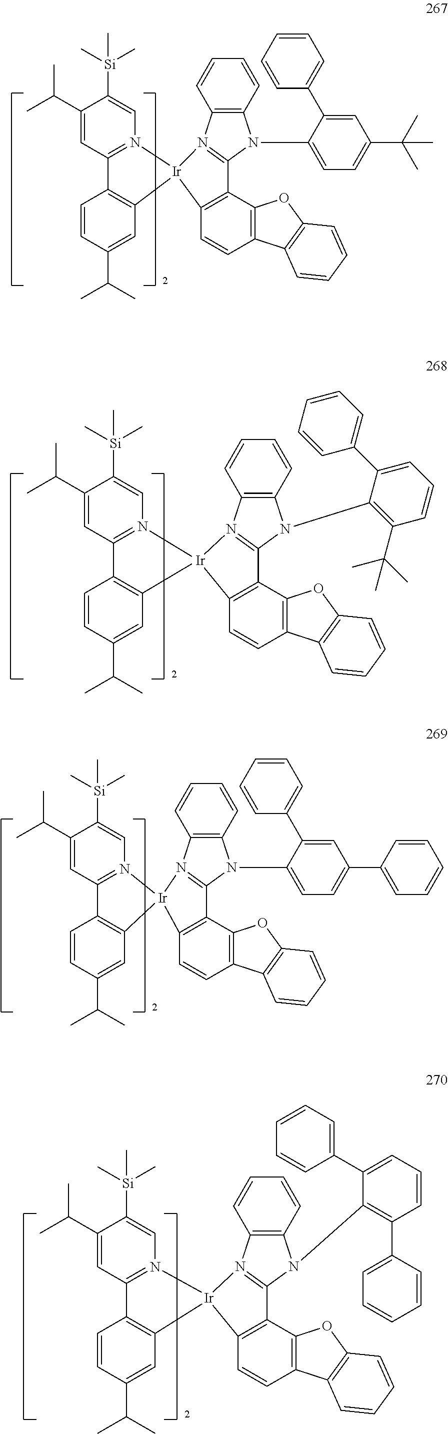

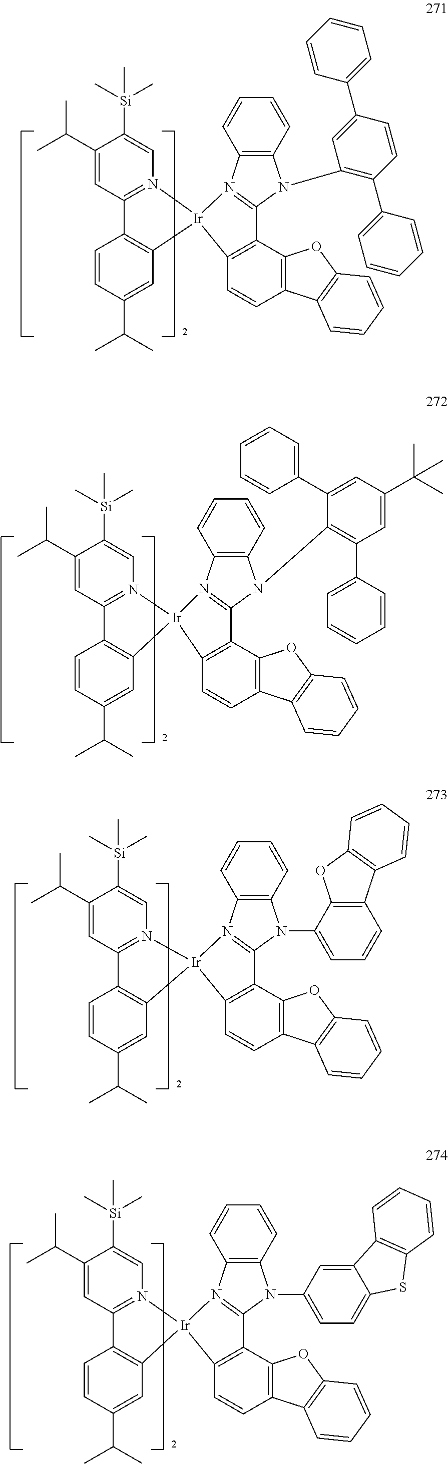

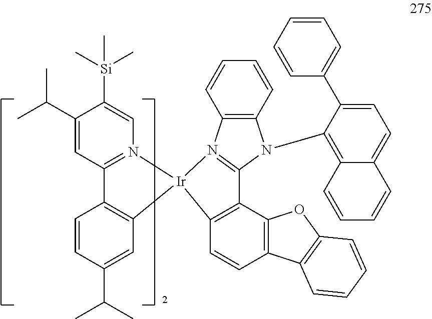

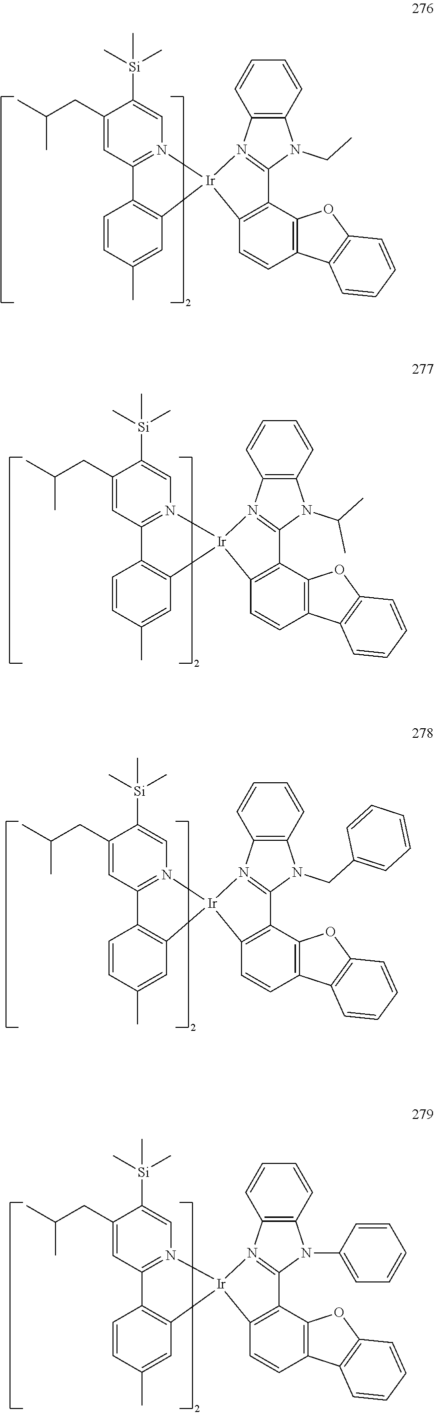

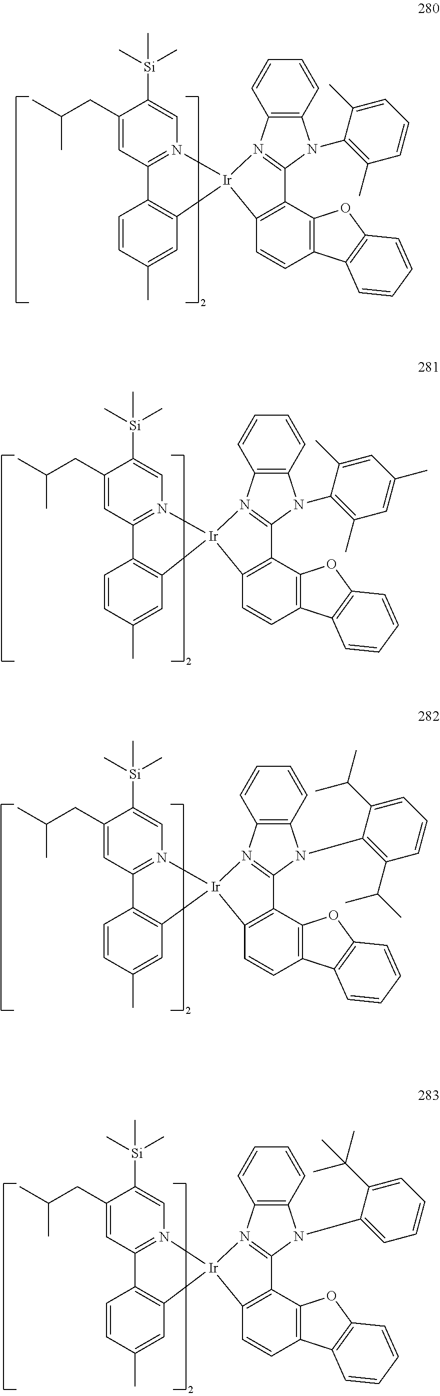

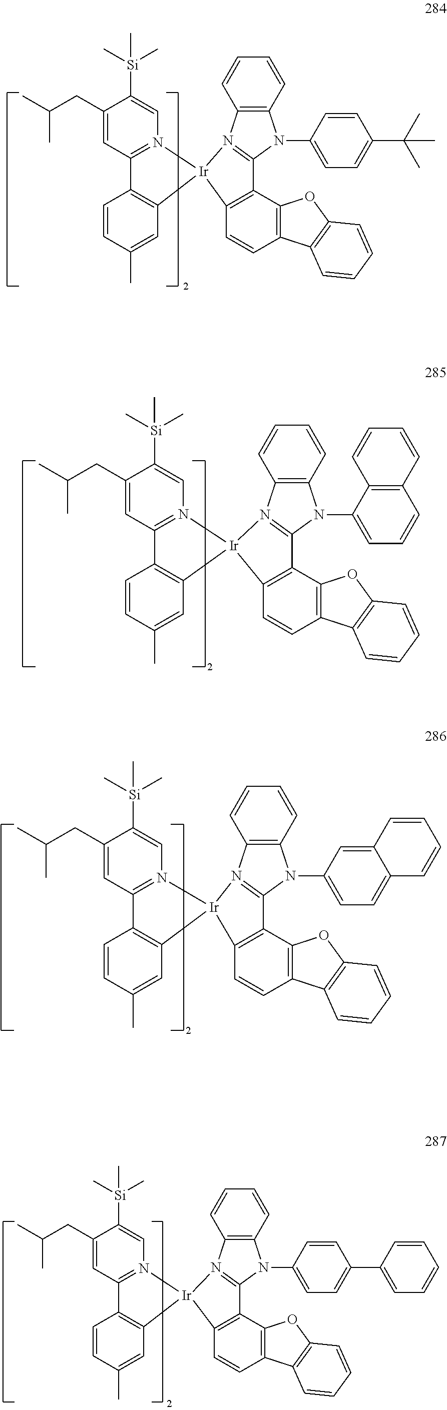

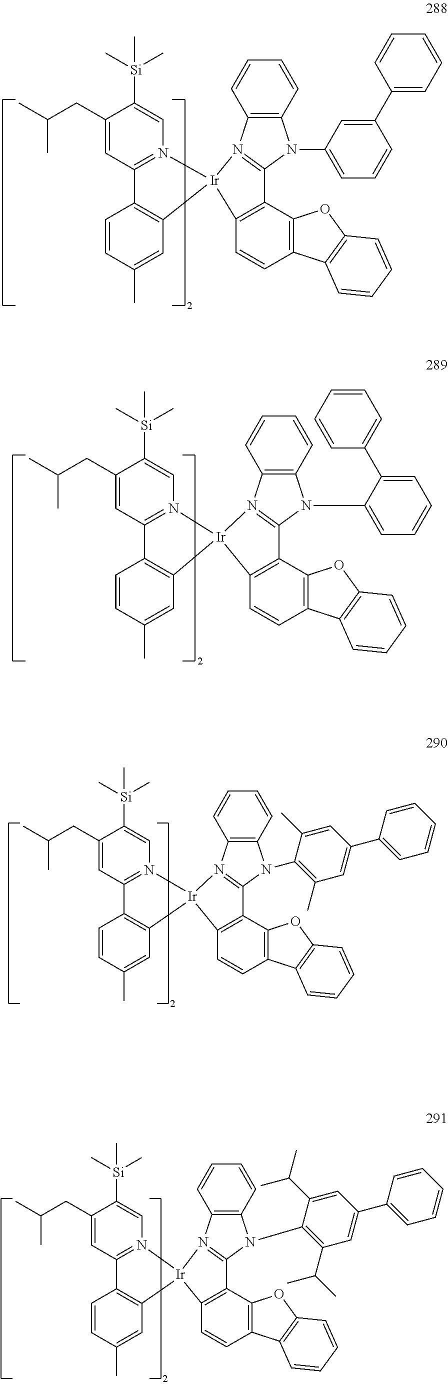

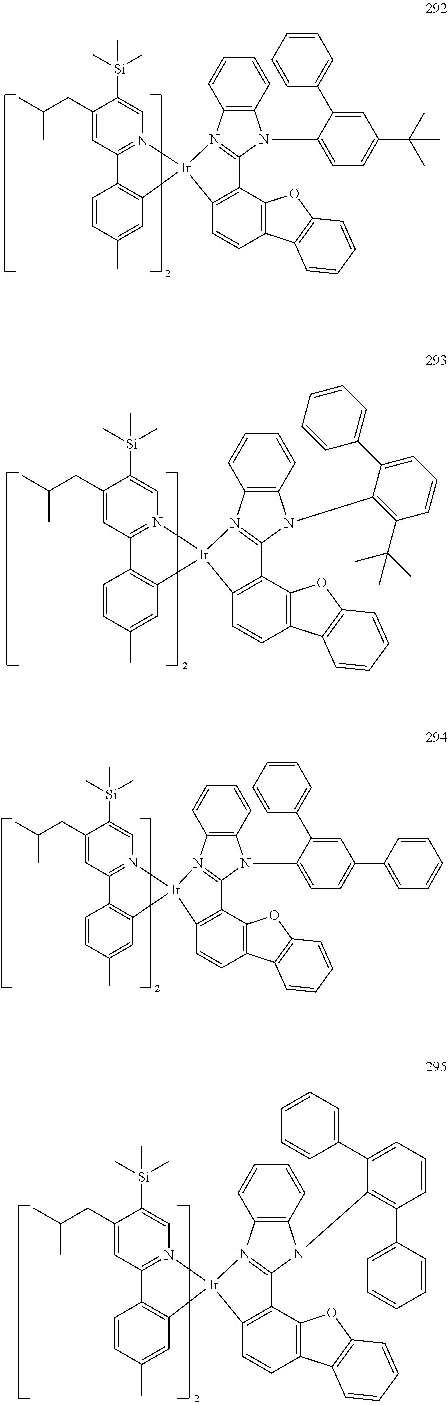

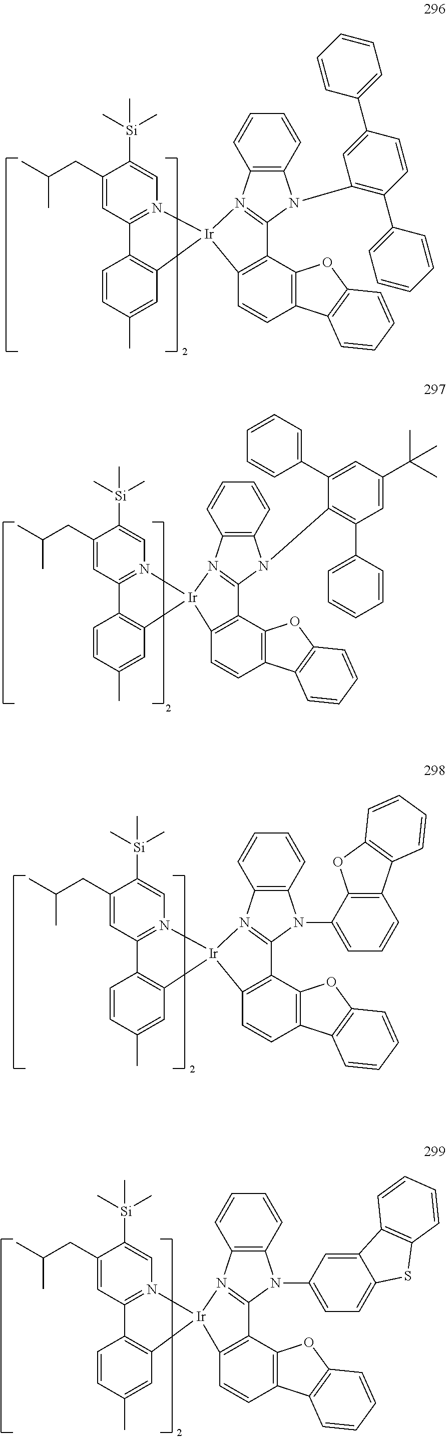

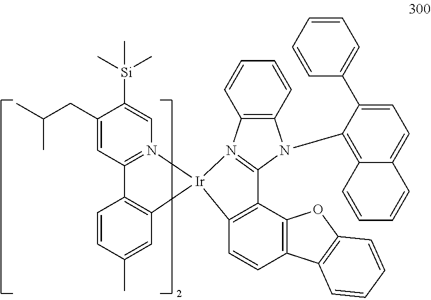

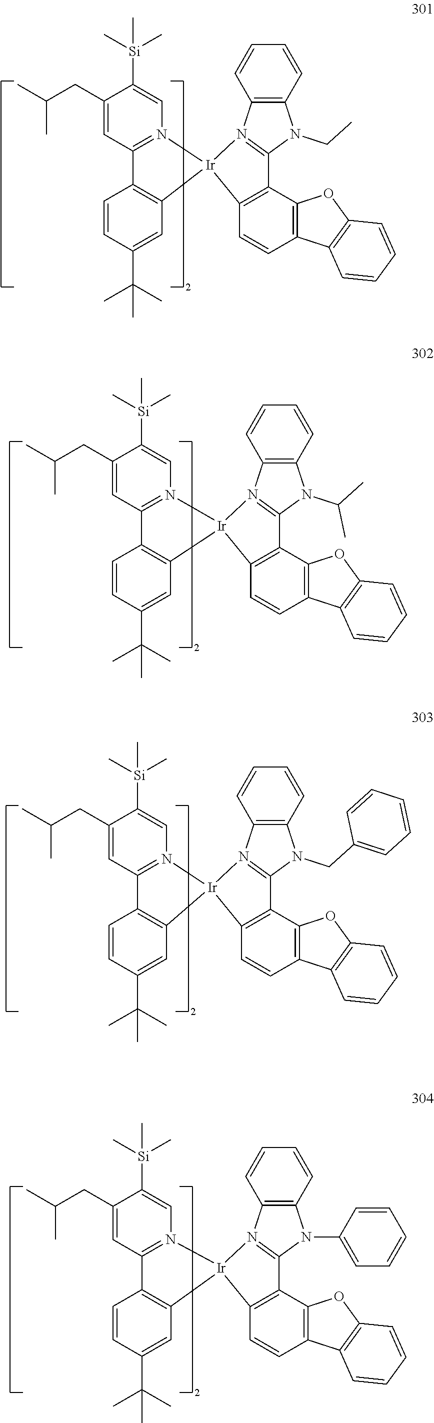

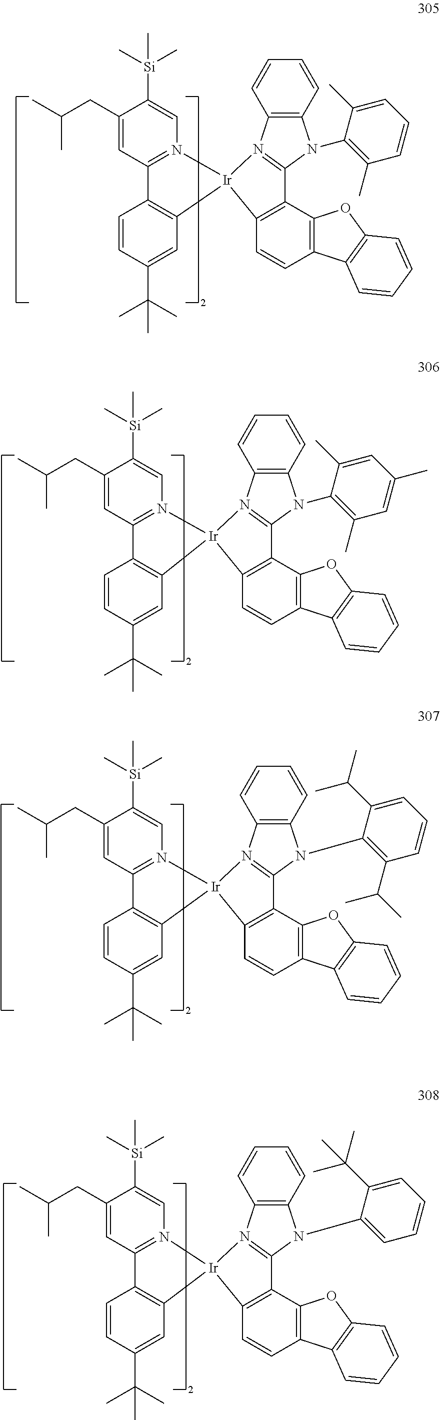

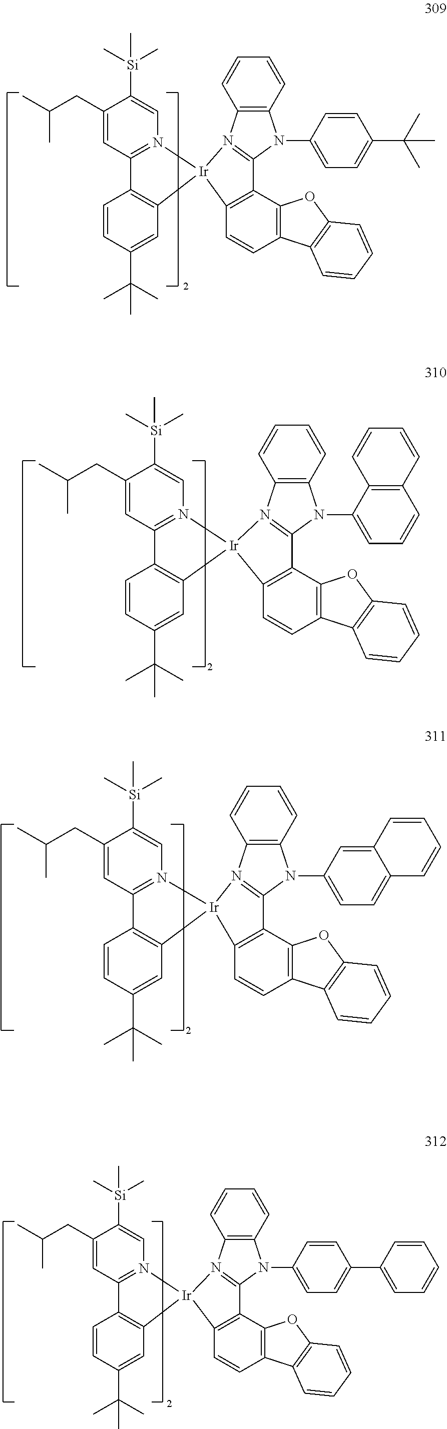

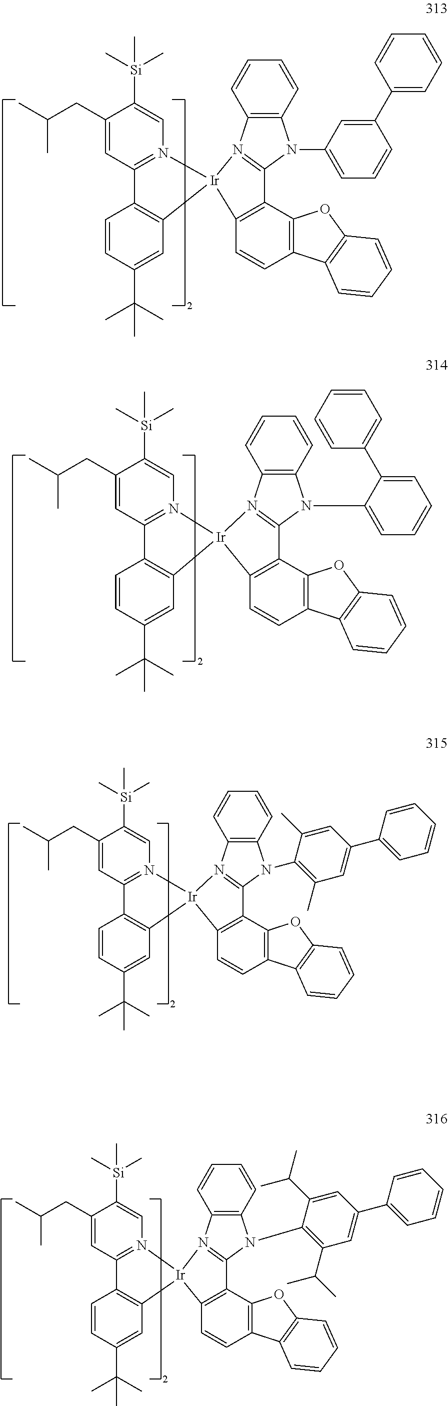

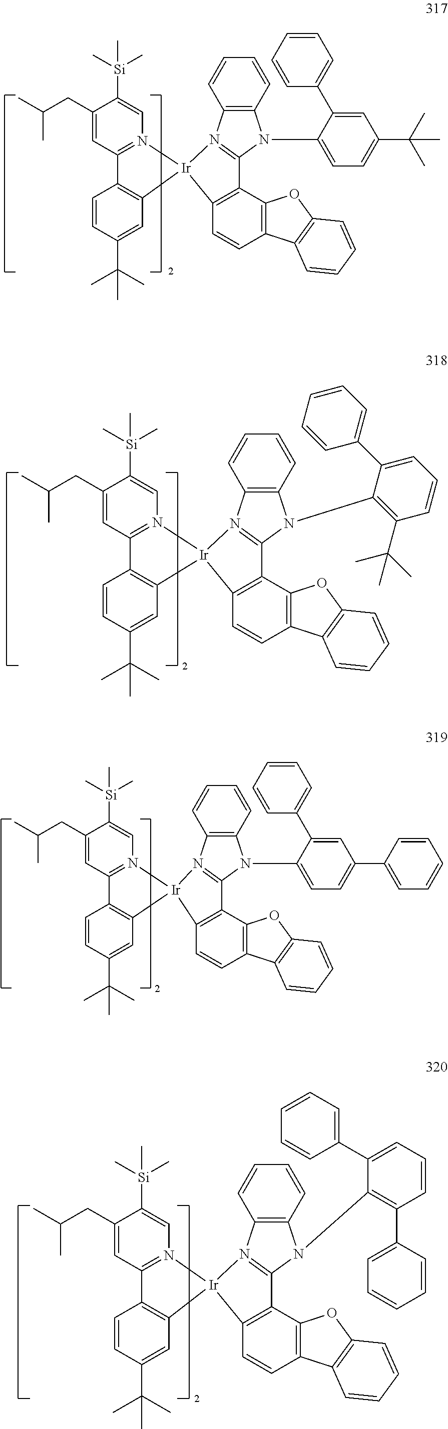

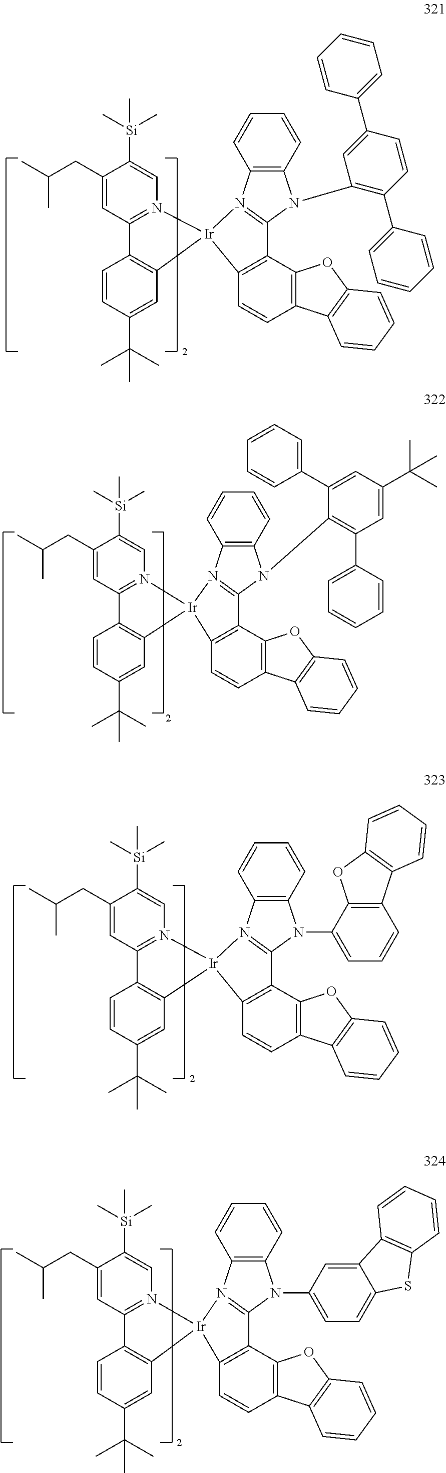

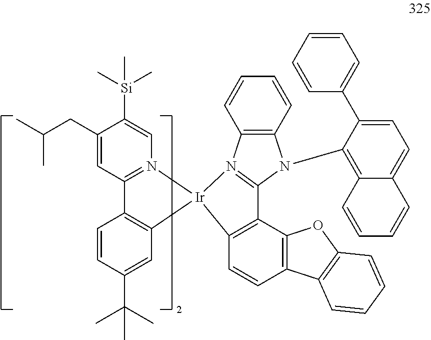

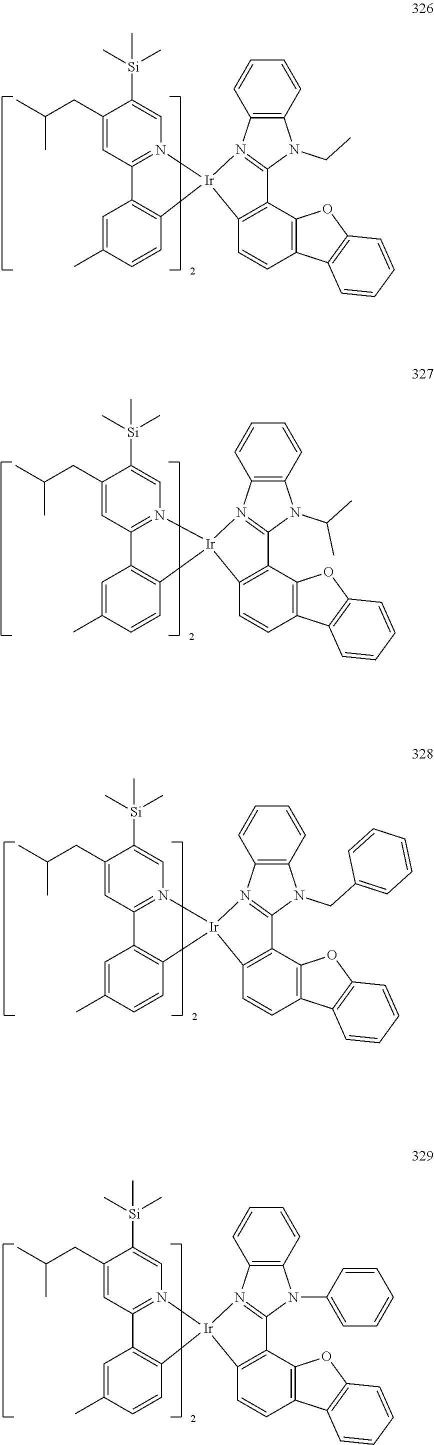

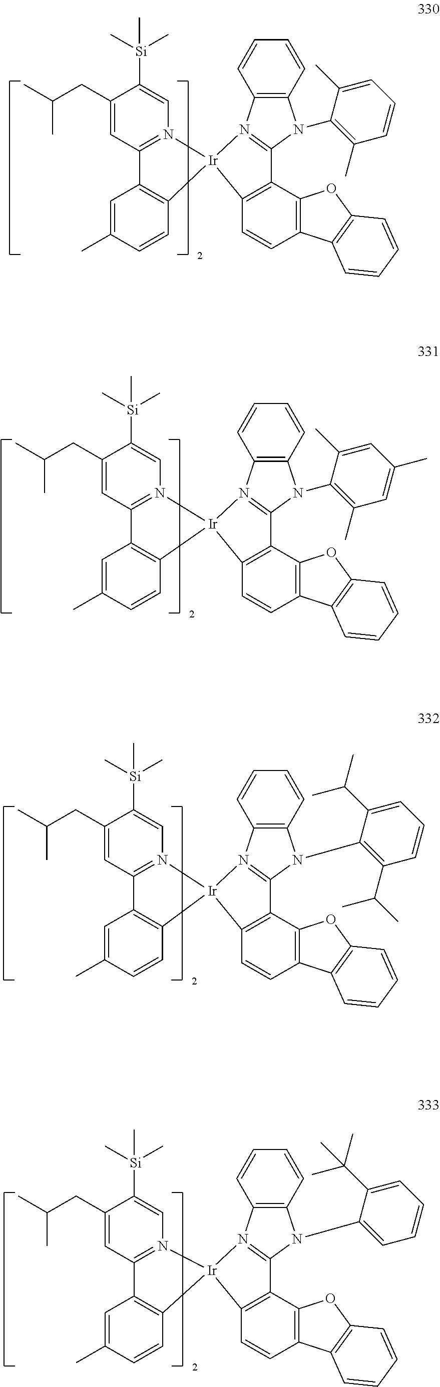

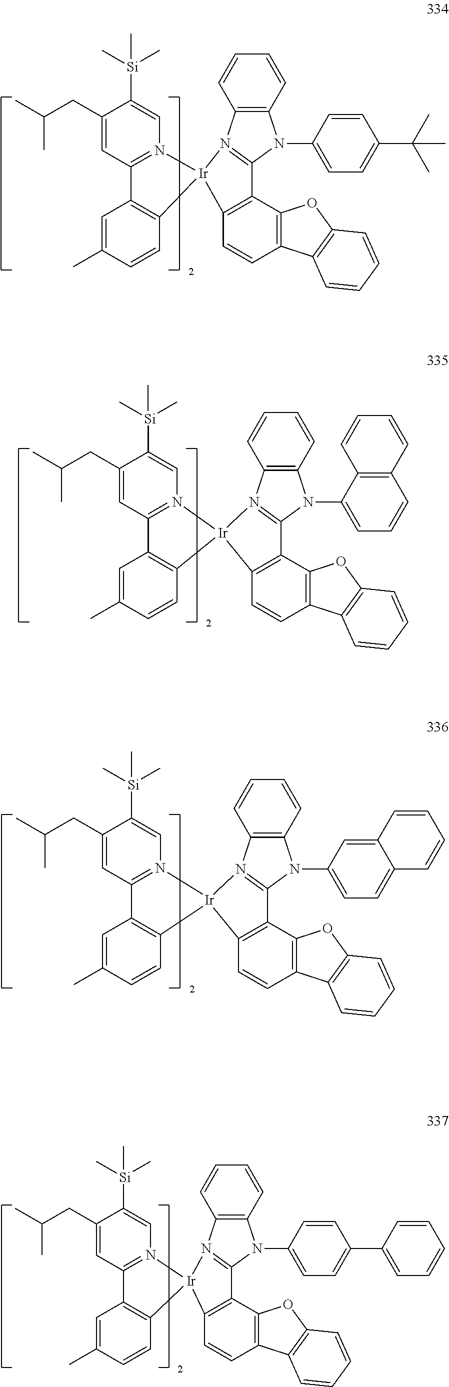

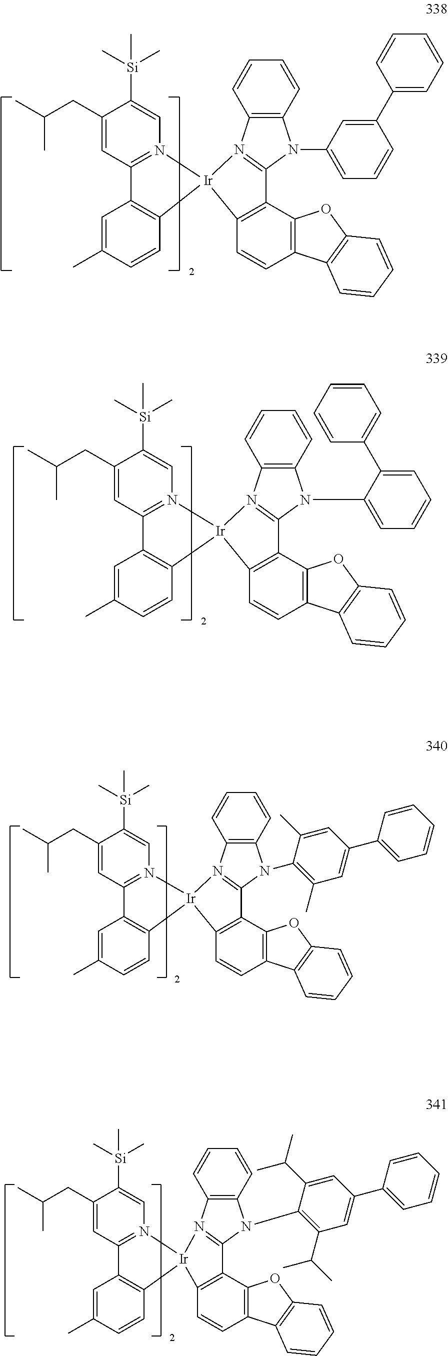

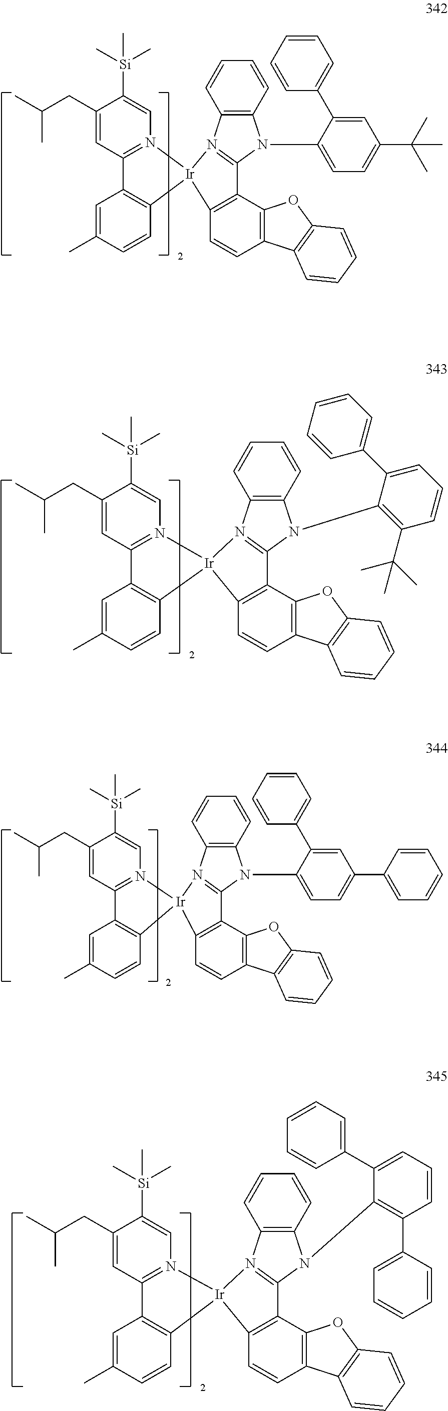

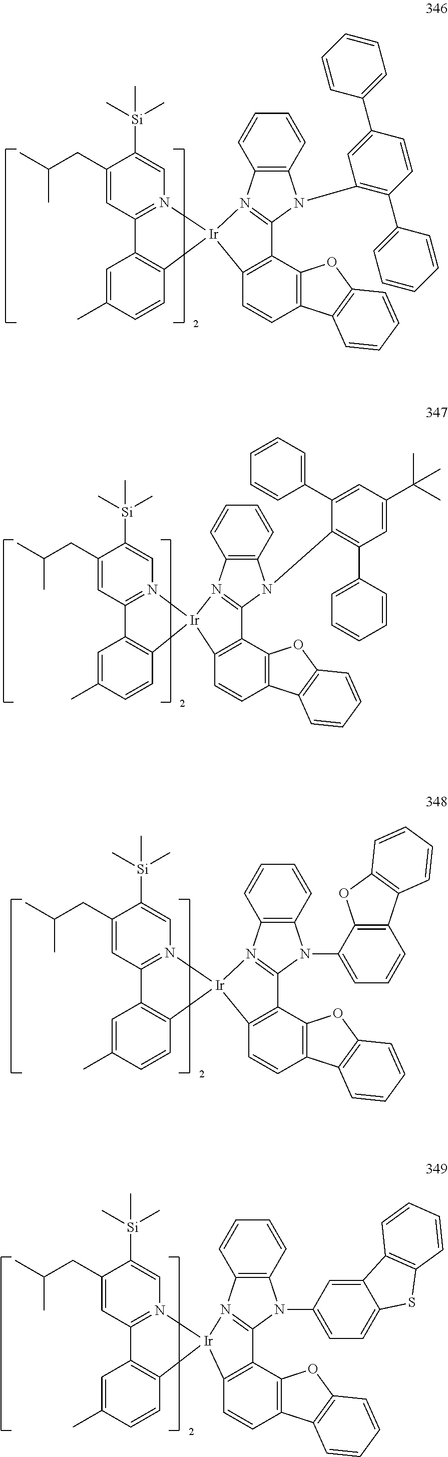

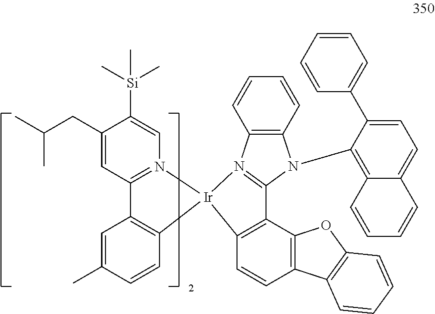

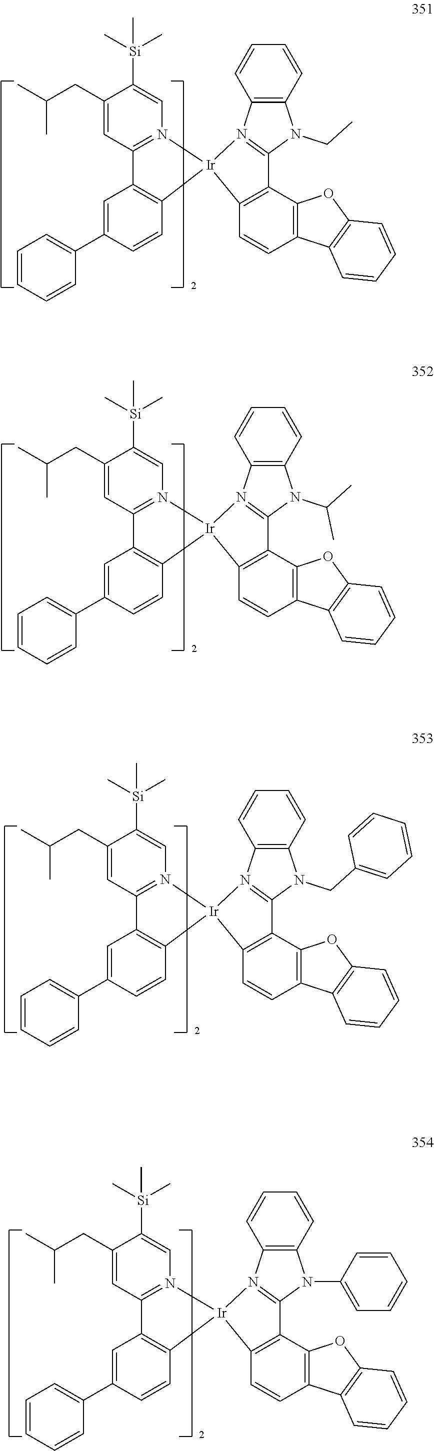

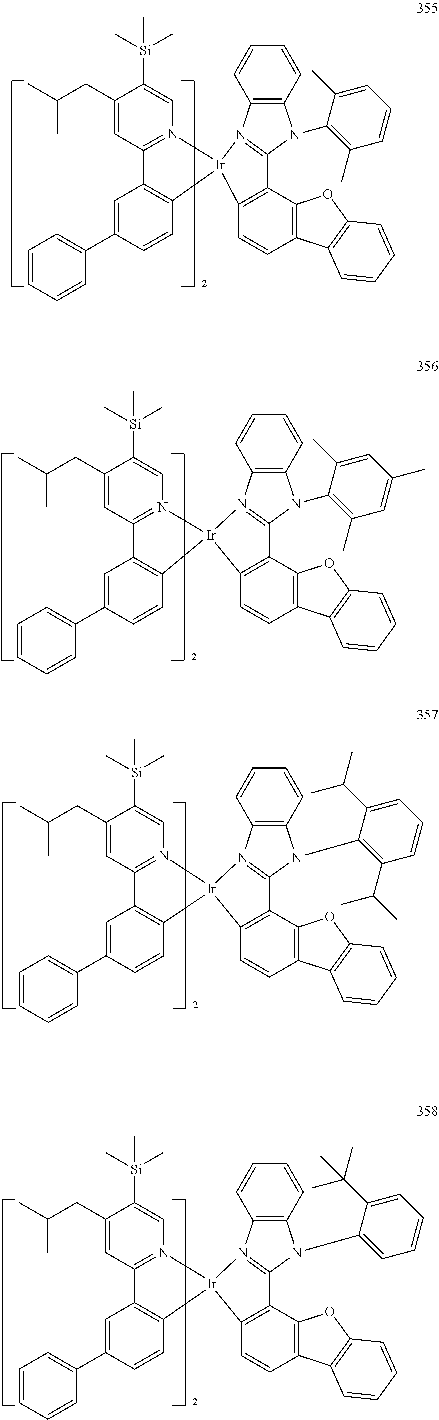

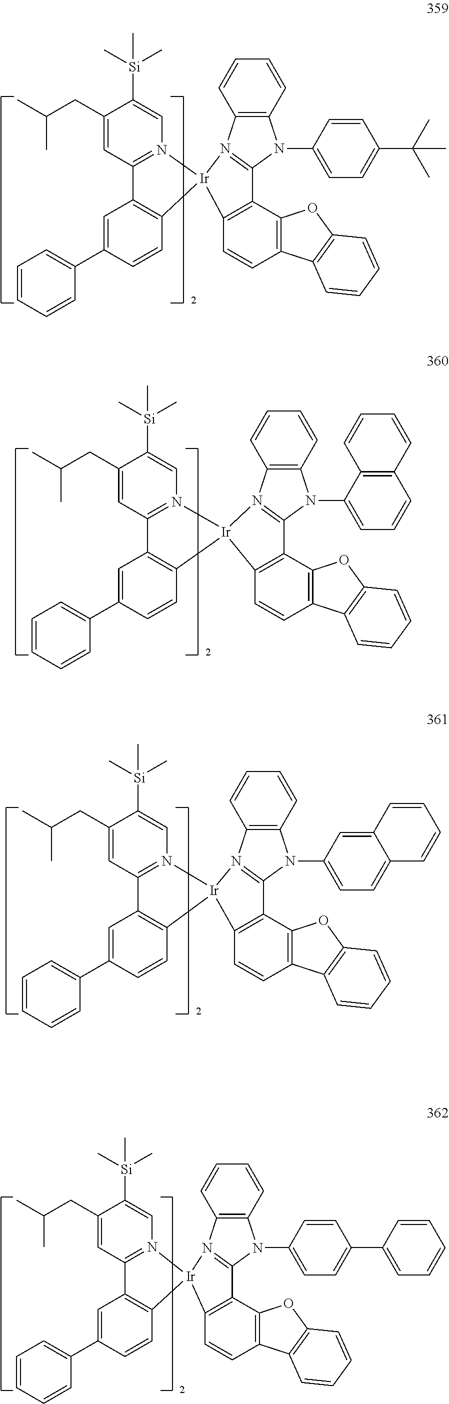

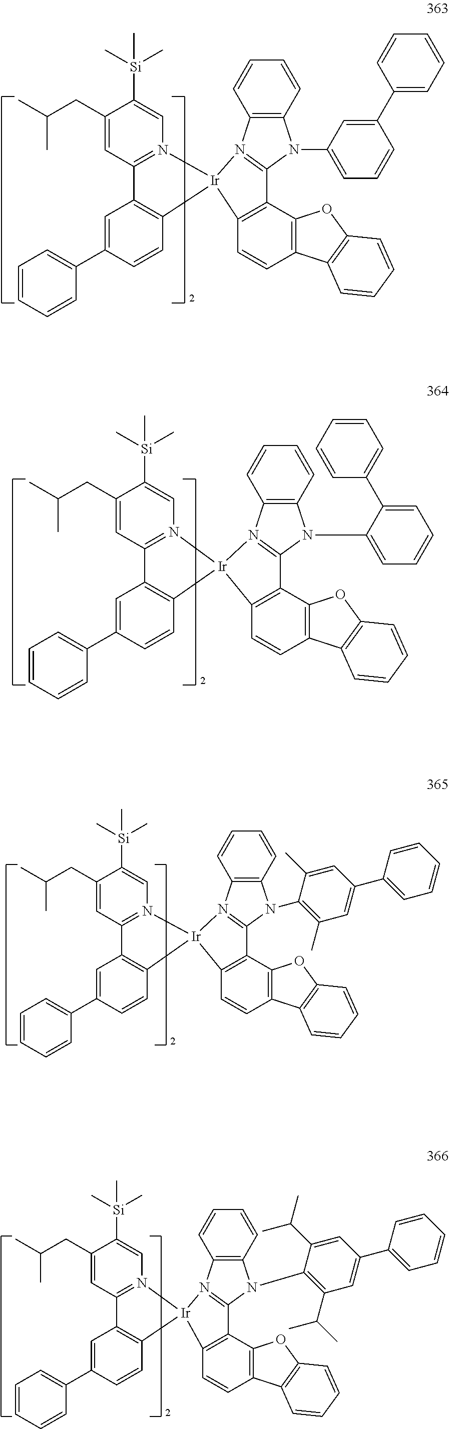

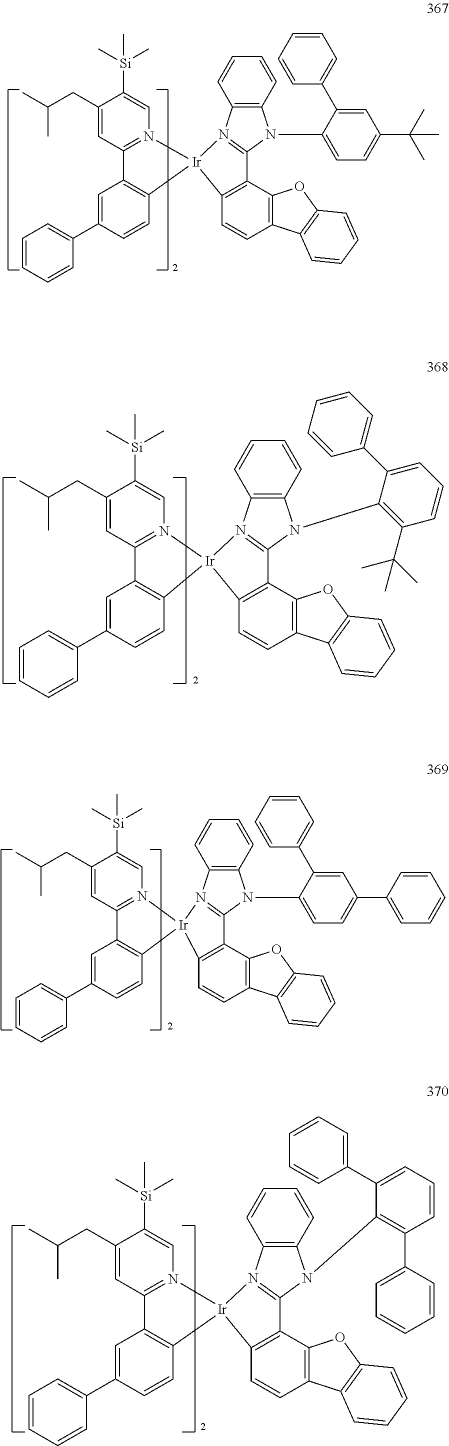

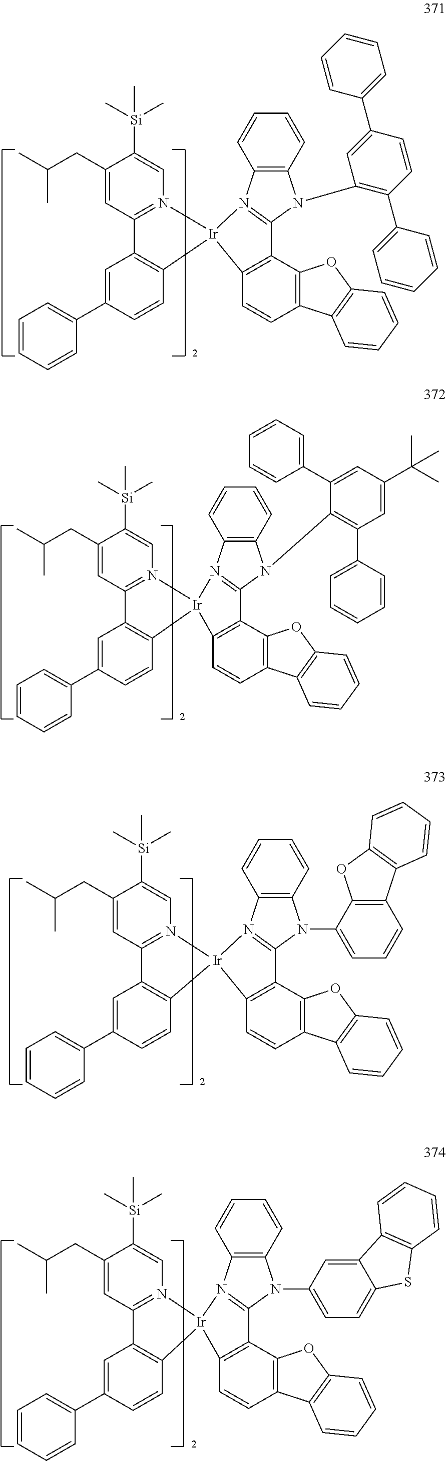

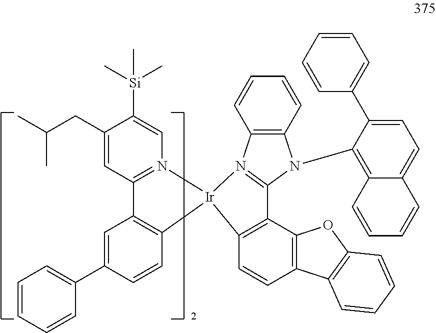

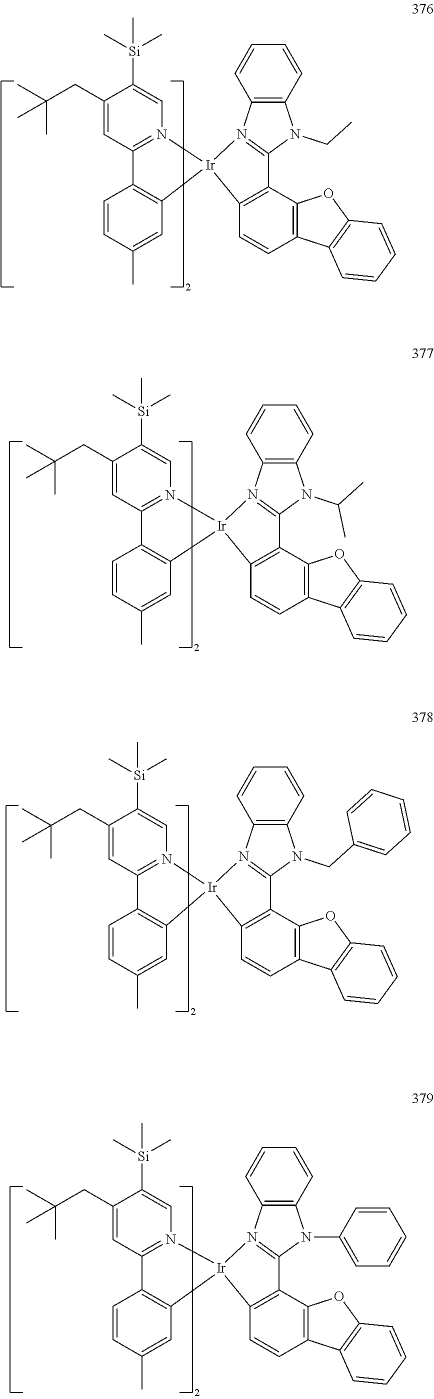

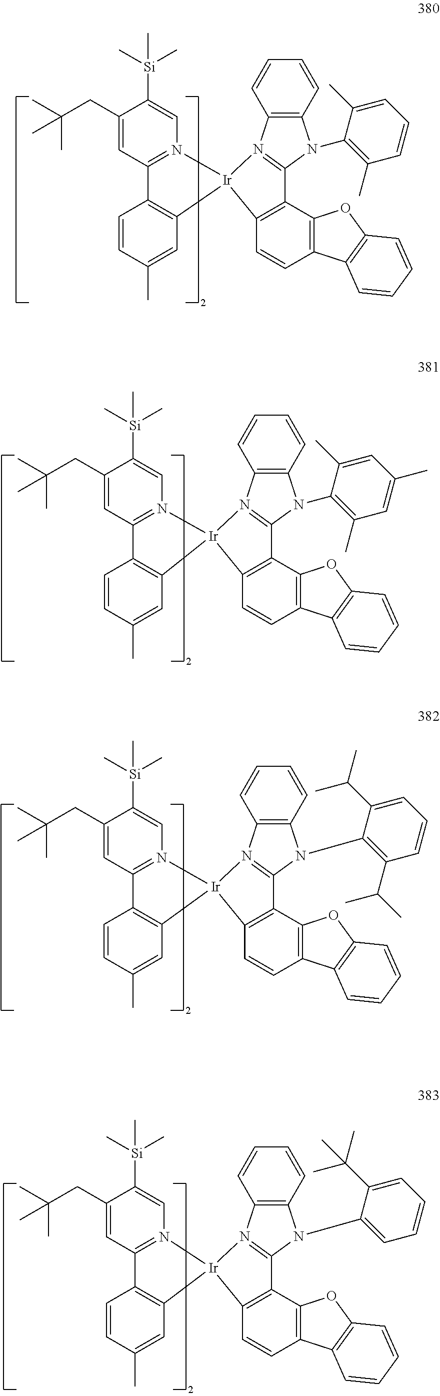

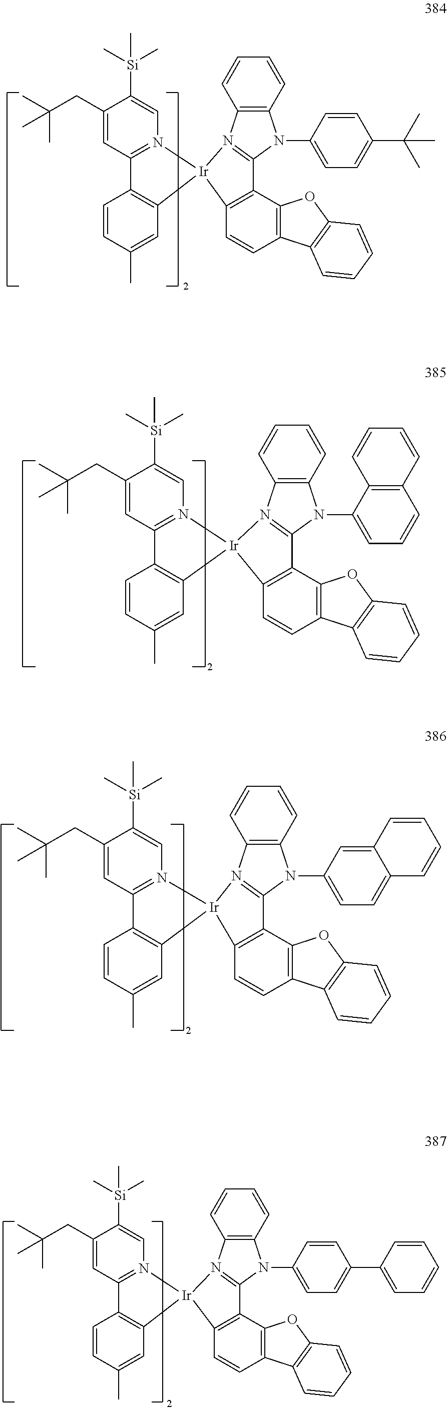

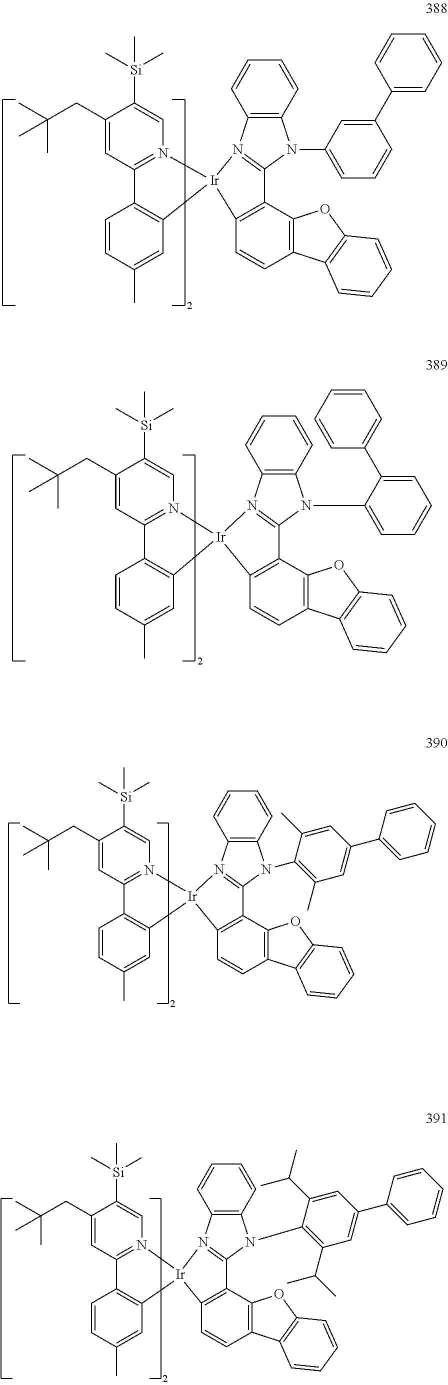

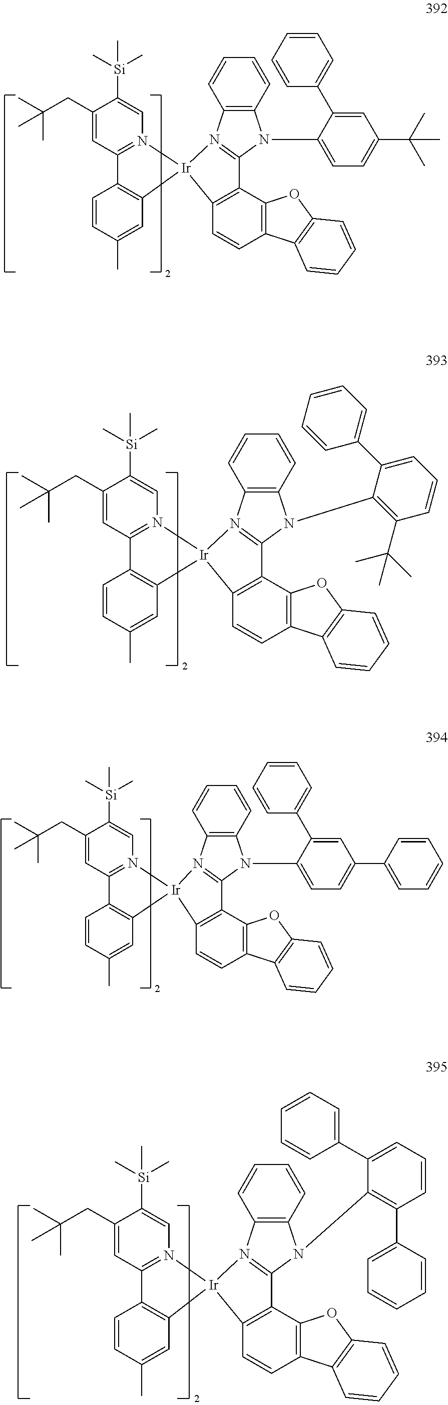

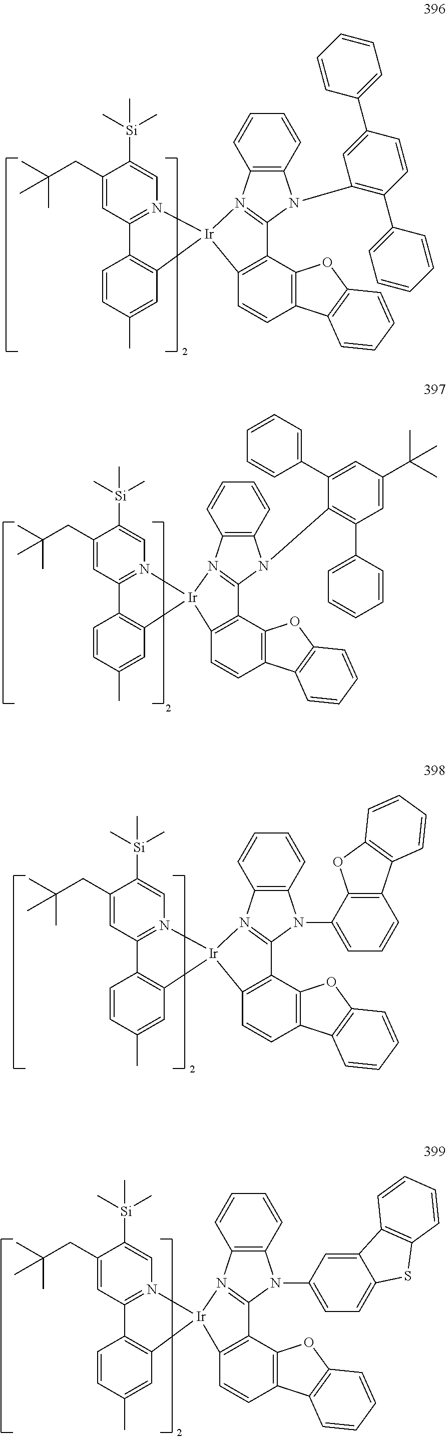

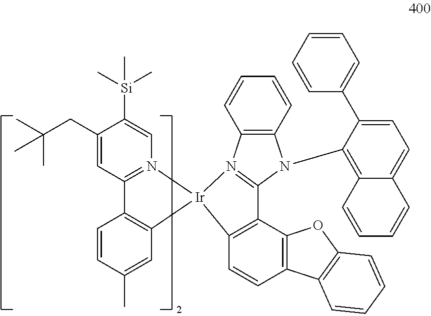

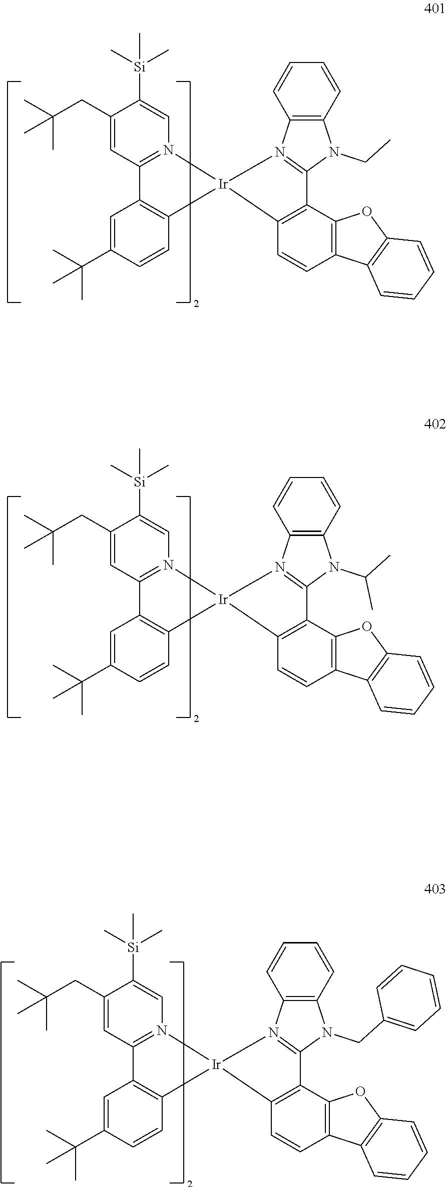

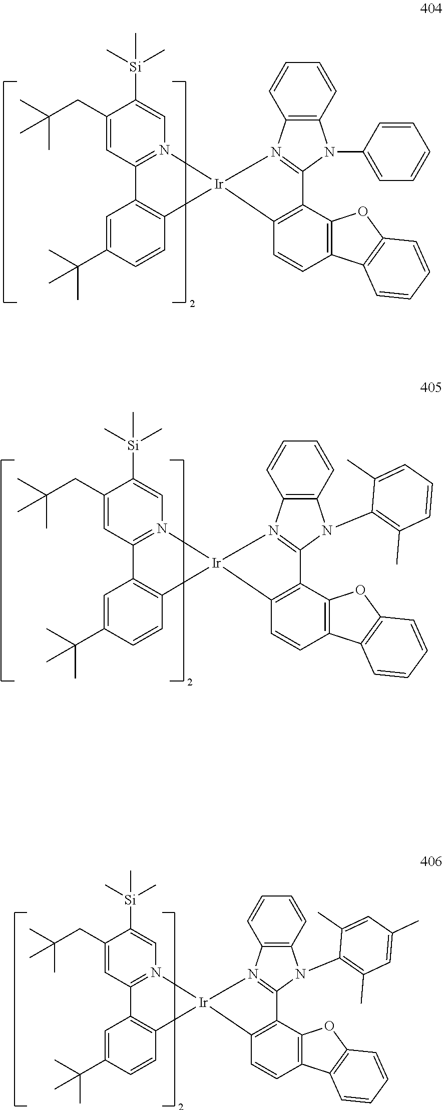

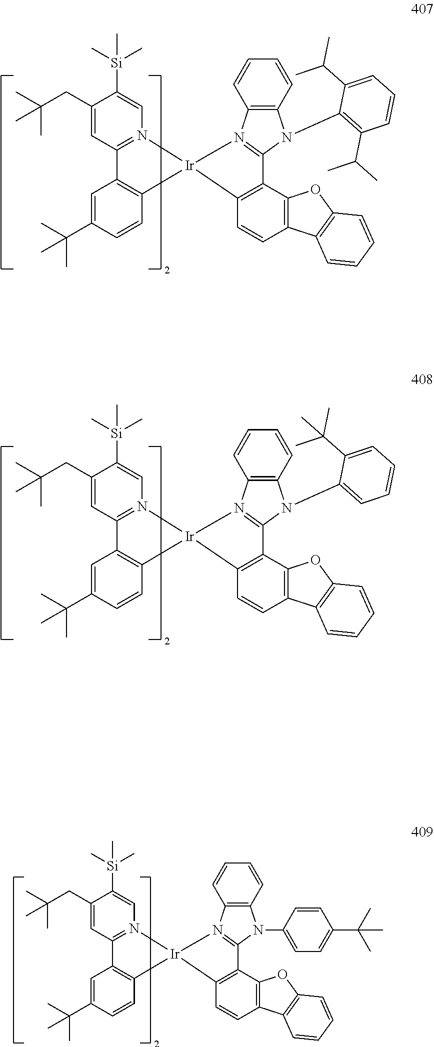

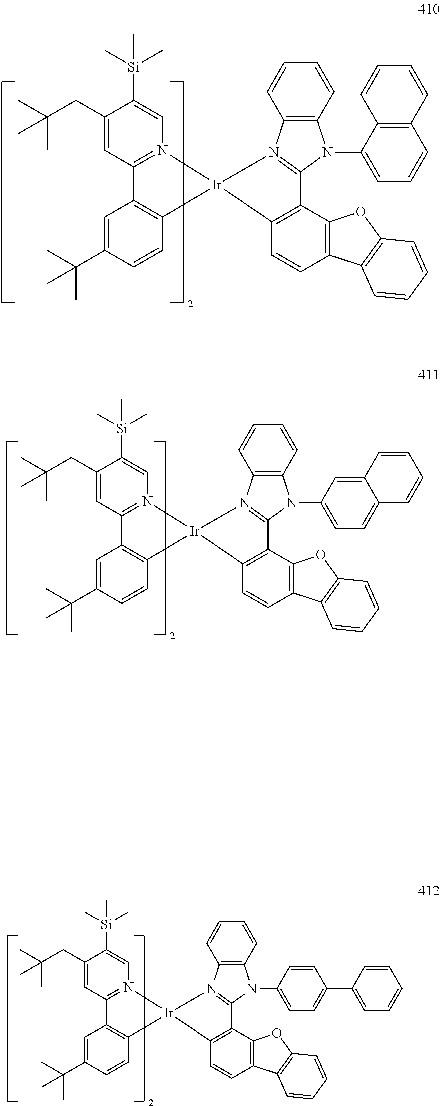

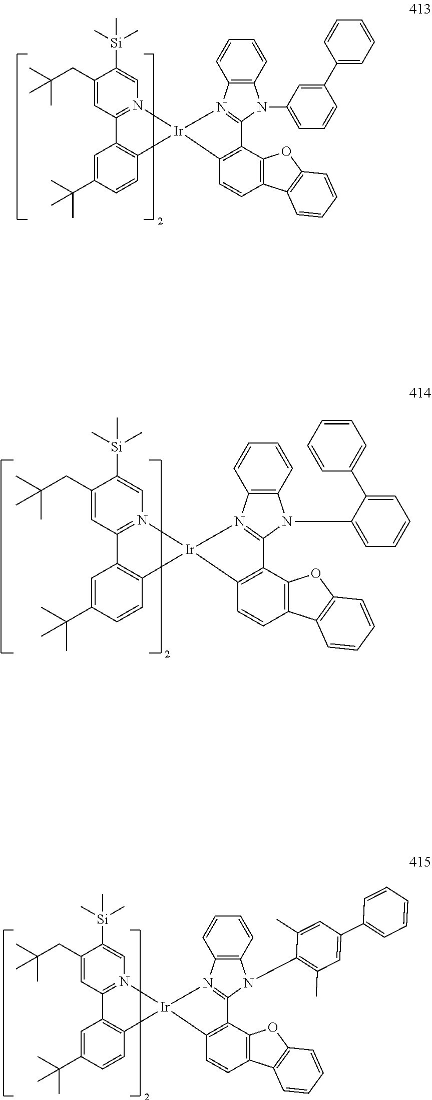

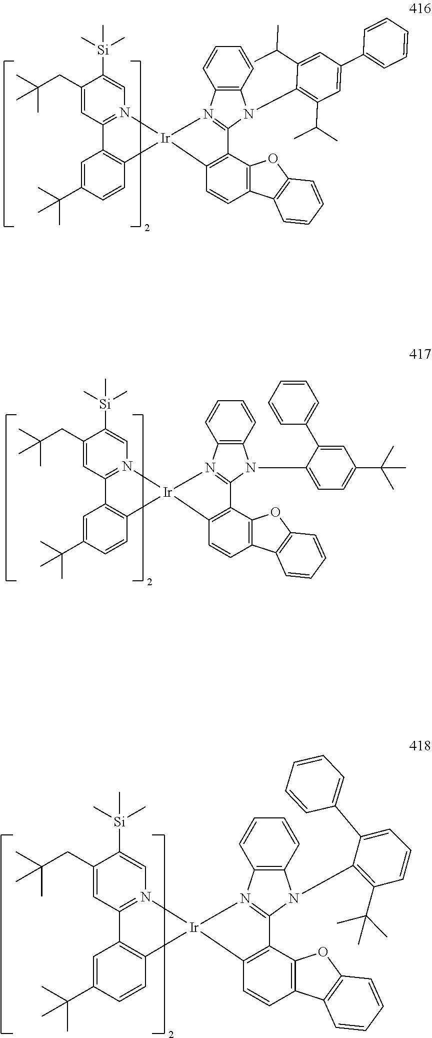

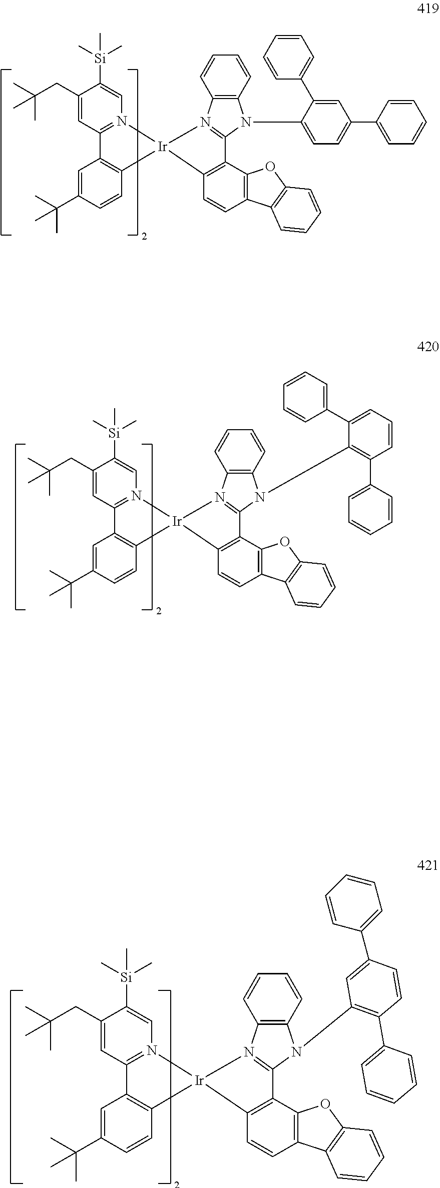

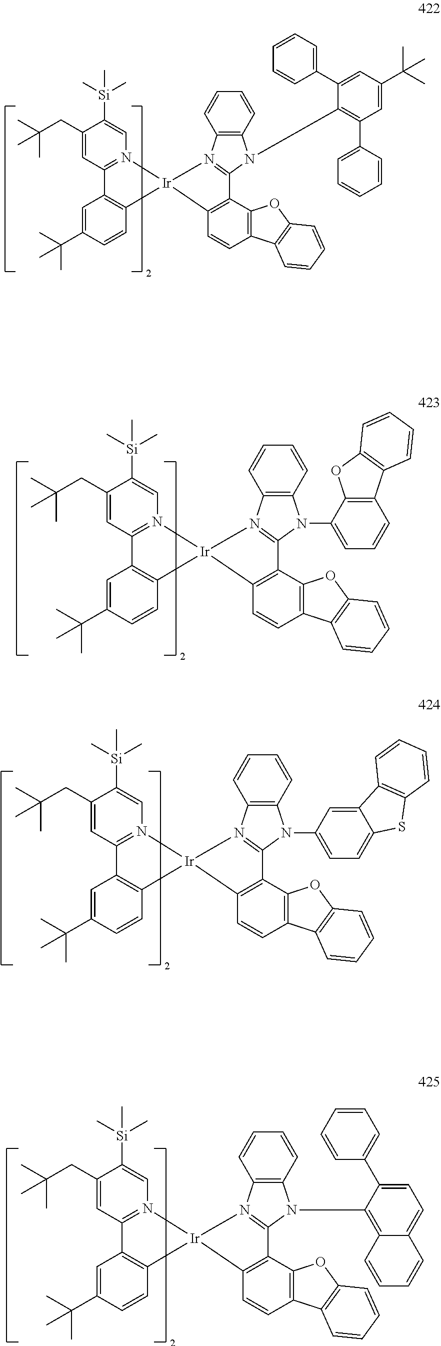

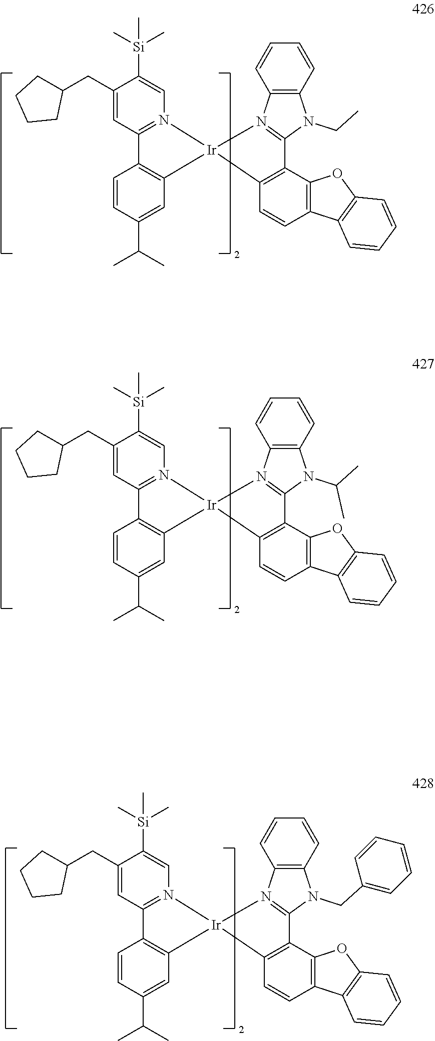

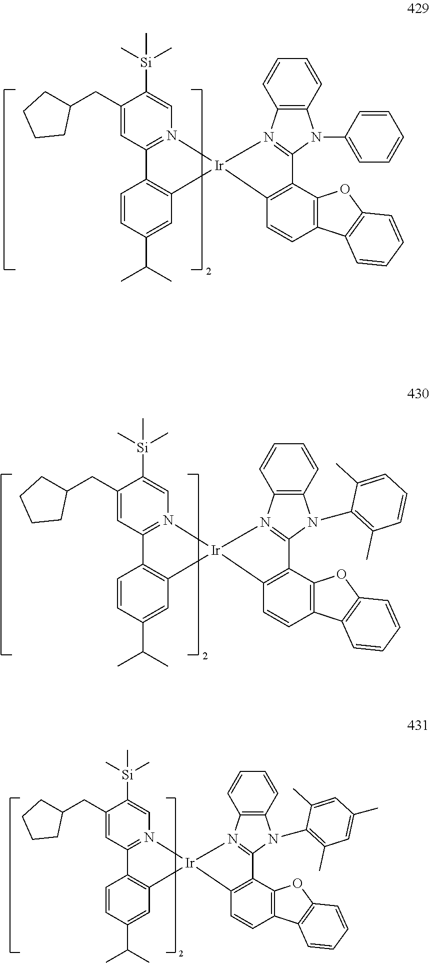

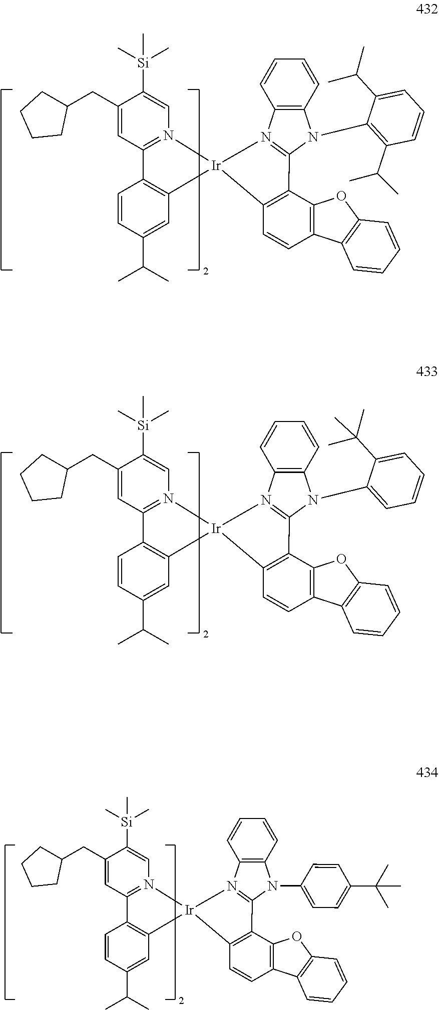

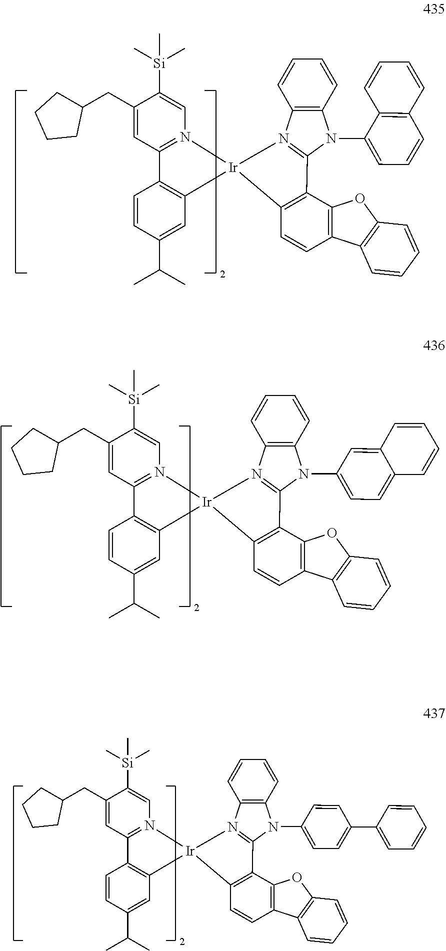

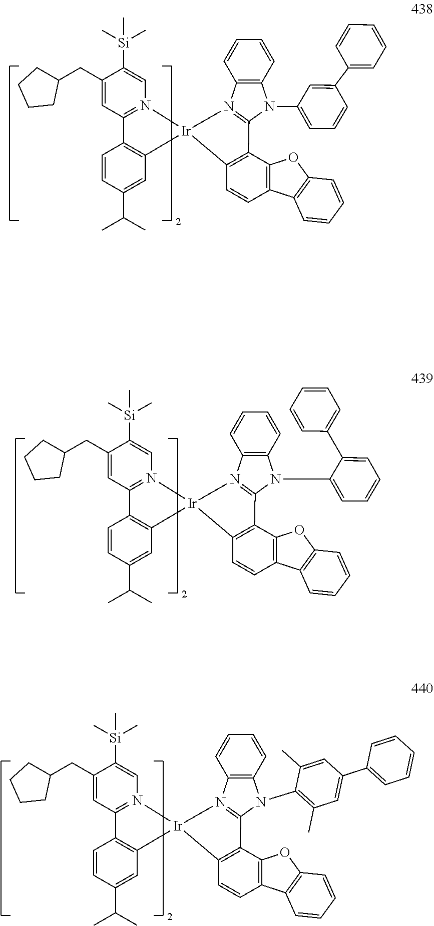

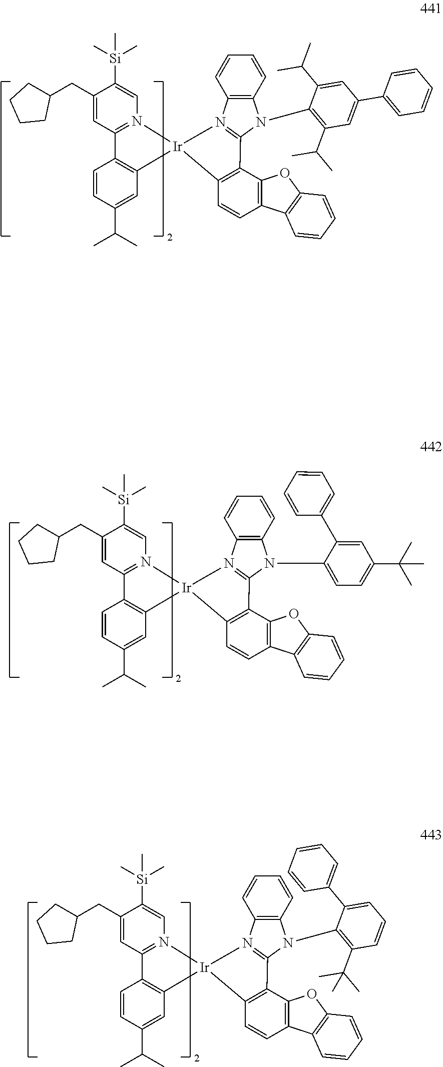

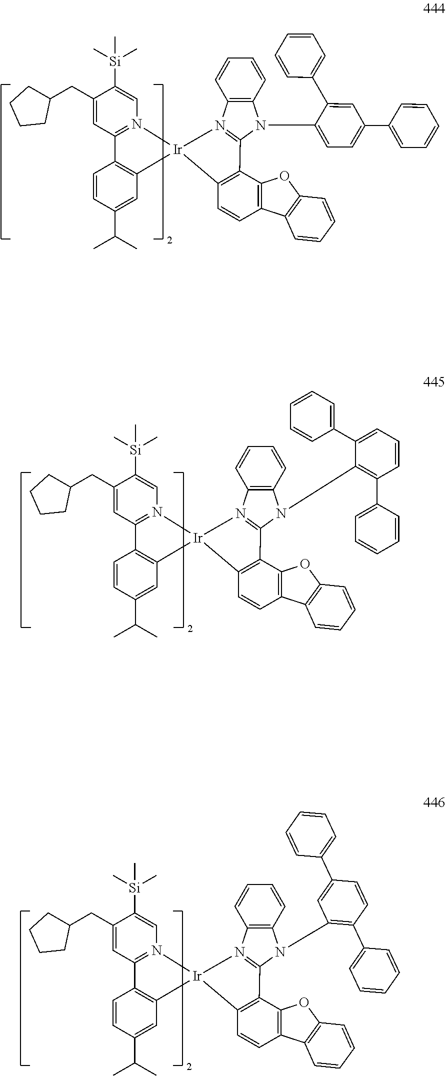

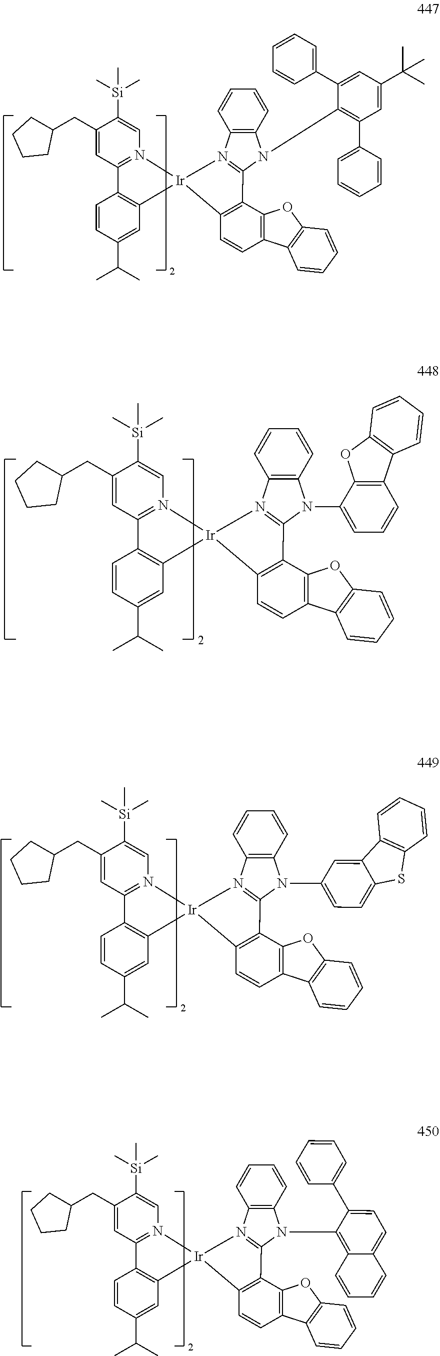

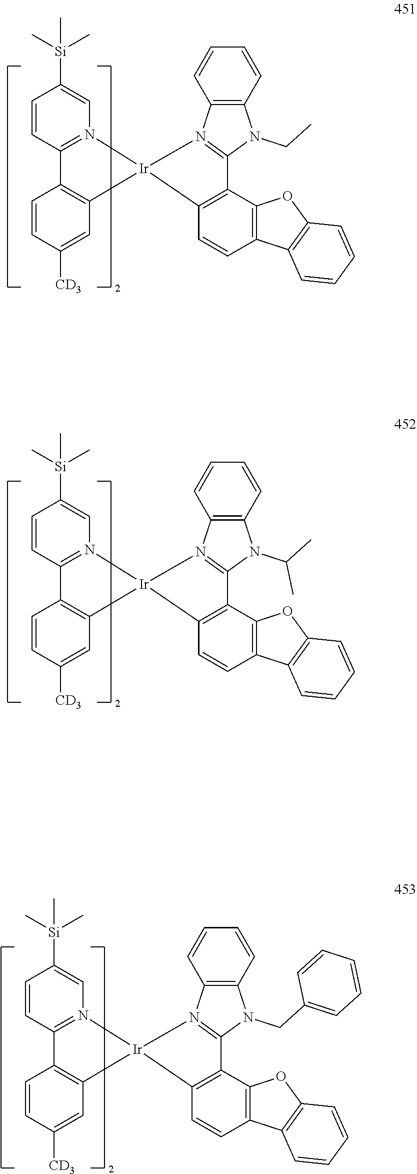

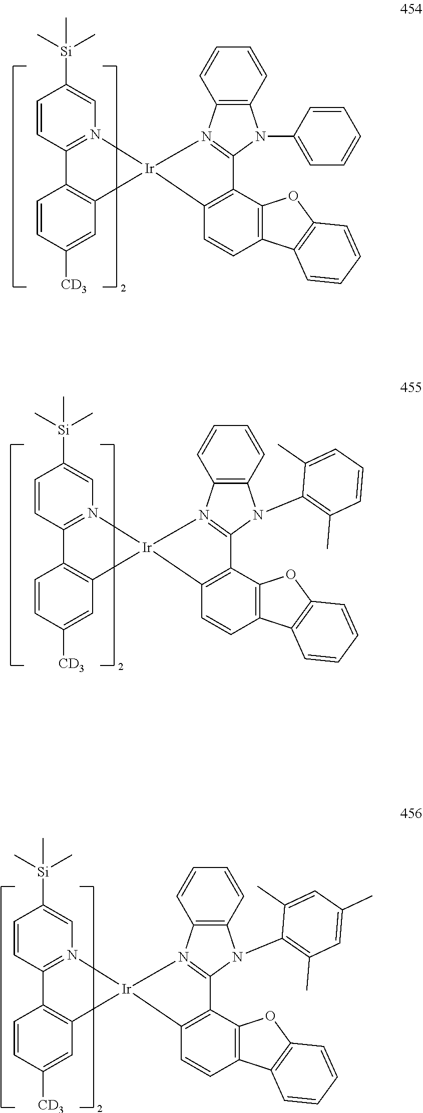

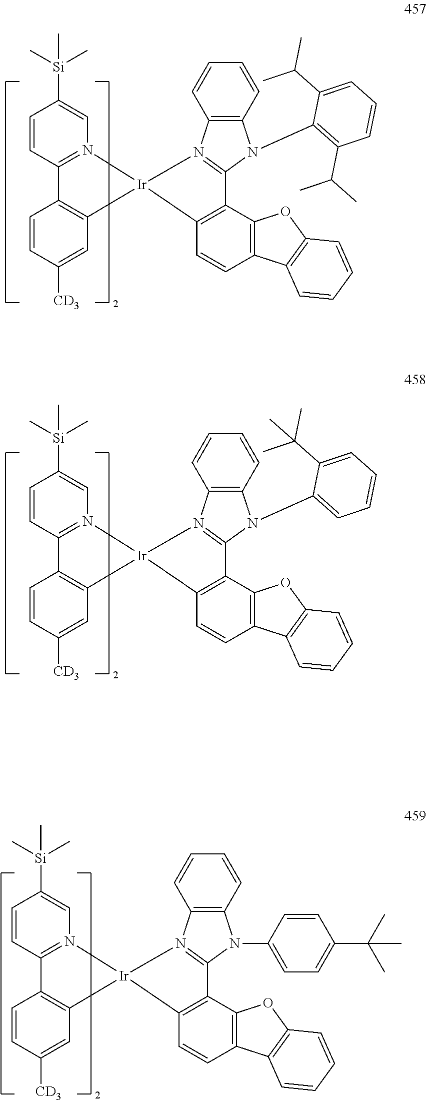

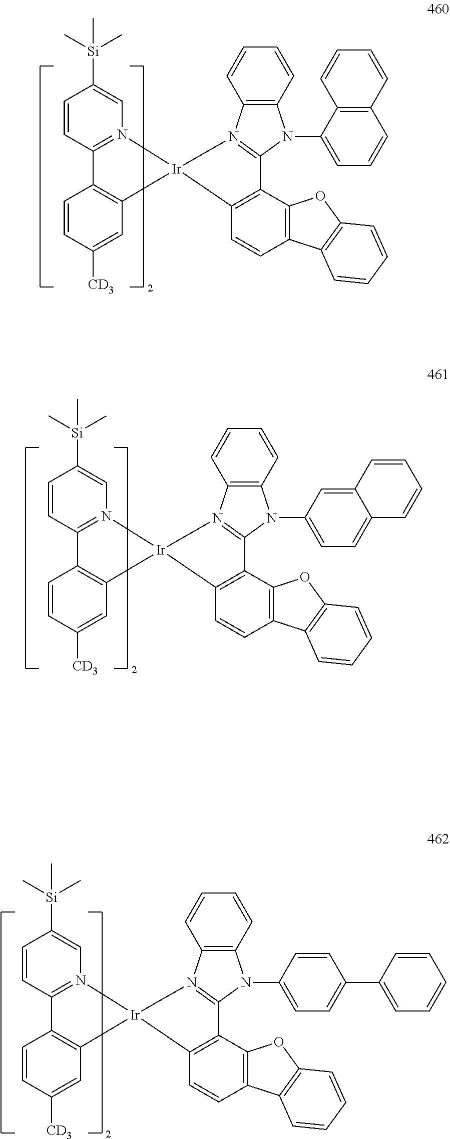

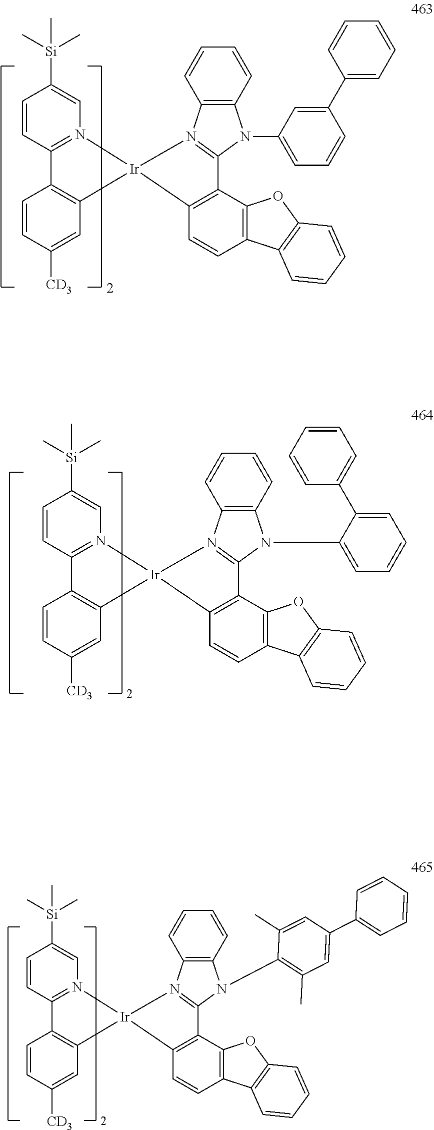

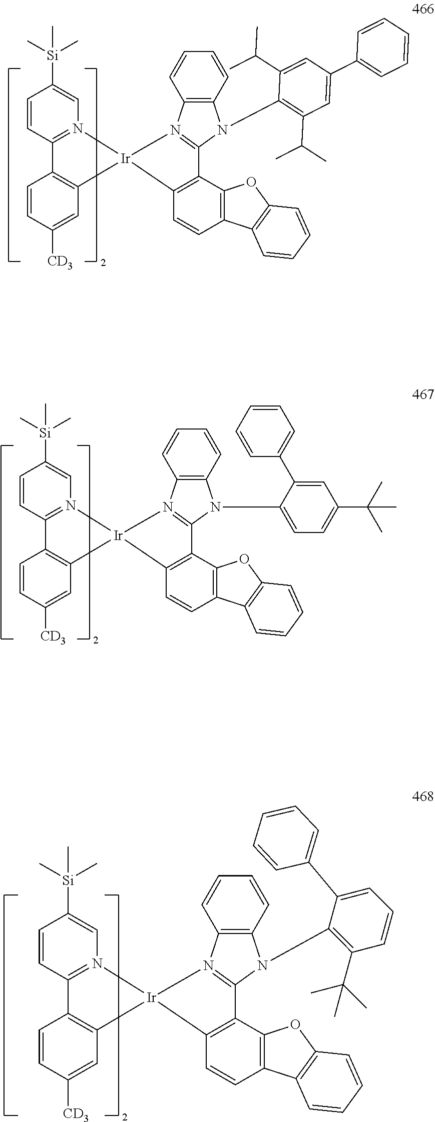

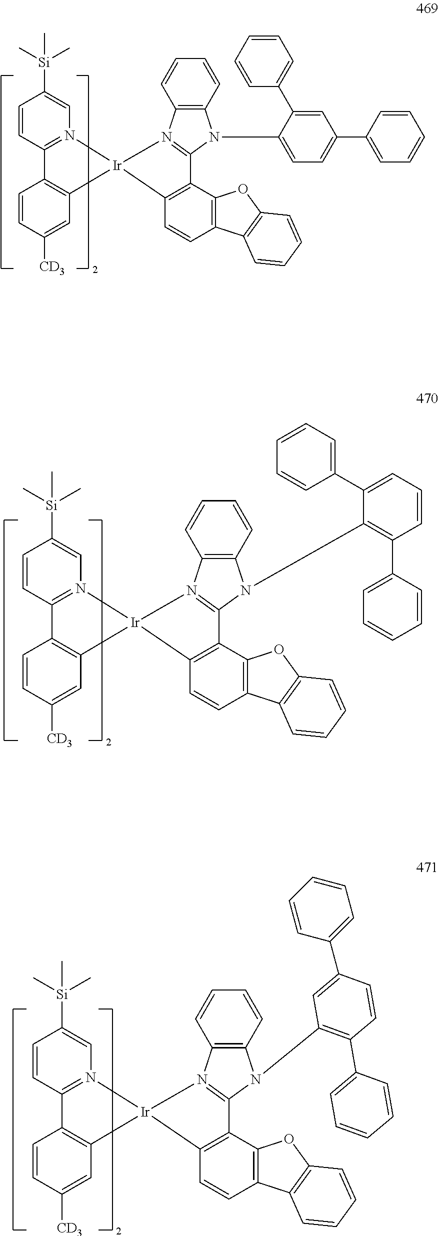

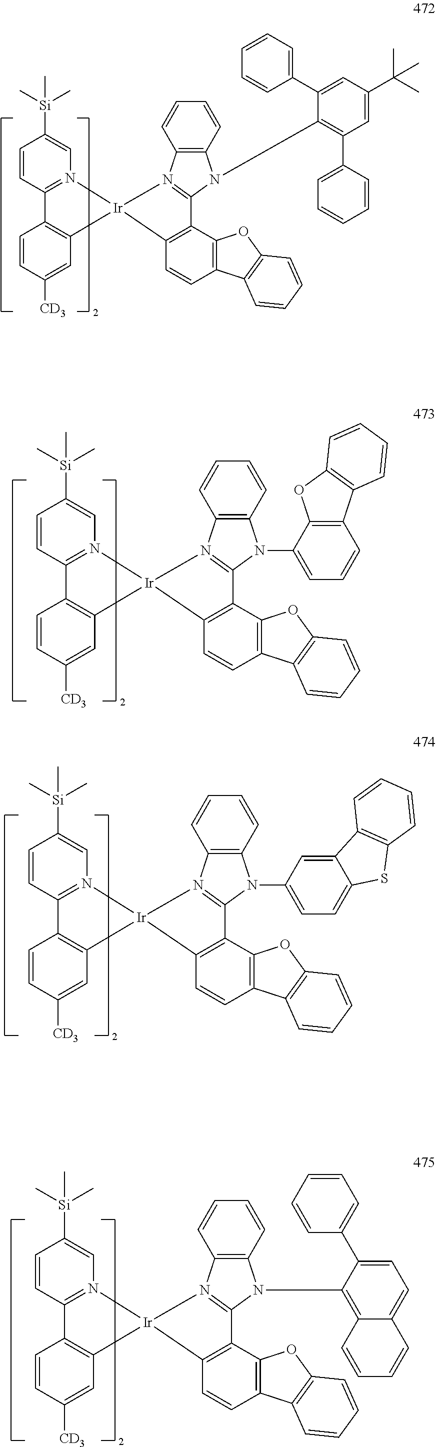

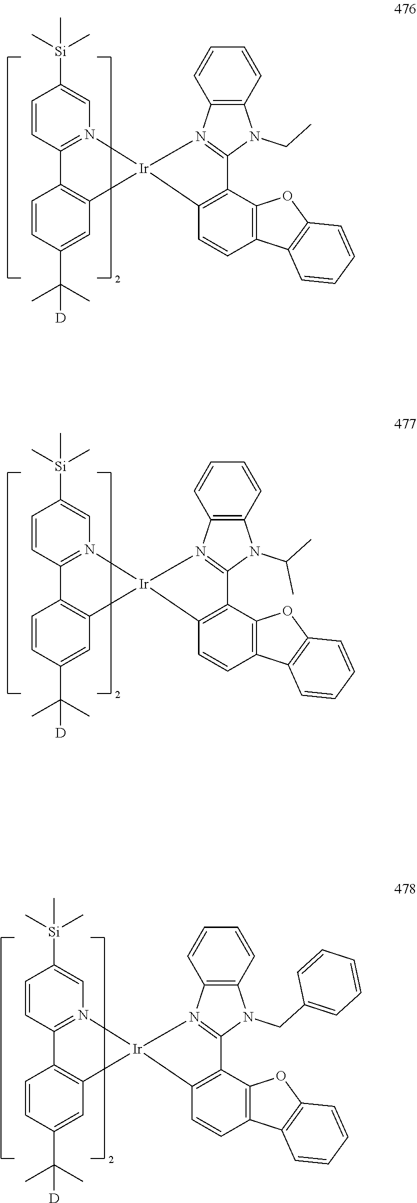

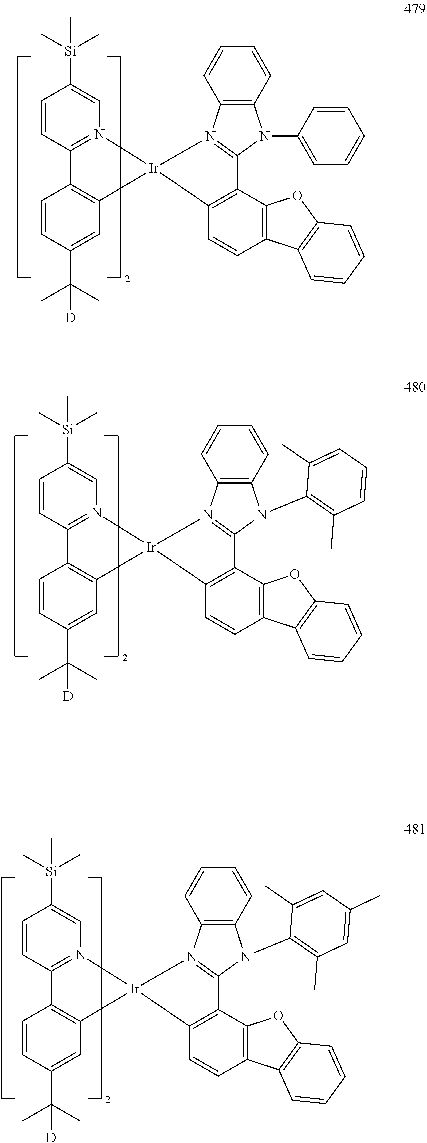

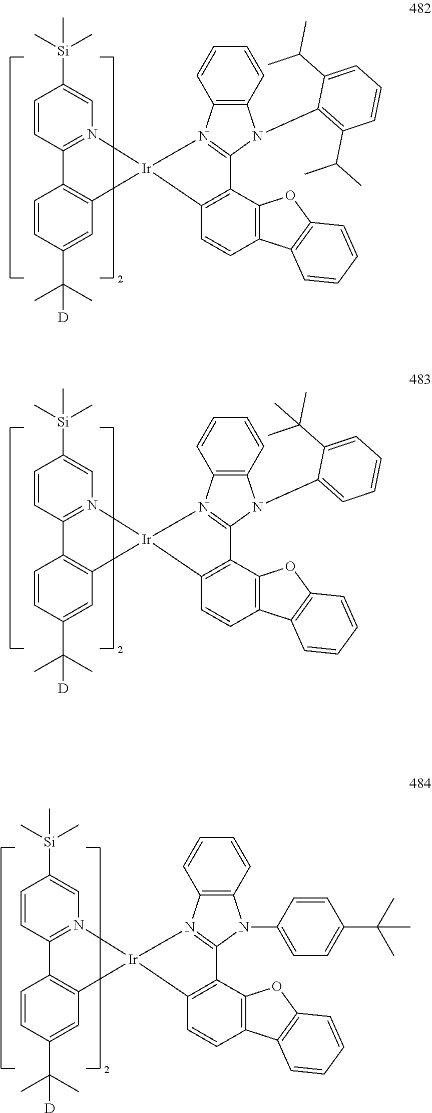

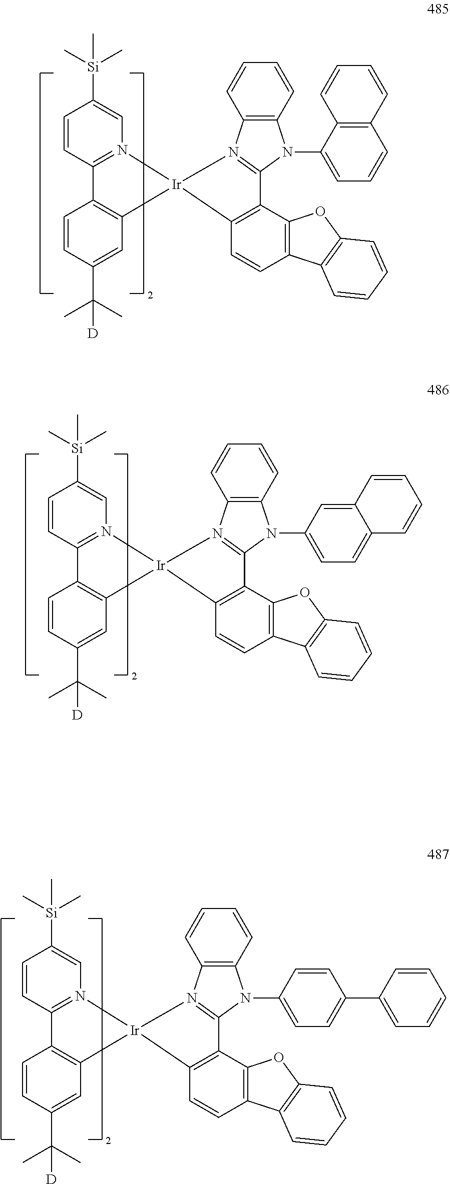

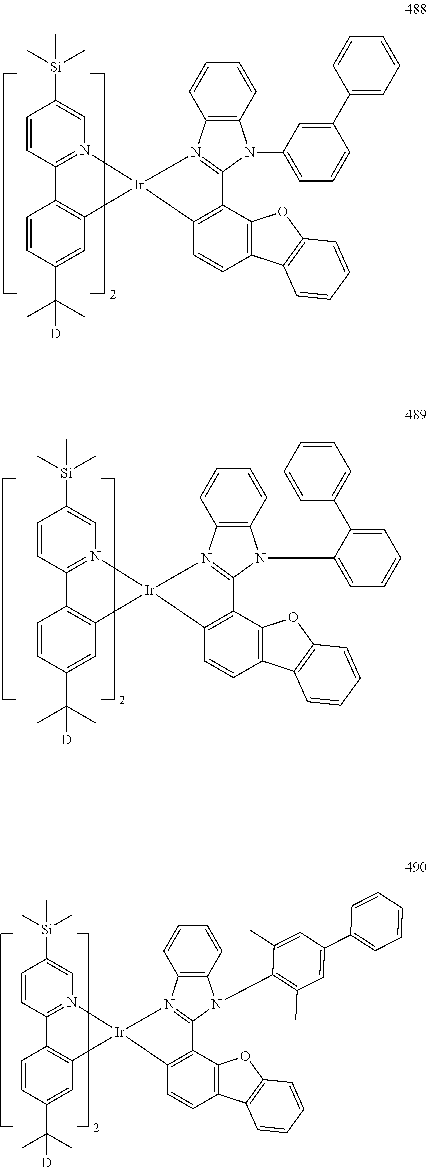

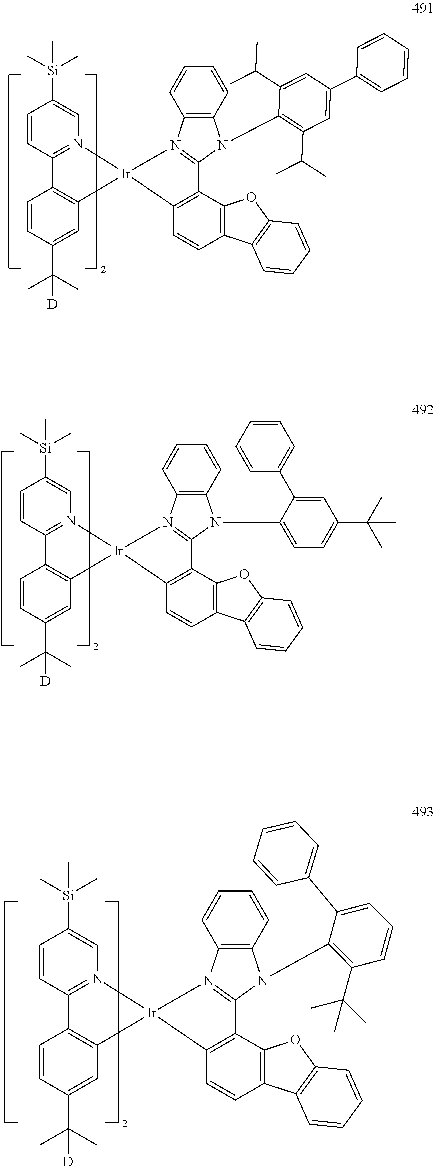

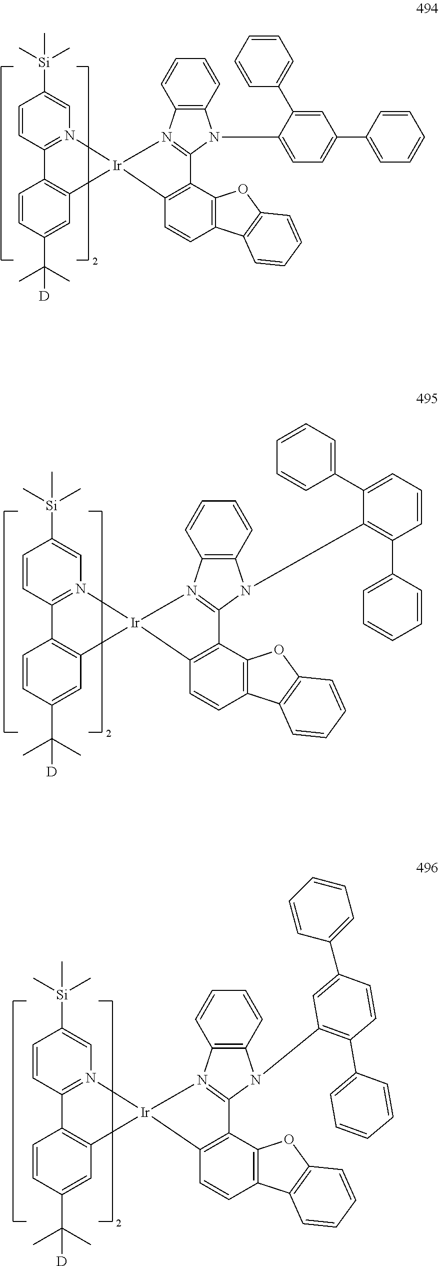

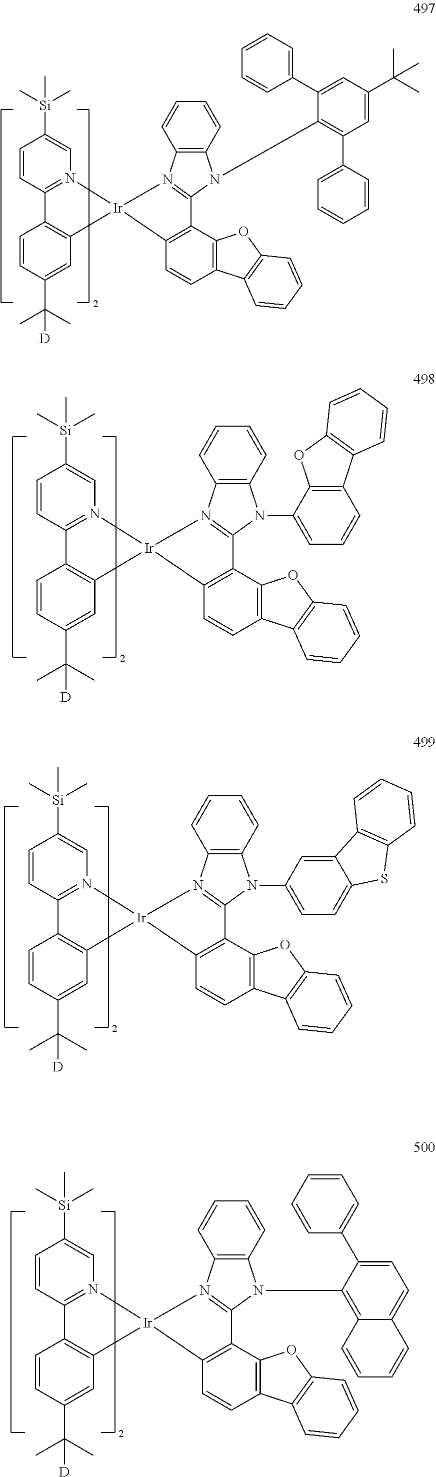

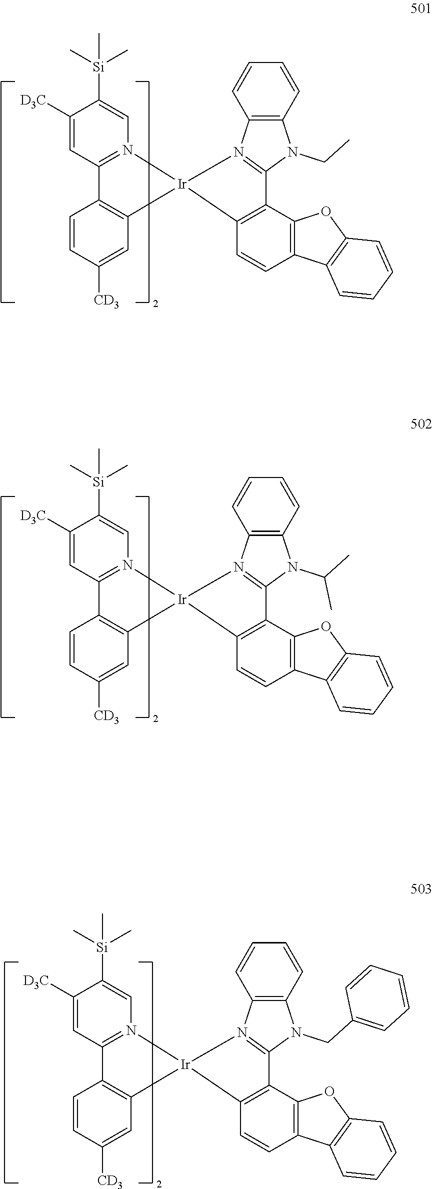

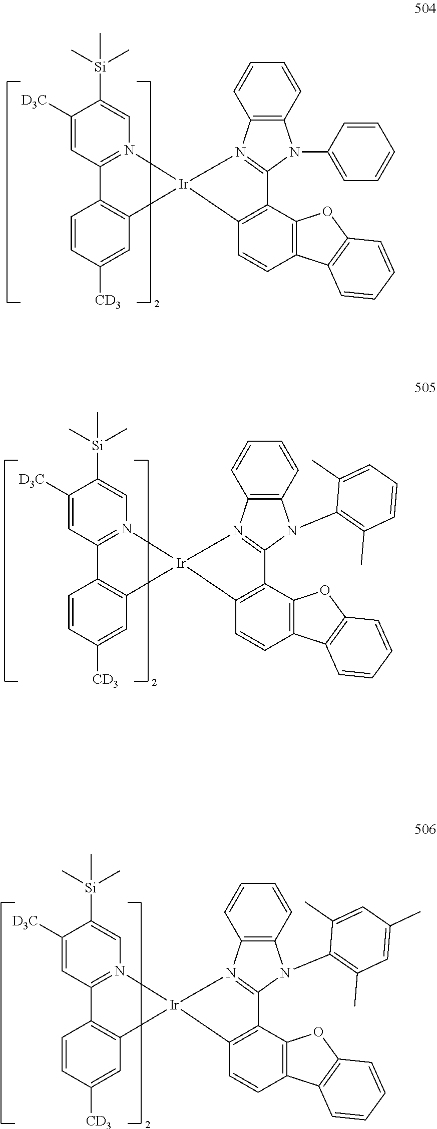

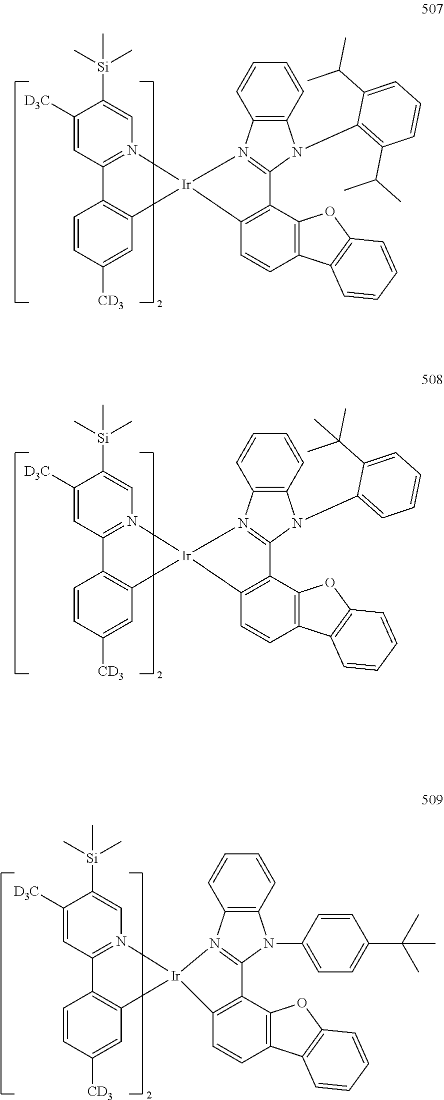

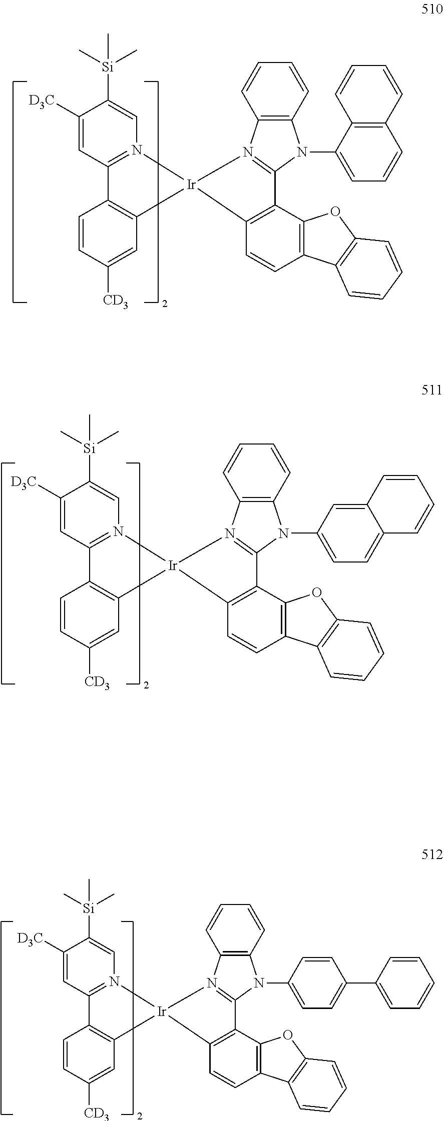

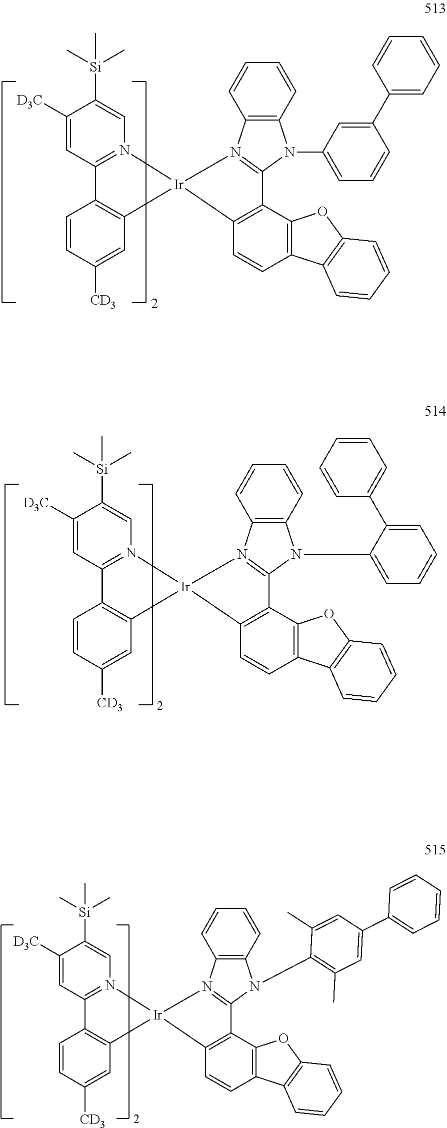

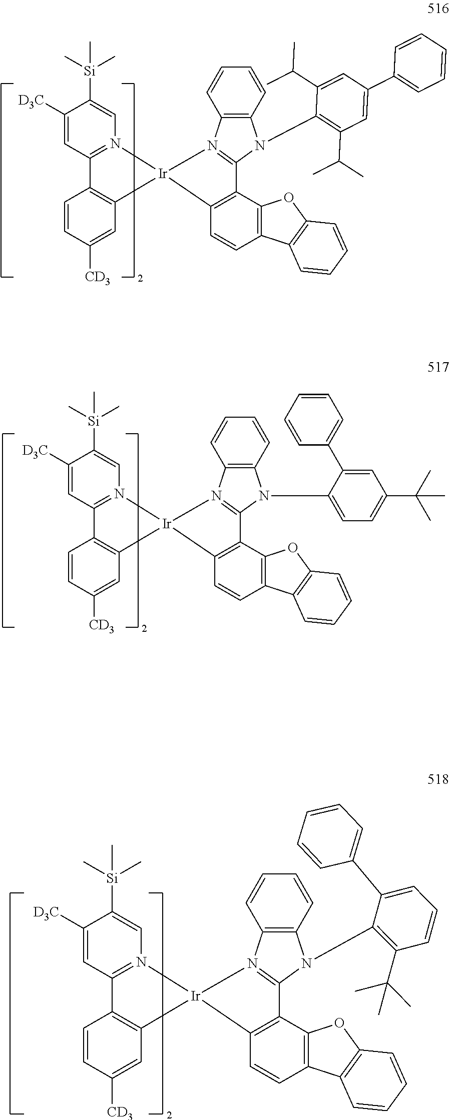

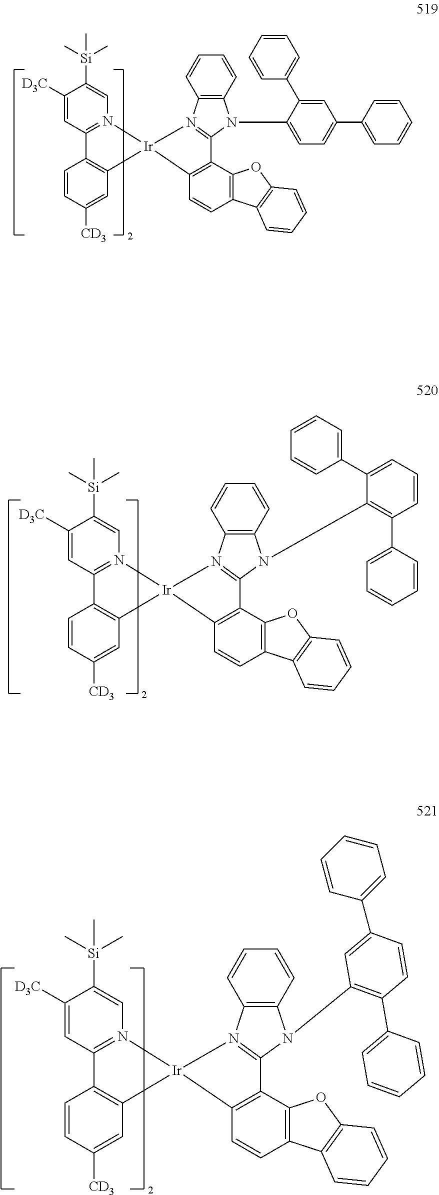

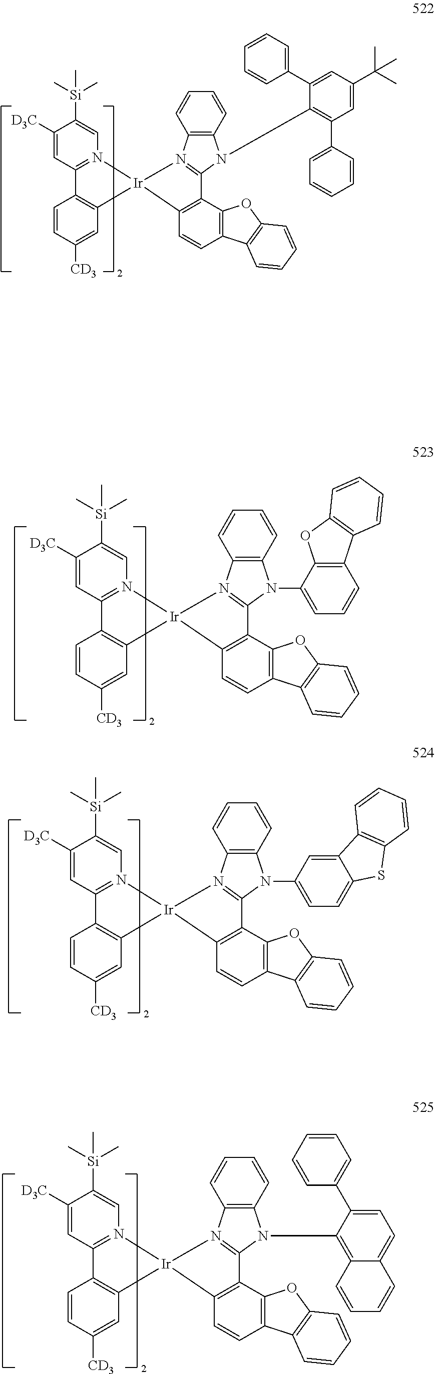

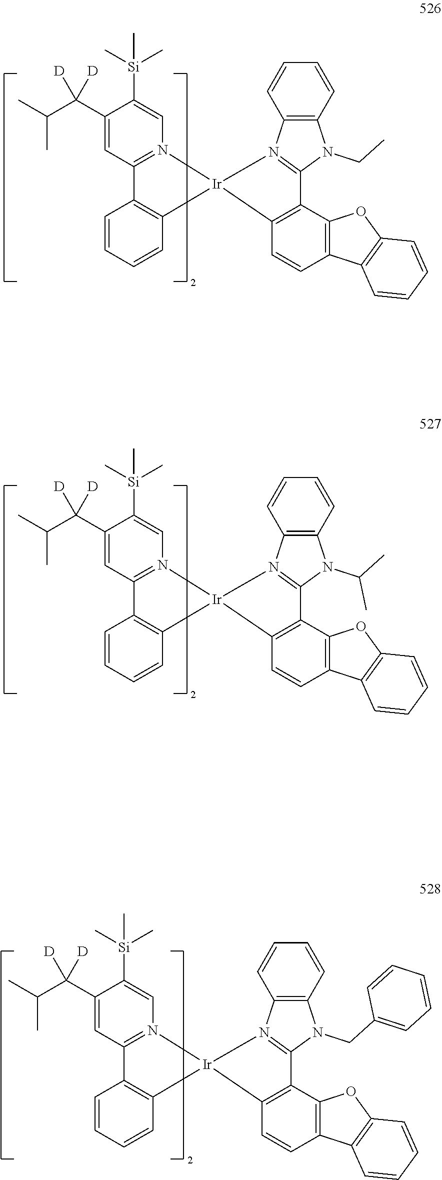

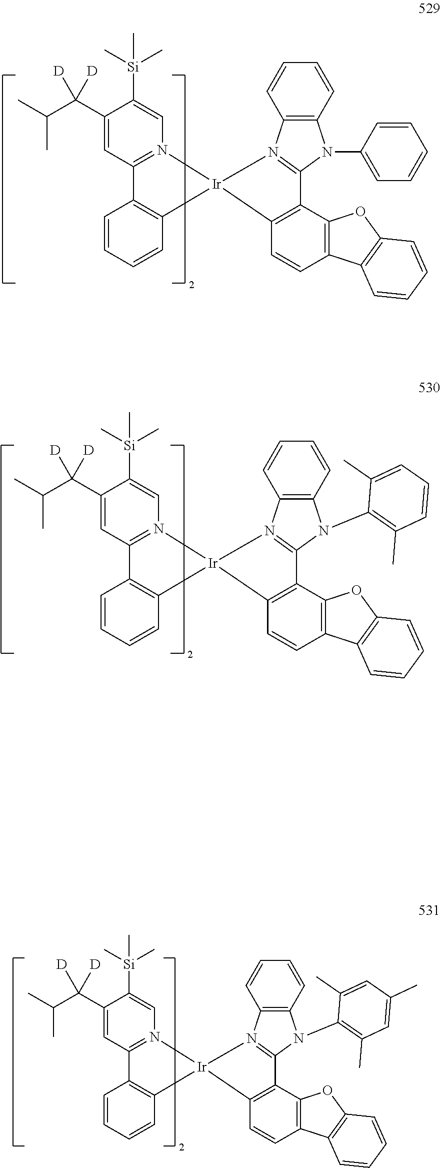

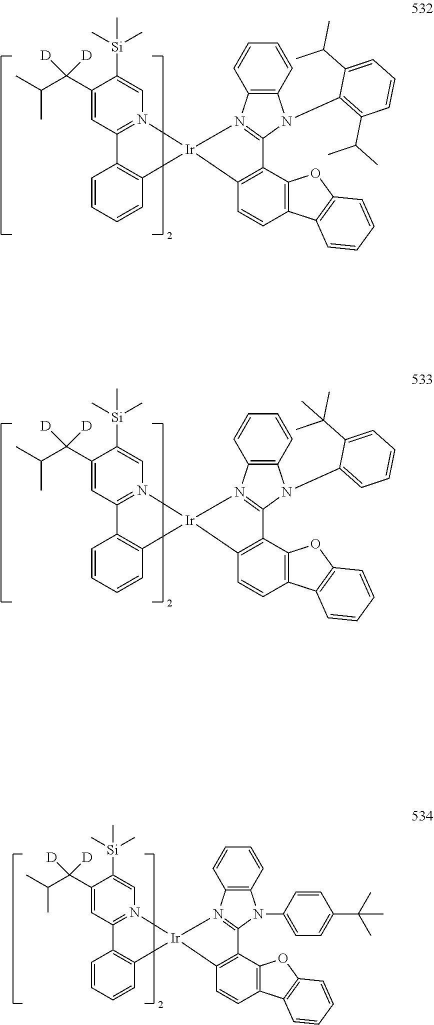

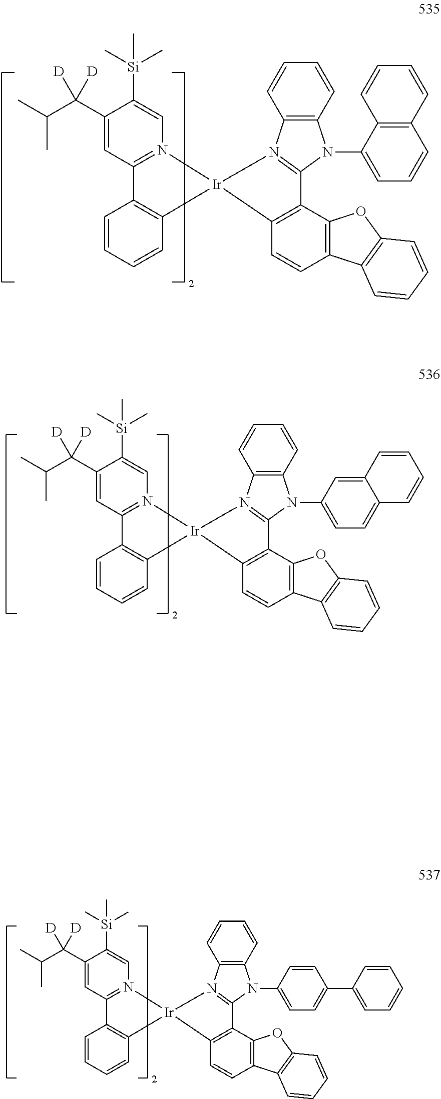

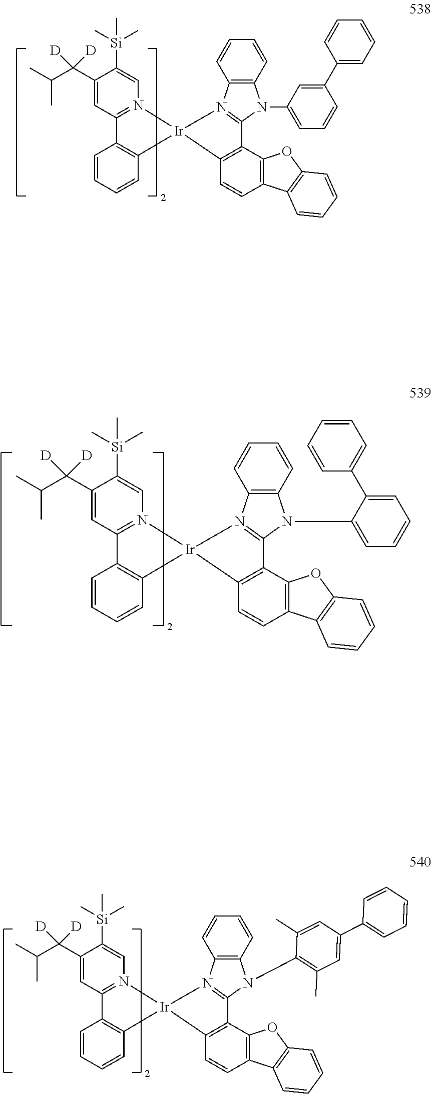

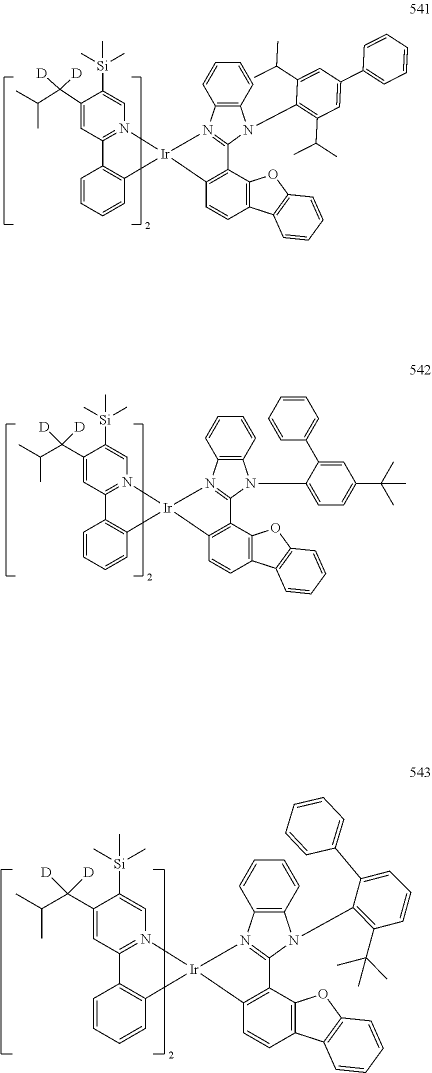

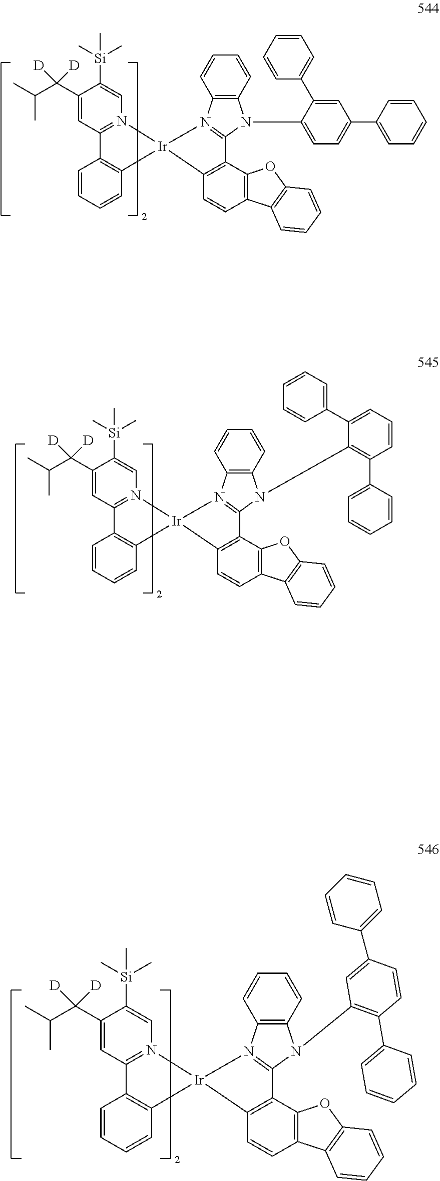

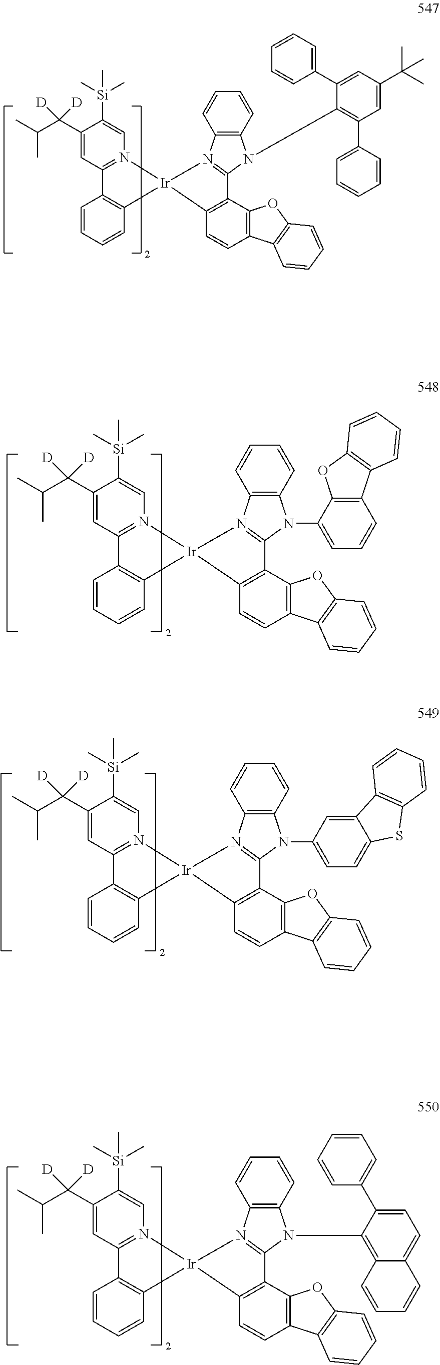

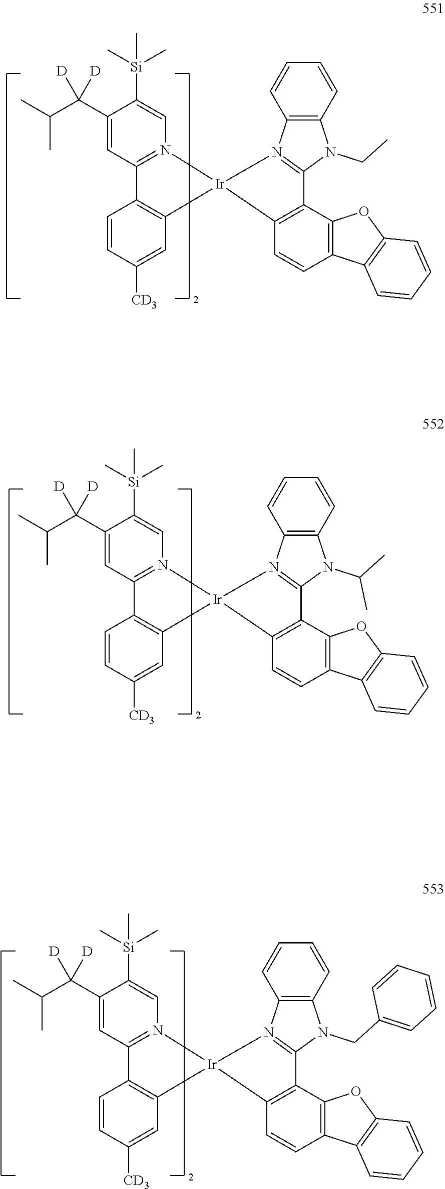

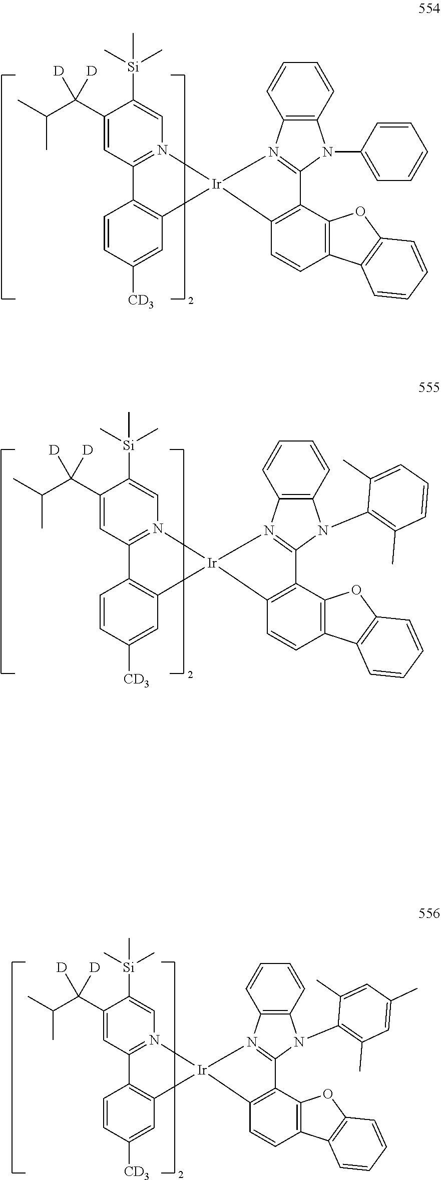

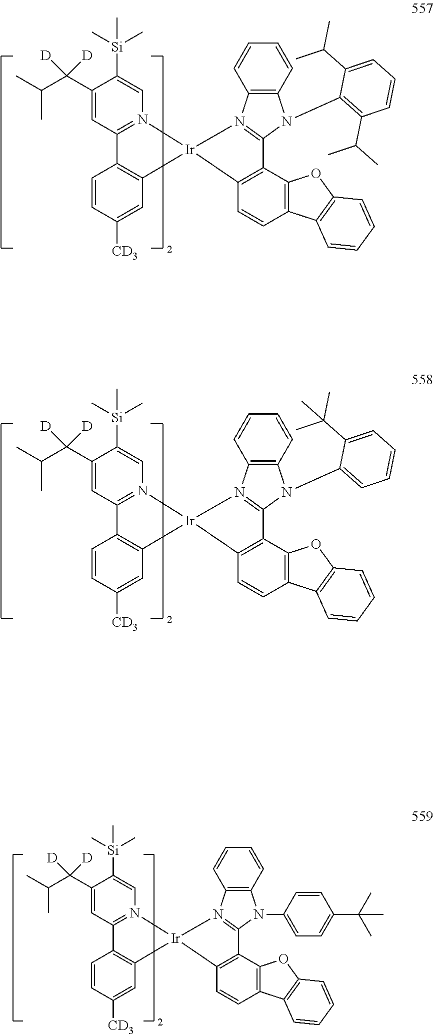

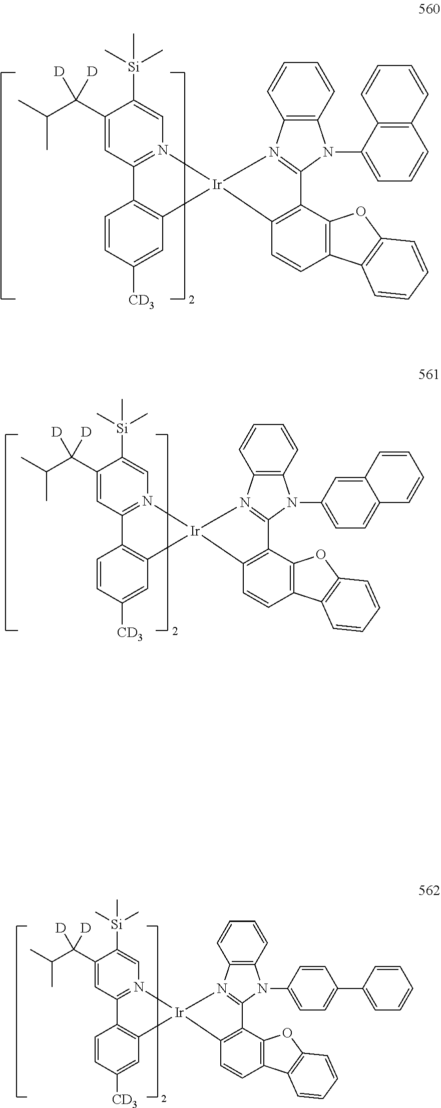

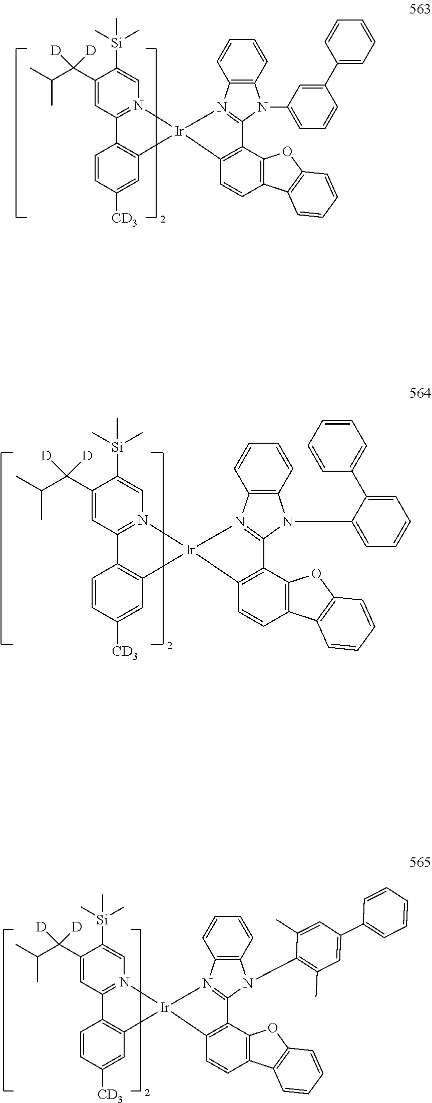

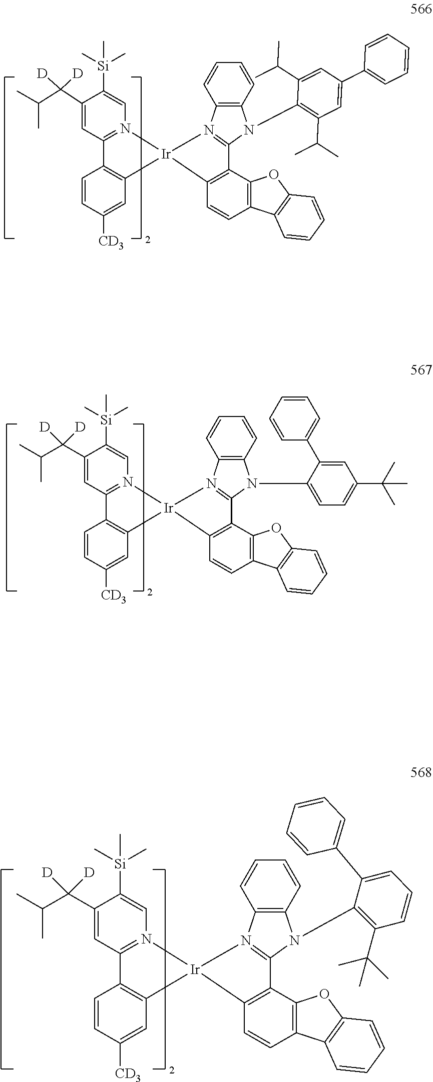

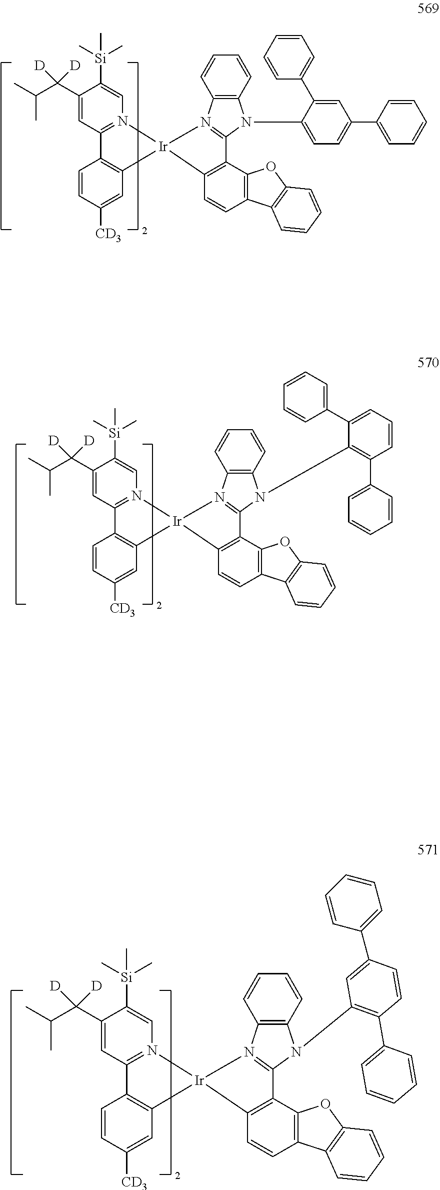

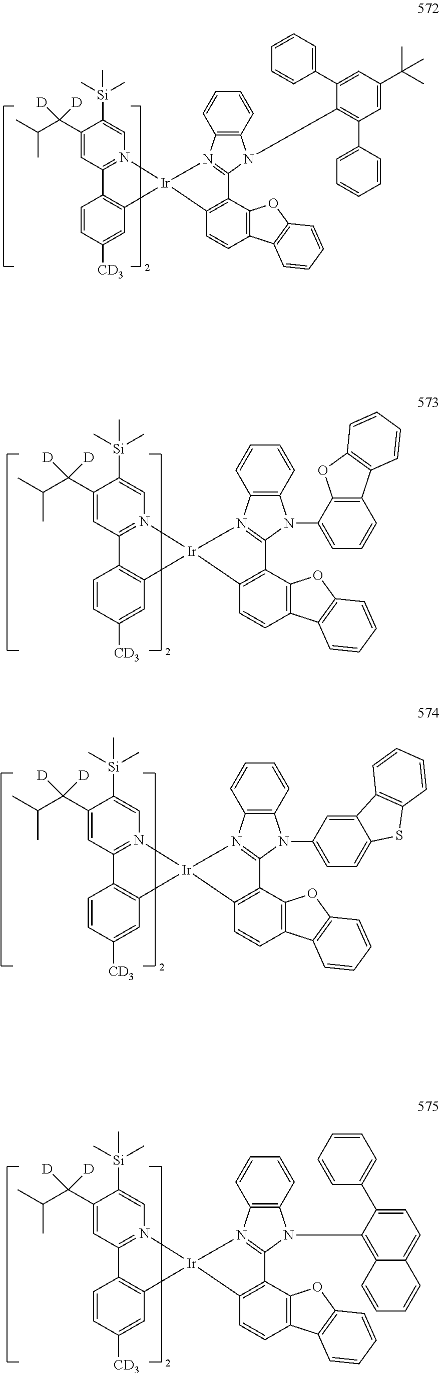

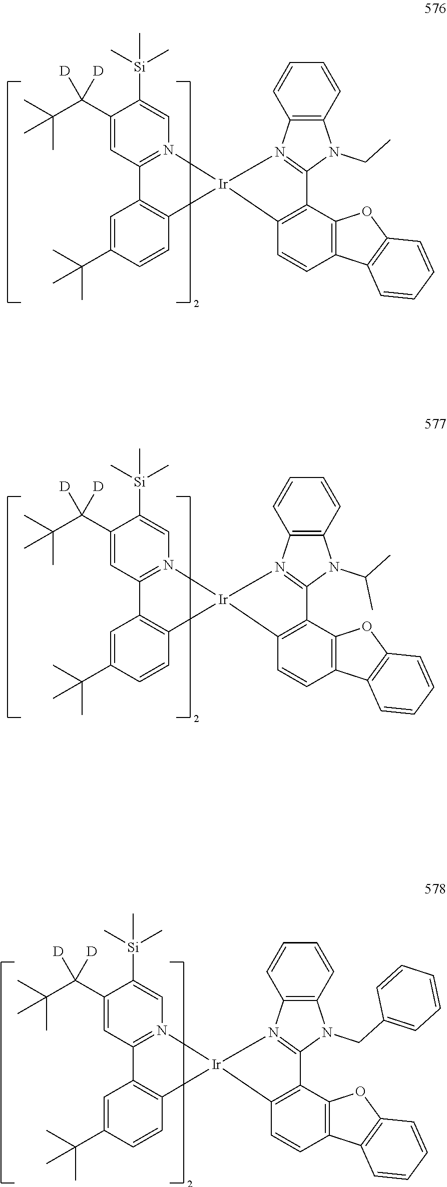

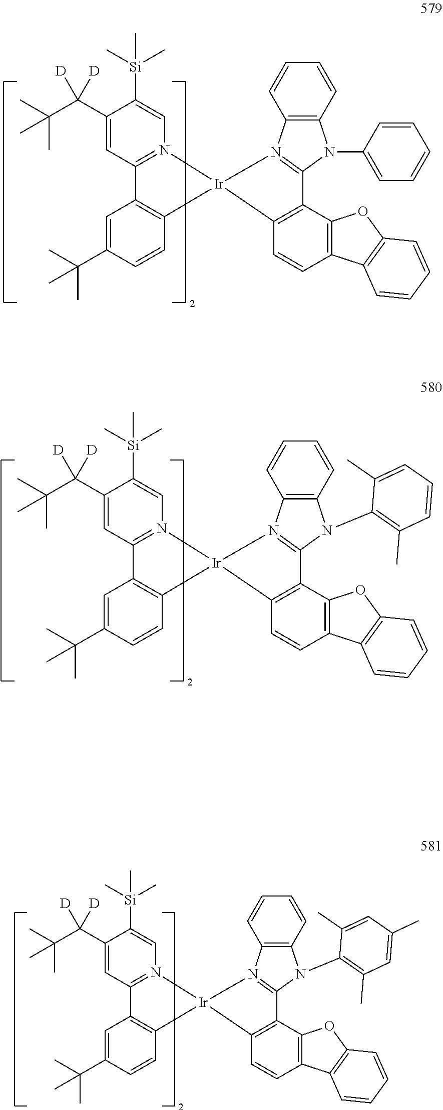

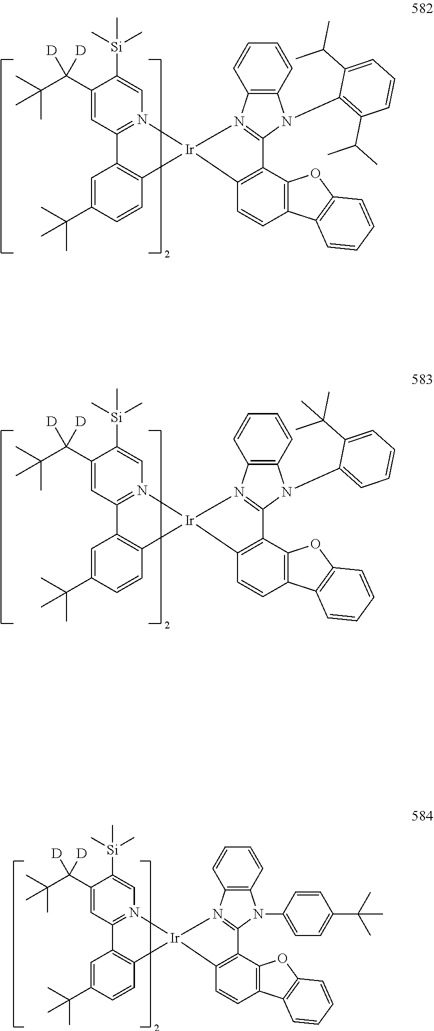

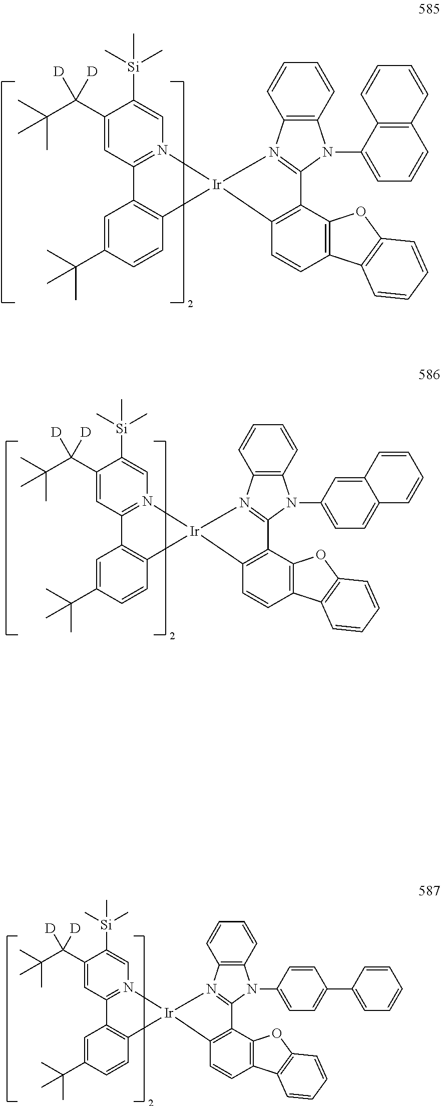

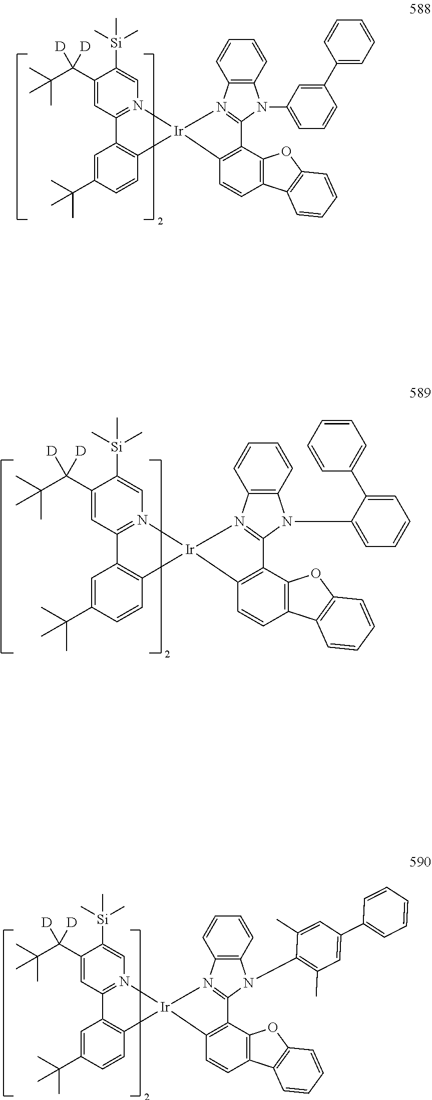

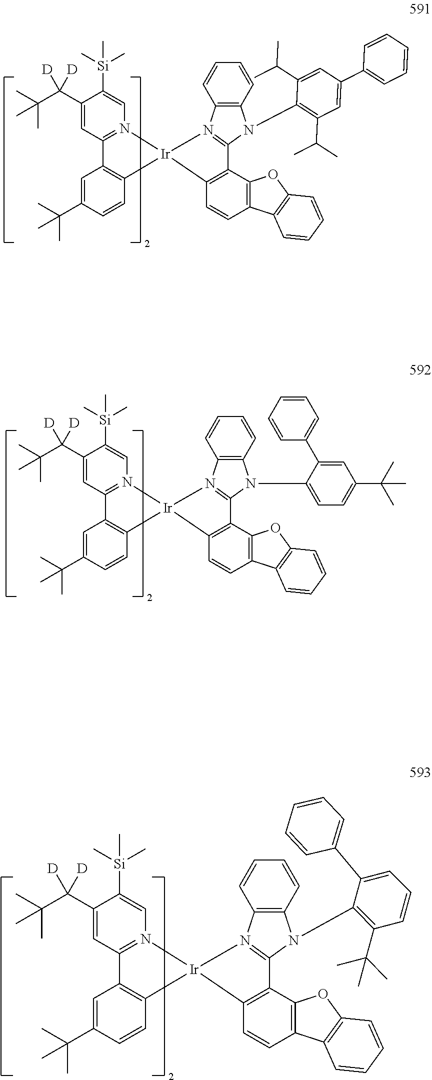

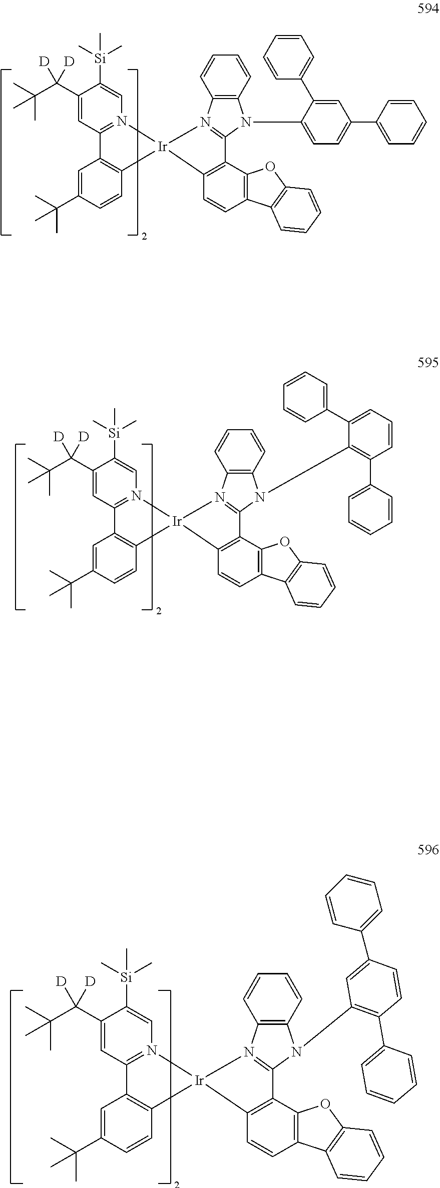

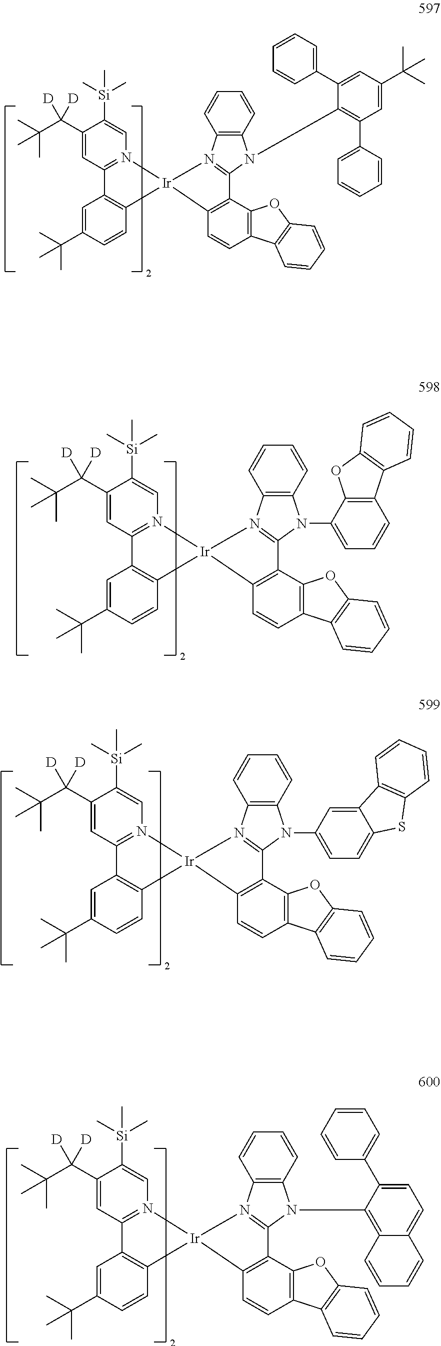

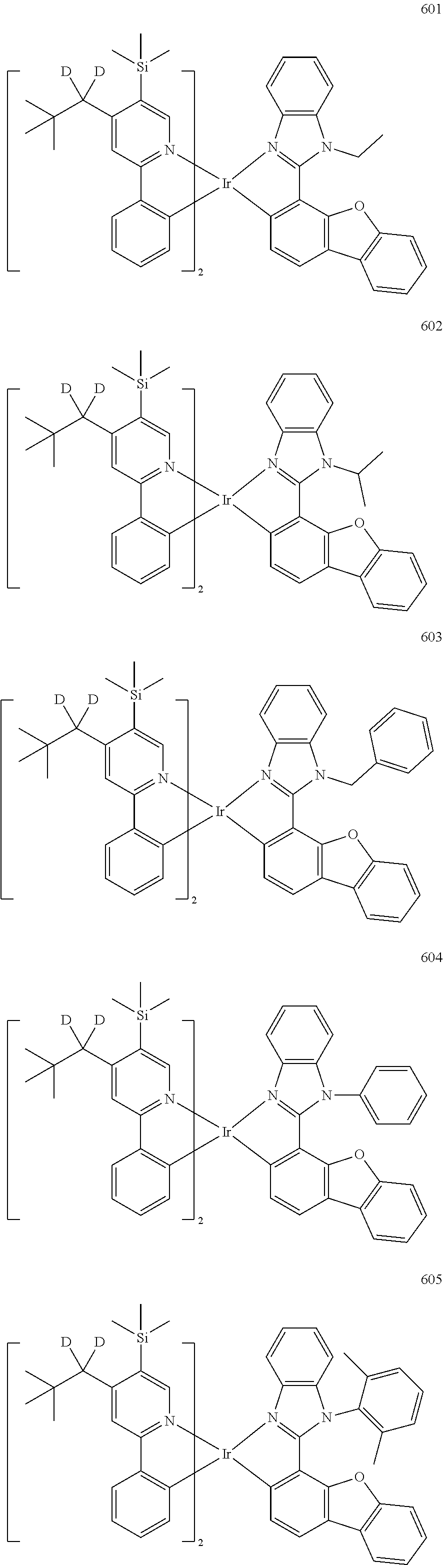

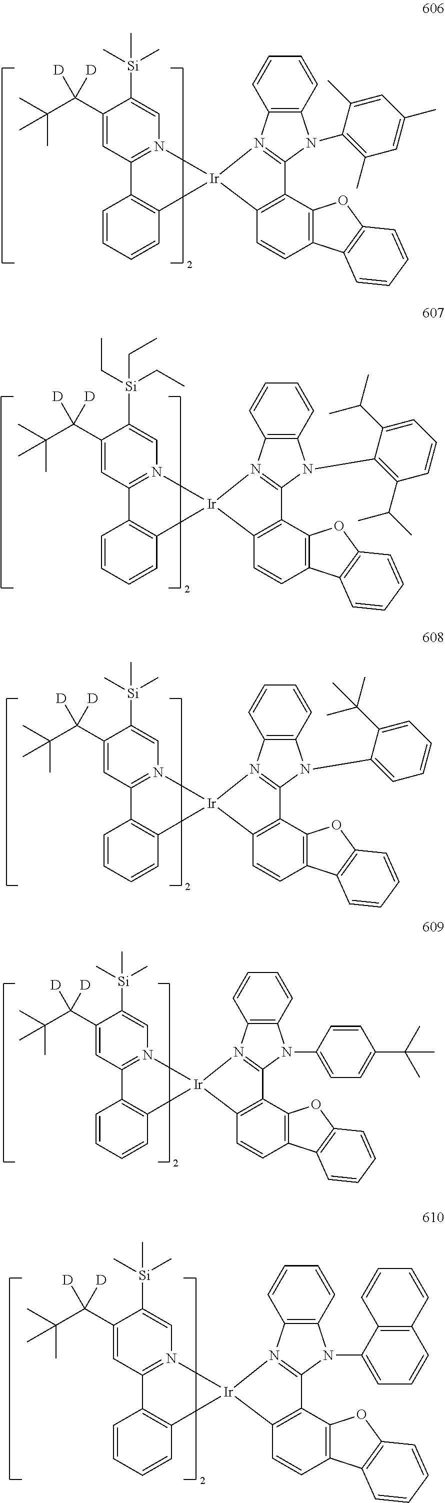

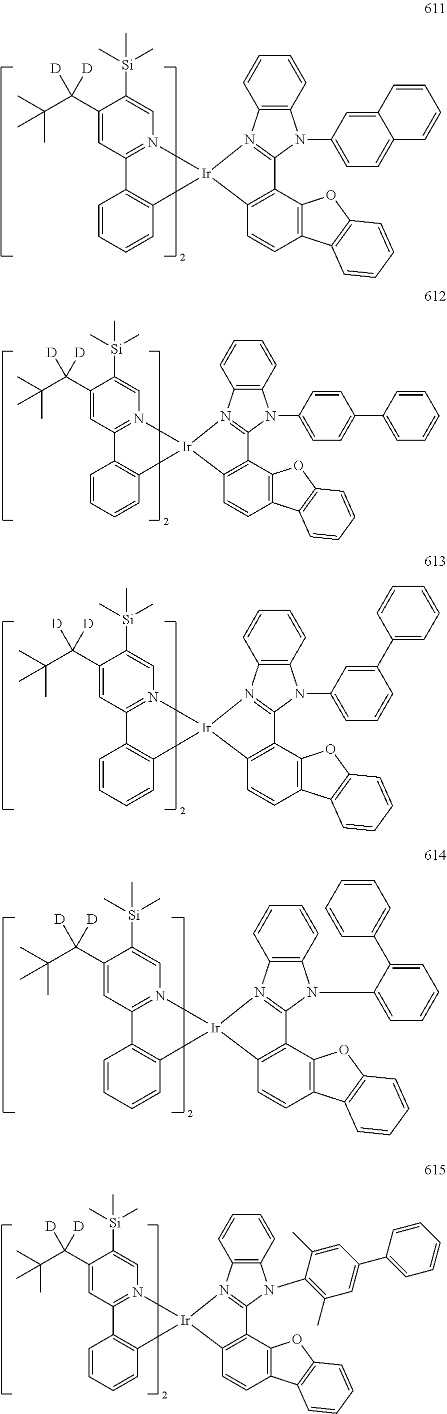

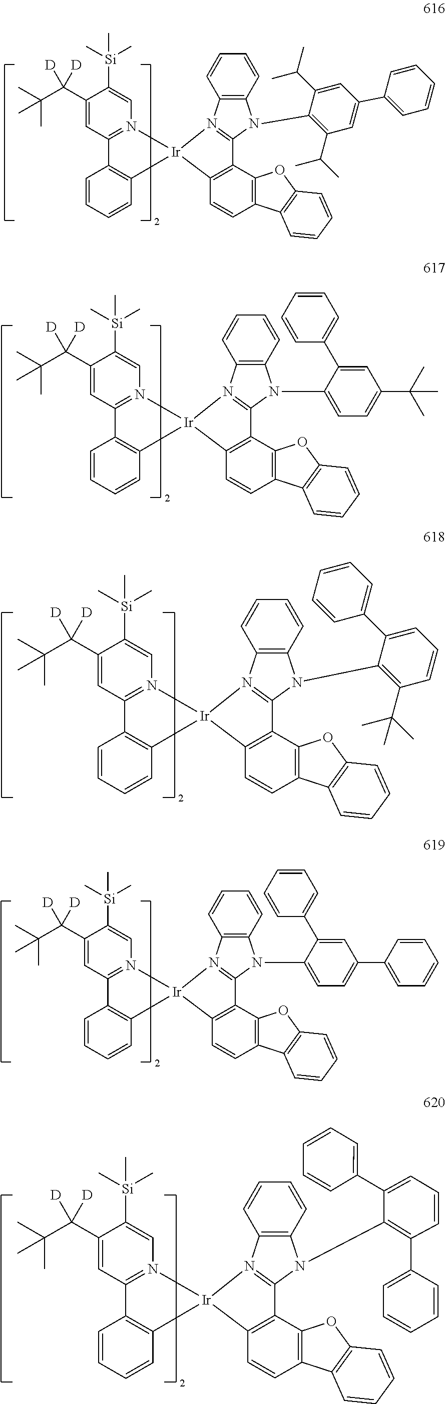

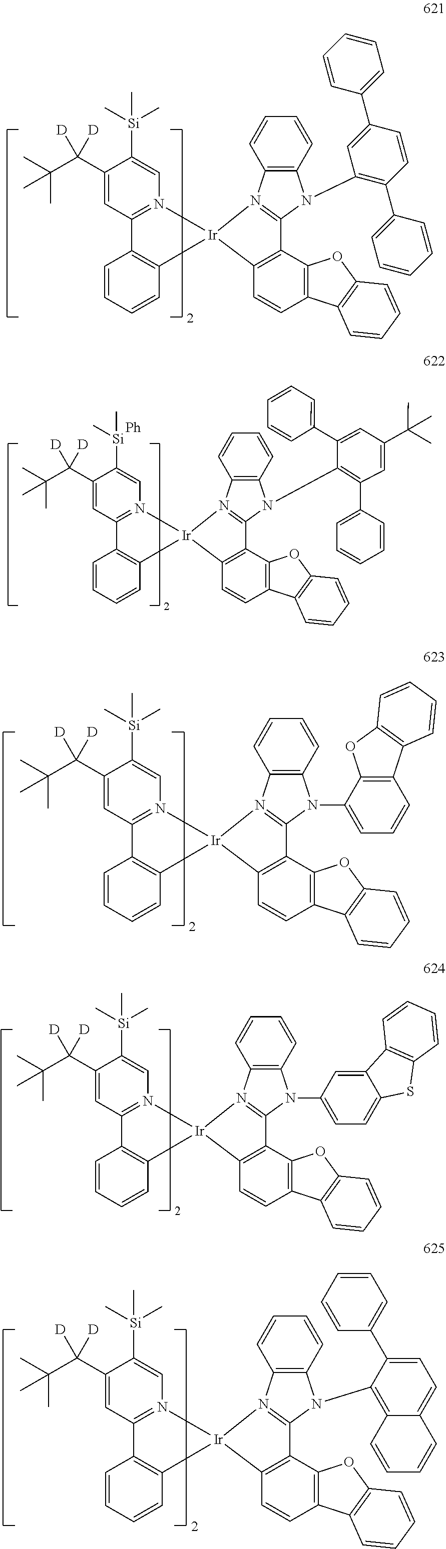

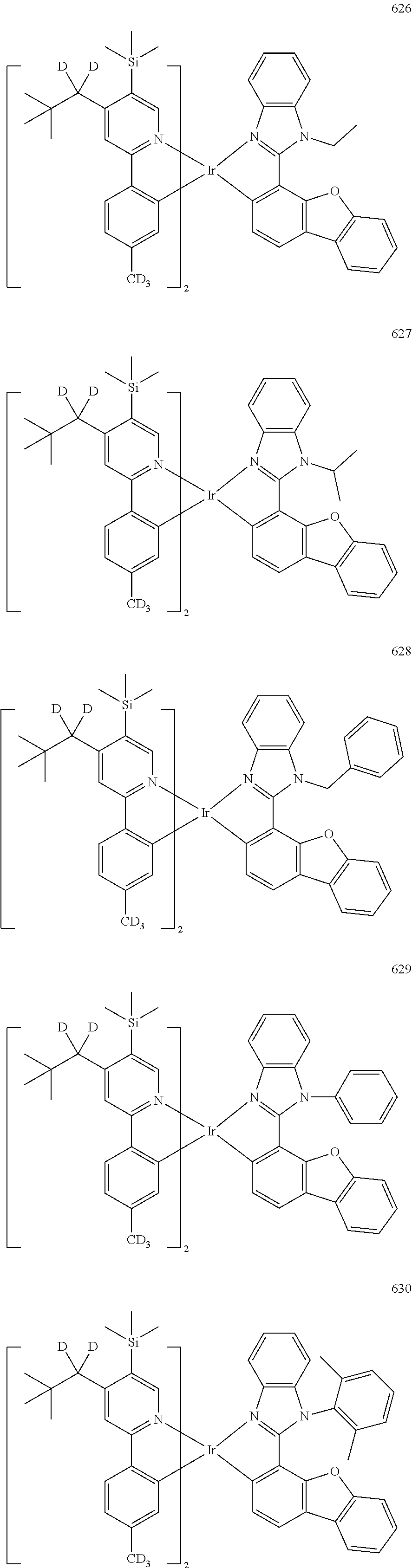

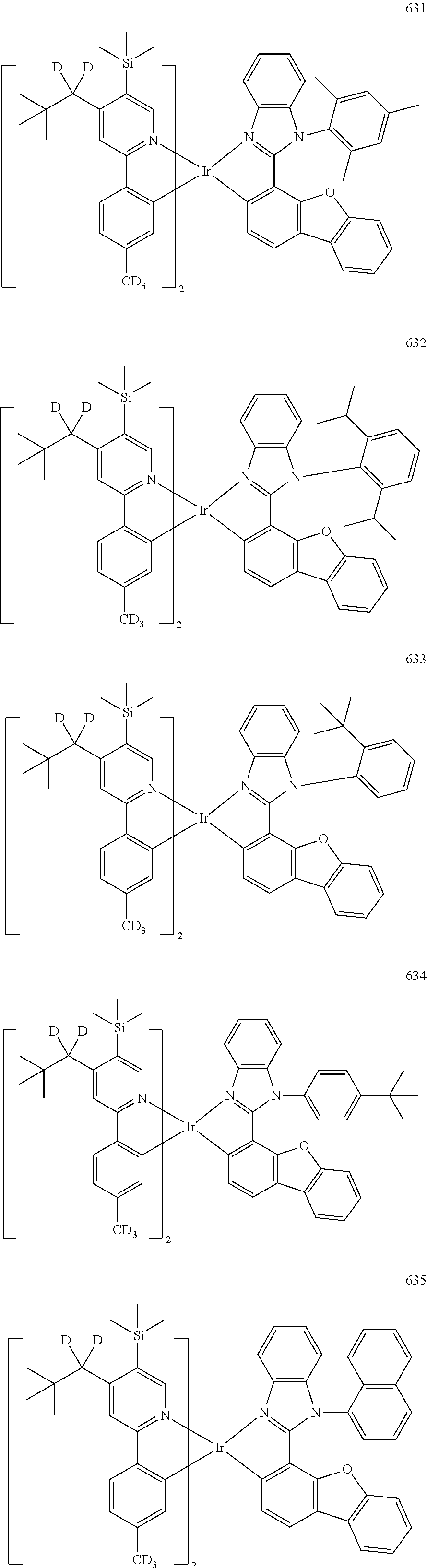

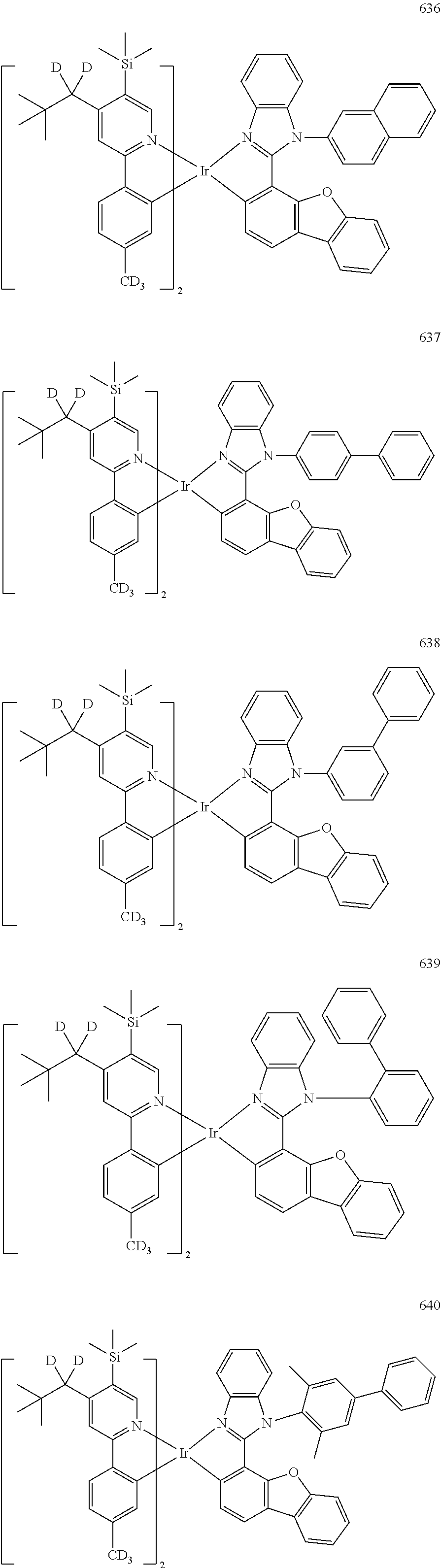

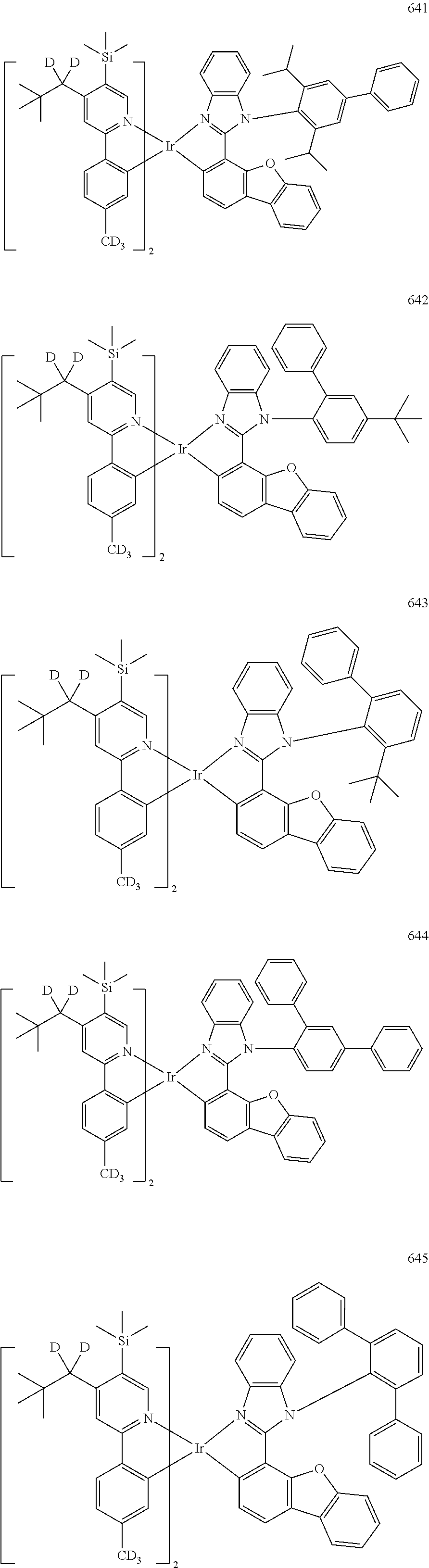

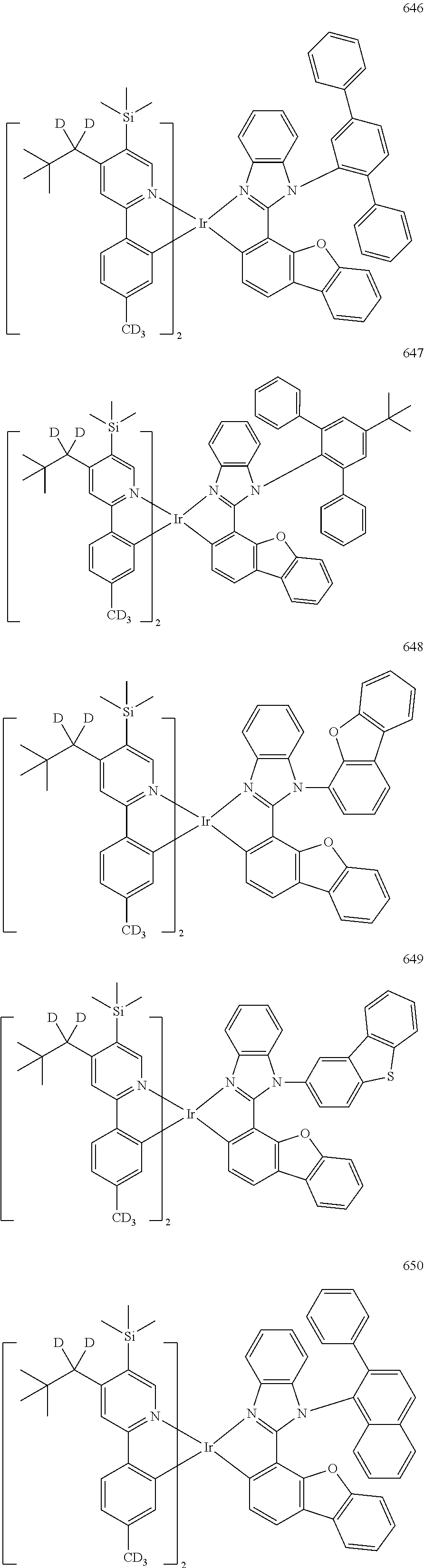

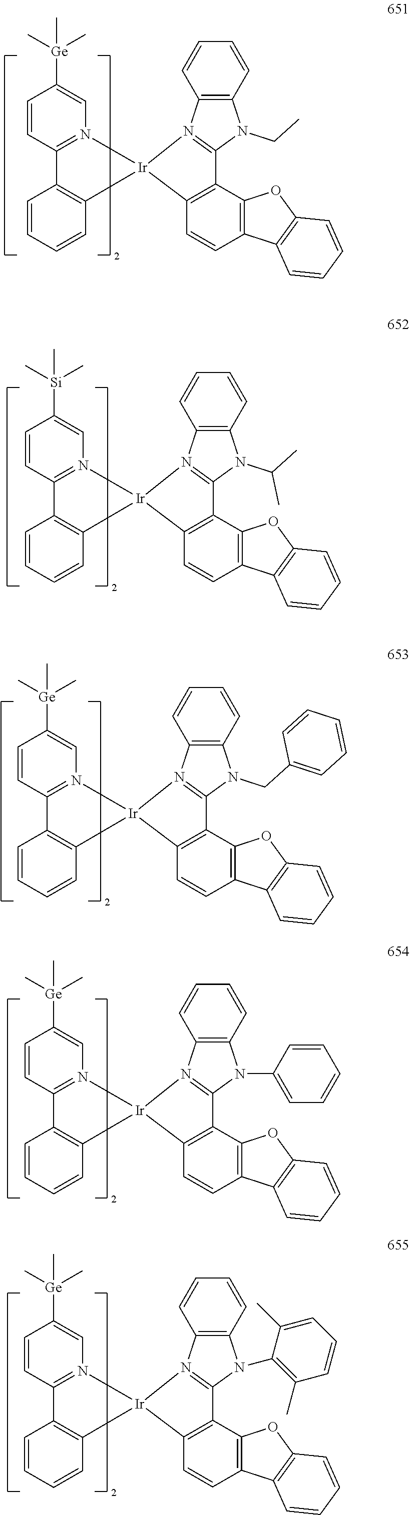

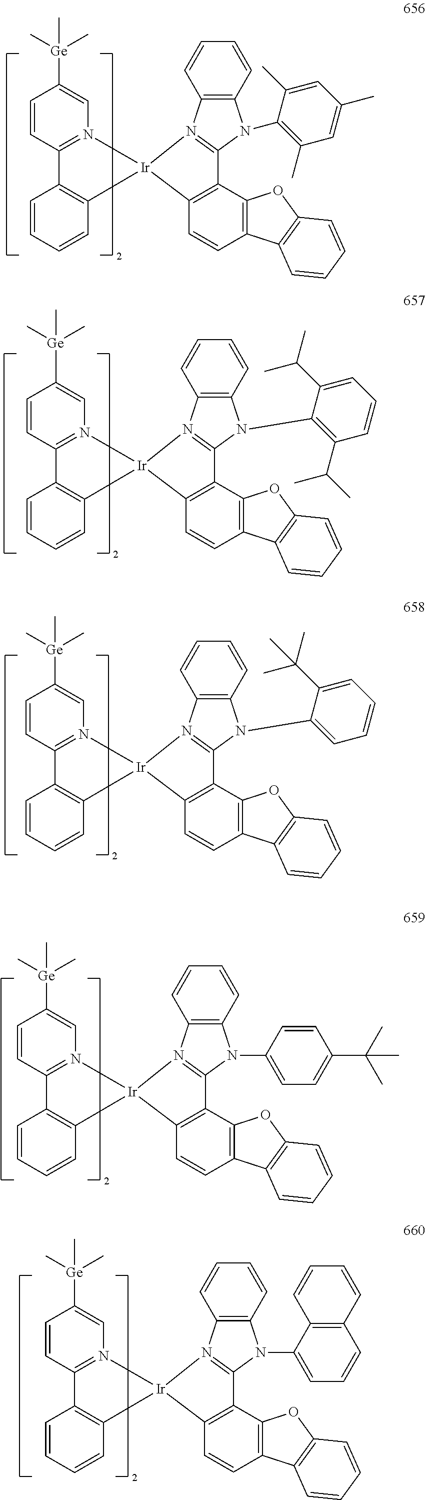

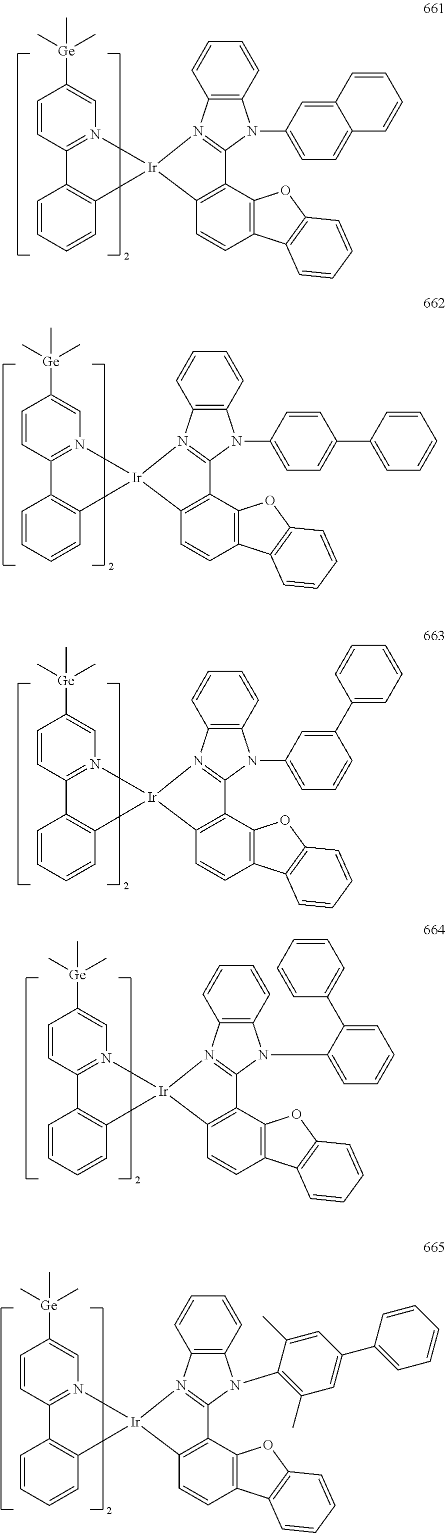

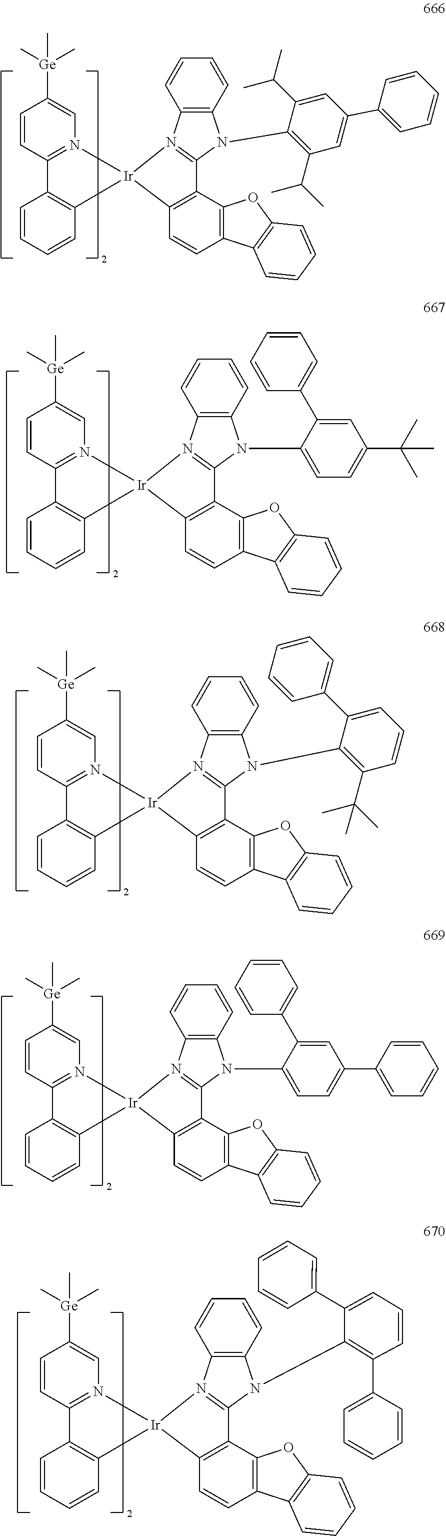

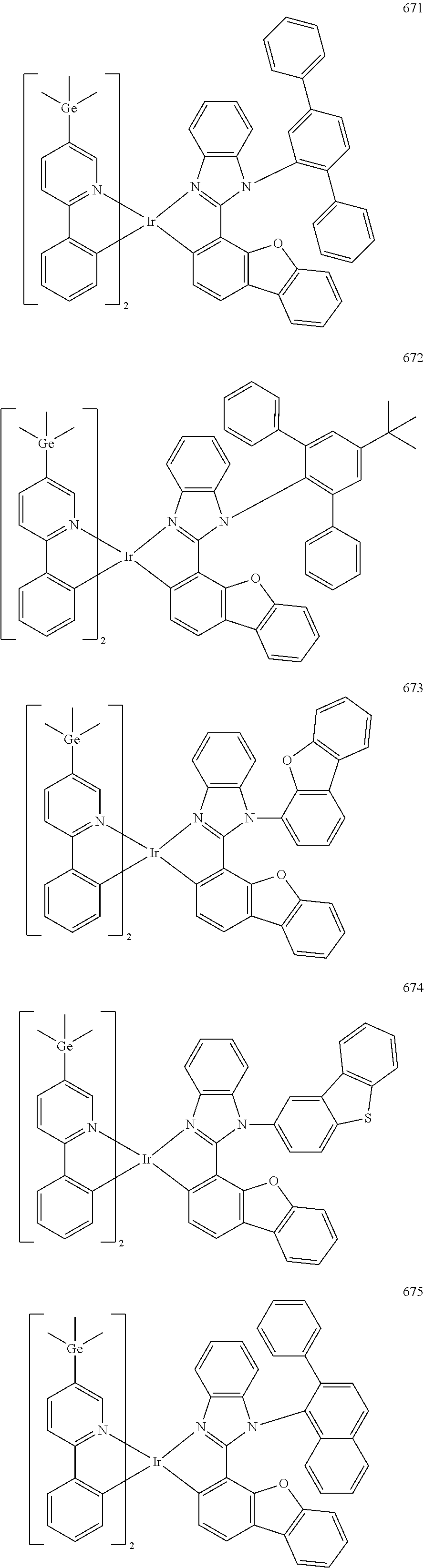

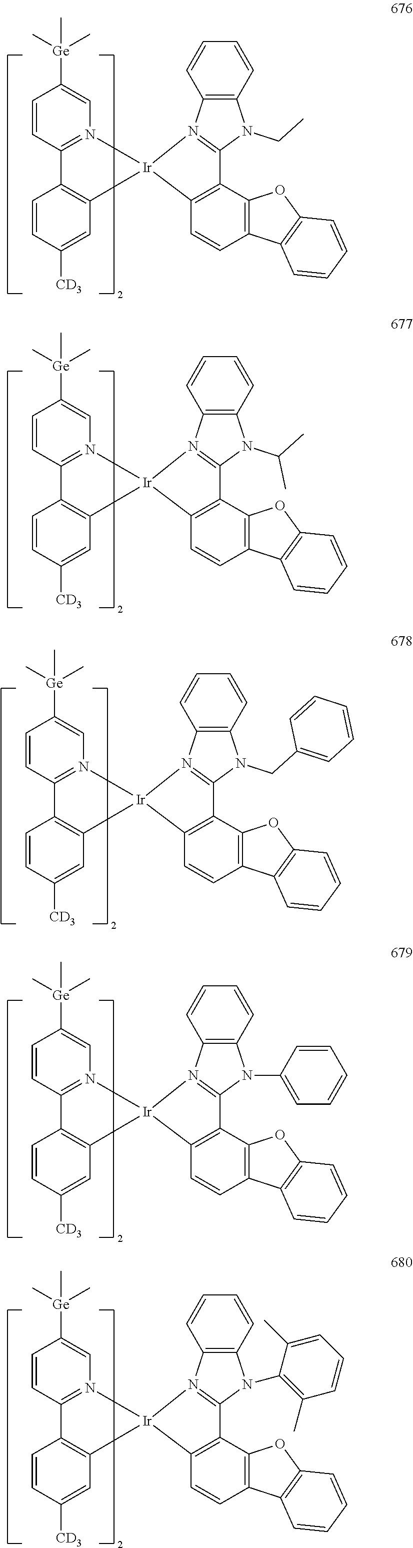

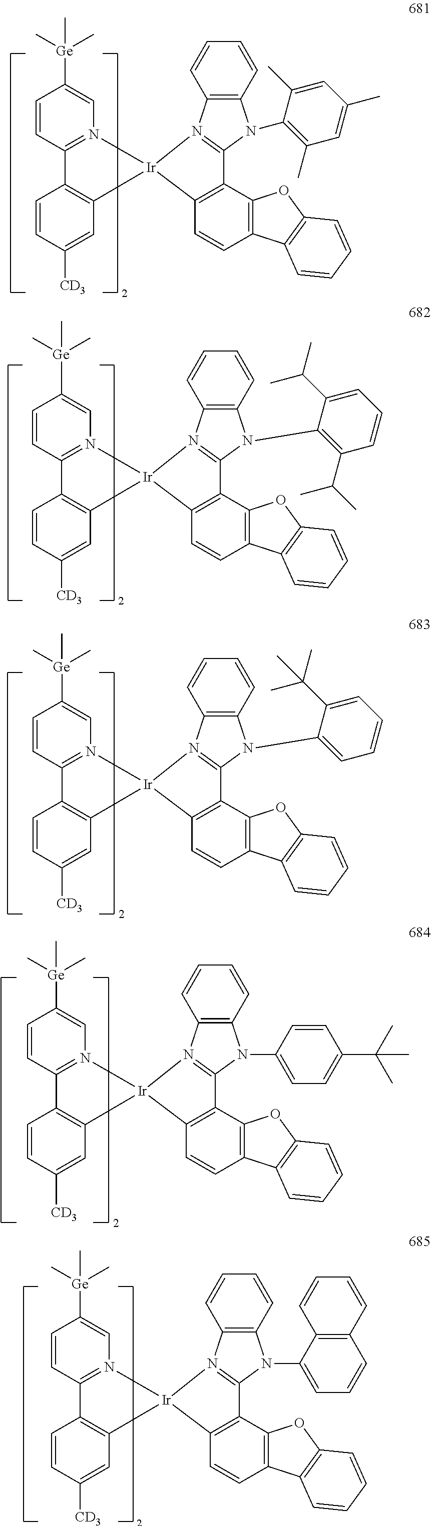

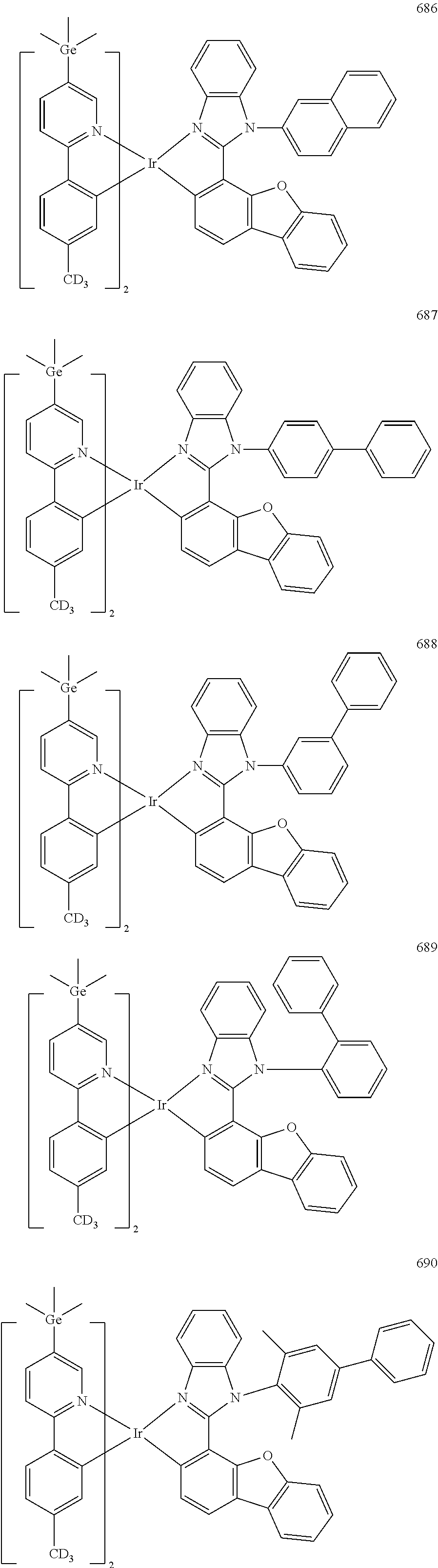

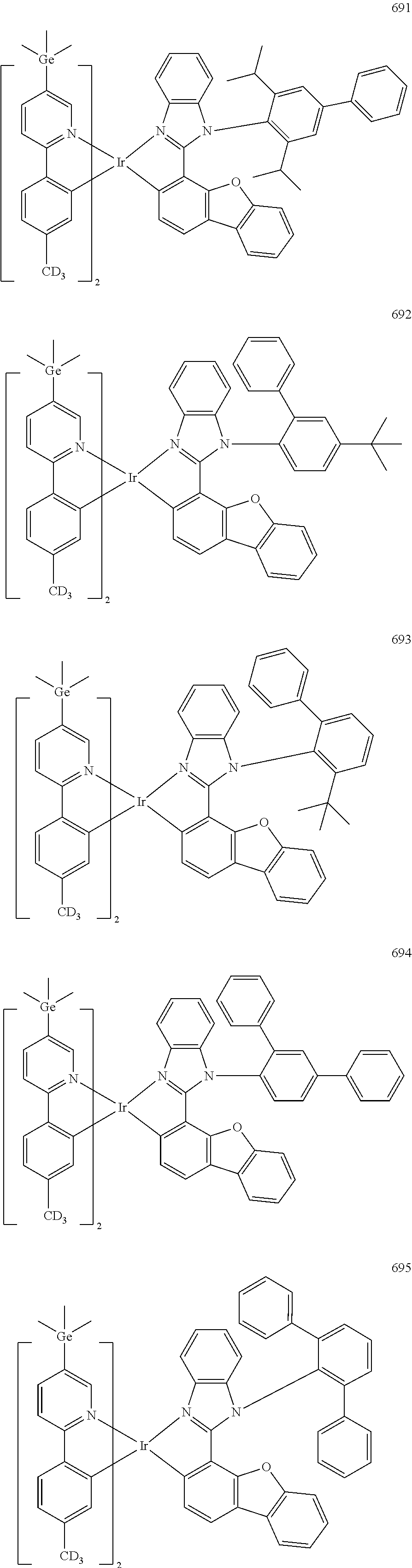

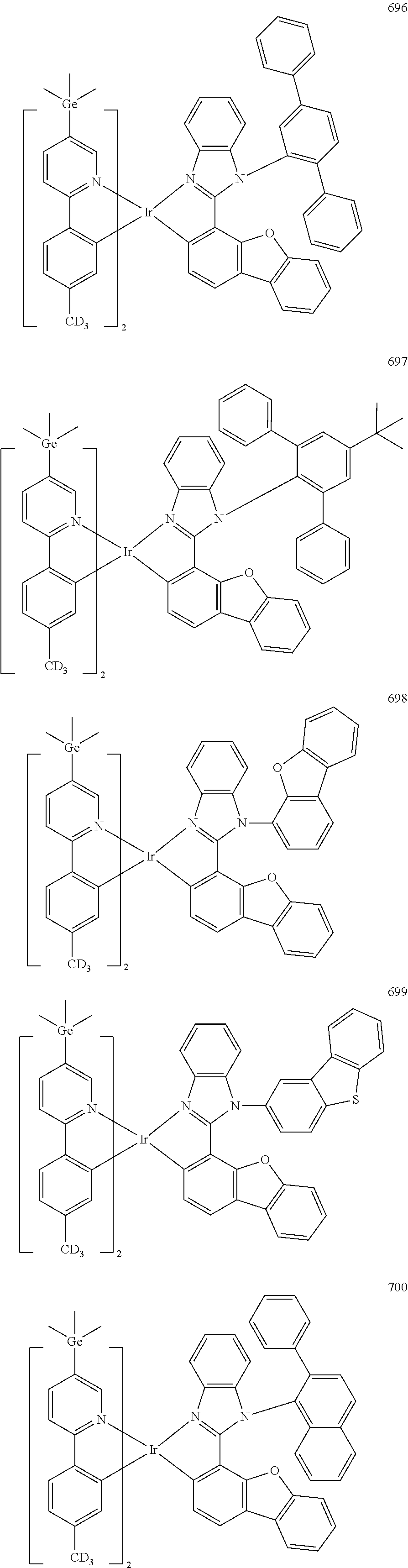

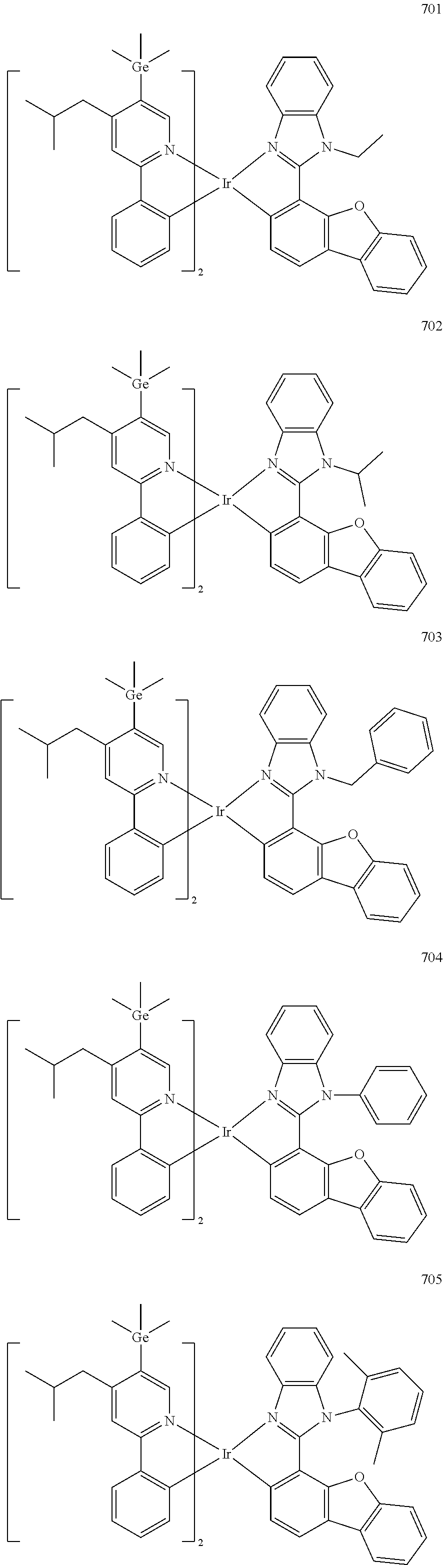

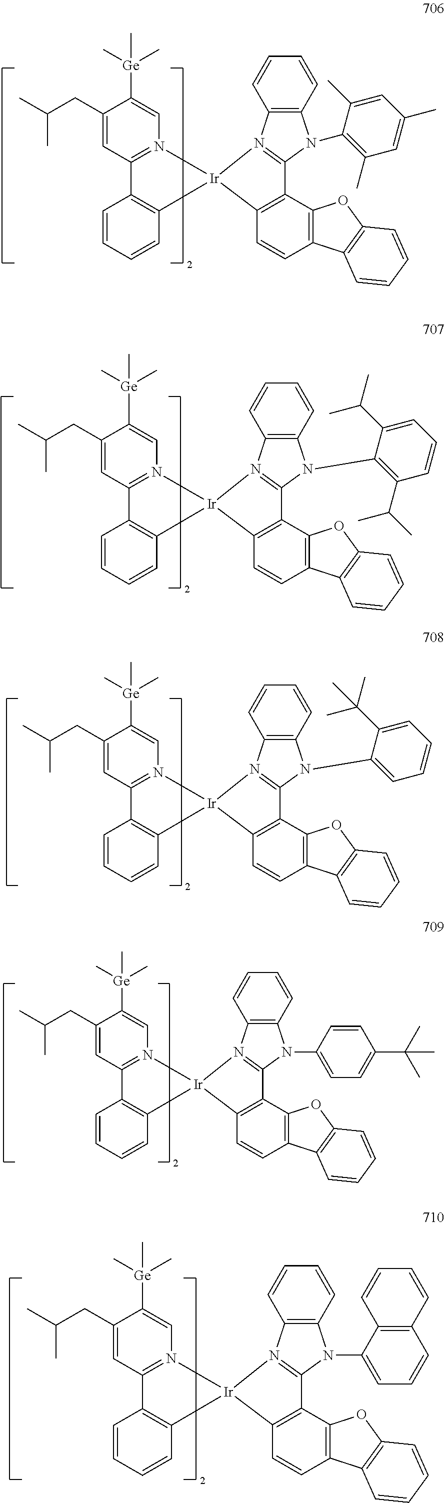

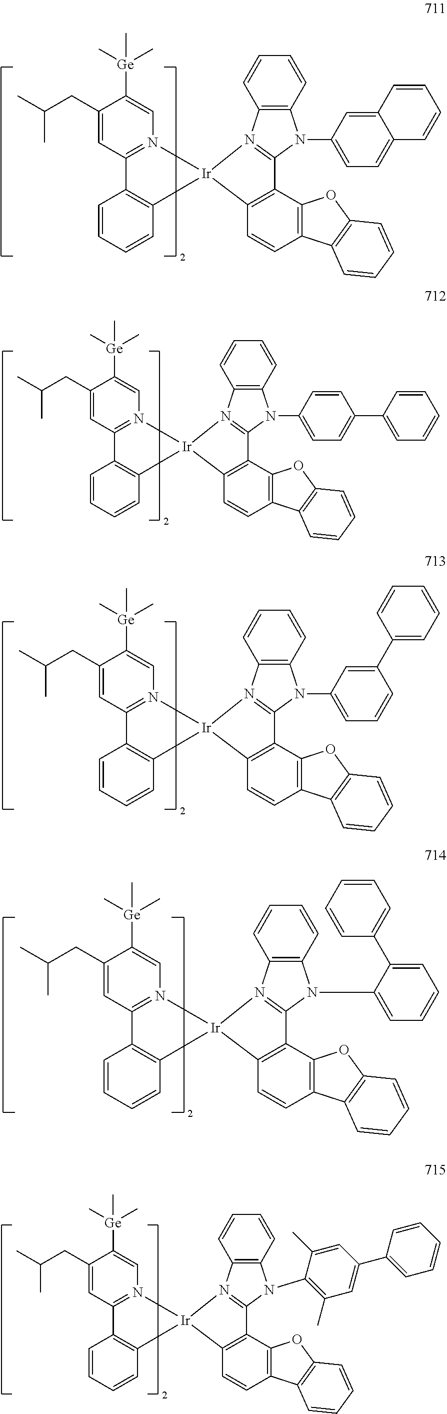

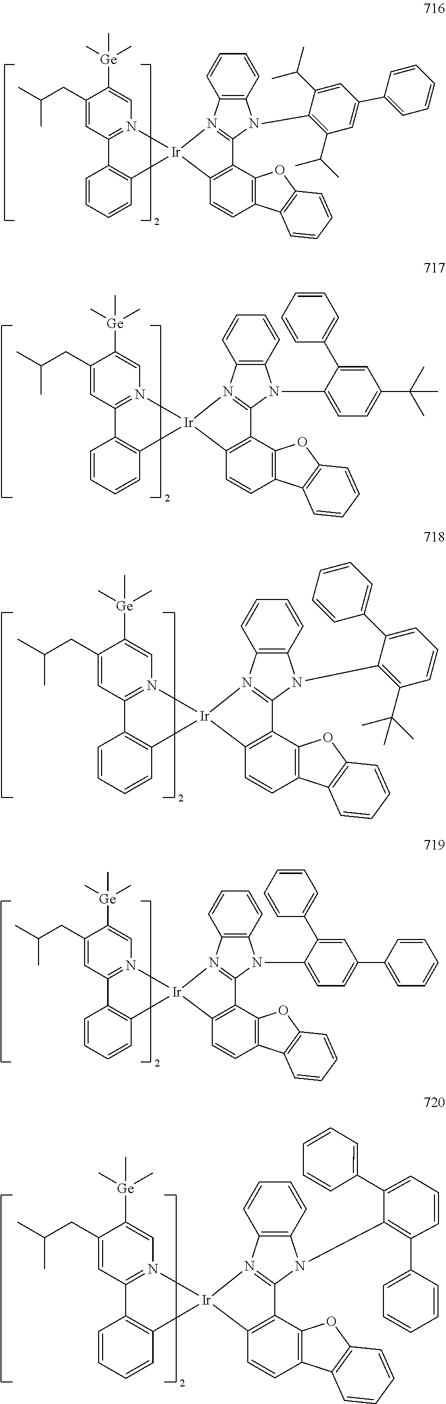

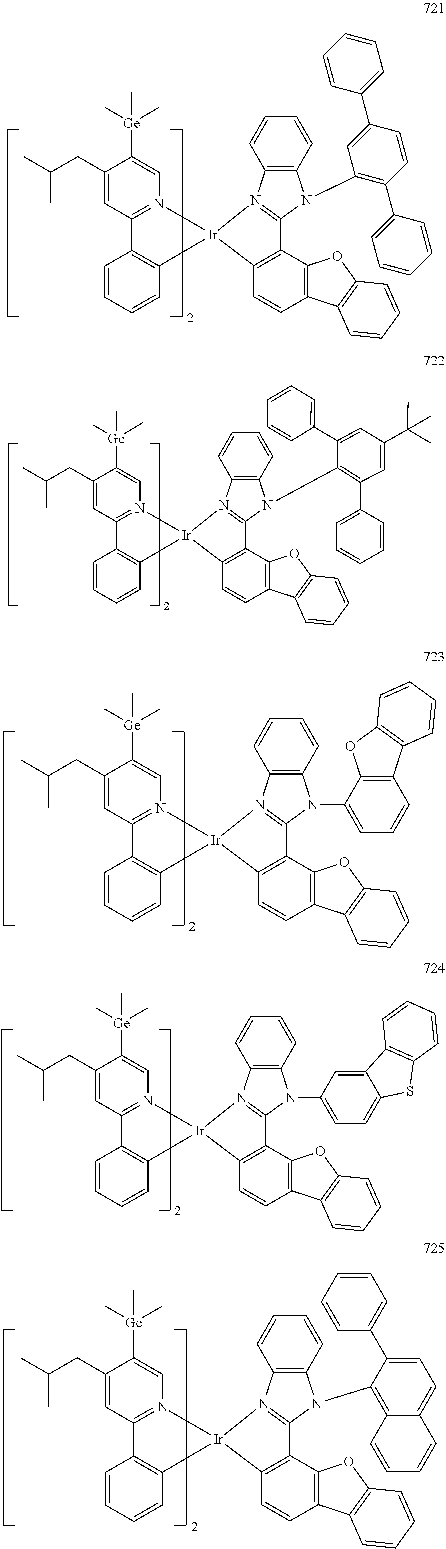

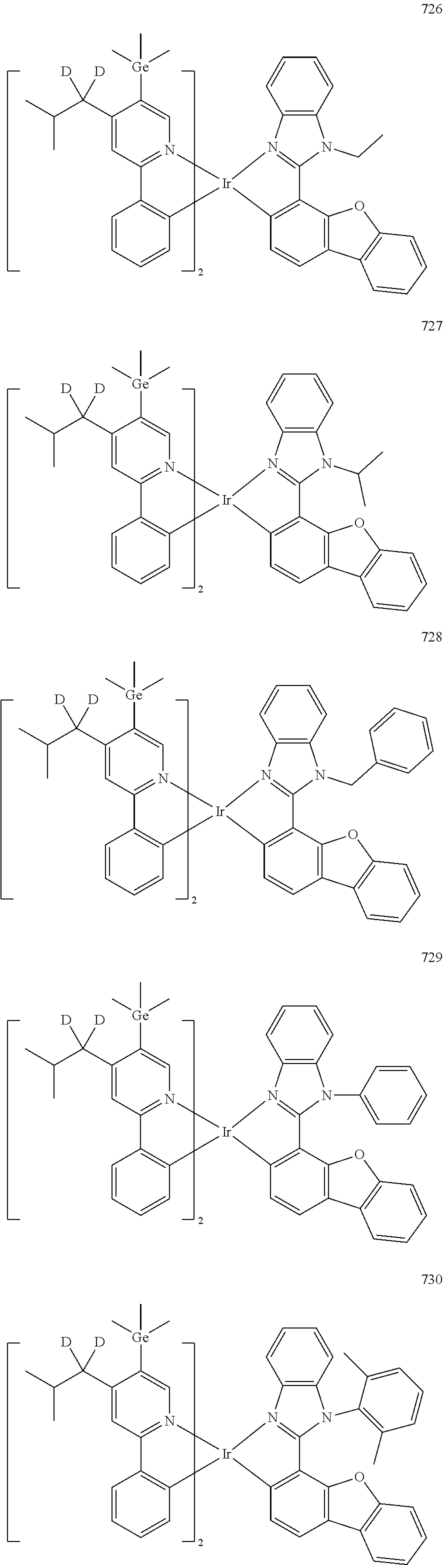

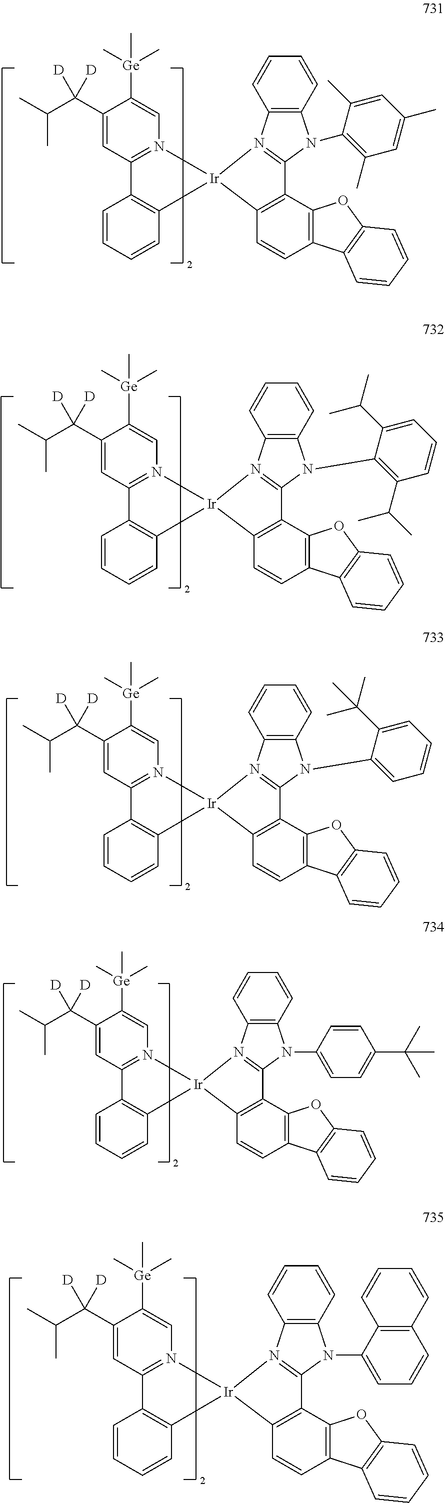

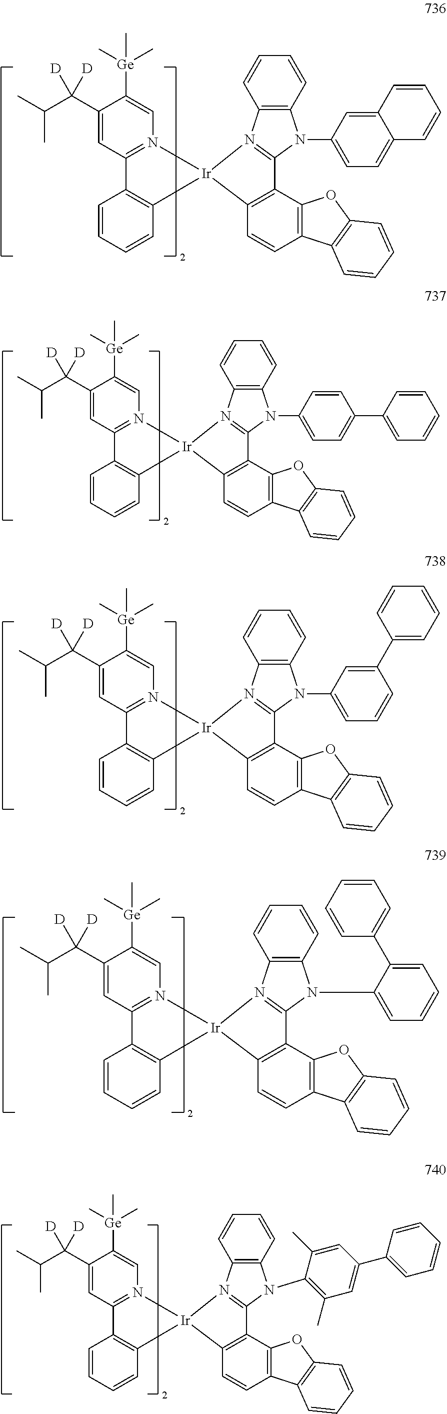

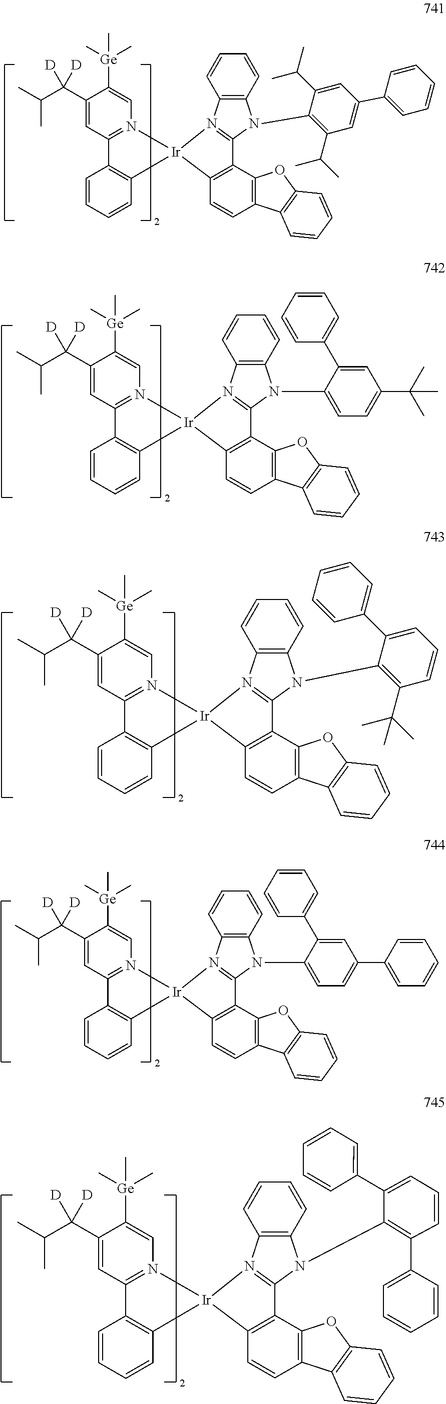

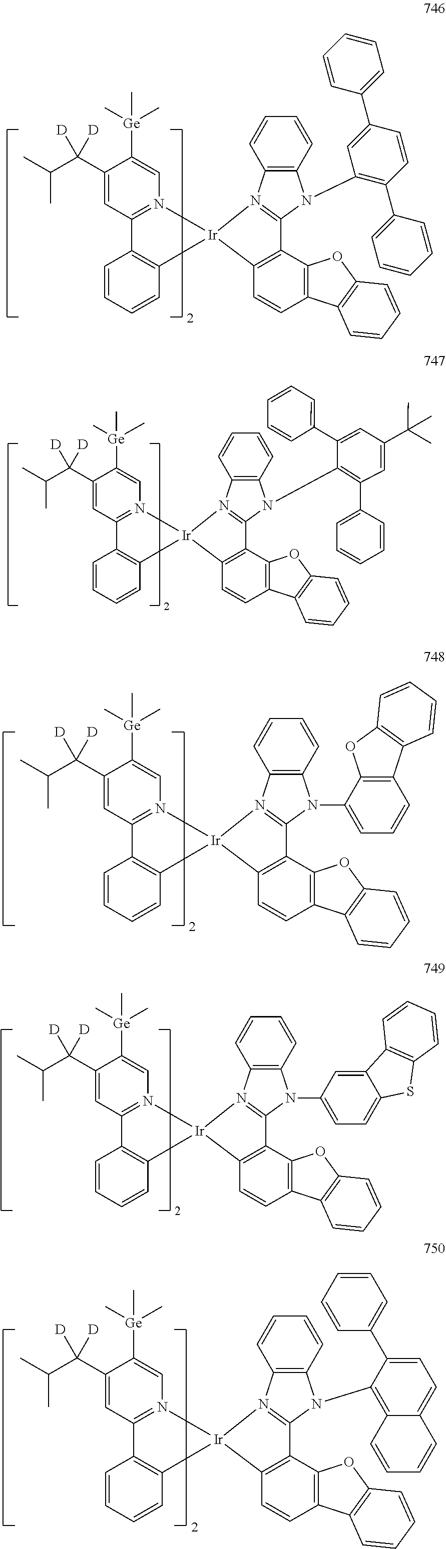

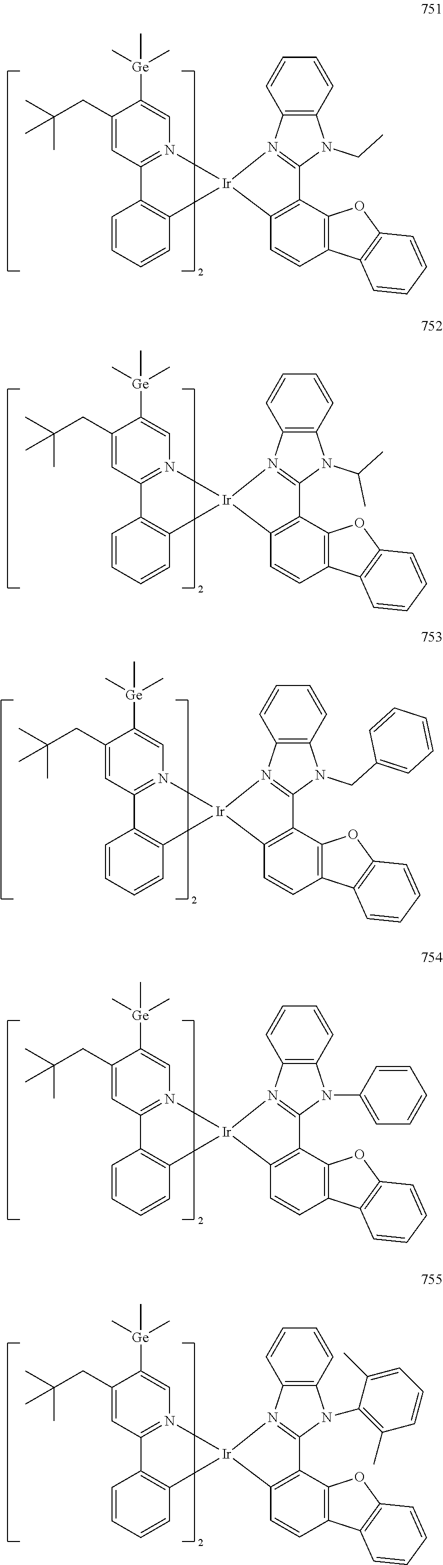

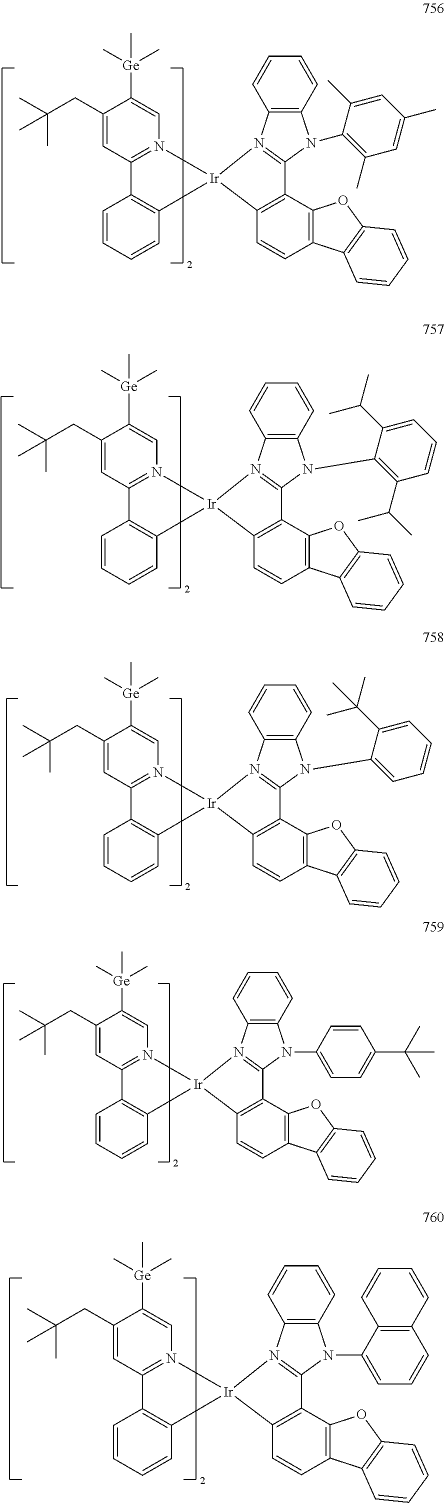

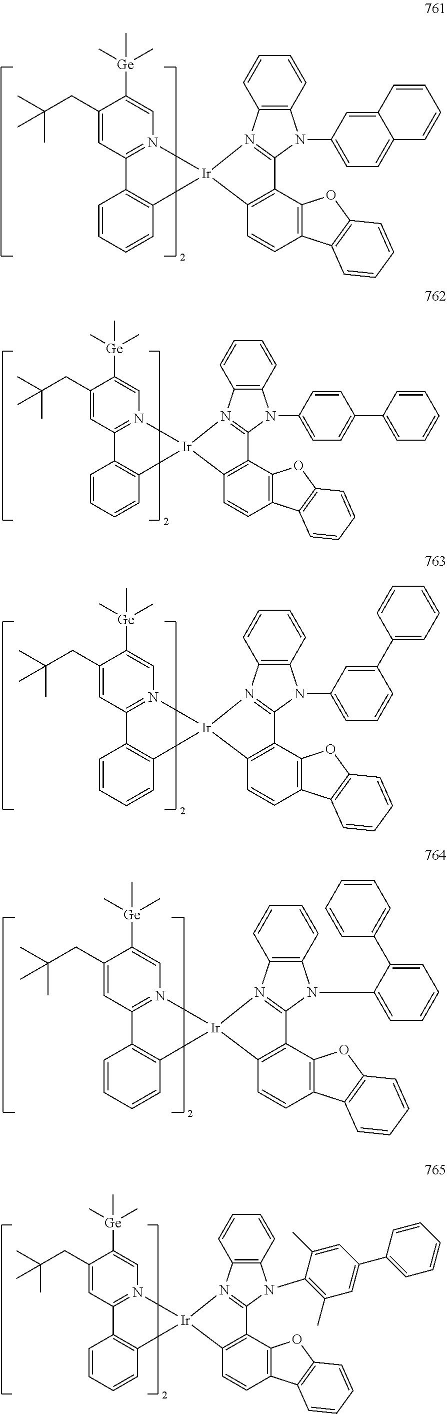

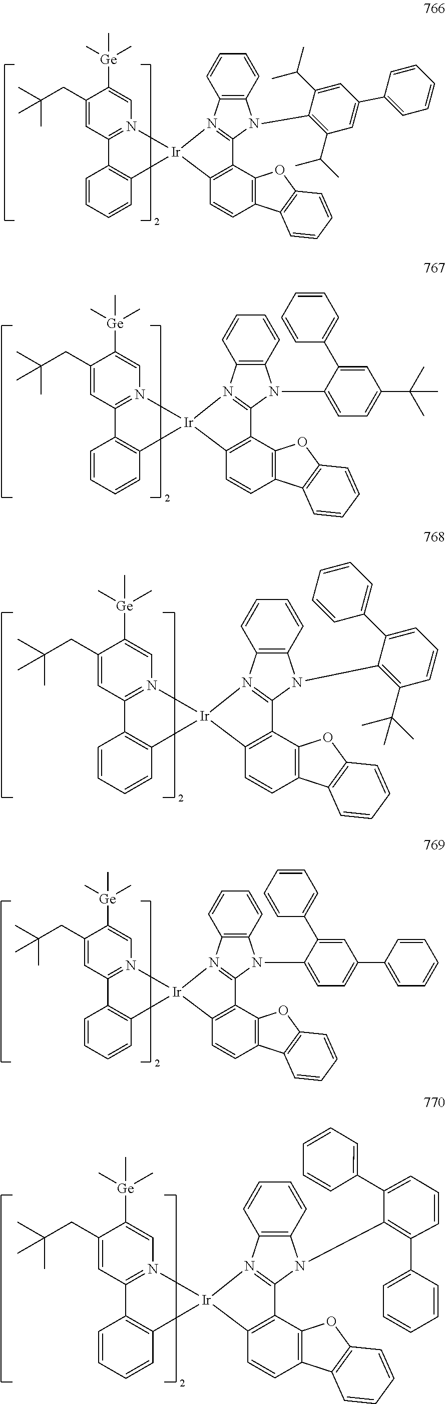

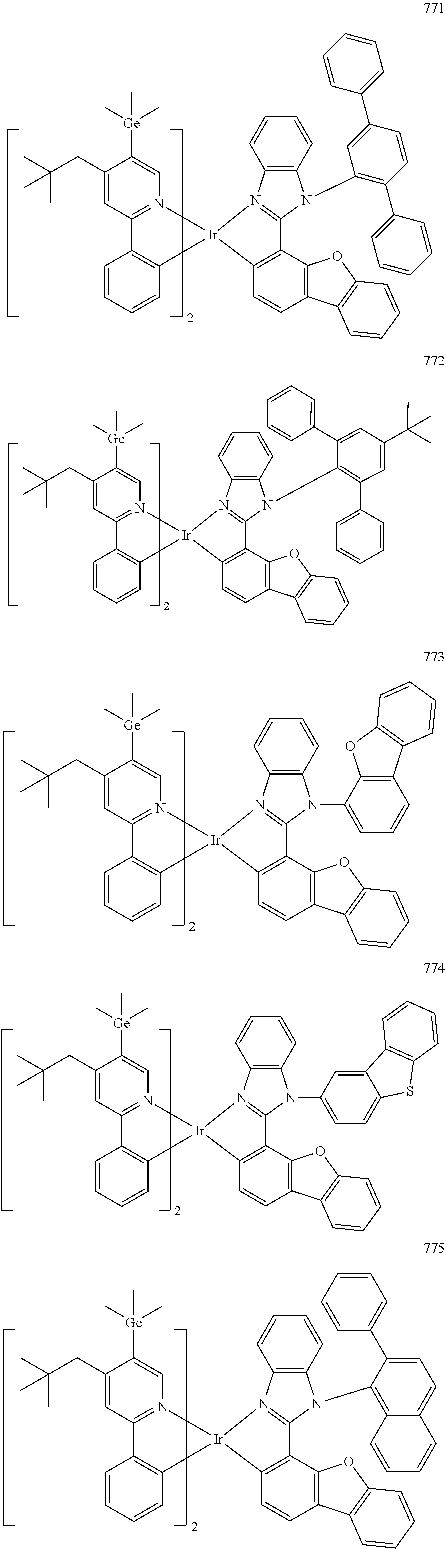

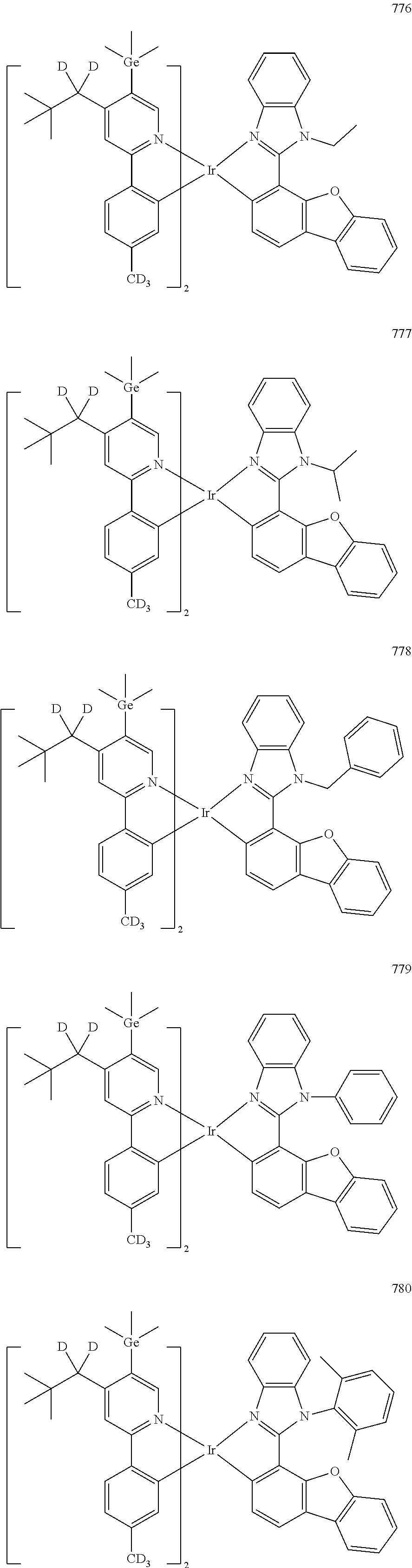

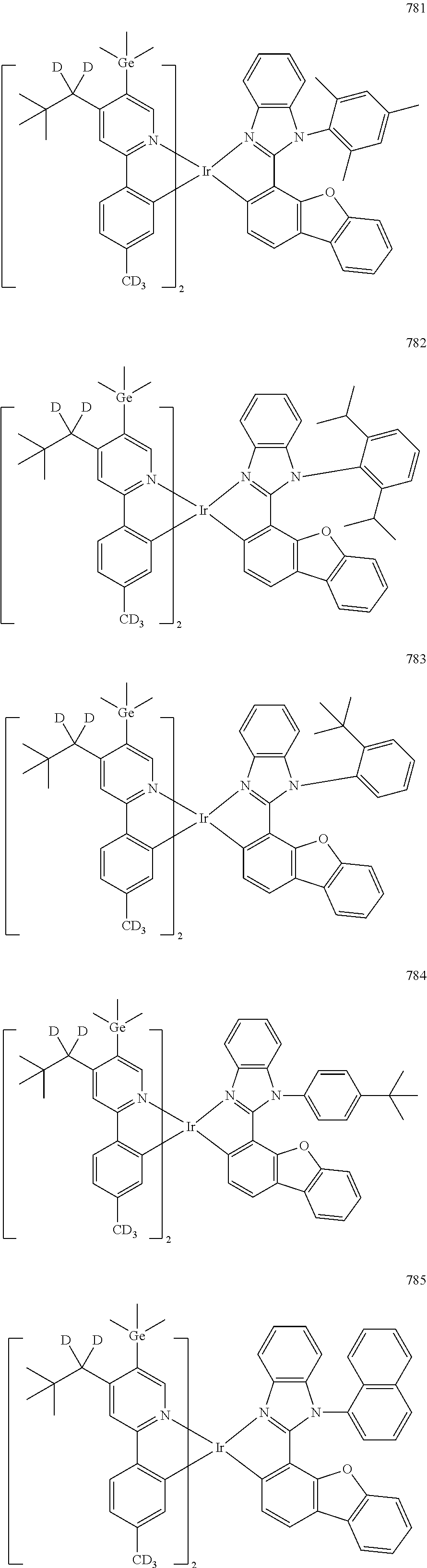

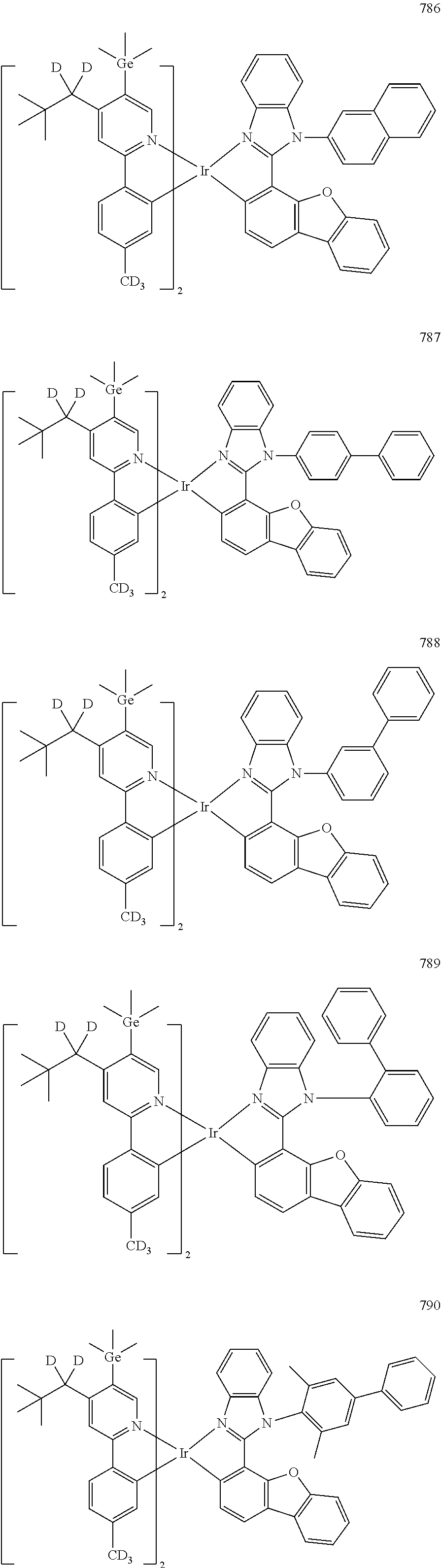

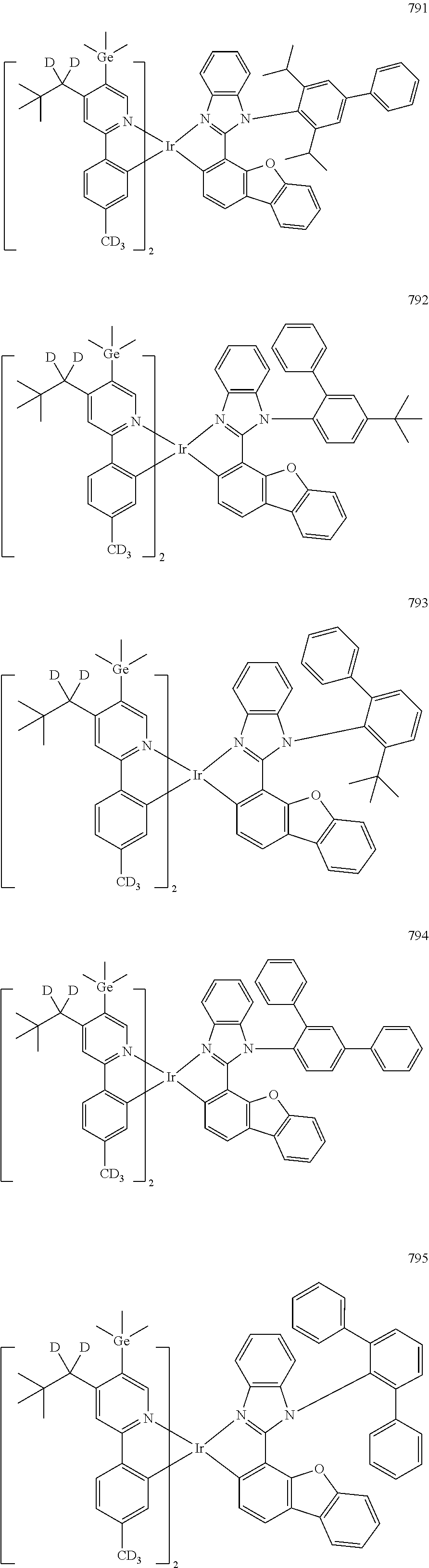

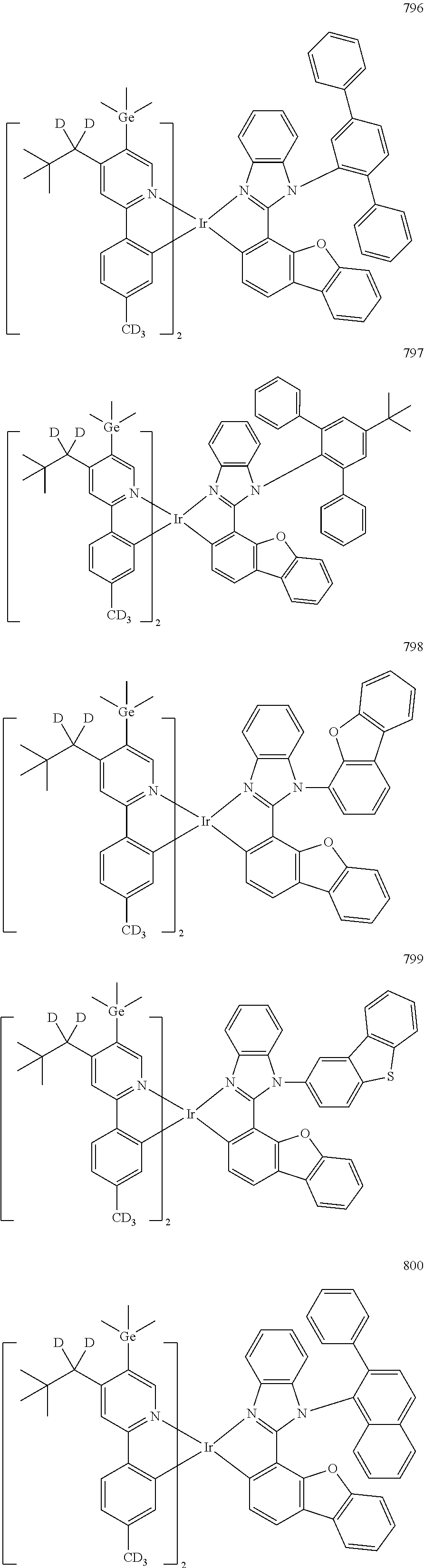

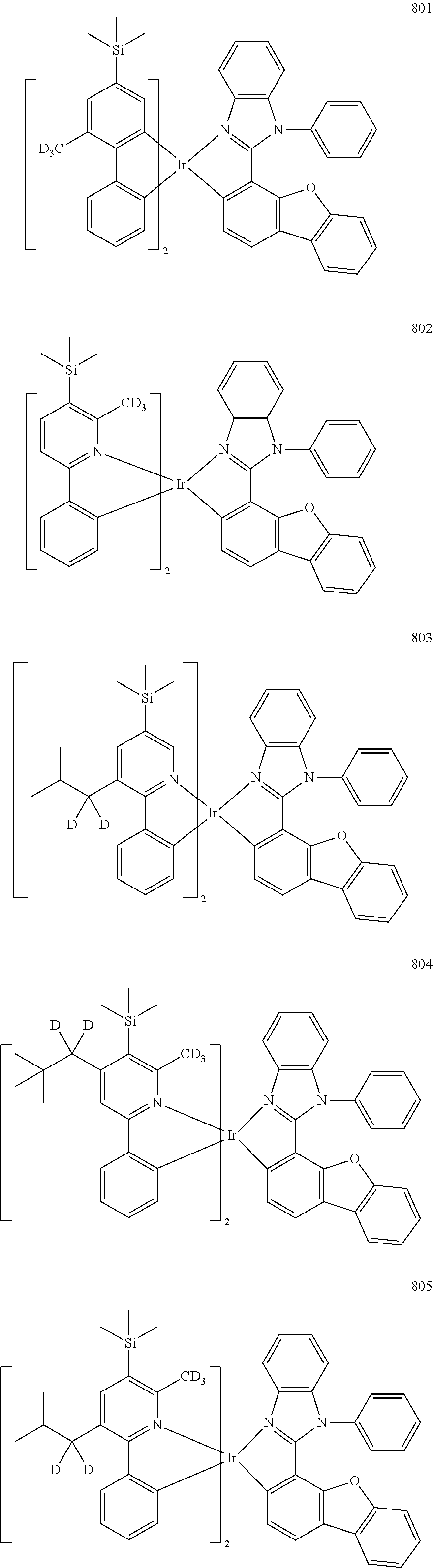

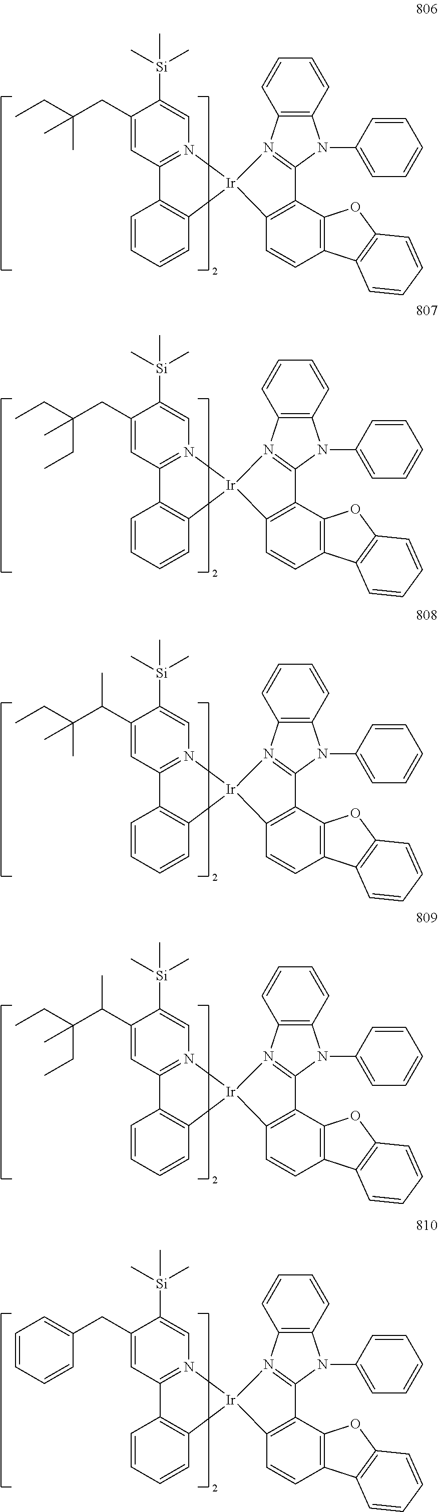

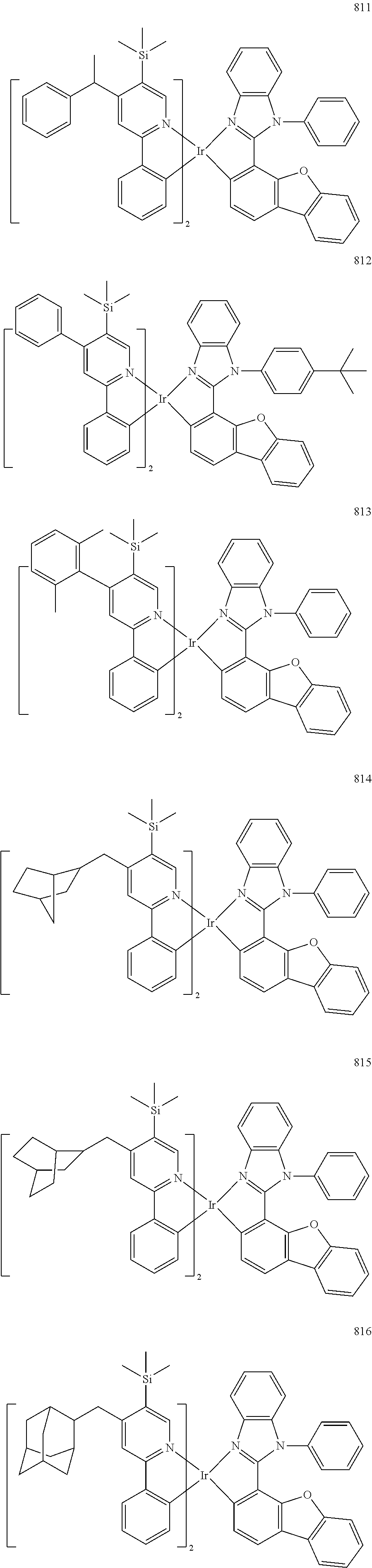

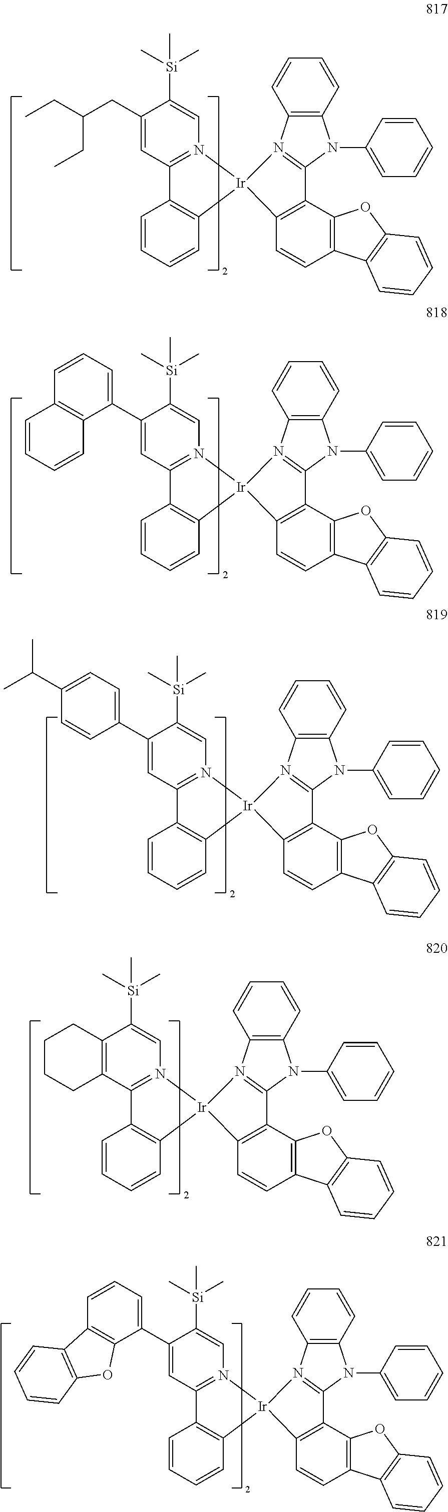

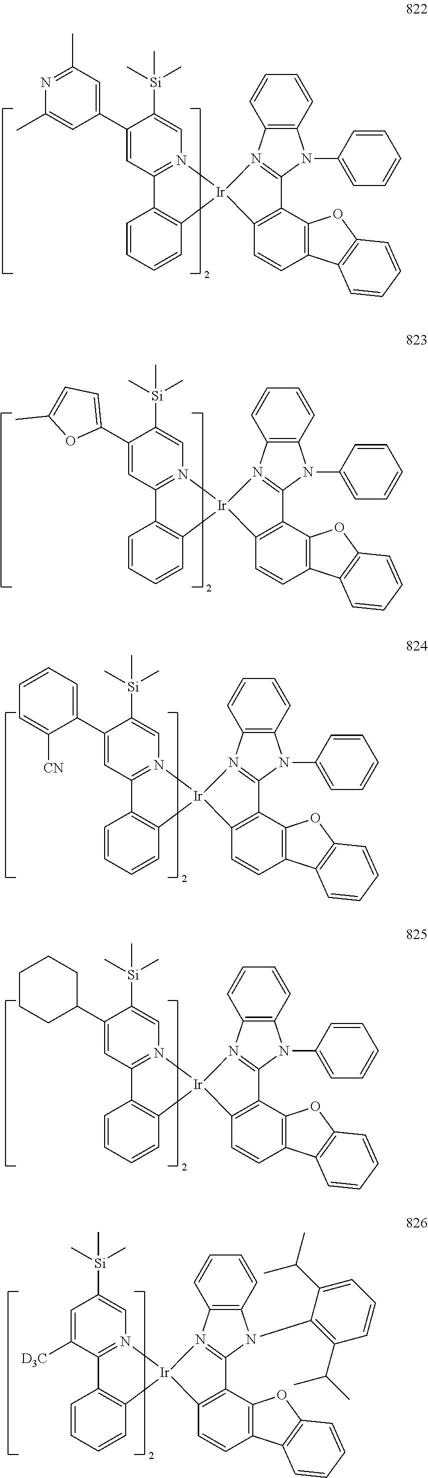

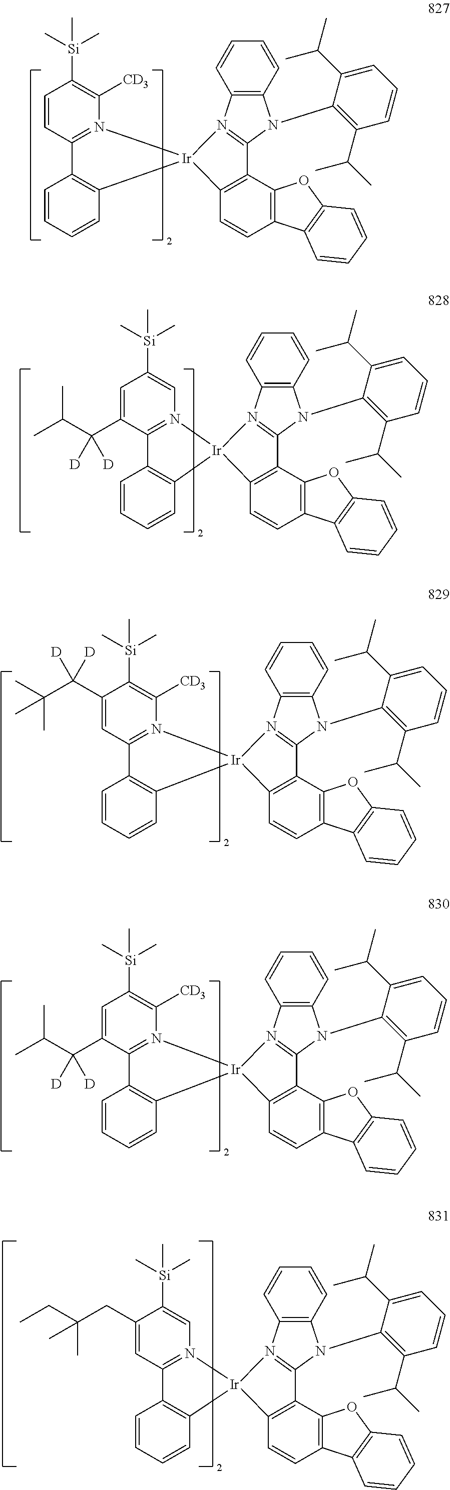

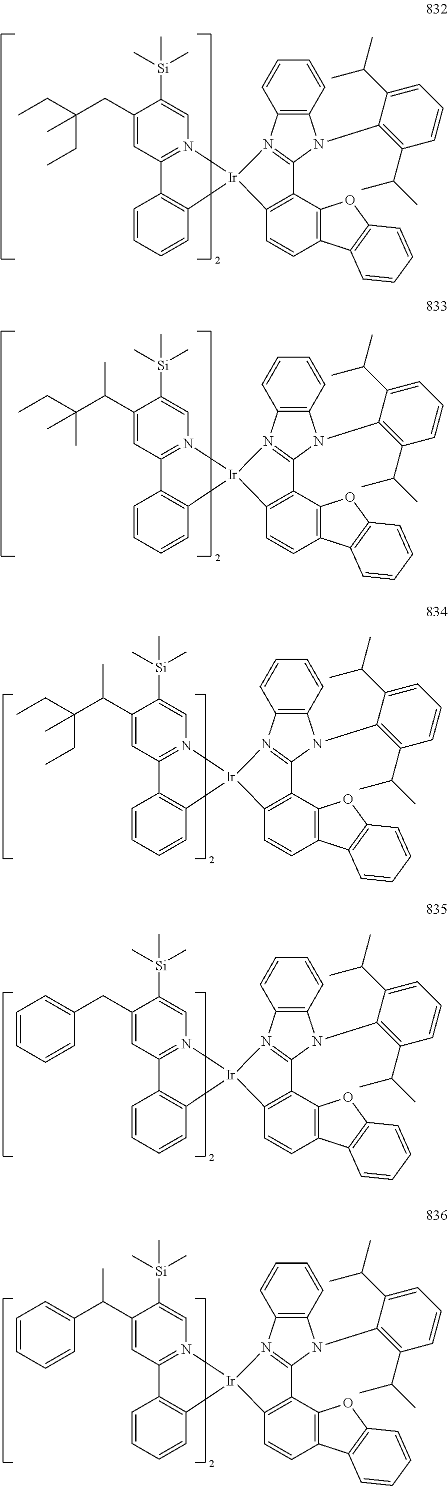

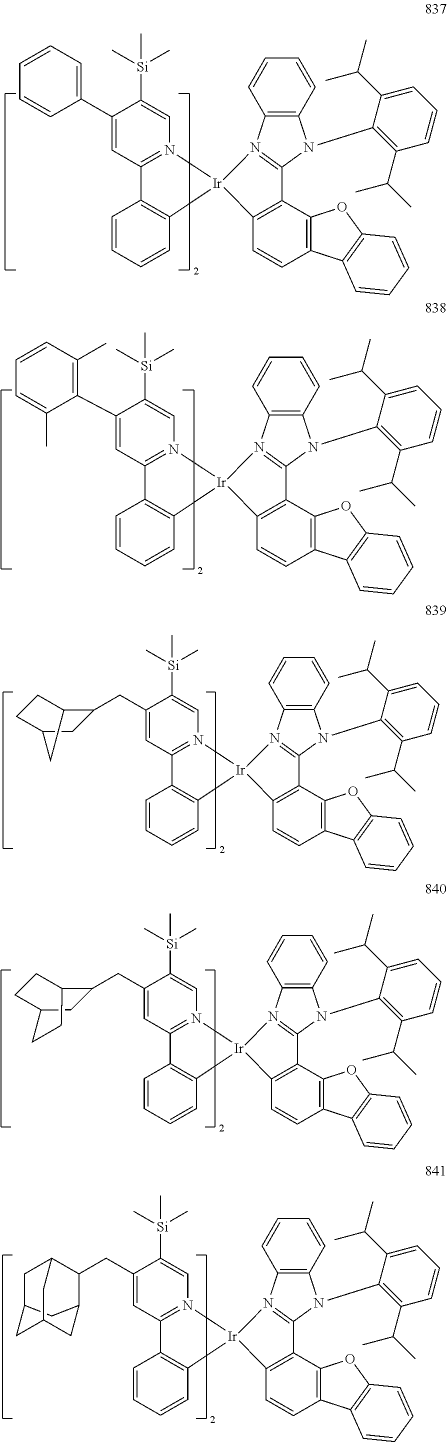

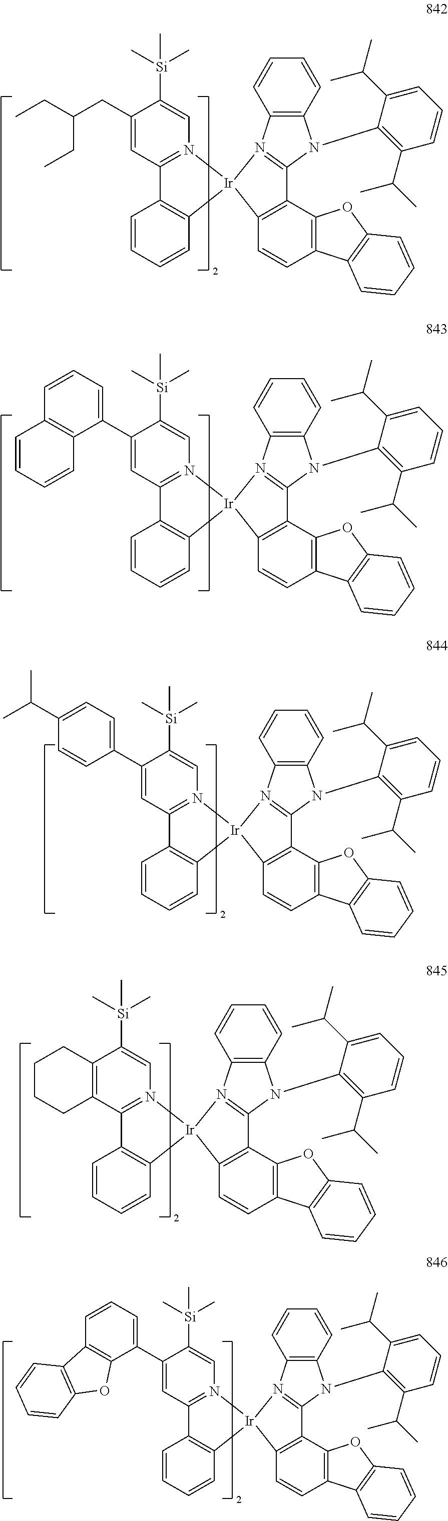

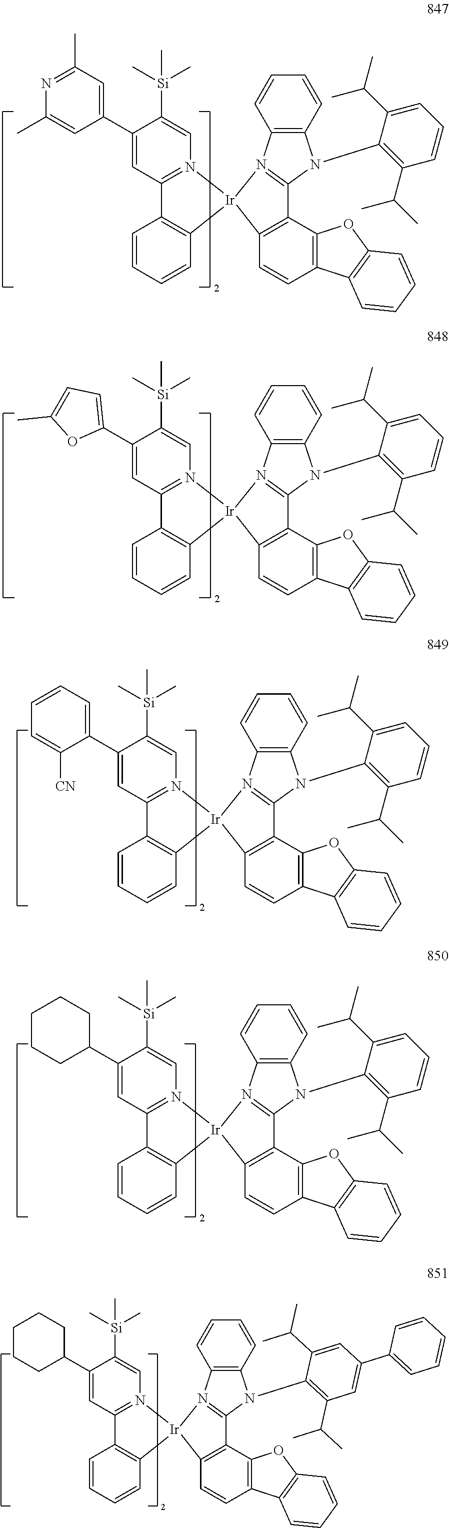

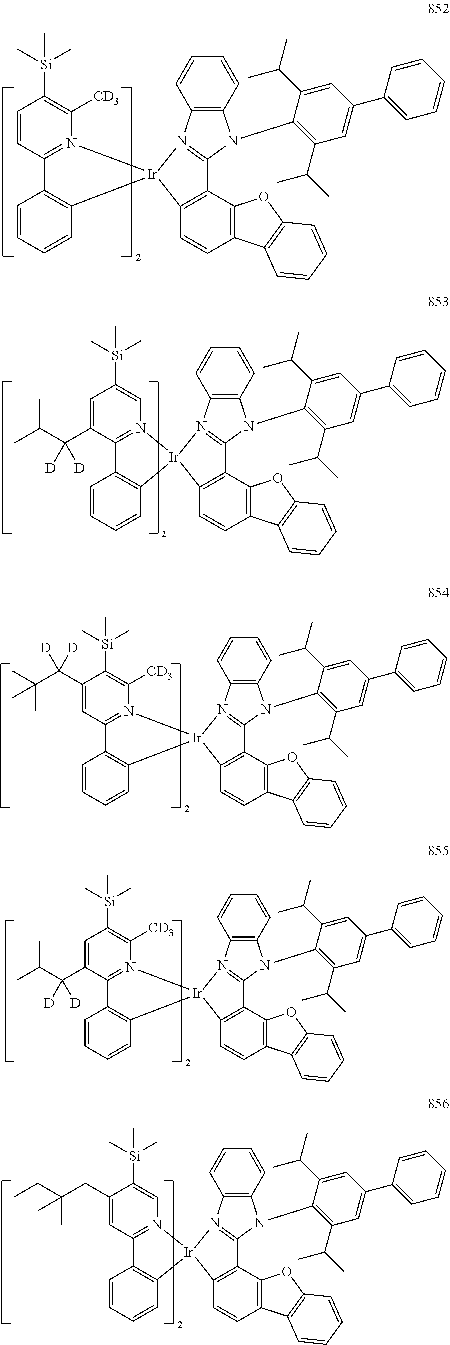

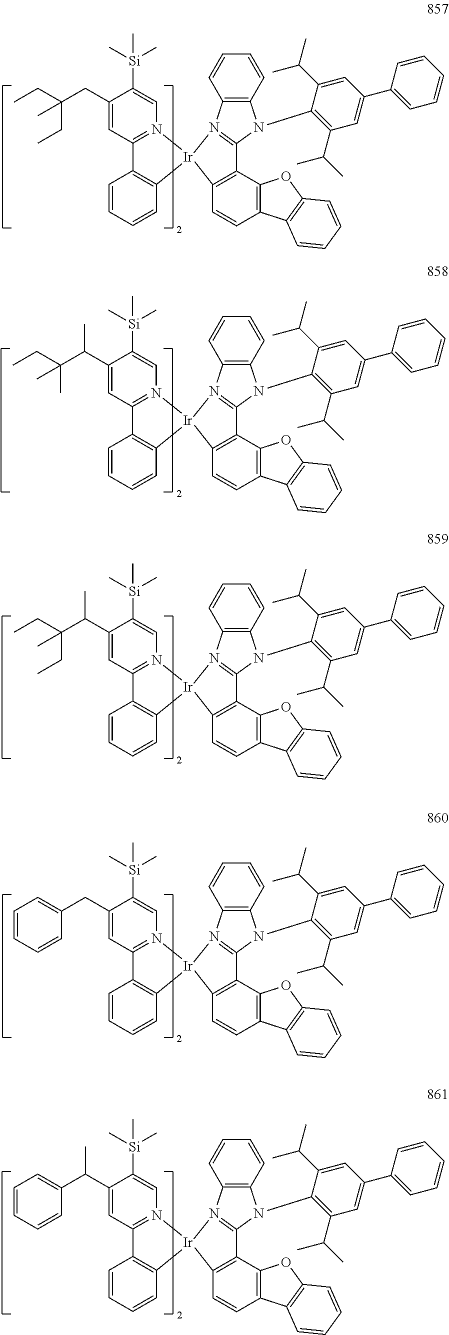

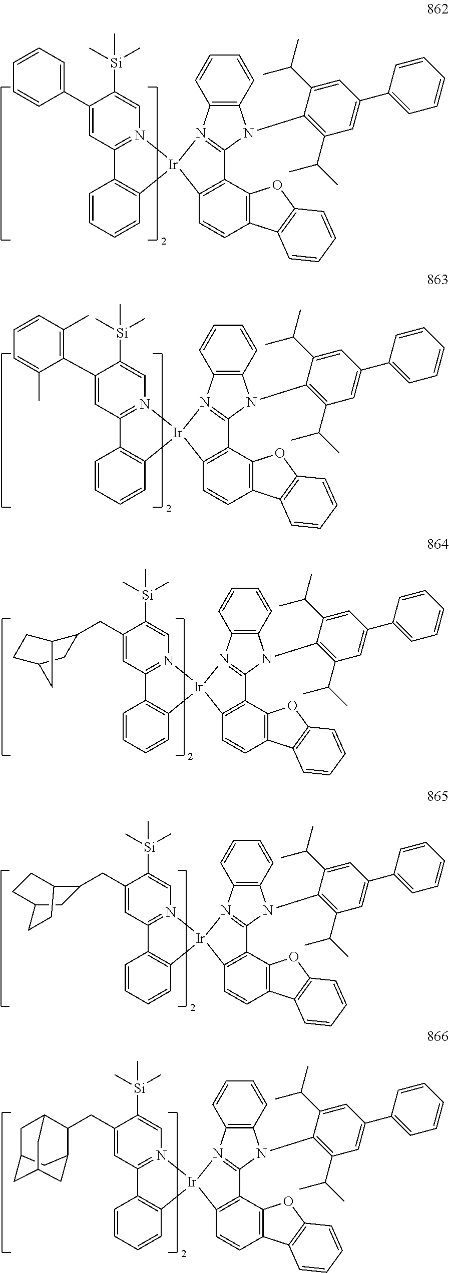

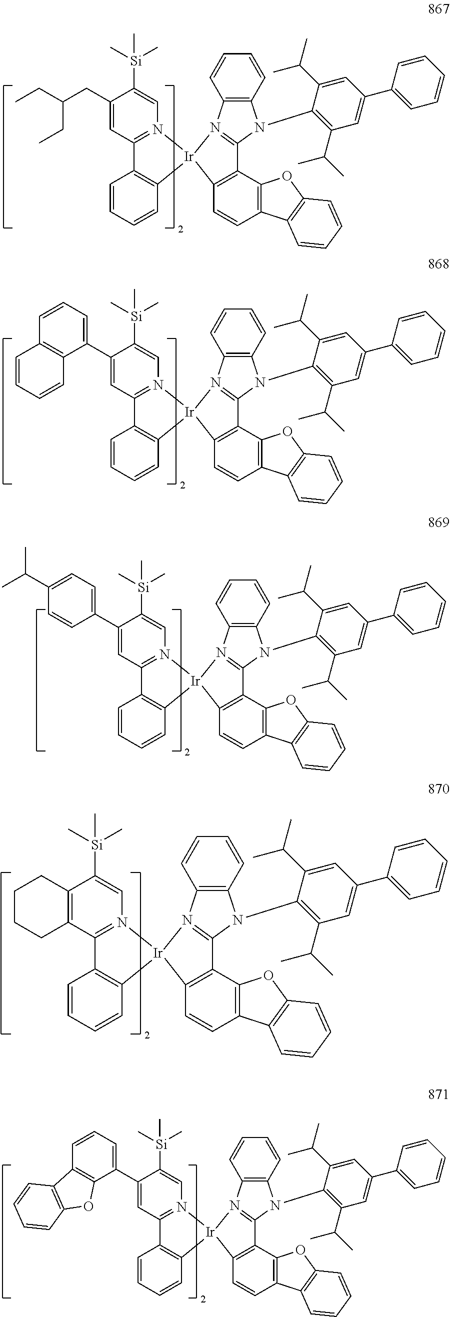

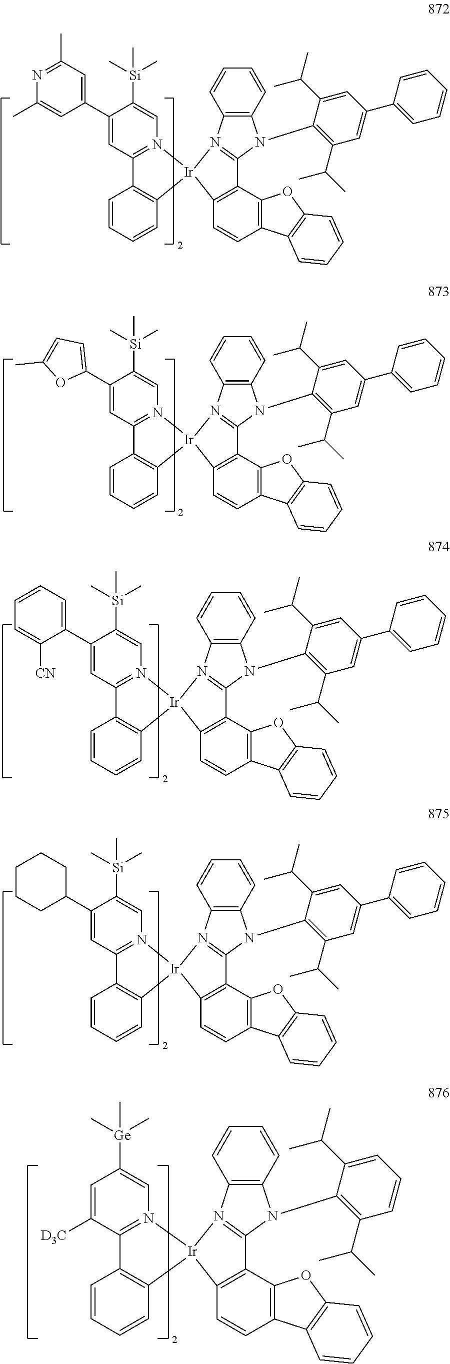

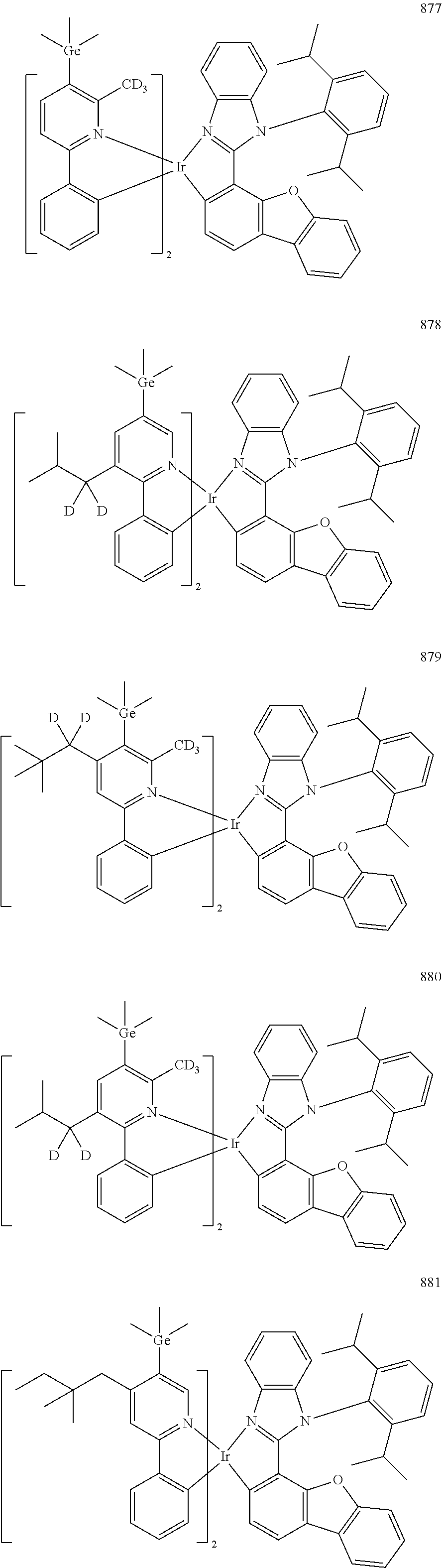

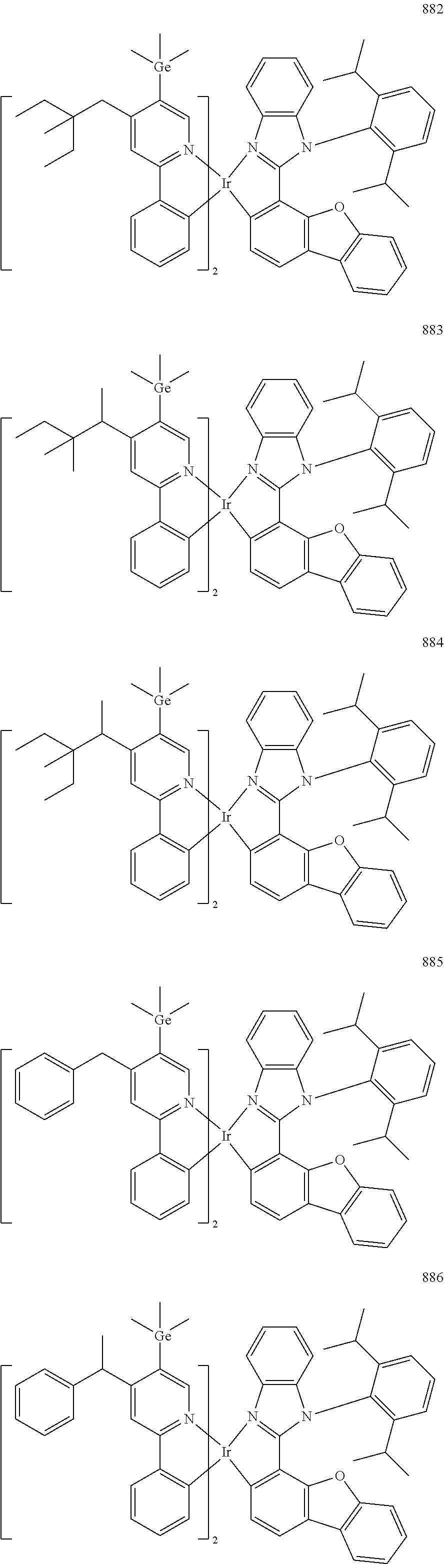

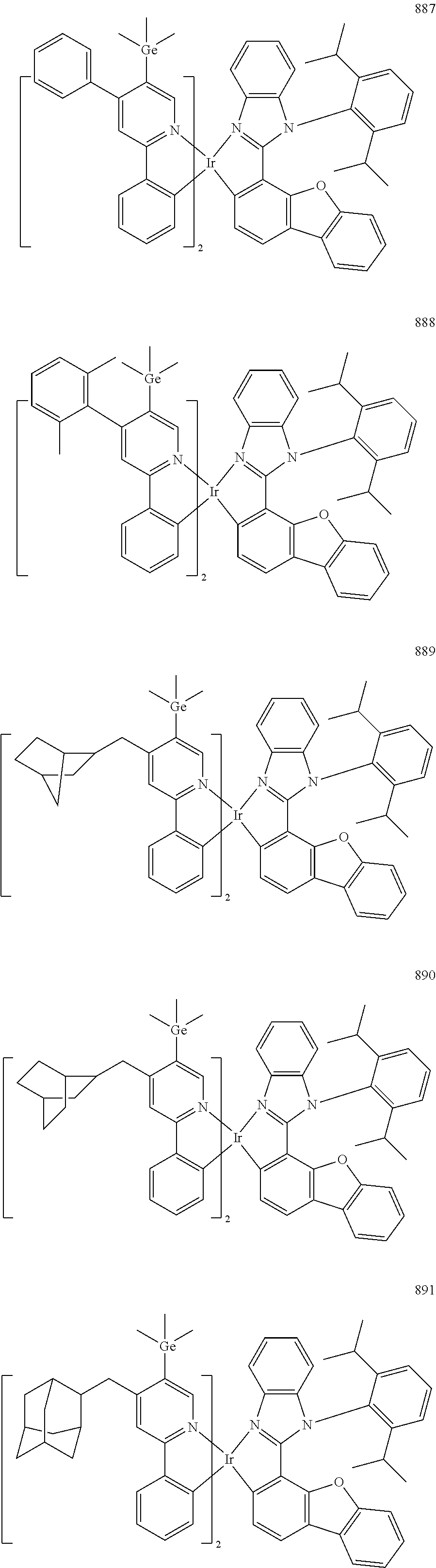

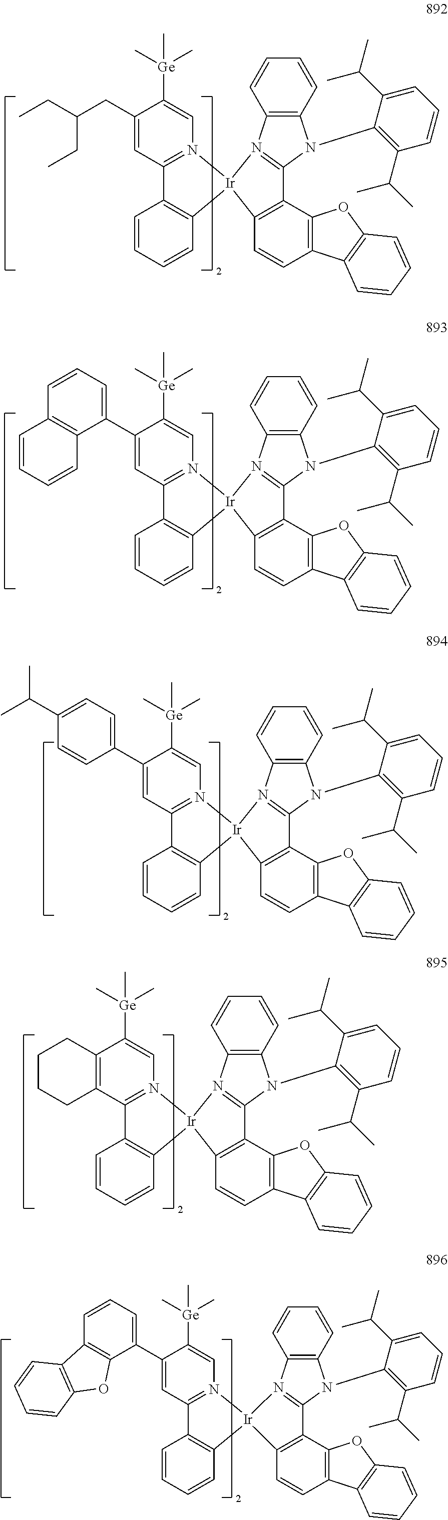

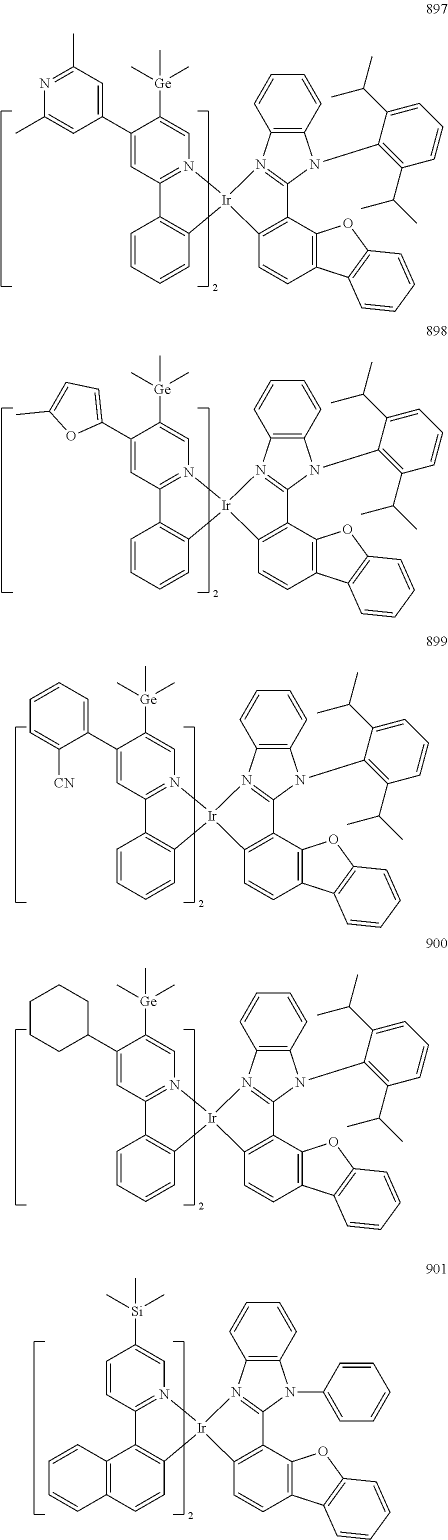

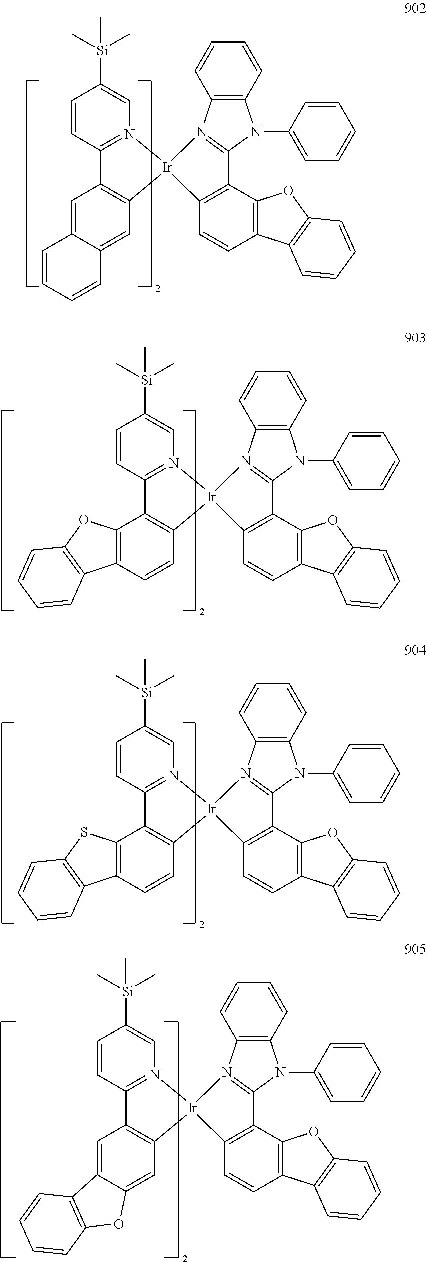

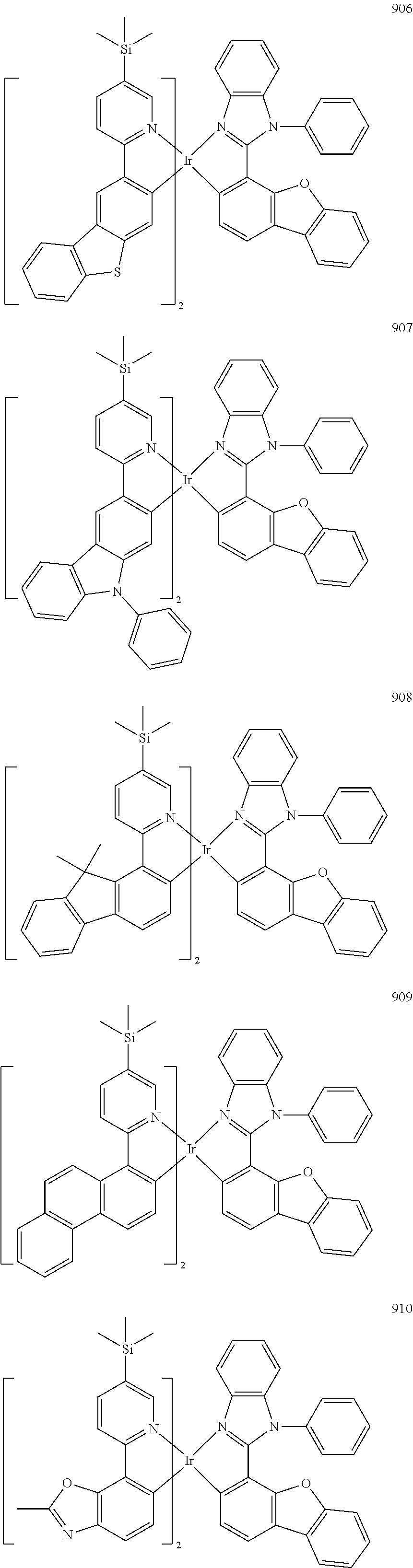

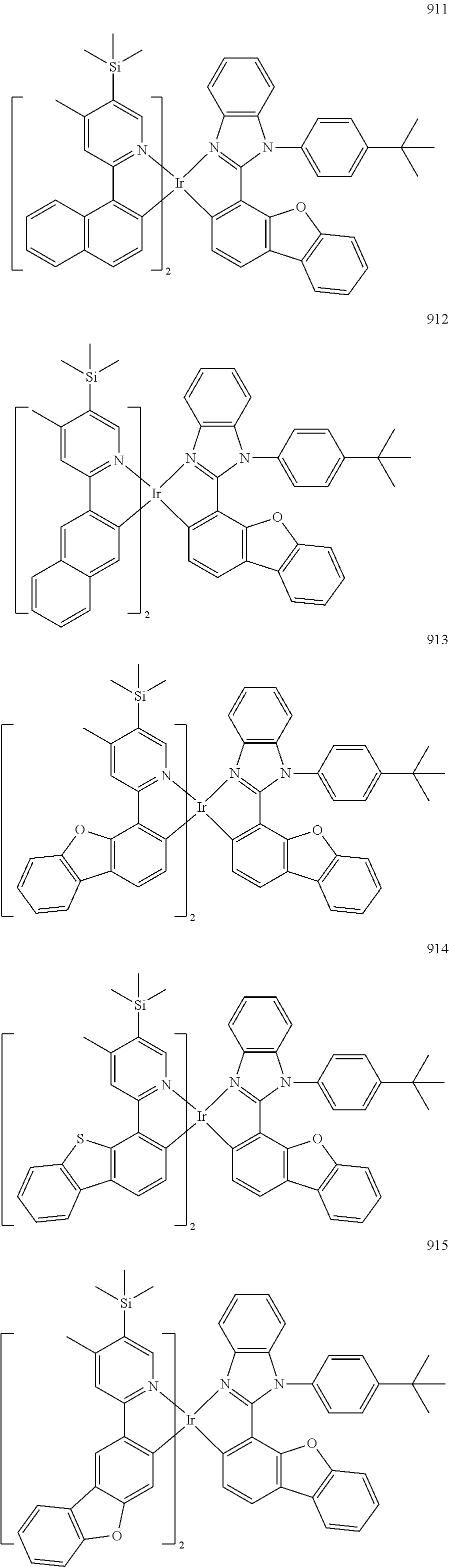

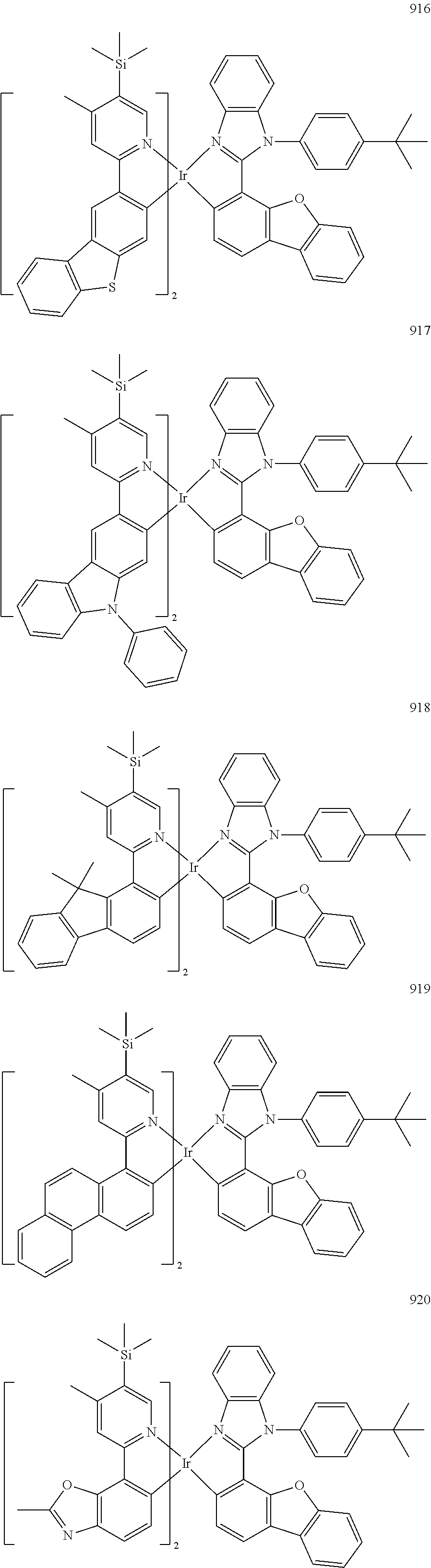

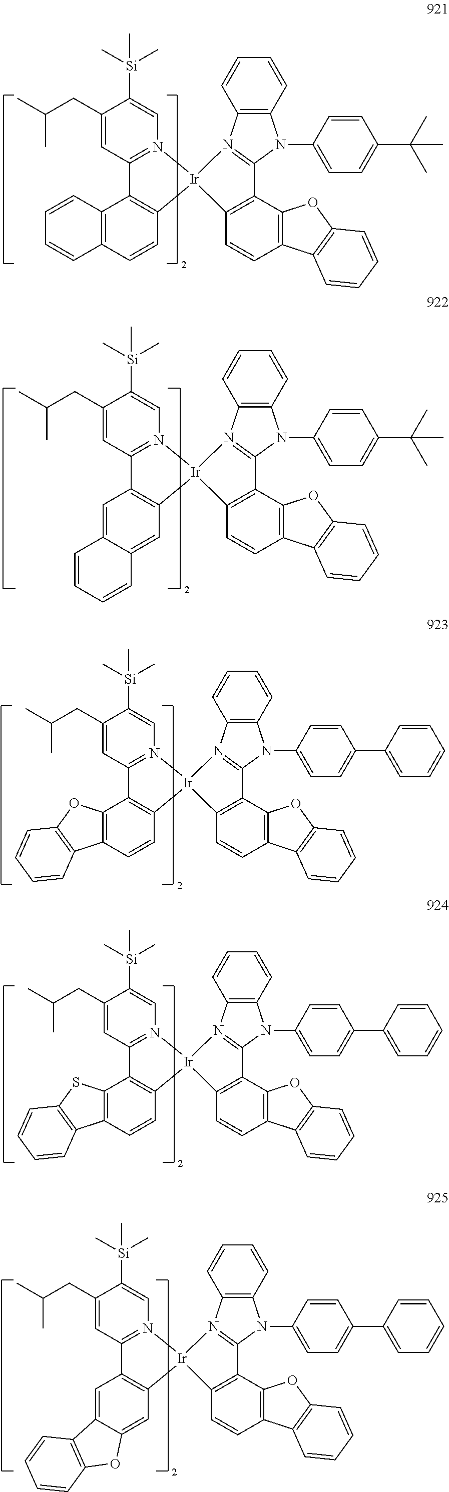

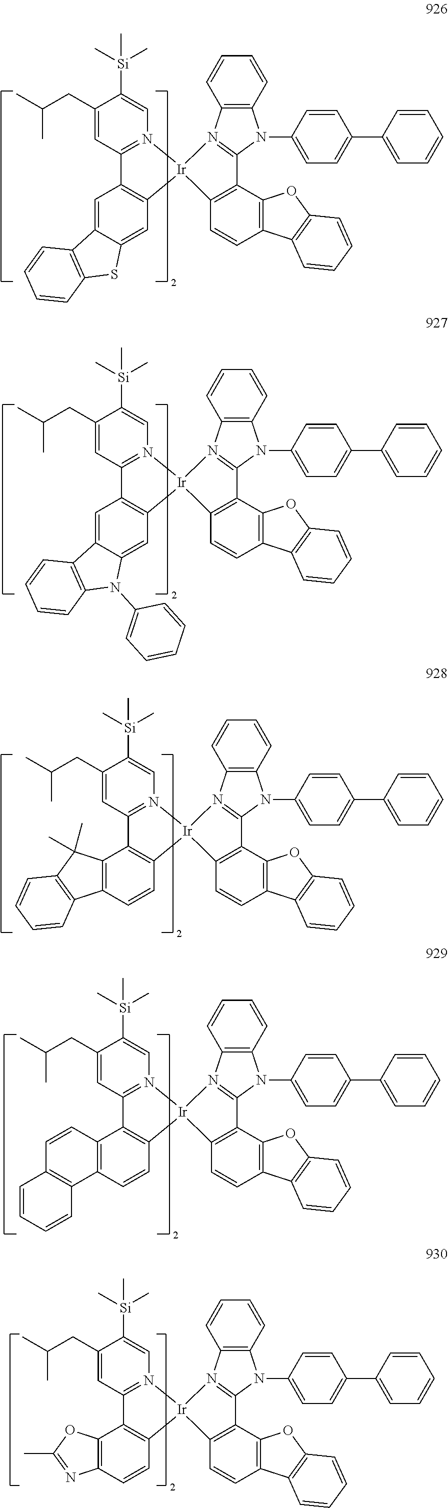

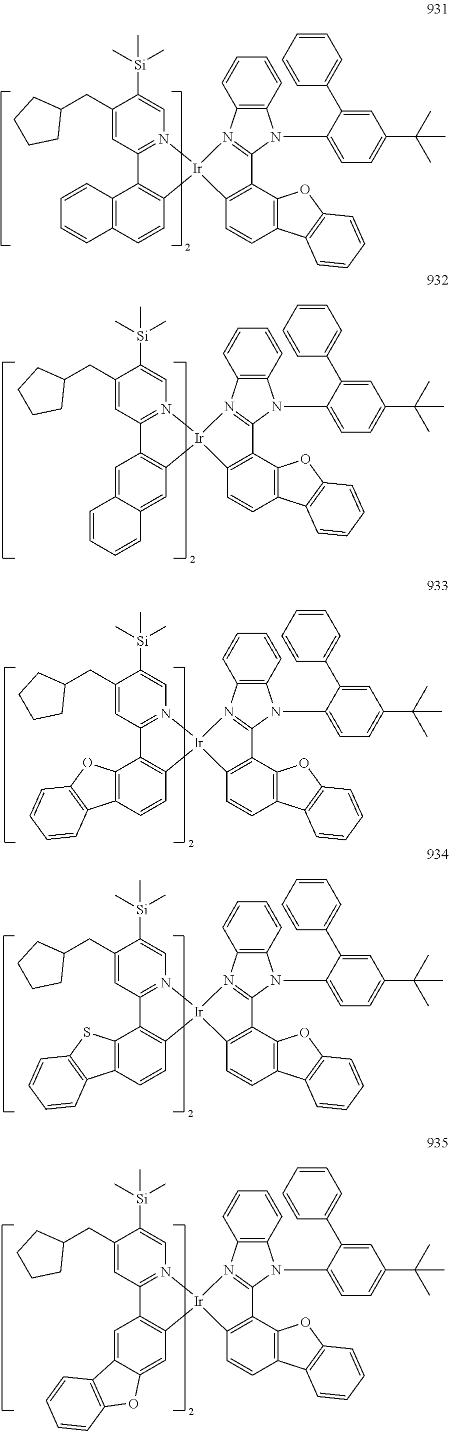

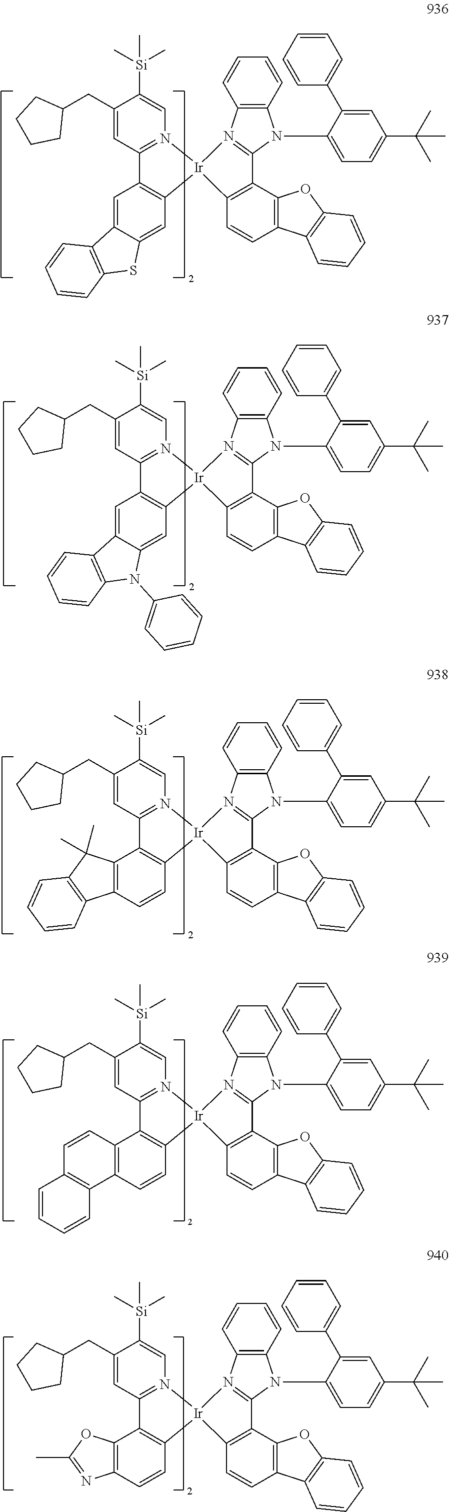

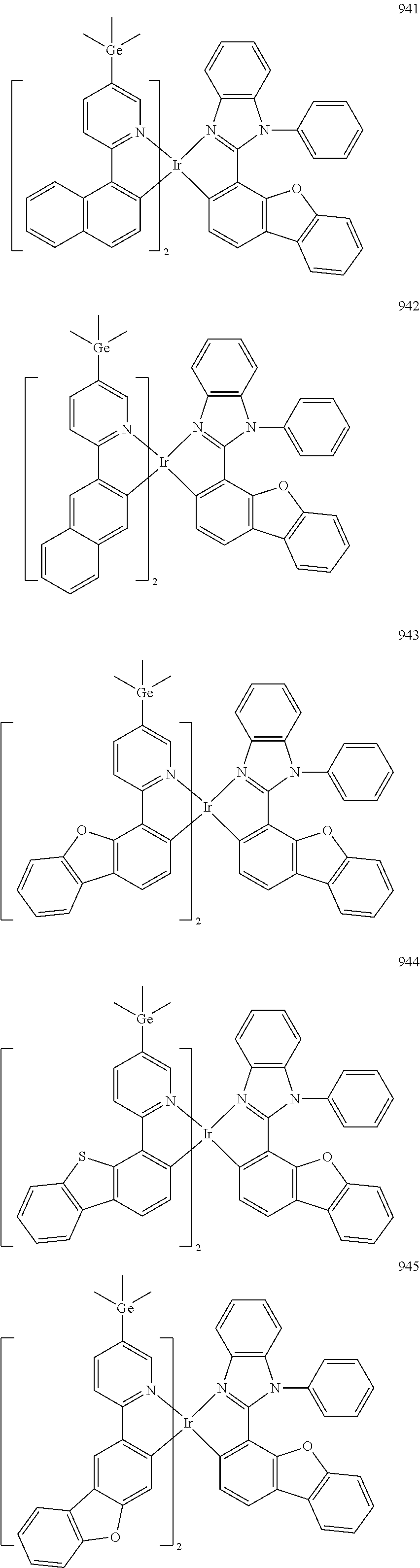

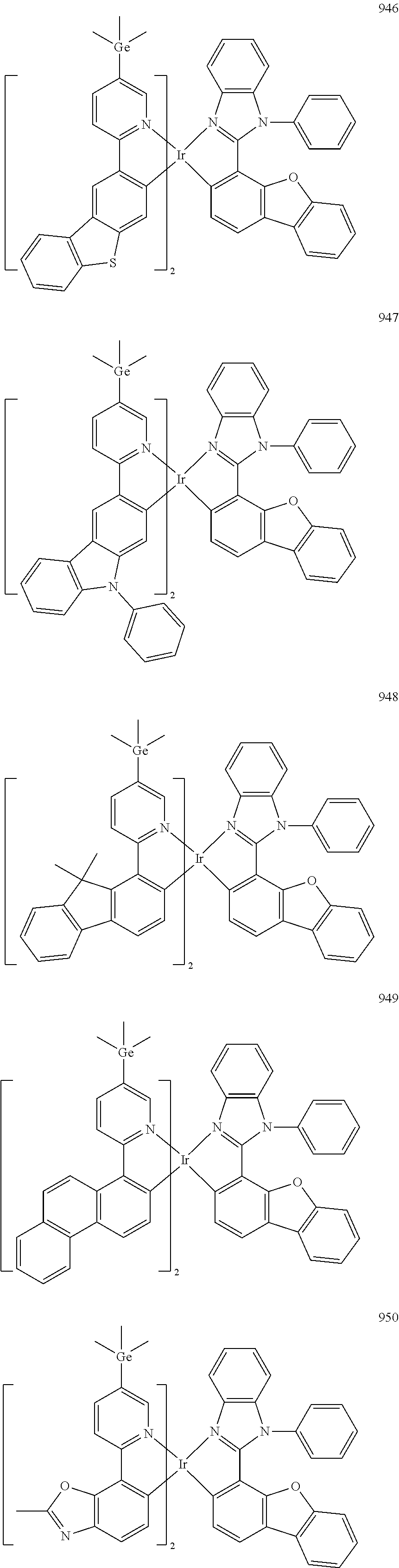

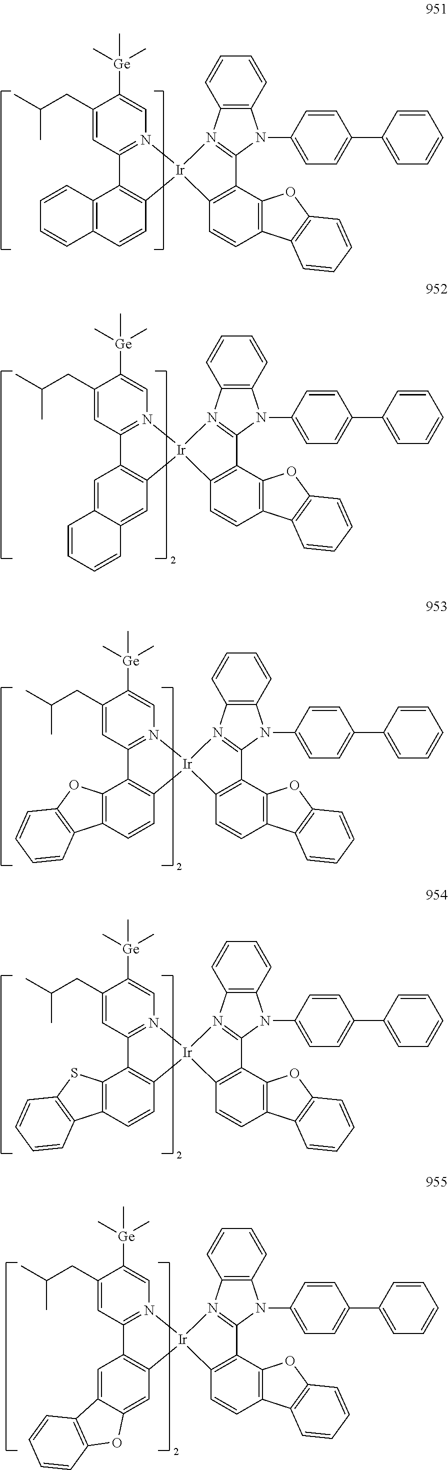

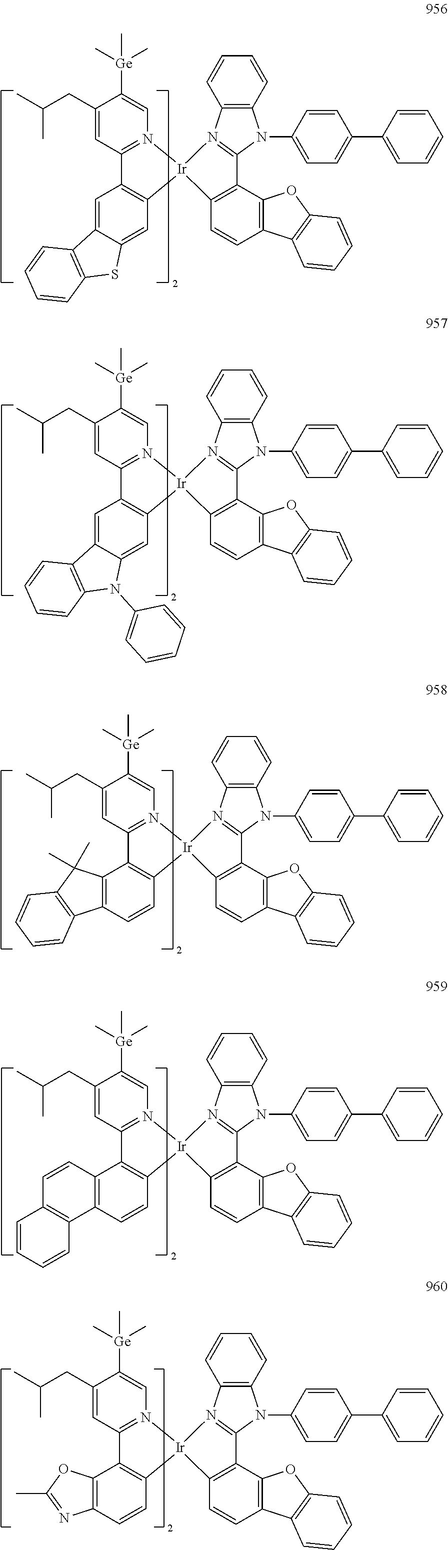

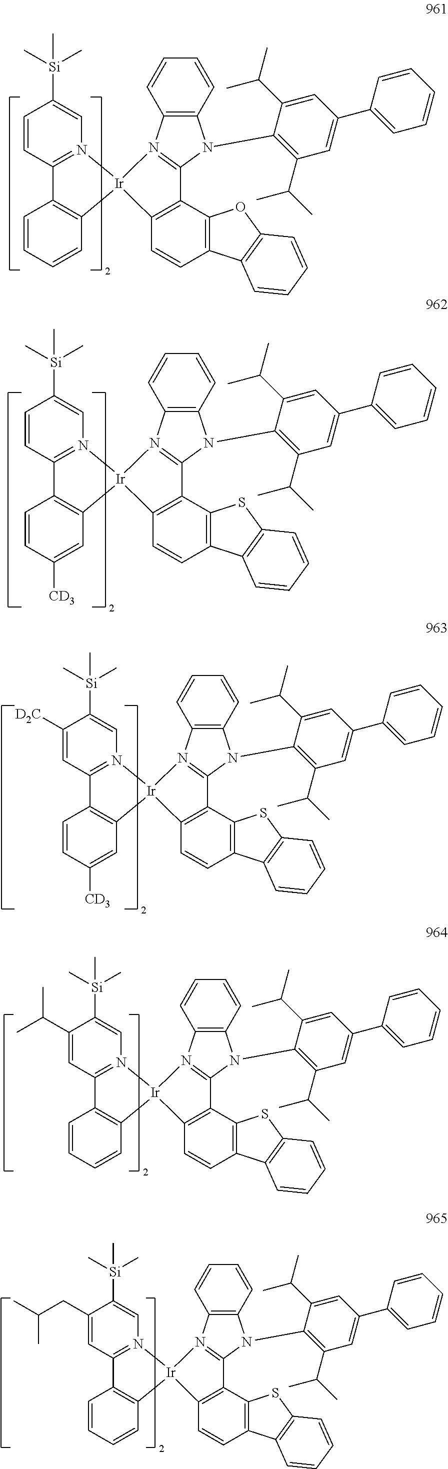

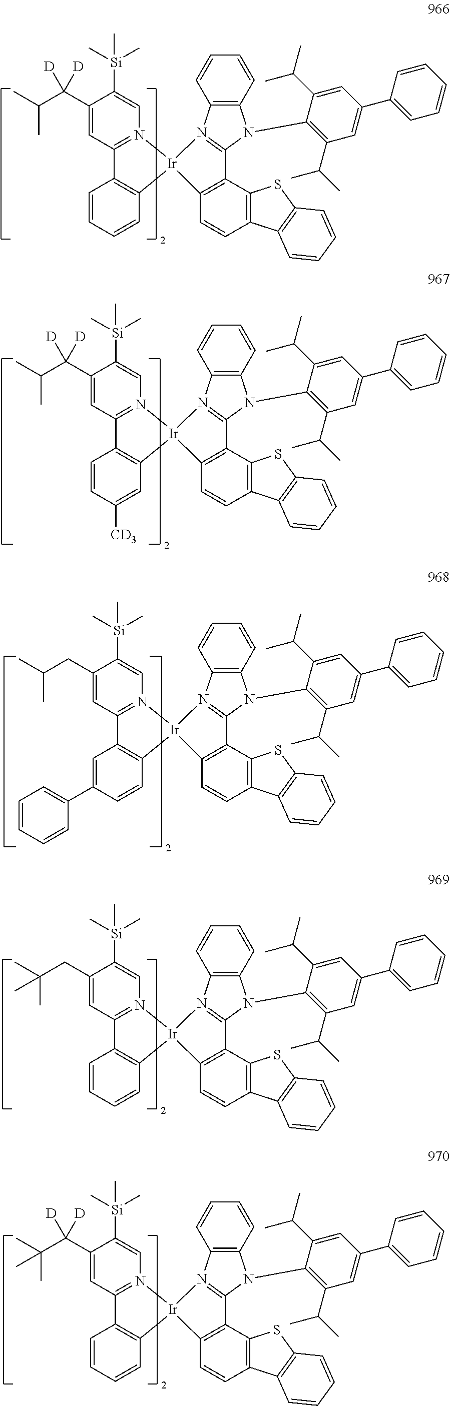

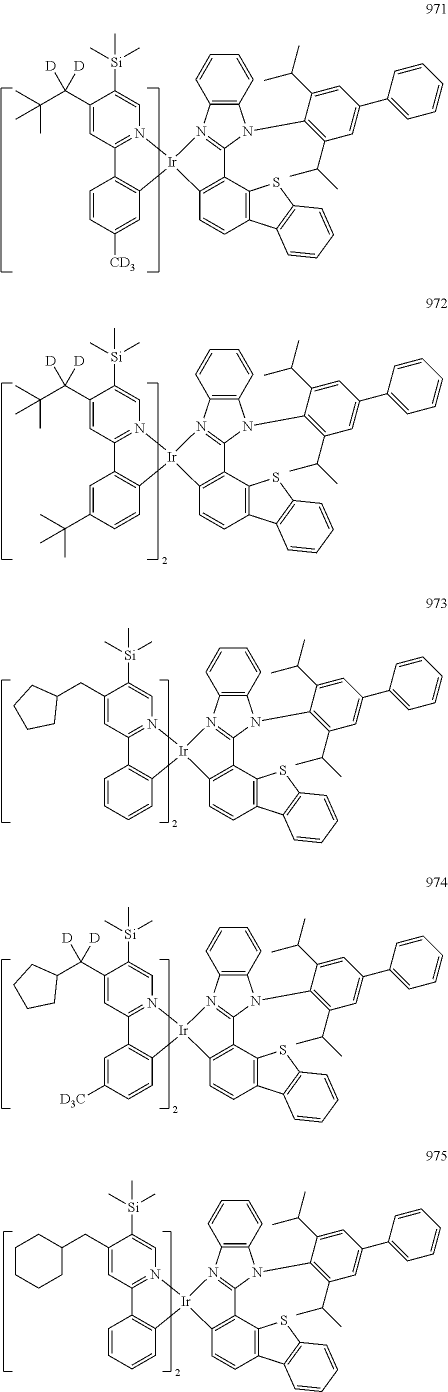

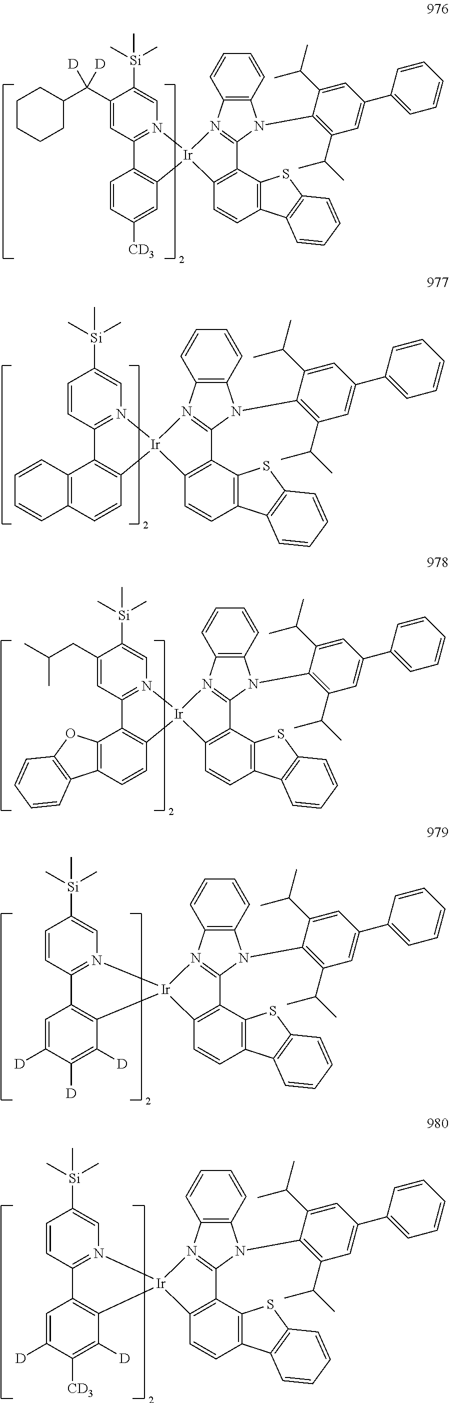

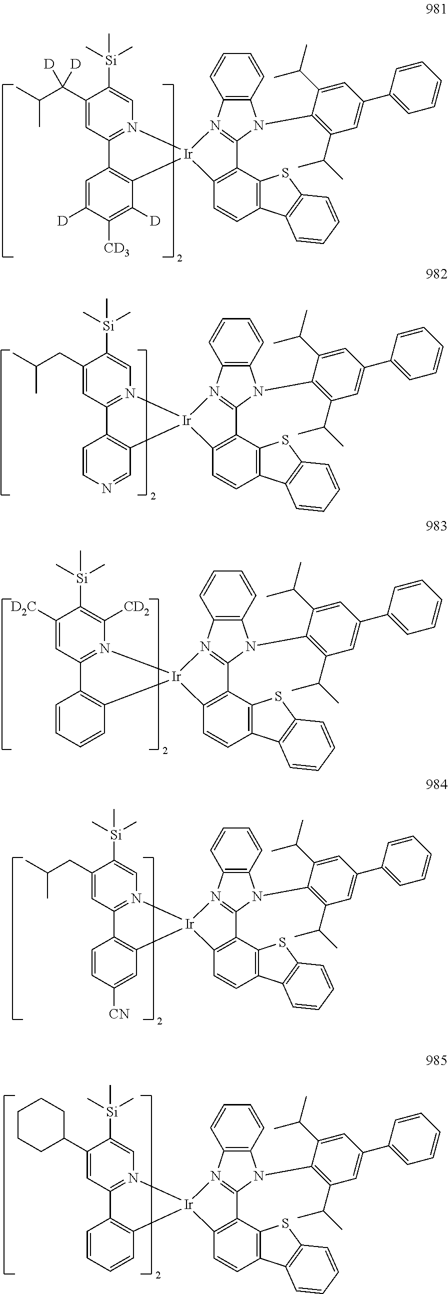

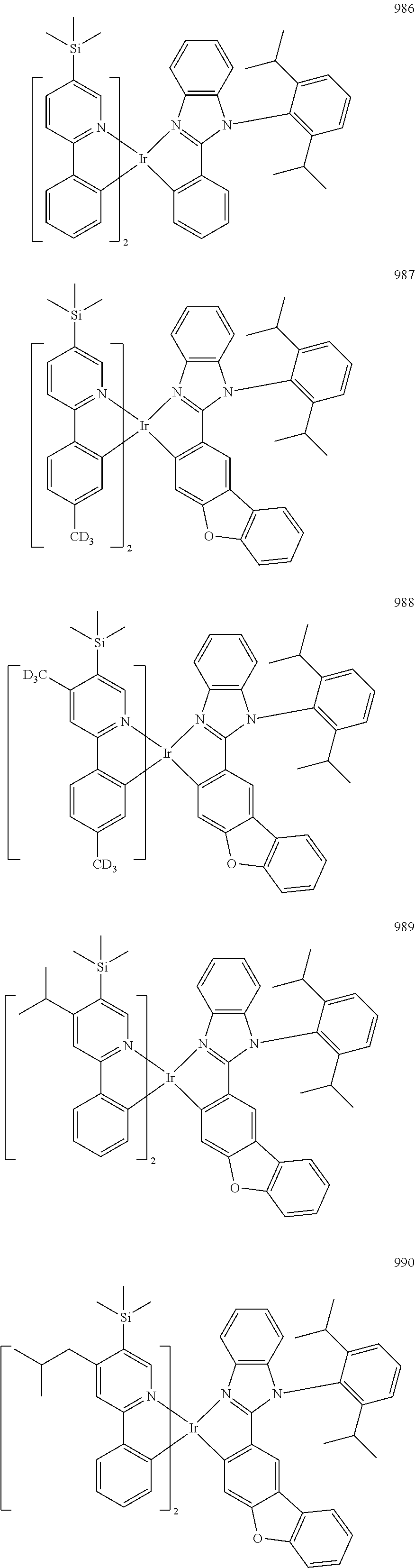

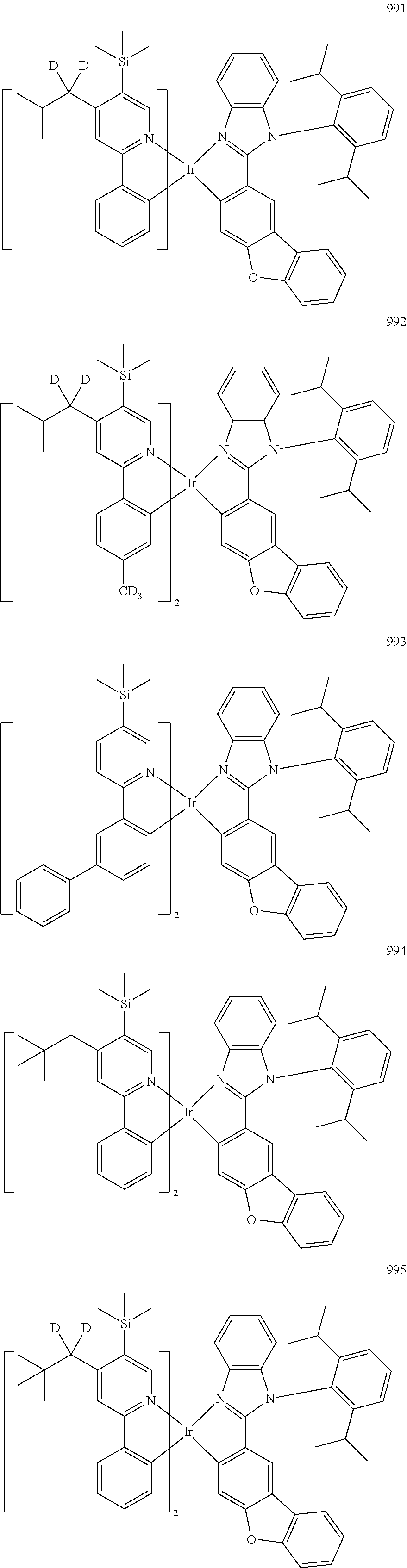

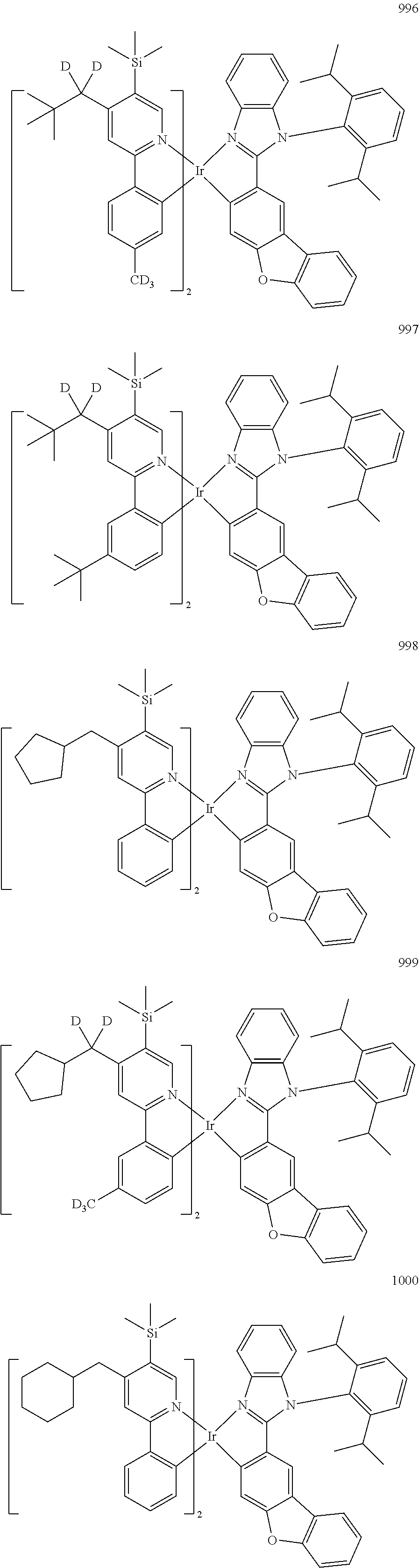

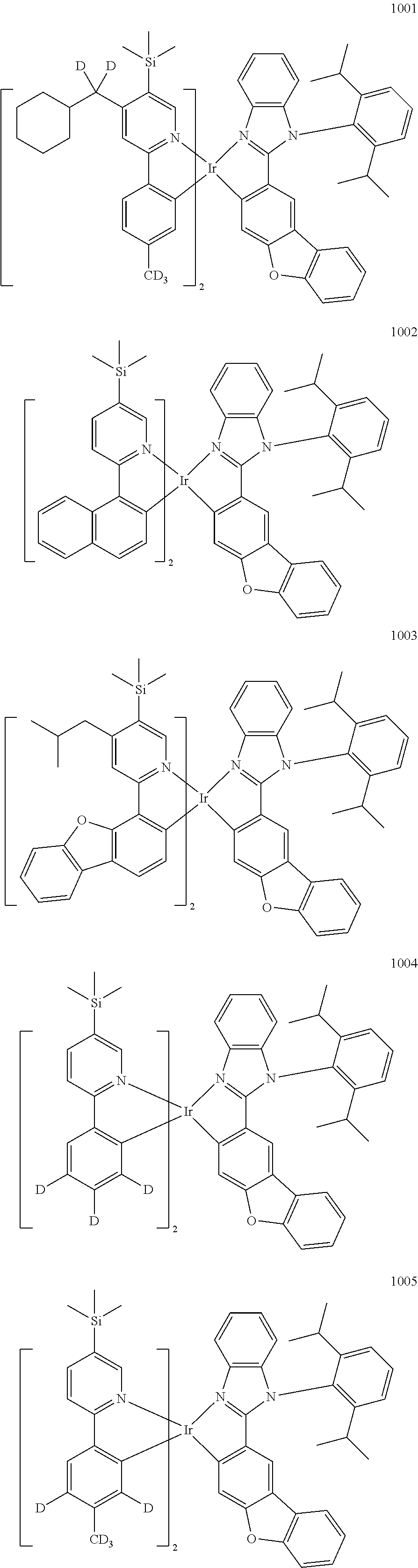

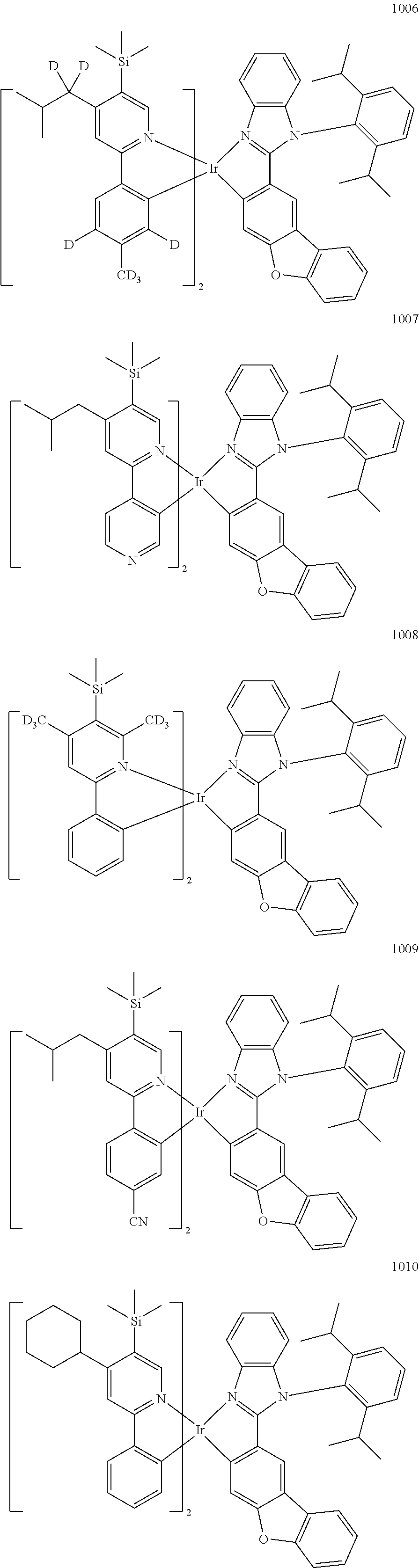

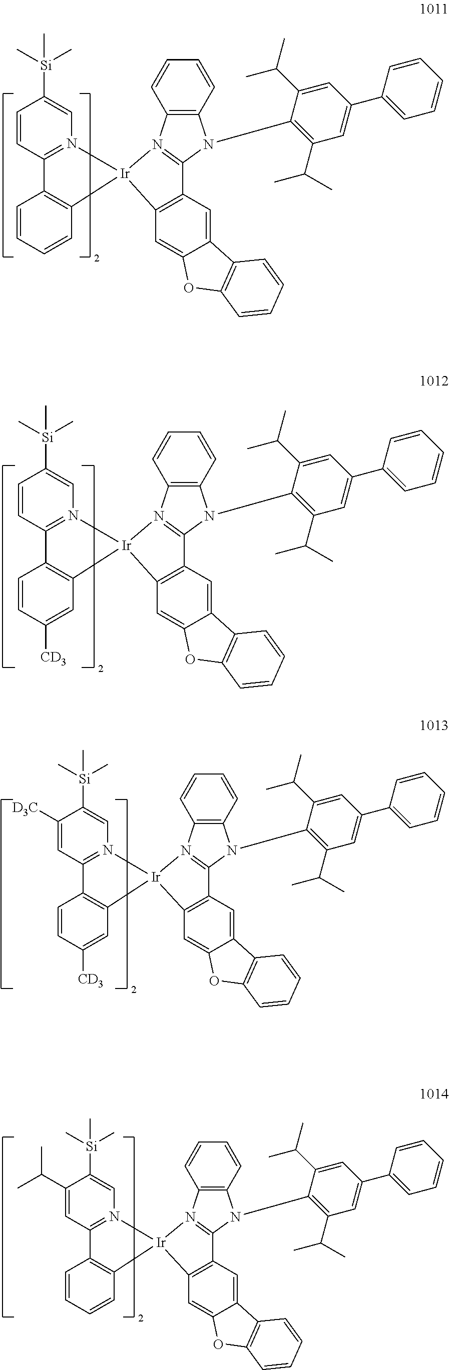

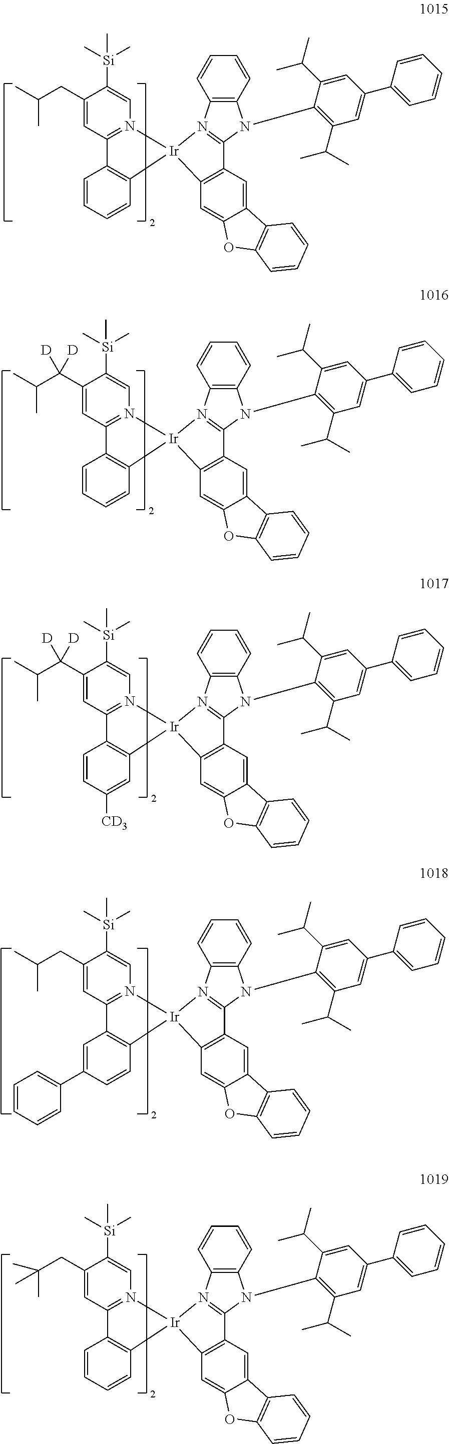

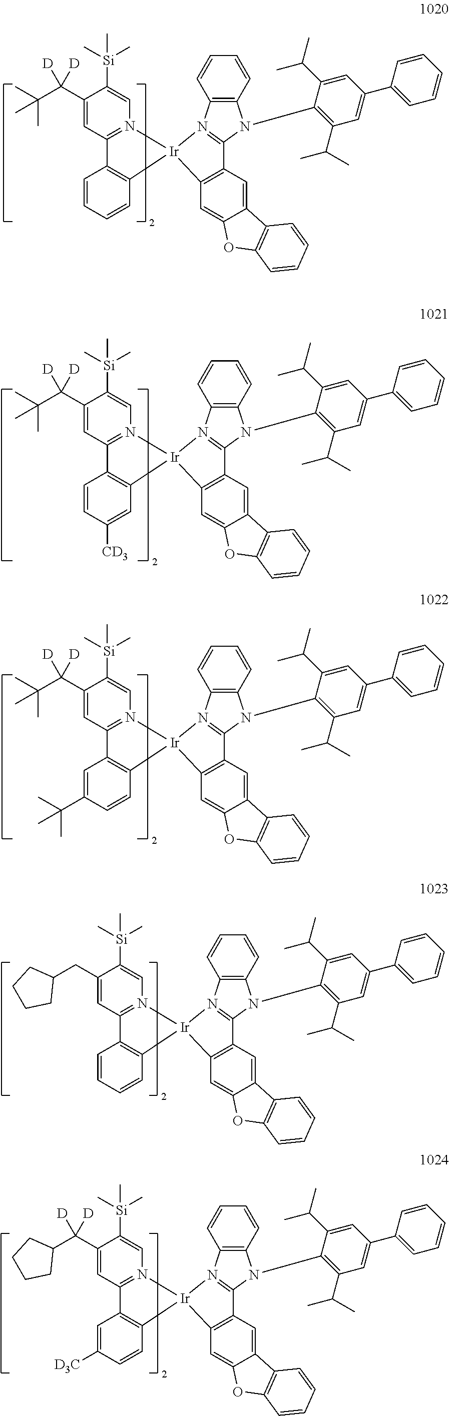

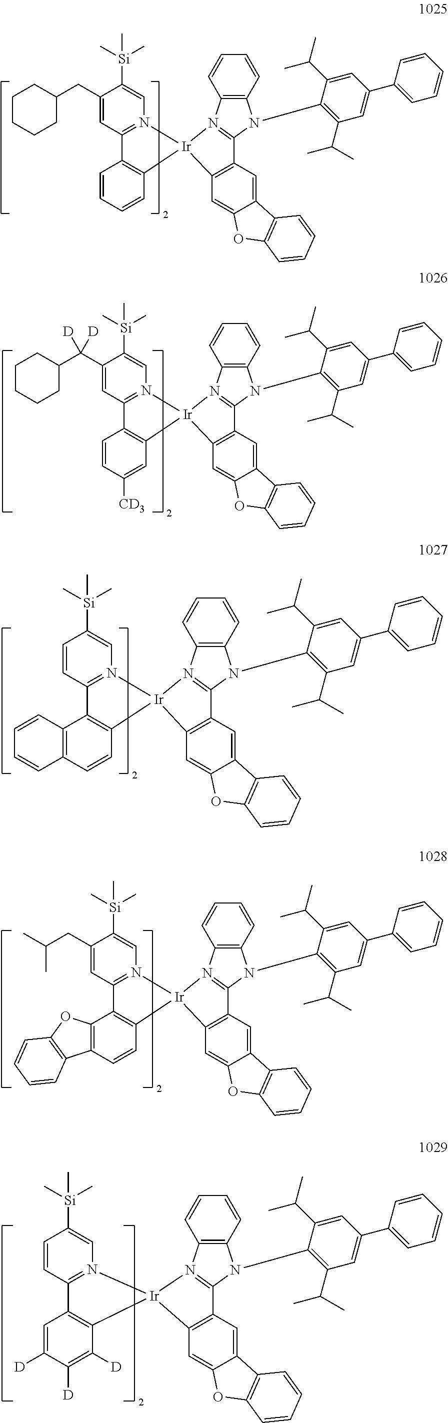

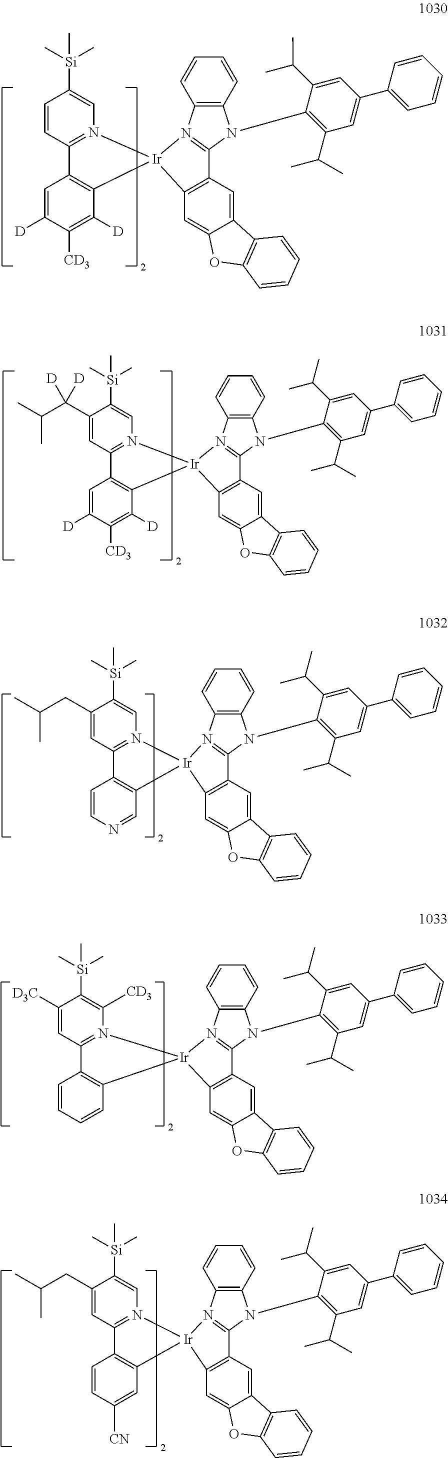

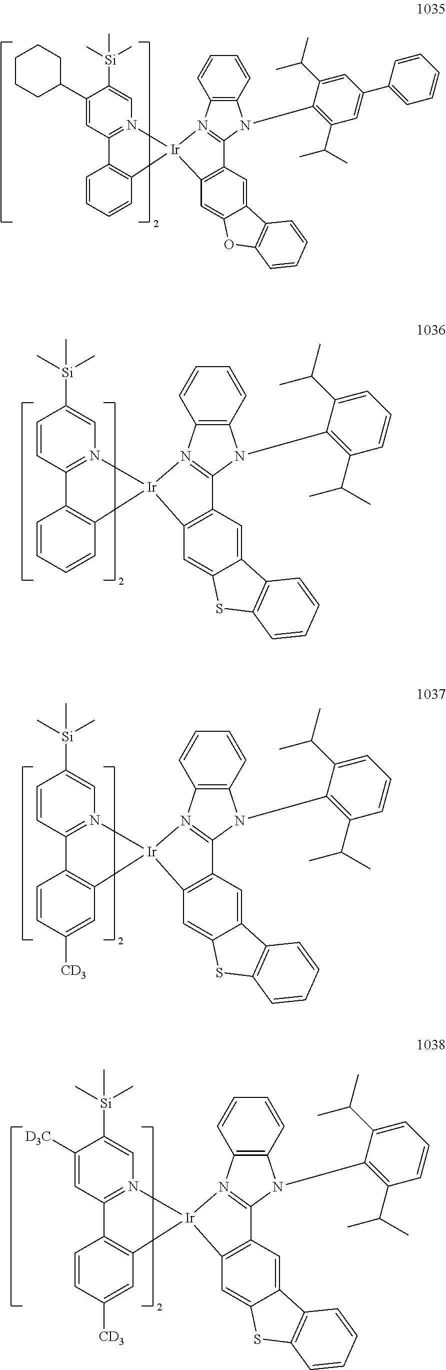

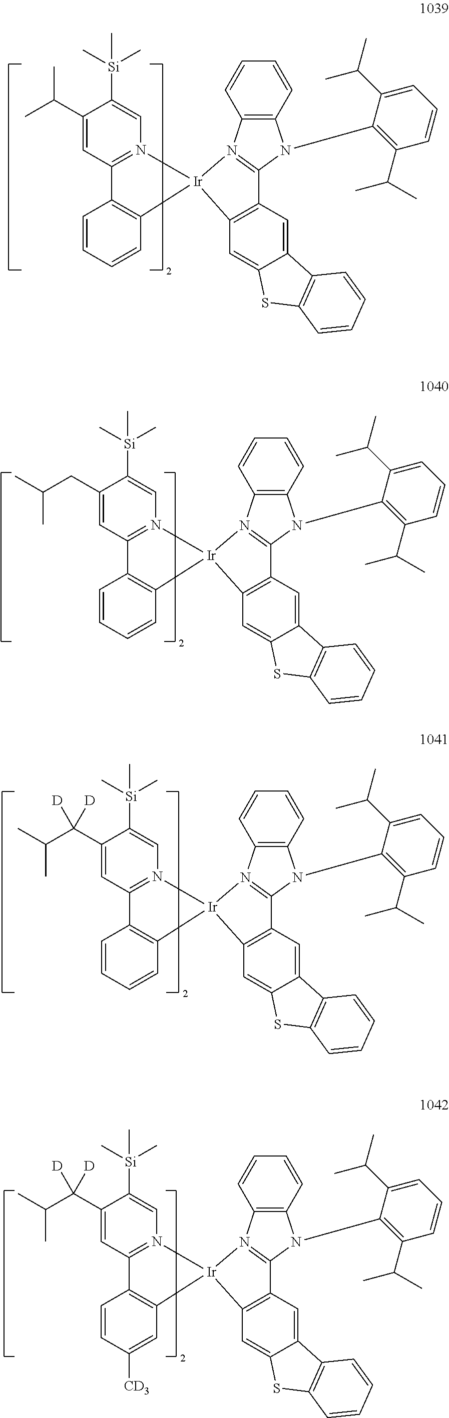

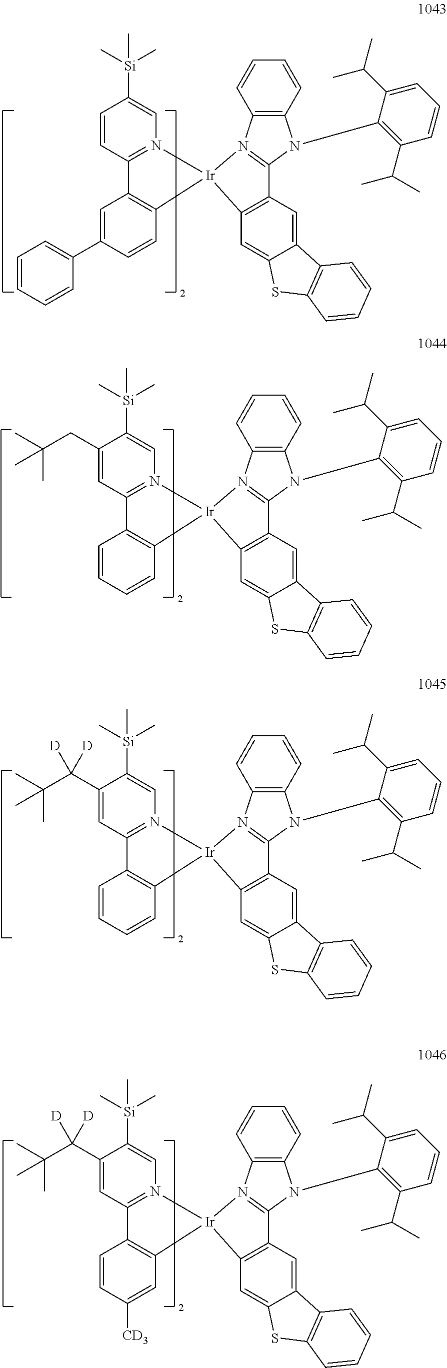

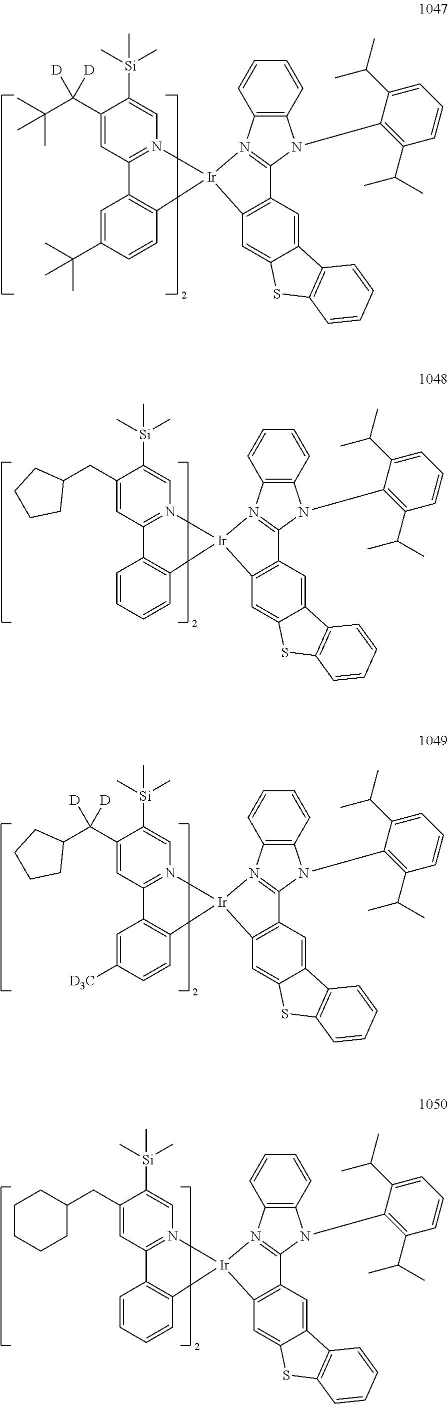

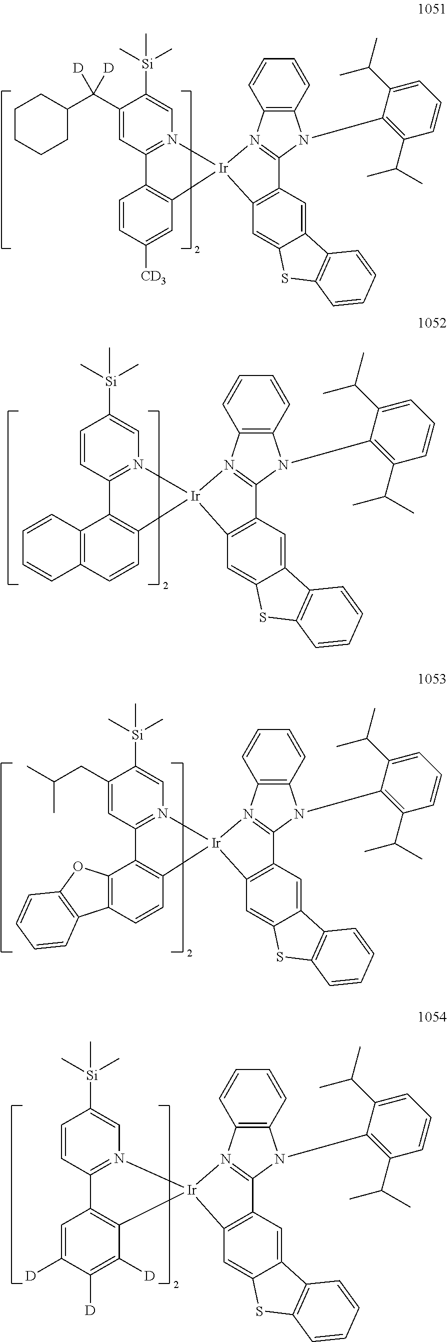

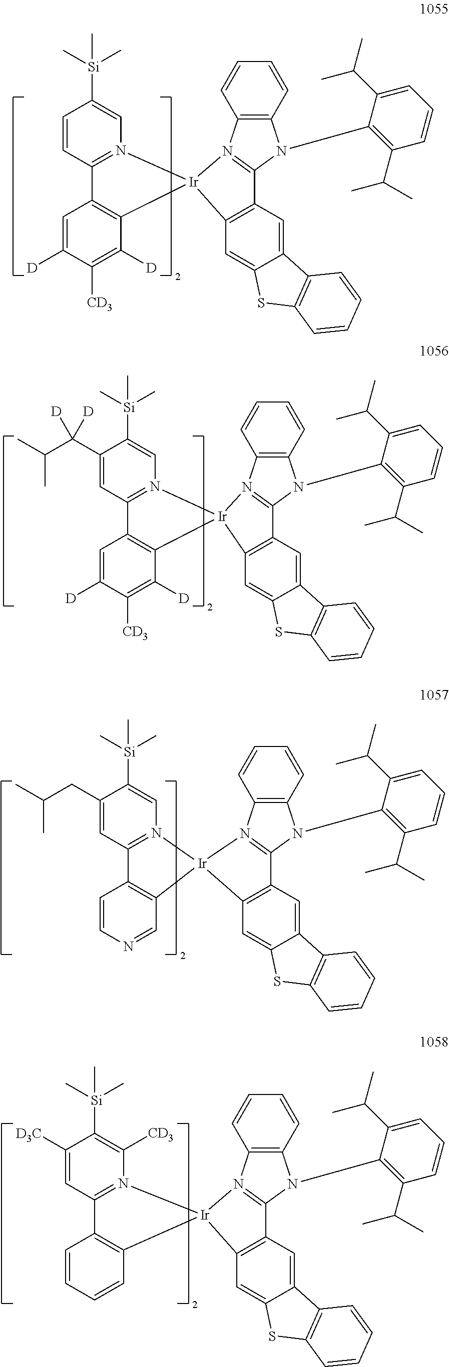

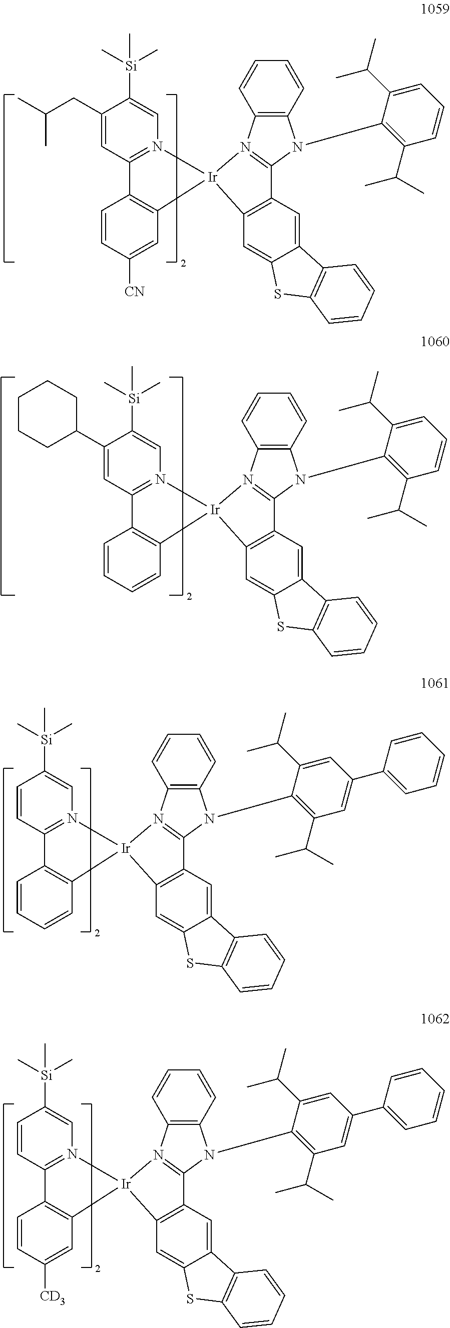

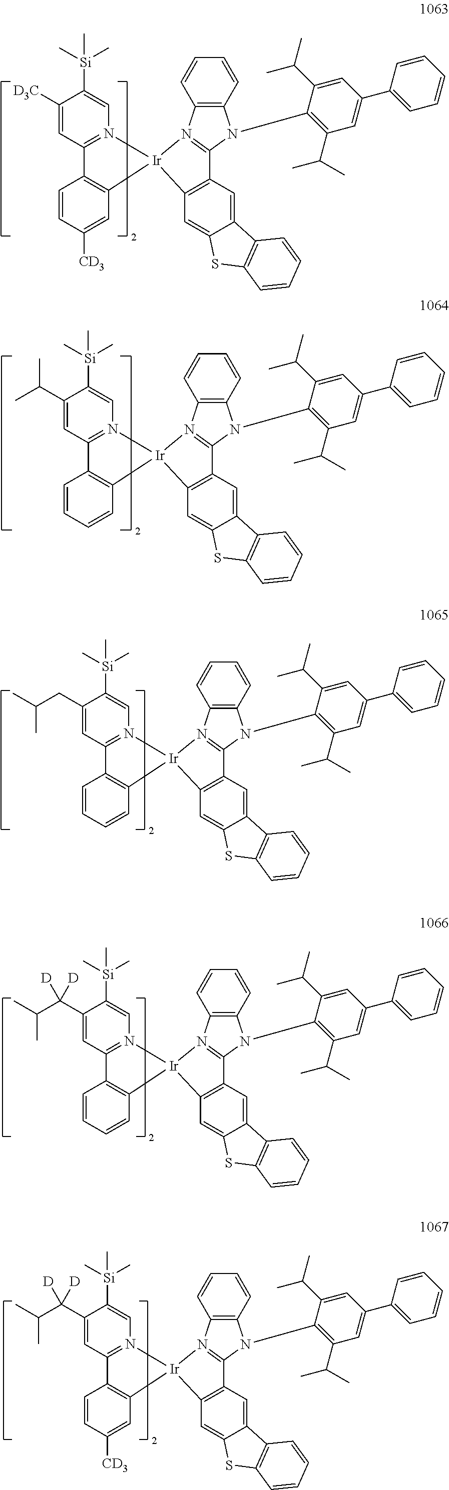

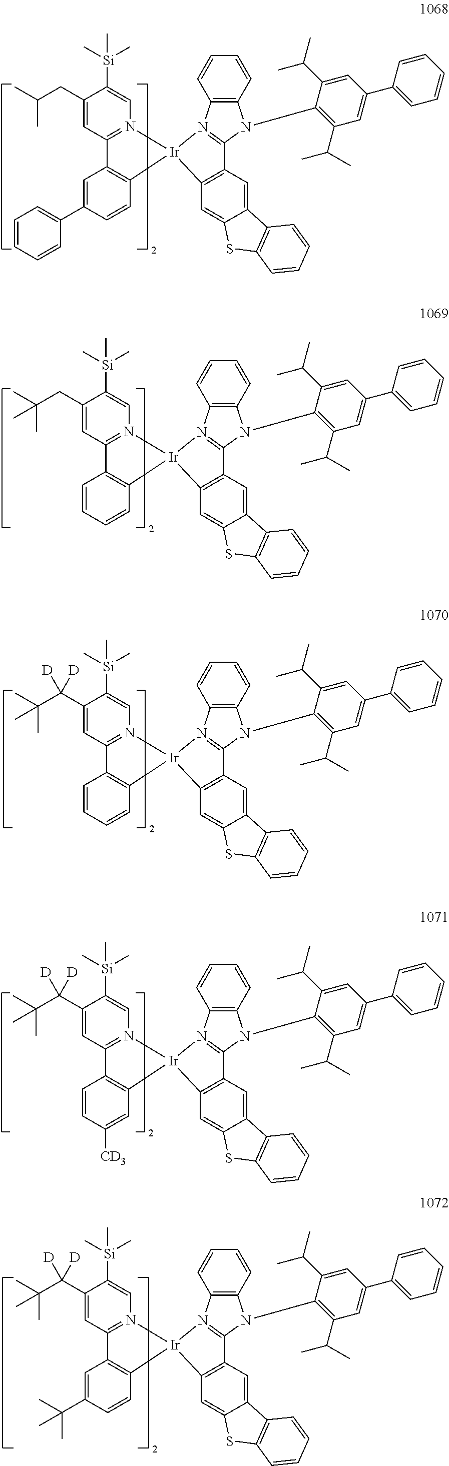

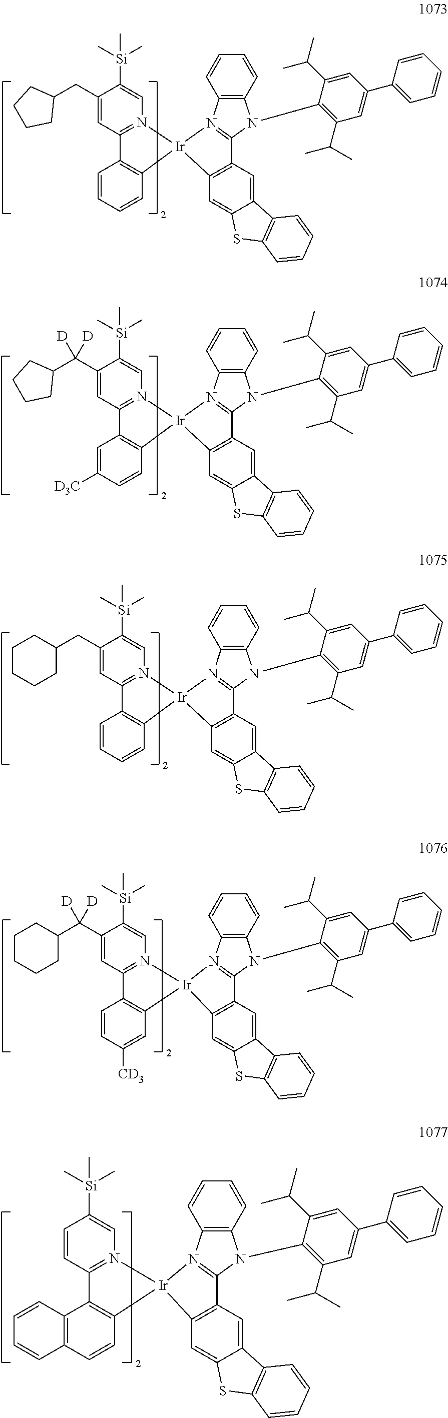

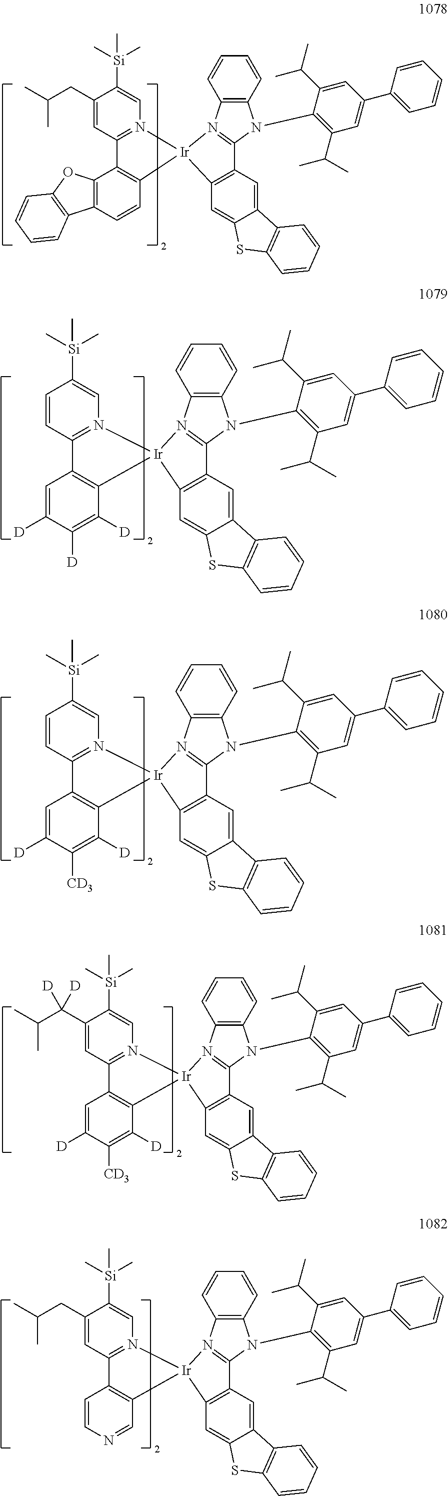

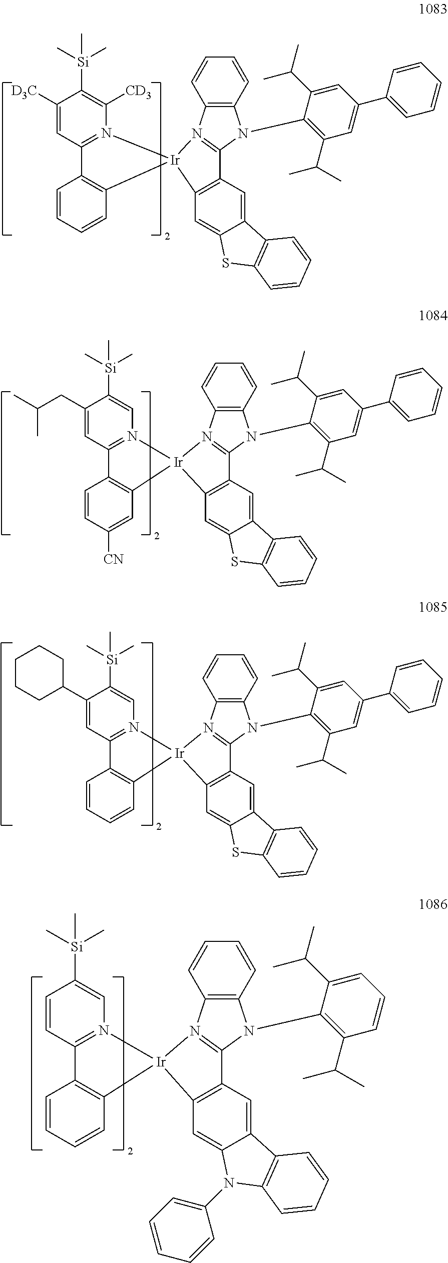

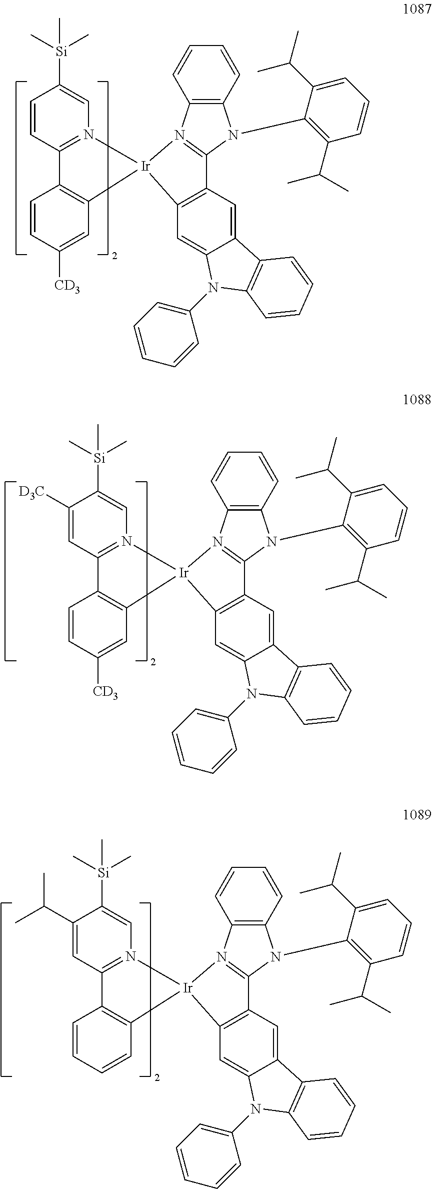

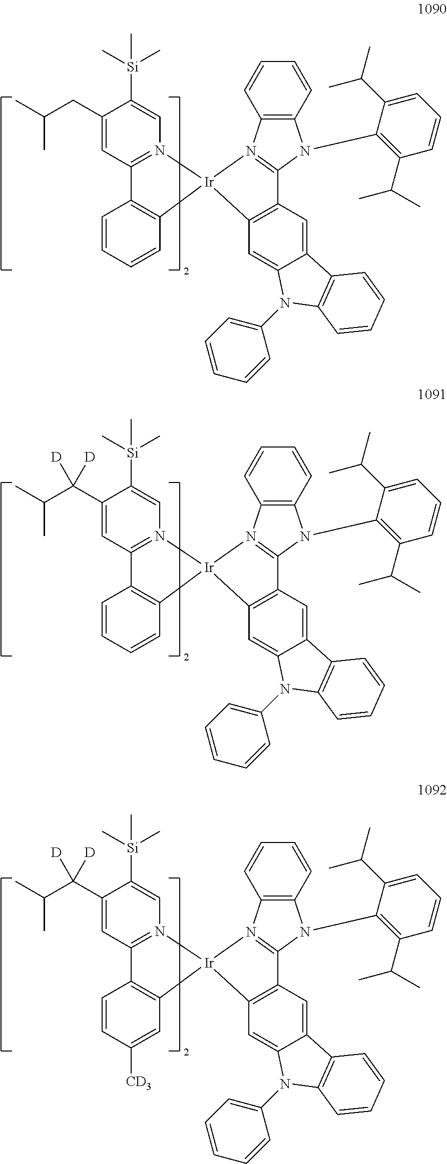

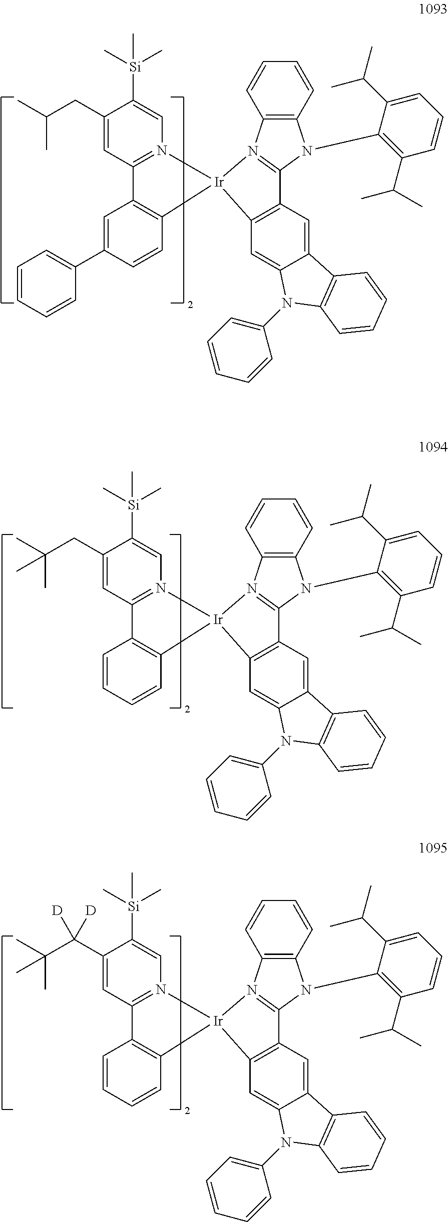

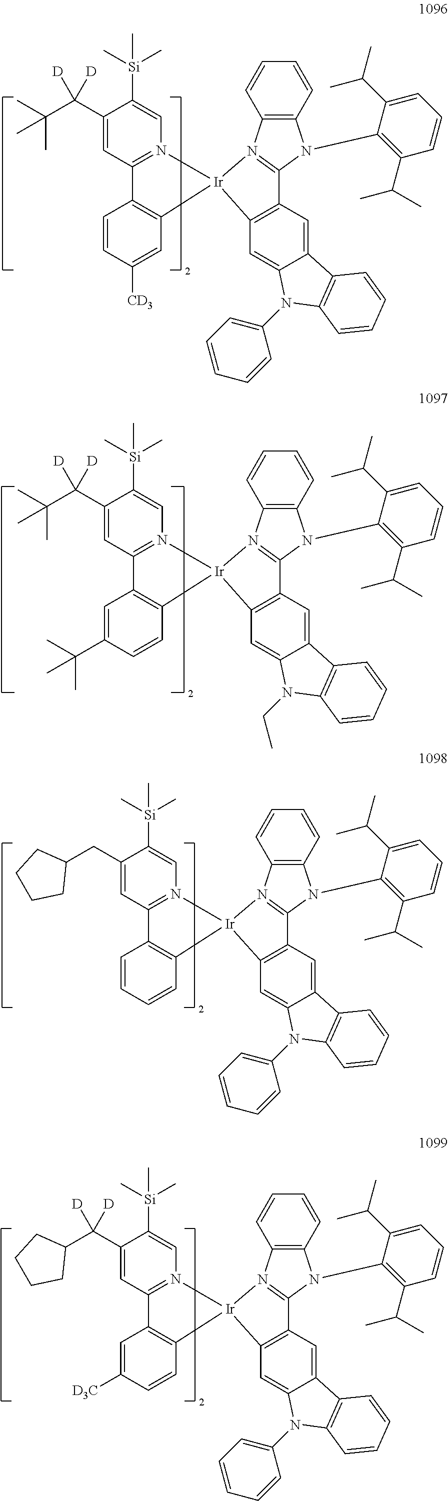

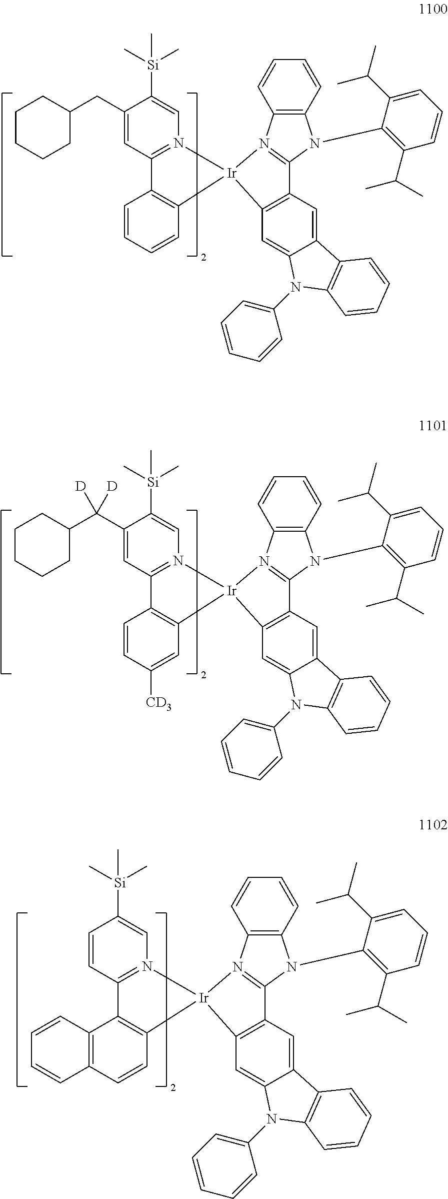

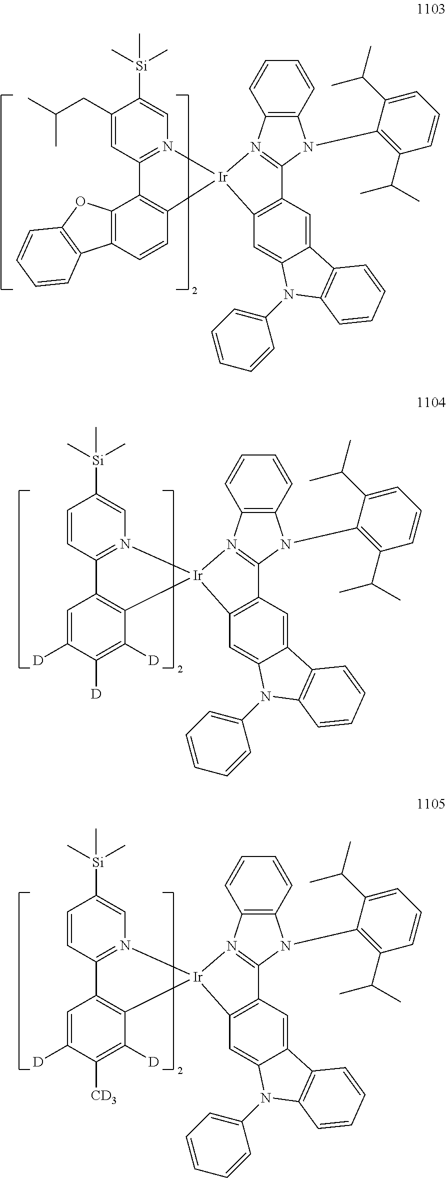

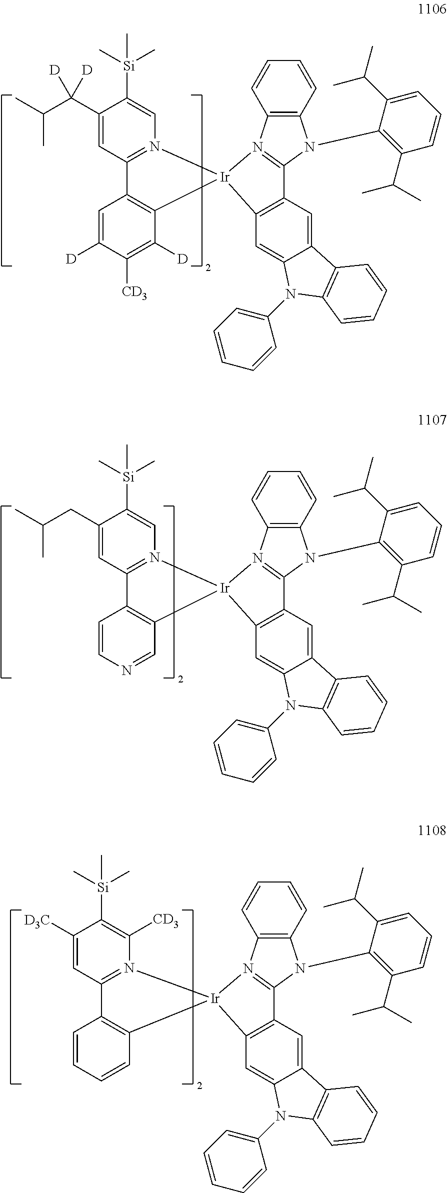

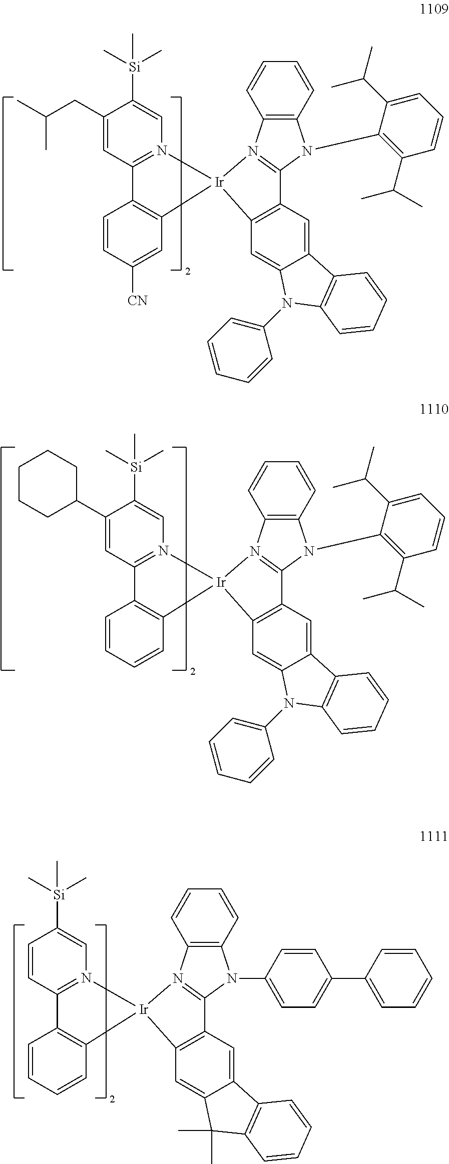

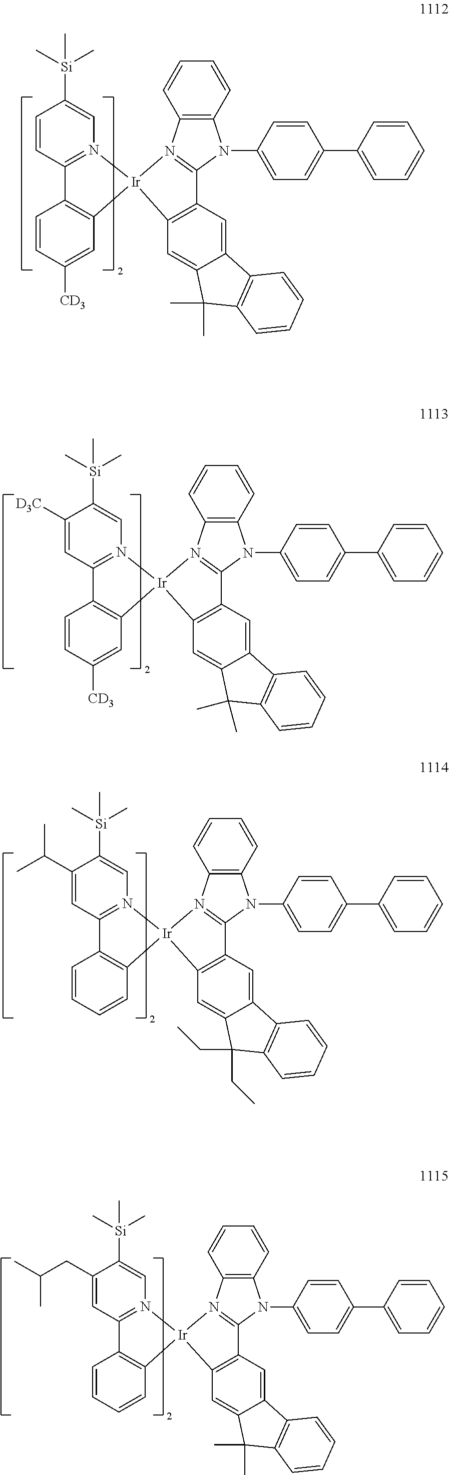

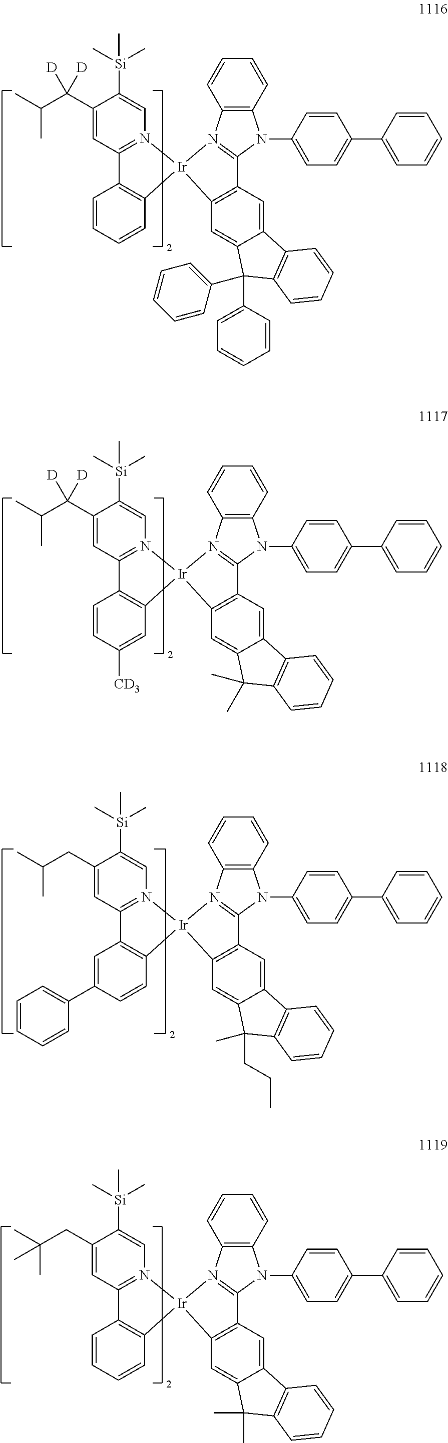

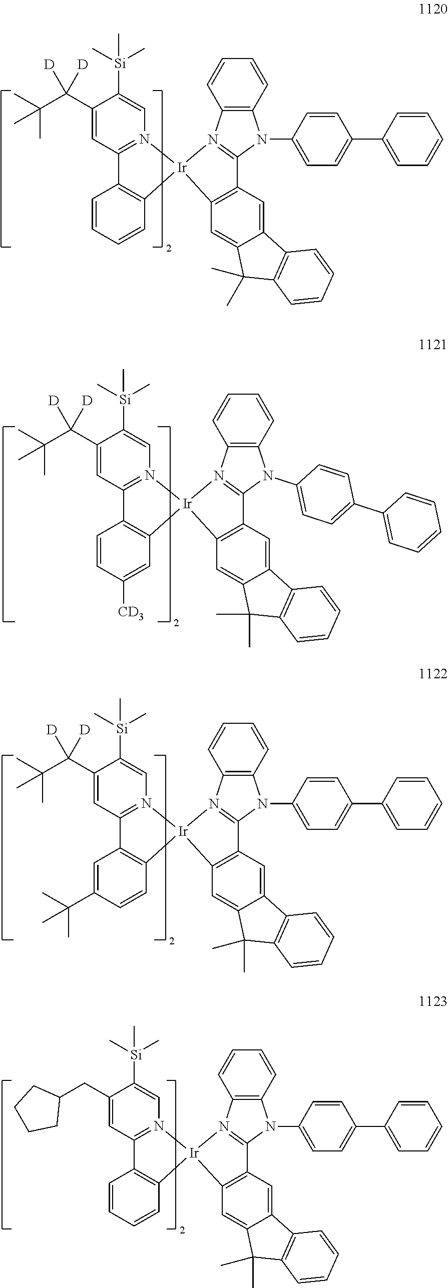

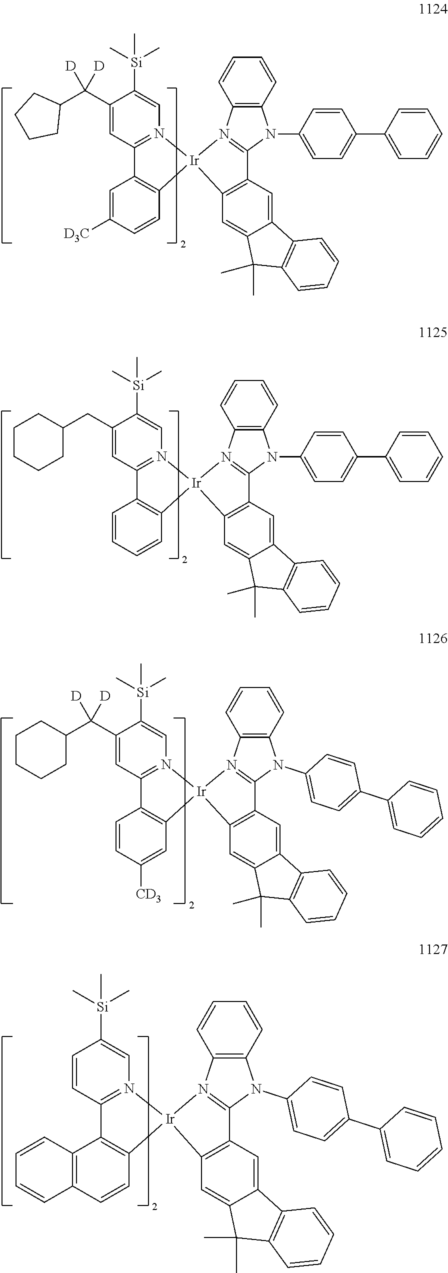

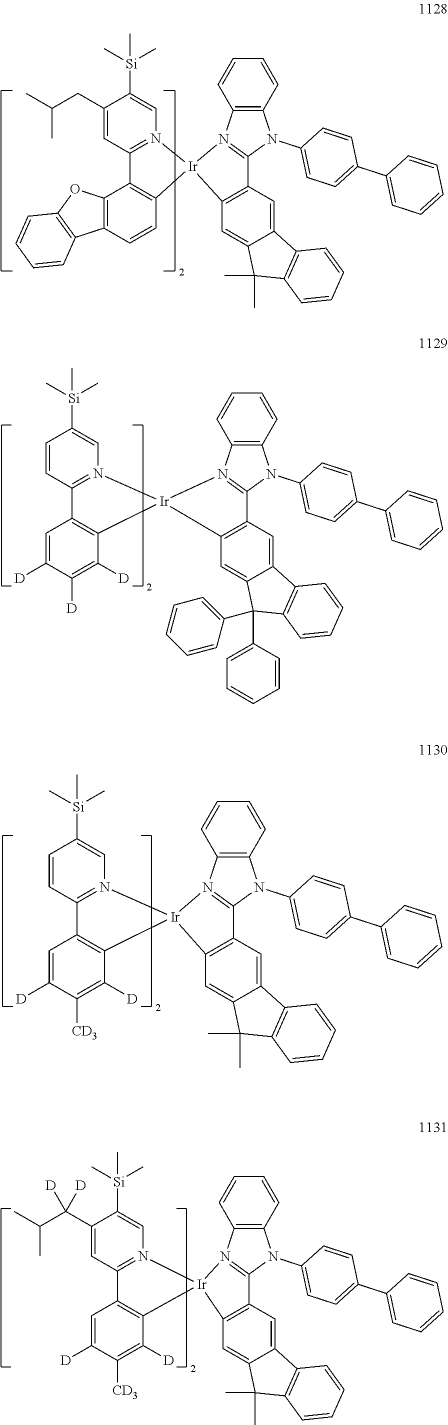

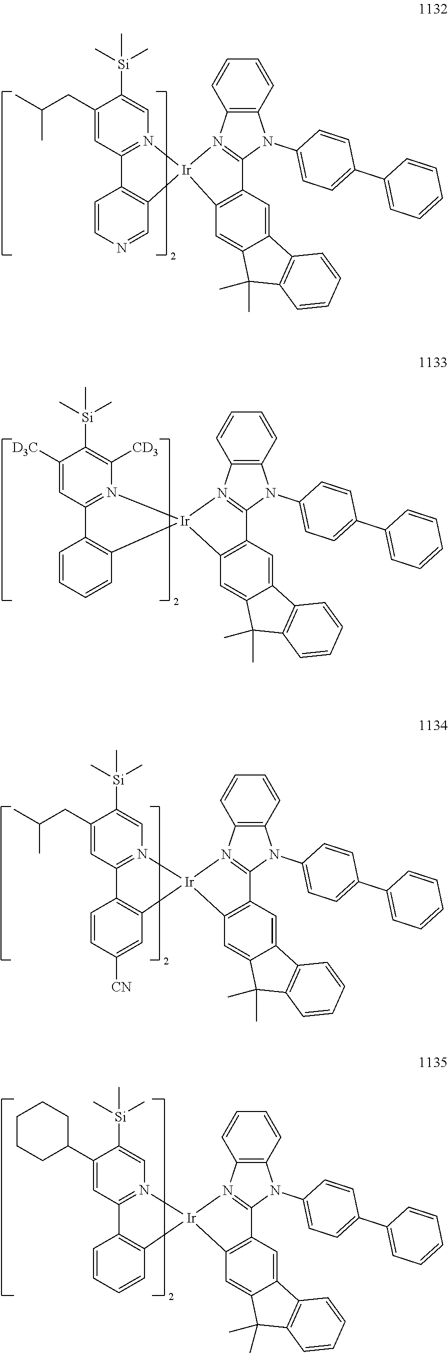

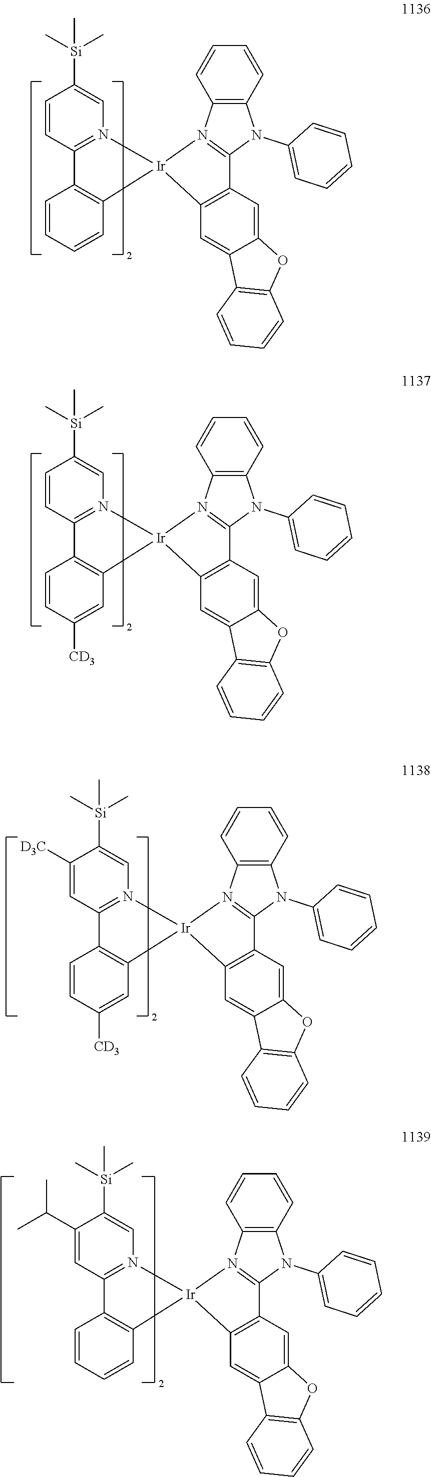

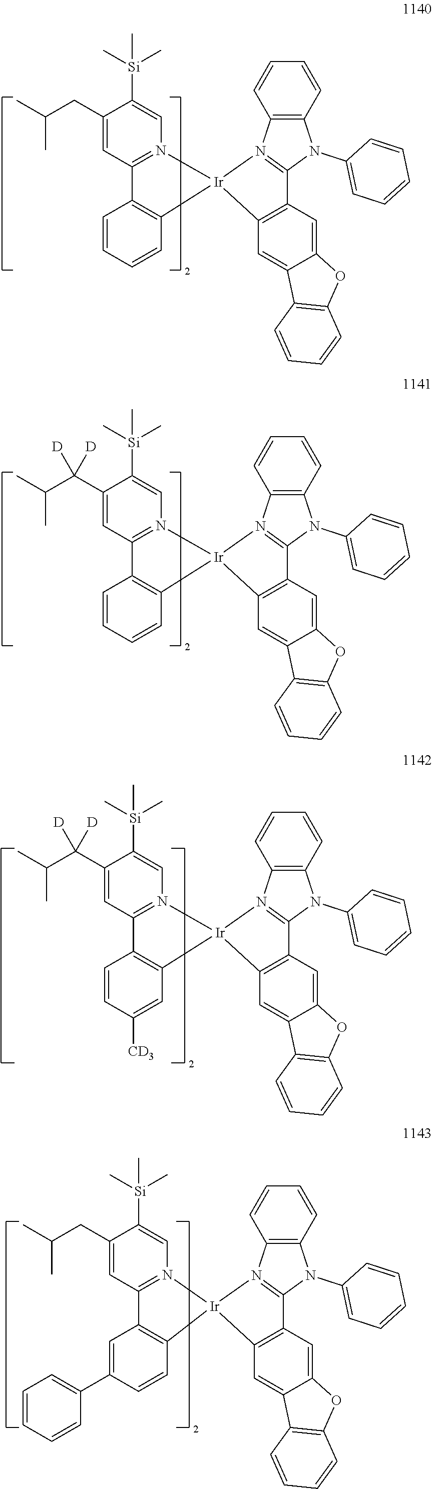

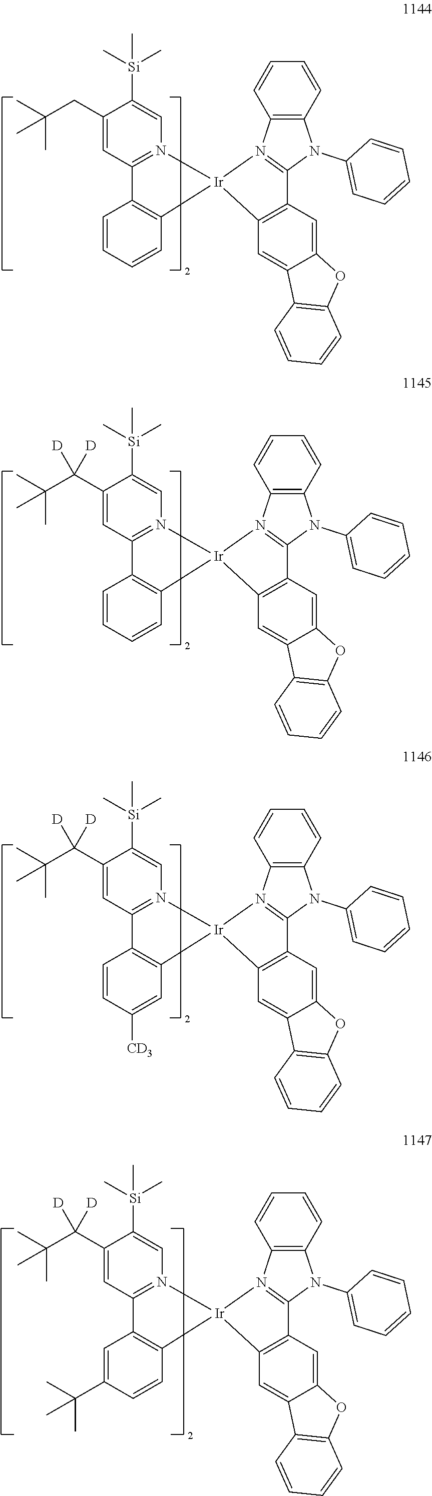

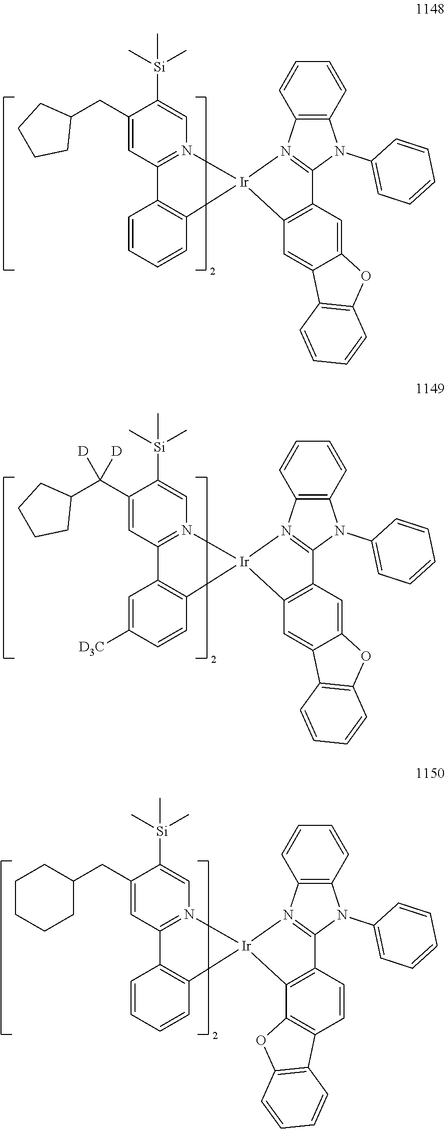

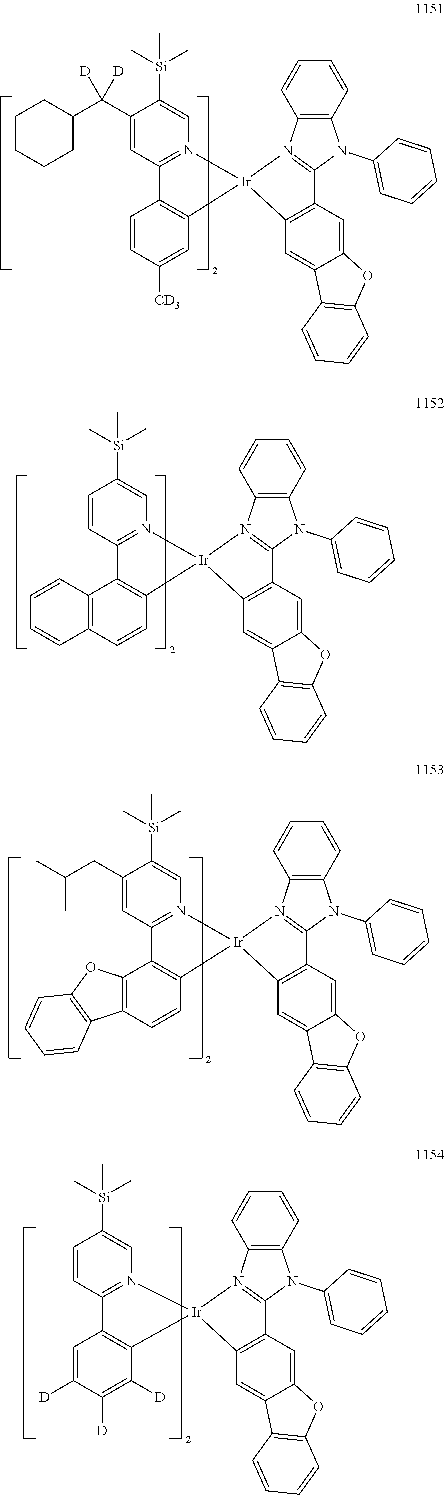

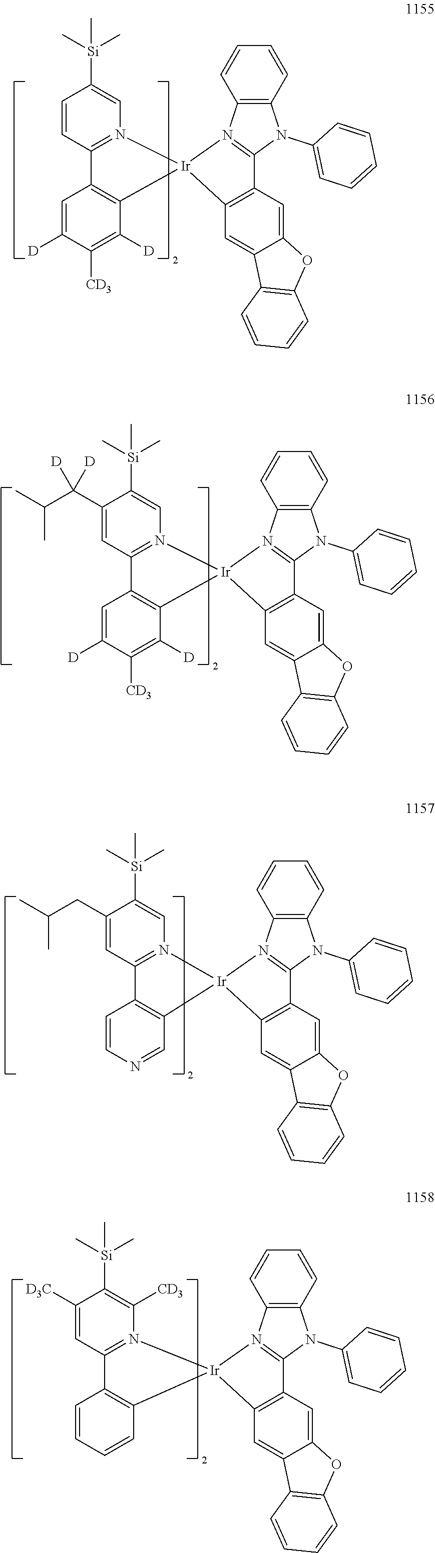

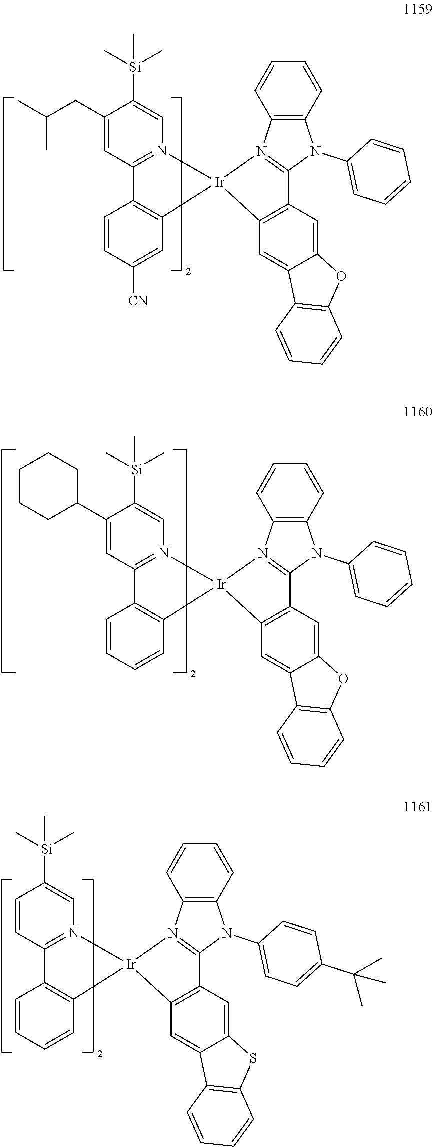

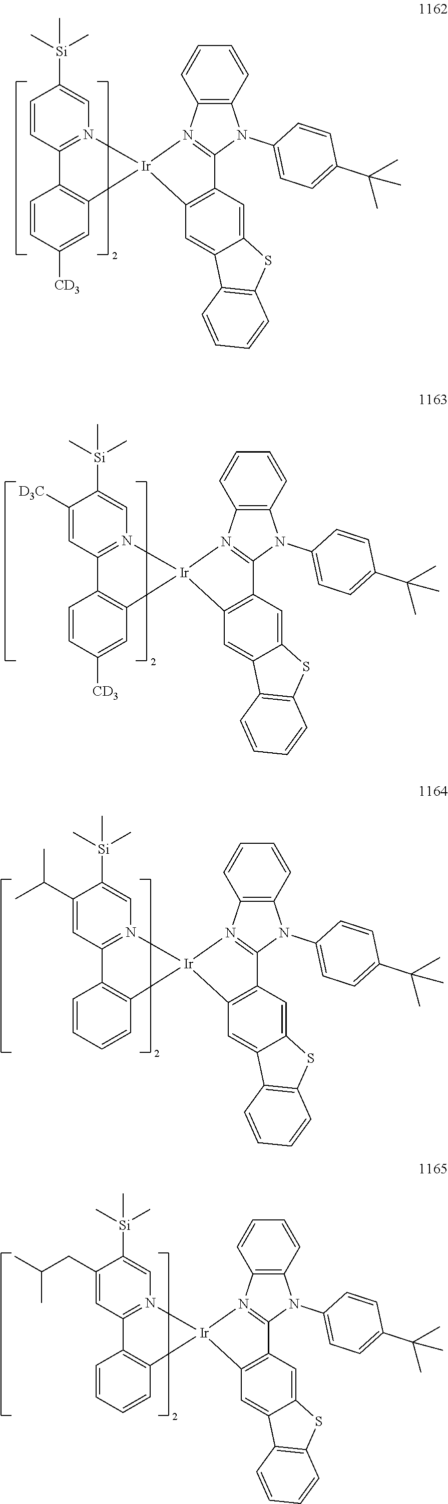

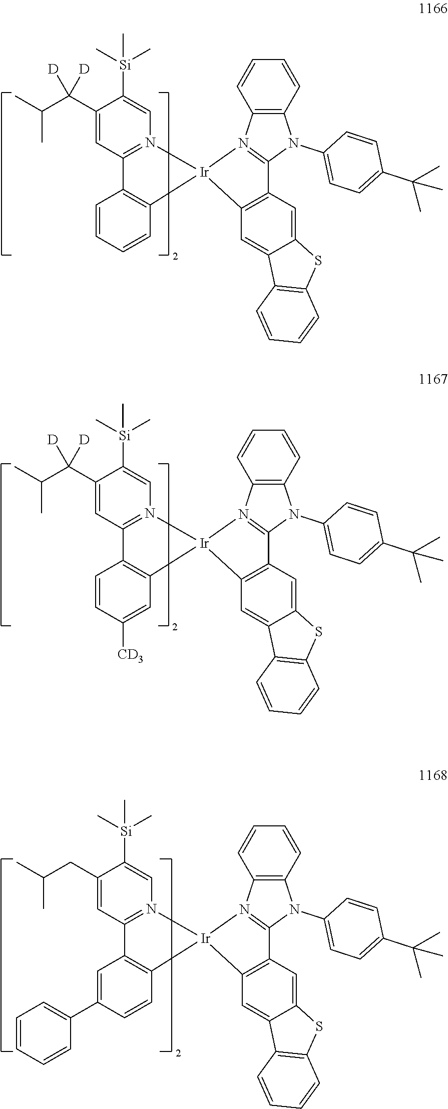

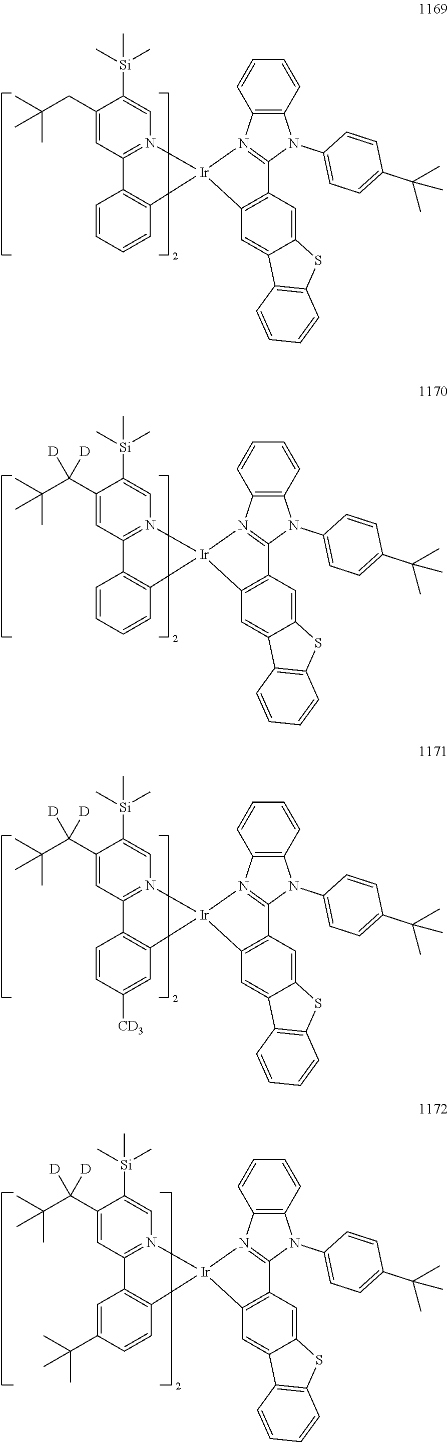

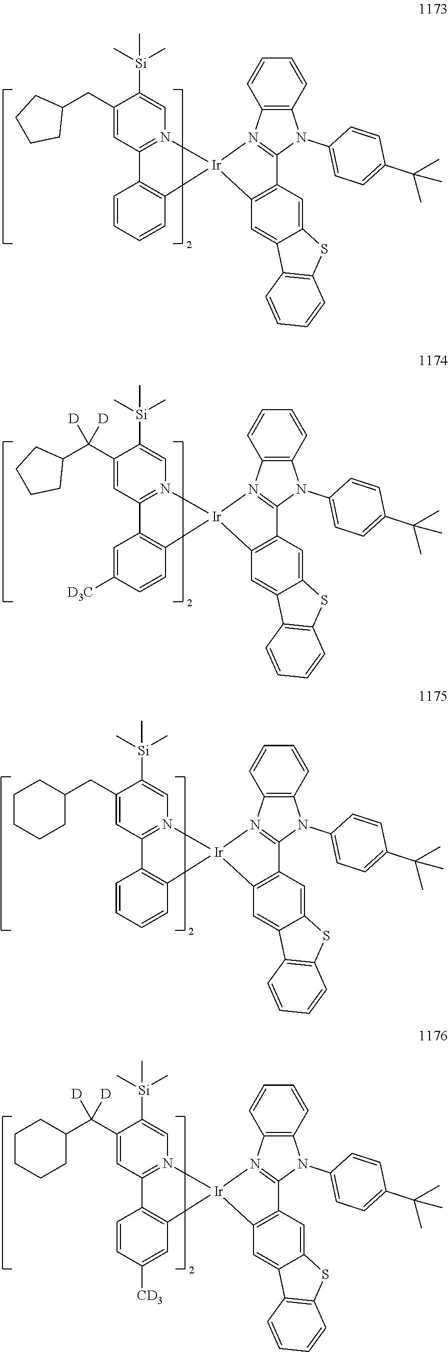

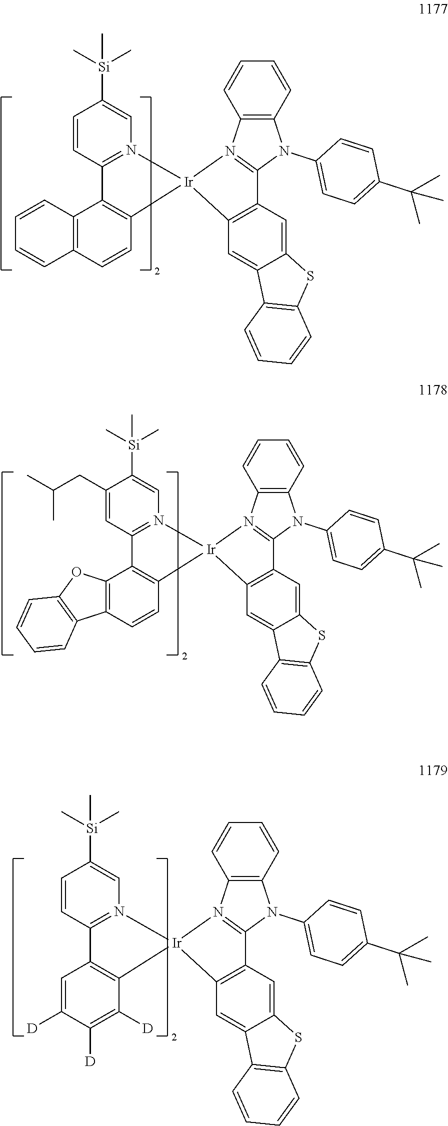

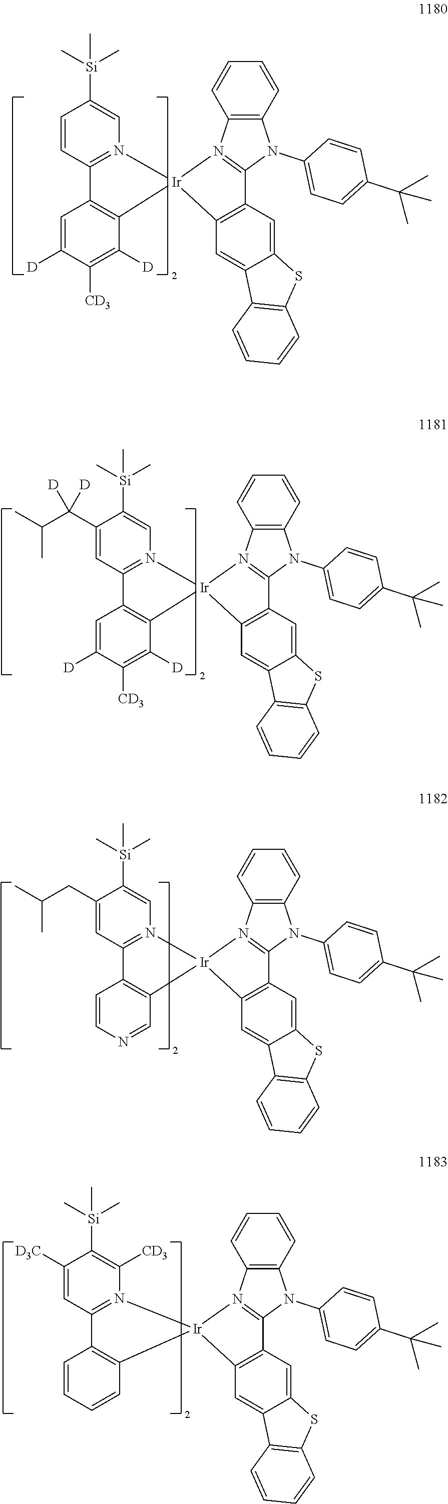

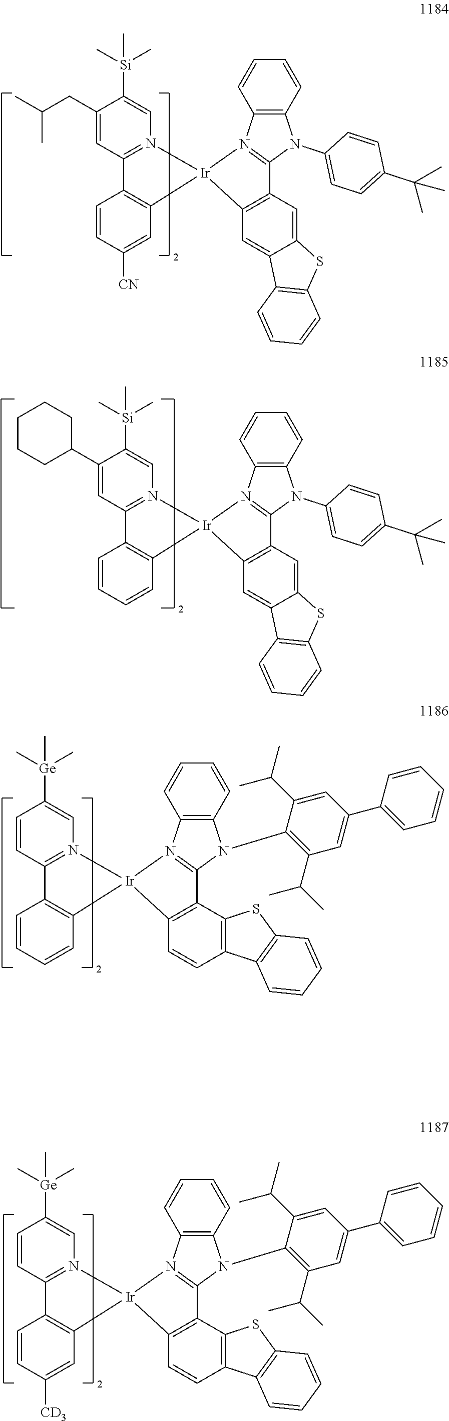

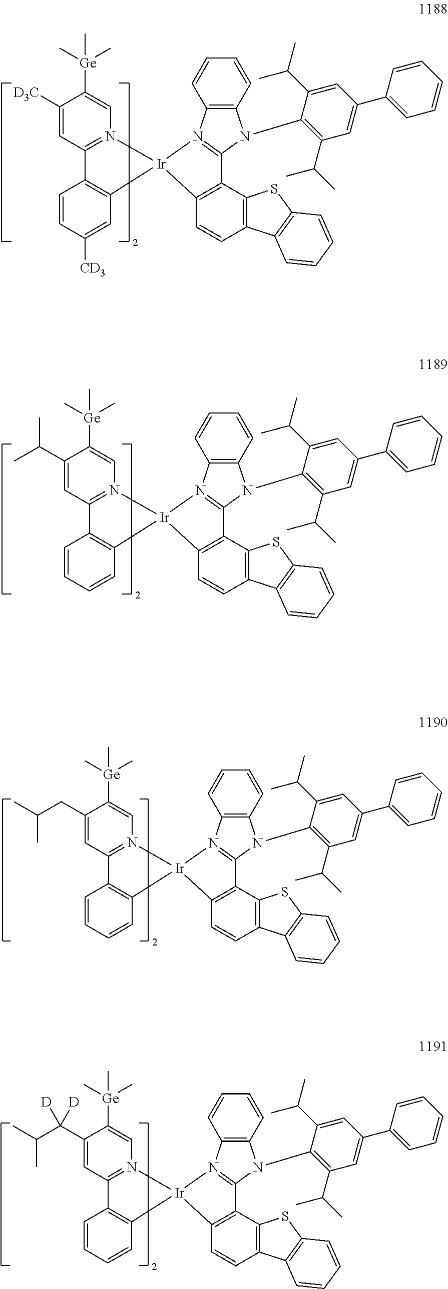

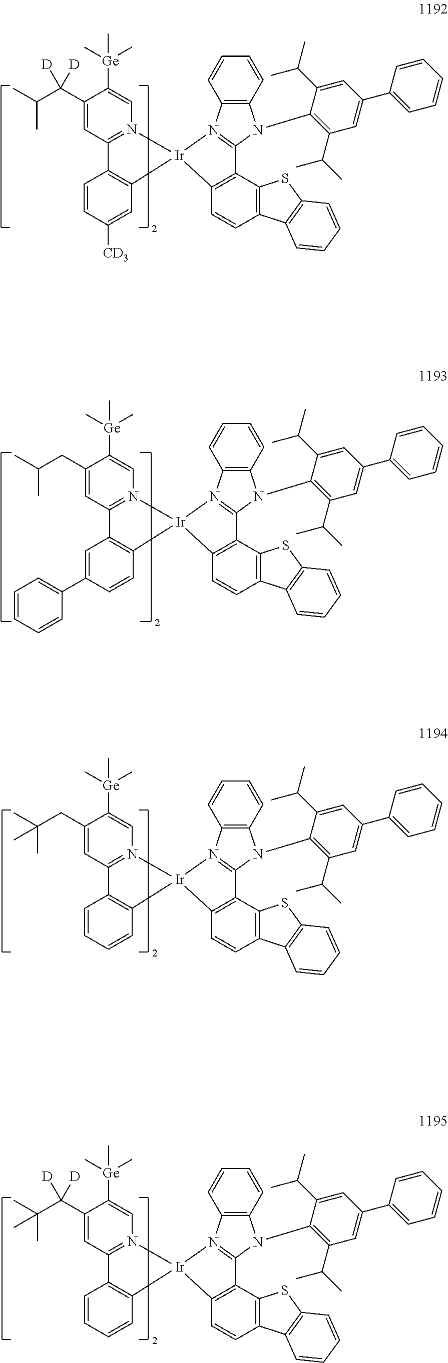

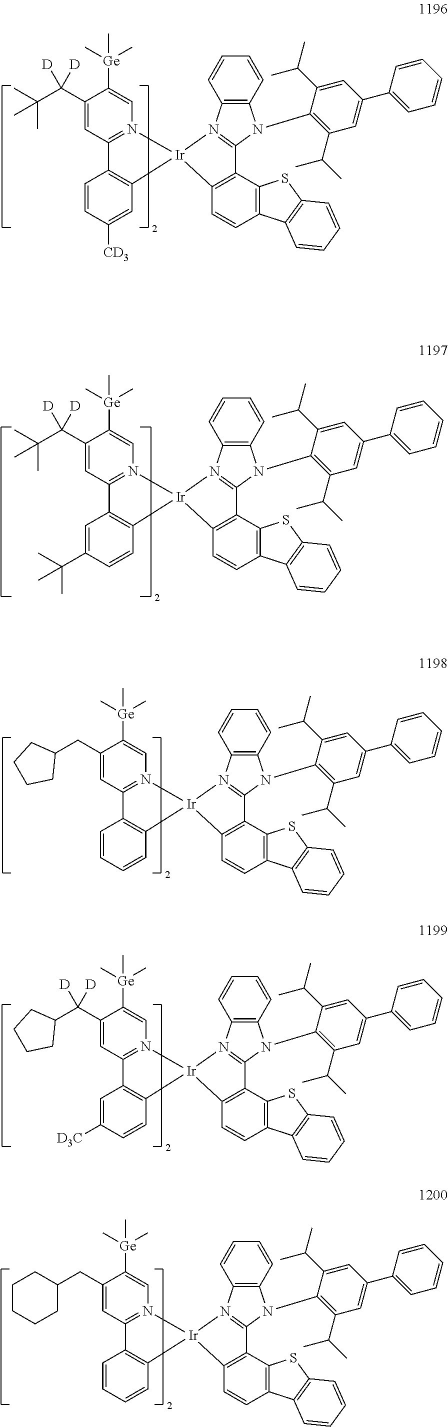

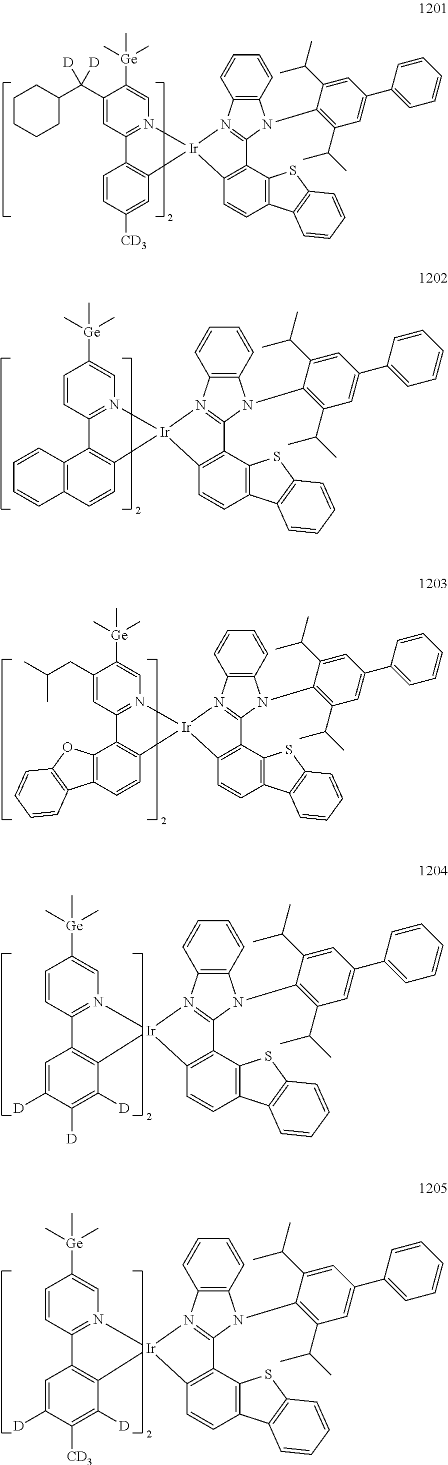

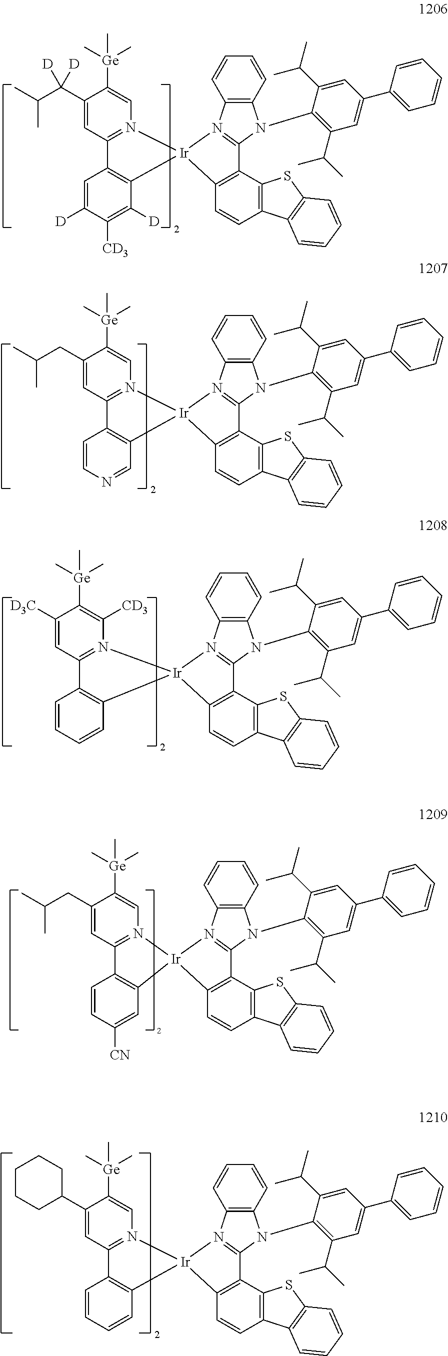

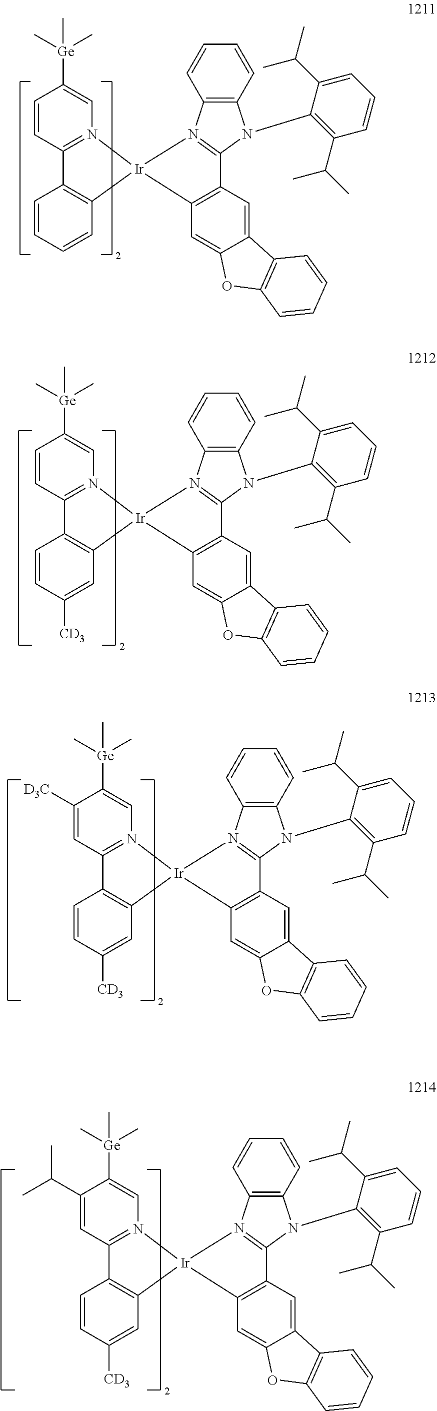

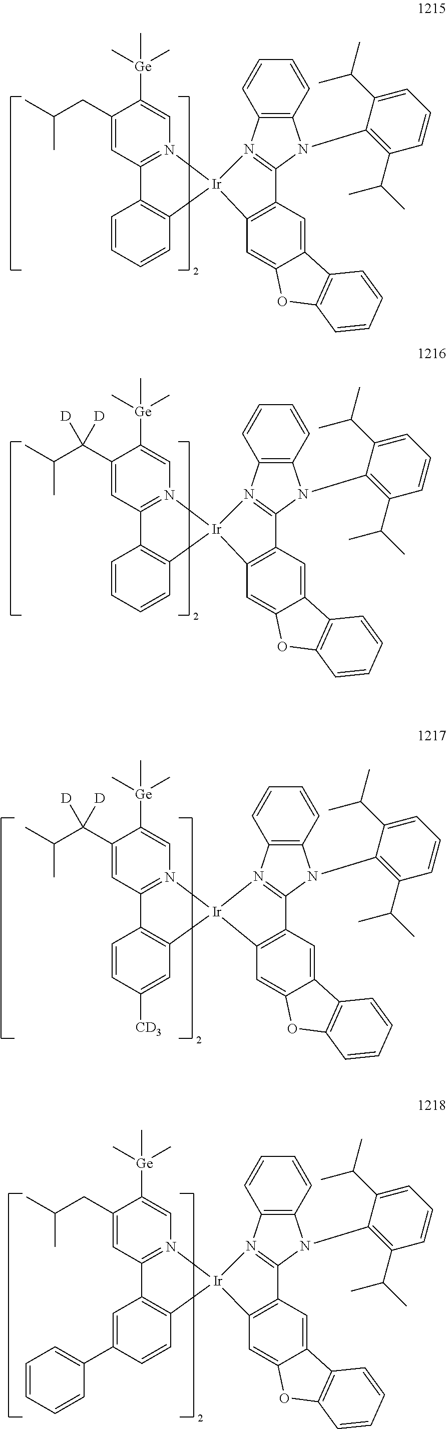

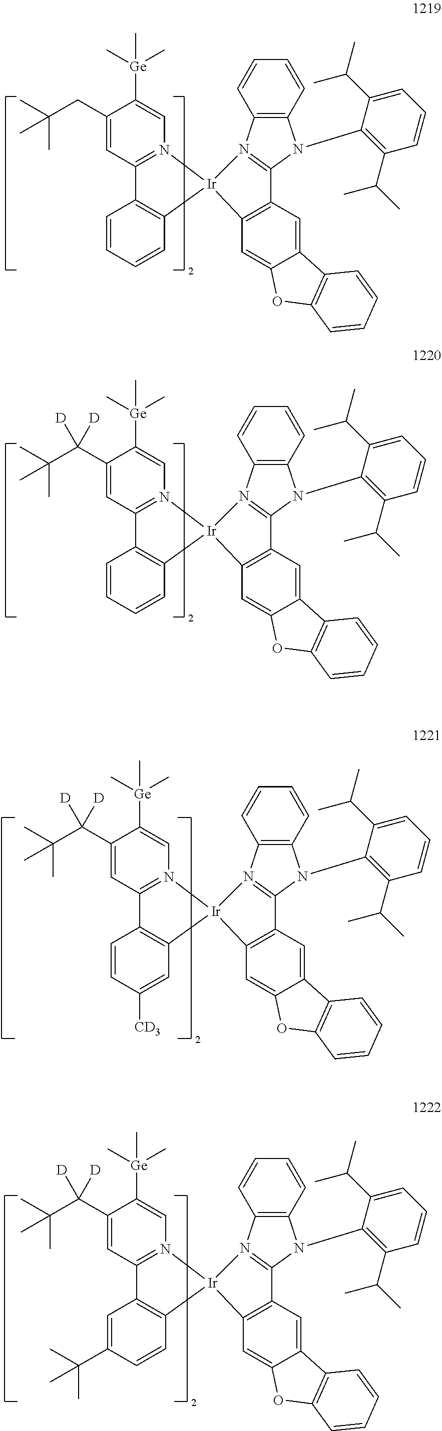

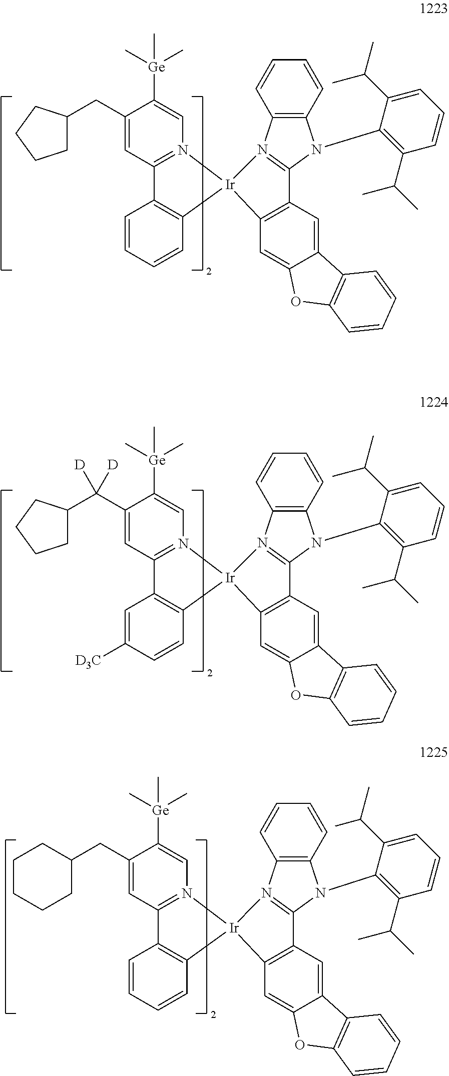

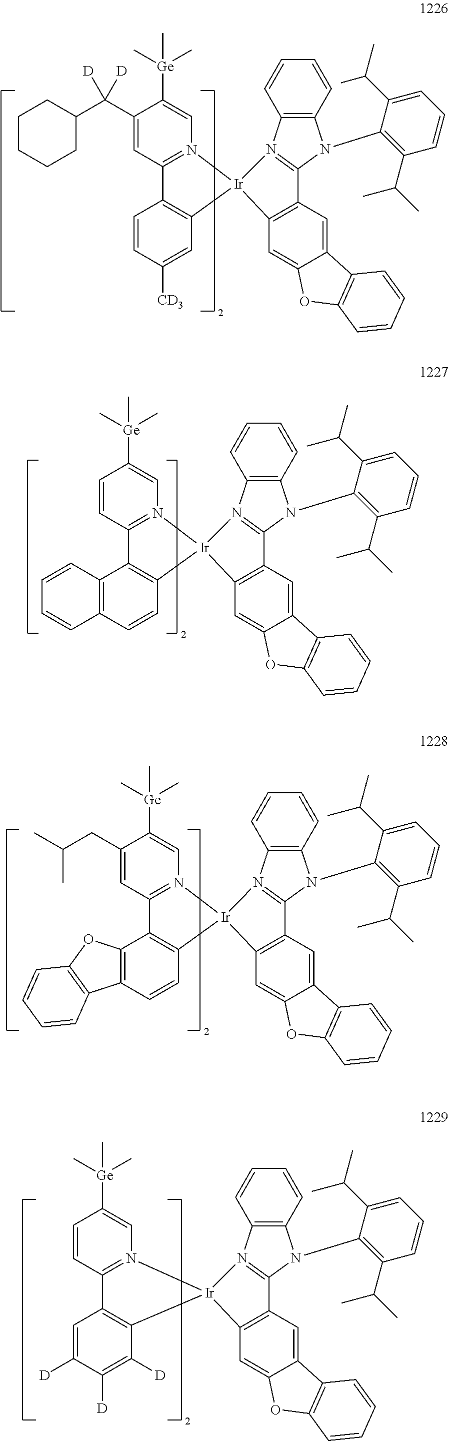

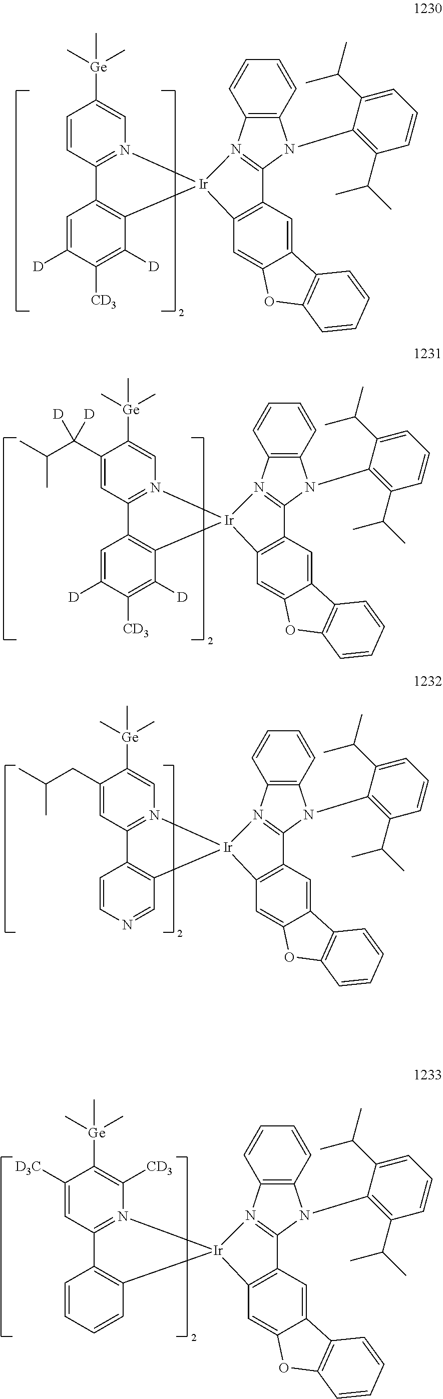

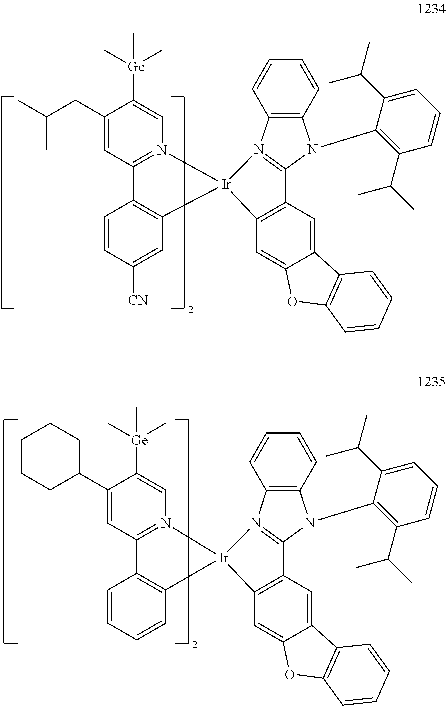

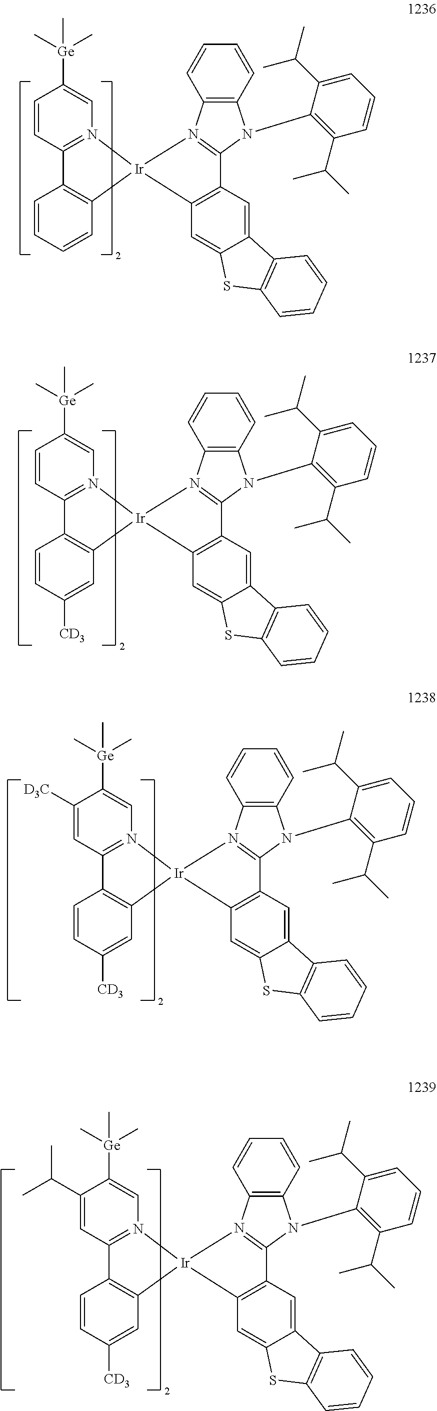

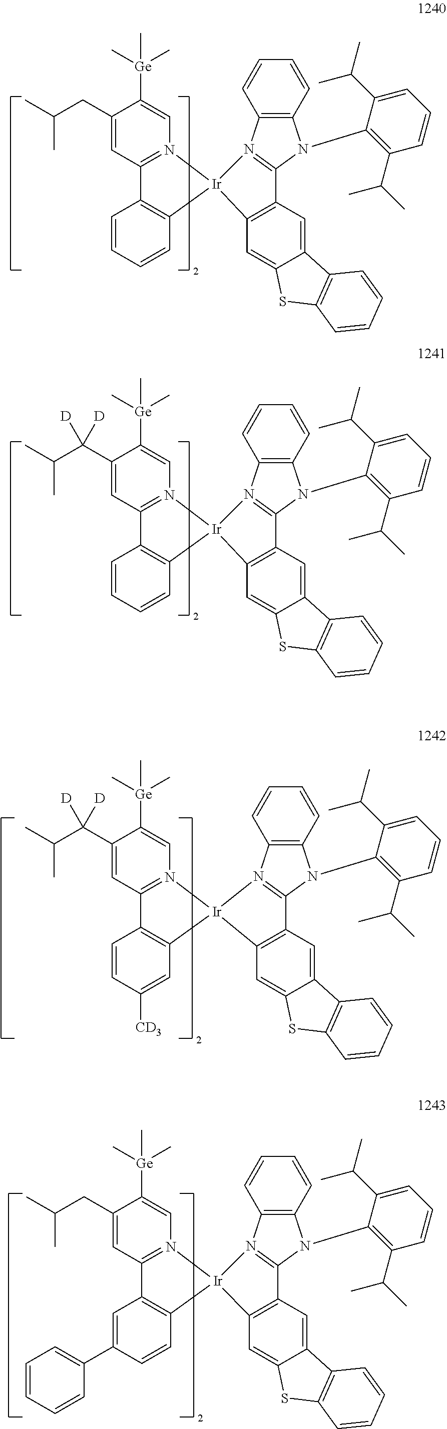

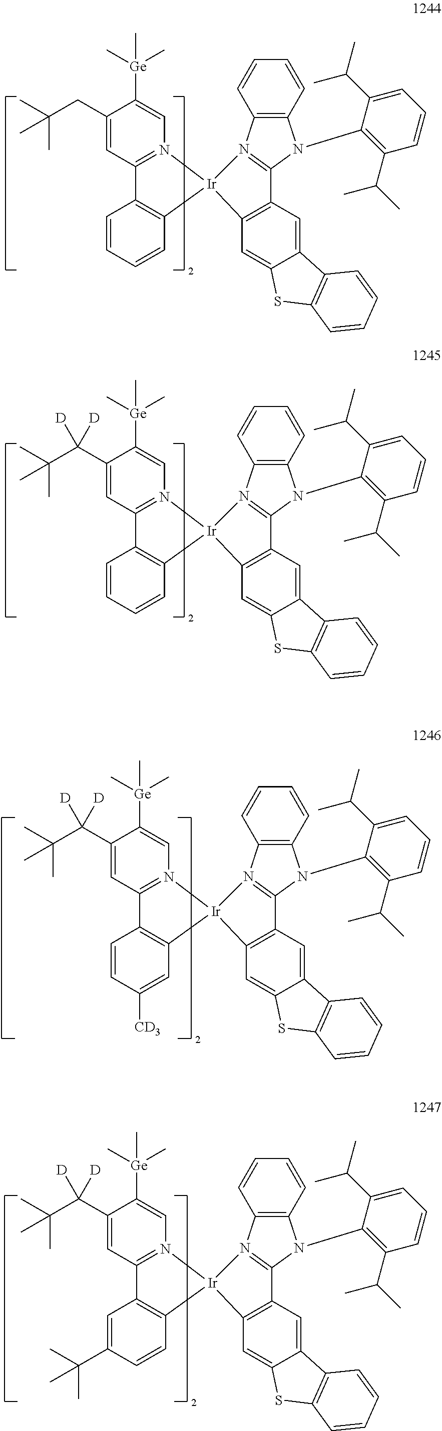

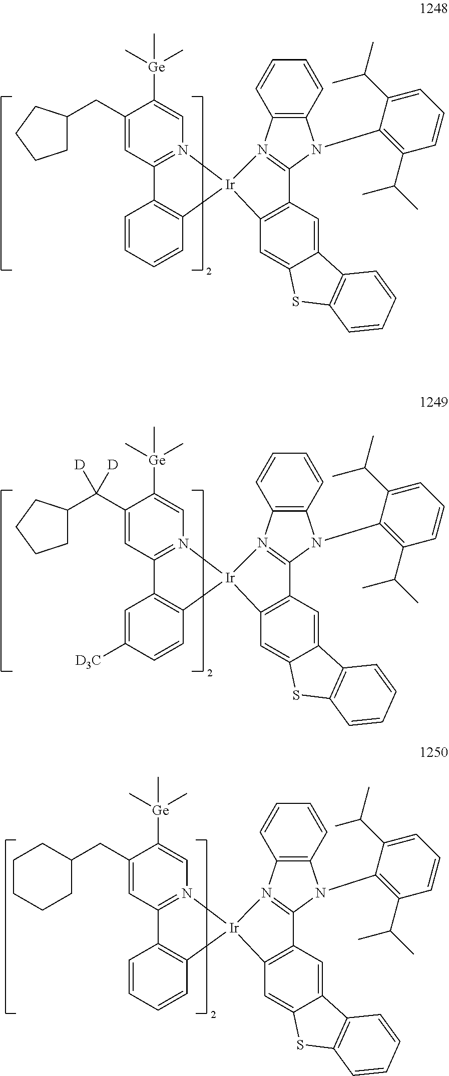

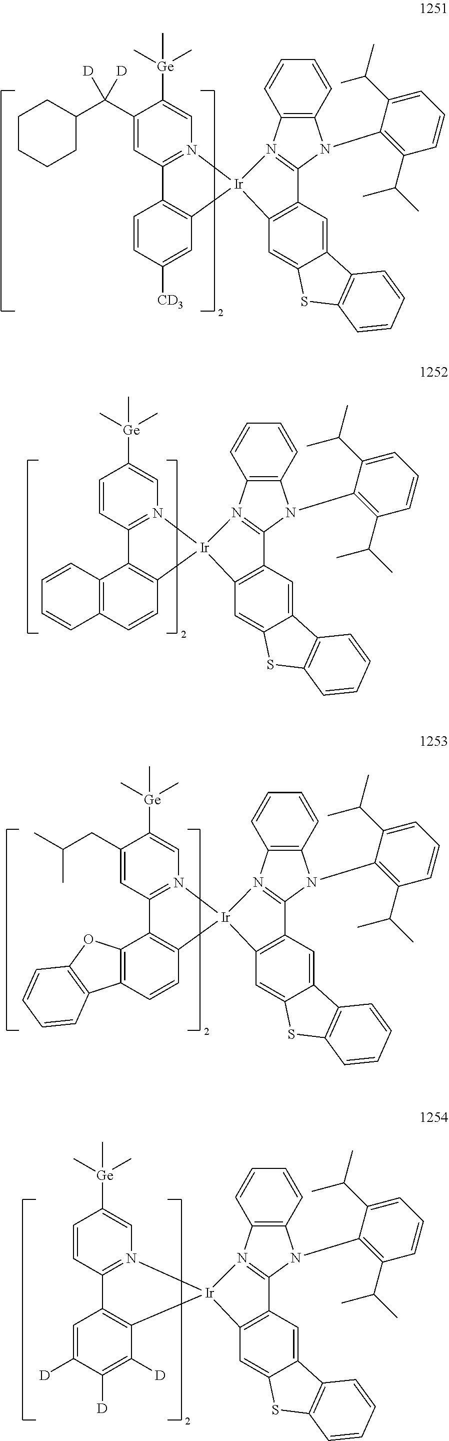

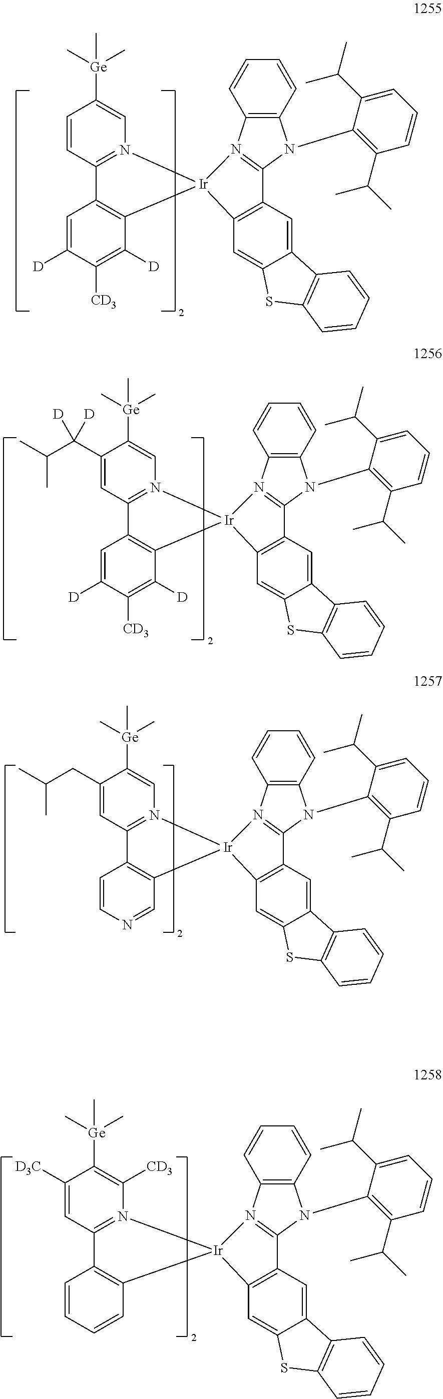

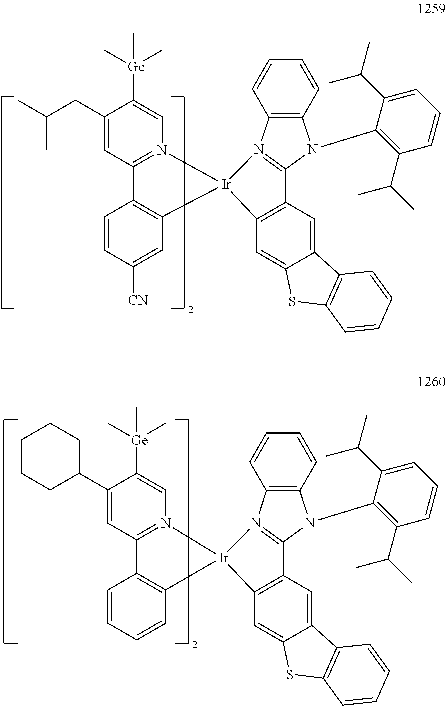

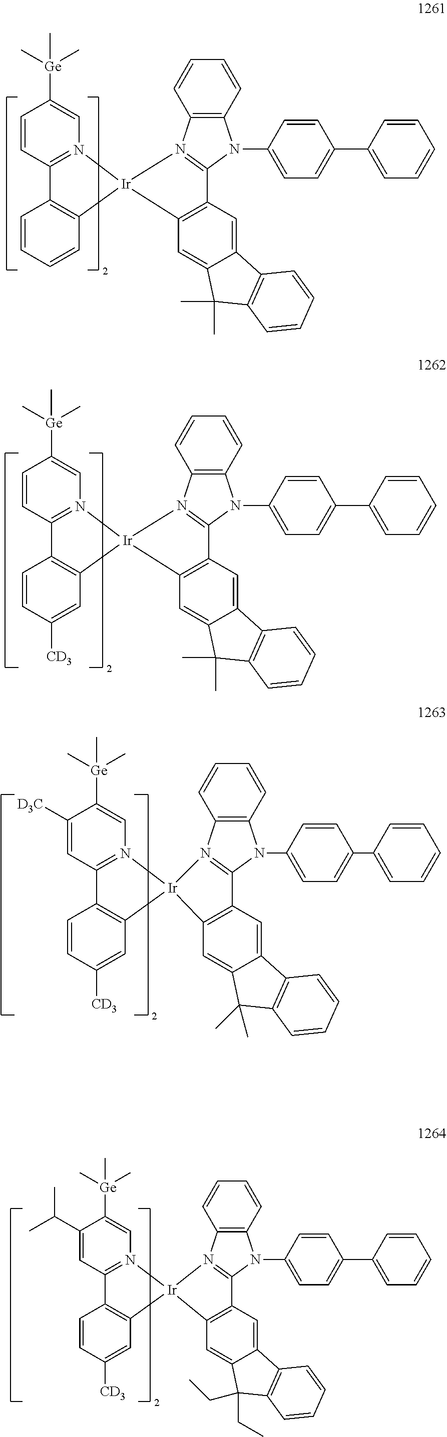

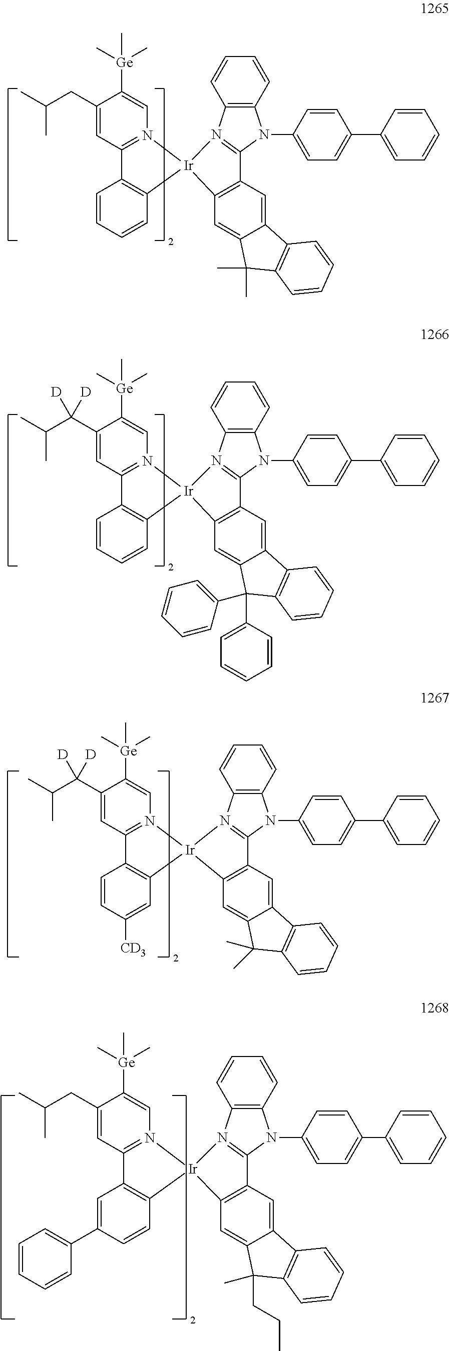

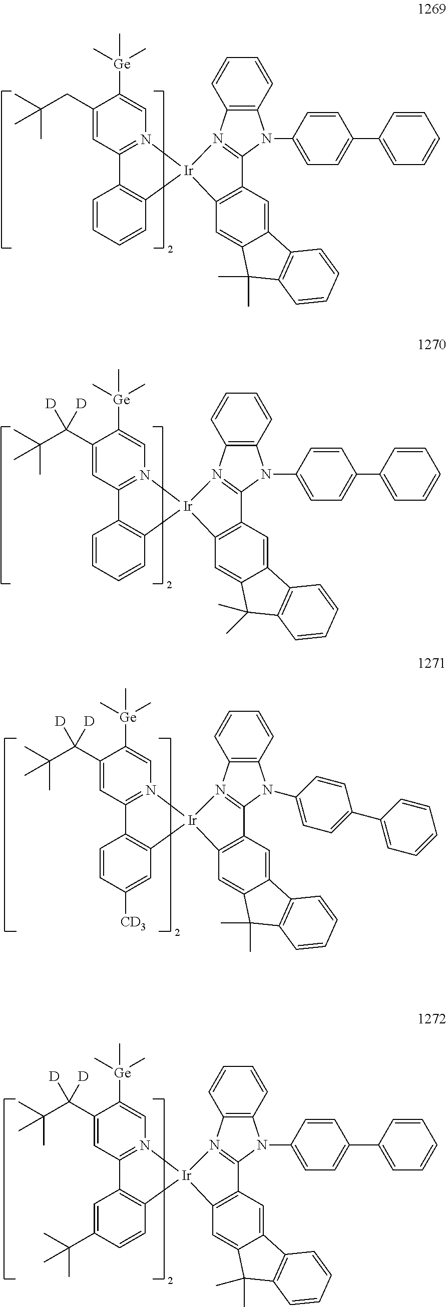

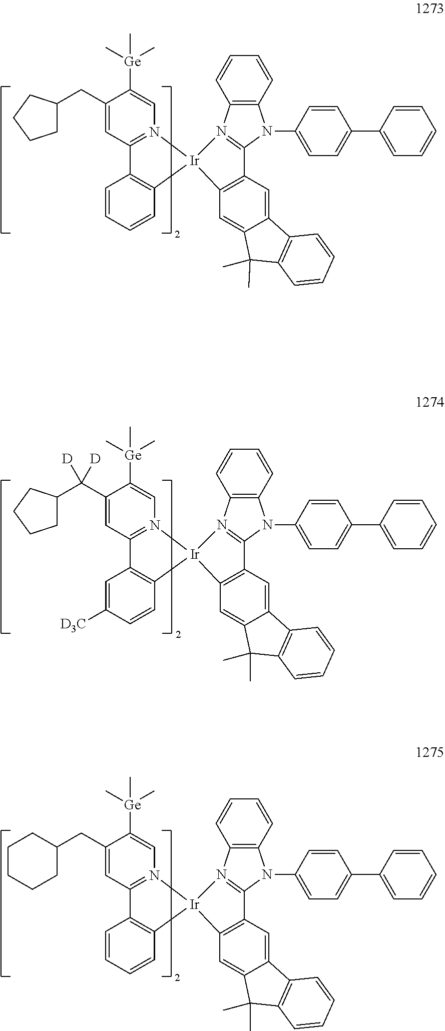

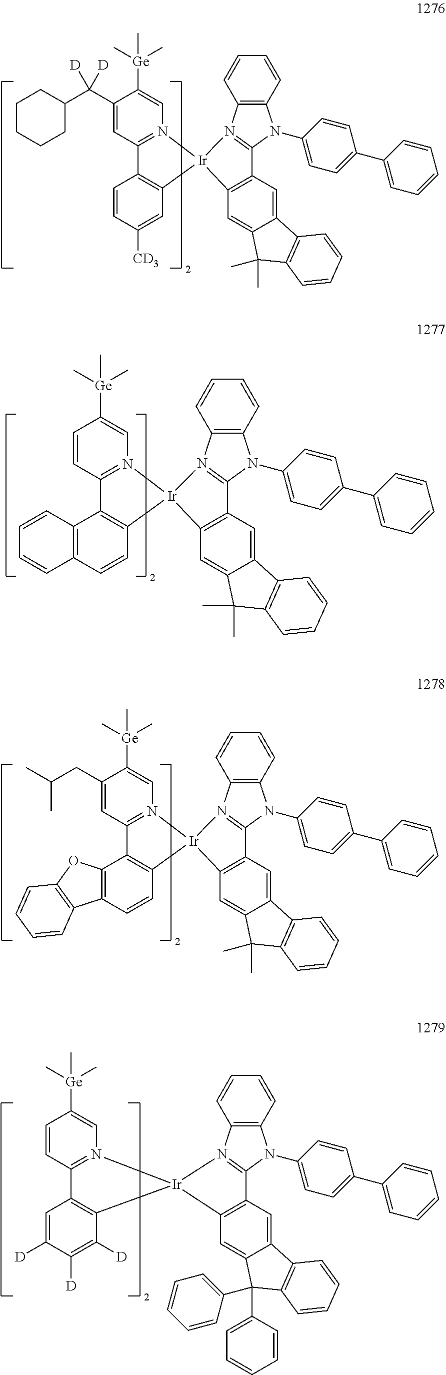

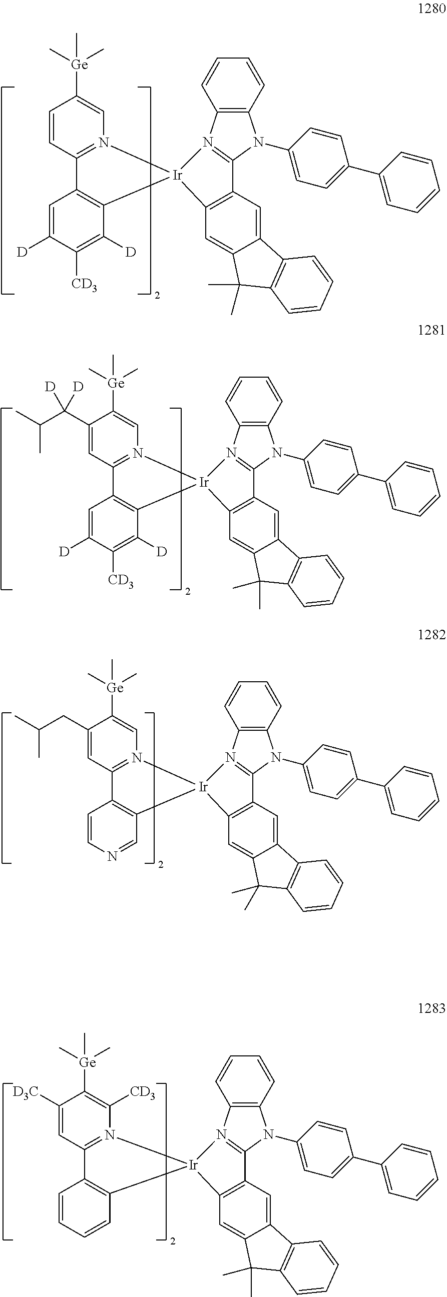

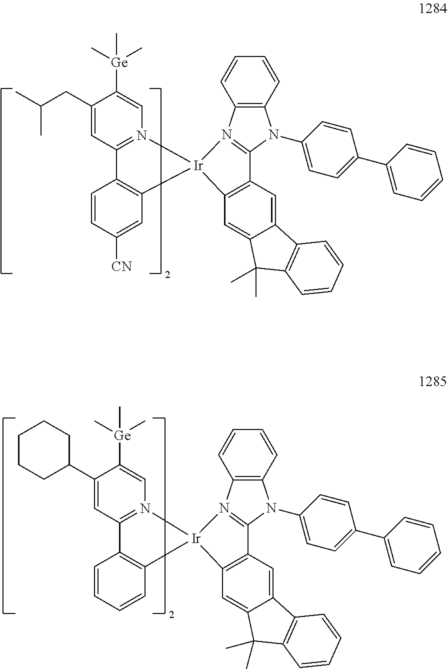

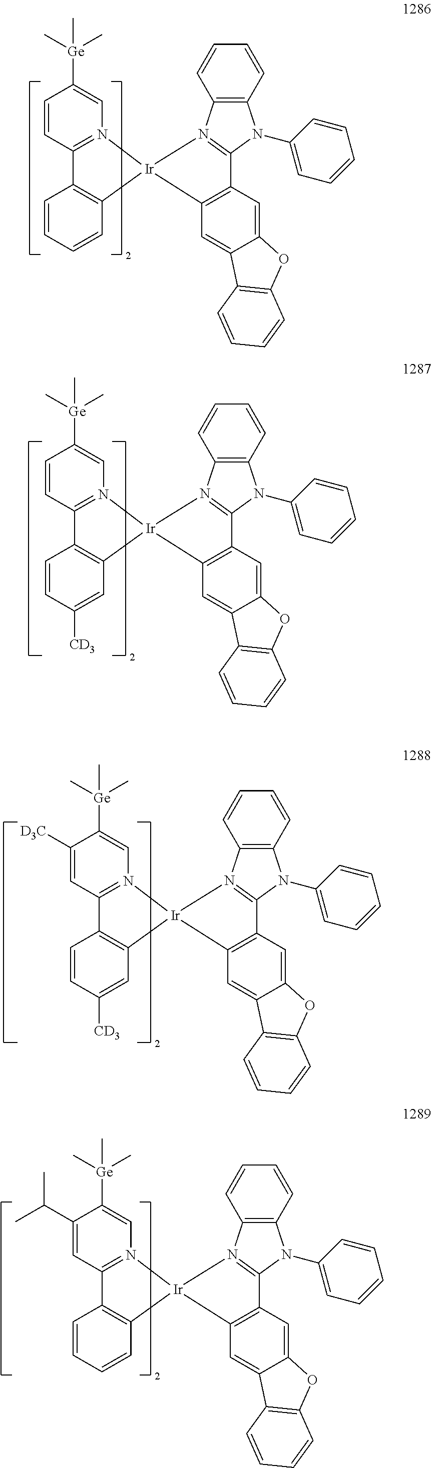

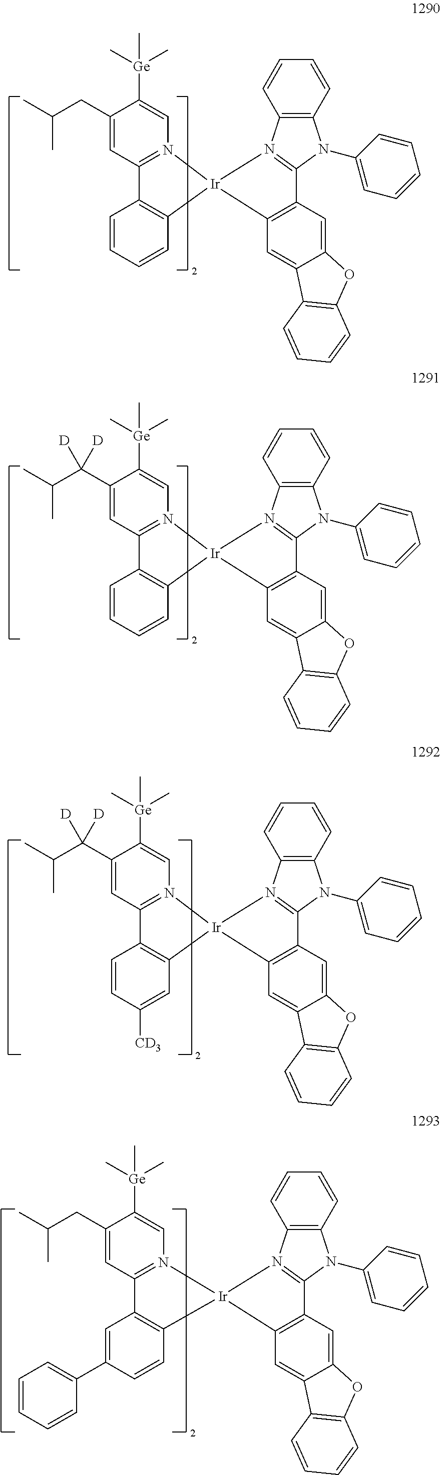

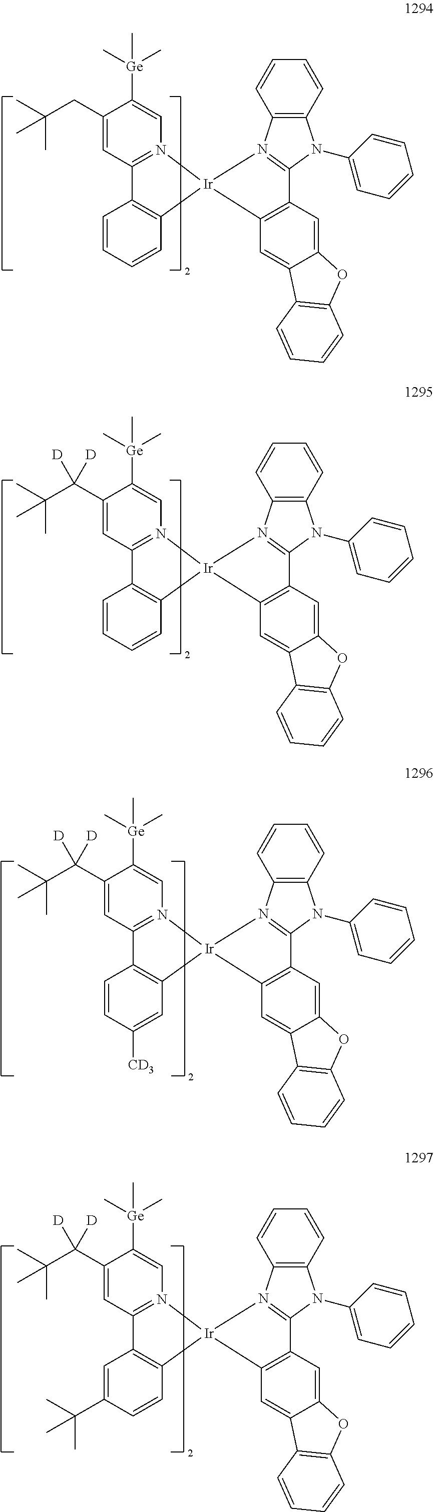

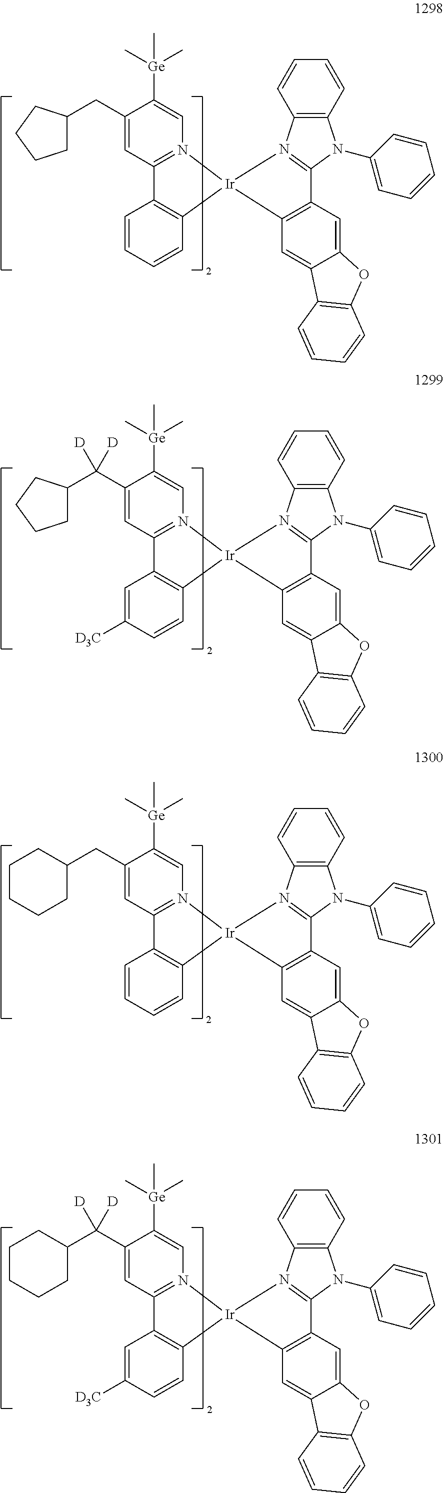

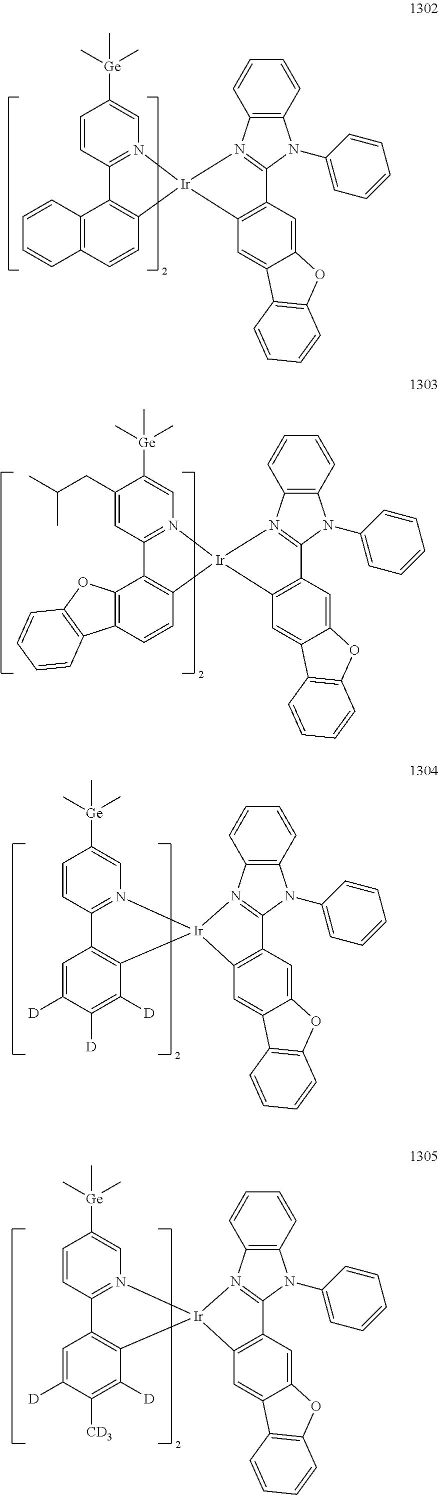

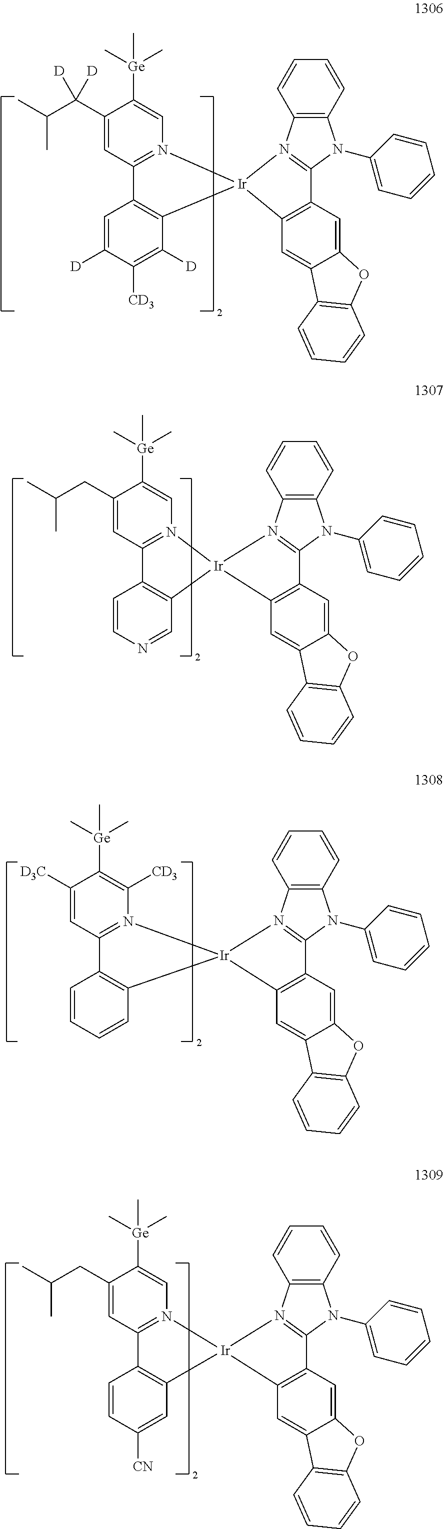

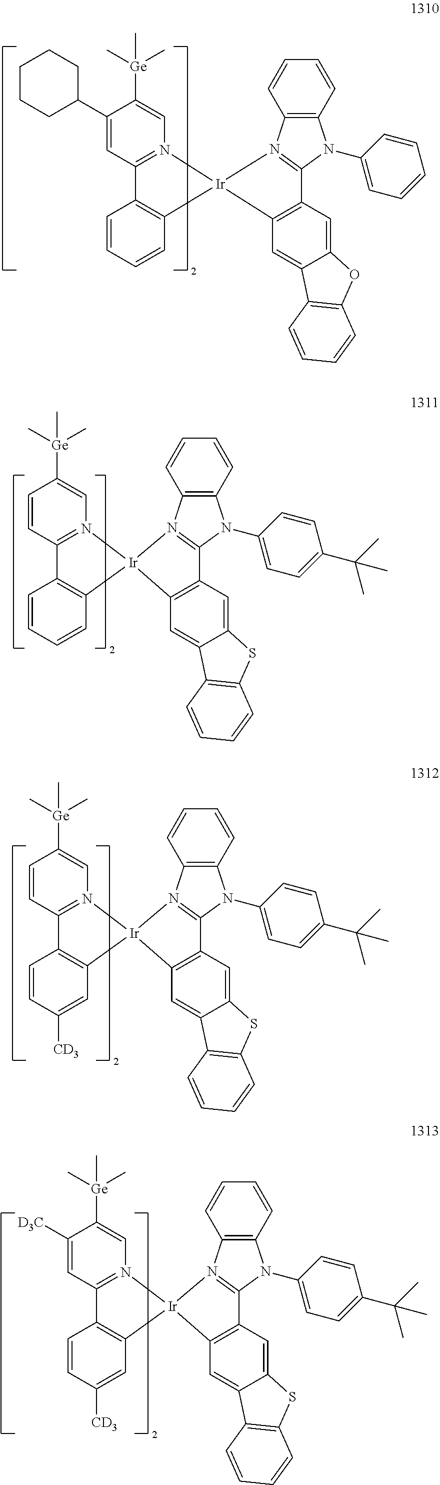

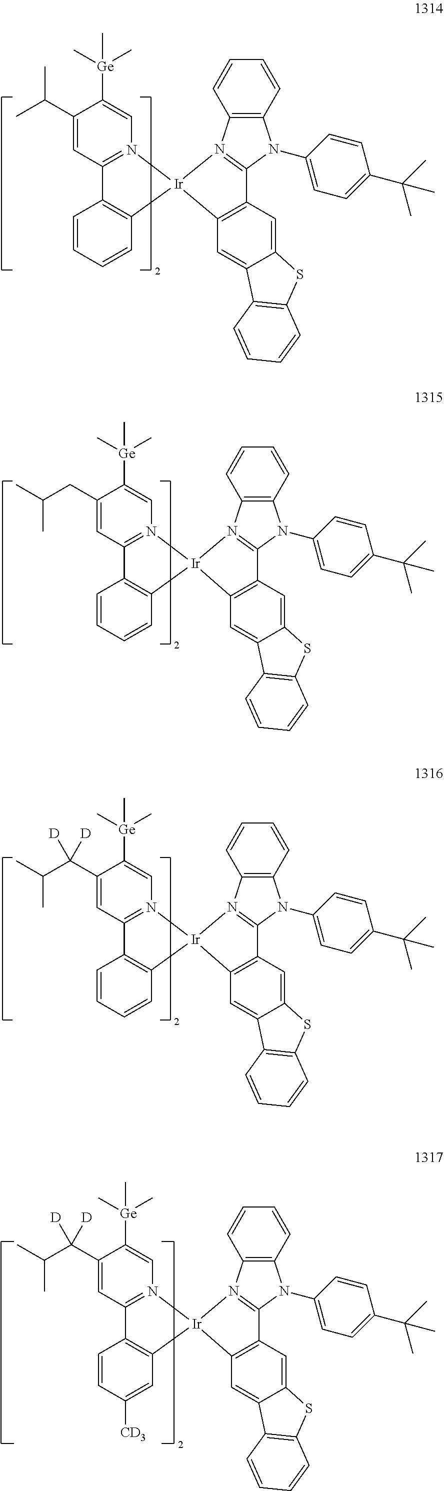

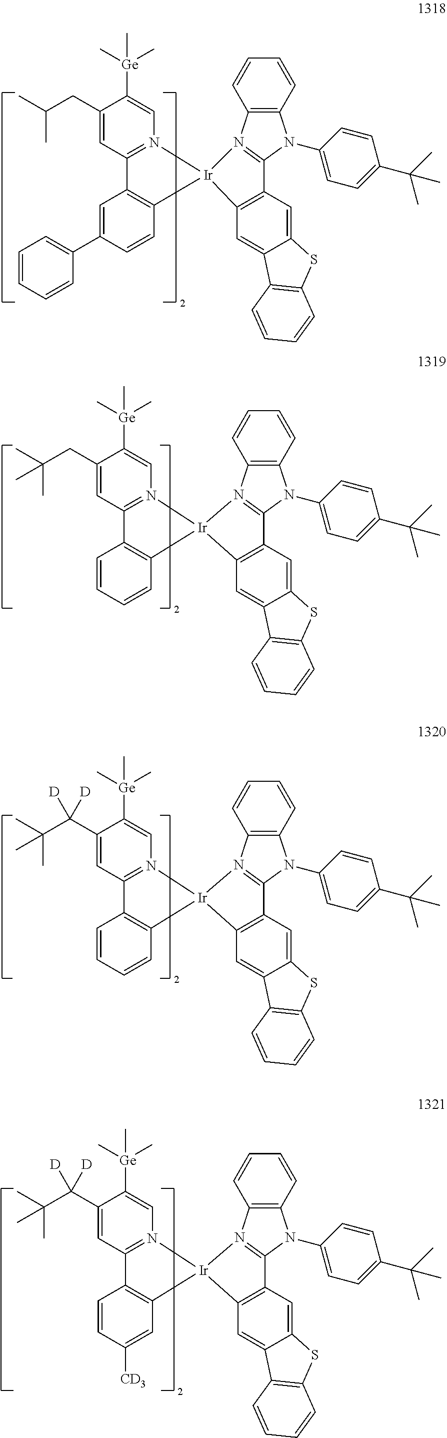

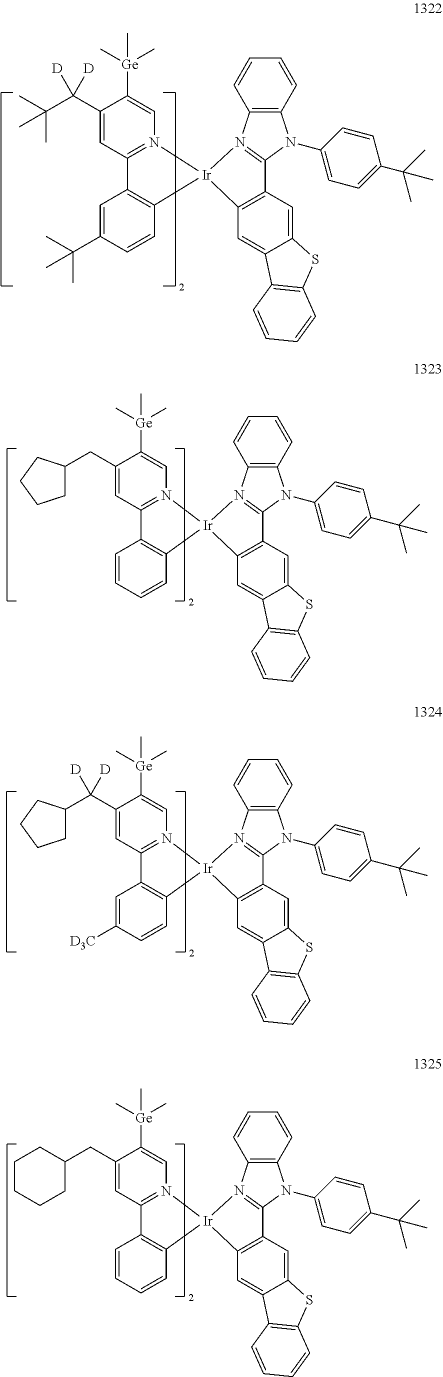

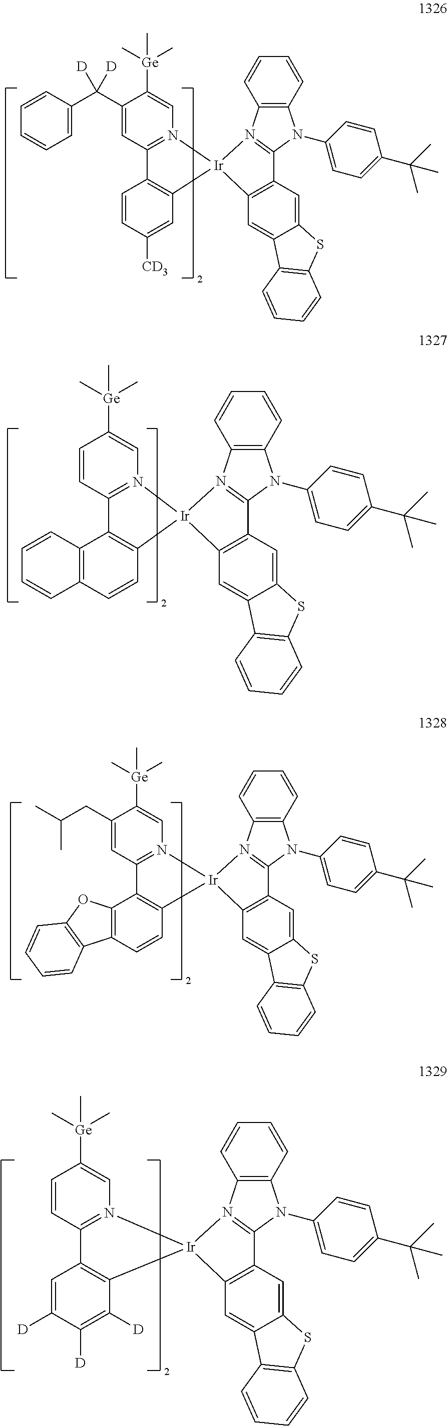

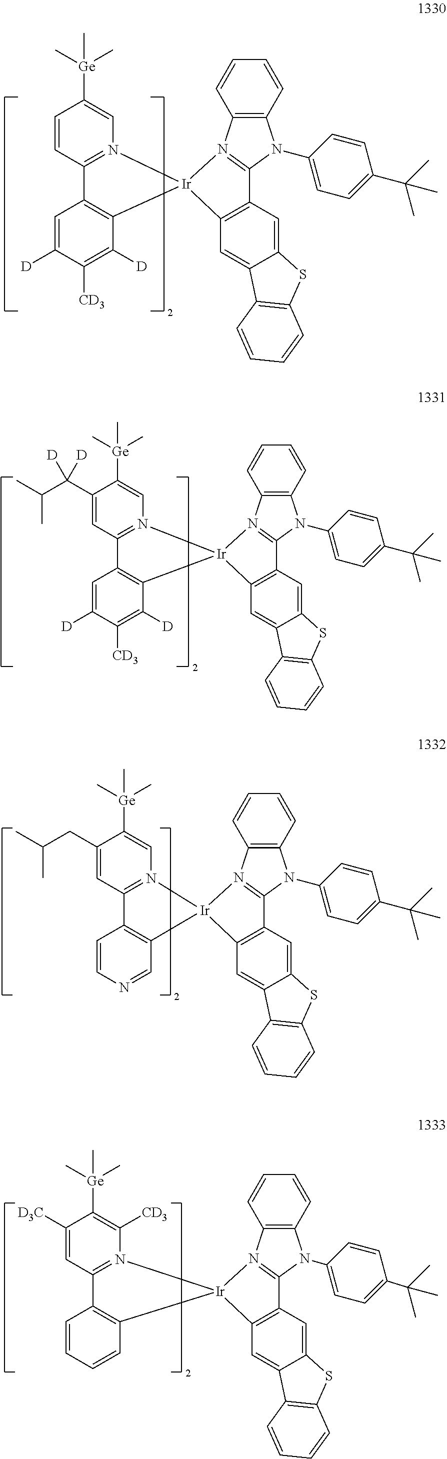

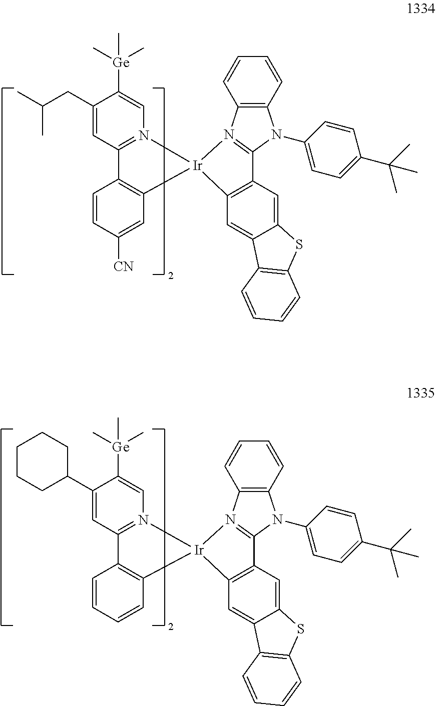

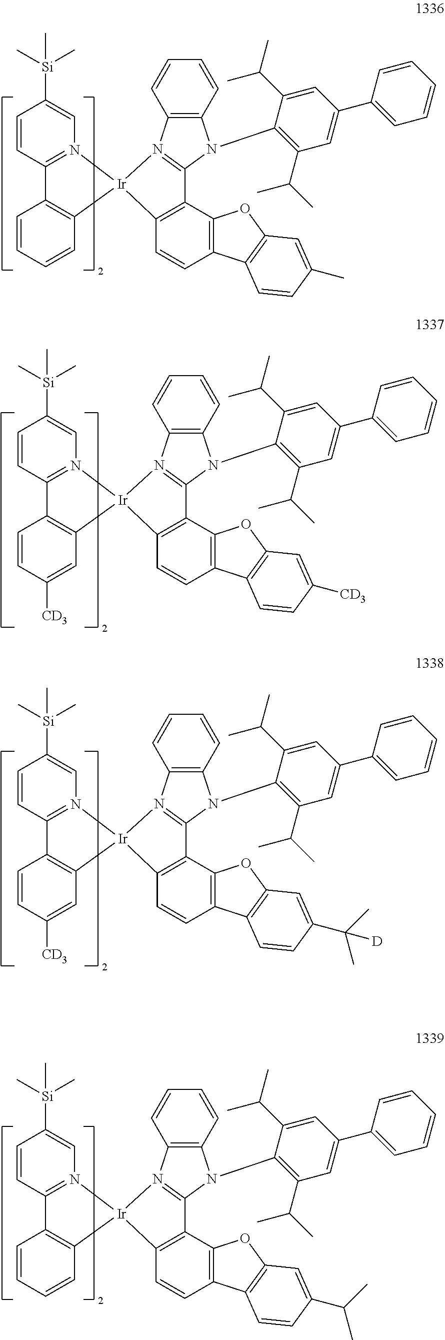

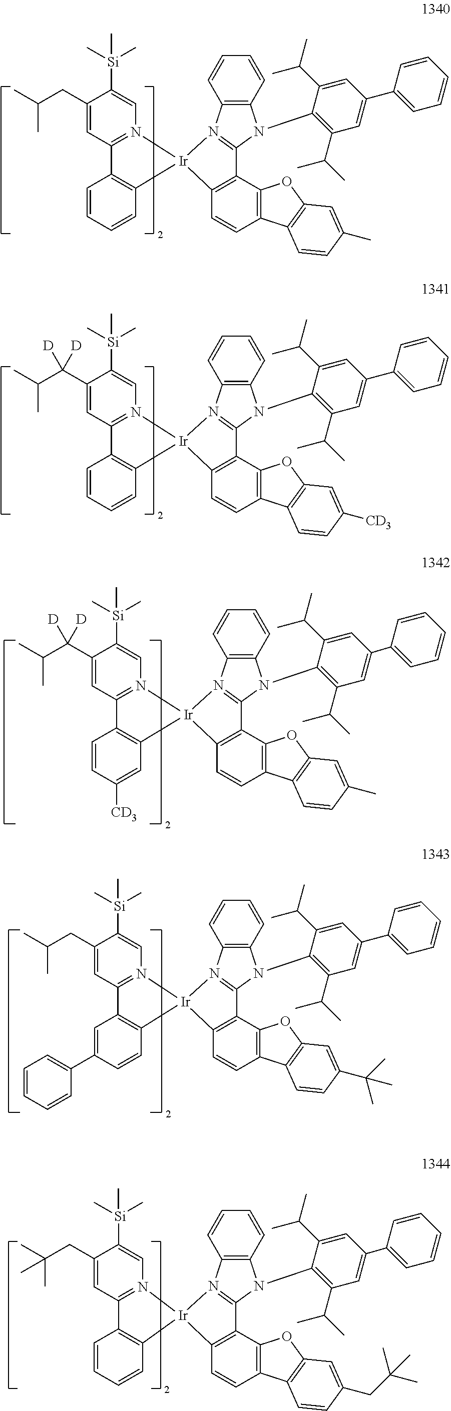

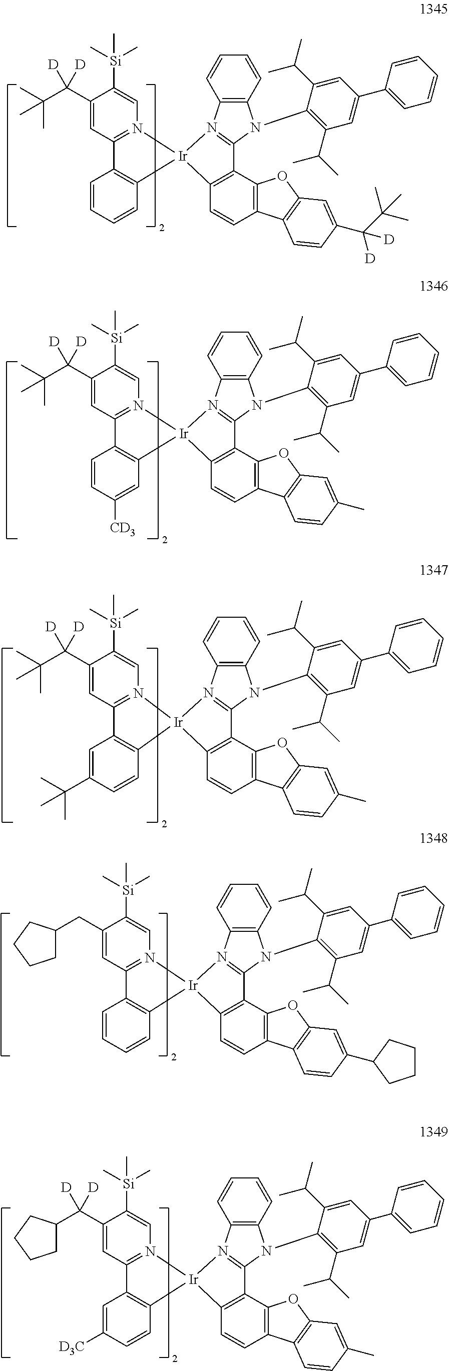

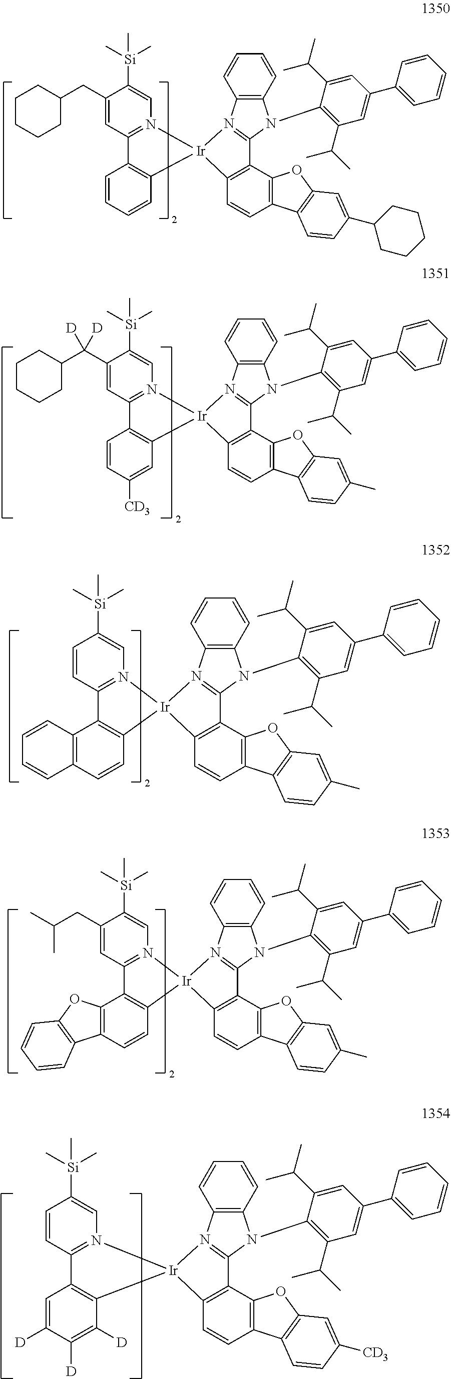

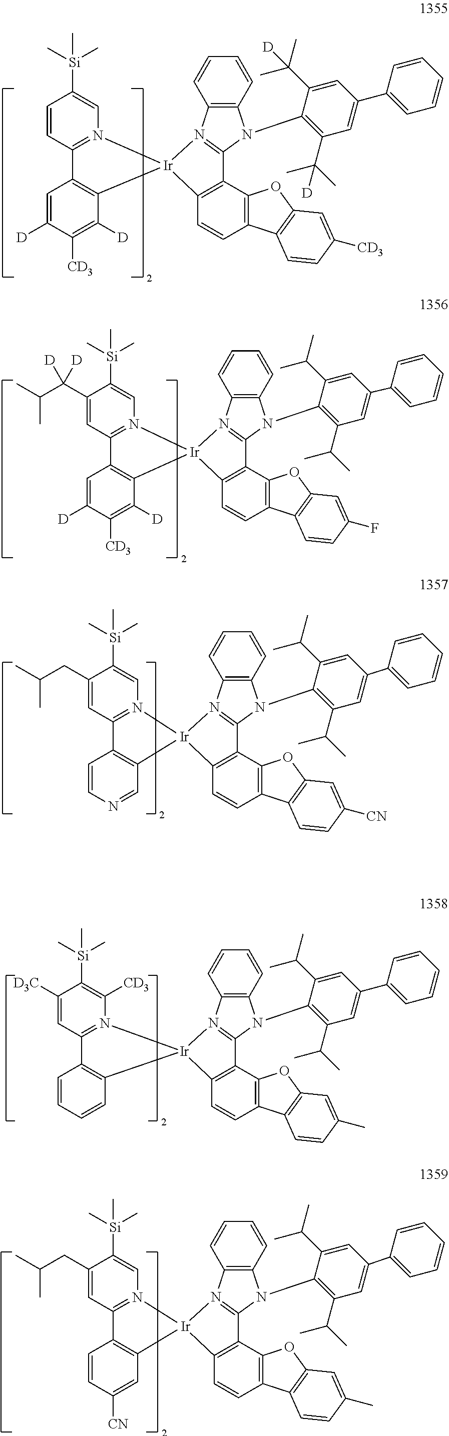

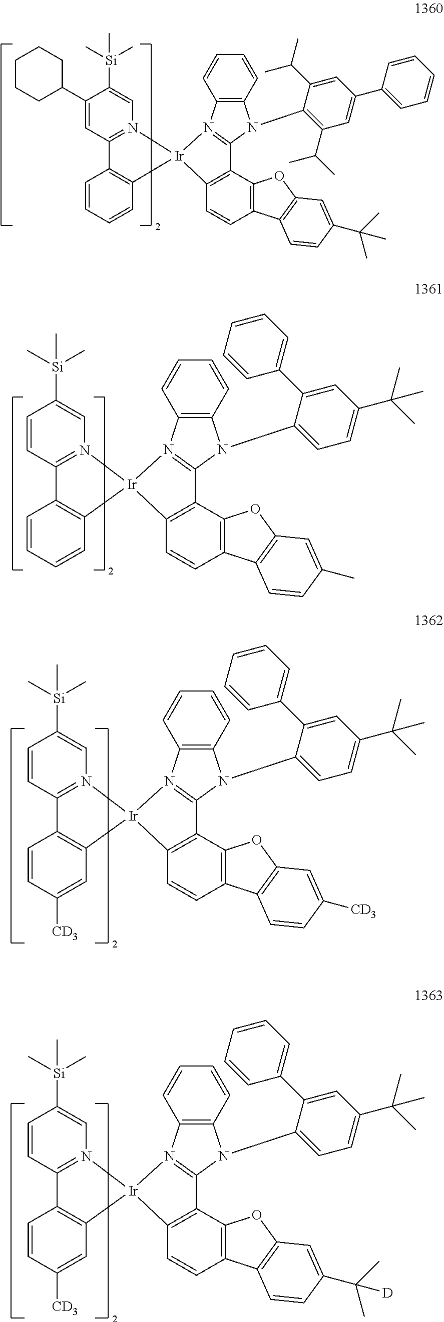

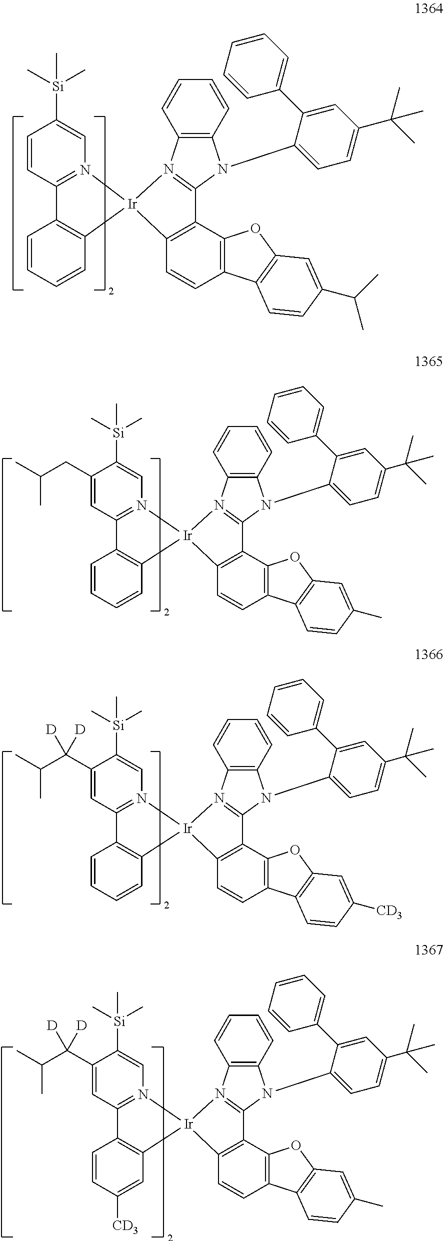

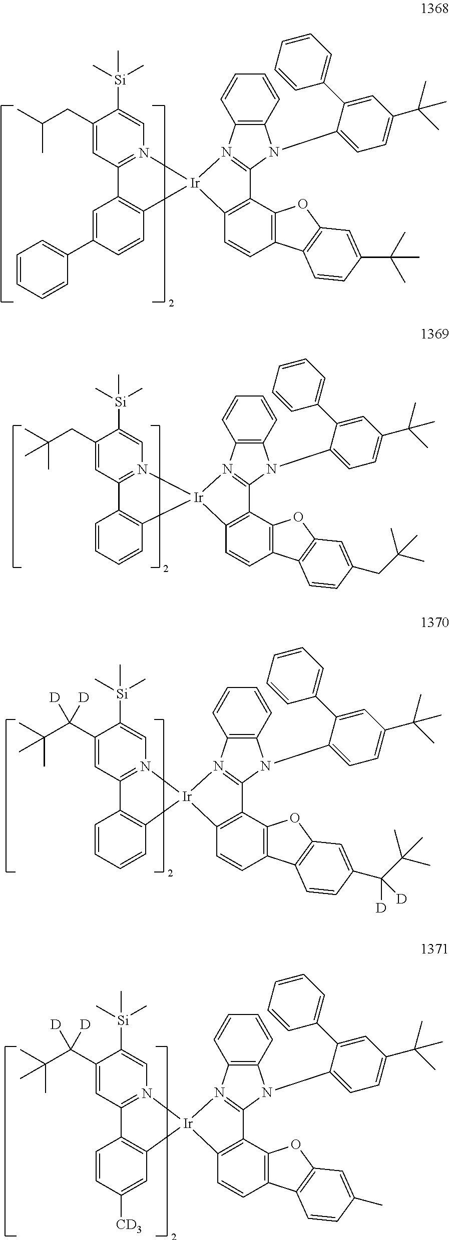

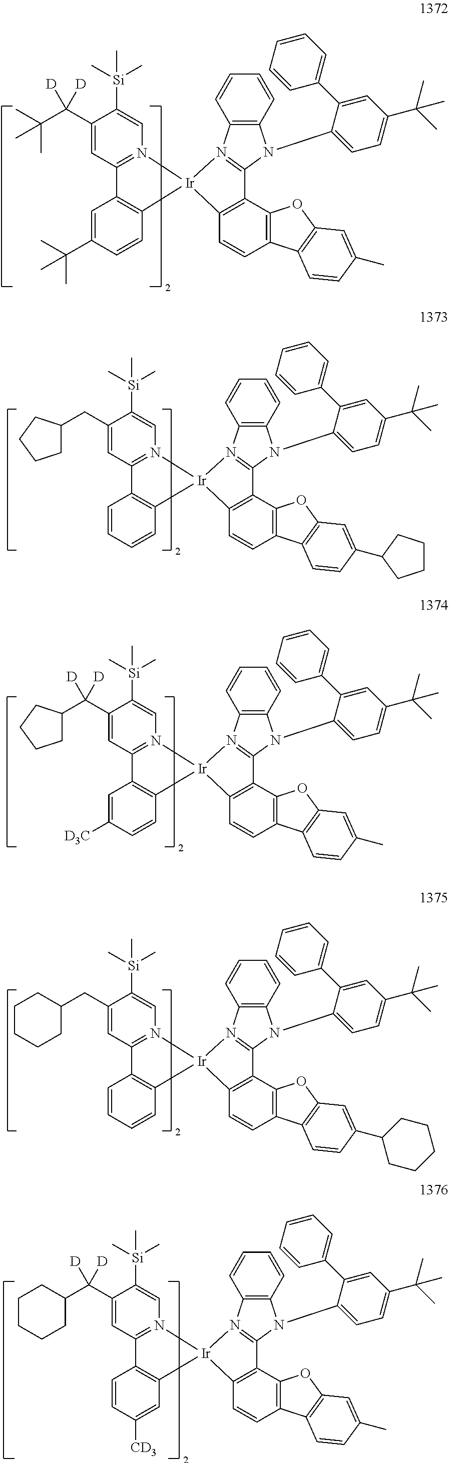

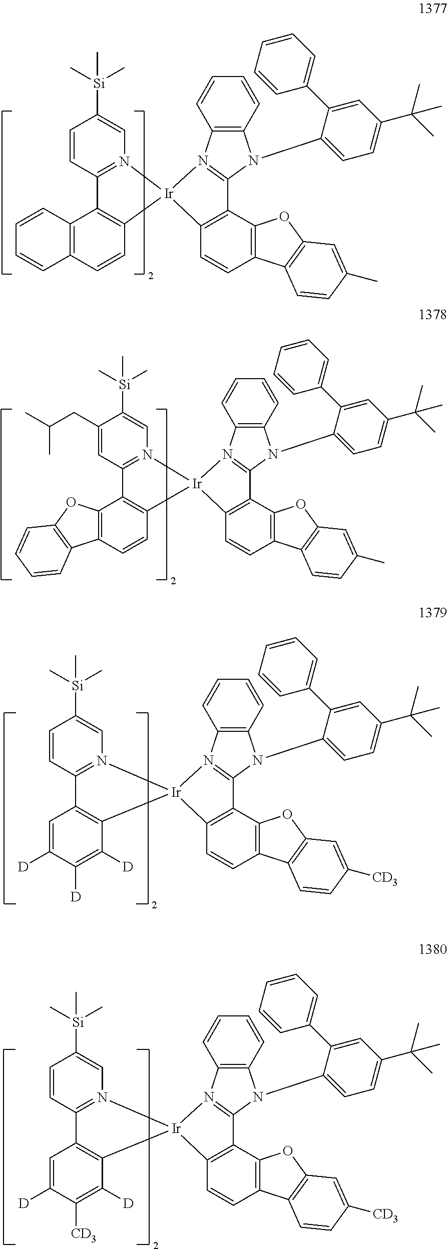

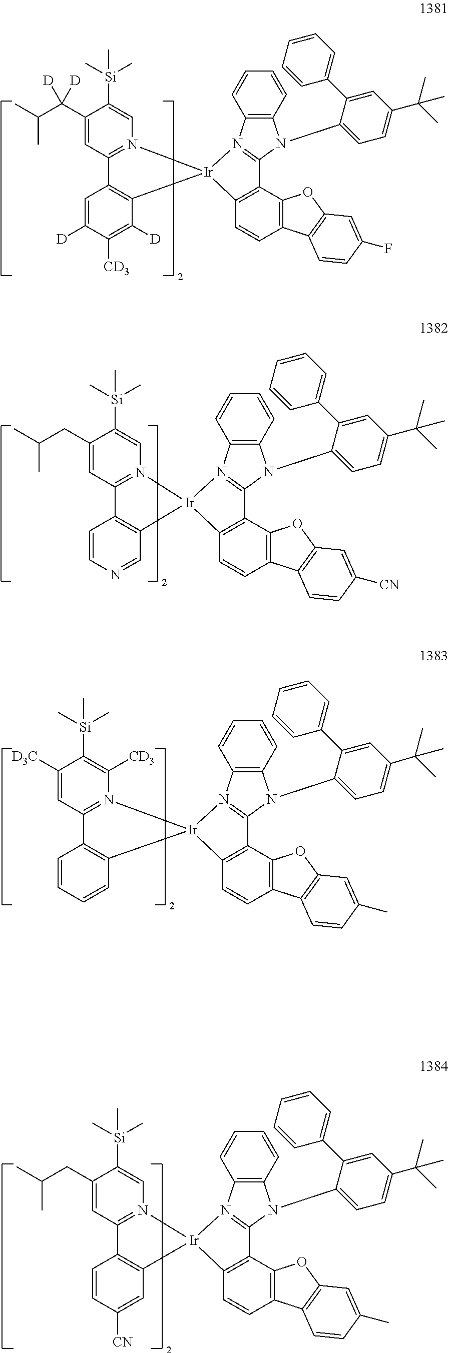

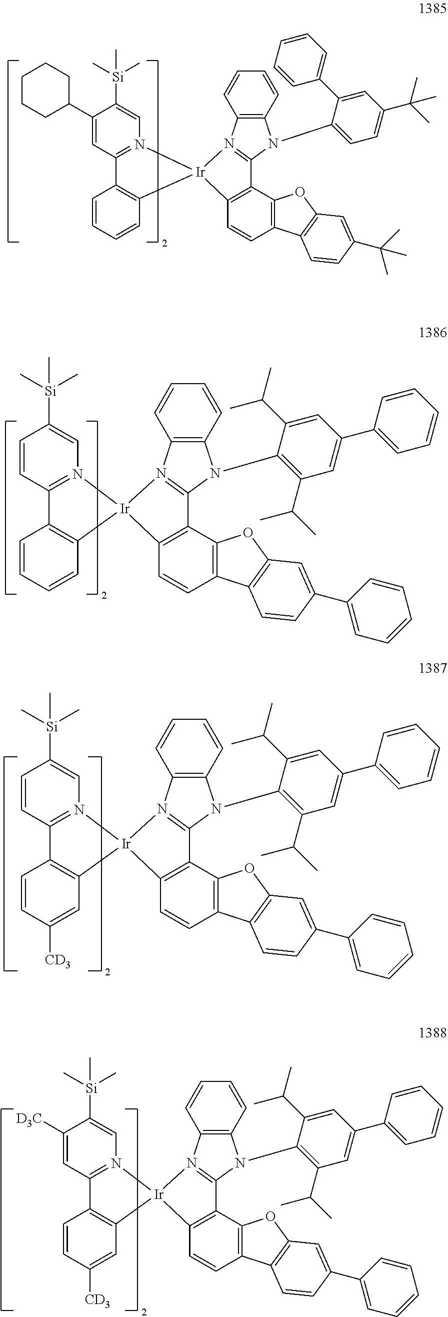

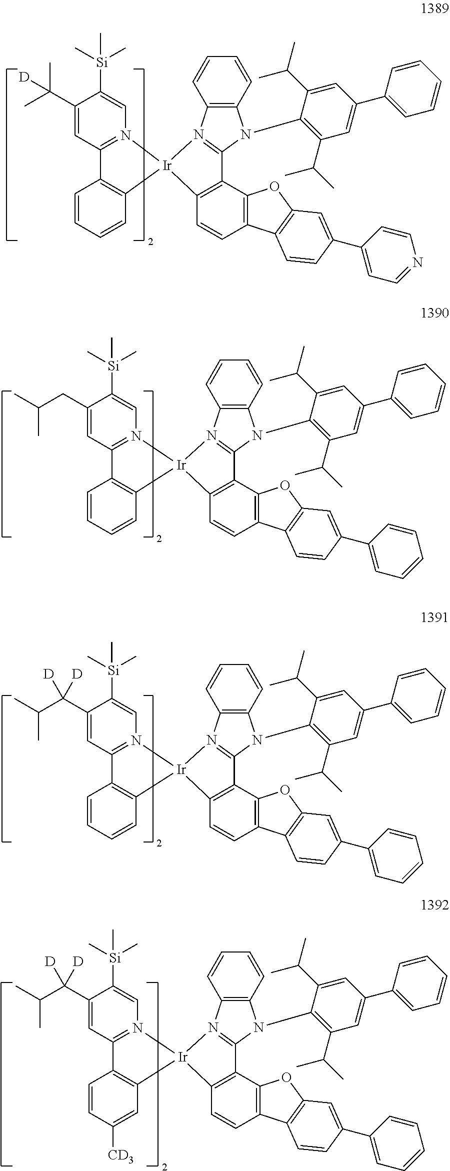

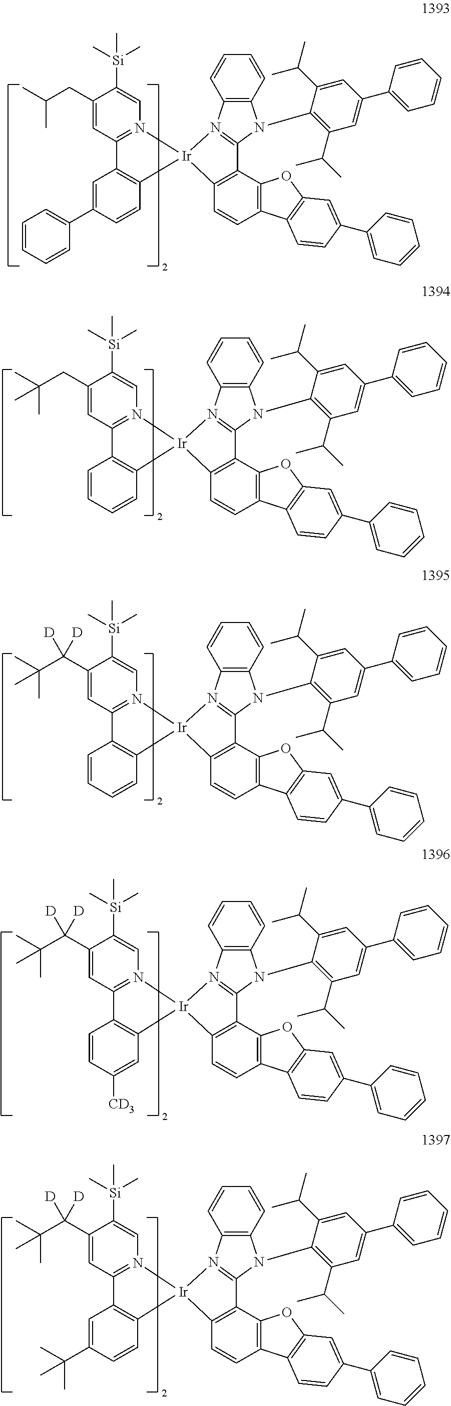

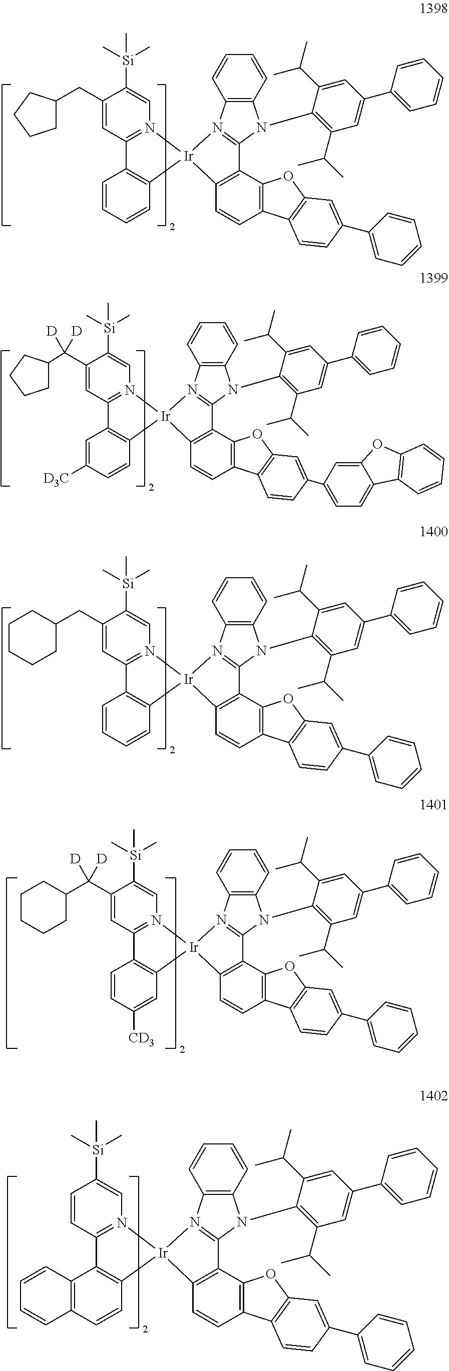

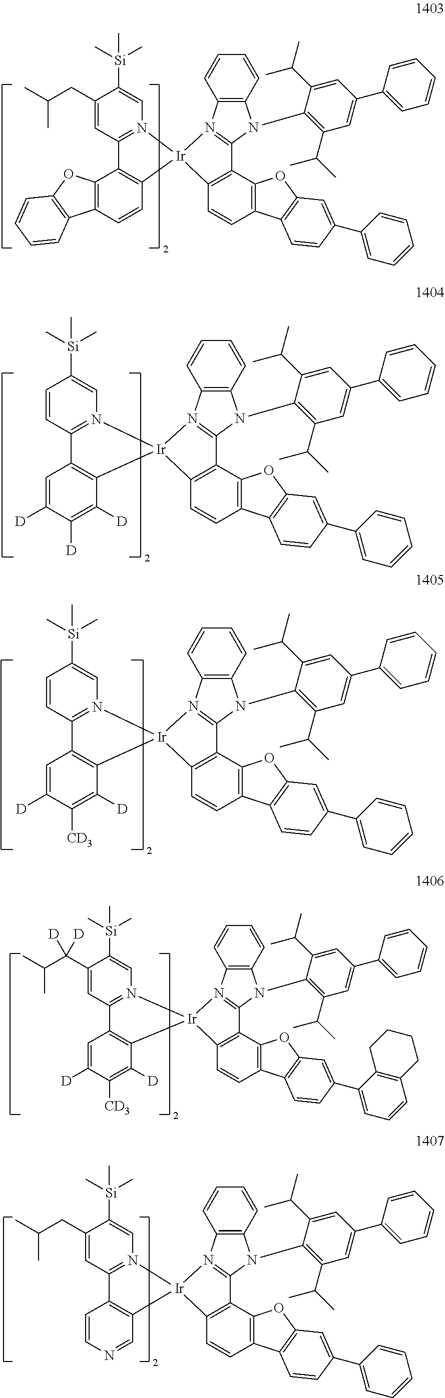

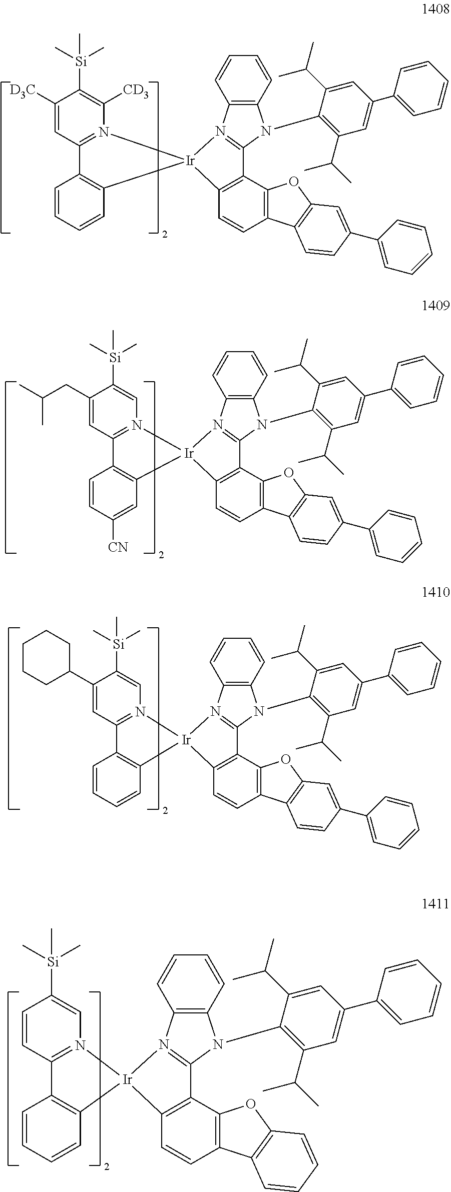

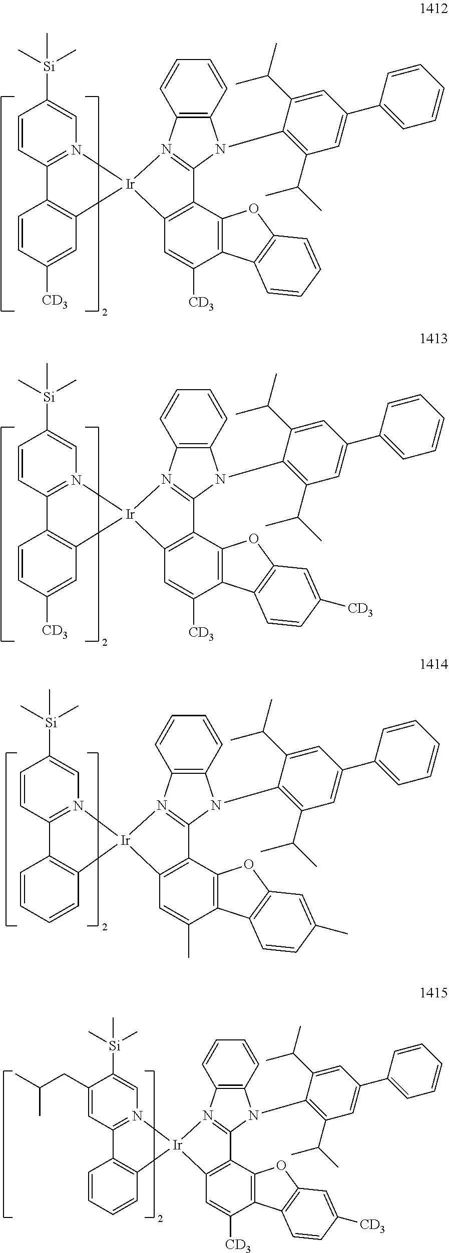

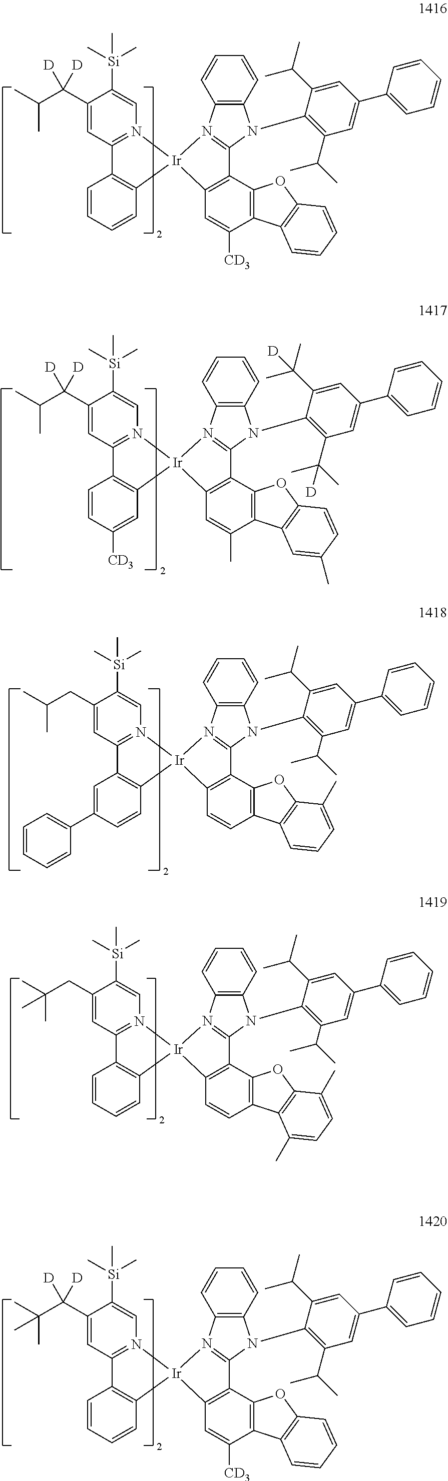

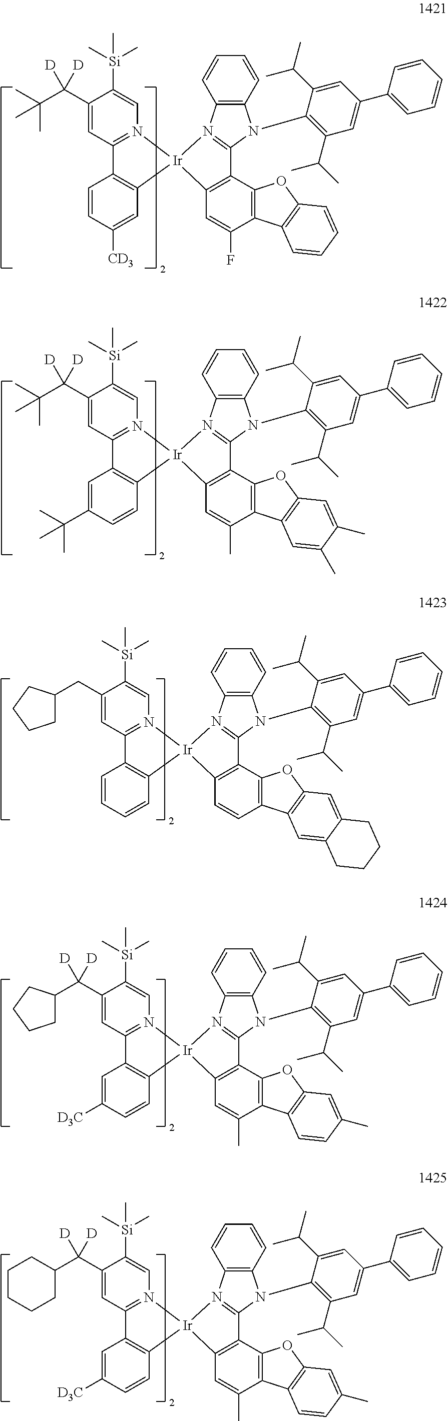

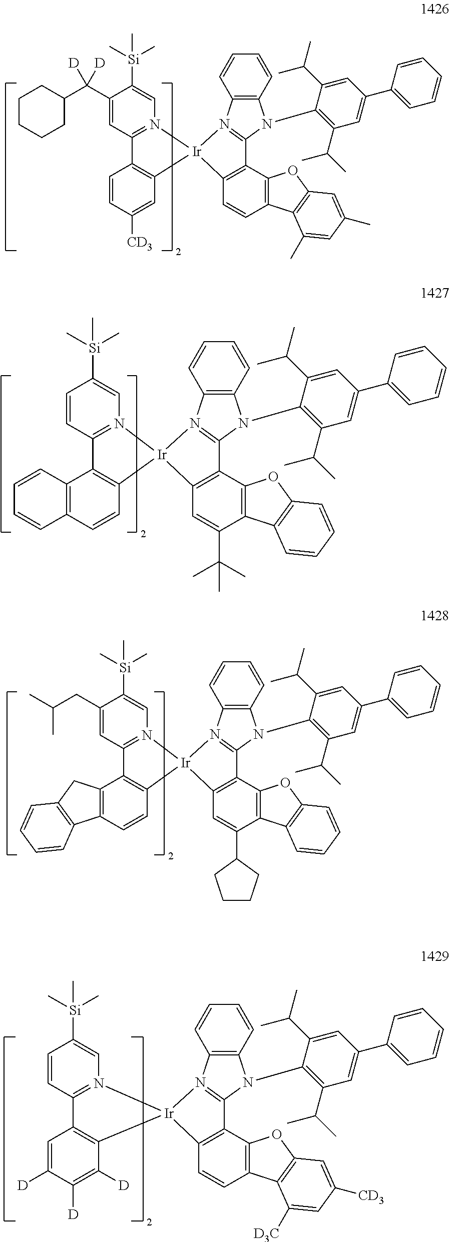

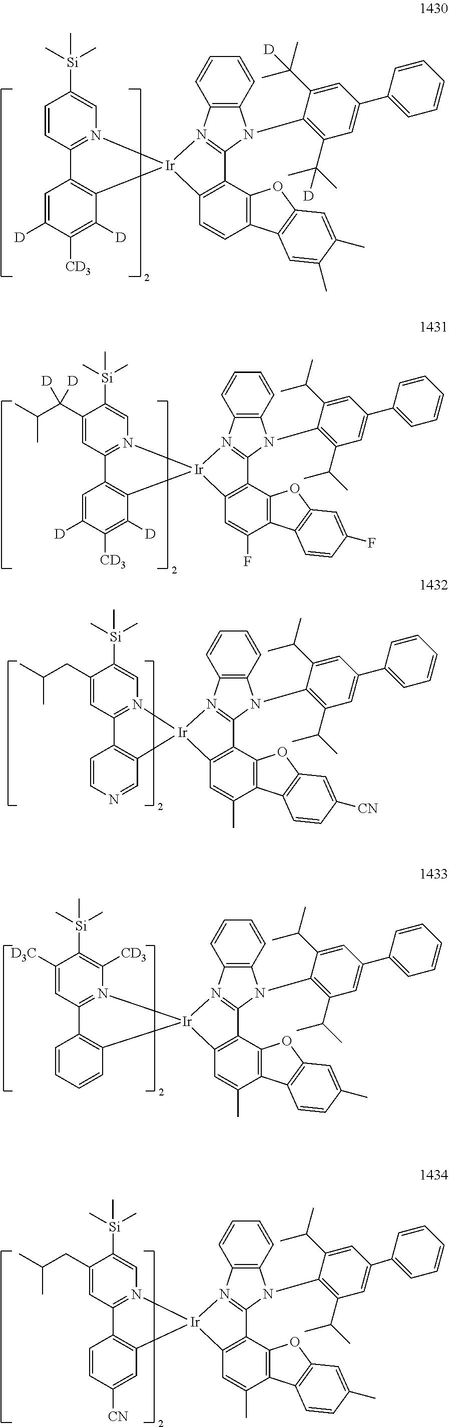

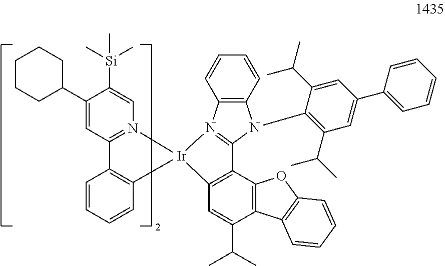

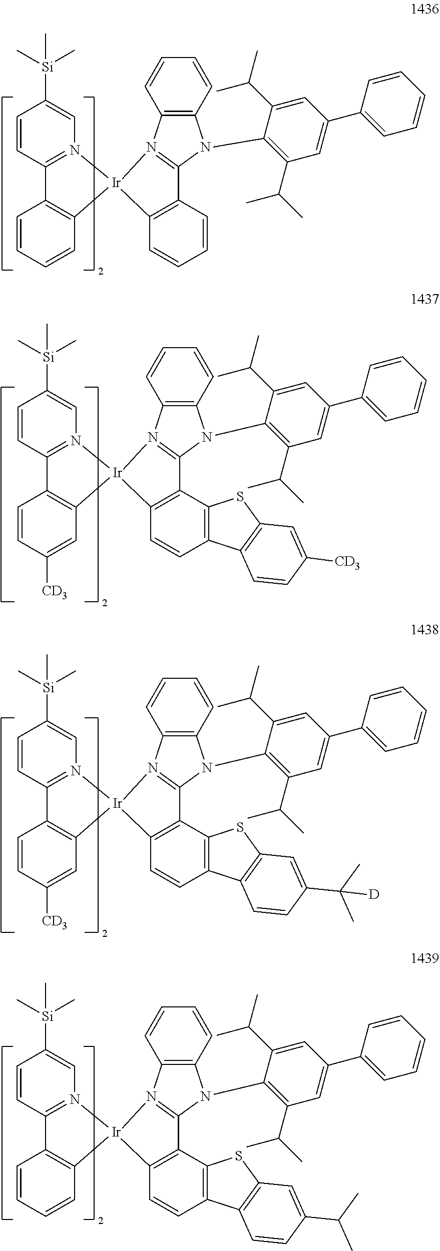

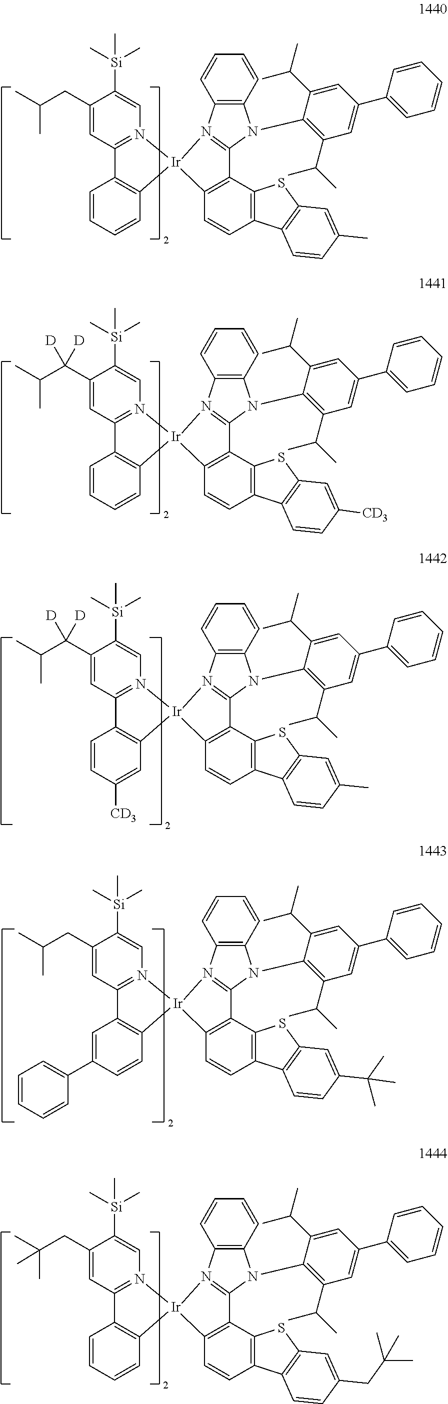

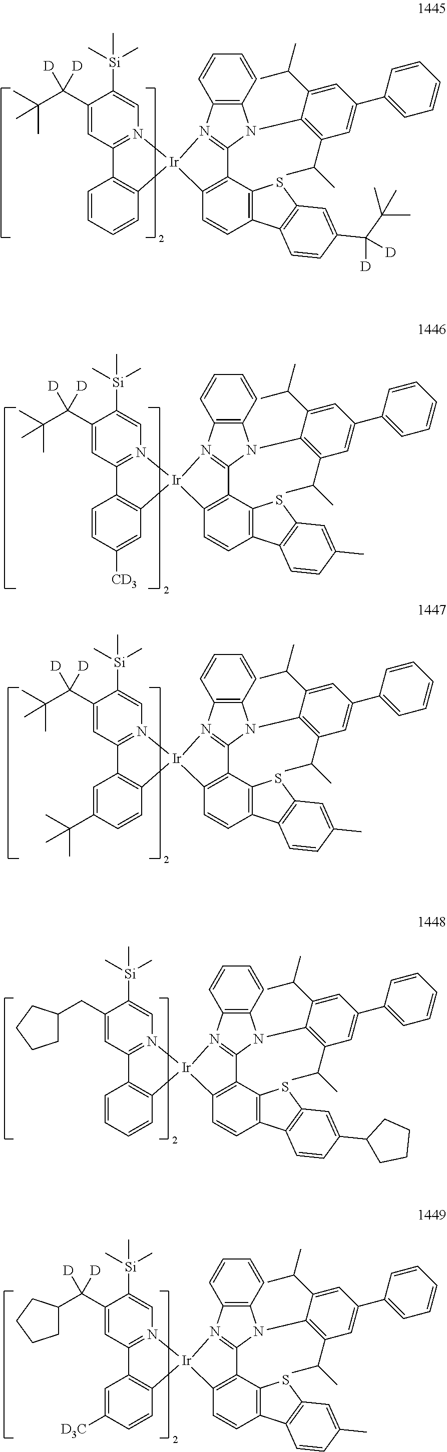

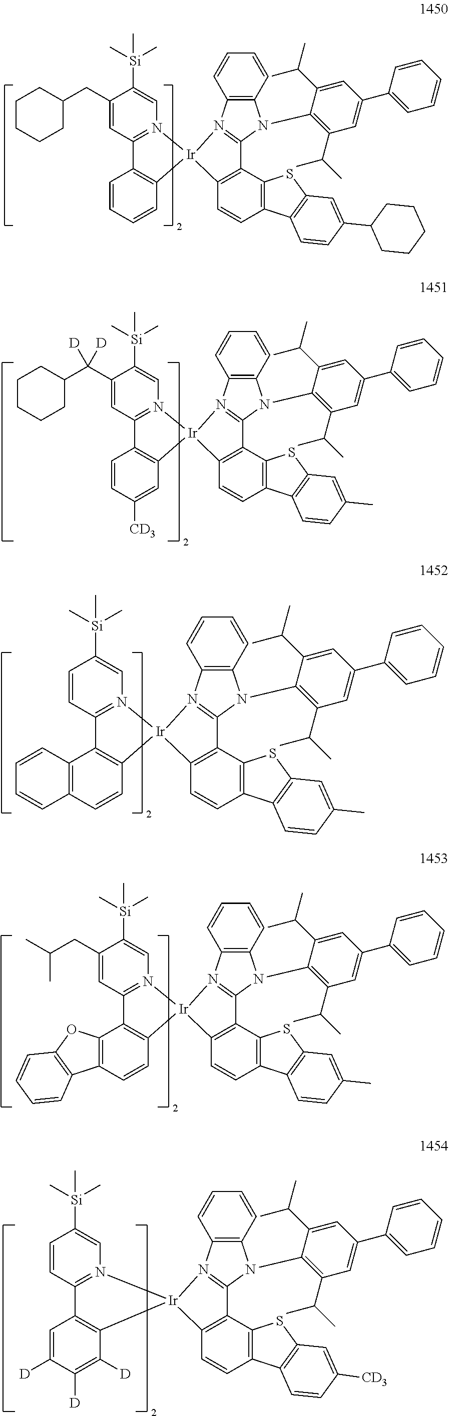

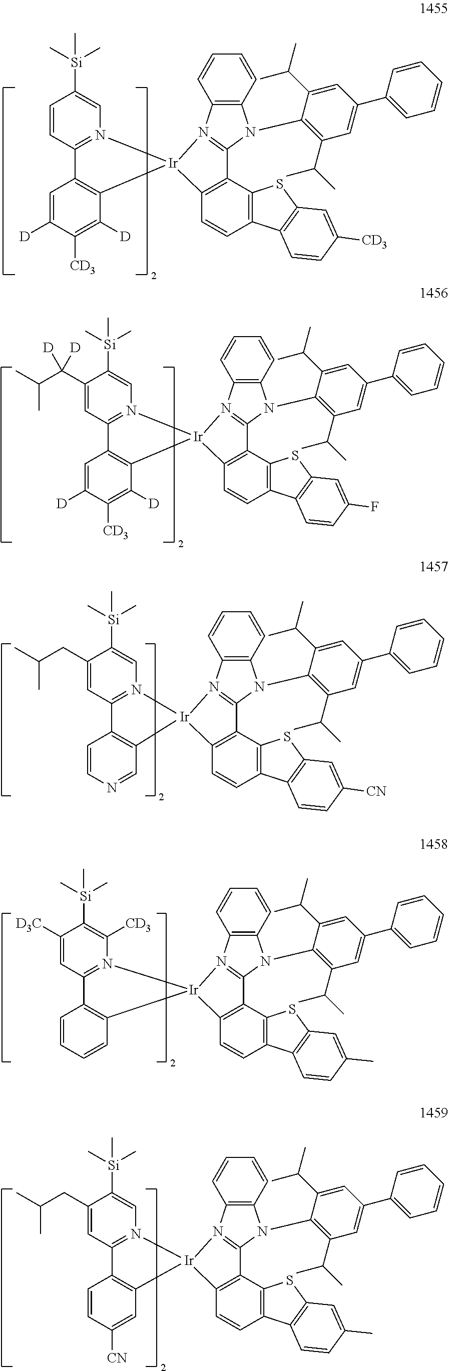

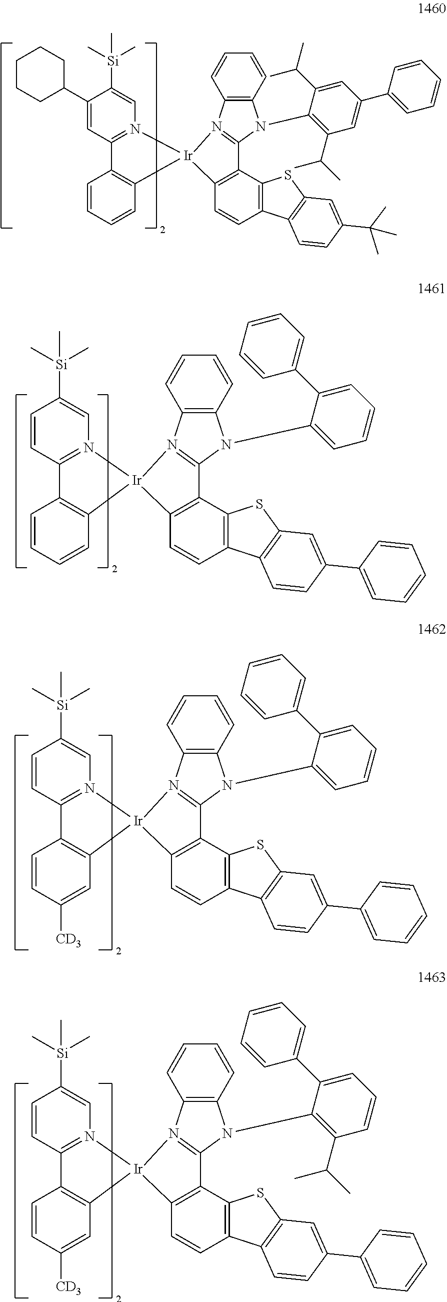

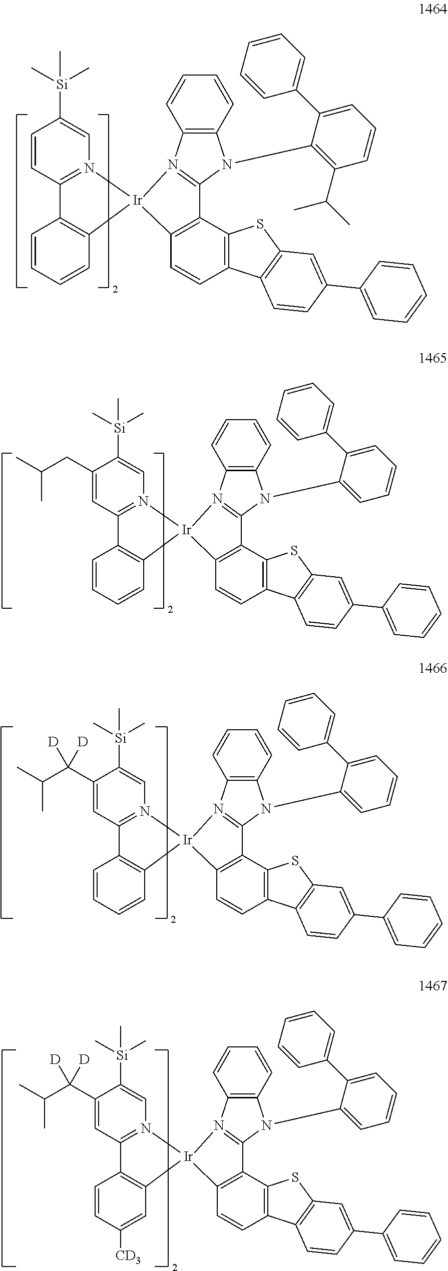

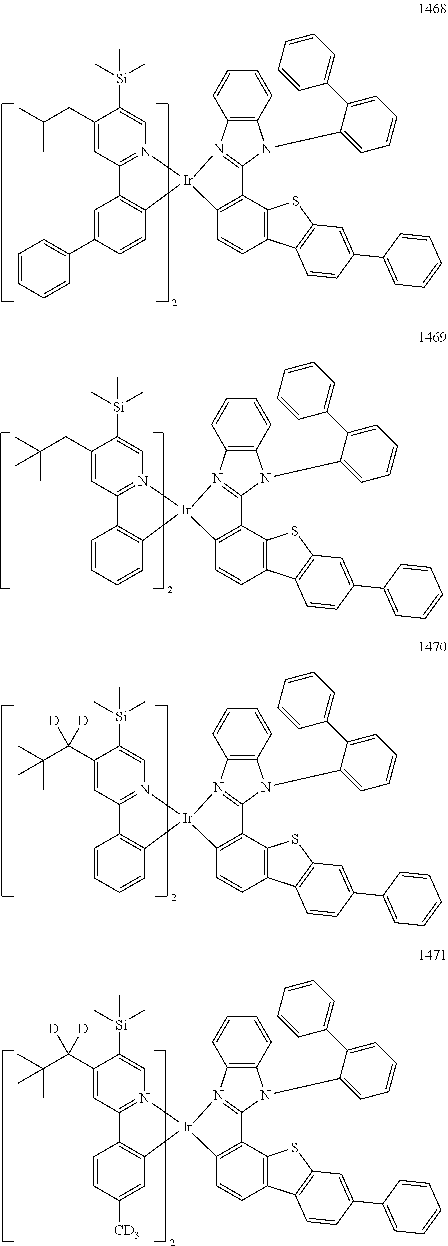

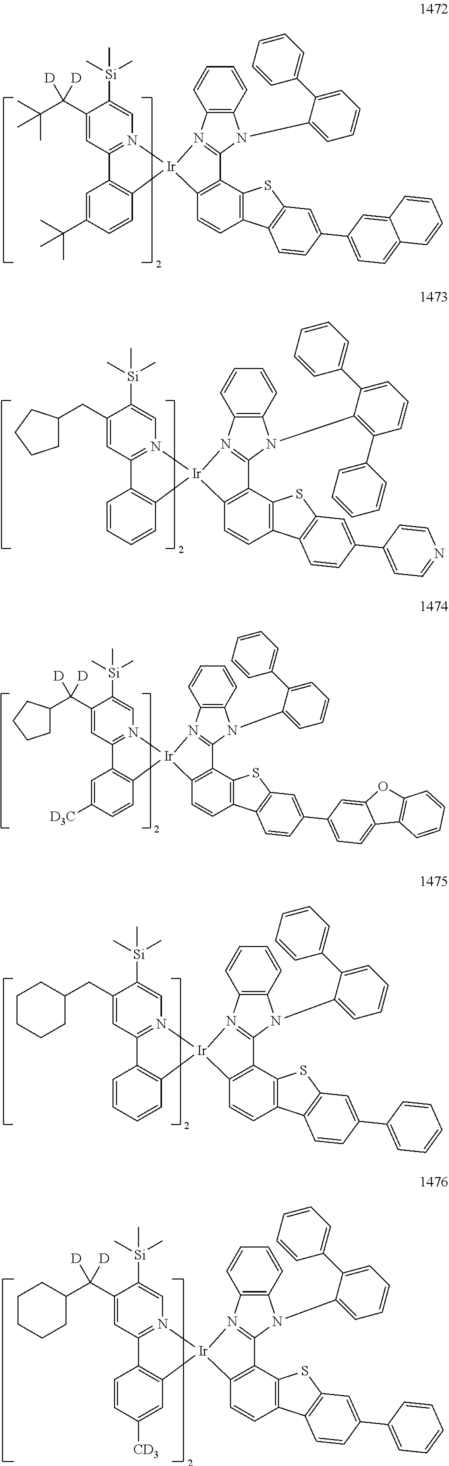

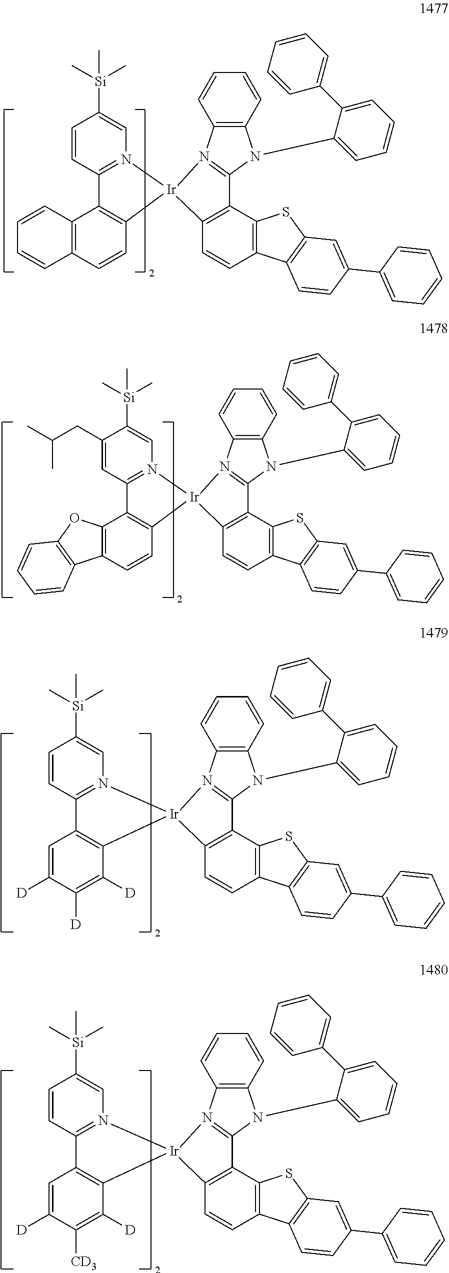

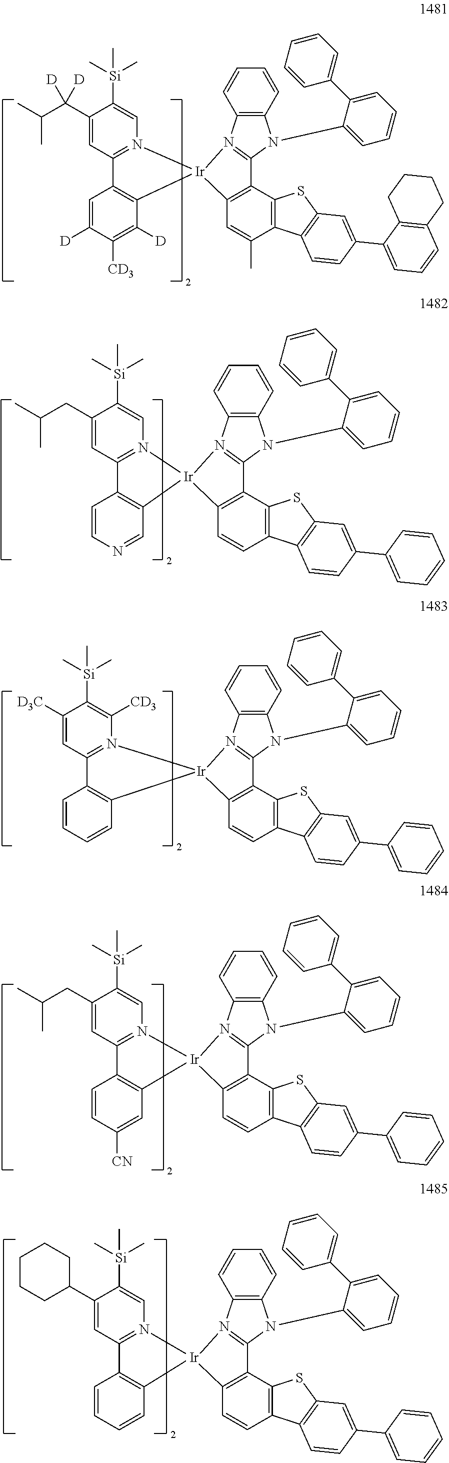

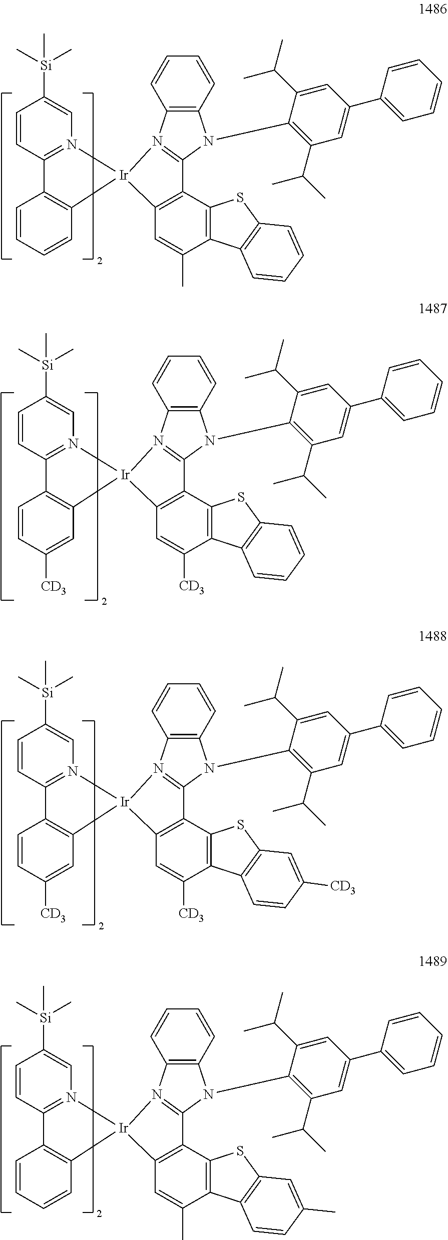

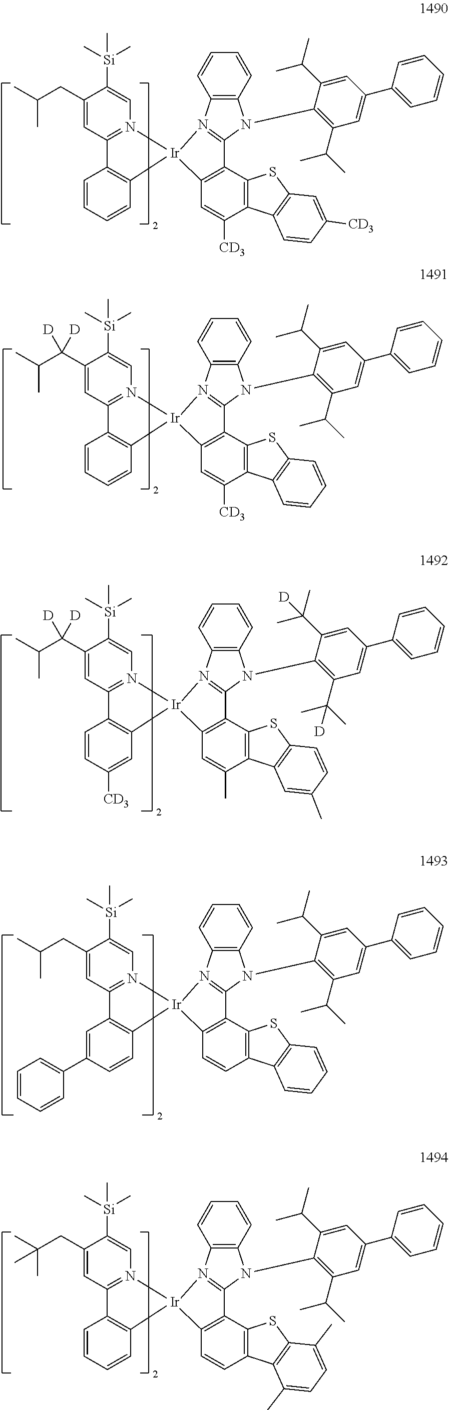

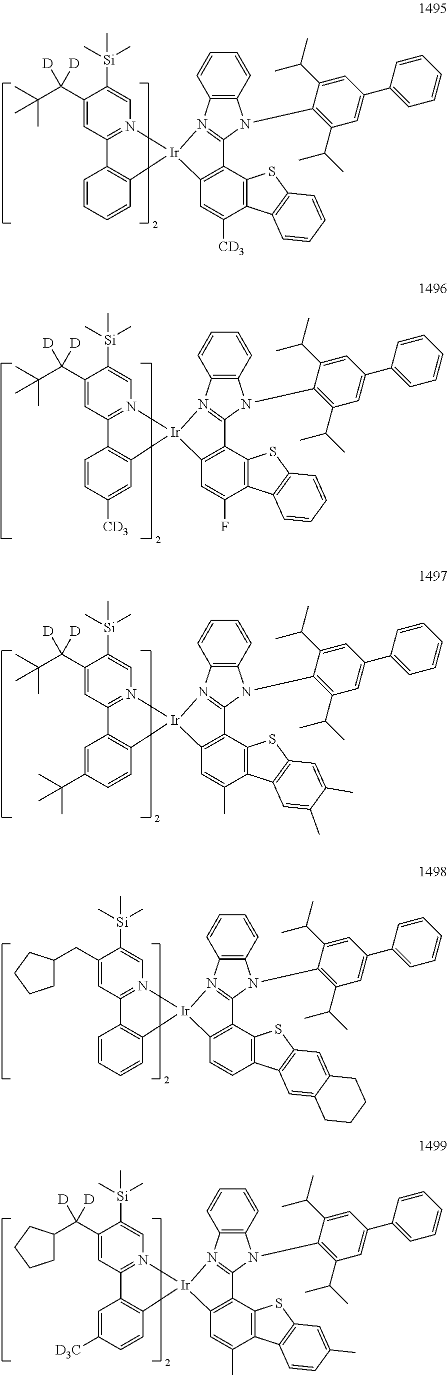

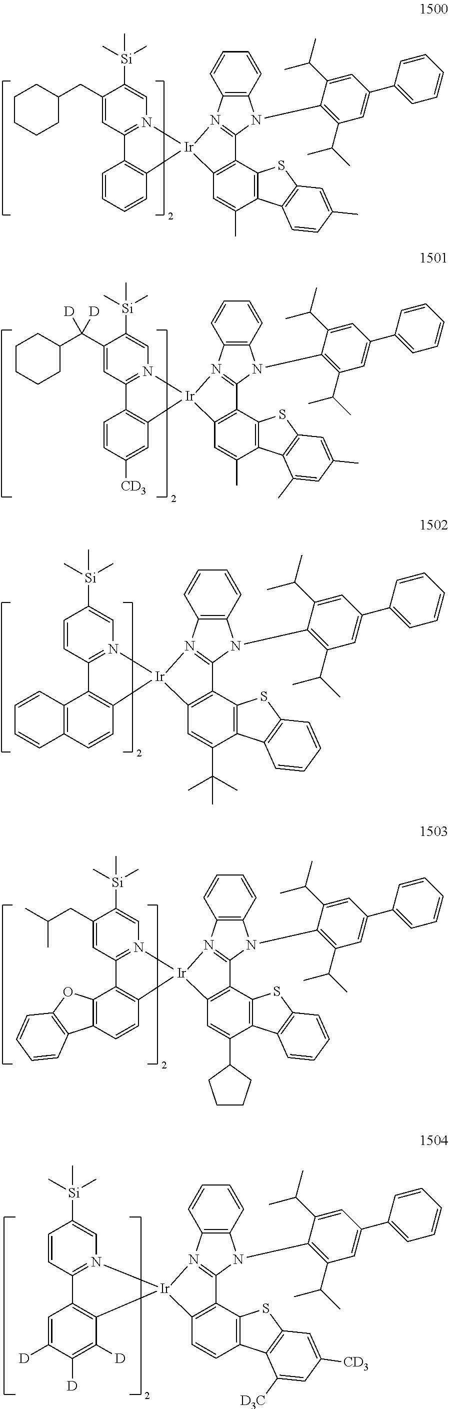

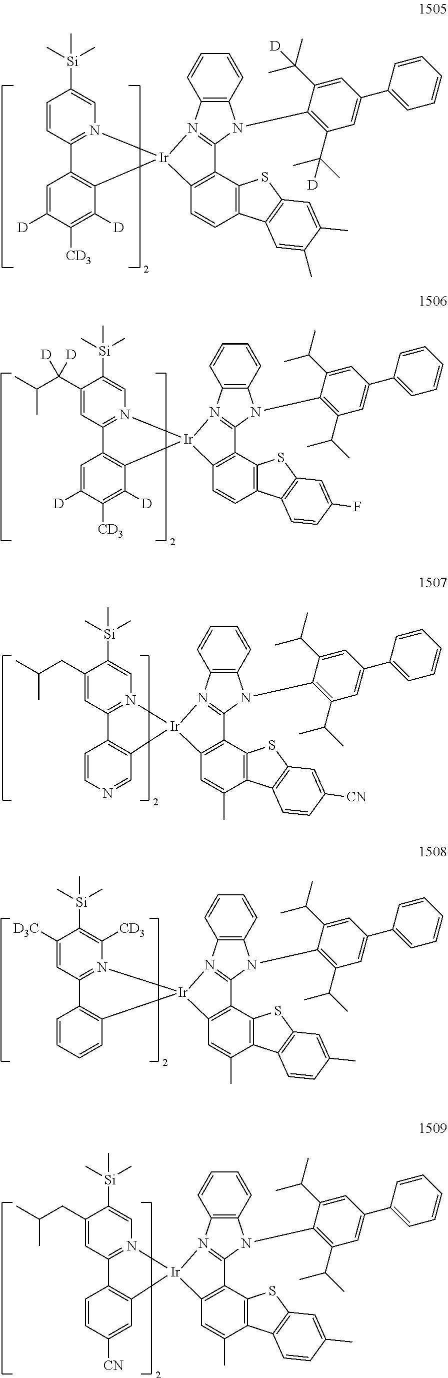

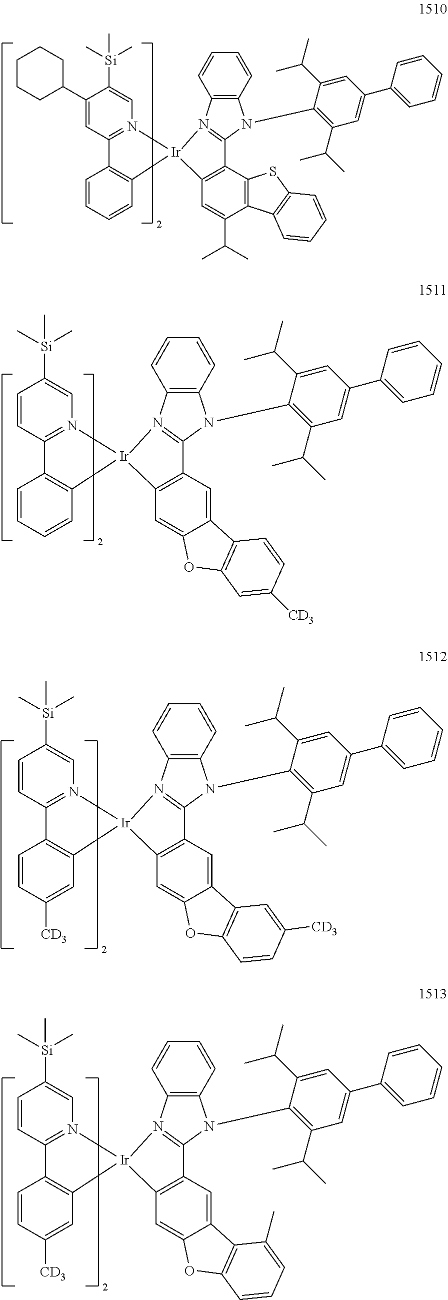

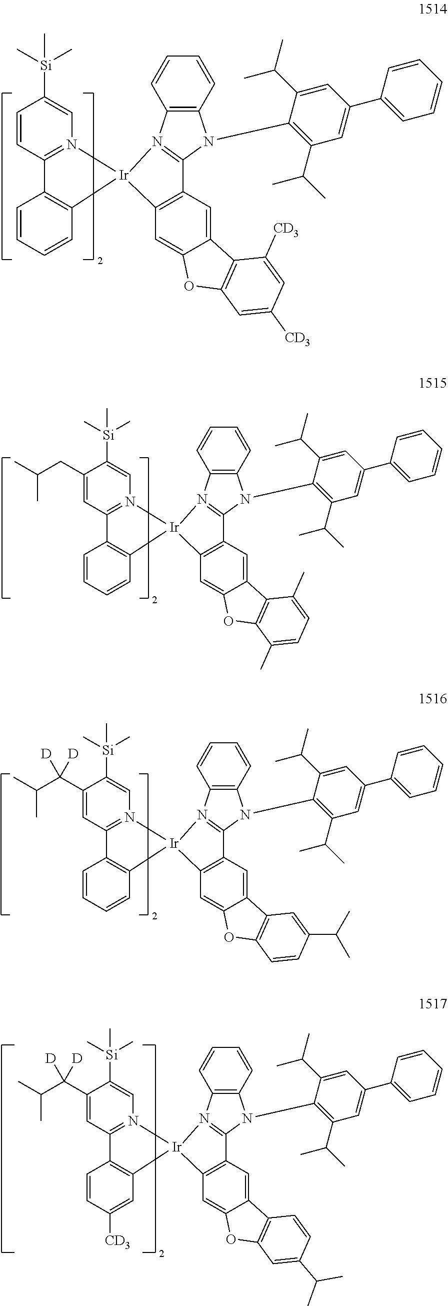

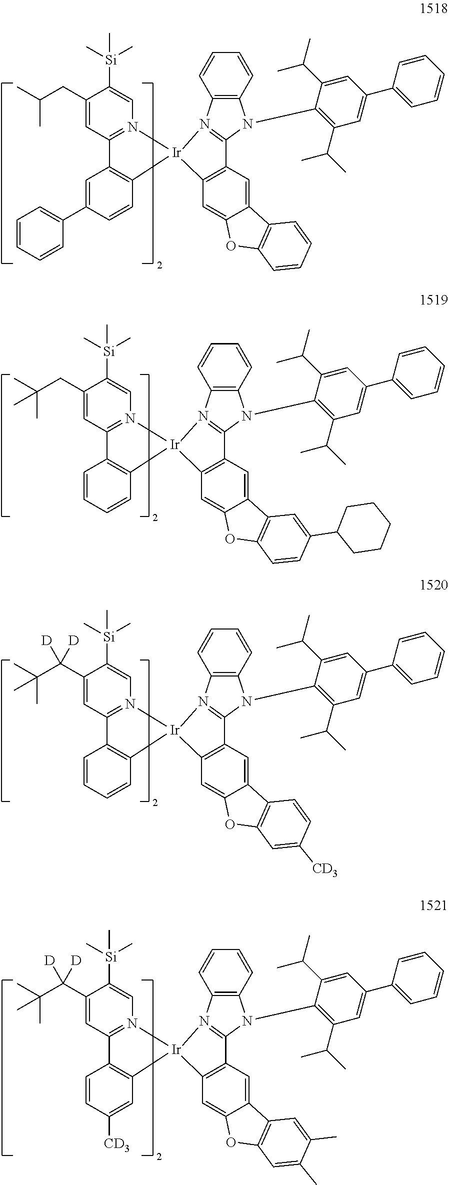

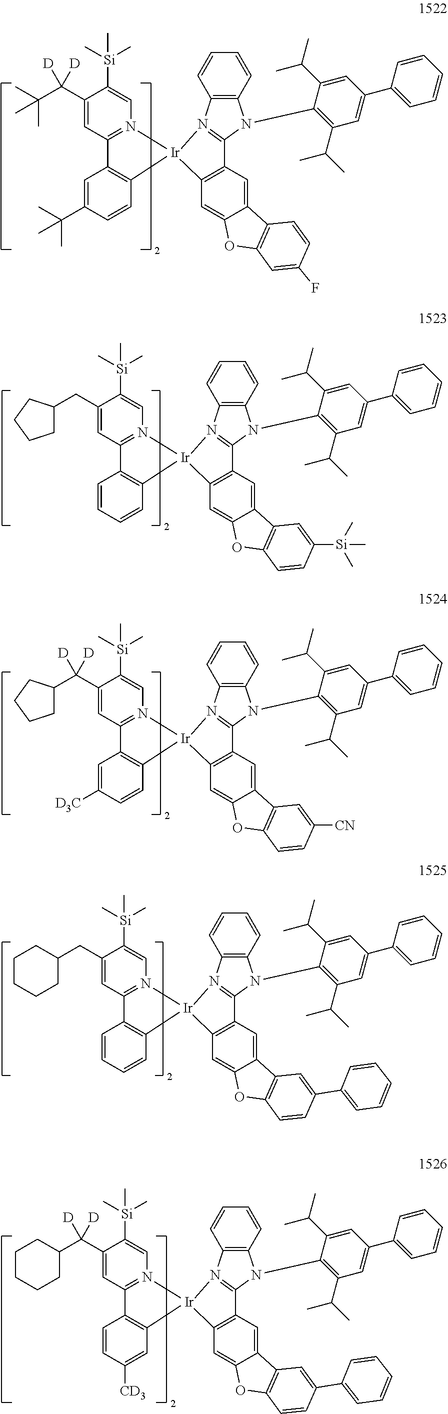

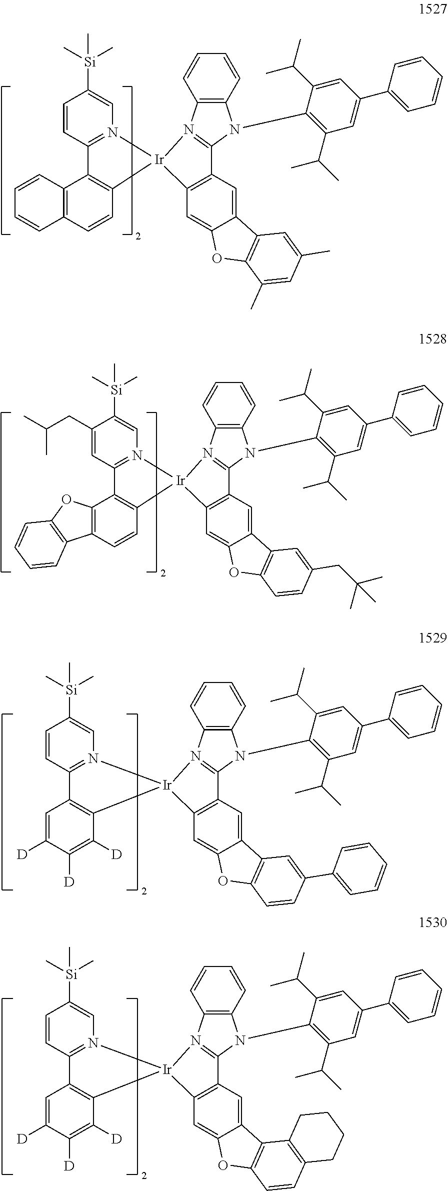

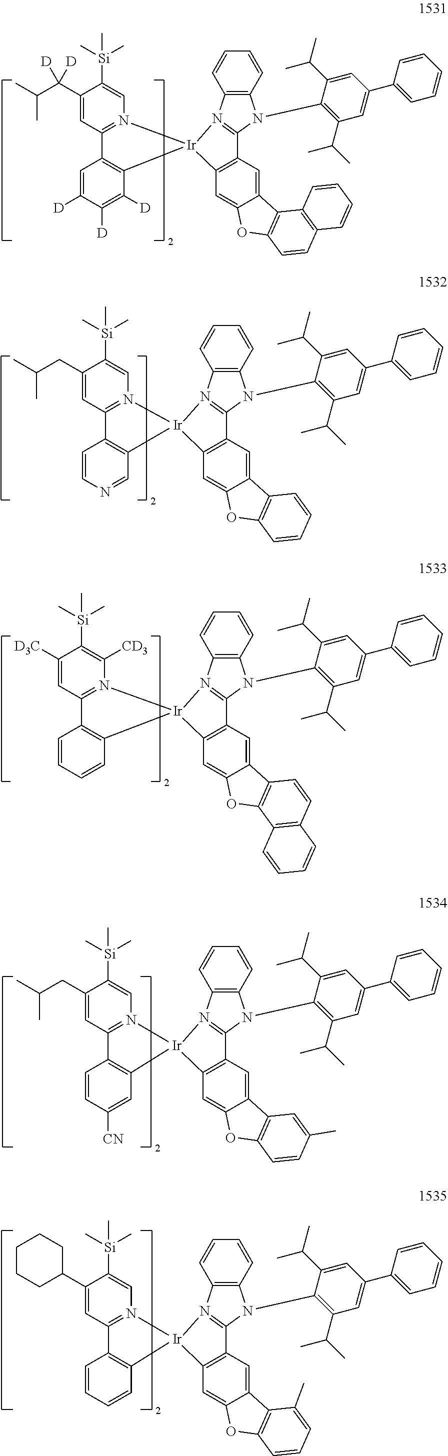

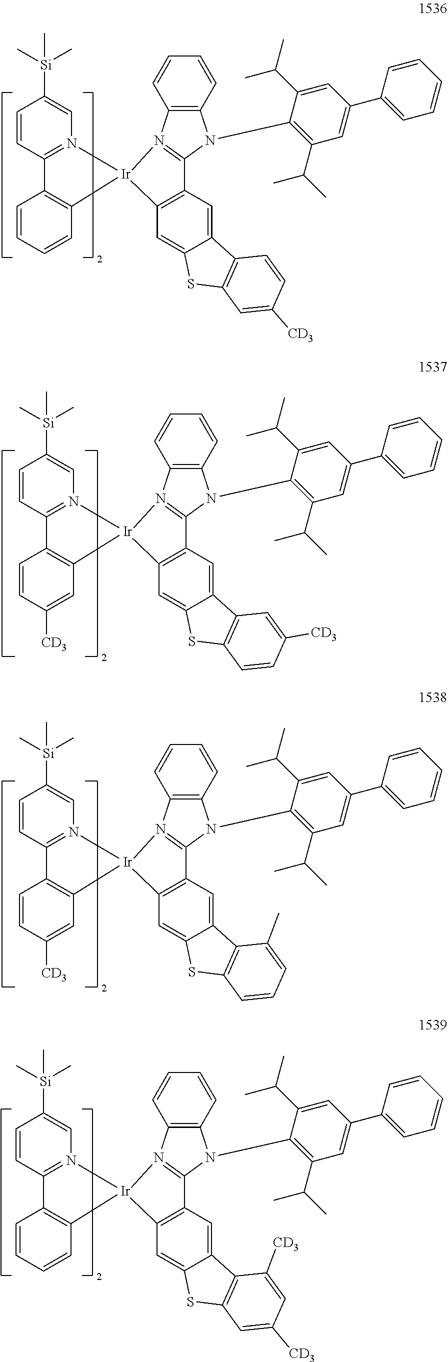

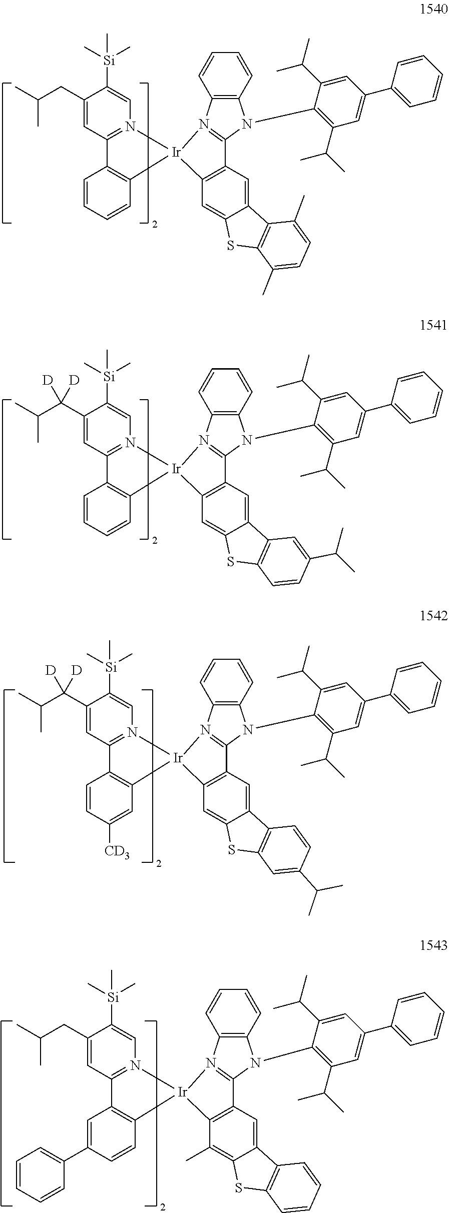

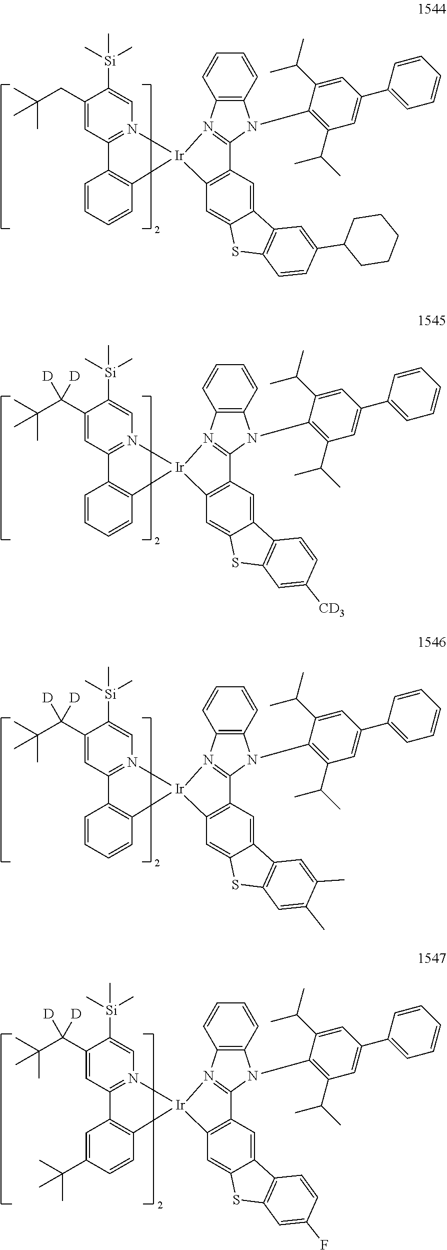

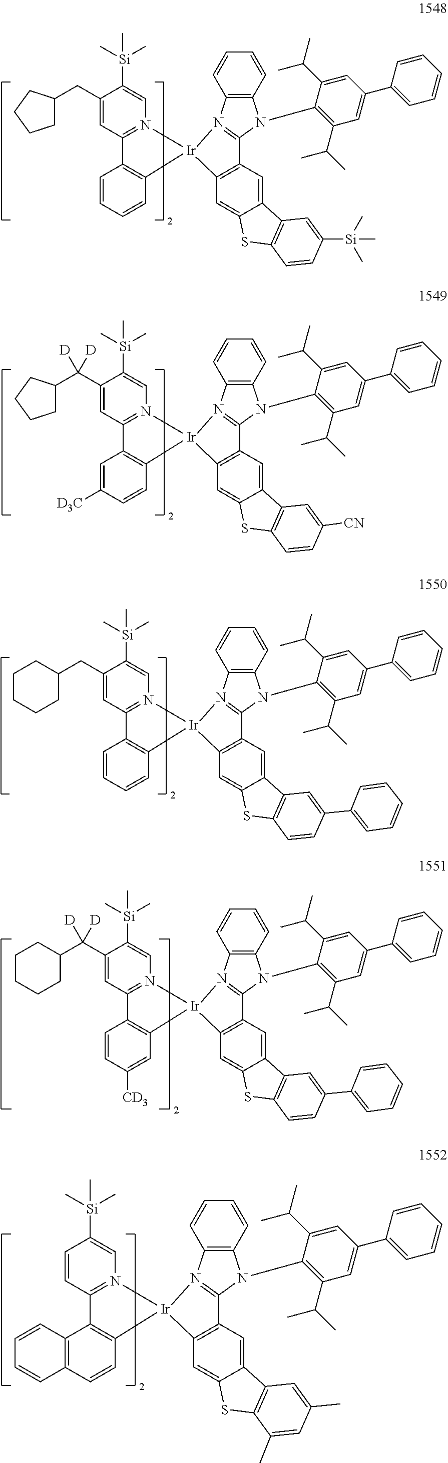

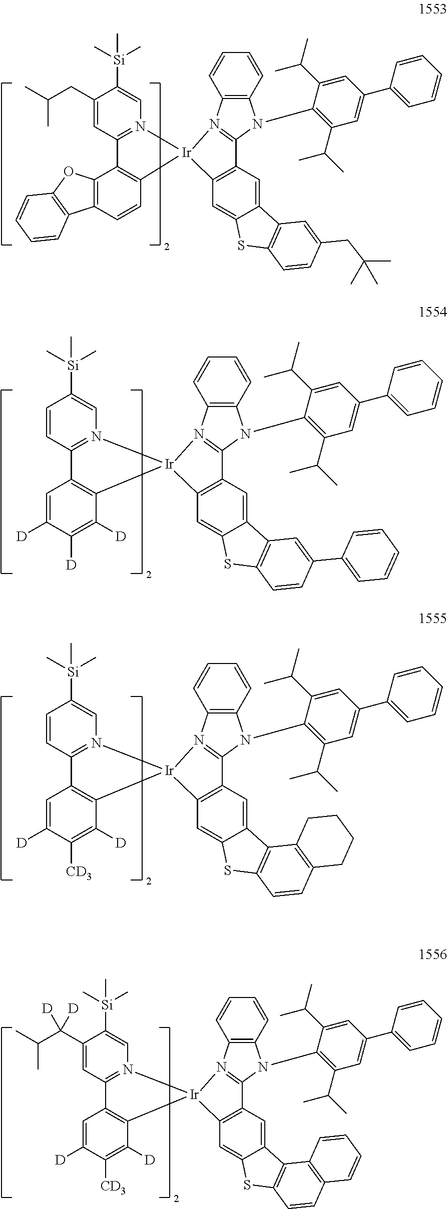

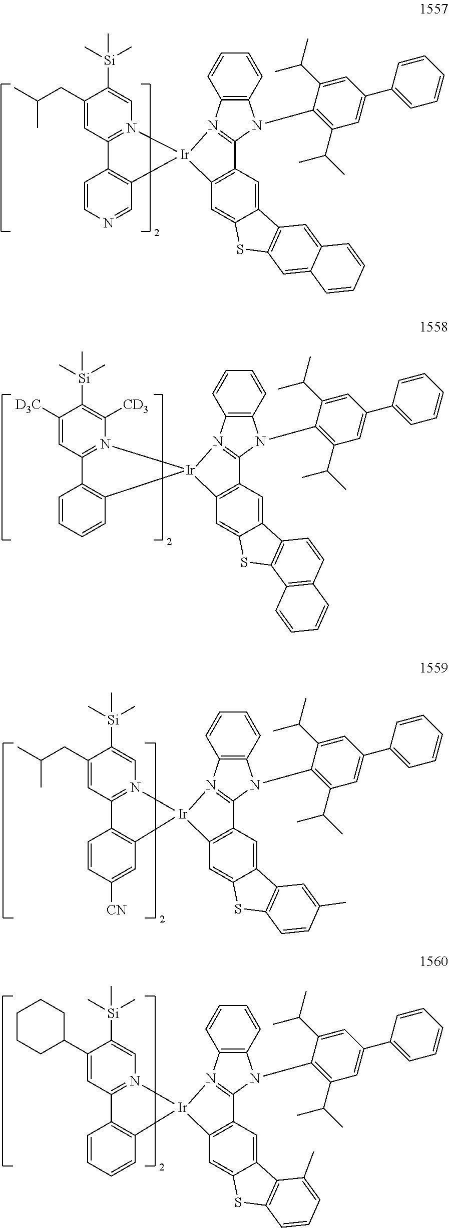

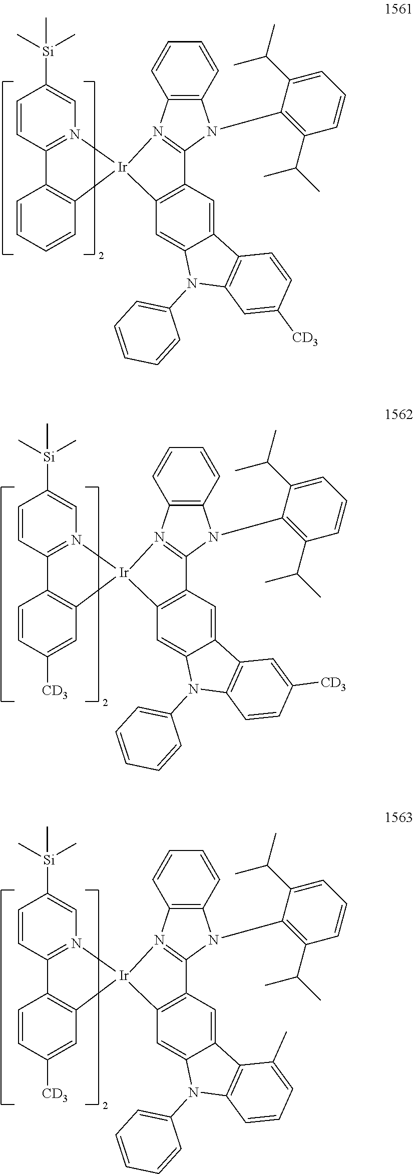

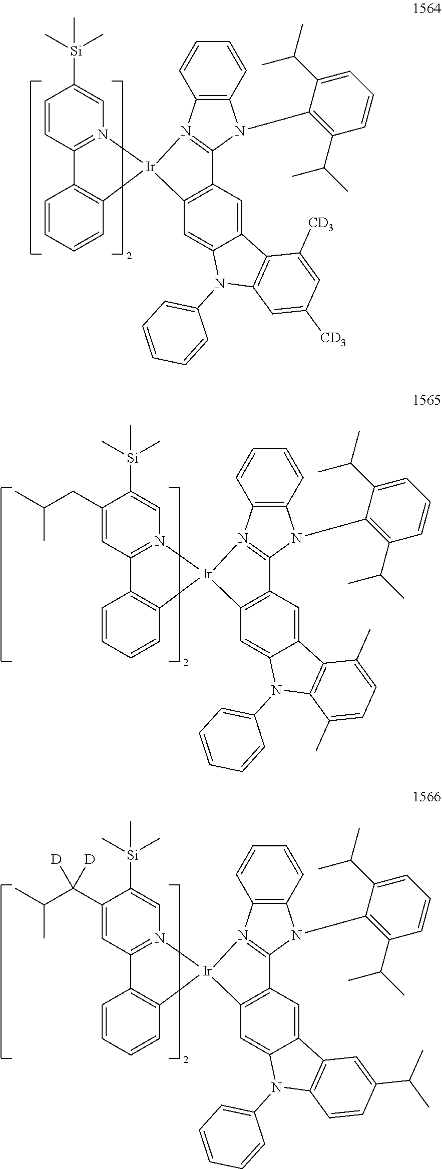

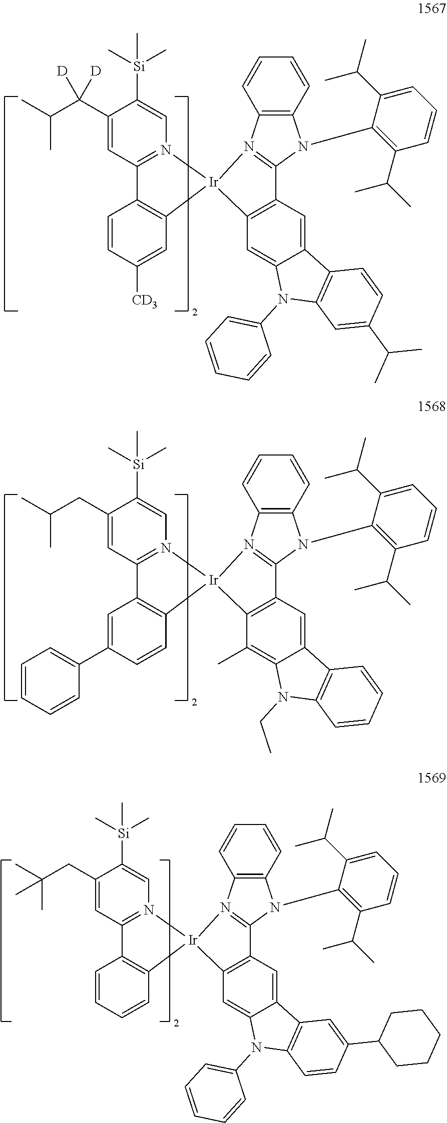

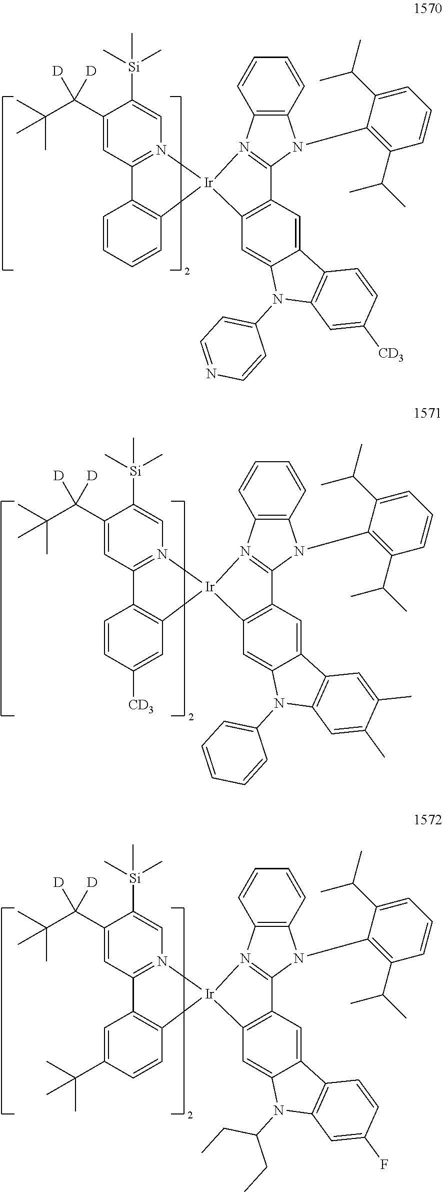

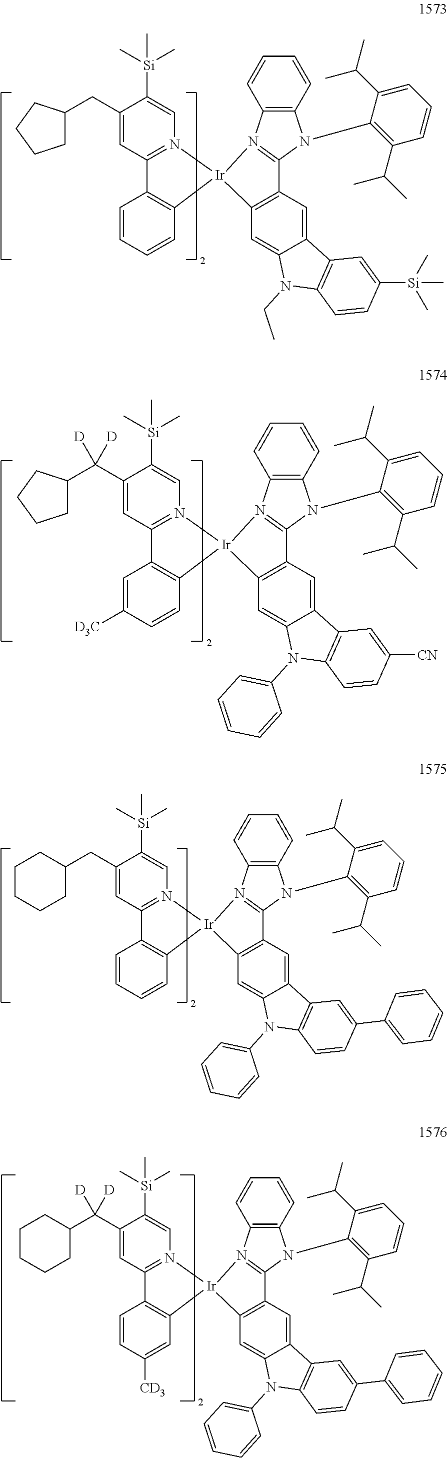

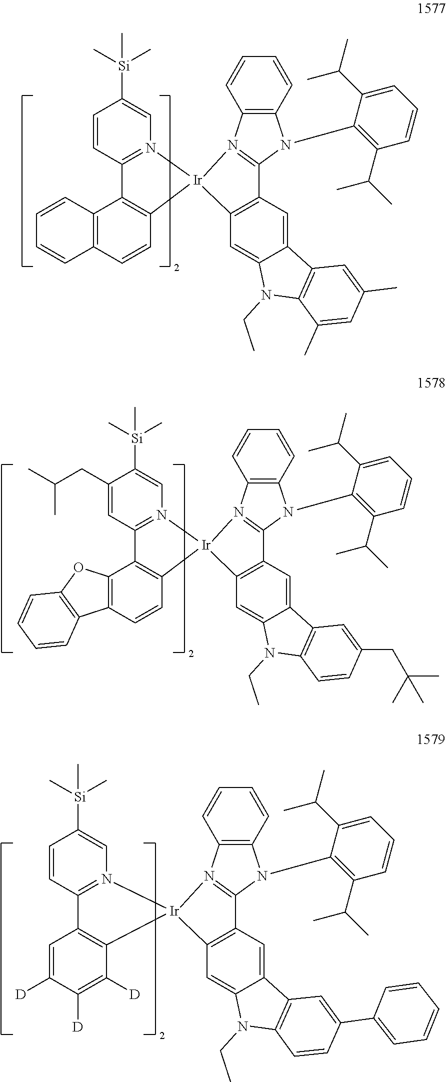

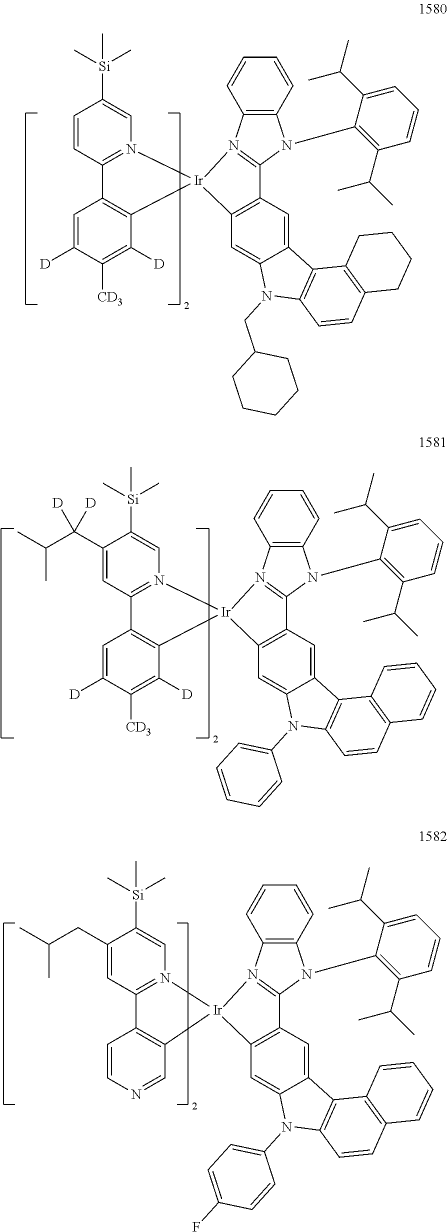

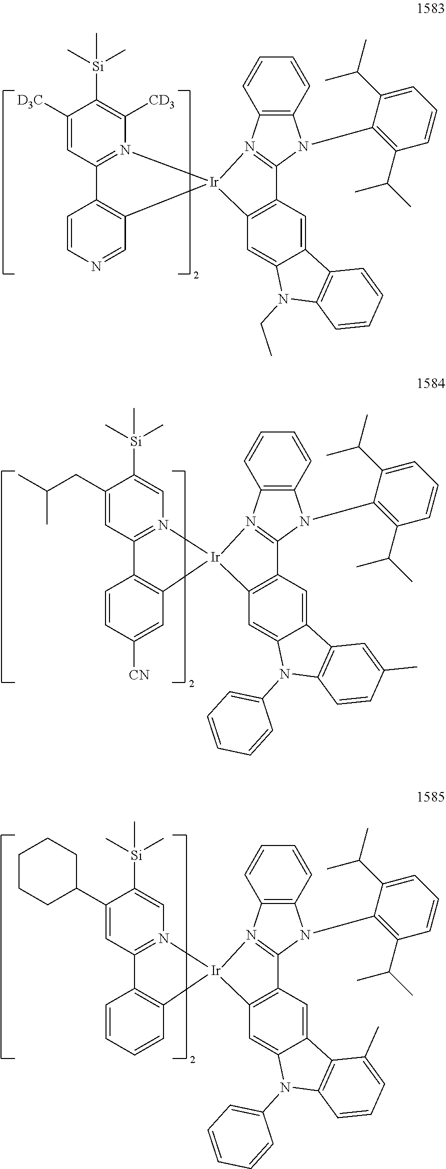

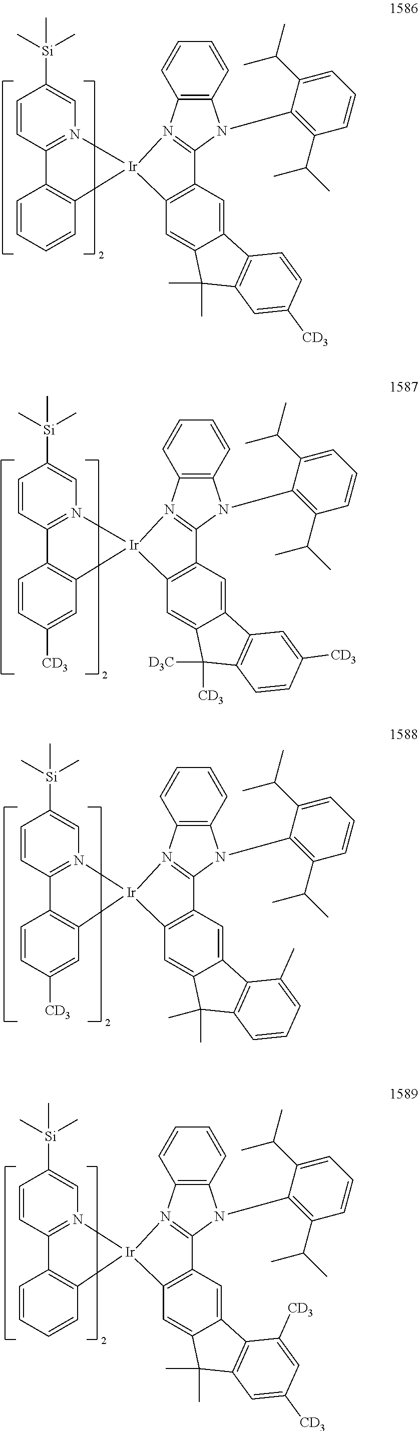

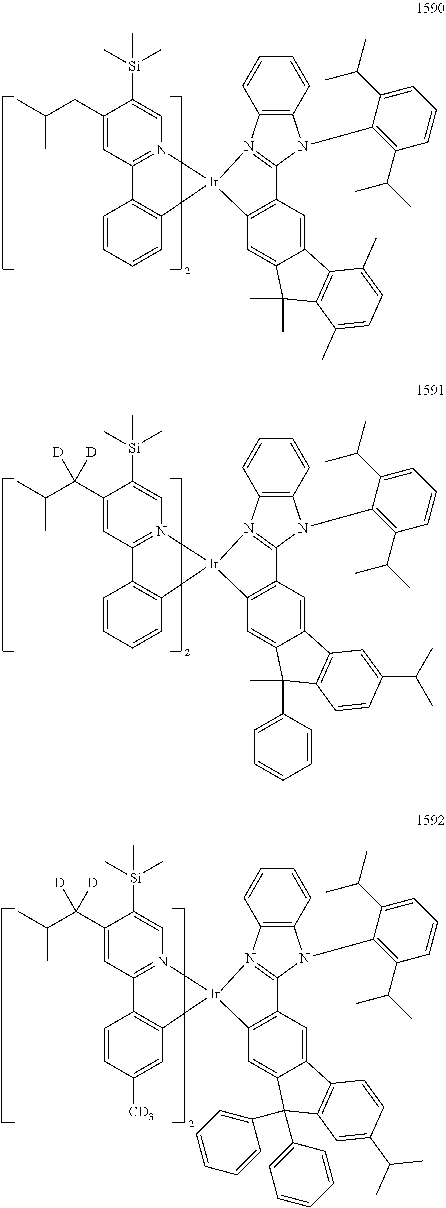

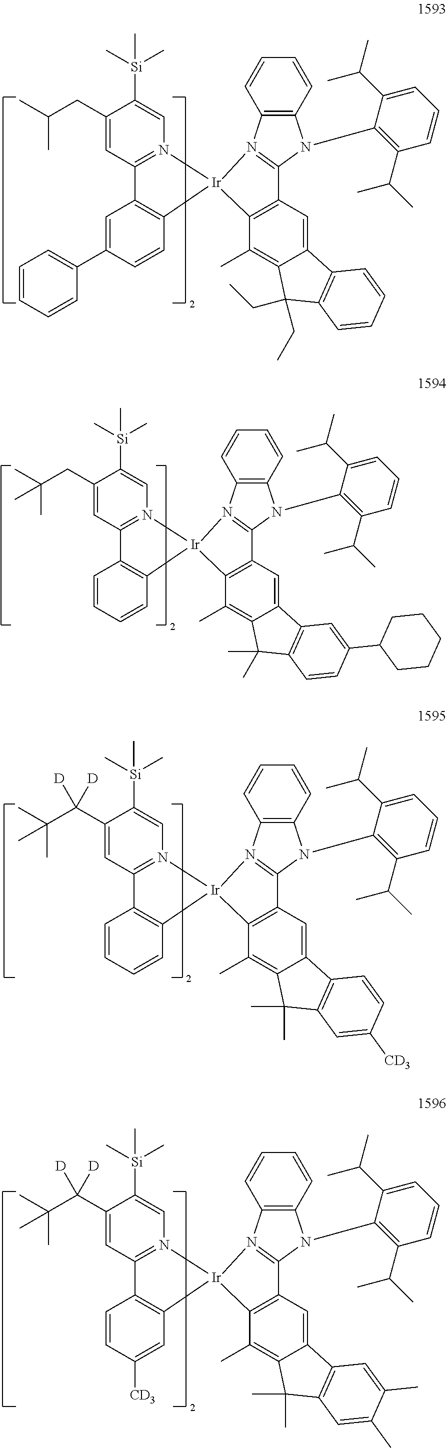

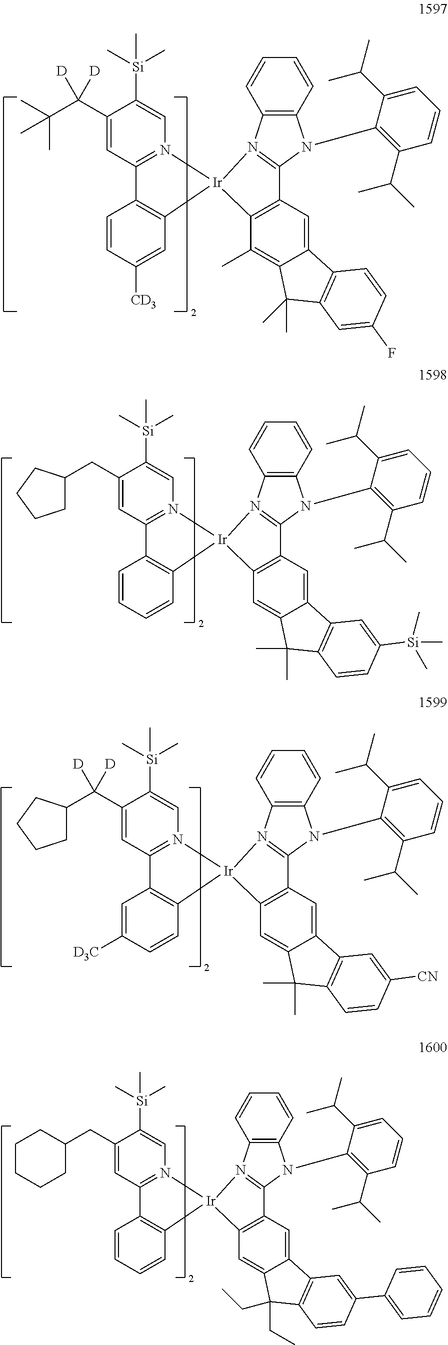

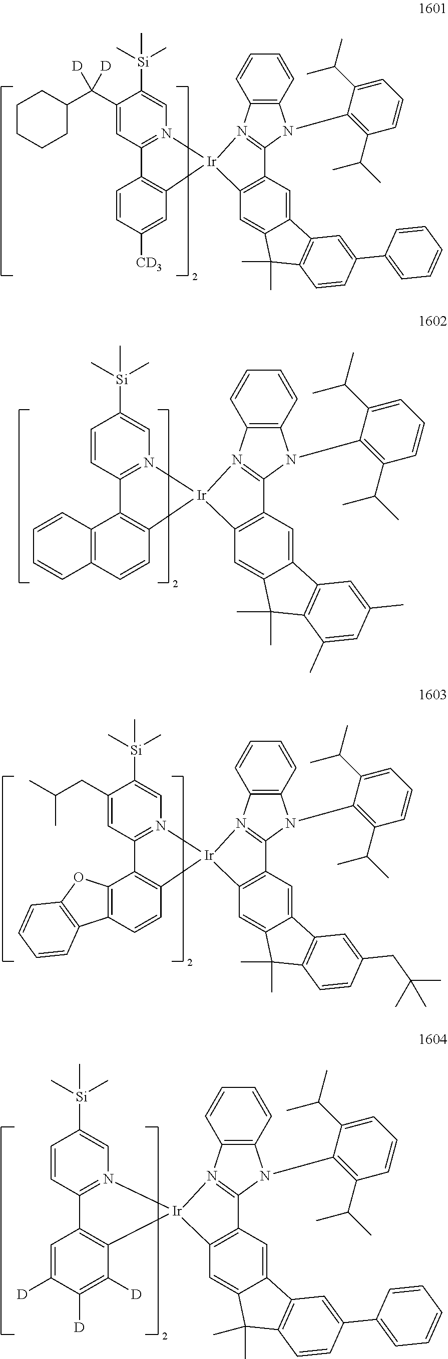

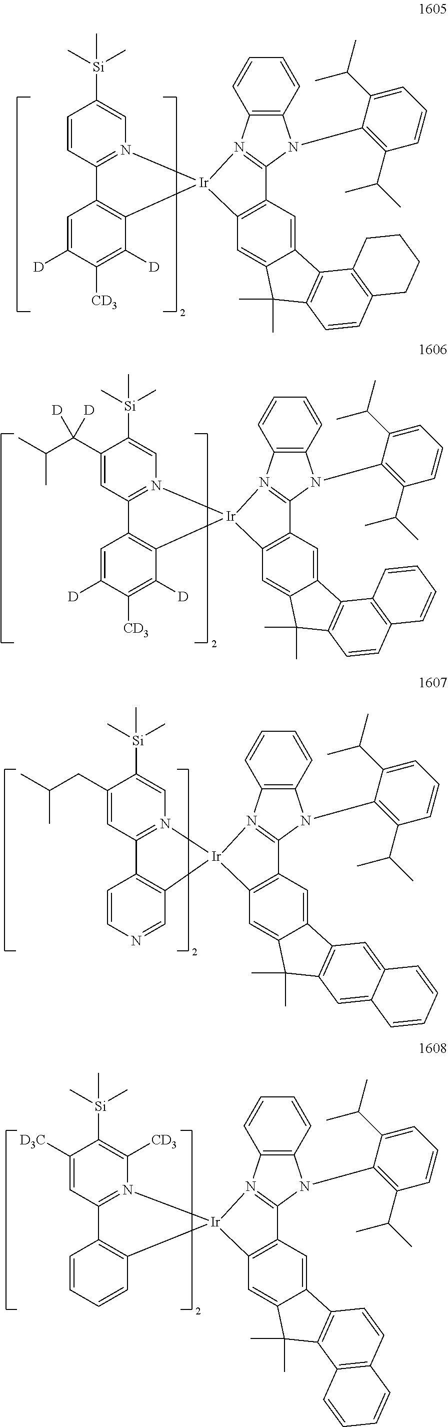

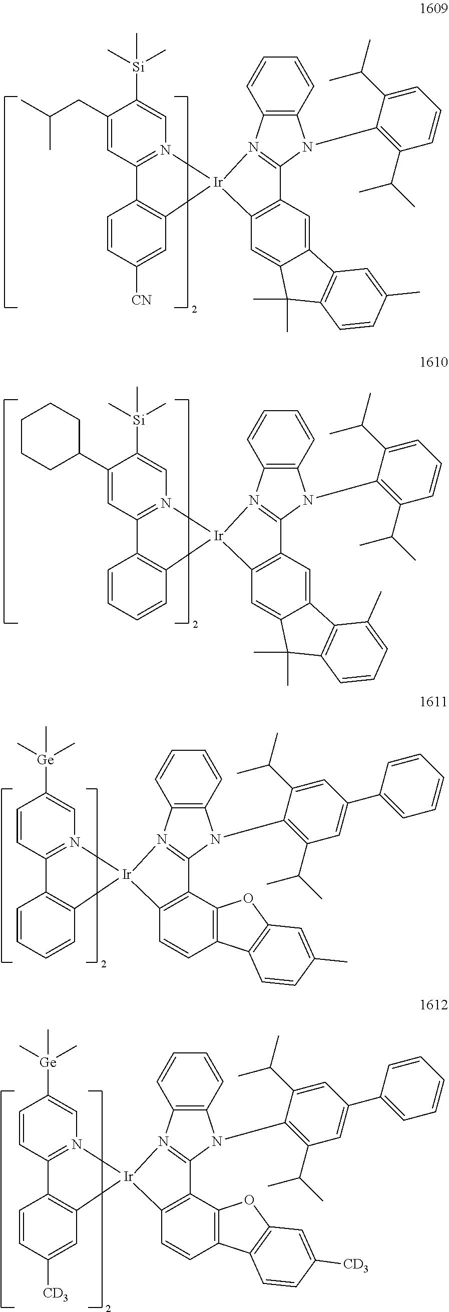

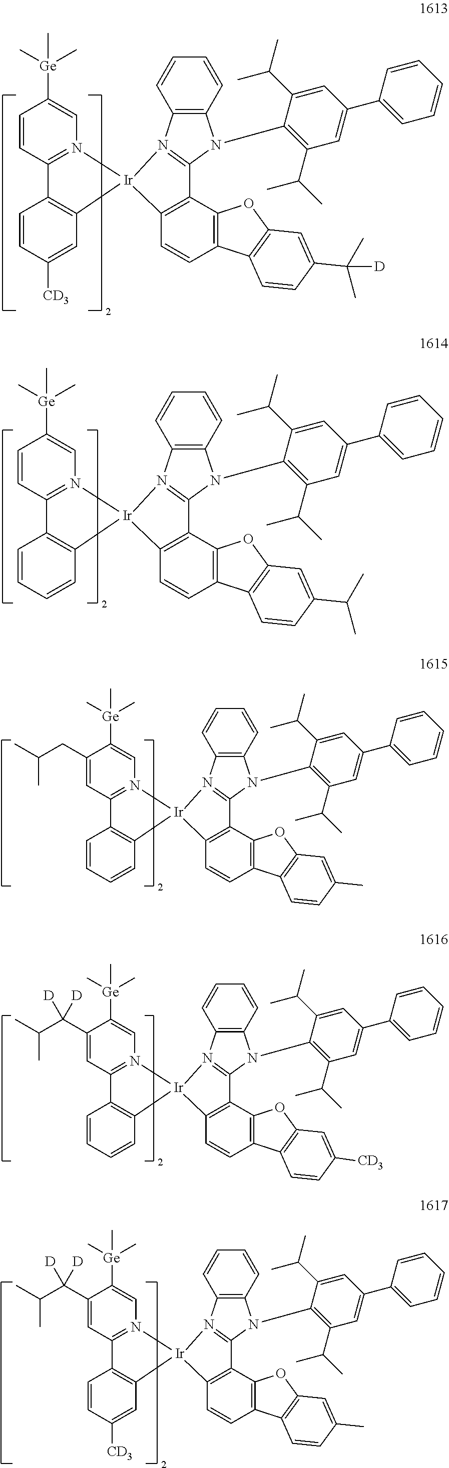

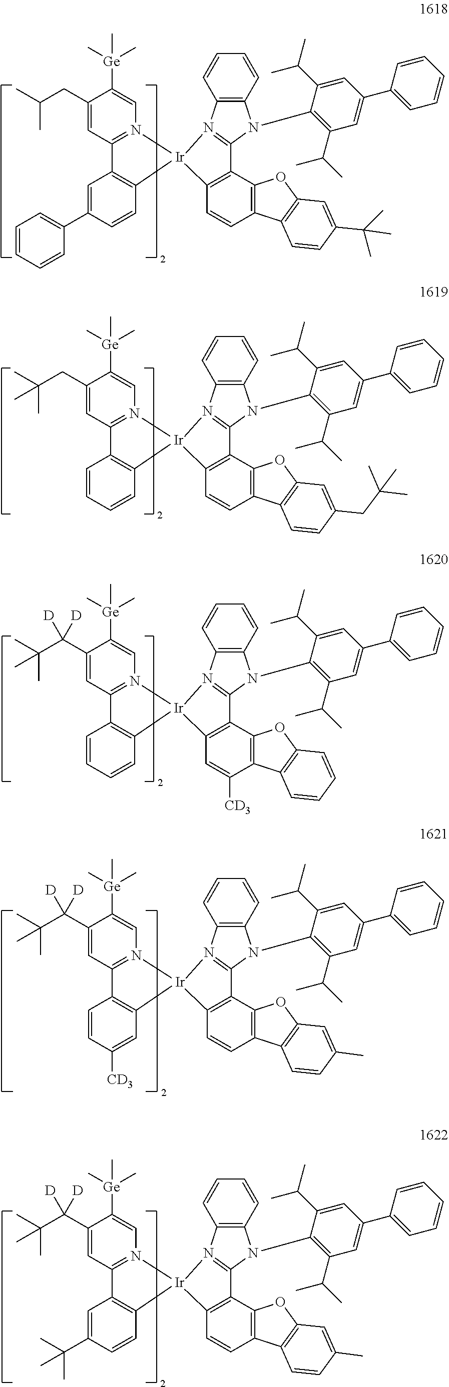

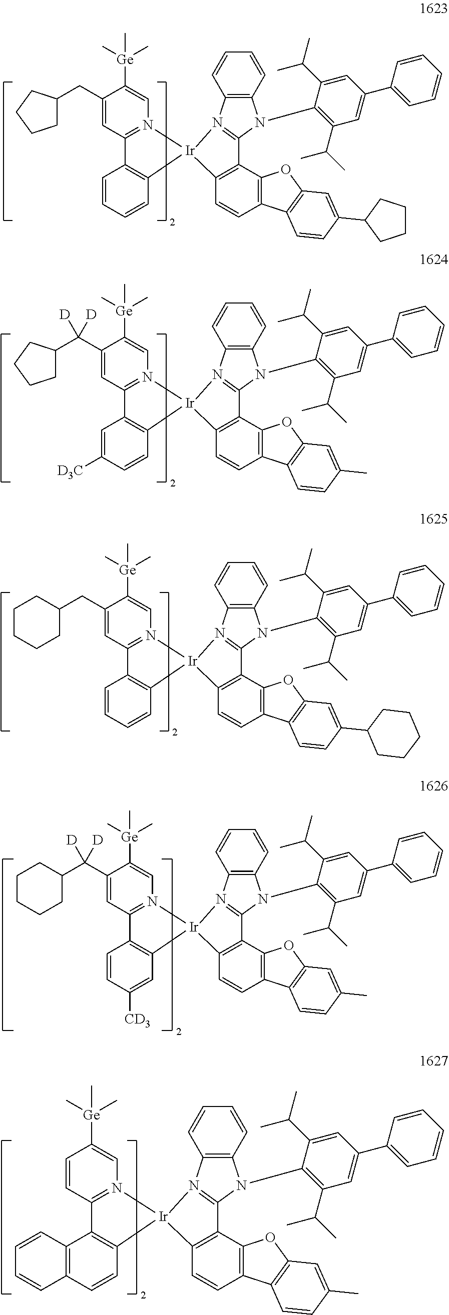

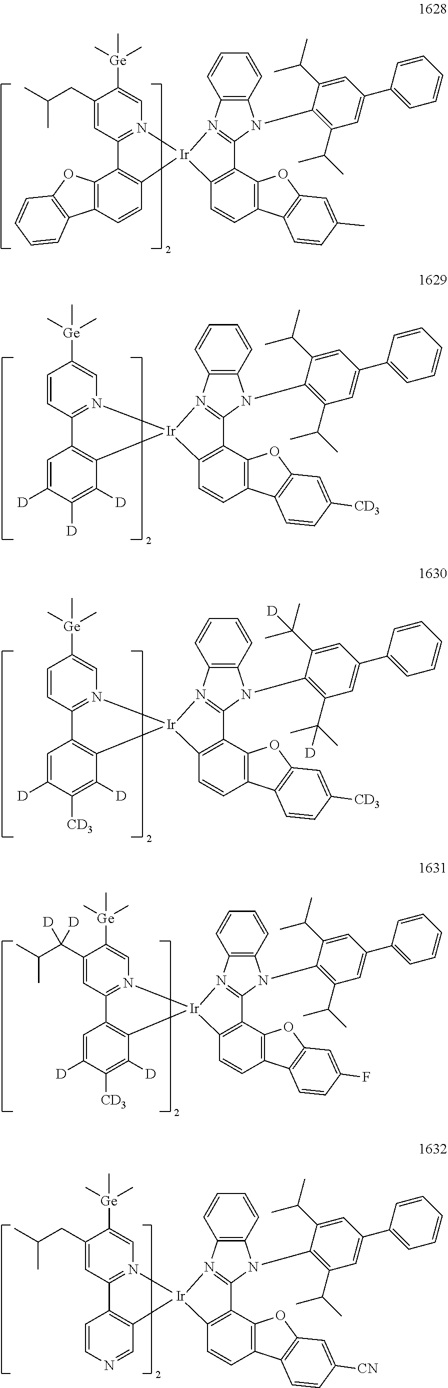

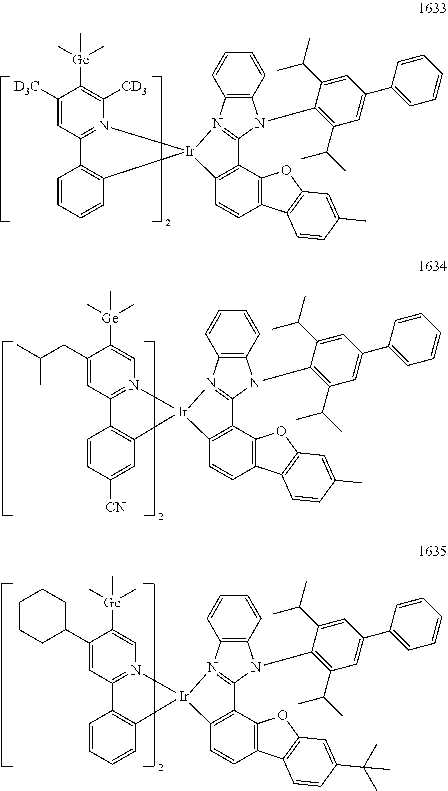

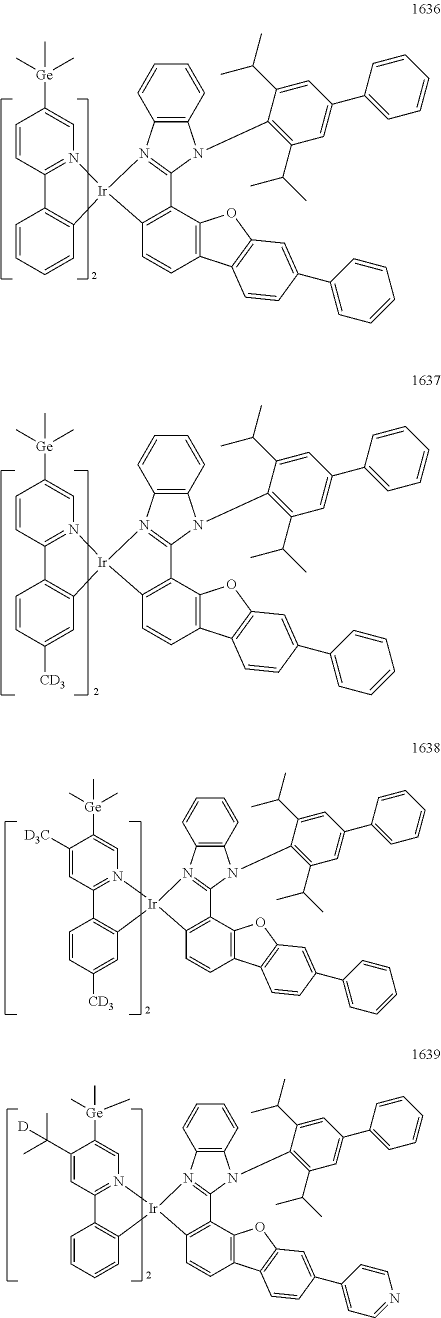

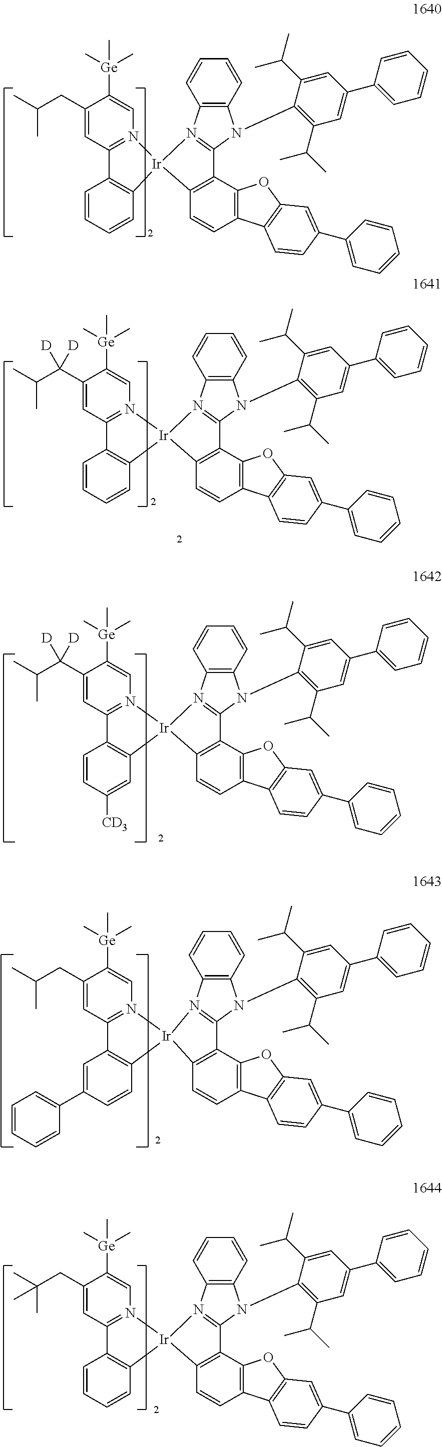

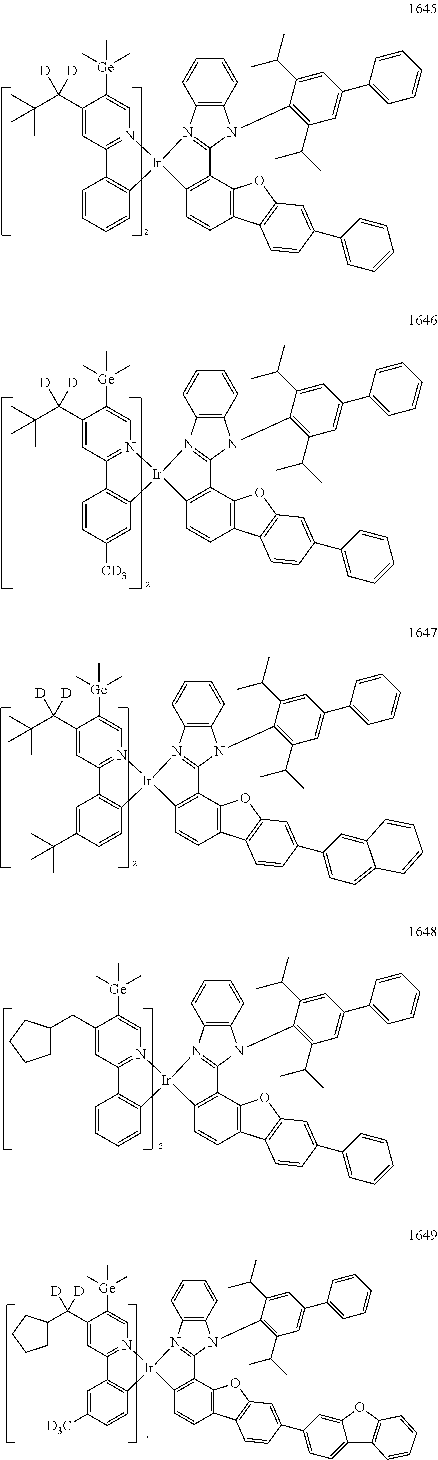

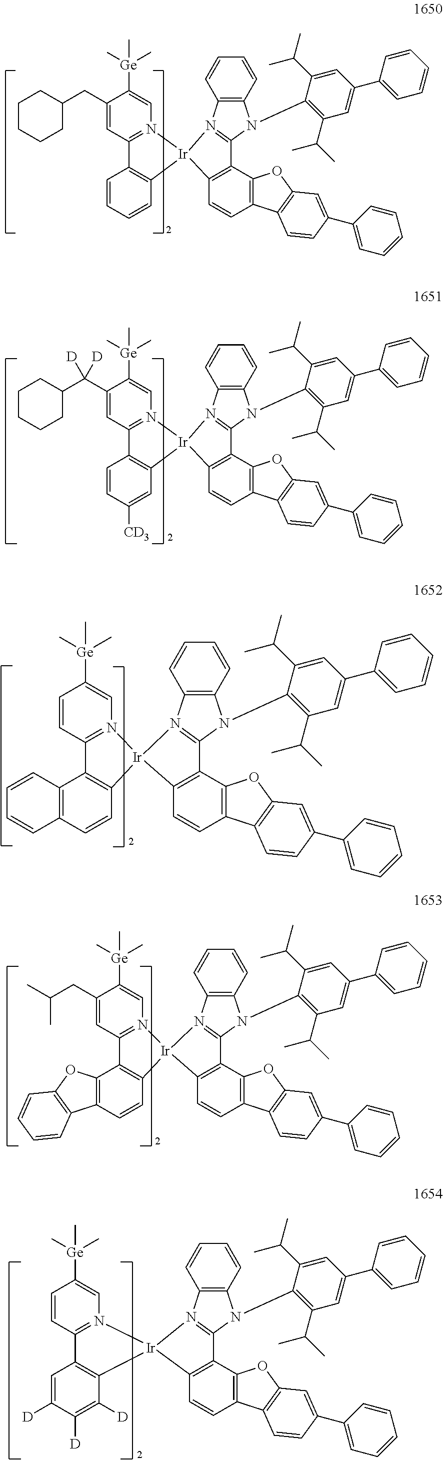

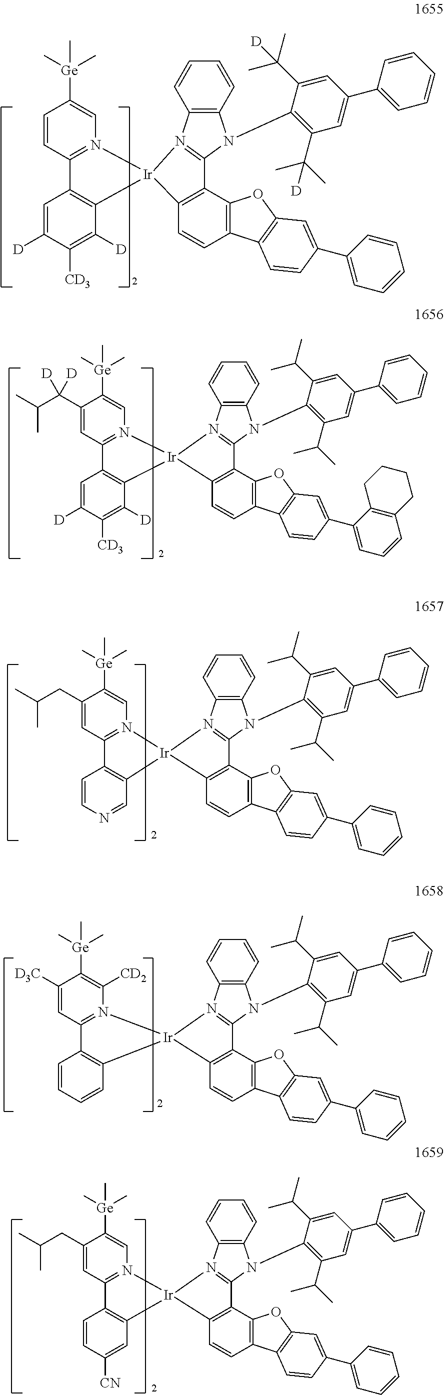

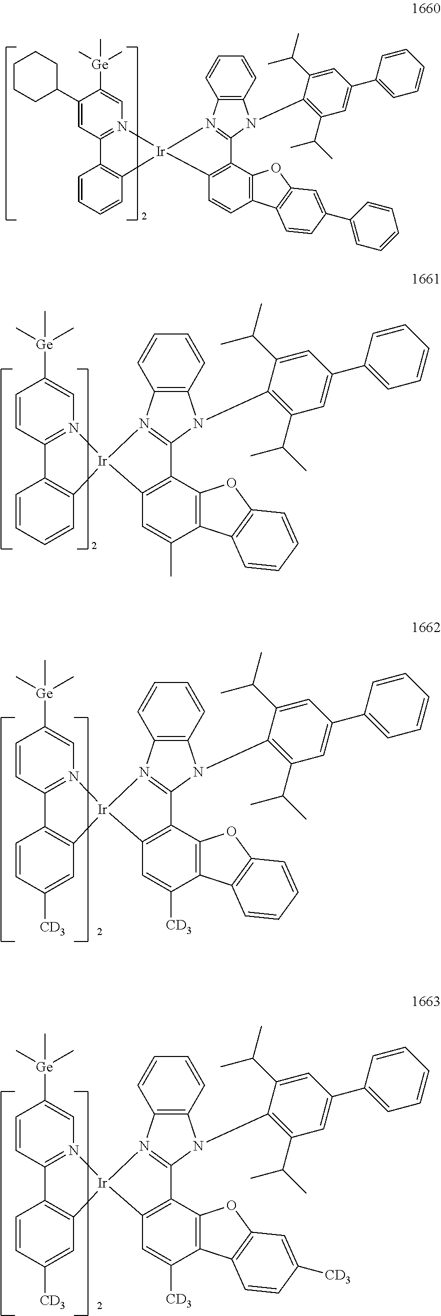

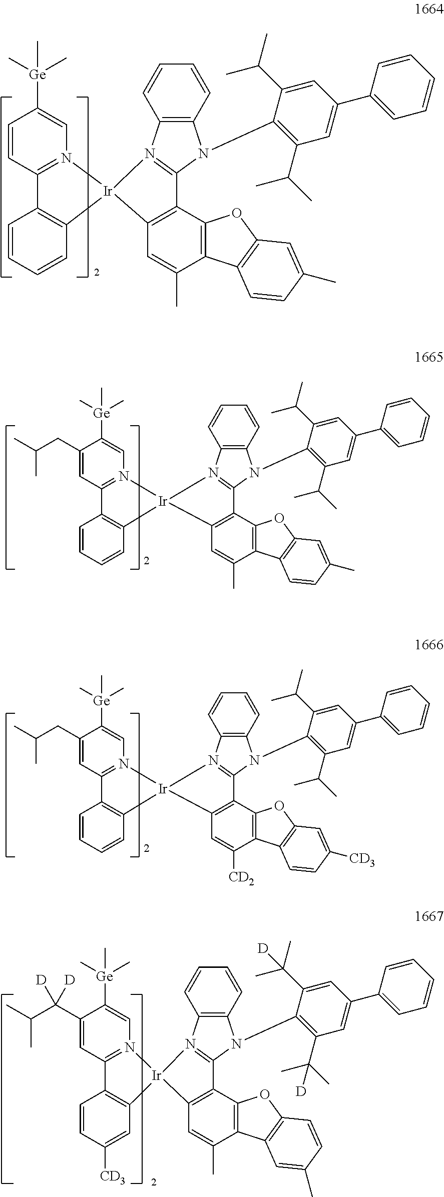

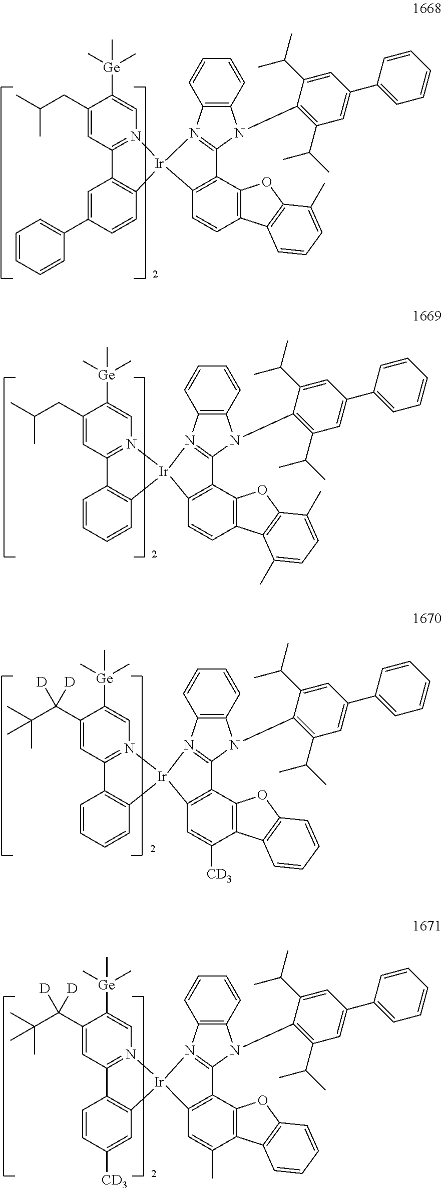

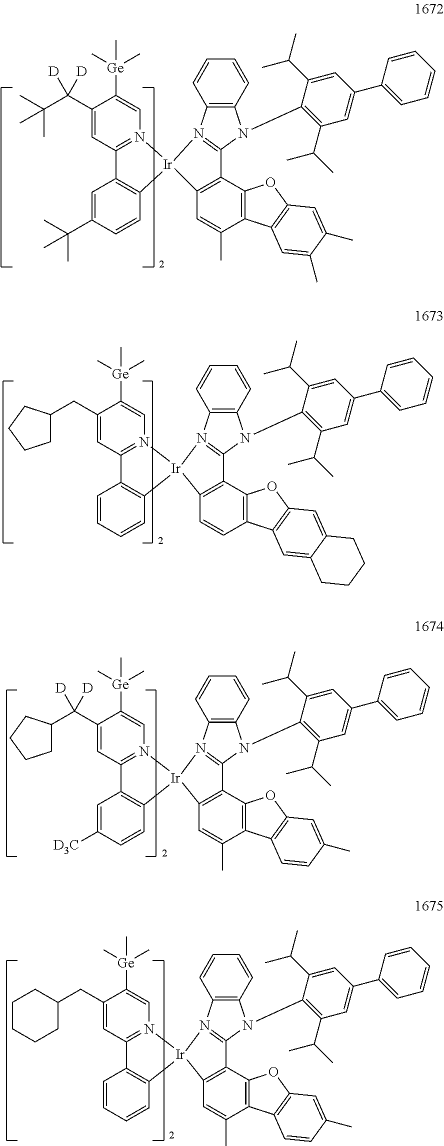

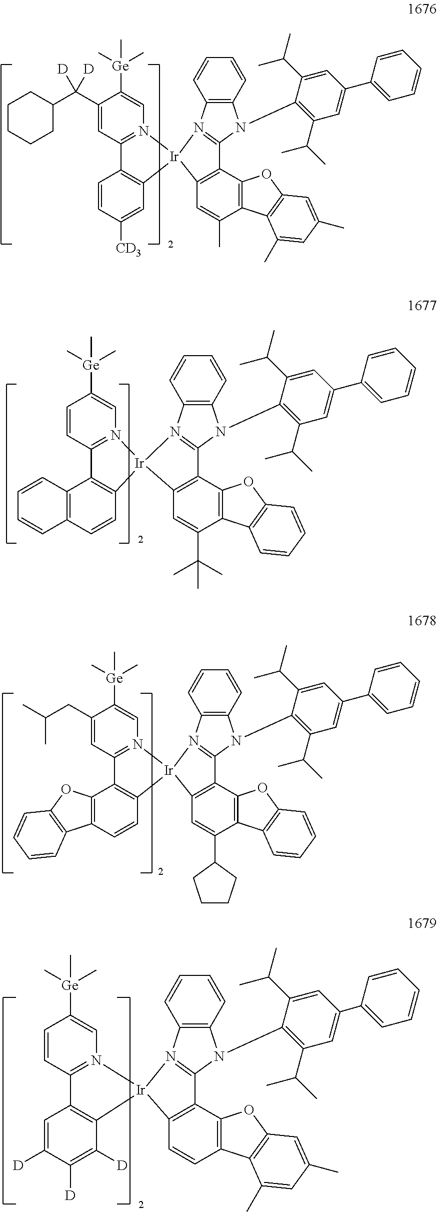

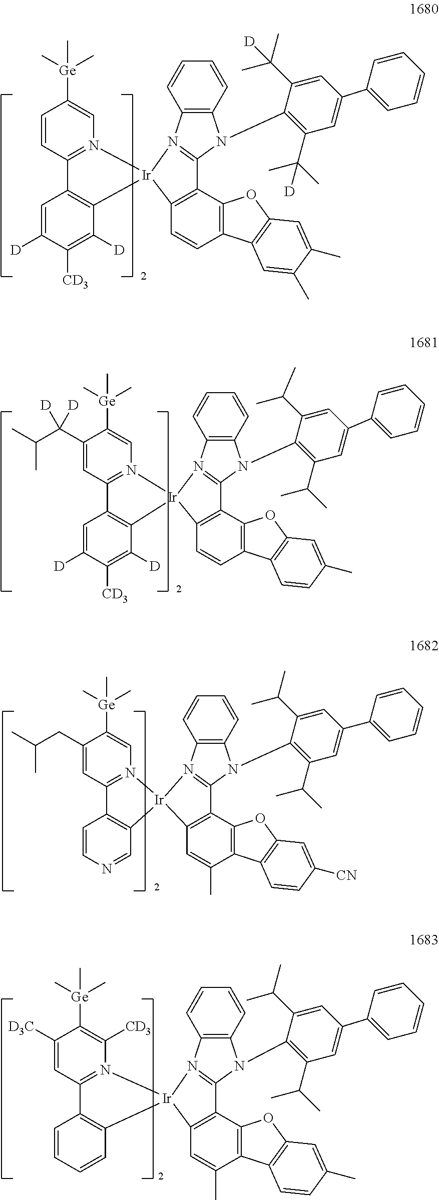

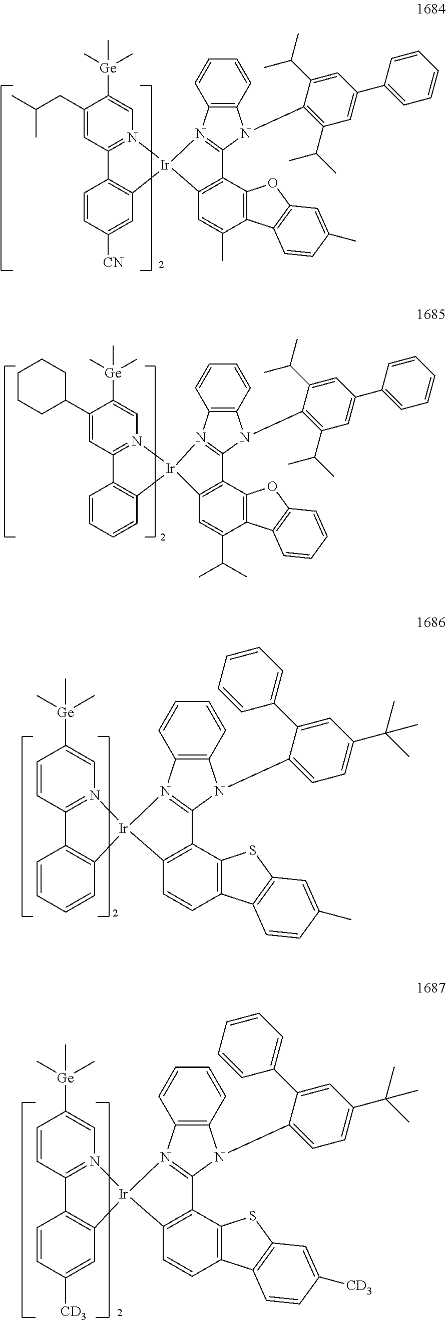

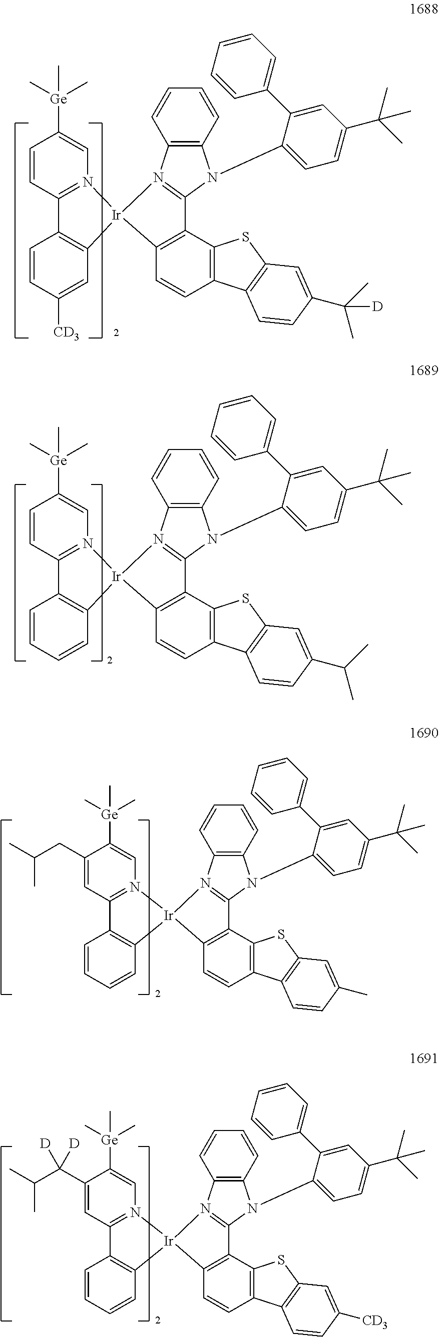

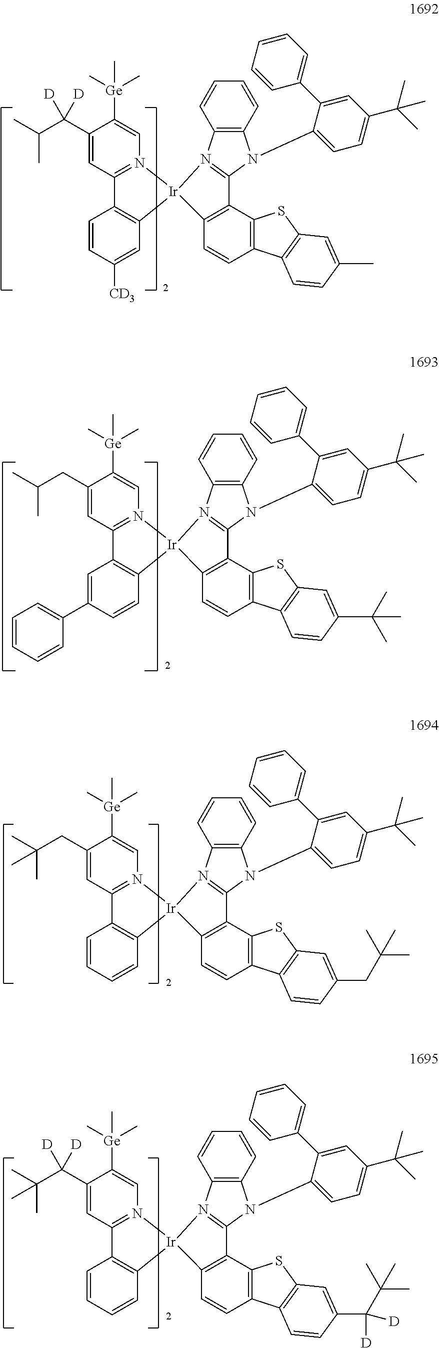

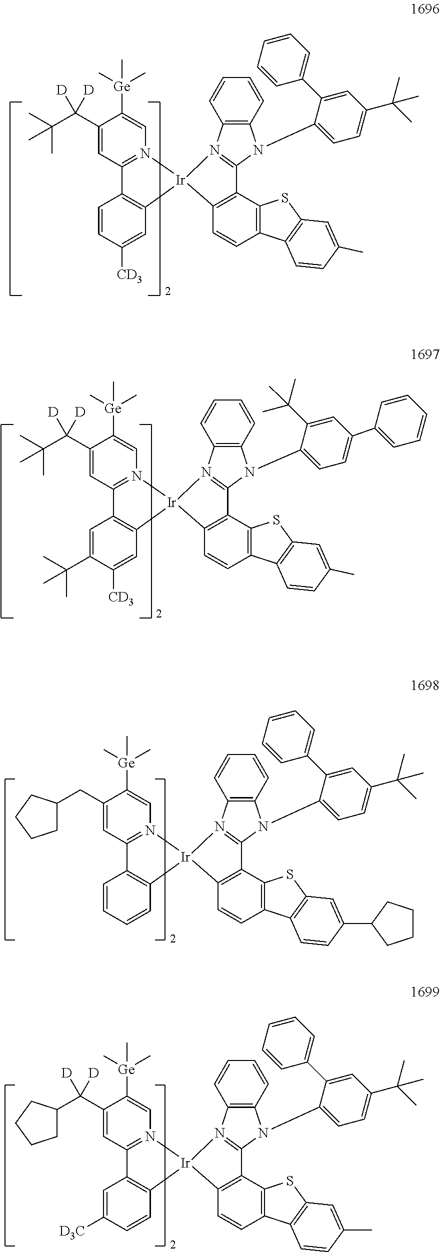

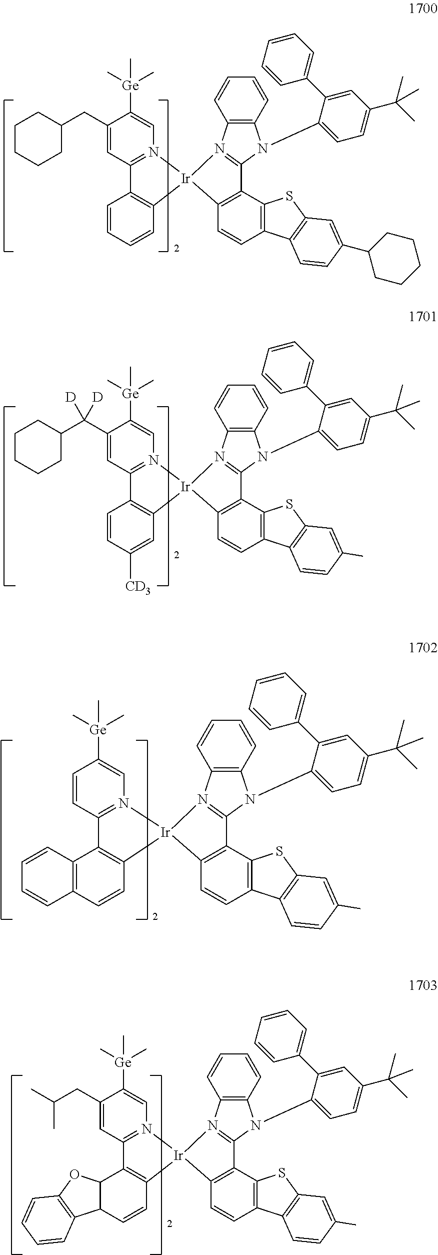

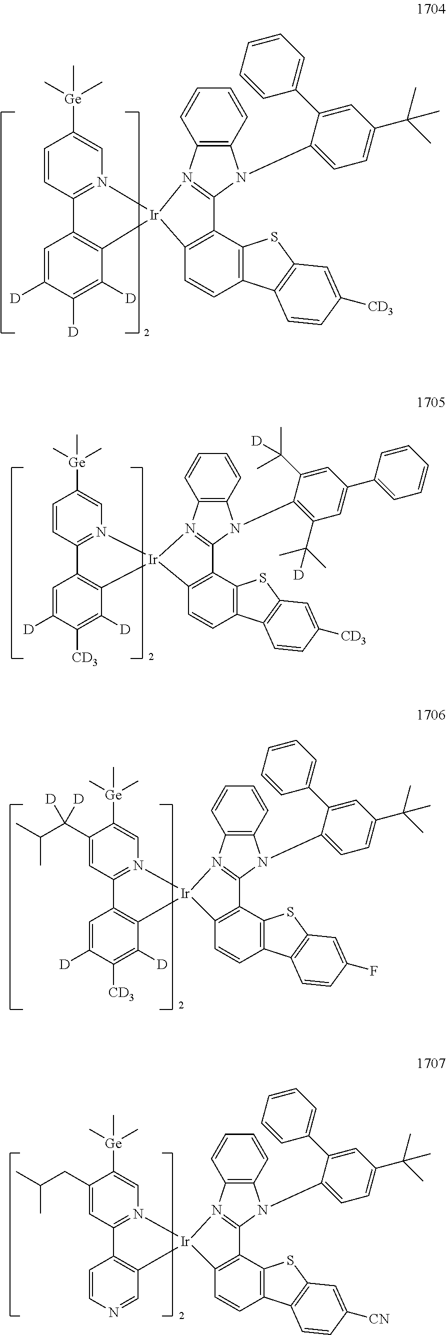

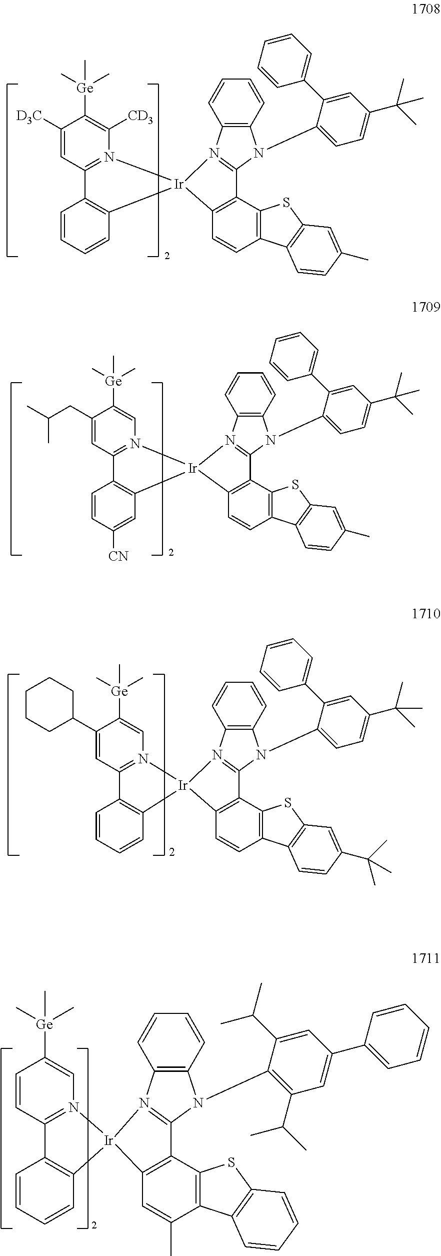

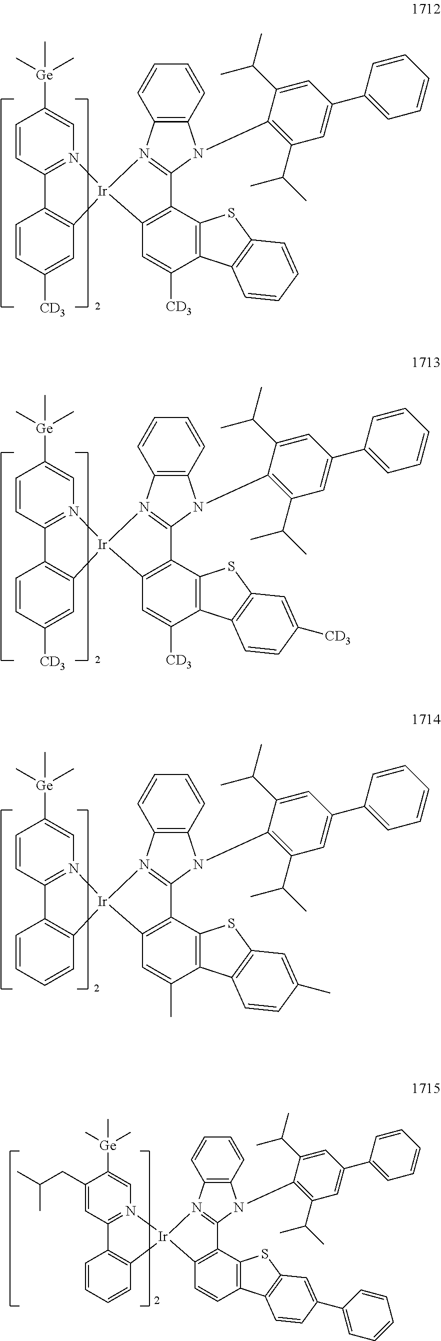

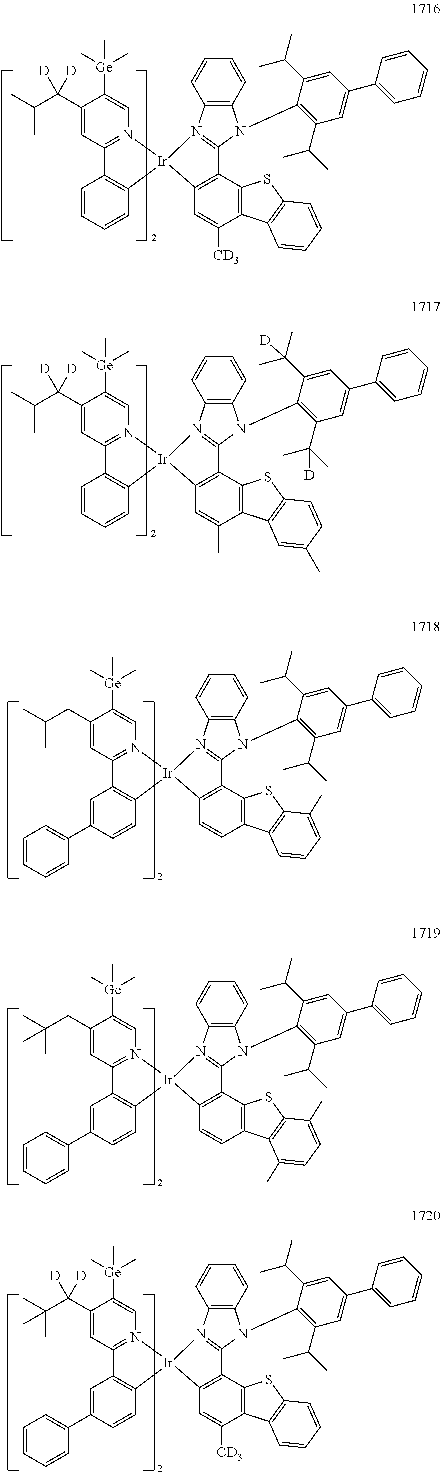

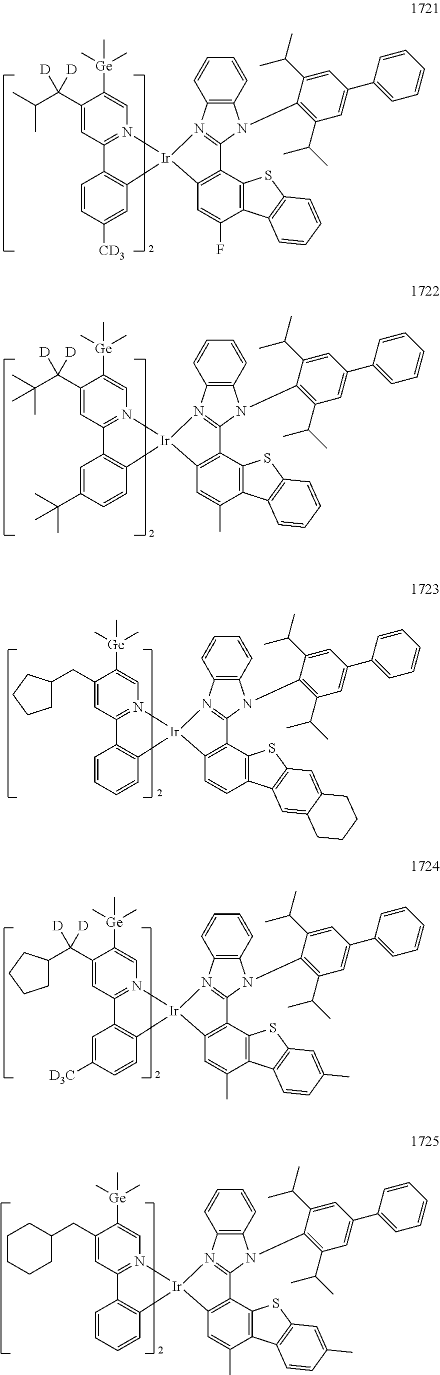

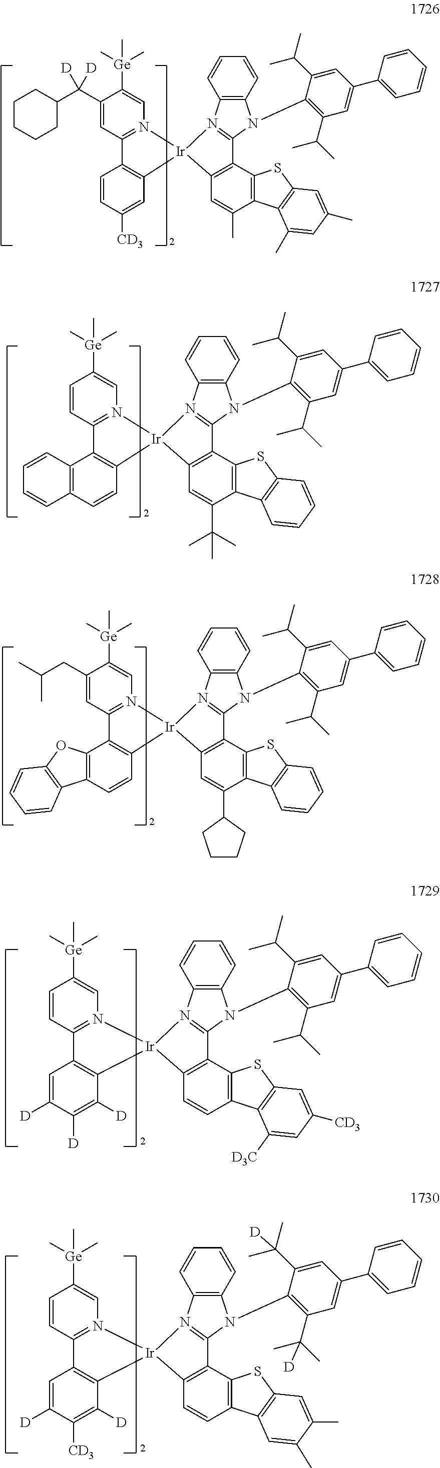

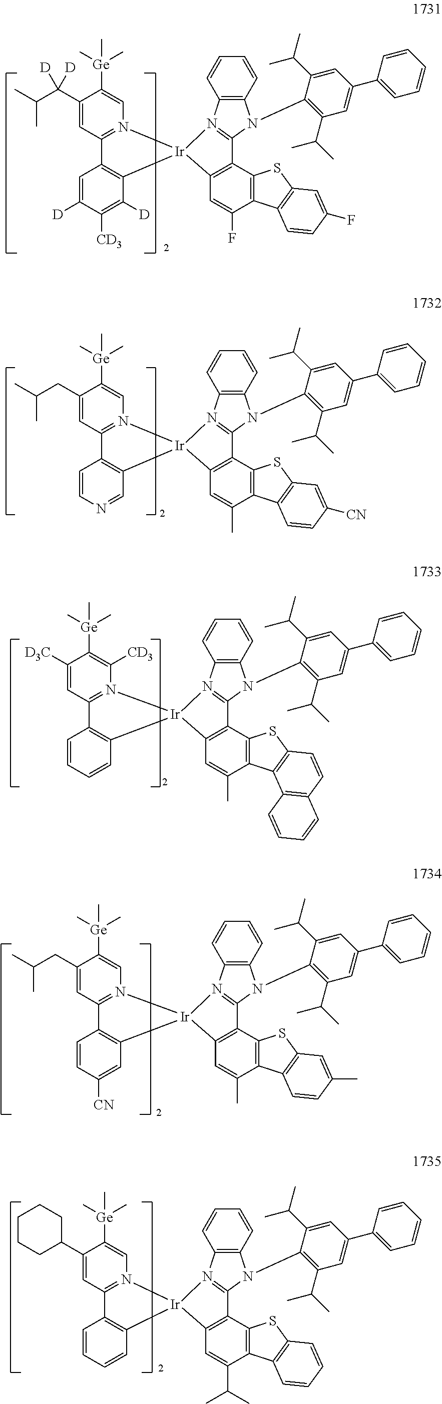

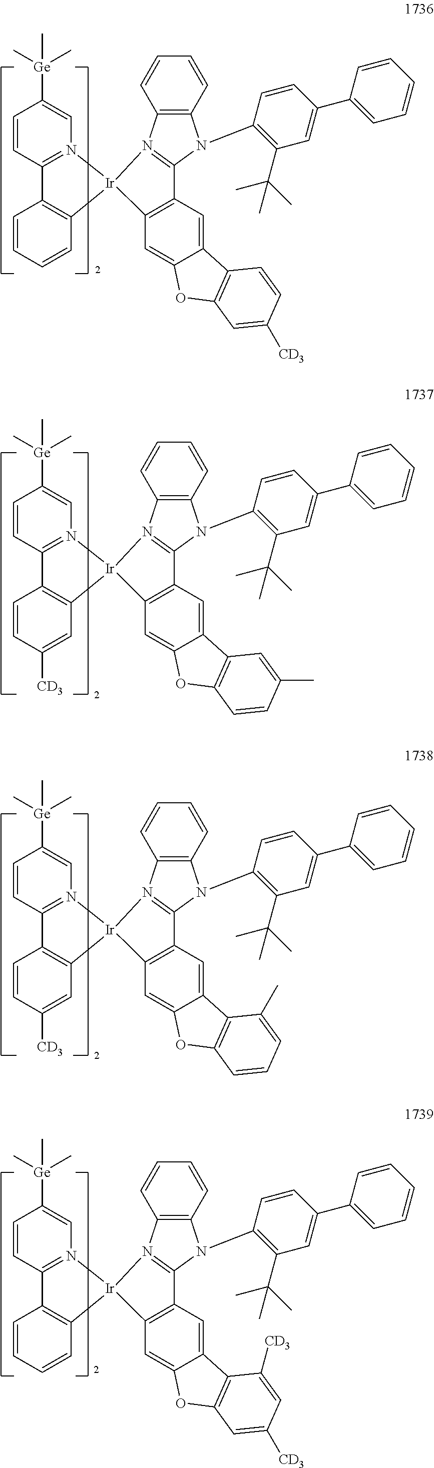

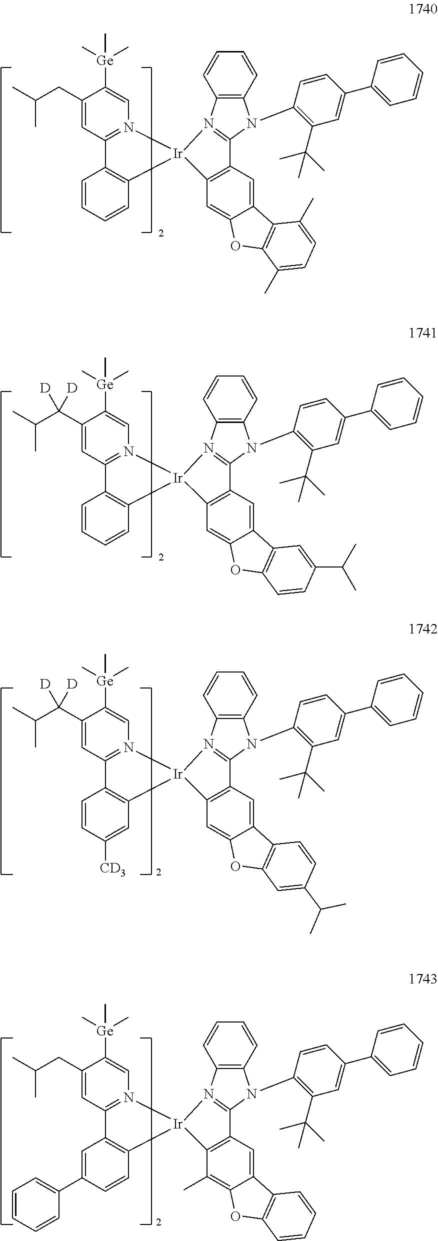

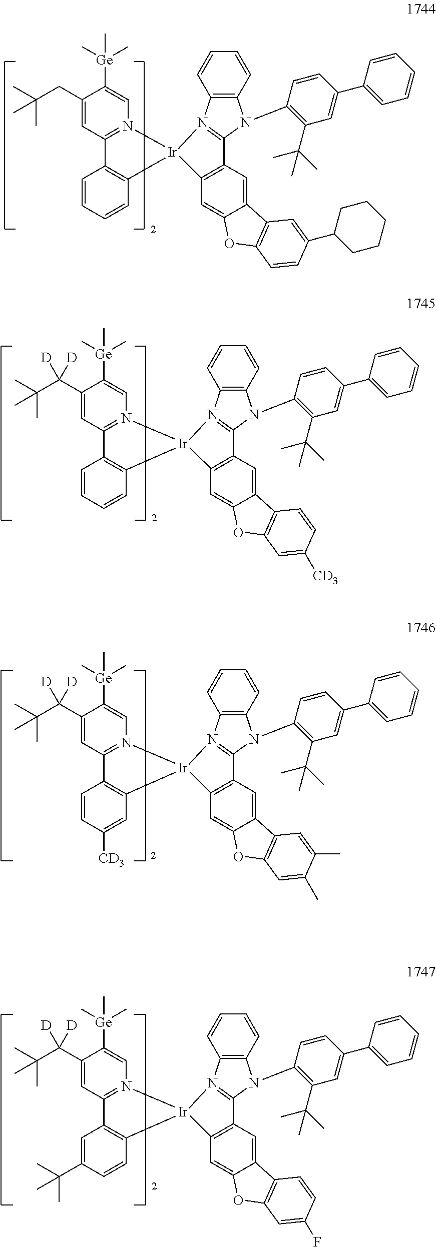

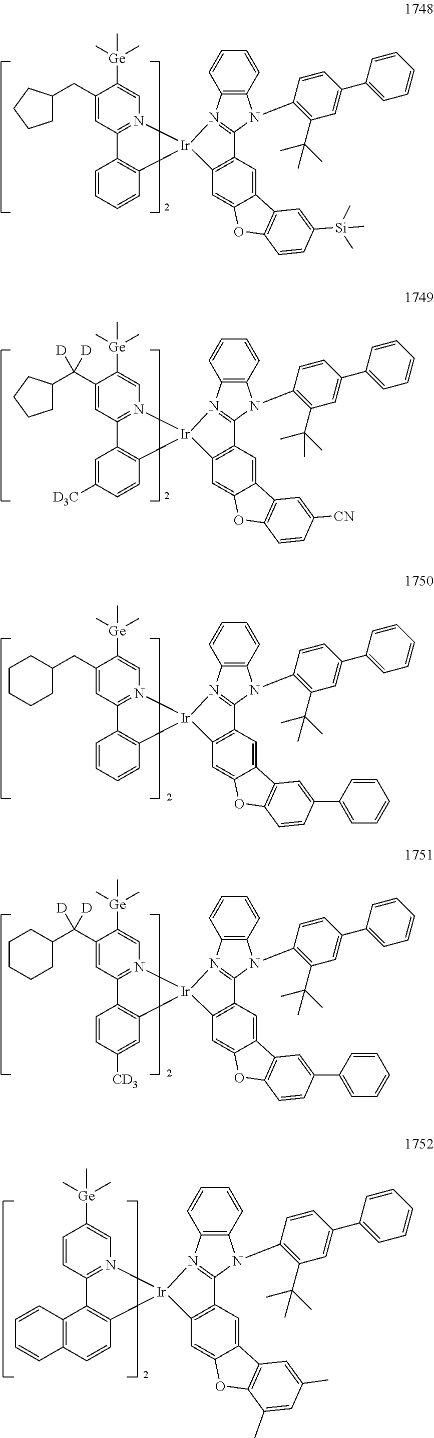

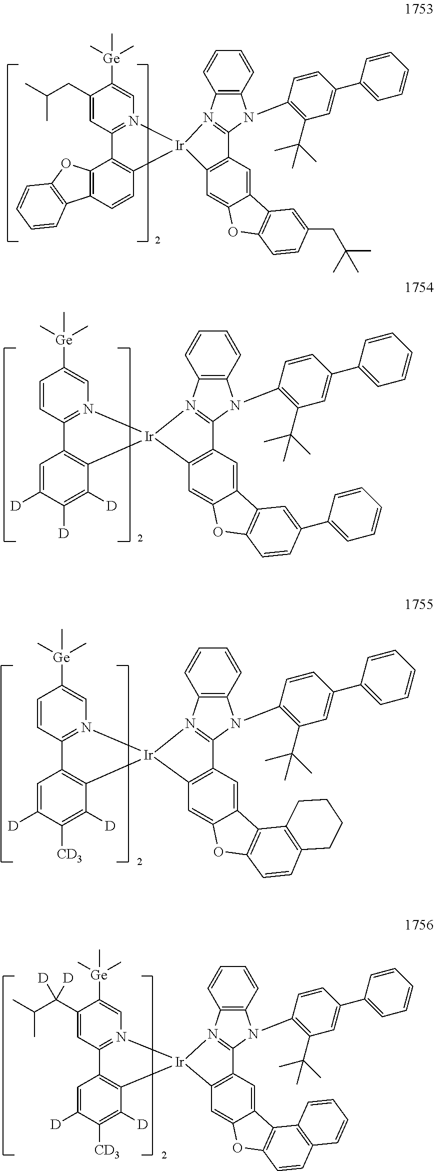

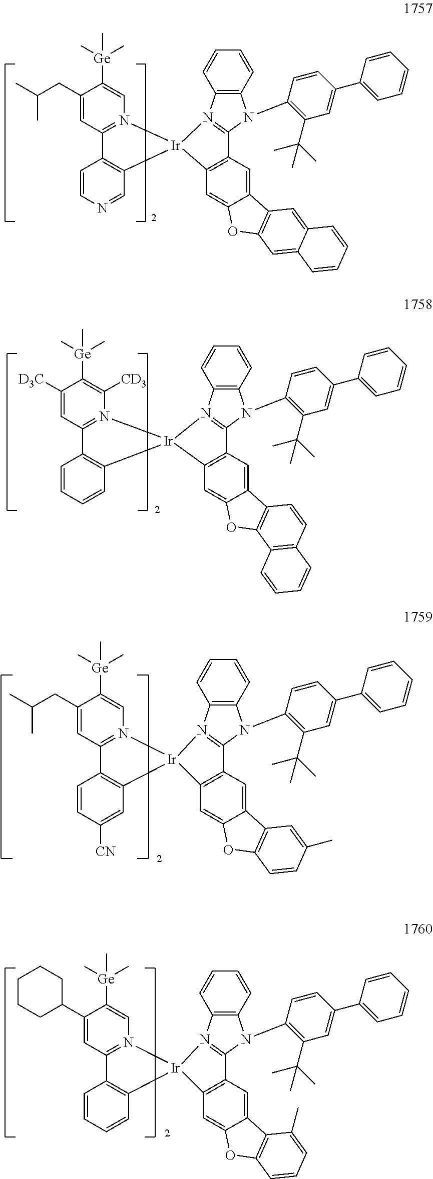

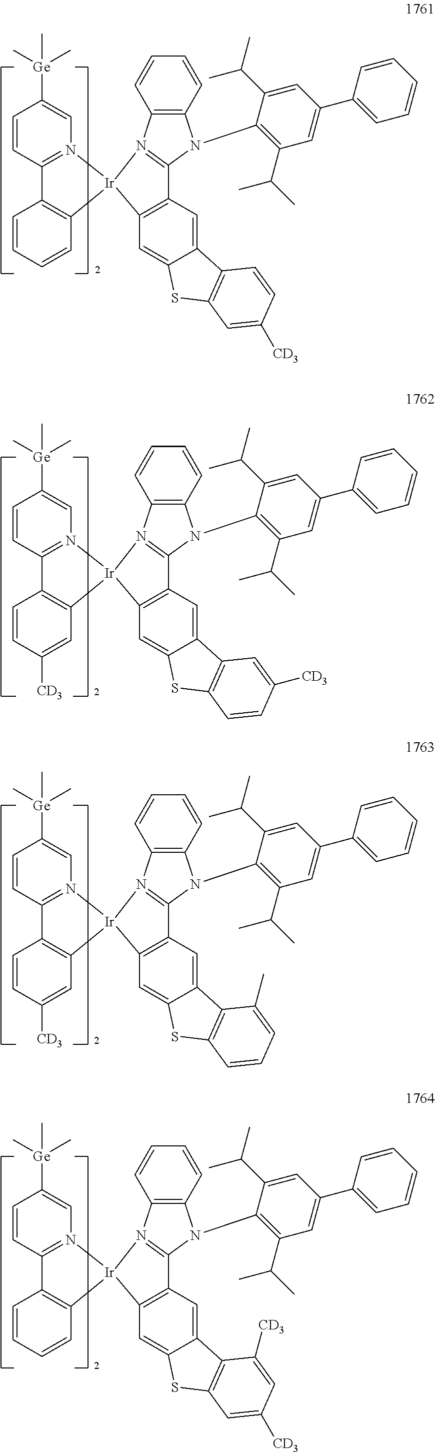

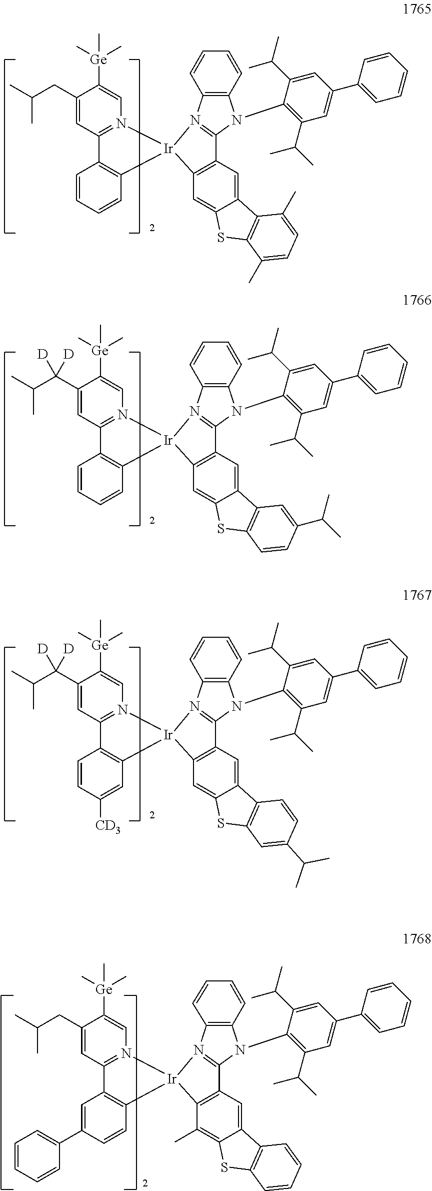

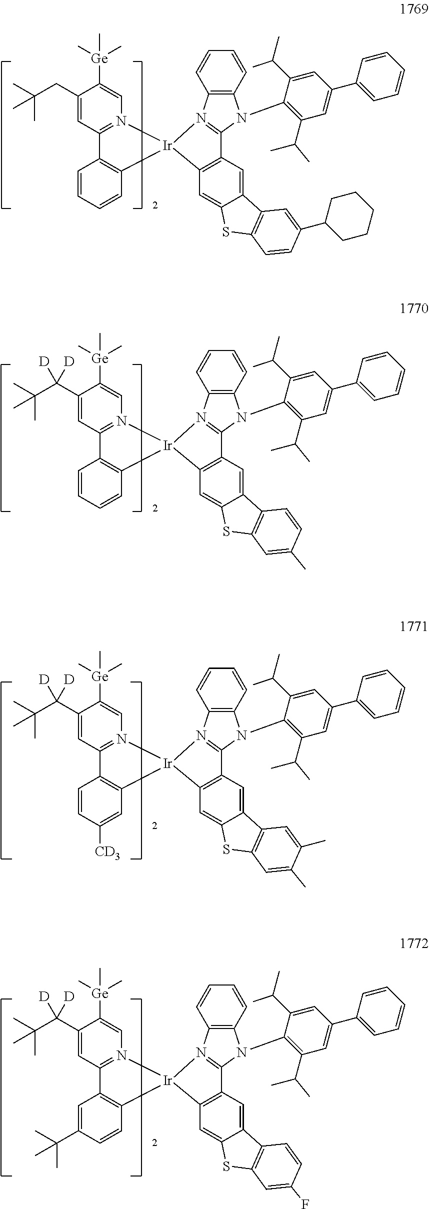

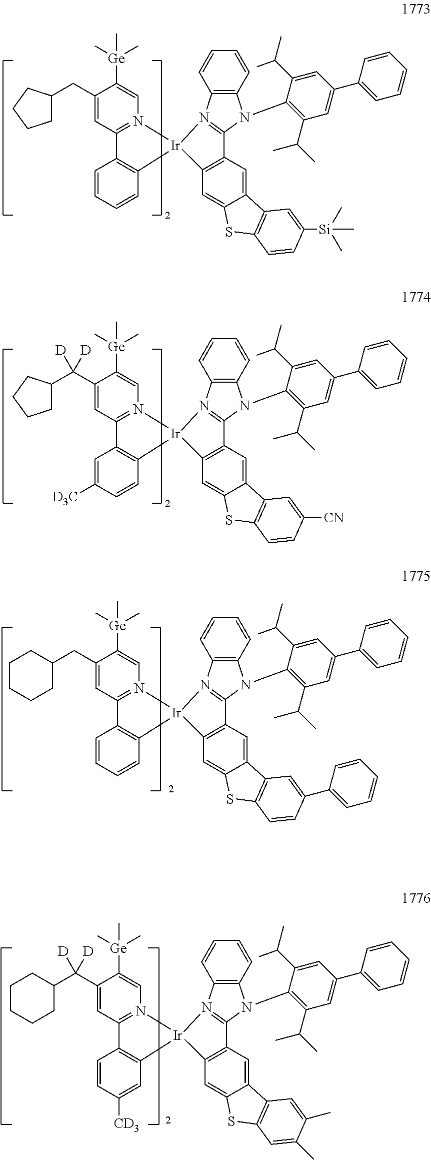

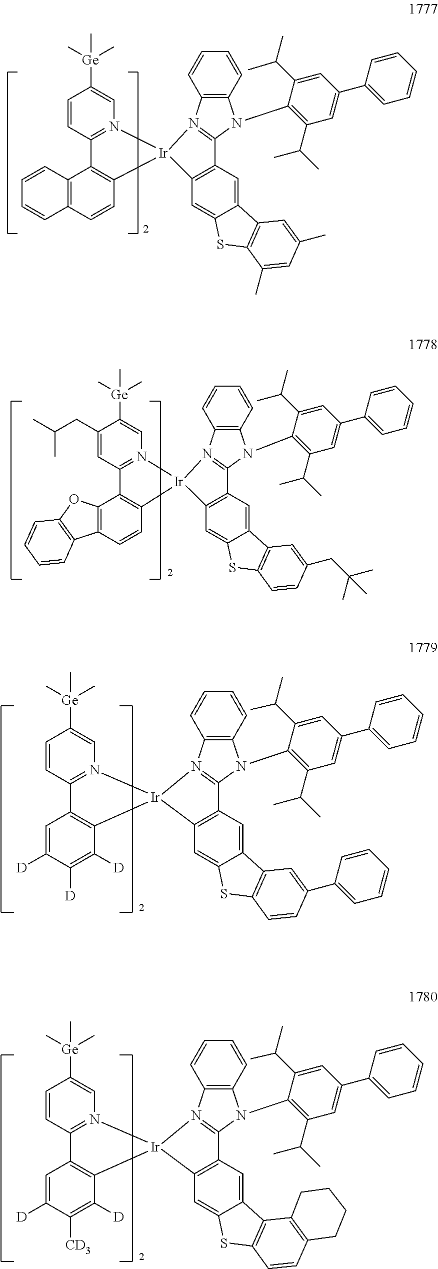

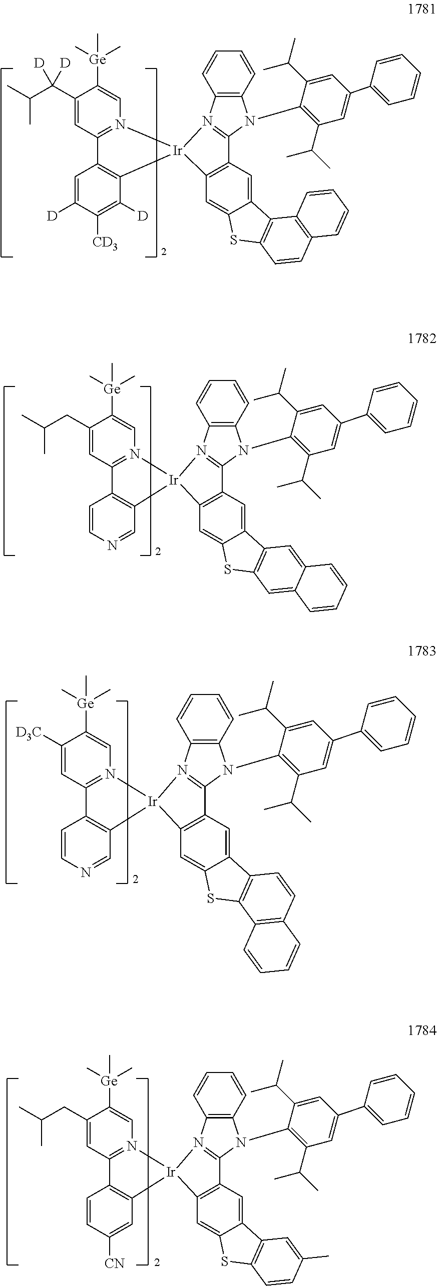

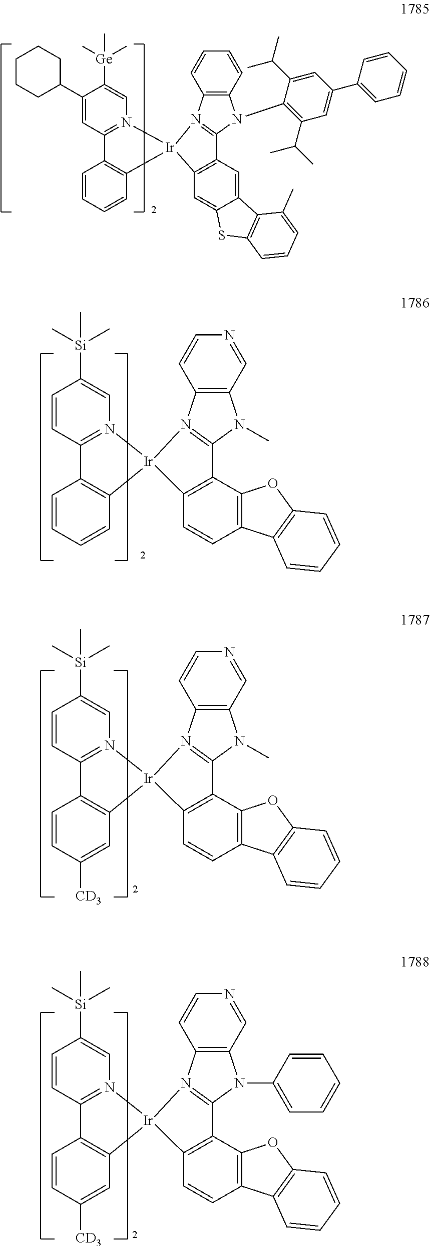

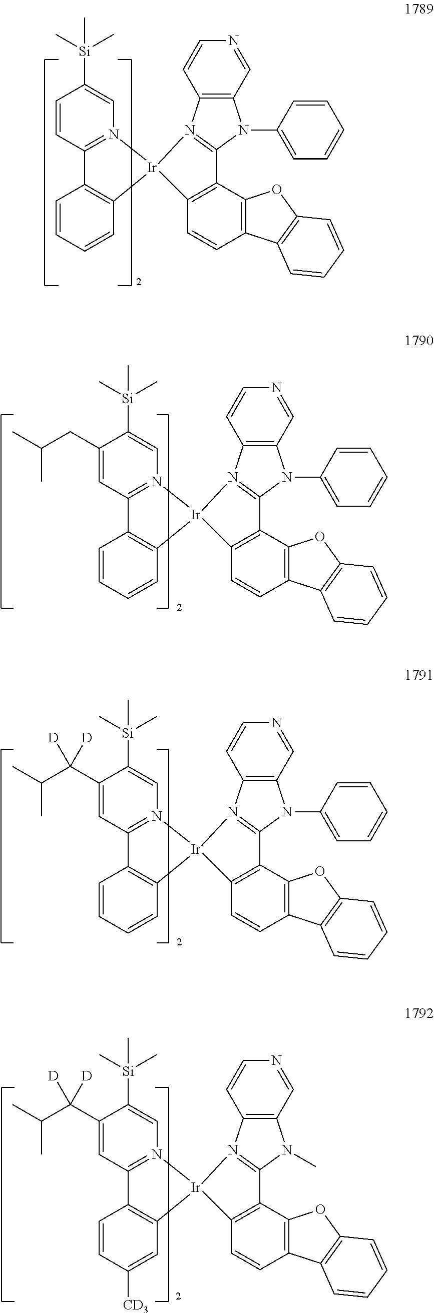

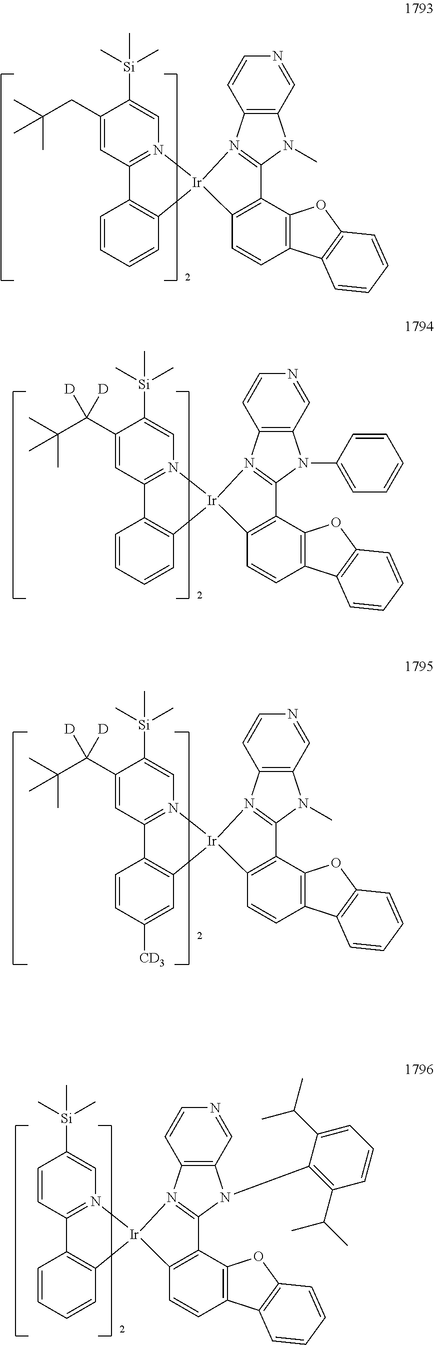

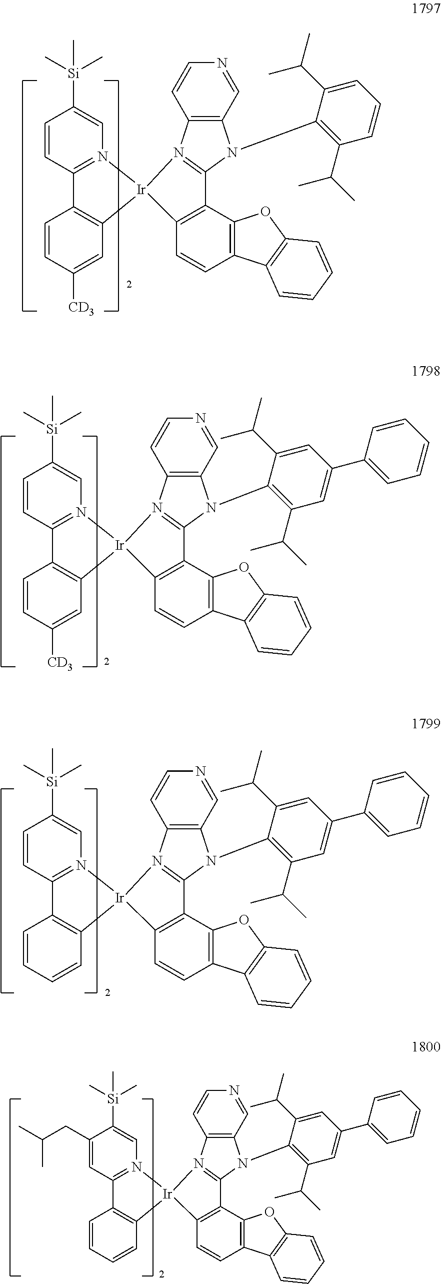

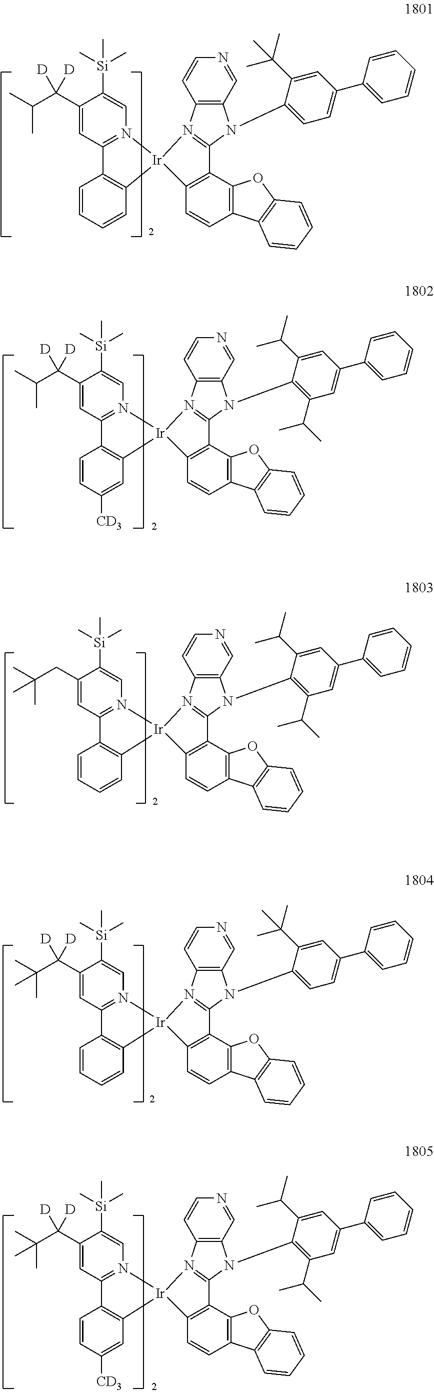

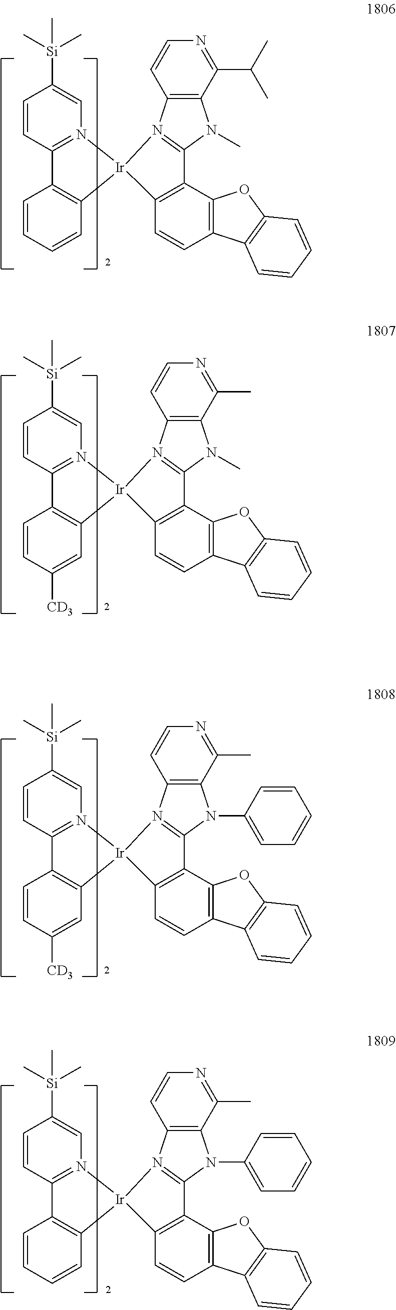

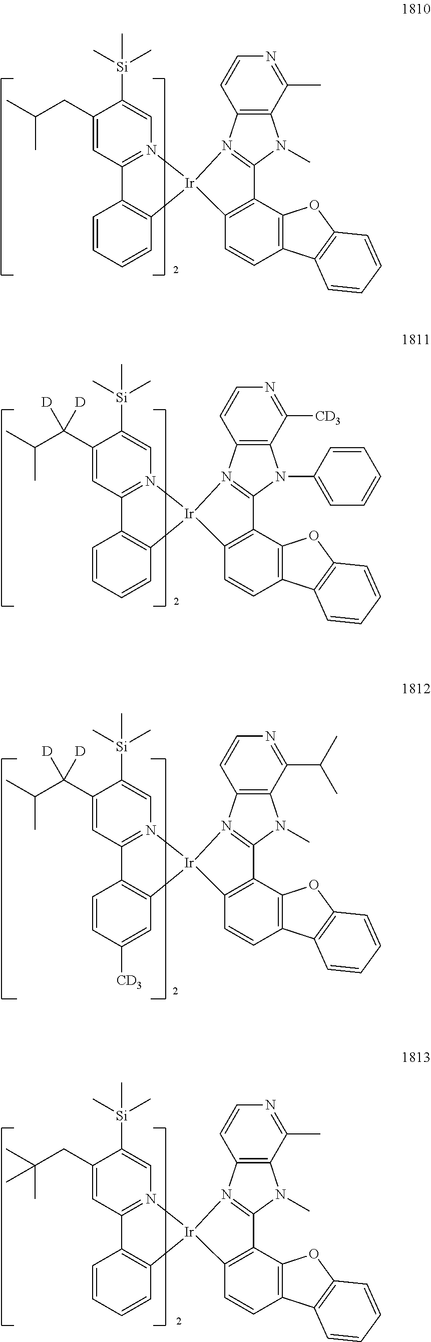

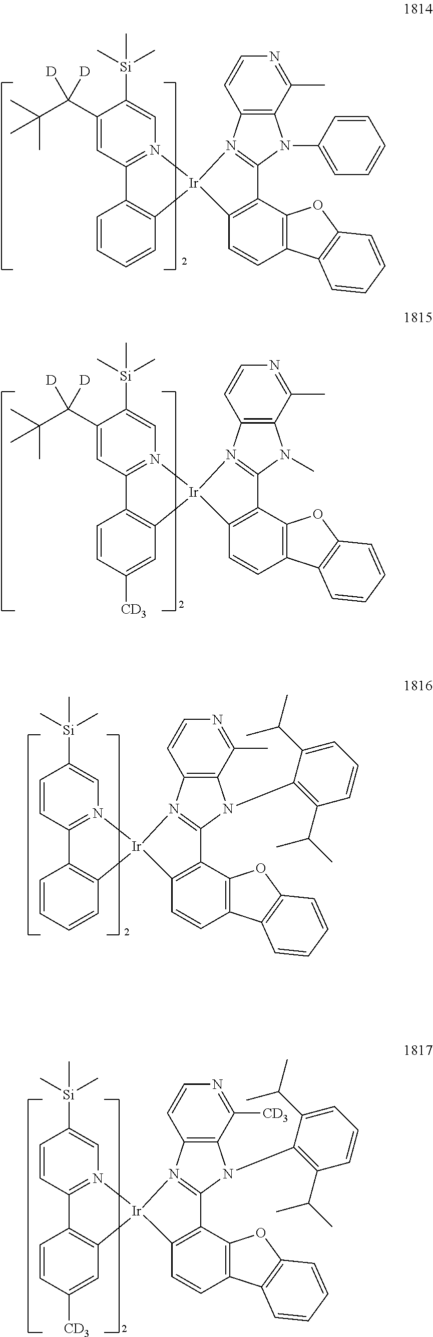

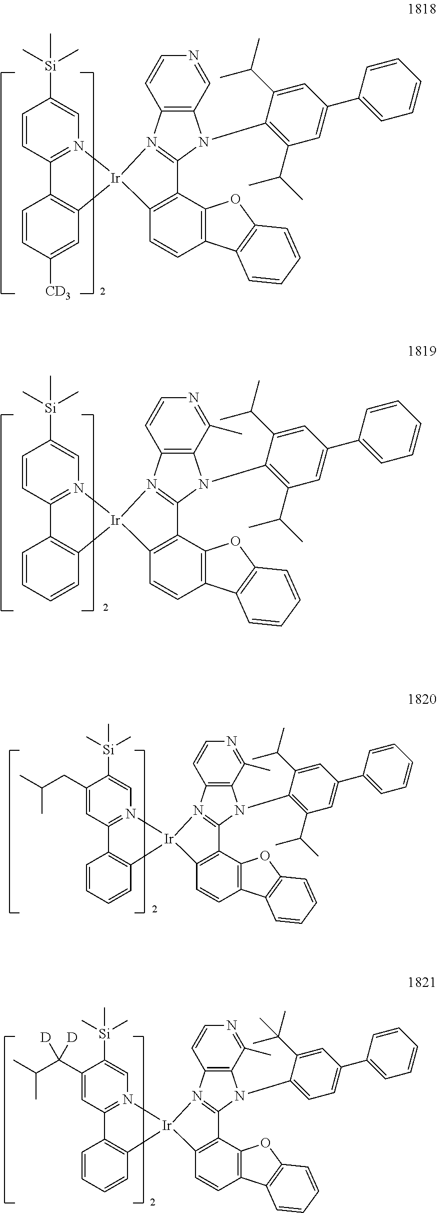

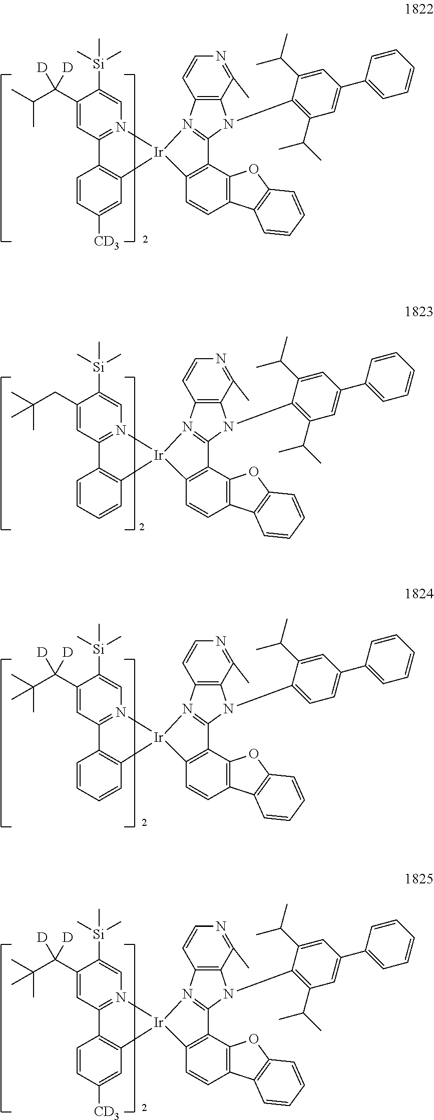

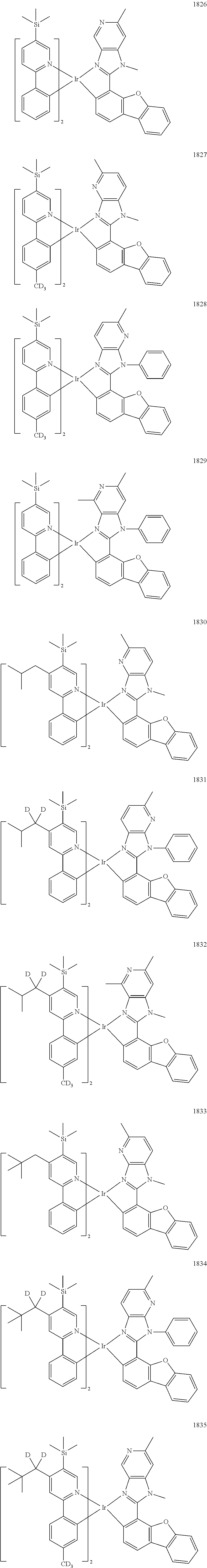

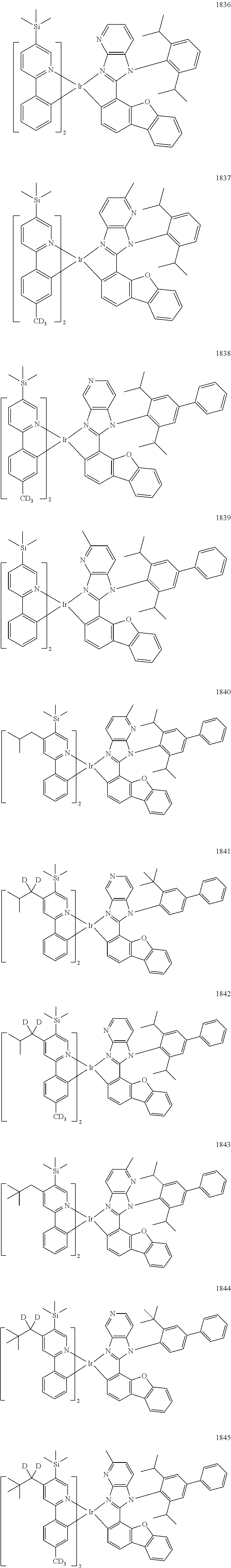

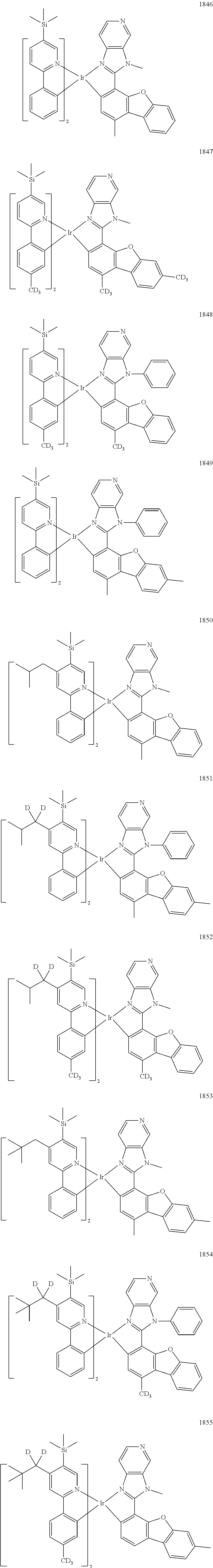

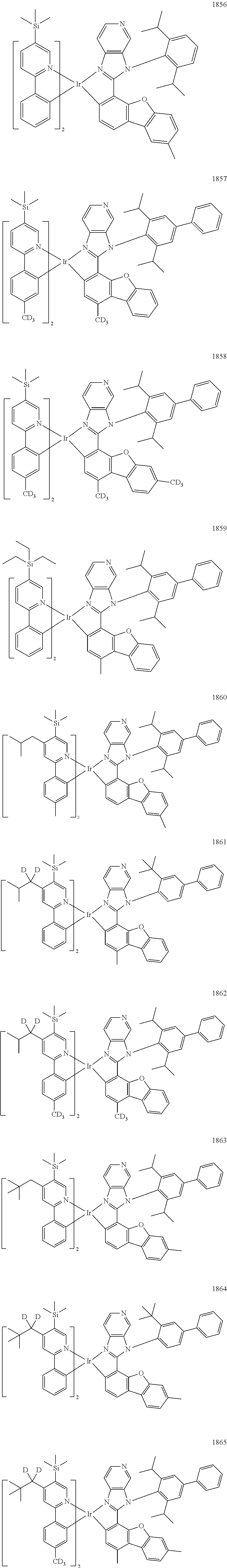

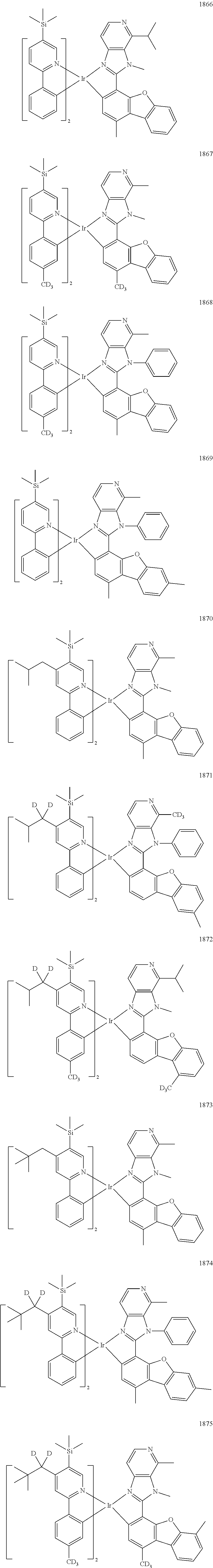

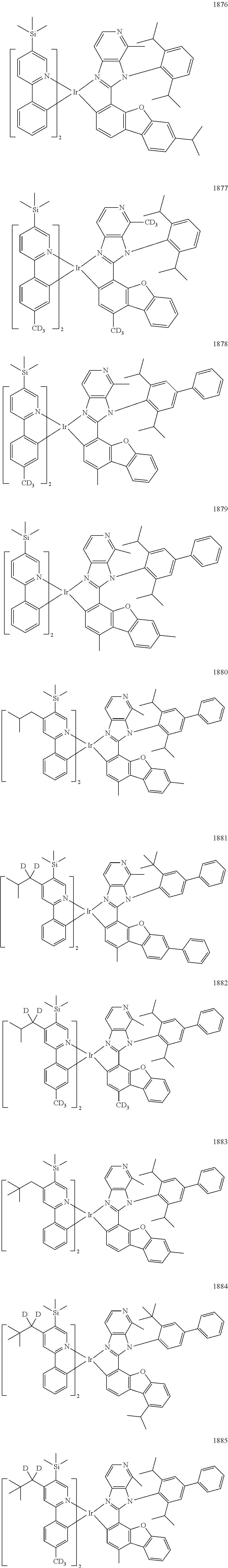

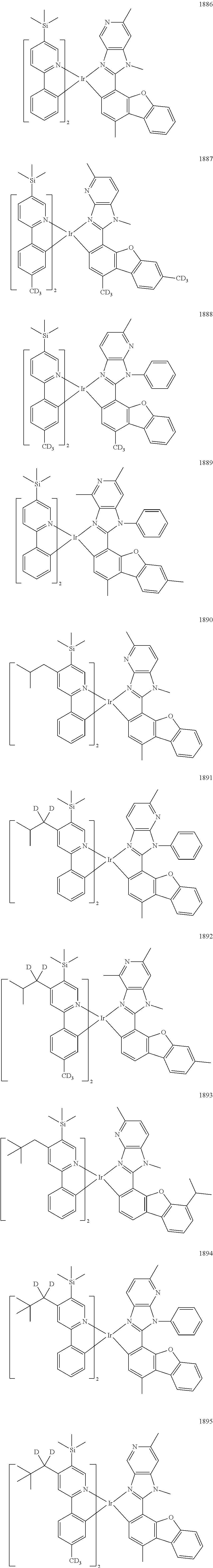

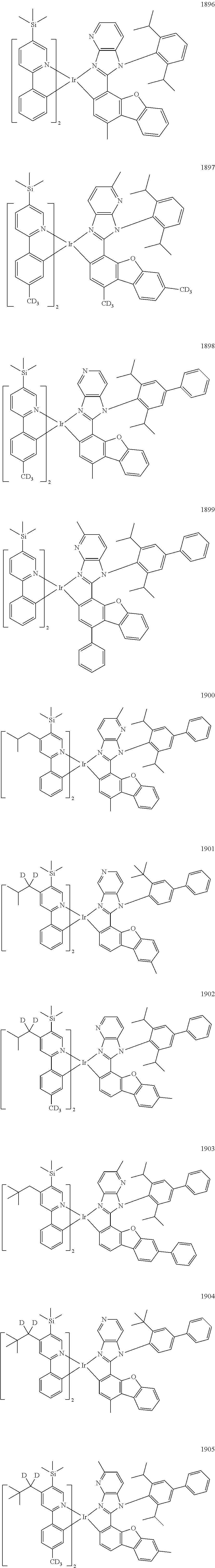

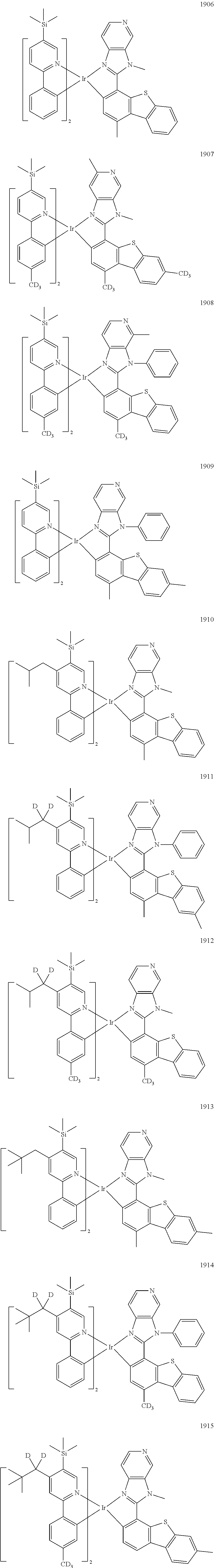

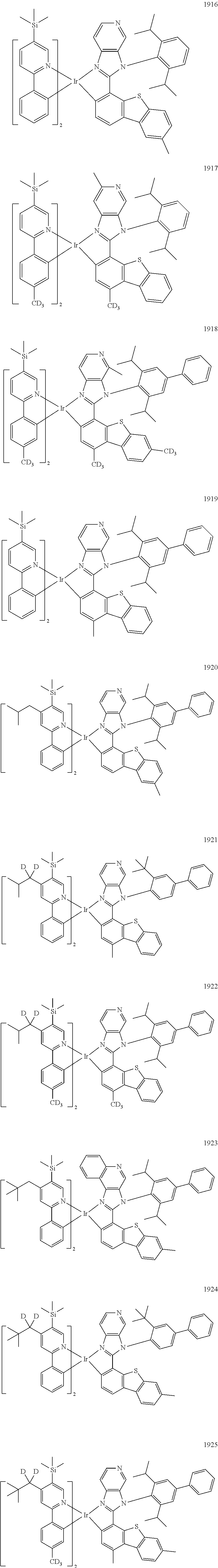

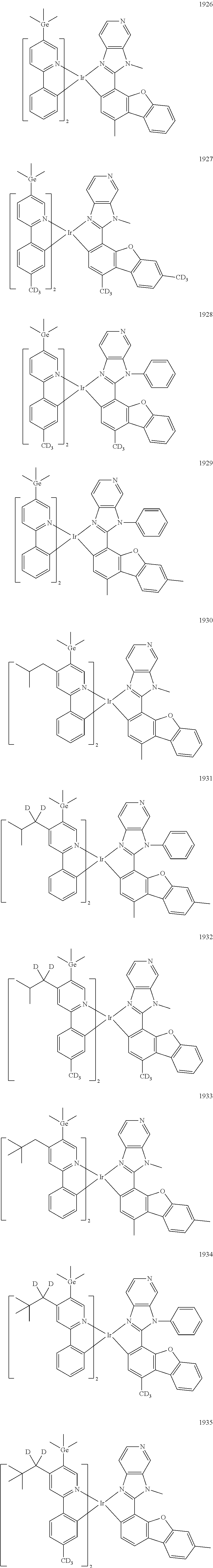

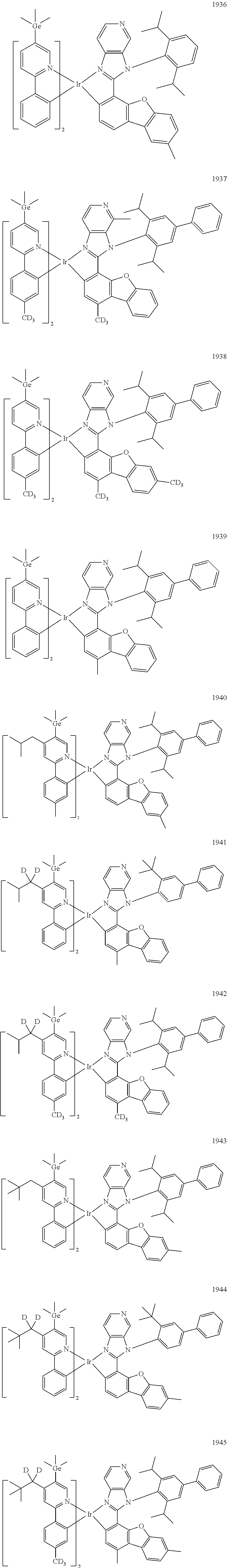

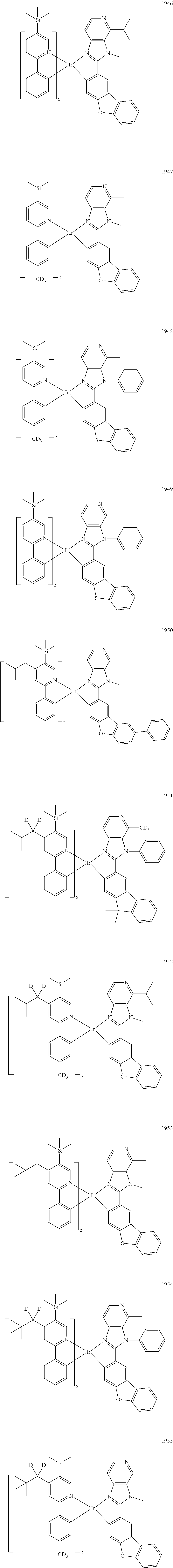

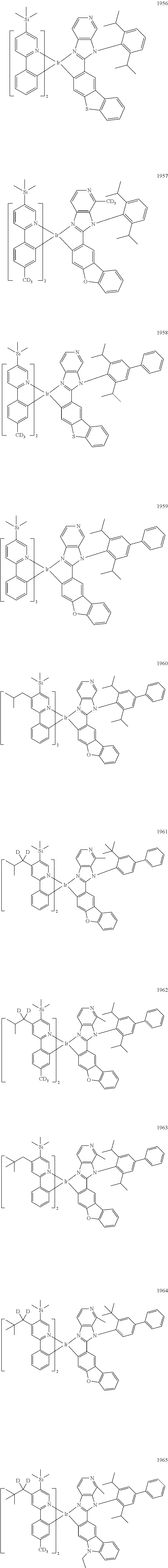

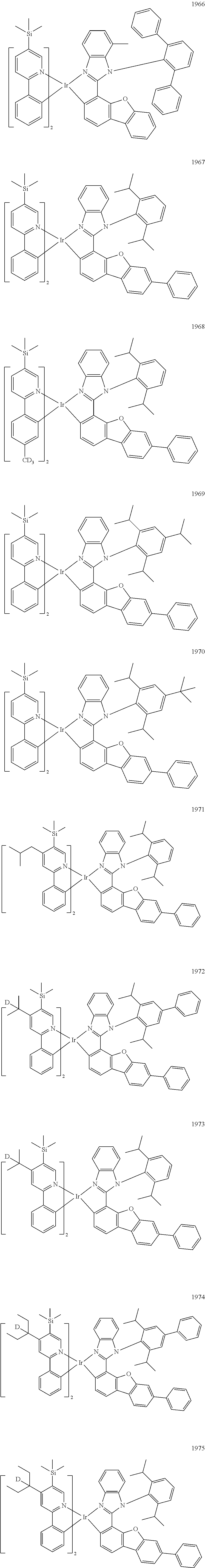

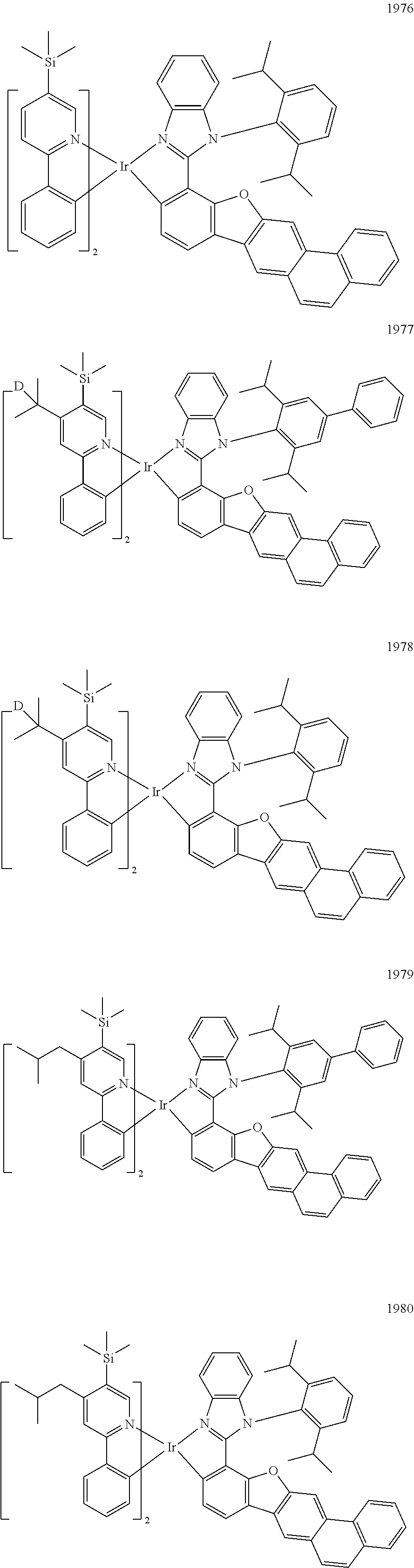

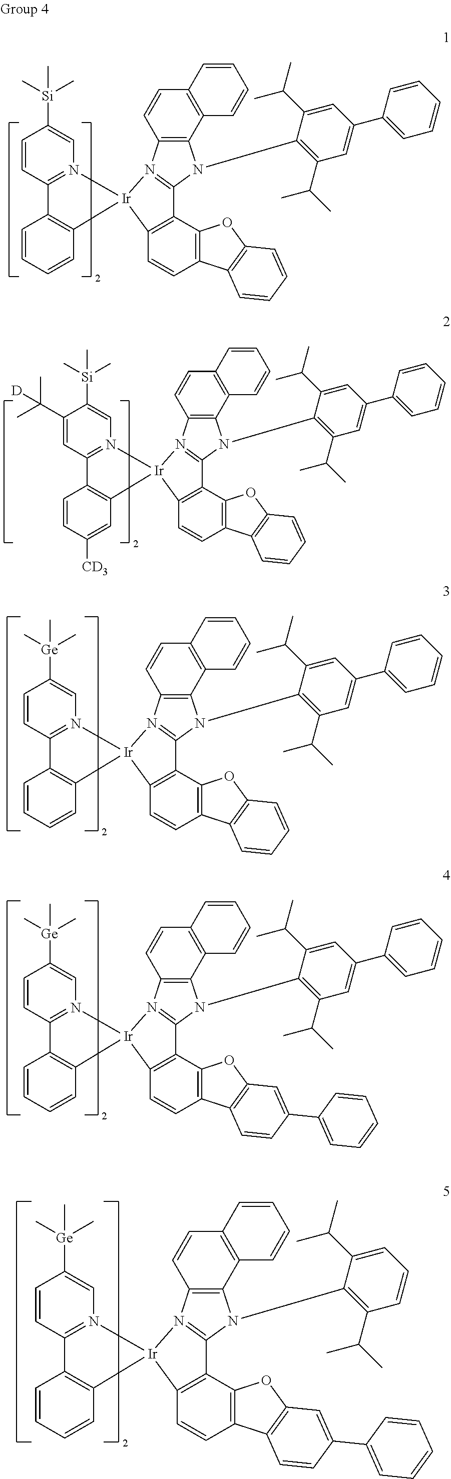

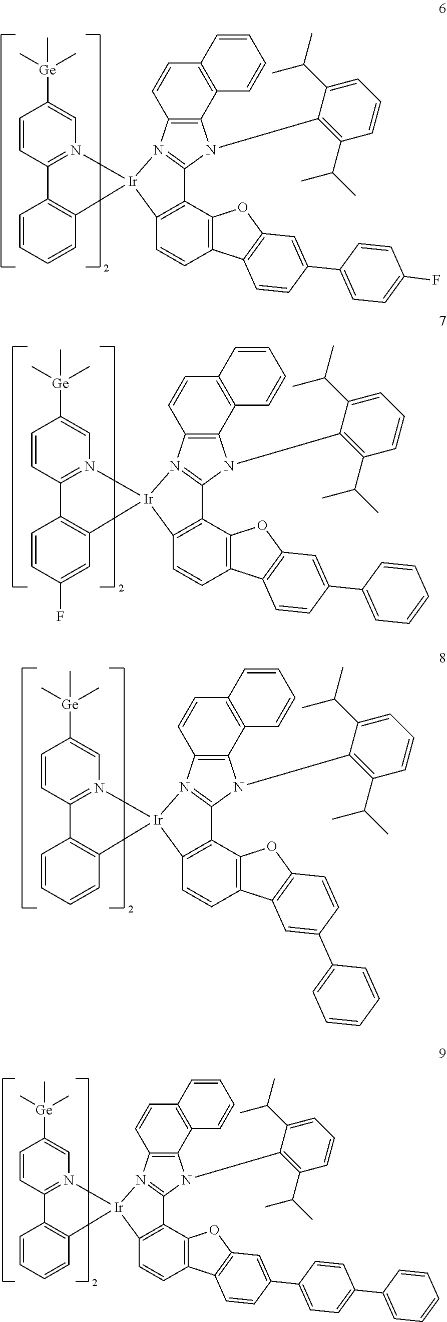

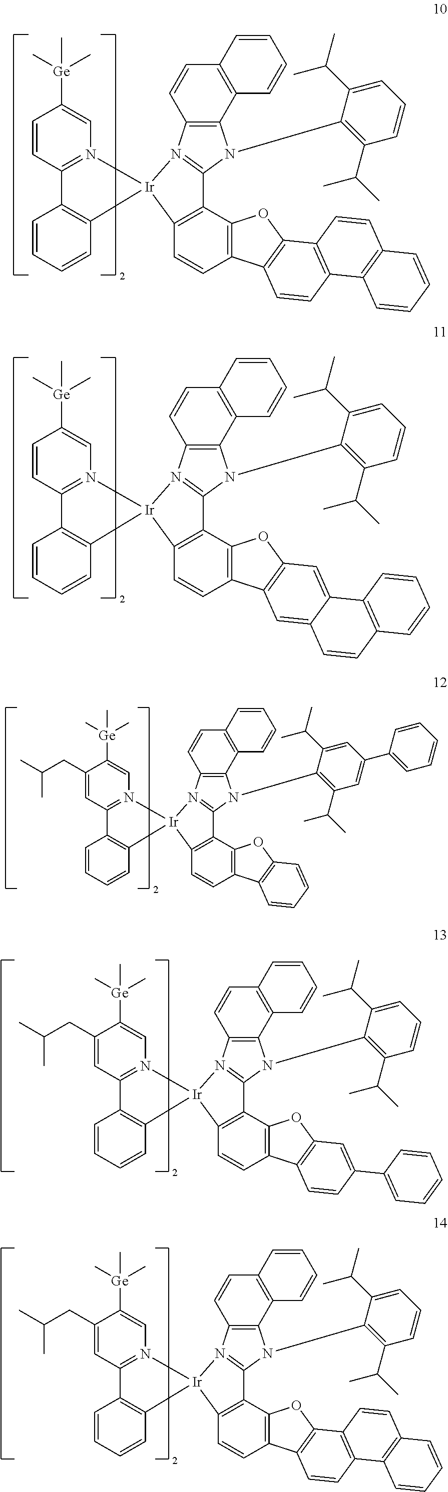

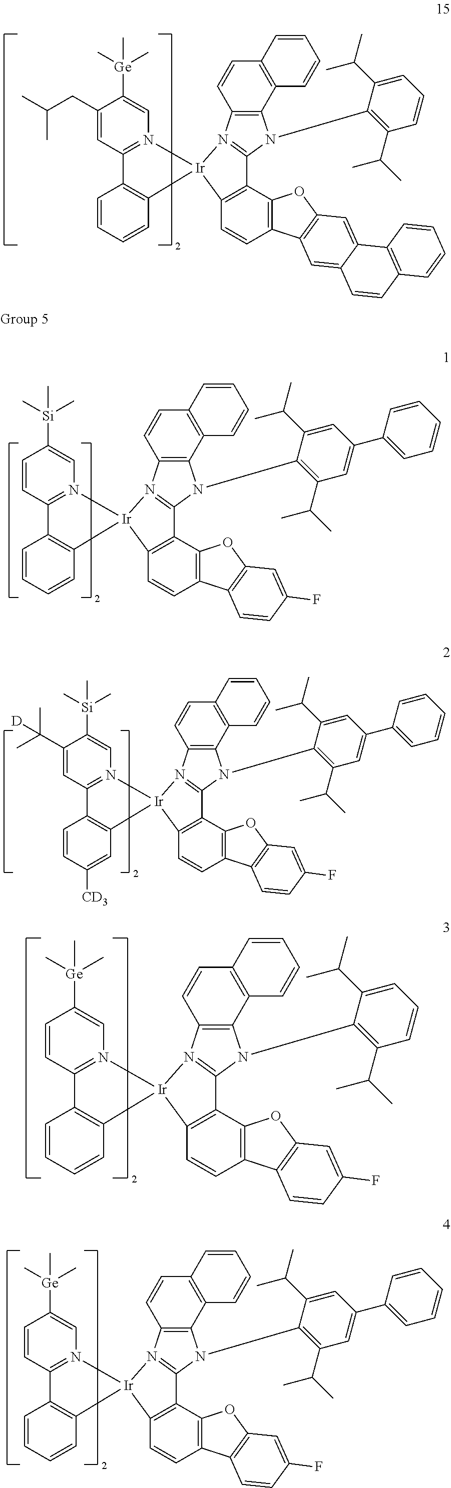

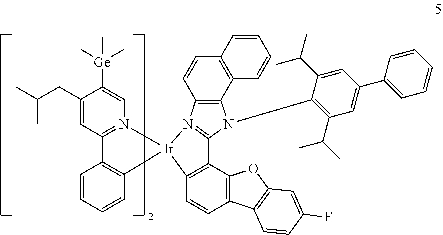

The green emission unit 30a of the OLED substrate 101 including the organometallic compound represented by Formula 1 may emit green light having a maximum emission wavelength in a range of about 500 nm to about 550 nm, for example, about 515 nm to about 530 nm, and a full width at half maximum (FWHM) (at photoluminescence (PL) spectrum) of 70 nm or lower, for example, 60 nm or lower.

The term “C₁-C₆₀ alkyl group” as used herein refers to a linear or branched saturated aliphatic hydrocarbon monovalent group having 1 to 60 carbon atoms, and non-limiting examples thereof include a methyl group, an ethyl group, a propyl group, an iso-butyl group, a sec-butyl group, a tert-butyl group, a pentyl group, an iso-amyl group, and a hexyl group. The term “C₁-C₆₀ alkylene group” as used herein refers to a divalent group having the same structure as the C₁-C₆₀ alkyl group.

The term “C₁-C₆₀ alkoxy group” as used herein refers to a monovalent group represented by -OA₁₀₁ (wherein A₁₀₁ is the C₁-C₆₀ alkyl group), and non-limiting examples thereof include a methoxy group, an ethoxy group, and an iso-propyloxy group.

The term “C₁-C₆₀ alkylthio group” as used herein refers to a monovalent group represented by -SA₁₀₂ (wherein A₁₀₂ is the C₁-C₆₀ alkyl group), and non-limiting examples thereof include a methylthio group, an ethylthio group, and an iso-propylthio group.

The term “C₁-C₆₀ aryloxy group” as used herein refers to a monovalent group represented by -OA₁₀₃ (wherein A₁₃₁ is the C₆-C₆₀ aryl group), and non-limiting examples thereof include a phenoxy group and a naphthoxy group.

The term “C₁-C₆₀ arylthio group” as used herein refers to a monovalent group represented by -SA₁₀₄ (wherein A₁₀₄ is the C₆-C₆₀ aryl group), and non-limiting examples thereof include a phenylthiol group and a naphthylthio group.

The term “C₂-C₆₀ alkenyl group” as used herein refers to a hydrocarbon group formed by including at least one carbon-carbon double bond in the middle or at the terminus of the C₂-C₆₀ alkyl group, and examples thereof include an ethenyl group, a propenyl group, and a butenyl group. The term “C₂-C₆₀ alkenylene group” as used herein refers to a divalent group having the same structure as the C₂-C₆₀ alkenyl group.

The term “C₂-C₆₀ alkynyl group” as used herein refers to a hydrocarbon group formed by including at least one carbon-carbon triple bond in the middle or at the terminus of the C₂-C₆₀ alkyl group, and examples thereof include an ethynyl group, and a propynyl group. The term “C₂-C₆₀ alkynylene group” as used herein refers to a divalent group having the same structure as the C₂-C₆₀ alkynyl group.

The term “C₃-C₁₀ cycloalkyl group” as used herein refers to a monovalent saturated hydrocarbon monocyclic group having 3 to 10 carbon atoms, and non-limiting examples thereof include a cyclopropyl group, a cyclobutyl group, a cyclopentyl group, a cyclohexyl group, and a cycloheptyl group. The term “C₃-C₁₀ cycloalkylene group” as used herein refers to a divalent group having the same structure as the C₃-C₁₀ cycloalkyl group.

The term “a (C₁-C₂₀ alkyl)C₃-C₁₀ cycloalkyl group” as used herein refers to a monovalent saturated hydrocarbon monocyclic group having 3 to 10 carbon atoms attached to an alkylene group. A non-limiting example includes a —CH₂-cyclopropyl group.

The term “C₁-C₁₀ heterocycloalkyl group” as used herein refers to a monovalent saturated monocyclic group having at least one heteroatom selected from N, O, P, Si and S as a ring-forming atom and 1 to 10 carbon atoms, and non-limiting examples thereof include a tetrahydrofuranyl group, and a tetrahydrothiophenyl group. The term “C₁-C₁₀ heterocycloalkylene group” as used herein refers to a divalent group having the same structure as the C₁-C₁₀ heterocycloalkyl group.

The term “(C₁-C₂₀ alkyl)C₁-C₁₀ heterocycloalkyl group” as used herein refers to a monovalent saturated monocyclic group having at least one heteroatom selected from N, O, P, Si and S as a ring-forming atom and 1 to 10 carbon atoms attached to an alkylene group. A non-limiting example includes a —CH₂— tetrahydrofuranyl group. The term “C₃-C₁₀ cycloalkenyl group” as used herein refers to a monovalent monocyclic group that has 3 to 10 carbon atoms and at least one carbon-carbon double bond in the ring thereof and that has no aromaticity, and non-limiting examples thereof include a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₁C₁₀ heterocycloalkenyl group” as used herein refers to a monovalent monocyclic group that has at least one heteroatom selected from N, O, P, Si, and S as a ring-forming atom, 1 to 10 carbon atoms, and at least one carbon-carbon double bond in its ring. Examples of the C₁-C₁₀ heterocycloalkenyl group are a 2,3-dihydrofuranyl group, and a 2,3-dihydrothiophenyl group. The term “C₁-C₁₀ heterocycloalkenylene group” as used herein refers to a divalent group having the same structure as the C₁-C₁₀ heterocycloalkenyl group. The term “C₆-C₆₀ aryl group” as used herein refers to a monovalent group having a carbocyclic aromatic system having 6 to 60 carbon atoms, and the term “C₆-C₆₀ arylene group” as used herein refers to a divalent group having a carbocyclic aromatic system having 6 to 60 carbon atoms. Non-limiting examples of the C₆-C₆₀ aryl group include a phenyl group, a naphthyl group, an anthracenyl group, a phenanthrenyl group, a pyrenyl group, and a chrysenyl group. When the C₆-C₆₀ aryl group and the C₆-C₆₀ arylene group each include two or more rings, the rings may be fused to each other. The term “C₇-C₆₀ alkylaryl group” as used herein refers to a C₆-C₆₀ aryl group substituted with at least one C₁-C₆₀ alkyl group.

The terms “a (C₁-C₂₀ alkyl)phenyl group” and “(C₁-C₂₀ alkyl)biphenyl group” refer to a monovalent phenyl group or biphenyl group, respectively, attached to an alkylene group. A non-limiting example of a (C₁-C₂₀ alkyl)phenyl group includes a —CH₂-phenyl group A non-limiting example of a (C₁-C₂₀ alkyl)biphenyl group includes a —CH₂-biphenyl group

The term “C₁-C₆₀ heteroaryl group” as used herein refers to a monovalent group having a carbocyclic aromatic system that has at least one heteroatom selected from N, O, P, Si, and S as a ring-forming atom, and 1 to 60 carbon atoms. The term “C₁-C₆₀ heteroarylene group” as used herein refers to a divalent group having a carbocyclic aromatic system that has at least one heteroatom selected from N, O, P, and S as a ring-forming atom, and 1 to 60 carbon atoms. Non-limiting examples of the C₁-C₆₀ heteroaryl group include a pyridinyl group, a pyrimidinyl group, a pyrazinyl group, a pyridazinyl group, a triazinyl group, a quinolinyl group, and an isoquinolinyl group. When the C₁-C₆₀ heteroaryl group and the C₁-C₆₀ heteroarylene group each include two or more rings, the rings may be fused to each other. The term “C₂-C₆₀ alkylheteroaryl group” refers to a C₁-C₆₀ heteroaryl group substituted with at least one C₁-C₆₀ alkyl group.

The term “C₆-C₆₀ aryloxy group” as used herein indicates -OA₁₀₂ (wherein A₁₀₂ is the C₆-C₆₀ aryl group), and the term a “C₆-C₆₀ arylthio group” as used herein indicates -SA₁₀₃ (wherein A₁₀₃ is the C₆-C₆₀ aryl group).

As used herein, the number of carbons in each group that is substituted (e.g., C₁-C₆₀) excludes the number of carbons in the substituent. For example, a C₁-C₆₀alkyl group can be substituted with a C₁-C₆₀ alkyl group. The total number of carbons included in the C₁-C₆₀ alkyl group substituted with the C₁-C₆₀ alkyl group is not limited to 60 carbons. In addition, more than one C₁-C₆₀ alkyl substituent may be present on the C₁-C₆₀ alkyl group. This definition is not limited to the C₁-C₆₀ alkyl group and applies to all substituted groups that recite a carbon range.

The term “monovalent non-aromatic condensed polycyclic group” as used herein refers to a monovalent group (for example, having 8 to 60 carbon atoms) having two or more rings condensed to each other, only carbon atoms as ring-forming atoms, and having no aromaticity in its entire molecular structure. Examples of the monovalent non-aromatic condensed polycyclic group include a fluorenyl group. The term “divalent non-aromatic condensed polycyclic group” as used herein refers to a divalent group having the same structure as the monovalent non-aromatic condensed polycyclic group.

The term “monovalent non-aromatic condensed heteropolycyclic group” as used herein refers to a monovalent group (for example, having 2 to 60 carbon atoms) having two or more rings condensed to each other, a heteroatom selected from N, O, P, Si, and S, other than carbon atoms, as a ring-forming atom, and no aromaticity in its entire molecular structure. Non-limiting examples of the monovalent non-aromatic condensed heteropolycyclic group include a carbazolyl group. The term “divalent non-aromatic condensed heteropolycyclic group” as used herein refers to a divalent group having the same structure as the monovalent non-aromatic condensed heteropolycyclic group.

### Examples

The maximum emission wavelength and FWHM as described above may be confirmed from Table 1 herein.

TABLE 1

| | | Maximum | |
|---|---|---|---|
| | | emission | |
| Film | | wavelength | FWHM |
| No. | Dopant | (nm) | (nm) |
| 1 | 125 of Group 1 | 523 | 53.2 |
| 2 | 1621 of Group 1 | 524 | 47.1 |
| 3 | 1 of Group 2 | 522 | 56.3 |
| 4 | 3 of Group 2 | 523 | 56.7 |
| 5 | 5 of Group 2 | 522 | 56.1 |
| 6 | 16 of Group 3 | 526 | 59.2 |
| 7 | 20 of Group 3 | 528 | 54.7 |
| 8 | 1966 of Group 3 | 524 | 52.4 |
| 9 | 1 of Group 4 | 522 | 57.0 |
| 10 | 670 of Group 3 | 527 | 56.7 |
| 11 | 2 of Group 4 | 523 | 55.3 |
| 12 | 1 of Group 5 | 522 | 56.9 |
| 13 | 2 of Group 5 | 523 | 56.8 |
| 14 | 1967 of Group 3 | 529 | 51.5 |
| 15 | 1968 of Group 3 | 530 | 52.4 |
| 16 | 1969 of Group 3 | 529 | 52.2 |
| 17 | 1970 of Group 3 | 529 | 52.6 |
| 18 | 1971 of Group 3 | 529 | 51.6 |

Films 1 to 18 in Table 1 each have a thickness of 50 nm. The films were prepared by co-depositing Compound H2-2, Compound H3-15, and each dopant in Table 1 at a weight ratio of 7.5:2.5:0.5 on a quartz substrate washed using chloroform and pure water. The maximum emission wavelength and FWHM in Table 1 were evaluated by measuring PL spectra of Films 1 to 18 by using an ISC PC1 spectrofluorometer, in which a xenon lamp is mounted.

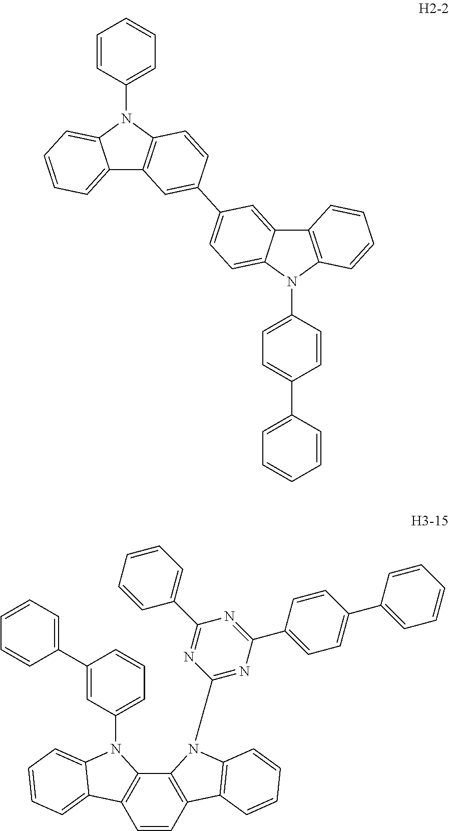 [SMILES: c1ccc(-c2ccc(-n3c4ccccc4c4cc(-c5ccc6c(c5)c5ccccc5n6-c5ccccc5)ccc43)cc2)cc1 ; c1ccc(-c2ccc(-c3nc(-c4ccccc4)nc(-n4c5ccccc5c5ccc6c7ccccc7n(-c7cccc(-c8ccccc8)c7)c6c54)n3)cc2)cc1]

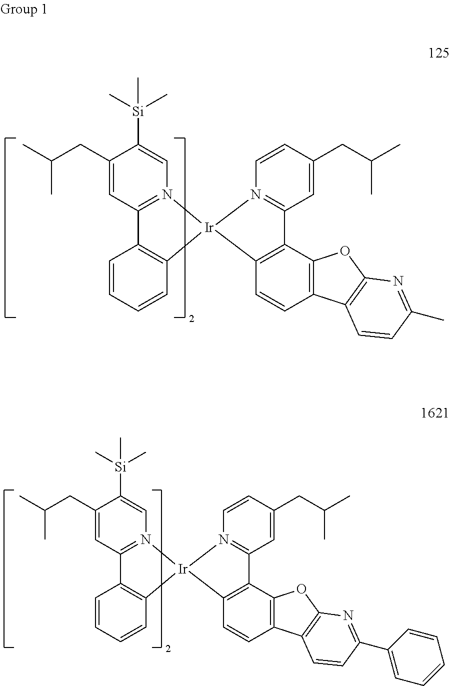

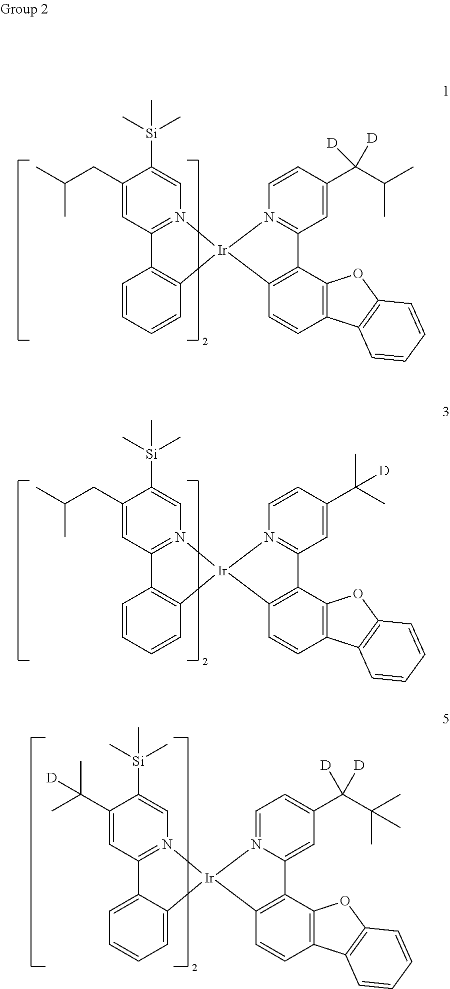

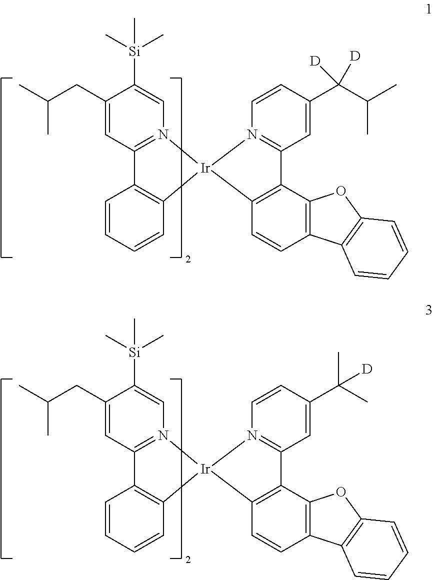

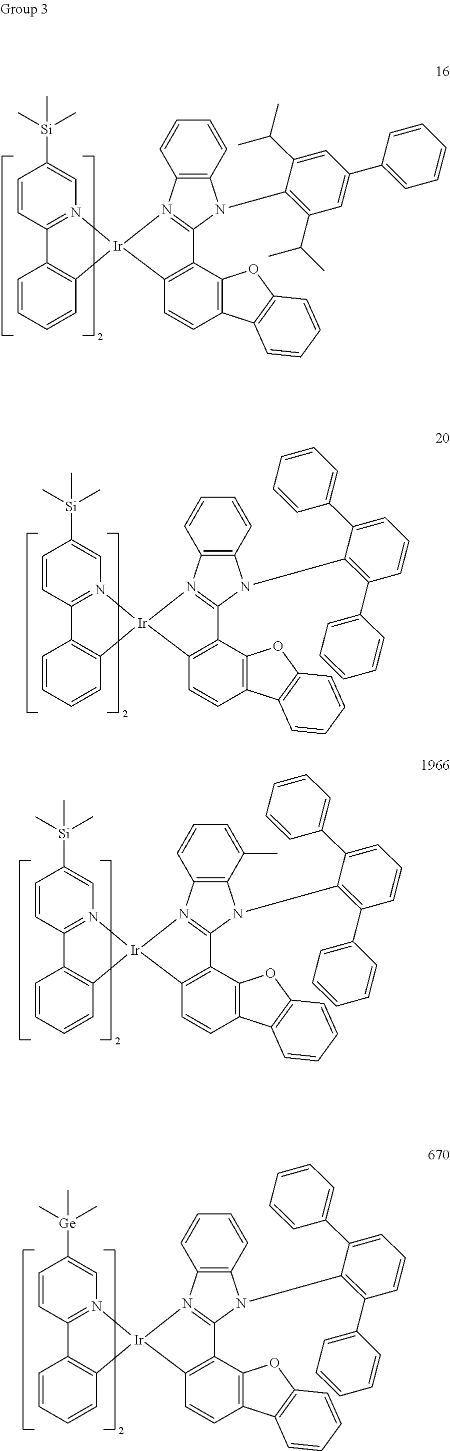

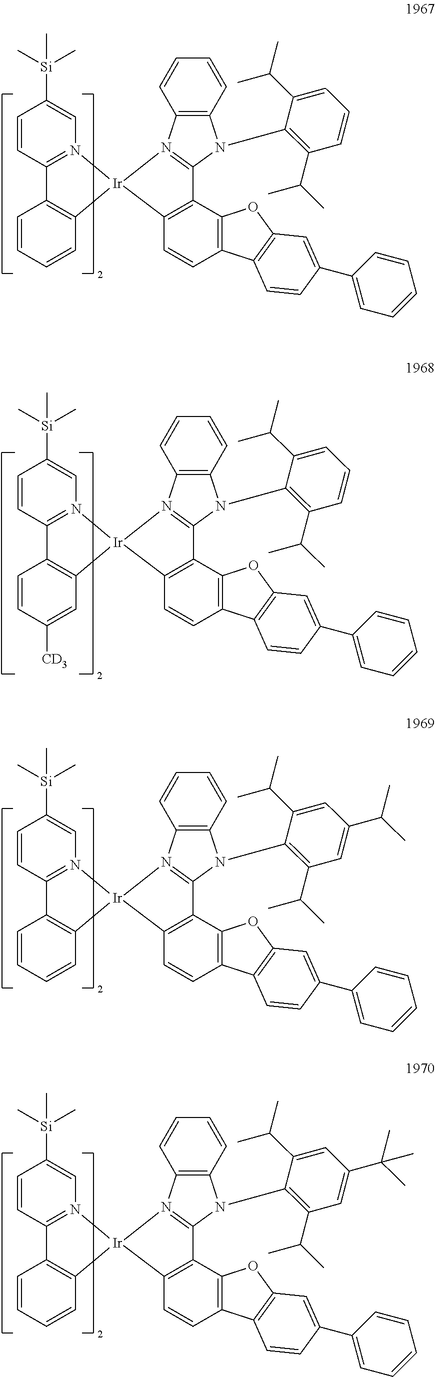

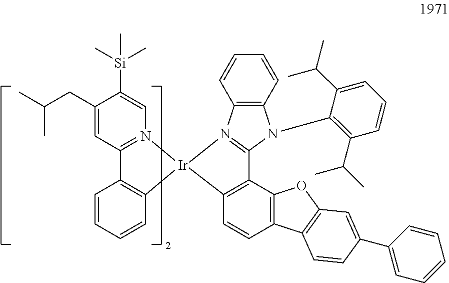

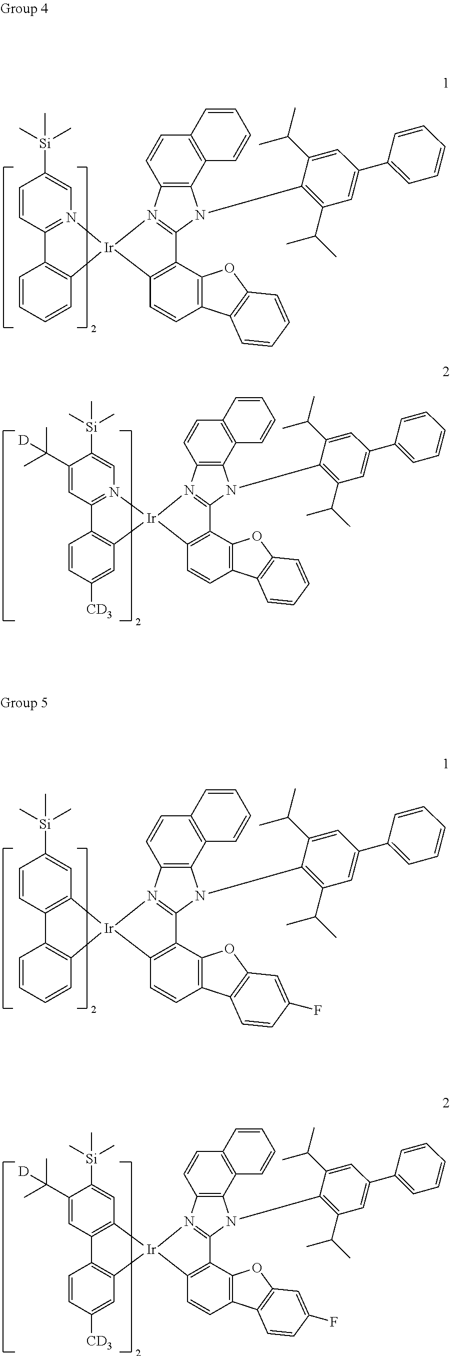

From Table 1, it is found that the organometallic compound represented by Formula 1 may emit green light having the maximum emission wavelength and FHWM as described above, and thus, when the organometallic compound represented by Formula 1 is used, a high-quality display apparatus may be realized.

Synthesis Example of Compound 125 of [Group 1] in Table 1 is as follows:

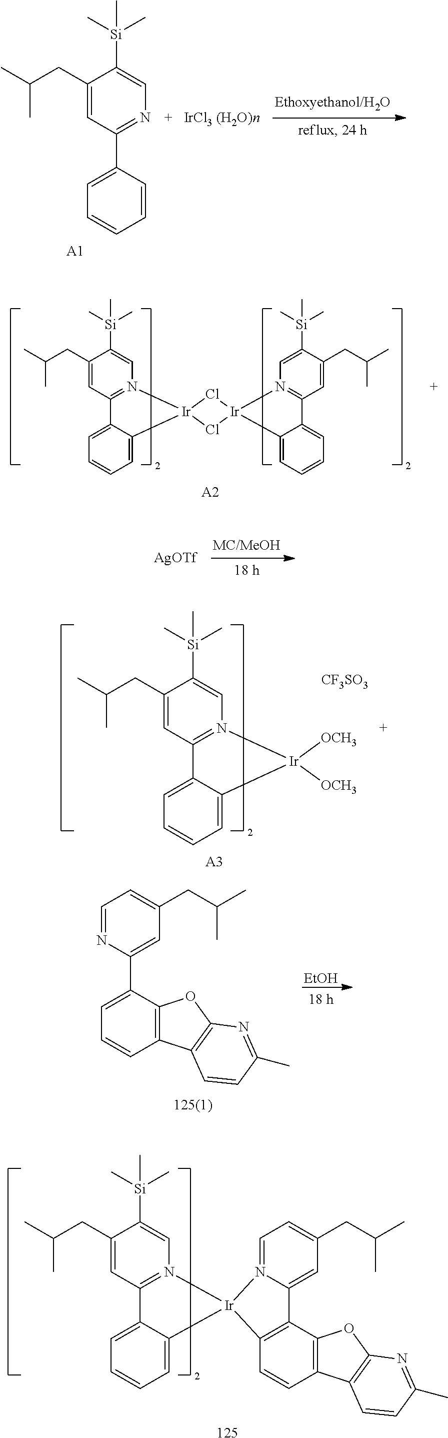

### Synthesis of Compound A2

7.9 grams (g) (27.8 mmol) of Compound A1 and 4.4 g (12.6 mmol) of iridium chloride were mixed with 120 milliliters (mL) of ethoxyethanol and 40 mL of distilled water. Then, the mixture was stirred under reflux for 24 hours, and then the temperature was dropped to room temperature. A solid was formed therefrom, and then separated by filtration. The solid was sufficiently washed with water, methanol, and hexane in the stated order, and dried in a vacuum oven to thereby obtain 7.6 g of Compound A2 (yield: 76%).

### Synthesis of Compound A3

3.3 g (2.1 mmol) of Compound A2 was mixed with 90 mL of methylene chloride, and a solution, in which 1.1 g (4.1 mmol) of AgOTf is dissolved in 30 mL of methanol, was added thereto. Then, the mixture was stirred for 18 hours at room temperature while blocking light by using an aluminum foil. The resultant was celite-filtered to remove a solid formed therefrom and filtered under reduced pressure to thereby obtain a solid (Compound A3). The solid was used in the following reaction without any further purification.

### Synthesis of Compound 125 of [Group 1]

4.0 g (4.1 mmol) of Compound A3 and 4.5 mmol of Compound 125(1) were mixed with 40 mL of ethanol and stirred under reflux for 18 hours, followed by lowering the temperature. The thus obtained mixture was under reduced pressure to obtain a solid which then was subjected to column chromatography (eluent: methylene chloride (MC) and hexane) to thereby obtain Compound 125 of [Group 1],

It may be understood by a person skilled in the art that other compounds in Table 1 can be synthesized by using the following compounds instead of Compound A1 and/or Compound 125(1), based on the above Synthesis Example:

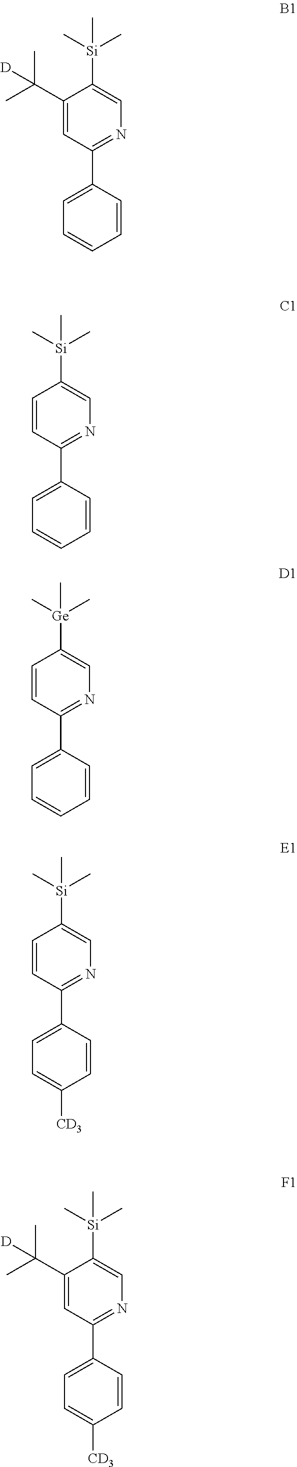

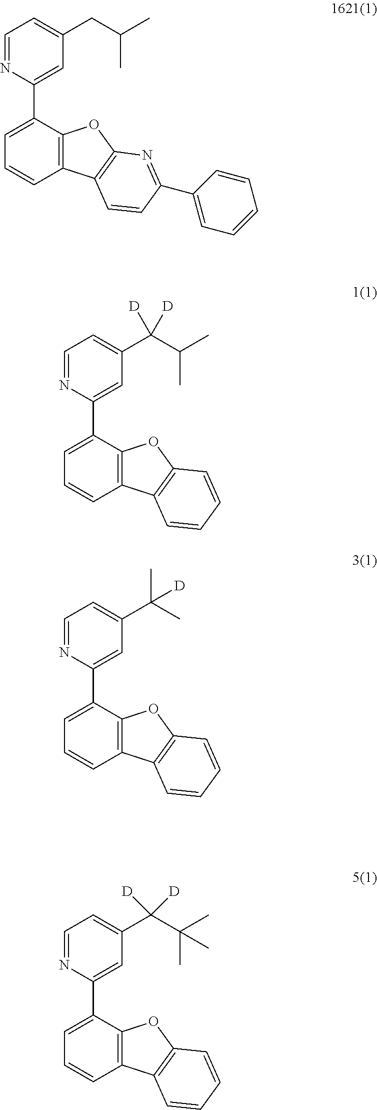

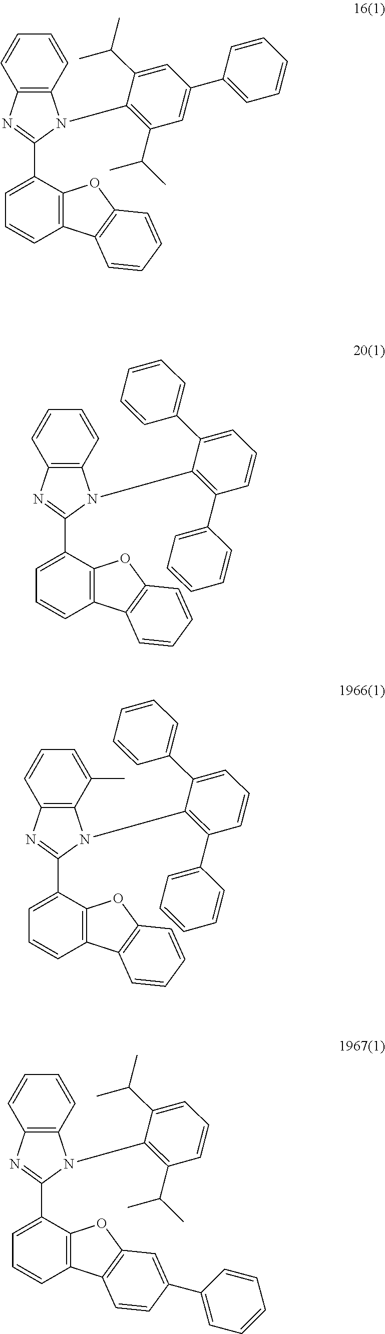 [SMILES: CC(C)c1cc(-c2ccccc2)cc(C(C)C)c1-n1c(-c2cccc3c2oc2ccccc23)nc2ccccc21 ; c1ccc(-c2cccc(-c3ccccc3)c2-n2c(-c3cccc4c3oc3ccccc34)nc3ccccc32)cc1 ; Cc1cccc2nc(-c3cccc4c3oc3ccccc34)n(-c3c(-c4ccccc4)cccc3-c3ccccc3)c12 ; CC(C)c1cccc(C(C)C)c1-n1c(-c2cccc3c2oc2cc(-c4ccccc4)ccc23)nc2ccccc21]

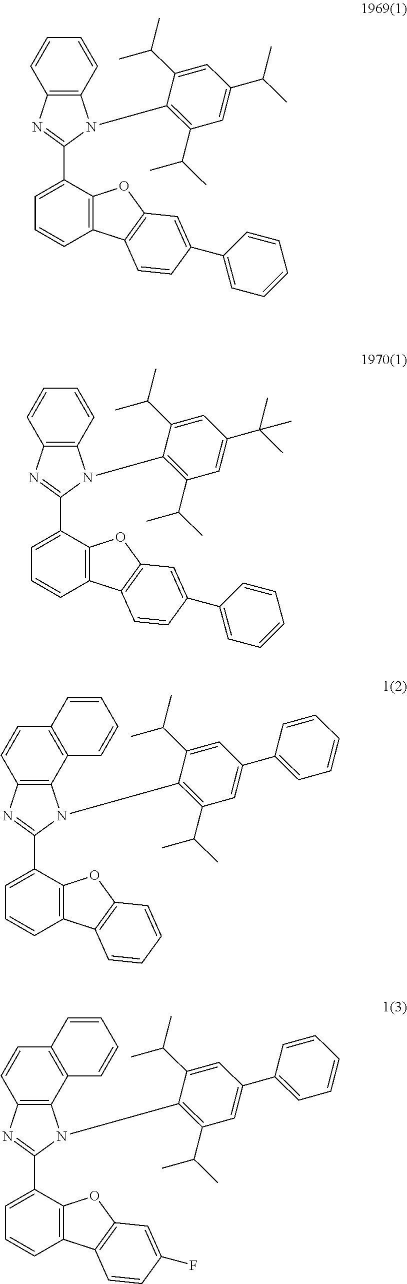 [SMILES: CC(C)c1cc(C(C)C)c(-n2c(-c3cccc4c3oc3cc(-c5ccccc5)ccc34)nc3ccccc32)c(C(C)C)c1 ; CC(C)c1cc(C(C)(C)C)cc(C(C)C)c1-n1c(-c2cccc3c2oc2cc(-c4ccccc4)ccc23)nc2ccccc21 ; CC(C)c1cc(-c2ccccc2)cc(C(C)C)c1-n1c(-c2cccc3c2oc2ccccc23)nc2ccc3ccccc3c21 ; CC(C)c1cc(-c2ccccc2)cc(C(C)C)c1-n1c(-c2cccc3c2oc2cc(F)ccc23)nc2ccc3ccccc3c21]

The display apparatus according to one or more embodiments described above may be applied to various electronic devices. For example, the display apparatus may be usefully applied to small-sized electronic devices such as portable devices and wearable devices, and medium- to large-sized electronic devices such as home appliances.

Although many features are specifically described in the above description, the description should be construed as examples of specific embodiments rather than limiting the scope of rights. For example, one of ordinary skill in the art would understand that the features and connection relationship between the OLED substrates, the color-controlling unit, and the display apparatus including and the OLED substrates and the color-controlling unit may be variously modified. Therefore, the scope of rights should not be determined by the described embodiments, but should be determined by the inventive concept described in the claims.

As apparent from the foregoing description, a display apparatus having high efficiency and excellent color characteristics may be realized. A display apparatus in which green light is applied to a light source OLED may be realized.

A display apparatus showing excellent performance in which green light and blue light is applied to a light source OLED, and a plurality of quantum dot color-conversion elements and a plurality of color filter elements are used.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
an organic light-emitting device (OLED) substrate comprising a structure in which at least one blue emission unit and at least one green emission unit are stacked and wherein the structure emits a mixture of blue light and green light; and
a color-controlling unit on the OLED substrate for controlling color of light generated from the OLED substrate,
wherein the color-controlling unit comprises a first color-controlling element comprising a first quantum dot for green color conversion, a second color-controlling element comprising a second quantum dot for red color conversion, a third color-controlling element for blue light emission, a first color filter located on the first color-controlling element, and a second color filter located on the second color-controlling element,
wherein the at least one of the at least one green emission unit of the OLED substrate comprises an organometallic compound represented by Formula 1:
M(L₁)ₙ₁(L₂)ₙ₂ Formula 1
wherein, in Formula 1,
M is a transition metal,
L₁ is a ligand represented by Formula 2A,
n1 is 1, 2, or 3, and when n1 is 2 or greater, at least two L₁(s) are identical to or different from each other,
L₂ is an organic ligand,
n2 is 0, 1, or 2, and when n2 is 2, two L₂(s) are identical to or different from each other,
the sum of n1 and n2 is 2 or 3, and
L₁ is different from L₂,
Formula 2A 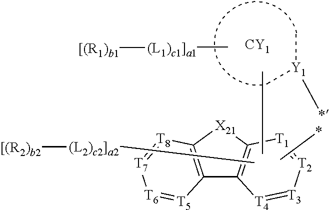
wherein, in Formula 2A,
Y₁ is C or N,
ring CY₁ is a C₅-C₃₀ carbocyclic group or a C₁-C₃₀ heterocyclic group,
X₂₁ is O, S, S(═O), Se, N(R₂₉), C(R₂₉)(R₃₀), or Si(R₂₉)(R₃₀),
T₁ to T₄ are each independently a carbon atom not bound to ring CY₁, or M in Formula 1, N, a carbon atom bound to ring CY₁, or a carbon atom bound to M in Formula 1, one of Ti to T₄ is a carbon atom bound to M in Formula 1, another one of T₁ to T₄, which is not bound to bound to M, is a carbon atom bound to ring CY₁,
T₅ to T₈ are each independently C or N,
L₁ and L₂ are each independently a single bond, a C₅-C₃₀ carbocyclic group unsubstituted or substituted with at least one R₁₀ₐ, or a C₁-C₃₀ heterocyclic group unsubstituted or substituted with at least one R₁₀ₐ,
c1 and c2 are each independently an integer from 1 to 5,
R₁, R₂, R₂₉, and R₃₀ are each independently hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₁-C₆₀ alkylthio group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed hetero polycyclic group, —N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉),
b1 and b2 are each independently an integer from 0 to 20,
a1 is an integer from 0 to 20, and when a1 is 2 or greater, at least two groups represented by *-[(L₁)_{c1}-(R₁)_{b1}] are identical to or different from each other,
a2 is an integer from 0 to 6, and when a2 is 2 or greater, at least two groups represented by *-[(L₂)_{c2}-(R₂)_{b2}] are identical to or different from each other,
at least two of a plurality of R₁(s) are optionally bound to each other to form a C₅-C₃₀ carbocyclic group unsubstituted or substituted with at least one R₁₀ₐ or a C₁-C₃₀ heterocyclic group unsubstituted or substituted with at least one R₁₀ₐ,
at least two of a plurality of R₂(s) are optionally bound to each other to form a C₅-C₃₀ carbocyclic group unsubstituted or substituted with at least one R₁₀ₐ or a C₁-C₃₀ heterocyclic group unsubstituted or substituted with at least one R₁₀ₐ,
at least two of R₁, R₂, R₂₉, and R₃₀ are optionally bound to form a C₅-C₃₀ carbocyclic group unsubstituted or substituted with at least one R₁₀ₐ or a C₁-C₃₀ heterocyclic group unsubstituted or substituted with at least one R₁₀ₐ,
R₁₀ₐ is understood by referring to the description of R₁ provided herein,
and *′ in Formula 2A each indicate a binding site to M in Formula 1, and
a substituent of the substituted C₁-C₆₀ alkyl group, the substituted C₂-C₆₀ alkenyl group, the substituted C₂-C₆₀ alkynyl group, the substituted C₁-C₆₀ alkoxy group, the substituted C₁-C₆₀ alkylthio group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, and the substituted monovalent non-aromatic condensed heteropolycyclic group is:
deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, or a C₁-C₆₀ alkylthio group;
a C₁-C₆₀ alkyl group, a C₂-C₆₀ alkenyl group, a C₂-C₆₀ alkynyl group, a C₁-C₆₀ alkoxy group, or a C₁-C₆₀ alkylthio group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₁₈)(Q₁₉), —P(Q₁₈)(Q₁₉), or any combination thereof;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₁-C₆₀ alkylthio group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), —P(Q₂₈)(Q₂₉), or any combination thereof;
—N(Q₃₁)(Q₃₂), —Si(Q₃₃)(Q₃₄)(Q₃₅), —Ge(Q₃₃)(Q₃₄)(Q₃₅), —B(Q₃₆)(Q₃₇), —P(═O)(Q₃₈)(Q₃₉), or —P(Q₃₈)(Q₃₉); or
any combination thereof,
wherein Q₁ to Q₉, Q₁₁ to Q₁₉, Q₂₁ to Q₂₉ and Q₃₁ to Q₃₉ are each independently: hydrogen; deuterium; —F; —Cl; —Br; —I; a hydroxyl group; a cyano group; a nitro group; an amino group; an amidino group; a hydrazine group; a hydrazone group; a carboxylic acid group or a salt thereof; a sulfonic acid group or a salt thereof; a phosphoric acid group or a salt thereof; a C₁-C₆₀ alkyl group unsubstituted or substituted with deuterium, a C₁-C₆₀ alkyl group, a C₆-C₆₀ aryl group, or any combination thereof; a C₂-C₆₀ alkenyl group; a C₂-C₆₀ alkynyl group; a C₁-C₆₀ alkoxy group; a C₁-C₆₀ alkylthio group; a C₃-C₁₀ cycloalkyl group; a C₁-C₁₀ heterocycloalkyl group; a C₃-C₁₀ cycloalkenyl group; a C₁-C₁₀ heterocycloalkenyl group; a C₆-C₆₀ aryl group unsubstituted or substituted with deuterium, a C₁-C₆₀ alkyl group, a C₆-C₆₀ aryl group, or any combination thereof; a C₆-C₆₀ aryloxy group; a C₆-C₆₀ arylthio group; a C₁-C₆₀ heteroaryl group; a monovalent non-aromatic condensed polycyclic group; or a monovalent non-aromatic condensed heteropolycyclic group.

2. The display apparatus of claim 1, wherein the OLED substrate has a tandem structure.

3. The display apparatus of claim 1, wherein the OLED substrate comprises a first blue emission unit, a green emission unit, and a second blue emission unit, which are sequentially stacked, and the green emission unit is located between the first and the second blue emission units.

4. The display apparatus of claim 3, further comprising: a first charge-generation layer located between the first blue emission unit and the green emission unit; and a second charge-generation layer located between the green emission unit and the second blue emission unit.

5. The display apparatus of claim 1, wherein, Y₁ in Formula 2A is N, and ring CY₁ in Formula 2A is:
a pyridine group, a pyrimidine group, a quinoline group, an isoquinoline group, a benzoquinoline group, a benzoisoquinoline group, an imidazole group, a benzimidazole group, a naphthoimidazole group, a pyridoimidazole group, or a pyrimidoimidazole group; or
a pyridine group, a pyrimidine group, a quinoline group, an isoquinoline group, a benzoquinoline group, a benzoisoquinoline group, an imidazole group, a benzimidazole group, a naphthoimidazole group, a pyridoimidazole group, or a pyrimidoimidazole group, each condensed with a cyclohexane group, a cyclohexene group, a norbornane group, or any combination thereof.

6. The display apparatus of claim 1, wherein, in Formula 2A, R₁, R₂, R₂₉, and R₃₀ are each independently:
hydrogen, deuterium, —F, or a cyano group;
a C₁-C₂₀ alkyl group unsubstituted or substituted with deuterium, —F, a cyano group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a C₁-C₁₀ heterocycloalkyl group, a deuterated C₁-C₁₀ heterocycloalkyl group, a fluorinated Cr C₁₀ heterocycloalkyl group, a (C₁-C₂₀ alkyl)C₁-C₁₀ heterocycloalkyl group, a phenyl group, a deuterated phenyl group, a fluorinated a phenyl group, a (C₁-C₂₀ alkyl)phenyl group, a biphenyl group, a deuterated biphenyl group, a fluorinated biphenyl group, a (C₁-C₂₀ alkyl)biphenyl group, or any combination thereof;
a C₃-C₁₀ cycloalkyl group, a C₁-C₁₀ heterocycloalkyl group, a phenyl group, or a biphenyl group, each unsubstituted or substituted with deuterium, —F, a cyano group, a C₁-C₂₀ alkyl group, a deuterated C₁-C₂₀ alkyl group, a fluorinated C₁-C₂₀ alkyl group, a C₁-C₂₀ alkoxy group, a deuterated C₁-C₂₀ alkoxy group, a fluorinated C₁-C₂₀ alkoxy group, a C₃-C₁₀ cycloalkyl group, a deuterated C₃-C₁₀ cycloalkyl group, a fluorinated C₃-C₁₀ cycloalkyl group, a (C₁-C₂₀ alkyl)C₃-C₁₀ cycloalkyl group, a C₁-C₁₀ heterocycloalkyl group, a deuterated C₁-C₁₀ heterocycloalkyl group, a fluorinated Cr C₁₀ heterocycloalkyl group, a (C₁-C₂₀ alkyl)C₁-C₁₀ heterocycloalkyl group, a phenyl group, a deuterated phenyl group, a fluorinated a phenyl group, a (C₁-C₂₀ alkyl)phenyl group, a biphenyl group, a deuterated biphenyl group, a fluorinated a biphenyl group, a (C₁-C₂₀ alkyl)biphenyl group, or any combination thereof; or
—Si(Q₃)(Q₄)(Q₅) or —Ge(Q₃)(Q₄)(Q₅).

7. The display apparatus of claim 1, wherein a group represented by 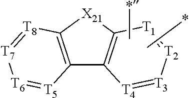
in Formula 2A is represented by one of Formulae CY2-1 to CY2-6: 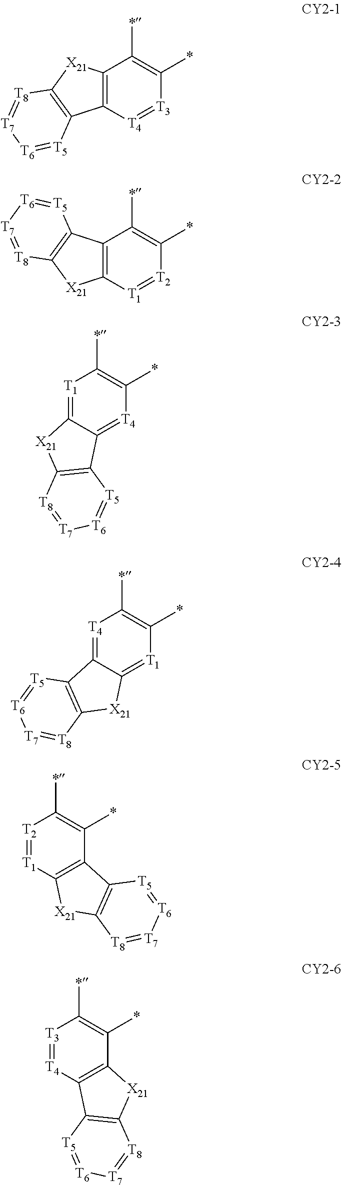
wherein, in Formulae CY2-1 to CY2-6,
T₁ to T₄ are each independently C or N,
X₂₁ and T₅ to T₈ are respectively understood by referring to the descriptions of X₂₁ and T₅ to T₈ in claim 1,
* indicates a binding site to M in Formula 1, and
*″ indicates a binding site to ring CY₁ in Formula 2A.

8. The display apparatus of claim 1, wherein L₂ in Formula 1 is represented by one of Formulae 3A to 3F: 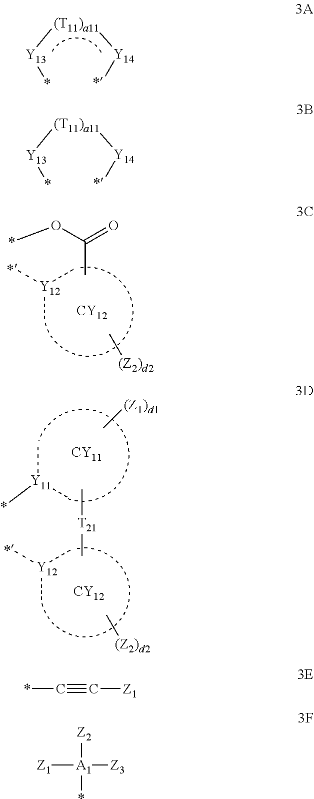
wherein in Formulae 3A to 3F,
Y₁₃ is O, N, N(Z₁), P(Z₁)(Z₂), or As(Z₁)(Z₂),
Y₁₄ is O, N, N(Z₃), P(Z₃)(Z₄), or As(Z₃)(Z₄),
T₁₁ is a single bond, a double bond, *—C(Z₁₁)(Z₁₂)—*′, *—C(Z₁₁)═C(Z₁₂)—*′, *═C(Z₁₁)—*′, *—C(Z₁₁)=*′, *═C(Z₁₁)—C(Z₁₂)═C(Z₁₃)—*′, *—C(Z₁₁)═C(Z₁₂)—C(Z₁₃)=*′, *—N(Z₁₁)—*′, or a C₅-C₃₀ carbocyclic group unsubstituted or substituted with at least one Z₁₁,
a11 is an integer from 1 to 10, and when a11 is 2 or greater, at least two T₁₁(s) are identical to or different from each other,
Y₁₁ and Y₁₂ are each independently C or N,
T₂₁ is a single bond, a double bond, O, S, C(Z₁₁)(Z₁₂), Si(Z₁₁)(Z₁₂), or N(Z₁₁),
ring CY₁₁ and ring CY₁₂ are each independently a C₅-C₃₀ carbocyclic group or a C₁-C₃₀ heterocyclic group,
A₁ is P or As,
Z₁ to Z₄ and Z₁₁ to Z₁₃ are each understood by referring to the descriptions of R₁ in claim 1,
d1 and d2 are each independently an integer from 0 to 20, and
* and *′ each indicate a binding site to M in Formula 1.

9. The display apparatus of claim 8, wherein a group represented by 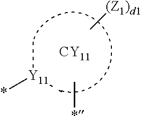
in Formula 3D is represented by one of Formulae CY11(1) to CY11(25): 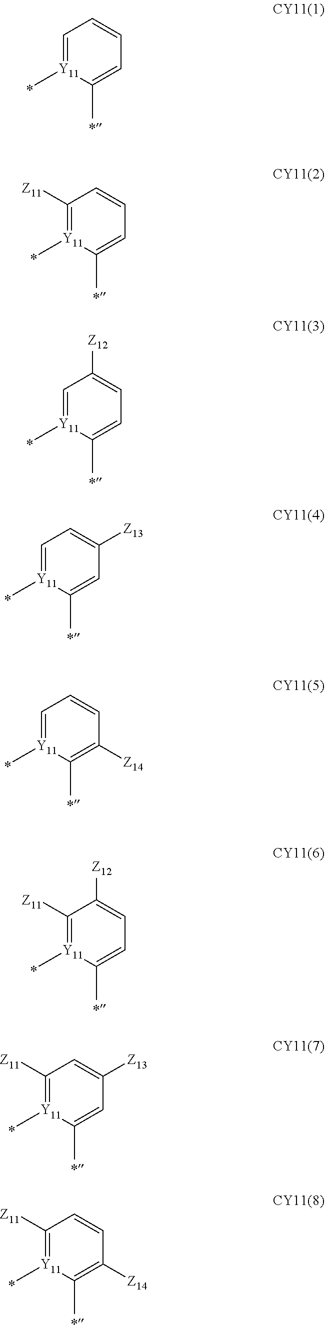 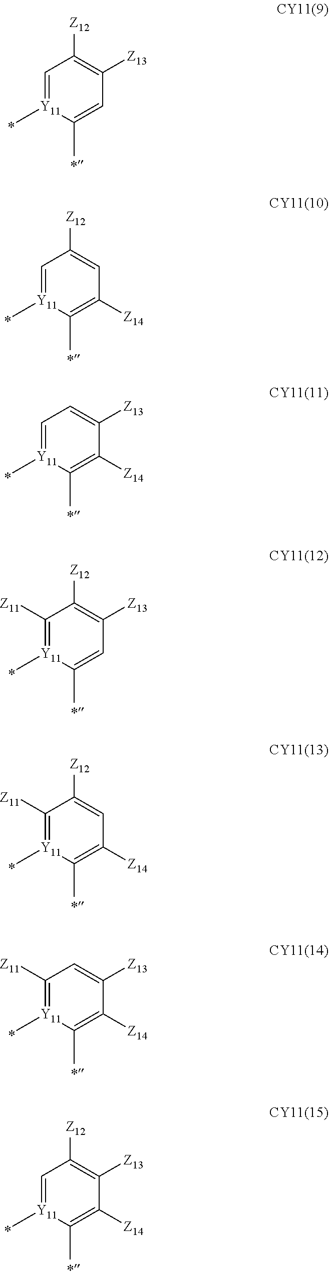 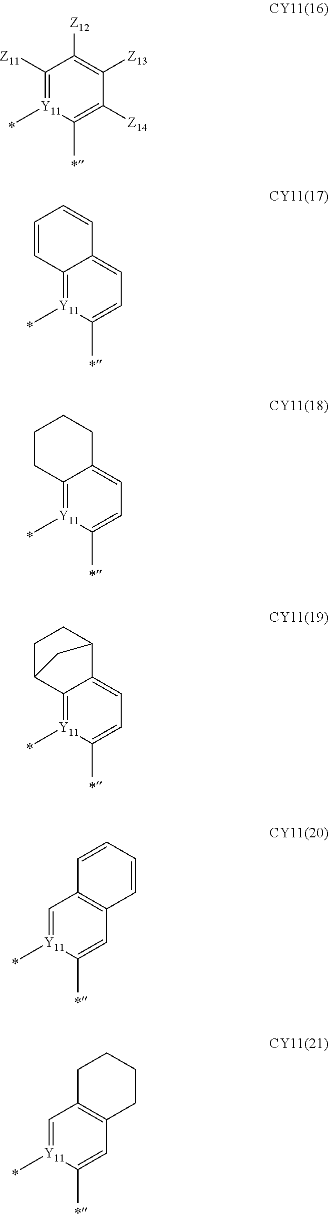 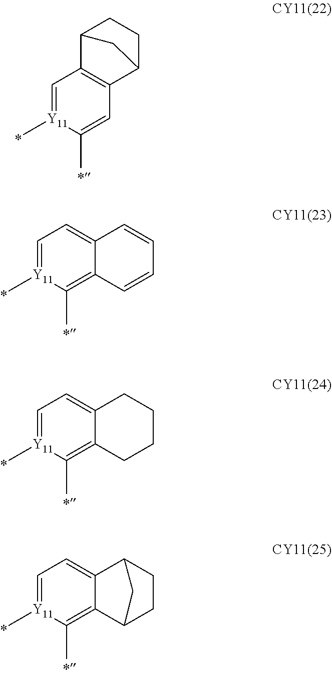
wherein, in Formulae CY11(1) to CY11(25),
X₁₁ is understood by referring to the description of X₁₁ in claim 8,
Z₁₁ to Z₁₄ are each understood by referring to the description of Z₁ in claim 8, wherein Z₁₁ to Z₁₄ are not each hydrogen,
* indicates a binding site to M in Formula 1, and
*″ indicates a binding site to T₂₁ in Formula 3D.

10. The display apparatus of claim 9, wherein Z₁₂ in Formulae CY11(3), CY11(6), CY11(9), CY11(10), CY11(12), CY11(13), CY11(15), and CY11(16) is represented by —Si(Q₃)(Q₄)(Q₅) or -Ge(Q₃)(Q₄)(Q₅).

11. The display apparatus of claim 1, wherein the first color filter is a blue cut filter, and the second color filter is a blue and green cut filter.

12. The display apparatus of claim 1, wherein the first color filter is an absorption-type green color filter, and the second color filter is an absorption-type red color filter.

13. The display apparatus of claim 1, wherein the third color-controlling element comprises a blue color filter, and the display apparatus further comprises a light-scattering element located between the blue color filter and the OLED substrate.

14. The display apparatus of claim 1, wherein the third color-controlling element comprises a color-conversion element comprising a third quantum dot for blue conversion, and the display apparatus further comprises a third color filter on the third color-controlling element.

15. The display apparatus of claim 14, wherein the third color filter is a green cut filter or an absorption-type blue color filter.

16. The display apparatus of claim 1, wherein a core portion of the second quantum dot is greater in size than a core portion of the first quantum dot.

17. The display apparatus of claim 1, wherein the first color-controlling element corresponds to a first sub-pixel region, the second color-controlling element corresponds to a second sub-pixel region, and the third color-controlling element corresponds to a third sub-pixel region, and
the display apparatus further comprises a fourth sub-pixel region, and the fourth sub-pixel region emits a color different from colors emitted from the first to third sub-pixel regions.

18. The display apparatus of claim 17, wherein the fourth sub-pixel region is a blank region not having a color-controlling element on the OLED substrate or a light-scattering element the OLED substrate.

19. The display apparatus of claim 1, wherein the display apparatus further comprises a thin-film transistor (TFT) array substrate comprising a plurality of TFTs for driving pixel regions on the OLED substrate.

20. An electronic apparatus comprising the display apparatus of claim 1.
